(19) United States
(12) Patent Application Publication
(10) Pub. No.: US 2025/0125273 A1
(43) Pub. Date: Apr. 17, 2025

(54) NON-VOLATILE FIELD PROGRAMMABLE MULTICHIP PACKAGE

(71) Applicant: iCometrue Company Ltd., Zhubei City (TW)

(72) Inventors: Mou-Shiung Lin, Hsinchu City (TW); Jin-Yuan Lee, Miaoli County (TW)

(21) Appl. No.: 18/964,442

(22) Filed: Dec. 1, 2024

Related U.S. Application Data
(63) Continuation-in-part of application No. 18/242,492, filed on Sep. 5, 2023.
Application No. 18/242,492 is a continuation-in-part of application No. 18/231,415, filed on Aug. 8, 2023.
(60) Provisional application No. 63/396,585, filed on Aug. 9, 2022.
(60) Provisional application No. 63/605,450, filed on Dec. 1, 2023.
(60) Provisional application No. 63/560,763, filed on Mar. 3, 2024.

(51) Int. Cl. H01L 23/538; H01L 23/00; H01L 25/18; H10B 80/00

(52) U.S. Cl. CPC H01L 23/5385; H01L 24/05; H01L 24/08; H01L 25/18; H01L 2224/05647; H01L 2224/08235; H10B 80/00

(57) ABSTRACT

A multi-chip package includes a ball-grid-array (BGA) substrate; a field-programmable-gate-array (FPGA) integrated-circuit (IC) chip over the ball-grid-array (BGA) substrate; a plurality of first metal bumps between the field-programmable-gate-array (FPGA) integrated-circuit (IC) chip and ball-grid-array (BGA) substrate, wherein each of the plurality of first metal bumps has a top end joining the field-programmable-gate-array (FPGA) integrated-circuit (IC) chip and a bottom end joining the ball-grid-array (BGA) substrate; a non-volatile-memory (NVM) integrated-circuit (IC) chip package over the ball-grid-array (BGA) substrate, wherein the non-volatile-memory (NVM) integrated-circuit (IC) chip package comprises a circuit substrate, a non-volatile-memory (NVM) integrated-circuit (IC) chip over and coupling to the circuit substrate and a plurality of second metal bumps under and on the circuit substrate and bonded to the ball-grid-array (BGA) substrate; and a plurality of tin-containing bumps under and on the ball-grid-array (BGA) substrate.

### PRIORITY CLAIM

This application is a continuation-in-part of application Ser. No. 18/242,492, filed Sep. 5, 2023, which is a continuation-in-part of application Ser. No. 18/231,415, filed Aug. 8, 2023, which claims priority benefits from U.S. provisional application No. 63/396,585, filed on Aug. 9, 2022 and entitled “NON-VOLATILE FIELD PROGRAMMABLE MULTICHIP PACKAGE”. This application claims priority benefits from U.S. provisional application No. 63/605,450, filed on Dec. 1, 2023 and entitled “NON-VOLATILE FIELD PROGRAMMABLE MULTICHIP PACKAGE” and U.S. provisional application No. 63/560,763, filed on Mar. 3, 2024 and entitled “NON-VOLATILE FIELD PROGRAMMABLE MULTICHIP PACKAGE”. The present application incorporates the foregoing disclosures herein by reference.

### FIELD OF THE DISCLOSURE

The present invention relates to a multi-chip package, and more particularly to a non-volatile field programmable multi-chip package.

### BRIEF DESCRIPTION OF THE RELATED ART

The Field Programmable Gate Array (FPGA) semiconductor integrated circuit (IC) has been used for development of new or innovated applications, or for small volume applications or business demands. When an application or business demand expands to a certain volume and extends to a certain time period, the semiconductor IC supplier may usually implement the application in an Application Specific IC (ASIC) chip, or a Customer-Owned Tooling (COT) IC chip. The switch from the FPGA design to the ASIC or COT design is because the current FPGA IC chip, for a given application and compared with an ASIC or COT chip, (1) has a larger semiconductor chip size, lower fabrication yield, and higher fabrication cost, (2) consumes more power, and (3) gives lower performance. When the semiconductor technology nodes or generations migrate, following the Moore's Law, to advanced nodes or generations (for example below 20 nm), the Non-Recurring Engineering (NRE) cost for designing an ASIC or COT chip increases greatly (more than US $5M or even exceeding US $10M, US $20M, US $50M or US $100M). The cost of a photo mask set for an ASIC or COT chip at the 16 nm technology node or generation may be over US $1M, US $2M, US $3M, or US $5M. The high NRE cost in implementing the innovation and/or application using the advanced IC technology nodes or generations slows down or even stops the innovation and/or application using advanced and powerful semiconductor technology nodes or generations. A new approach or technology is needed to inspire the continuing innovation and to lower down the barrier for implementing the innovation in the semiconductor IC chips using the advanced and powerful semiconductor technology nodes or generations.

### SUMMARY OF THE DISCLOSURE

One aspect of the disclosure provides a multichip package, logic package, logic package drive, logic device, logic module, logic drive, logic disk, logic storage, logic storage drive, logic disk drive, logic solid-state disk, logic solid-state drive, Field Programmable Gate Array (FPGA) logic disk, or FPGA logic drive (to be abbreviated as “logic drive” or “logic storage” below, that is when “logic drive” is mentioned below, it means and reads as “multichip package, logic package, logic package drive, logic device, logic module, logic drive, logic disk, logic disk drive, logic storage, logic storage drive, logic solid-state disk, logic solid-state drive, FPGA logic disk, or FPGA logic drive”) comprising plural FPGA IC chips for field programming purposes. The logic drive is a standardized commodity device or product formed by a multichip packaging method using one or a plurality of standardized commodity FPGA IC chips, one or a plurality of non-volatile memory IC chips, one or a plurality of volatile memory IC chips, one or a plurality of computing and/or processing logic IC chips, and/or one or a plurality of cooperating or supporting (CS) logic IC chips. The logic drive is to be used for different specific applications when field programmed or user programmed. The abbreviated “logic drive” may be alternatively referred to as “logic storage”, or “logic storage drive”.

Another aspect of the disclosure provides a standardized commodity logic drive in a multichip package comprising one or a plurality of standardized commodity FPGA IC chips and one or a plurality of non-volatile memory IC chips for use in different algorithms, architectures and/or applications requiring logic, computing and/or processing functions by field programming, wherein data stored in the one or a plurality of non-volatile memory IC chips are used for configuring the one or a plurality of standardized commodity FPGA IC chips in the same multichip package. Uses of the standardized commodity logic drive is analogues to uses of a standardized commodity data storage device or drive, for example, solid-state disk (drive), data storage hard disk (drive), data storage floppy disk, Universal Serial Bus (USB) flash drive, USB drive, USB stick, flash-disk, or USB memory, and differs in that the latter has memory functions for data storage, while the former has logic functions for processing and/or computing. The multichip package may be in a 2D planar format with IC chips disposed on the same horizontal plane or in a 3D stacked format with chips stacked vertically with at least two stacking IC chips. The multichip package may be in a format with IC chips both disposed in a horizontal plane (the 2D planar format) and stacked in the vertical direction (the 3D stacked format), wherein the 2D and 3D formats include all types of multichip packages disclosed and specified in this invention, and each of the one or the plurality of non-volatile memory IC chips may comprise NAND flash memory cells, NOR flash memory cells, Magnetoresistive Random Access Memory (MRAM) cells, Resistive Random Access Memory (RRAM) cells, or Ferroelectric Random Access Memory (FRAM), (as described and specified in details below). The standardized commodity logic drive in a multichip package may further comprise volatile memory chips, for example SRAM and DRAM chips. The standardized commodity logic drive in a multichip package may further comprise one or a plurality of cooperating or supporting (CS) logic IC chips (as described and specified below), and/or computing and processing logic IC chips comprising Digital Signal Processor (DSP) IC chips, Graphic Processing Unit (GPU) IC chips, Data Processing Unit (DPU) IC chips, Tensor flow Processing Unit (TPU) IC chips, Micro-Control Unit (MCU) IC chips, Artificial Intelligent Unit (AIU) IC chips, Machine Learning Unit (MLU) IC chips, and/or Application Specific IC (ASIC) chips (as described and specified below). For the first example, the multichip package may comprise the FPGA and CPU chips for configuration the functions of the multichip package. For the second example, the multichip package may comprise the FPGA and GPU chips for configuration the functions of the multichip package. For the third example, the multichip package may comprise FPGA, CPU and GPU chips for configuration the functions of the multichip package.

Another aspect of the disclosure provides a method to reduce Non-Recurring Engineering (NRE) expenses for implementing (i) an innovation, (ii) an innovation process or application, and/or (iii) accelerating workload processing or application in semiconductor IC chips by using the standardized commodity logic drive, wherein the standardized commodity logic drive is implemented in the multichip package using the 2D planar format and 3D stacked format including all types of multichip packages disclosed in this invention. A person, user, or developer with an innovation and/or an application concept or idea or an aim for accelerating workload processing may purchase the standardized commodity logic drive and develop or write software codes or programs to load into the standardized commodity logic drive to implement his/her innovation and/or application concept or idea; wherein said innovation and/or application (maybe abbreviated as innovation below) comprises (i) innovative algorithms and/or architectures of computing, processing, learning and/or inferencing, and/or (ii) innovative and/or specific applications. The developed software codes or programs related to the innovation are used for configuring the one or a plurality of FPGA IC chips in the multichip package, and may be stored in the one or a plurality of non-volatile memory IC chips in the same multichip package. With non-volatile memory cells in the one or a plurality of non-volatile memory IC chips in the multichip package, the logic drive may be used as an alternative of the ASIC chip fabricated using advanced technology nodes. The standard commodity logic drive comprises one or a plurality of FPGA IC chips fabricated by advanced technology nodes or generations more advanced than 20 nm or 10 nm using FIN Field Effective Transistors (FINFETs) or Gate-All-Around Field Effective Transistors (GAAFETs). The innovation is implemented in the logic drive by configuring the hardware of FPGA IC chips by altering or changing the data in the 5T or 6T SRAM cells of the programmable interconnection (configurable switches including pass/no-pass switching gates and multiplexers) and/or programmable logic circuits, cells or blocks (including LUTs and multiplexers) therein using the data stored in the non-volatile memory cells in (i) the one or the plurality of non-volatile memory IC chips (in the multichip package using the 2D and 3D formats), and/or, (ii) the one or the plurality of FPGA IC chips in the multichip package. Compared to the implementation by developing a logic ASIC or COT IC chip, implementing the same or similar innovation and/or application using the logic drive may reduce the NRE cost down to smaller than US $1M by developing a software and installing it in the purchased or rented standard commodity logic drive. The standardized commodity logic drive having the configured data or information (for configuring the one or the plurality of FPGA IC chips) non-volatily stored in the non-volatile memory cells in the one or the plurality of non-volatile memory IC chips, and/or in the one or a plurality of FPGA IC chips, the configured standardized commodity logic drive may be sold to a user as an ASIC chip. Alternatively, an un-configured standardized commodity logic drive without the configured data or information (for configuring the one or the plurality of FPGA IC chips) non-volatily stored in the non-volatile memory cells in the one or the plurality of non-volatile memory IC chips, and/or the one or the plurality of FPGA IC chips may be sold to a user directly, and the user may configure/reconfigure the bought standardized commodity logic drive by himself or herself. The aspect of the disclosure inspires the innovation and lowers the barrier for implementing the innovation in IC chips designed and fabricated using an advanced IC technology node or generation, for example, a technology node or generation more advanced than or below 20 nm or 10 nm.

Another aspect of the disclosure provides a programmable or configurable multichip package in the 2D planar or 3D stacked packages comprising one or a plurality of FPGA IC chips to configure functions of the multichip package. This is a concept of a FPGA IC chip embedded in a multichip package (FPGA e-Multichip). The multichip package may further comprise non-volatile and volatile memory chips, (as described and specifies above), wherein the non-volatile and volatile memory chips may comprise configurable or programmable logic cells (comprising Look-Up-Tables, LUT) and configurable or programmable switches. The multichip package may further comprise one or a plurality of cooperating or supporting (CS) IC chips (as described and specified below), and/or computing and processing units comprising Digital Signal Processor (DSP), Graphic Processing Unit (GPU), Data Processing Unit (DPU), Tensor flow Processing Unit (TPU), Micro-Control Unit (MCU), Artificial Intelligent Unit (AIU), Machine Learning Unit (MLU), and/or Application Specific IC chip (ASIC) (as described and specified below), wherein the cooperating or supporting (CS) logic IC chips (as described and specified below), and/or computing and processing units (logic IC chips) may comprise configurable or programmable logic cells (comprising Look-Up-Tables, LUT) and configurable or programmable switches. For the first example, the multichip package may comprise the FPGA and CPU chips for configuration the functions of the multichip package. For the second example, the multichip package may comprise the FPGA and GPU chips for configuring the functions of the multichip package. For the third example, the multichip package may comprise FPGA, CPU and GPU chips for configuring the functions of the multichip package. The one or a plurality of cooperating or supporting (CS) IC chips (as described and specified below) may comprise an I/O or control chip, a hard macro IC chip, a power management IC chip, an Innovated ASIC or COT (abbreviated as IAC below) SOC (System-On-Chip) chip, and/or the cryptography or security IC chip. Each of the hard macro IC chips comprises hard macro circuits, including DSP slices for multiplication or division, phase locked loop (PLL) for analog clock generation, digital clock manager (DCM), block random-access memory (RAM) cells for logic operation, ARM Cortex processor/controller cores and/or CPU cores. The ARM Cortex processor/controller cores are 8, 16, 32. 64-bit or greater than 64-bit Reduced Instruction Set Computing (RISC) ARM processor/controller cores licensed from the ARM Holdings. The power management IC chip comprises voltage regulators.

The first semiconductor IC chip in the 2D planar or 3D stacked multichip package may comprise a logic cell coupling to the second semiconductor IC chip in the same multichip package through a metal interconnect (of the multichip package) between the first and second semiconductor IC chip, wherein the logic cell may be configured by the data stored in an on-chip memory cell as described and specified in this invention, wherein the logic cell comprises a Look-Up-Table (LUT) configured by data stored in an on-chip memory cell. Alternatively, the first and second semiconductor IC chips may comprise first and second logic cells, respectively. Wherein the first logic cell couples to the second logic cell through a metal interconnect (of the multichip package) between the first and second semiconductor IC chips, wherein the first and second logic cell each may be configured by the data stored in an on-chip memory cell as described and specified in this invention, wherein each of the first and second logic cells comprises a Look-Up-Table (LUT) configurable by data stored in an on-chip memory cell. The first and second semiconductor IC chips may be any types of semiconductor IC chips mentioned above in the multichip package, for example, (i) the first and second semiconductor IC chips are FPGA IC chips, (ii) the first semiconductor IC chip is FPGA IC chips, and the second semiconductor IC chips is CPU, GPU, IAC or CS IC chip as described above; (iii) the first semiconductor IC chip is an IAC chip comprising configurable logic cells and the second semiconductor IC chips is CPU, GPU, or CS IC chip.

The first semiconductor IC chip in the 2D planar or 3D stacked multichip package may comprise a configurable or programmable interconnection switch coupling to the second semiconductor IC chip in the same multichip package through a metal interconnect (of the multichip package) between the first and second semiconductor IC chip, wherein the configurable or programmable interconnection switch is configured by the data stored in an on-chip memory cell as described and specified in this invention. Alternatively, the first and second semiconductor IC chips may comprise first and second configurable or programmable interconnection switches, respectively, wherein the first configurable or programmable interconnection switch couples to the second configurable or programmable interconnection switch through a metal interconnect (of the multichip package) between the first and second semiconductor IC chips, wherein the first and second configurable or programmable interconnection switch each may be configured by the data stored in an on-chip memory cell as described and specified above in this invention. The first and second semiconductor IC chips may be any types of semiconductor IC chips mentioned in the multichip package; for example, (i) the first and second semiconductor IC chips are FPGA IC chips, (ii) the first semiconductor IC chip is the FPGA IC chip, and the second semiconductor IC chip is CPU, GPU, IAC or CS IC chip as described above; (iii) the first semiconductor IC chip is the IAC chip comprising configurable logic cells and the second semiconductor IC chip is CPU, GPU, or CS IC chip.

The 2D planar or 3D stacked multichip package may further comprise one or a plurality of I/O or control chip (comprising both large I/O circuits and small I/O circuits), wherein the one or a plurality of I/O or control chip may comprise large and small I/O circuits, and may further comprise power manage circuits (for example, voltage regulators or voltage converters) for power supply for another semiconductor IC chip in the 2D planar or 3D stacked multichip package. The I/O or control IC chip is used to (i) enable coupling between chips (as mentioned above) packaged in the same multichip, each chip may comprise I/O circuits with different sizes (driving and receiving capability) and supply voltage Vdd's (different voltage swings). A first semiconductor IC chip in the multichip package may be fabricated using a more mature or less advanced process technology node (for example, equal to or more mature than 20 nm), and may have large I/O circuits only (the driving capability equal to or larger than 1 pF or 2 pF) with a higher power supply voltage (equal to or higher than 0.7, 1.0, 1.5 or 2V), while a second semiconductor IC chip in the same multichip package may be fabricated using a more advanced process technology node (for example, equal to or more advanced than 10 nm or 20 nm), and may have small I/O circuits only (the driving capability equal to or smaller than 0.5 pF or 1 pF) with a lower power supply voltage (equal to or lower than 1.2 or 0.8 V), wherein a portion of the large I/O circuits on the first semiconductor IC chip couple to the external circuit of the multichip package, and another portion of the large I/O circuits on the first semiconductor IC chip couple to the large I/O circuits on the I/O chip. The I/O chip is configured to convert signals received at its large I/O circuits (from the first semiconductor IC chip) and couple to its small I/O circuits, and the small I/O circuits on the I/O chip couples to the small I/O circuits of the second semiconductor IC chip. In the reverse signal transmitting direction, the I/O chip is configured to convert signals received at its small I/O circuits (from the second semiconductor IC chip) and couple to its large I/O circuits, and the large I/O circuits on the I/O chip couples to the large I/O circuits of the first semiconductor IC chip. Through the I/O chip, each chip in the same multichip would be able to couple to any of other chips (in the same multichip package) fabricated in different process technology nodes (with different power supply voltages Vdd's); and (ii) to enable coupling between third and fourth semiconductor IC chips (as mentioned above) packaged in the same multichip package, each chip may comprise small I/O circuits only. A portion of small I/O circuits of the third semiconductor IC chip couple to the small I/O circuits of the fourth semiconductor IC chip, and another portion of small I/O circuits of the third semiconductor IC chip couple to the small I/O circuits of the I/O chip. The I/O chip is configured to convert signals received at its small I/O circuits (from the third semiconductor IC chip) and couple to its large I/O circuits, and the large I/O circuits on the I/O chip couple to the external circuits of the multichip package. In the reverse signal transmitting direction, the I/O chip is configured to convert signals received at its large I/O circuits (from the external circuits of the multichip package) and couple to its small I/O circuits, and the small I/O circuits on the I/O chip couple to the small I/O circuits of the third semiconductor IC chip. Through the I/O chip, each chip in the same multichip having only smaller I/O circuits would be able to couple to the external circuits of the multichip package. As examples, (a) the first semiconductor IC chip is a non-volatile memory chip and the second semiconductor IC chip is the FPGA, CPU, GPU or DPU chip; (b) the first semiconductor IC chip is an IAC chip and the second semiconductor IC chip is a FPGA, CPU, GPU or DPU chip; (c) the first semiconductor IC chip is a power management chip and the second semiconductor IC chip is a FPGA, CPU, GPU or DPU chip, (d) each of the third and fourth semiconductor IC chips is a FPGA chip, (e) the third semiconductor IC chip is a FPGA chip and the fourth semiconductor IC chip is CPU, GPU or DPU chip, and (f) the third semiconductor IC chip is a CPU chip and the fourth semiconductor IC chip is FPGA, GPU or DPU chip.

Another aspect of the disclosure provides the 2D planar or 3D stacked multichip package comprising a chip-on-chip package, wherein the chip-on-chip package comprises a first semiconductor IC chip with an active surface (having transistors) facing up, and a second semiconductor IC chip over the first semiconductor IC chip with an active surface (having transistors) facing down. The first and second semiconductor IC chips are bonded by die-to-wafer or wafer-to-wafer reflow solder bonding, thermal compressing bonding or copper-to-copper oxide-to-oxide direct hybrid bonding. The first semiconductor IC chip in the chip-on-chip package may comprise a logic cell coupling to the second semiconductor IC chip in the same chip-on-chip package through a metal bond (of the chip-on-chip package) between the first and second semiconductor IC chips, Wherein the logic cell may be configured by the data stored in an on-chip memory cell as described and specified in this invention, wherein the logic cell comprises a Look-Up-Table (LUT) configured by the data stored in an on-chip memory cell. Alternatively, the first and second semiconductor IC chips may comprise first and second logic cells, respectively, wherein the first logic cell couples to the second logic cell through a metal bond (of the chip-on-chip package) between the first and second semiconductor IC chips, wherein the first and second logic cell each may be configured by the data stored in an on-chip memory cell as described and specified in this invention, wherein each of the first and second logic cells comprises a Look-Up-Table (LUT) configured by the data stored in an on-chip memory cell. The first and second semiconductor IC chips may be any types of semiconductor IC chips mentioned above in the multichip package; for example, (i) the first and second semiconductor IC chips are FPGA IC chips, (ii) the first semiconductor IC chip is FPGA IC chip, and the second semiconductor IC chip is CPU, GPU, IAC or CS logic IC chip as described above; (iii) the first semiconductor IC chip is an IAC chip comprising configurable logic cells and the second semiconductor IC chip is CPU, GPU, DPU or other CS logic IC chip, wherein the CPU, GPU, DPU and/or other CS logic IC chip may comprise configurable or programmable logic cells (comprising Look-Up-Tables, LUT); (iv) the first semiconductor IC chip is an I/O or control IC chip comprising configurable logic cells and the second semiconductor IC chip is CPU, GPU, DPU or CS logic IC chip, wherein the CPU, GPU, DPU and/or CS logic IC chip may comprise configurable or programmable logic cells (comprising Look-Up-Tables, LUT), wherein the I/O or control IC chip may further comprise power management circuits (for example, DC to DC voltage conversion, voltage regulating, battery charging, power source selection, voltage scaling, and/or power sequencing); (v) the first semiconductor IC chip is power management IC chip (comprising circuits for DC to DC voltage conversion, voltage regulating, battery charging, power source selection, voltage scaling, and/or power sequencing), and the second semiconductor IC chip is FPGA, CPU, GPU, IAC or other CS IC logic chip as described above.

The first semiconductor IC chip in the chip-on-chip package may comprise a configurable or programmable interconnection switch coupling to the second semiconductor IC chip in the same chip-on-chip package through a metal bond (of the chip-on-chip package) between the first and second semiconductor IC chips, Wherein the configurable or programmable interconnection switch is configured by the data stored in an on-chip memory cell as described and specified above in this invention. Alternatively, the first and second semiconductor IC chips may comprise first and second configurable or programmable interconnection switches, respectively, wherein the first configurable or programmable interconnection switch couples to the second configurable or programmable interconnection switch through a metal bond (of the chip-on-chip package) between the first and second semiconductor IC chips, wherein each of the first and second configurable or programmable interconnection switches may be configured by the data stored in an on-chip memory cell as described and specified above in this invention. The first and second semiconductor IC chips may be any types of semiconductor IC chips mentioned above in the multichip package; for example, (i) the first and second semiconductor IC chips are FPGA IC chips, (ii) the first semiconductor IC chip is FPGA IC chips, and the second semiconductor IC chip is a SRAM IC chip; (iii) the first semiconductor IC chip is SRAM IC chips, and the second semiconductor IC chip is a FPGA IC chip; (iv) the first semiconductor IC chip is FPGA IC chip, and the second semiconductor IC chip is CPU, GPU, IAC or CS logic IC chip as described above; (v) the first semiconductor IC chip is an IAC chip comprising configurable or programmable interconnection switches and the second semiconductor IC chip is CPU, GPU, or other CS logic IC chip, wherein the CPU, GPU, DPU and/or CS logic IC chip may comprise configurable or programmable interconnection switches; (vi) the first semiconductor IC chip is an I/O or control IC chip comprising configurable or programmable interconnection switches and the second semiconductor IC chip is CPU, GPU, DPU or CS logic IC chip, wherein the CPU, GPU, DPU and/or CS logic IC chip may comprise configurable or programmable interconnection switches, wherein the I/O or control IC chip may further comprise power management circuits (comprising circuits for, for example, DC to DC voltage conversion, voltage regulating, battery charging, power source selection, voltage scaling, and/or power sequencing); (vii) the first semiconductor IC chip is power management IC chip (comprising circuits for, for example, DC to DC voltage conversion, voltage regulating, battery charging, power source selection, voltage scaling, and/or power sequencing), and the second semiconductor IC chip is FPGA, CPU, GPU, IAC or other CS IC logic chip as described above. For the purpose of increasing yield of wafer-to-wafer bonding, in the examples (i), (ii) and (iii), the FPGA IC chip may have a self-test and repair capability circuit, wherein the FPGA IC chip may comprise between 0.1% and 10% or 1% and 5% of spare logic cells for repairing.

Another aspect of the disclosure provides the 2D planar or 3D stacked multichip package comprising a chip-on-chip package, wherein the chip-on-chip package comprises a first semiconductor IC chip with an active surface (having transistors) facing up, and a second semiconductor IC chip over the first semiconductor IC chip and with an active surface (having transistors) facing up. The first semiconductor IC chip may be a power supply or a power management IC chip (PMIC) configured for supplying power voltages to and managing the power distribution and consumption of the second semiconductor IC chip; the chip-on-chip package is becoming a chip-on-PMIC package. The PMIC chip may comprise power management circuits for DC to DC voltage conversion, voltage regulating, battery charging, power source selection, voltage scaling, and/or power sequencing. The second semiconductor IC chip may be (i) a computing and processing logic IC chip, for example, an FPGA IC chip, Digital Signal Processor (DSP) IC chip, Graphic Processing Unit (GPU) IC chip, Data Processing Unit (DPU) IC chip, Tensor flow Processing Unit (TPU) IC chip, Micro-Control Unit (MCU) IC chip, Artificial Intelligent Unit (AIU) IC chip, Machine Learning Unit (MLU) IC chip, and/or Application Specific IC (ASIC) chip; (ii) a volatile memory IC chip, for example, a SRAM IC chip or DRAM IC chip; (iii) a non-volatile memory IC chip, for example, a NAND flash memory IC chip, NOR flash memory IC chip, Magnetoresistive Random Access Memory (MRAM) IC chip, Resistive Random Access Memory (RRAM) IC chip, or Ferroelectric Random Access Memory (FRAM) IC chip; or (iv) a mixed-mode or analog IC chip.

The chip-on-PMIC package comprises power/ground distribution networks, planes or scheme for delivering and distributing power/ground supply voltage/current to the second semiconductor IC chip on the PMIC chip. The power/ground distribution networks, planes or scheme is formed by using the same fabrication processes as forming the interconnection layers of a conventional semiconductor IC chip, for example, the damascene copper electroplating process with chemical-mechanical-polishing (CMP) process, and comprises 4 metal layers, for example, (i) a power voltage metal layer with design patterns in metal planes or large-area metal pieces and with a thickness between 0.1 and 10 m or 0.5 and 5 μm, wherein the metal plane or large-area metal piece has openings or holes in it for ground voltage from PMIC chip to pass therethrough; (ii) a ground voltage metal layer over the power voltage metal layer and with design patterns in metal planes or large-area metal pieces and with a thickness between 0.1 and 10 m or 0.5 and 5 μm, wherein the metal planes or large-area metal pieces has openings or holes in it for underlying power voltage to pass therethrough. A decoupling capacitor may be formed in the power/ground distribution networks, planes or scheme, wherein the decoupling capacitor comprises: (a) a first electrode using the power plane or large-area metal piece, (b) a second electrode using the ground plane or large-area metal piece, and (c) an inter-metal dielectric layer, between the first (power) electrode and the second (ground) electrode, comprising high dielectric constant material, for example, hafnium oxide (HfO₂) or tantalum oxide (Ta₂O₅); (iii) a first power/ground fine-distributing layer over the ground voltage metal layer to distribute power/ground to transistors in local area of the second semiconductor IC chip, wherein the first power/ground fine-distributing layer has a thickness between 0.05 and 5 μm or 0.1 and 2 μm, (iv) a second power/ground fine-distributing layer over the first power/ground fine-distributing layer to distribute power/ground to transistors in local area of the second semiconductor IC chip, wherein the second power/ground fine-distributing layer has a thickness between 0.05 and 5 μm or 0.1 and 2 μm. The power/ground distribution networks, planes or scheme in the chip-on-PMIC may be formed as top layers of the interconnection scheme of the PMIC chip, or formed at the bottom of the second semiconductor IC chip at wafer level process before diced or sawed apart. The second semiconductor IC chip may comprise a silicon substrate and a plurality of through silicon vias (TSVs) vertically in the silicon substrate, wherein the silicon substrate has a thickness between 0.1 and 20 micrometers, between 1 and 10 μm or between 1 and 5 μm, and the TSVs have the diameter between 0.5 and 20 μm, between 1 and 10 μm or between 1 and 5 μm.

Depending on the methods of forming the chip-on-PMIC package using wafer-to-wafer or die-to-wafer bonding process, the chip-on-PMIC package may be in one of following 4 types: (i) if the chip-on-PMIC package is formed using copper-to-copper oxide-to-oxide direct hybrid bonding by a wafer-to-wafer bonding process, the power/ground distribution networks, planes or scheme is formed in the top layers of metal interconnection scheme of the PMIC chip. In this case, the power/ground supply voltage/current for the second semiconductor IC chip is from the power/ground distribution networks, planes or scheme in the PMIC chip and passes through the TSVs in the silicon substrate of the second semiconductor IC chip, while the signals (S_{chip}) for the second semiconductor IC chip are from the external circuits of the chip-on-PMIC package through the metal contacts, copper pillars, or solder bumps at the top surface of the second semiconductor IC chip. The power/ground supply voltage/current (Vdd′ and Vss) at the power or ground voltage metal layer in the PMIC chip is from the external power supply sources (Vdd and Vss) of the chip-on-PMIC package, and through the metal contacts, copper pillars, or solder bumps at the top surface of the second semiconductor IC chip, stacked vias formed by the interconnection metals of the second semiconductor IC chip, TSVs in the silicon substrate of the second semiconductor IC chip, direct hybrid bonds, stacked vias formed by the interconnection metals of the PMIC chip, the power management circuits of the PMIC chip, to the power or ground voltage metal layer (Vdd′ or Vss) of the the power/ground distribution networks, planes or scheme in the PMIC chip. In some designs, the external power supply sources (Vdd and Vss) of the chip-on-PMIC package may couple to the power or ground voltage metal layer (Vdd and Vss) directly without through the power management circuits of the PMIC chip and provide power supply (Vdd and Vss) for the second semiconductor IC chip. The signals (S_{PMIC}) for the PMIC chip go through the similar paths as the Vdd and Vss. The power/ground voltage supply for the second semiconductor IC chip is separated from the signal I/Os for the second semiconductor IC chip, wherein the power/ground voltage supply is from the bottom of the second semiconductor IC chip and signals are from the top of the second semiconductor IC chip, respectively; (ii) if the chip-on-PMIC package is formed using copper-to-copper oxide-to-oxide direct hybrid bonding by a wafer-to-wafer bonding process and the PMIC chip has TSVs in its silicon substrate, the power/ground distribution networks, planes or scheme is formed in the top layers of metal interconnection scheme of the PMIC chip. In this case, the power/ground supply voltage/current for the second semiconductor IC chip is from the power/ground distribution networks, planes or scheme in the PMIC chip and passes through the TSVs in the silicon substrate of the second semiconductor IC chip, while the signals (S_{chip}) for the second semiconductor IC chip is from the external circuits of the chip-on-PMIC package through the metal contacts, copper pillars, or solder bumps at the top surface of the second semiconductor IC chip. The power/ground supply voltage/current (Vdd and Vss) at the power or ground layer in the PMIC chip is from the external power supply sources (Vdd and Vss) of the chip-on-PMIC package, and through the metal contacts, copper pillars, or solder bumps at the bottom surface of the PMIC chip, TSVs in the silicon substrate of the PMIC chip, up to the power or ground voltage metal layer (Vdd or Vss), down to the power management circuits of the PMIC chip, and up again to the power or ground voltage metal layer (Vdd′ or Vss). In some designs, the external power supply sources (Vdd and Vss) of the chip-on-PMIC package may couple to the power or ground voltage metal layer (Vdd and Vss) directly without through the power management circuits of the PMIC chip and provide power supply (Vdd and Vss) for the second semiconductor IC chip. The signals (S_{PMIC}) for the PMIC chip is from the external circuits of the chip-on-PMIC package, and through the metal contacts, copper pillars, or solder bumps at the top surface of the second semiconductor IC chip, stacked vias formed by the interconnection metals of the second semiconductor IC chip, TSVs in the silicon substrate of the second semiconductor IC chip, direct hybrid bonds, and stacked vias formed by the interconnection metals of the PMIC chip. The power/ground voltage supplies for the second semiconductor IC chip and the PMIC chip are separated from the signal I/Os for the second semiconductor IC chip and the PMIC chip, wherein the power/ground voltage supplies are from the bottom of the chip-on-PMIC package and signals are from the top of the chip-on-PMIC package, respectively; (iii) if the chip-on-PMIC package is formed using solder reflow, thermal compression bonding or copper-to-copper oxide-to-oxide direct hybrid bonding by a die-to-wafer bonding process and the PMIC chip has TSVs, the power/ground distribution networks, planes or scheme is formed at the bottom of the second semiconductor IC chip. In this case, the power/ground supply voltage/current for the second semiconductor IC chip is from the power/ground distribution networks, planes or scheme in the second semiconductor IC chip, and passes through the TSVs in the silicon substrate of the second semiconductor IC chip, while the signals (S_{chip}) for the second semiconductor IC chip is from the external circuits of the chip-on-PMIC package through the metal contacts, copper pillars, or solder bumps at the top surface of the of the second semiconductor IC chip. The power/ground supply voltage/current (Vdd and Vss) at the power or ground voltage metal layer of the power/ground distribution networks, planes or scheme in the second semiconductor IC chip is from the external power supply sources (Vdd and Vss) of the chip-on-PMIC package, and through the metal contacts, copper pillars, or solder bumps at the bottom surface of the PMIC chip, TSVs in the silicon substrate of the PMIC chip, up to the direct hybrid bonds, up to the power or ground voltage metal layer (Vdd or Vss), down to the direct hybrid bonds, down to the power management circuits of the PMIC chip, up to the direct hybrid bonds, and up to the power or ground voltage metal layer (Vdd′ or Vss). In some designs, the external power supply sources (Vdd and Vss) of the chip-on-PMIC package may couple to the power or ground voltage metal layer (Vdd and Vss) directly without through the power management circuits of the PMIC chip and provide power supply (Vdd and Vss) for the second semiconductor IC chip. The signals (S_{PMIC}) for the PMIC chip are from the external circuits of the chip-on-PMIC package, and through the metal contacts, copper pillars, or solder bumps at the top surface of the of the second semiconductor IC chip, stacked vias formed by the interconnection metals of the second semiconductor IC chip, TSVs in the silicon substrate of the second semiconductor IC chip, direct hybrid bonds, and stacked vias formed by the interconnection metals of the PMIC chip. The power/ground voltage supplies for the second semiconductor IC chip and the PMIC chip are separated from the signal I/Os for the second semiconductor IC chip and the PMIC chip, wherein the power/ground voltage supplies are from the bottom of the chip-on-PMIC package and signals are from the top of the chip-on-PMIC package, respectively; (iv) if the chip-on-PMIC package is formed using solder reflow, thermal compression bonding or copper-to-copper oxide-to-oxide direct hybrid bonding by a die-to-wafer bonding process and the chip-on-PMIC package has Through-Polymer-metal-Vias (TPVs, the polymer may be a molding compound), the power/ground distribution networks, planes or scheme is formed at the bottom of the second semiconductor IC chip. In this case, the power/ground supply voltage/current for the second semiconductor IC chip is from the power/ground distribution networks, planes or scheme in the second semiconductor IC chip, and passes through the TSVs in the silicon substrate of the second semiconductor IC chip, while the signals (S_{chip}) for the second semiconductor IC chip is from the external circuits of the chip-on-PMIC package through the metal contacts, copper pillars, or solder bumps at the top surface of the second semiconductor IC chip. The power/ground supply voltage/current (Vdd and Vss) at the power or ground voltage metal layer of the power/ground distribution networks, planes or scheme in the second semiconductor IC chip is from the external power supply sources (Vdd and Vss) of the chip-on-PMIC package, and through the metal contacts, copper pillars, or solder bumps at the bottom surface of the chip-on-PMIC package, the TPVs, the power or ground voltage metal layer (Vdd or Vss), down to the solder bumps, down to the power management circuits of the PMIC chip, up to the solder bumps, and up to the power or ground voltage metal layer (Vdd′ or Vss). In some designs, the external power supply sources (Vdd and Vss) of the chip-on-PMIC package may couple to the power or ground voltage metal layer (Vdd and Vss) directly without through the power management circuits of the PMIC chip and provide power supply (Vdd and Vss) for the second semiconductor IC chip. The signals (S_{PMIC}) for the PMIC chip is from the external circuits of the chip-on-PMIC package, and through the metal contacts, copper pillars, or solder bumps at the top surface of the second semiconductor IC chip, stacked vias formed by the interconnection metals of the second semiconductor IC chip, TSVs in the silicon substrate of the second semiconductor IC chip, solder bumps, and stacked vias formed by the interconnection metals of the PMIC chip. The power/ground voltage supplies for the second semiconductor IC chip and the PMIC chip are separated from the signal I/Os for the second semiconductor IC chip and the PMIC chip, wherein the power/ground voltage supplies are from the bottom of the chip-on-PMIC package and signals are from the top of the chip-on-PMIC package, respectively.

Another aspect of the disclosure provides the standard commodity FPGA IC chip used in the 2D planar or 3D stacked multichip package, and designed, implemented and fabricated using an advanced semiconductor technology node or generation, for example, more advanced than or equal to, or below or equal to 20 nm or 10 nm, and for example using the technology node of 16 nm, 14 nm, 12 nm, 10 nm, 7 nm, 5 nm or 3 nm; with a chip size and manufacturing yield optimized with the minimum manufacturing cost for the used semiconductor technology node or generation. The I/O or control chip may be fabricated by mature or less advanced technology nodes, for example, less advanced than 20 nm or 30 nm. Transistors used in the advanced semiconductor technology node or generation for the FPGA IC chip may be a FIN Field-Effect-Transistor (FINFET), a FINFET on Silicon-On-Insulator (FINFET SOI) or a GAAFET. The standard commodity FPGA IC chip may only communicate or couple directly with other chips in or of the logic drive only; its I/O circuits may require only small I/O drivers or receivers, and small or none Electrostatic Discharge (ESD) devices. All or most control and/or Input/Output (I/O) circuits or units (for example, the off-logic-drive I/O circuits, i.e., large I/O circuits, communicating with circuits or components external or outside of the logic drive) are outside of, or not included in, the standard commodity FPGA IC chip, but are included in the I/O or control chip packaged in the same logic drive. None or minimal area of the standard commodity FPGA IC chip is used for the control or I/O circuits, for example, less than 15%, 10%, 5%, 2% or 1% area (not counting the seal ring and the dicing area of the chip; that means, only including area upto the inner boundary of the seal ring) is used for the control or I/O circuits; or, none or minimal transistors of the standard commodity FPGA IC chip are used for the control or I/O circuits, for example, less than 15%, 10%, 5%, 2% or 1% of the total number of transistors are used for the control or I/O circuits; or all or most area of the standard commodity FPGA IC chip is used for (i) logic blocks comprising logic gate arrays, computing units or operators, and/or Look-Up-Tables (LUTs) and multiplexers, and/or (ii) programmable interconnection. For example, greater than 85%, 90%, 95% or 99% area (not counting the seal ring and the dicing area of the chip; that means, only including area upto the inner boundary of the seal ring) is used for logic blocks, and/or programmable interconnection; or, all or most transistors of the standard commodity FPGA IC chip are used for logic blocks or repetitive arrays, and/or programmable interconnection, for example, greater than 85%, 90%, 95% or 99% of the total number of transistors are used for logic blocks, and/or programmable interconnection.

A multi-chip package may comprises: (1) an interconnection bridge comprising a first silicon substrate, an interconnection scheme over the first silicon substrate, a first metal contact at a top of the interconnection bridge, a second metal contact at the top of the interconnection bridge and a first insulating dielectric layer at the top of the interconnection bridge and covering a sidewall of each of the first and second metal contacts, wherein the first insulating dielectric layer is not extending over a top surface of each of the first and second metal contacts, wherein the first metal contact couples to the second metal contact through the interconnection scheme; (2) a second insulating dielectric layer at a same horizontal level as the interconnection bridge, wherein the first insulating dielectric layer is not extending over the second insulating dielectric layer; (3) a first semiconductor IC chip over the interconnection bridge and second insulating dielectric layer and across an edge of the interconnection bridge, wherein the first semiconductor IC chip comprises a first metal bump at a bottom of the first semiconductor IC chip, wherein the first metal bump is bonded to the first metal contact; (4) a second semiconductor IC chip over the interconnection bridge and second insulating dielectric layer and across an edge of the interconnection bridge, wherein the second semiconductor IC chip comprises a second metal bump at a bottom of the second semiconductor IC chip, wherein the second metal bump is bonded to the second metal contact, wherein the second semiconductor IC chip couples to the first semiconductor IC chip through, in sequence, the second metal bump, second metal contact, interconnection scheme, first metal contact and first metal bump; and (5) an underfill between the first semiconductor IC chip and interconnection bridge, between the second semiconductor IC chip and interconnection bridge and in contact with a bottom surface of each of the first and second semiconductor IC chips and a top surface of the first insulating dielectric layer, covering a sidewall of each of the first and second metal bumps, wherein the underfill is further between the first semiconductor IC chip and second insulating dielectric layer, between the second semiconductor IC chip and second insulating dielectric layer and in contact with a top surface of the second insulating dielectric layer. For an alternative, the multi-chip package may further comprises a connector at the same horizontal level as the second insulating dielectric layer and interconnection bridge and under the first semiconductor IC chip, wherein the connector comprises a second silicon substrate and a through-silicon metal via vertically in the second silicon substrate, wherein the first semiconductor IC chip comprises a third metal bump at a bottom of the first semiconductor IC chip, wherein the third metal bump couples to the through-silicon metal via and is over and aligned with the through-silicon metal via, wherein the connector has no transistor therein. For an alternative, the connector may be a passive device without any transistor therein and the interconnection bridge may be a passive device without any transistor therein. For an alternative, the multi-chip package may further comprises a third semiconductor IC chip at the same horizontal level as the second insulating dielectric layer and interconnection bridge and under the first semiconductor IC chip, wherein the third semiconductor IC chip comprises a third metal contact at a top of the third semiconductor IC chip and a third insulating dielectric layer at the top of the third semiconductor IC chip and covering a sidewall of the third metal contact, wherein the third insulating dielectric layer is not extending over a top surface of the third metal contact, wherein the first semiconductor IC chip further comprises a third metal bump at the bottom of the first semiconductor IC chip, wherein the third metal bump is bonded to the third metal contact, wherein the underfill is further between the first and third semiconductor IC chips and in contact with a top surface of the third insulating dielectric layer, covering a sidewall of the third metal bump; for a first aspect, the third semiconductor IC chip may be an application-specific integrated-circuit (ASIC) chip or system-on-chip (SoC) IC chip, input/output (I/O) IC chip, static-random-access-memory (SRAM) IC chip, wherein the first semiconductor IC chip may comprise a first input/output (I/O) circuit coupling to a second input/output (I/O) circuit of the third semiconductor IC chip through, in sequence, the third metal bump and third metal contact, wherein each of the first and second input/output (I/O) circuits has a voltage supply (Vdd) equal to or smaller than 1 volt, 0.8 volts or 0.5 volts and generates a voltage swing equal to or smaller than 1 volt, 0.8 volts or 0.5 volts, wherein the multi-chip package may further comprise a fourth metal bump at a bottom of the multi-chip package, and the third semiconductor IC chip comprises a third input/output (I/O) circuit coupling to the fourth metal bump, wherein the third input/output (I/O) circuit has a voltage supply (Vdd) equal to or greater than 0.7 volts, 1 volt, 1.2 volts or 1.5 volts and generates a voltage swing equal to or greater than 0.7 volts, 1 volt, 1.2 volts or 1.5 volts, wherein the third semiconductor IC chip is an application-specific integrated-circuit (ASIC) chip, system-on-chip (SoC) IC chip, input/output (I/O) IC chip or static-random-access-memory (SRAM) IC chip; for a second aspect, the first semiconductor IC chip may comprise a first input/output (I/O) circuit coupling to a second input/output (I/O) circuit of the third semiconductor IC chip through, in sequence, the third metal bump and third metal contact, wherein each of the first and second input/output (I/O) circuits has a driving capability smaller than 1 pF; for a third aspect, the third semiconductor IC chip may be a NVM IC chip for storing data therein and the first semiconductor IC chip is a FPGA IC chip, wherein the FPGA IC chip is configured in accordance with the data; for a fourth aspect, the third semiconductor IC chip may comprise a second silicon substrate and a through-silicon metal via vertically in the second silicon substrate. For an alternative, the first semiconductor IC chip may be a first FPGA IC chip and the second semiconductor IC chip may be a second FPGA IC chip, wherein the first FPGA IC chip comprises a first logic cell configured to be programmed to perform a first logic operation, wherein the first logic cell comprises a first look-up-table (LUT) having a plurality of first memory cells to store a plurality of first resulting data associated with the first logic operation, and a first selection circuit comprising a first set of input points for a first input data set for the first logic operation and a second set of input points for a second input data set for the first logic operation, wherein the first selection circuit is configured to select, in accordance with the first input data set, second input data from the second input data set as second output data for the first logic operation, and wherein the second FPGA IC chip comprises a second logic cell configured to be programmed to perform a second logic operation, wherein the second logic cell comprises a second look-up-table (LUT) having a plurality of second memory cells to store a plurality of second resulting data associated with the second logic operation, and a second selection circuit comprising a third set of input points for a third input data set for the second logic operation and a fourth set of input points for a fourth input data set for the second logic operation, wherein the second selection circuit is configured to select, in accordance with the third input data set, fourth input data from the fourth input data set as second output data for the second logic operation, wherein the first logic cell couples to the second logic cell through the bonded first and second copper pads. For an alternative, the first semiconductor IC chip may be a first FPGA IC chip and the second semiconductor IC chip may be a second FPGA IC chip, wherein the first FPGA IC chip comprises a first programmable interconnection circuit in the first FPGA IC chip, wherein the first programmable interconnection circuit comprises a first switch, wherein the first switch has a first node connected to a first interconnect and a second node connected to a second interconnect, wherein the first switch is configured to control coupling between the first and second interconnects by first data stored in a first memory cell in the first FPGA IC chip, wherein the second FPGA IC chip comprises a second programmable interconnection circuit in the second FPGA IC chip, wherein the second programmable interconnection circuit comprises a second switch, wherein the second switch has a third node connected to a third interconnect and a fourth node connected to a fourth interconnect, wherein the second switch is configured to control coupling between the third and fourth interconnects by second data stored in a second memory cell in the second FPGA IC chip, wherein the first switch couples to the second switch through the second interconnect, bonded first and second copper pads and third interconnect. For an alternative, the first semiconductor IC chip may be a central-processing-unit (CPU) IC chip and the second semiconductor IC chip may be a FPGA IC chip. For an alternative, the first semiconductor IC chip may be a graphic-processing-unit (GPU) IC chip and the second semiconductor IC chip may be a FPGA IC chip. For an alternative, wherein the first semiconductor IC chip may be an application-specific integrated-circuit (ASIC) chip or system-on-chip (SoC) chip and the second semiconductor IC chip may be a FPGA IC chip. For an alternative, each of the first and second semiconductor IC chips may be a FPGA IC chip.

A multi-chip package may comprises: (1) a first semiconductor IC chip comprising a first silicon substrate, a first through-silicon metal via vertically in the first silicon substrate, a first transistor at a top surface of the first silicon substrate and a first interconnection scheme over the first silicon substrate, wherein the first interconnection scheme couples to the first through-silicon metal via and first transistor, wherein the first interconnection scheme comprises a first oxide layer and first copper pad at a top of the first semiconductor IC chip, wherein the first copper pad is in the first oxide layer, and (2) a second semiconductor IC chip over and bonded to the first semiconductor IC chip, wherein the second semiconductor IC chip comprises a second silicon substrate, a second through-silicon metal via vertically in the second silicon substrate, a second transistor at a bottom surface of the second silicon substrate and a second interconnection scheme under the second silicon substrate, wherein the second interconnection scheme couples to the second through-silicon metal via and second transistor, wherein the second interconnection scheme comprises a second oxide layer and second copper pad at a bottom of the second semiconductor IC chip, wherein the second copper pad is in the second oxide layer, wherein a bottom surface of the second oxide layer is bonded to and in contact with a top surface of the first oxide layer, and a bottom surface of the second copper pad is bonded to and in contact with a top surface of the first copper pad. For an alternative, each of the first and second semiconductor IC chips may be a FPGA IC chip. For an alternative, the multi-chip package may further comprise: (1) a third semiconductor IC chip over and coupling to the second semiconductor IC chip, wherein the third semiconductor IC chip comprises a third silicon substrate, a third through-silicon metal via vertically in the third silicon substrate, a third transistor at a top surface of the third silicon substrate and a third interconnection scheme over the third silicon substrate, wherein the third interconnection scheme couples to the third through-silicon metal via and third transistor, wherein the third interconnection scheme comprises a third oxide layer and third copper pad at a top of the third semiconductor IC chip, wherein the third copper pad is in the third oxide layer; (2) a fourth semiconductor IC chip over and bonded to the third semiconductor IC chip, wherein the fourth semiconductor IC chip comprises a fourth silicon substrate, a fourth through-silicon metal via vertically in the fourth silicon substrate, a fourth transistor at a bottom surface of the fourth silicon substrate and a fourth interconnection scheme under the fourth silicon substrate, wherein the fourth interconnection scheme couples to the fourth through-silicon metal via and fourth transistor, wherein the fourth interconnection scheme comprises a fourth oxide layer and fourth copper pad at a bottom of the fourth semiconductor IC chip, wherein the fourth copper pad is in the fourth oxide layer, wherein a bottom surface of the fourth oxide layer is bonded to and in contact with a top surface of the third oxide layer, and a bottom surface of the fourth copper pad is bonded to and in contact with a top surface of the third copper pad; and (3) a metal bump between the second and third semiconductor IC chips and coupling the second through-silicon metal via to the third through-silicon metal via, wherein each of the first, second, third and fourth semiconductor IC chips may be a FPGA IC chip. For an alternative, the multi-chip package may further comprises a third semiconductor IC chip over and coupling to the second semiconductor IC chip and a metal bump between the second and third semiconductor IC chips and coupling the third semiconductor IC chip to the second semiconductor IC chip, wherein the third semiconductor IC chip may be a NVM IC chip for storing data therein, the first semiconductor IC chip may be a first FPGA IC chip and the second semiconductor IC chip may be a second FPGA IC chip, wherein each of the first and second FPGA IC chips is configured in accordance with the data. For an alternative, the multi-chip package may further comprise: (1) a third semiconductor IC chip under and coupling to the first semiconductor IC chip, wherein the third semiconductor IC chip comprises a third silicon substrate, a third through-silicon metal via vertically in the third silicon substrate, a third transistor at a bottom surface of the third silicon substrate and a third interconnection scheme under the third silicon substrate, wherein the third interconnection scheme couples to the third through-silicon metal via and third transistor; and (2) a metal bump between the first and third semiconductor IC chips and coupling the first through-silicon metal via to the third through-silicon metal via, wherein the third semiconductor IC chip may be an input/output (I/O) IC chip and the first semiconductor IC chip may be a FPGA IC chip, wherein the FPGA IC chip comprises a first input/output (I/O) circuit coupling to a second input/output (I/O) circuit of the input/output (I/O) IC chip through the metal bump, wherein each of the first and second input/output (I/O) circuits has a driving capability smaller than 1 pF.

A multi-chip package may comprise: (1) a first FPGA IC chip; and (2) a second FPGA IC chip over and bonded to the first FPGA IC chip. For an alternative, the first FPGA IC chip may comprise a silicon substrate and a through-silicon metal via vertically in the silicon substrate. For an alternative, each of the first and second FPGA IC chips may comprise a silicon substrate and a through-silicon metal via vertically in the silicon substrate. For an alternative, the first FPGA IC chip may comprise a first silicon substrate and a plurality of first transistors at a first active surface over the first silicon substrate, and the second FPGA IC chip may comprise a second silicon substrate and a plurality of second transistors at a second active surface under the second silicon substrate, and faces the first FPGA IC chip; for a first bonding structure, the first FPGA IC chip may comprise a first oxide layer and a first copper pad at a top of the first FPGA IC chip, wherein the first copper pad is in the first oxide layer, and wherein the second FPGA IC chip may comprise a second oxide layer and second copper pad at a bottom of the second FPGA IC chip, wherein the second copper pad is in the second oxide layer, wherein a bottom surface of the second oxide layer is bonded to and in contact with a top surface of the first oxide layer, and a bottom surface of the second copper pad is bonded to and in contact with a top surface of the first copper pad; for a second bonding structure, the first field-programmable-gate-array (FPGA) integrated-circuit chip comprises a metal pad at its top, and wherein the second field-programmable-gate-array (FPGA) integrated-circuit chip comprises a metal bump at its bottom, wherein the metal bump is bonded to the metal pad with a tin-containing solder in between; for a first aspect, the first FPGA IC chip may comprise a first logic cell configured by first data stored in a first memory cell in the first FPGA IC chip, wherein the first logic cell has a first output point coupling to circuits of the second FPGA IC chip through the bonded first and second copper pads; for a second aspect, the first FPGA IC chip may comprise a first logic cell, wherein the first logic cell is configured to be programmed to perform a first logic operation, comprising a look-up-table (LUT) having a plurality of memory cells to store a plurality of resulting data associated with the first logic operation, and a first selection circuit comprising a first set of input points for a first input data set for the first logic operation and a second set of input points for a second input data set for the first logic operation, wherein the first selection circuit is configured to select, in accordance with the first input data set, second input data from the second input data set as first output data at a first output point for the first logic operation, wherein the first output point of the first logic cell couples to circuits of the second FPGA IC chip through the bonded first and second copper pads; for a third aspect, the first FPGA IC chip may comprise a first logic cell configured by first data stored in a first memory cell in the first FPGA IC chip, and the second FPGA IC chip may comprise a second logic cell configured by second data stored in a second memory cell in the second FPGA IC chip, wherein the first logic cell has an output point coupling to an input point of the second logic cell through the bonded first and second copper pads; for a fourth aspect, the first FPGA IC chip may comprise a first logic cell configured to be programmed to perform a first logic operation, wherein the first logic cell comprises a first look-up-table (LUT) having a plurality of first memory cells to store a plurality of first resulting data associated with the first logic operation, and a first selection circuit comprising a first set of input points for a first input data set for the first logic operation and a second set of input points for a second input data set for the first logic operation, wherein the first selection circuit is configured to select, in accordance with the first input data set, second input data from the second input data set as second output data for the first logic operation, and wherein the second FPGA IC chip may comprise a second logic cell configured to be programmed to perform a second logic operation, wherein the second logic cell comprises a second look-up-table (LUT) having a plurality of second memory cells to store a plurality of second resulting data associated with the second logic operation, and a second selection circuit comprising a third set of input points for a third input data set for the second logic operation and a fourth set of input points for a fourth input data set for the second logic operation, wherein the second selection circuit is configured to select, in accordance with the third input data set, fourth input data from the fourth input data set as second output data for the second logic operation, wherein the first logic cell couples to the second logic cell through the bonded first and second copper pads; for a fifth aspect, the first field-programmable-gate-array (FPGA) integrated-circuit chip may comprise a first look-up-table and the second field-programmable-gate-array (FPGA) integrated-circuit chip may comprise a second look-up-table, wherein the first look-up-table couples to the second look-up-table through the bonded first and second copper pads; for a sixth aspect, the first FPGA IC chip may comprise a first programmable interconnection circuit in the first FPGA IC chip, wherein the first programmable interconnection circuit comprises a switch, wherein the switch has a first node connected to a first interconnect and a second node connected to a second interconnect, wherein the switch is configured to control coupling between the first and second interconnects by first data stored in a first memory cell in the first FPGA IC chip, wherein the second interconnect couples to a circuit of the second field-programmable-gate-array (FPGA) integrated-circuit through the bonded first and second copper pads; for a seventh aspect, the first FPGA IC chip may comprise a first programmable interconnection circuit in the first FPGA IC chip, wherein the first programmable interconnection circuit comprises a first switch, wherein the first switch has a first node connected to a first interconnect and a second node connected to a second interconnect, wherein the first switch is configured to control coupling between the first and second interconnects by first data stored in a first memory cell in the first FPGA IC chip, wherein the second FPGA IC chip may comprise a second programmable interconnection circuit in the second FPGA IC chip, wherein the second programmable interconnection circuit comprises a second switch, wherein the second switch has a third node connected to a third interconnect and a fourth node connected to a fourth interconnect, wherein the second switch is configured to control coupling between the third and fourth interconnects by second data stored in a second memory cell in the second FPGA IC chip, wherein the first switch couples to the second switch through the second interconnect, bonded first and second copper pads and third interconnect.

A field programmable package comprises: a first interconnection scheme; a semiconductor integrated-circuit (IC) chip coupling to the first interconnection scheme; and a multichip package having a first and second metal contact bonded to the first interconnection scheme, wherein the multichip package comprises a non-volatile memory (NVM) integrated-circuit (IC) chip having a non-volatile memory (NVM) cell for storing first data therein and a field-programmable-gate-array (FPGA) integrated-circuit (IC) chip having a volatile memory cell for storing second data therein associated with the first data and a switch circuit for controlling, in accordance with the second data stored in the volatile memory cell, coupling between first and second input/output (I/O) pads of the field-programmable-gate-array (FPGA) integrated-circuit (IC) chip, wherein the first input/output (I/O) pad of the field-programmable-gate-array (FPGA) integrated-circuit (IC) chip couples to the first metal contact and the second input/output (I/O) pad of the field-programmable-gate-array (FPGA) integrated-circuit (IC) chip couples to the second metal contact, wherein the first interconnection scheme comprises a first metal interconnect coupling the first metal contact to the semiconductor integrated-circuit (IC) chip and a second metal interconnect coupling to the second metal contact, wherein the switch circuit is configured for controlling, in accordance with the second data stored in the volatile memory cell, coupling between the first and second metal interconnects. In an alternative, the first interconnection scheme is under the multichip package and across an edge of the multichip package, wherein the edge of the multichip package is recessed from an edge of the first interconnection scheme. In an alternative, the semiconductor integrated-circuit (IC) chip is bonded to the first interconnection scheme and arranged at a same horizontal level as the multichip package. In an alternative, the first interconnection scheme is a ball-grid-array (BGA) substrate or interposer. In an alternative, each of the first and second metal contacts comprises tin. In an alternative, each of the first and second metal contacts comprises a copper layer. In an alternative, the semiconductor integrated-circuit (IC) chip is a graphic-processing-unit (GPU) integrated circuit (IC) chip, central-processing-unit (CPU) integrated circuit (IC) chip, application-specific integrated circuit (ASIC) chip or digital signal processing (DSP) integrated circuit (IC) chip. In an alternative, the semiconductor integrated-circuit (IC) chip is an input/output (I/O) chip configured as an interface chip having a first interface with a circuit external to the field programmable package and a second interface with the multichip package, wherein each of the first and second interfaces is in accordance with an industry standard of peripheral component interconnect express (PCIe), universal-chiplet-interconnect express (UCIe), serial-advanced-technology-attachment (SATA) or Wi-Fi (wireless fidelity). In an alternative, the semiconductor integrated-circuit (IC) chip is an input/output (I/O) chip configured as a transceiver chip. In an alternative, the non-volatile memory (NVM) integrated-circuit (IC) chip and field-programmable-gate-array (FPGA) integrated-circuit (IC) chip are assembled in a vertical direction. In an alternative, the multichip package further comprises a second interconnection scheme under the field-programmable-gate-array (FPGA) integrated-circuit (IC) chip, across an edge of the field-programmable-gate-array (FPGA) integrated-circuit (IC) chip and coupling to the field-programmable-gate-array (FPGA) integrated-circuit (IC) chip, an insulating dielectric layer at a same horizontal level as the field-programmable-gate-array (FPGA) integrated-circuit (IC) chip and a metal via at the same horizontal level as the field-programmable-gate-array (FPGA) integrated-circuit (IC) chip and insulating dielectric layer and vertically in the insulating dielectric layer, wherein the non-volatile memory (NVM) integrated-circuit (IC) chip is over the field-programmable-gate-array (FPGA) integrated-circuit (IC) chip and couples to the field-programmable-gate-array (FPGA) integrated-circuit (IC) chip through, in sequence, the metal via and second interconnection scheme. In an alternative, the non-volatile memory (NVM) integrated-circuit (IC) chip and field-programmable-gate-array (FPGA) integrated-circuit (IC) chip are assembled in a horizontal direction. In an alternative, the multichip package further comprises a first circuit substrate under the non-volatile memory (NVM) integrated-circuit (IC) chip and field-programmable-gate-array (FPGA) integrated-circuit (IC) chip and couples to the non-volatile memory (NVM) integrated-circuit (IC) chip and field-programmable-gate-array (FPGA) integrated-circuit (IC) chip, (1) wherein each of the first and second metal contacts is under and on the first circuit substrate and couples the first circuit substrate to the first interconnection scheme, wherein the multichip package further comprises a first metal bump between the field-programmable-gate-array (FPGA) integrated-circuit (IC) chip and first circuit substrate and coupling the field-programmable-gate-array (FPGA) integrated-circuit (IC) chip to the first circuit substrate, wherein the first metal bump has a top surface joining the field-programmable-gate-array (FPGA) integrated-circuit (IC) chip and a bottom surface joining the first circuit substrate, or (2) wherein the multichip package further comprises a second circuit substrate between the field-programmable-gate-array (FPGA) integrated-circuit (IC) chip and first circuit substrate, a first metal bump between the field-programmable-gate-array (FPGA) integrated-circuit (IC) chip and second circuit substrate and coupling the field-programmable-gate-array (FPGA) integrated-circuit (IC) chip to the second circuit substrate, and a second metal bump between the first and second circuit substrates and coupling the second circuit substrate to the first circuit substrate, wherein the second circuit substrate is a ball-grid-array (BGA) substrate, or (3) wherein the multichip package further comprises a second interconnection scheme under the field-programmable-gate-array (FPGA) integrated-circuit (IC) chip, across an edge of the field-programmable-gate-array (FPGA) integrated-circuit (IC) chip and coupling to the field-programmable-gate-array (FPGA) integrated-circuit (IC) chip, an insulating dielectric layer at a same horizontal level as the field-programmable-gate-array (FPGA) integrated-circuit (IC) chip and over the second interconnection scheme and a metal bump between the second interconnection scheme and first circuit substrate and coupling the second interconnection scheme to the first circuit substrate, or (4) wherein the multichip package further comprises a first metal bump between the non-volatile memory (NVM) integrated-circuit (IC) chip and first circuit substrate and coupling the non-volatile memory (NVM) integrated-circuit (IC) chip to the first circuit substrate, wherein the first metal bump has a top surface joining the non-volatile memory (NVM) integrated-circuit (IC) chip and a bottom surface joining the first circuit substrate, or (5) wherein the multichip package further comprises a second circuit substrate between the non-volatile memory (NVM) integrated-circuit (IC) chip and first circuit substrate, a wirebonded wire having a first end joining a top surface of the non-volatile memory (NVM) integrated-circuit (IC) chip and a second end joining a top surface of the second circuit substrate, a metal bump between the first and second circuit substrates and coupling the second circuit substrate to the first circuit substrate and a molded polymer over the second circuit substrate and encapsulating the non-volatile memory (NVM) integrated-circuit (IC) chip and wirebonded wire.

A field programmable package comprises: a first interconnection scheme; a semiconductor integrated-circuit (IC) chip coupling to the first interconnection scheme; and a multichip package having a first and second metal contact bonded to the first interconnection scheme, wherein the multichip package comprises a non-volatile memory (NVM) integrated-circuit (IC) chip having a non-volatile memory (NVM) cell for storing first data therein and a field-programmable-gate-array (FPGA) integrated-circuit (IC) chip configured to be programmed to perform a logic operation, comprising a volatile memory cell for storing second data therein associated with the first data and a selection circuit comprising a first set of input points for a first input data set for the logic operation, a second set of input points for a second input data set for the logic operation and an output point for the logic operation, wherein the second input data set has data associated with the second data stored in the volatile memory cell, wherein the selection circuit is configured to select, in accordance with the first input data set, input data from the second input data set as output data at the output point for the logic operation, wherein the field-programmable-gate-array (FPGA) integrated-circuit (IC) chip comprises a first input/output (I/O) pad coupling the first metal contact to one of the first set of input points and a second input/output (I/O) pad coupling the second metal contact to the output point, wherein the first interconnection scheme comprises a first metal interconnect coupling the first metal contact to the semiconductor integrated-circuit (IC) chip and a second metal interconnect coupling to the second metal contact. In an alternative, the first interconnection scheme is under the multichip package and across an edge of the multichip package, wherein the edge of the multichip package is recessed from an edge of the first interconnection scheme. In an alternative, the semiconductor integrated-circuit (IC) chip is bonded to the first interconnection scheme and arranged at a same horizontal level as the multichip package. In an alternative, the first interconnection scheme is a ball-grid-array (BGA) substrate or interposer. In an alternative, each of the first and second metal contacts comprises tin. In an alternative, each of the first and second metal contacts comprises a copper layer. In an alternative, the semiconductor integrated-circuit (IC) chip is a graphic-processing-unit (GPU) integrated circuit (IC) chip, central-processing-unit (CPU) integrated circuit (IC) chip, application-specific integrated circuit (ASIC) chip or digital signal processing (DSP) integrated circuit (IC) chip. In an alternative, the semiconductor integrated-circuit (IC) chip is an input/output (I/O) chip configured as an interface chip having a first interface with a circuit external to the field programmable package and a second interface with the multichip package, wherein each of the first and second interfaces is in accordance with an industry standard of peripheral component interconnect express (PCIe), universal-chiplet-interconnect express (UCIe), serial-advanced-technology-attachment (SATA) or Wi-Fi (wireless fidelity). In an alternative, the semiconductor integrated-circuit (IC) chip is an input/output (I/O) chip configured as a transceiver chip. In an alternative, the non-volatile memory (NVM) integrated-circuit (IC) chip and field-programmable-gate-array (FPGA) integrated-circuit (IC) chip are assembled in a vertical direction. In an alternative, the multichip package further comprises a second interconnection scheme under the field-programmable-gate-array (FPGA) integrated-circuit (IC) chip, across an edge of the field-programmable-gate-array (FPGA) integrated-circuit (IC) chip and coupling to the field-programmable-gate-array (FPGA) integrated-circuit (IC) chip, an insulating dielectric layer at a same horizontal level as the field-programmable-gate-array (FPGA) integrated-circuit (IC) chip and a metal via at the same horizontal level as the field-programmable-gate-array (FPGA) integrated-circuit (IC) chip and insulating dielectric layer and vertically in the insulating dielectric layer, wherein the non-volatile memory (NVM) integrated-circuit (IC) chip is over the field-programmable-gate-array (FPGA) integrated-circuit (IC) chip and couples to the field-programmable-gate-array (FPGA) integrated-circuit (IC) chip through, in sequence, the metal via and second interconnection scheme. In an alternative, the non-volatile memory (NVM) integrated-circuit (IC) chip and field-programmable-gate-array (FPGA) integrated-circuit (IC) chip are assembled in a horizontal direction. In an alternative, the multichip package further comprises a first circuit substrate under the non-volatile memory (NVM) integrated-circuit (IC) chip and field-programmable-gate-array (FPGA) integrated-circuit (IC) chip and couples to the non-volatile memory (NVM) integrated-circuit (IC) chip and field-programmable-gate-array (FPGA) integrated-circuit (IC) chip, (1) wherein each of the first and second metal contacts is under and on the first circuit substrate and couples the first circuit substrate to the first interconnection scheme, wherein the multichip package further comprises a first metal bump between the field-programmable-gate-array (FPGA) integrated-circuit (IC) chip and first circuit substrate and coupling the field-programmable-gate-array (FPGA) integrated-circuit (IC) chip to the first circuit substrate, wherein the first metal bump has a top surface joining the field-programmable-gate-array (FPGA) integrated-circuit (IC) chip and a bottom surface joining the first circuit substrate, or (2) wherein the multichip package further comprises a second circuit substrate between the field-programmable-gate-array (FPGA) integrated-circuit (IC) chip and first circuit substrate, a first metal bump between the field-programmable-gate-array (FPGA) integrated-circuit (IC) chip and second circuit substrate and coupling the field-programmable-gate-array (FPGA) integrated-circuit (IC) chip to the second circuit substrate, and a second metal bump between the first and second circuit substrates and coupling the second circuit substrate to the first circuit substrate, wherein the second circuit substrate is a ball-grid-array (BGA) substrate, or (3) wherein the multichip package further comprises a second interconnection scheme under the field-programmable-gate-array (FPGA) integrated-circuit (IC) chip, across an edge of the field-programmable-gate-array (FPGA) integrated-circuit (IC) chip and coupling to the field-programmable-gate-array (FPGA) integrated-circuit (IC) chip, an insulating dielectric layer at a same horizontal level as the field-programmable-gate-array (FPGA) integrated-circuit (IC) chip and over the second interconnection scheme and a metal bump between the second interconnection scheme and first circuit substrate and coupling the second interconnection scheme to the first circuit substrate, or (4) wherein the multichip package further comprises a first metal bump between the non-volatile memory (NVM) integrated-circuit (IC) chip and first circuit substrate and coupling the non-volatile memory (NVM) integrated-circuit (IC) chip to the first circuit substrate, wherein the first metal bump has a top surface joining the non-volatile memory (NVM) integrated-circuit (IC) chip and a bottom surface joining the first circuit substrate, or (5) wherein the multichip package further comprises a second circuit substrate between the non-volatile memory (NVM) integrated-circuit (IC) chip and first circuit substrate, a wirebonded wire having a first end joining a top surface of the non-volatile memory (NVM) integrated-circuit (IC) chip and a second end joining a top surface of the second circuit substrate, a metal bump between the first and second circuit substrates and coupling the second circuit substrate to the first circuit substrate and a molded polymer over the second circuit substrate and encapsulating the non-volatile memory (NVM) integrated-circuit (IC) chip and wirebonded wire.

A field programmable package comprises: a first semiconductor integrated-circuit (IC) chip; a second semiconductor integrated-circuit (IC) chip having a volatile memory cell for storing first data therein and a switch circuit for controlling, in accordance with the first data stored in the volatile memory cell, coupling between first and second input/output (I/O) pads of the second semiconductor integrated-circuit (IC) chip; and an interconnection scheme comprising a first metal interconnect coupling the first input/output (I/O) pad of the second semiconductor integrated-circuit (IC) chip to the first semiconductor integrated-circuit (IC) chip and a second metal interconnect coupling to the second input/output (I/O) pad of the second semiconductor integrated-circuit (IC) chip, wherein the switch circuit is configured for controlling, in accordance with the first data stored in the volatile memory cell, coupling between the first and second metal interconnects. In an alternative, the interconnection scheme is under each of the first and second semiconductor integrated-circuit (IC) chips and across an edge of each of the first and second semiconductor integrated-circuit (IC) chips. In an alternative, the first and second semiconductor integrated-circuit (IC) chips are bonded to the interconnection scheme and arranged at a same horizontal level. In an alternative, the interconnection scheme is a ball-grid-array (BGA) substrate or interposer. In an alternative, the first semiconductor integrated-circuit (IC) chip is a graphic-processing-unit (GPU) integrated circuit (IC) chip, central-processing-unit (CPU) integrated circuit (IC) chip, application-specific integrated circuit (ASIC) chip or digital signal processing (DSP) integrated circuit (IC) chip. In an alternative, the first semiconductor integrated-circuit (IC) chip is an input/output (I/O) chip configured as an interface chip having a first interface with a circuit external to the field programmable package and a second interface with the second semiconductor integrated-circuit (IC) chip, wherein each of the first and second interfaces is in accordance with an industry standard of peripheral component interconnect express (PCIe), universal-chiplet-interconnect express (UCIe), serial-advanced-technology-attachment (SATA) or Wi-Fi (wireless fidelity). In an alternative, the first semiconductor integrated-circuit (IC) chip is an input/output (I/O) chip configured as a transceiver chip. In an alternative, the field programmable package further comprises a non-volatile memory (NVM) integrated-circuit (IC) chip having a non-volatile memory (NVM) cell for storing second data therein, wherein the second data is associated with the first data.

A field programmable package comprises: a first semiconductor integrated-circuit (IC) chip; a second semiconductor integrated-circuit (IC) chip configured to be programmed to perform a logic operation, comprising a volatile memory cell for storing first data therein and a selection circuit comprising a first set of input points for a first input data set for the logic operation, a second set of input points for a second input data set for the logic operation and an output point for the logic operation, wherein the second input data set has data associated with the first data stored in the volatile memory cell, wherein the selection circuit is configured to select, in accordance with the first input data set, input data from the second input data set as output data at the output point for the logic operation, wherein the second semiconductor integrated-circuit (IC) chip comprises a first input/output (I/O) pad coupling to one of the first set of input points and a second input/output (I/O) pad coupling to the output point; and an interconnection scheme comprising a first metal interconnect coupling the first input/output (I/O) pad of the second semiconductor integrated-circuit (IC) chip to the first semiconductor integrated-circuit (IC) chip and a second metal interconnect coupling to the second input/output (I/O) pad of the second semiconductor integrated-circuit (IC) chip. In an alternative, the interconnection scheme is under each of the first and second semiconductor integrated-circuit (IC) chips and across an edge of each of the first and second semiconductor integrated-circuit (IC) chips. In an alternative, the first and second semiconductor integrated-circuit (IC) chips are bonded to the interconnection scheme and arranged at a same horizontal level. In an alternative, the interconnection scheme is a ball-grid-array (BGA) substrate or interposer. In an alternative, the first semiconductor integrated-circuit (IC) chip is a graphic-processing-unit (GPU) integrated circuit (IC) chip, central-processing-unit (CPU) integrated circuit (IC) chip, application-specific integrated circuit (ASIC) chip or digital signal processing (DSP) integrated circuit (IC) chip. In an alternative, the first semiconductor integrated-circuit (IC) chip is an input/output (I/O) chip configured as an interface chip having a first interface with a circuit external to the field programmable package and a second interface with the second semiconductor integrated-circuit (IC) chip, wherein each of the first and second interfaces is in accordance with an industry standard of peripheral component interconnect express (PCIe), universal-chiplet-interconnect express (UCIe), serial-advanced-technology-attachment (SATA) or Wi-Fi (wireless fidelity). In an alternative, the first semiconductor integrated-circuit (IC) chip is an input/output (I/O) chip configured as a transceiver chip. In an alternative, the field programmable package further comprises a non-volatile memory (NVM) integrated-circuit (IC) chip having a non-volatile memory (NVM) cell for storing second data therein, wherein the second data is associated with the first data.

A field programmable package comprises: a first interconnection scheme; a semiconductor integrated-circuit (IC) chip coupling to the first interconnection scheme; and a multichip package having a plurality of first and second metal contacts bonded to the first interconnection scheme, wherein the multichip package comprises a non-volatile memory (NVM) integrated-circuit (IC) chip having a non-volatile memory (NVM) cell for storing first data therein, and a field-programmable-gate-array (FPGA) integrated-circuit (IC) chip having an encryption/decryption circuit therein, a plurality of first metal lines running in a first direction and coupling the encryption/decryption circuit to the plurality of first metal contacts respectively and a plurality of second metal lines running in a second direction perpendicular to the first direction and coupling the encryption/decryption circuit to the plurality of second metal contacts respectively, wherein the encryption/decryption circuit comprises a plurality of programmable circuit units arranged in an array with N rows and M columns, wherein each of M and N is greater than or equal to 2, wherein each of the programmable circuit units comprises a volatile memory cell for storing second data therein associated with the first data and a switch circuit having a first node coupling to one of the plurality of first metal lines, a second node coupling to one of the plurality of second metal lines and a third node coupling to the volatile memory cell, wherein the switch circuit is configured for controlling, in accordance with the second data stored in the volatile memory cell, coupling between said one of the plurality of first metal lines and said one of the plurality of second metal lines, wherein the first interconnection scheme comprises a plurality of first metal interconnects each coupling one of the plurality of first metal contacts to a circuit external to the field programmable package and a plurality of second metal interconnects each coupling one of the plurality of second metal contacts to the semiconductor integrated-circuit (IC) chip. In an alternative, an encrypted data set at the plurality of first metal lines is configured to be decrypted by the encryption/decryption circuit into a decrypted data set at the plurality of second metal lines. In an alternative, a non-encrypted data set at the plurality of second metal lines is configured to be encrypted by the encryption/decryption circuit into an encrypted data set at the plurality of first metal lines. In an alternative, M is greater than N. In an alternative, M is equal to N. In an alternative, M is less than N. In an alternative, the field-programmable-gate-array (FPGA) integrated-circuit (IC) chip comprises an input/output (I/O) pad coupling to the first node of the switch circuit of each of the plurality of programmable circuit units in a row of the N rows through one of the plurality of first metal lines and coupling to one of the plurality of first metal interconnects through one of the plurality of first metal contacts. In an alternative, the field-programmable-gate-array (FPGA) integrated-circuit (IC) chip comprises an input/output (I/O) pad coupling to the second node of the switch circuit of each of the plurality of programmable circuit units in a column of the M columns through one of the plurality of second metal lines and coupling to one of the plurality of second metal interconnects through one of the plurality of second metal contacts. In an alternative, the first interconnection scheme is under the multichip package and across an edge of the multichip package, wherein the edge of the multichip package is recessed from an edge of the first interconnection scheme. In an alternative, the semiconductor integrated-circuit (IC) chip is bonded to the first interconnection scheme and arranged at a same horizontal level as the multichip package. In an alternative, the first interconnection scheme is a ball-grid-array (BGA) substrate or interposer. In an alternative, each of the first and second metal contacts comprises tin. In an alternative, each of the first and second metal contacts comprises a copper layer. In an alternative, the semiconductor integrated-circuit (IC) chip is a graphic-processing-unit (GPU) integrated circuit (IC) chip, central-processing-unit (CPU) integrated circuit (IC) chip, application-specific integrated circuit (ASIC) chip or digital signal processing (DSP) integrated circuit (IC) chip. In an alternative, the semiconductor integrated-circuit (IC) chip is an input/output (I/O) chip configured as an interface chip having a first interface with a circuit external to the field programmable package and a second interface with the multichip package, wherein each of the first and second interfaces is in accordance with an industry standard of peripheral component interconnect express (PCIe), universal-chiplet-interconnect express (UCIe), serial-advanced-technology-attachment (SATA) or Wi-Fi (wireless fidelity). In an alternative, the semiconductor integrated-circuit (IC) chip is an input/output (I/O) chip configured as a transceiver chip. In an alternative, the non-volatile memory (NVM) integrated-circuit (IC) chip and field-programmable-gate-array (FPGA) integrated-circuit (IC) chip are assembled in a vertical direction. In an alternative, the multichip package further comprises a second interconnection scheme under the field-programmable-gate-array (FPGA) integrated-circuit (IC) chip, across an edge of the field-programmable-gate-array (FPGA) integrated-circuit (IC) chip and coupling to the field-programmable-gate-array (FPGA) integrated-circuit (IC) chip, an insulating dielectric layer at a same horizontal level as the field-programmable-gate-array (FPGA) integrated-circuit (IC) chip and a metal via at the same horizontal level as the field-programmable-gate-array (FPGA) integrated-circuit (IC) chip and insulating dielectric layer and vertically in the insulating dielectric layer, wherein the non-volatile memory (NVM) integrated-circuit (IC) chip is over the field-programmable-gate-array (FPGA) integrated-circuit (IC) chip and couples to the field-programmable-gate-array (FPGA) integrated-circuit (IC) chip through, in sequence, the metal via and second interconnection scheme. In an alternative, the non-volatile memory (NVM) integrated-circuit (IC) chip and field-programmable-gate-array (FPGA) integrated-circuit (IC) chip are assembled in a horizontal direction. In an alternative, the multichip package further comprises a first circuit substrate under the non-volatile memory (NVM) integrated-circuit (IC) chip and field-programmable-gate-array (FPGA) integrated-circuit (IC) chip and couples to the non-volatile memory (NVM) integrated-circuit (IC) chip and field-programmable-gate-array (FPGA) integrated-circuit (IC) chip, wherein each of the first and second metal contacts is under and on the first circuit substrate and couples the first circuit substrate to the first interconnection scheme, (1) wherein the multichip package further comprises a first metal bump between the field-programmable-gate-array (FPGA) integrated-circuit (IC) chip and first circuit substrate and coupling the field-programmable-gate-array (FPGA) integrated-circuit (IC) chip to the first circuit substrate, wherein the first metal bump has a top surface joining the field-programmable-gate-array (FPGA) integrated-circuit (IC) chip and a bottom surface joining the first circuit substrate, or (2) wherein the multichip package further comprises a second circuit substrate between the field-programmable-gate-array (FPGA) integrated-circuit (IC) chip and first circuit substrate, a first metal bump between the field-programmable-gate-array (FPGA) integrated-circuit (IC) chip and second circuit substrate and coupling the field-programmable-gate-array (FPGA) integrated-circuit (IC) chip to the second circuit substrate, and a second metal bump between the first and second circuit substrates and coupling the second circuit substrate to the first circuit substrate, wherein the second circuit substrate is a ball-grid-array (BGA) substrate, or (3) wherein the multichip package further comprises a second interconnection scheme under the field-programmable-gate-array (FPGA) integrated-circuit (IC) chip, across an edge of the field-programmable-gate-array (FPGA) integrated-circuit (IC) chip and coupling to the field-programmable-gate-array (FPGA) integrated-circuit (IC) chip, an insulating dielectric layer at a same horizontal level as the field-programmable-gate-array (FPGA) integrated-circuit (IC) chip and over the second interconnection scheme and a metal bump between the second interconnection scheme and first circuit substrate and coupling the second interconnection scheme to the first circuit substrate, or (4) wherein the multichip package further comprises a first metal bump between the non-volatile memory (NVM) integrated-circuit (IC) chip and first circuit substrate and coupling the non-volatile memory (NVM) integrated-circuit (IC) chip to the first circuit substrate, wherein the first metal bump has a top surface joining the non-volatile memory (NVM) integrated-circuit (IC) chip and a bottom surface joining the first circuit substrate, or (5) wherein the multichip package further comprises a second circuit substrate between the non-volatile memory (NVM) integrated-circuit (IC) chip and first circuit substrate, a wirebonded wire having a first end joining a top surface of the non-volatile memory (NVM) integrated-circuit (IC) chip and a second end joining a top surface of the second circuit substrate, a metal bump between the first and second circuit substrates and coupling the second circuit substrate to the first circuit substrate and a molded polymer over the second circuit substrate and encapsulating the non-volatile memory (NVM) integrated-circuit (IC) chip and wirebonded wire.

A field programmable package comprises: a first semiconductor integrated-circuit (IC) chip; a second semiconductor integrated-circuit (IC) chip having an encryption/decryption circuit therein, a plurality of first metal lines running in a first direction and coupling to the encryption/decryption circuit and a plurality of second metal lines running in a second direction perpendicular to the first direction and coupling to the encryption/decryption circuit, wherein the encryption/decryption circuit comprises a plurality of programmable circuit units arranged in an array with N rows and M columns, wherein each of M and N is greater than or equal to 2, wherein each of the programmable circuit units comprises a volatile memory cell for storing first data therein and a switch circuit having a first node coupling to one of the plurality of first metal lines, a second node coupling to one of the plurality of second metal lines and a third node coupling to the volatile memory cell, wherein the switch circuit is configured for controlling, in accordance with the first data stored in the volatile memory cell, coupling between said one of the plurality of first metal lines and said one of the plurality of second metal lines, wherein the second semiconductor integrated-circuit (IC) chip comprises a plurality of first input/output (I/O) pads each coupling to one of the plurality of first metal lines and a plurality of second input/output (I/O) pads each coupling to one of the plurality of second metal lines; and an interconnection scheme comprising a plurality of first metal interconnects each coupling one of the plurality of first input/output (I/O) pads of the second semiconductor integrated-circuit (IC) chip to a circuit external to the field programmable package and a plurality of second metal interconnects each coupling one of the plurality of second input/output (I/O) pads of the second semiconductor integrated-circuit (IC) chip to the first semiconductor integrated-circuit (IC) chip. In an alternative, an encrypted data set at the plurality of first metal lines is configured to be decrypted by the encryption/decryption circuit into a decrypted data set at the plurality of second metal lines. In an alternative, a non-encrypted data set at the plurality of second metal lines is configured to be encrypted by the encryption/decryption circuit into an encrypted data set at the plurality of first metal lines. In an alternative, M is greater than N. In an alternative, M is equal to N. In an alternative, M is less than N. In an alternative, the first node of the switch circuit of each of the plurality of programmable circuit units in a row of the M rows couples to the first node of the switch circuit of each of the others of the plurality of programmable circuit units in the row and one of the plurality of first metal lines and the second node of the switch circuit of each of the plurality of programmable circuit units in a column of the N columns couples to the second node of the switch circuit of each of the others of the plurality of programmable circuit units in the column and one of the plurality of second metal lines. In an alternative, the interconnection scheme is under each of the first and second semiconductor integrated-circuit (IC) chips and across an edge of each of the first and second semiconductor integrated-circuit (IC) chips. In an alternative, the first and second semiconductor integrated-circuit (IC) chips are bonded to the interconnection scheme and arranged at a same horizontal level. In an alternative, the interconnection scheme is a ball-grid-array (BGA) substrate or interposer. In an alternative, the first semiconductor integrated-circuit (IC) chip is a graphic-processing-unit (GPU) integrated circuit (IC) chip, central-processing-unit (CPU) integrated circuit (IC) chip, application-specific integrated circuit (ASIC) chip or digital signal processing (DSP) integrated circuit (IC) chip. In an alternative, the first semiconductor integrated-circuit (IC) chip is an input/output (I/O) chip configured as an interface chip having a first interface with a circuit external to the field programmable package and a second interface with the second semiconductor integrated-circuit (IC) chip, wherein each of the first and second interfaces is in accordance with an industry standard of peripheral component interconnect express (PCIe), universal-chiplet-interconnect express (UCIe), serial-advanced-technology-attachment (SATA) or Wi-Fi (wireless fidelity). In an alternative, the first semiconductor integrated-circuit (IC) chip is an input/output (I/O) chip configured as a transceiver chip. In an alternative, the field programmable package further comprises a non-volatile memory (NVM) integrated-circuit (IC) chip having a plurality of non-volatile memory (NVM) cell for storing second data therein associated with the first data.

These, as well as other components, steps, features, benefits, and advantages of the present application, will now become clear from a review of the following detailed description of illustrative embodiments, the accompanying drawings, and the claims.

### BRIEF DESCRIPTION OF THE DRAWINGS

The drawings disclose illustrative embodiments of the present application. They do not set forth all embodiments. Other embodiments may be used in addition or instead. Details that may be apparent or unnecessary may be omitted to save space or for more effective illustration. Conversely, some embodiments may be practiced without all of the details that are disclosed. When the same reference number or reference indicator appears in different drawings, it may refer to the same or like components or steps.

Aspects of the disclosure may be more fully understood from the following description when read together with the accompanying drawings, which are to be regarded as illustrative in nature, and not as limiting. The drawings are not necessarily to scale, emphasis instead being placed on the principles of the disclosure. In the drawings:

FIGS. 1A-1C are schematic views showing block diagrams of first through third types of field programmable logic cells or elements in accordance with an embodiment of the present application.

FIGS. 2A and 2B are circuit diagrams illustrating programmable interconnects controlled by first and second types of field programmable switch cells in accordance with an embodiment of the present application.

FIG. 2C is a schematic view showing a field programmable switch matrix in accordance with an embodiment of the present application.

FIGS. 3A-3F are schematically cross-sectional views showing first through sixth types of semiconductor IC chips in accordance with an embodiment of the present application.

FIGS. 3G and 3H are cross-sectional views showing a second kind of connection structure for through silicon vias (TSVs) and a first interconnection scheme for a chip (FISC) in accordance with an embodiment of the present application.

FIG. 3I is a cross-sectional view showing a third kind of connection structure for through silicon vias (TSVs) and a first interconnection scheme for a chip (FISC) in accordance with an embodiment of the present application.

FIG. 3J is a cross-sectional view showing a fourth kind of connection structure for through silicon vias (TSVs) and a first interconnection scheme for a chip (FISC) in accordance with an embodiment of the present application.

FIGS. 4A and 4B are schematically cross-sectional views showing first and second types of vertical-through-via (VTV) connectors in accordance with an embodiment of the present application.

FIG. 4C is a schematically cross-sectional view showing each type of first, second and third types of subsystem units in accordance with an embodiment of the present application.

FIG. 4D is a circuit diagram of a dedicated field programmable integrated-circuit (DFPIC) chip in accordance with an embodiment of the present application.

FIG. 4E is a circuit diagram of an embedded field programmable integrated-circuit (eFPIC) chip in accordance with an embodiment of the present application.

FIGS. 5A-1, 5A-2, 5A-3, 5A-4 and 5A-5 are schematically top views showing a first type of FPMCPs for first, second, third, fourth and fifth alternatives respectively in accordance with an embodiment of the present application.

FIG. 5B is a block diagram illustrating inter-chip interconnection between semiconductor IC chips of a first type of FPMCPs for first and second alternatives in accordance with an embodiment of the present application.

FIG. 5C is a block diagram illustrating operation of semiconductor IC chips of a first type of FPMCPs for first and second alternatives in accordance with an embodiment of the present application.

FIG. 5D is a block diagram illustrating connection of a first type of FPMCPs for first and second alternatives to external circuits in accordance with an embodiment of the present application.

FIGS. 5E-5G are various block diagrams illustrating various connections to program or configure a FPGA IC chips or chiplet in accordance with data stored in a NVM IC chip.

FIG. 5H shows a voltage-level shift-up circuit in accordance with an embodiment of the present application.

FIG. 5I shows a voltage-level shift-down circuit in accordance with an embodiment of the present application.

FIG. 5J is a block diagram for illustrating a method for optimizing performance of a first type of FPMCP for either first or second alternative for acceleration in accordance with an embodiment of the present application.

FIGS. 6A, 7, 8A and 9A are schematically cross-sectional views showing first through fourth structures for a first type of FPMCP for any first, second or third alternative respectively in accordance with an embodiment of the present application.

FIGS. 6B, 8B and 9D are schematically cross-sectional views showing first, second and fourth structures for a first type of FPMCP for either third or fourth alternative respectively in accordance with an embodiment of the present application.

FIG. 6C is a schematically cross-sectional view showing a second type of metal bump, pillar or pad provided under two through silicon vias (TSVs) in accordance with an embodiment of the present application.

FIG. 9B is a schematically cross-sectional view showing a fourth structure for a first type of FPMCP for a second alternative in accordance with an embodiment of the present application.

FIG. 9C is a schematically cross-sectional view showing a fourth structure provided with a second type of interconnection substrate for a first type of FPMCP for either first or second alternative in accordance with an embodiment of the present application.

FIGS. 10-12 are schematically cross-sectional views showing second through fourth types of FPMCPs in accordance with an embodiment of the present application.

FIGS. 13A and 13B are schematically cross-sectional views showing various structures for a fifth type of FPMCP in accordance with an embodiment of the present application.

FIGS. 13C and 13D are schematically cross-sectional views showing a process of bonding a thermal compression bump to a thermal compression pad in accordance with an embodiment of the present application.

FIG. 13E is a schematically cross-sectional view showing a second type of metal bump, pillar or pad provided under two through silicon vias (TSVs) in accordance with an embodiment of the present application.

FIGS. 13F and 13G are schematically cross-sectional views showing twenty-second and twenty-third types of FPMCP in accordance with an embodiment of the present application

FIG. 14 is a schematically cross-sectional view showing a sixth type of FPMCPs in accordance with an embodiment of the present application.

FIGS. 15A and 15B are schematically cross-sectional views showing various structures for a seventh type of two FPMCPs in accordance with an embodiment of the present application.

FIGS. 16-18 are schematically cross-sectional views showing eighth through tenth types of FPMCPs in accordance with an embodiment of the present application.

FIGS. 19 and 19-1 are schematically cross-sectional views showing an eleventh type of FPMCP for a first alternative in accordance with an embodiment of the present application.

FIGS. 19-2 through 19-9 are schematically cross-sectional views showing eleventh type of FPMCPs for second through ninth alternatives respectively in accordance with an embodiment of the present application.

FIGS. 20-22 are schematically cross-sectional views showing twelfth through fourteenth types of FPMCPs respectively in accordance with an embodiment of the present application.

FIGS. 23A and 23B are schematically cross-sectional views showing various structures for a fifteenth type of FPMCP in accordance with an embodiment of the present application.

FIGS. 23C-23M are schematically cross-sectional views showing a process for fabricating a three-dimensional chip package for a fifteenth type of FPMCP in FIG. 23A in accordance with an embodiment of the present application.

FIG. 24 is a schematically cross-sectional view showing a sixteenth type of FPMCP in accordance with an embodiment of the present application.

FIGS. 25A, 25B and 25C are schematically cross-sectional views showing a seventeenth type of FPMCP for first, second and third alternatives respectively in accordance with an embodiment of the present application.

FIGS. 26-29 are schematically cross-sectional views showing eighteenth through twenty-first types of FPMCPs in accordance with an embodiment of the present application.

FIG. 30 is a schematically top view showing each type of twenty-fourth through twenty-eighth types of FPMCP in accordance with an embodiment of the present application.

FIGS. 31-35 are schematically cross-sectional views showing a twenty-fourth through twenty-eighth types of FPMCP along a cross-sectional line D-D or E-E in FIG. 30 in accordance with an embodiment of the present application.

FIGS. 35A and 35B are enlarged cross-sectional views showing a metal bonding pad and insulating bonding layer employed for a second form for a top structure of a semiconductor IC chip in accordance with an embodiment of the present application.

FIGS. 35C and 35D are enlarged cross-sectional views showing a metal bonding pad and insulating bonding layer employed for a second form for a bottom structure of a DFPIC or eFPIC chip in accordance with an embodiment of the present application.

FIG. 36 is a schematically cross-sectional view showing a twenty-ninth type of FPMCP in accordance with an embodiment of the present application.

While certain embodiments are depicted in the drawings, one skilled in the art will appreciate that the embodiments depicted are illustrative and that variations of those shown, as well as other embodiments described herein, may be envisioned and practiced within the scope of the present application.

### DETAILED DESCRIPTION OF THE DISCLOSURE

Illustrative embodiments are now described. Other embodiments may be used in addition or instead. Details that may be apparent or unnecessary may be omitted to save space or for a more effective presentation. Conversely, some embodiments may be practiced without all of the details that are disclosed.

### Specification for Field Programmable Logic Cell or Element

### 1. First Type of Field Programmable Logic Cell or Element

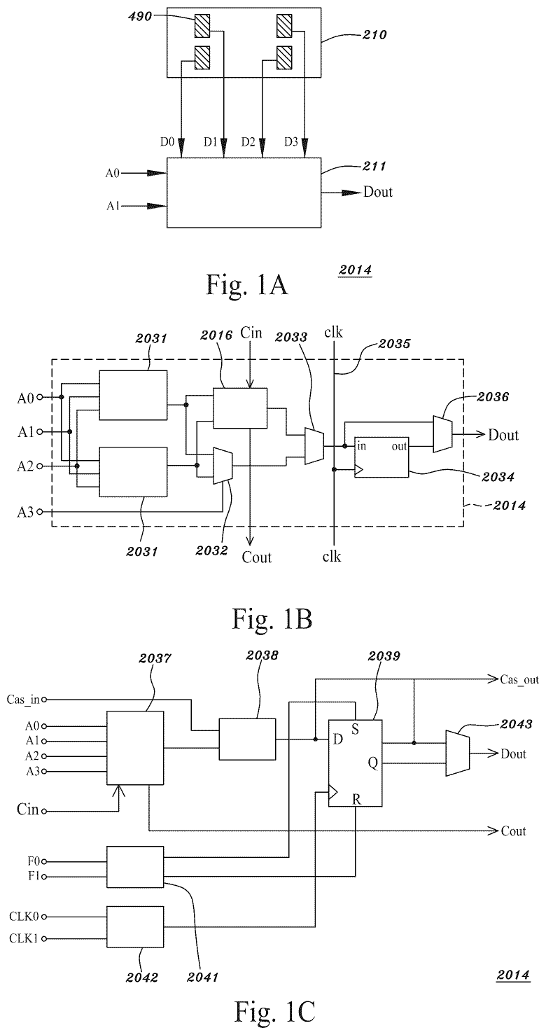

FIG. 1A is a schematic view showing a block diagram of a first type of field programmable logic cell or element in accordance with an embodiment of the present application. Referring to FIG. 1A, the first type of field programmable logic cell or element (LCE) 2014, i.e., field configurable logic cell or element, may be configured to perform logic operation on its input data set, i.e., A0 and A1. The first type of field programmable logic cell or element (LCE) 2014, i.e., logic gate or circuit, may include (1) multiple memory cells 490, i.e., configuration-programming-memory (CPM) cells, each configured to save or store one of resulting values or programming codes, e.g., D0, D1, D2 and D3, of its look-up table (LUT) 210, i.e., CPM data, and (2) a selection circuit 211, such as multiplexer, coupling to its memory cells 490 and configured to receive the resulting values of its look-up table (LUT) 210. For the field programmable logic cell or element (LCE) 2014, its selection circuit 211 may include a first set of two input points arranged in parallel for a first input data set of its selection circuit 211 associated with the input data set, i.e., A0 and A1, of the first type of field programmable logic cell or element (LCE) and a second set of four input points arranged in parallel for a second input data set, e.g., D0, D1, D2 and D3, of its selection circuit 211 each associated with one of the resulting values or programming codes of its look-up table (LUT) 210 saved or stored in its memory cells 490. Its selection circuit 211 is configured to select, in accordance with the first input data set, e.g., A0 and A1, of its selection circuit 211, a data input from the second input data set, e.g., D0, D1, D2 and D3, of its selection circuit 211 as a data output, i.e., Dout, of its selection circuit 211 for output data of the first type of field programmable logic cell or element (LCE) 2014. Each of its memory cells 490 may be (1) a volatile memory cell, such as static-random-access-memory (SRAM) cell, or (2) a non-volatile memory cell, such as magnetoresistive random-access-memory (MRAM) cell, resistive random-access-memory (RRAM) cell or floating-gate containing memory cell.

### 2. Second Type of Field Programmable Logic Cell or Element

FIG. 1B is a schematic view showing a block diagram of a second type of field programmable logic cell or element in accordance with an embodiment of the present application. Referring to FIG. 1B, the second type of field programmable logic cell or element (LCE) 2014 may be configured to perform logic operation on its input data set, i.e., A0-A3, including (1) two logic gates or circuits 2031 each provided with (i) a selection circuit (not shown), such as multiplexer, having a first set of three data inputs coupling respectively to three data inputs A0-A2 of the input data set A0-A3 of the second type of field programmable logic cell or element (LCE) 2014 and (ii) multiple memory cells, i.e., configuration-programming-memory (CPM) cells, (not shown) for storing multiple resulting values, i.e., CPM data, therein respectively, coupling to a second set of data inputs of the selection circuit, wherein each of the memory cells of each of its two logic gates or circuits 2031 may be a volatile memory cell, such as static-random-access-memory (SRAM) cell, or a non-volatile memory cell, such as magnetoresistive random-access-memory (MRAM) cell, resistive random-access-memory (RRAM) cell or floating-gate containing memory cell, wherein the selection circuit may select, in accordance with the first set of three data inputs of the selection circuit, input data from the second set of data inputs of the selection circuit as a data output of the selection circuit, (2) a fixed-wired adding unit 2016, i.e., full adder, having two-bit data inputs each coupling to the data output of the selection circuit of one of its two logic gates or circuits 2031, wherein its fixed-wired adding unit 2016 may be configured to take a carry-in data input of its fixed-wired adding unit 2016 coupling to a data input Cin of the second type of field programmable logic cell or element (LCE) 2014, which passes from a carry-out data output, i.e., Cout, of another fixed-wired adding unit 2016 of another second type of field programmable logic cell or element (LCE) 2014 in a previous stage, into account to add the two-bit data inputs of its fixed-wired adding unit 2016 as a first data output of its fixed-wired adding unit 2016 for a sum of addition and a second data output, i.e., carry-out data output, of its fixed-wired adding unit 2016 for a carry of addition coupling to a data output Cout of the second type of field programmable logic cell or element (LCE) 2014, which passes to a carry-in data input, i.e., Cin, of another adding unit 2016 of another second type of field programmable logic cell or element (LCE) 2014 in a next stage, (3) a multiplexer 2032, i.e., LUT selection multiplexer, having a first set of data input coupling to a data input A3 of the input data set A0-A3 of the second type of field programmable logic cell or element (LCE) 2014 and a second set of two data inputs each coupling to the data output of the selection circuit of one of its two logic gate or circuits 2031, wherein its multiplexer 2032 may select, in accordance with the first set of data input of its multiplexer 2032, input data from the second set of two data inputs of its multiplexer 2032 as a data output of its multiplexer 2032, (4) a multiplexer 2033, i.e., addition-selection multiplexer, having a first set of data input coupling to a programming code stored in a memory cell (not shown) of the second type of field programmable logic cell or element (LCE) 2014, which may be a volatile memory cell, such as static-random-access-memory (SRAM) cell, or a non-volatile memory cell, such as magnetoresistive random-access-memory (MRAM) cell, resistive random-access-memory (RRAM) cell or floating-gate containing memory cell, and a second set of two data inputs coupling to the first data output of its fixed-wired adding unit 2016 and the data output of its multiplexer 2032 respectively, wherein its multiplexer 2033 may select, in accordance with the first set of data input of its multiplexer 2033, input data from the second set of two data inputs of its multiplexer 2033 as a data output of its multiplexer 2033 that may be asynchronous, (5) a D-type flip-flop circuit 2034 having a first data input coupling to the data output of its multiplexer 2033 to be registered or stored therein and a second data input coupling to a clock signal elk on a clock bus 2035, wherein its D-type flip-flop circuit 2034 may synchronously generate, in accordance with the second data input of its D-type flip-flop circuit 2034, a data output associated with the first data input of its D-type flip-flop circuit 2034, wherein the data output of its D-type flip-flop circuit 2034 may be synchronous with the clock signal elk, and (6) a multiplexer 2036, i.e., synchronization-selection multiplexer, having a first set of data input coupling to a memory cell (not shown) of the second type of field programmable logic cell or element (LCE) 2014, which may be a volatile memory cell, such as static-random-access-memory (SRAM) cell, or a non-volatile memory cell, such as magnetoresistive random-access-memory (MRAM) cell, resistive random-access-memory (RRAM) cell or floating-gate containing memory cell, and a second set of two data inputs coupling to the data output of its multiplexer 2033 and the data output of its D-type flip-flop circuit 2034 respectively, wherein its multiplexer 2036 may select, in accordance with the first set of data input of its multiplexer 2036, input data from the second set of two data inputs of its multiplexer 2036 as a data output, i.e., Dout, of its multiplexer 2036 for output data of the second type of field programmable logic cell or element (LCE) 2014.

### 3. Third Type of Field Programmable Logic Cell or Element

FIG. 1C is a schematic view showing a block diagram of a third type of field programmable logic cell or element in accordance with an embodiment of the present application. Referring to FIG. 1C, the third type of field programmable logic cell or element (LCE) 2014 may be configured to perform logic operation on its input data set, i.e., A0-A3 and Cin, including a logic operator or circuit 2037 having (1) a selection circuit (not shown), such as multiplexer, having a first set of data inputs coupling to four-bit data inputs, i.e., A0-A3, of the input data set of the third type of field programmable logic cell or element (LCE) 2014 and a carry-in data input, i.e., Cin, of the input data set of the third type of field programmable logic cell or element (LCE) 2014 respectively, (2) a first set of memory cells, i.e., configuration-programming-memory (CPM) cells, (not shown), for storing multiple resulting values, i.e., CPM data, therein respectively, coupling to a second set of data inputs of the selection circuit and (3) a second set of memory cells, i.e., configuration-programming-memory (CPM) cells, (not shown), for storing multiple resulting values, i.e., CPM data, therein respectively, coupling to a third set of data inputs of the selection circuit, wherein each of the first and second sets of memory cells of the logic operator or circuit 2037 may be a volatile memory cell, such as static-random-access-memory (SRAM) cell, or a non-volatile memory cell, such as magnetoresistive random-access-memory (MRAM) cell, resistive random-access-memory (RRAM) cell or floating-gate containing memory cell, wherein the selection circuit is configured to select, in accordance with the first set of data inputs of the selection circuit, input data from the second set of data inputs of the selection circuit as a first data output of the selection circuit and select, in accordance with the first set of data inputs of the selection circuit, input data from the third set of data inputs of the selection circuit as a second data output of the selection circuit. In an example, when its logic operator or circuit 2037 performs an addition operation, its logic operator or circuit 2037 may be configured to take the carry-in data input, i.e., Cin, of the input data set of the third type of field programmable logic cell or element (LCE) 2014 from a carry-out data output Cout of another third type of field programmable logic cell or element (LCE) 2014 in a previous stage into account to add two-bit digits (A0, A1) of the input data set of the third type of field programmable logic cell or element (LCE) 2014 and two-bit digits (A2, A3) of the input data set of the input data set of the third type of field programmable logic cell or element (LCE) 2014 as a sum of addition of the two two-bit digits (A0, A1) and (A2, A3) at the first data output of the selection circuit and a carry of addition of the two two-bit digits (A0, A1) and (A2, A3) at the second data output of the selection circuit for a carry-out data output, i.e., Cout, of output data of the third type of field programmable logic cell or element (LCE) 2014, which may be associated with a carry-in data input Cin of another third type of field programmable logic cell or element (LCE) 2014 in a next stage. In another example, when its logic operator or circuit 2037 performs a logic operation, its logic operator or circuit 2037 may be configured to select, in accordance with the four-bit data inputs, i.e., A0-A3, of the input data set of the third type of field programmable logic cell or element (LCE) 2014, input data from the second set of data inputs of the selection circuit as a data output of the logic operation at the first data output of the selection circuit.

Referring to FIG. 1C, the third type of field programmable logic cell or element (LCE) 2014 may further include (1) a cascade circuit 2038 provided with a logic gate having a first data input associated with a data input, i.e., Cas_in, of the third type of field programmable logic cell or element (LCE) 2014 for cascade data passed through one or more hard wires from a data output, i.e., Cas_out, of another third type of field programmable logic cell or element (LCE) 2014 in a previous stage and a second data input associated with the first data output of the selection circuit of its logic operator or circuit 2037, wherein the logic gate of its cascade circuit 2038 may perform AND or OR logic operation on the first and second data inputs of its cascade circuit 2038 as a data output of its cascade circuit 2038, wherein the data output of its cascade circuit 2038 may be asynchronous, (2) a D-type flip-flop circuit 2039 having a first data input coupling to the data output of its cascade circuit 2038 to be registered or stored therein and a second data input coupling to a clock signal on a clock bus 2040, wherein its D-type flip-flop circuit 2039 may synchronously generate, in accordance with the second data input of its D-type flip-flop circuit 2039, a data output associated with the first data input of its D-type flip-flop circuit 2039, wherein the data output of its D-type flip-flop circuit 2039 may be synchronous with the clock signal, (3) a set-reset control circuit 2041 coupling to its D-type flip-flop circuit 2039 to set, reset or unchange its D-type flip-flop circuit 2039 in accordance with two data inputs of its set-reset control circuit 2041 coupling respectively to two data inputs, i.e., F0 and F1, of the third type of field programmable logic cell or element (LCE) 2014, and (4) a clock control circuit 2042 coupling to its D-type flip-flop circuit 2039 through the clock bus 2040, wherein its clock control circuit 2042 is configured to generate, in accordance with two data inputs of its clock control circuit 2042 coupling to two data inputs, i.e., CLK0 and CLK1, of the third type of field programmable logic cell or element (LCE) 2014 respectively, the clock signal on the clock bus 2040 in one of various modes. For example, its clock control circuit 2042 may be controlled to be enabled or disabled in accordance with the data input, i.e., CLK0, of the third type of field programmable logic cell or element (LCE) 2014. The clock signal may be controlled in a mode to be the same as a reference clock in accordance with the data input, i.e., CLK1, of the third type of field programmable logic cell or element (LCE) 2014, or the clock signal may be controlled in another mode to be inverted to the reference clock in accordance with the data input, i.e., CLK1, of the third type of field programmable logic cell or element (LCE) 2014.

Referring to FIG. 1C, the third type of field programmable logic cell or element (LCE) 2014 may further include a multiplexer 2043, i.e., synchronization-selection multiplexer, having a first set of data input coupling to a memory cell (not shown) of the third type of field programmable logic cell or element (LCE) 2014, which may be a volatile memory cell, such as static-random-access-memory (SRAM) cell, or a non-volatile memory cell, such as magnetoresistive random-access-memory (MRAM) cell, resistive random-access-memory (RRAM) cell or floating-gate containing memory cell, and a second set of two data inputs coupling to the data output of its cascade circuit 2038 and the data output of its D-type flip-flop circuit 2039 respectively, wherein its multiplexer 2043 may select, in accordance with the first set of data input of its multiplexer 2043, input data from the second set of two data inputs of its multiplexer 2043 as a data output, i.e., Dout, of its multiplexer 2043 for output data of the third type of field programmable logic cell or element (LCE) 2014. The third type of field programmable logic cell or element (LCE) 2014 may further include a data output, i.e., Cas_out, for cascade data coupling to the data output of its cascade circuit 2038, wherein the data output, i.e., Cas_out, of the third type of field programmable logic cell or element (LCE) 2014 may be passed through one or more hard wires to the data input, i.e., Cas_in, of another third type of field programmable logic cell or element (LCE) 2014 in a next stage.

### Specification for Field Programmable Switch Cell

### 1. First Type of Field Programmable Switch Cell

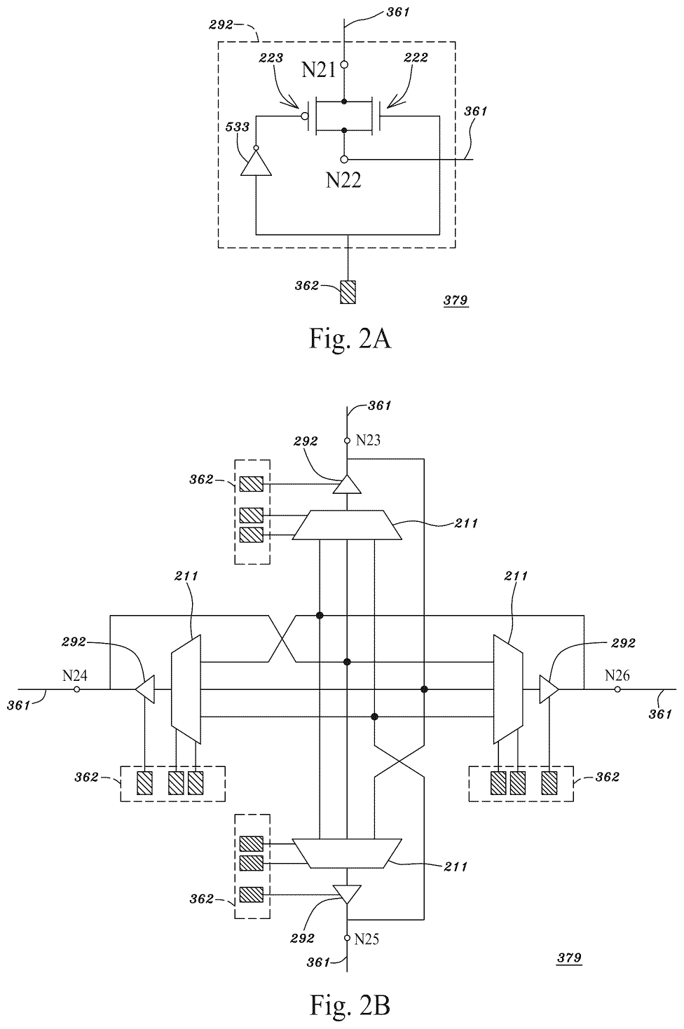

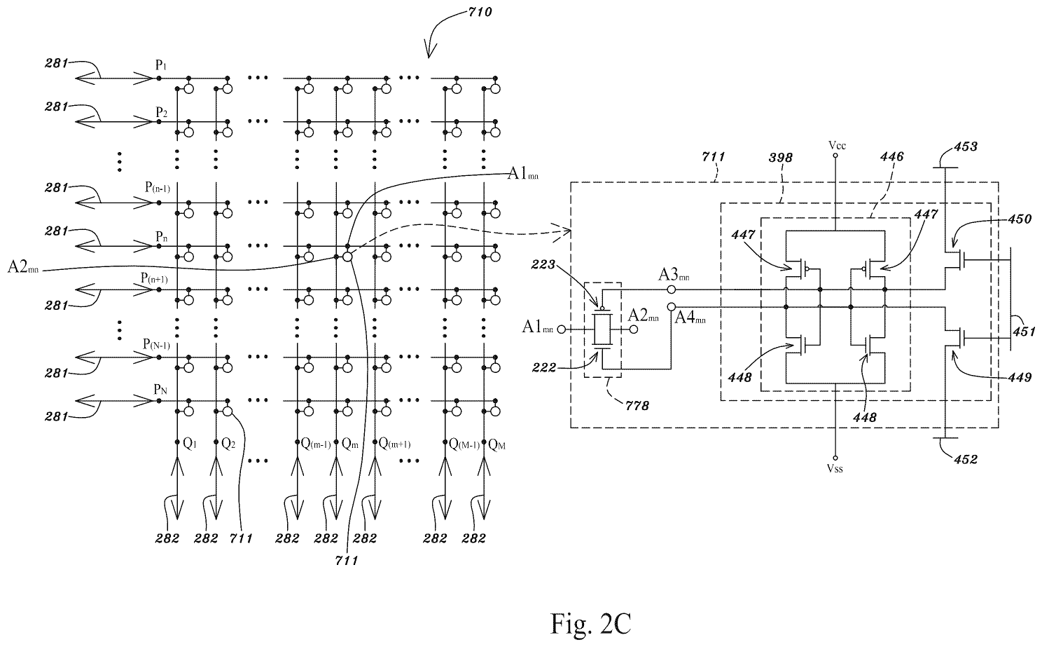

FIG. 2A is a circuit diagram illustrating programmable interconnects controlled by a first type of field programmable switch cell in accordance with an embodiment of the present application. Referring to FIG. 2A, the first type of field programmable switch cell 379, i.e., field-programmable interconnection (FPI) circuits or configurable switch cell, is configured to control coupling of its multiple nodes, i.e., N21 and N22, including (1) a pass/no-pass switch 292 composed of an N-type metal-oxide-semiconductor (MOS) transistor 222, a P-type metal-oxide-semiconductor (MOS) transistor 223 coupling in parallel to the N-type metal-oxide-semiconductor (MOS) transistor 222, wherein each of the N-type and P-type metal-oxide-semiconductor (MOS) transistors 222 and 223 may be configured to form a channel between two opposites nodes N21 and N22 of the first type of field programmable switch cell 379 coupling to two programmable interconnects 361 respectively, and an inverter 533 having an input point coupling to a gate terminal of the N-type MOS transistor 222 and an output point coupling to a gate terminal of the P-type MOS transistor 223, wherein the inverter 533 is configured to invert a data input of the inverter 533 at the input point of the inverter 533 as a data output of the inverter 533 at the output point of the inverter 533, and (2) a memory cell 362, i.e., configuration-programming-memory (CPM) cell, configured for storing or saving a programming code, i.e., CPM data, therein, wherein its memory cell 362 couples to the input point of the inverter 533 of its pass/no-pass switch 292 and the gate terminal of the N-type MOS transistor 222 of its pass/no-pass switch 292. Thereby, its pass/no-pass switch 292 is configured to control, in accordance with a data input of its pass/no-pass switch 292 associated with the programming code stored or saved in its memory cell 362, coupling between the two programmable interconnects 361.

### 2. Second Type of Field Programmable Switch Cell

FIG. 2B is a circuit diagram illustrating programmable interconnects controlled by a second type of field programmable switch cell in accordance with an embodiment of the present application. Referring to FIG. 2B, the second type of field programmable switch cell 379, i.e., field-programmable interconnection (FPI) circuits or configurable switch cell, is configured to control coupling of its multiple nodes, i.e., N23-N26, including (1) four sets of memory cells 362, i.e., configuration-programming-memory (CPM) cells, at its front, rear, left and right sides respectively, wherein each set of its four sets of memory cells 362 is configured to store or save first and second sets of programming code, i.e., CPM data, (2) four selection circuits 211, such as multiplexer, at its front, rear, left and right sides respectively, wherein each of its four selection circuits 211 may be configured to select, in accordance with a first input data set thereof at a first set of input points thereof associated with a first set of programming codes saved or stored in a set of its four sets of memory cells 362, a data input from a second input data set thereof at a second set of three input points thereof as a data output thereof at an output point thereof, and (2) four pass/no-pass switches 292 at its front, rear, left and right sides respectively, wherein each of its four pass/no-pass switches 292 may have an input point coupling to the output point of one of its four selection circuits 211 to be configured to control, in accordance with a first data input thereof associated with a second set of programming codes saved or stored in a set of its four sets of memory cells 362, coupling between the input point thereof for a second data input thereof associated with the data output of said one of its four selection circuits 211 and an output point thereof for a data output thereof and amplify the second data input thereof as the data output thereof at the output point thereof to act as one of four data outputs of the second type of field programmable switch cell 379 at one of its four nodes N23, N24, N25 and N26. Each of the second set of three input points of each of its four selection circuits 211 may couple to one of the second set of three input points of each of another two of its four selection circuits 211 and to the output point of one of its four pass/no-pass switches 292, the input point of which couples to the output point of the other of its four pass/no-pass switches 292. Thereby, each of its four selection circuits 211 may select, in accordance with the first input data set thereof at the first set of input points thereof associated with a first set of programming codes saved or stored in a specific set of its four sets of memory cells 362, a data input from the second input data set thereof at the second set of three input points thereof coupling respectively to three of its four nodes N23, N24, N25 and N26 coupling respectively to four programmable interconnects 361 extending in four different directions respectively, and one of its four pass/no-pass switches 292, the input point of which couples to the output point of said each of its four pass/no-pass switches 292, may be switched, in accordance with the first data input thereof associated with a second set of programming codes saved or stored in the specific set of its four sets of memory cells 362, to pass the second data input thereof as the data output thereof at the other of its four nodes N23, N24, N25 and N26. For example, a front one of its selection circuits 211 may select, in accordance with the first input data set thereof at the first set of input points thereof associated with a first set of programming codes saved or stored in a front set of its four sets of memory cells 362, a data input from the second input data set thereof at the second set of three input points thereof coupling respectively to three nodes N24, N25 and N26 of its four nodes N23, N24, N25 and N26 at its left, rear and right sides, and a front one of its four pass/no-pass switches 292 may be switched, in accordance with the first data input thereof associated with a second set of programming codes saved or stored in the front set of its four sets of memory cells 362, to pass the second data input thereof as the data output thereof at the other node N23 of its four nodes N23, N24, N25 and N26. Accordingly, data from one of the four programmable interconnects 361 coupling respectively to its four nodes N23, N24, N25 and N26 may be switched by the second type of field programmable switch cell 379 to be passed to another one, two or three of the four programmable interconnects 361. Each of its four sets of memory cells 362 may be (1) a volatile memory cell, such as static-random-access-memory (SRAM) cell, or (2) a non-volatile memory cell, such as magnetoresistive random-access-memory (MRAM) cell, resistive random-access-memory (RRAM) cell or floating-gate containing memory cell.

### Specification for Field Programmable Switch Matrix

FIG. 2C is a schematic view showing a field programmable switch matrix in accordance with an embodiment of the present application. Referring to FIG. 2C, a field programmable switch matrix 710 may be an encryption/decryption circuit used for field programmable encryption/decryption, a programmable interconnection circuit used for field programmable interconnection and/or a programmable logic circuit used for field programmable logics. The field programmable switch matrix 710 may include multiple field programmable switch units 711, i.e., programmable circuit units, arranged in multiple rows having the number of N and multiple columns having the number of M, wherein the number of M may be greater than or equal to 2 and range from 4 to 16, such as 8, and the number of N may be greater than or equal to 2 and range from 4 to 16, such as 8. In a case, the number of M may be equal to the number of N. Alternatively, the number of M may be different from the number of N. Referring to FIG. 2C, for the field programmable switch matrix 710, each of its field programmable switch units 711 may include (1) a pass/no-pass switch 778 having an N-type metal-oxide-semiconductor (MOS) transistor 222 and a P-type metal-oxide-semiconductor (MOS) transistor 223 each configured to form a channel having an end at a first node A1ₘₙ of its pass/no-pass switch 778 coupling to a node Pₙ of its nodes P₁-P_{N} and the other opposite end at a second node A2ₘₙ of its pass/no-pass switch 778 coupling to a node Qₘ of its nodes Q₁-Q_{M} and (2) a memory cell 398, such as static random-access memory (SRAM) cell or non-volatile memory (NVM) cell, for storing or registering data or information therein associated with a password, encryption/decryption codes or programming codes. For the field programmable switch matrix 710, the pass/no-pass switches 778 of its field programmable switch units 711 arranged in each row may have the first nodes A1ₘₙ coupling to each other and to a node Pₙ of its nodes P₁-P_{N} and the pass/no-pass switches 778 of its field programmable switch units 711 arranged in each column may have the second nodes A2ₘₙ coupling to each other and to a node Qₘ of its nodes Q₁-Q_{M}.

For more elaboration, referring to FIG. 2C, for the field programmable switch matrix 710, the memory cell 398 of each of its field programmable switch units 711 may have a memory unit 446 composed of 4 data-latch transistors 447 and 448, that is, two pairs of a P-type MOS transistor 447 and N-type MOS transistor 448 both having respective drain terminals coupled to each other, respective gate terminals coupled to each other and respective source terminals coupled to the voltage Vcc of power supply and to the voltage Vss of ground reference, and the gate terminals of the P-type and N-type MOS transistors 447 and 448 in the left pair are coupled to the drain terminals of the P-type and N-type MOS transistors 447 and 448 in the right pair, acting as a first output point A3ₘₙ of the memory unit 446 for a first data output of the memory unit 446 coupling to the gate terminal of the P-type metal-oxide-semiconductor (MOS) transistor 223 of the pass/no-pass switch 778 of said each of its field programmable switch units 711. The gate terminals of the P-type and N-type MOS transistors 447 and 448 in the right pair are coupled to the drain terminals of the P-type and N-type MOS transistors 447 and 448 in the left pair, acting as a second output point A4ₘₙ of the memory unit 446 for a second data output of the memory unit 446 coupling to the gate terminal of the N-type metal-oxide-semiconductor (MOS) transistor 222 of the pass/no-pass switch 778 of said each of its field programmable switch units 711. The memory cell 398 of each of its field programmable switch units 711 may further include two switches or transfer (write) transistors 449 and 450, such as N-type or P-type MOS transistors, wherein the switch 449 may have a gate terminal coupled to a word line 451 and a channel having a terminal coupled to a bit line 452 and another terminal coupled to the drain terminals of the P-type and N-type MOS transistors 447 and 448 in the left pair and the gate terminals of the P-type and N-type MOS transistors 447 and 448 in the right pair, and the switch 450 may have a gate terminal coupled to the word line 451 and a channel having a terminal coupled to a bit-bar line 453 and another terminal coupled to the drain terminals of the P-type and N-type MOS transistors 447 and 448 in the right pair and the gate terminals of the P-type and N-type MOS transistors 447 and 448 in the left pair. A logic level on the bit line 452 is opposite a logic level on the bit-bar line 453. Each of the switches 449 and 450 may be considered as a programming transistor for writing the data or information associated with the password, encryption/decryption codes or programming codes into storage nodes of the 4 data-latch transistors 447 and 448, i.e., at the drains and gates of the 4 data-latch transistors 447 and 448. Each of the switches 449 and 450 may be controlled via the word line 451 to turn on connection from the bit line 452 to the drain terminals of the P-type and N-type MOS transistors 447 and 448 in the left pair and the gate terminals of the P-type and N-type MOS transistors 447 and 448 in the right pair via the channel of the switch 449 and connection from the bit-bar line 453 to the drain terminals of the P-type and N-type MOS transistors 447 and 448 in the right pair and the gate terminals of the P-type and N-type MOS transistors 447 and 448 in the left pair via the switch 450. Thereby the logic level on the bit line 452 may be reloaded into the conductive line between the gate terminals of the P-type and N-type MOS transistors 447 and 448 in the right pair and the conductive line between the drain terminals of the P-type and N-type MOS transistors 447 and 448 in the left pair, and the logic level on the bit-bar line 453 may be reloaded into the conductive line between the gate terminals of the P-type and N-type MOS transistors 447 and 448 in the left pair and the conductive line between the drain terminals of the P-type and N-type MOS transistors 447 and 448 in the right pair. Thus, the logic level on the bit line 452 may be registered or latched in the conductive line between the gate terminals of the P-type and N-type MOS transistors 447 and 448 in the right pair and in the conductive line between the drain terminals of the P-type and N-type MOS transistors 447 and 448 in the left pair; a logic level on the bit-bar line 453 may be registered or latched in the conductive line between the gate terminals of the P-type and N-type MOS transistors 447 and 448 in the left pair and in the conductive line between the drain terminals of the P-type and N-type MOS transistors 447 and 448 in the right pair.

Referring to FIG. 2C, for the field programmable switch matrix 710, the pass/no-pass switch 778 of each of its field programmable switch units 711 may control, in accordance with its two data outputs at its respective two nodes A3ₘₙ and A4ₘₙ, coupling between its first and second nodes A1ₘₙ and A2ₘₙ. For example, the pass/no-pass switch 778 of each of its field programmable switch units 711 may be controlled by the memory cell 398 of said each of its field programmable switch units 711 to be turned on to couple its first node A1ₘₙ to its second node A2ₘₙ or to be turned off to cut off connection between its first and second nodes A1ₘₙ and A2ₘₙ. For example, the pass/no-pass switch 778 of only one of its field programmable switch units 711 in each row may be turned on to couple its first node A1ₘₙ to its second node A2ₘₙ, and each of the pass/no-pass switches 778 of the others of its field programmable switch units 711 in said each row may be turned off to cut off coupling between its first and second nodes A1ₘₙ and A2ₘₙ; the pass/no-pass switch 778 of only one of its field programmable switch units 711 in each column may be turned on to couple its first node A1ₘₙ to its second node A2ₘₙ, and each of the pass/no-pass switches 778 of the others of its field programmable switch units 711 in said each column may be turned off to cut off coupling between its first and second nodes A1ₘₙ and A2ₘₙ.

### Specification for Semiconductor Integrated-Circuit (IC) Chip

### 1. First Type of Semiconductor IC Chip

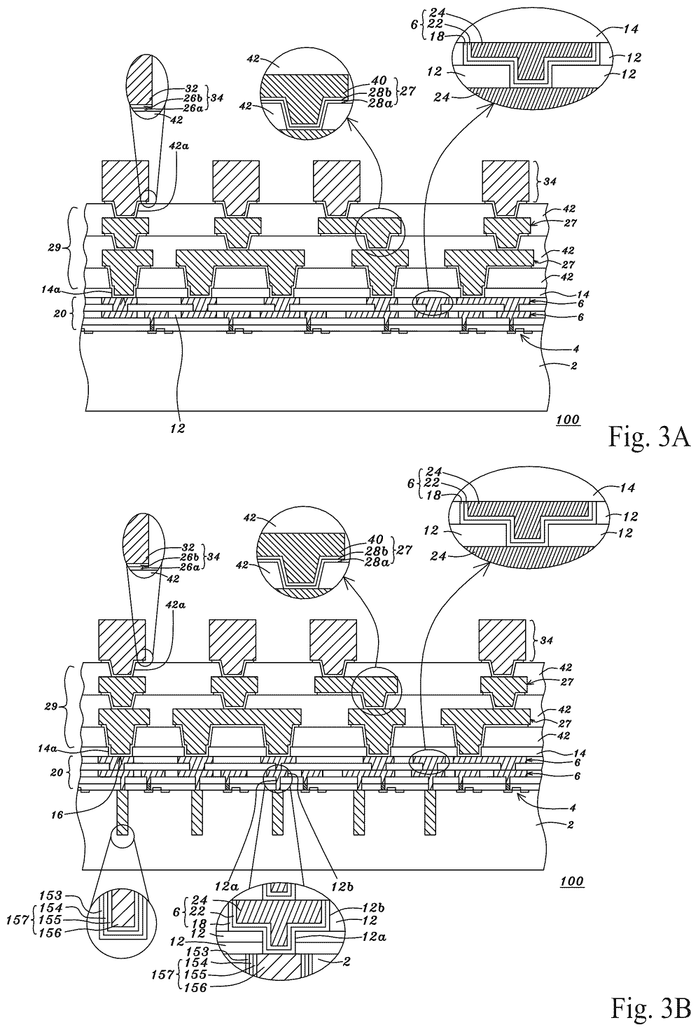

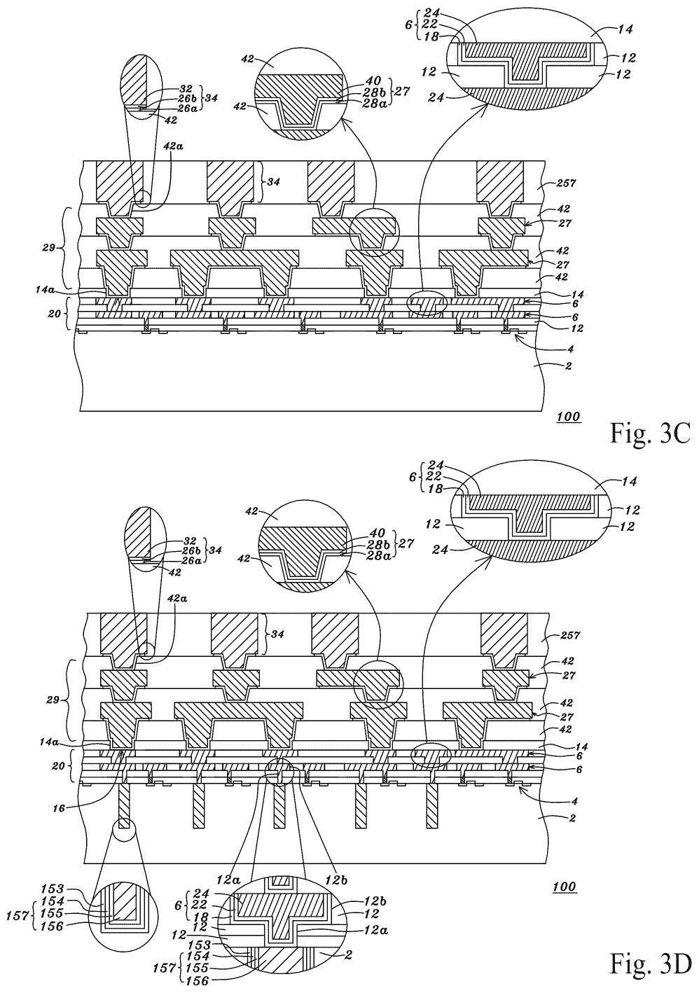

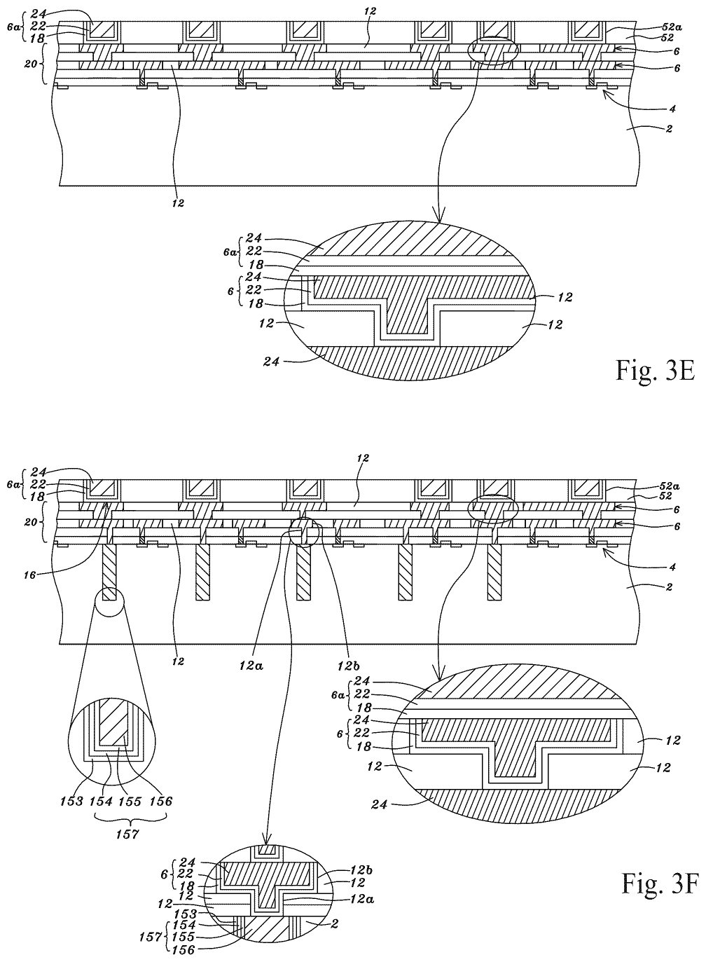

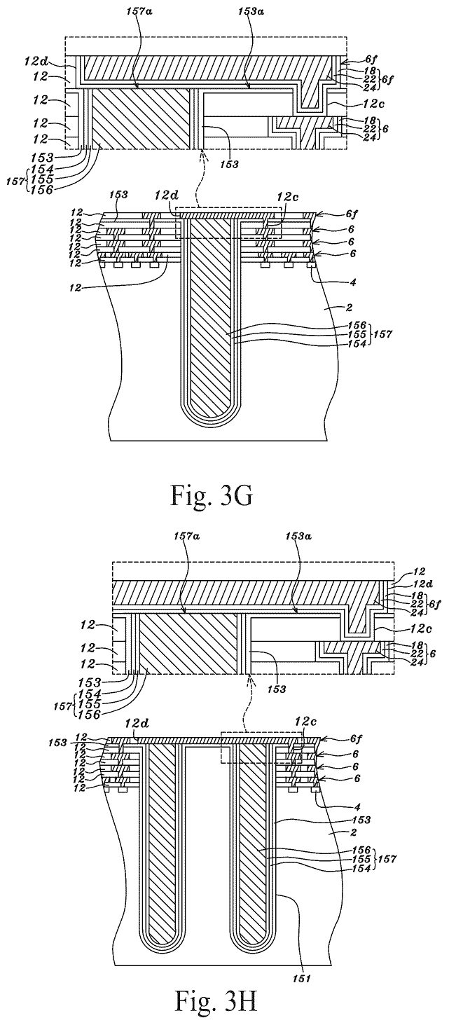

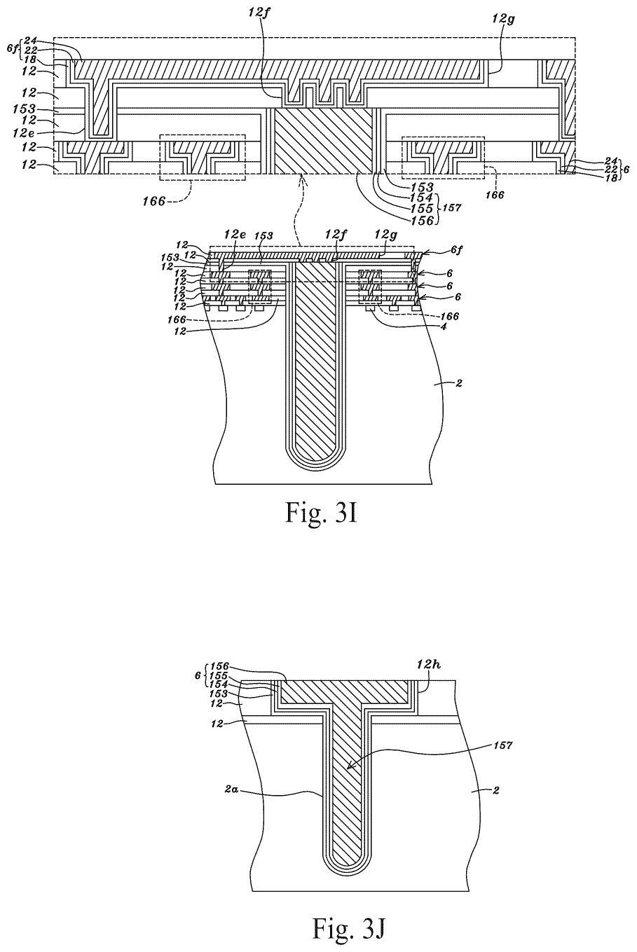

FIG. 3A is a schematically cross-sectional view showing a first type of semiconductor IC chip in accordance with an embodiment of the present application. Referring to FIG. 3A, the first type of semiconductor IC chip 100 may include (1) a semiconductor substrate 2, such as silicon substrate, GaAs substrate, SiGe substrate or silicon-on-insulator (SOI) substrate; (2) multiple semiconductor devices 4, such as planar metal-oxide-semiconductor (MOS) transistors, fin field effective transistors (FINFETs), gate-all-around field effective transistors (GAAFETs) or passive devices, at a top surface of its semiconductor substrate 2; (3) a first interconnection scheme for a chip (FISC) 20 over its semiconductor substrate 2, provided with one or more interconnection metal layers 6 coupling to its semiconductor devices 4 and one or more insulating dielectric layers 12 each between neighboring two of its interconnection metal layers 6, wherein each of its one or more interconnection metal layers 6 may have a thickness between 0.1 and 2 micrometers; (4) a passivation layer 14 over its first interconnection scheme for a chip (FISC) 20, wherein multiple openings 14a in its passivation layer 14 may be aligned with and over multiple metal pads or input/output (I/O) pads of the topmost one of the interconnection metal layers 6 of its first interconnection scheme for a chip (FISC) 20; (5) a second interconnection scheme for a chip (SISC) 29 optionally provided over its passivation layer 14, provided with one or more interconnection metal layers 27 coupling to the topmost one of the interconnection metal layers 6 of its first interconnection scheme for a chip (FISC) 20 through the openings 14a in its passivation layer 14 and one or more polymer layers 42, i.e., insulating dielectric layers, each between neighboring two of its interconnection metal layers 27, under a bottommost one of its interconnection metal layers 27 or over a topmost one of its interconnection metal layers 27, wherein multiple openings 42a in the topmost one of its polymer layers 42 may be aligned with and over multiple metal pads or input/output (I/O) pads of the topmost one of the interconnection metal layers 27 of its second interconnection scheme for a chip (SISC) 29, wherein each of the interconnection metal layers 27 of its second interconnection scheme for a chip (SISC) 29 may have a thicknesses between 3 and 5 micrometers; and (6) multiple micro-bumps, micro-pillars or micro-pads 34 each on one of the metal pads or input/output (I/O) pads of the topmost one of the interconnection metal layers 27 of its second interconnection scheme for a chip (SISC) 29 or, if the second interconnection scheme for a chip (SISC) 29 is not provided, on one of the metal pads or input/output (I/O) pads of the topmost one of the interconnection metal layers 6 of its first interconnection scheme for a chip (FISC) 20.

For the first type of semiconductor IC chip 100 in case for a field-programmable-gate-array (FPGA) IC chip 200 mentioned in the following paragraphs, its semiconductor devices 4 may be provided with (1) a first group thereof for any type of the first, second and third types of field programmable logic cells or elements (LCEs) 2014 as illustrated in FIGS. 1A-1C to be arranged in the first type of semiconductor IC chip 100, (2) a second group thereof for either type of the first and second types of field programmable switch cell 379 as illustrated in FIGS. 2A and 2B to be arranged in the first type of semiconductor IC chip 100 and (3) a third group thereof for the field programmable switch matrix 710 as illustrated in FIG. 2C to be arranged in the first type of semiconductor IC chip 100.

Referring to FIG. 3A, for the first type of semiconductor IC chip 100, each of the interconnection metal layers 6 of its first interconnection scheme for a chip (FISC) 20 may include (1) a copper layer 24 having lower portions in openings in a lower one of the insulating dielectric layers 12, such as SiOC layers having a thickness of between 3 nm and 500 nm, and upper portions having a thickness of between 3 nm and 500 nm over the lower one of the insulating dielectric layers 12 and in openings in an upper one of the insulating dielectric layers 12, (2) an adhesion metal layer 18, such as titanium or titanium nitride having a thickness of between 1 nm and 50 nm, at a bottom and sidewall of each of the lower portions of the copper layer 24 and at a bottom and sidewall of each of the upper portions of the copper layer 24, and (3) an electroplating seed layer 22, such as copper, between the copper layer 24 and the adhesion metal layer 18, wherein the copper layer 24 has a top surface substantially coplanar with a top surface of the upper one of the insulating dielectric layers 12. Each of the interconnection metal layers 6 of its first interconnection scheme for a chip (FISC) 20 may be patterned with a metal line or trace having a thickness between 0.1 and 2 micrometers, between 3 nm and 1,000 nm or between 10 nm and 500 nm, or thinner than or equal to 5 nm, 10 nm, 30 nm, 50 nm, 100 nm, 200 nm, 300 nm, 500 nm or 1,000 nm and a width between 3 nm and 1,000 nm or between 10 nm and 500 nm, or narrower than 5 nm, 10 nm, 20 nm, 30 nm, 70 nm, 100 nm, 300 nm, 500 nm or 1,000 nm, for example. Each of the insulating dielectric layers 12 of its first interconnection scheme for a chip (FISC) 20 may be made of a layer of silicon oxide or silicon oxycarbide having a thickness between 0.1 and 2 micrometers, between 3 nm and 1,000 nm or between 10 nm and 500 nm, or thinner than 5 nm, 10 nm, 30 nm, 50 nm, 100 nm, 200 nm, 300 nm, 500 nm or 1,000 nm. Alternatively, each of the insulating dielectric layers 12 of its first interconnection scheme for a chip (FISC) 20 may include a material having a low dielectric constant of lower than 3, for example. Alternatively, each of the insulating dielectric layers 12 of its first interconnection scheme for a chip (FISC) 20 may be a composite layer including two silicon-oxynitride layers at a top and bottom thereof and a silicon-oxide layer between the two silicon-oxynitride layers thereof. Alternatively, the topmost one of the interconnection metal layers 6 of its first interconnection scheme for a chip (FISC) 20 may be made of a layer of aluminum having a thickness between 1 and 5 micrometers.

Referring to FIG. 3A, for the first type of semiconductor IC chip 100, its passivation layer 14 containing a silicon-nitride, SiON or SiCN layer having a thickness greater than 0.3 μm for example and, alternatively, a polymer layer having a thickness between 1 and 10 μm may protect the semiconductor devices 4 and the interconnection metal layers 6 from being damaged by moisture foreign ion contamination, or from water moisture or contamination form external environment, for example sodium mobile ions. Each of the openings 14a in its passivation layer 14 may have a transverse dimension, from a top view, of between 0.5 and 20 μm.

Referring to FIG. 3A, for the first type of semiconductor IC chip 100, each of the interconnection metal layers 27 of its second interconnection scheme for a chip (SISC) 29 may include (1) a copper layer 40 having lower portions in openings in one of the polymer layers 42 having a thickness of between 0.3 μm and 20 μm, and upper portions having a thickness between 0.3 m and 20 μm over said one of the polymer layers 42, (2) an adhesion metal layer 28a, such as titanium or titanium nitride having a thickness of between 1 nm and 50 nm, at a bottom and sidewall of each of the lower portions of the copper layer 40 and at a bottom of each of the upper portions of the copper layer 40, and (3) an electroplating seed layer 28b, such as copper, between the copper layer 40 and the adhesion metal layer 28a, wherein said each of the upper portions of the copper layer 40 may have a sidewall not covered by the adhesion metal layer 28a. Each of the interconnection metal layers 27 of its second interconnection scheme for a chip (SISC) 29 may be patterned with a metal line or trace having a thickness between, for example, 0.3 μm and 20 μm, 0.5 m and 10 μm, 1 μm and 5 μm, 1 μm and 10 μm, or 2 μm and 10 μm, or thicker than or equal to 0.3 μm, 0.5 μm, 0.7 μm, 1 μm, 1.5 μm, 2 μm or 3 μm and a width between, for example, 0.3 μm and 20 μm, 0.5 μm and 10 μm, 1 μm and 5 μm, 1 μm and 10 μm, or 2 μm and 10 μm, or wider than or equal to 0.3 μm, 0.5 μm, 0.7 μm, 1 μm, 1.5 μm, 2 μm or 3 μm. Each of the polymer layers 42 of its second interconnection scheme for a chip (SISC) 29 may have a thickness between, for example, 0.3 μm and 20 μm, 0.5 m and 10 μm, 1 μm and 5 μm, or 1 μm and 10 μm, or thicker than or equal to 0.3 μm, 0.5 μm, 0.7 μm, 1 μm, 1.5 μm, 2 μm or 3 μm.

Referring to FIG. 3A, for the first type of semiconductor IC chip 100, each of its micro-bumps, micro-pillars or micro-pads 34 may be of one type of various types, i.e., first through fourth types. A first type of micro-bumps, micro-pillars or micro-pads 34 may include, as seen in FIG. 3A, (1) an adhesion metal layer 26a, such as titanium (Ti) or titanium nitride (TiN) layer having a thickness of between 1 nm and 50 nm, on the topmost one of the interconnection metal layers 27 of its second interconnection scheme for a chip (SISC) 29 or, if the second interconnection scheme for a chip (SISC) 29 is not provided, on the topmost one of the interconnection metal layers 6 of its first interconnection scheme for a chip (FISC) 20, (2) an electroplating seed layer 26b, such as copper, on its adhesion metal layer 26a and (3) a copper layer 32 having a thickness of between 1 μm and 60 μm, between 2 μm and 20 μm or between 10 μm and 50 μm on its seed layer 26b.

Alternatively, a second type of micro-bumps, micro-pillars or micro-pads 34 may include the adhesion metal layer 26a, seed layer 26b and copper layer 32 as mentioned above, and may further include a tin-containing solder cap made of tin or a tin-silver alloy, which has a thickness of between 1 μm and 50 μm or between 20 μm and 100 μm on its copper layer 32.

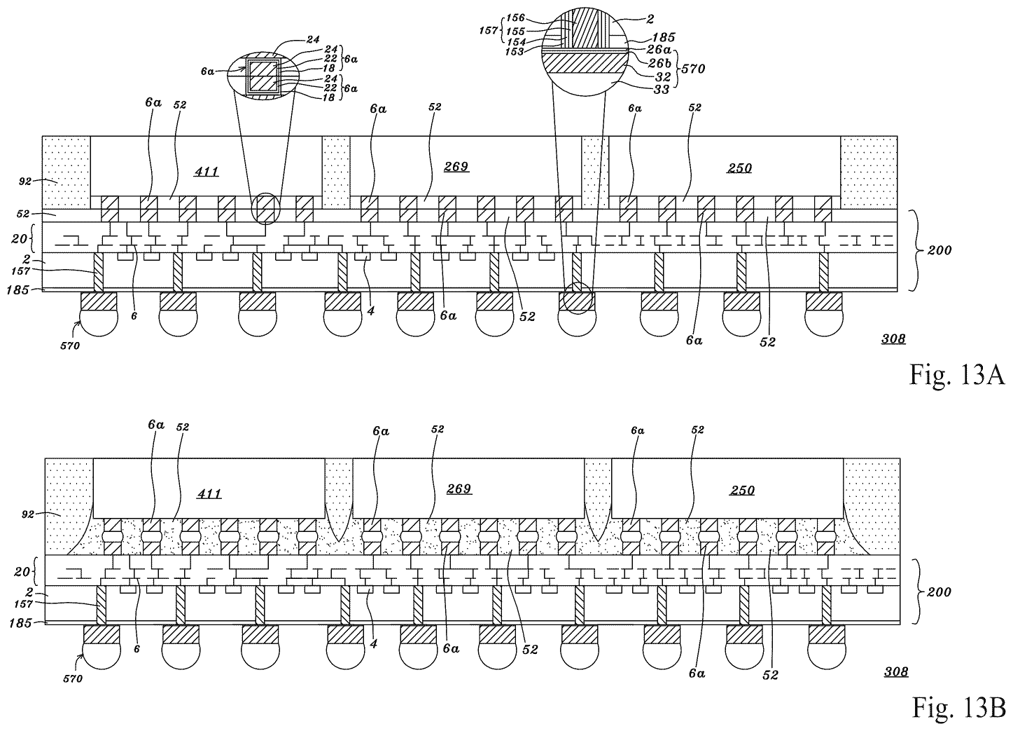

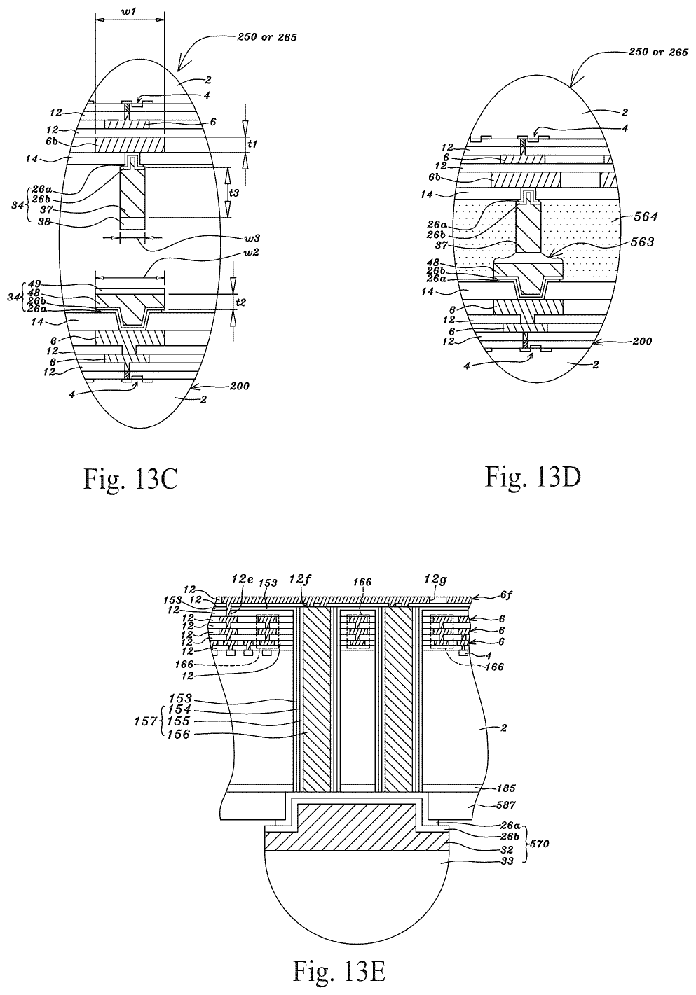

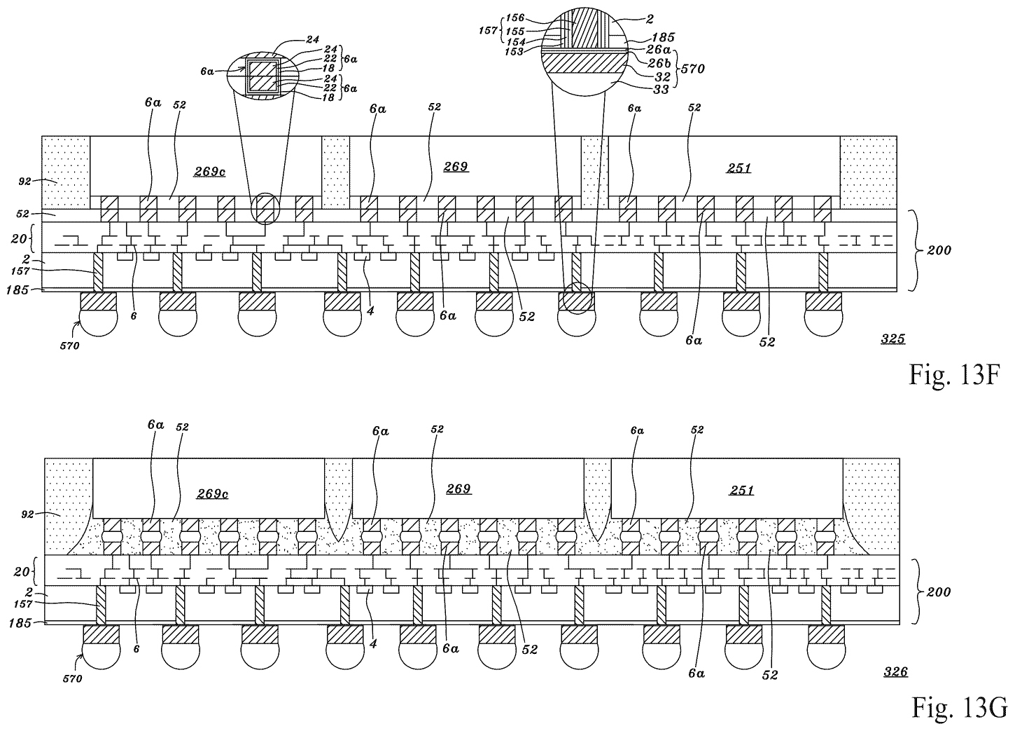

Alternatively, a third type of micro-bumps, micro-pillars or micro-pads 34 may be thermal compression bumps, as seen in FIG. 13C, including the adhesion metal layer 26a and seed layer 26b as mentioned above, and may further include a copper layer 37 having a thickness t3 of between 2 μm and 20 μm, such as 3 μm, and a largest transverse dimension w3, such as diameter in a circular shape, between 1 μm and 15 μm, such as 3 μm, on its seed layer 26b and a solder cap 38 made of a tin-silver alloy, a tin-gold alloy, a tin-copper alloy, a tin-indium alloy, indium or tin, which has a thickness of between 1 μm and 15 μm, such as 2 μm, and a largest transverse dimension, such as diameter in a circular shape, between 1 μm and 15 μm, such as 3 μm, on its copper layer 37. The third type of micro-bumps, micro-pillars or micro-pads 34 are formed respectively on multiple metal pads or input/output (I/O) pads 6b, as seen in FIG. 13C, provided by a frontmost one of the interconnection metal layers 27 of its second interconnection scheme for a chip (SISC) 29 or by, if the second interconnection scheme for a chip (SISC) 29 is not provided, a frontmost one of the interconnection metal layers 6 of its first interconnection scheme for a chip (FISC) 20, wherein each of the metal pads or input/output (I/O) pads 6b may have a thickness t1 between 1 and 10 micrometers or between 2 and 10 micrometers and a largest transverse dimension w1, such as diameter in a circular shape, between 1 μm and 15 μm, such as 5 μm. A pitch between neighboring two of its third type of micro-bumps, micro-pillars or micro-pads 34 may be between 3 μm and 20 μm.

Alternatively, a fourth type of micro-bumps, micro-pillars or micro-pads 34 may be thermal compression pads, as seen in FIG. 13C, including the adhesion metal layer 26a and seed layer 26b as mentioned above, and further including a copper layer 48 having a thickness t2 of between 1 μm and 10 μm or between 2 and 10 micrometers and a largest transverse dimension w2, such as diameter in a circular shape, between 1 μm and 15 μm, such as 5 μm, on its seed layer 26b and a metal cap 49 made of a tin-silver alloy, a tin-gold alloy, a tin-copper alloy, a tin-indium alloy, indium, tin or gold, which has a thickness of between 0.1 μm and 5 μm, such as 1 μm, on its copper layer 48. Neighboring two of its fourth type of micro-bumps, micro-pillars or micro-pads 34 may have a pitch between 3 μm and 20 μm.

### 2. Second Type of Semiconductor IC Chip

FIG. 3B is a schematically cross-sectional view showing a second type of semiconductor IC chip in accordance with an embodiment of the present application. Referring to FIG. 3B, the second type of semiconductor IC chip 100 may have a similar structure as illustrated in FIG. 3A. For an element indicated by the same reference number shown in FIGS. 3A and 3B, the specification of the element as seen in FIG. 3B may be referred to that of the element as illustrated in FIG. 3A. The difference between the first and second types of semiconductor IC chips 100 is that the second type of semiconductor IC chip 100 may further include multiple through silicon vias (TSV) 157 in its semiconductor substrate 2. For a first kind of connection structure for its through silicon vias (TSVs) 157 and its first interconnection scheme for a chip (FISC) 20 as seen in FIG. 3B, each of its through silicon vias (TSV) 157 may couple to one or more of its semiconductor devices 4 through one or more the interconnection metal layers 6 of its first interconnection scheme for a chip (FISC) 20. Each of its through silicon vias (TSVs) 157 may have a depth between 30 μm and 200 μm and a largest transverse dimension, such as diameter or width, between 2 μm and 20 μm or between 4 μm and 10 μm. In some case, for the second type of semiconductor IC chip 100, each of its through silicon vias (TSV) 157 may pass through a layer of field oxide at a top surface of its semiconductor substrate 2, and thus may be called a through field-oxide via (TFOV).

Referring to FIG. 3B, for the first kind of connection structure for the through silicon vias (TSVs) 157 and first interconnection scheme for a chip (FISC) 20 of the second type of semiconductor IC chip 100 as seen in FIG. 3B, each of the through silicon vias (TSV) 157 of the second type of semiconductor IC chip 100 may include (1) an electroplated copper layer 156 having a depth between 30 and 200 micrometers and a largest transverse dimension, such as diameter or width, between 2 and 20 micrometers or between 4 and 10 micrometers in the semiconductor substrate 2 of the second type of semiconductor IC chip 100, (2) an adhesion metal layer 154, such as titanium (Ti), titanium-nitride (TiN), tantalum (Ta) or tantalum-nitride (TaN) layer having a thickness between 1 and 50 nanometers, at the bottom and sidewall of its electroplated copper layer 156, and (3) an electroplating seed layer 155, such as copper seed layer 155 having a thickness between 3 and 200 nanometers, at the bottom and sidewall of its electroplated copper layer 156 and between its electroplated copper layer 156 and its adhesion metal layer 154. The second type of semiconductor IC chip 100 may further include an insulating lining layer 153, such as thermally grown silicon oxide (SiO₂) and/or CVD silicon nitride (Si₃N₄), at the bottom and sidewall of the electroplated copper layer 156 of each of the through silicon vias (TSV) 157 of the second type of semiconductor IC chip 100, wherein the adhesion metal layer 154 of said each of the through silicon vias (TSV) 157 may be between the electroplated copper layer 156 of said each of the through silicon vias (TSV) 157 and the insulating lining layer 153 of the second type of semiconductor IC chip 100.

For more elaboration, with regard to the second type of semiconductor IC chip 100 as seen in FIG. 3B, for the first kind of connection structure for its through silicon vias (TSVs) 157 and its first interconnection scheme for a chip (FISC) 20, each of multiple openings 12a in a lower one, or lower multiple, of the insulating dielectric layers 12 of its first interconnection scheme for a chip (FISC) 20 between the bottommost one of the interconnection metal layers 6 of its first interconnection scheme for a chip (FISC) 20 and its semiconductor substrate 2 may be vertically over one of its through silicon vias (TSVs) 157, and the bottommost one of the interconnection metal layers 6 of its first interconnection scheme for a chip (FISC) 20 may have a first portion in each of the multiple openings 12a and contacting a top surface of each of its through silicon vias (TSVs) 157 and a second portion in each of multiple openings 12b in an upper one of the insulating dielectric layers 12 of its first interconnection scheme for a chip (FISC) 20 on the lower one, or lower multiple, of the insulating dielectric layers 12 of its first interconnection scheme for a chip (FISC) 20, wherein the second portion of the bottommost one of the interconnection metal layers 6 of its first interconnection scheme for a chip (FISC) 20 is further over each of the multiple openings 12a and on a top surface of the lower one, or lower multiple, of the insulating dielectric layers 12 and has a top surface substantially coplanar with a top surface of the upper one of the insulating dielectric layers 12 of its first interconnection scheme for a chip 20 (FISC). The copper layer 24 of the bottommost one of the interconnection metal layers 6 of its first interconnection scheme for a chip (FISC) 20 may have a first portion in each of the multiple openings 12a and a second portion in each of the multiple openings 12b, over each of the multiple openings 12a and over the top surface of the lower one, or lower multiple, of the insulating dielectric layers 12, and the adhesion metal layer 18 of the bottommost one of the interconnection metal layers 6 of its first interconnection scheme for a chip (FISC) 20 may have a first portion in each of the multiple openings 12a, at a bottom and sidewall of the first portion of the copper layer 24 of the bottommost one of the interconnection metal layers 6 of its first interconnection scheme for a chip (FISC) 20, between the first portion of the copper layer 24 of the bottommost one of the interconnection metal layers 6 of its first interconnection scheme for a chip (FISC) 20 and a top surface of one of its through silicon vias (TSVs) 157 and in contact with the top surface of said one of its through silicon vias (TSVs) 157 and a second portion in each of the multiple openings 12b, on the top surface of the lower one, or lower multiple, of the insulating dielectric layers 12 and at a bottom and sidewall of the second portion of the copper layer 24 of the bottommost one of the interconnection metal layers 6 of its first interconnection scheme for a chip (FISC) 20, wherein the first portion of the copper layer 24 of the bottommost one of the interconnection metal layers 6 of its first interconnection scheme for a chip (FISC) 20, the first portion of the adhesion metal layer 18 of the bottommost one of the interconnection metal layers 6 of its first interconnection scheme for a chip (FISC) 20 and the electroplating seed layer 22 between the first portion of the copper layer 24 of the bottommost one of the interconnection metal layers 6 of its first interconnection scheme for a chip (FISC) 20 and the first portion of the adhesion metal layer 18 of the bottommost one of the interconnection metal layers 6 of its first interconnection scheme for a chip (FISC) 20 may be provided as the first portion of the bottommost one of the interconnection metal layers 6 of its first interconnection scheme for a chip (FISC) 20, and the second portion of the copper layer 24 of the bottommost one of the interconnection metal layers 6 of its first interconnection scheme for a chip (FISC) 20, the second portion of the adhesion metal layer 18 of the bottommost one of the interconnection metal layers 6 of its first interconnection scheme for a chip (FISC) 20 and the electroplating seed layer 22 between the second portion of the copper layer 24 of the bottommost one of the interconnection metal layers 6 of its first interconnection scheme for a chip (FISC) 20 and the second portion of the adhesion metal layer 18 of the bottommost one of the interconnection metal layers 6 of its first interconnection scheme for a chip (FISC) 20 may be provided as the second portion of the bottommost one of the interconnection metal layers 6 of its first interconnection scheme for a chip (FISC) 20.

Alternatively, FIGS. 3G and 3H are cross-sectional views showing a second kind of connection structure for through silicon vias (TSVs) and a first interconnection scheme for a chip (FISC) in accordance with an embodiment of the present application. When the second type of semiconductor IC chip 100 is a memory IC chip, such as static random-access memory (SRAM) IC chip, dynamic random-access memory (DRAM) IC chip, non-volatile memory IC chip, NAND flash memory IC chip, NOR flash memory IC chip, magnetoresistive random access memory (MRAM) IC chip, resistive random access memory (RRAM) IC chip or ferroelectric random access memory (FRAM) IC chip, the second type of semiconductor IC chip 100 may be provided with a second kind of connection structure for its through silicon vias (TSVs) 157 and its first interconnection scheme for a chip 20 (FISC) as seen in FIG. 3G instead of the first kind of connection structure for the through silicon vias (TSVs) 157 and the first interconnection scheme for a chip 20 (FISC) as seen in FIG. 3B. For an element indicated by the same reference number shown in FIGS. 3B and 3G, the specification of the element as seen in FIG. 3G may be referred to that of the element as illustrated in FIG. 3B unless otherwise mentioned below. With regard to the second type of semiconductor IC chip 100 as seen in FIGS. 3B and 3G, for the second kind of connection structure for its through silicon vias (TSVs) 157 and its first interconnection scheme for a chip 20 (FISC) as seen in FIG. 3G, a middle one of the interconnection metal layers 6 of its first interconnection scheme for a chip 20 (FISC) is defined as a reference layer 6f, wherein its first interconnection scheme for a chip 20 (FISC) may include a first group of the interconnection metal layers 6 between the reference layer 6f of its first interconnection scheme for a chip 20 (FISC) and its semiconductor substrate 2 and a first group of the insulating dielectric layers 12 between the reference layer 6f of its first interconnection scheme for a chip 20 (FISC) and its semiconductor substrate 2, wherein each of the first group of the insulating dielectric layers 12 may be between neighboring two of the first group of the interconnection metal layers 6 of its first interconnection scheme for a chip 20 (FISC), between the topmost one of the first group of the interconnection metal layers 6 of its first interconnection scheme for a chip 20 (FISC) and the reference layer 6f of its first interconnection scheme for a chip 20 (FISC) or between the bottommost one of the first group of the interconnection metal layers 6 of its first interconnection scheme for a chip 20 (FISC) and its semiconductor substrate 2. Its first interconnection scheme for a chip 20 (FISC) may include a second group of the interconnection metal layers 6 between the reference layer 6f of its first interconnection scheme for a chip 20 (FISC) and its passivation layer 14 and a second group of the insulating dielectric layers 12 over the reference layer 6f of its first interconnection scheme for a chip 20 (FISC) between the reference layer 6f of its first interconnection scheme for a chip 20 (FISC) and its passivation layer 14, wherein each of the second group of the insulating dielectric layers 12 may be between neighboring two of the second group of the interconnection metal layers 6 of its first interconnection scheme for a chip 20 (FISC) or between the bottommost one of the second group of the interconnection metal layers 6 of its first interconnection scheme for a chip 20 (FISC) and the reference layer 6f of its first interconnection scheme for a chip 20 (FISC). Each of its through silicon vias (TSV) 157 may couple to one or more of its semiconductor devices 4, such as transistors, through the reference layer 6f of its first interconnection scheme for a chip 20 (FISC) and each of the first group of the interconnection metal layers 6 of its first interconnection scheme for a chip 20 (FISC). Each of the first and second groups of the interconnection metal layers 6 of its first interconnection scheme for a chip 20 (FISC) may have the same specification as that for the interconnection metal layer 6 of the first interconnection scheme for a chip 20 (FISC) for the first kind of connection structure for its through silicon vias (TSVs) 157 and its first interconnection scheme for a chip 20 (FISC) as mentioned in FIG. 3B. Each of the first and second groups of the insulating dielectric layers 12 of its first interconnection scheme for a chip 20 (FISC) may have the same specification as that for the insulating dielectric layer 12 of the first interconnection scheme for a chip 20 (FISC) for the first kind of connection structure for its through silicon vias (TSVs) 157 and its first interconnection scheme for a chip 20 (FISC) as mentioned in FIG. 3B. Each of the first group of the interconnection metal layers 6 of its first interconnection scheme for a chip 20 (FISC) may be thinner than each of the second group of the interconnection metal layers 6 of its first interconnection scheme for a chip 20 (FISC). Further, each of its through silicon vias (TSVs) 157 may vertically extend in and through each of the first group of the insulating dielectric layers 12 and in its semiconductor substrate 2 and may have a top surface 157a in contact with a bottom surface of the reference layer 6f of its first interconnection scheme for a chip 20 (FISC).

With regard to the second type of semiconductor IC chip 100 as seen in FIGS. 3B and 3G, for the second kind of connection structure for its through silicon vias (TSVs) 157 and its first interconnection scheme for a chip 20 (FISC) as seen in FIG. 3G, each of its through silicon vias (TSVs) 157 may have a depth between 3 μm and 200 μm, between 5 μm and 20 μm, between 2 μm and 10 μm, between 1.5 μm and 5 μm or 0.5 μm and 3 μm and a largest transverse dimension, such as diameter or width, between 0.5 μm and 25 μm or 1 μm and 5 μm. Each of its through silicon vias (TSVs) 157 may include (1) an electroplated copper layer 156 having a depth between 3 μm and 200 μm, between 5 μm and 20 μm, between 2 μm and 10 μm, between 1.5 μm and 5 μm or 0.5 μm and 3 m and a largest transverse dimension, such as diameter or width, between 0.5 μm and 25 μm or 1 μm and 5 μm in its semiconductor substrate 2 and each of the first group of the insulating dielectric layers 12 of its first interconnection scheme for a chip 20 (FISC), (2) an adhesion metal layer 154, such as titanium, titanium nitride, tantalum or tantalum nitride, having a thickness between 1 and 50 nanometers, at a bottom and sidewall of the electroplated copper layer 156 of its through silicon vias (TSVs) 157, and (3) an electroplating seed layer 155, such as copper, having a thickness between 3 and 200 nanometers, between the electroplated copper layer 156 and adhesion metal layer 154 of its through silicon vias (TSVs) 157. The second type of semiconductor IC chip 100 may further include an insulating lining layer 153, such as silicon oxide, silicon oxynitride or silicon nitride, having a thickness between 3 and 200 nanometers or between 5 and 120 nanometers on a bottom surface of the reference layer 6f of its first interconnection scheme for a chip 20 (FISC), on a top surface of the topmost one of the first group of the insulating dielectric layers 12 of its first interconnection scheme for a chip 20 (FISC), between the bottom surface of the reference layer 6f of its first interconnection scheme for a chip 20 (FISC) and the top surface of the topmost one of the first group of the insulating dielectric layers 12 of its first interconnection scheme for a chip 20 (FISC), at the bottom and sidewall of the electroplated copper layer 156 of each of its through silicon vias (TSVs) 157, on an outer sidewall of each of its through silicon vias (TSVs) 157, on an inner sidewall of each opening in its semiconductor substrate 2 and between the inner sidewall of said each opening in its semiconductor substrate 2 and the outer sidewall of said each of its through silicon vias (TSVs) 157. Its insulating lining layer 153 may have a top surface 153a substantially coplanar with a top surface of the electroplated copper layer 156 of each of its through silicon vias (TSVs) 157, i.e., the top surface 157a. The reference layer 6f of its first interconnection scheme for a chip 20 (FISC) may have a first portion in each of multiple openings 12c vertically through its insulating lining layer 153 and the topmost one of the first group of the insulating dielectric layers 12 of its first interconnection scheme for a chip 20 (FISC) and contacting the top surface of the topmost one of the first group of the interconnection metal layers 6 of its first interconnection scheme for a chip 20 (FISC) and a second portion in each of multiple openings 12d in a reference one of the insulating dielectric layers 12 of its first interconnection scheme for a chip 20 on the top surface 153a of its insulating lining layer 153, wherein the second portion of the reference layer 6f of its first interconnection scheme for a chip 20 (FISC) is further over each of the multiple openings 12c and on the top surface 153a of its insulating lining layer 153 and the top surface 157a of each of its through silicon vias (TSVs) 157 and has a top surface substantially coplanar with a top surface of the reference one of the insulating dielectric layers 12 of its first interconnection scheme for a chip 20 (FISC). The copper layer 24 of the reference layer 6f of its first interconnection scheme for a chip (FISC) 20 may have a first portion in each of the multiple openings 12c and a second portion in each of the multiple openings 12d, over each of the multiple openings 12c and the top surface 153a of its insulating lining layer 153, and the adhesion metal layer 18 of the reference layer 6f of its first interconnection scheme for a chip (FISC) 20 may have a first portion in each of the multiple openings 12c, at a bottom and sidewall of the first portion of the copper layer 24 of the reference layer 6f of its first interconnection scheme for a chip (FISC) 20, between the first portion of the copper layer 24 of the reference layer 6f of its first interconnection scheme for a chip (FISC) 20 and the top surface of the topmost one of the first group of the interconnection metal layers 6 of its first interconnection scheme for a chip 20 (FISC) and in contact with the top surface of the topmost one of the first group of the interconnection metal layers 6 of its first interconnection scheme for a chip 20 (FISC) and a second portion in each of the multiple openings 12d, on the top surface 153a of its insulating lining layer 153 and the top surface 157a of each of its through silicon vias (TSVs) 157 and at a bottom and sidewall of the second portion of the copper layer 24 of the reference layer 6f of its first interconnection scheme for a chip (FISC) 20, wherein the first portion of the copper layer 24 of the reference layer 6f of its first interconnection scheme for a chip (FISC) 20, the first portion of the adhesion metal layer 18 of the reference layer 6f of its first interconnection scheme for a chip (FISC) 20 and the electroplating seed layer 22 between the first portion of the copper layer 24 of the reference layer 6f of its first interconnection scheme for a chip (FISC) 20 and the first portion of the adhesion metal layer 18 of the reference layer 6f of its first interconnection scheme for a chip (FISC) 20 may be provided as the first portion of the reference layer 6f of its first interconnection scheme for a chip (FISC) 20, and the second portion of the copper layer 24 of the reference layer 6f of its first interconnection scheme for a chip (FISC) 20, the second portion of the adhesion metal layer 18 of the reference layer 6f of its first interconnection scheme for a chip (FISC) 20 and the electroplating seed layer 22 between the second portion of the copper layer 24 of the reference layer 6f of its first interconnection scheme for a chip (FISC) 20 and the second portion of the adhesion metal layer 18 of the reference layer 6f of its first interconnection scheme for a chip (FISC) 20 may be provided as the second portion of the reference layer 6f of its first interconnection scheme for a chip (FISC) 20.

Alternatively, with regard to the second type of semiconductor IC chip 100, for the second kind of connection structure for its through silicon vias (TSVs) 157 and its first interconnection scheme for a chip 20 (FISC) as seen in FIG. 3H, two or more of its through silicon vias (TSVs) 157 as seen in FIG. 3H may be arranged as its set of through silicon vias (TSVs) 157 and the second portion of the copper layer 24 of the reference layer 6f of its first interconnection scheme for a chip (FISC) 20 may couple the set of its through silicon vias (TSVs) 157. For an element indicated by the same reference number shown in FIGS. 3G and 3H, the specification of the element as seen in FIG. 3H may be referred to that of the element as illustrated in FIG. 3G. Further, each of the set of its through silicon vias (TSVs) 157 may couple to one of its semiconductor devices 4, such as transistors, through, in sequence, the second portion of the copper layer 24 of the reference layer 6f of its first interconnection scheme for a chip (FISC) 20, one of the first portions of the copper layer 24 of the reference layer 6f of its first interconnection scheme for a chip (FISC) 20 and each of the first group of the interconnection metal layers 6 of its first interconnection scheme for a chip 20 (FISC).

Referring to FIGS. 3G and 3H, besides the memory IC chip, the second type of semiconductor IC chip 100 may be a logic IC chip, such as FPGA IC chip, central-processing-unit (CPU) IC chip, digital signal processor (DSP) IC chip, graphic processing unit (GPU) IC chip, data processing unit (DPU) IC chip, tensor flow processing unit (TPU) IC chip, micro-control unit (MCU) IC chip, artificial intelligent unit (AIU) IC chip, machine learning unit (MLU) IC chip, application-specific integrated-circuit (ASIC) chip or system-on-chip (SoC) IC chip, having the second kind of connection structure for its through silicon vias (TSVs) 157 and its first interconnection scheme for a chip 20 (FISC) as seen in FIGS. 3G and 3H. In case that the second type of semiconductor IC chip 100 is used as a memory IC chip, the number of the second group of the interconnection metal layers 6 of its first interconnection scheme for a chip 20 (FISC) may be smaller than or equal to 2 or 4 and the number of the first group of the interconnection metal layers 6 of its first interconnection scheme for a chip 20 (FISC) may be greater than or equal to 1, 2 or 3. In case that the second type of semiconductor IC chip 100 is used as a logic IC chip, the number of the second group of the interconnection metal layers 6 of its first interconnection scheme for a chip 20 (FISC) may be smaller than or equal to 2 or 5 and the number of the first group of the interconnection metal layers 6 of its first interconnection scheme for a chip 20 (FISC) may be greater than or equal to 4, 7 or 10. The second type of semiconductor IC chip 100 may be an auxiliary IC chip, such as input/output (I/O) IC chip, control IC chip or power-management integrated-circuit (PMIC) chip, having the second kind of connection structure for its through silicon vias (TSVs) 157 and its first interconnection scheme for a chip 20 (FISC) as seen in FIGS. 3G and 3H. Alternatively, the second kind of connection structure for the through silicon vias (TSVs) 157 and the first interconnection scheme for a chip 20 (FISC) as seen in FIGS. 3G and 3H may be used for an interposer 551 or 661 as seen in FIGS. 6A, 6B, 16, 19, 19-1, 19-2, 19-4, 23A, 23B, 25B and 25C.

Alternatively, FIG. 3I is a cross-sectional view showing a third kind of connection structure for through silicon vias (TSVs) and a first interconnection scheme for a chip (FISC) in accordance with an embodiment of the present application. When the second type of semiconductor IC chip 100 is a logic IC chip, such as FPGA IC chip, central-processing-unit (CPU) IC chip, digital signal processor (DSP) IC chip, graphic processing unit (GPU) IC chip, data processing unit (DPU) IC chip, tensor flow processing unit (TPU) IC chip, micro-control unit (MCU) IC chip, artificial intelligent unit (AIU) IC chip, machine learning unit (MILU) IC chip, application-specific integrated-circuit (ASIC) chip or system-on-chip (SoC) IC chip, or a static random-access memory (SRAM) IC chip, the second type of semiconductor IC chip 100 may be provided with a third kind of connection structure for its through silicon vias (TSVs) 157 and its first interconnection scheme for a chip 20 (FISC) as seen in FIG. 3I instead of the first kind of connection structure for the through silicon vias (TSVs) 157 and the first interconnection scheme for a chip 20 (FISC) as seen in FIG. 3B. For an element indicated by the same reference number shown in FIGS. 3B, 3G and 3I, the specification of the element as seen in FIG. 3I may be referred to that of the element as illustrated in FIGS. 3B and 3G unless otherwise mentioned below. The third kind of connection structure for its through silicon vias (TSVs) 157 and its first interconnection scheme for a chip 20 (FISC) may have a similar structure to the second kind of connection structure for its through silicon vias (TSVs) 157 and its first interconnection scheme for a chip 20 (FISC) as illustrated in FIG. 3G. The difference therebetween is that for the third kind of connection structure for its through silicon vias (TSVs) 157 and its first interconnection scheme for a chip 20 (FISC), its insulating lining layer 153, such as silicon oxide, silicon oxynitride or silicon nitride, having a thickness between 3 and 200 nanometers or between 5 and 120 nanometers may be formed on a top surface of the second topmost one of the first group of the insulating dielectric layers 12 of its first interconnection scheme for a chip 20 (FISC), at the bottom and sidewall of the electroplated copper layer 156 of each of its through silicon vias (TSVs) 157, on an outer sidewall of each of its through silicon vias (TSVs) 157, on an inner sidewall of each opening in its semiconductor substrate 2 and between the inner sidewall of said each opening in its semiconductor substrate 2 and the outer sidewall of said each of its through silicon vias (TSVs) 157. Its insulating lining layer 153 may have a top surface 153a substantially coplanar with the top surface of the electroplated copper layer 156 of each of its through silicon vias (TSVs) 157, i.e., the top surface 157a. The topmost one of the first group of the insulating dielectric layers 12 of its first interconnection scheme for a chip 20 (FISC) may be formed on the top surface 153a of its insulating lining layer 153 and the top surface 157a of each of its through silicon vias (TSVs) 157. The reference layer 6f of its first interconnection scheme for a chip 20 (FISC) may have a first portion in each of multiple openings 12e vertically through its insulating lining layer 153 and the topmost one and second topmost one of the first group of the insulating dielectric layers 12 of its first interconnection scheme for a chip 20 (FISC) and contacting the top surface of the topmost one of the first group of the interconnection metal layers 6 of its first interconnection scheme for a chip 20 (FISC), a second portion in each of multiple openings 12f vertically through the topmost one of the first group of the insulating dielectric layers 12 of its first interconnection scheme for a chip 20 (FISC) and contacting the top surface 157a of one of its through silicon vias (TSVs) 157 and a third portion in each of multiple openings 12g in a reference one of the insulating dielectric layers 12 of its first interconnection scheme for a chip 20 on the topmost one of the first group of the insulating dielectric layers 12 of its first interconnection scheme for a chip 20 (FISC), wherein the second portion of the reference layer 6f of its first interconnection scheme for a chip 20 (FISC) is further over each of the multiple openings 12e and 12f and on a top surface of the topmost one of the first group of the insulating dielectric layers 12 of its first interconnection scheme for a chip 20 (FISC) and has a top surface substantially coplanar with a top surface of the reference one of the insulating dielectric layers 12 of its first interconnection scheme for a chip 20 (FISC). The multiple openings 12f may have a number greater than or equal to 1, 2 or 3, for example, over each of its through silicon vias (TSVs) 157. The copper layer 24 of the reference layer 6f of its first interconnection scheme for a chip (FISC) 20 may have a first portion in each of the multiple openings 12e, a second portion in each of the multiple openings 12f and a third portion in each of the multiple openings 12g, over each of the multiple openings 12e and 12f and the top surface of the topmost one of the first group of the insulating dielectric layers 12 of its first interconnection scheme for a chip 20 (FISC), and the adhesion metal layer 18 of the reference layer 6f of its first interconnection scheme for a chip (FISC) 20 may have a first portion in each of the multiple openings 12e, at a bottom and sidewall of the first portion of the copper layer 24 of the reference layer 6f of its first interconnection scheme for a chip (FISC) 20, between the first portion of the copper layer 24 of the reference layer 6f of its first interconnection scheme for a chip (FISC) 20 and the top surface of the topmost one of the first group of the interconnection metal layers 6 of its first interconnection scheme for a chip 20 (FISC) and in contact with the top surface of the topmost one of the first group of the interconnection metal layers 6 of its first interconnection scheme for a chip 20 (FISC), a second portion in each of the openings 12f, at a bottom and sidewall of the second portion of the copper layer 24 of the reference layer 6f of its first interconnection scheme for a chip (FISC) 20, between the second portion of the copper layer 24 of the reference layer 6f of its first interconnection scheme for a chip (FISC) 20 and the top surface of one of its through silicon vias (TSVs) 157 and in contact with the top surface of said one of its through silicon vias (TSVs) 157, and a third portion in each of the multiple openings 12f, on the top surface of the topmost one of the first group of the insulating dielectric layers 12 of its first interconnection scheme for a chip 20 (FISC) and at a bottom and sidewall of the third portion of the copper layer 24 of the reference layer 6f of its first interconnection scheme for a chip (FISC) 20, wherein the first portion of the copper layer 24 of the reference layer 6f of its first interconnection scheme for a chip (FISC) 20, the first portion of the adhesion metal layer 18 of the reference layer 6f of its first interconnection scheme for a chip (FISC) 20 and the electroplating seed layer 22 between the first portion of the copper layer 24 of the reference layer 6f of its first interconnection scheme for a chip (FISC) 20 and the first portion of the adhesion metal layer 18 of the reference layer 6f of its first interconnection scheme for a chip (FISC) 20 may be provided as the first portion of the reference layer 6f of its first interconnection scheme for a chip (FISC) 20; the second portion of the copper layer 24 of the reference layer 6f of its first interconnection scheme for a chip (FISC) 20, the second portion of the adhesion metal layer 18 of the reference layer 6f of its first interconnection scheme for a chip (FISC) 20 and the electroplating seed layer 22 between the second portion of the copper layer 24 of the reference layer 6f of its first interconnection scheme for a chip (FISC) 20 and the second portion of the adhesion metal layer 18 of the reference layer 6f of its first interconnection scheme for a chip (FISC) 20 may be provided as the second portion of the reference layer 6f of its first interconnection scheme for a chip (FISC) 20; the third portion of the copper layer 24 of the reference layer 6f of its first interconnection scheme for a chip (FISC) 20, the third portion of the adhesion metal layer 18 of the reference layer 6f of its first interconnection scheme for a chip (FISC) 20 and the electroplating seed layer 22 between the third portion of the copper layer 24 of the reference layer 6f of its first interconnection scheme for a chip (FISC) 20 and the third portion of the adhesion metal layer 18 of the reference layer 6f of its first interconnection scheme for a chip (FISC) 20 may be provided as the third portion of the reference layer 6f of its first interconnection scheme for a chip (FISC) 20.

Referring to FIG. 3I, for the second type of semiconductor IC chip 100, the first group of the interconnection metal layers 6 of its first interconnection scheme for a chip 20 (FISC) may provide a seal ring 166 surrounding each of its through silicon vias (TSVs) 157, wherein the seal ring 166 may couple to a voltage of ground reference. For more elaboration, each of its seal rings 166 may be provided by a ring-shaped portion of each of the first group of the interconnection metal layers 6 of its first interconnection scheme for a chip 20 (FISC) stacked and aligned with and coupling to the ring-shaped portion(s) of the other(s) of the first group of the interconnection metal layers 6 of its first interconnection scheme for a chip 20 (FISC) to surround one of its through silicon vias (TSVs) 157.

Alternatively, with regard to the second type of semiconductor IC chip 100, for the third kind of connection structure for its through silicon vias (TSVs) 157 and its first interconnection scheme for a chip 20 (FISC) as seen in FIG. 3I, two or more of its through silicon vias (TSVs) 157 may be arranged as its set of through silicon vias (TSVs) 157 and the reference layer 6f of its first interconnection scheme for a chip (FISC) 20 may couple the set of its through silicon vias (TSVs) 157. For example, one of the set of its through silicon vias (TSVs) 157 may couple to another or the other of the set of its through silicon vias (TSVs) 157 through, in sequence, one of the second portions of the copper layer 24 of the reference layer 6f of its first interconnection scheme for a chip (FISC) 20 on said one of the set of its through silicon vias (TSVs) 157, the third portion of the copper layer 24 of the reference layer 6f of its first interconnection scheme for a chip (FISC) 20 and one of the second portions of the copper layer 24 of the reference layer 6f of its first interconnection scheme for a chip (FISC) 20 on said another or the other of the set of its through silicon vias (TSVs) 157. Further, each of the set of its through silicon vias (TSVs) 157 may couple to one of its semiconductor devices 4, such as transistors, through, in sequence, one of the second portions of the copper layer 24 of the reference layer 6f of its first interconnection scheme for a chip (FISC) 20 on said each of the set of its through silicon vias (TSVs) 157, the third portion of the copper layer 24 of the reference layer 6f of its first interconnection scheme for a chip (FISC) 20, one of the first portions of the copper layer 24 of the reference layer 6f of its first interconnection scheme for a chip (FISC) 20 and each of the first group of the interconnection metal layers 6 of its first interconnection scheme for a chip 20 (FISC).

Alternatively, besides the logic IC chip, the second type of semiconductor IC chip 100 may be a memory integrated-circuit (IC) chip, such as dynamic random-access memory (DRAM) IC chip, non-volatile memory IC chip, NAND flash memory IC chip, NOR flash memory IC chip, magnetoresistive random access memory (MRAM) IC chip, resistive random access memory (RRAM) IC chip or ferroelectric random access memory (FRAM) IC chip, having the third kind of connection structure for its through silicon vias (TSVs) 157 and its first interconnection scheme for a chip 20 (FISC) as seen in FIG. 3I. In case that the second type of semiconductor IC chip 100 is used as a memory IC chip, the number of the second group of the interconnection metal layers 6 of its first interconnection scheme for a chip 20 (FISC) may be smaller than or equal to 2 or 4 and the number of the first group of the interconnection metal layers 6 of its first interconnection scheme for a chip 20 (FISC) may be greater than or equal to 1, 2 or 3. In case that the second type of semiconductor IC chip 100 is used as a logic IC chip, the number of the second group of the interconnection metal layers 6 of its first interconnection scheme for a chip 20 (FISC) may be smaller than or equal to 2 or 5 and the number of the first group of the interconnection metal layers 6 of its first interconnection scheme for a chip 20 (FISC) may be greater than or equal to 4, 7 or 10. The second type of semiconductor IC chip 100 may be an auxiliary IC chip, such as input/output (I/O) IC chip, control IC chip or power-management integrated-circuit (PMIC) chip, having the third kind of connection structure for its through silicon vias (TSVs) 157 and its first interconnection scheme for a chip 20 (FISC) as seen in FIG. 3I. Alternatively, the third kind of connection structure for the through silicon vias (TSVs) 157 and the first interconnection scheme for a chip 20 (FISC) as seen in FIG. 3I may be used for an interposer 551 or 661 as seen in FIGS. 6A, 6B, 16, 19, 19-1, 19-2, 19-4, 23A, 23B, 25B and 25C.

Alternatively, FIG. 3J is a cross-sectional view showing a fourth kind of connection structure for through silicon vias (TSVs) and a first interconnection scheme for a chip (FISC) in accordance with an embodiment of the present application. A fourth kind of connection structure for the through silicon vias (TSVs) 157 and the first interconnection scheme for a chip 20 (FISC) as seen in FIG. 3J may be employed into an interposer 551 or 661 as seen in FIGS. 6A, 6B, 16, 19, 19-1, 19-2, 19-4, 23A, 23B, 25B and 25C. Alternatively, when the second type of semiconductor IC chip 100 is (1) a logic IC chip, such as FPGA IC chip, central-processing-unit (CPU) IC chip, digital signal processor (DSP) IC chip, graphic processing unit (GPU) IC chip, data processing unit (DPU) IC chip, tensor flow processing unit (TPU) IC chip, micro-control unit (MCU) IC chip, artificial intelligent unit (AIU) IC chip, machine learning unit (MLU) IC chip, application-specific integrated-circuit (ASIC) chip or system-on-chip (SoC) IC chip, (2) a memory IC chip, such as static random-access memory (SRAM) IC chip, dynamic random-access memory (DRAM) IC chip, non-volatile memory IC chip, NAND flash memory IC chip, NOR flash memory IC chip, magnetoresistive random access memory (MRAM) IC chip, resistive random access memory (RRAM) IC chip or ferroelectric random access memory (FRAM) IC chip, or (3) an auxiliary IC chip, such as input/output (I/O) IC chip, control IC chip or power-management integrated-circuit (PMIC) chip, the second type of semiconductor IC chip 100 may be provided with a fourth kind of connection structure for its through silicon vias (TSVs) 157 and its first interconnection scheme for a chip 20 (FISC) as seen in FIG. 3J instead of the first kind of connection structure for the through silicon vias (TSVs) 157 and the first interconnection scheme for a chip 20 (FISC) as seen in FIG. 3B. For an element indicated by the same reference number shown in FIGS. 3B and 3J, the specification of the element as seen in FIG. 3J may be referred to that of the element as illustrated in FIG. 3B unless otherwise mentioned below. The fourth kind of connection structure for its through silicon vias (TSVs) 157 and its first interconnection scheme for a chip 20 (FISC) may have a similar structure to the first kind of connection structure for its through silicon vias (TSVs) 157 and its first interconnection scheme for a chip 20 (FISC) as illustrated in FIG. 3B. The difference therebetween is that for the fourth kind of connection structure for its through silicon vias (TSVs) 157 and its first interconnection scheme for a chip 20 (FISC), the bottommost one of the interconnection metal layers 6 of its first interconnection scheme for a chip 20 (FISC) and each of its through silicon vias (TSVs) 157 may be formed to be integral as a part. For more elaboration, the bottommost one of the interconnection metal layers 6 of its first interconnection scheme for a chip (FISC) 20 may have a first portion, formed as its through silicon vias (TSVs) 157, in each of multiple openings 2a in and through a lower one of the insulating dielectric layers 12 of its first interconnection scheme for a chip 20 (FISC) and in its semiconductor substrate 2, and a second portion, formed as its metal lines or traces, in each of multiple openings 12h in an upper one of the insulating dielectric layers 12 of its first interconnection scheme for a chip 20 (FISC) on the lower one of the insulating dielectric layers 12 of its first interconnection scheme for a chip 20 (FISC), wherein the second portion of the bottommost one of the interconnection metal layers 6 of its first interconnection scheme for a chip (FISC) 20 is further over each of the multiple openings 2a and a top surface of the lower one of the insulating dielectric layers 12 and has a top surface substantially coplanar with a top surface of the upper one of the insulating dielectric layers 12 of its first interconnection scheme for a chip 20 (FISC). The bottommost one of the interconnection metal layers 6 of its first interconnection scheme for a chip 20 (FISC) may include (1) an electroplated copper layer 156 in each of the multiple openings 12h and each of the multiple openings 2a, (2) an adhesion metal layer 154 at a bottom and sidewall of each of the multiple openings 12h and a bottom and sidewall of each of the multiple openings 2a, and (3) an electroplating seed layer 155 at the bottom and sidewall of each of the multiple openings 12h and the bottom and sidewall of each of the multiple openings 2a and between the electroplated copper layer 156 and adhesion metal layer 154. The electroplated copper layer 156 of the bottommost one of the interconnection metal layers 6 of its first interconnection scheme for a chip (FISC) 20 may have a first portion in each of the multiple openings 2a and a second portion in each of the multiple openings 12h, over each of the multiple openings 2a and the lower one of the insulating dielectric layers 12, and the adhesion metal layer 154 of the bottommost one of the interconnection metal layers 6 of its first interconnection scheme for a chip (FISC) 20 may have a first portion in each of the multiple openings 2a and at a bottom and sidewall of the first portion of the electroplated copper layer 156 of the bottommost one of the interconnection metal layers 6 of its first interconnection scheme for a chip (FISC) 20 and a second portion in each of the multiple openings 12h, over the lower one of the insulating dielectric layers 12 and at a bottom and sidewall of the second portion of the electroplated copper layer 156 of the bottommost one of the interconnection metal layers 6 of its first interconnection scheme for a chip (FISC) 20. The first portion of the electroplated copper layer 156 of the bottommost one of the interconnection metal layers 6 of its first interconnection scheme for a chip (FISC) 20, the first portion of the adhesion metal layer 154 of the bottommost one of the interconnection metal layers 6 of its first interconnection scheme for a chip (FISC) 20 and the electroplating seed layer 155 between the first portion of the electroplated copper layer 156 of the bottommost one of the interconnection metal layers 6 of its first interconnection scheme for a chip (FISC) 20 and the first portion of the adhesion metal layer 154 of the bottommost one of the interconnection metal layers 6 of its first interconnection scheme for a chip (FISC) 20 may be provided as the first portion of the bottommost one of the interconnection metal layers 6 of its first interconnection scheme for a chip (FISC) 20, and the second portion of the electroplated copper layer 156 of the bottommost one of the interconnection metal layers 6 of its first interconnection scheme for a chip (FISC) 20, the second portion of the adhesion metal layer 154 of the bottommost one of the interconnection metal layers 6 of its first interconnection scheme for a chip (FISC) 20 and the electroplating seed layer 155 between the second portion of the electroplated copper layer 156 of the bottommost one of the interconnection metal layers 6 of its first interconnection scheme for a chip (FISC) 20 and the second portion of the adhesion metal layer 154 of the bottommost one of the interconnection metal layers 6 of its first interconnection scheme for a chip (FISC) 20 may be provided as the second portion of the bottommost one of the interconnection metal layers 6 of its first interconnection scheme for a chip (FISC) 20. The first portion of the electroplated copper layer 156 of the bottommost one of the interconnection metal layers 6 of its first interconnection scheme for a chip (FISC) 20 may have a depth between 30 and 200 micrometers and a largest transverse dimension, such as diameter or width, between 2 and 20 micrometers or between 4 and 10 micrometers. The second portion of the electroplated copper layer 156 of the bottommost one of the interconnection metal layers 6 of its first interconnection scheme for a chip (FISC) 20 may have a thickness between 3 nm and 500 nm. The adhesion metal layer 154 of the bottommost one of the interconnection metal layers 6 of its first interconnection scheme for a chip (FISC) 20 may be a titanium (Ti), titanium-nitride (TiN), tantalum (Ta) or tantalum-nitride (TaN) layer having a thickness between 1 and 50 nanometers. The electroplating seed layer 155 of the bottommost one of the interconnection metal layers 6 of its first interconnection scheme for a chip (FISC) 20 may be made of copper having a thickness between 3 and 200 nanometers. The fourth type of semiconductor IC chip 100 may further include an insulating lining layer 153, such as thermally grown silicon oxide (SiO₂) and/or CVD silicon nitride (Si₃N₄), at a bottom and sidewall of the first portion of the bottommost one of the interconnection metal layers 6 of its first interconnection scheme for a chip (FISC) 20 and a bottom and sidewall of the second portion of the bottommost one of the interconnection metal layers 6 of its first interconnection scheme for a chip (FISC) 20.

Alternatively, with regard to the interposer of the second type of semiconductor IC chip 100, for the fourth kind of connection structure for its through silicon vias (TSVs) 157 and its first interconnection scheme for a chip 20 (FISC) as seen in FIG. 3J, two or more of its through silicon vias (TSVs) 157 may be arranged as its set of through silicon vias (TSVs) 157 and the second portion of the electroplated copper layer 156 of the bottommost one of the interconnection metal layers 6 of its first interconnection scheme for a chip (FISC) 20 may couple the set of its through silicon vias (TSVs) 157.

### 3. Third Type of Semiconductor IC Chip

FIG. 3C is a schematically cross-sectional view showing a third type of semiconductor IC chip in accordance with an embodiment of the present application. Referring to FIG. 3C, the third type of semiconductor IC chip 100 may have a similar structure as illustrated in FIG. 3A. For an element indicated by the same reference number shown in FIGS. 3A and 3C, the specification of the element as seen in FIG. 3C may be referred to that of the element as illustrated in FIG. 3A. The difference between the first and third types of semiconductor IC chips 100 is that the third type of semiconductor IC chip 100 may be provided with the first type of micro-bumps, micro-pillars or micro-pads 34 at its top and a polymer layer 257, i.e., insulating dielectric layer, on the topmost one of the polymer layers 42 of its second interconnection scheme for a chip (SISC) 29 or, if the second interconnection scheme for a chip (SISC) 29 is not provided, on its passivation layer 14, wherein its polymer layer 257 may be horizontally around each of its first type of micro-bumps, micro-pillars or micro-pads 34 and may have a top surface substantially coplanar with a top surface of each of its first type of micro-bumps, micro-pillars or micro-pads 34, i.e., a top surface of the copper layer 32 thereof, wherein its polymer layer 257 is not extending over the top surface of each of its first type of micro-bumps, micro-pillars or micro-pads 34.

### 4. Fourth Type of Semiconductor IC Chip

FIG. 3D is a schematically cross-sectional view showing a fourth type of semiconductor IC chip in accordance with an embodiment of the present application. Referring to FIG. 3D, the fourth type of semiconductor IC chip 100 may have a similar structure as illustrated in FIG. 3B. For an element indicated by the same reference number shown in FIGS. 3A, 3B, 3D and 3G-3J, the specification of the element as seen in FIG. 3D may be referred to that of the element as illustrated in FIGS. 3A, 3B and 3G-3J. The fourth type of semiconductor IC chip 100 may have the same specification as illustrated for any kind of the first through fourth kinds of connection structures for the through silicon vias (TSVs) 157 and the first interconnection scheme for a chip (FISC) for the second type of semiconductor IC chip 100 as shown in FIGS. 3B and 3G-3J. The difference between the second and fourth types of semiconductor IC chips 100 is that the fourth type of semiconductor IC chip 100 may be provided with the first type of micro-bumps, micro-pillars or micro-pads 34 at its top and a polymer layer 257, i.e., insulating dielectric layer, on the topmost one of the polymer layers 42 of its second interconnection scheme for a chip (SISC) 29 or, if the second interconnection scheme for a chip (SISC) 29 is not provided, on its passivation layer 14, wherein its polymer layer 257 may be horizontally around each of its first type of micro-bumps, micro-pillars or micro-pads 34 and may have a top surface substantially coplanar with a top surface of each of its first type of micro-bumps, micro-pillars or micro-pads 34, i.e., a top surface of the copper layer 32 thereof, wherein its polymer layer 257 is not extending over the top surface of each of its first type of micro-bumps, micro-pillars or micro-pads 34.

### 5. Fifth Type of Semiconductor IC Chip

FIG. 3E is a schematically cross-sectional view showing a fifth type of semiconductor IC chip in accordance with an embodiment of the present application. Referring to FIG. 3E, the fifth type of semiconductor IC chip 100 may have a similar structure as illustrated in FIG. 3A. For an element indicated by the same reference number shown in FIGS. 3A and 3E, the specification of the element as seen in FIG. 3E may be referred to that of the element as illustrated in FIG. 3A. The difference between the first and fifth types of semiconductor IC chips 100 is that the fifth type of semiconductor IC chip 100 may be provided with (1) an insulating bonding layer 52 at its active side and on the topmost one of the insulating dielectric layers 12 of its first interconnection scheme for a chip (FISC) 20 and (2) multiple metal pads or input/output (I/O) pads 6a at its active side and in multiple openings 52a in its insulating bonding layer 52 and on the topmost one of the interconnection metal layers 6 of its first interconnection scheme for a chip (FISC) 20, instead of the second interconnection scheme for a chip (SISC) 29, the passivation layer 14 and micro-bumps, micro-pillars or micro-pads 34 as seen in FIG. 3A. For the fifth type of semiconductor IC chip 100, its insulating bonding layer 52 may include a silicon-oxide layer having a thickness between 0.1 and 2 micrometers. Each of its metal pads or input/output (I/O) pads 6a may include (1) a copper layer 24 having a thickness of between 3 nm and 500 nm in one of the openings 52a in its insulating bonding layer 52, (2) an adhesion metal layer 18, such as titanium or titanium nitride having a thickness of between 1 nm and 50 nm, at a bottom and sidewall of the copper layer 24 of said each of its metal pads or input/output (I/O) pads 6a and on the topmost one of the interconnection metal layers 6 of its first interconnection scheme for a chip (FISC) 20, and (3) an electroplating seed layer 22, such as copper, between the copper layer 24 and adhesion metal layer 18 of said each of its metal pads 6a, wherein said each of its metal pads or input/output (I/O) pads 6a, i.e., the copper layer 24 thereof, may have a top surface substantially coplanar with a top surface of its insulating bonding layer 52, i.e., a top surface of the silicon-oxide layer thereof.

### 6. Sixth Type of Semiconductor IC Chip

FIG. 3F is a schematically cross-sectional view showing a sixth type of semiconductor IC chip in accordance with an embodiment of the present application. Referring to FIG. 3F, the sixth type of semiconductor IC chip 100 may have a similar structure as illustrated in FIG. 3E. For an element indicated by the same reference number shown in FIGS. 3A, 3B, 3E and 3F, the specification of the element as seen in FIG. 3F may be referred to that of the element as illustrated in FIGS. 3A, 3B and 3E. The sixth type of semiconductor IC chip 100 may have the same specification as illustrated for any kind of the first through fourth kinds of connection structures for the through silicon vias (TSVs) 157 and the first interconnection scheme for a chip (FISC) for the second type of semiconductor IC chip 100 as shown in FIGS. 3B and 3G-3J. The difference between the fifth and sixth types of semiconductor IC chips 100 is that the sixth type of semiconductor IC chip 100 may further include multiple through silicon vias (TSVs) 157 in its semiconductor substrate 2, wherein each of its through silicon vias (TSVs) 157 may couple to one or more of its semiconductor devices 4 through one or more the interconnection metal layers 6 of its first interconnection scheme for a chip (FISC) 20. Each of its through silicon vias (TSVs) 157 may have a depth between 30 μm and 200 μm and a largest transverse dimension, such as diameter or width, between 2 μm and 20 μm or between 4 μm and 10 m. Each of its through silicon vias (TSVs) 157 may have the same specification as that of the through silicon vias (TSVs) 157 of the second type of semiconductor IC chip 100 as illustrated in FIG. 3B.

### Specification for Vertical-Through-Via (VTV) Connector

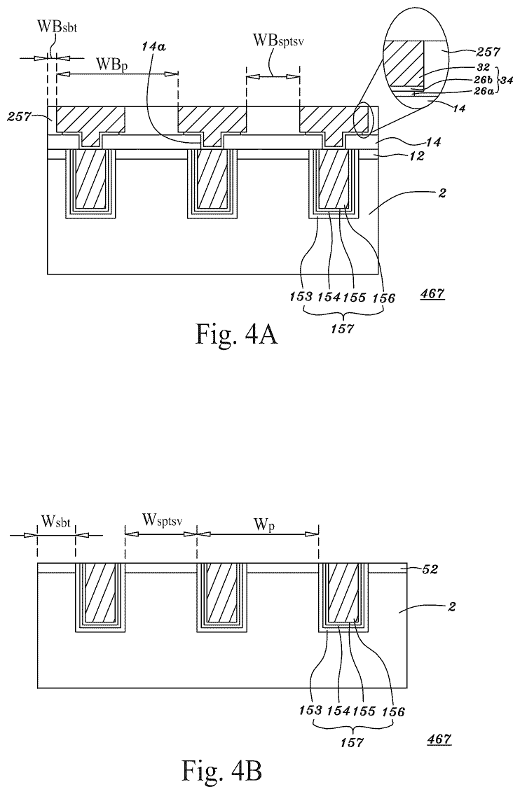

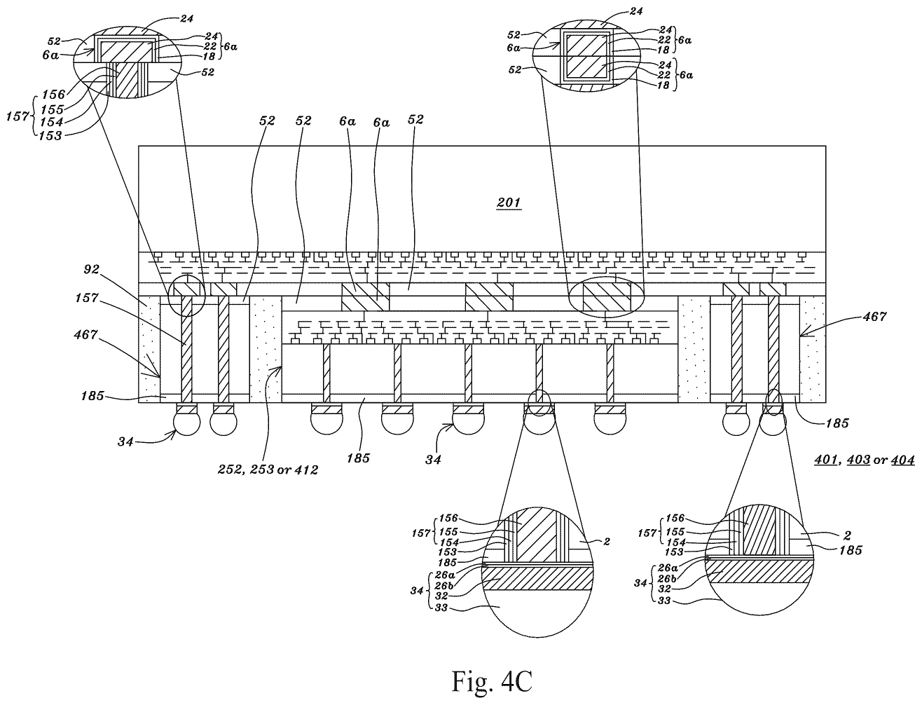

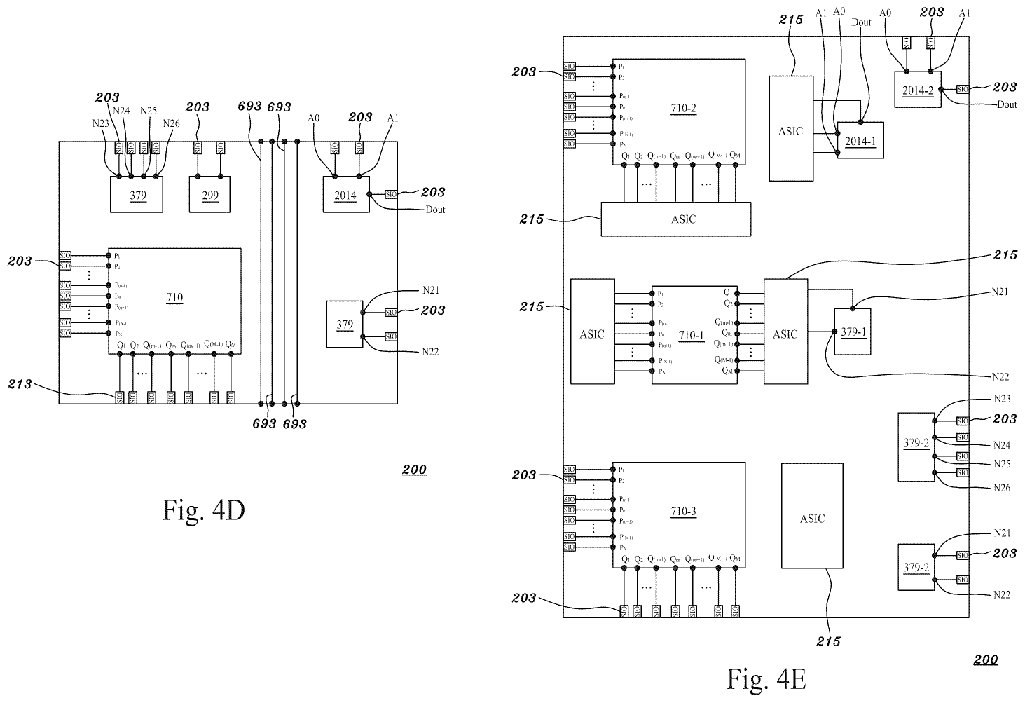

FIGS. 4A and 4B are schematically cross-sectional views showing first and second types of vertical-through-via (VTV) connectors in accordance with an embodiment of the present application. Referring to FIGS. 4A and 4B, each of the first and second types of vertical-through-via (VTV) connectors 467 is provided for vertical connection to transmit signals or deliver a power source or ground reference in a vertical direction.

### 1. First Type of Vertical-Through-Via (VTV) Connector

Referring to FIG. 4A, the first type of vertical-through-via (VTV) connector 467 may have a similar structure as the second type of semiconductor IC chip 100 as illustrated in FIG. 3B. For an element indicated by the same reference number shown in FIGS. 3A, 3B and 4A, the specification of the element as seen in FIG. 4A may be referred to that of the element as illustrated in FIGS. 3A and 3B. The difference between the first type of vertical-through-via (VTV) connectors 467 and the first type of semiconductor IC chip 100 is that the first type of vertical-through-via (VTV) connector 467 is a passive device or component without any transistor, first interconnection scheme for a chip (FISC) 20 and second interconnection scheme for a chip (SISC) 29 of the second type of semiconductor IC chip 100 as seen in FIG. 3B. For more elaboration, the first type of vertical-through-via (VTV) connectors 467 include (1) the semiconductor substrate 2, such as silicon substrate, wherein the semiconductor substrate 2 may be alternatively replaced with a glass substrate, (2) an insulating dielectric layer 12 on the semiconductor substrate 2, wherein the insulating dielectric layer 12 may include a silicon-oxide layer having a thickness between 0.1 and 2 μm, (3) the through silicon vias (TSVs) 157 in the semiconductor substrate 2, wherein each of the through silicon vias (TSVs) 157 extends vertically through the insulating dielectric layer 12 and has a top surface substantially coplanar with a top surface of the insulating dielectric layer 12, wherein each of the through silicon vias (TSVs) 157 may have a depth between 30 μm and 200 μm and a largest transverse dimension, such as diameter or width, between 2 μm and 20 μm or between 4 μm and 10 μm, (3) the passivation layer 14 on the top surface of the insulating dielectric layer 12, wherein the passivation layer 14 may include a silicon-nitride layer having a thickness of greater than 0.3 micrometers and, optionally, a polymer layer, such as polyimide, having a thickness between 1 and 5 micrometers on the silicon-nitride layer, wherein the electroplated copper layer 156 of each of the through silicon vias (TSVs) 157 may have a contact point at a bottom of one of multiple opening 14a in the passivation layer 14, wherein each of the openings 14a may have a largest transverse dimension, from a top view, between 0.5 and 20 micrometers or between 20 and 200 micrometers, (4) the first type of micro-bumps, micro-pillars or micro-pads 34 each on the contact point of the electroplated copper layer 156 of one of the through silicon vias (TSVs) 157, wherein each of its first type of micro-bumps, micro-pillars or micro-pads 34 may have the same specification as that of the first type of micro-bump, micro-pillar or micro-pad 34 as illustrated in FIG. 3A and may have the adhesion metal layer 26a on a top surface of one of its through silicon vias (TSVs) 157 and its passivation layer 14, and (5) a polymer layer 257, i.e., insulating dielectric layer, at the top thereof and on its passivation layer 14, wherein its polymer layer 257 may be horizontally around each of its first type of micro-bumps, micro-pillars or micro-pads 34 and have a top surface coplanar with a top surface of each of its first type of micro-bumps, micro-pillars or micro-pads 34, wherein its polymer layer 257 is not extending over the top surface of each of its first type of micro-bumps, micro-pillars or micro-pads 34.

Referring to FIG. 4A, for the first type of vertical-through-via (VTV) connector 467, each of its through silicon vias (TSV) 157 may have the same specification as that of the through silicon vias (TSV) 157 of the second type of semiconductor IC chip 100 as illustrated in FIG. 3B. Each of its micro-bumps, micro-pillars or micro-pads 34 may have the same specification as that of the first type of micro-bumps, micro-pillars or micro-pads 34 respectively as illustrated in FIG. 3A. Multiple trenches 14b may be formed in its passivation layer 14 to form multiple insulating-material islands 14c between neighboring two of the trenches 14b. A pitch WBₚ between each neighboring two of its first, second, third or fourth type of micro-bumps, micro-pillars or micro-pads 34 may range from 20 to 150 micrometers or from 40 to 100 micrometers; and a space WBₛₚₜₛᵥ between each neighboring two of its first, second, third or fourth type of micro-bumps, micro-pillars or micro-pads 34 may range from 20 to 150 micrometers or from 40 to 100 micrometers. A distance WB_{sbt} between its edge and one of its first, second, third or fourth type of micro-bumps, micro-pillars or micro-pads 34 may be smaller than the space WBₛₚₜₛᵥ between neighboring two of its first, second, third or fourth type of micro-bumps, micro-pillars or micro-pads 34 and optionally its edge may be aligned with an edge of said one of its first, second, third or fourth type of micro-bumps, micro-pillars or micro-pads 34; alternatively, the distance WB_{sbt} between its edge and one of its first, second, third or fourth type of micro-bumps, micro-pillars or micro-pads 34 may be smaller than 50, 40 or 30 micrometers.

### 2. Second Type of Vertical-Through-Via (VTV) Connector

Referring to FIG. 4B, the second type of vertical-through-via (VTV) connector 467 may have similar structure as the first type of vertical-through-via (VTV) connector 467 as illustrated in FIG. 4A. For an element indicated by the same reference number shown in FIGS. 4A and 4B, the specification of the element as seen in FIG. 4B may be referred to that of the element as illustrated in FIG. 4A. The difference between the first and second type of vertical-through-via (VTV) connectors 467 is that the second type of vertical-through-via (VTV) connector 467 may be formed without the passivation layer 14 and micro-bumps, micro-pillars or micro-pads 34 of the first type of vertical-through-via (VTV) connector 467 as seen in FIG. 4A. Further, the insulating dielectric layer 12 of the second type of vertical-through-via (VTV) connector 467 may be used as an insulating bonding layer 52 made of a silicon-oxide layer having a thickness between 0.1 and 2 micrometers. For the second type of vertical-through-via (VTV) connector 467, its insulating bonding layer 52 may have a top surface coplanar with a top surface of each of its through silicon vias (TSVs) 157.

Referring to FIG. 4B, for the second type of vertical-through-via (VTV) connector 467, a pitch Wₚ between each neighboring two of its through silicon vias (TSVs) 157 may range from 20 to 150 micrometers or from 40 to 100 micrometers; and a space Wₛₚₜₛᵥ between each neighboring two of its through silicon vias (TSVs) 157 may range from 20 to 150 micrometers or from 40 to 100 micrometers. A distance W_{sbt} between its edge and one of its through silicon vias (TSVs) 157 may be smaller than 50, 40 or 30 micrometers.

### Specification for Subsystem Units

### 1. First Type of Subsystem Unit

FIG. 4C is a schematically cross-sectional view showing each type of first, second and third types of subsystem units in accordance with an embodiment of the present application. Referring to FIG. 4C, the first type of subsystem unit 401 may include (1) a logic chip, application-specific integrated-circuit (ASIC) chip or system-on-chip (SoC) IC chip, such as FPGA IC chip 201, at its top, wherein its FPGA IC chip 201 may include the first, second or third type of field programmable logic cell or element (LCE) 2014 as illustrated in FIGS. 1A-1C, the first or second type of field programmable switch cell 379 as illustrated in FIGS. 2A and 2B and the field programmable switch matrix 710 as illustrated in FIG. 2C, (2) a high-bandwidth-memory (HBM) IC chip 252, such as dynamic random-access memory (DRAM) IC chip, static random-access memory (SRAM) IC chip, magnetoresistive random-access memory (MRAM) IC chip or resistive random-access memory (RRAM) IC chip, on a bottom of its FPGA IC chip 200, wherein its high-bandwidth-memory (HBM) IC chip 252 may include the first, second or third type of field programmable logic cell or element (LCE) 2014 as illustrated in FIGS. 1A-1C, the first or second type of field programmable switch cell 379 as illustrated in FIGS. 2A and 2B and the field programmable switch matrix 710 as illustrated in FIG. 2C, and (3) multiple vertical-through-via (VTV) connectors 467 on the bottom of its FPGA IC chip 201. Its FPGA IC chip 201 may have the same specification as the fifth type of semiconductor IC chip 100 illustrated in FIG. 3E to be turned upside down, its high-bandwidth-memory (HBM) IC chip 252 may have the same specification as the sixth type of semiconductor IC chip 100 illustrated in FIG. 3F and each of its vertical-through-via (VTV) connectors 467 may have the same specification as the second type of vertical-through-via (VTV) connector 467 illustrated in FIG. 4B.

Referring to FIG. 4C, for the first type of subsystem unit 401, its high-bandwidth-memory (HBM) IC chip 252 may be provided, for hybrid bonding, with (1) the insulating bonding layer 52, i.e., silicon oxide, having the top surface attached to and in contact with the bottom surface of the insulating bonding layer 52, i.e., silicon oxide, of its FPGA IC chip 201 and (2) the metal pads or input/output (I/O) pads 6a, i.e., the copper layer 24 thereof, each having the top surface bonded to and in contact with the bottom surface of one of the metal pads or input/output (I/O) pads 6a, i.e., the copper layer 24 thereof, of its FPGA IC chip 201. The bottom surface of the semiconductor substrate 2 of its FPGA IC chip 201, at which the semiconductor devices 4, such as transistors, of its FPGA IC chip 201 are formed as illustrated in FIG. 3E, faces the top surface of the semiconductor substrate 2 of its high-bandwidth-memory (HBM) IC chip 252, at which the semiconductor devices 4, such as transistors, of its high-bandwidth-memory (HBM) IC chip 252 are formed as illustrated in FIG. 3F. Each of its vertical-through-via (VTV) connectors 467 may be provided, for hybrid bonding, with (1) the insulating bonding layer 52, i.e., silicon oxide, having the top surface attached to and in contact with the bottom surface of the insulating bonding layer 52, i.e., silicon oxide, of its FPGA IC chip 201 and (2) the through silicon vias (TSVs) 157, i.e., the copper layer 24 thereof, each having the top surface bonded to and in contact with the bottom surface of one of the metal pads or input/output (I/O) pads 6a, i.e., the copper layer 24 thereof, of its FPGA IC chip 201. Each of the metal pads or input/output (I/O) pads 6a of each of its FPGA IC chip 201 and high-bandwidth-memory (HBM) IC chip 252 may have a width, diameter or transverse dimension smaller than 5, 3, 1 or 0.5 micrometers, or between 0.1 and 5 micrometers, 0.1 and 3 micrometers, 0.1 and 1 micrometers, or 0.1 and 0.5 micrometers. The pitch between neighboring two of the metal pads or input/output (I/O) pads 6a of each of its FPGA IC chip 201 and high-bandwidth-memory (HBM) IC chip 252 may be smaller than 10, 5, 2 or 1 micrometers, or between 0.2 and 10 micrometers, 0.2 and 5 micrometers, 0.2 and 2 micrometers, or 0.2 and 1 micrometers.

Referring to FIG. 4C, the first type of subsystem unit 401 may further include a polymer layer 92 or insulating dielectric layer, i.e., sealing layer, such as silicon-oxide-containing molding compound, epoxy-based material or polyimide, on the bottom of its FPGA IC chip 201 and horizontally around each of its high-bandwidth-memory (HBM) IC chip 252 and vertical-through-via (VTV) connectors 467. The semiconductor substrate 2 of each of its high-bandwidth-memory (HBM) IC chip 252 and vertical-through-via (VTV) connectors 467 may have a portion, at a backside of the semiconductor substrate 2 of said each of its high-bandwidth-memory (HBM) IC chip 252 and vertical-through-via (VTV) connectors 467, removed by a chemical-mechanical-polishing (CMP) or mechanical grinding process, and its polymer layer 92 may have a portion, at a backside of its polymer layer 92, removed by the chemical-mechanical-polishing (CMP) or mechanical grinding process. Its polymer layer 92 may have a vertical sidewall coplanar with a vertical sidewall of its FPGA IC chip 201. An insulating dielectric layer 185, such as silicon-oxide layer or silicon-nitride layer, may be formed on the backside of the semiconductor substrate 2 of each of its high-bandwidth-memory (HBM) IC chip 252 and vertical-through-via (VTV) connectors 467, wherein the insulating dielectric layer 185 of each of its high-bandwidth-memory (HBM) IC chip 252 and vertical-through-via (VTV) connectors 467 may have a bottom surface coplanar with a bottom surface of each of the through silicon vias 157 of each of its high-bandwidth-memory (HBM) IC chip 252 and vertical-through-via (VTV) connectors 467 and the bottom surface of its polymer layer 92. The first type of subsystem unit 401 may further include multiple micro-bumps, micro-pillars or micro-pads 34 in an array at its bottom to act as its external pins for coupling to external circuits outside of the first type of subsystem unit 401. Each of its micro-bumps, micro-pillars or micro-pads 34 may be of any type of first, second, third and fourth types having the same specification as the first, second, third and fourth types of micro-bumps, micro-pillars or micro-pads 34 as illustrated in FIG. 3A to be turned upside down respectively. For example, each of its first type of micro-bumps, micro-pillars or micro-pads 34 may include (1) an adhesion metal layer 26a, such as titanium (Ti) or titanium nitride (TiN) layer having a thickness between 1 nm and 50 nm, on the bottom surface of one of the through silicon vias 157, i.e., the copper layer 156 thereof, of one of its high-bandwidth-memory (HBM) IC chip 252 and vertical-through-via (VTV) connectors 467 and on the bottom surface of the insulating dielectric layer 185 of said one of its high-bandwidth-memory (HBM) IC chip 252 and vertical-through-via (VTV) connectors 467, (2) an electroplating seed layer 26b, such as copper, on and under the adhesion metal layer 26a of said each of its first type of micro-bumps, micro-pillars or micro-pads 34 and (3) a copper layer 32 having a thickness between 1 μm and 60 μm on and under the electroplating seed layer 26b of said each of its first type of micro-bumps, micro-pillars or micro-pads 34. Alternatively, each of its second type of micro-bumps, micro-pillars or micro-pads 34 may include the adhesion metal layer 26a, seed layer 26b and copper layer 32 as mentioned for its first type of micro-bumps, micro-pillars or micro-pads 34, and may further include a tin-containing solder cap 33 made of tin or a tin-silver alloy having a thickness between 1 μm and 50 μm or between 20 μm and 100 μm on and under the copper layer 32 of said each of its second type of micro-bumps, micro-pillars or micro-pads 34. Alternatively, each of its third or fourth type of micro-bumps, micro-pillars or micro-pads 34 may include the adhesion metal layer 26a on the bottom surface of one of the through silicon vias 157, i.e., the copper layer 156 thereof, of one of its high-bandwidth-memory (HBM) IC chip 252 and vertical-through-via (VTV) connectors 467 and on the bottom surface of the insulating dielectric layer 185 of said one of its high-bandwidth-memory (HBM) IC chip 252 and vertical-through-via (VTV) connectors 467.

Referring to FIG. 4C, for the first type of subsystem unit 401, its FPGA IC chip 201 may couple to one of its micro-bumps, micro-pillars or micro-pads 34 through, in sequence, one of the through silicon vias (TSVs) 157 of one of its high-bandwidth-memory (HBM) IC chip 252 and vertical-through-via (VTV) connectors 467 for transmitting a signal or clock or delivering a power or ground voltage therebetween. Its high-bandwidth-memory (HBM) IC chip 252 may have a set of small I/O circuits coupling respectively to a set of small I/O circuits of its FPGA IC chip 201 through the bonding of a set of metal pads or input/output (I/O) pads 6a of its high-bandwidth-memory (HBM) IC chip 252 to a set of metal pads or input/output (I/O) pads 6a of its FPGA IC chip 201 respectively for parallel data transmission with a data bit width of equal to or greater than 64, 128, 256, 512, 1024, 2048, 4096, 8K, or 16K, wherein each of the set of small I/O circuits of its FPGA IC chip 201 may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts or 0.5 volts and/or a voltage swing equal to or smaller than 1.2 volts, 1 volt, 0.8 volts or 0.5 volts, for example, and each of the set of small I/O circuits of its high-bandwidth-memory (HBM) IC chip 252 may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts or 0.5 volts and/or a voltage swing equal to or smaller than 1.2 volts, 1 volt, 0.8 volts or 0.5 volts, for example.

### 2. Second Type of Subsystem Unit

Referring to FIG. 4C, the second type of subsystem unit 403 may have a similar structure to that of the first type of subsystem unit 401. The difference between the first and second types of subsystem units 401 and 403 is that the high-bandwidth-memory (HBM) IC chip 252 of the first type of subsystem unit 401 may be replaced with an input/output (I/O) or control chip 253 for the second type of subsystem unit 403, wherein its input/output (I/O) or control chip 253 may have power management circuits, such as voltage regulators or voltage converters, therein, and wherein its input/output (I/O) or control chip 253 may include the first, second or third type of field programmable logic cell or element (LCE) 2014 as illustrated in FIGS. 1A-1C, the first or second type of field programmable switch cell 379 as illustrated in FIGS. 2A and 2B and the field programmable switch matrix 710 as illustrated in FIG. 2C.

Referring to FIG. 4C, for the second type of subsystem unit 403, its FPGA IC chip 201 may couple to one of its micro-bumps, micro-pillars or micro-pads 34 through, in sequence, one of the through silicon vias (TSVs) 157 of one of its input/output (I/O) or control chip 253 and vertical-through-via (VTV) connectors 467 for transmitting a signal or clock or delivering a power or ground voltage therebetween. Its input/output (I/O) or control chip 253 may have a set of small I/O circuits coupling respectively to a set of small I/O circuits of its FPGA IC chip 201 through the bonding of a set of metal pads or input/output (I/O) pads 6a of its input/output (I/O) or control chip 253 to a set of metal pads or input/output (I/O) pads 6a of its FPGA IC chip 201 respectively, wherein each of the set of small I/O circuits of its FPGA IC chip 201 may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts or 0.5 volts and/or a voltage swing equal to or smaller than 1.2 volts, 1 volt, 0.8 volts or 0.5 volts, for example, and each of the set of small I/O circuits of its input/output (I/O) or control chip 253 may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts or 0.5 volts and/or a voltage swing equal to or smaller than 1.2 volts, 1 volt, 0.8 volts or 0.5 volts, for example. Its input/output (I/O) or control chip 253 may have a set of large I/O circuits each coupling to one of its micro-bumps, micro-pillars or micro-pads 34 through one of the through silicon vias (TSVs) 157 of its input/output (I/O) or control chip 253, wherein each of the set of large I/O circuits of its input/output (I/O) or control chip 253 may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts.

### 3. Third Type of Subsystem Unit

Referring to FIG. 4C, the third type of subsystem unit 404 may have a similar structure to that of the first type of subsystem unit 401. The difference between the first and third types of subsystem units 401 and 404 is that the high-bandwidth-memory (HBM) IC chip 252 of the first type of subsystem unit 401 may be replaced with a cooperating and supporting (CS) logic IC chip 412 for the third type of subsystem unit 404.

Referring to FIG. 4C, for the third type of subsystem unit 404, its cooperating and supporting (CS) logic IC chip 412, i.e., application-specific integrated-circuit (ASIC) chip or system-on-chip (SoC) IC chip, includes the following functional blocks: (1) a large input/output (I/O) block configured for Ethernet ports, serial-advanced-technology-attachment (SATA) ports, peripheral-components-interconnect express (PCIe) ports, universal-chiplet-interconnect express (UCIe) ports, universal-serial-bus (USB) ports, serializer/deserializer (SerDes) ports, Wi-Fi (wireless fidelity) ports or Thunderbolt ports, each having multiple large input/output (I/O) circuits each for coupling to one of its micro-bumps, micro-pillars or micro-pads 34, wherein each of the large input/output (I/O) circuits of the large input/output (I/O) block of its cooperating and supporting (CS) logic IC chip 412 may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts; (2) a small-input/output (I/O) block having multiple small input/output (I/O) circuits each for coupling to one of multiple small input/output (I/O) circuits of its FPGA IC chip 201 for data transmission therebetween, wherein each of the small I/O circuits of each of its cooperating and supporting (CS) logic IC chip 412 and FPGA IC chip 201 may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts or 0.5 volts and/or a voltage swing equal to or smaller than 1.2 volts, 1 volt, 0.8 volts or 0.5 volts, for example; (3) a cryptography block configured to decrypt encrypted data transmitted from its micro-bumps, micro-pillars or micro-pads 34 through the large input/output (I/O) circuits of its cooperating and supporting (CS) logic IC chip 412 as decrypted data to be passed to its FPGA IC chip 201 through the small input/output (I/O) circuits of its cooperating and supporting (CS) logic IC chip 412 and to encrypt data transmitted from its FPGA IC chip 201 through the small input/output (I/O) circuits of its cooperating and supporting (CS) logic IC chip 412 as encrypted data to be passed to its micro-bumps, micro-pillars or micro-pads 34 through the large input/output (I/O) circuits of its cooperating and supporting (CS) logic IC chip 412; (4) a regulating block configured to regulate a voltage of power supply from an input voltage of 12, 5, 3.3 or 2.5 volts as an output voltage of 3.3, 2.5, 1.8, 1.5, 1.35, 1.2, 1.0, 0.75 or 0.5 volts to be delivered to its FPGA IC chip 201; (5) an innovated application-specific-integrated-circuit (ASIC) or customer-owned tooling (COT) block, i.e., IAC block, configured to implement intellectual-property (IP) circuits, application-specific (AS) circuits, analog circuits, mixed-mode signal circuits, radio-frequency (RF) circuits, and/or transmitter, receiver, transceiver circuits for customers, each coupling to its FPGA IC chip 201 through the small input/output (I/O) circuits of its cooperating and supporting (CS) logic IC chip 412; and (6) a hard-macro block for its FPGA IC chip 201, wherein the hard-macro block of its cooperating and supporting (CS) logic IC chip 412 may include a digital-signal-processing (DSP) slice for multiplication or division, block random-access memory (RAM) cells for logic operation, central-processing unit (CPU) cores, intellectual property (IP) cores, floating-point calculator, machine-learning-processing (MLP) circuit, central-processing-unit (CPU) circuit, graphic-processing-unit (GPU) circuit, data-processing-unit (DPU) circuit, and/or application-processing-unit (APU) circuit, each coupling to its FPGA IC chip 201 through the small input/output (I/O) circuits of its cooperating and supporting (CS) logic IC chip 412, wherein the central-processing-unit (CPU) cores may be ARM Cortex processor/controller cores based on a reduced instruction set computing (RISC) architecture or x86 central-processing-unit (CPU) cores based on complex instruction set computing (CISC) architecture, wherein the ARM Cortex processor/controller cores may be 8-bit, 16-bit, 32-bit, 64-bit or more-than-64-bit reduced-instruction-set-computing (RISC) ARM processor/controller cores licensed from ARM Holdings. Alternatively, the hard-macro block of its cooperating and supporting (CS) logic IC chip 412 may further include a phase locked loop (PLL) circuit or digital clock manager (DCM) configured to generate a clock signal to its FPGA IC chip 201. Its cooperating and supporting (CS) logic IC chip 412 may further include the first, second or third type of field programmable logic cell or element (LCE) 2014 as illustrated in FIGS. 1A-1C, the first or second type of field programmable switch cell 379 as illustrated in FIGS. 2A and 2B and the field programmable switch matrix 710 as illustrated in FIG. 2C. Its cooperating and supporting (CS) logic IC chip 412 may be configured as an interface chip having a first interface with an external circuit of the third type of subsystem unit 404 and a second interface with its FPGA IC chip 201, wherein each of the first and second interfaces may be in accordance with an industry standard of Ethernet, PCIe, SATA, UCIe, USB, SerDes, Wi-Fi or Thunderbolt. Alternatively, its cooperating and supporting (CS) logic IC chip 412 may be configured as a transceiver chip or central-processing-unit (CPU) coherent chip.

### Specification for FPMCP

Abiding by the Moore's Law, the advanced semiconductor chip technology provides chips with high circuit density, high operation frequency, high computing speed and low power consumption, while on the other hand, in the “More-than-Moore” approach, the advanced packaging technology provides heterogeneous integration to include multiple chips fabricated by different technology nodes of 5 nm, 7 nm, 10 nm or less advanced than 10 nm, for example, or multiple chips having different functions, such as central-processing unit (CPU), graphic-processing unit (GPU), application-specific integrated circuits (ASIC), power-management integrated circuits (PMIC), field-programmable gate array (FPGA), static random-access memory (SRAM), dynamic random-access memory (DRAM), non-volatile memory, flash memory, magnetoresistive random-access memory (MRAM) or resistive random-access memory (RRAM), in a single package made by advanced multi-chip packaging technologies, such as Si-interposer-based package, fan-out package and 3D stacking package.

A field-programmable multi-chip package (FPMCP) may be formed by packaging one or more FPGA IC chips, one or more non-volatile memory (NVM) IC chips, one or more logic computing IC chips, such as central-processing-unit (CPU) IC chips, graphic-processing-unit (GPU) IC chips, or application-specific integrated-circuit (ASIC) chips or system-on chips (SoC), and one or more auxiliary IC chips, such as input/output (I/O) IC chips, control IC chips, power-management integrated-circuit (PMIC) chips, in a single package by using the advanced multi-chip packaging technologies. Through configuring or re-configuring the FPGA IC chip in the FPMCP, the FPGA IC chip could work with the other chips in the same package to provide various functions therefore increase the application flexibility of the multi-chip package. The purposes of including the FPGA IC chips in the FPMCP may be: (1) using the unique feature of the field-programmability of the FPGA IC chips to configure or re-configure the FPGA IC chips for defining or changing the functions and applications of the FPMCP; (2) using the characteristic of software-defined-hardware of the FPGA IC chips to generate hardware electrical circuits for specific logic computing purpose. The FPGA IC chips in the FPMCP may be configured to cooperate with the logic computing chips in the FPMCP to accelerate the computing speed of these chips. With the non-volatile memory chips packaged in the FPMCP, the configuration or re-configuration data or information of the FPGA IC chips could be stored in the non-volatile memory cells of the non-volatile memory chips. By including the NVM and FPGA chips in the FPMCP, the FPMCP becomes non-volatile field programmable, and turns into an application-specific system package (ASSPak) for specific applications.

### Dedicated Field Programmable Integrated-Circuit (DFPIC) Chip

FIG. 4D is a circuit diagram of a dedicated field programmable integrated-circuit (DFPIC) chip in accordance with an embodiment of the present application. The FPGA IC chip 200, 100i, 100j or 601 mentioned in the following paragraphs may be a dedicated field programmable integrated-circuit (DFPIC) chip 200 as illustrated in FIG. 4D. Referring to FIG. 4D, the dedicated field programmable integrated-circuit (DFPIC) chip 200, i.e., system-on-chip (SoC) chip, may include (1) multiple small input/output (SIO) circuits 203 embedded therein and each having an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts, 0.7 volts or 0.5 volts and/or a voltage swing equal to or smaller than 1.2 volts, 1 volt, 0.8 volts, 0.7 volts or 0.5 volts, for example, (2) silicon intellectual property (IP) for multiple first, second or third type of field programmable logic cells or elements (LCE) 2014 embedded therein and each having the specification as illustrated for one in FIGS. 1A-1C and having the data inputs A0 and A1 as seen in FIG. 1A (shown in FIG. 4D) or data inputs A0-A3 as seen in FIGS. 1B and 1C (not shown in FIG. 4D) coupling to respective two or four of its small input/output (SIO) circuits 203, or metal pads or input/output (I/O) pads, and the data output Dout coupling to another of its small input/output (SIO) circuits 203, or metal pads or input/output (I/O) pads, (3) silicon intellectual property (IP) for multiple first or second type of field programmable switch cells 379 embedded therein and each having the specification as illustrated for one in FIGS. 2A and 2B with the nodes N21 and N22 as seen in FIG. 2A or nodes N23-N26 as seen in FIG. 2B coupling to respective two or four of its small input/output (SIO) circuits 203, or metal pads or input/output (I/O) pads, (4) silicon intellectual property (IP) for the field programmable switch matrix 710 embedded therein and having the specification as illustrated for one in FIG. 2C with the nodes P₁-P_{N} each coupling to one of its small input/output (SIO) circuits 203, or metal pads or input/output (I/O) pads, and the nodes Q₁-Q_{M} each coupling to one of its small input/output (SIO) circuits 203, or metal pads or input/output (I/O) pads, (5) multiple metal lines or traces 693 each coupling two metal pads or input/output (I/O) pads of the dedicated field programmable integrated-circuit (DFPIC) chip 200 at two opposite sides of the dedicated field programmable integrated-circuit (DFPIC) chip 200 to form a path coupling two circuits external of the dedicated field programmable integrated-circuit (DFPIC) chip 200, and (6) multiple volatile memory cells 299, such as cache static-random-access-memory (SRAM) cells, for storing volatile data therein, wherein each of its volatile memory cells may couple to multiple of its small input/output (SIO) circuits 203, or metal pads or input/output (I/O) pads.

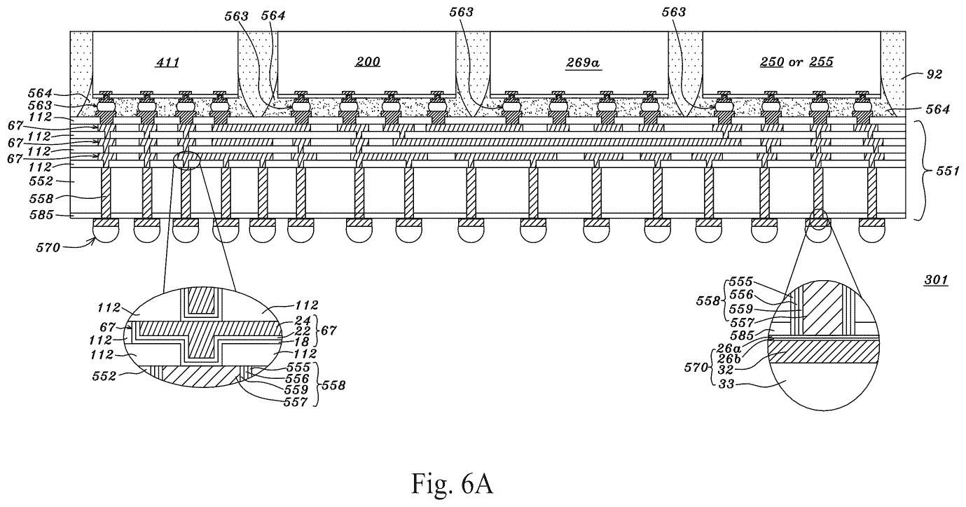

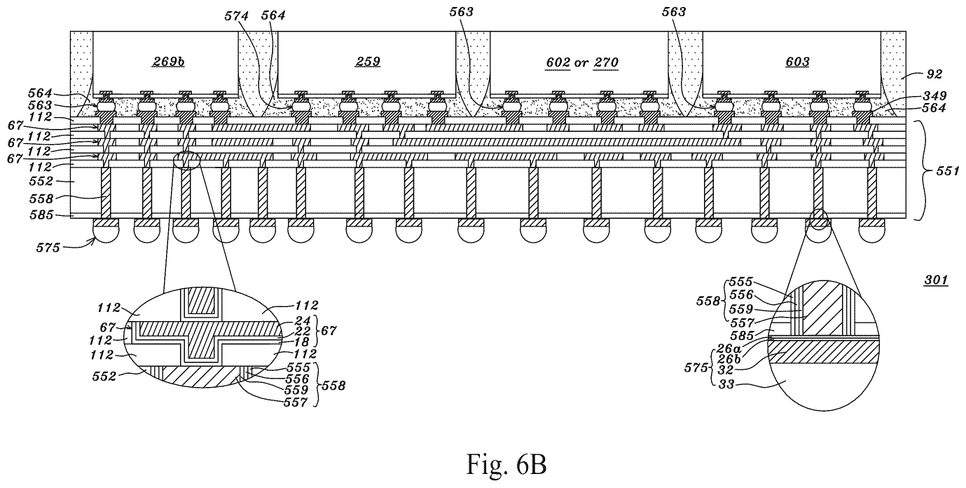

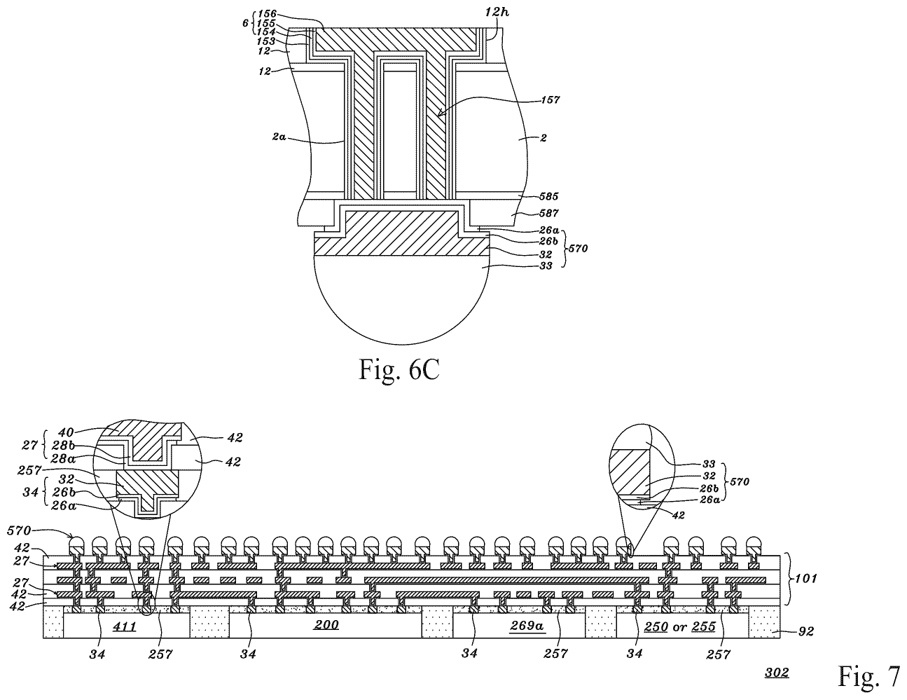

Thereby, referring to FIG. 4D, when the dedicated field programmable integrated-circuit (DFPIC) chip 200, 100i, 100j or 601 is packaged with the other semiconductor IC chips selected from one or more of another FPGA IC chip(s) 200, 100i, 100j or 601, the logic computing IC chip(s) 269, the CPU IC chip(s) 269b, the GPU IC chip(s) 269a, the ASIC or SoC chip(s) 269c, the DSP IC chip(s) 270, the control chip(s) 260, the HBM IC chip(s) 251 or 602, the NVM IC chip(s) 250, the DPIIC chip(s) 410, IAC chip 402 or the auxiliary IC chip(s) 411 or 603, with the first, second and third types of subsystem units 401, 403 and 404 as illustrated in FIGS. 5A-2, 6A, 7, 8A, 9A and 9B and/or with the FPGA/NVM multi-chip package 259 as illustrated in FIGS. 6B, 8B and 9D in any type of the first through seventeenth types of FPMCPs 301-314, 314-1, 314-2, 314-3, 314-4, 314-5, 314-6, 314-7, 314-8, 315-320 and 461 as illustrated in FIGS. 6A, 6B, 7, 8A, 8B, 9A-9D, 10, 11, 12, 13A, 13B, 14, 15A, 15B, 16, 17, 18, 19, 19-1, 19-2, 19-3, 19-4, 19-5, 19-6, 19-7, 19-8, 19-9, 20, 21, 22, 23A, 23B, 24, 25A, 25B and 25C, the dedicated field programmable integrated-circuit (DFPIC) chip 200, 100i, 100j or 601 may include the first, second or third type of field programmable logic cells or elements (LCE) 2014 each configured to select, in accordance with the data inputs A0 and A1 as seen in FIG. 1A or the data inputs A0, A1, A2 and A3 as seen in FIGS. 1B and 1C, one from the resulting values or programming codes stored in the memory cells 490 thereof as seen in FIG. 1A (but not shown in FIGS. 1B and 1C) as the data output Dout or to be operated for the data output Dout, wherein each of the data inputs A0 and A1 or data inputs A0, A1, A2 and A3 of one of its first, second or third type of field programmable logic cells or elements (LCE) 2014 may be received from a common one of the other semiconductor IC chips, such as another FPGA IC chip 200, 100i, 100j or 601, logic computing IC chip 269, CPU IC chip 269b, GPU IC chip 269a, ASIC or SoC chip 269c, DSP IC chip 270, control chip 260, HBM IC chip 251 or 602, NVM IC chip 250, DPIIC chip 410, IAC chip 402 or auxiliary IC chip 411 or 603, form a common one of the first, second and third types of subsystem units 401, 403 and 404 or from the FPGA/NVM multi-chip package 259 through one of its small input/output (SIO) circuits 203, or metal pads or input/output (I/O) pads, and the data output Dout of said one of its first, second or third type of field programmable logic cells or elements (LCE) 2014 may be passed to the common one or another of the other semiconductor IC chips, such as another FPGA IC chip 200, 100i, 100j or 601, logic computing IC chip 269, CPU IC chip 269b, GPU IC chip 269a, ASIC or SoC chip 269c, DSP IC chip 270, control chip 260, HBM IC chip 251 or 602, NVM IC chip 250, DPIIC chip 410, IAC chip 402 or auxiliary IC chip 411 or 603, to the common one or another of the first, second and third types of subsystem units 401, 403 and 404 or to the FPGA/NVM multi-chip package 259 through another of its small input/output (SIO) circuits 203, or metal pads or input/output (I/O) pads. Further, the data inputs A0 and A1 or data inputs A0, A1, A2 and A3 of another of its first, second or third type of field programmable logic cells or elements (LCE) 2014 may be received from respective two or four of the other semiconductor IC chips, first, second and third types of subsystem units 401, 403 and 404 and/or FPGA/NVM multi-chip package 259 through respective two or four of its small input/output (SIO) circuits 203, or metal pads or input/output (I/O) pads, and the data output Dout of said another of its first, second or third type of field programmable logic cells or elements (LCE) 2014 may be passed to each of the respective two or four of, or another of, the other semiconductor IC chips, first, second and third types of subsystem units 401, 403 and 404 and/or FPGA/NVM multi-chip package 259 through another of its small input/output (SIO) circuits 203, or metal pads or input/output (I/O) pads. Further, the dedicated field programmable integrated-circuit (DFPIC) chip 200, 100i, 100j or 601 may include the first or second type of field programmable switch cells 379 each configured to control, in accordance with the programming code stored in the memory cells 362 thereof as seen in FIG. 2A, coupling between the nodes N21 and N22 thereof as seen in FIG. 2A coupling to a common one or respective two of the other semiconductor IC chips, first, second and third types of subsystem units 401, 403 and 404 and/or FPGA/NVM multi-chip package 259 through respective two of its small input/output (SIO) circuits 203, or metal pads or input/output (I/O) pads, or to select, in accordance with the programming codes stored in the memory cells 362 thereof as seen in FIG. 2B, one from the nodes N23-N26 thereof to transmit a signal, or to couple, to another of, or the others of, the nodes N23-N26 thereof, wherein the nodes N23-N26 thereof may couple to a common one or respective four of the other semiconductor IC chips, first, second and third types of subsystem units 401, 403 and 404 and/or FPGA/NVM multi-chip package 259 through respective four of its small input/output (SIO) circuits 203, or metal pads or input/output (I/O) pads. Accordingly, in a first clock, a signal received from a first one of the bonded metal bumps or contacts 363, 463, 563, 563a, 563b, 563-1, 563-2, 563-3, 568, 569, 573, 574 or 663, micro-bumps, micro-pillars or micro-pads 34 or metal pads 6a on or at a surface of a first one of the other semiconductor IC chips, first, second and third types of subsystem units 401, 403 and 404 and/or FPGA/NVM multi-chip package 259 to a first one of its small input/output (SIO) circuits 203, or metal pads or input/output (I/O) pads, may be controlled by its first or second type of field programmable switch cells 379 to be passed to a second one of its small input/output (SIO) circuits 203, or metal pads or input/output (I/O) pads, coupling to a second one of the bonded metal bumps or contacts 363, 463, 563, 563a, 563b, 563-1, 563-2, 563-3, 568, 569, 573, 574 or 663, micro-bumps, micro-pillars or micro-pads 34 or metal pads 6a on or at a surface of a second one of the other semiconductor IC chips, first, second and third types of subsystem units 401, 403 and 404 and/or FPGA/NVM multi-chip package 259, and a signal received from a third one of the bonded metal bumps or contacts 363, 463, 563, 563a, 563b, 563-1, 563-2, 563-3, 568, 569, 573, 574 or 663, micro-bumps, micro-pillars or micro-pads 34 or metal pads 6a on or at the surface of the first one of the other semiconductor IC chips, first, second and third types of subsystem units 401, 403 and 404 and/or FPGA/NVM multi-chip package 259 to a third one of its small input/output (SIO) circuits 203, or metal pads or input/output (I/O) pads, may be controlled by its first or second type of field programmable switch cells 379 to be passed to a fourth one of its small input/output (SIO) circuits 203, or metal pads or input/output (I/O) pads, coupling to a fourth one of the bonded metal bumps or contacts 363, 463, 563, 563a, 563b, 563-1, 563-2, 563-3, 568, 569, 573, 574 or 663, micro-bumps, micro-pillars or micro-pads 34 or metal pads 6a on or at the surface of the second one of the other semiconductor IC chips, first, second and third types of subsystem units 401, 403 and 404 and/or FPGA/NVM multi-chip package 259; in a second clock, a signal received from the first one of the bonded metal bumps or contacts 363, 463, 563, 563a, 563b, 563-1, 563-2, 563-3, 568, 569, 573, 574 or 663, micro-bumps, micro-pillars or micro-pads 34 or metal pads 6a to the first one of its small input/output (SIO) circuits 203, or metal pads or input/output (I/O) pads, may be controlled by its first or second type of field programmable switch cells 379 to be passed to the fourth one of its small input/output (SIO) circuits 203, or metal pads or input/output (I/O) pads, and a signal received from the third one of the bonded metal bumps or contacts 363, 463, 563, 563a, 563b, 563-1, 563-2, 563-3, 568, 569, 573, 574 or 663, micro-bumps, micro-pillars or micro-pads 34 or metal pads 6a to the third one of its small input/output (SIO) circuits 203, or metal pads or input/output (I/O) pads, may be controlled by its first or second type of field programmable switch cells 379 to be passed to the second one of its small input/output (SIO) circuits 203, or metal pads or input/output (I/O) pads. Further, the dedicated field programmable integrated-circuit (DFPIC) chip 200, 100i, 100j or 601 may include the field programmable switch matrix 710 as illustrated in FIG. 2C configured to control, in accordance with the password, encryption/decryption codes or programming codes stored in the memory cell 398 of each of the field programmable switch units 711 thereof, coupling between each of the nodes P₁-P_{N} thereof and each of the nodes Q₁-Q_{M} thereof, wherein each of the nodes P₁-P_{N} thereof may couple to a common one of the other semiconductor IC chips, first, second and third types of subsystem units 401, 403 and 404 and/or FPGA/NVM multi-chip package 259 through one of its small input/output (SIO) circuits 203, or metal pads or input/output (I/O) pads, and each of the nodes Q₁-Q_{M} thereof may couple to another common one of the other semiconductor IC chips, first, second and third types of subsystem units 401, 403 and 404 and/or FPGA/NVM multi-chip package 259 through another of its small input/output (SIO) circuits 203, or metal pads or input/output (I/O) pads.

Embedded Field Programmable Integrated-Circuit (eFPIC) Chip

FIG. 4E is a circuit diagram of an embedded field programmable integrated-circuit (eFPIC) chip in accordance with an embodiment of the present application. A FPGA IC chip 200 may be an embedded field programmable integrated-circuit (eFPIC) chip 200 as illustrated in FIG. 4E. Referring to FIG. 4E, the embedded field programmable integrated-circuit (eFPIC) chip 200 may be an application specific integrated-circuit (ASIC), customer-owned-tooling (COT) or system-on-chip (SoC) chip, such as central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (ILU) IC chip, digital-signal-processing (DSP) IC chip, power management IC chip, control IC chip or input/output (I/O) IC chip. The embedded field programmable integrated-circuit (eFPIC) chip 200, i.e., system-on-chip (SoC) chip, may include (1) multiple small input/output (SIO) circuits 203 embedded therein and each having an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts, 0.7 volts or 0.5 volts and/or a voltage swing equal to or smaller than 1.2 volts, 1 volt, 0.8 volts, 0.7 volts or 0.5 volts, for example, (2) multiple application specific integrated-circuit (ASIC) cores 215 embedded therein, each of which may be a CPU, GPU, DPU, APU, TPU, MCU, AIU, MLU or DSP core; for example, one of its ASIC cores 215 may be a CPU core, another of its ASIC cores 215 may be a GPU core and still another of its ASIC cores 215 may be a DSP core, (3) silicon intellectual property (IP) for a first group of the first, second or third type of field programmable logic cells or elements (LCE) 2014-1 embedded therein and each having the specification of the first, second or third type of field programmable logic cells or elements (LCE) 2014 as illustrated in FIGS. 1A-1C and having the data inputs A0 and A1 as seen in FIG. 1A (shown in FIG. 4E) or data inputs A0-A3 as seen in FIGS. 1B and 1C (not shown in FIG. 4E) coupling to respective two or four internal circuits of a first one of its ASIC cores 215, and the data output Dout coupling to another internal circuit of the first one of its ASIC cores 215, (4) silicon intellectual property (IP) for a second group of the first, second or third type of field programmable logic cells or elements (LCE) 2014-2 embedded therein and each having the specification of the first, second or third type of field programmable logic cells or elements (LCE) 2014 as illustrated in FIGS. 1A-1C and having the data inputs A0 and A1 as seen in FIG. 1A (shown in FIG. 4E) or data inputs A0-A3 as seen in FIGS. 1B and 1C (not shown in FIG. 4E) coupling to respective two or four of its small input/output (SIO) circuits 203, or metal pads or input/output (I/O) pads, and the data output Dout coupling to another of its small input/output (SIO) circuits 203, or metal pads or input/output (I/O) pads, (5) silicon intellectual property (IP) for a first group of the first or second type of field programmable switch cells 379-1 embedded therein and each having the specification of the first or second type of field programmable switch cells 379 as illustrated in FIGS. 2A and 2B with the nodes N21 and N22 as seen in FIG. 2A or nodes N23-N26 as seen in FIG. 2B coupling to respective two or fourth internal circuits of a second one of its ASIC cores 215, (6) silicon intellectual property (IP) for a second group of the first or second type of field programmable switch cells 379-2 embedded therein and each having the specification of the first or second type of field programmable switch cells 379 as illustrated in FIGS. 2A and 2B with the nodes N21 and N22 as seen in FIG. 2A or nodes N23-N26 as seen in FIG. 2B coupling to respective two or four of its small input/output (SIO) circuits 203, or metal pads or input/output (I/O) pads, (7) silicon intellectual property (IP) for a first field programmable switch matrix 710-1 embedded therein and having the specification of the field programmable switch matrix 710 as illustrated in FIG. 2C with the nodes P₁-P_{N} each coupling to an internal circuit of a third one of its ASIC cores 215 and the nodes Q₁-Q_{M} each coupling to an internal circuit of the second one of its ASIC cores 215; for example, the second one of its ASIC cores 215 may have a first internal circuit may perform operation on an input data set including data from the node Q₁-Q_{M} of the first field programmable switch matrix 710-1 into a data output to be passed to the node N21 or N23 of one of the first group of the first or second type of field programmable switch cells 379-1 and said one of the first group of the first or second type of field programmable switch cells 379-1 may have the node(s) N22 or N24-N26 coupling to a second internal circuit of the second one of its ASIC cores 215, (8) silicon intellectual property (IP) for a second field programmable switch matrix 710-2 embedded therein and having the specification of the field programmable switch matrix 710 as illustrated in FIG. 2C with the nodes P₁-P_{N} each coupling to one of its small input/output (SIO) circuits 203, or metal pads or input/output (I/O) pads, and the nodes Q₁-Q_{M} each coupling to an internal circuit of a fourth one of its ASIC cores 215, and (9) silicon intellectual property (IP) for a third field programmable switch matrix 710-3 embedded therein and having the specification of the field programmable switch matrix 710 as illustrated in FIG. 2C with the nodes P₁-P_{N} each coupling to one of its small input/output (SIO) circuits 203, or metal pads or input/output (I/O) pads, and the nodes Q₁-Q_{M} each coupling to one of its small input/output (SIO) circuits 203, or metal pads or input/output (I/O) pads.

Thereby, referring to FIG. 4E, when the embedded field programmable integrated-circuit (eFPIC) chip 200, 100i, 100j or 601 is packaged with the other semiconductor IC chips selected from one or more of another FPGA IC chip(s) 200, 100i, 100j or 601, the logic computing IC chip(s) 269, the CPU IC chip(s) 269b, the GPU IC chip(s) 269a, the ASIC or SoC chip(s) 269c, the DSP IC chip(s) 270, the control chip(s) 260, the HBM IC chip(s) 251 or 602, the NVM IC chip(s) 250, the DPIIC chip(s) 410, IAC chip 402 or the auxiliary IC chip(s) 411 or 603, with the first, second and third types of subsystem units 401, 403 and 404 as illustrated in FIGS. 5A-2, 6A, 7, 8A, 9A and 9B and/or with the FPGA/NVM multi-chip package 259 as illustrated in FIGS. 6B, 8B and 9D in any type of the first through seventeenth types of FPMCPs 301-314, 314-1, 314-2, 314-3, 314-4, 314-5, 314-6, 314-7, 314-8, 315-320 and 461 as illustrated in FIGS. 6A, 6B, 7, 8A, 8B, 9A-9D, 10, 11, 12, 13A, 13B, 14, 15A, 15B, 16, 17, 18, 19, 19-1, 19-2, 19-3, 19-4, 19-5, 19-6, 19-7, 19-8, 19-9, 20, 21, 22, 23A, 23B, 24, 25A, 25B and 25C, the embedded field programmable integrated-circuit (eFPIC) chip 200, 100i, 100j or 601 may include the first and second groups of the first, second or third type of field programmable logic cells or elements (LCE) 2014-1 and 2014-2 each configured to select, in accordance with the data inputs A0 and A1 as seen in FIG. 1A or the data inputs A0, A1, A2 and A3 as seen in FIGS. 1B and 1C, one from the resulting values or programming codes stored in the memory cells 490 thereof as seen in FIG. 1A (but not shown in FIGS. 1B and 1C) as the data output Dout or to be operated for the data output Dout, wherein each of the data inputs A0 and A1 or data inputs A0, A1, A2 and A3 of one of the second group of its first, second or third type of field programmable logic cells or elements (LCE) 2014-2 may be received from a common one of the other semiconductor IC chips, such as another FPGA IC chip 200, 100i, 100j or 601, logic computing IC chip 269, CPU IC chip 269b, GPU IC chip 269a, ASIC or SoC chip 269c, DSP IC chip 270, control chip 260, HBM IC chip 251 or 602, NVM IC chip 250, DPIIC chip 410, IAC chip 402 or auxiliary IC chip 411 or 603, form a common one of the first, second and third types of subsystem units 401, 403 and 404 or from the FPGA/NVM multi-chip package 259 through one of its small input/output (SIO) circuits 203, or metal pads or input/output (I/O) pads, and the data output Dout of said one of the second group of its first, second or third type of field programmable logic cells or elements (LCE) 2014-2 may be passed to the common one or another of the other semiconductor IC chips, such as another FPGA IC chip 200, 100i, 100j or 601, logic computing IC chip 269, CPU IC chip 269b, GPU IC chip 269a, ASIC or SoC chip 269c, DSP IC chip 270, control chip 260, HBM IC chip 251 or 602, NVM IC chip 250, DPIIC chip 410, IAC chip 402 or auxiliary IC chip 411 or 603, to the common one or another of the first, second and third types of subsystem units 401, 403 and 404 or to the FPGA/NVM multi-chip package 259 through another of its small input/output (SIO) circuits 203, or metal pads or input/output (I/O) pads. Further, the data inputs A0 and A1 or data inputs A0, A1, A2 and A3 of another of the second group of its first, second or third type of field programmable logic cells or elements (LCE) 2014-2 may be received from respective two or four of the other semiconductor IC chips, first, second and third types of subsystem units 401, 403 and 404 and/or FPGA/NVM multi-chip package 259 through respective two or four of its small input/output (SIO) circuits 203, or metal pads or input/output (I/O) pads, and the data output Dout of said another of the second group of its first, second or third type of field programmable logic cells or elements (LCE) 2014-2 may be passed to each of the respective two or four of, or another of, the other semiconductor IC chips, first, second and third types of subsystem units 401, 403 and 404 and/or FPGA/NVM multi-chip package 259 through another of its small input/output (SIO) circuits 203, or metal pads or input/output (I/O) pads. Further, the embedded field programmable integrated-circuit (eFPIC) chip 200, 100i, 100j or 601 may include the first and second groups of the first or second type of field programmable switch cells 379-1 and 379-2 each configured to control, in accordance with the programming code stored in the memory cells 362 thereof as seen in FIG. 2A, coupling between the nodes N21 and N22 thereof as seen in FIG. 2A or to select, in accordance with the programming codes stored in the memory cells 362 thereof as seen in FIG. 2B, one from the nodes N23-N26 thereof to transmit a signal, or to couple, to another of, or the others of, the nodes N23-N26 thereof, wherein the nodes N21 and N22 or N23-N26 of one of the second group of the first or second type of field programmable switch cells 379-2 may couple to a common one or respective two or four of the other semiconductor IC chips, first, second and third types of subsystem units 401, 403 and 404 and/or FPGA/NVM multi-chip package 259 through respective two of its small input/output (SIO) circuits 203, or metal pads or input/output (I/O) pads, through respective two or four of its small input/output (SIO) circuits 203, or metal pads or input/output (I/O) pads. Accordingly, in a first clock, a signal received from a first one of the bonded metal bumps or contacts 363, 463, 563, 563a, 563b, 563-1, 563-2, 563-3, 568, 569, 573, 574 or 663, micro-bumps, micro-pillars or micro-pads 34 or metal pads 6a on or at a surface of a first one of the other semiconductor IC chips, first, second and third types of subsystem units 401, 403 and 404 and/or FPGA/NVM multi-chip package 259 to a first one of its small input/output (SIO) circuits 203, or metal pads or input/output (I/O) pads, may be controlled by the second group of its first or second type of field programmable switch cells 379-2 to be passed to a second one of its small input/output (SIO) circuits 203, or metal pads or input/output (I/O) pads, coupling to a second one of the bonded metal bumps or contacts 363, 463, 563, 563a, 563b, 563-1, 563-2, 563-3, 568, 569, 573, 574 or 663, micro-bumps, micro-pillars or micro-pads 34 or metal pads 6a on or at a surface of a second one of the other semiconductor IC chips, first, second and third types of subsystem units 401, 403 and 404 and/or FPGA/NVM multi-chip package 259, and a signal received from a third one of the bonded metal bumps or contacts 363, 463, 563, 563a, 563b, 563-1, 563-2, 563-3, 568, 569, 573, 574 or 663, micro-bumps, micro-pillars or micro-pads 34 or metal pads 6a on or at the surface of the first one of the other semiconductor IC chips, first, second and third types of subsystem units 401, 403 and 404 and/or FPGA/NVM multi-chip package 259 to a third one of its small input/output (SIO) circuits 203, or metal pads or input/output (I/O) pads, may be controlled by the second group of its first or second type of field programmable switch cells 379-2 to be passed to a fourth one of its small input/output (SIO) circuits 203, or metal pads or input/output (I/O) pads, coupling to a fourth one of the bonded metal bumps or contacts 363, 463, 563, 563a, 563b, 563-1, 563-2, 563-3, 568, 569, 573, 574 or 663, micro-bumps, micro-pillars or micro-pads 34 or metal pads 6a on or at the surface of the second one of the other semiconductor IC chips, first, second and third types of subsystem units 401, 403 and 404 and/or FPGA/NVM multi-chip package 259; in a second clock, a signal received from the first one of the bonded metal bumps or contacts 363, 463, 563, 563a, 563b, 563-1, 563-2, 563-3, 568, 569, 573, 574 or 663, micro-bumps, micro-pillars or micro-pads 34 or metal pads 6a to the first one of its small input/output (SIO) circuits 203, or metal pads or input/output (I/O) pads, may be controlled by its first or second type of field programmable switch cells 379 to be passed to the fourth one of its small input/output (SIO) circuits 203, or metal pads or input/output (I/O) pads, and a signal received from the third one of the bonded metal bumps or contacts 363, 463, 563, 563a, 563b, 563-1, 563-2, 563-3, 568, 569, 573, 574 or 663, micro-bumps, micro-pillars or micro-pads 34 or metal pads 6a to the third one of its small input/output (SIO) circuits 203, or metal pads or input/output (I/O) pads, may be controlled by its first or second type of field programmable switch cells 379 to be passed to the second one of its small input/output (SIO) circuits 203, or metal pads or input/output (I/O) pads. Further, the embedded field programmable integrated-circuit (eFPIC) chip 200, 100i, 100j or 601 may include the first, second and third field programmable switch matrices 710-1, 710-2 and 710-3 each configured to control, in accordance with the password, encryption/decryption codes or programming codes stored in the memory cell 398 of each of the field programmable switch units 711 thereof, coupling between each of the nodes P₁-P_{N} thereof and each of the nodes Q₁-Q_{M} thereof, wherein each of the nodes P₁-P_{N} of the second field programmable switch matrix 710-2 may couple to a common one of the other semiconductor IC chips, first, second and third types of subsystem units 401, 403 and 404 and/or FPGA/NVM multi-chip package 259 through one of its small input/output (SIO) circuits 203, or metal pads or input/output (I/O) pads; further, each of the nodes P₁-P_{N} of the third field programmable switch matrix 710-3 may couple to a common one of the other semiconductor IC chips, first, second and third types of subsystem units 401, 403 and 404 and/or FPGA/NVM multi-chip package 259 through one of its small input/output (SIO) circuits 203, or metal pads or input/output (I/O) pads, and each of the nodes Q₁-Q_{M} of the third field programmable switch matrix 710-3 may couple to another common one of the other semiconductor IC chips, first, second and third types of subsystem units 401, 403 and 404 and/or FPGA/NVM multi-chip package 259 through one of its small input/output (SIO) circuits 203, or metal pads or input/output (I/O) pads.

### First Type of FPMCP

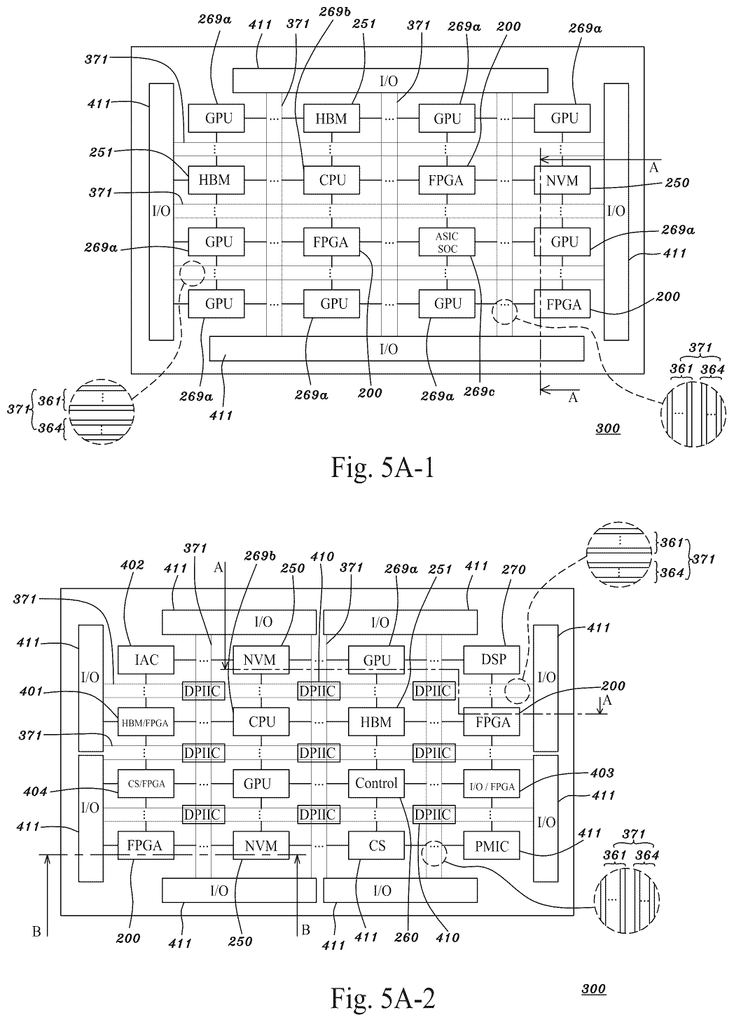

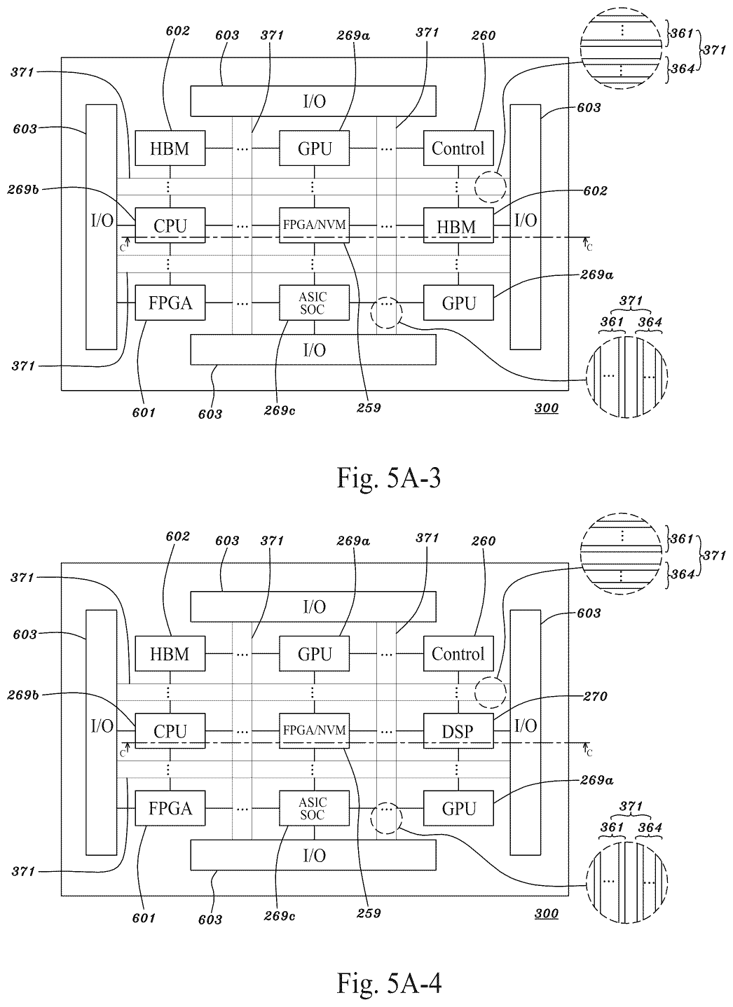

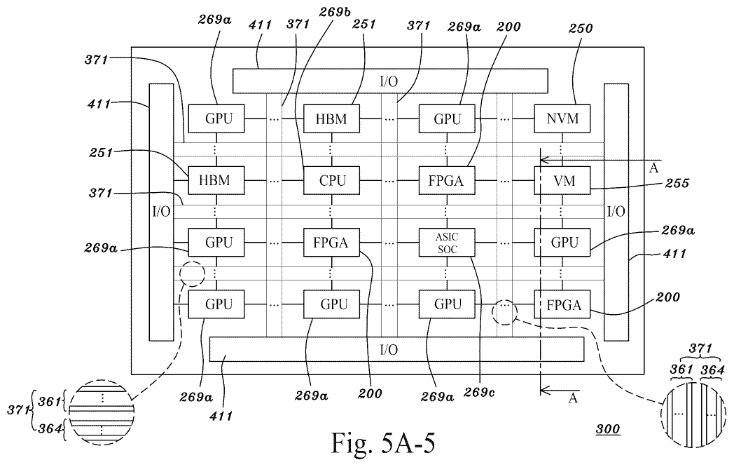

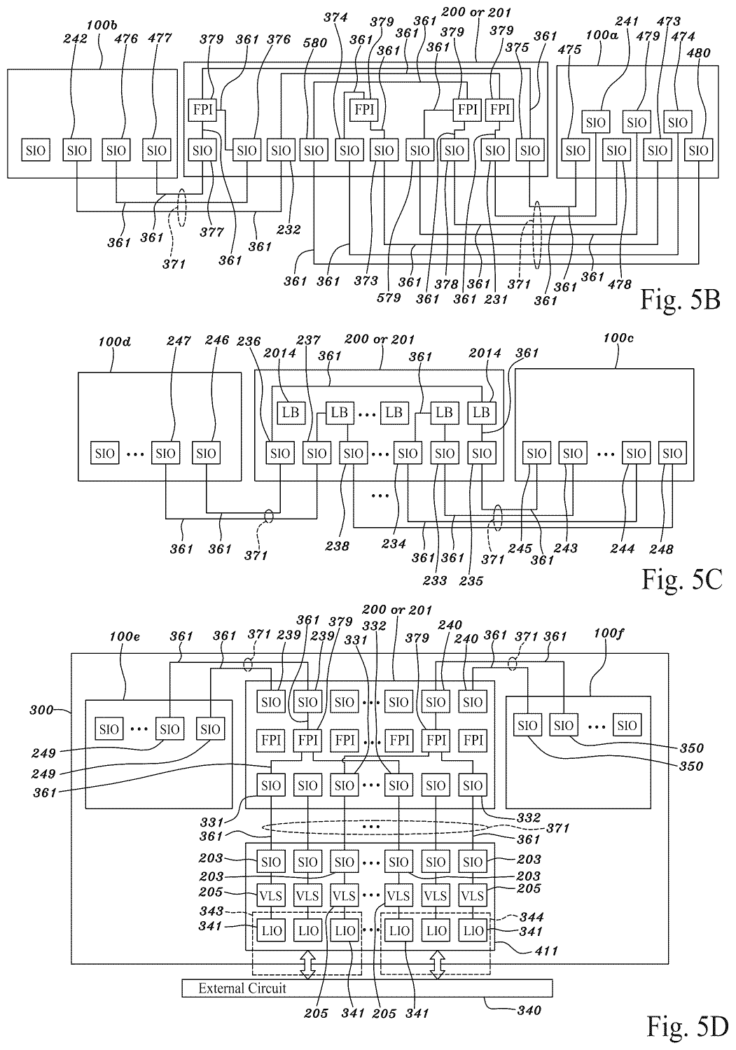

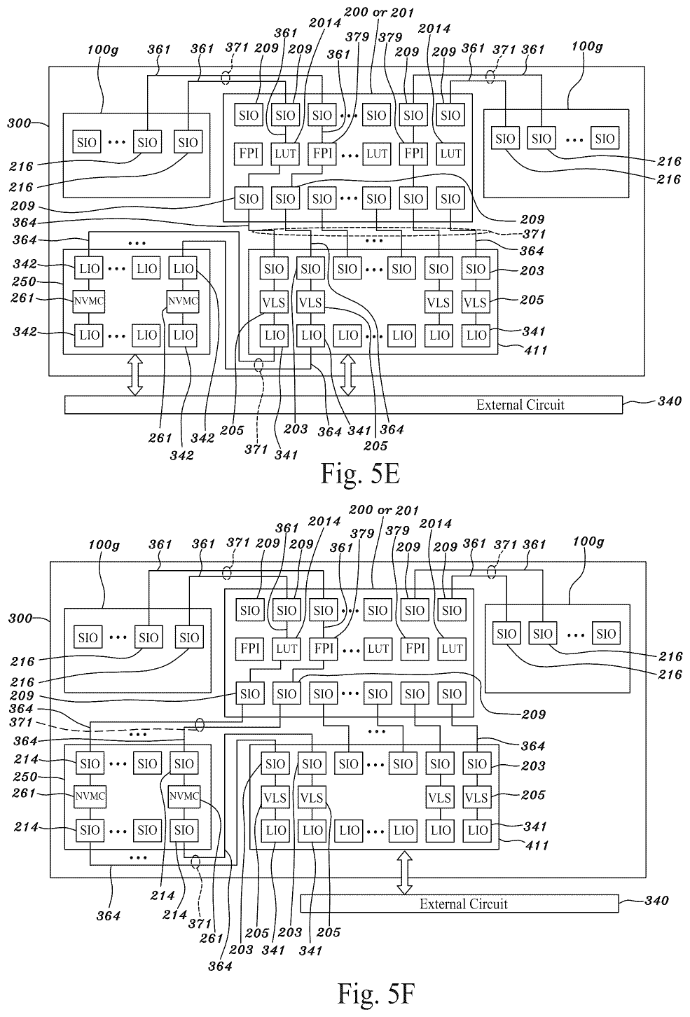

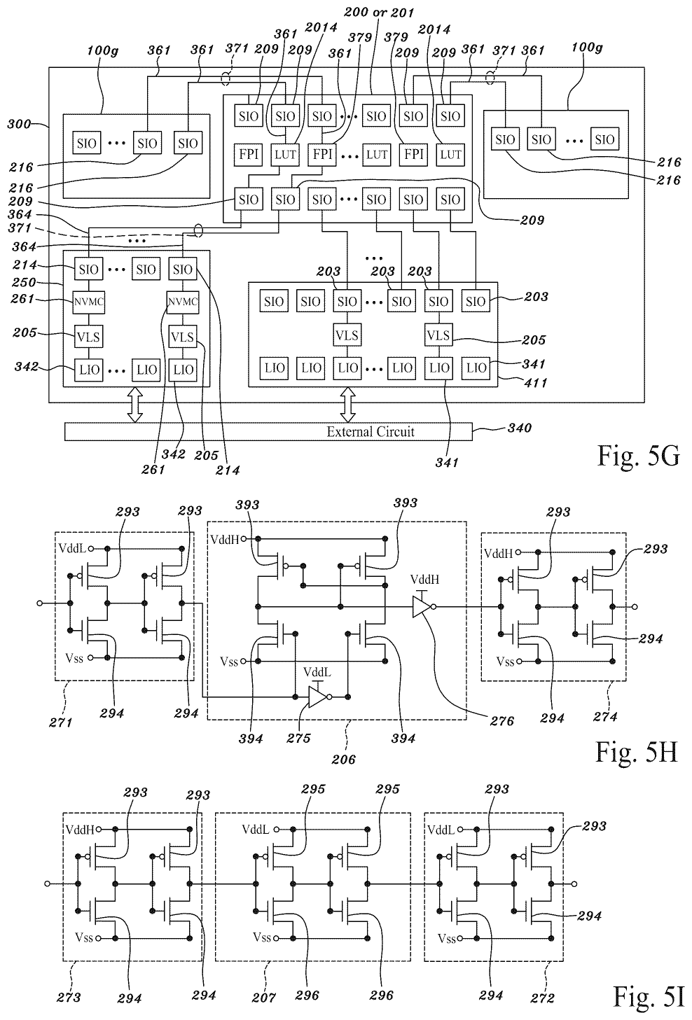

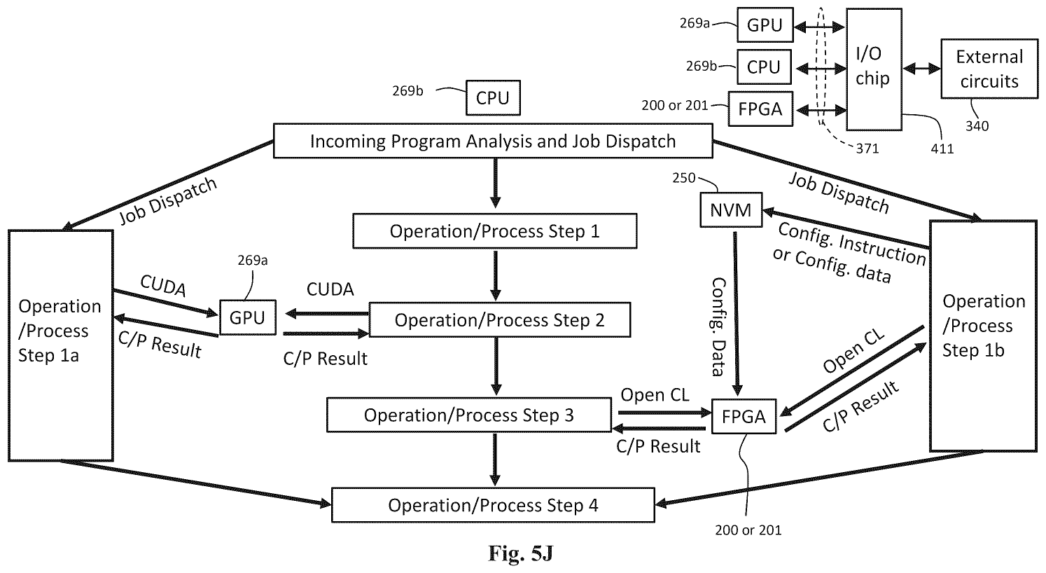

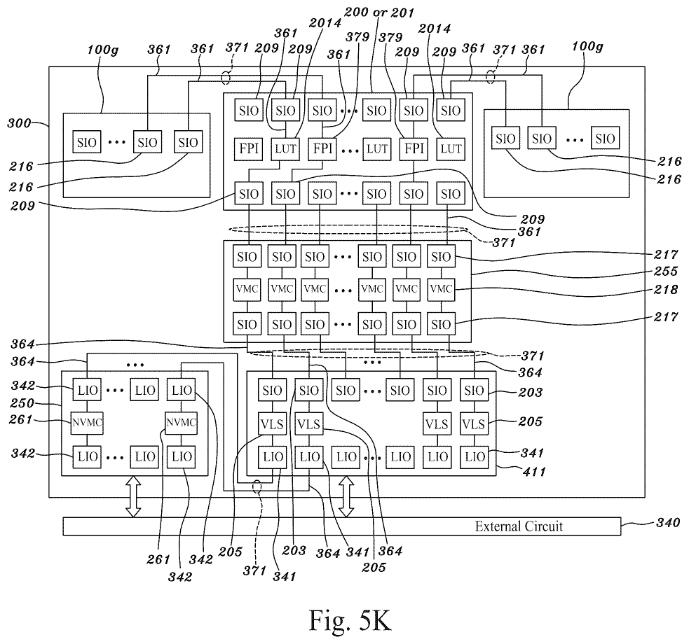

FIG. 5A-1 is a schematically top view showing a first type of FPMCP for a first alternative in accordance with an embodiment of the present application. Referring to FIG. 5A-1, the first type of FPMCP 300 for the first alternative may be packaged with multiple semiconductor IC chips, including three FPGA IC chips 200, i.e., logic chips, in a single-die type, one NVM IC chip 250, multiple logic computing IC chips, i.e., eight graphic-processing-unit (GPU) IC chips 269a, one central-processing-unit (CPU) IC chip 269b, and one application-specific integrated-circuit (ASIC) chip or system-on-chip (SoC) chip 269c, two high bandwidth memory (HBM) IC chips 251, and four auxiliary IC chips 411, arranged in a same horizontal level, wherein each of its FPGA IC chips 200 may be the dedicated field programmable integrated-circuit (DFPIC) chip as illustrated in FIG. 4D or embedded field programmable integrated-circuit (eFPIC) chip as illustrated in FIG. 4E. For the first type of FPMCP 300 for the first alternative, each of its FPGA IC chips 200 may include the first, second or third type of field programmable logic cell or element (LCE) 2014 as illustrated in FIGS. 1A-1C, the first or second type of field programmable switch cell 379 as illustrated in FIGS. 2A and 2B and the field programmable switch matrix 710 as illustrated in FIG. 2C; each of its high bandwidth memory (HBM) IC chips 251 may be a high speed, high bandwidth, wide bitwidth dynamic-random-access-memory (DRAM) IC chip, high speed, high bandwidth, wide bitwidth cache static-random-access-memory (SRAM) chip, high speed, high bandwidth, wide bitwidth magnetoresistive random-access-memory (MRAM) chip or high speed, high bandwidth, wide bitwidth resistive random-access-memory (RRAM) chip; each of its auxiliary IC chips 411 may be an input/output (I/O) IC chip, control IC chip or power-management integrated-circuit (PMIC) chip; its NVM IC chip 250 may be a NAND or NOR flash IC chip, magnetoresistive random-access memory (MRAM) IC chip, resistive random-access memory (RRAM) IC chip or ferroelectric random-access memory (FRAM) IC chip; its application-specific integrated-circuit (ASIC) chip or system-on-chip (SoC) chip 269c may have intellectual-property (IP) circuits, application-specific (AS) circuits, analog circuits, mixed-mode signal circuits, radio-frequency (RF) circuits, and/or transmitter, receiver or transceiver circuits therein; each of its auxiliary IC chips 411 may include the following functional blocks: (1) a large-input/output (I/O) block configured for various input/output (I/O), formats, protocols or industry standards such as Ethernet, peripheral component interconnect express (PCIe), serial-advanced-technology-attachment (SATA), universal chiplet interconnect express (UCIe), universal serial bus (USB), serializer/deserializer (SerDes), Wi-Fi (wireless fidelity) or Thunderbolt, and with multiple large input/output (LIO) circuits 341 as seen in FIGS. 5D-5G, each having an I/O power efficiency greater than 3, 5 or 10 pico-Joules per bit, per switch or per voltage swing and/or having an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts; (2) a small-input/output (I/O) block having multiple small input/output (SIO) circuits 203, as seen in FIGS. 5D-5G, configured to couple to all of its FPGA IC chips 200, logic computing IC chips 269a, 269b and 269c and high bandwidth memory (HBM) IC chips 251 for data transmission therebetween, wherein each of the small input/output (SIO) circuits 203 of the small-input/output (I/O) block of said each of its auxiliary IC chips 411 may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts, 0.7 volts or 0.5 volts and/or a voltage swing equal to or smaller than 1.2 volts, 1 volt, 0.8 volts, 0.7 volts or 0.5 volts, for example; (3) a cryptography block configured to decrypt encrypted data transmitted from its NVM IC chip 250 through the large or small input/output (LIO or SIO) circuits 341 or 203 of said each of its auxiliary IC chips 411 as decrypted data to be passed to its FPGA IC chips 200, logic computing IC chips 269a, 269b and 269c and high bandwidth memory (HBM) IC chips 251 through the small input/output (SIO) circuits 203 of said each of its auxiliary IC chips 411 and to encrypt data transmitted from its FPGA IC chips 200, logic computing IC chips 269a, 269b and 269c and high bandwidth memory (HBM) IC chips 251 through the small input/output (SIO) circuits 203 of said each of its auxiliary IC chips 411 as encrypted data to be passed to its NVM IC chip 250 through the large or small input/output (LIO or SIO) circuits 341 or 203 of said each of its auxiliary IC chips 411; (4) a regulating block for direct-current-to-direct-current (DC-to-DC) voltage conversion, voltage regulating, battery charging, power source selection, voltage scaling, and/or power sequencing, wherein the regulating block may be configured to regulate a voltage of power supply from an input voltage of 12, 5, 3.3 or 2.5 volts as an output voltage of 3.3, 2.5, 1.8, 1.5, 1.35, 1.2, 1.0, 0.75 or 0.5 volts to be delivered to its FPGA IC chips 200, logic computing IC chips 269a, 269b and 269c, high bandwidth memory (HBM) IC chips 251 and NVM IC chip 250; (5) an innovated application-specific-integrated-circuit (ASIC) or customer-owned tooling (COT) block, i.e., IAC block, configured to implement intellectual-property (IP) circuits, application-specific (AS) circuits, analog circuits, mixed-mode signal circuits, radio-frequency (RF) circuits, and/or transmitter, receiver, transceiver circuits for customers, each coupling to its FPGA IC chips 200, logic computing IC chips 269a, 269b and 269c and high bandwidth memory (HBM) IC chips 251 through the small input/output (SIO) circuits 203 of said each of its auxiliary IC chips 411; and (6) a hard-macro block for its FPGA IC chips 200, wherein the hard-macro block may include a digital-signal-processing (DSP) slice for multiplication or division, block random-access memory (RAM) cells for logic operation, central-processing unit (CPU) cores, intellectual property (IP) cores, floating-point calculator, machine-learning-processing (MLP) circuit, central-processing-unit (CPU) circuit, graphic-processing-unit (GPU) circuit, data-processing-unit (DPU) circuit, and/or application-processing-unit (APU) circuit, each coupling to its FPGA IC chips 200, logic computing IC chips 269a, 269b and 269c and high bandwidth memory (HBM) IC chips 251 through the small input/output (SIO) circuits 203 of said each of its auxiliary IC chips 411, wherein the central-processing-unit (CPU) cores may be ARM Cortex processor/controller cores based on a reduced instruction set computing (RISC) architecture or x86 central-processing-unit (CPU) cores based on complex instruction set computing (CISC) architecture, wherein the ARM Cortex processor/controller cores may be 8-bit, 16-bit, 32-bit, 64-bit or more-than-64-bit reduced-instruction-set-computing (RISC) ARM processor/controller cores licensed from ARM Holdings. Alternatively, the hard-macro block of each of its auxiliary IC chips 411 may further include a phase locked loop (PLL) circuit or digital clock manager (DCM) configured to generate a clock signal to its FPGA IC chips 200, logic computing IC chips 269a, 269b and 269c and high bandwidth memory (HBM) IC chips 251. For the first type of FPMCP 300 for the first alternative, its FPGA IC chips 200, NVM IC chip 250, logic computing IC chips 269a, 269b and 269c and high bandwidth memory (HBM) IC chips 251 may be arranged in an array within its center region; its auxiliary IC chips 411 may be arranged in its peripheral region surrounding its center region. Each of its auxiliary IC chips 411 may be configured as an interface chip having a first interface with an external circuit of the first type of FPMCP 300 for the first alternative and a second interface with any another of its semiconductor IC chips 200, 250, 269a, 269b, 269c, 251 and 411, wherein each of the first and second interfaces may be in accordance with an industry standard of Ethernet, PCIe, SATA, UCIe, USB, SerDes, Wi-Fi or Thunderbolt. Alternatively, each of its auxiliary IC chips 411 may be configured as a transceiver chip or central-processing-unit (CPU) coherent chip.

FIG. 5A-2 is a schematically top view showing a first type of FPMCP for a second alternative in accordance with an embodiment of the present application. For an element indicated by the same reference number shown in FIGS. 5A-1 and 5A-2, the specification of the element as seen in FIG. 5A-2 may be referred to that of the element as illustrated in FIG. 5A-1. Referring to FIG. 5A-2, the first type of FPMCP 300 for the second alternative may be packaged with (1) multiple semiconductor IC chips, including two FPGA IC chips 200, i.e., logic chips, in a single-die type, two NVM IC chips 250, one dedicated control and input/output (I/O) chip 260, multiple logic computing IC chips, i.e., two graphic-processing-unit (GPU) IC chips 269a, i.e., data-processing-unit (DPU) IC chips, one central-processing-unit (CPU) IC chip 269b and one digital-signal-processing (DSP) IC chip 270, one high-bandwidth-memory (HBM) IC chip 251, eight auxiliary IC chips 411 and one innovated application-specific-IC (ASIC) or customer-owned-tooling (COT) (abbreviated as IAC below) chip 402, and (2) the first, second and third types of subsystem units 401, 403 and 404 as illustrated in FIG. 4C, all arranged in a same horizontal level, wherein each of its FPGA IC chips 200 may be the dedicated field programmable integrated-circuit (DFPIC) chip as illustrated in FIG. 4D or embedded field programmable integrated-circuit (eFPIC) chip as illustrated in FIG. 4E, wherein its dedicated control and input/output (I/O) chip 260 may be an application-specific integrated-circuit (ASIC) chip or system-on-chip (SoC) IC chip and may be configured to control data transmission between any two of its FPGA IC chips 200, logic computing IC chips 269a, 269b and 270, high-bandwidth-memory (HBM) IC chip 251, NVM IC chips 250, IAC chip 402, auxiliary IC chips 411 and first, second and third types of subsystem units 401, 403 and 404 and to control data transmission from one of its FPGA IC chips 200, logic computing IC chips 269a, 269b and 270, high-bandwidth-memory (HBM) IC chip 251, NVM IC chips 250, IAC chip 402, auxiliary IC chips 411 and first, second and third types of subsystem units 401, 403 and 404 to a circuit external of the first type of FPMCP 300 for the second alternative, and wherein its IAC chip 402 may include therein intellectual-property (IP) circuits, application-specific (AS) circuits, analog circuits, mixed-mode signal circuits, radio-frequency (RF) circuits, and/or transmitter, receiver or transceiver circuits, etc. Further, its high-bandwidth-memory (HBM) IC chip 251 may be arranged next to one of its graphic-processing unit (GPU) IC chips 269a, central-processing-unit (CPU) IC chip 269b and FPGA IC chips 200 for parallel data transmission therebetween with a data bit width of equal to or greater than 64, 128, 256, 512, 1024, 2048, 4096, 8K, or 16K. Each of its auxiliary IC chips 411 may include the following functional blocks: (1) a large input/output (I/O) block configured for various input/output (I/O) formats, protocols or industry standards such as Ethernet, peripheral component interconnect express (PCIe), serial-advanced-technology-attachment (SATA), universal chiplet interconnect express (UCIe), universal serial bus (USB), serializer/deserializer (SerDes), Wi-Fi (wireless fidelity) or Thunderbolt, and with multiple large input/output (LIO) circuits 341 as seen in FIGS. 5D-5G, each having an I/O power efficiency greater than 3, 5 or 10 pico-Joules per bit, per switch or per voltage swing and/or having an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts; (2) a small-input/output (I/O) block having multiple small input/output (SIO) circuits 203, as seen in FIGS. 5D-5G, configured to couple to its FPGA IC chips 200 or 201, logic computing IC chips 269a, 269b and 270 and high bandwidth memory (HBM) IC chips 251 for data transmission therebetween, wherein each of the small I/O (SIO) circuits 203 of the small-input/output (I/O) block of said each of its auxiliary IC chips 411 may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts or 0.5 volts and/or a voltage swing equal to or smaller than 1.2 volts, 1 volt, 0.8 volts or 0.5 volts, for example; (3) a cryptography block configured to decrypt encrypted data transmitted from any of its NVM IC chips 250 through the large or small input/output (LIO or SIO) circuits 341 or 203 of said each of its auxiliary IC chips 411 as decrypted data to be passed to its FPGA IC chips 200 or 201, logic computing IC chips 269a, 269b and 270 and high bandwidth memory (HBM) IC chips 251 through the small input/output (SIO) circuits 203 of said each of its auxiliary IC chips 411 and to encrypt data transmitted from its FPGA IC chips 200 or 201, logic computing IC chips 269a, 269b and 270 and high bandwidth memory (HBM) IC chips 251 through the small input/output (SIO) circuits 203 of said each of its auxiliary IC chips 411 as encrypted data to be passed to said any of its NVM IC chips 250 through the large or small input/output (LIO or SIO) circuits 341 or 203 of said each of its auxiliary IC chips 411; (4) a regulating block for direct-current-to-direct-current (DC-to-DC) voltage conversion, voltage regulating, battery charging, power source selection, voltage scaling, and/or power sequencing, wherein the regulating block may be configured to regulate a voltage of power supply from an input voltage of 12, 5, 3.3 or 2.5 volts as an output voltage of 3.3, 2.5, 1.8, 1.5, 1.35, 1.2, 1.0, 0.75 or 0.5 volts to be delivered to its FPGA IC chips 200 or 201, logic computing IC chips 269a, 269b and 270, high bandwidth memory (HBM) IC chips 251 and NVM IC chips 250; (5) an innovated application-specific-integrated-circuit (ASIC) or customer-owned tooling (COT) block, i.e., IAC block, configured to implement intellectual-property (IP) circuits, application-specific (AS) circuits, analog circuits, mixed-mode signal circuits, radio-frequency (RF) circuits, and/or transmitter, receiver, transceiver circuits for customers, each coupling to its FPGA IC chips 200 or 201, logic computing IC chips 269a, 269b and 270 and high bandwidth memory (HBM) IC chips 251 through the small input/output (SIO) circuits 203 of said each of its auxiliary IC chips 411; and (6) a hard-macro block for its FPGA IC chips 200 and 201, wherein each of its FPGA IC chips 201 may be provided by one of its first and second types of subsystem units 401, 403 and 404 as illustrated in FIG. 4C, wherein the hard-macro block of said each of its auxiliary IC chips 411 may include a digital-signal-processing (DSP) slice for multiplication or division, block random-access memory (RAM) cells for logic operation, central-processing unit (CPU) cores, intellectual property (IP) cores, floating-point calculator, machine-learning-processing (MLP) circuit, central-processing-unit (CPU) circuit, graphic-processing-unit (GPU) circuit, data-processing-unit (DPU) circuit, and/or application-processing-unit (APU) circuit, each coupling to its FPGA IC chips 200 and 201 through the small input/output (SIO) circuits 203 of said each of its auxiliary IC chips 411, wherein the central-processing-unit (CPU) cores may be ARM Cortex processor/controller cores based on a reduced instruction set computing (RISC) architecture or x86 central-processing-unit (CPU) cores based on complex instruction set computing (CISC) architecture, wherein the ARM Cortex processor/controller cores may be 8-bit, 16-bit, 32-bit, 64-bit or more-than-64-bit reduced-instruction-set-computing (RISC) ARM processor/controller cores licensed from ARM Holdings. Alternatively, the hard-macro block of said each of its auxiliary IC chips 411 may further include a phase locked loop (PLL) circuit or digital clock manager (DCM) configured to generate a clock signal to its FPGA IC chips 200 and 201. For the first type of FPMCP 300 for the second alternative, its CPU IC chip 269b, DSP IC chip 270, dedicated control and input/output (I/O) chip 260, FPGA IC chips 200, GPU IC chips 269a, NVM IC chips 250, IAC chip 402, HBM IC chip 251 and first, second and third types of subsystem units 401, 403 and 404 may be arranged in an array within its center region, and its eight auxiliary IC chips 411 may be arranged in its peripheral region surrounding its center region, wherein each of its eight auxiliary IC chips 411 may be used as an input/output (I/O) or control chip. Each of its auxiliary IC chips 411 may be configured as an interface chip having a first interface with an external circuit of the first type of FPMCP 300 for the second alternative and a second interface with any another of its semiconductor IC chips 200, 250, 260, 269a, 269b, 270, 251, 411 and 402 or any of its first, second and third types of subsystem units 401, 403 and 404, wherein each of the first and second interfaces may be in accordance with an industry standard of Ethernet, PCIe, SATA, UCIe, USB, SerDes, Wi-Fi or Thunderbolt. Alternatively, each of its auxiliary IC chips 411 may be configured as a transceiver chip or central-processing-unit (CPU) coherent chip.

FIG. 5A-3 is a schematically top view showing a first type of FPMCP for a third alternative in accordance with an embodiment of the present application. Referring to FIG. 5A-3, the first type of FPMCP 300 for the third alternative may be packaged with (1) multiple semiconductor IC chips, including a FPGA IC chip 601, i.e., logic chips, in a single-die type, one dedicated control and input/output (I/O) chip 260, multiple logic computing IC chips, i.e., two graphic-processing-unit (GPU) IC chips 269a, i.e., data-processing-unit (DPU) IC chips, one central-processing-unit (CPU) IC chip 269b and one application-specific integrated-circuit (ASIC) chip or system-on-chip (SoC) chip 269c, two high-bandwidth-memory (HBM) IC chips 602, four auxiliary IC chips 603, and (2) a FPGA/NVM multi-chip package 259, all arranged in a same horizontal level, wherein each of its FPGA IC chip 601 and the FPGA IC chip(s) 200, 100i and/or 100j of its FPGA/NVM multi-chip package 259 may be the dedicated field programmable integrated-circuit (DFPIC) chip as illustrated in FIG. 4D or embedded field programmable integrated-circuit (eFPIC) chip as illustrated in FIG. 4E. For the first type of FPMCP 300 for the third alternative, its FPGA IC chip 601 may include the first, second or third type of field programmable logic cell or element (LCE) 2014 as illustrated in FIGS. 1A-1C, the first or second type of field programmable switch cell 379 as illustrated in FIGS. 2A and 2B and the field programmable switch matrix 710 as illustrated in FIG. 2C; each of its high bandwidth memory (HBM) IC chips 602 may be a high speed, high bandwidth, wide bitwidth dynamic-random-access-memory (DRAM) IC chip, high speed, high bandwidth, wide bitwidth cache static-random-access-memory (SRAM) chip, high speed, high bandwidth, wide bitwidth magnetoresistive random-access-memory (MRAM) chip or high speed, high bandwidth, wide bitwidth resistive random-access-memory (RRAM) chip; each of its auxiliary IC chips 603 may be an input/output (I/O) IC chip, control IC chip or power-management integrated-circuit (PMIC) chip; its application-specific integrated-circuit (ASIC) chip or system-on-chip (SoC) chip 269c may have intellectual-property (IP) circuits, application-specific (AS) circuits, analog circuits, mixed-mode signal circuits, radio-frequency (RF) circuits, and/or transmitter, receiver or transceiver circuits therein; its dedicated control and input/output (I/O) chip 260 may be an application-specific integrated-circuit (ASIC) chip or system-on-chip (SoC) IC chip and may be configured to control data transmission between any two of its FPGA IC chip 601, logic computing IC chips 269a, 269b and 269c, high-bandwidth-memory (HBM) IC chips 602, auxiliary IC chips 603 and FPGA/NVM multi-chip package 259 and to control data transmission from one of its FPGA IC chip 601, logic computing IC chips 269a, 269b and 269c, high-bandwidth-memory (HBM) IC chips 602, auxiliary IC chips 603 and FPGA/NVM multi-chip package 259 to a circuit external of the first type of FPMCP 300 for the third alternative. Further, for the first type of FPMCP 300 for the third alternative, its FPGA/NVM multi-chip package 259 may be any type of the second through seventeenth types of FPMCPs 305-314, 314-1, 314-2, 314-3, 314-4, 314-5, 314-6, 314-7, 314-8, 315-320 and 461 as illustrated in FIGS. 10, 11, 12, 13A, 13B, 14, 15A, 15B, 16, 17, 18, 19, 19-1, 19-2, 19-3, 19-4, 19-5, 19-6, 19-7, 19-8, 19-9, 20, 21, 22, 23A, 23B, 24, 25A, 25B and 25C. Further, a left front one of its high-bandwidth-memory (HBM) IC chips 602 may be arranged next to a front one of its graphic-processing unit (GPU) IC chips 269a for parallel data transmission therebetween with a data bit width of equal to or greater than 64, 128, 256, 512, 1024, 2048, 4096, 8K, or 16K; alternatively, the left front one of its high-bandwidth-memory (HBM) IC chips 602 may be arranged next to its central-processing-unit (CPU) IC chip 269b for parallel data transmission therebetween with a data bit width of equal to or greater than 64, 128, 256, 512, 1024, 2048, 4096, 8K, or 16K; a right one of its high-bandwidth-memory (HBM) IC chips 602 may be arranged next to a right rear one of its graphic-processing unit (GPU) IC chips 269a for parallel data transmission therebetween with a data bit width of equal to or greater than 64, 128, 256, 512, 1024, 2048, 4096, 8K, or 16K; alternatively, the right one of its high-bandwidth-memory (HBM) IC chips 602 may be arranged next to its FPGA/NVM multi-chip package 259 for parallel data transmission between the right one of its high-bandwidth-memory (HBM) IC chips 602 and any of the FPGA IC chip(s) 200, 100i and/or 100j of its FPGA/NVM multi-chip package 259 with a data bit width of equal to or greater than 64, 128, 256, 512, 1024, 2048, 4096, 8K, or 16K. Each of its auxiliary IC chips 603 may have the same circuits as the auxiliary IC chip 411 illustrated in FIGS. 5D-5G and include the following functional blocks: (1) a large input/output (I/O) block configured for various input/output (I/O) formats, protocols or industry standards such as Ethernet, peripheral component interconnect express (PCIe), serial-advanced-technology-attachment (SATA), universal chiplet interconnect express (UCIe), universal serial bus (USB), serializer/deserializer (SerDes), Wi-Fi (wireless fidelity) or Thunderbolt, and with multiple large input/output (LIO) circuits 341 as seen in FIGS. 5D-5G, each having an I/O power efficiency greater than 3, 5 or 10 pico-Joules per bit, per switch or per voltage swing and/or having an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts; (2) a small-input/output (I/O) block having multiple small input/output (SIO) circuits 203 configured to couple to its FPGA IC chip 601, logic computing IC chips 269a, 269b and 269c, high bandwidth memory (HBM) IC chips 602 and FPGA/NVM multi-chip package 259 for data transmission therebetween, wherein each of the small I/O (SIO) circuits 203 of the small-input/output (I/O) block of said each of its auxiliary IC chips 603 may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts or 0.5 volts and/or a voltage swing equal to or smaller than 1.2 volts, 1 volt, 0.8 volts or 0.5 volts, for example; (3) a cryptography block configured to decrypt encrypted data transmitted from (said any of) the NVM IC chip(s) 250 of its FPGA/NVM multi-chip package 259 through the large or small input/output (LIO or SIO) circuits 341 or 203 of said each of its auxiliary IC chips 603 as decrypted data to be passed to its FPGA IC chip 601 and (said any of) the FPGA IC chip(s) 200, 100i and/or 100j of its FPGA/NVM multi-chip package 259, its logic computing IC chips 269a, 269b and 269c and high bandwidth memory (HBM) IC chips 602 through the small input/output (SIO) circuits 203 of said each of its auxiliary IC chips 603 and to encrypt data transmitted from its FPGA IC chip 601 and (said any of) the FPGA IC chip(s) 200, 100i and/or 100j of its FPGA/NVM multi-chip package 259, its logic computing IC chips 269a, 269b and 269c and its high bandwidth memory (HBM) IC chips 602 through the small input/output (SIO) circuits 203 of said each of its auxiliary IC chips 603 as encrypted data to be passed to (said any of) the NVM IC chip(s) 250 of its FPGA/NVM multi-chip package 259 through the large or small input/output (LIO or SIO) circuits 341 or 203 of said each of its auxiliary IC chips 603; (4) a regulating block for direct-current-to-direct-current (DC-to-DC) voltage conversion, voltage regulating, battery charging, power source selection, voltage scaling, and/or power sequencing, wherein the regulating block may be configured to regulate a voltage of power supply from an input voltage of 12, 5, 3.3 or 2.5 volts as an output voltage of 3.3, 2.5, 1.8, 1.5, 1.35, 1.2, 1.0, 0.75 or 0.5 volts to be delivered to its FPGA IC chip 601, logic computing IC chips 269a, 269b and 269c, high-bandwidth-memory (HBM) IC chips 602 and FPGA/NVM multi-chip package 259; (5) an innovated application-specific-integrated-circuit (ASIC) or customer-owned tooling (COT) block, i.e., IAC block, configured to implement intellectual-property (IP) circuits, application-specific (AS) circuits, analog circuits, mixed-mode signal circuits, radio-frequency (RF) circuits, and/or transmitter, receiver, transceiver circuits for customers, each coupling to its FPGA IC chip 601, logic computing IC chips 269a, 269b and 269c, high-bandwidth-memory (HBM) IC chips 602 and FPGA/NVM multi-chip package 259 through the small input/output (SIO) circuits 203 of said each of its auxiliary IC chips 603; and (6) a hard-macro block for its FPGA IC chip 601 and (said any of) the FPGA IC chip(s) 200, 100i and/or 100j of its FPGA/NVM multi-chip package 259, wherein the hard-macro block of said each of its auxiliary IC chips 603 may include a digital-signal-processing (DSP) slice for multiplication or division, block random-access memory (RAM) cells for logic operation, central-processing unit (CPU) cores, intellectual property (IP) cores, floating-point calculator, machine-learning-processing (MLP) circuit, central-processing-unit (CPU) circuit, graphic-processing-unit (GPU) circuit, data-processing-unit (DPU) circuit, and/or application-processing-unit (APU) circuit, each coupling to its FPGA IC chip 601 and (said any of) the FPGA IC chip(s) 200, 100i and/or 100j of its FPGA/NVM multi-chip package 259 through the small input/output (SIO) circuits 203 of said each of its auxiliary IC chips 603, wherein the central-processing-unit (CPU) cores may be ARM Cortex processor/controller cores based on a reduced instruction set computing (RISC) architecture or x86 central-processing-unit (CPU) cores based on complex instruction set computing (CISC) architecture, wherein the ARM Cortex processor/controller cores may be 8-bit, 16-bit, 32-bit, 64-bit or more-than-64-bit reduced-instruction-set-computing (RISC) ARM processor/controller cores licensed from ARM Holdings. Alternatively, the hard-macro block of said each of its auxiliary IC chips 603 may further include a phase locked loop (PLL) circuit or digital clock manager (DCM) configured to generate a clock signal to its FPGA IC chip 601 and (said any of) the FPGA IC chip(s) 200, 100i and/or 100j of its FPGA/NVM multi-chip package 259. For the first type of FPMCP 300 for the third alternative, its CPU IC chip 269b, dedicated control and input/output (I/O) chip 260, FPGA IC chip 601, GPU IC chips 269a, HBM IC chips 602, application-specific integrated-circuit (ASIC) chip or system-on-chip (SoC) chip 269c and FPGA/NVM multi-chip package 259 may be arranged in an array within its center region, and its four auxiliary IC chips 603 may be arranged in its peripheral region surrounding its center region, wherein each of its four auxiliary IC chips 603 may be used as an input/output (I/O) or control chip. Each of its auxiliary IC chips 603 may be configured as an interface chip having a first interface with an external circuit of the first type of FPMCP 300 for the third alternative and a second interface with any another of its semiconductor IC chips 601, 260, 269a, 269b, 269c, 602 and 603 or its FPGA/NVM multi-chip package 259, wherein each of the first and second interfaces may be in accordance with an industry standard of Ethernet, PCIe, SATA, UCIe, USB, SerDes, Wi-Fi or Thunderbolt. Alternatively, each of its auxiliary IC chips 411 may be configured as a transceiver chip or central-processing-unit (CPU) coherent chip.

FIG. 5A-4 is a schematically top view showing a first type of FPMCP for a fourth alternative in accordance with an embodiment of the present application. For an element indicated by the same reference number shown in FIGS. 5A-3 and 5A-4, the specification of the element as seen in FIG. 5A-4 may be referred to that of the element as illustrated in FIG. 5A-3. The first type of FPMCP for the fourth alternative as seen in FIG. 5A-4 may have a similar structure to the first type of FPMCP for the third alternative as seen in FIG. 5A-3. The difference therebetween is that the right one of the high-bandwidth-memory (HBM) IC chips 602 of the first type of FPMCP for the third alternative as seen in FIG. 5A-3 may be replaced with another logic computing IC chip, such as digital-signal-processing (DSP) IC chip 270. For the first type of FPMCP for the fourth alternative as seen in FIG. 5A-4, its dedicated control and input/output (I/O) chip 260 may be an application-specific integrated-circuit (ASIC) chip or system-on-chip (SoC) IC chip and may be configured to control data transmission between any two of its FPGA IC chip 601, logic computing IC chips 269a, 269b, 269c and 270, high-bandwidth-memory (HBM) IC chip 602, auxiliary IC chips 603 and FPGA/NVM multi-chip package 259 and to control data transmission from one of its FPGA IC chip 601, logic computing IC chips 269a, 269b, 269c and 270, high-bandwidth-memory (HBM) IC chip 602, auxiliary IC chips 603 and FPGA/NVM multi-chip package 259 to a circuit external of the first type of FPMCP 300 for the fourth alternative. Further, for the first type of FPMCP 300 for the fourth alternative, its FPGA/NVM multi-chip package 259 may be the any type of the second through seventeenth types of FPMCPs 305-314, 314-1, 314-2, 314-3, 314-4, 314-5, 314-6, 314-7, 314-8, 315-320 and 461 as illustrated in FIGS. 10, 11, 12, 13A, 13B, 14, 15A, 15B, 16, 17, 18, 19, 19-1, 19-2, 19-3, 19-4, 19-5, 19-6, 19-7, 19-8, 19-9, 20, 21, 22, 23A, 23B, 24, 25A, 25B and 25C. Each of its auxiliary IC chips 603 may have the same circuits as the auxiliary IC chip 411 illustrated in FIGS. 5D-5G and may include the following functional blocks: (1) a large input/output (I/O) block configured for various input/output (I/O) formats, protocols or industry standards such as Ethernet, peripheral component interconnect express (PCIe), serial-advanced-technology-attachment (SATA), universal chiplet interconnect express (UCIe), universal serial bus (USB), serializer/deserializer (SerDes), Wi-Fi (wireless fidelity) or Thunderbolt, and with multiple large input/output (LIO) circuits 341 as seen in FIGS. 5D-5G, each having an I/O power efficiency greater than 3, 5 or 10 pico-Joules per bit, per switch or per voltage swing and/or having an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts, (2) a small-input/output (I/O) block having multiple small input/output (SIO) circuits configured to couple to its FPGA IC chip 601, logic computing IC chips 269a, 269b, 269c and 270, high bandwidth memory (HBM) IC chip 602 and FPGA/NVM multi-chip package 259 for data transmission therebetween, wherein each of the small I/O circuits of the small-input/output (I/O) block of said each of its auxiliary IC chips 603 may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts or 0.5 volts and/or a voltage swing equal to or smaller than 1.2 volts, 1 volt, 0.8 volts or 0.5 volts, for example; (3) a cryptography block configured to decrypt encrypted data transmitted from (said any of) the NVM IC chip(s) 250 of its FPGA/NVM multi-chip package 259 through the large or small input/output (LIO or SIO) circuits 341 or 203 of said each of its auxiliary IC chips 603 as decrypted data to be passed to its FPGA IC chip 601 and the FPGA IC chip(s) 200, 100i and/or 100j of its FPGA/NVM multi-chip package 259, its logic computing IC chips 269a, 269b, 269c and 270 and high bandwidth memory (HBM) IC chip 602 through the small input/output (SIO) circuits 203 of said each of its auxiliary IC chips 603 and to encrypt data transmitted from its FPGA IC chip 601 and the FPGA IC chip(s) 200, 100i and/or 100j of its FPGA/NVM multi-chip package 259, its logic computing IC chips 269a, 269b, 269c and 270 and its high bandwidth memory (HBM) IC chip 602 through the small input/output (SIO) circuits 203 of said each of its auxiliary IC chips 603 as encrypted data to be passed to (said any of) the NVM IC chip(s) 250 of its FPGA/NVM multi-chip package 259 through the large or small input/output (LIO or SIO) circuits 341 or 203 of said each of its auxiliary IC chips 603; (4) a regulating block for direct-current-to-direct-current (DC-to-DC) voltage conversion, voltage regulating, battery charging, power source selection, voltage scaling, and/or power sequencing, wherein the regulating block may be configured to regulate a voltage of power supply from an input voltage of 12, 5, 3.3 or 2.5 volts as an output voltage of 3.3, 2.5, 1.8, 1.5, 1.35, 1.2, 1.0, 0.75 or 0.5 volts to be delivered to its FPGA IC chip 601, logic computing IC chips 269a, 269b, 269c and 270, high-bandwidth-memory (HBM) IC chip 602 and FPGA/NVM multi-chip package 259; (5) an innovated application-specific-integrated-circuit (ASIC) or customer-owned tooling (COT) block, i.e., IAC block, configured to implement intellectual-property (IP) circuits, application-specific (AS) circuits, analog circuits, mixed-mode signal circuits, radio-frequency (RF) circuits, and/or transmitter, receiver, transceiver circuits for customers, each coupling to its FPGA IC chip 601, logic computing IC chips 269a, 269b, 269c and 270, high-bandwidth-memory (HBM) IC chip 602 and FPGA/NVM multi-chip package 259 through the small input/output (SIO) circuits 203 of said each of its auxiliary IC chips 603; and (6) a hard-macro block for its FPGA IC chip 601 and the FPGA IC chip(s) 200, 100i and/or 100j of its FPGA/NVM multi-chip package 259, wherein the hard-macro block of said each of its auxiliary IC chips 603 may include a digital-signal-processing (DSP) slice for multiplication or division, block random-access memory (RAM) cells for logic operation, central-processing unit (CPU) cores, intellectual property (IP) cores, floating-point calculator, machine-learning-processing (MLP) circuit, central-processing-unit (CPU) circuit, graphic-processing-unit (GPU) circuit, data-processing-unit (DPU) circuit, and/or application-processing-unit (APU) circuit, each coupling to its FPGA IC chip 601 and the FPGA IC chip(s) 200, 100i and/or 100j of its FPGA/NVM multi-chip package 259 through the small input/output (SIO) circuits 203 of said each of its auxiliary IC chips 603, wherein the central-processing-unit (CPU) cores may be ARM Cortex processor/controller cores based on a reduced instruction set computing (RISC) architecture or x86 central-processing-unit (CPU) cores based on complex instruction set computing (CISC) architecture, wherein the ARM Cortex processor/controller cores may be 8-bit, 16-bit, 32-bit, 64-bit or more-than-64-bit reduced-instruction-set-computing (RISC) ARM processor/controller cores licensed from ARM Holdings. Alternatively, the hard-macro block of said each of its auxiliary IC chips 603 may further include a phase locked loop (PLL) circuit or digital clock manager (DCM) configured to generate a clock signal to its FPGA IC chip 601 and the FPGA IC chip(s) 200, 100i and/or 100j of its FPGA/NVM multi-chip package 259. For the first type of FPMCP 300 for the fourth alternative, its CPU IC chip 269b, dedicated control and input/output (I/O) chip 260, FPGA IC chip 601, GPU IC chips 269a, HBM IC chip 602, application-specific integrated-circuit (ASIC) chip or system-on-chip (SoC) chip 269c, digital-signal-processing (DSP) IC chip 270 and FPGA/NVM multi-chip package 259 may be arranged in an array within its center region, and its four auxiliary IC chips 603 may be arranged in its peripheral region surrounding its center region, wherein each of its four auxiliary IC chips 603 may be used as an input/output (I/O) or control chip. Each of its auxiliary IC chips 603 may be configured as an interface chip having a first interface with an external circuit of the first type of FPMCP 300 for the fourth alternative and a second interface with any another of its semiconductor IC chips 601, 260, 269a, 269b, 269c, 270, 602 and 603 or its FPGA/NVM multi-chip package 259, wherein each of the first and second interfaces may be in accordance with an industry standard of Ethernet, PCIe, SATA, UCe, USB, SerDes, Wi-Fi or Thunderbolt. Alternatively, each of its auxiliary IC chips 411 may be configured as a transceiver chip or central-processing-unit (CPU) coherent chip.

FIG. 5A-5 is a schematically top view showing a first type of FPMCP for a fifth alternative in accordance with an embodiment of the present application. For an element indicated by the same reference number shown in FIGS. 5A-1 and 5A-5, the specification of the element as seen in FIG. 5A-5 may be referred to that of the element as illustrated in FIG. 5A-1. Referring to FIG. 5A-5, the first type of FPMCP 300 for the fifth alternative may be packaged with multiple semiconductor IC chips, including three FPGA IC chips 200, i.e., logic chips, in a single-die type, one NVM IC chip 250, one volatile memory (VM) IC chip 255, multiple logic computing IC chips, i.e., seven graphic-processing-unit (GPU) IC chips 269a, one central-processing-unit (CPU) IC chip 269b, and one application-specific integrated-circuit (ASIC) IC chip or system-on chip (SoC) 269c, two high bandwidth memory (HBM) IC chips 251, and four auxiliary IC chips 411, arranged in the same horizontal level. For the first type of FPMCP 300 for the third alternative, its FPGA IC chips 200, NVM IC chip 250, VM IC chip 255, logic computing IC chips 269a, 269b and 269c and high bandwidth memory (HBM) IC chips 251 may be arranged in an array within its center region; its auxiliary IC chips 411 may be arranged in its peripheral region surrounding its center region.

FIG. 5H shows a voltage-level shift-up circuit in accordance with an embodiment of the present application. FIG. 5I shows a voltage-level shift-down circuit in accordance with an embodiment of the present application. Referring to FIGS. 5A-1, 5A-2, 5A-3, 5A-4, 5A-5, 5H and 5I, for each of the first type of FPMCPs 300 for the first through fifth alternatives, each of its auxiliary IC chips 411 and/or 603 may further include a voltage-level shift block including multiple voltage-level shift (VLS) circuits 205, as seen in FIGS. 5D-5G, each coupling between one of the small input/output (SIO) circuits 203 of the small-input/output (I/O) block thereof and one of the large input/output (LIO) circuits 341 of the large-input/output (I/O) block thereof. Each of the voltage-level shift (VLS) circuits 205 of the voltage-level shift block of said each of its auxiliary IC chips 411 and/or 603 may include a voltage-level shift-up circuit 206, as seen in FIG. 5H, coupling between an input buffer 271 of one of the small input/output (SIO) circuits 203, as seen in FIGS. 5D-5G, of the small-input/output (I/O) block of said each of its auxiliary IC chips 411 and/or 603 and an output buffer 274 of one of the large input/output (LIO) circuits 341, as seen in FIGS. 5D-5G, of the large-input/output (I/O) block of said each of its auxiliary IC chips 411 and/or 603, and a voltage-level shift-down circuit 207, as seen in FIG. 5I, coupling between an input buffer 273 of said one of the large input/output (LIO) circuits 341 and an output buffer 272 of said one of the small input/output (SIO) circuits 203. In this case, referring to FIGS. 5A-1, 5A-2, 5A-5, 5H and 5I, each of the input and output buffers 271 and 272 of each of the small input/output (SIO) circuits 203 of the small-input/output (I/O) block of each of its auxiliary IC chips 411 and/or 603 may include two inverters, i.e., two-stage tri-state buffer, each having a P-type MOS transistor 293 and N-type MOS transistor 294 both having respective gate terminals coupling to each other, respective drain terminals coupling to each other and respective source terminals configured to couple to the voltage VddL of low-voltage power supply and to the voltage Vss of ground reference. Each of the input and output buffers 273 and 274 of each of the large input/output (LIO) circuits 341 of the large-input/output (I/O) block of each of its auxiliary IC chips 411 and/or 603 may include two inverters, i.e., two-stage tri-state buffer, each having a P-type MOS transistor 293 and N-type MOS transistor 294 both having respective gate terminals coupling to each other, respective drain terminals coupling to each other and respective source terminals configured to couple to the voltage VddH of high-voltage power supply and to the voltage Vss of ground reference. The voltage VddH of high-voltage power supply may be higher than the voltage VddL of low-voltage power supply, wherein the voltage VddH of high-voltage power supply may be equal to or higher than 0.7 volts, 1 volt, 1.2 volts, 1.5 volts or 2 volts and the voltage VddL of low-voltage power supply may be equal to or smaller than 1.2 volts, 1 volt, 0.8 volts, 0.7 volts or 0.5 volts. Accordingly, the voltage-level shift-up circuit 206 may shift data from the voltage VddL of low-voltage power supply at an input node thereof coupling to the input buffer 271 of said one of the small input/output (SIO) circuits 203 to the voltage VddH of high-voltage power supply at an output node thereof coupling to the output buffer 274 of said one of the large input/output (LIO) circuits 341; the voltage-level shift-down circuit 207 may shift data from the voltage VddH of high-voltage power supply at an input node thereof coupling to the input buffer 273 of said one of the large input/output (LIO) circuits 341 to the voltage VddL of low-voltage power supply at an output node thereof coupling to the output buffer 272 of said one of the small input/output (SIO) circuits 203.

For more elaboration, referring to FIGS. 5A-1, 5A-2, 5A-3, 5A-4, 5A-5 and 5D-5H, for each of the first type of FPMCPs 300 for the first through fifth alternatives, the gate terminals of the P-type MOS transistor 293 and N-type MOS transistor 294 of a first stage of the two invertors of each of the input buffers 271 of each of the small input/output (SIO) circuits 203 of the small-input/output (I/O) block of each of its auxiliary IC chips 411 and/or 603 may act as an input node of said each of the input buffers 271, the drain terminals of the P-type MOS transistor 293 and N-type MOS transistor 294 of the first stage of the two invertors of said each of the input buffers 271 may couple to the gate terminals of the P-type MOS transistor 293 and N-type MOS transistor 294 of a second stage of the two invertors of said each of the input buffers 271, and the drain terminals of the P-type MOS transistor 293 and N-type MOS transistor 294 of the second stage of the two invertors of said each of the input buffers 271 may act as an output node of said each of the input buffers 271 to couple to an input node of the voltage-level shift-up circuit 206 of one of the voltage-level shift (VLS) circuits 205 of the voltage-level shift block of said each of its auxiliary IC chips 411 and/or 603. Each of the two inverters of said each of the input buffers 271 is configured to invert a data input thereof at the gate terminals of the P-type MOS transistor 293 and N-type MOS transistor 294 thereof as a data output thereof at the drain terminals of the P-type MOS transistor 293 and N-type MOS transistor 294 thereof.

For more elaboration, referring to FIGS. 5A-1, 5A-2, 5A-3, 5A-4, 5A-5 and 5D-5H, for each of the first type of FPMCPs 300 for the first through fifth alternatives, the gate terminals of the P-type MOS transistor 293 and N-type MOS transistor 294 of a first stage of the two invertors of each of the output buffers 274 of each of the large input/output (LIO) circuits 341 of the large-input/output (I/O) block of each of its auxiliary IC chips 411 and/or 603 may couple to an output node of the voltage-level shift-up circuit 206 of one of the voltage-level shift (VLS) circuits 205 of the voltage-level shift block of said each of its auxiliary IC chips 411 and/or 603, the drain terminals of the P-type MOS transistor 293 and N-type MOS transistor 294 of the first stage of the two invertors of said each of the output buffers 274 may couple to the gate terminals of the P-type MOS transistor 293 and N-type MOS transistor 294 of a second stage of the two invertors of said each of the output buffers 274, and the drain terminals of the P-type MOS transistor 293 and N-type MOS transistor 294 of the second stage of the two invertors of said each of the output buffers 274 may act as an output node of said each of the output buffers 274. Each of the two inverters of said each of the output buffers 274 is configured to invert a data input thereof at the gate terminals of the P-type MOS transistor 293 and N-type MOS transistor 294 thereof as a data output thereof at the drain terminals of the P-type MOS transistor 293 and N-type MOS transistor 294 thereof.

For more elaboration, referring to FIGS. 5A-1, 5A-2, 5A-3, 5A-4, 5A-5, 5D-5G and 5I, for each of the first type of FPMCPs 300 for the first through fifth alternatives, the gate terminals of the P-type MOS transistor 293 and N-type MOS transistor 294 of a first stage of the two invertors of each of the input buffers 273 of each of the large input/output (LIO) circuits 341 of the large-input/output (I/O) block of each of its auxiliary IC chips 411 and/or 603 may act as an input node of said each of the input buffers 273, the drain terminals of the P-type MOS transistor 293 and N-type MOS transistor 294 of the first stage of the two invertors of said each of the input buffers 273 may couple to the gate terminals of the P-type MOS transistor 293 and N-type MOS transistor 294 of a second stage of the two invertors of said each of the input buffers 273, and the drain terminals of the P-type MOS transistor 293 and N-type MOS transistor 294 of the second stage of the two invertors of said each of the input buffers 273 may act as an output node of said each of the input buffers 273 to couple to an input node of the voltage-level shift-down circuit 207 of one of the voltage-level shift (VLS) circuits 205 of the voltage-level shift block of said each of its auxiliary IC chips 411 and/or 603. Each of the two inverters of said each of the input buffers 273 is configured to invert a data input thereof at the gate terminals of the P-type MOS transistor 293 and N-type MOS transistor 294 thereof as a data output thereof at the drain terminals of the P-type MOS transistor 293 and N-type MOS transistor 294 thereof.

For more elaboration, referring to FIGS. 5A-1, 5A-2, 5A-3, 5A-4, 5A-4, 5D-5G and 5I, for each of the first type of FPMCPs 300 for the first through fifth alternatives, the gate terminals of the P-type MOS transistor 293 and N-type MOS transistor 294 of a first stage of the two invertors of each of the output buffers 272 of each of the small input/output (SIO) circuits 203 of the small-input/output (I/O) block of each of its auxiliary IC chips 411 and/or 603 may act as an input node of said each of the output buffers 272 to couple to an output node of the voltage-level shift-down circuit 207 of one of the voltage-level shift (VLS) circuits 205 of the voltage-level shift block of said each of its auxiliary IC chips 411 and/or 603, the drain terminals of the P-type MOS transistor 293 and N-type MOS transistor 294 of the first stage of the two invertors of said each of the output buffers 272 may couple to the gate terminals of the P-type MOS transistor 293 and N-type MOS transistor 294 of a second stage of the two invertors of said each of the output buffers 272, and the drain terminals of the P-type MOS transistor 293 and N-type MOS transistor 294 of the second stage of the two invertors of said each of the output buffers 272 may act as an output node of said each of the output buffers 272. Each of the two inverters of said each of the output buffers 272 is configured to invert a data input thereof at the gate terminals of the P-type MOS transistor 293 and N-type MOS transistor 294 thereof as a data output thereof at the drain terminals of the P-type MOS transistor 293 and N-type MOS transistor 294 thereof.

Referring to FIG. 5H, for each of the first type of FPMCPs 300 for the first through fifth alternatives as seen in FIGS. 5A-1, 5A-2, 5A-3, 5A-4 and 5A-5, the voltage-level shift-up circuit 206 of each of the voltage-level shift (VLS) circuits 205, as seen in FIGS. 5D-5G, of the voltage-level shift block of each of its auxiliary IC chips 411 and/or 603 may include (1) two pairs of a P-type MOS transistor 393 and N-type MOS transistor 394 both having respective drain terminals coupling to each other and respective source terminals configured to couple to the voltage VddH of high-voltage power supply and to the voltage Vss of ground reference, wherein the P-type MOS transistor 393 in each pair of the two pairs may have a gate terminal coupling to the drain terminals of the P-type MOS transistor 393 and N-type MOS transistor 394 in the other pair of the two pairs, (2) an inverter 275 configured to invert a data input thereof at an input node thereof as a data output thereof at an output node thereof with the voltage VddL of power supply, and (3) an inverter 276 configured to invert a data input thereof at an input node thereof as a data output thereof at an output node thereof with the voltage VddH of power supply, wherein the input node of the inverter 275 of the voltage-level shift-up circuit 206 of said each of the voltage-level shift (VLS) circuits 205 may act as the input node of the voltage-level shift-up circuit 206 of said each of the voltage-level shift (VLS) circuits 205 to couple to the output node of the input buffer 271 of one of the small input/output (SIO) circuits 203 of the small-input/output (I/O) block of said each of its auxiliary IC chips 411 and/or 603 and may couple to the gate terminal of the N-type MOS transistor 394 in one pair of the two pairs, and the output node of the inverter 275 of the voltage-level shift-up circuit 206 of said each of the voltage-level shift (VLS) circuits 205 may couple to the gate terminal of the N-type MOS transistor 394 in the other pair of the two pairs, wherein the input node of the inverter 276 of the voltage-level shift-up circuit 206 of said each of the voltage-level shift (VLS) circuits 205 may couple to the drain terminals of the P-type MOS transistor 393 and N-type MOS transistor 394 in said one pair of the two pairs and the gate terminal of the P-type MOS transistor 393 in said the other pair of the two pairs, and the output node of the inverter 276 of the voltage-level shift-up circuit 206 of said each of the voltage-level shift (VLS) circuits 205 may act as the output node of the voltage-level shift-up circuit 206 of said each of the voltage-level shift (VLS) circuits 205 to couple to the input node of the output buffer 274 of one of the large input/output (LIO) circuits 341 of the large-input/output (I/O) block of said each of its auxiliary IC chips 411 and/or 603.

Referring to FIG. 5I, for each of the first type of FPMCPs 300 for the first through fifth alternatives as seen in FIGS. 5A-1, 5A-2, 5A-3, 5A-4 and 5A-5, the voltage-level shift-down circuit 207 of each of the voltage-level shift (VLS) circuits 205, as seen in FIGS. 5D-5G, of the voltage-level shift block of each of its auxiliary IC chips 411 and/or 603 may include two stages of a P-type MOS transistor 395 and N-type MOS transistor 396 both having respective gate terminals coupling to each other, respective drain terminals coupling to each other and respective source terminals configured to couple to the voltage VddL of low-voltage power supply and to the voltage Vss of ground reference, wherein the gate terminals of the P-type MOS transistor 395 and N-type MOS transistor 396 in a first stage of the two stages may act as the input node of the voltage-level shift-down circuit 207 of said each of the voltage-level shift (VLS) circuits 205, the drain terminals of the P-type MOS transistor 395 and N-type MOS transistor 396 in the first stage of the two stages may couple to the gate terminals of the P-type MOS transistor 395 and N-type MOS transistor 396 in a second stage of the two stages, and the drain terminals of the P-type MOS transistor 395 and N-type MOS transistor 396 in the second stage of the two stages may act as the output node of the voltage-level shift-down circuit 207 of said each of the voltage-level shift (VLS) circuits 205.

Referring to FIG. 5A-1, the first type of FPMCP 300 for the first alternative may include multiple inter-chip interconnects 371 each coupling two of its FPGA IC chips 200, NVM IC chip 250, logic computing IC chips 269a, 269b and 269c, high bandwidth memory (HBM) IC chips 251 and auxiliary IC chips 411, wherein the inter-chip interconnects 371 of the first type of FPMCP 300 for the first alternative may be divided into multiple programmable interconnects 361 allowed to be programmed or configured and multiple non-programmable interconnects 364 not allowed to be programmed or configured. Each of its FPGA IC chips 200 may include (1) the first type of field programmable logic cell or element (LCE) 2014 or 2014-2 as illustrated in FIGS. 1A, 4D and 4E, the data inputs A0 and A1 of which may couple to respective two of the programmable interconnects 361 of its inter-chip interconnects 371 through respective two of the small input/output (SIO) circuits 203, or metal pads or input/output (I/O) pads, of said each of its FPGA IC chips 200 and the data output Dout of which may couple to another of the programmable interconnects 361 of its inter-chip interconnects 371 through another of the small input/output (SIO) circuits 203, or metal pads or input/output (I/O) pads, of said each of its FPGA IC chips 200, wherein each of said two of the programmable interconnects 361 of its inter-chip interconnects 371 may couple to a circuit external to the first type of FPMCP 300 for the first alternative, the other of its FPGA IC chips 200 or one of its NVM IC chip 250, logic computing IC chips 269a, 269b and 269c, high bandwidth memory (HBM) IC chips 251 and auxiliary IC chips 411, and said another of the programmable interconnects 361 of its inter-chip interconnects 371 may couple to a circuit external to the first type of FPMCP 300 for the first alternative, the other of its FPGA IC chips 200 or another of its NVM IC chip 250, logic computing IC chips 269a, 269b and 269c, high bandwidth memory (HBM) IC chips 251 and auxiliary IC chips 411, for example, (2) the second or third type of field programmable logic cell or element (LCE) 2014 or 2014-2 as illustrated in FIGS. 1B, 1C, 4D and 4E, the data inputs A0-A3 of which may couple to respective four of the programmable interconnects 361 of its inter-chip interconnects 371 through respective four of the small input/output (SIO) circuits 203, or metal pads or input/output (I/O) pads, of said each of its FPGA IC chips 200 and the data output Dout of which may couple to another of the programmable interconnects 361 of its inter-chip interconnects 371 through another of the small input/output (SIO) circuits 203, or metal pads or input/output (I/O) pads, of said each of its FPGA IC chips 200, wherein each of said four of the programmable interconnects 361 of its inter-chip interconnects 371 may couple to a circuit external to the first type of FPMCP 300 for the first alternative, the other of its FPGA IC chips 200 or one of its NVM IC chip 250, logic computing IC chips 269a, 269b and 269c, high bandwidth memory (HBM) IC chips 251 and auxiliary IC chips 411, and said another of the programmable interconnects 361 of its inter-chip interconnects 371 may couple to a circuit external to the first type of FPMCP 300 for the first alternative, the other of its FPGA IC chips 200 or another of its NVM IC chip 250, logic computing IC chips 269a, 269b and 269c, high bandwidth memory (HBM) IC chips 251 and auxiliary IC chips 411, for example, (3) the first type of field programmable switch cell 379 or 379-2 as illustrated in FIGS. 2A, 4D and 4E, the two nodes N21 and N22 of which may couple to respective two of the programmable interconnects 361 of its inter-chip interconnects 371 through respective two of the small input/output (SIO) circuits 203, or metal pads or input/output (I/O) pads, of said each of its FPGA IC chips 200, to control coupling between said two of the programmable interconnects 361 of its inter-chip interconnects 371, wherein one of said two of the programmable interconnects 361 of its inter-chip interconnects 371 may couple to a circuit external to the first type of FPMCP 300 for the first alternative, another of its FPGA IC chips 200 or one of its NVM IC chip 250, logic computing IC chips 269a, 269b and 269c, high bandwidth memory (HBM) IC chips 251 and auxiliary IC chips 411, and the other of said two of the programmable interconnects 361 of its inter-chip interconnects 371 may couple to a circuit external to the first type of FPMCP 300 for the first alternative, the other of its FPGA IC chips 200 or another of its NVM IC chip 250, logic computing IC chips 269a, 269b and 269c, high bandwidth memory (HBM) IC chips 251 and auxiliary IC chips 411, for example, (4) the second type of field programmable switch cell 379 or 379-2 as illustrated in FIGS. 2B, 4D and 4E, the four nodes N23-N26 of which may couple to respective four of the programmable interconnects 361 of its inter-chip interconnects 371 through respective four of the small input/output (SIO) circuits 203, or metal pads or input/output (I/O) pads, of said each of its FPGA IC chips 200, to control coupling from one of said four of the programmable interconnects 361 of its inter-chip interconnects 371 to the other one or more of said four of the programmable interconnects 361 of its inter-chip interconnects 371, wherein said one of said four of the programmable interconnects 361 of its inter-chip interconnects 371 may couple to a circuit external to the first type of FPMCP 300 for the first alternative, another of its FPGA IC chips 200 or one of its NVM IC chip 250, logic computing IC chips 269a, 269b and 269c, high bandwidth memory (HBM) IC chips 251 and auxiliary IC chips 411, and said the other one or more of said four of the programmable interconnects 361 of its inter-chip interconnects 371 may couple to a circuit external to the first type of FPMCP 300 for the first alternative, the other of its FPGA IC chips 200 or another of its NVM IC chip 250, logic computing IC chips 269a, 269b and 269c, high bandwidth memory (HBM) IC chips 251 and auxiliary IC chips 411, for example, (5) the field programmable switch matrix 710 or 710-3 as illustrated in FIGS. 2C, 4D and 4E, each of the nodes P₁-P_{N} of which may couple to a first programmable interconnect of the programmable interconnects 361 of its inter-chip interconnects 371 through one of a first set of the small input/output (SIO) circuits 203, or metal pads or input/output (I/O) pads, of said each of its FPGA IC chips 200, each of the nodes Q₁-Q_{M} of which may couple to a second programmable interconnect of the programmable interconnects 361 of its inter-chip interconnects 371 through one of a second set of the small input/output (SIO) circuits 203, or metal pads or input/output (I/O) pads, of said each of its FPGA IC chips 200 and each of the pass/no-pass switches 778 of which may control coupling between one of the first programmable interconnects 361 of its inter-chip interconnects 371 and one of the second programmable interconnects 361 of its inter-chip interconnects 371, wherein said each of its FPGA IC chips 200 may have a set of first metal lines 281 arranged in a first direction and each coupling one of the first set of the small input/output (SIO) circuits 203, or metal pads or input/output (I/O) pads, of said each of its FPGA IC chips 200 to one of the nodes P₁-P_{N} of the field programmable switch matrix 710 or 710-3 of said each of its FPGA IC chips 200 and a set of second metal lines 282 arranged in a second direction and each coupling one of the second set of the small input/output (SIO) circuits 203, or metal pads or input/output (I/O) pads, of said each of its FPGA IC chips 200 to one of the nodes Q₁-Q_{M} of the field programmable switch matrix 710 or 710-3 of said each of its FPGA IC chips 200, wherein the first direction may be perpendicular to the second direction, wherein each of the first programmable interconnects 361 of its inter-chip interconnects 371 may couple to a circuit external to the first type of FPMCP 300 for the first alternative, the other of its FPGA IC chips 200 or one of its NVM IC chip 250, logic computing IC chips 269a, 269b and 269c, high bandwidth memory (HBM) IC chips 251 and auxiliary IC chips 411, and each of the second programmable interconnects 361 of its inter-chip interconnects 371 may couple to a circuit external to the first type of FPMCP 300 for the first alternative, the other of its FPGA IC chips 200 or another of its NVM IC chip 250, logic computing IC chips 269a, 269b and 269c, high bandwidth memory (HBM) IC chips 251 and auxiliary IC chips 411, for example, and/or (6) the field programmable switch matrix 710-2 as illustrated in FIGS. 2C and 4E, each of the nodes P₁-P_{N} of which may couple to one of the programmable interconnects 361 of its inter-chip interconnects 371 through one of the small input/output (SIO) circuits 203, or metal pads or input/output (I/O) pads, of said each of its FPGA IC chips 200 and each of the pass/no-pass switches 778 of which may control coupling between one of the programmable interconnects 361 of its inter-chip interconnects 371 and one of the internal circuits of the fourth one of the ASIC cores 215 of said each of its FPGA IC chips 200, wherein said each of its FPGA IC chips 200 may have a set of first metal lines 281 arranged in a first direction and each coupling one of the small input/output (SIO) circuits 203, or metal pads or input/output (I/O) pads, of said each of its FPGA IC chips 200 to one of the nodes P₁-P_{N} of the field programmable switch matrix 710-2 of said each of its FPGA IC chips 200 and a set of second metal lines 282 arranged in a second direction and each coupling one of the internal circuits of the fourth one of the ASIC cores 215 of said each of its FPGA IC chips 200 to one of the nodes Q₁-Q_{M} of the field programmable switch matrix 710-2 of said each of its FPGA IC chips 200, wherein the first direction may be perpendicular to the second direction, wherein each of the programmable interconnects 361 of its inter-chip interconnects 371 may couple to a circuit external to the first type of FPMCP 300 for the first alternative, the other of its FPGA IC chips 200 or one of its NVM IC chip 250, logic computing IC chips 269a, 269b and 269c, high bandwidth memory (HBM) IC chips 251 and auxiliary IC chips 411, for example. Data transmission may be built between one of the programmable interconnects 361 of its inter-chip interconnects 371 and one of the programmable interconnects 361 of any of its FPGA IC chips 200 via one of the small input/output (I/O) circuits (SIO) 203, or metal pads or input/output (I/O) pads, of said any of its FPGA IC chips 200, wherein said one of the small input/output (I/O) circuits (SIO) 203, or metal pads or input/output (I/O) pads, of said any of its FPGA IC chips 200 may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts or 0.5 volts and/or a voltage swing equal to or smaller than 1.2 volts, 1 volt, 0.8 volts or 0.5 volts, for example.

Referring to FIG. 5A-1, for the first type of FPMCP 300 for the first alternative, one or more of the programmable interconnects 361 of its inter-chip interconnects 371 may couple each of its FPGA IC chips 200 to its NVM IC chip 250. One or more of the programmable interconnects 361 of its inter-chip interconnects 371 may couple each of its FPGA IC chips 200 to all of its logic computing IC chips 269a, 269b and 269c. One or more of the programmable interconnects 361 of its inter-chip interconnects 371 may couple each of its FPGA IC chips 200 to either of its high bandwidth memory (HBM) IC chips 251 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple each of its FPGA IC chips 200 to all of its auxiliary IC chips 411. One or more of the programmable interconnects 361 of its inter-chip interconnects 371 may couple each of its FPGA IC chips 200 to the others of its FPGA IC chips 200. One or more of the programmable interconnects 361 of its inter-chip interconnects 371 may couple each of its graphic-processing-unit (GPU) IC chips 269a to its NVM IC chip 250. One or more of the programmable interconnects 361 of its inter-chip interconnects 371 may couple each of its graphic-processing-unit (GPU) IC chips 269a to its central-processing-unit (CPU) IC chip 269b. One or more of the programmable interconnects 361 of its inter-chip interconnects 371 may couple each of its graphic-processing-unit (GPU) IC chips 269a to its application-specific integrated-circuit (ASIC) chip or system-on-chip (SoC) chip 269c. One or more of the programmable interconnects 361 of its inter-chip interconnects 371 may couple each of its graphic-processing-unit (GPU) IC chips 269a to either of its high bandwidth memory (HBM) IC chips 251 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple each of its graphic-processing-unit (GPU) IC chips 269a to all of its auxiliary IC chips 411. One or more of the programmable interconnects 361 of its inter-chip interconnects 371 may couple each of its graphic-processing-unit (GPU) IC chips 269a to the others of its graphic-processing-unit (GPU) IC chips 269a. One or more of the programmable interconnects 361 of its inter-chip interconnects 371 may couple its central-processing-unit (CPU) IC chip 269b to its NVM IC chip 250. One or more of the programmable interconnects 361 of its inter-chip interconnects 371 may couple its central-processing-unit (CPU) IC chip 269b to its application-specific integrated-circuit (ASIC) chip or system-on-chip (SoC) chip 269c. One or more of the programmable interconnects 361 of its inter-chip interconnects 371 may couple its central-processing-unit (CPU) IC chip 269b to either of its high bandwidth memory (HBM) IC chips 251 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple its central-processing-unit (CPU) IC chip 269b to all of its auxiliary IC chips 411. One or more of the programmable interconnects 361 of its inter-chip interconnects 371 may couple its application-specific integrated-circuit (ASIC) IC chip or system-on-chip (SoC) chip 269c to its NVM IC chip 250. One or more of the programmable interconnects 361 of its inter-chip interconnects 371 may couple its application-specific integrated-circuit (ASIC) chip or system-on-chip (SoC) chip 269c to either of its high bandwidth memory (HBM) IC chips 251 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple its application-specific integrated-circuit (ASIC) chip or system-on-chip (SoC) chip 269c to all of its auxiliary IC chips 411. One or more of the programmable interconnects 361 of its inter-chip interconnects 371 may couple its NVM IC chip 250 to either of its high bandwidth memory (HBM) IC chips 251 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple its NVM IC chip 250 to all of its auxiliary IC chips 411. One or more of the programmable interconnects 361 of its inter-chip interconnects 371 may couple each of its high bandwidth memory (HBM) IC chips 251 to any of its auxiliary IC chips 411 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple its high bandwidth memory (HBM) IC chips 251 to each other for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple each of its auxiliary IC chips 411 to the others of its auxiliary IC chips 411. Each of its FPGA IC chips 200, graphic-processing-unit (GPU) IC chips 269a, central-processing-unit (CPU) IC chip 269b, application-specific integrated-circuit (ASIC) chip or system-on-chip (SoC) chip 269c, NVM IC chip 250, auxiliary IC chips 411 and high-bandwidth-memory (HBM) IC chips 251 may include the first, second or third type of field programmable logic cell or element (LCE) 2014 as illustrated in FIGS. 1A-1C, the first or second type of field programmable switch cell 379 as illustrated in FIGS. 2A and 2B and the field programmable switch matrix 710 as illustrated in FIG. 2C.

Referring to FIG. 5A-2, the first type of FPMCP 300 for the second alternative may include multiple inter-chip interconnects 371 each coupling two of its CPU IC chip 269b, DSP IC chip 270, dedicated control and input/output (I/O) chip 260, FPGA IC chips 200, GPU IC chips 269a, auxiliary IC chips 411, NVM IC chips 250, IAC chip 402, HBM IC chip 251 and first, second and third types of subsystem units 401, 403 and 404, wherein the inter-chip interconnects 371 of the standard commodity logic drive 300 for the second alternative may be divided into multiple programmable interconnects 361 allowed to be programmed or configured and multiple non-programmable interconnects 364 not allowed to be programmed or configured. The first type of FPMCP 300 for the second alternative may be further packaged with multiple dedicated programmable interconnection integrated-circuit (DPIIC) chips 410 each at corners of four of its CPU IC chip 269b, DSP IC chip 270, dedicated control and input/output (I/O) chip 260, FPGA IC chips 200, GPU IC chips 269a, auxiliary IC chips 411, NVM IC chips 250, IAC chip 402, HBM IC chip 251 and first, second and third types of subsystem units 401, 403 and 404. Each of its FPGA IC chips 200 and 201 may include (1) the first type of field programmable logic cell or element (LCE) 2014 or 2014-2 as illustrated in FIGS. 1A, 4D and 4E, the data inputs A0 and A1 of which may couple to respective two of the programmable interconnects 361 of its inter-chip interconnects 371 through respective two of the small input/output (SIO) circuits 203, or metal pads or input/output (I/O) pads, of said each of its FPGA IC chips 200 and 201 and the data output Dout of which may couple to another of the programmable interconnects 361 of its inter-chip interconnects 371 through another of the small input/output (SIO) circuits 203, or metal pads or input/output (I/O) pads, of said each of its FPGA IC chips 200 and 201, wherein each of said two of the programmable interconnects 361 of its inter-chip interconnects 371 may couple to a circuit external to the first type of FPMCP 300 for the second alternative, another of its FPGA IC chips 200 and 201 or one of its DPIIC chips 410, CPU IC chip 269b, DSP IC chip 270, dedicated control and input/output (I/O) chip 260, FPGA IC chips 200, GPU IC chips 269a, auxiliary IC chips 411, NVM IC chips 250, IAC chip 402, HBM IC chip 251 and first, second and third types of subsystem units 401, 403 and 404, and said another of the programmable interconnects 361 of its inter-chip interconnects 371 may couple to a circuit external to the first type of FPMCP 300 for the second alternative, another of its FPGA IC chips 200 and 201 or another of its DPIIC chips 410, CPU IC chip 269b, DSP IC chip 270, dedicated control and input/output (I/O) chip 260, FPGA IC chips 200, GPU IC chips 269a, auxiliary IC chips 411, NVM IC chips 250, IAC chip 402, HBM IC chip 251 and first, second and third types of subsystem units 401, 403 and 404, for example, and/or (2) the second or third type of field programmable logic cell or element (LCE) 2014 or 2014-2 as illustrated in FIGS. 1B, 1C, 4D and 4E, the data inputs A0-A3 of which may couple to respective four of the programmable interconnects 361 of its inter-chip interconnects 371 through respective four of the small input/output (SIO) circuits 203, or metal pads or input/output (I/O) pads, of said each of its FPGA IC chips 200 and the data output Dout of which may couple to another of the programmable interconnects 361 of its inter-chip interconnects 371 through another of the small input/output (SIO) circuits 203, or metal pads or input/output (I/O) pads, of said each of its FPGA IC chips 200, wherein each of said four of the programmable interconnects 361 of its inter-chip interconnects 371 may couple to a circuit external to the first type of FPMCP 300 for the second alternative, another of its FPGA IC chips 200 and 201 or one of its DPIIC chips 410, CPU IC chip 269b, DSP IC chip 270, dedicated control and input/output (I/O) chip 260, FPGA IC chips 200, GPU IC chips 269a, auxiliary IC chips 411, NVM IC chips 250, IAC chip 402, HBM IC chip 251 and first, second and third types of subsystem units 401, 403 and 404, and said another of the programmable interconnects 361 of its inter-chip interconnects 371 may couple to a circuit external to the first type of FPMCP 300 for the second alternative, still another of its FPGA IC chips 200 and 201 or another of its DPIIC chips 410, CPU IC chip 269b, DSP IC chip 270, dedicated control and input/output (I/O) chip 260, FPGA IC chips 200, GPU IC chips 269a, auxiliary IC chips 411, NVM IC chips 250, IAC chip 402, HBM IC chip 251 and first, second and third types of subsystem units 401, 403 and 404, for example. Each of its dedicated programmable interconnection integrated-circuit (DPIIC) chips 410 and FPGA IC chips 200 and 201 may include (1) the first type of field programmable switch cell 379 or 379-2 as illustrated in FIGS. 2A, 4D and 4E, the two nodes N21 and N22 of which may couple to respective two of the programmable interconnects 361 of its inter-chip interconnects 371 through respective two of the small input/output (SIO) circuits 203, or metal pads or input/output (I/O) pads, of said each of its DPIIC chips 410 and FPGA IC chips 200 and 201, to control coupling between said two of the programmable interconnects 361 of its inter-chip interconnects 371, wherein one of said two of the programmable interconnects 361 of its inter-chip interconnects 371 may couple to a circuit external to the first type of FPMCP 300 for the second alternative, another of its DPIIC chips 410 and FPGA IC chips 200 and 201 or one of its CPU IC chip 269b, DSP IC chip 270, dedicated control and input/output (I/O) chip 260, FPGA IC chips 200, GPU IC chips 269a, auxiliary IC chips 411, NVM IC chips 250, IAC chip 402, HBM IC chip 251 and first, second and third types of subsystem units 401, 403 and 404, and the other of said two of the programmable interconnects 361 of its inter-chip interconnects 371 may couple to a circuit external to the first type of FPMCP 300 for the second alternative, still another of its DPIIC chips 410 and FPGA IC chips 200 and 201 or another of its CPU IC chip 269b, DSP IC chip 270, dedicated control and input/output (I/O) chip 260, FPGA IC chips 200, GPU IC chips 269a, auxiliary IC chips 411, NVM IC chips 250, IAC chip 402, HBM IC chip 251 and first, second and third types of subsystem units 401, 403 and 404, for example, (2) the second type of field programmable switch cell 379 or 379-2 as illustrated in FIGS. 2B, 4D and 4E, the four nodes N23-N26 of which may couple to respective four of the programmable interconnects 361 of its inter-chip interconnects 371 through respective four of the small input/output (SIO) circuits 203, or metal pads or input/output (I/O) pads, of said each of its DPIIC chips 410 and FPGA IC chips 200 and 201, to control coupling from one of said four of the programmable interconnects 361 of its inter-chip interconnects 371 to the other one or more of said four of the programmable interconnects 361 of its inter-chip interconnects 371, wherein said one of said four of the programmable interconnects 361 of its inter-chip interconnects 371 may couple to a circuit external to the first type of FPMCP 300 for the second alternative, another of its DPIIC chips 410 and FPGA IC chips 200 and 201 or one of its CPU IC chip 269b, DSP IC chip 270, dedicated control and input/output (I/O) chip 260, FPGA IC chips 200, GPU IC chips 269a, auxiliary IC chips 411, NVM IC chips 250, IAC chip 402, HBM IC chip 251 and first, second and third types of subsystem units 401, 403 and 404, and said the other one or more of said four of the programmable interconnects 361 of its inter-chip interconnects 371 may couple to a circuit external to the first type of FPMCP 300 for the second alternative, still another of its DPIIC chips 410 and FPGA IC chips 200 and 201 or another of its CPU IC chip 269b, DSP IC chip 270, dedicated control and input/output (I/O) chip 260, FPGA IC chips 200, GPU IC chips 269a, auxiliary IC chips 411, NVM IC chips 250, IAC chip 402, HBM IC chip 251 and first, second and third types of subsystem units 401, 403 and 404, for example, (3) the field programmable switch matrix 710 or 710-3 as illustrated in FIGS. 2C, 4D and 4E, each of the nodes P₁-P_{N} of which may couple to a first programmable interconnect of the programmable interconnects 361 of its inter-chip interconnects 371 through one of a first set of the small input/output (SIO) circuits 203, or metal pads or input/output (I/O) pads, of said each of its DPIIC chips 410 and FPGA IC chips 200 and 201, each of the nodes Q₁-Q_{M} of which may couple to a second programmable interconnect of the programmable interconnects 361 of its inter-chip interconnects 371 through one of a second set of the small input/output (SIO) circuits 203, or metal pads or input/output (I/O) pads, of said each of its DPIIC chips 410 and FPGA IC chips 200 and 201 and each of the pass/no-pass switches 778 of which may control coupling between one of the first programmable interconnects 361 of its inter-chip interconnects 371 and one of the second programmable interconnects 361 of its inter-chip interconnects 371, wherein said each of its DPIIC chips 410 and FPGA IC chips 200 and 201 may have a set of first metal lines 281 arranged in a first direction and each coupling one of the first set of the small input/output (SIO) circuits 203, or metal pads or input/output (I/O) pads, of said each of its DPIIC chips 410 and FPGA IC chips 200 and 201 to one of the nodes P₁-P_{N} of the field programmable switch matrix 710 or 710-3 of said each of its DPIIC chips 410 and FPGA IC chips 200 and 201 and a set of second metal lines 282 arranged in a second direction and each coupling one of the second set of the small input/output (SIO) circuits 203, or metal pads or input/output (I/O) pads, of said each of its DPIIC chips 410 and FPGA IC chips 200 and 201 to one of the nodes Q₁-Q_{M} of the field programmable switch matrix 710 or 710-3 of said each of its DPIIC chips 410 and FPGA IC chips 200 and 201, wherein the first direction may be perpendicular to the second direction, wherein each of the first programmable interconnects 361 of its inter-chip interconnects 371 may couple to a circuit external to the first type of FPMCP 300 for the second alternative, another of its DPIIC chips 410 and FPGA IC chips 200 and 201 or one of its CPU IC chip 269b, DSP IC chip 270, dedicated control and input/output (I/O) chip 260, FPGA IC chips 200, GPU IC chips 269a, auxiliary IC chips 411, NVM IC chips 250, IAC chip 402, HBM IC chip 251 and first, second and third types of subsystem units 401, 403 and 404, and each of the second programmable interconnects 361 of its inter-chip interconnects 371 may couple to a circuit external to the first type of FPMCP 300 for the second alternative, still another of its DPIIC chips 410 and FPGA IC chips 200 and 201 or another of its CPU IC chip 269b, DSP IC chip 270, dedicated control and input/output (I/O) chip 260, FPGA IC chips 200, GPU IC chips 269a, auxiliary IC chips 411, NVM IC chips 250, IAC chip 402, HBM IC chip 251 and first, second and third types of subsystem units 401, 403 and 404, for example, and/or (4) the field programmable switch matrix 710-2 as illustrated in FIGS. 2C and 4E, each of the nodes P₁-P_{N} of which may couple to one of the programmable interconnects 361 of its inter-chip interconnects 371 through one of the small input/output (SIO) circuits 203, or metal pads or input/output (I/O) pads, of said each of its DPIIC chips 410 and FPGA IC chips 200 and 201 and each of the pass/no-pass switches 778 of which may control coupling between one of the programmable interconnects 361 of its inter-chip interconnects 371 and one of the internal circuits of the fourth one of the ASIC cores 215 of said each of its DPIIC chips 410 and FPGA IC chips 200 and 201, wherein said each of its DPIIC chips 410 and FPGA IC chips 200 and 201 may have a set of first metal lines 281 arranged in a first direction and each coupling one of the small input/output (SIO) circuits 203, or metal pads or input/output (I/O) pads, of said each of its DPIIC chips 410 and FPGA IC chips 200 and 201 to one of the nodes P₁-P_{N} of the field programmable switch matrix 710-2 of said each of its DPIIC chips 410 and FPGA IC chips 200 and 201 and a set of second metal lines 282 arranged in a second direction and each coupling one of the internal circuits of the fourth one of the ASIC cores 215 of said each of its DPIIC chips 410 and FPGA IC chips 200 and 201 to one of the nodes Q₁-Q_{M} of the field programmable switch matrix 710-2 of said each of its DPIIC chips 410 and FPGA IC chips 200 and 201, wherein the first direction may be perpendicular to the second direction, wherein each of the programmable interconnects 361 of its inter-chip interconnects 371 may couple to a circuit external to the first type of FPMCP 300 for the second alternative, another of its DPIIC chips 410 and FPGA IC chips 200 and 201 or one of its CPU IC chip 269b, DSP IC chip 270, dedicated control and input/output (I/O) chip 260, FPGA IC chips 200, GPU IC chips 269a, auxiliary IC chips 411, NVM IC chips 250, IAC chip 402, HBM IC chip 251 and first, second and third types of subsystem units 401, 403 and 404, for example. Data transmission may be built (1) between one of the programmable interconnects 361 of its inter-chip interconnects 371 and one of the programmable interconnects 361 of any of its FPGA IC chips 200 and 201 via one of the small input/output (I/O) circuits (SIO) 203, or metal pads or input/output (I/O) pads, of said any of its FPGA IC chips 200 and 201, wherein said one of the small input/output (I/O) circuits (SIO) 203, or metal pads or input/output (I/O) pads, of said any of its FPGA IC chips 200 and 201 may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts or 0.5 volts and/or a voltage swing equal to or smaller than 1.2 volts, 1 volt, 0.8 volts or 0.5 volts, for example, and (2) between one of the programmable interconnects 361 of its inter-chip interconnects 371 and one of the programmable interconnects 361 of any of its dedicated programmable interconnection integrated-circuit (DPIIC) chips 410 via one of the small input/output (I/O) circuits (SIO), or metal pads or input/output (I/O) pads, of said any of its dedicated programmable interconnection integrated-circuit (DPIIC) chips 410, wherein said one of the small input/output (I/O) circuits (SIO), or metal pads or input/output (I/O) pads, of said any of its dedicated programmable interconnection integrated-circuit (DPIIC) chips 410 may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts or 0.5 volts and/or a voltage swing equal to or smaller than 1.2 volts, 1 volt, 0.8 volts or 0.5 volts, for example. Alternatively, each of its dedicated programmable interconnection integrated-circuit (DPIIC) chips 410 may further include the first, second or third type of field programmable logic cell or element (LCE) 2014 as illustrated in FIGS. 1A-1C.

Referring to FIG. 5A-2, for the first type of FPMCP 300 for the second alternative, one or more of the programmable interconnects 361 of its inter-chip interconnects 371 may couple each of its FPGA IC chips 200 and 201 to all of its DPIIC chips 410. One or more of the programmable interconnects 361 of its inter-chip interconnects 371 may couple each of its FPGA IC chips 200 and 201 to its dedicated control and input/output (I/O) chip 260. One or more of the programmable interconnects 361 of its inter-chip interconnects 371 may couple each of its FPGA IC chips 200 and 201 to both of its NVM IC chips 250. One or more of the programmable interconnects 361 of its inter-chip interconnects 371 may couple each of its FPGA IC chips 200 and 201 to both of its GPU IC chips 269a. One or more of the programmable interconnects 361 of its inter-chip interconnects 371 may couple each of its FPGA IC chips 200 and 201 to its CPU IC chip 269b. One or more of the programmable interconnects 361 of its inter-chip interconnects 371 may couple each of its FPGA IC chips 200 and 201 to all of its auxiliary IC chips 411. One or more of the programmable interconnects 361 of its inter-chip interconnects 371 may couple each of its FPGA IC chips 200 and 201 to its DSP IC chip 270. One or more of the programmable interconnects 361 of its inter-chip interconnects 371 may couple each of its FPGA IC chips 200 and 201 to its HBM IC chip 251 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple each of its FPGA IC chips 200 and 201 to the others of its FPGA IC chips 200 and 201. One or more of the programmable interconnects 361 of its inter-chip interconnects 371 may couple each of its FPGA IC chips 200 and 201 to its IAC chip 402. One or more of the programmable interconnects 361 of its inter-chip interconnects 371 may couple each of its FPGA IC chips 200 to its first type of subsystem unit 401. One or more of the programmable interconnects 361 of its inter-chip interconnects 371 may couple each of its FPGA IC chips 200 to its second type of subsystem unit 403. One or more of the programmable interconnects 361 of its inter-chip interconnects 371 may couple each of its FPGA IC chips 200 to its third type of subsystem unit 404. One or more of the programmable interconnects 361 of its inter-chip interconnects 371 may couple each of its DPIIC chips 410 to its dedicated control and input/output (I/O) chip 260. One or more of the programmable interconnects 361 of its inter-chip interconnects 371 may couple each of its DPIIC chips 410 to both of its NVM IC chips 250. One or more of the programmable interconnects 361 of its inter-chip interconnects 371 may couple each of its DPIIC chips 410 or chiplets to both of its GPU IC chips 269a. One or more of the programmable interconnects 361 of its inter-chip interconnects 371 may couple each of its DPIIC chips 410 to its CPU IC chip or chiplet 269b. One or more of the programmable interconnects 361 of its inter-chip interconnects 371 may couple each of its DPIIC chips 410 to all of its auxiliary IC chips 411. One or more of the programmable interconnects 361 of its inter-chip interconnects 371 may couple each of its DPIIC chips 410 to its DSP IC chip 270. One or more of the programmable interconnects 361 of its inter-chip interconnects 371 may couple each of its DPIIC chips 410 to both of its HBM IC chips 251 and 252. One or more of the programmable interconnects 361 of its inter-chip interconnects 371 may couple each of its DPIIC chips 410 to the others of its DPIIC chips 410. One or more of the programmable interconnects 361 of its inter-chip interconnects 371 may couple each of its DPIIC chips 410 to its IAC chip 402. One or more of the programmable interconnects 361 of its inter-chip interconnects 371 may couple each of its DPIIC chips 410 to its first type of subsystem unit 401. One or more of the programmable interconnects 361 of its inter-chip interconnects 371 may couple each of its DPIIC chips 410 to its second type of subsystem unit 403. One or more of the programmable interconnects 361 of its inter-chip interconnects 371 may couple each of its DPIIC chips 410 to its third type of subsystem unit 404. One or more of the programmable interconnects 361 of its inter-chip interconnects 371 may couple its CPU IC chip 269b to both of its GPU IC chips 269a. One or more of the programmable interconnects 361 of its inter-chip interconnects 371 may couple its DSP IC chip 270 to both of its GPU IC chips 269a. One or more of the programmable interconnects 361 of its inter-chip interconnects 371 may couple its CPU IC chip 269b to both of its NVM IC chips 250. One or more of the programmable interconnects 361 of its inter-chip interconnects 371 may couple its DSP IC chip 270 to both of its NVM IC chips 250. One or more of the programmable interconnects 361 of its inter-chip interconnects 371 may couple its CPU IC chip 269b to its HBM IC chip 251 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple its DSP IC chip 270 to its HBM IC chip 251 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple its CPU IC chip 269b to its IAC chip 402. One or more of the programmable interconnects 361 of its inter-chip interconnects 371 may couple its CPU IC chip 269b to all of its auxiliary IC chips 411. One or more of the programmable interconnects 361 of its inter-chip interconnects 371 may couple its DSP IC chip 270 to its IAC chip 402. One or more of the programmable interconnects 361 of its inter-chip interconnects 371 may couple its DSP IC chip 270 to all of its auxiliary IC chips 411. One or more of the programmable interconnects 361 of its inter-chip interconnects 371 may couple its CPU IC chip 269b to its first type of subsystem unit 401. One or more of the programmable interconnects 361 of its inter-chip interconnects 371 may couple its DSP IC chip 270 to its first type of subsystem unit 401. One or more of the programmable interconnects 361 of its inter-chip interconnects 371 may couple its CPU IC chip 269b to its second type of subsystem unit 403. One or more of the programmable interconnects 361 of its inter-chip interconnects 371 may couple its DSP IC chip 270 to its second type of subsystem unit 403. One or more of the programmable interconnects 361 of its inter-chip interconnects 371 may couple its CPU IC chip 269b to its third type of subsystem unit 404. One or more of the programmable interconnects 361 of its inter-chip interconnects 371 may couple its DSP IC chip 270 to its third type of subsystem unit 404. One or more of the programmable interconnects 361 of its inter-chip interconnects 371 may couple its CPU IC chip 269b to its DSP IC chip 270. One or more of the programmable interconnects 361 of its inter-chip interconnects 371 may couple each of its GPU IC chips 269a to its HBM IC chip 251 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple each of its GPU IC chips 269a to both of its NVM IC chips 250. One or more of the programmable interconnects 361 of its inter-chip interconnects 371 may couple one of its GPU IC chips 269a to the other of its GPU IC chips 269a. One or more of the programmable interconnects 361 of its inter-chip interconnects 371 may couple each of its GPU IC chips 269a to its IAC chip 402. One or more of the programmable interconnects 361 of its inter-chip interconnects 371 may couple each of its GPU IC chips 269a to all of its auxiliary IC chips 411. One or more of the programmable interconnects 361 of its inter-chip interconnects 371 may couple each of its GPU IC chips 269a to its first type of subsystem unit 401. One or more of the programmable interconnects 361 of its inter-chip interconnects 371 may couple each of its GPU IC chips 269a to its second type of subsystem unit 403. One or more of the programmable interconnects 361 of its inter-chip interconnects 371 may couple each of its GPU IC chips 269a to its third type of subsystem unit 404. One or more of the programmable interconnects 361 of its inter-chip interconnects 371 may couple each of its NVM IC chips 250 to its dedicated control and input/output (I/O) chip 260. One or more of the programmable interconnects 361 of its inter-chip interconnects 371 may couple each of its HBM IC chips 251 and 252 to its dedicated control and input/output (I/O) chip 260. One or more of the programmable interconnects 361 of its inter-chip interconnects 371 may couple each of its GPU IC chips 269a to its dedicated control and input/output (I/O) chip 260. One or more of the programmable interconnects 361 of its inter-chip interconnects 371 may couple its CPU IC chip 269b to its dedicated control and input/output (I/O) chip 260. One or more of the programmable interconnects 361 of its inter-chip interconnects 371 may couple its DSP IC chip 270 to its dedicated control and input/output (I/O) chip 260. One or more of the programmable interconnects 361 of its inter-chip interconnects 371 may couple each of its auxiliary IC chips 411 to its dedicated control and input/output (I/O) chip 260. One or more of the programmable interconnects 361 of its inter-chip interconnects 371 may couple its first type of subsystem unit 401 to its dedicated control and input/output (I/O) chip 260. One or more of the programmable interconnects 361 of its inter-chip interconnects 371 may couple its second type of subsystem unit 403 to its dedicated control and input/output (I/O) chip 260 or chiplet. One or more of the programmable interconnects 361 of its inter-chip interconnects 371 may couple its third type of subsystem unit 404 to its dedicated control and input/output (I/O) chip 260 or chiplet. One or more of the programmable interconnects 361 of its inter-chip interconnects 371 may couple each of its NVM IC chips 250 to both of its HBM IC chips 251 and 252. One or more of the programmable interconnects 361 of its inter-chip interconnects 371 may couple each of its NVM IC chips 250 to its IAC chip 402. One or more of the programmable interconnects 361 of its inter-chip interconnects 371 may couple each of its NVM IC chips 250 to all of its auxiliary IC chips 411. One or more of the programmable interconnects 361 of its inter-chip interconnects 371 may couple each of its NVM IC chips 250 to its first type of subsystem unit 401. One or more of the programmable interconnects 361 of its inter-chip interconnects 371 may couple each of its NVM IC chips 250 to its second type of subsystem unit 403. One or more of the programmable interconnects 361 of its inter-chip interconnects 371 may couple each of its NVM IC chips 250 to its third type of subsystem unit 404. One or more of the programmable interconnects 361 of its inter-chip interconnects 371 may couple each of its HBM IC chips 251 and 252 to its IAC chip 402. One or more of the programmable interconnects 361 of its inter-chip interconnects 371 may couple each of its HBM IC chips 251 and 252 to all of its auxiliary IC chips 411. One or more of the programmable interconnects 361 of its inter-chip interconnects 371 may couple its HBM IC chip 251 to its first type of subsystem unit 401. One or more of the programmable interconnects 361 of its inter-chip interconnects 371 may couple each of its HBM IC chips 251 and 252 to its second type of subsystem unit 403. One or more of the programmable interconnects 361 of its inter-chip interconnects 371 may couple each of its HBM IC chips 251 and 252 to its third type of subsystem unit 404. One or more of the programmable interconnects 361 of its inter-chip interconnects 371 may couple its IAC chip 402 to all of its auxiliary IC chips 411. One or more of the programmable interconnects 361 of its inter-chip interconnects 371 may couple its IAC chip 402 to its first type of subsystem unit 401. One or more of the programmable interconnects 361 of its inter-chip interconnects 371 may couple its IAC chip 402 to its second type of subsystem unit 403. One or more of the programmable interconnects 361 of its inter-chip interconnects 371 may couple its IAC chip 402 to its third type of subsystem unit 404. One or more of the programmable interconnects 361 of its inter-chip interconnects 371 may couple its IAC chip 402 to its dedicated control and input/output (I/O) chip 260. One or more of the programmable interconnects 361 of its inter-chip interconnects 371 may couple each of its auxiliary IC chips 411 to its first type of subsystem unit 401. One or more of the programmable interconnects 361 of its inter-chip interconnects 371 may couple each of its auxiliary IC chips 411 to its second type of subsystem unit 403. One or more of the programmable interconnects 361 of its inter-chip interconnects 371 may couple one of its NVM IC chips 250 to the other of its NVM IC chips 250 or chiplets. One or more of the programmable interconnects 361 of its inter-chip interconnects 371 may couple its first type of subsystem unit 401 to its second type of subsystem unit 403. One or more of the programmable interconnects 361 of its inter-chip interconnects 371 may couple its first type of subsystem unit 401 to its third type of subsystem unit 404. One or more of the programmable interconnects 361 of its inter-chip interconnects 371 may couple its second type of subsystem unit 403 to its third type of subsystem unit 404. Each of its FPGA IC chips 200, graphic-processing-unit (GPU) IC chips 269a, central-processing-unit (CPU) IC chip 269b, NVM IC chips 250, auxiliary IC chips 411, high-bandwidth-memory (HBM) IC chips 251 and 252, control and input/output (I/O) chip 260 and IAC chip 402 may include the first, second or third type of field programmable logic cell or element (LCE) 2014 as illustrated in FIGS. 1A-1C, the first or second type of field programmable switch cell 379 as illustrated in FIGS. 2A and 2B and the field programmable switch matrix 710 as illustrated in FIG. 2C.

Referring to FIG. 5A-3, the first type of FPMCP 300 for the third alternative may include multiple inter-chip interconnects 371 each coupling two of its FPGA IC chip 601, logic computing IC chips 269a, 269b and 269c, high bandwidth memory (HBM) IC chips 602, dedicated control and input/output (I/O) chip 260, FPGA/NVM multi-chip package 259 and auxiliary IC chips 603, wherein the inter-chip interconnects 371 of the first type of FPMCP 300 for the third alternative may be divided into multiple programmable interconnects 361 allowed to be programmed or configured and multiple non-programmable interconnects 364 not allowed to be programmed or configured. Its FPGA IC chip 601 may include (1) the first type of field programmable logic cell or element (LCE) 2014 or 2014-2 as illustrated in FIGS. 1A, 4D and 4E, the data inputs A0 and A1 of which may couple to respective two of the programmable interconnects 361 of its inter-chip interconnects 371 through respective two of the small input/output (SIO) circuits 203, or metal pads or input/output (I/O) pads, of its FPGA IC chip 601 and the data output Dout of which may couple to another of the programmable interconnects 361 of its inter-chip interconnects 371 through another of the small input/output (SIO) circuits 203, or metal pads or input/output (I/O) pads, of its FPGA IC chip 601, wherein each of said two of the programmable interconnects 361 of its inter-chip interconnects 371 may couple to a circuit external to the first type of FPMCP 300 for the third alternative or one of its logic computing IC chips 269a, 269b and 269c, high bandwidth memory (HBM) IC chips 602, dedicated control and input/output (I/O) chip 260, FPGA/NVM multi-chip package 259 and auxiliary IC chips 603, and said another of the programmable interconnects 361 of its inter-chip interconnects 371 may couple to a circuit external to the first type of FPMCP 300 for the third alternative or another of its logic computing IC chips 269a, 269b and 269c, high bandwidth memory (HBM) IC chips 602, dedicated control and input/output (I/O) chip 260, FPGA/NVM multi-chip package 259 and auxiliary IC chips 603, for example, (2) the second or third type of field programmable logic cell or element (LCE) 2014 or 2014-2 as illustrated in FIGS. 1B, 1C, 4D and 4E, the data inputs A0-A3 of which may couple to respective four of the programmable interconnects 361 of its inter-chip interconnects 371 through respective four of the small input/output (SIO) circuits 203, or metal pads or input/output (I/O) pads, of its FPGA IC chip 601 and the data output Dout of which may couple to another of the programmable interconnects 361 of its inter-chip interconnects 371 through another of the small input/output (SIO) circuits 203, or metal pads or input/output (I/O) pads, of its FPGA IC chip 601, wherein each of said four of the programmable interconnects 361 of its inter-chip interconnects 371 may couple to a circuit external to the first type of FPMCP 300 for the third alternative or one of its logic computing IC chips 269a, 269b and 269c, high bandwidth memory (HBM) IC chips 602, dedicated control and input/output (I/O) chip 260, FPGA/NVM multi-chip package 259 and auxiliary IC chips 603, and said another of the programmable interconnects 361 of its inter-chip interconnects 371 may couple to a circuit external to the first type of FPMCP 300 for the first alternative or another of its logic computing IC chips 269a, 269b and 269c, high bandwidth memory (HBM) IC chips 602, dedicated control and input/output (I/O) chip 260, FPGA/NVM multi-chip package 259 and auxiliary IC chips 603, for example, (3) the first type of field programmable switch cell 379 or 379-2 as illustrated in FIGS. 2A, 4D and 4E, the two nodes N21 and N22 of which may couple to respective two of the programmable interconnects 361 of its inter-chip interconnects 371 through respective two of the small input/output (SIO) circuits 203, or metal pads or input/output (I/O) pads, of its FPGA IC chip 601, to control coupling between said two of the programmable interconnects 361 of its inter-chip interconnects 371, wherein one of said two of the programmable interconnects 361 of its inter-chip interconnects 371 may couple to a circuit external to the first type of FPMCP 300 for the third alternative or one of its logic computing IC chips 269a, 269b and 269c, high bandwidth memory (HBM) IC chips 602, dedicated control and input/output (I/O) chip 260, FPGA/NVM multi-chip package 259 and auxiliary IC chips 603 and the other of said two of the programmable interconnects 361 of its inter-chip interconnects 371 may couple to a circuit external to the first type of FPMCP 300 for the third alternative or another of its logic computing IC chips 269a, 269b and 269c, high bandwidth memory (HBM) IC chips 602, dedicated control and input/output (I/O) chip 260, FPGA/NVM multi-chip package 259 and auxiliary IC chips 603, for example, (4) the second type of field programmable switch cell 379 or 379-2 as illustrated in FIGS. 2B, 4D and 4E, the four nodes N23-N26 of which may couple to respective four of the programmable interconnects 361 of its inter-chip interconnects 371 through respective four of the small input/output (SIO) circuits 203, or metal pads or input/output (I/O) pads, of its FPGA IC chip 601, to control coupling from one of said four of the programmable interconnects 361 of its inter-chip interconnects 371 to the other one or more of said four of the programmable interconnects 361 of its inter-chip interconnects 371, wherein said one of said four of the programmable interconnects 361 of its inter-chip interconnects 371 may couple to a circuit external to the first type of FPMCP 300 for the third alternative or one of its logic computing IC chips 269a, 269b and 269c, high bandwidth memory (HBM) IC chips 602, dedicated control and input/output (I/O) chip 260, FPGA/NVM multi-chip package 259 and auxiliary IC chips 603 and said the other one or more of said four of the programmable interconnects 361 of its inter-chip interconnects 371 may couple to a circuit external to the first type of FPMCP 300 for the third alternative or another of its logic computing IC chips 269a, 269b and 269c, high bandwidth memory (HBM) IC chips 602, dedicated control and input/output (I/O) chip 260, FPGA/NVM multi-chip package 259 and auxiliary IC chips 603, for example, (5) the field programmable switch matrix 710 or 710-3 as illustrated in FIGS. 2C, 4D and 4E, each of the nodes P₁-P_{N} of which may couple to a first programmable interconnect of the programmable interconnects 361 of its inter-chip interconnects 371 through one of a first set of the small input/output (SIO) circuits 203, or metal pads or input/output (I/O) pads, of its FPGA IC chip 601, each of the nodes Q₁-Q_{M} of which may couple to a second programmable interconnect of the programmable interconnects 361 of its inter-chip interconnects 371 through one of a second set of the small input/output (SIO) circuits 203, or metal pads or input/output (I/O) pads, of its FPGA IC chip 601 and each of the pass/no-pass switches 778 of which may control coupling between one of the first programmable interconnects 361 of its inter-chip interconnects 371 and one of the second programmable interconnects 361 of its inter-chip interconnects 371, wherein its FPGA IC chip 601 may have a set of first metal lines 281 arranged in a first direction and each coupling one of the first set of the small input/output (SIO) circuits 203, or metal pads or input/output (I/O) pads, of its FPGA IC chip 601 to one of the nodes P₁-P_{N} of the field programmable switch matrix 710 or 710-3 of its FPGA IC chip 601 and a set of second metal lines 282 arranged in a second direction and each coupling one of the second set of the small input/output (SIO) circuits 203, or metal pads or input/output (I/O) pads, of its FPGA IC chip 601 to one of the nodes Q₁-Q_{M} of the field programmable switch matrix 710 or 710-3 of its FPGA IC chip 601, wherein the first direction may be perpendicular to the second direction, wherein each of the first programmable interconnects 361 of its inter-chip interconnects 371 may couple to a circuit external to the first type of FPMCP 300 for the third alternative or one of its logic computing IC chips 269a, 269b and 269c, high bandwidth memory (HBM) IC chips 602, dedicated control and input/output (I/O) chip 260, FPGA/NVM multi-chip package 259 and auxiliary IC chips 603 and each of the second programmable interconnects 361 of its inter-chip interconnects 371 may couple to a circuit external to the first type of FPMCP 300 for the third alternative or another of its logic computing IC chips 269a, 269b and 269c, high bandwidth memory (HBM) IC chips 602, dedicated control and input/output (I/O) chip 260, FPGA/NVM multi-chip package 259 and auxiliary IC chips 603, for example, and/or (6) the field programmable switch matrix 710-2 as illustrated in FIGS. 2C and 4E, each of the nodes P₁-P_{N} of which may couple to a programmable interconnect of the programmable interconnects 361 of its inter-chip interconnects 371 through one of a set of the small input/output (SIO) circuits 203, or metal pads or input/output (I/O) pads, of its FPGA IC chip 601 and each of the pass/no-pass switches 778 of which may control coupling between one of the programmable interconnects 361 of its inter-chip interconnects 371 and one of the internal circuits of the fourth one of the ASIC cores 215 of its FPGA IC chip 601, wherein its FPGA IC chip 601 may have a set of first metal lines 281 arranged in a first direction and each coupling one of the set of the small input/output (SIO) circuits 203, or metal pads or input/output (I/O) pads, of its FPGA IC chip 601 to one of the nodes P₁-P_{N} of the field programmable switch matrix 710-2 of its FPGA IC chip 601 and a set of second metal lines 282 arranged in a second direction and each coupling one of the internal circuits of the fourth one of the ASIC cores 215 of its FPGA IC chip 601 to one of the nodes Q₁-Q_{M} of the field programmable switch matrix 710-2 of its FPGA IC chip 601, wherein the first direction may be perpendicular to the second direction, wherein each of the programmable interconnects 361 of its inter-chip interconnects 371 may couple to a circuit external to the first type of FPMCP 300 for the third alternative or one of its logic computing IC chips 269a, 269b and 269c, high bandwidth memory (HBM) IC chips 602, dedicated control and input/output (I/O) chip 260, FPGA/NVM multi-chip package 259 and auxiliary IC chips 603, for example. Any of the FPGA IC chip(s) 200, 100i and/or 100j of its FPGA/NVM multi-chip package 259 may include (1) the first type of field programmable logic cell or element (LCE) 2014 or 2014-2 as illustrated in FIGS. 1A, 4D and 4E, the data inputs A0 and A1 of which may couple to respective two of the programmable interconnects 361 of its inter-chip interconnects 371 through, in sequence, respective two of the small input/output (SIO) circuits 203, or metal pads or input/output (I/O) pads, of said any of the FPGA IC chip(s) 200, 100i and/or 100j of its FPGA/NVM multi-chip package 259 and respective two of the metal bumps or contacts 574 of its FPGA/NVM multi-chip package 259 and the data output Dout of which may couple to another of the programmable interconnects 361 of its inter-chip interconnects 371 through, in sequence, another of the small input/output (SIO) circuits 203, or metal pads or input/output (I/O) pads, of said any of the FPGA IC chip(s) 200, 100i and/or 100j of its FPGA/NVM multi-chip package 259 and another of the metal bumps or contacts 574 of its FPGA/NVM multi-chip package 259, wherein each of said two of the programmable interconnects 361 of its inter-chip interconnects 371 may couple to a circuit external to the first type of FPMCP 300 for the third alternative or one of its FPGA IC chip 601, logic computing IC chips 269a, 269b and 269c, high bandwidth memory (HBM) IC chips 602, dedicated control and input/output (I/O) chip 260 and auxiliary IC chips 603, and said another of the programmable interconnects 361 of its inter-chip interconnects 371 may couple to a circuit external to the first type of FPMCP 300 for the third alternative or another of its FPGA IC chip 601, logic computing IC chips 269a, 269b and 269c, high bandwidth memory (HBM) IC chips 602, dedicated control and input/output (I/O) chip 260 and auxiliary IC chips 603, for example, (2) the second or third type of field programmable logic cell or element (LCE) 2014 or 2014-2 as illustrated in FIGS. 1B, 1C, 4D and 4E, the data inputs A0-A3 of which may couple to respective four of the programmable interconnects 361 of its inter-chip interconnects 371 through, in sequence, respective four of the small input/output (SIO) circuits 203, or metal pads or input/output (I/O) pads, of said any of the FPGA IC chip(s) 200, 100i and/or 100j of its FPGA/NVM multi-chip package 259 and respective four of the metal bumps or contacts 574 of its FPGA/NVM multi-chip package 259 and the data output Dout of which may couple to another of the programmable interconnects 361 of its inter-chip interconnects 371 through another of the small input/output (SIO) circuits 203, or metal pads or input/output (I/O) pads, of said any of the FPGA IC chip(s) 200, 100i and/or 100j of its FPGA/NVM multi-chip package 259 and another of the metal bumps or contacts 574 of its FPGA/NVM multi-chip package 259, wherein each of said four of the programmable interconnects 361 of its inter-chip interconnects 371 may couple to a circuit external to the first type of FPMCP 300 for the third alternative or one of its FPGA IC chip 601, logic computing IC chips 269a, 269b and 269c, high bandwidth memory (HBM) IC chips 602, dedicated control and input/output (I/O) chip 260 and auxiliary IC chips 603, and said another of the programmable interconnects 361 of its inter-chip interconnects 371 may couple to a circuit external to the first type of FPMCP 300 for the third alternative or another of its FPGA IC chip 601, logic computing IC chips 269a, 269b and 269c, high bandwidth memory (HBM) IC chips 602, dedicated control and input/output (I/O) chip 260 and auxiliary IC chips 603, for example, (3) the first type of field programmable switch cell 379 or 379-2 as illustrated in FIGS. 2A, 4D and 4E, the two nodes N21 and N22 of which may couple to respective two of the programmable interconnects 361 of its inter-chip interconnects 371 through, in sequence, respective two of the small input/output (SIO) circuits 203, or metal pads or input/output (I/O) pads, of said any of the FPGA IC chip(s) 200, 100i and/or 100j of its FPGA/NVM multi-chip package 259 and respective two of the metal bumps or contacts 574 of its FPGA/NVM multi-chip package 259, to control coupling between said two of the programmable interconnects 361 of its inter-chip interconnects 371, wherein one of said two of the programmable interconnects 361 of its inter-chip interconnects 371 may couple to a circuit external to the first type of FPMCP 300 for the third alternative or one of its FPGA IC chip 601, logic computing IC chips 269a, 269b and 269c, high bandwidth memory (HBM) IC chips 602, dedicated control and input/output (I/O) chip 260 and auxiliary IC chips 603, and the other of said two of the programmable interconnects 361 of its inter-chip interconnects 371 may couple to a circuit external to the first type of FPMCP 300 for the third alternative or another of its FPGA IC chip 601, logic computing IC chips 269a, 269b and 269c, high bandwidth memory (HBM) IC chips 602, dedicated control and input/output (I/O) chip 260 and auxiliary IC chips 603, for example, (4) the second type of field programmable switch cell 379 or 379-2 as illustrated in FIGS. 2B, 4D and 4E, the four nodes N23-N26 of which may couple to respective four of the programmable interconnects 361 of its inter-chip interconnects 371 through, in sequence, respective four of the small input/output (SIO) circuits 203, or metal pads or input/output (I/O) pads, of said any of the FPGA IC chip(s) 200, 100i and/or 100j of its FPGA/NVM multi-chip package 259 and respective four of the metal bumps or contacts 574 of its FPGA/NVM multi-chip package 259, to control coupling from one of said four of the programmable interconnects 361 of its inter-chip interconnects 371 to the other one or more of said four of the programmable interconnects 361 of its inter-chip interconnects 371, wherein said one of said four of the programmable interconnects 361 of its inter-chip interconnects 371 may couple to a circuit external to the first type of FPMCP 300 for the third alternative or one of its FPGA IC chip 601, logic computing IC chips 269a, 269b and 269c, high bandwidth memory (HBM) IC chips 602, dedicated control and input/output (I/O) chip 260 and auxiliary IC chips 603, and said the other one or more of said four of the programmable interconnects 361 of its inter-chip interconnects 371 may couple to a circuit external to the first type of FPMCP 300 for the third alternative or another of its FPGA IC chip 601, logic computing IC chips 269a, 269b and 269c, high bandwidth memory (HBM) IC chips 602, dedicated control and input/output (I/O) chip 260 and auxiliary IC chips 603, for example, (5) the field programmable switch matrix 710 or 710-3 as illustrated in FIGS. 2C, 4D and 4E, each of the nodes P₁-P_{N} which may couple to a first programmable interconnect of the programmable interconnects 361 of its inter-chip interconnects 371 through, in sequence, one of a first set of the small input/output (SIO) circuits 203, or metal pads or input/output (I/O) pads, of said any of the FPGA IC chip(s) 200, 100i and/or 100j of its FPGA/NVM multi-chip package 259 and one of a first set of the metal bumps or contacts 574 of its FPGA/NVM multi-chip package 259, each of the nodes Q₁-Q_{M} of which may couple to a second programmable interconnect of the programmable interconnects 361 of its inter-chip interconnects 371 through, in sequence, one of a second set of the small input/output (SIO) circuits 203, or metal pads or input/output (I/O) pads, of said any of the FPGA IC chip(s) 200, 100i and/or 100j of its FPGA/NVM multi-chip package 259 and one of a second set of the metal bumps or contacts 574 of its FPGA/NVM multi-chip package 259 and each of the pass/no-pass switches 778 of which may control coupling between one of the first programmable interconnects 361 of its inter-chip interconnects 371 and one of the second programmable interconnects 361 of its inter-chip interconnects 371, wherein said any of the FPGA IC chip(s) 200, 100i and/or 100j of its FPGA/NVM multi-chip package 259 may have a set of first metal lines 281 arranged in a first direction and each coupling one of the first set of the small input/output (SIO) circuits 203, or metal pads or input/output (I/O) pads, of said any of the FPGA IC chip(s) 200, 100i and/or 100j of its FPGA/NVM multi-chip package 259 to one of the nodes P₁-P_{N} of the field programmable switch matrix 710 or 710-3 of said any of the FPGA IC chip(s) 200, 100i and/or 100j of its FPGA/NVM multi-chip package 259 and a set of second metal lines 282 arranged in a second direction and each coupling one of the second set of the small input/output (SIO) circuits 203, or metal pads or input/output (I/O) pads, of said any of the FPGA IC chip(s) 200, 100i and/or 100j of its FPGA/NVM multi-chip package 259 to one of the nodes Q₁-Q_{M} of the field programmable switch matrix 710 or 710-3 of said any of the FPGA IC chip(s) 200, 100i and/or 100j of its FPGA/NVM multi-chip package 259, wherein the first direction may be perpendicular to the second direction, wherein each of the first programmable interconnects 361 of its inter-chip interconnects 371 may couple to a circuit external to the first type of FPMCP 300 for the third alternative or one of its FPGA IC chip 601, logic computing IC chips 269a, 269b and 269c, high bandwidth memory (HBM) IC chips 602, dedicated control and input/output (I/O) chip 260 and auxiliary IC chips 603, and each of the second programmable interconnects 361 of its inter-chip interconnects 371 may couple to a circuit external to the first type of FPMCP 300 for the third alternative or another of its FPGA IC chip 601, logic computing IC chips 269a, 269b and 269c, high bandwidth memory (HBM) IC chips 602, dedicated control and input/output (I/O) chip 260 and auxiliary IC chips 603, for example, and/or (6) the field programmable switch matrix 710-2 as illustrated in FIGS. 2C and 4E, each of the nodes P₁-P_{N} of which may couple to a programmable interconnect of the programmable interconnects 361 of its inter-chip interconnects 371 through, in sequence, one of the small input/output (SIO) circuits 203, or metal pads or input/output (I/O) pads, of said any of the FPGA IC chip(s) 200, 100i and/or 100j of its FPGA/NVM multi-chip package 259 and one of the metal bumps or contacts 574 of its FPGA/NVM multi-chip package 259 and each of the pass/no-pass switches 778 of which may control coupling between one of the programmable interconnects 361 of its inter-chip interconnects 371 and one of the internal circuits of the fourth one of the ASIC cores 215 of said any of the FPGA IC chip(s) 200, 100i and/or 100j of its FPGA/NVM multi-chip package 259, wherein said any of the FPGA IC chip(s) 200, 100i and/or 100j of its FPGA/NVM multi-chip package 259 may have a set of first metal lines 281 arranged in a first direction and each coupling one of the small input/output (SIO) circuits 203, or metal pads or input/output (I/O) pads, of said any of the FPGA IC chip(s) 200, 100i and/or 100j of its FPGA/NVM multi-chip package 259 to one of the nodes P₁-P_{N} of the field programmable switch matrix 710-2 of said any of the FPGA IC chip(s) 200, 100i and/or 100j of its FPGA/NVM multi-chip package 259 and a set of second metal lines 282 arranged in a second direction and each coupling one of the internal circuits of the fourth one of the ASIC cores 215 of said any of the FPGA IC chip(s) 200, 100i and/or 100j of its FPGA/NVM multi-chip package 259 to one of the nodes Q₁-Q_{M} of the field programmable switch matrix 710-2 of said any of the FPGA IC chip(s) 200, 100i and/or 100j of its FPGA/NVM multi-chip package 259, wherein the first direction may be perpendicular to the second direction, wherein each of the programmable interconnects 361 of its inter-chip interconnects 371 may couple to a circuit external to the first type of FPMCP 300 for the third alternative or one of its FPGA IC chip 601, logic computing IC chips 269a, 269b and 269c, high bandwidth memory (HBM) IC chips 602, dedicated control and input/output (I/O) chip 260 and auxiliary IC chips 603, for example. Data transmission may be built between one of the programmable interconnects 361 of its inter-chip interconnects 371 and one of the programmable interconnects 361 of its FPGA IC chip 601 via one of the small input/output (I/O) circuits of its FPGA IC chip 601, wherein said one of the small input/output (I/O) circuits of its FPGA IC chip 601 may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts or 0.5 volts and/or a voltage swing equal to or smaller than 1.2 volts, 1 volt, 0.8 volts or 0.5 volts, for example. For the first type of FPMCP 300 for the third alternative, one or more of the programmable interconnects 361 of its inter-chip interconnects 371 may couple its FPGA IC chip 601 to all of its logic computing IC chips 269a, 269b and 269c. One or more of the programmable interconnects 361 of its inter-chip interconnects 371 may couple its FPGA IC chip 601 to either of its high bandwidth memory (HBM) IC chips 602 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple its FPGA IC chip 601 to all of its auxiliary IC chips 603. One or more of the programmable interconnects 361 of its inter-chip interconnects 371 may couple its FPGA IC chip 601 to its dedicated control and input/output (I/O) chip 260. One or more of the programmable interconnects 361 of its inter-chip interconnects 371 may couple its FPGA IC chip 601 to its FPGA/NVM multi-chip package 259. One or more of the programmable interconnects 361 of its inter-chip interconnects 371 may couple each of its graphic-processing-unit (GPU) IC chips 269a to its central-processing-unit (CPU) IC chip 269b. One or more of the programmable interconnects 361 of its inter-chip interconnects 371 may couple each of its graphic-processing-unit (GPU) IC chips 269a to its application-specific integrated-circuit (ASIC) chip or system-on-chip (SoC) chip 269c. One or more of the programmable interconnects 361 of its inter-chip interconnects 371 may couple each of its graphic-processing-unit (GPU) IC chips 269a to either of its high bandwidth memory (HBM) IC chips 602 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple each of its graphic-processing-unit (GPU) IC chips 269a to all of its auxiliary IC chips 603. One or more of the programmable interconnects 361 of its inter-chip interconnects 371 may couple each of its graphic-processing-unit (GPU) IC chips 269a to its dedicated control and input/output (I/O) chip 260. One or more of the programmable interconnects 361 of its inter-chip interconnects 371 may couple each of its graphic-processing-unit (GPU) IC chips 269a to its FPGA/NVM multi-chip package 259. One or more of the programmable interconnects 361 of its inter-chip interconnects 371 may couple each of its graphic-processing-unit (GPU) IC chips 269a to the other of its graphic-processing-unit (GPU) IC chips 269a. One or more of the programmable interconnects 361 of its inter-chip interconnects 371 may couple its central-processing-unit (CPU) IC chip 269b to its application-specific integrated-circuit (ASIC) chip or system-on-chip (SoC) chip 269c. One or more of the programmable interconnects 361 of its inter-chip interconnects 371 may couple its central-processing-unit (CPU) IC chip 269b to either of its high bandwidth memory (HBM) IC chips 602 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple its central-processing-unit (CPU) IC chip 269b to all of its auxiliary IC chips 603. One or more of the programmable interconnects 361 of its inter-chip interconnects 371 may couple its central-processing-unit (CPU) IC chip 269b to its dedicated control and input/output (I/O) chip 260. One or more of the programmable interconnects 361 of its inter-chip interconnects 371 may couple its central-processing-unit (CPU) IC chip 269b to its FPGA/NVM multi-chip package 259. One or more of the programmable interconnects 361 of its inter-chip interconnects 371 may couple its application-specific integrated-circuit (ASIC) chip or system-on-chip (SoC) chip 269c to either of its high bandwidth memory (HBM) IC chips 602 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple its application-specific integrated-circuit (ASIC) chip or system-on-chip (SoC) chip 269c to all of its auxiliary IC chips 603. One or more of the programmable interconnects 361 of its inter-chip interconnects 371 may couple its application-specific integrated-circuit (ASIC) chip or system-on-chip (SoC) chip 269c to its dedicated control and input/output (I/O) chip 260. One or more of the programmable interconnects 361 of its inter-chip interconnects 371 may couple its application-specific integrated-circuit (ASIC) chip or system-on-chip (SoC) chip 269c to its FPGA/NVM multi-chip package 259. One or more of the programmable interconnects 361 of its inter-chip interconnects 371 may couple each of its high bandwidth memory (HBM) IC chips 602 to any of its auxiliary IC chips 603 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple its high bandwidth memory (HBM) IC chips 602 to each other for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple each of its high bandwidth memory (HBM) IC chips 602 to its dedicated control and input/output (I/O) chip 260 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple each of its high bandwidth memory (HBM) IC chips 602 to its FPGA/NVM multi-chip package 259 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple each of its auxiliary IC chips 603 to the others of its auxiliary IC chips 603. One or more of the programmable interconnects 361 of its inter-chip interconnects 371 may couple each of its auxiliary IC chips 603 to its dedicated control and input/output (I/O) chip 260. One or more of the programmable interconnects 361 of its inter-chip interconnects 371 may couple each of its auxiliary IC chips 603 to its FPGA/NVM multi-chip package 259. One or more of the programmable interconnects 361 of its inter-chip interconnects 371 may couple its dedicated control and input/output (I/O) chip 260 to its FPGA/NVM multi-chip package 259. Its FPGA IC chip 601, graphic-processing-unit (GPU) IC chips 269a, central-processing-unit (CPU) IC chip 269b, application-specific integrated-circuit (ASIC) chip or system-on-chip (SoC) chip 269c, dedicated control and input/output (I/O) chip 260, auxiliary IC chips 603 and high-bandwidth-memory (HBM) IC chips 602 may include the first, second or third type of field programmable logic cell or element (LCE) 2014 as illustrated in FIGS. 1A-1C and the first or second type of field programmable switch cell 379 as illustrated in FIGS. 2A and 2B and the field programmable switch matrix 710 as illustrated in FIG. 2C.

Referring to FIG. 5A-4, the first type of FPMCP 300 for the fourth alternative may include multiple inter-chip interconnects 371 each coupling two of its FPGA IC chip 601, logic computing IC chips 269a, 269b, 269c and 270, high bandwidth memory (HBM) IC chip 602, dedicated control and input/output (I/O) chip 260, FPGA/NVM multi-chip package 259 and auxiliary IC chips 603, wherein the inter-chip interconnects 371 of the first type of FPMCP 300 for the fourth alternative may be divided into multiple programmable interconnects 361 allowed to be programmed or configured and multiple non-programmable interconnects 364 not allowed to be programmed or configured. Its FPGA IC chip 601 may include (1) the first type of field programmable logic cell or element (LCE) 2014 or 2014-2 as illustrated in FIGS. 1A, 4D and 4E, the data inputs A0 and A1 of which may couple to respective two of the programmable interconnects 361 of its inter-chip interconnects 371 through respective two of the small input/output (SIO) circuits 203, or metal pads or input/output (I/O) pads, of its FPGA IC chip 601 and the data output Dout of which may couple to another of the programmable interconnects 361 of its inter-chip interconnects 371 through another of the small input/output (SIO) circuits 203, or metal pads or input/output (I/O) pads, of its FPGA IC chip 601, wherein each of said two of the programmable interconnects 361 of its inter-chip interconnects 371 may couple to a circuit external to the first type of FPMCP 300 for the fourth alternative or one of its logic computing IC chips 269a, 269b, 269c and 270, high bandwidth memory (HBM) IC chip 602, dedicated control and input/output (I/O) chip 260, FPGA/NVM multi-chip package 259 and auxiliary IC chips 603, and said another of the programmable interconnects 361 of its inter-chip interconnects 371 may couple to a circuit external to the first type of FPMCP 300 for the fourth alternative or another of its logic computing IC chips 269a, 269b, 269c and 270, high bandwidth memory (HBM) IC chip 602, dedicated control and input/output (I/O) chip 260, FPGA/NVM multi-chip package 259 and auxiliary IC chips 603, (2) the second or third type of field programmable logic cell or element (LCE) 2014 or 2014-2 as illustrated in FIGS. 1B, 1C, 4D and 4E, the data inputs A0-A3 of which may couple to respective four of the programmable interconnects 361 of its inter-chip interconnects 371 through respective four of the small input/output (SIO) circuits 203, or metal pads or input/output (I/O) pads, of its FPGA IC chip 601 and the data output Dout of which may couple to another of the programmable interconnects 361 of its inter-chip interconnects 371 through another of the small input/output (SIO) circuits 203, or metal pads or input/output (I/O) pads, of its FPGA IC chip 601, wherein each of said four of the programmable interconnects 361 of its inter-chip interconnects 371 may couple to a circuit external to the first type of FPMCP 300 for the fourth alternative or one of its logic computing IC chips 269a, 269b, 269c and 270, high bandwidth memory (HBM) IC chip 602, dedicated control and input/output (I/O) chip 260, FPGA/NVM multi-chip package 259 and auxiliary IC chips 603, and said another of the programmable interconnects 361 of its inter-chip interconnects 371 may couple to a circuit external to the first type of FPMCP 300 for the fourth alternative or another of its logic computing IC chips 269a, 269b, 269c and 270, high bandwidth memory (HBM) IC chip 602, dedicated control and input/output (I/O) chip 260, FPGA/NVM multi-chip package 259 and auxiliary IC chips 603, for example, (3) the first type of field programmable switch cell 379 or 379-2 as illustrated in FIGS. 2A, 4D and 4E, the two nodes N21 and N22 of which may couple to respective two of the programmable interconnects 361 of its inter-chip interconnects 371 through respective two of the small input/output (SIO) circuits 203, or metal pads or input/output (I/O) pads, of its FPGA IC chip 601, to control coupling between said two of the programmable interconnects 361 of its inter-chip interconnects 371, wherein one of said two of the programmable interconnects 361 of its inter-chip interconnects 371 may couple to a circuit external to the first type of FPMCP 300 for the fourth alternative or one of its logic computing IC chips 269a, 269b, 269c and 270, high bandwidth memory (HBM) IC chip 602, dedicated control and input/output (I/O) chip 260, FPGA/NVM multi-chip package 259 and auxiliary IC chips 603, and the other of said two of the programmable interconnects 361 of its inter-chip interconnects 371 may couple to a circuit external to the first type of FPMCP 300 for the fourth alternative or another of its logic computing IC chips 269a, 269b, 269c and 270, high bandwidth memory (HBM) IC chip 602, dedicated control and input/output (I/O) chip 260, FPGA/NVM multi-chip package 259 and auxiliary IC chips 603, for example, (4) the second type of field programmable switch cell 379 or 379-2 as illustrated in FIGS. 2B, 4D and 4E, the four nodes N23-N26 of which may couple to respective four of the programmable interconnects 361 of its inter-chip interconnects 371 through respective four of the small input/output (SIO) circuits 203, or metal pads or input/output (I/O) pads, of its FPGA IC chip 601, to control coupling from one of said four of the programmable interconnects 361 of its inter-chip interconnects 371 to the other one or more of said four of the programmable interconnects 361 of its inter-chip interconnects 371, wherein said one of said four of the programmable interconnects 361 of its inter-chip interconnects 371 may couple to a circuit external to the first type of FPMCP 300 for the fourth alternative or one of its logic computing IC chips 269a, 269b, 269c and 270, high bandwidth memory (HBM) IC chip 602, dedicated control and input/output (I/O) chip 260, FPGA/NVM multi-chip package 259 and auxiliary IC chips 603, and said the other one or more of said four of the programmable interconnects 361 of its inter-chip interconnects 371 may couple to a circuit external to the first type of FPMCP 300 for the fourth alternative or another of its logic computing IC chips 269a, 269b, 269c and 270, high bandwidth memory (HBM) IC chip 602, dedicated control and input/output (I/O) chip 260, FPGA/NVM multi-chip package 259 and auxiliary IC chips 603, for example, (5) the field programmable switch matrix 710 or 710-3 as illustrated in FIGS. 2C, 4D and 4E, each of the nodes P₁-P_{N} of which may couple to a first programmable interconnect of the programmable interconnects 361 of its inter-chip interconnects 371 through one of a first set of the small input/output (SIO) circuits 203, or metal pads or input/output (I/O) pads, of its FPGA IC chip 601, each of the nodes Q₁-Q_{M} of which may couple to a second programmable interconnect of the programmable interconnects 361 of its inter-chip interconnects 371 through one of a second set of the small input/output (SIO) circuits 203, or metal pads or input/output (I/O) pads, of its FPGA IC chip 601 and each of the pass/no-pass switches 778 of which may control coupling between one of the first programmable interconnects 361 of its inter-chip interconnects 371 and one of the second programmable interconnects 361 of its inter-chip interconnects 371, wherein its FPGA IC chip 601 may have a set of first metal lines 281 arranged in a first direction and each coupling one of the first set of the small input/output (SIO) circuits 203, or metal pads or input/output (I/O) pads, of its FPGA IC chip 601 to one of the nodes P₁-P_{N} of the field programmable switch matrix 710 or 710-3 of its FPGA IC chip 601 and a set of second metal lines 282 arranged in a second direction and each coupling one of the second set of the small input/output (SIO) circuits 203, or metal pads or input/output (I/O) pads, of its FPGA IC chip 601 to one of the nodes Q₁-Q_{M} of the field programmable switch matrix 710 or 710-3 of its FPGA IC chip 601, wherein the first direction may be perpendicular to the second direction, wherein each of the first programmable interconnects 361 of its inter-chip interconnects 371 may couple to a circuit external to the first type of FPMCP 300 for the fourth alternative or one of its logic computing IC chips 269a, 269b, 269c and 270, high bandwidth memory (HBM) IC chip 602, dedicated control and input/output (I/O) chip 260, FPGA/NVM multi-chip package 259 and auxiliary IC chips 603, and each of the second programmable interconnects 361 of its inter-chip interconnects 371 may couple to a circuit external to the first type of FPMCP 300 for the fourth alternative or another of its logic computing IC chips 269a, 269b, 269c and 270, high bandwidth memory (HBM) IC chip 602, dedicated control and input/output (I/O) chip 260, FPGA/NVM multi-chip package 259 and auxiliary IC chips 603, for example, and/or (6) the field programmable switch matrix 710-2 as illustrated in FIGS. 2C and 4E, each of the nodes P₁-P_{N} of which may couple to a programmable interconnect of the programmable interconnects 361 of its inter-chip interconnects 371 through one of a set of the small input/output (SIO) circuits 203, or metal pads or input/output (I/O) pads, of its FPGA IC chip 601 and each of the pass/no-pass switches 778 of which may control coupling between one of the programmable interconnects 361 of its inter-chip interconnects 371 and one of the internal circuits of the fourth one of the ASIC cores 215 of its FPGA IC chip 601, wherein its FPGA IC chip 601 may have a set of first metal lines 281 arranged in a first direction and each coupling one of the set of the small input/output (SIO) circuits 203, or metal pads or input/output (I/O) pads, of its FPGA IC chip 601 to one of the nodes P₁-P_{N} of the field programmable switch matrix 710-2 of its FPGA IC chip 601 and a set of second metal lines 282 arranged in a second direction and each coupling one of the internal circuits of the fourth one of the ASIC cores 215 of its FPGA IC chip 601 to one of the nodes Q₁-Q_{M} of the field programmable switch matrix 710-2 of its FPGA IC chip 601, wherein the first direction may be perpendicular to the second direction, wherein each of the programmable interconnects 361 of its inter-chip interconnects 371 may couple to a circuit external to the first type of FPMCP 300 for the fourth alternative or one of its logic computing IC chips 269a, 269b, 269c and 270, high bandwidth memory (HBM) IC chip 602, dedicated control and input/output (I/O) chip 260, FPGA/NVM multi-chip package 259 and auxiliary IC chips 603, for example. Any of the FPGA IC chip(s) 200, 100i and/or 100j of its FPGA/NVM multi-chip package 259 may include (1) the first type of field programmable logic cell or element (LCE) 2014 or 2014-2 as illustrated in FIGS. 1A, 4D and 4E, the data inputs A0 and A1 of which may couple to respective two of the programmable interconnects 361 of its inter-chip interconnects 371 through, in sequence, respective two of the small input/output (SIO) circuits 203, or metal pads or input/output (I/O) pads, of said any of the FPGA IC chip(s) 200, 100i and/or 100j of its FPGA/NVM multi-chip package 259 and respective two of the metal bumps or contacts 574 of its FPGA/NVM multi-chip package 259 and the data output Dout of which may couple to another of the programmable interconnects 361 of its inter-chip interconnects 371 through, in sequence, another of the small input/output (SIO) circuits 203, or metal pads or input/output (I/O) pads, of said any of the FPGA IC chip(s) 200, 100i and/or 100j of its FPGA/NVM multi-chip package 259 and another of the metal bumps or contacts 574 of its FPGA/NVM multi-chip package 259, wherein each of said two of the programmable interconnects 361 of its inter-chip interconnects 371 may couple to a circuit external to the first type of FPMCP 300 for the fourth alternative or one of its FPGA IC chip 601, logic computing IC chips 269a, 269b, 269c and 270, high bandwidth memory (HBM) IC chip 602, dedicated control and input/output (I/O) chip 260 and auxiliary IC chips 603, and said another of the programmable interconnects 361 of its inter-chip interconnects 371 may couple to a circuit external to the first type of FPMCP 300 for the fourth alternative or another of its FPGA IC chip 601, logic computing IC chips 269a, 269b, 269c and 270, high bandwidth memory (HBM) IC chip 602, dedicated control and input/output (I/O) chip 260 and auxiliary IC chips 603, for example, (2) the second or third type of field programmable logic cell or element (LCE) 2014 or 2014-2 as illustrated in FIGS. 1B, 1C, 4D and 4E, the data inputs A0-A3 of which may couple to respective four of the programmable interconnects 361 of its inter-chip interconnects 371 through, in sequence, respective four of the small input/output (SIO) circuits 203, or metal pads or input/output (I/O) pads, of said any of the FPGA IC chip(s) 200, 100i and/or 100j of its FPGA/NVM multi-chip package 259 and respective four of the metal bumps or contacts 574 of its FPGA/NVM multi-chip package 259 and the data output Dout of which may couple to another of the programmable interconnects 361 of its inter-chip interconnects 371 through another of the small input/output (SIO) circuits 203, or metal pads or input/output (I/O) pads, of said any of the FPGA IC chip(s) 200, 100i and/or 100j of its FPGA/NVM multi-chip package 259 and another of the metal bumps or contacts 574 of its FPGA/NVM multi-chip package 259, wherein each of said four of the programmable interconnects 361 of its inter-chip interconnects 371 may couple to a circuit external to the first type of FPMCP 300 for the fourth alternative or one of its FPGA IC chip 601, logic computing IC chips 269a, 269b, 269c and 270, high bandwidth memory (HBM) IC chip 602, dedicated control and input/output (I/O) chip 260 and auxiliary IC chips 603, and said another of the programmable interconnects 361 of its inter-chip interconnects 371 may couple to a circuit external to the first type of FPMCP 300 for the fourth alternative or another of its FPGA IC chip 601, logic computing IC chips 269a, 269b, 269c and 270, high bandwidth memory (HBM) IC chip 602, dedicated control and input/output (I/O) chip 260 and auxiliary IC chips 603, for example, (3) the first type of field programmable switch cell 379 or 379-2 as illustrated in FIGS. 2A, 4D and 4E, the two nodes N21 and N22 of which may couple to respective two of the programmable interconnects 361 of its inter-chip interconnects 371 through, in sequence, respective two of the small input/output (SIO) circuits 203, or metal pads or input/output (I/O) pads, of said any of the FPGA IC chip(s) 200, 100i and/or 100j of its FPGA/NVM multi-chip package 259 and respective two of the metal bumps or contacts 574 of its FPGA/NVM multi-chip package 259, to control coupling between said two of the programmable interconnects 361 of its inter-chip interconnects 371, wherein one of said two of the programmable interconnects 361 of its inter-chip interconnects 371 may couple to a circuit external to the first type of FPMCP 300 for the fourth alternative or one of its FPGA IC chip 601, logic computing IC chips 269a, 269b, 269c and 270, high bandwidth memory (HBM) IC chip 602, dedicated control and input/output (I/O) chip 260 and auxiliary IC chips 603, and the other of said two of the programmable interconnects 361 of its inter-chip interconnects 371 may couple to a circuit external to the first type of FPMCP 300 for the fourth alternative or another of its FPGA IC chip 601, logic computing IC chips 269a, 269b, 269c and 270, high bandwidth memory (HBM) IC chip 602, dedicated control and input/output (I/O) chip 260 and auxiliary IC chips 603, for example, (4) the second type of field programmable switch cell 379 or 379-2 as illustrated in FIGS. 2B, 4D and 4E, the four nodes N23-N26 of which may couple to respective four of the programmable interconnects 361 of its inter-chip interconnects 371 through, in sequence, respective four of the small input/output (SIO) circuits 203, or metal pads or input/output (I/O) pads, of said any of the FPGA IC chip(s) 200, 100i and/or 100j of its FPGA/NVM multi-chip package 259 and respective four of the metal bumps or contacts 574 of its FPGA/NVM multi-chip package 259, to control coupling from one of said four of the programmable interconnects of its inter-chip interconnects 371 to the other one or more of said four of the programmable interconnects 361 of its inter-chip interconnects 371, wherein said one of said four of the programmable interconnects 361 of its inter-chip interconnects 371 may couple to a circuit external to the first type of FPMCP 300 for the fourth alternative or one of its FPGA IC chip 601, logic computing IC chips 269a, 269b, 269c and 270, high bandwidth memory (HBM) IC chip 602, dedicated control and input/output (I/O) chip 260 and auxiliary IC chips 603, and said the other one or more of said four of the programmable interconnects 361 of its inter-chip interconnects 371 may couple to a circuit external to the first type of FPMCP 300 for the third alternative or another of its FPGA IC chip 601, logic computing IC chips 269a, 269b, 269c and 270, high bandwidth memory (HBM) IC chip 602, dedicated control and input/output (I/O) chip 260 and auxiliary IC chips 603, for example, (5) the field programmable switch matrix 710 or 710-3 as illustrated in FIGS. 2C, 4D and 4E, each of the nodes P₁-P_{N} of which may couple to a first programmable interconnect of the programmable interconnects 361 of its inter-chip interconnects 371 through, in sequence, one of a first set of the small input/output (SIO) circuits 203, or metal pads or input/output (I/O) pads, of said any of the FPGA IC chip(s) 200, 100i and/or 100j of its FPGA/NVM multi-chip package 259 and one of a first set of the metal bumps or contacts 574 of its FPGA/NVM multi-chip package 259, each of the nodes Q₁-Q_{M} of which may couple to a second programmable interconnect of the programmable interconnects 361 of its inter-chip interconnects 371 through, in sequence, one of a second set of the small input/output (SIO) circuits 203, or metal pads or input/output (I/O) pads, of said any of the FPGA IC chip(s) 200, 100i and/or 100j of its FPGA/NVM multi-chip package 259 and one of a second set of the metal bumps or contacts 574 of its FPGA/NVM multi-chip package 259 and each of the pass/no-pass switches 778 of which may control coupling between one of the first programmable interconnect of its inter-chip interconnects 371 and one of the second programmable interconnects 361 of its inter-chip interconnects 371, wherein said any of the FPGA IC chip(s) 200, 100i and/or 100j may have a set of first metal lines 281 arranged in a first direction and each coupling one of the first set of the small input/output (SIO) circuits 203, or metal pads or input/output (I/O) pads, of said any of the FPGA IC chip(s) 200, 100i and/or 100j of its FPGA/NVM multi-chip package 259 to one of the nodes P₁-P_{N} of the field programmable switch matrix 710 of said any of the FPGA IC chip(s) 200, 100i and/or 100j of its FPGA/NVM multi-chip package 259 and a set of second metal lines 282 arranged in a second direction and each coupling one of the second set of the small input/output (SIO) circuits 203, or metal pads or input/output (I/O) pads, of said any of the FPGA IC chip(s) 200, 100i and/or 100j of its FPGA/NVM multi-chip package 259 to one of the nodes Q₁-Q_{M} of the field programmable switch matrix 710 of said any of the FPGA IC chip(s) 200, 100i and/or 100j of its FPGA/NVM multi-chip package 259, wherein the first direction may be perpendicular to the second direction, wherein each of the first programmable interconnects 361 of its inter-chip interconnects 371 may couple to a circuit external to the first type of FPMCP 300 for the fourth alternative or one of its FPGA IC chip 601, logic computing IC chips 269a, 269b, 269c and 270, high bandwidth memory (HBM) IC chip 602, dedicated control and input/output (I/O) chip 260 and auxiliary IC chips 603, and each of the second programmable interconnects 361 of its inter-chip interconnects 371 may couple to a circuit external to the first type of FPMCP 300 for the fourth alternative or another of its FPGA IC chip 601, logic computing IC chips 269a, 269b, 269c and 270, high bandwidth memory (HBM) IC chip 602, dedicated control and input/output (I/O) chip 260 and auxiliary IC chips 603, for example, and/or (6) the field programmable switch matrix 710-2 as illustrated in FIGS. 2C and 4E, each of the nodes P₁-P_{N} of which may couple to a programmable interconnect of the programmable interconnects 361 of its inter-chip interconnects 371 through, in sequence, one of the small input/output (SIO) circuits 203, or metal pads or input/output (I/O) pads, of said any of the FPGA IC chip(s) 200, 100i and/or 100j of its FPGA/NVM multi-chip package 259 and one of the metal bumps or contacts 574 of its FPGA/NVM multi-chip package 259 and each of the pass/no-pass switches 778 of which may control coupling between one of the programmable interconnects 361 of its inter-chip interconnects 371 and one of the internal circuits of the fourth one of the ASIC cores 215 of said any of the FPGA IC chip(s) 200, 100i and/or 100j of its FPGA/NVM multi-chip package 259, wherein said any of the FPGA IC chip(s) 200, 100i and/or 100j of its FPGA/NVM multi-chip package 259 may have a set of first metal lines 281 arranged in a first direction and each coupling one of the small input/output (SIO) circuits 203, or metal pads or input/output (I/O) pads, of said any of the FPGA IC chip(s) 200, 100i and/or 100j of its FPGA/NVM multi-chip package 259 to one of the nodes P₁-P_{N} of the field programmable switch matrix 710-2 of said any of the FPGA IC chip(s) 200, 100i and/or 100j of its FPGA/NVM multi-chip package 259 and a set of second metal lines 282 arranged in a second direction and each coupling one of the internal circuits of the fourth one of the ASIC cores 215 of said any of the FPGA IC chip(s) 200, 100i and/or 100j of its FPGA/NVM multi-chip package 259 to one of the nodes Q₁-Q_{M} of the field programmable switch matrix 710-2 of said any of the FPGA IC chip(s) 200, 100i and/or 100j of its FPGA/NVM multi-chip package 259, wherein the first direction may be perpendicular to the second direction, wherein each of the programmable interconnects 361 of its inter-chip interconnects 371 may couple to a circuit external to the first type of FPMCP 300 for the fourth alternative or one of its FPGA IC chip 601, logic computing IC chips 269a, 269b, 269c and 270, high bandwidth memory (HBM) IC chip 602, dedicated control and input/output (I/O) chip 260 and auxiliary IC chips 603, for example. Data transmission may be built between one of the programmable interconnects 361 of its inter-chip interconnects 371 and one of the programmable interconnects 361 of its FPGA IC chip 601 via one of the small input/output (I/O) circuits of its FPGA IC chip 601, wherein said one of the small input/output (I/O) circuits of its FPGA IC chip 601 may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts or 0.5 volts and/or a voltage swing equal to or smaller than 1.2 volts, 1 volt, 0.8 volts or 0.5 volts, for example. For the first type of FPMCP 300 for the fourth alternative, one or more of the programmable interconnects 361 of its inter-chip interconnects 371 may couple its FPGA IC chip 601 to all of its logic computing IC chips 269a, 269b, 269c and 270. One or more of the programmable interconnects 361 of its inter-chip interconnects 371 may couple its FPGA IC chip 601 to its high bandwidth memory (HBM) IC chip 602 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple its FPGA IC chip 601 to all of its auxiliary IC chips 603. One or more of the programmable interconnects 361 of its inter-chip interconnects 371 may couple its FPGA IC chip 601 to its dedicated control and input/output (I/O) chip 260. One or more of the programmable interconnects 361 of its inter-chip interconnects 371 may couple its FPGA IC chip 601 to its FPGA/NVM multi-chip package 259. One or more of the programmable interconnects 361 of its inter-chip interconnects 371 may couple each of its graphic-processing-unit (GPU) IC chips 269a to its central-processing-unit (CPU) IC chip 269b. One or more of the programmable interconnects 361 of its inter-chip interconnects 371 may couple each of its graphic-processing-unit (GPU) IC chips 269a to its application-specific integrated-circuit (ASIC) chip or system-on-chip (SoC) chip 269c. One or more of the programmable interconnects 361 of its inter-chip interconnects 371 may couple each of its graphic-processing-unit (GPU) IC chips 269a to its digital-signal-processing (DSP) IC chip 270. One or more of the programmable interconnects 361 of its inter-chip interconnects 371 may couple each of its graphic-processing-unit (GPU) IC chips 269a to its high bandwidth memory (HBM) IC chip 602 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple each of its graphic-processing-unit (GPU) IC chips 269a to all of its auxiliary IC chips 603. One or more of the programmable interconnects 361 of its inter-chip interconnects 371 may couple each of its graphic-processing-unit (GPU) IC chips 269a to its dedicated control and input/output (I/O) chip 260. One or more of the programmable interconnects 361 of its inter-chip interconnects 371 may couple each of its graphic-processing-unit (GPU) IC chips 269a to its FPGA/NVM multi-chip package 259. One or more of the programmable interconnects 361 of its inter-chip interconnects 371 may couple each of its graphic-processing-unit (GPU) IC chips 269a to the other of its graphic-processing-unit (GPU) IC chips 269a. One or more of the programmable interconnects 361 of its inter-chip interconnects 371 may couple its central-processing-unit (CPU) IC chip 269b to its application-specific integrated-circuit (ASIC) chip or system-on-chip (SoC) chip 269c. One or more of the programmable interconnects 361 of its inter-chip interconnects 371 may couple its central-processing-unit (CPU) IC chip 269b to its digital-signal-processing (DSP) IC chip 270. One or more of the programmable interconnects 361 of its inter-chip interconnects 371 may couple its central-processing-unit (CPU) IC chip 269b to its high bandwidth memory (HBM) IC chip 602 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple its central-processing-unit (CPU) IC chip 269b to all of its auxiliary IC chips 603. One or more of the programmable interconnects 361 of its inter-chip interconnects 371 may couple its central-processing-unit (CPU) IC chip 269b to its dedicated control and input/output (I/O) chip 260. One or more of the programmable interconnects 361 of its inter-chip interconnects 371 may couple its central-processing-unit (CPU) IC chip 269b to its FPGA/NVM multi-chip package 259. One or more of the programmable interconnects 361 of its inter-chip interconnects 371 may couple its application-specific integrated-circuit (ASIC) chip or system-on-chip (SoC) chip 269c to its digital-signal-processing (DSP) IC chip 270. One or more of the programmable interconnects 361 of its inter-chip interconnects 371 may couple its application-specific integrated-circuit (ASIC) chip or system-on-chip (SoC) chip 269c to its high bandwidth memory (HBM) IC chip 602 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple its application-specific integrated-circuit (ASIC) chip or system-on-chip (SoC) chip 269c to all of its auxiliary IC chips 603. One or more of the programmable interconnects 361 of its inter-chip interconnects 371 may couple its application-specific integrated-circuit (ASIC) chip or system-on-chip (SoC) chip 269c to its dedicated control and input/output (I/O) chip 260. One or more of the programmable interconnects 361 of its inter-chip interconnects 371 may couple its application-specific integrated-circuit (ASIC) chip or system-on-chip (SoC) chip 269c to its FPGA/NVM multi-chip package 259. One or more of the programmable interconnects 361 of its inter-chip interconnects 371 may couple its digital-signal-processing (DSP) IC chip 270 to its high bandwidth memory (HBM) IC chip 602 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple its digital-signal-processing (DSP) IC chip 270 to all of its auxiliary IC chips 603. One or more of the programmable interconnects 361 of its inter-chip interconnects 371 may couple its digital-signal-processing (DSP) IC chip 270 to its dedicated control and input/output (I/O) chip 260. One or more of the programmable interconnects 361 of its inter-chip interconnects 371 may couple its digital-signal-processing (DSP) IC chip 270 to its FPGA/NVM multi-chip package 259. One or more of the programmable interconnects 361 of its inter-chip interconnects 371 may couple its high bandwidth memory (HBM) IC chip 602 to any of its auxiliary IC chips 603 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple its high bandwidth memory (HBM) IC chip 602 to its dedicated control and input/output (I/O) chip 260 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple its high bandwidth memory (HBM) IC chip 602 to its FPGA/NVM multi-chip package 259 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple each of its auxiliary IC chips 603 to the others of its auxiliary IC chips 603. One or more of the programmable interconnects 361 of its inter-chip interconnects 371 may couple each of its auxiliary IC chips 603 to its dedicated control and input/output (I/O) chip 260. One or more of the programmable interconnects 361 of its inter-chip interconnects 371 may couple each of its auxiliary IC chips 603 to its FPGA/NVM multi-chip package 259. One or more of the programmable interconnects 361 of its inter-chip interconnects 371 may couple its dedicated control and input/output (I/O) chip 260 to its FPGA/NVM multi-chip package 259. Its FPGA IC chip 601, graphic-processing-unit (GPU) IC chips 269a, central-processing-unit (CPU) IC chip 269b, application-specific integrated-circuit (ASIC) chip or system-on-chip (SoC) chip 269c, digital-signal-processing (DSP) IC chip 270, dedicated control and input/output (I/O) chip 260, auxiliary IC chips 603 and high-bandwidth-memory (HBM) IC chips 602 may include the first, second or third type of field programmable logic cell or element (LCE) 2014 as illustrated in FIGS. 1A-1C, the first or second type of field programmable switch cell 379 as illustrated in FIGS. 2A and 2B and the field programmable switch matrix 710 as illustrated in FIG. 2C.

Referring to FIG. 5A-5, the first type of FPMCP 300 for the fifth alternative may include multiple inter-chip interconnects 371 each coupling two of its FPGA IC chips 200, NVM IC chip 250, VM IC chip 255, logic computing IC chips 269a, 269b and 269c, high bandwidth memory (HBM) IC chips 251 and auxiliary IC chips 411, wherein the inter-chip interconnects 371 of the first type of FPMCP 300 may be divided into multiple programmable interconnects 361 allowed to be programmed or configured and multiple non-programmable interconnects 364 not allowed to be programmed or configured. Each of its FPGA IC chips 200 may include (1) the first type of field programmable switch cell 379 as illustrated in FIG. 2A, the two nodes N21 and N22 of which may couple to two of the programmable interconnects 361 of its inter-chip interconnects 371 respectively, to control coupling between said two of the programmable interconnects 361 of its inter-chip interconnects 371 and/or (2) the second type of field programmable switch cell 379 as illustrated in FIG. 2B, the four nodes N23-N26 of which may couple to four of the programmable interconnects 361 of its inter-chip interconnects 371 respectively, to control coupling from one of said four of the programmable interconnects 361 of its inter-chip interconnects 371 to the other one or more of said four of the programmable interconnects 361 of its inter-chip interconnects 371. Data transmission may be built (1) between one of the programmable interconnects 361 of its inter-chip interconnects 371 and one of the programmable interconnects 361 of any of its FPGA IC chips 200 via one of the small input/output (I/O) circuits of said any of its FPGA IC chips 200. For the first type of FPMCP 300 for the third alternative, one or more of the programmable interconnects 361 of its inter-chip interconnects 371 may couple each of its FPGA IC chips 200 to its NVM IC chip 250. One or more of the programmable interconnects 361 of its inter-chip interconnects 371 may couple each of its FPGA IC chips 200 to its VM IC chip 255. One or more of the programmable interconnects 361 of its inter-chip interconnects 371 may couple each of its FPGA IC chips 200 to all of its logic computing IC chips 269a, 269b and 269c. One or more of the programmable interconnects 361 of its inter-chip interconnects 371 may couple each of its FPGA IC chips 200 to either of its high bandwidth memory (HBM) IC chips 251 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple each of its FPGA IC chips 200 to all of its auxiliary IC chips 411. One or more of the programmable interconnects 361 of its inter-chip interconnects 371 may couple each of its FPGA IC chips 200 to the others of its FPGA IC chips 200. One or more of the programmable interconnects 361 of its inter-chip interconnects 371 may couple each of its graphic-processing-unit (GPU) IC chips 269a to its NVM IC chip 250. One or more of the programmable interconnects 361 of its inter-chip interconnects 371 may couple each of its graphic-processing-unit (GPU) IC chips 269a to its VM IC chip 255. One or more of the programmable interconnects 361 of its inter-chip interconnects 371 may couple each of its graphic-processing-unit (GPU) IC chips 269a to its central-processing-unit (CPU) IC chip 269b. One or more of the programmable interconnects 361 of its inter-chip interconnects 371 may couple each of its graphic-processing-unit (GPU) IC chips 269a to its application-specific integrated-circuit (ASIC) IC chip or system-on chip (SoC) 269c. One or more of the programmable interconnects 361 of its inter-chip interconnects 371 may couple each of its graphic-processing-unit (GPU) IC chips 269a to either of its high bandwidth memory (HBM) IC chips 251 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple each of its graphic-processing-unit (GPU) IC chips 269a to all of its auxiliary IC chips 411. One or more of the programmable interconnects 361 of its inter-chip interconnects 371 may couple each of its graphic-processing-unit (GPU) IC chips 269a to the others of its graphic-processing-unit (GPU) IC chips 269a. One or more of the programmable interconnects 361 of its inter-chip interconnects 371 may couple its central-processing-unit (CPU) IC chip 269b to its NVM IC chip 250. One or more of the programmable interconnects 361 of its inter-chip interconnects 371 may couple its central-processing-unit (CPU) IC chip 269b to its VM IC chip 255. One or more of the programmable interconnects 361 of its inter-chip interconnects 371 may couple its central-processing-unit (CPU) IC chip 269b to its application-specific integrated-circuit (ASIC) IC chip or system-on chip (SoC) 269c. One or more of the programmable interconnects 361 of its inter-chip interconnects 371 may couple its central-processing-unit (CPU) IC chip 269b to either of its high bandwidth memory (HBM) IC chips 251 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple its central-processing-unit (CPU) IC chip 269b to all of its auxiliary IC chips 411. One or more of the programmable interconnects 361 of its inter-chip interconnects 371 may couple its application-specific integrated-circuit (ASIC) IC chip or system-on chip (SoC) 269c to its NVM IC chip 250. One or more of the programmable interconnects 361 of its inter-chip interconnects 371 may couple its application-specific integrated-circuit (ASIC) IC chip or system-on chip (SoC) 269c to its VM IC chip 255. One or more of the programmable interconnects 361 of its inter-chip interconnects 371 may couple its application-specific integrated-circuit (ASIC) IC chip or system-on chip (SoC) 269c to either of its high bandwidth memory (HBM) IC chips 251 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple its application-specific integrated-circuit (ASIC) IC chip or system-on chip (SoC) 269c to all of its auxiliary IC chips 411. One or more of the programmable interconnects 361 of its inter-chip interconnects 371 may couple its NVM IC chip 250 to either of its high bandwidth memory (HBM) IC chips 251 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple its NVM IC chip 250 to all of its auxiliary IC chips 411. One or more of the programmable interconnects 361 of its inter-chip interconnects 371 may couple its NVM IC chip 250 to its VM IC chip 255. One or more of the programmable interconnects 361 of its inter-chip interconnects 371 may couple its VM IC chip 255 to either of its high bandwidth memory (HBM) IC chips 251 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple its VM IC chip 255 to all of its auxiliary IC chips 411. One or more of the programmable interconnects 361 of its inter-chip interconnects 371 may couple each of its high bandwidth memory (HBM) IC chips 251 to any of its auxiliary IC chips 411 for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple its high bandwidth memory (HBM) IC chips 251 to each other for parallel data transmission therebetween with a data bit width of equal to or greater than 64, 128, 256, 512, 1024, 2048, 4096, 8K, or 16K. One or more of the programmable interconnects 361 of its inter-chip interconnects 371 may couple each of its auxiliary IC chips 411 to the others of its auxiliary IC chips 411. Each of its FPGA IC chips 200, graphic-processing-unit (GPU) IC chips 269a, central-processing-unit (CPU) IC chip 269b, application-specific integrated-circuit (ASIC) IC chip or system-on chip (SoC) 269c, NVM IC chip 250, VM IC chip 255, auxiliary IC chips 411 and high-bandwidth-memory (HBM) IC chips 251 may include the first, second or third type of field programmable logic cell or element (LCE) 2014 as illustrated in FIGS. 1A-1C and the first or second type of field programmable switch cell 379 as illustrated in FIGS. 2A and 2B.

Referring to FIG. 5A-1, the first type of FPMCP 300 for the first alternative may be provided with two groups of semiconductor IC chips, i.e., a group of mature-technology semiconductor IC chips and a group of advanced-technology semiconductor IC chips. For the first type of FPMCP 300 for the first alternative, its group of advanced-technology semiconductor IC chips may include its graphic-processing-unit (GPU) IC chips 269a, central-processing-unit (CPU) IC chip 269b, application-specific integrated-circuit (ASIC) chip or system-on-chip (SoC) chip 269c and FPGAIC chips 200, each of which may be fabricated using a relatively advanced process technology node equal to or more advanced than 10 nm or 20 nm, for example, and may have multiple small input/output (I/O) circuits each having an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts. Its group of mature-technology semiconductor IC chips may include its NVM IC chip 250 and auxiliary IC chips 411, each of which may be fabricated using a relatively mature process technology node equal to or more mature than 20 nm, for example, and may have multiple large input/output (I/O) circuits each having an I/O power efficiency greater than 3, 5 or 10 pico-Joules per bit, per switch or per voltage swing and/or having an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or equal to or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts.

Referring to FIG. 5A-2, the first type of FPMCP 300 for the second alternative may be provided with two groups of semiconductor IC chips, i.e., a group of mature-technology semiconductor IC chips and a group of advanced-technology semiconductor IC chips. For the first type of FPMCP 300 for the second alternative, its group of advanced-technology semiconductor IC chips may include its graphic-processing-unit (GPU) IC chips 269a, central-processing-unit (CPU) IC chip 269b, digital-signal-processing (DSP) IC chip 270 and FPGA IC chips 200 and 201, each of which may be fabricated using a relatively advanced process technology node equal to or more advanced than 10 nm or 20 nm, for example, and may have multiple small I/O circuits each having an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts. Its group of mature-technology semiconductor IC chips may include its NVM IC chips 250, IAC chip 402 and auxiliary IC chips 411, each of which may be fabricated using a relatively mature process technology node equal to or more mature than 20 nm, for example, and may have multiple large I/O circuits each having an I/O power efficiency greater than 3, 5 or 10 pico-Joules per bit, per switch or per voltage swing and/or having an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or equal to or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts.

Referring to FIG. 5A-5, the first type of FPMCP 300 for the fifth alternative may be provided with two groups of semiconductor IC chips, i.e., a group of mature-technology semiconductor IC chips and a group of advanced-technology semiconductor IC chips. For the first type of FPMCP 300 for the first alternative, its group of advanced-technology semiconductor IC chips may include its graphic-processing-unit (GPU) IC chips 269a, central-processing-unit (CPU) IC chip 269b, application-specific integrated-circuit (ASIC) IC chip or system-on chip (SoC) 269c and FPGA IC chips 200, each of which may be fabricated using a relatively advanced process technology node equal to or more advanced than 10 nm or 20 nm, for example, and may have multiple small input/output (I/O) circuits each having an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts. Its group of mature-technology semiconductor IC chips may include its NVM IC chip 250, VM IC chip 250 and auxiliary IC chips 411, each of which may be fabricated using a relatively mature process technology node equal to or more mature than 20 nm, for example, and may have multiple large input/output (I/O) circuits each having an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or equal to or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts.

Referring to FIGS. 5A-1, 5A-2 and 5A-5, for each of the first type of FPMCPs 300 for the first, second and fifth alternatives, each of its auxiliary IC chips 411 may have the large input/output (LIO) circuits 341 for receiving first input signals or data from the large input/output (I/O) circuits of its first semiconductor IC chip, selected from its group of mature-technology semiconductor IC chips, to be converted by said each of its auxiliary IC chips 411 as first output signals or data of said each of its auxiliary IC chips 411, and said each of its auxiliary IC chips 411 may have multiple small input/output (SIO) circuits 203 for transmitting the first output signals or data to the small input/output (I/O) circuits of its second semiconductor IC chip selected from its group of advanced-technology semiconductor IC chips. Further, the small input/output (SIO) circuits 203 of said each of its auxiliary IC chips 411 may receive second input signals or data from the small input/output (I/O) circuits of its second semiconductor IC chip to be converted by said each of its auxiliary IC chips 411 as second output signals or data of said each of its auxiliary IC chips 411, and the large input/output (LIO) circuits 341 of said each of its auxiliary IC chips 411 may transmit the second output signals or data to the large input/output (I/O) circuits of its first semiconductor IC chip. For a case for the first type of FPMCP 300 for the first alternative as illustrated in FIG. 5A-1, its first semiconductor IC chip may be its NVM IC chip 250 or one of the others of its auxiliary IC chips 411 and its second semiconductor IC chip may be any of its graphic-processing-unit (GPU) IC chips 269a, central-processing-unit (CPU) IC chip 269b, application-specific integrated-circuit (ASIC) chip or system-on-chip (SoC) chip 269c and FPGA IC chips 200. For a case for the first type of FPMCP 300 for the second alternative as illustrated in FIG. 5A-2, its first semiconductor IC chip may be its NVM IC chip 250 or one of the others of its auxiliary IC chips 411 and its second semiconductor IC chip may be any of its graphic-processing-unit (GPU) IC chips 269a, central-processing-unit (CPU) IC chip 269b, DSP IC chip 270 and FPGA IC chips 200 and 201. For a case for the first type of FPMCP 300 for the fifth alternative as illustrated in FIG. 5A-5, its first semiconductor IC chip may be its VM IC chip 255 and its second semiconductor IC chip may be any of its graphic-processing-unit (GPU) IC chips 269a, central-processing-unit (CPU) IC chip 269b, application-specific integrated-circuit (ASIC) IC chip or system-on chip (SoC) 269c and FPGA IC chips 200.

Referring to FIG. 5A-3, the first type of FPMCP 300 for the third alternative may be provided with two groups of semiconductor IC chips, i.e., a group of mature-technology semiconductor IC chips and a group of advanced-technology semiconductor IC chips. For the first type of FPMCP 300 for the third alternative, its group of advanced-technology semiconductor IC chips may include its graphic-processing-unit (GPU) IC chips 269a, central-processing-unit (CPU) IC chip 269b, application-specific integrated-circuit (ASIC) chip or system-on-chip (SoC) chip 269c and FPGA IC chip 601, each of which may be fabricated using a relatively advanced process technology node equal to or more advanced than 10 nm or 20 nm, for example, and may have multiple small input/output (I/O) circuits each having an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts. Its group of mature-technology semiconductor IC chips may include its auxiliary IC chips 603, each of which may be fabricated using a relatively mature process technology node equal to or more mature than 20 nm, for example, and may have multiple large input/output (I/O) circuits each having an I/O power efficiency greater than 3, 5 or 10 pico-Joules per bit, per switch or per voltage swing and/or having an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or equal to or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts.

Referring to FIG. 5A-4, the first type of FPMCP 300 for the fourth alternative may be provided with two groups of semiconductor IC chips, i.e., a group of mature-technology semiconductor IC chips and a group of advanced-technology semiconductor IC chips. For the first type of FPMCP 300 for the fourth alternative, its group of advanced-technology semiconductor IC chips may include its graphic-processing-unit (GPU) IC chips 269a, central-processing-unit (CPU) IC chip 269b, application-specific integrated-circuit (ASIC) chip or system-on-chip (SoC) chip 269c, digital-signal-processing (DSP) IC chip 270 and FPGA IC chip 601, each of which may be fabricated using a relatively advanced process technology node equal to or more advanced than 10 nm or 20 nm, for example, and may have multiple small input/output (I/O) circuits each having an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts. Its group of mature-technology semiconductor IC chips may include its auxiliary IC chips 603, each of which may be fabricated using a relatively mature process technology node equal to or more mature than 20 nm, for example, and may have multiple large input/output (I/O) circuits each having an I/O power efficiency greater than 3, 5 or 10 pico-Joules per bit, per switch or per voltage swing and/or having an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or equal to or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts.

Referring to FIGS. 5A-3 and 5A-4, for each of the first type of FPMCPs 300 for the third and fourth alternatives, each of its auxiliary IC chips 603 may have the large input/output (LIO) circuits 341 for receiving first input signals or data from the large input/output (I/O) circuits of its first semiconductor IC chip, selected from its group of mature-technology semiconductor IC chips, to be converted by said each of its auxiliary IC chips 603 as first output signals or data of said each of its auxiliary IC chips 603, and said each of its auxiliary IC chips 603 may have multiple small input/output (SIO) circuits 203 for transmitting the first output signals or data to its FPGA/NVM multi-chip package 259 and/or the small input/output (I/O) circuits of its second semiconductor IC chip selected from its group of advanced-technology semiconductor IC chips. Further, the small input/output (SIO) circuits 203 of said each of its auxiliary IC chips 603 may receive second input signals or data from its FPGA/NVM multi-chip package 259 and/or the small input/output (I/O) circuits of its second semiconductor IC chip to be converted by said each of its auxiliary IC chips 603 as second output signals or data of said each of its auxiliary IC chips 603, and the large input/output (LIO) circuits 341 of said each of its auxiliary IC chips 603 may transmit the second output signals or data to the large input/output (I/O) circuits of its first semiconductor IC chip. For a case for the first type of FPMCP 300 for the third alternative as illustrated in FIG. 5A-3, its first semiconductor IC chip may be one of the others of its auxiliary IC chips 603 and its second semiconductor IC chip may be any of its graphic-processing-unit (GPU) IC chips 269a, central-processing-unit (CPU) IC chip 269b, application-specific integrated-circuit (ASIC) chip or system-on-chip (SoC) chip 269c and FPGA IC chip 601. For a case for the first type of FPMCP 300 for the fourth alternative as illustrated in FIG. 5A-4, its first semiconductor IC chip may be one of the others of its auxiliary IC chips 411 and its second semiconductor IC chip may be any of its graphic-processing-unit (GPU) IC chips 269a, central-processing-unit (CPU) IC chip 269b, application-specific integrated-circuit (ASIC) chip or system-on-chip (SoC) chip 269c, DSP IC chip 270 and FPGA IC chip 601.

Alternatively, referring to FIGS. 5A-3 and 5A-4, for each of the first type of FPMCPs 300 for the third and fourth alternatives, each of its auxiliary IC chips 603 may have the large input/output (LIO) circuits 341 for receiving first input signals or data from its FPGA/NVM multi-chip package 259 and/or the large input/output (I/O) circuits of its first semiconductor IC chip, selected from its group of mature-technology semiconductor IC chips, to be converted by said each of its auxiliary IC chips 603 as first output signals or data of said each of its auxiliary IC chips 603, and said each of its auxiliary IC chips 603 may have multiple small input/output (SIO) circuits 203 for transmitting the first output signals or data to the small input/output (I/O) circuits of its second semiconductor IC chip selected from its group of advanced-technology semiconductor IC chips. Further, the small input/output (SIO) circuits 203 of said each of its auxiliary IC chips 603 may receive second input signals or data from the small input/output (I/O) circuits of its second semiconductor IC chip to be converted by said each of its auxiliary IC chips 603 as second output signals or data of said each of its auxiliary IC chips 603, and the large input/output (LIO) circuits 341 of said each of its auxiliary IC chips 603 may transmit the second output signals or data to its FPGA/NVM multi-chip package 259 and/or the large input/output (I/O) circuits of its first semiconductor IC chip. For a case for the first type of FPMCP 300 for the third alternative as illustrated in FIG. 5A-3, its first semiconductor IC chip may be one of the others of its auxiliary IC chips 603 and its second semiconductor IC chip may be any of its graphic-processing-unit (GPU) IC chips 269a, central-processing-unit (CPU) IC chip 269b, application-specific integrated-circuit (ASIC) chip or system-on-chip (SoC) chip 269c and FPGA IC chip 601. For a case for the first type of FPMCP 300 for the fourth alternative as illustrated in FIG. 5A-4, its first semiconductor IC chip may be one of the others of its auxiliary IC chips 411 and its second semiconductor IC chip may be any of its graphic-processing-unit (GPU) IC chips 269a, central-processing-unit (CPU) IC chip 269b, application-specific integrated-circuit (ASIC) chip or system-on-chip (SoC) chip 269c, DSP IC chip 270 and FPGA IC chip 601.

FIGS. 5E-5G and 5K are various block diagrams illustrating various connections to program or configure a FPGA IC chip or chiplet in accordance with data stored in a NVM IC chip. Referring to FIGS. 5A-1, 5A-2 and 5E, for each of the first type of FPMCPs 300 for the first and second alternatives, in a first aspect its NVM IC chip 250 or either may have multiple large input/output (LIO) circuits 342, each of which may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Each of a first group of the large input/output (LIO) circuits 342 of its NVM IC chip 250 or said either may have a first large receiver or metal input/output (I/O) pad for receiving first encrypted CPM data from a circuit 340 external of said each of the first type of FPMCPs 300 for the first and second alternatives to be stored in one of multiple non-volatile memory cells (NVMCs) 261 of its NVM IC chip 250 or said either. Each of a second group of the large input/output (LIO) circuits 342 of its NVM IC chip 250 or said either may have a first large driver coupling to a second large receiver, i.e., input buffer 273 as seen in FIG. 5I, or metal input/output (I/O) pad of one of the large input/output (LIO) circuits 341 of the large-input/output (I/O) block of any of its auxiliary IC chips 411 via a non-programmable interconnect 364 of its inter-chip interconnects 371 for passing the first encrypted CPM data from the first large driver to the second large receiver. Alternatively, each of the large input/output (LIO) circuits 341 of the large-input/output (I/O) block of said any of its auxiliary IC chips 411 may have the second large receiver or metal input/output (I/O) pad for receiving the first encrypted CPM data from a circuit 340 external of said each of the first type of FPMCPs 300 for the first and second alternatives. Next, the first encrypted CPM data may be shift by the voltage-level shift-down circuit 207, as seen in FIG. 5I, of one of the voltage-level shift (VLS) circuits 205 of the voltage-level shift block of said any of its auxiliary IC chips 411 to be carried with the voltage VddL of low-voltage power supply and then decrypted by the cryptography block of said any of its auxiliary IC chips 411 as first decrypted CPM data carried with the voltage VddL of low-voltage power supply. Next, each of the small input/output (SIO) circuits 203 of the small-input/output (I/O) block of said any of its auxiliary IC chips 411 may have a first small driver, i.e., output buffer 272 as seen in FIG. 5I, or metal input/output (I/O) pad coupling to a first small receiver or metal input/output (I/O) pad of one of a first group of small input/output (SIO) circuits 209 of any of its FPGA IC chips 200 and/or 201 via another non-programmable interconnect 364 of its inter-chip interconnects 371 for passing the first decrypted CPM data from the first small driver to the first small receiver, wherein each of the first group of small input/output (SIO) circuits 209 of said any of its FPGA IC chips 200 and/or 201 may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts, 0.7 volts or 0.5 volts and/or a voltage swing equal to or smaller than 1.2 volts, 1 volt, 0.8 volts, 0.7 volts or 0.5 volts, for example. Next, the memory cells 490 of one of the first type of field programmable logic cells or elements (LCEs) 2014, as illustrated in FIG. 1A, of said any of its FPGA IC chips 200 and/or 201 or the memory cells of one of the second or third type of field programmable logic cells or elements (LCEs) 2014, as illustrated in FIGS. 1B-1C, of said any of its FPGA IC chips 200 and/or 201 may store therein data associated with the first decrypted CPM data to be programmed, configured or reconfigured in accordance with the first decrypted CPM data, the memory cell(s) 362 of the first type of field programmable switch cells 379, as illustrated in FIG. 2A, of said any of its FPGA IC chips 200 and/or 201 or the four sets of memory cell(s) 362 of the second type of field programmable switch cells 379, as illustrated in FIG. 2B, of said any of its FPGA IC chips 200 and/or 201 may store therein data associated with the first decrypted CPM data to be programmed, configured or reconfigured in accordance with the first decrypted CPM data and/or the memory cell 398 of each of the field programmable switch units 711 of the field programmable switch matrix 710, as illustrated in FIG. 2C, of said any of its FPGA IC chips 200 and/or 201 may store therein data, i.e., programming codes, password or encryption/decryption codes, associated with the first decrypted CPM data to be programmed, configured or reconfigured in accordance with the first decrypted CPM data. Furthermore, each of the first group of small input/output (SIO) circuits 209 of said any of its FPGA IC chips 200 and/or 201 may have a second small driver or metal input/output (I/O) pad coupling to a second small receiver, i.e., input buffer 271 as seen in FIG. 5H, or metal input/output (I/O) pad of one of the small input/output (SIO) circuits 203 of the small-input/output (I/O) block of said any of its auxiliary IC chips 411 via another non-programmable interconnect 364 of its inter-chip interconnects 371 for passing second CPM data, associated with data stored (1) in the memory cells 490 of one of the first type of field programmable logic cells or elements (LCEs) 2014, as illustrated in FIG. 1A, of said any of its FPGA IC chips 200 and/or 201 or the memory cells of one of the second or third type of field programmable logic cell or elements (LCEs) 2014, as illustrated in FIGS. 1B-1C, of said any of its FPGA IC chips 200 and/or 201, (2) in the memory cell(s) 362 of the first type of field programmable switch cells 379, as illustrated in FIG. 2A, of said any of its FPGA IC chips 200 and/or 201 or the four sets of memory cell(s) 362 of the second type of field programmable switch cells 379, as illustrated in FIG. 2B, of said any of its FPGA IC chips 200 and/or 201 and/or (3) in the memory cell 398 of each of the field programmable switch units 711 of the field programmable switch matrix 710, as illustrated in FIG. 2C, of said any of its FPGA IC chips 200 and/or 201, from the second small driver to the second small receiver. Next, the second CPM data may be encrypted by the cryptography block of said any of its auxiliary IC chips 411 as second encrypted CPM data and then the second encrypted CPM data may be shift by the voltage-level shift-up circuit 206, as seen in FIG. 5H, of one of the voltage-level shift (VLS) circuits 205 of the voltage-level shift block of said any of its auxiliary IC chips 411 to be carried with the voltage VddH of high-voltage power supply. Next, each of the large input/output (LIO) circuits 341 of the large-input/output (I/O) block of said any of its auxiliary IC chips 411 may have a second large driver, i.e., output buffer 274 as seen in FIG. 5H, or metal input/output (I/O) pad coupling to a third large receiver or metal input/output (I/O) pad of one of the second group of the large input/output (LIO) circuits 342 of its NVM IC chip 250 or said either via another non-programmable interconnect 364 of its inter-chip interconnects 371 for passing the second encrypted CPM data from the second large driver to the third large receiver to be stored in another of the non-volatile memory cells (NVMCs) 261 of its NVM IC chip 250 or said either, and then each of the first group of the large input/output (I/O) circuits 342 of its NVM IC chip 250 or said either may have a third large driver for driving or transmitting the second encrypted CPM data to a circuit 340 external of said each of the first type of FPMCPs 300 for the first and second alternatives. Alternatively, each of the large input/output (LIO) circuits 341 of the large-input/output (I/O) block of said any of its auxiliary IC chips 411 may have the second large driver or metal input/output (I/O) pad for driving or transmitting the second encrypted CPM data to a circuit 340 external of said each of the first type of FPMCPs 300 for the first and second alternatives.

Referring to FIGS. 5A-1, 5A-2 and 5E, for each of the first type of FPMCPs 300 for the first and second alternatives, in a second aspect its NVM IC chip 250 or either may have multiple large input/output (LIO) circuits 342, each of which may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Each of a first group of the large input/output (LIO) circuits 342 of its NVM IC chip 250 or said either may have a first large receiver or metal input/output (I/O) pad for receiving first CPM data from a circuit 340 external of said each of the first type of FPMCPs 300 for the first and second alternatives to be stored in one of multiple non-volatile memory cells (NVMCs) 261 of its NVM IC chip 250 or said either. Each of a second group of the large input/output (LIO) circuits 342 of its NVM IC chip 250 or said either may have a first large driver or metal input/output (I/O) pad coupling to a second large receiver, i.e., input buffer 273 as seen in FIG. 5I, or metal input/output (I/O) pad of one of the large input/output (LIO) circuits 341 of the large-input/output (I/O) block of any of its auxiliary IC chips 411 via a non-programmable interconnect 364 of its inter-chip interconnects 371 for passing the first CPM data from the first large driver to the second large receiver. Alternatively, each of the large input/output (LIO) circuits 341 of the large-input/output (I/O) block of said any of its auxiliary IC chips 411 may have the second large receiver or metal input/output (I/O) pad for receiving the first CPM data from a circuit 340 external of said each of the first type of FPMCPs 300 for the first and second alternatives. Next, the first CPM data may be shift by the voltage-level shift-down circuit 207, as seen in FIG. 5I, of one of the voltage-level shift (VLS) circuits 205 of the voltage-level shift block of said any of its auxiliary IC chips 411 to be carried with the voltage VddL of low-voltage power supply. Next, each of the small input/output (SIO) circuits 203 of the small-input/output (I/O) block of said any of its auxiliary IC chips 411 may have a first small driver, i.e., output buffer 272 as seen in FIG. 5I, or metal input/output (I/O) pad coupling to a first small receiver or metal input/output (I/O) pad of one of a first group of small input/output (SIO) circuits 209 of any of its FPGA IC chips 200 and/or 201 via another non-programmable interconnect 364 of its inter-chip interconnects 371 for passing the first CPM data from the first small driver to the first small receiver, wherein each of the first group of small input/output (SIO) circuits 209 of said any of its FPGA IC chips 200 and/or 201 may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts, 0.7 volts or 0.5 volts and/or a voltage swing equal to or smaller than 1.2 volts, 1 volt, 0.8 volts, 0.7 volts or 0.5 volts, for example. Next, the memory cells 490 of one of the first type of field programmable logic cells or elements (LCEs) 2014, as illustrated in FIG. 1A, of said any of its FPGA IC chips 200 and/or 201 or the memory cells of one of the second or third type of field programmable logic cells or elements (LCEs) 2014, as illustrated in FIGS. 1B-1C, of said any of its FPGA IC chips 200 and/or 201 may store therein data associated with the first CPM data to be programmed, configured or reconfigured in accordance with the first CPM data, the memory cell(s) 362 of the first type of field programmable switch cells 379, as illustrated in FIG. 2A, of said any of its FPGA IC chips 200 and/or 201 or the four sets of memory cell(s) 362 of the second type of field programmable switch cells 379, as illustrated in FIG. 2B, of said any of its FPGA IC chips 200 and/or 201 may store therein data associated with the first CPM data to be programmed, configured or reconfigured in accordance with the first CPM data and/or the memory cell 398 of each of the field programmable switch units 711 of the field programmable switch matrix 710, as illustrated in FIG. 2C, of said any of its FPGA IC chips 200 and/or 201 may store therein data associated with the first decrypted CPM data to be programmed, configured or reconfigured in accordance with the first decrypted CPM data. Furthermore, each of the first group of small input/output (SIO) circuits 209 of said any of its FPGA IC chips 200 and/or 201 may have a second small driver or metal input/output (I/O) pad coupling to a second small receiver, i.e., input buffer 271 as seen in FIG. 5H, or metal input/output (I/O) pad of one of the small input/output (SIO) circuits 203 of the small-input/output (I/O) block of said any of its auxiliary IC chips 411 via another non-programmable interconnect 364 of its inter-chip interconnects 371 for passing second CPM data associated with data, i.e., programming codes, password or encryption/decryption codes, stored (1) in the memory cells 490 of one of the first type of field programmable logic cells or elements (LCEs) 2014, as illustrated in FIG. 1A, of said any of its FPGA IC chips 200 and/or 201 or the memory cells of one of the second or third type of field programmable logic cells or elements (LCEs) 2014, as illustrated in FIGS. 1B-1C, of said any of its FPGA IC chips 200 and/or 201, (2) in the memory cell(s) 362 of the first type of field programmable switch cells 379, as illustrated in FIG. 2A, of said any of its FPGA IC chips 200 and/or 201 or the four sets of memory cell(s) 362 of the second type of field programmable switch cells 379, as illustrated in FIG. 2B, of said any of its FPGA IC chips 200 and/or 201 and/or (3) in the memory cell 398 of each of the field programmable switch units 711 of the field programmable switch matrix 710, as illustrated in FIG. 2C, of said any of its FPGA IC chips 200 and/or 201, from the second small driver to the second small receiver. Next, the second CPM data may be shift by the voltage-level shift-up circuit 206, as seen in FIG. 5H, of one of the voltage-level shift (VLS) circuits 205 of the voltage-level shift block of said any of its auxiliary IC chips 411 to be carried with the voltage VddH of high-voltage power supply. Next, each of the large input/output (LIO) circuits 341 of the large-input/output (I/O) block of said any of its auxiliary IC chips 411 may have a second large driver, i.e., output buffer 274 as seen in FIG. 5H, or metal input/output (I/O) pad coupling to a third large receiver or metal input/output (I/O) pad of one of the second group of the large input/output (LIO) circuits 342 of its NVM IC chip 250 or said either via another non-programmable interconnect 364 of its inter-chip interconnects 371 for passing the second CPM data from the second large driver to the third large receiver to be stored in another of the non-volatile memory cells (NVMCs) 261 of its NVM IC chip 250 or said either, and then each of the first group of the large input/output (LIO) circuits 342 of its NVM IC chip 250 or said either may have a third large driver or metal input/output (I/O) pad for driving or transmitting the second CPM data to a circuit 340 external of said each of the first type of FPMCPs 300 for the first and second alternatives. Alternatively, each of the large input/output (LIO) circuits 341 of the large-input/output (I/O) block of said any of its auxiliary IC chips 411 may have the second large driver or metal input/output (I/O) pad for driving or transmitting the second CPM data to a circuit 340 external of said each of the first type of FPMCPs 300 for the first and second alternatives.

Referring to FIGS. 5A-1, 5A-2 and 5E, for each of the first type of FPMCPs 300 for the first and second alternatives, in a third aspect its NVM IC chip 250 or either may have multiple large input/output (LIO) circuits 342, each of which may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Each of a first group of the large input/output (I/O) circuits 341 of its NVM IC chip 250 or said either may have a first large receiver or metal input/output (I/O) pad for receiving first encrypted CPM data from a circuit 340 external of said each of the first type of FPMCPs 300 for the first and second alternatives to be stored in one of multiple non-volatile memory cells (NVMCs) 261 of its NVM IC chip 250 or said either. Each of a second group of the large input/output (LIO) circuits 342 of its NVM IC chip 250 or said either may have a first large driver or metal input/output (I/O) pad coupling to a second large receiver, i.e., input buffer 273 as seen in FIG. 5I, or metal input/output (I/O) pad of one of the large input/output (LIO) circuits 341 of the large-input/output (I/O) block of any of its auxiliary IC chips 411 via a non-programmable interconnect 364 of its inter-chip interconnects 371 for passing the first encrypted CPM data from the first large driver to the second large receiver. Alternatively, each of the large input/output (LIO) circuits 341 of the large-input/output (I/O) block of said any of its auxiliary IC chips 411 may have the second large receiver or metal input/output (I/O) pad for receiving the first encrypted CPM data from a circuit 340 external of said each of the first type of FPMCPs 300 for the first and second alternatives. Next, the first encrypted CPM data may be shift by the voltage-level shift-down circuit 207, as seen in FIG. 5I, of one of the voltage-level shift (VLS) circuits 205 of the voltage-level shift block of said any of its auxiliary IC chips 411 to be carried with the voltage VddL of low-voltage power supply. Next, each of the small input/output (SIO) circuits 203 of the small-input/output (I/O) block of said any of its auxiliary IC chips 411 may have a first small driver, i.e., output buffer 272 as seen in FIG. 5I, or metal input/output (I/O) pad coupling to a first small receiver or metal input/output (I/O) pad of one of a first group of small input/output (SIO) circuits 209 of any of its FPGA IC chips 200 and/or 201 via another non-programmable interconnect 364 of its inter-chip interconnects 371 for passing the first encrypted CPM data from the first small driver to the first small receiver, wherein each of the first group of small input/output (SIO) circuits 209 of said any of its FPGA IC chips 200 and/or 201 may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts, 0.7 volts or 0.5 volts and/or a voltage swing equal to or smaller than 1.2 volts, 1 volt, 0.8 volts, 0.7 volts or 0.5 volts, for example. Next, said any of its FPGA IC chips 200 and/or 201 may include a cryptography block configured to decrypt the first encrypted CPM data as first decrypted CPM data. Next, the memory cells 490 of one of the first type of field programmable logic cells or elements (LCEs) 2014, as illustrated in FIG. 1A, of said any of its FPGA IC chips 200 and/or 201 or the memory cells of one of the second or third type of field programmable logic cells or elements (LCEs) 2014, as illustrated in FIGS. 1B-1C, of said any of its FPGA IC chips 200 and/or 201 may store therein data associated with the first decrypted CPM data to be programmed, configured or reconfigured in accordance with the first decrypted CPM data, the memory cell(s) 362 of the first type of field programmable switch cells 379, as illustrated in FIG. 2A, of said any of its FPGA IC chips 200 and/or 201 or the four sets of memory cell(s) 362 of the second type of field programmable switch cells 379, as illustrated in FIG. 2B, of said any of its FPGA IC chips 200 and/or 201 may store therein data associated with the first decrypted CPM data to be programmed, configured or reconfigured in accordance with the first decrypted CPM data and/or the memory cell 398 of each of the field programmable switch units 711 of the field programmable switch matrix 710, as illustrated in FIG. 2C, of said any of its FPGA IC chips 200 and/or 201 may store therein data, i.e., programming codes, password or encryption/decryption codes, associated with the first decrypted CPM data to be programmed, configured or reconfigured in accordance with the first decrypted CPM data. Furthermore, second CPM data associated with data, i.e., programming codes, password or encryption/decryption codes, stored (1) in the memory cells 490 of one of the first type of field programmable logic cells or elements (LCEs) 2014, as illustrated in FIG. 1A, of said any of its FPGA IC chips 200 and/or 201 or the memory cells of one of the second or third type of field programmable logic cells or elements (LCEs) 2014, as illustrated in FIGS. 1B-1C, of said any of its FPGA IC chips 200 and/or 201, (2) in the memory cell(s) 362 of the first type of field programmable switch cells 379, as illustrated in FIG. 2A, of said any of its FPGA IC chips 200 and/or 201 or the four sets of memory cell(s) 362 of the second type of field programmable switch cells 379, as illustrated in FIG. 2B, of said any of its FPGA IC chips 200 and/or 201 and/or (3) in the memory cell 398 of each of the field programmable switch units 711 of the field programmable switch matrix 710, as illustrated in FIG. 2C, of said any of its FPGA IC chips 200 and/or 201, may be encrypted by the cryptography block of said any of its FPGA IC chips 200 and/or 201 as second encrypted CPM data. Each of the first group of small input/output (SIO) circuits 209 of said any of its FPGA IC chips 200 and/or 201 may have a second small driver or metal input/output (I/O) pad coupling to a second small receiver, i.e., input buffer 271 as seen in FIG. 5H, or metal input/output (I/O) pad of one of the small input/output (SIO) circuits 203 of the small-input/output (I/O) block of said any of its auxiliary IC chips 411 via another non-programmable interconnect 364 of its inter-chip interconnects 371 for passing the second encrypted CPM data from the second small driver to the second small receiver. Next, the second encrypted CPM data may be shift by the voltage-level shift-up circuit 206, as seen in FIG. 5H, of one of the voltage-level shift (VLS) circuits 205 of the voltage-level shift block of said any of its auxiliary IC chips 411 to be carried with the voltage VddH of high-voltage power supply. Next, each of the large input/output (LIO) circuits 341 of said any of its auxiliary IC chips 411 may have a second large driver, i.e., output buffer 274 as seen in FIG. 5H, or metal input/output (I/O) pad coupling to a third large receiver or metal input/output (I/O) pad of one of the second group of the large input/output (LIO) circuits 341 of its NVM IC chip 250 or said either via another non-programmable interconnect 364 of its inter-chip interconnects 371 for passing the second encrypted CPM data from the second large driver to the third large receiver to be stored in another of the non-volatile memory cells (NVMCs) 261 of its NVM IC chip 250 or said either, and then each of the first group of the large input/output (I/O) circuits 341 of its NVM IC chip 250 or said either may have a third large driver for driving or transmitting the second encrypted CPM data to a circuit 340 external of said each of the first type of FPMCPs 300 for the first and second alternatives. Alternatively, each of the large input/output (LIO) circuits 341 of said any of its auxiliary IC chips 411 may have the second large driver or metal input/output (I/O) pad for driving or transmitting the second encrypted CPM data to a circuit 340 external of said each of the first type of FPMCPs 300 for the first and second alternatives.

Referring to FIGS. 5A-1, 5A-2 and 5E, for each of the first type of FPMCPs 300 for the first and second alternatives, in a fourth aspect its NVM IC chip 250 or either may have multiple large input/output (LIO) circuits 342, each of which may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Each of a first group of the large input/output (LIO) circuits 342 of its NVM IC chip 250 or said either may have a first large receiver or metal input/output (I/O) pad for receiving first encrypted CPM data from a circuit 340 external of said each of the first type of FPMCPs 300 for the first and second alternatives. Its NVM IC chip 250 or said either may include a cryptography block configured to decrypt the first encrypted CPM data as first decrypted CPM data to be stored in one of multiple non-volatile memory cells (NVMCs) 261 of its NVM IC chip 250 or said either. Each of a second group of the large input/output (LIO) circuits 342 of its NVM IC chip 250 or said either may have a first large driver or metal input/output (I/O) pad coupling to a second large receiver, i.e., input buffer 273 as seen in FIG. 5I, or metal input/output (I/O) pad of one of the large input/output (LIO) circuits 341 of the large-input/output (I/O) block of any of its auxiliary IC chips 411 via a non-programmable interconnect 364 of its inter-chip interconnects 371 for passing the first decrypted CPM data from the first large driver to the second large receiver. Next, the first decrypted CPM data may be shift by the voltage-level shift-down circuit 207, as seen in FIG. 5I, of one of the voltage-level shift (VLS) circuits 205 of the voltage-level shift block of said any of its auxiliary IC chips 411 to be carried with the voltage VddL of low-voltage power supply. Next, each of the small input/output (SIO) circuits 203 of the small-input/output (I/O) block of said any of its auxiliary IC chips 411 may have a first small driver, i.e., output buffer 272 as seen in FIG. 5I, or metal input/output (I/O) pad coupling to a first small receiver or metal input/output (I/O) pad of one of a first group of small input/output (SIO) circuits 209 of any of its FPGA IC chips 200 and/or 201 via another non-programmable interconnect 364 of its inter-chip interconnects 371 for passing the first decrypted CPM data from the first small driver to the first small receiver, wherein each of the first group of small input/output (SIO) circuits 209 of said any of its FPGA IC chips 200 and/or 201 may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts, 0.7 volts or 0.5 volts and/or a voltage swing equal to or smaller than 1.2 volts, 1 volt, 0.8 volts, 0.7 volts or 0.5 volts, for example. Next, the memory cells 490 of one of the first type of field programmable logic cells or elements (LCEs) 2014, as illustrated in FIG. 1A, of said any of its FPGA IC chips 200 and/or 201 or the memory cells of one of the second or third type of field programmable logic cells or elements (LCEs) 2014, as illustrated in FIGS. 1B-1C, of said any of its FPGA IC chips 200 and/or 201 may store therein data associated with the first decrypted CPM data to be programmed, configured or reconfigured in accordance with the first decrypted CPM data, the memory cell(s) 362 of the first type of field programmable switch cells 379, as illustrated in FIG. 2A, of said any of its FPGA IC chips 200 and/or 201 or the four sets of memory cell(s) 362 of the second type of field programmable switch cells 379, as illustrated in FIG. 2B, of said any of its FPGA IC chips 200 and/or 201 may store therein data associated with the first decrypted CPM data to be programmed, configured or reconfigured in accordance with the first decrypted CPM data and/or the memory cell 398 of each of the field programmable switch units 711 of the field programmable switch matrix 710, as illustrated in FIG. 2C, of said any of its FPGA IC chips 200 and/or 201 may store therein data, i.e., programming codes, password or encryption/decryption codes, associated with the first decrypted CPM data to be programmed, configured or reconfigured in accordance with the first decrypted CPM data. Furthermore, each of the first group of small input/output (SIO) circuits 209 of said any of its FPGA IC chips 200 and/or 201 may have a second small driver or metal input/output (I/O) pad coupling to a second small receiver, i.e., input buffer 271 as seen in FIG. 5H, or metal input/output (I/O) pad of one of the small input/output (SIO) circuits 203 of the small-input/output (I/O) block of said any of its auxiliary IC chips 411 via another non-programmable interconnect 364 of its inter-chip interconnects 371 for passing second CPM data, associated with data stored (1) in the memory cells 490 of one of the first type of field programmable logic cells or elements (LCEs) 2014, as illustrated in FIG. 1A, of said any of its FPGA IC chips 200 and/or 201 or the memory cells of one of the second or third type of field programmable logic cell or elements (LCEs) 2014, as illustrated in FIGS. 1B-1C, of said any of its FPGA IC chips 200 and/or 201, (2) in the memory cell(s) 362 of the first type of field programmable switch cells 379, as illustrated in FIG. 2A, of said any of its FPGA IC chips 200 and/or 201 or the four sets of memory cell(s) 362 of the second type of field programmable switch cells 379, as illustrated in FIG. 2B, of said any of its FPGA IC chips 200 and/or 201 and/or (3) in the memory cell 398 of each of the field programmable switch units 711 of the field programmable switch matrix 710, as illustrated in FIG. 2C, of said any of its FPGA IC chips 200 and/or 201, from the second small driver to the second small receiver. Next, the second CPM data may be shift by the voltage-level shift-up circuit 206, as seen in FIG. 5H, of one of the voltage-level shift (VLS) circuits 205 of the voltage-level shift block of said any of its auxiliary IC chips 411 to be carried with the voltage VddH of high-voltage power supply. Next, each of the large input/output (LIO) circuits 341 of the large-input/output (I/O) block of said any of its auxiliary IC chips 411 may have a second large driver, i.e., output buffer 274 as seen in FIG. 5H, or metal input/output (I/O) pad coupling to a third large receiver or metal input/output (I/O) pad of one of the second group of the large input/output (LIO) circuits 342 of its NVM IC chip 250 or said either via another non-programmable interconnect 364 of its inter-chip interconnects 371 for passing the second CPM data from the second large driver to the third large receiver to be stored in another of the non-volatile memory cells (NVMCs) 261 of its NVM IC chip 250 or said either. The second CPM data may be encrypted by the cryptography block of its NVM IC chip 250 or said either as second encrypted CPM data. Each of the first group of the large input/output (LIO) circuits 342 of its NVM IC chip 250 or said either may have a third large driver or metal input/output (I/O) pad for driving or transmitting the second encrypted CPM data to a circuit 340 external of said each of the first type of FPMCPs 300 for the first and second alternatives.

Referring to FIGS. 5A-1, 5A-2 and 5F, for each of the first type of FPMCPs 300 for the first and second alternatives, in a fifth aspect one of the large input/output (LIO) circuits 341 of the large-input/output (I/O) block of any of its auxiliary IC chips 411 may have a large receiver, i.e., input buffer 273 as seen in FIG. 5I, or metal input/output (I/O) pad for receiving first encrypted CPM data from a circuit 340 external of said each of the first type of FPMCPs 300 for the first and second alternatives. The first encrypted CPM data may be shift by the voltage-level shift-down circuit 207, as seen in FIG. 5I, of one of the voltage-level shift (VLS) circuits 205 of the voltage-level shift block of said any of its auxiliary IC chips 411 to be carried with the voltage VddL of low-voltage power supply and then decrypted by the cryptography block of said any of its auxiliary IC chips 411 as first decrypted CPM data carried with the voltage VddL of low-voltage power supply. Next, each of the small input/output (SIO) circuits 203 of the small-input/output (I/O) block of said any of its auxiliary IC chips 411 may have a first small driver, i.e., output buffer 272 as seen in FIG. 5I, or metal input/output (I/O) pad coupling to a first small receiver or metal input/output (I/O) pad of one of a first group of small input/output (SIO) circuits 214 of its NVM IC chip 250 or either via a non-programmable interconnect 364 of its inter-chip interconnects 371 for passing the first decrypted CPM data from the first small driver to the first small receiver to be stored in one of multiple non-volatile memory cells (NVMCs) 261 of its NVM IC chip 250 or said either. A second group of small input/output (SIO) circuits 214 of its NVM IC chip 250 or said either may have a second small driver or metal input/output (I/O) pad coupling to a second small receiver or metal input/output (I/O) pad of one of a first group of small input/output (SIO) circuits 209 of any of its FPGA IC chips 200 and/or 201 via another non-programmable interconnect 364 of its inter-chip interconnects 371 for passing the first decrypted CPM data from the second small driver to the second small receiver, wherein each of the first group of small input/output (SIO) circuits 209 of said any of its FPGA IC chips 200 and/or 201 and each of the first and second groups of small input/output (SIO) circuits 214 of its NVM IC chip 250 or said either may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts, 0.7 volts or 0.5 volts and/or a voltage swing equal to or smaller than 1.2 volts, 1 volt, 0.8 volts, 0.7 volts or 0.5 volts, for example. Next, the memory cells 490 of one of the first type of field programmable logic cells or elements (LCEs) 2014, as illustrated in FIG. 1A, of said any of its FPGA IC chips 200 and/or 201 or the memory cells of one of the second or third type of field programmable logic cells or elements (LCEs) 2014, as illustrated in FIGS. 1B-1C, of said any of its FPGA IC chips 200 and/or 201 may store therein data associated with the first decrypted CPM data to be programmed, configured or reconfigured in accordance with the first decrypted CPM data, the memory cell(s) 362 of the first type of field programmable switch cells 379, as illustrated in FIG. 2A, of said any of its FPGA IC chips 200 and/or 201 or the four sets of memory cell(s) 362 of the second type of field programmable switch cells 379, as illustrated in FIG. 2B, of said any of its FPGA IC chips 200 and/or 201 may store therein data associated with the first decrypted CPM data to be programmed, configured or reconfigured in accordance with the first decrypted CPM data and/or the memory cell 398 of each of the field programmable switch units 711 of the field programmable switch matrix 710, as illustrated in FIG. 2C, of said any of its FPGA IC chips 200 and/or 201 may store therein data, i.e., programming codes, password or encryption/decryption codes, associated with the first decrypted CPM data to be programmed, configured or reconfigured in accordance with the first decrypted CPM data. Furthermore, each of the first group of small input/output (SIO) circuits 209 of said any of its FPGA IC chips 200 and/or 201 may have a third small driver or metal input/output (I/O) pad coupling to a third small receiver or metal input/output (I/O) pad of one of the second group of small input/output (SIO) circuits 214 of its NVM IC chip 250 or said either via another non-programmable interconnect 364 of its inter-chip interconnects 371 for passing second CPM data associated with data, i.e., programming codes, password or encryption/decryption codes, stored (1) in the memory cells 490 of one of the first type of field programmable logic cells or elements (LCEs) 2014, as illustrated in FIG. 1A, of said any of its FPGA IC chips 200 and/or 201 or the memory cells of one of the second or third type of field programmable logic cell or elements (LCEs) 2014, as illustrated in FIGS. 1B-1C, of said any of its FPGA IC chips 200 and/or 201 (2) in the memory cell(s) 362 of the first type of field programmable switch cells 379, as illustrated in FIG. 2A, of said any of its FPGA IC chips 200 and/or 201 or the four sets of memory cell(s) 362 of the second type of field programmable switch cells 379, as illustrated in FIG. 2B, of said any of its FPGA IC chips 200 and/or 201 and/or (3) in the memory cell 398 of each of the field programmable switch units 711 of the field programmable switch matrix 710, as illustrated in FIG. 2C, of said any of its FPGA IC chips 200 and/or 201, from the third small driver to the third small receiver to be stored in another of the non-volatile memory cells (NVMCs) 261 of its NVM IC chip 250 or said either. Next, each of the first group of small input/output (SIO) circuits 214 of its NVM IC chip 250 or said either may have a fourth small driver or metal input/output (I/O) pad coupling to a fourth small receiver, i.e., input buffer 271 as seen in FIG. 5H, or metal input/output (I/O) pad of one of the small input/output (SIO) circuits 203 of the small-input/output (I/O) block of said any of its auxiliary IC chips 411 via another non-programmable interconnect 364 of its inter-chip interconnects 371 for passing the second CPM data from the fourth small driver to the fourth small receiver. Next, the second CPM data may be encrypted by the cryptography block of said any of its auxiliary IC chips 411 as second encrypted CPM data and then the second encrypted CPM data may be shift by the voltage-level shift-up circuit 206, as seen in FIG. 5H, of one of the voltage-level shift (VLS) circuits 205 of the voltage-level shift block of said any of its auxiliary IC chips 411 to be carried with the voltage VddH of high-voltage power supply. Each of the large input/output (LIO) circuits 341 of the large-input/output (I/O) block of said any of its auxiliary IC chips 411 may have the large driver, i.e., output buffer 274 as seen in FIG. 5H, or metal input/output (I/O) pad for driving or transmitting the second encrypted CPM data to a circuit 340 external of said each of the first type of FPMCPs 300 for the first and second alternatives.

Referring to FIGS. 5A-1, 5A-2 and 5F, for each of the first type of FPMCPs 300 for the first and second alternatives, in a sixth aspect one of the large input/output (LIO) circuits 341 of the large-input/output (I/O) block of any of its auxiliary IC chips 411 may have a large receiver, i.e., input buffer 273 as seen in FIG. 5I, or metal input/output (I/O) pad for receiving first CPM data from a circuit 340 external of said each of the first type of FPMCPs 300 for the first and second alternatives. The first CPM data may be shift by the voltage-level shift-down circuit 207, as seen in FIG. 5I, of one of the voltage-level shift (VLS) circuits 205 of the voltage-level shift block of said any of its auxiliary IC chips 411 to be carried with the voltage VddL of low-voltage power supply. Next, each of the small input/output (SIO) circuits 203 of the small-input/output (I/O) block of said any of its auxiliary IC chips 411 may have a first small driver, i.e., output buffer 272 as seen in FIG. 5I, or metal input/output (I/O) pad coupling to a first small receiver or metal input/output (I/O) pad of one of a first group of small input/output (SIO) circuits 214 of its NVM IC chip 250 or either via a non-programmable interconnect 364 of its inter-chip interconnects 371 for passing the first CPM data from the first small driver to the first small receiver to be stored in one of multiple non-volatile memory cells (NVMCs) 261 of its NVM IC chip 250 or said either. A second group of small input/output (SIO) circuits 214 of its NVM IC chip 250 or said either may have a second small driver or metal input/output (I/O) pad coupling to a second small receiver or metal input/output (I/O) pad of one of a first group of small input/output (SIO) circuits 209 of any of its FPGA IC chips 200 and/or 201 via another non-programmable interconnect 364 of its inter-chip interconnects 371 for passing the first CPM data from the second small driver to the second small receiver, wherein each of the first group of small input/output (SIO) circuits 209 of said any of its FPGA IC chips 200 and/or 201 and each of the first and second groups of small input/output (SIO) circuits 214 of its NVM IC chip 250 or said either may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts, 0.7 volts or 0.5 volts and/or a voltage swing equal to or smaller than 1.2 volts, 1 volt, 0.8 volts, 0.7 volts or 0.5 volts, for example. Next, the memory cells 490 of one of the first type of field programmable logic cells or elements (LCEs) 2014, as illustrated in FIG. 1A, of said any of its FPGA IC chips 200 and/or 201 or the memory cells of one of the second or third type of field programmable logic cells or elements (LCEs) 2014, as illustrated in FIGS. 1B-1C, of said any of its FPGA IC chips 200 and/or 201 may store therein data associated with the first CPM data to be programmed, configured or reconfigured in accordance with the first CPM data, the memory cell(s) 362 of the first type of field programmable switch cells 379, as illustrated in FIG. 2A, of said any of its FPGA IC chips 200 and/or 201 or the four sets of memory cell(s) 362 of the second type of field programmable switch cells 379, as illustrated in FIG. 2B, of said any of its FPGA IC chips 200 and/or 201 may store therein data associated with the first CPM data to be programmed, configured or reconfigured in accordance with the first CPM data and/or the memory cell 398 of each of the field programmable switch units 711 of the field programmable switch matrix 710, as illustrated in FIG. 2C, of said any of its FPGA IC chips 200 and/or 201 may store therein data, i.e., programming codes, password or encryption/decryption codes, associated with the first decrypted CPM data to be programmed, configured or reconfigured in accordance with the first decrypted CPM data. Furthermore, each of the first group of small input/output (SIO) circuits 209 of said any of its FPGA IC chips 200 and/or 201 may have a third small driver or metal input/output (I/O) pad coupling to a third small receiver or metal input/output (I/O) pad of one of the second group of small input/output (SIO) circuits 214 of its NVM IC chip 250 or said either via another non-programmable interconnect 364 of its inter-chip interconnects 371 for passing second CPM data, associated with data, i.e., programming codes, password or encryption/decryption codes, stored (1) in the memory cells 490 of one of the first type of field programmable logic cells or elements (LCEs) 2014, as illustrated in FIG. 1A, of said any of its FPGA IC chips 200 and/or 201 or the memory cells of one of the second or third type of field programmable logic cell or elements (LCEs) 2014, as illustrated in FIGS. 1B-1C, of said any of its FPGA IC chips 200 and/or 201, (2) in the memory cell(s) 362 of the first type of field programmable switch cells 379, as illustrated in FIG. 2A, of said any of its FPGA IC chips 200 and/or 201 or the four sets of memory cell(s) 362 of the second type of field programmable switch cells 379, as illustrated in FIG. 2B, of said any of its FPGA IC chips 200 and/or 201 and/or (3) in the memory cell 398 of each of the field programmable switch units 711 of the field programmable switch matrix 710, as illustrated in FIG. 2C, of said any of its FPGA IC chips 200 and/or 201, from the third small driver to the third small receiver to be stored in another of the non-volatile memory cells (NVMCs) 261 of its NVM IC chip 250 or said either. Next, each of the first group of small input/output (SIO) circuits 214 of its NVM IC chip 250 or said either may have a fourth small driver or metal input/output (I/O) pad coupling to a fourth small receiver, i.e., input buffer 271 as seen in FIG. 5H, or metal input/output (I/O) pad of one of the small input/output (SIO) circuits 203 of the small-input/output (I/O) block of said any of its auxiliary IC chips 411 via another non-programmable interconnect 364 of its inter-chip interconnects 371 for passing the second CPM data from the fourth small driver to the fourth small receiver. Next, the second CPM data may be shift by the voltage-level shift-up circuit 206, as seen in FIG. 5H, of one of the voltage-level shift (VLS) circuits 205 of the voltage-level shift block of said any of its auxiliary IC chips 411 to be carried with the voltage VddH of high-voltage power supply. Each of the large input/output (LIO) circuits 341 of the large-input/output (I/O) block of said any of its auxiliary IC chips 411 may have the large driver, i.e., output buffer 274 as seen in FIG. 5H, or metal input/output (I/O) pad for driving or transmitting the second CPM data to a circuit 340 external of said each of the first type of FPMCPs 300 for the first and second alternatives.

Referring to FIGS. 5A-1, 5A-2 and 5F, for each of the first type of FPMCPs 300 for the first and second alternatives, in a seventh aspect one of the large input/output (LIO) circuits 341 of the large-input/output (I/O) block of any of its auxiliary IC chips 411 may have a large receiver, i.e., input buffer 273 as seen in FIG. 5I, or metal input/output (I/O) pad for receiving first encrypted CPM data from a circuit 340 external of said each of the first type of FPMCPs 300 for the first and second alternatives. The first encrypted CPM data may be shift by the voltage-level shift-down circuit 207, as seen in FIG. 5I, of one of the voltage-level shift (VLS) circuits 205 of the voltage-level shift block of said any of its auxiliary IC chips 411 to be carried with the voltage VddL of low-voltage power supply. Next, each of the small input/output (SIO) circuits 203 of the small-input/output (I/O) block of said any of its auxiliary IC chips 411 may have a first small driver, i.e., output buffer 272 as seen in FIG. 5I, or metal input/output (I/O) pad coupling to a first small receiver or metal input/output (I/O) pad of one of a first group of small input/output (SIO) circuits 214 of its NVM IC chip 250 or either via a non-programmable interconnect 364 of its inter-chip interconnects 371 for passing the first encrypted CPM data from the first small driver to the first small receiver. Its NVM IC chip 250 or said either may include a cryptography block configured to decrypt the first encrypted CPM data as first decrypted CPM data to be stored in one of multiple non-volatile memory cells (NVMCs) 261 of its NVM IC chip 250 or said either. A second group of small input/output (SIO) circuits 214 of its NVM IC chip 250 or said either may have a second small driver or metal input/output (I/O) pad coupling to a second small receiver or metal input/output (I/O) pad of one of a first group of small input/output (SIO) circuits 209 of any of its FPGA IC chips 200 and/or 201 via another non-programmable interconnect 364 of its inter-chip interconnects 371 for passing the first decrypted CPM data from the second small driver to the second small receiver, wherein each of the first group of small input/output (SIO) circuits 209 of said any of its FPGA IC chips 200 and/or 201 and each of the first and second groups of small input/output (SIO) circuits 214 of its NVM IC chip 250 or said either may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts, 0.7 volts or 0.5 volts and/or a voltage swing equal to or smaller than 1.2 volts, 1 volt, 0.8 volts, 0.7 volts or 0.5 volts, for example. Next, the memory cells 490 of one of the first type of field programmable logic cells or elements (LCEs) 2014, as illustrated in FIG. 1A, of said any of its FPGA IC chips 200 and/or 201 or the memory cells of one of the second or third type of field programmable logic cells or elements (LCEs) 2014, as illustrated in FIGS. 1B-1C, of said any of its FPGA IC chips 200 and/or 201 may store therein data associated with the first decrypted CPM data to be programmed, configured or reconfigured in accordance with the first decrypted CPM data, the memory cell(s) 362 of the first type of field programmable switch cells 379, as illustrated in FIG. 2A, of said any of its FPGA IC chips 200 and/or 201 or the four sets of memory cell(s) 362 of the second type of field programmable switch cells 379, as illustrated in FIG. 2B, of said any of its FPGA IC chips 200 and/or 201 may store therein data associated with the first decrypted CPM data to be programmed, configured or reconfigured in accordance with the first decrypted CPM data and/or the memory cell 398 of each of the field programmable switch units 711 of the field programmable switch matrix 710, as illustrated in FIG. 2C, of said any of its FPGA IC chips 200 and/or 201 may store therein data, i.e., programming codes, password or encryption/decryption codes, associated with the first decrypted CPM data to be programmed, configured or reconfigured in accordance with the first decrypted CPM data. Furthermore, each of the first group of small input/output (SIO) circuits 209 of said any of its FPGA IC chips 200 and/or 201 may have a third small driver or metal input/output (I/O) pad coupling to a third small receiver or metal input/output (I/O) pad of one of the second group of small input/output (SIO) circuits 214 of its NVM IC chip 250 or said either via another non-programmable interconnect 364 of its inter-chip interconnects 371 for passing second CPM data, associated with data, i.e., programming codes, password or encryption/decryption codes, stored (1) in the memory cells 490 of one of the first type of field programmable logic cells or elements (LCEs) 2014, as illustrated in FIG. 1A, of said any of its FPGA IC chips 200 and/or 201 or the memory cells of one of the second or third type of field programmable logic cell or elements (LCEs) 2014, as illustrated in FIGS. 1B-1C, of said any of its FPGA IC chips 200 and/or 201, (2) in the memory cell(s) 362 of the first type of field programmable switch cells 379, as illustrated in FIG. 2A, of said any of its FPGA IC chips 200 and/or 201 or the four sets of memory cell(s) 362 of the second type of field programmable switch cells 379, as illustrated in FIG. 2B, of said any of its FPGA IC chips 200 and/or 201 and/or (3) in the memory cell 398 of each of the field programmable switch units 711 of the field programmable switch matrix 710, as illustrated in FIG. 2C, of said any of its FPGA IC chips 200 and/or 201, from the third small driver to the third small receiver to be stored in another of the non-volatile memory cells (NVMCs) 261 of its NVM IC chip 250 or said either. Next, the second CPM data may be encrypted by the cryptography block of its NVM IC chip 250 or said either as second encrypted CPM data. Next, each of the first group of small input/output (SIO) circuits 214 of its NVM IC chip 250 or said either may have a fourth small driver or metal input/output (I/O) pad coupling to a fourth small receiver, i.e., input buffer 271 as seen in FIG. 5H, or metal input/output (I/O) pad of one of the small input/output (SIO) circuits 203 of the small-input/output (I/O) block of said any of its auxiliary IC chips 411 via another non-programmable interconnect 364 of its inter-chip interconnects 371 for passing the second encrypted CPM data from the fourth small driver to the fourth small receiver. Next, the second encrypted CPM data may be shift by the voltage-level shift-up circuit 206, as seen in FIG. 5H, of one of the voltage-level shift (VLS) circuits 205 of the voltage-level shift block of said any of its auxiliary IC chips 411 to be carried with the voltage VddH of high-voltage power supply. Each of the large input/output (LIO) circuits 341 of the large-input/output (I/O) block of said any of its auxiliary IC chips 411 may have the large driver, i.e., output buffer 274 as seen in FIG. 5H, or metal input/output (I/O) pad for driving or transmitting the second encrypted CPM data to a circuit 340 external of said each of the first type of FPMCPs 300 for the first and second alternatives.

Referring to FIGS. 5A-1, 5A-2 and 5F, for each of the first type of FPMCPs 300 for the first and second alternatives, in an eighth aspect one of the large input/output (LIO) circuits 341 of the large-input/output (I/O) block of any of its auxiliary IC chips 411 may have a large receiver, i.e., input buffer 273 as seen in FIG. 5I, or metal input/output (I/O) pad for receiving first encrypted CPM data from a circuit 340 external of said each of the first type of FPMCPs 300 for the first and second alternatives. The first encrypted CPM data may be shift by the voltage-level shift-down circuit 207, as seen in FIG. 5I, of one of the voltage-level shift (VLS) circuits 205 of the voltage-level shift block of said any of its auxiliary IC chips 411 to be carried with the voltage VddL of low-voltage power supply. Next, each of the small input/output (SIO) circuits 203 of the small-input/output (I/O) block of said any of its auxiliary IC chips 411 may have a first small driver, i.e., output buffer 272 as seen in FIG. 5I, or metal input/output (I/O) pad coupling to a first small receiver or metal input/output (I/O) pad of one of a first group of small input/output (SIO) circuits 214 of its NVM IC chip 250 or either via a non-programmable interconnect 364 of its inter-chip interconnects 371 for passing the first encrypted CPM data from the first small driver to the first small receiver to be stored in one of multiple non-volatile memory cells (NVMCs) 261 of its NVM IC chip 250 or said either. A second group of small input/output (SIO) circuits 214 of its NVM IC chip 250 or said either may have a second small driver or metal input/output (I/O) pad coupling to a second small receiver or metal input/output (I/O) pad of one of a first group of small input/output (SIO) circuits 209 of any of its FPGA IC chips 200 and/or 201 via another non-programmable interconnect 364 of its inter-chip interconnects 371 for passing the first encrypted CPM data from the second small driver to the second small receiver, wherein each of the first group of small input/output (SIO) circuits 209 of said any of its FPGA IC chips 200 and/or 201 and each of the first and second groups of small input/output (SIO) circuits 214 of its NVM IC chip 250 or said either may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts, 0.7 volts or 0.5 volts and/or a voltage swing equal to or smaller than 1.2 volts, 1 volt, 0.8 volts, 0.7 volts or 0.5 volts, for example. Next, said any of its FPGA IC chips 200 and/or 201 may include a cryptography block configured to decrypt the first encrypted CPM data as first decrypted CPM data. The memory cells 490 of one of the first type of field programmable logic cells or elements (LCEs) 2014, as illustrated in FIG. 1A, of said any of its FPGA IC chips 200 and/or 201 or the memory cells of one of the second or third type of field programmable logic cells or elements (LCEs) 2014, as illustrated in FIGS. 1B-1C, of said any of its FPGA IC chips 200 and/or 201 may store therein data associated with the first decrypted CPM data to be programmed, configured or reconfigured in accordance with the first decrypted CPM data, the memory cell(s) 362 of the first type of field programmable switch cells 379, as illustrated in FIG. 2A, of said any of its FPGA IC chips 200 and/or 201 or the four sets of memory cell(s) 362 of the second type of field programmable switch cells 379, as illustrated in FIG. 2B, of said any of its FPGA IC chips 200 and/or 201 may store therein data associated with the first decrypted CPM data to be programmed, configured or reconfigured in accordance with the first decrypted CPM data and/or the memory cell 398 of each of the field programmable switch units 711 of the field programmable switch matrix 710, as illustrated in FIG. 2C, of said any of its FPGA IC chips 200 and/or 201 may store therein data, i.e., programming codes, password or encryption/decryption codes, associated with the first decrypted CPM data to be programmed, configured or reconfigured in accordance with the first decrypted CPM data. Furthermore, second CPM data, associated with data, i.e., programming codes, password or encryption/decryption codes, stored (1) in the memory cells 490 of one of the first type of field programmable logic cells or elements (LCEs) 2014, as illustrated in FIG. 1A, of said any of its FPGA IC chips 200 and/or 201 or the memory cells of one of the second or third type of field programmable logic cell or elements (LCEs) 2014, as illustrated in FIGS. 1B-1C, of said any of its FPGA IC chips 200 and/or 201, (2) in the memory cell(s) 362 of the first type of field programmable switch cells 379, as illustrated in FIG. 2A, of said any of its FPGA IC chips 200 and/or 201 or the four sets of memory cell(s) 362 of the second type of field programmable switch cells 379, as illustrated in FIG. 2B, of said any of its FPGA IC chips 200 and/or 201 and/or (3) in the memory cell 398 of each of the field programmable switch units 711 of the field programmable switch matrix 710, as illustrated in FIG. 2C, of said any of its FPGA IC chips 200 and/or 201, may be encrypted by the cryptography block of said any of its FPGA IC chips 200 and/or 201 as second encrypted CPM data. Each of the first group of small input/output (SIO) circuits 209 of said any of its FPGA IC chips 200 and/or 201 may have a third small driver or metal input/output (I/O) pad coupling to a third small receiver or metal input/output (I/O) pad of one of the second group of small input/output (SIO) circuits 214 of its NVM IC chip 250 or said either via another non-programmable interconnect 364 of its inter-chip interconnects 371 for passing the second encrypted CPM data from the third small driver to the third small receiver to be stored in another of the non-volatile memory cells (NVMCs) 261 of its NVM IC chip 250 or said either. Next, each of the first group of small input/output (SIO) circuits 214 of its NVM IC chip 250 or said either may have a fourth small driver or metal input/output (I/O) pad coupling to a fourth small receiver, i.e., input buffer 271 as seen in FIG. 5H, or metal input/output (I/O) pad of one of the small input/output (SIO) circuits 203 of the small-input/output (I/O) block of said any of its auxiliary IC chips 411 via another non-programmable interconnect 364 of its inter-chip interconnects 371 for passing the second encrypted CPM data from the fourth small driver to the fourth small receiver. Next, the second encrypted CPM data may be shift by the voltage-level shift-up circuit 206, as seen in FIG. 5H, of one of the voltage-level shift (VLS) circuits 205 of the voltage-level shift block of said any of its auxiliary IC chips 411 to be carried with the voltage VddH of high-voltage power supply. Each of the large input/output (LIO) circuits 341 of the large-input/output (I/O) block of said any of its auxiliary IC chips 411 may have the large driver, i.e., output buffer 274 as seen in FIG. 5H, or metal input/output (I/O) pad for driving or transmitting the second encrypted CPM data to a circuit 340 external of said each of the first type of FPMCPs 300 for the first and second alternatives.

Referring to FIGS. 5A-1, 5A-2 and 5G, for each of the first type of FPMCPs 300 for the first and second alternatives, in a ninth aspect its NVM IC chip 250 or either may have multiple large input/output (LIO) circuits 342, each of which may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Each of the large input/output (LIO) circuits 342 of its NVM IC chip 250 or said either may have a large receiver or metal input/output (I/O) pad for receiving first encrypted CPM data from a circuit 340 external of said each of the first type of FPMCPs 300 for the first and second alternatives. Next, its NVM IC chip 250 or said either may include multiple voltage-level shift (VLS) circuits 205 each provided with a voltage-level shift-down circuit, having the same circuit as one illustrated in FIG. 5I, to shift the first encrypted CPM data to be carried with the voltage VddL of low-voltage power supply. Next, its NVM IC chip 250 or said either may further include a cryptography block configured to decrypt the first encrypted CPM data as first decrypted CPM data, carried with the voltage VddL of low-voltage power supply, to be stored in one of multiple non-volatile memory cells (NVMCs) 261 of its NVM IC chip 250 or said either. Each of multiple small input/output (SIO) circuits 214 of its NVM IC chip 250 or said either may have a first small driver or metal input/output (I/O) pad coupling to a first small receiver or metal input/output (I/O) pad of one of a first group of small input/output (SIO) circuits 209 of any of its FPGA IC chips 200 and/or 201 via a non-programmable interconnect 364 of its inter-chip interconnects 371 for passing the first decrypted CPM data from the first small driver to the first small receiver, wherein each of the first group of small input/output (SIO) circuits 209 of said any of its FPGA IC chips 200 and/or 201 and each of the small input/output (SIO) circuits 214 of its NVM IC chip 250 or said either may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts, 0.7 volts or 0.5 volts and/or a voltage swing equal to or smaller than 1.2 volts, 1 volt, 0.8 volts, 0.7 volts or 0.5 volts, for example. Next, the memory cells 490 of one of the first type of field programmable logic cells or elements (LCEs) 2014, as illustrated in FIG. 1A, of said any of its FPGA IC chips 200 and/or 201 or the memory cells of one of the second or third type of field programmable logic cells or elements (LCEs) 2014, as illustrated in FIGS. 1B-1C, of said any of its FPGA IC chips 200 and/or 201 may store therein data associated with the first decrypted CPM data to be programmed, configured or reconfigured in accordance with the first decrypted CPM data, the memory cell(s) 362 of the first type of field programmable switch cells 379, as illustrated in FIG. 2A, of said any of its FPGA IC chips 200 and/or 201 or the four sets of memory cell(s) 362 of the second type of field programmable switch cells 379, as illustrated in FIG. 2B, of said any of its FPGA IC chips 200 and/or 201 may store therein data, i.e., programming codes, password or encryption/decryption codes, associated with the first decrypted CPM data to be programmed, configured or reconfigured in accordance with the first decrypted CPM data and/or the memory cell 398 of each of the field programmable switch units 711 of the field programmable switch matrix 710, as illustrated in FIG. 2C, of said any of its FPGA IC chips 200 and/or 201 may store therein data associated with the first decrypted CPM data to be programmed, configured or reconfigured in accordance with the first decrypted CPM data. Furthermore, each of the first group of small input/output (SIO) circuits 209 of said any of its FPGA IC chips 200 and/or 201 may have a second small driver or metal input/output (I/O) pad coupling to a second small receiver or metal input/output (I/O) pad of one of the small input/output (SIO) circuits 214 of its NVM IC chip 250 or said either via another non-programmable interconnect 364 of its inter-chip interconnects 371 for passing second CPM data, associated with data, i.e., programming codes, password or encryption/decryption codes, stored (1) in the memory cells 490 of one of the first type of field programmable logic cells or elements (LCEs) 2014, as illustrated in FIG. 1A, of said any of its FPGA IC chips 200 and/or 201 or the memory cells of one of the second or third type of field programmable logic cell or elements (LCEs) 2014, as illustrated in FIGS. 1B-1C, of said any of its FPGA IC chips 200 and/or 201, (2) in the memory cell(s) 362 of the first type of field programmable switch cells 379, as illustrated in FIG. 2A, of said any of its FPGA IC chips 200 and/or 201 or the four sets of memory cell(s) 362 of the second type of field programmable switch cells 379, as illustrated in FIG. 2B, of said any of its FPGA IC chips 200 and/or 201 and/or (3) in the memory cell 398 of each of the field programmable switch units 711 of the field programmable switch matrix 710, as illustrated in FIG. 2C, of said any of its FPGA IC chips 200 and/or 201, from the second small driver to the second small receiver to be stored in another of the non-volatile memory cells (NVMCs) 261 of its NVM IC chip 250 or said either. Next, the second CPM data may be encrypted by the cryptography block of its NVM IC chip 250 or said either as second encrypted CPM data. Next, each of the voltage-level shift (VLS) circuits 205 of its NVM IC chip 250 or said either may include a voltage-level shift-up circuit, having the same circuit as one illustrated in FIG. 5H, to shift the second encrypted CPM data to be carried with the voltage VddH of high-voltage power supply. Next, each of the large input/output (LIO) circuits 342 of its NVM IC chip 250 or said either may have a large driver or metal input/output (I/O) pad for driving or transmitting the second encrypted CPM data to a circuit 340 external of said each of the first type of FPMCPs 300 for the first and second alternatives.

Referring to FIGS. 5A-1, 5A-2 and 5G, for each of the first type of FPMCPs 300 for the first and second alternatives, in a tenth aspect its NVM IC chip 250 or either may have multiple large input/output (LIO) circuits 342, each of which may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Each of the large input/output (LIO) circuits 342 of its NVM IC chip 250 or said either may have a large receiver or metal input/output (I/O) pad for receiving first CPM data from a circuit 340 external of said each of the first type of FPMCPs 300 for the first and second alternatives. Next, its NVM IC chip 250 or said either may include multiple voltage-level shift (VLS) circuits 205 each provided with a voltage-level shift-down circuit, having the same circuit as one illustrated in FIG. 5I, to shift the first CPM data to be carried with the voltage VddL of low-voltage power supply to be stored in one of multiple non-volatile memory cells (NVMCs) 261 of its NVM IC chip 250 or said either. Each of multiple small input/output (SIO) circuits 214 of its NVM IC chip 250 or said either may have a first small driver or metal input/output (I/O) pad coupling to a first small receiver or metal input/output (I/O) pad of one of a first group of small input/output (SIO) circuits 209 of any of its FPGA IC chips 200 and/or 201 via a non-programmable interconnect 364 of its inter-chip interconnects 371 for passing the first CPM data from the first small driver to the first small receiver, wherein each of the first group of small input/output (SIO) circuits 209 of said any of its FPGA IC chips 200 and/or 201 and each of the small input/output (SIO) circuits 214 of its NVM IC chip 250 or said either may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts, 0.7 volts or 0.5 volts and/or a voltage swing equal to or smaller than 1.2 volts, 1 volt, 0.8 volts, 0.7 volts or 0.5 volts, for example. Next, the memory cells 490 of one of the first type of field programmable logic cells or elements (LCEs) 2014, as illustrated in FIG. 1A, of said any of its FPGA IC chips 200 and/or 201 or the memory cells of one of the second or third type of field programmable logic cells or elements (LCEs) 2014, as illustrated in FIGS. 1B-1C, of said any of its FPGA IC chips 200 and/or 201 may store therein data associated with the first CPM data to be programmed, configured or reconfigured in accordance with the first CPM data, the memory cell(s) 362 of the first type of field programmable switch cells 379, as illustrated in FIG. 2A, of said any of its FPGA IC chips 200 and/or 201 or the four sets of memory cell(s) 362 of the second type of field programmable switch cells 379, as illustrated in FIG. 2B, of said any of its FPGA IC chips 200 and/or 201 may store therein data, i.e., programming codes, password or encryption/decryption codes, associated with the first CPM data to be programmed, configured or reconfigured in accordance with the first CPM data and/or the memory cell 398 of each of the field programmable switch units 711 of the field programmable switch matrix 710, as illustrated in FIG. 2C, of said any of its FPGA IC chips 200 and/or 201 may store therein data associated with the first decrypted CPM data to be programmed, configured or reconfigured in accordance with the first decrypted CPM data. Furthermore, each of the first group of small input/output (SIO) circuits 209 of said any of its FPGA IC chips 200 and/or 201 may have a second small driver or metal input/output (I/O) pad coupling to a second small receiver or metal input/output (I/O) pad of one of the small input/output (SIO) circuits 214 of its NVM IC chip 250 or said either via another non-programmable interconnect 364 of its inter-chip interconnects 371 for passing second CPM data, associated with data, i.e., programming codes, password or encryption/decryption codes, stored (1) in the memory cells 490 of one of the first type of field programmable logic cells or elements (LCEs) 2014, as illustrated in FIG. 1A, of said any of its FPGA IC chips 200 and/or 201 or the memory cells of one of the second or third type of field programmable logic cell or elements (LCEs) 2014, as illustrated in FIGS. 1B-1C, of said any of its FPGA IC chips 200 and/or 201, (2) in the memory cell(s) 362 of the first type of field programmable switch cells 379, as illustrated in FIG. 2A, of said any of its FPGA IC chips 200 and/or 201 or the four sets of memory cell(s) 362 of the second type of field programmable switch cells 379, as illustrated in FIG. 2B, of said any of its FPGA IC chips 200 and/or 201 and/or (3) in the memory cell 398 of each of the field programmable switch units 711 of the field programmable switch matrix 710, as illustrated in FIG. 2C, of said any of its FPGA IC chips 200 and/or 201, from the second small driver to the second small receiver to be stored in another of the non-volatile memory cells (NVMCs) 261 of its NVM IC chip 250 or said either. Next, each of the voltage-level shift (VLS) circuits 205 of its NVM IC chip 250 or said either may include a voltage-level shift-up circuit, having the same circuit as one illustrated in FIG. 5H, to shift the second CPM data to be carried with the voltage VddH of high-voltage power supply. Next, each of the large input/output (LIO) circuits 342 of its NVM IC chip 250 or said either may have a large driver or metal input/output (I/O) pad for driving or transmitting the second CPM data to a circuit 340 external of said each of the first type of FPMCPs 300 for the first and second alternatives.

Referring to FIGS. 5A-1, 5A-2 and 5G, for each of the first type of FPMCPs 300 for the first and second alternatives, in an eleventh aspect its NVM IC chip 250 or either may have multiple large input/output (LIO) circuits 342, each of which may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Each of the large input/output (LIO) circuits 342 of its NVM IC chip 250 or said either may have a large receiver or metal input/output (I/O) pad for receiving first encrypted CPM data from a circuit 340 external of said each of the first type of FPMCPs 300 for the first and second alternatives. Next, its NVM IC chip 250 or said either may include multiple voltage-level shift (VLS) circuits 205 each provided with a voltage-level shift-down circuit, having the same circuit as one illustrated in FIG. 5I, to shift the first encrypted CPM data to be carried with the voltage VddL of low-voltage power supply to be stored in one of multiple non-volatile memory cells (NVMCs) 261 of its NVM IC chip 250 or said either. Each of multiple small input/output (SIO) circuits 214 of its NVM IC chip 250 or said either may have a first small driver or metal input/output (I/O) pad coupling to a first small receiver or metal input/output (I/O) pad of one of a first group of small input/output (SIO) circuits 209, or input/output (I/O) pads, of any of its FPGA IC chips 200 and/or 201 via a non-programmable interconnect 364 of its inter-chip interconnects 371 for passing the first encrypted CPM data from the first small driver to the first small receiver, wherein each of the first group of small input/output (SIO) circuits 209 of said any of its FPGA IC chips 200 and/or 201 and each of the small input/output (SIO) circuits 214 of its NVM IC chip 250 or said either may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts, 0.7 volts or 0.5 volts and/or a voltage swing equal to or smaller than 1.2 volts, 1 volt, 0.8 volts, 0.7 volts or 0.5 volts, for example. Next, said any of its FPGA IC chips 200 and/or 201 may further include a cryptography block configured to decrypt the first encrypted CPM data as first decrypted CPM data. Next, the memory cells 490 of one of the first type of field programmable logic cells or elements (LCEs) 2014, as illustrated in FIG. 1A, of said any of its FPGA IC chips 200 and/or 201 or the memory cells of one of the second or third type of field programmable logic cells or elements (LCEs) 2014, as illustrated in FIGS. 1B-1C, of said any of its FPGA IC chips 200 and/or 201 may store therein data associated with the first decrypted CPM data to be programmed, configured or reconfigured in accordance with the first decrypted CPM data, the memory cell(s) 362 of the first type of field programmable switch cells 379, as illustrated in FIG. 2A, of said any of its FPGA IC chips 200 and/or 201 or the four sets of memory cell(s) 362 of the second type of field programmable switch cells 379, as illustrated in FIG. 2B, of said any of its FPGA IC chips 200 and/or 201 may store therein data associated with the first decrypted CPM data to be programmed, configured or reconfigured in accordance with the first decrypted CPM data and/or the memory cell 398 of each of the field programmable switch units 711 of the field programmable switch matrix 710, as illustrated in FIG. 2C, of said any of its FPGA IC chips 200 and/or 201 may store therein data, i.e., programming codes, password or encryption/decryption codes, associated with the first decrypted CPM data to be programmed, configured or reconfigured in accordance with the first decrypted CPM data. Furthermore, second CPM data, associated with data, i.e., programming codes, password or encryption/decryption codes, stored (1) in the memory cells 490 of one of the first type of field programmable logic cells or elements (LCEs) 2014, as illustrated in FIG. 1A, of said any of its FPGA IC chips 200 and/or 201 or the memory cells of one of the second or third type of field programmable logic cell or elements (LCEs) 2014, as illustrated in FIGS. 1B-1C, of said any of its FPGA IC chips 200 and/or 201, (2) in the memory cell(s) 362 of the first type of field programmable switch cells 379, as illustrated in FIG. 2A, of said any of its FPGA IC chips 200 and/or 201 or the four sets of memory cell(s) 362 of the second type of field programmable switch cells 379, as illustrated in FIG. 2B, of said any of its FPGA IC chips 200 and/or 201 and/or (3) in the memory cell 398 of each of the field programmable switch units 711 of the field programmable switch matrix 710, as illustrated in FIG. 2C, of said any of its FPGA IC chips 200 and/or 201, may be encrypted by the cryptography block of said any of its FPGA IC chips 200 and/or 201 as second encrypted CPM data. Next, each of the first group of small input/output (SIO) circuits 209 of said any of its FPGA IC chips 200 and/or 201 may have a second small driver or metal input/output (I/O) pad coupling to a second small receiver or metal input/output (I/O) pad of one of the second group of small input/output (SIO) circuits 214 of its NVM IC chip 250 or said either via another non-programmable interconnect 364 of its inter-chip interconnects 371 for passing the second encrypted CPM data from the second small driver to the second small receiver to be stored in another of the non-volatile memory cells (NVMCs) 261 of its NVM IC chip 250 or said either. Next, each of the voltage-level shift (VLS) circuits 205 of its NVM IC chip 250 or said either may include a voltage-level shift-up circuit, having the same circuit as one illustrated in FIG. 5H, to shift the second encrypted CPM data to be carried with the voltage VddH of high-voltage power supply. Next, each of the large input/output (LIO) circuits 342 of its NVM IC chip 250 or said either may have a large driver or metal input/output (I/O) pad for driving or transmitting the second encrypted CPM data to a circuit 340 external of said each of the first type of FPMCPs 300 for the first and second alternatives.

Referring to FIGS. 5A-5 and 5K, for the first type of FPMCP 300 for the fifth alternative, in a twelfth aspect for a configuration mode its NVM IC chip 250 may have multiple large input/output (LIO) circuits 342, each of which may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Each of a first group of the large input/output (LIO) circuits 342 of its NVM IC chip 250 may have a first large receiver or metal input/output (I/O) pad for receiving first encrypted CPM data from a circuit 340 external of the first type of FPMCP 300 for the fifth alternative to be stored in one of a first group of non-volatile memory cells (NVMCs) 261 of its NVM IC chip 250. Each of a second group of the large input/output (LIO) circuits 342 of its NVM IC chip 250 may have a first large driver coupling to a second large receiver, i.e., input buffer 273 as seen in FIG. 5I, or metal input/output (I/O) pad of one of the large input/output (LIO) circuits 341 of the large input/output (I/O) block of any of its auxiliary IC chips 411 via a non-programmable interconnect 364 of its inter-chip interconnects 371 for passing the first encrypted CPM data from the first large driver to the second large receiver. Alternatively, each of the large input/output (LIO) circuits 341 of the large input/output (I/O) block of said any of its auxiliary IC chips 411 may have the second large receiver or metal input/output (I/O) pad for receiving the first encrypted CPM data from a circuit 340 external of the first type of FPMCP 300 for the fifth alternative. Next, the first encrypted CPM data may be shift by the voltage-level shift-down circuit 207, as seen in FIG. 5I, of one of the voltage-level shift (VLS) circuits 205 of the voltage-level shift block of said any of its auxiliary IC chips 411 to be carried with the voltage VddL of low-voltage power supply and then decrypted by the cryptography block of said any of its auxiliary IC chips 411 as first decrypted CPM data carried with the voltage VddL of low-voltage power supply. Next, each of the small input/output (SIO) circuits 203 of the small-input/output (I/O) block of said any of its auxiliary IC chips 411 may have a first small driver, i.e., output buffer 272 as seen in FIG. 5I, or metal input/output (I/O) pad coupling to a first small receiver or metal input/output (I/O) pad of one of a first group of small input/output (SIO) circuits 217 of its VM IC chip 255 via another non-programmable interconnect 364 of its inter-chip interconnects 371 for passing the first decrypted CPM data from the first small driver to the first small receiver to be stored in one of a first group of volatile memory cells 218, such as dynamic random-access memory (DRAM) or static random-access memory (SRAM) cells, of its VM IC chip 255, wherein communication between the small input/output (SIO) circuits 203 of the small-input/output (I/O) block of said any of its auxiliary IC chips 411 and the first group of small input/output (SIO) circuits 217 of its VM IC chip 255 may be in accordance with a protocol of Serial Advanced Technology Attachment (SATA) for data serial transmission. Each of a second group of the small input/output (SIO) circuits 217 of its VM IC chip 255 may have a second small driver coupling to a second small receiver or metal input/output (I/O) pad of one of a first group of small input/output (SIO) circuits 209 of any of its FPGA IC chips 200 via another non-programmable interconnect 364 of its inter-chip interconnects 371 for passing the first decrypted CPM data from the second small driver to the second small receiver, wherein communication between the second group of the small input/output (SIO) circuits 217 of its VM IC chip 255 and the first group of the small input/output (SIO) circuits 209 of said any of its FPGA IC chips 200 may be in accordance with a protocol of Peripheral Component Interconnect Express (PCIe) for data parallel transmission. Thus, the second group of the small input/output (SIO) circuits 217 of its VM IC chip 255 may have a data-bit width more than that of the first group of the small input/output (SIO) circuits 217 of its VM IC chip 255, wherein the data-bit width of the first group of the small input/output (SIO) circuits 217 of its VM IC chip 255 may be equal to or greater than 1 bit, 2 bits, 4 bits, 8 bits, 16 bits or 32 bits, and the data-bit width of the second group of the small input/output (SIO) circuits 217 of its VM IC chip 255 may be equal to or greater than 32 bits, 64 bits, 128 bits or 256 bits, for example. It is noted that each of the small input/output (SIO) circuits 217 of its VM IC chip 255 and each of the small input/output (SIO) circuits 209 of said any of its FPGA IC chips 200 may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts, 0.7 volts or 0.5 volts and/or a voltage swing equal to or smaller than 1.2 volts, 1 volt, 0.8 volts, 0.7 volts or 0.5 volts, for example. Next, the memory cells 490 of one of the first type of field programmable logic cells or elements (LCEs) 2014, as illustrated in FIG. 1A, of said any of its FPGA IC chips 200 or the memory cells of one of the second or third type of field programmable logic cells or elements (LCEs) 2014, as illustrated in FIGS. 1B-1C, of said any of its FPGA IC chips 200 may store therein data associated with the first decrypted CPM data to be programmed, configured or reconfigured in accordance with the first decrypted CPM data, and/or the memory cell(s) 362 of the first type of field programmable switch cells 379, as illustrated in FIG. 2A, of said any of its FPGA IC chips 200 or the four sets of memory cell(s) 362 of the second type of field programmable switch cells 379, as illustrated in FIG. 2B, of said any of its FPGA IC chips 200 may store therein data associated with the first decrypted CPM data to be programmed, configured or reconfigured in accordance with the first decrypted CPM data. Furthermore, each of the first group of the small input/output (SIO) circuits 209 of said any of its FPGA IC chips 200 may have a third small driver or metal input/output (I/O) pad coupling to a third small receiver of one of the second group of the small input/output (SIO) circuits 217 of its VM IC chip 255 via another non-programmable interconnect 364 of its inter-chip interconnects 371 for passing second CPM data, associated with data stored (1) in the memory cells 490 of one of the first type of field programmable logic cells or elements (LCEs) 2014, as illustrated in FIG. 1A, of said any of its FPGA IC chips 200 or the memory cells of one of the second or third type of field programmable logic cell or elements (LCEs) 2014, as illustrated in FIGS. 1B-1C, of said any of its FPGA IC chips 200 and/or (2) in the memory cell(s) 362 of the first type of field programmable switch cells 379, as illustrated in FIG. 2A, of said any of its FPGA IC chips 200 or the four sets of memory cell(s) 362 of the second type of field programmable switch cells 379, as illustrated in FIG. 2B, of said any of its FPGA IC chips 200, from the third small driver to the third small receiver to be stored in another of the first group of the volatile memory cells 218 of its VM IC chip 255. Next, each of the first group of the small input/output (SIO) circuits 217 of its VM IC chip 255 may have a fourth small driver or metal input/output (I/O) pad coupling to a fourth small receiver, i.e., input buffer 271 as seen in FIG. 5H, or metal input/output (I/O) pad of one of the small input/output (SIO) circuits 203 of the small-input/output (I/O) block of said any of its auxiliary IC chips 411 via another non-programmable interconnect 364 of its inter-chip interconnects 371 for passing the second CPM data from the fourth small driver to the fourth small receiver. Next, the second CPM data may be encrypted by the cryptography block of said any of its auxiliary IC chips 411 as second encrypted CPM data and then the second encrypted CPM data may be shift by the voltage-level shift-up circuit 206, as seen in FIG. 5H, of one of the voltage-level shift (VLS) circuits 205 of the voltage-level shift block of said any of its auxiliary IC chips 411 to be carried with the voltage VddH of high-voltage power supply. Next, each of the large input/output (LIO) circuits 341 of the large input/output (I/O) block of said any of its auxiliary IC chips 411 may have a second large driver, i.e., output buffer 274 as seen in FIG. 5H, or metal input/output (I/O) pad coupling to a third large receiver or metal input/output (I/O) pad of one of the second group of the large input/output (LIO) circuits 342 of its NVM IC chip 250 via another non-programmable interconnect 364 of its inter-chip interconnects 371 for passing the second encrypted CPM data from the second large driver to the third large receiver to be stored in another of the first group of the non-volatile memory cells (NVMCs) 261 of its NVM IC chip 250, and then each of the first group of the large input/output (I/O) circuits 342 of its NVM IC chip 250 may have a third large driver for passing the second encrypted CPM data to a circuit 340 external of the first type of FPMCP 300 for the fifth alternative. Alternatively, each of the large input/output (LIO) circuits 341 of the large input/output (I/O) block of said any of its auxiliary IC chips 411 may have the second large driver or metal input/output (I/O) pad for driving or transmitting the second encrypted CPM data to a circuit 340 external of the first type of FPMCP 300 for the fifth alternative.

Referring to FIGS. 5A-5 and 5K, for the first type of FPMCP 300 for the fifth alternative, in the twelfth aspect for an operation mode each of the first group of the large input/output (LIO) circuits 342 of its NVM IC chip 250 may have the first large receiver or metal input/output (I/O) pad for receiving first operation data from a circuit 340 external of the first type of FPMCP 300 for the fifth alternative to be stored in one of a second group of non-volatile memory cells (NVMCs) 261 of its NVM IC chip 250. Each of the second group of the large input/output (LIO) circuits 342 of its NVM IC chip 250 may have the first large driver coupling to the second large receiver, i.e., input buffer 273 as seen in FIG. 5I, or metal input/output (I/O) pad of one of the large input/output (LIO) circuits 341 of the large input/output (I/O) block of said any of its auxiliary IC chips 411 for passing the first operation data from the first large driver to the second large receiver. Alternatively, each of the large input/output (LIO) circuits 341 of the large input/output (I/O) block of said any of its auxiliary IC chips 411 may have the second large receiver or metal input/output (I/O) pad for receiving the first operation data from a circuit 340 external of the first type of FPMCP 300 for the fifth alternative. Next, the first operation data may be shift by the voltage-level shift-down circuit 207, as seen in FIG. 5I, of one of the voltage-level shift (VLS) circuits 205 of the voltage-level shift block of said any of its auxiliary IC chips 411 to be carried with the voltage VddL of low-voltage power supply. Next, each of the small input/output (SIO) circuits 203 of the small-input/output (I/O) block of said any of its auxiliary IC chips 411 may have the first small driver, i.e., output buffer 272 as seen in FIG. 5I, or metal input/output (I/O) pad coupling to the first small receiver or metal input/output (I/O) pad of one of the first group of small input/output (SIO) circuits 217 of its VM IC chip 255 for passing the first operation data from the first small driver to the first small receiver to be stored in one of a second group of the volatile memory cells 218 of its VM IC chip 255. Each of the second group of the small input/output (SIO) circuits 217 of its VM IC chip 255 may have the second small driver coupling to the second small receiver or metal input/output (I/O) pad of one of the first group of small input/output (SIO) circuits 209 of said any of its FPGA IC chips 200 for passing the first operation data from the second small driver to the second small receiver. Next, one of the first type of field programmable logic cells or elements (LCEs) 2014, as illustrated in FIG. 1A, of said any of its FPGA IC chips 200 may have a piece of input data in its input data set, i.e., A0 and A1, which is associated with the first operation data, or one of the second or third type of field programmable logic cells or elements (LCEs) 2014, as illustrated in FIGS. 1B-1C, of said any of its FPGA IC chips 200 may have a piece of input data in its input data set, i.e., A0-A3, which is associated with the first operation data. Alternatively, one of the nodes N21 and N22 of the first type of field programmable switch cells 379, as illustrated in FIG. 2A, of said any of its FPGA IC chips 200 may have a piece of input data associated with the first operation data, or one of the nodes N23-N26 of the second type of field programmable switch cells 379, as illustrated in FIG. 2B, of said any of its FPGA IC chips 200 may have a piece of input data associated with the first operation data. Furthermore, each of the first group of the small input/output (SIO) circuits 209 of said any of its FPGA IC chips 200 may have the third small driver or metal input/output (I/O) pad coupling to the third small receiver of one of the second group of the small input/output (SIO) circuits 217 of its VM IC chip 255 for passing second operation data, associated with (1) the data output, i.e., Dout, of one of the first type of field programmable logic cells or elements (LCEs) 2014, as illustrated in FIG. 1A, of said any of its FPGA IC chips 200 or the data output, i.e., Dout, of one of the second or third type of field programmable logic cell or elements (LCEs) 2014, as illustrated in FIGS. 1B-1C, of said any of its FPGA IC chips 200 and/or (2) output data at one of the nodes N21 and N22 of the first type of field programmable switch cells 379, as illustrated in FIG. 2A, of said any of its FPGA IC chips 200 or output data at one of the nodes N23-N26 of the second type of field programmable switch cells 379, as illustrated in FIG. 2B, of said any of its FPGA IC chips 200, from the third small driver to the third small receiver to be stored in another of the second group of the volatile memory cells 218 of its VM IC chip 255. Next, each of the first group of the small input/output (SIO) circuits 217 of its VM IC chip 255 may have the fourth small driver or metal input/output (I/O) pad coupling to the fourth small receiver, i.e., input buffer 271 as seen in FIG. 5H, or metal input/output (I/O) pad of one of the small input/output (SIO) circuits 203 of the small-input/output (I/O) block of said any of its auxiliary IC chips 411 for passing the second operation data from the fourth small driver to the fourth small receiver. Next, the second operation data may be shift by the voltage-level shift-up circuit 206, as seen in FIG. 5H, of one of the voltage-level shift (VLS) circuits 205 of the voltage-level shift block of said any of its auxiliary IC chips 411 to be carried with the voltage VddH of high-voltage power supply. Next, each of the large input/output (LIO) circuits 341 of the large input/output (I/O) block of said any of its auxiliary IC chips 411 may have the second large driver, i.e., output buffer 274 as seen in FIG. 5H, or metal input/output (I/O) pad coupling to the third large receiver or metal input/output (I/O) pad of one of the second group of the large input/output (LIO) circuits 342 of its NVM IC chip 250 for passing the second operation data from the second large driver to the third large receiver to be stored in another of the second group of the non-volatile memory cells (NVMCs) 261 of its NVM IC chip 250, and then each of the first group of the large input/output (I/O) circuits 342 of its NVM IC chip 250 may have the third large driver for passing the second operation data to a circuit 340 external of the first type of FPMCP 300 for the fifth alternative. Alternatively, each of the large input/output (LIO) circuits 341 of the large input/output (I/O) block of said any of its auxiliary IC chips 411 may have the second large driver or metal input/output (I/O) pad for driving or transmitting the second operation data to a circuit 340 external of the first type of FPMCP 300 for the fifth alternative.

Further, referring to FIGS. 5A-5 and 5K, for the first type of FPMCP 300 for the fifth alternative, in the twelfth aspect for the operation mode each of the second group of the small input/output (SIO) circuits 217 of its VM IC chip 255 may have the second small driver coupling to a fifth small receiver or metal input/output (I/O) pad of one of small input/output (SIO) circuits of any of its computing IC chips, such as graphic-processing-unit (GPU) IC chips 269a, central-processing-unit (CPU) IC chip 269b and application-specific integrated-circuit (ASIC) IC chip, for passing the first operation data from the second small driver to the fifth small receiver via its inter-chip interconnects 371 to be stored in one of volatile memory cells, such as dynamic random-access memory (DRAM) or static random-access memory (SRAM) cells, of said any of its computing IC chips and to be computed by a computing circuit of said any of its computing IC chips. Next, third operation data resulted from the computing circuit of said any of its computing IC chips may be stored in another of the volatile memory cells of said any of its computing IC chips and passed from a fifth small driver or metal input/output (I/O) pad of one of the small input/output (SIO) circuits of said any of its computing IC chips to the third small receiver of one of the second group of the small input/output (SIO) circuits 217 of its VM IC chip 255 via its inter-chip interconnects 371 to be stored in another of the second group of the volatile memory cells 218 of its VM IC chip 255. Next, each of the first group of the small input/output (SIO) circuits 217 of its VM IC chip 255 may have the fourth small driver or metal input/output (I/O) pad coupling to the fourth small receiver, i.e., input buffer 271 as seen in FIG. 5H, or metal input/output (I/O) pad of one of the small input/output (SIO) circuits 203 of the small-input/output (I/O) block of said any of its auxiliary IC chips 411 for passing the third operation data from the fourth small driver to the fourth small receiver via its inter-chip interconnects 371. Next, the third operation data may be shift by the voltage-level shift-up circuit 206, as seen in FIG. 5H, of one of the voltage-level shift (VLS) circuits 205 of the voltage-level shift block of said any of its auxiliary IC chips 411 to be carried with the voltage VddH of high-voltage power supply. Next, each of the large input/output (LIO) circuits 341 of the large input/output (I/O) block of said any of its auxiliary IC chips 411 may have the second large driver, i.e., output buffer 274 as seen in FIG. 5H, or metal input/output (I/O) pad coupling to the third large receiver or metal input/output (I/O) pad of one of the second group of the large input/output (LIO) circuits 342 of its NVM IC chip 250 for passing the third operation data from the second large driver to the third large receiver via its inter-chip interconnects 371 to be stored in another of the second group of the non-volatile memory cells (NVMCs) 261 of its NVM IC chip 250, and then each of the first group of the large input/output (I/O) circuits 342 of its NVM IC chip 250 may have the third large driver for passing the third operation data to a circuit 340 external of the first type of FPMCP 300 for the fifth alternative. Alternatively, each of the large input/output (LIO) circuits 341 of the large input/output (I/O) block of said any of its auxiliary IC chips 411 may have the second large driver or metal input/output (I/O) pad for driving or transmitting the third operation data to a circuit 340 external of the first type of FPMCP 300 for the fifth alternative.

Referring to FIGS. 5A-1, 5A-2, 5A-5, 5E-5G and 5K, for each of the first type of FPMCPs 300 for the first, second and fifth alternatives in any aspect of the first through twelfth aspects as mentioned above, said any of its FPGA IC chips 200 and/or 201 may include a second group of small input/output (SIO) circuits 209 each provided with a small driver or receiver or metal input/output (I/O) pad coupling to any of the first type of field programmable logic cells or elements (LCEs) 2014, as illustrated in FIG. 1A, of said any of its FPGA IC chips 200 and/or 201, the second or third type of field programmable logic cell or elements (LCEs) 2014, as illustrated in FIGS. 1B-1C, of said any of its FPGA IC chips 200 and/or 201, the first or second type of field programmable switch cells 379, as illustrated in FIGS. 2A-2B, of said any of its FPGA IC chips 200 and/or 201 and/or the field programmable switch units 711 of the field programmable switch matrix 710, as illustrated in FIG. 2C, of said any of its FPGA IC chips 200 and/or 201 through one of the programmable interconnects 361 thereof and to a small driver or receiver or metal input/output (I/O) pad of any of multiple small input/output (SIO) circuits 216 of any of its semiconductor IC chips 100g through one of the programmable interconnects 361 of its inter-chip interconnects 371. Each of the second group of small input/output (SIO) circuits 209 of said any of its FPGA IC chips 200 and/or 201 and each of the small input/output (SIO) circuits 216 of said any of its semiconductor IC chips 100g may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts, 0.7 volts or 0.5 volts and/or a voltage swing equal to or smaller than 1.2 volts, 1 volt, 0.8 volts, 0.7 volts or 0.5 volts, for example. Said any of its semiconductor IC chips 100g may be one of its graphic-processing-unit (GPU) IC chips 269a, central-processing-unit (CPU) IC chip 269b, application-specific integrated-circuit (ASIC) chip or system-on-chip (SoC) chip 269c and high bandwidth memory (HBM) IC chips 251, another of its auxiliary IC chips 411, or another of its FPGA IC chips 200 and/or 201.

Accordingly, referring to FIGS. 5A-1, 5A-2, 5A-5, 5E-5G and 5K, for each of the first type of FPMCPs 300 for the first, second and fifth alternatives, in each of the first through twelfth aspects each of its FPGA IC chips 200 and/or 201 may be programmed, configured or reconfigured for different function/application. For example, each of its FPGA IC chips 200 and/or 201 may be programmed, configured or reconfigured as a micro-controller unit (MCU) chip and thus said each of the first type of FPMCPs 300 for the first, second and fifth alternatives may be used in a smart car or robot. Alternatively, each of its FPGA IC chips 200 and/or 201 may be programmed, configured or reconfigured as a digital-signal-processor (DSP) chip and thus said each of the first type of FPMCPs 300 for the first, second and fifth alternatives may be used in the application of multimedia, cloud data center or smart network.

Further, FIG. 5B is a block diagram illustrating inter-chip interconnection between semiconductor IC chips of a first type of FPMCP for any first, second or fifth alternative in accordance with an embodiment of the present application. Referring to FIGS. 5A-1, 5A-2, 5A-5 and 5B, for each of the first type of FPMCPs 300 for the first, second and fifth alternatives, each of its FPGA IC chips 200 and/or 201 may include the first or second type of field programmable switch cell 379, i.e., field-programmable interconnection (FPI) circuits as illustrated in FIGS. 2A-2B and the field programmable switch matrix 710 as illustrated in FIG. 2C, to be programmed, configured or reconfigured to change or control inter-chip interconnection between its first and second semiconductor IC chips 100a and 100b. Said each of its FPGA IC chips 200 and/or 201 may have (1) multiple first small input/output (SIO) circuits 231, or input/output (I/O) pads, each coupling to the node N21 of a first one of the first type of field programmable switch cells 379 thereof, as illustrated in FIG. 2A, one of the nodes N23-N26 of a first one of the second type of field programmable switch cells 379 thereof, as illustrated in FIG. 2B, or one of the nodes P₁-P_{N} of a first one of the field programmable switch matrices 710 thereof, as illustrated in FIG. 2C, through one of the programmable interconnects 361 thereof and to one of multiple small input/output (SIO) circuits 241, or input/output (I/O) pads, of its first semiconductor IC chip 100a through one of the programmable interconnects 361 of its inter-chip interconnects 371 to form a first signal path between the node N21 of the first one of the first type of field programmable switch cells 379 thereof and said one of the small input/output (SIO) circuits 241, or input/output (I/O) pads, of its first semiconductor IC chip 100a, between said one of the nodes N23-N26 of the first one of the second type of field programmable switch cells 379 thereof and said one of the small input/output (SIO) circuits 241, or input/output (I/O) pads, of its first semiconductor IC chip 100a or between said one of the nodes P₁-P_{N} of the first one of the field programmable switch matrices 710 thereof and said one of the small input/output (SIO) circuits 241, or input/output (I/O) pads, of its first semiconductor IC chip 100a, (2) multiple second small input/output (SIO) circuits 232, or input/output (I/O) pads, each coupling to the node N22 of the first one of the first type of field programmable switch cells 379 thereof, as illustrated in FIG. 2A, one of the others of the nodes N23-N26 of the first one of the second type of field programmable switch cells 379 thereof, as illustrated in FIG. 2B, or one of the nodes Q₁-Q_{M} of the first one of the field programmable switch matrices 710 thereof, as illustrated in FIG. 2C, through another of the programmable interconnects 361 thereof and to one of multiple small input/output (SIO) circuits 242, or input/output (I/O) pads, of its second semiconductor IC chip 100b through another of the programmable interconnects 361 of its inter-chip interconnects 371 to form a second signal path between the node N22 of the first one of the first type of field programmable switch cells 379 thereof and said one of the small input/output (SIO) circuits 242, or input/output (I/O) pads, of its second semiconductor IC chip 100b, between said one of the others of the nodes N23-N26 of the first one of the second type of field programmable switch cells 379 thereof and said one of the small input/output (SIO) circuits 242, or input/output (I/O) pads, of its second semiconductor IC chip 100b or between said one of the nodes Q₁-Q_{M} of the first one of the field programmable switch matrices 710 thereof and said one of the small input/output (SIO) circuits 242, or input/output (I/O) pads, of its second semiconductor IC chip 100b, (3) multiple third small input/output (SIO) circuits 373, or input/output (I/O) pads, each coupling to the node N21 of a second one of the first type of field programmable switch cells 379 thereof, as illustrated in FIG. 2A, one of the nodes N23-N26 of a second one of the second type of field programmable switch cells 379 thereof, as illustrated in FIG. 2B, or one of the nodes P₁-P_{N} of a second one of the field programmable switch matrices 710 thereof, as illustrated in FIG. 2C, through another of the programmable interconnects 361 thereof and to one of multiple small input/output (SIO) circuits 473, or input/output (I/O) pads, of its first semiconductor IC chip 100a through another of the programmable interconnects 361 of its inter-chip interconnects 371 to form a third signal path between the node N21 of the second one of the first type of field programmable switch cells 379 thereof and said one of the small input/output (SIO) circuits 473, or input/output (I/O) pads, of its first semiconductor IC chip 100a, between said one of the nodes N23-N26 of the second one of the second type of field programmable switch cells 379 thereof and said one of the small input/output (SIO) circuits 473, or input/output (I/O) pads, of its first semiconductor IC chip 100a or between said one of the nodes P₁-P_{N} of the second one of the field programmable switch matrices 710 thereof and said one of the small input/output (SIO) circuits 473, or input/output (I/O) pads, of its first semiconductor IC chip 100a, (4) multiple fourth small input/output (SIO) circuits 374, or input/output (I/O) pads, each coupling to the node N22 of the second one of the first type of field programmable switch cells 379 thereof, as illustrated in FIG. 2A, one of the others of the nodes N23-N26 of the second one of the second type of field programmable switch cells 379 thereof, as illustrated in FIG. 2B, or one of the nodes Q₁-Q_{M} of the second one of the field programmable switch matrices 710 thereof, as illustrated in FIG. 2C, through another of the programmable interconnects 361 thereof and to one of multiple small input/output (SIO) circuits 474, or input/output (I/O) pads, of its first semiconductor IC chip 100a through another of the programmable interconnects 361 of its inter-chip interconnects 371 to form a fourth signal path between the node N22 of the second one of the first type of field programmable switch cells 379 thereof and said one of the small input/output (SIO) circuits 474, or input/output (I/O) pads, of its first semiconductor IC chip 100a, between said one of the others of the nodes N23-N26 of the second one of the second type of field programmable switch cells 379 thereof and said one of the small input/output (SIO) circuits 474, or input/output (I/O) pads, of its first semiconductor IC chip 100a or between said one of the nodes Q₁-Q_{M} of the second one of the field programmable switch matrices 710 thereof and said one of the small input/output (SIO) circuits 474, or input/output (I/O) pads, of its first semiconductor IC chip 100a, (5) multiple fifth small input/output (SIO) circuits 375, or input/output (I/O) pads, each coupling to one of the nodes N23-N26 of a third one of the second type of field programmable switch cells 379 thereof, as illustrated in FIG. 2B, or one of the nodes P₁-P_{N} of a third one of the field programmable switch matrices 710 thereof, as illustrated in FIG. 2C, through another of the programmable interconnects 361 thereof and to one of multiple small input/output (SIO) circuits 475, or input/output (I/O) pads, of its first semiconductor IC chip 100a through another of the programmable interconnects 361 of its inter-chip interconnects 371 to form a fifth signal path between said one of the nodes N23-N26 of the third one of the second type of field programmable switch cells 379 thereof and said one of the small input/output (SIO) circuits 475, or input/output (I/O) pads, of its first semiconductor IC chip 100a or between said one of the nodes P₁-P_{N} of the third one of the field programmable switch matrices 710 thereof and said one of the small input/output (SIO) circuits 475, or input/output (I/O) pads, of its first semiconductor IC chip 100a, (6) multiple sixth small input/output (SIO) circuits 376, or input/output (I/O) pads, each coupling to another of the nodes N23-N26 of the third one of the second type of field programmable switch cells 379 thereof, as illustrated in FIG. 2B, or one of the nodes Q₁-Q_{M} of the third one of the field programmable switch matrices 710 thereof, as illustrated in FIG. 2C, through another of the programmable interconnects 361 thereof and to one of multiple small input/output (SIO) circuits 476, or input/output (I/O) pads, of its second semiconductor IC chip 100b through another of the programmable interconnects 361 of its inter-chip interconnects 371 to form a sixth signal path between said another of the nodes N23-N26 of the third one of the second type of field programmable switch cells 379 thereof and said one of the small input/output (SIO) circuits 476, or input/output (I/O) pads, of its second semiconductor IC chip 100b or between said one of the nodes Q₁-Q_{M} of the third one of the field programmable switch matrices 710 thereof and said one of the small input/output (SIO) circuits 476, or input/output (I/O) pads, of its second semiconductor IC chip 100b, (7) multiple seventh small input/output (SIO) circuits 377, or input/output (I/O) pads, each coupling to one of the others of the nodes N23-N26 of the third one of the second type of field programmable switch cells 379 thereof, as illustrated in FIG. 2B or another of the nodes Q₁-Q_{M} of the third one of the field programmable switch matrices 710 thereof, as illustrated in FIG. 2C through another of the programmable interconnects 361 thereof and to one of multiple small input/output (SIO) circuits 477, or input/output (I/O) pads, of its second semiconductor IC chip 100b through another of the programmable interconnects 361 of its inter-chip interconnects 371 to form a seventh signal path between said one of the others of the nodes N23-N26 of the third one of the second type of field programmable switch cells 379 thereof and said one of the small input/output (SIO) circuits 477, or input/output (I/O) pads, of its second semiconductor IC chip 100b or between said another of the nodes Q₁-Q_{M} of the third one of the field programmable switch matrices 710 thereof and said one of the small input/output (SIO) circuits 477, or input/output (I/O) pads, of its second semiconductor IC chip 100b, (8) multiple eighth small input/output (SIO) circuits 378, or input/output (I/O) pads, each coupling to one of the nodes N23-N26 of a fourth one of the second type of field programmable switch cells 379 thereof, as illustrated in FIG. 2B, or one of the nodes P₁-P_{N} of a fourth one of the field programmable switch matrices 710 thereof, as illustrated in FIG. 2C, through another of the programmable interconnects 361 thereof and to one of multiple small input/output (SIO) circuits 478, or input/output (I/O) pads, of its first semiconductor IC chip 100a through another of the programmable interconnects 361 of its inter-chip interconnects 371 to form an eighth signal path between said one of the nodes N23-N26 of the fourth one of the second type of field programmable switch cells 379 thereof and said one of the small input/output (SIO) circuits 478, or input/output (I/O) pads, of its first semiconductor IC chip 100a or between said one of the nodes P₁-P_{N} of the fourth one of the field programmable switch matrices 710 thereof and said one of the small input/output (SIO) circuits 478, or input/output (I/O) pads, of its first semiconductor IC chip 100a, (9) multiple ninth small input/output (SIO) circuits 579, or input/output (I/O) pads, each coupling to another of the nodes N23-N26 of the fourth one of the second type of field programmable switch cells 379 thereof, as illustrated in FIG. 2B, or one of the nodes Q₁-Q_{M} of the fourth one of the field programmable switch matrices 710 thereof, as illustrated in FIG. 2C, through another of the programmable interconnects 361 thereof and to one of multiple small input/output (SIO) circuits 479, or input/output (I/O) pads, of its first semiconductor IC chip 100a through another of the programmable interconnects 361 of its inter-chip interconnects 371 to form a ninth signal path between said another of the nodes N23-N26 of the fourth one of the second type of field programmable switch cells 379 thereof and said one of the small input/output (SIO) circuits 479, or input/output (I/O) pads, of its first semiconductor IC chip 100a or between said one of the nodes Q₁-Q_{M} of the fourth one of the field programmable switch matrices 710 thereof and said one of the small input/output (SIO) circuits 479, or input/output (I/O) pads, of its first semiconductor IC chip 100a, and (10) multiple tenth small input/output (SIO) circuits 580, or input/output (I/O) pads, each coupling to one of the others of the nodes N23-N26 of the fourth one of the second type of field programmable switch cells 379 thereof, as illustrated in FIG. 2B, or another of the nodes P₁-P_{N} of the fourth one of the field programmable switch matrices 710 thereof, as illustrated in FIG. 2C, through another of the programmable interconnects 361 thereof and to one of multiple small input/output (SIO) circuits 480, or input/output (I/O) pads, of its first semiconductor IC chip 100a through another of the programmable interconnects 361 of its inter-chip interconnects 371 to form a tenth signal path between said one of the others of the nodes N23-N26 of the fourth one of the second type of field programmable switch cells 379 thereof and said one of the small input/output (SIO) circuits 480, or input/output (I/O) pads, of its first semiconductor IC chip 100a or between said another of the nodes P₁-P_{N} of the fourth one of the field programmable switch matrices 710 thereof and said one of the small input/output (SIO) circuits 480, or input/output (I/O) pads, of its first semiconductor IC chip 100a, wherein each of the first through tenth small input/output (SIO) circuits 231, 232, 373, 374, 375, 376, 377, 378, 579 and 580 of said each of its FPGA IC chips 200 and/or 201, each of the small input/output (SIO) circuits 241, 473, 474, 475, 478, 479 and 480 of its first semiconductor IC chip 100a and each of the small input/output (SIO) circuits 242, 476 and 477 of its second semiconductor IC chip 100b may have an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts, respectively. Accordingly, the first one of the first or second type of field programmable switch cells 379 of said each of its FPGA IC chips 200 and/or 201 or the first one of the field programmable switch matrices 710 of said each of its FPGA IC chips 200 and/or 201 may be programmed, configured or reconfigured in accordance with CPM data, i.e., programming codes, password or encryption/decryption codes, stored in the memory cells 362 thereof as seen in FIG. 2A, the four sets of memory cells 362 thereof as seen in FIG. 2B or the memory cell 398 of each of the field programmable switch units 711 of the first one of the field programmable switch matrices 710 thereof as seen in FIG. 2C to control coupling between the first and second signal paths. The second one of the first or second type of field programmable switch cells 379 of said each of its FPGA IC chips 200 and/or 201 or the second one of the field programmable switch matrices 710 of said each of its FPGA IC chips 200 and/or 201 may be programmed, configured or reconfigured in accordance with CPM data, i.e., programming codes, password or encryption/decryption codes, stored in the memory cells 362 thereof as seen in FIG. 2A, the four sets of memory cells 362 thereof as seen in FIG. 2B or the memory cell 398 of each of the field programmable switch units 711 of the second one of the field programmable switch matrices 710 thereof as seen in FIG. 2C to control coupling between the third and fourth signal paths. The third one of the second type of field programmable switch cells 379 of said each of its FPGA IC chips 200 and/or 201 may be programmed, configured or reconfigured in accordance with CPM data stored in the four sets of memory cells 362 thereof as seen in FIG. 2B to select one from the fifth, sixth and seventh signal paths to couple to another of the fifth, sixth and seventh signal paths, and, for example, to select the fifth signal path to couple to one of the sixth and seventh signal paths or select the sixth signal path to couple to one of the fifth and seventh signal paths, or the third one of the field programmable switch matrices 710 of said each of its FPGA IC chips 200 and/or 201 may be programmed, configured or reconfigured in accordance with CPM data, i.e., programming codes, password or encryption/decryption codes, stored in the memory cell 398 of each of the field programmable switch units 711 of the third one of the field programmable switch matrices 710 thereof as seen in FIG. 2C to select one from the sixth and seventh signal paths to couple to the fifth signal path. The fourth one of the second type of field programmable switch cells 379 of said each of its FPGA IC chips 200 and/or 201 may be programmed, configured or reconfigured in accordance with CPM data stored in the four sets of memory cells 362 thereof as seen in FIG. 2B to select one from the eighth, ninth and tenth signal paths to couple to another of the eighth, ninth and tenth signal paths, and, for example, to select the eighth signal path to couple to one of the ninth and tenth signal paths, or the fourth one of the field programmable switch matrices 710 of said each of its FPGA IC chips 200 and/or 201 may be programmed, configured or reconfigured in accordance with CPM data, i.e., programming codes, password or encryption/decryption codes, stored in the memory cell 398 of each of the field programmable switch units 711 of the fourth one of the field programmable switch matrices 710 thereof as seen in FIG. 2C to select one from the eighth and tenth signal paths to couple to the ninth signal path.

Referring to FIGS. 5A-1, 5A-2, 5A-5 and 5B, for said each of the first type of FPMCPs 300 for the first, second and fifth alternatives, its first semiconductor IC chip 100a may be one of its graphic-processing-unit (GPU) IC chips 269a and its second semiconductor IC chip 100b may be one of its central-processing-unit (CPU) IC chip 269b, its application-specific integrated-circuit (ASIC) chip or system-on-chip (SoC) chip 269c, its auxiliary IC chips 411, its NVM IC chips 250, its VM IC chip 255, its high bandwidth memory (HBM) IC chips 251 and 252, its input/output (I/O) or control chip 253, its cooperating and supporting (CS) logic IC chip 412, its dedicated control and input/output (I/O) chip 260, its digital-signal-processing (DSP) IC chip 270, its IAC chip 402, another of its graphic-processing-unit (GPU) IC chips 269a and another of its FPGA IC chips 200 and 201 selected in combination for one of the first, second and fifth alternatives. Alternatively, its first semiconductor IC chip 100a may be its central-processing-unit (CPU) IC chip 269b and its second semiconductor IC chip 100b may be one of its graphic-processing-unit (GPU) IC chips 269a, its application-specific integrated-circuit (ASIC) chip or system-on-chip (SoC) chip 269c, its auxiliary IC chips 411, its NVM IC chips 250, its VM IC chip 255, its high bandwidth memory (HBM) IC chips 251 and 252, its input/output (I/O) or control chip 253, its cooperating and supporting (CS) logic IC chip 412, its dedicated control and input/output (I/O) chip 260, its digital-signal-processing (DSP) IC chip 270, its IAC chip 402 and another of its FPGA IC chips 200 and 201 selected in combination for one of the first, second and fifth alternatives. Alternatively, its first semiconductor IC chip 100a may be its application-specific integrated-circuit (ASIC) IC chip or system-on chip (SoC) 269c for the first or fifth alternative or its digital-signal-processing (DSP) IC chip 270 for the second alternative and its second semiconductor IC chip 100b may be one of its graphic-processing-unit (GPU) IC chips 269a, its central-processing-unit (CPU) IC chip 269b, its auxiliary IC chips 411, its NVM IC chips 250, its VM IC chip 255, its high bandwidth memory (HBM) IC chips 251 and 252, its input/output (I/O) or control chip 253, its cooperating and supporting (CS) logic IC chip 412, its dedicated control and input/output (I/O) chip 260, its IAC chip 402 and another of its FPGA IC chips 200 and 201 selected in combination for one of the first, second and fifth alternatives. Alternatively, its first semiconductor IC chip 100a may be one of its auxiliary IC chips 411 and its second semiconductor IC chip 100b may be one of its graphic-processing-unit (GPU) IC chips 269a, its central-processing-unit (CPU) IC chip 269b, its application-specific integrated-circuit (ASIC) chip or system-on-chip (SoC) chip 269c, its NVM IC chips 250, its VM IC chip 255, its high bandwidth memory (HBM) IC chips 251 and 252, its input/output (I/O) or control chip 253, its cooperating and supporting (CS) logic IC chip 412, its dedicated control and input/output (I/O) chip 260, its digital-signal-processing (DSP) IC chip 270, its IAC chip 402, another of its auxiliary IC chips 411 and another of its FPGA IC chips 200 and 201 selected in combination for one of the first, second and fifth alternatives. Alternatively, its first semiconductor IC chip 100a may be its NVM IC chip 250 or either and its second semiconductor IC chip 100b may be one of its graphic-processing-unit (GPU) IC chips 269a, its central-processing-unit (CPU) IC chip 269b, its application-specific integrated-circuit (ASIC) chip or system-on-chip (SoC) chip 269c, its auxiliary IC chips 411, its VM IC chip 255, its high bandwidth memory (HBM) IC chips 251 and 252, its input/output (I/O) or control chip 253, its cooperating and supporting (CS) logic IC chip 412, its dedicated control and input/output (I/O) chip 260, its digital-signal-processing (DSP) IC chip 270, its IAC chip 402 and another of its FPGA IC chips 200 and 201 selected in combination for one of the first, second and fifth alternatives. Alternatively, its first semiconductor IC chip 100a may be one of its high bandwidth memory (HBM) IC chips 251 and/or 252 and its second semiconductor IC chip 100b may be one of its graphic-processing-unit (GPU) IC chips 269a, its central-processing-unit (CPU) IC chip 269b, its application-specific integrated-circuit (ASIC) chip or system-on-chip (SoC) chip 269c, its auxiliary IC chips 411, its NVM IC chip 250, its VM IC chip 255, the other of its high bandwidth memory (HBM) IC chips 251 and 252, its input/output (I/O) or control chip 253, its cooperating and supporting (CS) logic IC chip 412, its dedicated control and input/output (I/O) chip 260, its digital-signal-processing (DSP) IC chip 270, its IAC chip 402 and another of its FPGA IC chips 200 and 201 selected in combination for one of the first, second and fifth alternatives. Alternatively, its first semiconductor IC chip 100a may be another of its FPGA IC chips 200 and/or 201 and its second semiconductor IC chip 100b may be one of its graphic-processing-unit (GPU) IC chips 269a, its central-processing-unit (CPU) IC chip 269b, its application-specific integrated-circuit (ASIC) chip or system-on-chip (SoC) chip 269c, its auxiliary IC chips 411, its NVM IC chips 250, its VM IC chip 255, its high bandwidth memory (HBM) IC chips 251 and 252, its input/output (I/O) or control chip 253, its cooperating and supporting (CS) logic IC chip 412, its dedicated control and input/output (I/O) chip 260, its digital-signal-processing (DSP) IC chip 270, its IAC chip 402 and the other of its FPGA IC chips 200 and 201 selected in combination for one of the first, second and fifth alternatives. Alternatively, its first semiconductor IC chip 100a may be its VM IC chip 255 and its second semiconductor IC chip 100b may be one of its graphic-processing-unit (GPU) IC chips 269a, its central-processing-unit (CPU) IC chip 269b, its application-specific integrated-circuit (ASIC) IC chip or system-on chip (SoC) 269c, its auxiliary IC chips 411, its NVM IC chip 250, its high bandwidth memory (HBM) IC chips 251 and another of its FPGA IC chips 200 for the fifth alternative.

Further, FIG. 5C is a block diagram illustrating operation of semiconductor IC chips of a first type of FPMCP for either first or second alternative in accordance with an embodiment of the present application. Referring to FIGS. 5A-1, 5A-2, 5A-5 and 5C, for each of the first type of FPMCPs 300 for the first, second and fifth alternatives, each of its FPGA IC chips 200 and/or 201 may cooperate with the others of its FPGA IC chips 200 and/or 201, each of its logic computing IC chips 269a, 269b, 269c and 270, each of its NVM IC chips 250, its VM IC chip 255, each of its high bandwidth memory (HBM) IC chips 251 and 252, its input/output (I/O) or control chip 253, its cooperating and supporting (CS) logic IC chip 412, its dedicated control and input/output (I/O) chip 260, its IAC chip 402 and each of its auxiliary IC chips 411 selected in combination for one of the first, second and fifth alternatives. For example, each of its FPGA IC chips 200 and/or 201 may have (1) an eleventh small input/output (SIO) circuit 233, or input/output (I/O) pad, coupling to a first small input/output (SIO) circuit 243, or input/output (I/O) pad, of its third semiconductor IC chip 100c through one of the programmable interconnects 361 of its inter-chip interconnects 371, (2) a twelfth small input/output (SIO) circuit 234, or input/output (I/O) pad, coupling to a second small input/output (SIO) circuit 244, or input/output (I/O) pad, of its third semiconductor IC chip 100c through another of the programmable interconnects 361 of its inter-chip interconnects 371, (3) a thirteenth small input/output (SIO) circuit 235, or input/output (I/O) pad, coupling to a third small input/output (SIO) circuit 245, or input/output (I/O) pad, of its third semiconductor IC chip 100c through another of the programmable interconnects 361 of its inter-chip interconnects 371, (4) a fourteenth small input/output (SIO) circuit 236, or input/output (I/O) pad, coupling to a first small input/output (SIO) circuit 246, or input/output (I/O) pad, of its fourth semiconductor IC chip 100d through another of the programmable interconnects 361 of its inter-chip interconnects 371, (5) a fifteenth small input/output (SIO) circuit 237, or input/output (I/O) pad, coupling to a second small input/output (SIO) circuit 247, or input/output (I/O) pad, of its fourth semiconductor IC chip 100d through another of the programmable interconnects 361 of its inter-chip interconnects 371, and (6) a sixteenth small input/output (SIO) circuit 238, or input/output (I/O) pad, coupling to a fourth small input/output (SIO) circuit 248, or input/output (I/O) pad, of its third semiconductor IC chip 100c through another of the programmable interconnects 361 of its inter-chip interconnects 371. Each of the eleventh through sixteenth small input/output (SIO) circuits 233-238 of said each of its FPGA IC chips 200 and/or 201, each of the first through fourth small input/output (SIO) circuits 243, 244, 245 and 248 of its third semiconductor IC chip 100c and each of the first and second small input/output (SIO) circuits 246 and 247 of its fourth semiconductor IC chip 100d may have an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts, respectively.

For example, referring to FIGS. 5A-1, 5A-2, 5A-5 and 5C, said each of its FPGA IC chips 200 and/or 201 may include (1) a first one of the first, second or third type of field programmable logic cells or elements (LCEs) 2014 thereof, as illustrated in FIGS. 1A-1C, having the data input A0 passed from the eleventh small input/output (SIO) circuit 233 thereof through one of the programmable interconnects 361 thereof and the data output, i.e., Dout, passed to the twelfth small input/output (SIO) circuit 234 thereof through another of the programmable interconnects 361 thereof, (2) a second one of the first, second or third type of field programmable logic cells or elements (LCEs) 2014 thereof having the data input A0 passed from the thirteenth small input/output (SIO) circuit 235 thereof through another of the programmable interconnects 361 thereof and the data output, i.e., Dout, passed to the fourteenth small input/output (SIO) circuit 236 thereof through another of the programmable interconnects 361 thereof, and (3) a third one of the first, second or third type of field programmable logic cells or elements (LCEs) 2014 thereof having the data input A0 passed from the fifteenth small input/output (SIO) circuit 237 thereof through another of the programmable interconnects 361 thereof and the data output, i.e., Dout, passed to the sixteenth small input/output (SIO) circuit 238 thereof through another of the programmable interconnects 361 thereof. Accordingly, referring to FIGS. 1A-1C, 5A-1, 5A-2, 5A-5 and 5C, the first one of the first, second or third type of field programmable logic cells or elements (LCEs) 2014 may be programmed, configured or reconfigured in accordance with CPM data stored in the memory cells 490 thereof to select or process data in accordance with the input data set thereof, i.e., A0 and A1 or A0-A3, having the data input A0 from the first small input/output (SIO) circuit 243 of its third semiconductor IC chip 100c through the eleventh small input/output (SIO) circuit 233 of said each of its FPGA IC chips 200 and/or 201, as or into the data output, i.e., Dout, to be passed back to the second small input/output (SIO) circuit 244 of its third semiconductor IC chip 100c through the twelfth small input/output (SIO) circuit 234 of said each of its FPGA IC chips 200 and/or 201. The second one of the first, second or third type of field programmable logic cells or elements (LCEs) 2014 may be programmed, configured or reconfigured in accordance with CPM data stored in the memory cells 490 thereof to select or process data in accordance with the input data set thereof, i.e., A0 and A1 or A0-A3, having the data input A0 from the third small input/output (SIO) circuit 245 of its third semiconductor IC chip 100c through the thirteenth small input/output (SIO) circuit 235 of said each of its FPGA IC chips 200 and/or 201, as or into the data output, i.e., Dout, to be passed to the first small input/output (SIO) circuit 246 of its fourth semiconductor IC chip 100d through the fourteenth small input/output (SIO) circuit 236 of said each of its FPGA IC chips 200 and/or 201. The third one of the first, second or third type of field programmable logic cells or elements (LCEs) 2014 may be programmed, configured or reconfigured in accordance with CPM data stored in the memory cells 490 thereof to select or process data in accordance with the input data set thereof, i.e., A0 and A1 or A0-A3, having the data input A0 from the second small input/output (SIO) circuit 247 of its fourth semiconductor IC chip 100d through the fifteenth small input/output (SIO) circuit 237 of said each of its FPGA IC chips 200 and/or 201, as or into the data output, i.e., Dout, to be passed to the fourth small input/output (SIO) circuit 248 of its third semiconductor IC chip 100c through the sixteenth small input/output (SIO) circuit 238 of said each of its FPGA IC chips 200 and/or 201.

Thereby, referring to FIGS. 1A-1C, 5A-1, 5A-2, 5A-5 and 5C, changing the configuration of the first, second and third ones of the first, second or third type of field programmable logic cells or elements (LCEs) 2014 by changing the CPM data stored in the memory cells 490 of the first, second and third ones of the first type of field programmable logic cells or elements (LCEs) 2014 or by changing the CPM data stored in the memory cells of the first, second and third ones of the second or third type of field programmable logic cells or elements (LCEs) 2014 makes it possible for each of the first type of FPMCPs 300 for the first, second and fifth alternatives to be used for various applications thus resulting in great application flexibility.

Referring to FIGS. 5A-1, 5A-2, 5A-5 and 5C, for each of the first type of FPMCPs for the first, second and fifth alternatives, its third semiconductor IC chip 100c may be one of its graphic-processing-unit (GPU) IC chips 269a and its fourth semiconductor IC chip 100d may be one of its central-processing-unit (CPU) IC chip 269b, its application-specific integrated-circuit (ASIC) IC chip or system-on chip (SoC) 269c, its auxiliary IC chips 411, its NVM IC chips 250, its VM IC chip 255, its high bandwidth memory (HBM) IC chips 251 and 252, its input/output (I/O) or control chip 253, its cooperating and supporting (CS) logic IC chip 412, its dedicated control and input/output (I/O) chip 260, its digital-signal-processing (DSP) IC chip 270, its IAC chip 402, another of its graphic-processing-unit (GPU) IC chips 269a and another of its FPGA IC chips 200 and 201 selected in combination for one of the first, second and fifth alternatives. Alternatively, its third semiconductor IC chip 100c may be its central-processing-unit (CPU) IC chip 269b and its fourth semiconductor IC chip 100d may be one of its graphic-processing-unit (GPU) IC chips 269a, its application-specific integrated-circuit (ASIC) IC chip or system-on chip (SoC) 269c, its auxiliary IC chips 411, its NVM IC chips 250, its VM IC chip 255, its high bandwidth memory (HBM) IC chips 251 and 252, its input/output (I/O) or control chip 253, its cooperating and supporting (CS) logic IC chip 412, its dedicated control and input/output (I/O) chip 260, its digital-signal-processing (DSP) IC chip 270, its IAC chip 402 and another of its FPGA IC chips 200 and 201 selected in combination for one of the first, second and fifth alternatives. Alternatively, its third semiconductor IC chip 100c may be its application-specific integrated-circuit (ASIC) IC chip or system-on chip (SoC) 269c for the first or fifth alternative or its digital-signal-processing (DSP) IC chip 270 for the second alternative and its fourth semiconductor IC chip 100d may be one of its graphic-processing-unit (GPU) IC chips 269a, its central-processing-unit (CPU) IC chip 269b, its auxiliary IC chips 411, its NVM IC chips 250, its VM IC chip 255, its high bandwidth memory (HBM) IC chips 251 and 252, its input/output (I/O) or control chip 253, its cooperating and supporting (CS) logic IC chip 412, its dedicated control and input/output (I/O) chip 260, its IAC chip 402 and another of its FPGA IC chips 200 and 201 selected in combination for one of the first, second and fifth alternatives. Alternatively, its third semiconductor IC chip 100c may be one of its auxiliary IC chips 411 and its fourth semiconductor IC chip 100d may be one of its graphic-processing-unit (GPU) IC chips 269a, its central-processing-unit (CPU) IC chip 269b, its application-specific integrated-circuit (ASIC) IC chip or system-on chip (SoC) 269c, its NVM IC chips 250, its VM IC chip 255, its high bandwidth memory (HBM) IC chips 251 and 252, its input/output (I/O) or control chip 253, its cooperating and supporting (CS) logic IC chip 412, its dedicated control and input/output (I/O) chip 260, its digital-signal-processing (DSP) IC chip 270, its IAC chip 402, another of its auxiliary IC chips 411 and another of its FPGA IC chips 200 and 201 selected in combination for one of the first, second and fifth alternatives. Alternatively, its third semiconductor IC chip 100c may be its NVM IC chip 250 or either and its fourth semiconductor IC chip 100d may be one of its graphic-processing-unit (GPU) IC chips 269a, its central-processing-unit (CPU) IC chip 269b, its application-specific integrated-circuit (ASIC) IC chip or system-on chip (SoC) 269c, its auxiliary IC chips 411, its VM IC chip 255, its high bandwidth memory (HBM) IC chips 251 and 252, its input/output (I/O) or control chip 253, its cooperating and supporting (CS) logic IC chip 412, its dedicated control and input/output (I/O) chip 260, its digital-signal-processing (DSP) IC chip 270, its IAC chip 402 and another of its FPGA IC chips 200 and 201 selected in combination for one of the first, second and fifth alternatives. Alternatively, its third semiconductor IC chip 100c may be one of its high bandwidth memory (HBM) IC chips 251 and/or 252 and its fourth semiconductor IC chip 100d may be one of its graphic-processing-unit (GPU) IC chips 269a, its central-processing-unit (CPU) IC chip 269b, its application-specific integrated-circuit (ASIC) IC chip or system-on chip (SoC) 269c, its auxiliary IC chips 411, its NVM IC chips 250, its VM IC chip 255, the other of its high bandwidth memory (HBM) IC chips 251 and 252, its input/output (I/O) or control chip 253, its cooperating and supporting (CS) logic IC chip 412, its dedicated control and input/output (I/O) chip 260, its digital-signal-processing (DSP) IC chip 270, its IAC chip 402 and another of its FPGA IC chips 200 and 201 selected in combination for one of the first, second and fifth alternatives. Alternatively, its third semiconductor IC chip 100c may be another of its FPGA IC chips 200 and/or 201 and its fourth semiconductor IC chip 100d may be one of its graphic-processing-unit (GPU) IC chips 269a, its central-processing-unit (CPU) IC chip 269b, its application-specific integrated-circuit (ASIC) IC chip or system-on chip (SoC) 269c, its auxiliary IC chips 411, its NVM IC chips 250, its VM IC chip 255, its high bandwidth memory (HBM) IC chips 251 and 252, its input/output (I/O) or control chip 253, its cooperating and supporting (CS) logic IC chip 412, its dedicated control and input/output (I/O) chip 260, its digital-signal-processing (DSP) IC chip 270, its IAC chip 402 and the other of its FPGA IC chips 200 and 201 selected in combination for one of the first, second and fifth alternatives. Alternatively, its third semiconductor IC chip 100c may be its VM IC chip 255 and its fourth semiconductor IC chip 100d may be one of its graphic-processing-unit (GPU) IC chips 269a, its central-processing-unit (CPU) IC chip 269b, its application-specific integrated-circuit (ASIC) IC chip or system-on chip (SoC) 269c, its auxiliary IC chips 411, its NVM IC chip 250, its high bandwidth memory (HBM) IC chips 251 and another of its FPGA IC chips 200 for the fifth alternative.

Further, FIG. 5D is a block diagram illustrating connection of a first type of FPMCP for any first, second or third alternative to external circuits in accordance with an embodiment of the present application. Referring to FIGS. 5A-1, 5A-2, 5A-5 and 5D, for each of the first type of FPMCPs 300 for the first, second and fifth alternatives, each of its FPGA IC chips 200 and/or 201 may include the second type of field programmable switch cell 379, i.e., field-programmable interconnection (FPI) circuits as illustrated in FIG. 2B and the field programmable switch matrix 710 as illustrated in FIG. 2C, to be programmed, configured or reconfigured to change or control inter-chip interconnection between one of its fifth and sixth semiconductor IC chips 100e and 100f and an external circuit 340 of said each of the first type of FPMCPs 300 for the first, second and fifth alternatives. Said each of its FPGA IC chips 200 and/or 201 may have (1) multiple seventeenth small input/output (SIO) circuits 239, or input/output (I/O) pads each coupling to a first one of the nodes N23-N26 of one of a first group of the second type of field programmable switch cells 379 thereof, as illustrated in FIG. 2B, or one of the nodes P₁-P_{N} of a fifth one of the field programmable switch matrices 710 thereof, as illustrated in FIG. 2C, through one of the programmable interconnects 361 thereof and to one of multiple small input/output (SIO) circuits 249, or input/output (I/O) pads, of its fifth semiconductor IC chip 100e through one of the programmable interconnects 361 of its inter-chip interconnects 371 to form an eleventh signal path between the first one of the nodes N23-N26 of said one of the first group of the second type of field programmable switch cells 379 thereof and said one of the small input/output (SIO) circuits 249 of its fifth semiconductor IC chip 100e or between said one of the nodes P₁-P_{N} of the fifth one of the field programmable switch matrices 710 thereof and said one of the small input/output (SIO) circuits 249 of its fifth semiconductor IC chip 100e, (2) multiple eighteenth small input/output (SIO) circuits 240, or input/output (I/O) pads each coupling to a first one of the nodes N23-N26 of one of a second group of the second type of field programmable switch cells 379 thereof, as illustrated in FIG. 2B, or one of the nodes P₁-P_{N} of a sixth one of the field programmable switch matrices 710 thereof, as illustrated in FIG. 2C, through another of the programmable interconnects 361 thereof and to one of multiple small input/output (SIO) circuits 350, or input/output (I/O) pads, of its sixth semiconductor IC chip 100f through one of the programmable interconnects 361 of its inter-chip interconnects 371 to form a twelfth signal path between the first one of the nodes N23-N26 of said one of the second group of the second type of field programmable switch cells 379 thereof and said one of the small input/output (SIO) circuits 350 of its sixth semiconductor IC chip 100f or between said one of the nodes P₁-P_{N} of the sixth one of the field programmable switch matrices 710 thereof and said one of the small input/output (SIO) circuits 350 of its sixth semiconductor IC chip 100f, (3) multiple nineteenth small input/output (SIO) circuits 331, or input/output (I/O) pads, for a first format or protocol 343 of various input/output (I/O) formats, protocols or industry standards such as Ethernet, peripheral component interconnect express (PCIe), serial-advanced-technology-attachment (SATA), universal chiplet interconnect express (UCIe), universal serial bus (USB), serializer/deserializer (SerDes), Wi-Fi (wireless fidelity) or Thunderbolt, each coupling to a second one of the nodes N23-N26 of one of the first and second groups of the second type of field programmable switch cells 379 thereof, as illustrated in FIG. 2B, or one of a first group of the nodes Q₁-Q_{M} of one of the fifth and sixth ones of the field programmable switch matrices 710 thereof, as illustrated in FIG. 2C, through one of the programmable interconnects 361 thereof and to one of a first group of the small input/output (I/O) circuits 203 of the small-input/output (I/O) block of one of its auxiliary IC chips 411 through one of the programmable interconnects 361 of its inter-chip interconnects 371 to form a thirteenth signal path between the second one of the nodes N23-N26 of said one of the first and second groups of the second type of field programmable switch cells 379 thereof and said one of the first group of the small input/output (I/O) circuits 203 of the small-input/output (I/O) block of said one of its auxiliary IC chips 411 or between said one of the first group of the nodes Q₁-Q_{M} and said one of the first group of the small input/output (I/O) circuits 203 of the small-input/output (I/O) block of said one of its auxiliary IC chips 411, and (4) multiple twentieth small input/output (SIO) circuits 332, or input/output (I/O) pads, for a second format or protocol 344 of the various input/output (I/O) formats, protocols or industry standards, each coupling to a third one of the nodes N23-N26 of one of the first and second groups of the second type of field programmable switch cells 379 thereof, as illustrated in FIG. 2B, or one of a second group of the nodes Q₁-Q_{M} of one of the fifth and sixth ones of the field programmable switch matrices 710 thereof, as illustrated in FIG. 2C, through one of the programmable interconnects 361 thereof and to one of a second group of the small input/output (I/O) circuits 203 of the small-input/output (I/O) block of one of its auxiliary IC chips 411 through one of the programmable interconnects 361 of its inter-chip interconnects 371 to form a fourteenth signal path between the third one of the nodes N23-N26 of said one of the first and second groups of the second type of field programmable switch cells 379 thereof and said one of the second group of the small input/output (I/O) circuits 203 or between said one of the second group of the nodes Q₁-Q_{M} and said one of the second group of the small input/output (I/O) circuits 203, wherein the first format or protocol 343 may be different from the second format or protocol 344. In an example, the first format or protocol 343 may be the format or protocol for Ethernet and the second format or protocol 344 may the format or protocol for peripheral component interconnect express (PCIe). Each of the seventeenth through twentieth small input/output (SIO) circuits 239, 240, 331 and 332 of said each of its FPGA IC chips 200 and/or 201, each of the small input/output (SIO) circuits 249 of its fifth semiconductor IC chip 100e and each of the small input/output (SIO) circuits 350 of its sixth semiconductor IC chip 100f may have an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts, respectively. A first group of the large input/output (I/O) circuits 341 of the large-input/output (I/O) block of said one of its auxiliary IC chips 411 may be provided for the first format or protocol 343, and a second group of the large input/output (I/O) circuits 341 of the large-input/output (I/O) block of said one of its auxiliary IC chips 411 may be provided for the second format or protocol 344. Said one of its auxiliary IC chips 411 may include a first group of the voltage-level shift (VLS) circuits 205 each having (1) the voltage-level shift-up circuit 206 coupling to the input buffer 271 of one of the first group of the small input/output (SIO) circuits 203 of the small-input/output (I/O) block thereof and to the output buffer 274 of one of the first group of the large input/output (LIO) circuits 341 of the large-input/output (I/O) block thereof and (2) the shift-down circuit 207 coupling to the output buffer 272 of said one of the first group of the small input/output (SIO) circuits 203 and to the input buffer 273 of said one of the first group of the large input/output (LIO) circuits 341, as illustrated in FIGS. 5H and 5I. Said one of its auxiliary IC chips 411 may include a second group of the voltage-level shift (VLS) circuits 205 each having (1) the voltage-level shift-up circuit 206 coupling to the input buffer 271 of one of the second group of the small input/output (SIO) circuits 203 of the small-input/output (I/O) block thereof and to the output buffer 274 of one of the second group of the large input/output (LIO) circuits 341 of the large-input/output (I/O) block thereof and (2) the shift-down circuit 207 coupling to the output buffer 272 of said one of the second group of the small input/output (SIO) circuits 203 and to the input buffer 273 of said one of the second group of the large input/output (LIO) circuits 341, as illustrated in FIGS. 5H and 5I. Thereby, the large input/output (I/O) circuits 341 of the large-input/output (I/O) block of said one of its auxiliary IC chips 411 may couple to the external circuit 340 of said each of the first type of FPMCPs 300 for the first, second fifth alternatives through various input/output (I/O) formats, protocols or industry standards such as Ethernet, peripheral component interconnect express (PCIe), serial-advanced-technology-attachment (SATA), universal chiplet interconnect express (UCIe), universal serial bus (USB), serializer/deserializer (SerDes), Wi-Fi (wireless fidelity) or Thunderbolt. Accordingly, each of the first group of the second type of field programmable switch cells 379 of said each of its FPGA IC chips 200 and/or 201 may be programmed, configured or reconfigured in accordance with CPM data stored in the four sets of memory cells 362 thereof to control coupling between each of the thirteenth paths and one of the fifteenth and sixteenth paths, each of the second group of the second type of field programmable switch cells 379 of said each of its FPGA IC chips 200 and/or 201 may be programmed, configured or reconfigured in accordance with CPM data stored in the four sets of memory cells 362 thereof to control coupling between each of the fourteenth paths and one of the fifteenth and sixteenth paths. Each of the fifth and sixth ones of the field programmable switch matrices 710 of said each of its FPGA IC chips 200 and/or 201 may be programmed, configured or reconfigured in accordance with CPM data, i.e., programming codes, password or encryption/decryption codes, stored in the memory cell 398 of each of the field programmable switch units 711 of said each of the fifth and sixth ones of the field programmable switch matrices 710 to control coupling between each of the thirteenth paths and one of the fifteenth and sixteenth paths and control coupling between each of the fourteenth paths and one of the fifteenth and sixteenth paths. Various input/output (I/O) formats, protocols or industry standards, such as Ethernet, PCIe, SATA, UCIe, USB, SerDes, Wi-Fi or Thunderbolt, between said each of the first type of FPMCPs 300 for the first, second and fifth alternatives and the external circuit 340 may be selected by said each of its FPGA IC chips 200 and/or 201, and thus the application flexibility of said each of the first type of FPMCPs 300 for the first, second and fifth alternatives may be increased.

Referring to FIGS. 5A-1, 5A-2, 5A-5 and 5D, for each of the first type of FPMCPs 300 for the first, second and fifth alternatives, its fifth semiconductor IC chip 100e may be one of its graphic-processing-unit (GPU) IC chips 269a and its sixth semiconductor IC chip 100f may be one of its central-processing-unit (CPU) IC chip 269b, its application-specific integrated-circuit (ASIC) IC chip or system-on chip (SoC) 269c, its auxiliary IC chips 411, its NVM IC chips 250, its VM IC chip 255, its high bandwidth memory (HBM) IC chips 251 and 252, its input/output (I/O) or control chip 253, its cooperating and supporting (CS) logic IC chip 412, its dedicated control and input/output (I/O) chip 260, its digital-signal-processing (DSP) IC chip 270, its IAC chip 402, another of its graphic-processing-unit (GPU) IC chips 269a and another of its FPGA IC chips 200 and 201 selected in combination for one of the first, second and fifth alternatives. Alternatively, its fifth semiconductor IC chip 100e may be its central-processing-unit (CPU) IC chip 269b and its sixth semiconductor IC chip 100f may be one of its graphic-processing-unit (GPU) IC chips 269a, its application-specific integrated-circuit (ASIC) IC chip or system-on chip (SoC) 269c, its auxiliary IC chips 411, its NVM IC chips 250, its VM IC chip 255, its high bandwidth memory (HBM) IC chips 251 and 252, its input/output (I/O) or control chip 253, its cooperating and supporting (CS) logic IC chip 412, its dedicated control and input/output (I/O) chip 260, its digital-signal-processing (DSP) IC chip 270, its IAC chip 402 and another of its FPGA IC chips 200 and 201 selected in combination for one of the first, second and fifth alternatives. Alternatively, its fifth semiconductor IC chip 100e may be its application-specific integrated-circuit (ASIC) IC chip or system-on chip (SoC) 269c for the first or fifth alternative or its digital-signal-processing (DSP) IC chip 270 for the second alternative and its sixth semiconductor IC chip 100f may be one of its graphic-processing-unit (GPU) IC chips 269a, its central-processing-unit (CPU) IC chip 269b, its auxiliary IC chips 411, its NVM IC chips 250, its VM IC chip 255, its high bandwidth memory (HBM) IC chips 251 and 252, its input/output (I/O) or control chip 253, its cooperating and supporting (CS) logic IC chip 412, its dedicated control and input/output (I/O) chip 260, its IAC chip 402 and another of its FPGA IC chips 200 and 201 selected in combination for one of the first, second and fifth alternatives. Alternatively, its fifth semiconductor IC chip 100e may be one of its auxiliary IC chips 411 and its sixth semiconductor IC chip 100f may be one of its graphic-processing-unit (GPU) IC chips 269a, its central-processing-unit (CPU) IC chip 269b, its application-specific integrated-circuit (ASIC) IC chip or system-on chip (SoC) 269c, its NVM IC chips 250, its VM IC chip 255, its high bandwidth memory (HBM) IC chips 251 and 252, its input/output (I/O) or control chip 253, its cooperating and supporting (CS) logic IC chip 412, its dedicated control and input/output (I/O) chip 260, its digital-signal-processing (DSP) IC chip 270, its IAC chip 402, another of its auxiliary IC chips 411 and another of its FPGA IC chips 200 and 201 selected in combination for one of the first, second and fifth alternatives. Alternatively, its fifth semiconductor IC chip 100e may be its NVM IC chip 250 or either and its sixth semiconductor IC chip 100f may be one of its graphic-processing-unit (GPU) IC chips 269a, its central-processing-unit (CPU) IC chip 269b, its application-specific integrated-circuit (ASIC) IC chip or system-on chip (SoC) 269c, its auxiliary IC chips 411, its VM IC chip 255, its high bandwidth memory (HBM) IC chips 251 and 252, its input/output (I/O) or control chip 253, its cooperating and supporting (CS) logic IC chip 412, its dedicated control and input/output (I/O) chip 260, its digital-signal-processing (DSP) IC chip 270, its IAC chip 402 and another of its FPGA IC chips 200 and 201 selected in combination for one of the first, second and fifth alternatives. Alternatively, its fifth semiconductor IC chip 100e may be one of its high bandwidth memory (HBM) IC chips 251 and/or 252 and its sixth semiconductor IC chip 100f may be one of its graphic-processing-unit (GPU) IC chips 269a, its central-processing-unit (CPU) IC chip 269b, its application-specific integrated-circuit (ASIC) IC chip or system-on chip (SoC) 269c, its auxiliary IC chips 411, its NVM IC chips 250, its VM IC chip 255, the other of its high bandwidth memory (HBM) IC chips 251 and 252, its input/output (I/O) or control chip 253, its cooperating and supporting (CS) logic IC chip 412, its dedicated control and input/output (I/O) chip 260, its digital-signal-processing (DSP) IC chip 270, its IAC chip 402 and another of its FPGA IC chips 200 and 201 selected in combination for one of the first, second and fifth alternatives. Alternatively, its fifth semiconductor IC chip 100e may be another of its FPGA IC chips 200 and/or 201 and its sixth semiconductor IC chip 100f may be one of its graphic-processing-unit (GPU) IC chips 269a, its central-processing-unit (CPU) IC chip 269b, its application-specific integrated-circuit (ASIC) IC chip or system-on chip (SoC) 269c, its auxiliary IC chips 411, its NVM IC chips 250, its VM IC chip 255, its high bandwidth memory (HBM) IC chips 251 and 252, its input/output (I/O) or control chip 253, its cooperating and supporting (CS) logic IC chip 412, its dedicated control and input/output (I/O) chip 260, its digital-signal-processing (DSP) IC chip 270, its IAC chip 402 and the other of its FPGA IC chips 200 and 201 selected in combination for one of the first, second and fifth alternatives. Alternatively, its fifth semiconductor IC chip 100e may be its VM IC chip 255 and its sixth semiconductor IC chip 100f may be one of its graphic-processing-unit (GPU) IC chips 269a, its central-processing-unit (CPU) IC chip 269b, its application-specific integrated-circuit (ASIC) IC chip or system-on chip (SoC) 269c, its auxiliary IC chips 411, its NVM IC chip 250, its high bandwidth memory (HBM) IC chips 251 and another of its FPGA IC chips 200 for the fifth alternative.

Referring to FIGS. 5A-1, 5A-2, 5A-5 and 5B-5D, for each of the first type of FPMCPs 300 for the first, second and fifth alternatives, by means of the field-programmable feature of each of its FPGA IC chips 200 and/or 201, the function of its first through sixth semiconductor IC chips 100a-100f may be changed or upgraded for specific applications even at a time when wafer processes are finished. Said each of the first type of FPMCPs 300 for the first, second and fifth alternatives may be changed for, for example, an upgrade of communications protocol, customized computing algorithms, localization of users, renewal of hardware or encryption for security. When a new application emerges, a speedy response to the market change could be achieved by re-configuring each of its FPGA IC chips 200 and/or 201 within a short period of time. There is no need to re-design/re-build of new semiconductor IC chips, resulting in cost saving. Taking development of artificial intelligence (AI) as an example, the algorithm of learning and inference may be optimized continuously based on accumulated results. Algorithms built on the hardware architecture of each of its FPGA IC chips 200 and/or 201 may be upgraded by configuring the hardware circuits of each of its FPGA IC chips 200 and/or 201 through software programming. Accordingly, said each of the first type of FPMCPs 300 for the first, second and fifth alternatives provides great flexibility during the development of artificial intelligence (AI).

For each of the first type of FPMCPs 300 for the first, second and fifth alternatives, each of its FPGA IC chips 200 and/or 201 may be programmed, configured or reconfigured in accordance with the CPM data to generate hardware electrical circuits for a specific computing purpose and then may cooperate with its logic computing IC chips, i.e., graphic-processing-unit (GPU) IC chips 269a, central-processing-unit (CPU) IC chip 269b, application-specific integrated-circuit (ASIC) chip or system-on-chip (SoC) chip 269c and/or digital-signal-processing (DSP) IC chip 270 selected in combination for one of the first, second and fifth alternatives, in executing computing processes. Each of its FPGA IC chips 200 and/or 201 may greatly accelerate the computing speed of its logic computing IC chips. For example, FIG. 5J is a block diagram for illustrating a method for optimizing performance of a first type of FPMCP for any first, second or fifth alternative for acceleration in accordance with an embodiment of the present application. Referring to FIGS. 5A-1, 5A-2, 5A-5 and 5J, the performance optimization and/or acceleration may be exercised on any one of its FPGA IC chips 200 and/or 201, any one of its graphic-processing-unit (GPU) IC chips 269a and its central-processing-unit (CPU) IC chip 269b. Said each of the first type of FPMCPs 300 for the first, second and fifth alternatives may be operated based on a CPU common programming language, such as python, JavaScript, Java, C#, C, or C++, Scala, Swift, Matlab, Assembly Language, Pascal, Visual Basic, or PL/SQL language, for the operations/processes of its central-processing-unit (CPU) IC chip 269b. Its central-processing-unit (CPU) IC chip 269b is configured to (1) analyze and assess an incoming software program for a requested job, written by one of the CPU common programming languages, to perform multiple operation/process steps, and (2) decide which of said any one of its FPGA IC chips 200 and/or 201, said any one of its graphic-processing-unit (GPU) IC chips 269a and its central-processing-unit (CPU) IC chip 269b is used for performance optimization and/or acceleration to perform which of the operation/process steps. For example, in the performance optimization and/or acceleration for said each of the first type of FPMCPs 300 for the first, second and fifth alternatives, the incoming software program for a requested job may be first analyzed by its central-processing-unit (CPU) IC chip 269b to determine six operation/process steps, comprising (1) a first stream for multiple operation/process steps 1-4 to be processed or performed in series, (2) a second stream for an operation/process step 1a to be processed or performed in parallel with the first stream, and (3) a third stream for an operation/process step 1b to be processed or performed in parallel with the first and second streams. Its central-processing-unit (CPU) IC chip 269b may assign or dispatch the operation/process steps 1a and 2 to said any one of its graphic-processing-unit (GPU) IC chips 269a and the operation/process steps 1b and 3 to said any one of its FPGA IC chips 200 and/or 201. Its central-processing-unit (CPU) IC chip 269b may compile or translate a first programming language, i.e., one of the CPU common languages, for the operation/process step 1a in the second stream and the operation/process step 2 in the first stream into a second programming language, such as language of compute unified device architecture (CUDA), for said any one of its graphic-processing-unit (GPU) IC chips 269a, and the first programming language for the operation/process step 1b in the third stream and the operation/process step 3 in the first stream into a third programming language, such as language of open computing language (Open CL), for said any one of its FPGA IC chips 200 and/or 201. The programming language of CUDA is developed for said any one of its graphic-processing-unit (GPU) IC chips 269a for general-purpose computing, called as general-purpose computing on graphic processing units (GPGPU), comprising reduced-instruction-set-computer (RISC) instructions in an instruction set for highly-parallel operation/process with a bit width equal to or greater than 256, 512, 1024, 2048, 5120, 10240 bits for example.

Referring to FIGS. 5A-1, 5A-2, 5A-5 and 5J, for the second stream, said anyone of its graphic-processing-unit (GPU) IC chips 269a may preform the operation/process step 1a in the second stream based on the second programming language for the operation/process step 1a, in parallel with the first and third streams, to generate or return a computing/process (C/P) result out of the operation/process step 1a to its central-processing-unit (CPU) IC chip 269b as a first input data set for the operation/process step 4. For the first stream, after its central-processing-unit (CPU) IC chip 269b performs the operation/process step 1 based on the first programming language for the operation/process step 1 to generate a computing/process (C/P) result as an output data set for the operation/process step 1, said any one of its graphic-processing-unit (GPU) IC chips 269a may preform the operation/process step 2 on the output data set for the operation/process step 1 based on the second programming language for the operation/process step 2, in parallel with the second and third streams, to generate or return a computing/process (C/P) result out of the operation/process step 2 to its central-processing-unit (CPU) IC chip 269b as an input data set for the operation/process step 3. In an example, said any one of its graphic-processing-unit (GPU) IC chips 269a may preform the operation/process step 2 before said any one of its graphic-processing-unit (GPU) IC chips 269a preforms the operation/process step 1a. Alternatively, said any one of its graphic-processing-unit (GPU) IC chips 269a may preform the operation/process step 2 after said any one of its graphic-processing-unit (GPU) IC chips 269a preforms the operation/process step 1a. Alternatively, said any one of its graphic-processing-unit (GPU) IC chips 269a may preform the operation/process steps 1a and 2 at the same time.

Referring to FIGS. 5A-1, 5A-2, 5A-5 and 5J, for the third stream, its central-processing-unit (CPU) IC chip 269b may (1) generate CPM data, that is debugged and verified, in accordance with the first programming language for the operation/process step 1b to be passed to its NVM IC chip 250 or either and stored therein and then to be downloaded to said any one of its FPGA IC chips 200 and/or 201 from its NVM IC chip 250 or said either to program, configure or reconfigure said any one of its FPGA IC chips 200 and/or 201, or (2) send an instruction to its NVM IC chip 250 or said either to select, in accordance with the first programming language for the operation/process step 1b, a first specific set from multiple sets of CPM data, i.e., resulting values or programmable codes, stored in its NVM IC chip 250 or said either to be downloaded to said any one of its FPGA IC chips 200 and/or 201 to program, configure or reconfigure said any one of its FPGA IC chips 200 and/or 201. Said any one of its FPGA IC chips 200 and/or 201 may preform or execute the operation/process step 1b in the third stream based on the third programming language for the operation/process step 1b, in parallel with the first and second streams, to generate or return a computing/process (C/P) result out of the operation/process step 1b to its central-processing-unit (CPU) IC chip 269b as a second input data set for the operation/process step 4.

Referring to FIGS. 5A-1, 5A-2, 5A-5 and 5J, for the first stream, after said any one of its FPGA IC chips 200 and/or 201 preforms the operation/process step 1b, said any one of its FPGA IC chips 200 and/or 201 may (1) generate CPM data, that is debugged and verified, in accordance with the first programming language for the operation/process step 3 to be passed to its NVM IC chip 250 or said either and stored therein and then to be downloaded to said any one of its FPGA IC chips 200 and/or 201 from its NVM IC chip 250 or said either to program, configure or reconfigure said any one of its FPGA IC chips 200 and/or 201, or (2) send an instruction to its NVM IC chip 250 or said either to select, in accordance with the first programming language for the operation/process step 3, a second specific set from the multiple sets of CPM data, i.e., resulting values or programmable codes, stored in its NVM IC chip 250 or said either to be downloaded to said any one of its FPGA IC chips 200 and/or 201 to program, configure or reconfigure said any one of its FPGA IC chips 200 and/or 201, and after its central-processing-unit (CPU) IC chip 269b receives the input data set for the operation/process step 3 from said any one of its graphic-processing-unit (GPU) IC chips 269a, said any one of its FPGA IC chips 200 and/or 201 may perform the operation/process step 3 on the input data set for the operation/process step 3 based on the third programming language for the operation/process step 3, in parallel with the second and third streams, to generate or return a computing/process (C/P) result out of the operation/process step 3 to its central-processing-unit (CPU) IC chip 269b as a third input data set for the operation/process step 4. For more elaboration, each set of the multiple sets of CPM data was developed, compiled, verified and debugged for a specific purpose or application before stored in its NVM IC chip 250 or said either. The number of the multiple sets of CPM data may be equal to or greater than 2, 3, 4, 5, 10, 20, 50 or 100. Said any one of its FPGA IC chips 200 and/or 201 may be programmed, configured or reconfigured as a computing/processing accelerator to speed up the operation/process steps 1b and 3.

Next, referring to FIGS. 5A-1, 5A-2, 5A-5 and 5J, after its central-processing-unit (CPU) IC chip 269b receives the first input data set for the operation/process step 4 from said any one of its graphic-processing-unit (GPU) IC chips 269a and the second and third input data sets for the operation/process step 4 from said any one of its FPGA IC chips 200 and/or 201, its central-processing-unit (CPU) IC chip 269b may preform the operation/process step 4 on the first, second and third input data sets for the operation/process step 4 based on the first programming language for the operation/process step 4.

Referring to FIGS. 5A-1, 5A-2, 5A-5 and 5J, for each of the first type of FPMCPs 300 for the first, second and fifth alternatives, each of its FPGA IC chips 200 and/or 201, graphic-processing-unit (GPU) IC chips 269a and central-processing-unit (CPU) IC chip 269b may couple to one of the small input/output (I/O) circuits of the small-input/output (I/O) block of one of its auxiliary IC chips 411 through one of the programmable or non-programmable interconnects 361 or 364 of its inter-chip interconnects 371. The large input/output (I/O) circuits 341 of the large-input/output (I/O) block of said one of its auxiliary IC chips 411 may couple to the external circuit 340 of said each of the first type of FPMCPs for the first, second and fifth alternatives 300 through various input/output (I/O) formats, protocols or industry standards such as Ethernet, peripheral component interconnect express (PCIe), serial-advanced-technology-attachment (SATA), universal chiplet interconnect express (UCIe), universal serial bus (USB), serializer/deserializer (SerDes), Wi-Fi (wireless fidelity) or Thunderbolt.

### First Structure for First Type of FPMCP

FIG. 6A is a schematically cross-sectional view showing a first structure for a first type of FPMCP for any first, second or fifth alternative in accordance with an embodiment of the present application. FIG. 6B is a schematically cross-sectional view showing a first structure for a first type of FPMCP for either third or fourth alternative in accordance with an embodiment of the present application. The first structure 301 may be fabricated for each of the first type of FPMCPs 300 for the first, second and fifth alternatives as illustrated in FIGS. 5A-1, 5A-2 and 5A-5, wherein FIG. 6A is a schematically cross-sectional view along a cross-sectional line A-A in any FIG. 5A-1, 5A-2 or 5A-5. Alternatively, the first structure 301 may be fabricated for each of the first type of FPMCPs 300 for the third and fourth alternatives as illustrated in FIGS. 5A-3 and 5A-4, wherein FIG. 6B is a schematically cross-sectional view along a cross-sectional line C-C in either FIG. 5A-3 or 5A-4. Referring to FIGS. 5A-1, 5A-2, 5A-3, 5A-4, 5A-5, 6A and 6B, the first structure 301 for each of the first type of field-programmable multi-chip packages 300 for the first through fifth alternatives may include (1) an interposer 551, which is a passive device or component without any transistor therein, and (2) the semiconductor IC chips 200, 250, 269a, 269b, 269c, 251 and 411 as illustrated in FIG. 5A-1 for the first alternative, the semiconductor IC chips 200, 250, 269a, 269b, 251, 270, 402 and 411 and first, second and third types of subsystem units 401, 403 and 404 as illustrated in FIG. 5A-2 for the second alternative, the semiconductor IC chips 601, 269a, 269b, 269c, 602 and 603 and FPGA/NVM multi-chip package 259 as illustrated in FIG. 5A-3 for the third alternative, or the semiconductor IC chips 601, 269a, 269b, 269c, 270, 602 and 603 and FPGA/NVM multi-chip package 259 as illustrated in FIG. 5A-4 for the fourth alternative, or the semiconductor IC chips 200, 250, 255, 269a, 269b, 269c, 251 and 411 as illustrated in FIG. 5A-5 for the fifth alternative, over its interposer 551. Each of its semiconductor IC chips 200, 250, 269a, 269b, 269c, 251 and 411 for the first alternative, each of its semiconductor IC chips 200, 250, 269a, 269b, 251, 270, 402 and 411 for the second alternative, each of its semiconductor IC chips 601, 269a, 269b, 269c, 602 and 603 for the third alternative, or each of its semiconductor IC chips 601, 269a, 269b, 269c, 270, 602 and 603 for the fourth alternative, or each of its semiconductor IC chips 200, 250, 255, 269a, 269b, 269c, 251 and 411 for the fifth alternative, may have the same specification as the first type of semiconductor IC chip 100 illustrated in FIG. 3A to be turned upside down.

Referring to FIGS. 5A-1, 5A-2. 5A-3, 5A-4, 5A-5, 6A and 6B, for the first structure 301 for each of the first type of field-programmable multi-chip packages 300 for the first through fifth alternatives, its interposer 551 may include (1) a silicon substrate 552, (2) multiple through silicon vias (TSVs) 558 extending vertically through the silicon substrate 552 of its interposer 551, (3) an interconnection scheme over the silicon substrate 552, having the same specification as illustrated for the FISC 20, SISC 29 or combination of FISC 20 and SISC 29 in FIGS. 3A, 3B and 3G-3J, wherein the interconnection scheme of its interposer 551 may be formed for the programmable interconnects 361 and non-programmable interconnects 364 of the inter-chip interconnects 371 of said each of the first type of field-programmable multi-chip packages 300 for the first through fifth alternatives as illustrated in FIGS. 5A-1, 5A-2, 5A-3, 5A-4 and 5A-5, including multiple interconnection metal layers 67 over the silicon substrate 552 of its interposer 551, coupling to the through silicon vias 558 of its interposer 551 and each having the same specification as that of the interconnection metal layer 6 of the FISC 20 or that of the interconnection metal layer 27 of the SISC 27, and multiple insulating dielectric layers 112 each between neighboring two of the interconnection metal layers 67 of its interposer 551, under the bottommost one of the interconnection metal layers 67 of its interposer 551 or over the topmost one of the interconnection metal layers 67 of its interposer 551, each having the same specification as that of the insulating dielectric layer 12 of the FISC 20 or that of polymer layer 42 of the SISC 29, and (4) an insulating dielectric layer 585, such as silicon-oxide layer or silicon-nitride layer, on a bottom surface of the silicon substrate 552 of its interposer 551, wherein the insulating dielectric layer 585 may have a bottom surface coplanar with a bottom surface of each of the through silicon vias 558. Each of the through silicon vias 558 of its interposer 551 may include a copper layer 557 extending vertically through the silicon substrate 552 of its interposer 551. Its interposer 551 may include an insulating lining layer 555 around a sidewall of the copper layer 557 of said each of the through silicon vias 558 and in the silicon substrate 552 of its interposer 551. Said each of the through silicon vias 558 of its interposer 551 may include an adhesion metal layer 556 around the sidewall of the copper layer 557 of said each of the through silicon vias 558 and between the copper layer 557 of said each of the through silicon vias 558 and the insulating lining layer 555 of its interposer 551, and an electroplating seed layer 559 around the sidewall of the copper layer 557 of said each of the through silicon vias 558 and between the copper layer 557 of said each of the through silicon vias 558 and the adhesion metal layer 556 of said each of the through silicon vias 558. Said each of the through silicon vias 558, i.e., the copper layer 557 thereof, may have a depth between 30 μm and 150 μm, or 50 μm and 100 μm, and a diameter or largest transverse size between 5 μm and 50 μm, or 5 μm and 15 μm. The adhesion metal layer 556 of said each of the through silicon vias 558 may include a titanium (Ti) or titanium nitride (TiN) layer having a thickness between 1 nm to 50 nm. The electroplating seed layer 559 of said each of the through silicon vias 558 may be a copper layer having a thickness of between 3 nm and 200 nm. The insulating lining layer 555 of its interposer 551 may include a thermally grown silicon oxide (SiO₂) and/or a CVD silicon nitride (Si₃N₄), for example.

Referring to FIGS. 5A-1, 5A-2, 5A-5 and 6A, for the first structure 301 for said each of the first type of field-programmable multi-chip packages 300 for the first, second and fifth alternatives, each of its semiconductor IC chips 200, 250, 269a, 269b, 269c, 251 and 411 as illustrated in FIG. 5A-1 for the first alternative, or each of its semiconductor IC chips 200, 250, 269a, 269b, 251, 270, 402 and 411 and first, second and third types of subsystem units 401, 403 and 404 as illustrated in FIG. 5A-2 for the second alternative, or each of its semiconductor IC chips 200, 250, 255, 269a, 269b, 269c, 251 and 411 as illustrated in FIG. 5A-5 for the fifth alternative, may have the first, second, third or fourth type of micro-bumps, micro-pillars or micro-pads 34 each bonded to a metal contact 349, such as copper contact or tin-containing contact, preformed on one of the metal pads of the topmost one of the interconnection metal layers 67 of its interposer 551 to form multiple bonded metal bumps or contacts 563 between said each of its semiconductor IC chips 200, 250, 269a, 269b, 269c, 251 and 411 for the first alternative, or said each of its semiconductor IC chips 200, 250, 269a, 269b, 251, 270, 402 and 411 and first, second and third types of subsystem units 401, 403 and 404 for the second alternative, or said each of its semiconductor IC chips 200, 250, 255, 269a, 269b, 269c, 251 and 411 for the fifth alternative, and its interposer 551. For example, each of its bonded metal bumps or contacts 563 may include (1) a copper layer having a thickness between 1 μm and 60 μm, between 2 μm and 20 μm or between 10 μm and 50 μm between said each of its semiconductor IC chips 200, 250, 269a, 269b, 269c, 251 and 411 for the first alternative, or said each of its semiconductor IC chips 200, 250, 269a, 269b, 251, 270, 402 and 411 and first, second and third types of subsystem units 401, 403 and 404 for the second alternative, or said each of its semiconductor IC chips 200, 250, 255, 269a, 269b, 269c, 251 and 411 for the fifth alternative, and its interposer 551, and (2) a solder cap, made of a tin-silver alloy, a tin-gold alloy, a tin-copper alloy, a tin-indium alloy, indium or tin, having a thickness of between 1 μm and 15 μm, between 1 μm and 50 μm or between 20 μm and 100 μm between the copper layer of said each of its bonded metal bumps or contacts 563 and its interposer 551. The first structure 301 for said each of the first type of field-programmable multi-chip packages 300 for the first, second and fifth alternatives may further include (1) an underfill 564, i.e., polymer layer, between each of its semiconductor IC chips 200, 250, 269a, 269b, 269c, 251 and 411 for the first alternative, or each of its semiconductor IC chips 200, 250, 269a, 269b, 251, 270, 402 and 411 and first, second and third types of subsystem units 401, 403 and 404 for the second alternative, or each of its semiconductor IC chips 200, 250, 255, 269a, 269b, 269c, 251 and 411 for the fifth alternative, and its interposer 551, covering a sidewall of each of its bonded metal bumps or contacts 563, (2) a polymer layer 92 or insulating dielectric layer, i.e., sealing layer, such as silicon-oxide-containing molding compound, epoxy-based material or polyimide, on a top surface of its interposer 551 and horizontally around each of its semiconductor IC chips 200, 250, 269a, 269b, 269c, 251 and 411 for the first alternative, or each of its semiconductor IC chips 200, 250, 269a, 269b, 251, 270, 402 and 411 and first, second and third types of subsystem units 401, 403 and 404 for the second alternative, or each of its semiconductor IC chips 200, 250, 255, 269a, 269b, 269c, 251 and 411 for the fifth alternative, wherein its polymer layer 92 may have a top surface coplanar with a top surface of each of its semiconductor IC chips 200, 250, 269a, 269b, 269c, 251 and 411 for the first alternative, or a top surface of each of its semiconductor IC chips 200, 250, 269a, 269b, 251, 270, 402 and 411 and first, second and third types of subsystem units 401, 403 and 404 for the second alternative, or a top surface of each of its semiconductor IC chips 200, 250, 255, 269a, 269b, 269c, 251 and 411 for the fifth alternative, and (3) multiple metal bumps, pillars or pads 570 in an array at its bottom to act as its external pins for coupling to the external circuits 340 as seen in FIG. 5D-5G or 5K outside of the first structure 301 for said each of the first type of field-programmable multi-chip packages 300 for the first, second and fifth alternatives, wherein each of its metal bumps, pillars or pads 570 may be formed on a bottom surface of one of the through silicon vias 558, i.e., the copper layer 557 thereof, of its interposer 551 and on a bottom surface of the insulating dielectric layer 585 of its interposer 551. Each of its semiconductor IC chips 200, 250, 269a, 269b, 269c, 251 and 411 for the first alternative, or each of its semiconductor IC chips 200, 250, 269a, 269b, 251, 270, 402 and 411 and first, second and third types of subsystem units 401, 403 and 404 for the second alternative, or each of its semiconductor IC chips 200, 250, 255, 269a, 269b, 269c, 251 and 411 for the fifth alternative, may couple to one of its metal bumps, pillars or pads 570 for external connection through, in sequence, each of the interconnection metal layers 67 of its interposer 551 and any of the through silicon vias 558 of its interposer 551. Its polymer layer 92 may have a vertical sidewall coplanar with a vertical sidewall of its interposer 551.

Referring to FIGS. 5A-1, 5A-2, 5A-5 and 6A, for the first structure 301 for each of the first type of field-programmable multi-chip packages 300 for the first, second and fifth alternatives, each of its metal bumps, pillars or pads 570 may be of one type of various types, i.e., first and second types. Each of its first type of metal bumps, pillars or pads 570 may include (1) an adhesion metal layer 26a, such as titanium (Ti) or titanium nitride (TiN) layer having a thickness between 1 nm and 50 nm, on the bottom surface of one of the through silicon vias 558, i.e., the copper layer 557 thereof, of its interposer 551 and on the bottom surface of the insulating dielectric layer 585 of its interposer 551, (2) an electroplating seed layer 26b, such as copper, on and under the adhesion metal layer 26a of said each of its first type of metal bumps, pillars or pads 570 and (3) a copper layer 32 having a thickness between 1 μm and 60 μm on and under the electroplating seed layer 26b of said each of its first type of metal bumps, pillars or pads 570. Alternatively, each of its second type of metal bumps, pillars or pads 570 may include the adhesion metal layer 26a, seed layer 26b and copper layer 32 as mentioned for its first type of metal bump, pillar or pad 570, and may further include a tin-containing solder cap 33 made of tin or a tin-silver alloy having a thickness between 1 μm and 50 μm or between 20 μm and 100 m on and under the copper layer 32 of said each of its second type of metal bumps, pillars or pads 570.

Alternatively, for the first structure 301 for each of the first type of field-programmable multi-chip packages 300 for the first, second and fifth alternatives, the silicon substrate 552 of its interposer 551 may be replaced with the semiconductor substrate 2 as illustrated in FIG. 3A, the through silicon vias (TSVs) 558 of its interposer 551 may be replaced with the through silicon vias (TSVs) 157 as illustrated in FIGS. 3B and 3G-3J, the insulating lining layer 555 of its interposer 551 may be replaced with the insulating lining layer 153 as illustrated in FIGS. 3B and 3G-3J, and the interconnection scheme of its interposer 551 may include the first interconnection scheme for a chip (FISC) 20 as illustrated in FIGS. 3B and 3G-3J. Accordingly, in a first aspect for its interposer 551, its interposer 551 may have the same specification as illustrated for any kind of the second through fourth kinds of connection structures for the through silicon vias 157 (TSVs) and the first interconnection scheme for a chip (FISC) for the second type of semiconductor IC chip 100 as shown in FIGS. 3G-3J. The semiconductor substrate 2 of its interposer 551 may have a lower portion to be removed using a chemical-mechanical-polishing (CMP) process to expose a bottom surface of each of the through silicon vias 157 (TSVs) of its interposer 551. Further, the insulating lining layer 153 of its interposer 551 at a bottom of the electroplated copper layer 156 of each of the through silicon vias 157 (TSVs) of its interposer 551 and the adhesion metal layer 154 and electroplating seed layer 155 at the bottom of the electroplated copper layer 156 of said each of the through silicon vias 157 (TSVs) may be removed to expose a bottom surface of the electroplated copper layer 156 of said each of the through silicon vias 157 (TSVs). Next, the semiconductor substrate 2 of its interposer 551 may be etched to form a recess from the bottom surface of the electroplated copper layer 156 of said each of the through silicon vias 157 (TSVs). Next, the insulating dielectric layer 585 of its interposer 551 as illustrated in FIG. 6A may be formed in the recess and on a bottom surface of the semiconductor substrate 2 of its interposer 551 and on the bottom surface of the electroplated copper layer 156 of said each of the through silicon vias 157 (TSVs). Next, the insulating dielectric layer 585 of its interposer 551 under said each of the through silicon vias 157 (TSVs) may be removed to have a bottom surface coplanar with the bottom surface of the electroplated copper layer 156 of said each of the through silicon vias 157 (TSVs). Next, each of its first or second type of metal bumps, pillars or pads 570 as illustrated in FIG. 6A may have the adhesion metal layer 26a thereof formed on the bottom surface of the electroplated copper layer 156 of one of the through silicon vias 157 (TSVs) of its interposer 551 and the bottom surface of the insulating dielectric layer 585 of its interposer 551. Alternatively, in a second aspect for its interposer 551, each of its first or second type of metal bumps, pillars or pads 570 as illustrated in FIG. 6A may have the adhesion metal layer 26a thereof formed on the bottom surface of the electroplated copper layer 156 of each of the set of through silicon vias 157 (TSVs) of its interposer 551 and the bottom surface of the insulating dielectric layer 585 of its interposer 551 to couple the set of through silicon vias 157 (TSVs) of its interposer 551, wherein the reference layer 6f of the first interconnection scheme for a chip (FISC) 20 of its interposer 551 for the second kind as illustrated in FIGS. 3G and 3H may couple the set of through silicon vias 157 (TSVs) of its interposer 551, the reference layer 6f of the first interconnection scheme for a chip (FISC) 20 of its interposer 551 for the third kind as illustrated in FIG. 3I may couple the set of through silicon vias 157 (TSVs) of its interposer 551, and the second portion of the bottommost one of the interconnection metal layers 6 of the first interconnection scheme for a chip (FISC) 20 of its interposer 551 for the fourth kind as illustrated in FIG. 3J may couple the set of through silicon vias 157 (TSVs) of its interposer 551, wherein a pitch or space between each neighboring two of the set of through silicon vias 157 (TSVs) of its interposer 551, i.e., the electroplated copper layers 156 thereof, may be between 5 and 50 micrometers.

Alternatively, FIG. 6C is a schematically cross-sectional view showing a second type of metal bump, pillar or pad provided under two through silicon vias (TSVs) in accordance with an embodiment of the present application. Referring to FIG. 6C, with regard to the first structure 301 for each of the first type of field-programmable multi-chip packages 300 for the first, second and fifth alternatives, for any kind of the second through fourth kinds of connection structures for the through silicon vias 157 (TSVs) and the first interconnection scheme for a chip (FISC) for a third aspect for its interposer 551, the third aspect for its interposer 551 may have a similar structure to the second aspect for its interposer 551. In FIG. 6C, its interposer 551 takes the fourth kind as an example. The difference therebetween is that for the third aspect its interposer 551 may further include an insulating dielectric layer 587, such as polymer, silicon oxide, silicon oxynitride or silicon nitride, having a thickness between 0.5 and 10 micrometers on the bottom surface of the insulating dielectric layer 585 of its interposer 551 as illustrated for the second aspect for its interposer 551, wherein an opening in the insulating dielectric layer 587 of its interposer 551 may be vertically under the set of through silicon vias 157 (TSVs) of its interposer 551 and said each of its first or second type of metal bumps, pillars or pads 570 as illustrated in FIG. 6A may be formed in and under the opening in the insulating dielectric layer 587 of its interposer 551 and under and on a bottom surface of the insulating dielectric layer 587 of its interposer 551 and have the adhesion metal layer 26a thereof formed on the bottom surface of the electroplated copper layer 156 of each of the set of through silicon vias 157 (TSVs) of its interposer 551, the bottom surface of the insulating dielectric layer 585 of its interposer 551 and the bottom surface of the insulating dielectric layer 587 of its interposer 551 to couple the set of through silicon vias 157 (TSVs) of its interposer 551.

Referring to FIGS. 5A-3, 5A-4 and 6B, for the first structure 301 for said each of the first type of field-programmable multi-chip packages 300 for the third and fourth alternatives, each of its semiconductor IC chips 601, 269a, 269b, 269c, 260, 602 and 603 as illustrated in FIG. 5A-3 for the third alternative, or each of its semiconductor IC chips 601, 269a, 269b, 269c, 270, 260, 602 and 603 as illustrated in FIG. 5A-4 for the fourth alternative, may have the first, second, third or fourth type of micro-bumps, micro-pillars or micro-pads 34 bonded to its interposer 551, which may have the same specification as that of the interposer 551 illustrated in FIG. 6A, to form multiple bonded metal bumps or contacts 563 between said each of its semiconductor IC chips 601, 269a, 269b, 269c, 260, 602 and 603 for the third alternative, or said each of its semiconductor IC chips 601, 269a, 269b, 269c, 270, 260, 602 and 603 for the fourth alternative, and its interposer 551. For example, each of its bonded metal bumps or contacts 563 may include (1) a copper layer having a thickness between 1 μm and 60 μm, between 2 μm and 20 μm or between 10 μm and 50 μm between said each of its semiconductor IC chips 601, 269a, 269b, 269c, 260, 602 and 603 for the third alternative, or said each of its semiconductor IC chips 601, 269a, 269b, 269c, 270, 260, 602 and 603 for the fourth alternative, and its interposer 551, and (2) a solder cap, made of a tin-silver alloy, a tin-gold alloy, a tin-copper alloy, a tin-indium alloy, indium or tin, having a thickness of between 1 μm and 15 μm, between 1 μm and 50 μm or between 20 μm and 100 μm between the copper layer of said each of its bonded metal bumps or contacts 563 and its interposer 551.

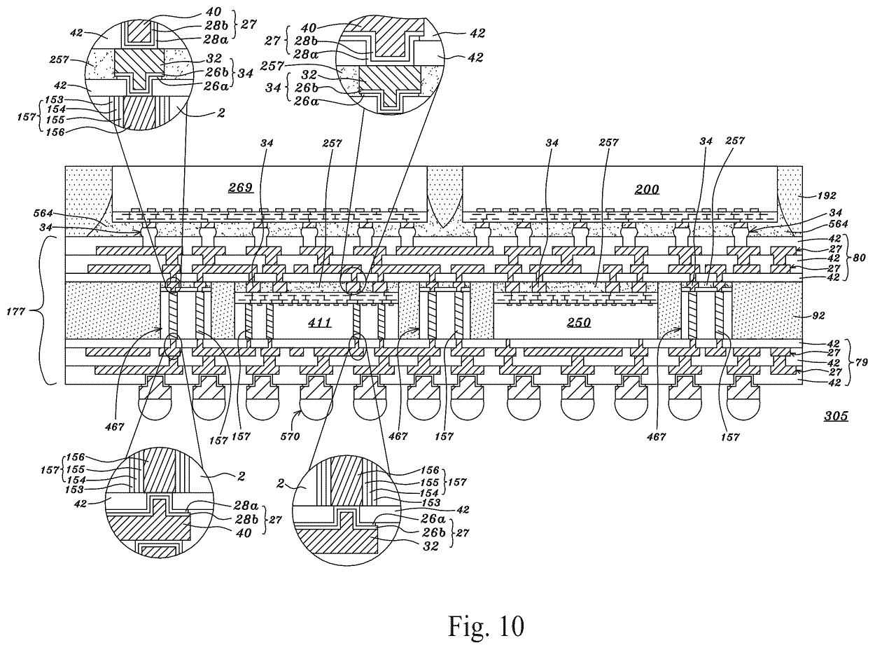

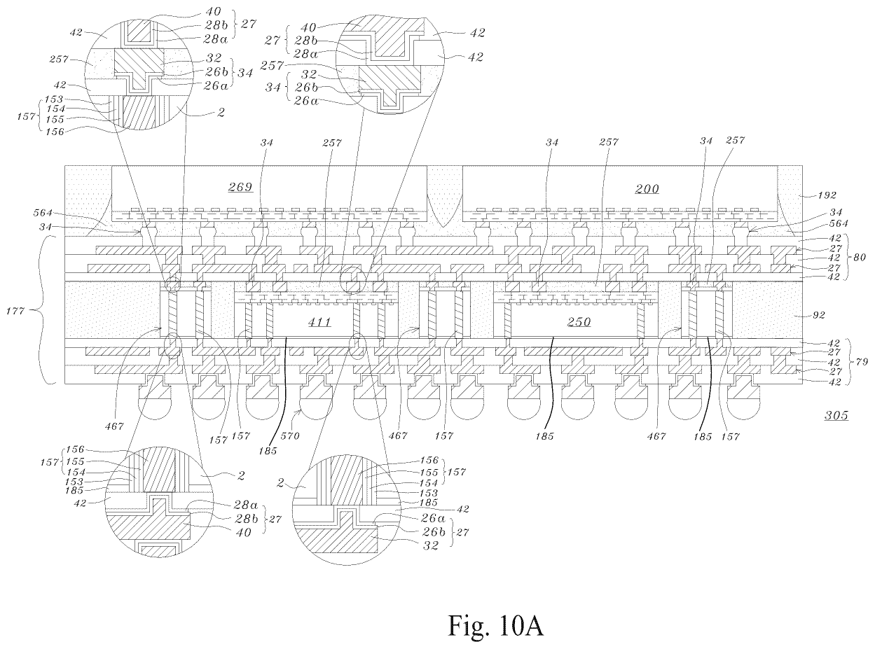

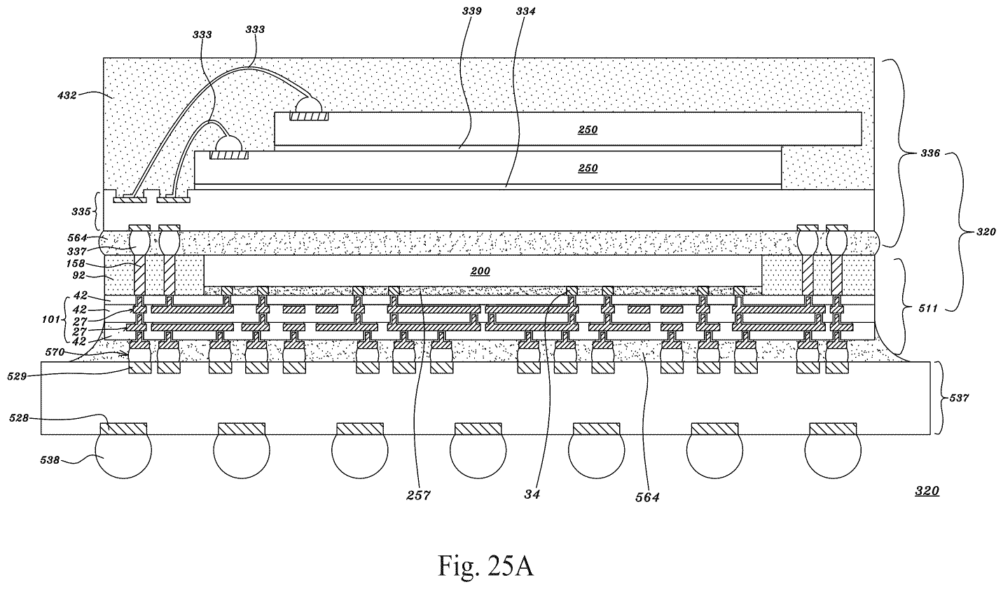

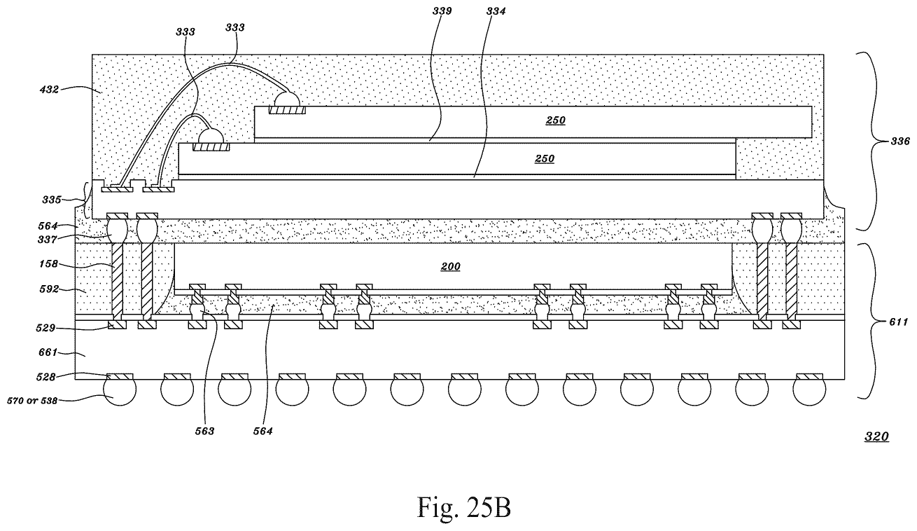

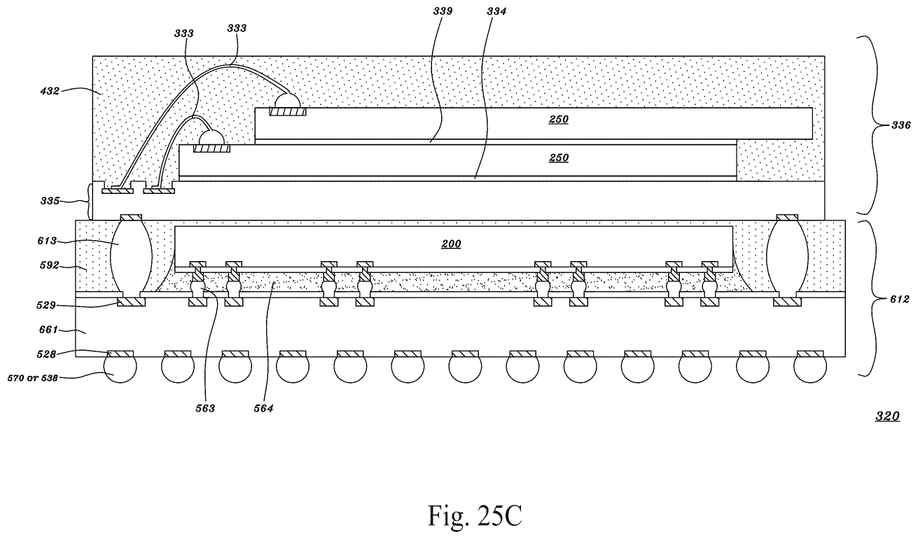

Further, for the first structure 301 for said each of the first type of field-programmable multi-chip packages 300 for the third and fourth alternatives, its FPGA/NVM multi-chip package 259 may be any type of the second through eighth types and twelfth through fourteenth types of FPMCPs 305-311 and 315-317 as seen in FIGS. 10, 11, 12, 13A, 13B, 14, 15A, 15B, 16, 20, 21 and 22 and the seventeenth type of FPMCPs 320 for the first through third alternatives as seen in FIGS. 25A-25C with the metal bumps, pillars or pads 570 at the bottom thereof bonded to its interposer 551, which may have the same specification as that of the interposer 551 illustrated in FIG. 6A, to form multiple bonded metal bumps or contacts 574 between its FPGA/NVM multi-chip package 259 and interposer 551; for example, each of its bonded metal bumps or contacts 574 may include (1) a copper layer having a thickness between 1 μm and 60 μm, between 2 μm and 20 μm or between 10 μm and 50 μm between its FPGA/NVM multi-chip package 259 and interposer 551, and (2) a solder cap, made of a tin-silver alloy, a tin-gold alloy, a tin-copper alloy, a tin-indium alloy, indium or tin, having a thickness of between 1 μm and 15 μm, between 1 μm and 50 μm or between 20 μm and 100 μm between the copper layer of said each of its bonded metal bumps or contacts 574 and its interposer 551.

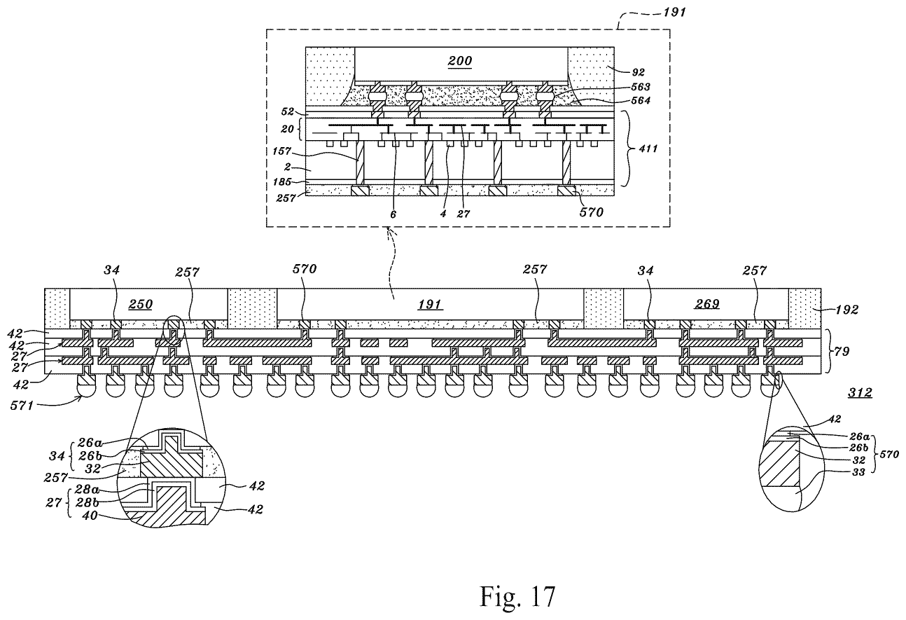

Alternatively, for the first structure 301 for said each of the first type of field-programmable multi-chip packages 300 for the third and fourth alternatives, its FPGA/NVM multi-chip package 259 may be the ninth type of FPMCP 312 as seen in FIG. 17 with the metal bumps, pillars or pads 571 at the bottom thereof bonded to its interposer 551 to form multiple bonded metal bumps or contacts 574 between its FPGA/NVM multi-chip package 259 and interposer 551, which may have the same specification as that of the interposer 551 illustrated in FIG. 6A; for example, each of its bonded metal bumps or contacts 574 may include (1) a copper layer having a thickness between 1 μm and 60 μm, between 2 μm and 20 μm or between 10 μm and 50 μm between its FPGA/NVM multi-chip package 259 and interposer 551, and (2) a solder cap, made of a tin-silver alloy, a tin-gold alloy, a tin-copper alloy, a tin-indium alloy, indium or tin, having a thickness of between 1 μm and 15 μm, between 1 μm and 50 μm or between 20 μm and 100 m between the copper layer of said each of its bonded metal bumps or contacts 574 and its interposer 551.

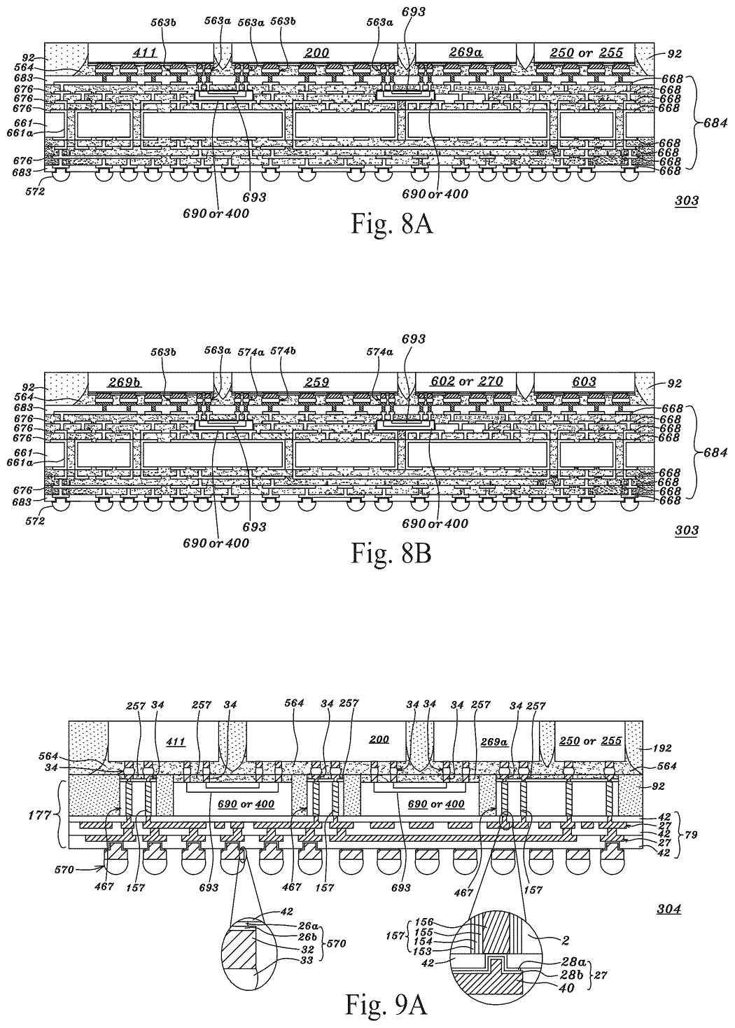

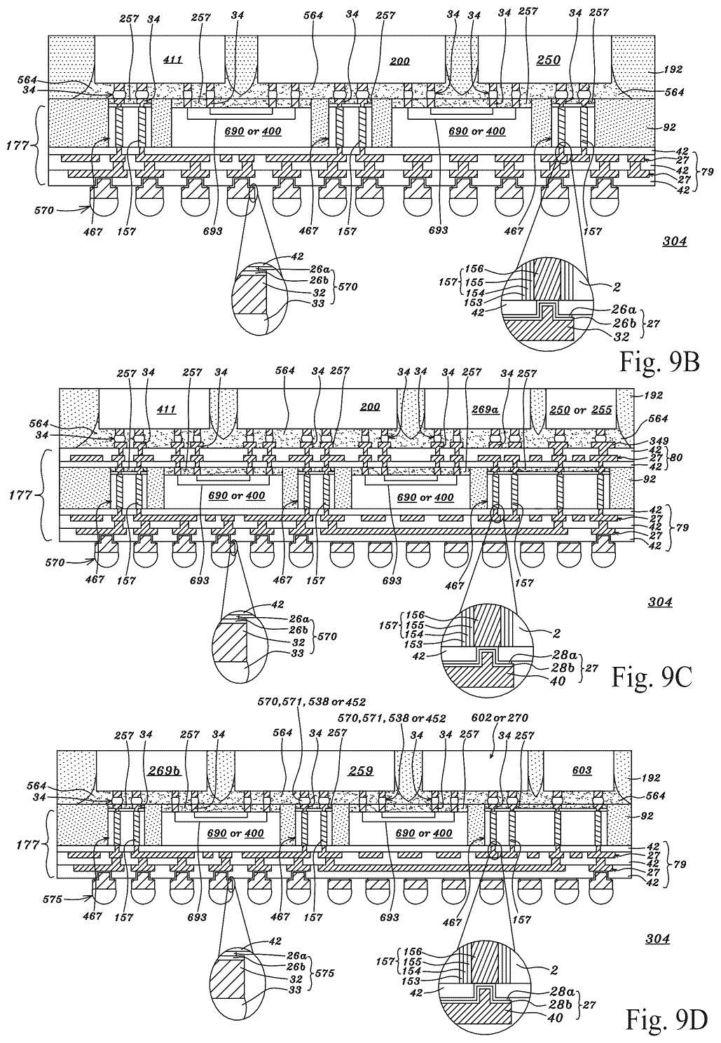

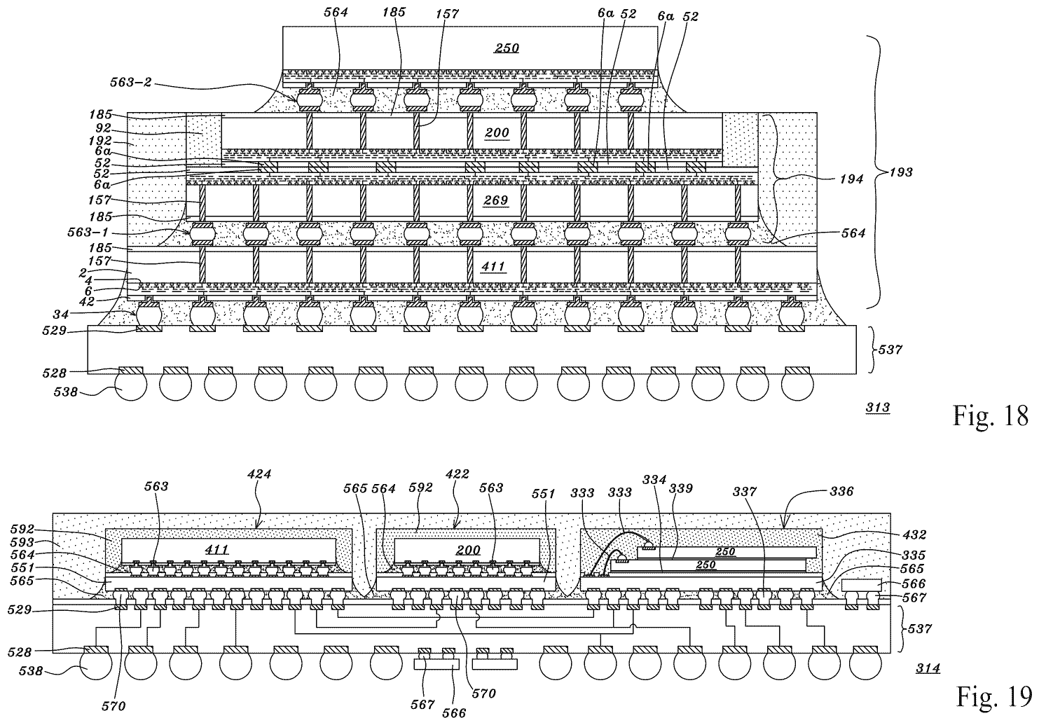

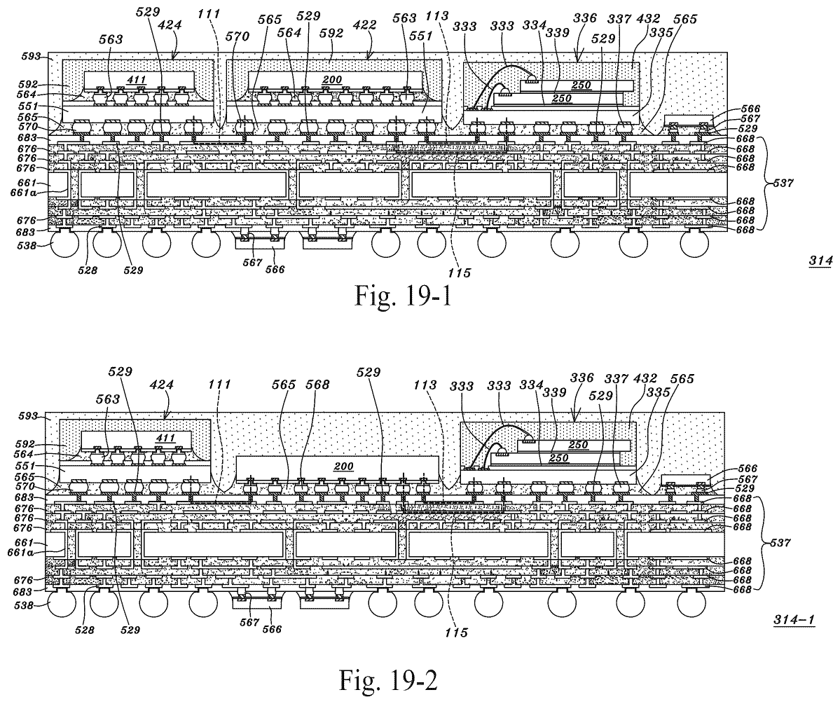

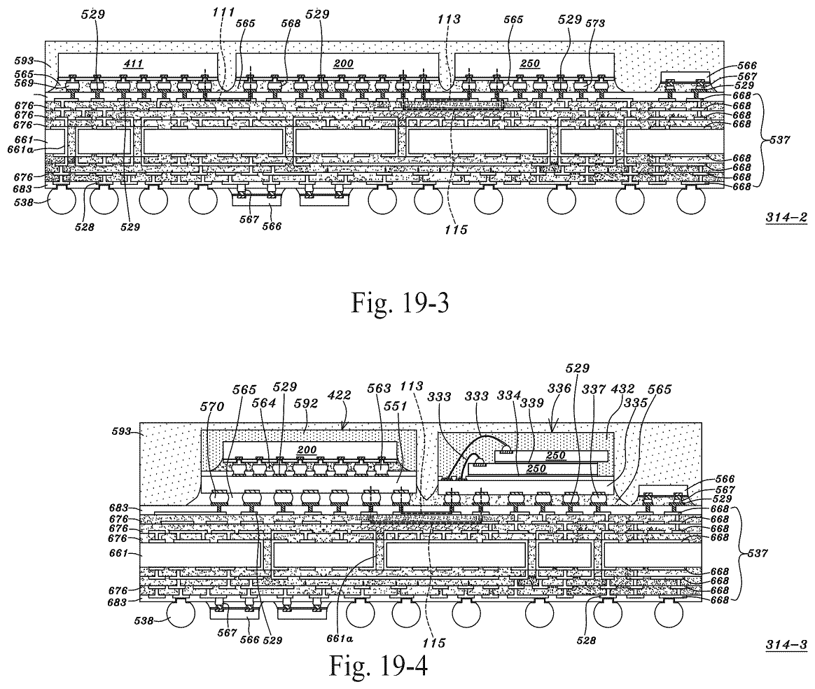

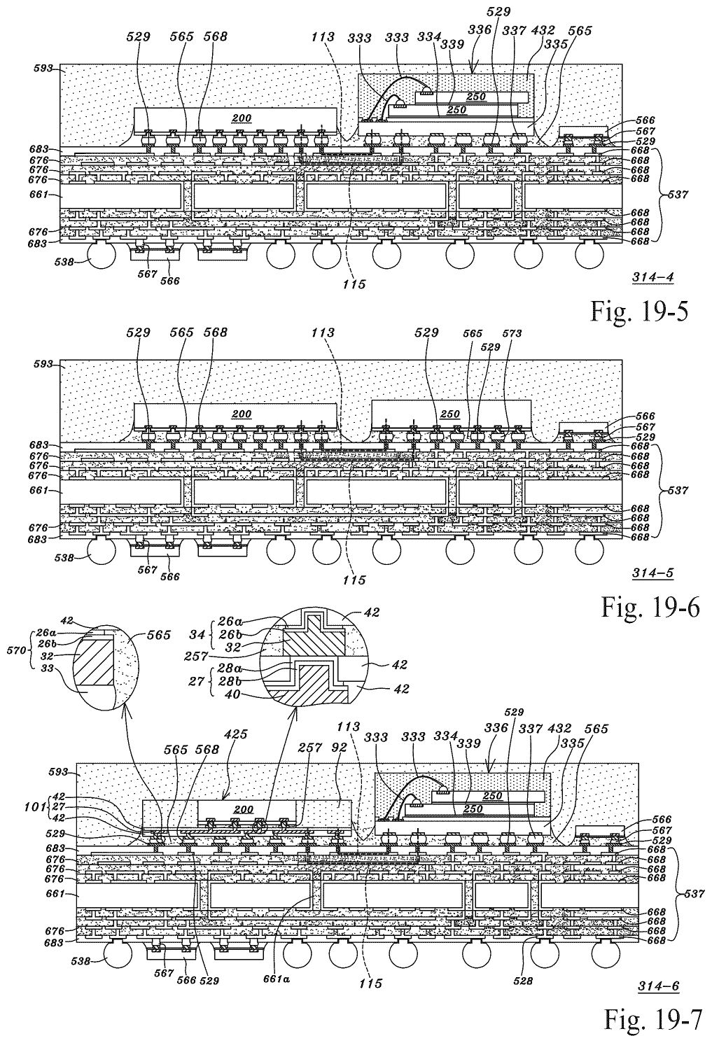

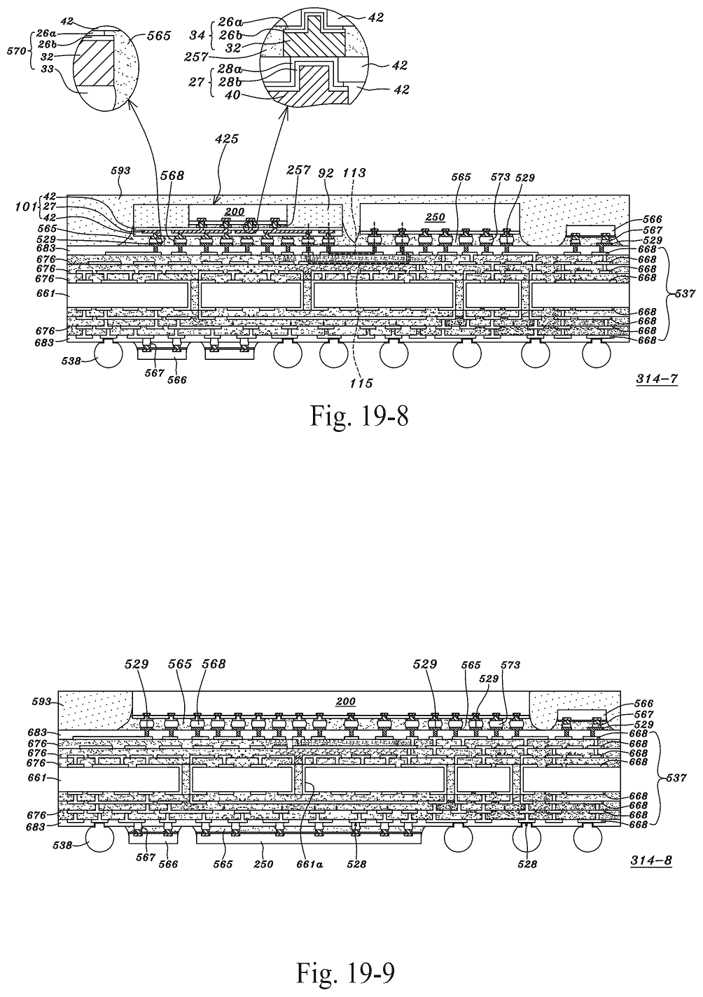

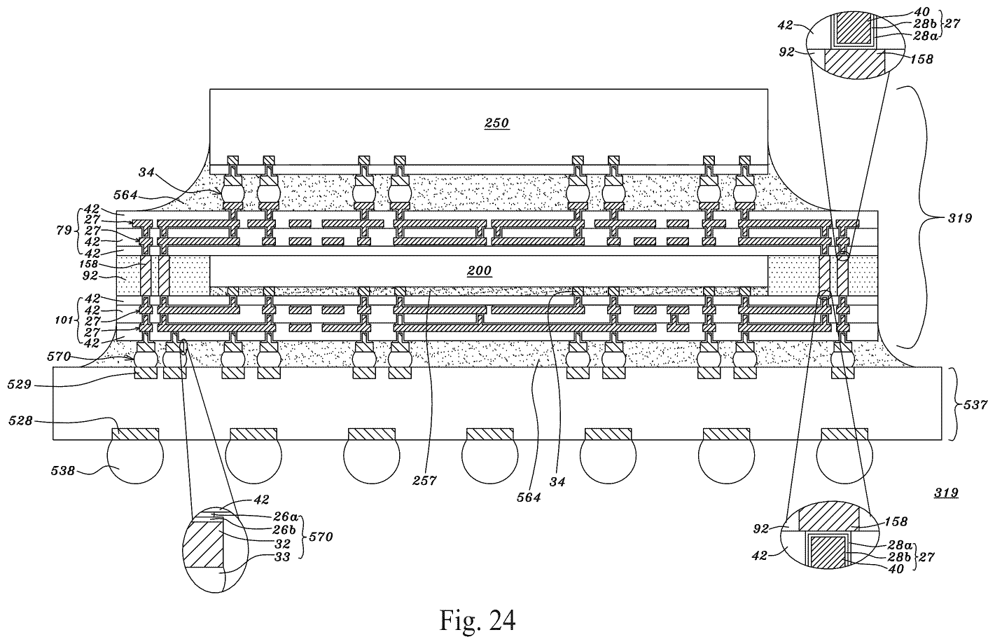

Alternatively, its FPGA/NVM multi-chip package 259 may be the tenth type of FPMCP 313 as seen in FIG. 18, eleventh type of FPMCP 314 for the first alternative as seen in FIGS. 19 and 19-1, eleventh type of FPMCP 314-1 for the second alternative as seen in FIG. 19-2, eleventh type of FPMCP 314-2 for the third alternative as seen in FIG. 19-3, eleventh type of FPMCP 314-3 for the fourth alternative as seen in FIG. 19-4, eleventh type of FPMCP 314-4 for the fifth alternative as seen in FIG. 19-5, eleventh type of FPMCP 314-5 for the sixth alternative as seen in FIG. 19-6, eleventh type of FPMCP 314-6 for the seventh alternative as seen in FIG. 19-7, eleventh type of FPMCP 314-7 for the eighth alternative as seen in FIG. 19-8, eleventh type of FPMCP 314-8 for the ninth alternative as seen in FIG. 19-9, sixteenth type of FPMCP 319 as seen in FIG. 24 or seventeenth type of FPMCP 320 for the second or third alternative as seen in FIG. 25B or 25C with the solder balls 538 at the bottom thereof bonded to its interposer 551, which may have the same specification as that of the interposer 551 illustrated in FIG. 6A, to form multiple bonded metal bumps or contacts 574 between its FPGA/NVM multi-chip package 259 and interposer 551; for example, each of its bonded metal bumps or contacts 574 may include a tin-lead alloy or tin-silver-copper alloy between its FPGA/NVM multi-chip package 259 and interposer 551.

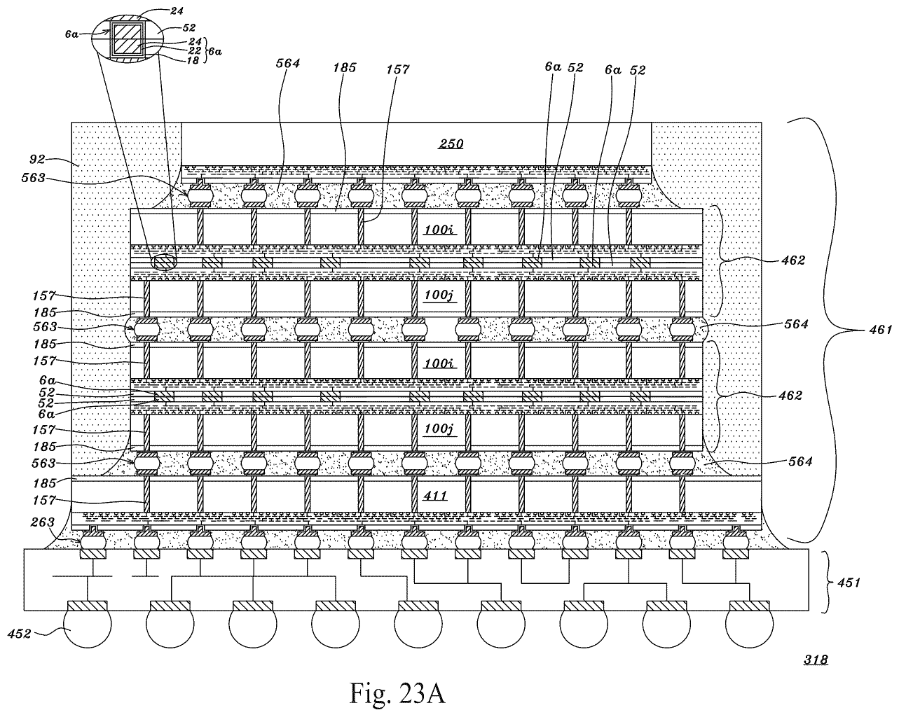

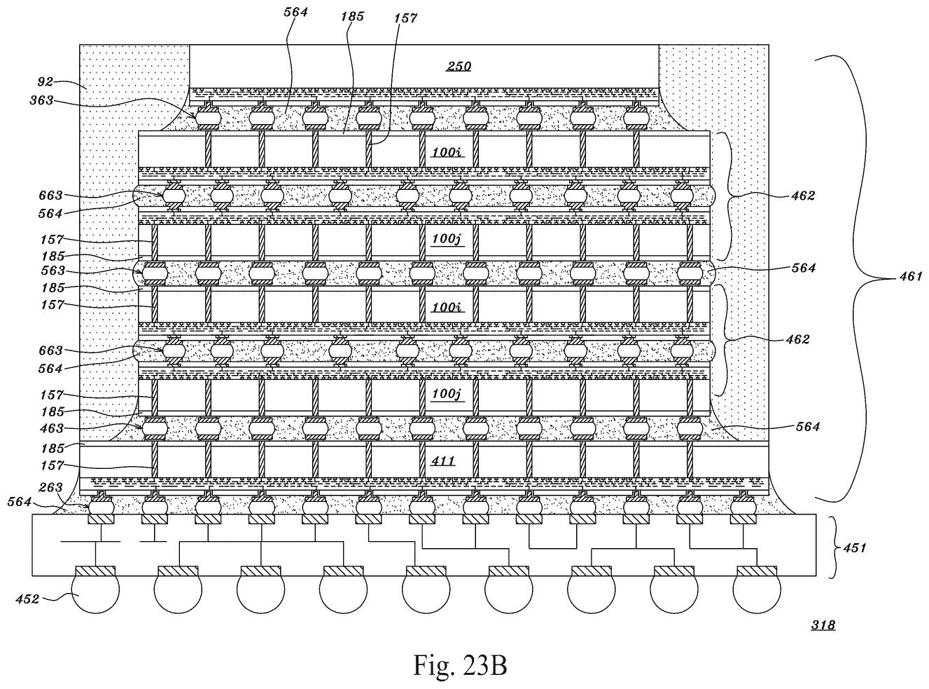

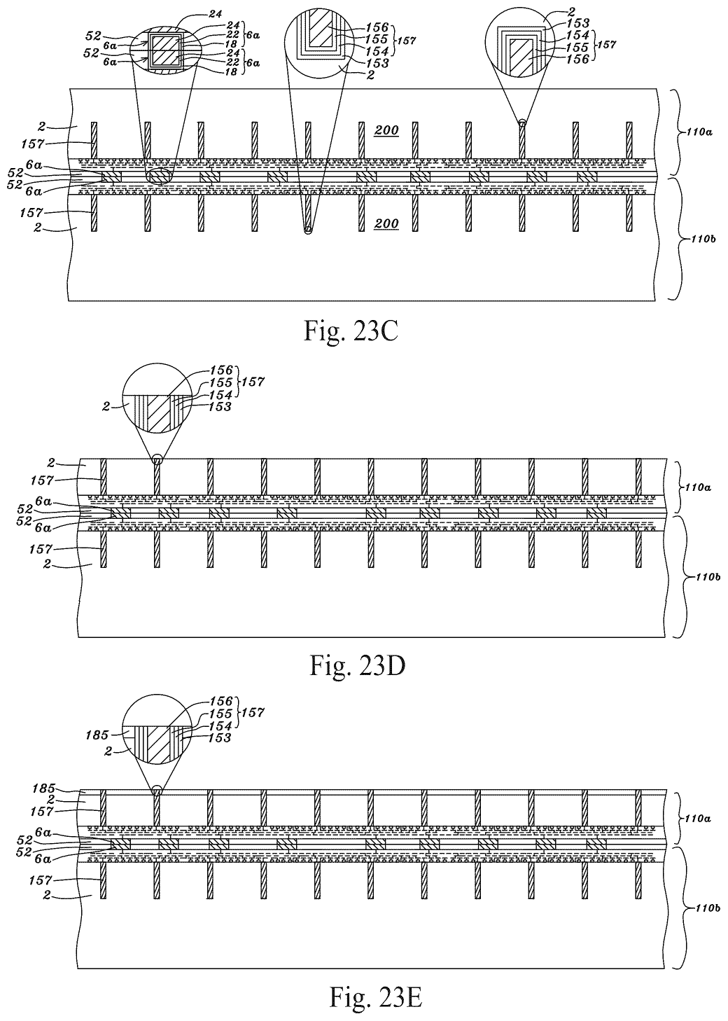

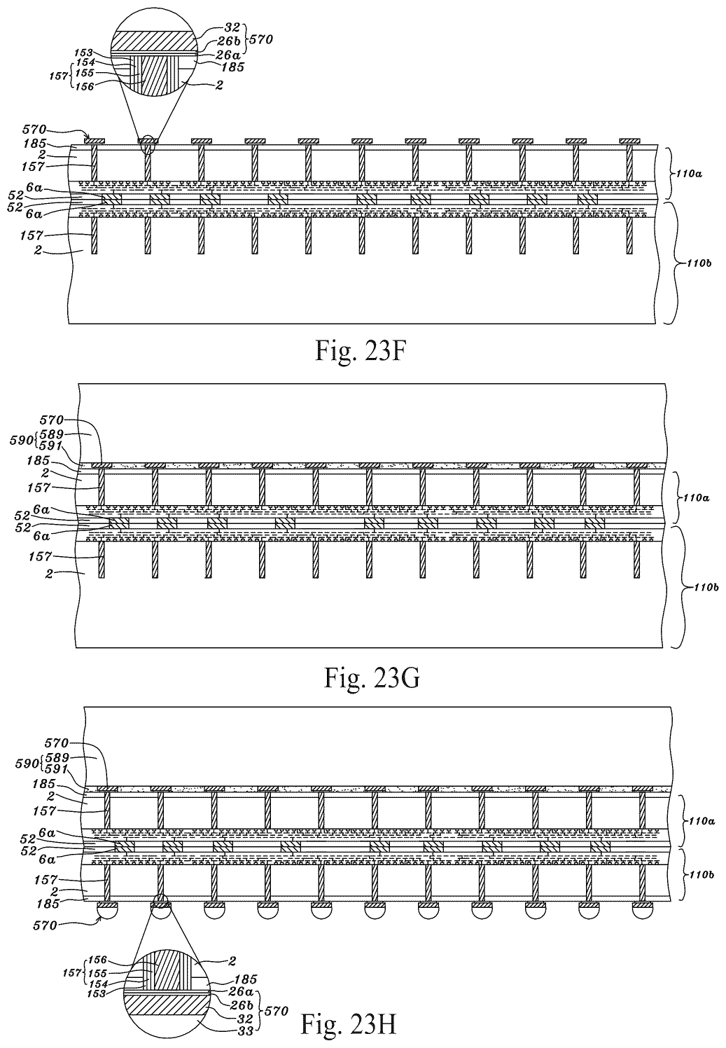

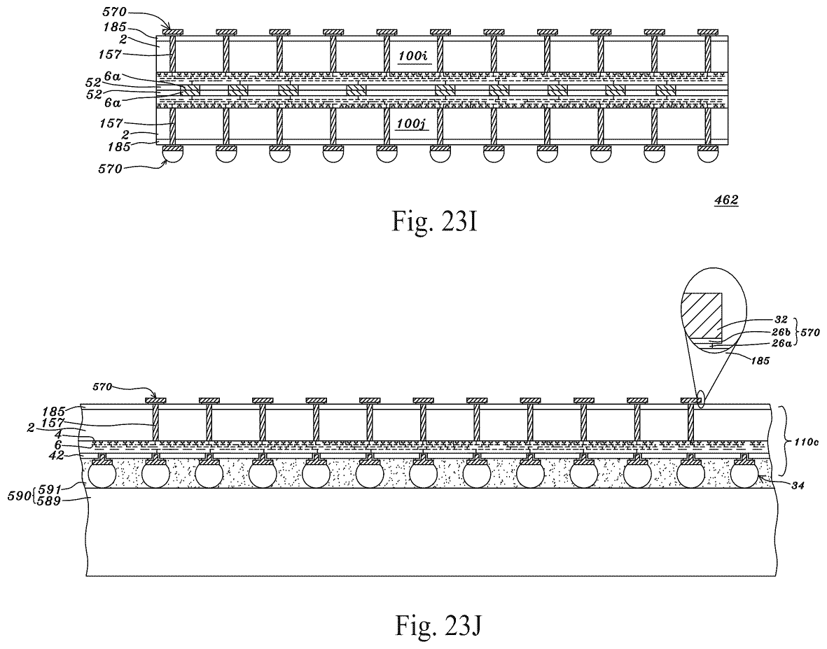

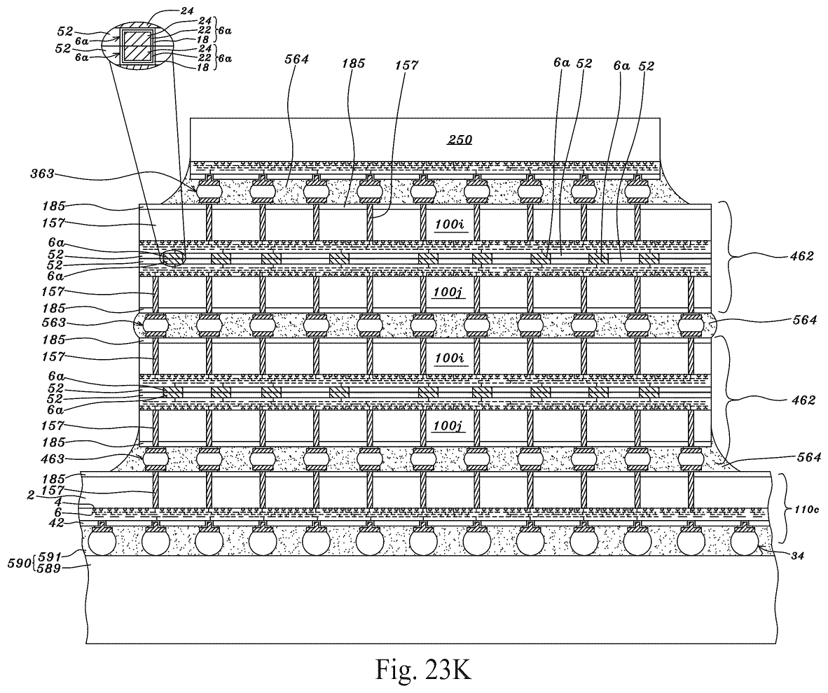

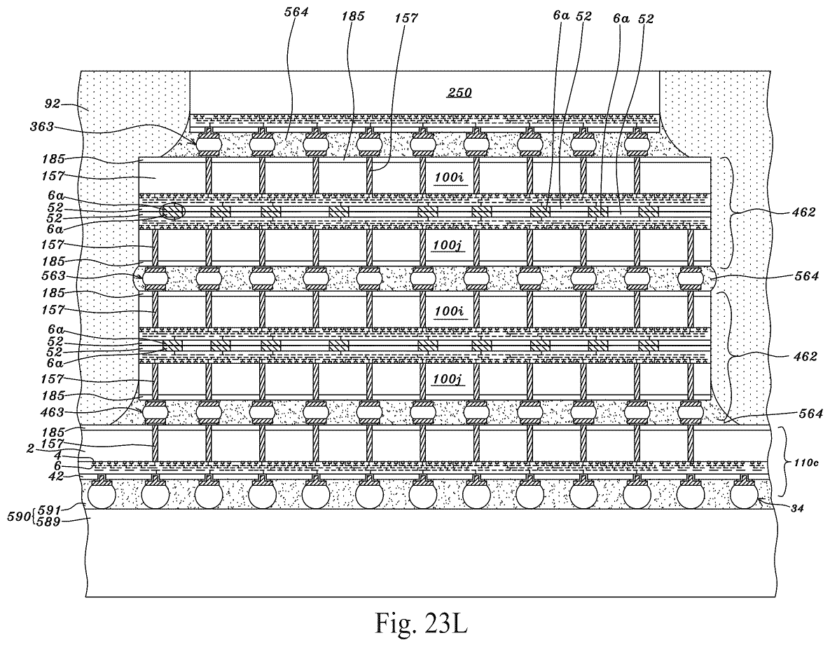

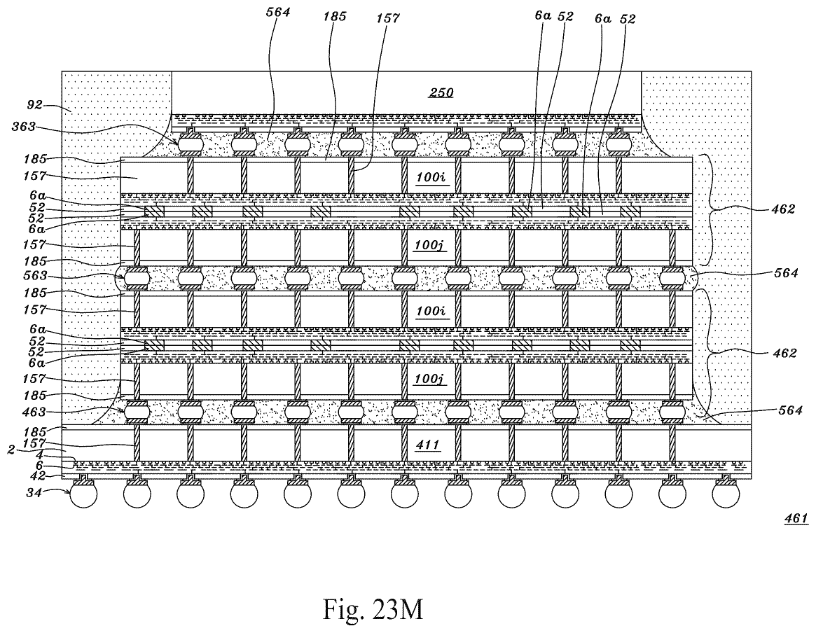

Alternatively, for the first structure 301 for said each of the first type of field-programmable multi-chip packages 300 for the third and fourth alternatives, its FPGA/NVM multi-chip package 259 may be the fifteenth type of FPMCP 318 as seen in FIG. 23A or 23B with the metal contacts 452 at the bottom thereof bonded to its interposer 551, which may have the same specification as that of the interposer 551 illustrated in FIG. 6A, to form multiple bonded metal bumps or contacts 574 between its FPGA/NVM multi-chip package 259 and interposer 551; for a first example, each of its bonded metal bumps or contacts 574 may include (1) a copper layer having a thickness between 1 μm and 60 μm, between 2 μm and 20 μm or between 10 μm and 50 m between its FPGA/NVM multi-chip package 259 and interposer 551, and (2) a solder cap, made of a tin-silver alloy, a tin-gold alloy, a tin-copper alloy, a tin-indium alloy, indium or tin, having a thickness of between 1 μm and 15 μm, between 1 μm and 50 μm or between 20 μm and 100 m between the copper layer of said each of its bonded metal bumps or contacts 574 and its interposer 551; for a second example, each of its bonded metal bumps or contacts 574 may include a tin-lead alloy or tin-silver-copper alloy between its FPGA/NVM multi-chip package 259 and interposer 551.

The first structure 301 for said each of the first type of field-programmable multi-chip packages 300 for the third and fourth alternatives may further include (1) an underfill 564, i.e., polymer layer, between each of its semiconductor IC chips 601, 269a, 269b, 269c, 260, 602 and 603 and FPGA/NVM multi-chip package 259 for the third alternative, or each of its semiconductor IC chips 601, 269a, 269b, 269c, 270, 260, 602 and 603 and FPGA/NVM multi-chip package 259 for the fourth alternative, and its interposer 551, covering a sidewall of each of its bonded metal bumps or contacts 574, (2) a polymer layer 92 or insulating dielectric layer, i.e., sealing layer, such as silicon-oxide-containing molding compound, epoxy-based material or polyimide, on a top surface of its interposer 551 and horizontally around each of its semiconductor IC chips 601, 269a, 269b, 269c, 260, 602 and 603 and FPGA/NVM multi-chip package 259 for the third alternative, or each of its semiconductor IC chips 601, 269a, 269b, 269c, 270, 260, 602 and 603 and FPGA/NVM multi-chip package 259 for the fourth alternative, wherein its polymer layer 92 may have a top surface coplanar with a top surface of each of its semiconductor IC chips 601, 269a, 269b, 269c, 260, 602 and 603 and FPGA/NVM multi-chip package 259 for the third alternative, or a top surface of each of its semiconductor IC chips 601, 269a, 269b, 269c, 270, 260, 602 and 603 and FPGA/NVM multi-chip package 259 for the fourth alternative, and (3) multiple metal bumps, pillars or pads 575 in an array at its bottom to act as its external pins for coupling to the external circuits outside of the first structure 301 for said each of the first type of field-programmable multi-chip packages 300 for the third and fourth alternatives, wherein each of its metal bumps, pillars or pads 571 may be formed on a bottom surface of one of the through silicon vias 558, i.e., the copper layer 557 thereof, of its interposer 551 and on a bottom surface of the insulating dielectric layer 585 of its interposer 551. Each of its semiconductor IC chips 601, 269a, 269b, 269c, 260, 602 and 603 and FPGA/NVM multi-chip package 259 for the third alternative, or each of its semiconductor IC chips 601, 269a, 269b, 269c, 270, 260, 602 and 603 and FPGA/NVM multi-chip package 259 for the fourth alternative, may couple to one of its metal bumps, pillars or pads 575 for external connection through, in sequence, each of the interconnection metal layers 67 of its interposer 551 and any of the through silicon vias 558 of its interposer 551. Its polymer layer 92 may have a vertical sidewall coplanar with a vertical sidewall of its interposer 551.

Referring to FIGS. 5A-3, 5A-4 and 6B, for the first structure 301 for said each of the first type of field-programmable multi-chip packages 300 for the third and fourth alternatives, each of its metal bumps, pillars or pads 575 may be of one type of various types, i.e., first and second types. Each of its first type of metal bumps, pillars or pads 575 may include (1) an adhesion metal layer 26a, such as titanium (Ti) or titanium nitride (TiN) layer having a thickness between 1 nm and 50 nm, on the bottom surface of one of the through silicon vias 558, i.e., the copper layer 557 thereof, of its interposer 551 and on the bottom surface of the insulating dielectric layer 585 of its interposer 551, (2) an electroplating seed layer 26b, such as copper, on and under the adhesion metal layer 26a of said each of its first type of metal bumps, pillars or pads 575 and (3) a copper layer 32 having a thickness between 1 μm and 60 μm on and under the electroplating seed layer 26b of said each of its first type of metal bumps, pillars or pads 575. Alternatively, each of its second type of metal bumps, pillars or pads 575 may include the adhesion metal layer 26a, seed layer 26b and copper layer 32 as mentioned for its first type of metal bump, pillar or pad 575, and may further include a tin-containing solder cap 33 made of tin or a tin-silver alloy having a thickness between 1 μm and 50 μm or between 20 μm and 100 μm on and under the copper layer 32 of said each of its second type of metal bumps, pillars or pads 575.

Alternatively, for the first structure 301 for each of the first type of field-programmable multi-chip packages 300 for the first through fifth alternatives, the silicon substrate 552 of its interposer 551 may be replaced with the semiconductor substrate 2 as illustrated in FIG. 3A, the through silicon vias (TSVs) 558 of its interposer 551 may be replaced with the through silicon vias (TSVs) 157 as illustrated in FIGS. 3B and 3G-3J, the insulating lining layer 555 of its interposer 551 may be replaced with the insulating lining layer 153 as illustrated in FIGS. 3B and 3G-3J, and the interconnection scheme of its interposer 551 may include the first interconnection scheme for a chip (FISC) 20 as illustrated in FIGS. 3B and 3G-3J. Accordingly, in a first aspect for its interposer 551, its interposer 551 may have the same specification as illustrated for any kind of the second through fourth kinds of connection structures for the through silicon vias 157 (TSVs) and the first interconnection scheme for a chip (FISC) for the second type of semiconductor IC chip 100 as shown in FIGS. 3G-3J. The semiconductor substrate 2 of its interposer 551 may have a lower portion to be removed using a chemical-mechanical-polishing (CMP) process to expose a bottom surface of each of the through silicon vias 157 (TSVs) of its interposer 551. Further, the insulating lining layer 153 of its interposer 551 at a bottom of the electroplated copper layer 156 of each of the through silicon vias 157 (TSVs) of its interposer 551 and the adhesion metal layer 154 and electroplating seed layer 155 at the bottom of the electroplated copper layer 156 of said each of the through silicon vias 157 (TSVs) may be removed to expose a bottom surface of the electroplated copper layer 156 of said each of the through silicon vias 157 (TSVs). Next, the semiconductor substrate 2 of its interposer 551 may be etched to form a recess from the bottom surface of the electroplated copper layer 156 of said each of the through silicon vias 157 (TSVs). Next, the insulating dielectric layer 585 of its interposer 551 as illustrated in FIG. 6A may be formed in the recess and on a bottom surface of the semiconductor substrate 2 of its interposer 551 and on the bottom surface of the electroplated copper layer 156 of said each of the through silicon vias 157 (TSVs). Next, the insulating dielectric layer 585 of its interposer 551 under said each of the through silicon vias 157 (TSVs) may be removed to have a bottom surface coplanar with the bottom surface of the electroplated copper layer 156 of said each of the through silicon vias 157 (TSVs). Next, each of its first or second type of metal bumps, pillars or pads 575 as illustrated in FIG. 6B may have the adhesion metal layer 26a thereof formed on the bottom surface of the electroplated copper layer 156 of one of the through silicon vias 157 (TSVs) of its interposer 551 and the bottom surface of the insulating dielectric layer 585 of its interposer 551. Alternatively, in a second aspect for its interposer 551, each of its first or second type of metal bumps, pillars or pads 575 as illustrated in FIG. 6B may have the adhesion metal layer 26a thereof formed on the bottom surface of the electroplated copper layer 156 of each of the set of through silicon vias 157 (TSVs) of its interposer 551 and the bottom surface of the insulating dielectric layer 585 of its interposer 551 to couple the set of through silicon vias 157 (TSVs) of its interposer 551, wherein the reference layer 6f of the first interconnection scheme for a chip (FISC) 20 of its interposer 551 for the second kind as illustrated in FIGS. 3G and 3H may couple the set of through silicon vias 157 (TSVs) of its interposer 551, the reference layer 6f of the first interconnection scheme for a chip (FISC) 20 of its interposer 551 for the third kind as illustrated in FIG. 3I may couple the set of through silicon vias 157 (TSVs) of its interposer 551, and the second portion of the bottommost one of the interconnection metal layers 6 of the first interconnection scheme for a chip (FISC) 20 of its interposer 551 for the fourth kind as illustrated in FIG. 3J may couple the set of through silicon vias 157 (TSVs) of its interposer 551, wherein a pitch or space between each neighboring two of the set of through silicon vias 157 (TSVs) of its interposer 551, i.e., the electroplated copper layers 156 thereof, may be between 5 and 50 micrometers.

Alternatively, FIG. 6C is a schematically cross-sectional view showing a second type of metal bump, pillar or pad provided under two through silicon vias (TSVs) in accordance with an embodiment of the present application. Referring to FIG. 6C, with regard to the first structure 301 for each of the first type of field-programmable multi-chip packages 300 for the first through fifth alternatives, for any kind of the second through fourth kinds of connection structures for the through silicon vias 157 (TSVs) and the first interconnection scheme for a chip (FISC) for a third aspect for its interposer 551, the third aspect for its interposer 551 may have a similar structure to the second aspect for its interposer 551. The difference therebetween is that for the third aspect its interposer 551 may further include an insulating dielectric layer 587, such as polymer, silicon oxide, silicon oxynitride or silicon nitride, having a thickness between 0.5 and 10 micrometers on the bottom surface of the insulating dielectric layer 585 of its interposer 551 as illustrated for the second aspect for its interposer 551, wherein an opening in the insulating dielectric layer 587 of its interposer 551 may be vertically under the set of through silicon vias 157 (TSVs) of its interposer 551 and said each of its first or second type of metal bumps, pillars or pads 575 as illustrated in FIG. 6B may be formed in and under the opening in the insulating dielectric layer 587 of its interposer 551 and under and on a bottom surface of the insulating dielectric layer 587 of its interposer 551 and have the adhesion metal layer 26a thereof formed on the bottom surface of the electroplated copper layer 156 of each of the set of through silicon vias 157 (TSVs) of its interposer 551, the bottom surface of the insulating dielectric layer 585 of its interposer 551 and the bottom surface of the insulating dielectric layer 587 of its interposer 551 to couple the set of through silicon vias 157 (TSVs) of its interposer 551.

### Second Structure for First Type of FPMCP

FIG. 7 is a schematically cross-sectional view showing a second structure for a first type of FPMCP for any first, second or fifth alternative in accordance with an embodiment of the present application. The second structure 302 may be fabricated for each of the first type of FPMCPs 300 for the first, second and fifth alternatives as illustrated in FIGS. 5A-1, 5A-2 and 5A-5, wherein FIG. 7 is a schematically cross-sectional view along a cross-sectional line A-A in either FIG. 5A-1, 5A-2 or 5A-5. Referring to FIG. 5A-1, 5A-2, 5A-5 and 7, the second structure 302 for each of the first type of field-programmable multi-chip packages 300 for the first, second and fifth alternatives may include (1) the semiconductor IC chips 200, 250, 269a, 269b, 269c, 251 and 411 as illustrated in FIGS. 5A-1 for the first alternative, or the semiconductor IC chips 200, 250, 269a, 269b, 251, 270, 402 and 411 and first, second and third types of subsystem units 401, 403 and 404 as illustrated in FIGS. 5A-2 for the second alternative, or the semiconductor IC chips 200, 250, 255, 269a, 269b, 269c, 251 and 411 as illustrated in FIG. 5A-5 for the fifth alternative, (2) a polymer layer 92 or insulating dielectric layer, i.e., sealing layer, such as silicon-oxide-containing molding compound, epoxy-based material or polyimide, horizontally around each of its semiconductor IC chips 200, 250, 269a, 269b, 269c, 251 and 411 for the first alternative, or each of its semiconductor IC chips 200, 250, 269a, 269b, 251, 270, 402 and 411 and first, second and third types of subsystem units 401, 403 and 404 for the second alternative, or each of its semiconductor IC chips 200, 250, 255, 269a, 269b, 269c, 251 and 411 for the fifth alternative, (3) a frontside interconnection scheme for a device (FISD) 101 over its semiconductor IC chips 200, 250, 269a, 269b, 269c, 251 and 411 for the first alternative, or its semiconductor IC chips 200, 250, 269a, 269b, 251, 270, 402 and 411 and first, second and third types of subsystem units 401, 403 and 404 for the second alternative, or its semiconductor IC chips 200, 250, 255, 269a, 269b, 269c, 251 and 411 for the fifth alternative, and its polymer layer 92 and (4) multiple metal bumps, pillars or pads 570 in an array at its top to act as its external pins for coupling to the external circuits 340 as seen in FIG. 5D-5G or 5K outside of the second structure 302 for said each of the first type of field-programmable multi-chip packages 300 for the first, second and fifth alternatives, wherein each of its metal bumps, pillars or pads 570 may be formed on a top surface of its frontside interconnection scheme for a device (FISD) 101. Each of its semiconductor IC chips 200, 250, 269a, 269b, 269c, 251 and 411 for the first alternative, or each of its semiconductor IC chips 200, 250, 269a, 269b, 251, 270, 402 and 411 for the second alternative, or each of its semiconductor IC chips 200, 250, 255, 269a, 269b, 269c, 251 and 411 for the fifth alternative, may have the same specification as the third type of semiconductor IC chip 100 illustrated in FIG. 3C and for the second alternative each of its first, second and third types of subsystem units 401, 403 and 404 may include the polymer layer 257 as illustrated in FIG. 3C to be formed at a bottom of said each of its first, second and third types of subsystem units 401, 403 and 404 as illustrated in FIG. 4C and covering a sidewall of each of the first, second, third or fourth type of micro-bumps, micro-pillars or micro-pads 34 of said each of its first, second and third types of subsystem units 401, 403 and 404. For the first alternative, each of the first type of micro-bumps, micro-pillars or micro-pads 34 of each of its semiconductor IC chips 200, 250, 269a, 269b, 269c, 251 and 411 may couple to its frontside interconnection scheme for a device (FISD) 101, and the top surface of the polymer layer 257 of each of its semiconductor IC chips 200, 250, 269a, 269b, 269c, 251 and 411 may be substantially coplanar with the top surface of each of the first type of micro-bumps, micro-pillars or micro-pads 34 of each of its semiconductor IC chips 200, 250, 269a, 269b, 269c, 251 and 411 and a top surface of its polymer layer 92. For the second alternative, each of the first type of micro-bumps, micro-pillars or micro-pads 34 of each of its semiconductor IC chips 200, 250, 269a, 269b, 251, 270, 402 and 411 and first, second and third types of subsystem units 401, 403 and 404 may couple to its frontside interconnection scheme for a device (FISD) 101, and the top surface of the polymer layer 257 of each of its semiconductor IC chips 200, 250, 269a, 269b, 251, 270, 402 and 411 and first, second and third types of subsystem units 401, 403 and 404 may be substantially coplanar with the top surface of each of the first type of micro-bumps, micro-pillars or micro-pads 34 of each of its semiconductor IC chips 200, 250, 269a, 269b, 251, 270, 402 and 411 and first, second and third types of subsystem units 401, 403 and 404 and a top surface of its polymer layer 92. For the fifth alternative, each of the first type of micro-bumps, micro-pillars or micro-pads 34 of each of its semiconductor IC chips 200, 250, 255, 269a, 269b, 269c, 251 and 411 may couple to its frontside interconnection scheme for a device (FISD) 101, and the top surface of the polymer layer 257 of each of its semiconductor IC chips 200, 250, 255, 269a, 269b, 269c, 251 and 411 may be substantially coplanar with the top surface of each of the first type of micro-bumps, micro-pillars or micro-pads 34 of each of its semiconductor IC chips 200, 250, 255, 269a, 269b, 269c, 251 and 411 and a top surface of its polymer layer 92.

Referring to FIGS. 5A-1, 5A-2, 5A-5 and 7, for the second structure 302 for said each of the first type of field-programmable multi-chip packages 300 for the first, second and fifth alternatives, its frontside interconnection scheme for a device (FISD) 101 may be formed for the programmable interconnects 361 and non-programmable interconnects 364 of the inter-chip interconnects 371 of said each of the first type of field-programmable multi-chip packages 300 for the first, second and fifth alternatives as illustrated in FIGS. 5A-1, 5A-2 and 5A-5, including (1) multiple interconnection metal layers 27 coupling to each of the first type of micro-bumps, micro-pillars or micro-pads 34 of each of its semiconductor IC chips 200, 250, 269a, 269b, 269c, 251 and 411 for the first alternative, or each of the first type of micro-bumps, micro-pillars or micro-pads 34 of each of its semiconductor IC chips 200, 250, 269a, 269b, 251, 270, 402 and 411 and first, second and third types of subsystem units 401, 403 and 404 for the second alternative, or each of the first type of micro-bumps, micro-pillars or micro-pads 34 of each of its semiconductor IC chips 200, 250, 255, 269a, 269b, 269c, 251 and 411 for the fifth alternative, and (2) one or more polymer layers 42, i.e., insulating dielectric layers, each between neighboring two of the interconnection metal layers 27 of its frontside interconnection scheme for a device (FISD) 101, under the bottommost one of the interconnection metal layers 27 of its frontside interconnection scheme for a device (FISD) 101 or over the topmost one of the interconnection metal layers 27 of its frontside interconnection scheme for a device (FISD) 101, wherein an upper one of the interconnection metal layers 27 of its frontside interconnection scheme for a device (FISD) 101 may couple to a lower one of the interconnection metal layers 27 of its frontside interconnection scheme for a device (FISD) 101 through an opening in one of the polymer layers 42 of its frontside interconnection scheme for a device (FISD) 101 between the upper and lower ones of the interconnection metal layers 27 of its frontside interconnection scheme for a device (FISD) 101. The bottommost one of the polymer layers 42 of its frontside interconnection scheme for a device (FISD) 101 may have a bottom surface in contact with the top surface of the polymer layer 257 of each of its semiconductor IC chips 200, 250, 269a, 269b, 269c, 251 and 411 for the first alternative, or the top surface of the polymer layer 257 of each of its semiconductor IC chips 200, 250, 269a, 269b, 251, 270, 402 and 411 and first, second and third types of subsystem units 401, 403 and 404 for the second alternative, or the top surface of the polymer layer 257 of each of its semiconductor IC chips 200, 250, 255, 269a, 269b, 269c, 251 and 411 for the fifth alternative, and the top surface of its polymer layer 92. Each opening in the bottommost one of the polymer layers 42 of its frontside interconnection scheme for a device (FISD) 101 may be over one of the first type of micro-bumps, micro-pillars or micro-pads 34 of one of its semiconductor IC chips 200, 250, 269a, 269b, 269c, 251 and 411 for the first alternative, or one of the first type of micro-bumps, micro-pillars or micro-pads 34 of each of its semiconductor IC chips 200, 250, 269a, 269b, 251, 270, 402 and 411 and first, second and third types of subsystem units 401, 403 and 404 for the second alternative, or one of the first type of micro-bumps, micro-pillars or micro-pads 34 of one of its semiconductor IC chips 200, 250, 255, 269a, 269b, 269c, 251 and 411 for the fifth alternative, and thus the bottommost one of the interconnection metal layers 27 of its frontside interconnection scheme for a device (FISD) 101 may couple to said one of the first type of micro-bumps, micro-pillars or micro-pads 34 through said each opening. Each of the interconnection metal layers 27 of its frontside interconnection scheme for a device (FISD) 101 may extend horizontally across an edge of each of its semiconductor IC chips 200, 250, 269a, 269b, 269c, 251 and 411 for the first alternative, or an edge of each of its semiconductor IC chips 200, 250, 269a, 269b, 251, 270, 402 and 411 and first, second and third types of subsystem units 401, 403 and 404 for the second alternative, or an edge of each of its semiconductor IC chips 200, 250, 255, 269a, 269b, 269c, 251 and 411 for the fifth alternative. The topmost one of the interconnection metal layers 27 of its frontside interconnection scheme for a device (FISD) 101 may have multiple metal pads at bottoms of multiple respective openings in the topmost one of the polymer layers 42 of its frontside interconnection scheme for a device (FISD) 101. The specification and process for the interconnection metal layers 27 and polymer layers 42 for its frontside interconnection scheme for a device (FISD) 101 may be referred to those for the second interconnection scheme for a chip (SISC) 29 as illustrated in FIG. 3A. Each of the polymer layers 42 of its frontside interconnection scheme for a device (FISD) 101 may be a layer of polyimide, benzocyclobutene (BCB), parylene, epoxy-based material or compound, photo epoxy SU-8, elastomer or silicone, having a thickness between, for example, 0.3 μm and 30 μm, 0.5 μm and 20 μm, 1 μm and 10 μm, or 0.5 um and 5 μm, or thicker than or equal to 0.3 μm, 0.5 μm, 0.7 μm, 1 μm, 1.5 μm, 2 μm, 3 μm or 5 μm. Each of the interconnection metal layers 27 of its frontside interconnection scheme for a device (FISD) 101 may be provided with multiple metal traces or lines each including (1) a copper layer 40 having one or more lower portions in openings in one of the polymer layers 42 of its frontside interconnection scheme for a device (FISD) 101 and an upper portion having a thickness between 0.3 μm and 20 μm over said one of the polymer layers 42 of its frontside interconnection scheme for a device (FISD) 101, (2) an adhesion metal layer 28a, such as titanium or titanium nitride having a thickness between 1 nm and 50 nm, at a bottom and sidewall of each of the one or more lower portions of the copper layer 40 of said each of the metal traces or lines and at a bottom of the upper portion of the copper layer 40 of said each of the metal traces or lines, and (3) a electroplating seed layer 28b, such as copper, between the copper layer 40 and adhesion metal layer 28a of said each of the metal traces or lines, wherein the upper portion of the copper layer 40 of said each of the metal traces or lines may have a sidewall not covered by the adhesion metal layer 28a of said each of the metal traces or lines. Each of the metal traces or lines of each of the interconnection metal layers 27 of its frontside interconnection scheme for a device (FISD) 101 may have a thickness between, for example, 0.3 μm and 30 μm, 0.5 μm and 20 μm, 1 μm and 10 μm, or 0.5 μm and 5 μm, or thicker than or equal to 0.3 μm, 0.5 μm, 0.7 μm, 1 μm, 1.5 μm, 2 μm, 3 μm or 5 μm, and a width between, for example, 0.3 μm and 30 μm, 0.5 μm and 20 μm, 1 μm and 10 μm, or 0.5 μm and 5 μm, or wider than or equal to 0.3 μm, 0.5 μm, 0.7 μm, 1 μm, 1.5 μm, 2 μm, 3 μm or 5 μm. Further, its polymer layer 92 may have a vertical sidewall coplanar with a vertical sidewall of its frontside interconnection scheme for a device (FISD) 101.

Referring to FIGS. 5A-1, 5A-2, 5A-5 and 7, for the second structure 302 for said each of the first type of field-programmable multi-chip packages 300 for the first, second and fifth alternatives, each of its metal bumps, pillars or pads 570 may be of a type selected from various types, i.e., first and second types, which may have the same specification as that of the first and second types of metal bumps, pillars or pads 570 respectively as illustrated in FIG. 6A to be turned upside down, and may have the adhesion metal layer 26a on a top surface of one of the metal pads of the topmost one of the interconnection metal layers 27 of its frontside interconnection scheme for a device (FISD) 101 and a top surface of the topmost one of the polymer layers 42 of its frontside interconnection scheme for a device (FISD) 101. Each of its semiconductor IC chips 200, 250, 269a, 269b, 269c, 251 and 411 for the first alternative, or each of its semiconductor IC chips 200, 250, 269a, 269b, 251, 270, 402 and 411 and first, second and third types of subsystem units 401, 403 and 404 for the second alternative, or each of its semiconductor IC chips 200, 250, 255, 269a, 269b, 269c, 251 and 411 for the fifth alternative, may couple to one of its metal bumps, pillars or pads 570 for external connection through each of the interconnection metal layers 27 of its frontside interconnection scheme for a device (FISD) 101.

### Third Structure for First Type of FPMCP

FIG. 8A is a schematically cross-sectional view showing a third structure for a first type of FPMCP for any first, second of fifth alternative in accordance with an embodiment of the present application. FIG. 8B is a schematically cross-sectional view showing a third structure for a first type of FPMCP for either third or fourth alternative in accordance with an embodiment of the present application. The third structure 303 may be fabricated for each of the first type of FPMCPs 300 for any first, second or fifth alternative as illustrated in FIGS. 5A-1, 5A-2 and 5A-5, wherein FIG. 8A is a schematically cross-sectional view along a cross-sectional line A-A in any FIG. 5A-1, 5A-2 or 5A-5. The third structure 303 for each of the first type of FPMCPs 300 for the first, second and fifth alternatives as seen in FIG. 8A may have a similar structure to the first structure 301 for the same as seen in FIG. 6A. For an element indicated by the same reference number shown in FIGS. 6A and 8A, the specification of the element as seen in FIG. 8A may be referred to that of the element as illustrated in FIG. 6A. The third structure 303 for each of the first type of FPMCPs 300 for the third and fourth alternatives as seen in FIG. 8B may have a similar structure to the first structure 301 for the same as seen in FIG. 6B. For an element indicated by the same reference number shown in FIGS. 6B and 8B, the specification of the element as seen in FIG. 8B may be referred to that of the element as illustrated in FIG. 6B. The difference therebetween is that the interposer 551 of the first structure 301 for each of the first type of FPMCPs 300 for the first through fifth alternatives as seen in FIGS. 6A and 6B may be replaced with an interconnection substrate 684, i.e., ball-grid-array (BGA) substrate, as seen in FIGS. 8A and 8B. Referring to FIGS. 5A-1, 5A-2, 5A-3, 5A-4, 5A-5, 8A and 8B, for the third structure 303 for each of the first type of FPMCPs 300 for the first through fifth alternatives, its interconnection substrate 684 may include (1) a core layer 661, such as FR4, containing epoxy or bismaleimide-triazine (BT) resin and having a thickness between 200 and 1000 micrometers or between 400 and 800 micrometers, wherein FR4 may be a composite material composed of woven fiberglass cloth and an epoxy resin binder, (2) multiple interconnection metal layers 668, made of copper, each having a thickness between 10 and 50 micrometers, between 25 and 50 micrometers, between 10 and 40 micrometers or between 10 and 20 micrometers and over or under the core layer 661 of its interconnection substrate 684, wherein each of the interconnection metal layers 668 of its interconnection substrate 684 over the core layer 661 of its interconnection substrate 684 may couple to any of the interconnection metal layers 668 of its interconnection substrate 684 under the core layer 661 of its interconnection substrate 684 through a through hole 661a in the core layer 661 of its interconnection substrate 684, (3) multiple polymer layers 676, i.e., insulating dielectric layers, such as Ajinomoto build-up films (ABFs) or layers of bismaleimide-triazine (BT) resin, each having a thickness between 10 and 50 micrometers, between 15 and 40 micrometers or between 20 and 30 micrometers and over or under the core layer 661 of its interconnection substrate 684 and between neighboring two of the interconnection metal layers 668 of its interconnection substrate 684, wherein each of the Ajinomoto build-up films (ABFs) may be made of epoxy, phenol hardener, cyanate ester and thermosetting olefin, and (4) two solder masks 683, each made of a polymer layer or an insulating dielectric layer having a thickness between 10 and 50 micrometers, between 15 and 40 micrometers or between 20 and 30 micrometers, at the top and bottom of its interconnection substrate 684 respectively to cover the topmost and bottommost ones of the interconnection metal layers 668 of its interconnection substrate 684 respectively, wherein the topmost and bottommost ones of the interconnection metal layers 668 of its interconnection substrate 684 may include multiple metal pads at bottoms and tops of multiple openings in the top and bottom ones of the two solder masks 683 of its interconnection substrate 684 respectively, and (5) multiple fine-line interconnection bridges (FIBs) 690, or dedicated field programmable integrated-circuit (DFPIC) chips 400 each having the same specification as the DFPIC chip 200 illustrated in FIG. 4D or embedded field programmable integrated-circuit (eFPIC) chips 400 each having the same specification as the eFPIC chip 200 illustrated in FIG. 4E, embedded in its interconnection substrate 684 and attached onto one of the interconnection metal layers 668 of its interconnection substrate 684 via an adhesive (not shown). One or more of the interconnection metal layers 668 of its interconnection substrate 684 and one or more of the polymer layers 676 of its interconnection substrate 684 may be arranged horizontally around each of the fine-line interconnection bridges (FIBs) 690, or DFPIC or eFPIC chips 400, of its interconnection substrate 684, and the topmost one of the interconnection metal layers 668 of its interconnection substrate 684 may be arranged over each of the fine-line interconnection bridges (FIBs) 690, or DFPIC or eFPIC chips 400, of its interconnection substrate 684.

Referring to FIGS. 5A-1, 5A-2, 5A-3, 5A-4, 5A-5, 8A and 8B, for the third structure 303 for each of the first type of FPMCPs 300 for the first through fifth alternatives, for a case that the fine-line interconnection bridges (FIBs) 690 are provided for its interconnection substrate 684, each of the fine-line interconnection bridges (FIBs) 690 of its interconnection substrate 684 may have a similar structure to the first type of semiconductor IC chip 100 as illustrated in FIG. 3A, but the difference therebetween is that each of the fine-line interconnection bridges (FIBs) 690 of its interconnection substrate 684 is a passive device or component without any transistor therein and the first, second, third or fourth type of micro-bumps, micro-pillars or micro-pads 34 as seen in FIG. 3A may not be formed for each of the fine-line interconnection bridges (FIBs) 690 of its interconnection substrate 684. Each of the fine-line interconnection bridges (FIBs) 690 of its interconnection substrate 684 may include (1) a semiconductor substrate having the same specification as the semiconductor substrate 2 of the first type of semiconductor IC chip 100 in FIG. 3A and (2) an interconnection scheme over the semiconductor substrate of said each of the fine-line interconnection bridges (FIBs) 690, having the same specification as illustrated for the first interconnection scheme for a chip (FISC) 20, second interconnection scheme for a chip (SISC) 29 or combination of the first and second interconnection schemes for a chip (FISC and SISC) 20 and 29 in FIG. 3A, wherein the interconnection scheme of said each of the fine-line interconnection bridges (FIBs) 690 may include multiple interconnection metal layers (not shown), each having the same specification as that of the interconnection metal layer 6 of the first interconnection scheme for a chip (FISC) 20 or that of the interconnection metal layer 27 of the second interconnection scheme for a chip (SISC) 29, and multiple insulating dielectric layers (not shown), each having the same specification as that of the insulating dielectric layer 12 of the first interconnection scheme for a chip (FISC) 20 or that of the polymer layer 42 of the second interconnection scheme for a chip (SISC) 29, each between neighboring two of the interconnection metal layers of the interconnection scheme of said each of the fine-line interconnection bridges (FIBs) 690, under the bottommost one of the interconnection metal layers of the interconnection scheme of said each of the fine-line interconnection bridges (FIBs) 690 or over the topmost one of the interconnection metal layers of the interconnection scheme of said each of the fine-line interconnection bridges (FIBs) 690. Said each of the fine-line interconnection bridges (FIBs) 690 may include (1) multiple metal pads provided by the topmost one of the interconnection metal layers of the interconnection scheme of said each of the fine-line interconnection bridges (FIBs) 690, and (2) multiple metal lines or traces 693 provided by one or more of the interconnection metal layers of the interconnection scheme of said each of the fine-line interconnection bridges (FIBs) 690, each coupling two of the metal pads of said each of the fine-line interconnection bridges (FIBs) 690 at two opposite sides of said each of the fine-line interconnection bridges (FIBs) 690. The combination selected from the interconnection metal layers 668 of its interconnection substrate 684 and the metal lines or traces 693 of the fine-line interconnection bridges (FIBs) 690 of its interconnection substrate 684 may be formed for the programmable interconnects 361 and non-programmable interconnects 364 of the inter-chip interconnects 371 of each of the first type of FPMCPs 300 for the first through fifth alternatives as illustrated in FIGS. 5A-1, 5A-2, 5A-3, 5A-4 and 5A-5. For a case that the DFPIC or eFPIC chips 400 are provided for its interconnection substrate 684, each of the DFPIC or eFPIC chips 400 of its interconnection substrate 684 may have a similar structure to the first type of semiconductor IC chip 100 as illustrated in FIG. 3A, but the difference therebetween is that the first, second, third or fourth type of micro-bumps, micro-pillars or micro-pads 34 as seen in FIG. 3A may not be formed for each of the DFPIC or eFPIC chips 400 of its interconnection substrate 684,

Referring to FIGS. 5A-1, 5A-2, 5A-3, 5A-4, 5A-5, 8A and 8B, for the third structure 303 for each of the first type of FPMCPs 300 for the first through fifth alternatives, the top one of the two solder masks 683 of its interconnection substrate 684 may be provided over each of the fine-line interconnection bridges (FIBs) 690, or DFPIC or eFPIC chips 400, of its interconnection substrate 684. A first group of openings in the top one of the two solder masks 683 of its interconnection substrate 684 may be formed over a first group of metal pads of the topmost one of the interconnection metal layers 668 of its interconnection substrate 684 respectively and vertically over the metal pads or input/output (I/O) pads of the fine-line interconnection bridges (FIBs) 690, or DFPIC or eFPIC chips 400, of its interconnection substrate 684 respectively; a second group of openings in the top one of the two solder masks 683 of its interconnection substrate 684 may be formed vertically over a second group of metal pads of the topmost one of the interconnection metal layers 668 of its interconnection substrate 684 respectively but not vertically over the metal pads or input/output (I/O) pads of the fine-line interconnection bridges (FIBs) 690, or DFPIC or eFPIC chips 400, of its interconnection substrate 684; and a third group of openings in the bottom one of the two solder masks 683 of its interconnection substrate 684 may be formed vertically under multiple metal pads of the bottommost one of the interconnection metal layers 668 of its interconnection substrate 684. Each of the interconnection metal layers 668 of its interconnection substrate 684 may be made of a copper layer with a thickness, for example, between 5 and 100 micrometers, between 5 and 50 micrometers or between 10 and 50 micrometers and may be thicker than that of each of the interconnection metal layers of the interconnection scheme of each of the fine-line interconnection bridges (FIBs) 690, or DFPIC or eFPIC chips 400, of its interconnection substrate 684. Its interconnection substrate 684 may further include multiple micro-bumps, micro-pillars or micro-pads each on one of the first and second groups of metal pads of the topmost one of the interconnection metal layers 668 of its interconnection substrate 684, wherein each of the micro-bumps, micro-pillars or micro-pads of its interconnection substrate 684 may be of a first, second, third or fourth type as illustrated for the first, second, third or fourth type of micro-bumps, micro-pillars or micro-pads 34 respectively in FIG. 3A.

Referring to FIGS. 5A-1, 5A-2, 5A-5 and 8A, for the third structure 303 for each of the first type of FPMCPs 300 for the first, second and fifth alternatives, each of its semiconductor IC chips 200, 250, 269a, 269b, 269c, 251 and 411 for the first alternative, or each of its semiconductor IC chips 200, 250, 269a, 269b, 251, 270, 402 and 411 for the second alternative, or each of its semiconductor IC chips 200, 250, 255, 269a, 269b, 269c, 251 and 411 for the fifth alternative, may have the same specification as the first type of semiconductor IC chip 100 illustrated in FIG. 3A to be turned upside down. Each of its semiconductor IC chips 200, 250, 269a, 269b, 269c, 251 and 411 for the first alternative, or each of its semiconductor IC chips 200, 250, 269a, 269b, 251, 270, 402 and 411 and first, second and third types of subsystem units 401, 403 and 404 for the second alternative, or each of its semiconductor IC chips 200, 250, 255, 269a, 269b, 269c, 251 and 411 for the fifth alternative, may have the first, second, third or fourth type of micro-bumps, micro-pillars or micro-pads 34 bonded respectively to the micro-bumps, micro-pillars or micro-pads of its interconnection substrate 684 to form (1) multiple high-density bonded metal bumps or contacts 563a between a peripheral portion of said each of its semiconductor IC chips 200, 250, 269a, 269b, 269c, 251 and 411 for the first alternative, or a peripheral portion of said each of its semiconductor IC chips 200, 250, 269a, 269b, 251, 270, 402 and 411 and first, second and third types of subsystem units 401, 403 and 404 for the second alternative, or a peripheral portion of said each of its semiconductor IC chips 200, 250, 255, 269a, 269b, 269c, 251 and 411 for the fifth alternative, and one of the fine-line interconnection bridges (FIBs) 690, or DFPIC or eFPIC chips 400, of its interconnection substrate 684, each coupling said each of its semiconductor IC chips 200, 250, 269a, 269b, 269c, 251 and 411 for the first alternative, or said each of its semiconductor IC chips 200, 250, 269a, 269b, 251, 270, 402 and 411 and first, second and third types of subsystem units 401, 403 and 404 for the second alternative, or said each of its semiconductor IC chips 200, 250, 255, 269a, 269b, 269c, 251 and 411 for the fifth alternative, to one of the metal pads or input/output (I/O) pads of said one of the fine-line interconnection bridges (FIBs) 690, or DFPIC or eFPIC chips 400, of its interconnection substrate 684 through one of the first group of metal pads of the topmost one of the interconnection metal layers 668 of its interconnection substrate 684, and (2) multiple low-density bonded metal bumps or contacts 563b between a central portion of said each of its semiconductor IC chips 200, 250, 269a, 269b, 269c, 251 and 411 for the first alternative, or a central portion of said each of its semiconductor IC chips 200, 250, 269a, 269b, 251, 270, 402 and 411 and first, second and third types of subsystem units 401, 403 and 404 for the second alternative, or a central portion of said each of its semiconductor IC chips 200, 250, 255, 269a, 269b, 269c, 251 and 411 for the fifth alternative, and its interconnection substrate 684, each coupling said each of its semiconductor IC chips 200, 250, 269a, 269b, 269c, 251 and 411 for the first alternative, or said each of its semiconductor IC chips 200, 250, 269a, 269b, 251, 270, 402 and 411 and first, second and third types of subsystem units 401, 403 and 404 for the second alternative, or said each of its semiconductor IC chips 200, 250, 255, 269a, 269b, 269c, 251 and 411 for the fifth alternative, to one of the second group of metal pads of the topmost one of the interconnection metal layers 668 of its interconnection substrate 684, wherein each of its high-density and low-density bonded metal bumps or contacts 563a and 563b may include a copper layer having a thickness between 2 μm and 20 μm between said each of its semiconductor IC chips 200, 250, 269a, 269b, 269c, 251 and 411 for the first alternative, or said each of its semiconductor IC chips 200, 250, 269a, 269b, 251, 270, 402 and 411 and first, second and third types of subsystem units 401, 403 and 404 for the second alternative, or said each of its semiconductor IC chips 200, 250, 255, 269a, 269b, 269c, 251 and 411 for the fifth alternative, and its interconnection substrate 684 and a solder cap, made of a tin-silver alloy, a tin-gold alloy, a tin-copper alloy, a tin-indium alloy, indium or tin, having a thickness of between 1 μm and 15 m between the copper layer of said each of its high-density and low-density bonded metal bumps or contacts 563a and 563b and its interconnection substrate 684. Accordingly, neighboring two of its semiconductor IC chips 200, 250, 269a, 269b, 269c, 251 and 411 for the first alternative, or neighboring two of its semiconductor IC chips 200, 250, 269a, 269b, 251, 270, 402 and 411 and first, second and third types of subsystem units 401, 403 and 404 for the second alternative, or neighboring two of its semiconductor IC chips 200, 250, 255, 269a, 269b, 269c, 251 and 411 for the fifth alternative, may couple to each other through, in sequence, (1) one of its high-density bonded metal bumps or contacts 563a under one of said neighboring two of its semiconductor IC chips 200, 250, 269a, 269b, 269c, 251 and 411 for the first alternative, or one of said neighboring two of its semiconductor IC chips 200, 250, 269a, 269b, 251, 270, 402 and 411 and first, second and third types of subsystem units 401, 403 and 404 for the second alternative, or one of its high-density bonded metal bumps or contacts 563a under one of said neighboring two of its semiconductor IC chips 200, 250, 255, 269a, 269b, 269c, 251 and 411 for the fifth alternative, (2) one of the metal lines or traces 693 of one of the fine-line interconnection bridges (FIBs) 690, or DFPIC or eFPIC chips 400, of its interconnection substrate 684 vertically under said neighboring two of its semiconductor IC chips 200, 250, 269a, 269b, 269c, 251 and 411 for the first alternative, or said neighboring two of its semiconductor IC chips 200, 250, 269a, 269b, 251, 270, 402 and 411 and first, second and third types of subsystem units 401, 403 and 404 for the second alternative, or said neighboring two of its semiconductor IC chips 200, 250, 255, 269a, 269b, 269c, 251 and 411 for the fifth alternative, and (3) one of its high-density bonded metal bumps or contacts 563a under the other of said neighboring two of its semiconductor IC chips 200, 250, 269a, 269b, 269c, 251 and 411 for the first alternative, or the other of said neighboring two of its semiconductor IC chips 200, 250, 269a, 269b, 251, 270, 402 and 411 and first, second and third types of subsystem units 401, 403 and 404 for the second alternative, or the other of said neighboring two of its semiconductor IC chips 200, 250, 255, 269a, 269b, 269c, 251 and 411 for the fifth alternative. Alternatively, each of the DFPIC or eFPIC chips 400 of its interconnection substrate 684 may be vertically under neighboring two of its semiconductor IC chips 200, 250, 269a, 269b, 269c, 251 and 411 for the first alternative, or neighboring two of its semiconductor IC chips 200, 250, 269a, 269b, 251, 270, 402 and 411 and first, second and third types of subsystem units 401, 403 and 404 for the second alternative, or neighboring two of its semiconductor IC chips 200, 250, 255, 269a, 269b, 269c, 251 and 411 for the fifth alternative, wherein said each of the DFPIC or eFPIC chips 400 may couple to a first device of said neighboring two of its semiconductor IC chips 200, 250, 269a, 269b, 269c, 251 and 411 for the first alternative, or said neighboring two of its semiconductor IC chips 200, 250, 269a, 269b, 251, 270, 402 and 411 and first, second and third types of subsystem units 401, 403 and 404 for the second alternative, or said neighboring two of its semiconductor IC chips 200, 250, 255, 269a, 269b, 269c, 251 and 411 for the fifth alternative, through a first group of its high-density bonded metal bumps or contacts 563a between the first device and said each of the DFPIC or eFPIC chips 400 and couple to a second device of said neighboring two of its semiconductor IC chips 200, 250, 269a, 269b, 269c, 251 and 411 for the first alternative, or said neighboring two of its semiconductor IC chips 200, 250, 269a, 269b, 251, 270, 402 and 411 and first, second and third types of subsystem units 401, 403 and 404 for the second alternative, or said neighboring two of its semiconductor IC chips 200, 250, 255, 269a, 269b, 269c, 251 and 411 for the fifth alternative, through a second group of its high-density bonded metal bumps or contacts 563a between the second device and said each of the DFPIC or eFPIC chips 400, wherein for the first or fifth alternative the first device may be its CPU IC chip 269b and the second device may be its FPGA IC chip 200 horizontally neighboring to its CPU IC chip 269b as seen in FIGS. 5A-1 and 5A-5, for example; for the first or fifth alternative the first device may be its GPU IC chip 269a and the second device may be its auxiliary IC chip 411 horizontally neighboring to its GPU IC chip 269a as seen in FIGS. 5A-1 and 5A-5, for example; for the first or fifth alternative the first device may be its GPU IC chip 269a and the second device may be its FPGA IC chip 200 horizontally neighboring to its GPU IC chip 269a as seen in FIGS. 5A-1 and 5A-5, for example; for the first or fifth alternative the first device may be its GPU IC chip 269a and the second device may be its application-specific integrated-circuit (ASIC) chip or system-on-chip (SoC) chip 269c horizontally neighboring to its GPU IC chip 269a as seen in FIGS. 5A-1 and 5A-5, for example, or wherein for the second alternative the first device may be its CPU IC chip 269b and the second device may be its GPU IC chip 269a horizontally neighboring to its CPU IC chip 269b as seen in FIG. 5A-2, for example. Said each of the DFPIC or eFPIC chips 400 may include (1) the first type of field programmable logic cell or element (LCE) 2014 or 2014-2 as illustrated in FIGS. 1A, 4D and 4E, the data inputs A0 and A1 of which may couple to the first device through, in sequence, respective two of the small input/output (SIO) circuits 203, or metal pads or input/output (I/O) pads, of said each of the DFPIC or eFPIC chips 400 and respective two of the first group of its high-density bonded metal bumps or contacts 563a and the data output Dout of which may couple to the second device through, in sequence, another of the small input/output (SIO) circuits 203, or metal pads or input/output (I/O) pads, of said each of the DFPIC or eFPIC chips 400 and one of the second group of its high-density bonded metal bumps or contacts 563a, (2) the second or third type of field programmable logic cell or element (LCE) 2014 or 2014-2 as illustrated in FIGS. 1B, 1C, 4D and 4E, the data inputs A0-A3 of which may couple to the first device through, in sequence, respective four of the small input/output (SIO) circuits 203, or metal pads or input/output (I/O) pads, of said each of the DFPIC or eFPIC chips 400 and respective four of the first group of its high-density bonded metal bumps or contacts 563a and the data output Dout of which may couple to the second device through, in sequence, another of the small input/output (SIO) circuits 203, or metal pads or input/output (I/O) pads, of said each of the DFPIC or eFPIC chips 400 and one of the second group of its high-density bonded metal bumps or contacts 563a, (3) the first type of field programmable switch cell 379 or 379-2 as illustrated in FIGS. 2A, 4D and 4E, the node N21 of which may couple to the first device through, in sequence, one of the small input/output (SIO) circuits 203, or metal pads or input/output (I/O) pads, of said each of the DFPIC or eFPIC chips 400 and one of the first group of its high-density bonded metal bumps or contacts 563a and the node N22 of which may couple to the second device through, in sequence, another of the small input/output (SIO) circuits 203, or metal pads or input/output (I/O) pads, of said each of the DFPIC or eFPIC chips 400 and one of the second group of its high-density bonded metal bumps or contacts 563a, to control coupling between the first and second devices, (4) the second type of field programmable switch cell 379 or 379-2 as illustrated in FIGS. 2B, 4D and 4E, the nodes N23 and N24 of which may couple to the first device through, in sequence, respective two of the small input/output (SIO) circuits 203, or metal pads or input/output (I/O) pads, of said each of the DFPIC or eFPIC chips 400 and respective two of the first group of its high-density bonded metal bumps or contacts 563a and the nodes N25 and N26 of which may couple to the second device through, in sequence, another respective two of the small input/output (SIO) circuits 203, or metal pads or input/output (I/O) pads, of said each of the DFPIC or eFPIC chips 400 and respective two of the second group of its high-density bonded metal bumps or contacts 563a, to control coupling from the node N23 to one or more of the nodes N24-N26 or to control coupling from the node N26 to one or more of the nodes N23-N25, (5) the field programmable switch matrix 710 or 710-3 as illustrated in FIGS. 2C, 4D and 4E, each of the nodes P₁-P_{N} of which may couple to the first device through, in sequence, one of the first metal lines 281 of said each of the DFPIC or eFPIC chips 400, one of the small input/output (SIO) circuits 203, or metal pads or input/output (I/O) pads, of said each of the DFPIC or eFPIC chips 400 and one of the first group of its high-density bonded metal bumps or contacts 563a, each of the nodes Q₁-Q_{M} of which may couple to the second device through, in sequence, one of the second metal lines 282 of said each of the DFPIC or eFPIC chips 400, another of the small input/output (SIO) circuits 203, or metal pads or input/output (I/O) pads, of said each of the DFPIC or eFPIC chips 400 and one of the second group of its high-density bonded metal bumps or contacts 563a and each of the pass/no-pass switches 778 of which may control coupling between the first and second devices, i.e., between one of the first group of its high-density bonded metal bumps or contacts 563a and one of the second group of its high-density bonded metal bumps or contacts 563a, and/or (6) the field programmable switch matrix 710-2 as illustrated in FIGS. 2C and 4E, each of some of the nodes P₁-P_{N} of which may couple to the first device through, in sequence, one of the first metal lines 281 of said each of the DFPIC or eFPIC chips 400, one of the small input/output (SIO) circuits 203, or metal pads or input/output (I/O) pads, of said each of the DFPIC or eFPIC chips 400 and one of the first group of its high-density bonded metal bumps or contacts 563a, each of the other some of the nodes P₁-P_{N} of which may couple to the second device through, in sequence, another of the first metal lines 281 of said each of the DFPIC or eFPIC chips 400, another of the small input/output (SIO) circuits 203, or metal pads or input/output (I/O) pads, of said each of the DFPIC or eFPIC chips 400 and one of the second group of its high-density bonded metal bumps or contacts 563a and each of the pass/no-pass switches 778 of which may control coupling between one of the first and second devices and one of the internal circuits of the fourth one of the ASIC cores 215 of said each of the DFPIC or eFPIC chips 400, i.e., between one of the first and second groups of its high-density bonded metal bumps or contacts 563a and one of the internal circuits of the fourth one of the ASIC cores 215 of said each of the DFPIC or eFPIC chips 400.

Referring to FIGS. 5A-3, 5A-4 and 8B, for the third structure 303 for each of the first type of FPMCPs 300 for the third and fourth alternatives, each of its semiconductor IC chips 601, 269a, 269b, 269c, 260, 602 and 603 as illustrated in FIG. 5A-3 for the third alternative, or each of its semiconductor IC chips 601, 269a, 269b, 269c, 270, 260, 602 and 603 as illustrated in FIG. 5A-4 for the fourth alternative, may have the same specification as the first type of semiconductor IC chip 100 illustrated in FIG. 3A to be turned upside down. Each of its semiconductor IC chips 601, 269a, 269b, 269c, 260, 602 and 603 for the third alternative, or each of its semiconductor IC chips 601, 269a, 269b, 269c, 270, 260, 602 and 603 for the fourth alternative, may have the first, second, third or fourth type of micro-bumps, micro-pillars or micro-pads 34 bonded respectively to the micro-bumps, micro-pillars or micro-pads of its interconnection substrate 684 to form (1) multiple high-density bonded metal bumps or contacts 563a between a peripheral portion of said each of its semiconductor IC chips 601, 269a, 269b, 269c, 260, 602 and 603 for the third alternative, or a peripheral portion of said each of its semiconductor IC chips 601, 269a, 269b, 269c, 270, 260, 602 and 603 for the fourth alternative, and one of the fine-line interconnection bridges (FIBs) 690, or DFPIC or eFPIC chips 400, of its interconnection substrate 684, each coupling said each of its semiconductor IC chips 601, 269a, 269b, 269c, 260, 602 and 603 for the third alternative, or said each of its semiconductor IC chips 601, 269a, 269b, 269c, 270, 260, 602 and 603 for the fourth alternative, to one of the metal pads or input/output (I/O) pads of said one of the fine-line interconnection bridges (FIBs) 690, or DFPIC or eFPIC chips 400, of its interconnection substrate 684 through one of the first group of metal pads of the topmost one of the interconnection metal layers 668 of its interconnection substrate 684, and (2) multiple low-density bonded metal bumps or contacts 563b between a central portion of said each of its semiconductor IC chips 601, 269a, 269b, 269c, 260, 602 and 603 for the third alternative, or a central portion of said each of its semiconductor IC chips 601, 269a, 269b, 269c, 270, 260, 602 and 603 for the fourth alternative, and its interconnection substrate 684, each coupling said each of its semiconductor IC chips 601, 269a, 269b, 269c, 260, 602 and 603 for the third alternative, or said each of its semiconductor IC chips 601, 269a, 269b, 269c, 270, 260, 602 and 603 for the fourth alternative, to one of the second group of metal pads of the topmost one of the interconnection metal layers 668 of its interconnection substrate 684, wherein each of its high-density and low-density bonded metal bumps or contacts 563a and 563b may include a copper layer having a thickness between 2 μm and 20 μm between said each of its semiconductor IC chips 601, 269a, 269b, 269c, 260, 602 and 603 for the third alternative, or said each of its semiconductor IC chips 601, 269a, 269b, 269c, 270, 260, 602 and 603 for the fourth alternative, and its interconnection substrate 684 and a solder cap, made of a tin-silver alloy, a tin-gold alloy, a tin-copper alloy, a tin-indium alloy, indium or tin, having a thickness of between 1 μm and 15 μm between the copper layer of said each of its high-density and low-density bonded metal bumps or contacts 563a and 563b and its interconnection substrate 684.

Further, referring to FIGS. 5A-3, 5A-4 and 8B, for the first structure 301 for said each of the first type of field-programmable multi-chip packages 300 for the third and fourth alternatives, its FPGA/NVM multi-chip package 259 may be any type of the second through eighth types and twelfth through fourteenth types of FPMCPs 305-311 and 315-317 as seen in FIGS. 10, 11, 12, 13A, 13B, 14, 15A, 15B, 16, 20, 21 and 22 and the seventeenth type of FPMCPs 320 for the first through third alternatives as seen in FIGS. 25A-25C with the metal bumps, pillars or pads 570 at the bottom thereof bonded to the micro-bumps, micro-pillars or micro-pads of its interconnection substrate 684 to form (1) multiple high-density bonded metal bumps or contacts 574a between a peripheral portion of its FPGA/NVM multi-chip package 259 and one of the fine-line interconnection bridges (FIBs) 690, or DFPIC or eFPIC chips 400, of its interconnection substrate 684, each coupling its FPGA/NVM multi-chip package 259 to one of the metal pads or input/output (I/O) pads of said one of the fine-line interconnection bridges (FIBs) 690, or DFPIC or eFPIC chips 400, of its interconnection substrate 684 through one of the first group of metal pads of the topmost one of the interconnection metal layers 668 of its interconnection substrate 684, and (2) multiple low-density bonded metal bumps or contacts 574b between a central portion of its FPGA/NVM multi-chip package 259 and its interconnection substrate 684, each coupling its FPGA/NVM multi-chip package 259 to one of the second group of metal pads of the topmost one of the interconnection metal layers 668 of its interconnection substrate 684, wherein each of its high-density and low-density bonded metal bumps or contacts 574a and 574b may include a copper layer having a thickness between 2 μm and 20 μm between its FPGA/NVM multi-chip package 259 and interconnection substrate 684 and a solder cap, made of a tin-silver alloy, a tin-gold alloy, a tin-copper alloy, a tin-indium alloy, indium or tin, having a thickness of between 1 μm and 15 μm between the copper layer of said each of its high-density and low-density bonded metal bumps or contacts 574a and 574b and its interconnection substrate 684.

Alternatively, referring to FIGS. 5A-3, 5A-4 and 8B, for the first structure 301 for said each of the first type of field-programmable multi-chip packages 300 for the third and fourth alternatives, its FPGA/NVM multi-chip package 259 may be the ninth type of FPMCP 312 as seen in FIG. 17 with the metal bumps, pillars or pads 571 at the bottom thereof bonded to the micro-bumps, micro-pillars or micro-pads of its interconnection substrate 684 to form (1) multiple high-density bonded metal bumps or contacts 574a between a peripheral portion of its FPGA/NVM multi-chip package 259 and one of the fine-line interconnection bridges (FIBs) 690, or DFPIC or eFPIC chips 400, of its interconnection substrate 684, each coupling its FPGA/NVM multi-chip package 259 to one of the metal pads or input/output (I/O) pads of said one of the fine-line interconnection bridges (FIBs) 690, or DFPIC or eFPIC chips 400, of its interconnection substrate 684 through one of the first group of metal pads of the topmost one of the interconnection metal layers 668 of its interconnection substrate 684, and (2) multiple low-density bonded metal bumps or contacts 574b between a central portion of its FPGA/NVM multi-chip package 259 and its interconnection substrate 684, each coupling its FPGA/NVM multi-chip package 259 to one of the second group of metal pads of the topmost one of the interconnection metal layers 668 of its interconnection substrate 684, wherein each of its high-density and low-density bonded metal bumps or contacts 574a and 574b may include a copper layer having a thickness between 2 μm and 20 μm between its FPGA/NVM multi-chip package 259 and interconnection substrate 684 and a solder cap, made of a tin-silver alloy, a tin-gold alloy, a tin-copper alloy, a tin-indium alloy, indium or tin, having a thickness of between 1 μm and 15 μm between the copper layer of said each of its high-density and low-density bonded metal bumps or contacts 574a and 574b and its interconnection substrate 684.

Alternatively, referring to FIGS. 5A-3, 5A-4 and 8B, its FPGA/NVM multi-chip package 259 may be the tenth type of FPMCP 313 as seen in FIG. 18, eleventh type of FPMCP 314 for the first alternative as seen in FIGS. 19 and 19-1, eleventh type of FPMCP 314-1 for the second alternative as seen in FIG. 19-2, eleventh type of FPMCP 314-2 for the third alternative as seen in FIG. 19-3, eleventh type of FPMCP 314-3 for the fourth alternative as seen in FIG. 19-4, eleventh type of FPMCP 314-4 for the fifth alternative as seen in FIG. 19-5, eleventh type of FPMCP 314-5 for the sixth alternative as seen in FIG. 19-6, eleventh type of FPMCP 314-6 for the seventh alternative as seen in FIG. 19-7, eleventh type of FPMCP 314-7 for the eighth alternative as seen in FIG. 19-8, eleventh type of FPMCP 314-8 for the ninth alternative as seen in FIG. 19-9, sixteenth type of FPMCP 319 as seen in FIG. 24 or seventeenth type of FPMCP 320 for second or third alternative as seen in FIG. 25B or 25C with the solder balls 538 at the bottom thereof bonded to the micro-bumps, micro-pillars or micro-pads of its interconnection substrate 684 to form (1) multiple high-density bonded metal bumps or contacts 574a between a peripheral portion of its FPGA/NVM multi-chip package 259 and one of the fine-line interconnection bridges (FIBs) 690, or DFPIC or eFPIC chips 400, of its interconnection substrate 684, each coupling its FPGA/NVM multi-chip package 259 to one of the metal pads or input/output (I/O) pads of said one of the fine-line interconnection bridges (FIBs) 690, or DFPIC or eFPIC chips 400, of its interconnection substrate 684 through one of the first group of metal pads of the topmost one of the interconnection metal layers 668 of its interconnection substrate 684, and (2) multiple low-density bonded metal bumps or contacts 574b between a central portion of its FPGA/NVM multi-chip package 259 and its interconnection substrate 684, each coupling its FPGA/NVM multi-chip package 259 to one of the second group of metal pads of the topmost one of the interconnection metal layers 668 of its interconnection substrate 684, wherein each of its high-density and low-density bonded metal bumps or contacts 574a and 574b may include a tin-lead alloy or tin-silver-copper alloy between its FPGA/NVM multi-chip package 259 and interconnection substrate 684.

Alternatively, referring to FIGS. 5A-3, 5A-4 and 8B, for the first structure 301 for said each of the first type of field-programmable multi-chip packages 300 for the third and fourth alternatives, its FPGA/NVM multi-chip package 259 may be the fifteenth type of FPMCP 318 as seen in FIG. 23A or 23B with the metal contacts 452 at the bottom thereof bonded to the micro-bumps, micro-pillars or micro-pads of its interconnection substrate 684 to form (1) multiple high-density bonded metal bumps or contacts 574a between a peripheral portion of its FPGA/NVM multi-chip package 259 and one of the fine-line interconnection bridges (FIBs) 690, or DFPIC or eFPIC chips 400, of its interconnection substrate 684, each coupling its FPGA/NVM multi-chip package 259 to one of the metal pads or input/output (I/O) pads of said one of the fine-line interconnection bridges (FIBs) 690, or DFPIC or eFPIC chips 400, of its interconnection substrate 684 through one of the first group of metal pads of the topmost one of the interconnection metal layers 668 of its interconnection substrate 684, and (2) multiple low-density bonded metal bumps or contacts 574b between a central portion of its FPGA/NVM multi-chip package 259 and its interconnection substrate 684, each coupling its FPGA/NVM multi-chip package 259 to one of the second group of metal pads of the topmost one of the interconnection metal layers 668 of its interconnection substrate 684; for a first example, each of its high-density and low-density bonded metal bumps or contacts 574a and 574b may include (1) a copper layer having a thickness between 1 μm and 60 μm, between 2 μm and 20 μm or between 10 μm and 50 m between its FPGA/NVM multi-chip package 259 and interconnection substrate 684, and (2) a solder cap, made of a tin-silver alloy, a tin-gold alloy, a tin-copper alloy, a tin-indium alloy, indium or tin, having a thickness of between 1 μm and 15 μm, between 1 μm and 50 μm or between 20 μm and 100 μm between the copper layer of said each of its high-density and low-density bonded metal bumps or contacts 574a and 574b and its interconnection substrate 684; for a second example, each of its high-density and low-density bonded metal bumps or contacts 574a and 574b may include a tin-lead alloy or tin-silver-copper alloy between its FPGA/NVM multi-chip package 259 and interconnection substrate 684.

Accordingly, referring to FIGS. 5A-3, 5A-4 and 8B, for the first structure 301 for each of the first type of field-programmable multi-chip packages 300 for the third and fourth alternatives, neighboring two of its semiconductor IC chips 601, 269a, 269b, 269c, 260, 602 and 603 for the third alternative, or neighboring two of its semiconductor IC chips 601, 269a, 269b, 269c, 270, 260, 602 and 603 for the fourth alternative, may couple to each other through, in sequence, (1) one of its high-density bonded metal bumps or contacts 563a under one of said neighboring two of its semiconductor IC chips 601, 269a, 269b, 269c, 260, 602 and 603 for the third alternative, or one of said neighboring two of its semiconductor IC chips 601, 269a, 269b, 269c, 270, 260, 602 and 603 for the fourth alternative, (2) one of the metal lines or traces 693 of one of the fine-line interconnection bridges (FIBs) 690, or DFPIC or eFPIC chips 400, of its interconnection substrate 684 vertically under said neighboring two of its semiconductor IC chips 601, 269a, 269b, 269c, 260, 602 and 603 for the third alternative, or said neighboring two of its semiconductor IC chips 601, 269a, 269b, 269c, 270, 260, 602 and 603 for the fourth alternative, and (3) one of its high-density bonded metal bumps or contacts 563a under the other of said neighboring two of its semiconductor IC chips 601, 269a, 269b, 269c, 260, 602 and 603 for the third alternative, or the other of said neighboring two of its semiconductor IC chips 601, 269a, 269b, 269c, 270, 260, 602 and 603 for the fourth alternative.

Further, referring to FIGS. 5A-3, 5A-4 and 8B, for the first structure 301 for each of the first type of field-programmable multi-chip packages 300 for the third and fourth alternatives, its FPGA/NVM multi-chip package 259 may couple to one of its semiconductor IC chips 269a, 269b, 269c and 602 for the third alternative neighboring to its FPGA/NVM multi-chip package 259, or one of its semiconductor IC chips 269a, 269b, 269c and 270 for the fourth alternative neighboring to its FPGA/NVM multi-chip package 259, through, in sequence, (1) one of its high-density bonded metal bumps or contacts 574a under its FPGA/NVM multi-chip package 259, (2) one of the metal lines or traces 693 of one of the fine-line interconnection bridges (FIBs) 690, or DFPIC or eFPIC chips 400, of its interconnection substrate 684 vertically under its FPGA/NVM multi-chip package 259 and said one of its semiconductor IC chips 269a, 269b, 269c and 602 for the third alternative, or said one of its semiconductor IC chips 269a, 269b, 269c and 270 for the fourth alternative, and (3) one of its high-density bonded metal bumps or contacts 563a under said one of its semiconductor IC chips 269a, 269b, 269c and 602 for the third alternative, or said one of its semiconductor IC chips 269a, 269b, 269c and 270 for the fourth alternative.

Alternatively, referring to FIGS. 5A-3, 5A-4 and 8B, for the first structure 301 for each of the first type of field-programmable multi-chip packages 300 for the third and fourth alternatives, each of the DFPIC or eFPIC chips 400 of its interconnection substrate 684 may be vertically under neighboring two of its semiconductor IC chips 601, 269a, 269b, 269c, 260, 602 and 603 and FPGA/NVM multi-chip package 259 for the third alternative, or neighboring two of its semiconductor IC chips 601, 269a, 269b, 269c, 270, 260, 602 and 603 and FPGA/NVM multi-chip package 259 for the fourth alternative, wherein said each of the DFPIC or eFPIC chips 400 may couple to a first device of said neighboring two of its semiconductor IC chips 601, 269a, 269b, 269c, 260, 602 and 603 and FPGA/NVM multi-chip package 259 for the third alternative, or neighboring two of its semiconductor IC chips 601, 269a, 269b, 269c, 270, 260, 602 and 603 and FPGA/NVM multi-chip package 259 for the fourth alternative, through a first group of its high-density bonded metal bumps or contacts 563a between the first device and said each of the DFPIC or eFPIC chips 400 and couple to a second device of said neighboring two of its semiconductor IC chips 601, 269a, 269b, 269c, 260, 602 and 603 and FPGA/NVM multi-chip package 259 for the third alternative, or neighboring two of its semiconductor IC chips 601, 269a, 269b, 269c, 270, 260, 602 and 603 and FPGA/NVM multi-chip package 259 for the fourth alternative, through a second group of its high-density bonded metal bumps or contacts 563a between the second device and said each of the DFPIC or eFPIC chips 400, wherein for each of the third and fourth alternatives the first device may be its FPGA/NVM multi-chip package 259 and the second device may be its CPU IC chip 269b horizontally neighboring to its FPGA/NVM multi-chip package 259 as seen in FIGS. 5A-3 and 5A-4, for example; for each of the third and fourth alternatives the first device may be its FPGA/NVM multi-chip package 259 and the second device may be its GPU IC chip 269a horizontally neighboring to its FPGA/NVM multi-chip package 259 as seen in FIGS. 5A-3 and 5A-4, for example; for each of the third and fourth alternatives the first device may be its FPGA/NVM multi-chip package 259 and the second device may be its application-specific integrated-circuit (ASIC) chip or system-on-chip (SoC) chip 269c horizontally neighboring to its FPGA/NVM multi-chip package 259 as seen in FIGS. 5A-3 and 5A-4, for example; for the third alternative the first device may be its FPGA/NVM multi-chip package 259 and the second device may be its HBM IC chip 602 horizontally neighboring to its FPGA/NVM multi-chip package 259 as seen in FIG. 5A-3, for example; for the fourth alternative the first device may be its FPGA/NVM multi-chip package 259 and the second device may be its digital-signal-processing (DSP) IC chip 270 horizontally neighboring to its FPGA/NVM multi-chip package 259 as seen in FIG. 5A-4, for example. Said each of the DFPIC or eFPIC chips 400 may include (1) the first type of field programmable logic cell or element (LCE) 2014 or 2014-2 as illustrated in FIGS. 1A, 4D and 4E, the data inputs A0 and A1 of which may couple to the first device through, in sequence, respective two of the small input/output (SIO) circuits 203, or metal pads or input/output (I/O) pads, of said each of the DFPIC or eFPIC chips 400 and respective two of the first group of its high-density bonded metal bumps or contacts 563a and the data output Dout of which may couple to the second device through, in sequence, another of the small input/output (SIO) circuits 203, or metal pads or input/output (I/O) pads, of said each of the DFPIC or eFPIC chips 400 and one of the second group of its high-density bonded metal bumps or contacts 563a, (2) the second or third type of field programmable logic cell or element (LCE) 2014 or 2014-2 as illustrated in FIGS. 1B, 1C, 4D and 4E, the data inputs A0-A3 of which may couple to the first device through, in sequence, respective four of the small input/output (SIO) circuits 203, or metal pads or input/output (I/O) pads, of said each of the DFPIC or eFPIC chips 400 and respective four of the first group of its high-density bonded metal bumps or contacts 563a and the data output Dout of which may couple to the second device through, in sequence, another of the small input/output (SIO) circuits 203, or metal pads or input/output (I/O) pads, of said each of the DFPIC or eFPIC chips 400 and one of the second group of its high-density bonded metal bumps or contacts 563a, (3) the first type of field programmable switch cell 379 or 379-2 as illustrated in FIGS. 2A, 4D and 4E, the node N21 of which may couple to the first device through, in sequence, one of the small input/output (SIO) circuits 203, or metal pads or input/output (I/O) pads, of said each of the DFPIC or eFPIC chips 400 and one of the first group of its high-density bonded metal bumps or contacts 563a and the node N22 of which may couple to the second device through, in sequence, another of the small input/output (SIO) circuits 203, or metal pads or input/output (I/O) pads, of said each of the DFPIC or eFPIC chips 400 and one of the second group of its high-density bonded metal bumps or contacts 563a, to control coupling between the first and second devices, (4) the second type of field programmable switch cell 379 or 379-2 as illustrated in FIGS. 2B, 4D and 4E, the nodes N23 and N24 of which may couple to the first device through, in sequence, respective two of the small input/output (SIO) circuits 203, or metal pads or input/output (I/O) pads, of said each of the DFPIC or eFPIC chips 400 and respective two of the first group of its high-density bonded metal bumps or contacts 563a and the nodes N25 and N26 of which may couple to the second device through, in sequence, another respective two of the small input/output (SIO) circuits 203, or metal pads or input/output (I/O) pads, of said each of the DFPIC or eFPIC chips 400 and respective two of the second group of its high-density bonded metal bumps or contacts 563a, to control coupling from the node N23 to one or more of the nodes N24-N26 or to control coupling from the node N26 to one or more of the nodes N23-N25, (5) the field programmable switch matrix 710 or 710-3 as illustrated in FIGS. 2C, 4D and 4E, each of the nodes P₁-P_{N} of which may couple to the first device through, in sequence, one of the first metal lines 281 of said each of the DFPIC or eFPIC chips 400, one of the small input/output (SIO) circuits 203, or metal pads or input/output (I/O) pads, of said each of the DFPIC or eFPIC chips 400 and one of the first group of its high-density bonded metal bumps or contacts 563a, each of the nodes Q₁-Q_{M} of which may couple to the second device through, in sequence, one of the second metal lines 282 of said each of the DFPIC or eFPIC chips 400, another of the small input/output (SIO) circuits 203, or metal pads or input/output (I/O) pads, of said each of the DFPIC or eFPIC chips 400 and one of the second group of its high-density bonded metal bumps or contacts 563a and each of the pass/no-pass switches 778 of which may control coupling between the first and second devices, i.e., between one of the first group of its high-density bonded metal bumps or contacts 563a and one of the second group of its high-density bonded metal bumps or contacts 563a, and/or (6) the field programmable switch matrix 710-2 as illustrated in FIGS. 2C and 4E, each of some of the nodes P₁-P_{N} of which may couple to the first device through, in sequence, one of the first metal lines 281 of said each of the DFPIC or eFPIC chips 400, one of the small input/output (SIO) circuits 203, or metal pads or input/output (I/O) pads, of said each of the DFPIC or eFPIC chips 400 and one of the first group of its high-density bonded metal bumps or contacts 563a, each of the other some of the nodes P₁-P_{N} of which may couple to the second device through, in sequence, another of the first metal lines 281 of said each of the DFPIC or eFPIC chips 400, another of the small input/output (SIO) circuits 203, or metal pads or input/output (I/O) pads, of said each of the DFPIC or eFPIC chips 400 and one of the second group of its high-density bonded metal bumps or contacts 563a and each of the pass/no-pass switches 778 of which may control coupling between one of the first and second devices and one of the internal circuits of the fourth one of the ASIC cores 215 of said each of the DFPIC or eFPIC chips 400, i.e., between one of the first and second groups of its high-density bonded metal bumps or contacts 563a and one of the internal circuits of the fourth one of the ASIC cores 215 of said each of the DFPIC or eFPIC chips 400.

Referring to FIGS. 5A-1, 5A-2, 5A-3, 5A-4, 5A-5, 8A and 8B, for the third structure 303 for each of the first type of FPMCPs 300 for the first through fifth alternatives, each of its high-density bonded metal bumps or contacts 563a and 574a may have the largest dimension in a horizontal cross section (for example, the diameter of a circle shape, or the diagonal length of a square or rectangle shape) between 3 μm and 60 μm, 5 μm and 50 μm, 5 μm and 40 μm, 5 μm and 30 μm, 5 μm and 20 μm, 5 m and 15 μm, or 3 μm and 10 μm, or smaller than or equal to 60 μm, 50 μm, 40 μm, 30 μm, 20 μm, 15 μm or 10 μm. The smallest space between neighboring two of its high-density bonded metal bumps or contacts 563a and 574a may be between, for example, 3 μm and 60 μm, 5 μm and 50 μm, 5 μm and 40 μm, 5 μm and 30 μm, 5 μm and 20 μm, 5 μm and 15 μm, or 3 μm and 10 μm, or smaller than or equal to 60 μm, 50 μm, 40 μm, 30 μm, 20 μm, 15 μm or 10 μm. Each of its low-density bonded metal bumps or contacts 563b and 574b may have the largest dimension in a horizontal cross section (for example, the diameter of a circle shape, or the diagonal length of a square or rectangle shape) between, for example, 20 μm and 200 μm, 20 μm and 150 μm, 20 μm and 100 μm, 20 μm and 75 μm, or 20 μm and 50 μm or larger than or equal to 20 μm, 30 μm, 40 μm, or 50 μm. The smallest space between neighboring two of its low-density bonded metal bumps or contacts 563b and 574b may be between, for example, 20 μm and 200 μm, 20 μm and 150 μm, 20 μm and 100 μm, 20 μm and 75 μm, or 20 μm and 50 μm or larger than or equal to 20 μm, 30 μm, 40 μm, or 50 μm. The ratio of the largest dimension in a horizontal cross section of each of its low-density bonded metal bumps or contacts 563b and 574b to that of each of its high-density bonded metal bumps or contacts 563a and 574a may be between 1.1 and 5 or greater than 1.2, 1.5 or 2, for example. The ratio of the smallest space between neighboring two of its low-density bonded metal bumps or contacts 563b and 574b to that between neighboring two of its high-density bonded metal bumps or contacts 563a and 574a may be between 1.1 and 5 or greater than 1.2, 1.5 or 2, for example.

Referring to FIGS. 5A-1, 5A-2, 5A-5 and 8A, the third structure 303 for said each of the first type of FPMCPs 300 for the first, second and fifth alternatives may further include an underfill 564, i.e., polymer layer, between each of its semiconductor IC chips 200, 250, 269a, 269b, 269c, 251 and 411 for the first alternative, or each of its semiconductor IC chips 200, 250, 269a, 269b, 251, 270, 402 and 411 and first, second and third types of subsystem units 401, 403 and 404 for the second alternative, or each of its semiconductor IC chips 200, 250, 255, 269a, 269b, 269c, 251 and 411 for the fifth alternative, and its interconnection substrate 684, covering a sidewall of each of its high-density and low-density bonded metal bumps or contacts 563a and 563b between said each of its semiconductor IC chips 200, 250, 269a, 269b, 269c, 251 and 411 for the first alternative, or said each of its semiconductor IC chips 200, 250, 269a, 269b, 251, 270, 402 and 411 and first, second and third types of subsystem units 401, 403 and 404 for the second alternative, or said each of its semiconductor IC chips 200, 250, 255, 269a, 269b, 269c, 251 and 411 for the fifth alternative, and its interconnection substrate 684. Its polymer layer 92 may be formed on a top surface of its interconnection substrate 684 and its underfill 564 and horizontally around each of its semiconductor IC chips 200, 250, 269a, 269b, 269c, 251 and 411 for the first alternative, or each of its semiconductor IC chips 200, 250, 269a, 269b, 251, 270, 402 and 411 and first, second and third types of subsystem units 401, 403 and 404 for the second alternative, or each of its semiconductor IC chips 200, 250, 255, 269a, 269b, 269c, 251 and 411 for the fifth alternative. Its polymer layer 92 may have a vertical sidewall coplanar with a vertical sidewall of its interconnection substrate 684. The third structure 303 for said each of the first type of FPMCPs 300 for the first, second and fifth alternatives may further include multiple metal bumps 572, such as solder bumps, in an array at its bottom to act as its external pins for coupling to the external circuits 340 as seen in FIG. 5D-5G or 5K outside of the third structure 303 for said each of the first type of FPMCPs 300 for the first, second and fifth alternatives, wherein each of its metal bumps 572 may be formed on one of the metal pads of the bottommost one of the interconnection metal layers 668 of its interconnection substrate 684 and each of its metal bumps 572 may be made of a lead-free solder containing tin, copper, silver, bismuth, indium, zinc, antimony and/or traces of other metals, e.g., Sn—Ag—Cu (SAC) solder, Sn—Ag solder or Sn—Ag—Cu—Zn solder. Each of its semiconductor IC chips 200, 250, 269a, 269b, 269c, 251 and 411 for the first alternative, or each of its semiconductor IC chips 200, 250, 269a, 269b, 251, 270, 402 and 411 and first, second and third types of subsystem units 401, 403 and 404 for the second alternative, or each of its semiconductor IC chips 200, 250, 255, 269a, 269b, 269c, 251 and 411 for the fifth alternative, may couple to one of its metal bumps 572 for external connection through each of the interconnection metal layers 668 of its interconnection substrate 684.

Referring to FIGS. 5A-3, 5A-4 and 8B, the third structure 303 for said each of the first type of FPMCPs 300 for the third and fourth alternatives may further include an underfill 564, i.e., polymer layer, between each of its semiconductor IC chips 601, 269a, 269b, 269c, 260, 602 and 603 and FPGA/NVM multi-chip package 259 for the third alternative, or each of its semiconductor IC chips 601, 269a, 269b, 269c, 270, 260, 602 and 603 and FPGA/NVM multi-chip package 259 for the fourth alternative, and its interconnection substrate 684, covering a sidewall of each of its high-density bonded metal bumps or contacts 563a and 574a and low-density bonded metal bumps or contacts 563b and 574b between said each of its semiconductor IC chips 601, 269a, 269b, 269c, 260, 602 and 603 and FPGA/NVM multi-chip package 259 for the third alternative, or said each of its semiconductor IC chips 601, 269a, 269b, 269c, 270, 260, 602 and 603 and FPGA/NVM multi-chip package 259 for the fourth alternative, and its interconnection substrate 684. Its polymer layer 92 may be formed on a top surface of its interconnection substrate 684 and its underfill 564 and horizontally around each of its semiconductor IC chips 601, 269a, 269b, 269c, 260, 602 and 603 and FPGA/NVM multi-chip package 259 for the third alternative, or each of its semiconductor IC chips 601, 269a, 269b, 269c, 270, 260, 602 and 603 and FPGA/NVM multi-chip package 259 for the fourth alternative. Its polymer layer 92 may have a vertical sidewall coplanar with a vertical sidewall of its interconnection substrate 684. The third structure 303 for said each of the first type of FPMCPs 300 for the third and fourth alternatives may further include multiple metal bumps 572, such as solder bumps, in an array at its bottom to act as its external pins for coupling to external circuits outside of the third structure 303 for said each of the first type of FPMCPs 300 for the third and fourth alternatives, wherein each of its metal bumps 572 may be formed on one of the metal pads of the bottommost one of the interconnection metal layers 668 of its interconnection substrate 684 and each of its metal bumps 572 may be made of a lead-free solder containing tin, copper, silver, bismuth, indium, zinc, antimony and/or traces of other metals, e.g., Sn—Ag—Cu (SAC) solder, Sn—Ag solder or Sn—Ag—Cu—Zn solder. Said each of its semiconductor IC chips 601, 269a, 269b, 269c, 260, 602 and 603 and FPGA/NVM multi-chip package 259 for the third alternative, or said each of its semiconductor IC chips 601, 269a, 269b, 269c, 270, 260, 602 and 603 and FPGA/NVM multi-chip package 259 for the fourth alternative, may couple to one of its metal bumps 572 for external connection through each of the interconnection metal layers 668 of its interconnection substrate 684.

Alternatively, referring to FIGS. 5A-1, 5A-2, 5A-5 and 8A, for the third structure 303 for said each of the first type of FPMCPs 300 for the first, second and fifth alternatives, its interconnection substrate 684 may be provided without the fine-line interconnection bridges (FIBs) 690, or DFPIC or eFPIC chips 400, therein and neighboring two of its semiconductor IC chips 200, 250, 269a, 269b, 269c, 251 and 411 for the first alternative, or neighboring two of its semiconductor IC chips 200, 250, 269a, 269b, 251, 270, 402 and 411 and first, second and third types of subsystem units 401, 403 and 404 for the second alternative, or neighboring two of its semiconductor IC chips 200, 250, 255, 269a, 269b, 269c, 251 and 411 for the fifth alternative, may couple to each other through, in sequence, (1) one of its high-density bonded metal bumps or contacts 563a under one of said neighboring two of its semiconductor IC chips 200, 250, 269a, 269b, 269c, 251 and 411 for the first alternative, or one of said neighboring two of its semiconductor IC chips 200, 250, 269a, 269b, 251, 270, 402 and 411 and first, second and third types of subsystem units 401, 403 and 404 for the second alternative, or one of said neighboring two of its semiconductor IC chips 200, 250, 255, 269a, 269b, 269c, 251 and 411 for the fifth alternative, (2) any or more of the interconnection metal layers 668 of its interconnection substrate 684 and (3) one of its high-density bonded metal bumps or contacts 563a under the other of said neighboring two of its semiconductor IC chips 200, 250, 269a, 269b, 269c, 251 and 411 for the first alternative, or the other of said neighboring two of its semiconductor IC chips 200, 250, 269a, 269b, 251, 270, 402 and 411 and first, second and third types of subsystem units 401, 403 and 404 for the second alternative, or the other of said neighboring two of its semiconductor IC chips 200, 250, 255, 269a, 269b, 269c, 251 and 411 for the fifth alternative.

Alternatively, referring to FIGS. 5A-3, 5A-4 and 8B, for the third structure 303 for each of the first type of FPMCPs 300 for the third and fourth alternatives, its interconnection substrate 684 may be provided without the fine-line interconnection bridges (FIBs) 690, or DFPIC or eFPIC chips 400, therein and neighboring two of its semiconductor IC chips 601, 269a, 269b, 269c, 260, 602 and 603 for the third alternative, or neighboring two of its semiconductor IC chips 601, 269a, 269b, 269c, 270, 260, 602 and 603 for the fourth alternative, may couple to each other through, in sequence, (1) one of its high-density bonded metal bumps or contacts 563a under one of said neighboring two of its semiconductor IC chips 601, 269a, 269b, 269c, 260, 602 and 603 for the third alternative, or one of said neighboring two of its semiconductor IC chips 601, 269a, 269b, 269c, 270, 260, 602 and 603 for the fourth alternative, (2) any or more of the interconnection metal layers 668 of its interconnection substrate 684 and (3) one of its high-density bonded metal bumps or contacts 563a under the other of said neighboring two of its semiconductor IC chips 601, 269a, 269b, 269c, 260, 602 and 603 for the third alternative, or the other of said neighboring two of its semiconductor IC chips 601, 269a, 269b, 269c, 270, 260, 602 and 603 for the fourth alternative. Its FPGA/NVM multi-chip package 259 may couple to one of its semiconductor IC chips 269a, 269b, 269c and 602 for the third alternative neighboring to its FPGA/NVM multi-chip package 259, or one of its semiconductor IC chips 269a, 269b, 269c and 270 for the fourth alternative neighboring to its FPGA/NVM multi-chip package 259, through, in sequence, (1) one of its high-density bonded metal bumps or contacts 574a under its FPGA/NVM multi-chip package 259, (2) any or more of the interconnection metal layers 668 of its interconnection substrate 684, and (3) one of its high-density bonded metal bumps or contacts 563a under said one of its semiconductor IC chips 269a, 269b, 269c and 602 for the third alternative, or said one of its semiconductor IC chips 269a, 269b, 269c and 270 for the fourth alternative.

### Fourth Structure for First Type of FPMCP

The fourth structure 304 may be fabricated for each of the first type of FPMCPs 300 for the first, second and fifth alternatives as illustrated in FIGS. 5A-1, 5A-2 and 5A-5. FIG. 9A is a schematically cross-sectional view showing a fourth structure provided with a first type of interconnection substrate for a first type of FPMCP for any first, second or fifth alternative in accordance with an embodiment of the present application, wherein FIG. 9A is a schematically cross-sectional view along a cross-sectional line A-A in either FIG. 5A-1, 5A-2 or 5A-5; FIG. 9B is a schematically cross-sectional view showing a fourth structure provided with a first type of interconnection substrate for a first type of FPMCP for a second alternative in accordance with an embodiment of the present application, wherein FIG. 9B is a schematically cross-sectional view along a cross-sectional line B-B in FIG. 5A-2; FIG. 9C is a schematically cross-sectional view showing a fourth structure provided with a second type of interconnection substrate for a first type of FPMCP for any first, second of fifth alternative in accordance with an embodiment of the present application, wherein FIG. 9C is a schematically cross-sectional view along a cross-sectional line A-A in any FIG. 5A-1, 5A-2 or 5A-5. Further, the fourth structure 304 may be fabricated for each of the first type of FPMCPs 300 for the third and fourth alternatives as illustrated in FIGS. 5A-3 and 5A-4. FIG. 9D is a schematically cross-sectional view showing a fourth structure provided with a first type of interconnection substrate for a first type of FPMCP for either third or fourth alternative in accordance with an embodiment of the present application, wherein FIG. 9D is a schematically cross-sectional view along a cross-sectional line C-C in FIG. 5A-3 and 5A-4. The fourth structure 304 for each of the first type of FPMCPs 300 for the first, second and fifth alternatives as seen in FIGS. 9A-9C may have a similar structure to the first structure 301 for the same as seen in FIG. 6A. For an element indicated by the same reference number shown in FIGS. 6A and 9A-9C, the specification of the element as seen in FIGS. 9A-9C may be referred to that of the element as illustrated in FIG. 6A. The difference therebetween is that the interposer 551 of the first structure 301 for each of the first type of FPMCPs 300 for the first, second and fifth alternatives as seen in FIG. 6A may be replaced with a first type of interconnection substrate 177 as seen in FIGS. 9A and 9B or a second type of interconnection substrate 177 as seen in FIG. 9C. The fourth structure 304 for each of the first type of FPMCPs 300 for the third and fourth alternatives as seen in FIG. 9D may have a similar structure to the first structure 301 for the same as seen in FIG. 6B. For an element indicated by the same reference number shown in FIGS. 6B and 9D, the specification of the element as seen in FIG. 9D may be referred to that of the element as illustrated in FIG. 6B. The difference therebetween is that the interposer 551 of the first structure 301 for each of the first type of FPMCPs 300 for the third and fourth alternatives as seen in FIG. 6B may be replaced with a first type of interconnection substrate 177 as seen in FIG. 9D or a second type of interconnection substrate 177 as seen in FIG. 9C. Referring to FIGS. 9A-9D, for the fourth structure 304 for each of the first type of FPMCPs 300 for the first through fifth alternatives, each type of its first and second types of interconnection substrates 177 may include (1) multiple fine-line interconnection bridges (FIBs) 690, or DFPIC or eFPIC chips 400, as illustrated in FIGS. 8A and 8B each provided further with multiple first type of micro-bumps, micro-pillars or micro-pads 34 at a top of said each of the fine-line interconnection bridges (FIBs) 690, or DFPIC or eFPIC chips 400, and on the metal pads or input/output (I/O) pads of said each of the fine-line interconnection bridges (FIBs) 690, or DFPIC or eFPIC chips 400, respectively, wherein each of the first type of micro-bumps, micro-pillars or micro-pads 34 of each of the fine-line interconnection bridges (FIBs) 690, or DFPIC or eFPIC chips 400, of said each type of its first and second types of interconnection substrates 177 may have the same specification as that of the first type of micro-bumps, micro-pillars or micro-pads 34 respectively as illustrated in FIG. 3A, that is, each of the first type of micro-bumps, micro-pillars or micro-pads 34 of each of the fine-line interconnection bridges (FIBs) 690, or DFPIC or eFPIC chips 400, of said each type of its first and second types of interconnection substrates 177 may have the adhesion metal layer 26a on one of the metal pads or input/output (I/O) pads of said each of the fine-line interconnection bridges (FIBs) 690, or DFPIC or eFPIC chips 400, of said each type of its first and second types of interconnection substrates 177, the electroplating seed layer 26b on the adhesion metal layer 26a of said each of the first type of micro-bumps, micro-pillars or micro-pads 34 and the copper layer on the electroplating seed layer 26b of said each of the first type of micro-bumps, micro-pillars or micro-pads 34, wherein said each of the fine-line interconnection bridges (FIBs) 690, or DFPIC or eFPIC chips 400, may be provided further with a polymer layer 257, i.e., insulating dielectric layer, at the top of said each of the fine-line interconnection bridges (FIBs) 690, or DFPIC or eFPIC chips 400, wherein the polymer layer 257 of said each of the fine-line interconnection bridges (FIBs) 690, or DFPIC or eFPIC chips 400, may be horizontally around each of the first type of micro-bumps, micro-pillars or micro-pads 34 of said each of the fine-line interconnection bridges (FIBs) 690, or DFPIC or eFPIC chips 400, and have a top surface coplanar with a top surface of each of the first type of micro-bumps, micro-pillars or micro-pads 34 of said each of the fine-line interconnection bridges (FIBs) 690, or DFPIC or eFPIC chips 400, wherein the polymer layer 257 of said each of the fine-line interconnection bridges (FIBs) 690, or DFPIC or eFPIC chips 400, is not extending over the top surface of each of the first type of micro-bumps, micro-pillars or micro-pads 34 of said each of the fine-line interconnection bridges (FIBs) 690, or DFPIC or eFPIC chips 400, (2) multiple vertical-through-via (VTV) connectors 467 each having the same specification as the first type of vertical-through-via (VTV) connector 467 illustrated in FIG. 4A, (3) a polymer layer 92 or insulating dielectric layer, i.e., sealing layer, such as silicon-oxide-containing molding compound, epoxy-based material or polyimide, horizontally around each of the fine-line interconnection bridges (FIBs) 690, or DFPIC or eFPIC chips 400, and vertical-through-via (VTV) connectors 467 of said each type of its first and second types of interconnection substrates 177 and in each gap between neighboring two of the fine-line interconnection bridges (FIBs) 690, or DFPIC or eFPIC chips 400, and vertical-through-via (VTV) connectors 467 of said each type of its first and second types of interconnection substrates 177, wherein the polymer layer 92 of said each type of its first and second types of interconnection substrates 177 may have a top surface coplanar with the top surface of the polymer layer 257 of each of the fine-line interconnection bridges (FIBs) 690, or DFPIC or eFPIC chips 400, and vertical-through-via (VTV) connectors 467 of said each type of its first and second types of interconnection substrates 177 and the top surface of each of the first type of micro-bumps, micro-pillars or micro-pads 34 of each of the fine-line interconnection bridges (FIBs) 690, or DFPIC or eFPIC chips 400, and vertical-through-via (VTV) connectors 467 of said each type of its first and second types of interconnection substrates 177, and (4) an interconnection scheme 79 under the fine-line interconnection bridges (FIBs) 690, or DFPIC or eFPIC chips 400, vertical-through-via (VTV) connectors 467 and polymer layer 92 of said each type of its first and second types of interconnection substrates 177. The semiconductor substrate 2 of each of the fine-line interconnection bridges (FIBs) 690, or DFPIC or eFPIC chips 400, and vertical-through-via (VTV) connectors 467 of said each type of its first and second types of interconnection substrates 177 may have a portion, at a backside of the semiconductor substrate 2 of said each of the fine-line interconnection bridges (FIBs) 690, or DFPIC or eFPIC chips 400, and vertical-through-via (VTV) connectors 467, removed by a chemical-mechanical-polishing (CMP) or mechanical grinding process such that each of the through silicon vias (TSVs) 157, that is, the electroplated copper layer 156 thereof, of each of the vertical-through-via (VTV) connectors 467 of said each type of its first and second types of interconnection substrates 177 may have a bottom surface substantially coplanar with a bottom surface of the semiconductor substrate 2 of each of the vertical-through-via (VTV) connectors 467 of said each type of its first and second types of interconnection substrates 177, a bottom surface of the semiconductor substrate 2 of each of the fine-line interconnection bridges (FIBs) 690, or DFPIC or eFPIC chips 400, of said each type of its first and second types of interconnection substrates 177 and a bottom surface of the polymer layer 92 of said each type of its first and second types of interconnection substrates 177. For an alternative case, said each type of its first and second types of interconnection substrates 177 may further include the insulating dielectric layer 185, such as silicon-oxide layer or silicon-nitride layer, illustrated in FIG. 4C but not shown in FIG. 9A formed on a bottom surface of the semiconductor substrate 2 of each of the fine-line interconnection bridges (FIBs) 690, or DFPIC or eFPIC chips 400, and vertical-through-via (VTV) connectors 467 of said each type of its first and second types of interconnection substrates 177, wherein the insulating dielectric layer 185 of said each type of its first and second types of interconnection substrates 177 may have a bottom surface coplanar with the bottom surface of each of the through silicon vias 157 of each of the vertical-through-via (VTV) connectors 467 of said each type of its first and second types of interconnection substrates 177 and the bottom surface of the polymer layer 92 of said each type of its first and second types of interconnection substrates 177. The interconnection scheme 79 of said each type of its first and second types of interconnection substrates 177 may be provided with one or more interconnection metal layers 27 coupling to each of the through silicon vias (TSV) 157 of each of the vertical-through-via (VTV) connectors 467 of said each type of its first and second types of interconnection substrates 177 and multiple polymer layers 42 each between neighboring two of the interconnection metal layers 27 of the interconnection scheme 79 of said each type of its first and second types of interconnection substrates 177, under the bottommost one of the interconnection metal layers 27 of the interconnection scheme 79 of said each type of its first and second types of interconnection substrates 177 or over the topmost one of the interconnection metal layers 27 of the interconnection scheme 79 of said each type of its first and second types of interconnection substrates 177, wherein an upper one of the interconnection metal layers 27 of the interconnection scheme 79 of said each type of its first and second types of interconnection substrates 177 may couple to a lower one of the interconnection metal layers 27 of the interconnection scheme 79 of said each type of its first and second types of interconnection substrates 177 through an opening in one of the polymer layers 42 of the interconnection scheme 79 of said each type of its first and second types of interconnection substrates 177 between the upper and lower ones of the interconnection metal layers 27 of the interconnection scheme 79 of said each type of its first and second types of interconnection substrates 177. The topmost one of the polymer layers 42 of the interconnection scheme 79 of said each type of its first and second types of interconnection substrates 177 may have a top surface in contact with the bottom surface of the polymer layer 92 of said each type of its first and second types of interconnection substrates 177, the bottom surface of the semiconductor substrate 2 of each of the vertical-through-via (VTV) connectors 467 of said each type of its first and second types of interconnection substrates 177 and the bottom surface of the semiconductor substrate 2 of each of the fine-line interconnection bridges (FIBs) 690, or DFPIC or eFPIC chips 400, of said each type of its first and second types of interconnection substrates 177. For the alternative case, the topmost one of the polymer layers 42 of the interconnection scheme 79 of said each type of its first and second types of interconnection substrates 177 may have a top surface in contact with the bottom surface of the polymer layer 92 of said each type of its first and second types of interconnection substrates 177 and the bottom surface of the insulating dielectric layer 185 of said each type of its first and second types of interconnection substrates 177. Each opening in the topmost one of the polymer layers 42 of the interconnection scheme 79 of said each type of its first and second types of interconnection substrates 177 may be under one of the through silicon vias (TSVs) 157 of one of the vertical-through-via (VTV) connectors 467 of said each type of its first and second types of interconnection substrates 177 and thus the topmost one of the interconnection metal layers 27 of the interconnection scheme 79 of said each type of its first and second types of interconnection substrates 177 may extend through said each opening to couple to said one of the through silicon vias (TSVs) 157. Each of the interconnection metal layers 27 of the interconnection scheme 79 of said each type of its first and second types of interconnection substrates 177 may extend horizontally across an edge of each of the fine-line interconnection bridges (FIBs) 690, or DFPIC or eFPIC chips 400, and vertical-through-via (VTV) connectors 467 of said each type of its first and second types of interconnection substrates 177. The bottommost one of the interconnection metal layers 27 of the interconnection scheme 79 of said each type of its first and second types of interconnection substrates 177 may have multiple metal pads or input/output (I/O) pads at tops of multiple respective openings in the bottommost one of the polymer layers 42 of the interconnection scheme 79 of said each type of its first and second types of interconnection substrates 177. The specification and process for the interconnection metal layers 27 and polymer layers 42 of the interconnection scheme 79 of said each type of its first and second types of interconnection substrates 177 may be referred to those for the second interconnection scheme for a chip (SISC) 29 as illustrated in FIG. 3A to be turned upside down. Referring to FIG. 9C, for the fourth structure 304 for each of the first type of FPMCPs 300 for the first through fifth alternatives, besides the above elements, its second type of interconnection substrate 177 may further include another interconnection scheme 80 over the fine-line interconnection bridges (FIBs) 690, or DFPIC or eFPIC chips 400, vertical-through-via (VTV) connectors 467 and polymer layer 92 of its second type of interconnection substrate 177. Each of the first type of micro-bumps, micro-pillars or micro-pads 34 of each of the fine-line interconnection bridges (FIBs) 690, or DFPIC or eFPIC chips 400, and vertical-through-via (VTV) connectors 467 of its second type of interconnection substrate 177 may couple to its interconnection scheme 80. The interconnection scheme 80 of its second type of interconnection substrate 177 may include (1) multiple interconnection metal layers 27 (only one is shown) coupling to each of the first type of micro-bumps, micro-pillars or micro-pads 34 of each of the fine-line interconnection bridges (FIBs) 690, or DFPIC or eFPIC chips 400, and vertical-through-via (VTV) connectors 467 of its second type of interconnection substrate 177 and (2) one or more polymer layers 42, i.e., insulating dielectric layers, each between neighboring two of the interconnection metal layers 27 of the interconnection scheme 80 of its second type of interconnection substrate 177, under the bottommost one of the interconnection metal layers 27 of the interconnection scheme 80 of its second type of interconnection substrate 177 or over the topmost one of the interconnection metal layers 27 of the interconnection scheme 80 of its second type of interconnection substrate 177, wherein an upper one of the interconnection metal layers 27 of the interconnection scheme 80 of its second type of interconnection substrate 177 may couple to a lower one of the interconnection metal layers 27 of the interconnection scheme 80 of its second type of interconnection substrate 177 through an opening in one of the polymer layers 42 of the interconnection scheme 80 of its second type of interconnection substrate 177 between the upper and lower ones of the interconnection metal layers 27 of the interconnection scheme 80 of its second type of interconnection substrate 177. The bottommost one of the polymer layers 42 of the interconnection scheme 80 of its second type of interconnection substrate 177 may have a bottom surface in contact with the top surface of the polymer layer 257 of each of the fine-line interconnection bridges (FIBs) 690, or DFPIC or eFPIC chips 400, and vertical-through-via (VTV) connectors 467 of its second type of interconnection substrate 177 and the top surface of the polymer layer 92 of its second type of interconnection substrate 177. Each opening in the bottommost one of the polymer layers 42 of the interconnection scheme 80 of its second type of interconnection substrate 177 may be over one of the first type of micro-bumps, micro-pillars or micro-pads 34 of one of the fine-line interconnection bridges (FIBs) 690, or DFPIC or eFPIC chips 400, and vertical-through-via (VTV) connectors 467 of its second type of interconnection substrate 177, and thus the bottommost one of the interconnection metal layers 27 of the interconnection scheme 80 of its second type of interconnection substrate 177 may couple to said one of the first type of micro-bumps, micro-pillars or micro-pads 34 through said each opening. Each of the interconnection metal layers 27 of the interconnection scheme 80 of its second type of interconnection substrate 177 may extend horizontally across an edge of each of the fine-line interconnection bridges (FIBs) 690, or DFPIC or eFPIC chips 400, and vertical-through-via (VTV) connectors 467 of its second type of interconnection substrate 177. The topmost one of the interconnection metal layers 27 of the interconnection scheme 80 of its second type of interconnection substrate 177 may have multiple metal pads at bottoms of multiple respective openings in the topmost one of the polymer layers 42 of the interconnection scheme 80 of its second type of interconnection substrate 177. The specification and process for the interconnection metal layers 27 and polymer layers 42 for the interconnection scheme 80 of its second type of interconnection substrate 177 may be referred to those for the second interconnection scheme for a chip (SISC) 29 as illustrated in FIG. 3A. Each of the polymer layers 42 of the interconnection scheme 80 of its second type of interconnection substrate 177 may be a layer of polyimide, benzocyclobutene (BCB), parylene, epoxy-based material or compound, photo epoxy SU-8, elastomer or silicone, having a thickness between, for example, 0.3 m and 30 μm, 0.5 μm and 20 μm, 1 μm and 10 μm, or 0.5 um and 5 μm, or thicker than or equal to 0.3 μm, 0.5 μm, 0.7 μm, 1 μm, 1.5 μm, 2 μm, 3 μm or 5 μm. Each of the interconnection metal layers 27 of the interconnection scheme 80 of its second type of interconnection substrate 177 may be provided with multiple metal traces or lines each including (1) a copper layer 40 having one or more lower portions in openings in one of the polymer layers 42 of the interconnection scheme 80 of its second type of interconnection substrate 177 and an upper portion having a thickness between 0.3 μm and 20 μm over said one of the polymer layers 42, (2) an adhesion metal layer 28a, such as titanium or titanium nitride having a thickness between 1 nm and 50 nm, at a bottom and sidewall of each of the one or more lower portions of the copper layer 40 of said each of the metal traces or lines and at a bottom of the upper portion of the copper layer 40 of said each of the metal traces or lines, and (3) an electroplating seed layer 28b, such as copper, between the copper layer 40 and adhesion metal layer 28a of said each of the metal traces or lines, wherein the upper portion of the copper layer 40 of said each of the metal traces or lines may have a sidewall not covered by the adhesion metal layer 28a of said each of the metal traces or lines. Each of the metal traces or lines of each of the interconnection metal layers 27 of the interconnection scheme 80 of its second type of interconnection substrate 177 may have a thickness between, for example, 0.3 μm and 30 μm, 0.5 μm and 20 μm, 1 μm and 10 μm, or 0.5 μm and 5 μm, or thicker than or equal to 0.3 μm, 0.5 μm, 0.7 μm, 1 μm, 1.5 μm, 2 μm, 3 μm or 5 μm, and a width between, for example, 0.3 μm and 30 μm, 0.5 μm and 20 μm, 1 μm and 10 μm, or 0.5 μm and 5 μm, or wider than or equal to 0.3 μm, 0.5 μm, 0.7 μm, 1 μm, 1.5 μm, 2 μm, 3 μm or 5 μm. The adhesion metal layer 28a of the bottommost one of the interconnection metal layers 27 of the interconnection scheme 80 of its second type of interconnection substrate 177 may be provided on and in contact with the copper layer 32 of each of the first type of micro-bumps, micro-pillars or micro-pads 34 of each of the fine-line interconnection bridges (FIBs) 690, or DFPIC or eFPIC chips 400, and vertical-through-via (VTV) connectors 467 of its second type of interconnection substrate 177 and between the copper layer 40 of the bottommost one of the interconnection metal layers 27 of the interconnection scheme 80 of its second type of interconnection substrate 177 and the copper layer 32 of each of the first type of micro-bumps, micro-pillars or micro-pads 34 of each of the fine-line interconnection bridges (FIBs) 690, or DFPIC or eFPIC chips 400, and vertical-through-via (VTV) connectors 467 of its second type of interconnection substrate 177.

Referring to FIGS. 5A-1, 5A-2, 5A-5 and 9A-9C, for the fourth structure 304 for said each of the first type of FPMCPs 300 for the first, second and fifth alternatives, each of its semiconductor IC chips 200, 250, 269a, 269b, 269c, 251 and 411 for the first alternative, or each of its semiconductor IC chips 200, 250, 269a, 269b, 251, 270, 402 and 411 for the second alternative, each of its semiconductor IC chips 200, 250, 255, 269a, 269b, 269c, 251 and 411 for the fifth alternative, may have the same specification as the first type of semiconductor IC chip 100 illustrated in FIG. 3A to be turned upside down. Each of its semiconductor IC chips 200, 250, 269a, 269b, 269c, 251 and 411 for the first alternative, or each of its semiconductor IC chips 200, 250, 269a, 269b, 251, 270, 402 and 411 and first, second and third types of subsystem units 401, 403 and 404 for the second alternative, or each of its semiconductor IC chips 200, 250, 255, 269a, 269b, 269c, 251 and 411 for the fifth alternative, may have the first, second, third or fourth type of micro-bumps, micro-pillars or micro-pads 34 each bonded to (1) one of the first type of micro-bumps, micro-pillars or micro-pads 34 of one of the fine-line interconnection bridges (FIBs) 690, or DFPIC or eFPIC chips 400, and vertical-through-via (VTV) connectors 467 of its first type of interconnection substrate 177 as seen in FIGS. 9A and 9B, or (2) a metal contact 349, such as copper contact or tin-containing contact, preformed on one of the metal pads of the topmost one of the interconnection metal layers 27 of the interconnection scheme 80 of its second type of interconnection substrate 177 as seen in FIG. 9C. Accordingly, neighboring two of its semiconductor IC chips 200, 250, 269a, 269b, 269c, 251 and 411 for the first alternative, or neighboring two of its semiconductor IC chips 200, 250, 269a, 269b, 251, 270, 402 and 411 and first, second and third types of subsystem units 401, 403 and 404 for the second alternative, or neighboring two of its semiconductor IC chips 200, 250, 255, 269a, 269b, 269c, 251 and 411 for the fifth alternative, may couple to each other through, in sequence in case for its first type of interconnection substrate 177 as seen in FIGS. 9A and 9B, (1) one of the first, second, third or fourth type of micro-bumps, micro-pillars or micro-pads 34 of one of said neighboring two of its semiconductor IC chips 200, 250, 269a, 269b, 269c, 251 and 411 for the first alternative, or one of the first, second, third or fourth type of micro-bumps, micro-pillars or micro-pads 34 of one of said neighboring two of its semiconductor IC chips 200, 250, 269a, 269b, 251, 270, 402 and 411 and first, second and third types of subsystem units 401, 403 and 404 for the second alternative, or one of the first, second, third or fourth type of micro-bumps, micro-pillars or micro-pads 34 of one of said neighboring two of its semiconductor IC chips 200, 250, 255, 269a, 269b, 269c, 251 and 411 for the fifth alternative, (2) one of the first type of micro-bumps, micro-pillars or micro-pads 34 of one of the fine-line interconnection bridges (FIBs) 690, or DFPIC or eFPIC chips 400, of its first type of interconnection substrate 177 vertically under said neighboring two of its semiconductor IC chips 200, 250, 269a, 269b, 269c, 251 and 411 for the first alternative, or said neighboring two of its semiconductor IC chips 200, 250, 269a, 269b, 251, 270, 402 and 411 and first, second and third types of subsystem units 401, 403 and 404 for the second alternative, or said neighboring two of its semiconductor IC chips 200, 250, 255, 269a, 269b, 269c, 251 and 411 for the fifth alternative, (3) one of the metal lines or traces 693 of said one of the fine-line interconnection bridges (FIBs) 690, or DFPIC or eFPIC chips 400, of its first type of interconnection substrate 177, (4) another of the first type of micro-bumps, micro-pillars or micro-pads 34 of said one of the fine-line interconnection bridges (FIBs) 690, or DFPIC or eFPIC chips 400, of its first type of interconnection substrate 177 and (5) one of the first, second, third or fourth type of micro-bumps, micro-pillars or micro-pads 34 of the other of said neighboring two of its semiconductor IC chips 200, 250, 269a, 269b, 269c, 251 and 411 for the first alternative, or one of the first, second, third or fourth type of micro-bumps, micro-pillars or micro-pads 34 of the other of said neighboring two of its semiconductor IC chips 200, 250, 269a, 269b, 251, 270, 402 and 411 and first, second and third types of subsystem units 401, 403 and 404 for the second alternative, or one of the first, second, third or fourth type of micro-bumps, micro-pillars or micro-pads 34 of the other of said neighboring two of its semiconductor IC chips 200, 250, 255, 269a, 269b, 269c, 251 and 411 for the fifth alternative, or through, in sequence in case for its second type of interconnection substrate 177 as seen in FIG. 9C, (1) one of the first, second, third or fourth type of micro-bumps, micro-pillars or micro-pads 34 of one of said neighboring two of its semiconductor IC chips 200, 250, 269a, 269b, 269c, 251 and 411 for the first alternative, or one of the first, second, third or fourth type of micro-bumps, micro-pillars or micro-pads 34 of one of said neighboring two of its semiconductor IC chips 200, 250, 269a, 269b, 251, 270, 402 and 411 and first, second and third types of subsystem units 401, 403 and 404 for the second alternative, or one of the first, second, third or fourth type of micro-bumps, micro-pillars or micro-pads 34 of one of said neighboring two of its semiconductor IC chips 200, 250, 255, 269a, 269b, 269c, 251 and 411 for the fifth alternative, (2) each of the interconnection metal layers 27 of the interconnection scheme 80 of its second type of interconnection substrate 177, (3) one of the first type of micro-bumps, micro-pillars or micro-pads 34 of one of the fine-line interconnection bridges (FIBs) 690, or DFPIC or eFPIC chips 400, of its second type of interconnection substrate 177 vertically under said neighboring two of its semiconductor IC chips 200, 250, 269a, 269b, 269c, 251 and 411 for the first alternative, or said neighboring two of its semiconductor IC chips 200, 250, 269a, 269b, 251, 270, 402 and 411 and first, second and third types of subsystem units 401, 403 and 404 for the second alternative, or said neighboring two of its semiconductor IC chips 200, 250, 255, 269a, 269b, 269c, 251 and 411 for the fifth alternative, (4) one of the metal lines or traces 693 of said one of the fine-line interconnection bridges (FIBs) 690, or DFPIC or eFPIC chips 400, of its second type of interconnection substrate 177, (5) another of the first type of micro-bumps, micro-pillars or micro-pads 34 of said one of the fine-line interconnection bridges (FIBs) 690, or DFPIC or eFPIC chips 400, of its second type of interconnection substrate 177, (6) each of the interconnection metal layers 27 of the interconnection scheme 80 of its second type of interconnection substrate 177 and (7) one of the first, second, third or fourth type of micro-bumps, micro-pillars or micro-pads 34 of the other of said neighboring two of its semiconductor IC chips 200, 250, 269a, 269b, 269c, 251 and 411 for the first alternative, or one of the first, second, third or fourth type of micro-bumps, micro-pillars or micro-pads 34 of the other of said neighboring two of its semiconductor IC chips 200, 250, 269a, 269b, 251, 270, 402 and 411 and first, second and third types of subsystem units 401, 403 and 404 for the second alternative, or one of the first, second, third or fourth type of micro-bumps, micro-pillars or micro-pads 34 of the other of said neighboring two of its semiconductor IC chips 200, 250, 250, 269a, 269b, 269c, 251 and 411 for the fifth alternative. The combination selected from the metal lines or traces 693 of the fine-line interconnection bridges (FIBs) 690, or DFPIC or eFPIC chips 400, of its first type of interconnection substrate 177, the through silicon vias (TSVs) 157 of the vertical-through-via (VTV) connectors 467 of its first type of interconnection substrate 177 and the interconnection metal layers 27 of the interconnection scheme 79 of its first type of interconnection substrate 177 may be formed for the programmable interconnects 361 and non-programmable interconnects 364 of its inter-chip interconnects 371. Alternatively, the combination selected from the metal lines or traces 693 of the fine-line interconnection bridges (FIBs) 690, or DFPIC or eFPIC chips 400, of its second type of interconnection substrate 177, the through silicon vias (TSVs) 157 of the vertical-through-via (VTV) connectors 467 of its second type of interconnection substrate 177, the interconnection metal layers 27 of the interconnection scheme 80 of its second type of interconnection substrate 177 and the interconnection metal layers 27 of the interconnection scheme 79 of its second type of interconnection substrate 177 may be formed for the programmable interconnects 361 and non-programmable interconnects 364 of its inter-chip interconnects 371.

Alternatively, referring to FIGS. 5A-1, 5A-2, 5A-5 and 9A-9C, for the fourth structure 304 for said each of the first type of FPMCPs 300 for the first, second and fifth alternatives, each of the DFPIC or eFPIC chips 400 of each type of its first and second types of interconnection substrates 177 may be vertically under neighboring two of its semiconductor IC chips 200, 250, 269a, 269b, 269c, 251 and 411 for the first alternative, or neighboring two of its semiconductor IC chips 200, 250, 269a, 269b, 251, 270, 402 and 411 and first, second and third types of subsystem units 401, 403 and 404 for the second alternative, or neighboring two of its semiconductor IC chips 200, 250, 255, 269a, 269b, 269c, 251 and 411 for the fifth alternative, wherein said each of the DFPIC or eFPIC chips 400 of its first or second type of interconnection substrate 177 may couple to a first device of said neighboring two of its semiconductor IC chips 200, 250, 269a, 269b, 269c, 251 and 411 for the first alternative, or said neighboring two of its semiconductor IC chips 200, 250, 269a, 269b, 251, 270, 402 and 411 and first, second and third types of subsystem units 401, 403 and 404 for the second alternative, or said neighboring two of its semiconductor IC chips 200, 250, 255, 269a, 269b, 269c, 251 and 411 for the fifth alternative, through, in sequence, a first group of the first type of micro-bumps, micro-pillars or micro-pads 34 of said each of the DFPIC or eFPIC chips 400 of its first type of interconnection substrate 177 under the first device and the first, second, third or fourth type of micro-bumps, micro-pillars or micro-pads 34 of the first device, or through, in sequence, a first group of the first type of micro-bumps, micro-pillars or micro-pads 34 of said each of the DFPIC or eFPIC chips 400 of its second type of interconnection substrate 177 under the first device, each of the interconnection metal layers 27 of the interconnection scheme 80 of its second type of interconnection substrate 177 and the first, second, third or fourth type of micro-bumps, micro-pillars or micro-pads 34 of the first device, and couple to a second device of said neighboring two of its semiconductor IC chips 200, 250, 269a, 269b, 269c, 251 and 411 for the first alternative, or said neighboring two of its semiconductor IC chips 200, 250, 269a, 269b, 251, 270, 402 and 411 and first, second and third types of subsystem units 401, 403 and 404 for the second alternative, or said neighboring two of its semiconductor IC chips 200, 250, 255, 269a, 269b, 269c, 251 and 411 for the fifth alternative, through, in sequence, a second group of the first type of micro-bumps, micro-pillars or micro-pads 34 of said each of the DFPIC or eFPIC chips 400 of its first type of interconnection substrate 177 under the second device and the first, second, third or fourth type of micro-bumps, micro-pillars or micro-pads 34 of the second device, or through, in sequence, a second group of the first type of micro-bumps, micro-pillars or micro-pads 34 of said each of the DFPIC or eFPIC chips 400 of its second type of interconnection substrate 177 under the second device, each of the interconnection metal layers 27 of the interconnection scheme 80 of its second type of interconnection substrate 177 and the first, second, third or fourth type of micro-bumps, micro-pillars or micro-pads 34 of the second device, wherein for the first or fifth alternative the first device may be its CPU IC chip 269b and the second device may be its FPGA IC chip 200 horizontally neighboring to its CPU IC chip 269b as seen in FIGS. 5A-1 and 5A-5, for example; for the first or fifth alternative the first device may be its GPU IC chip 269a and the second device may be its auxiliary IC chip 411 horizontally neighboring to its GPU IC chip 269a as seen in FIGS. 5A-1 and 5A-5, for example; for the first or fifth alternative the first device may be its GPU IC chip 269a and the second device may be its FPGA IC chip 200 horizontally neighboring to its GPU IC chip 269a as seen in FIGS. 5A-1 and 5A-5, for example; for the first or fifth alternative the first device may be its GPU IC chip 269a and the second device may be its application-specific integrated-circuit (ASIC) chip or system-on-chip (SoC) chip 269c horizontally neighboring to its GPU IC chip 269a as seen in FIGS. 5A-1 and 5A-5, for example, or wherein for the second alternative the first device may be its CPU IC chip 269b and the second device may be its GPU IC chip 269a horizontally neighboring to its CPU IC chip 269b as seen in FIG. 5A-2, for example. Said each of the DFPIC or eFPIC chips 400 may include (1) the first type of field programmable logic cell or element (LCE) 2014 or 2014-2 as illustrated in FIGS. 1A, 4D and 4E, the data inputs A0 and A1 of which may couple to the first device through, in sequence, respective two of the small input/output (SIO) circuits 203, or metal pads or input/output (I/O) pads, of said each of the DFPIC or eFPIC chips 400 of its first type of interconnection substrate 177, respective two of the first group of the first type of micro-bumps, micro-pillars or micro-pads 34 of said each of the DFPIC or eFPIC chips 400 of its first type of interconnection substrate 177 and respective two of the first, second, third or fourth type of micro-bumps, micro-pillars or micro-pads 34 of the first device, or through, in sequence, respective two of the small input/output (SIO) circuits 203, or metal pads or input/output (I/O) pads, of said each of the DFPIC or eFPIC chips 400 of its second type of interconnection substrate 177, respective two of the first group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and respective two of the first, second, third or fourth type of micro-bumps, micro-pillars or micro-pads 34 of the first device, and the data output Dout of which may couple to the second device through, in sequence, another of the small input/output (SIO) circuits 203, or metal pads or input/output (I/O) pads, of said each of the DFPIC or eFPIC chips 400 of its first type of interconnection substrate 177, one of the second group of the first type of micro-bumps, micro-pillars or micro-pads 34 of said each of the DFPIC or eFPIC chips 400 of its first type of interconnection substrate 177 and one of the first, second, third or fourth type of micro-bumps, micro-pillars or micro-pads 34 of the second device, or through, in sequence, another of the small input/output (SIO) circuits 203, or metal pads or input/output (I/O) pads, of said each of the DFPIC or eFPIC chips 400 of its second type of interconnection substrate 177, one of the second group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and one of the first, second, third or fourth type of micro-bumps, micro-pillars or micro-pads 34 of the second device, (2) the second or third type of field programmable logic cell or element (LCE) 2014 or 2014-2 as illustrated in FIGS. 1B, 1C, 4D and 4E, the data inputs A0-A3 of which may couple to the first device through, in sequence, respective four of the small input/output (SIO) circuits 203, or metal pads or input/output (I/O) pads, of said each of the DFPIC or eFPIC chips 400 of its first type of interconnection substrate 177, respective four of the first group of the first type of micro-bumps, micro-pillars or micro-pads 34 of said each of the DFPIC or eFPIC chips 400 of its first type of interconnection substrate 177 and respective four of the first, second, third or fourth type of micro-bumps, micro-pillars or micro-pads 34 of the first device, or through, in sequence, respective four of the small input/output (SIO) circuits 203, or metal pads or input/output (I/O) pads, of said each of the DFPIC or eFPIC chips 400 of its second type of interconnection substrate 177, respective four of the first group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and respective four of the first, second, third or fourth type of micro-bumps, micro-pillars or micro-pads 34 of the first device, and the data output Dout of which may couple to the second device through, in sequence, another of the small input/output (SIO) circuits 203, or metal pads or input/output (I/O) pads, of said each of the DFPIC or eFPIC chips 400 of its first type of interconnection substrate 177, one of the second group of the first type of micro-bumps, micro-pillars or micro-pads 34 of said each of the DFPIC or eFPIC chips 400 of its first type of interconnection substrate 177 and one of the first, second, third or fourth type of micro-bumps, micro-pillars or micro-pads 34 of the second device, or through, in sequence, another of the small input/output (SIO) circuits 203, or metal pads or input/output (I/O) pads, of said each of the DFPIC or eFPIC chips 400 of its second type of interconnection substrate 177, one of the second group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and one of the first, second, third or fourth type of micro-bumps, micro-pillars or micro-pads 34 of the second device, (3) the first type of field programmable switch cell 379 or 379-2 as illustrated in FIGS. 2A, 4D and 4E, the node N21 of which may couple to the first device through, in sequence, one of the small input/output (SIO) circuits 203, or metal pads or input/output (I/O) pads, of said each of the DFPIC or eFPIC chips 400 of its first type of interconnection substrate 177, one of the first group of the first type of micro-bumps, micro-pillars or micro-pads 34 of said each of the DFPIC or eFPIC chips 400 of its first type of interconnection substrate 177 and one of the first, second, third or fourth type of micro-bumps, micro-pillars or micro-pads 34 of the first device, or through, in sequence, one of the small input/output (SIO) circuits 203, or metal pads or input/output (I/O) pads, of said each of the DFPIC or eFPIC chips 400 of its second type of interconnection substrate 177, one of the first group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and one of the first, second, third or fourth type of micro-bumps, micro-pillars or micro-pads 34 of the first device, and the node N22 of which may couple to the second device through, in sequence, another of the small input/output (SIO) circuits 203, or metal pads or input/output (I/O) pads, of said each of the DFPIC or eFPIC chips 400 of its first type of interconnection substrate 177, one of the second group of the first type of micro-bumps, micro-pillars or micro-pads 34 of said each of the DFPIC or eFPIC chips 400 of its first type of interconnection substrate 177 and one of the first, second, third or fourth type of micro-bumps, micro-pillars or micro-pads 34 of the second device, or through, in sequence, another of the small input/output (SIO) circuits 203, or metal pads or input/output (I/O) pads, of said each of the DFPIC or eFPIC chips 400 of its second type of interconnection substrate 177, one of the second group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and one of the first, second, third or fourth type of micro-bumps, micro-pillars or micro-pads 34 of the second device, to control coupling between the first and second devices, (4) the second type of field programmable switch cell 379 or 379-2 as illustrated in FIGS. 2B, 4D and 4E, the nodes N23 and N24 of which may couple to the first device through, in sequence, respective two of the small input/output (SIO) circuits 203, or metal pads or input/output (I/O) pads, of said each of the DFPIC or eFPIC chips 400 of its first type of interconnection substrate 177, respective two of the first group of the first type of micro-bumps, micro-pillars or micro-pads 34 of said each of the DFPIC or eFPIC chips 400 of its first type of interconnection substrate 177 and respective two of the first, second, third or fourth type of micro-bumps, micro-pillars or micro-pads 34 of the first device, or through, in sequence, respective two of the small input/output (SIO) circuits 203, or metal pads or input/output (I/O) pads, of said each of the DFPIC or eFPIC chips 400 of its second type of interconnection substrate 177, respective two of the first group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and respective two of the first, second, third or fourth type of micro-bumps, micro-pillars or micro-pads 34 of the first device, and the nodes N25 and N26 of which may couple to the second device through, in sequence, another respective two of the small input/output (SIO) circuits 203, or metal pads or input/output (I/O) pads, of said each of the DFPIC or eFPIC chips 400 of its first type of interconnection substrate 177, respective two of the second group of the first type of micro-bumps, micro-pillars or micro-pads 34 of said each of the DFPIC or eFPIC chips 400 of its first type of interconnection substrate 177 and respective two of the first, second, third or fourth type of micro-bumps, micro-pillars or micro-pads 34 of the second device, or through, in sequence, another respective two of the small input/output (SIO) circuits 203, or metal pads or input/output (I/O) pads, of said each of the DFPIC or eFPIC chips 400 of its second type of interconnection substrate 177, respective two of the second group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and respective two of the first, second, third or fourth type of micro-bumps, micro-pillars or micro-pads 34 of the second device, to control coupling from the node N23 to one or more of the nodes N24-N26 or to control coupling from the node N26 to one or more of the nodes N23-N25, (5) the field programmable switch matrix 710 or 710-3 as illustrated in FIGS. 2C, 4D and 4E, each of the nodes P₁-P_{N} of which may couple to the first device through, in sequence, one of the first metal lines 281 of said each of the DFPIC or eFPIC chips 400 of its first type of interconnection substrate 177, one of the small input/output (SIO) circuits 203, or metal pads or input/output (I/O) pads, of said each of the DFPIC or eFPIC chips 400 of its first type of interconnection substrate 177, one of the first group of the first type of micro-bumps, micro-pillars or micro-pads 34 of said each of the DFPIC or eFPIC chips 400 of its first type of interconnection substrate 177 and one of the first, second, third or fourth type of micro-bumps, micro-pillars or micro-pads 34 of the first device, or through, in sequence, one of the first metal lines 281 of said each of the DFPIC or eFPIC chips 400 of its second type of interconnection substrate 177, one of the small input/output (SIO) circuits 203, or metal pads or input/output (I/O) pads, of said each of the DFPIC or eFPIC chips 400 of its second type of interconnection substrate 177, one of the first group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and one of the first, second, third or fourth type of micro-bumps, micro-pillars or micro-pads 34 of the first device, each of the nodes Q₁-Q_{M} of which may couple to the second device through, in sequence, one of the second metal lines 282 of said each of the DFPIC or eFPIC chips 400 of its first type of interconnection substrate 177, another of the small input/output (SIO) circuits 203, or metal pads or input/output (I/O) pads, of said each of the DFPIC or eFPIC chips 400 of its first type of interconnection substrate 177, one of the second group of the first type of micro-bumps, micro-pillars or micro-pads 34 of said each of the DFPIC or eFPIC chips 400 of its first type of interconnection substrate 177 and one of the first, second, third or fourth type of micro-bumps, micro-pillars or micro-pads 34 of the second device, or through, in sequence, one of the second metal lines 282 of said each of the DFPIC or eFPIC chips 400 of its second type of interconnection substrate 177, another of the small input/output (SIO) circuits 203, or metal pads or input/output (I/O) pads, of said each of the DFPIC or eFPIC chips 400 of its second type of interconnection substrate 177, one of the second group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and one of the first, second, third or fourth type of micro-bumps, micro-pillars or micro-pads 34 of the second device, and each of the pass/no-pass switches 778 of which may control coupling between the first and second devices, i.e., between one of the first group of the first type of micro-bumps, micro-pillars or micro-pads 34 of said each of the DFPIC or eFPIC chips 400 of its first or second type of interconnection substrate 177 and one of the second group of the first type of micro-bumps, micro-pillars or micro-pads 34 of said each of the DFPIC or eFPIC chips 400 of its first or second type of interconnection substrate 177, and/or (6) the field programmable switch matrix 710-2 as illustrated in FIGS. 2C and 4E, each of some of the nodes P₁-P_{N} of which may couple to the first device through, in sequence, one of the first metal lines 281 of said each of the DFPIC or eFPIC chips 400 of its first type of interconnection substrate 177, one of the small input/output (SIO) circuits 203, or metal pads or input/output (I/O) pads, of said each of the DFPIC or eFPIC chips 400 of its first type of interconnection substrate 177, one of the first group of the first type of micro-bumps, micro-pillars or micro-pads 34 of said each of the DFPIC or eFPIC chips 400 of its first type of interconnection substrate 177 and one of the first, second, third or fourth type of micro-bumps, micro-pillars or micro-pads 34 of the first device, or through, in sequence, one of the first metal lines 281 of said each of the DFPIC or eFPIC chips 400 of its second type of interconnection substrate 177, one of the small input/output (SIO) circuits 203, or metal pads or input/output (I/O) pads, of said each of the DFPIC or eFPIC chips 400 of its second type of interconnection substrate 177, one of the first group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and one of the first, second, third or fourth type of micro-bumps, micro-pillars or micro-pads 34 of the first device, each of the other some of the nodes P₁-P_{N} of which may couple to the second device through, in sequence, another of the first metal lines 281 of said each of the DFPIC or eFPIC chips 400 of its first type of interconnection substrate 177, another of the small input/output (SIO) circuits 203, or metal pads or input/output (I/O) pads, of said each of the DFPIC or eFPIC chips 400 of its first type of interconnection substrate 177, one of the second group of the first type of micro-bumps, micro-pillars or micro-pads 34 of said each of the DFPIC or eFPIC chips 400 of its first type of interconnection substrate 177 and one of the first, second, third or fourth type of micro-bumps, micro-pillars or micro-pads 34 of the second device, or through, in sequence, another of the first metal lines 281 of said each of the DFPIC or eFPIC chips 400 of its second type of interconnection substrate 177, another of the small input/output (SIO) circuits 203, or metal pads or input/output (I/O) pads, of said each of the DFPIC or eFPIC chips 400 of its second type of interconnection substrate 177, one of the second group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and one of the first, second, third or fourth type of micro-bumps, micro-pillars or micro-pads 34 of the second device, and each of the pass/no-pass switches 778 of which may control coupling between one of the first and second devices and one of the internal circuits of the fourth one of the ASIC cores 215 of said each of the DFPIC or eFPIC chips 400 of its first or second type of interconnection substrate 177, i.e., between one of the first and second groups of the first type of micro-bumps, micro-pillars or micro-pads 34 of said each of the DFPIC or eFPIC chips 400 of its first or second type of interconnection substrate 177 and one of the internal circuits of the fourth one of the ASIC cores 215 of said each of the DFPIC or eFPIC chips 400 of its first or second type of interconnection substrate 177.

Referring to FIGS. 5A-1, 5A-2, 5A-5 and 9A-9C, the fourth structure 304 for said each of the first type of FPMCPs 300 for the first, second and fifth alternatives may further include an underfill 564, i.e., polymer layer, between each of its semiconductor IC chips 200, 250, 269a, 269b, 269c, 251 and 411 for the first alternative, or each of its semiconductor IC chips 200, 250, 269a, 269b, 251, 270, 402 and 411 and first, second and third types of subsystem units 401, 403 and 404 for the second alternative, or each of its semiconductor IC chips 200, 250, 255, 269a, 269b, 269c, 251 and 411 for the fifth alternative, and its first or second type of interconnection substrate 177, covering a sidewall of each of the first, second, third or fourth type of micro-bumps, micro-pillars or micro-pads 34 of each of its semiconductor IC chips 200, 250, 269a, 269b, 269c, 251 and 411 for the first alternative, or a sidewall of each of the first, second, third or fourth type of micro-bumps, micro-pillars or micro-pads 34 of each of its semiconductor IC chips 200, 250, 269a, 269b, 251, 270, 402 and 411 and first, second and third types of subsystem units 401, 403 and 404 for the second alternative, or a sidewall of each of the first, second, third or fourth type of micro-bumps, micro-pillars or micro-pads 34 of each of its semiconductor IC chips 200, 250, 255, 269a, 269b, 269c, 251 and 411 for the fifth alternative. Its polymer layer 192 may be formed on a top surface of its first or second type of interconnection substrate 177 and horizontally around each of its semiconductor IC chips 200, 250, 269a, 269b, 269c, 251 and 411 for the first alternative, or each of its semiconductor IC chips 200, 250, 269a, 269b, 251, 270, 402 and 411 and first, second and third types of subsystem units 401, 403 and 404 for the second alternative, or a top surface of its first or second type of interconnection substrate 177 and horizontally around each of its semiconductor IC chips 200, 250, 255, 269a, 269b, 269c, 251 and 411 for the fifth alternative. Its polymer layer 192 may have a vertical sidewall coplanar with a vertical sidewall of its first or second type of interconnection substrate 177. The fourth structure 304 for said each of the first type of FPMCPs 300 for the first, second and fifth alternatives may further include multiple metal bumps, pillars or pads 570 in an array at its bottom to act as its external pins for coupling to the external circuits 340 as seen in FIG. 5D-5G or 5K outside of the fourth structure 304 for said each of the first type of field-programmable multi-chip packages 300 for the first, second and fifth alternatives, wherein each of its metal bumps, pillars or pads 570 may be of a type selected from various types, i.e., first and second types, having the same specification as that of the first and second types of metal bumps, pillars or pads 570 respectively as illustrated in FIG. 6A, and may have the adhesion metal layer 26a on a bottom surface of one of the metal pads of the bottommost one of the interconnection metal layers 27 of the interconnection scheme 79 of its first or second type of interconnection substrate 177 and a bottom surface of the bottommost one of the polymer layers 42 of the interconnection scheme 79 of its first or second type of interconnection substrate 177. Each of its semiconductor IC chips 200, 250, 269a, 269b, 269c, 251 and 411 for the first alternative, or each of its semiconductor IC chips 200, 250, 269a, 269b, 251, 270, 402 and 411 and first, second and third types of subsystem units 401, 403 and 404 for the second alternative, or each of its semiconductor IC chips 200, 250, 255, 269a, 269b, 269c, 251 and 411 for the fifth alternative, may couple to one of its metal bumps, pillars or pads 570 for external connection through, in sequence, any of the through silicon vias (TSVs) 157 of any of the vertical-through-via (VTV) connectors 467 of its first type of interconnection substrate 177 and each of the interconnection metal layers 27 of the interconnection scheme 79 of its first type of interconnection substrate 177, or through, in sequence, each of the interconnection metal layers 27 of the interconnection scheme 80 of its second type of interconnection substrate 177, any of the through silicon vias (TSVs) 157 of any of the vertical-through-via (VTV) connectors 467 of its second type of interconnection substrate 177 and each of the interconnection metal layers 27 of the interconnection scheme 79 of its second type of interconnection substrate 177.

Referring to FIGS. 5A-3, 5A-4 and 9D, for the fourth structure 304 for each of the first type of FPMCPs 300 for the third and fourth alternatives, each of its semiconductor IC chips 601, 269a, 269b, 269c, 260, 602 and 603 for the third alternative, or each of its semiconductor IC chips 601, 269a, 269b, 269c, 270, 260, 602 and 603 for the fourth alternative, may have the same specification as the first type of semiconductor IC chip 100 illustrated in FIG. 3A to be turned upside down. Each of its semiconductor IC chips 601, 269a, 269b, 269c, 260, 602 and 603 for the third alternative, or each of its semiconductor IC chips 601, 269a, 269b, 269c, 270, 260, 602 and 603 for the fourth alternative, may have the first, second, third or fourth type of micro-bumps, micro-pillars or micro-pads 34 each bonded to (1) one of the first type of micro-bumps, micro-pillars or micro-pads 34 of one of the fine-line interconnection bridges (FIBs) 690, or DFPIC or eFPIC chips 400, and vertical-through-via (VTV) connectors 467 of its first type of interconnection substrate 177 as seen in FIG. 9D, or (2) one of the metal pads of the topmost one of the interconnection metal layers 27 of the interconnection scheme 80 of its second type of interconnection substrate 177 as seen in FIG. 9C. Accordingly, neighboring two of its semiconductor IC chips 601, 269a, 269b, 269c, 260, 602 and 603 for the third alternative, or neighboring two of its semiconductor IC chips 601, 269a, 269b, 269c, 270, 260, 602 and 603 for the fourth alternative, may couple to each other through, in sequence in case for its first type of interconnection substrate 177 as seen in FIG. 9D, (1) one of the first, second, third or fourth type of micro-bumps, micro-pillars or micro-pads 34 of one of said neighboring two of its semiconductor IC chips 601, 269a, 269b, 269c, 260, 602 and 603 for the third alternative, or one of the first, second, third or fourth type of micro-bumps, micro-pillars or micro-pads 34 of one of said neighboring two of its semiconductor IC chips 601, 269a, 269b, 269c, 270, 260, 602 and 603 for the fourth alternative, (2) one of the first type of micro-bumps, micro-pillars or micro-pads 34 of one of the fine-line interconnection bridges (FIBs) 690, or DFPIC or eFPIC chips 400, of its first type of interconnection substrate 177 vertically under said neighboring two of its semiconductor IC chips 601, 269a, 269b, 269c, 260, 602 and 603 for the third alternative, or said neighboring two of its semiconductor IC chips 601, 269a, 269b, 269c, 270, 260, 602 and 603 for the fourth alternative, (3) one of the metal lines or traces 693 of said one of the fine-line interconnection bridges (FIBs) 690, or DFPIC or eFPIC chips 400, of its first type of interconnection substrate 177, (4) another of the first type of micro-bumps, micro-pillars or micro-pads 34 of said one of the fine-line interconnection bridges (FIBs) 690, or DFPIC or eFPIC chips 400, of its first type of interconnection substrate 177 and (5) one of the first, second, third or fourth type of micro-bumps, micro-pillars or micro-pads 34 of the other of said neighboring two of its semiconductor IC chips 601, 269a, 269b, 269c, 260, 602 and 603 for the third alternative, or one of the first, second, third or fourth type of micro-bumps, micro-pillars or micro-pads 34 of the other of said neighboring two of its semiconductor IC chips 601, 269a, 269b, 269c, 270, 260, 602 and 603 for the fourth alternative, or through, in sequence in case for its second type of interconnection substrate 177 as seen in FIG. 9C, (1) one of the first, second, third or fourth type of micro-bumps, micro-pillars or micro-pads 34 of one of said neighboring two of its semiconductor IC chips 601, 269a, 269b, 269c, 260, 602 and 603 for the third alternative, or one of the first, second, third or fourth type of micro-bumps, micro-pillars or micro-pads 34 of one of said neighboring two of its semiconductor IC chips 601, 269a, 269b, 269c, 270, 260, 602 and 603 for the fourth alternative, (2) each of the interconnection metal layers 27 of the interconnection scheme 80 of its second type of interconnection substrate 177, (3) one of the first type of micro-bumps, micro-pillars or micro-pads 34 of one of the fine-line interconnection bridges (FIBs) 690, or DFPIC or eFPIC chips 400, of its second type of interconnection substrate 177 vertically under said neighboring two of its semiconductor IC chips 601, 269a, 269b, 269c, 260, 602 and 603 for the third alternative, or said neighboring two of its semiconductor IC chips 601, 269a, 269b, 269c, 270, 260, 602 and 603 for the fourth alternative, (4) one of the metal lines or traces 693 of said one of the fine-line interconnection bridges (FIBs) 690, or DFPIC or eFPIC chips 400, of its second type of interconnection substrate 177, (5) another of the first type of micro-bumps, micro-pillars or micro-pads 34 of said one of the fine-line interconnection bridges (FIBs) 690, or DFPIC or eFPIC chips 400, of its second type of interconnection substrate 177, (6) each of the interconnection metal layers 27 of the interconnection scheme 80 of its second type of interconnection substrate 177 and (7) one of the first, second, third or fourth type of micro-bumps, micro-pillars or micro-pads 34 of the other of said neighboring two of its semiconductor IC chips 601, 269a, 269b, 269c, 260, 602 and 603 for the third alternative, or one of the first, second, third or fourth type of micro-bumps, micro-pillars or micro-pads 34 of the other of said neighboring two of its semiconductor IC chips 601, 269a, 269b, 269c, 270, 260, 602 and 603 for the fourth alternative. The combination selected from the metal lines or traces 693 of the fine-line interconnection bridges (FIBs) 690, or DFPIC or eFPIC chips 400, of its first type of interconnection substrate 177, the through silicon vias (TSVs) 157 of the vertical-through-via (VTV) connectors 467 of its first type of interconnection substrate 177 and the interconnection metal layers 27 of the interconnection scheme 79 of its first type of interconnection substrate 177 may be formed for the programmable interconnects 361 and non-programmable interconnects 364 of its inter-chip interconnects 371. Alternatively, the combination selected from the metal lines or traces 693 of the fine-line interconnection bridges (FIBs) 690, or DFPIC or eFPIC chips 400, of its second type of interconnection substrate 177, the through silicon vias (TSVs) 157 of the vertical-through-via (VTV) connectors 467 of its second type of interconnection substrate 177, the interconnection metal layers 27 of the interconnection scheme 80 of its second type of interconnection substrate 177 and the interconnection metal layers 27 of the interconnection scheme 79 of its second type of interconnection substrate 177 may be formed for the programmable interconnects 361 and non-programmable interconnects 364 of its inter-chip interconnects 371.

Further, referring to FIGS. 5A-3, 5A-4 and 9D, for the fourth structure 304 for each of the first type of FPMCPs 300 for the third and fourth alternatives, its FPGA/NVM multi-chip package 259 for a first scenario may be any type of the second through eighth types and twelfth through fourteenth types of FPMCPs 305-311 and 315-317 as seen in FIGS. 10, 11, 12, 13A, 13B, 14, 15A, 15B, 16, 20, 21 and 22 and the seventeenth type of FPMCPs 320 for the first through third alternatives as seen in FIGS. 25A-25C with the metal bumps, pillars or pads 570 at the bottom thereof each bonded to (1) one of the first type of micro-bumps, micro-pillars or micro-pads 34 of one of the fine-line interconnection bridges (FIBs) 690, or DFPIC or eFPIC chips 400, and vertical-through-via (VTV) connectors 467 of its first type of interconnection substrate 177 as seen in FIG. 9D, or (2) one of the metal pads of the topmost one of the interconnection metal layers 27 of the interconnection scheme 80 of its second type of interconnection substrate 177 as seen in FIG. 9C. Accordingly, for the first scenario, its FPGA/NVM multi-chip package 259 may couple to one of its semiconductor IC chips 269a, 269b, 269c and 602 for the third alternative neighboring to its FPGA/NVM multi-chip package 259, or one of its semiconductor IC chips 269a, 269b, 269c and 270 for the fourth alternative neighboring to its FPGA/NVM multi-chip package 259, through, in sequence in case for its first type of interconnection substrate 177 as seen in FIG. 9D, (1) one of the metal bumps, pillars or pads 570 of its FPGA/NVM multi-chip package 259, (2) one of the first type of micro-bumps, micro-pillars or micro-pads 34 of one of the fine-line interconnection bridges (FIBs) 690, or DFPIC or eFPIC chips 400, of its first type of interconnection substrate 177 vertically under its FPGA/NVM multi-chip package 259, (3) one of the metal lines or traces 693 of said one of the fine-line interconnection bridges (FIBs) 690, or DFPIC or eFPIC chips 400, of its first type of interconnection substrate 177, (4) another of the first type of micro-bumps, micro-pillars or micro-pads 34 of said one of the fine-line interconnection bridges (FIBs) 690, or DFPIC or eFPIC chips 400, of its first type of interconnection substrate 177 vertically under said one of its semiconductor IC chips 269a, 269b, 269c and 602 for the third alternative, or said one of its semiconductor IC chips 269a, 269b, 269c and 270 for the fourth alternative, and (5) one of the first, second, third or fourth type of micro-bumps, micro-pillars or micro-pads 34 of said one of its semiconductor IC chips 269a, 269b, 269c and 602 for the third alternative, or one of the first, second, third or fourth type of micro-bumps, micro-pillars or micro-pads 34 of said one of its semiconductor IC chips 269a, 269b, 269c and 270 for the fourth alternative, or through, in sequence in case for its second type of interconnection substrate 177 as seen in FIG. 9C, (1) one of the metal bumps, pillars or pads 570 of its FPGA/NVM multi-chip package 259, (2) each of the interconnection metal layers 27 of the interconnection scheme 80 of its second type of interconnection substrate 177, (3) one of the first type of micro-bumps, micro-pillars or micro-pads 34 of one of the fine-line interconnection bridges (FIBs) 690, or DFPIC or eFPIC chips 400, of its second type of interconnection substrate 177 vertically under its FPGA/NVM multi-chip package 259, (4) one of the metal lines or traces 693 of said one of the fine-line interconnection bridges (FIBs) 690, or DFPIC or eFPIC chips 400, of its second type of interconnection substrate 177, (5) another of the first type of micro-bumps, micro-pillars or micro-pads 34 of said one of the fine-line interconnection bridges (FIBs) 690, or DFPIC or eFPIC chips 400, of its second type of interconnection substrate 177 vertically under said one of its semiconductor IC chips 269a, 269b, 269c and 602 for the third alternative, or said one of its semiconductor IC chips 269a, 269b, 269c and 270 for the fourth alternative, (6) each of the interconnection metal layers 27 of the interconnection scheme 80 of its second type of interconnection substrate 177 and (7) one of the first, second, third or fourth type of micro-bumps, micro-pillars or micro-pads 34 of said one of its semiconductor IC chips 269a, 269b, 269c and 602 for the third alternative, or one of the first, second, third or fourth type of micro-bumps, micro-pillars or micro-pads 34 of said one of its semiconductor IC chips 269a, 269b, 269c and 270 for the fourth alternative.

Alternatively, referring to FIGS. 5A-3, 5A-4 and 9D, for the fourth structure 304 for each of the first type of FPMCPs 300 for the third and fourth alternatives, its FPGA/NVM multi-chip package 259 for a second scenario may be the ninth type of FPMCP 312 as seen in FIG. 17 with the metal bumps, pillars or pads 571 at the bottom thereof each bonded to (1) one of the first type of micro-bumps, micro-pillars or micro-pads 34 of one of the fine-line interconnection bridges (FIBs) 690, or DFPIC or eFPIC chips 400, and vertical-through-via (VTV) connectors 467 of its first type of interconnection substrate 177 as seen in FIG. 9D, or (2) one of the metal pads of the topmost one of the interconnection metal layers 27 of the interconnection scheme 80 of its second type of interconnection substrate 177 as seen in FIG. 9C. Accordingly, for the second scenario, its FPGA/NVM multi-chip package 259 may couple to one of its semiconductor IC chips 269a, 269b, 269c and 602 for the third alternative neighboring to its FPGA/NVM multi-chip package 259, or one of its semiconductor IC chips 269a, 269b, 269c and 270 for the fourth alternative neighboring to its FPGA/NVM multi-chip package 259, through, in sequence in case for its first type of interconnection substrate 177 as seen in FIG. 9D, (1) one of the metal bumps, pillars or pads 571 of its FPGA/NVM multi-chip package 259, (2) one of the first type of micro-bumps, micro-pillars or micro-pads 34 of one of the fine-line interconnection bridges (FIBs) 690, or DFPIC or eFPIC chips 400, of its first type of interconnection substrate 177 vertically under its FPGA/NVM multi-chip package 259, (3) one of the metal lines or traces 693 of said one of the fine-line interconnection bridges (FIBs) 690, or DFPIC or eFPIC chips 400, of its first type of interconnection substrate 177, (4) another of the first type of micro-bumps, micro-pillars or micro-pads 34 of said one of the fine-line interconnection bridges (FIBs) 690, or DFPIC or eFPIC chips 400, of its first type of interconnection substrate 177 vertically under said one of its semiconductor IC chips 269a, 269b, 269c and 602 for the third alternative, or said one of its semiconductor IC chips 269a, 269b, 269c and 270 for the fourth alternative, and (5) one of the first, second, third or fourth type of micro-bumps, micro-pillars or micro-pads 34 of said one of its semiconductor IC chips 269a, 269b, 269c and 602 for the third alternative, or one of the first, second, third or fourth type of micro-bumps, micro-pillars or micro-pads 34 of said one of its semiconductor IC chips 269a, 269b, 269c and 270 for the fourth alternative, or through, in sequence in case for its second type of interconnection substrate 177 as seen in FIG. 9C, (1) one of the metal bumps, pillars or pads 571 of its FPGA/NVM multi-chip package 259, (2) each of the interconnection metal layers 27 of the interconnection scheme 80 of its second type of interconnection substrate 177, (3) one of the first type of micro-bumps, micro-pillars or micro-pads 34 of one of the fine-line interconnection bridges (FIBs) 690, or DFPIC or eFPIC chips 400, of its second type of interconnection substrate 177 vertically under its FPGA/NVM multi-chip package 259, (4) one of the metal lines or traces 693 of said one of the fine-line interconnection bridges (FIBs) 690, or DFPIC or eFPIC chips 400, of its second type of interconnection substrate 177, (5) another of the first type of micro-bumps, micro-pillars or micro-pads 34 of said one of the fine-line interconnection bridges (FIBs) 690, or DFPIC or eFPIC chips 400, of its second type of interconnection substrate 177 vertically under said one of its semiconductor IC chips 269a, 269b, 269c and 602 for the third alternative, or said one of its semiconductor IC chips 269a, 269b, 269c and 270 for the fourth alternative, (6) each of the interconnection metal layers 27 of the interconnection scheme 80 of its second type of interconnection substrate 177 and (7) one of the first, second, third or fourth type of micro-bumps, micro-pillars or micro-pads 34 of said one of its semiconductor IC chips 269a, 269b, 269c and 602 for the third alternative, or one of the first, second, third or fourth type of micro-bumps, micro-pillars or micro-pads 34 of said one of its semiconductor IC chips 269a, 269b, 269c and 270 for the fourth alternative.

Alternatively, referring to FIGS. 5A-3, 5A-4 and 9D, for the fourth structure 304 for each of the first type of FPMCPs 300 for the third and fourth alternatives, its FPGA/NVM multi-chip package 259 for a third scenario may be the tenth type of FPMCP 313 as seen in FIG. 18, eleventh type of FPMCP 314 for the first alternative as seen in FIGS. 19 and 19-1, eleventh type of FPMCP 314-1 for the second alternative as seen in FIG. 19-2, eleventh type of FPMCP 314-2 for the third alternative as seen in FIG. 19-3, eleventh type of FPMCP 314-3 for the fourth alternative as seen in FIG. 19-4, eleventh type of FPMCP 314-4 for the fifth alternative as seen in FIG. 19-5, eleventh type of FPMCP 314-5 for the sixth alternative as seen in FIG. 19-6, eleventh type of FPMCP 314-6 for the seventh alternative as seen in FIG. 19-7, eleventh type of FPMCP 314-7 for the eighth alternative as seen in FIG. 19-8, eleventh type of FPMCP 314-8 for the ninth alternative as seen in FIG. 19-9, sixteenth type of FPMCP 319 as seen in FIG. 24 or seventeenth type of FPMCP 320 for second or third alternative as seen in FIG. 25B or 25C with the solder balls 538 at the bottom thereof each bonded to (1) one of the first type of micro-bumps, micro-pillars or micro-pads 34 of one of the fine-line interconnection bridges (FIBs) 690, or DFPIC or eFPIC chips 400, and vertical-through-via (VTV) connectors 467 of its first type of interconnection substrate 177 as seen in FIG. 9D, or (2) one of the metal pads of the topmost one of the interconnection metal layers 27 of the interconnection scheme 80 of its second type of interconnection substrate 177 as seen in FIG. 9C. Accordingly, for the third scenario, its FPGA/NVM multi-chip package 259 may couple to one of its semiconductor IC chips 269a, 269b, 269c and 602 for the third alternative neighboring to its FPGA/NVM multi-chip package 259, or one of its semiconductor IC chips 269a, 269b, 269c and 270 for the fourth alternative neighboring to its FPGA/NVM multi-chip package 259, through, in sequence in case for its first type of interconnection substrate 177 as seen in FIG. 9D, (1) one of the solder balls 538 of its FPGA/NVM multi-chip package 259, (2) one of the first type of micro-bumps, micro-pillars or micro-pads 34 of one of the fine-line interconnection bridges (FIBs) 690, or DFPIC or eFPIC chips 400, of its first type of interconnection substrate 177 vertically under its FPGA/NVM multi-chip package 259, (3) one of the metal lines or traces 693 of said one of the fine-line interconnection bridges (FIBs) 690, or DFPIC or eFPIC chips 400, of its first type of interconnection substrate 177, (4) another of the first type of micro-bumps, micro-pillars or micro-pads 34 of said one of the fine-line interconnection bridges (FIBs) 690, or DFPIC or eFPIC chips 400, of its first type of interconnection substrate 177 vertically under said one of its semiconductor IC chips 269a, 269b, 269c and 602 for the third alternative, or said one of its semiconductor IC chips 269a, 269b, 269c and 270 for the fourth alternative, and (5) one of the first, second, third or fourth type of micro-bumps, micro-pillars or micro-pads 34 of said one of its semiconductor IC chips 269a, 269b, 269c and 602 for the third alternative, or one of the first, second, third or fourth type of micro-bumps, micro-pillars or micro-pads 34 of said one of its semiconductor IC chips 269a, 269b, 269c and 270 for the fourth alternative, or through, in sequence in case for its second type of interconnection substrate 177 as seen in FIG. 9C, (1) one of the solder balls 538 of its FPGA/NVM multi-chip package 259, (2) each of the interconnection metal layers 27 of the interconnection scheme 80 of its second type of interconnection substrate 177, (3) one of the first type of micro-bumps, micro-pillars or micro-pads 34 of one of the fine-line interconnection bridges (FIBs) 690, or DFPIC or eFPIC chips 400, of its second type of interconnection substrate 177 vertically under its FPGA/NVM multi-chip package 259, (4) one of the metal lines or traces 693 of said one of the fine-line interconnection bridges (FIBs) 690, or DFPIC or eFPIC chips 400, of its second type of interconnection substrate 177, (5) another of the first type of micro-bumps, micro-pillars or micro-pads 34 of said one of the fine-line interconnection bridges (FIBs) 690, or DFPIC or eFPIC chips 400, of its second type of interconnection substrate 177 vertically under said one of its semiconductor IC chips 269a, 269b, 269c and 602 for the third alternative, or said one of its semiconductor IC chips 269a, 269b, 269c and 270 for the fourth alternative, (6) each of the interconnection metal layers 27 of the interconnection scheme 80 of its second type of interconnection substrate 177 and (7) one of the first, second, third or fourth type of micro-bumps, micro-pillars or micro-pads 34 of said one of its semiconductor IC chips 269a, 269b, 269c and 602 for the third alternative, or one of the first, second, third or fourth type of micro-bumps, micro-pillars or micro-pads 34 of said one of its semiconductor IC chips 269a, 269b, 269c and 270 for the fourth alternative.

Alternatively, referring to FIGS. 5A-3, 5A-4 and 9D, for the fourth structure 304 for each of the first type of FPMCPs 300 for the third and fourth alternatives, its FPGA/NVM multi-chip package 259 for a fourth scenario may be the fifteenth type of FPMCP 318 as seen in FIG. 23A or 23B with the metal contacts 452 at the bottom thereof each bonded to (1) one of the first type of micro-bumps, micro-pillars or micro-pads 34 of one of the fine-line interconnection bridges (FIBs) 690, or DFPIC or eFPIC chips 400, and vertical-through-via (VTV) connectors 467 of its first type of interconnection substrate 177 as seen in FIG. 9D, or (2) one of the metal pads of the topmost one of the interconnection metal layers 27 of the interconnection scheme 80 of its second type of interconnection substrate 177 as seen in FIG. 9C. Accordingly, for the fourth scenario, its FPGA/NVM multi-chip package 259 may couple to one of its semiconductor IC chips 269a, 269b, 269c and 602 for the third alternative neighboring to its FPGA/NVM multi-chip package 259, or one of its semiconductor IC chips 269a, 269b, 269c and 270 for the fourth alternative neighboring to its FPGA/NVM multi-chip package 259, through, in sequence in case for its first type of interconnection substrate 177 as seen in FIG. 9D, (1) one of the metal contacts 452 of its FPGA/NVM multi-chip package 259, (2) one of the first type of micro-bumps, micro-pillars or micro-pads 34 of one of the fine-line interconnection bridges (FIBs) 690, or DFPIC or eFPIC chips 400, of its first type of interconnection substrate 177 vertically under its FPGA/NVM multi-chip package 259, (3) one of the metal lines or traces 693 of said one of the fine-line interconnection bridges (FIBs) 690, or DFPIC or eFPIC chips 400, of its first type of interconnection substrate 177, (4) another of the first type of micro-bumps, micro-pillars or micro-pads 34 of said one of the fine-line interconnection bridges (FIBs) 690, or DFPIC or eFPIC chips 400, of its first type of interconnection substrate 177 vertically under said one of its semiconductor IC chips 269a, 269b, 269c and 602 for the third alternative, or said one of its semiconductor IC chips 269a, 269b, 269c and 270 for the fourth alternative, and (5) one of the first, second, third or fourth type of micro-bumps, micro-pillars or micro-pads 34 of said one of its semiconductor IC chips 269a, 269b, 269c and 602 for the third alternative, or one of the first, second, third or fourth type of micro-bumps, micro-pillars or micro-pads 34 of said one of its semiconductor IC chips 269a, 269b, 269c and 270 for the fourth alternative, or through, in sequence in case for its second type of interconnection substrate 177 as seen in FIG. 9C, (1) one of the metal contacts 452 of its FPGA/NVM multi-chip package 259, (2) each of the interconnection metal layers 27 of the interconnection scheme 80 of its second type of interconnection substrate 177, (3) one of the first type of micro-bumps, micro-pillars or micro-pads 34 of one of the fine-line interconnection bridges (FIBs) 690, or DFPIC or eFPIC chips 400, of its second type of interconnection substrate 177 vertically under its FPGA/NVM multi-chip package 259, (4) one of the metal lines or traces 693 of said one of the fine-line interconnection bridges (FIBs) 690, or DFPIC or eFPIC chips 400, of its second type of interconnection substrate 177, (5) another of the first type of micro-bumps, micro-pillars or micro-pads 34 of said one of the fine-line interconnection bridges (FIBs) 690, or DFPIC or eFPIC chips 400, of its second type of interconnection substrate 177 vertically under said one of its semiconductor IC chips 269a, 269b, 269c and 602 for the third alternative, or said one of its semiconductor IC chips 269a, 269b, 269c and 270 for the fourth alternative, (6) each of the interconnection metal layers 27 of the interconnection scheme 80 of its second type of interconnection substrate 177 and (7) one of the first, second, third or fourth type of micro-bumps, micro-pillars or micro-pads 34 of said one of its semiconductor IC chips 269a, 269b, 269c and 602 for the third alternative, or one of the first, second, third or fourth type of micro-bumps, micro-pillars or micro-pads 34 of said one of its semiconductor IC chips 269a, 269b, 269c and 270 for the fourth alternative.

Alternatively, referring to FIGS. 5A-3, 5A-4 and 9D, for the first structure 301 for the fourth structure 304 for each of the first type of FPMCPs 300 for the third and fourth alternatives, each of the DFPIC or eFPIC chips 400 of each type of its first and second types of interconnection substrates 177 may be vertically under neighboring two of its semiconductor IC chips 601, 269a, 269b, 269c, 260, 602 and 603 and FPGA/NVM multi-chip package 259 for the third alternative, or neighboring two of its semiconductor IC chips 601, 269a, 269b, 269c, 270, 260, 602 and 603 and FPGA/NVM multi-chip package 259 for the fourth alternative, wherein said each of the DFPIC or eFPIC chips 400 of its first or second type of interconnection substrate 177 may couple to a first device of said neighboring two of its semiconductor IC chips 601, 269a, 269b, 269c, 260, 602 and 603 and FPGA/NVM multi-chip package 259 for the third alternative, or neighboring two of its semiconductor IC chips 601, 269a, 269b, 269c, 270, 260, 602 and 603 and FPGA/NVM multi-chip package 259 for the fourth alternative, through, in sequence, a first group of the first type of micro-bumps, micro-pillars or micro-pads 34 of said each of the DFPIC or eFPIC chips 400 of its first type of interconnection substrate 177 under the first device and the first, second, third or fourth type of micro-bumps, micro-pillars or micro-pads 34 of the first device, or the metal bumps, pillars or pads 570 or 571, solder balls 538 or metal contacts 452 of the first device, or through, in sequence, a first group of the first type of micro-bumps, micro-pillars or micro-pads 34 of said each of the DFPIC or eFPIC chips 400 of its second type of interconnection substrate 177 under the first device, each of the interconnection metal layers 27 of the interconnection scheme 80 of its second type of interconnection substrate 177 and the first, second, third or fourth type of micro-bumps, micro-pillars or micro-pads 34 of the first device, or the metal bumps, pillars or pads 570 or 571, solder balls 538 or metal contacts 452 of the first device, and couple to a second device of said neighboring two of its semiconductor IC chips 601, 269a, 269b, 269c, 260, 602 and 603 and FPGA/NVM multi-chip package 259 for the third alternative, or neighboring two of its semiconductor IC chips 601, 269a, 269b, 269c, 270, 260, 602 and 603 and FPGA/NVM multi-chip package 259 for the fourth alternative, through, in sequence, a second group of the first type of micro-bumps, micro-pillars or micro-pads 34 of said each of the DFPIC or eFPIC chips 400 of its first type of interconnection substrate 177 under the second device and the first, second, third or fourth type of micro-bumps, micro-pillars or micro-pads 34 of the second device, or the metal bumps, pillars or pads 570 or 571, solder balls 538 or metal contacts 452 of the second device, or through, in sequence, a second group of the first type of micro-bumps, micro-pillars or micro-pads 34 of said each of the DFPIC or eFPIC chips 400 of its second type of interconnection substrate 177 under the second device, each of the interconnection metal layers 27 of the interconnection scheme 80 of its second type of interconnection substrate 177 and the first, second, third or fourth type of micro-bumps, micro-pillars or micro-pads 34 of the second device, or the metal bumps, pillars or pads 570 or 571, solder balls 538 or metal contacts 452 of the second device, wherein for each of the third and fourth alternatives the first device may be its FPGA/NVM multi-chip package 259 and the second device may be its CPU IC chip 269b horizontally neighboring to its FPGA/NVM multi-chip package 259 as seen in FIGS. 5A-3 and 5A-4, for example; for each of the third and fourth alternatives the first device may be its FPGA/NVM multi-chip package 259 and the second device may be its GPU IC chip 269a horizontally neighboring to its FPGA/NVM multi-chip package 259 as seen in FIGS. 5A-3 and 5A-4, for example; for each of the third and fourth alternatives the first device may be its FPGA/NVM multi-chip package 259 and the second device may be its application-specific integrated-circuit (ASIC) chip or system-on-chip (SoC) chip 269c horizontally neighboring to its FPGA/NVM multi-chip package 259 as seen in FIGS. 5A-3 and 5A-4, for example; for the third alternative the first device may be its FPGA/NVM multi-chip package 259 and the second device may be its HBM IC chip 602 horizontally neighboring to its FPGA/NVM multi-chip package 259 as seen in FIG. 5A-3, for example; for the fourth alternative the first device may be its FPGA/NVM multi-chip package 259 and the second device may be its digital-signal-processing (DSP) IC chip 270 horizontally neighboring to its FPGA/NVM multi-chip package 259 as seen in FIG. 5A-4, for example. Said each of the DFPIC or eFPIC chips 400 may include (1) the first type of field programmable logic cell or element (LCE) 2014 or 2014-2 as illustrated in FIGS. 1A, 4D and 4E, the data inputs A0 and A1 of which may couple to the first device through, in sequence, respective two of the small input/output (SIO) circuits 203, or metal pads or input/output (I/O) pads, of said each of the DFPIC or eFPIC chips 400 of its first type of interconnection substrate 177, respective two of the first group of the first type of micro-bumps, micro-pillars or micro-pads 34 of said each of the DFPIC or eFPIC chips 400 of its first type of interconnection substrate 177 and respective two of the first, second, third or fourth type of micro-bumps, micro-pillars or micro-pads 34 of the first device, or respective two of the metal bumps, pillars or pads 570 or 571, solder balls 538 or metal contacts 452 of the first device, or through, in sequence, respective two of the small input/output (SIO) circuits 203, or metal pads or input/output (I/O) pads, of said each of the DFPIC or eFPIC chips 400 of its second type of interconnection substrate 177, respective two of the first group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and respective two of the first, second, third or fourth type of micro-bumps, micro-pillars or micro-pads 34 of the first device, or respective two of the metal bumps, pillars or pads 570 or 571, solder balls 538 or metal contacts 452 of the first device, and the data output Dout of which may couple to the second device through, in sequence, another of the small input/output (SIO) circuits 203, or metal pads or input/output (I/O) pads, of said each of the DFPIC or eFPIC chips 400 of its first type of interconnection substrate 177, one of the second group of the first type of micro-bumps, micro-pillars or micro-pads 34 of said each of the DFPIC or eFPIC chips 400 of its first type of interconnection substrate 177 and one of the first, second, third or fourth type of micro-bumps, micro-pillars or micro-pads 34 of the second device, or one of the metal bumps, pillars or pads 570 or 571, solder balls 538 or metal contacts 452 of the second device, or through, in sequence, another of the small input/output (SIO) circuits 203, or metal pads or input/output (I/O) pads, of said each of the DFPIC or eFPIC chips 400 of its second type of interconnection substrate 177, one of the second group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and one of the first, second, third or fourth type of micro-bumps, micro-pillars or micro-pads 34 of the second device, or one of the metal bumps, pillars or pads 570 or 571, solder balls 538 or metal contacts 452 of the second device, (2) the second or third type of field programmable logic cell or element (LCE) 2014 or 2014-2 as illustrated in FIGS. 1B, 1C, 4D and 4E, the data inputs A0-A3 of which may couple to the first device through, in sequence, respective four of the small input/output (SIO) circuits 203, or metal pads or input/output (I/O) pads, of said each of the DFPIC or eFPIC chips 400 of its first type of interconnection substrate 177, respective four of the first group of the first type of micro-bumps, micro-pillars or micro-pads 34 of said each of the DFPIC or eFPIC chips 400 of its first type of interconnection substrate 177 and respective four of the first, second, third or fourth type of micro-bumps, micro-pillars or micro-pads 34 of the first device, or respective four of the metal bumps, pillars or pads 570 or 571, solder balls 538 or metal contacts 452 of the first device, or through, in sequence, respective four of the small input/output (SIO) circuits 203, or metal pads or input/output (I/O) pads, of said each of the DFPIC or eFPIC chips 400 of its second type of interconnection substrate 177, respective four of the first group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and respective four of the first, second, third or fourth type of micro-bumps, micro-pillars or micro-pads 34 of the first device, or respective four of the metal bumps, pillars or pads 570 or 571, solder balls 538 or metal contacts 452 of the first device, and the data output Dout of which may couple to the second device through, in sequence, another of the small input/output (SIO) circuits 203, or metal pads or input/output (I/O) pads, of said each of the DFPIC or eFPIC chips 400 of its first type of interconnection substrate 177, one of the second group of the first type of micro-bumps, micro-pillars or micro-pads 34 of said each of the DFPIC or eFPIC chips 400 of its first type of interconnection substrate 177 and one of the first, second, third or fourth type of micro-bumps, micro-pillars or micro-pads 34 of the second device, or one of the metal bumps, pillars or pads 570 or 571, solder balls 538 or metal contacts 452 of the second device, or through, in sequence, another of the small input/output (SIO) circuits 203, or metal pads or input/output (I/O) pads, of said each of the DFPIC or eFPIC chips 400 of its second type of interconnection substrate 177, one of the second group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and one of the first, second, third or fourth type of micro-bumps, micro-pillars or micro-pads 34 of the second device, or one of the metal bumps, pillars or pads 570 or 571, solder balls 538 or metal contacts 452 of the second device, (3) the first type of field programmable switch cell 379 or 379-2 as illustrated in FIGS. 2A, 4D and 4E, the node N21 of which may couple to the first device through, in sequence, one of the small input/output (SIO) circuits 203, or metal pads or input/output (I/O) pads, of said each of the DFPIC or eFPIC chips 400 of its first type of interconnection substrate 177, one of the first group of the first type of micro-bumps, micro-pillars or micro-pads 34 of said each of the DFPIC or eFPIC chips 400 of its first type of interconnection substrate 177 and one of the first, second, third or fourth type of micro-bumps, micro-pillars or micro-pads 34 of the first device, or one of the metal bumps, pillars or pads 570 or 571, solder balls 538 or metal contacts 452 of the first device, or through, in sequence, one of the small input/output (SIO) circuits 203, or metal pads or input/output (I/O) pads, of said each of the DFPIC or eFPIC chips 400 of its second type of interconnection substrate 177, one of the first group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and one of the first, second, third or fourth type of micro-bumps, micro-pillars or micro-pads 34 of the first device, or one of the metal bumps, pillars or pads 570 or 571, solder balls 538 or metal contacts 452 of the first device, and the node N22 of which may couple to the second device through, in sequence, another of the small input/output (SIO) circuits 203, or metal pads or input/output (I/O) pads, of said each of the DFPIC or eFPIC chips 400 of its first type of interconnection substrate 177, one of the second group of the first type of micro-bumps, micro-pillars or micro-pads 34 of said each of the DFPIC or eFPIC chips 400 of its first type of interconnection substrate 177 and one of the first, second, third or fourth type of micro-bumps, micro-pillars or micro-pads 34 of the second device, or one of the metal bumps, pillars or pads 570 or 571, solder balls 538 or metal contacts 452 of the second device, or through, in sequence, another of the small input/output (SIO) circuits 203, or metal pads or input/output (I/O) pads, of said each of the DFPIC or eFPIC chips 400 of its second type of interconnection substrate 177, one of the second group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and one of the first, second, third or fourth type of micro-bumps, micro-pillars or micro-pads 34 of the second device, or one of the metal bumps, pillars or pads 570 or 571, solder balls 538 or metal contacts 452 of the second device, to control coupling between the first and second devices, (4) the second type of field programmable switch cell 379 or 379-2 as illustrated in FIGS. 2B, 4D and 4E, the nodes N23 and N24 of which may couple to the first device through, in sequence, respective two of the small input/output (SIO) circuits 203, or metal pads or input/output (I/O) pads, of said each of the DFPIC or eFPIC chips 400 of its first type of interconnection substrate 177, respective two of the first group of the first type of micro-bumps, micro-pillars or micro-pads 34 of said each of the DFPIC or eFPIC chips 400 of its first type of interconnection substrate 177 and respective two of the first, second, third or fourth type of micro-bumps, micro-pillars or micro-pads 34 of the first device, or respective two of the metal bumps, pillars or pads 570 or 571, solder balls 538 or metal contacts 452 of the first device, or through, in sequence, respective two of the small input/output (SIO) circuits 203, or metal pads or input/output (I/O) pads, of said each of the DFPIC or eFPIC chips 400 of its second type of interconnection substrate 177, respective two of the first group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and respective two of the first, second, third or fourth type of micro-bumps, micro-pillars or micro-pads 34 of the first device, or respective two of the metal bumps, pillars or pads 570 or 571, solder balls 538 or metal contacts 452 of the first device, and the nodes N25 and N26 of which may couple to the second device through, in sequence, another respective two of the small input/output (SIO) circuits 203, or metal pads or input/output (I/O) pads, of said each of the DFPIC or eFPIC chips 400 of its first type of interconnection substrate 177, respective two of the second group of the first type of micro-bumps, micro-pillars or micro-pads 34 of said each of the DFPIC or eFPIC chips 400 of its first type of interconnection substrate 177 and respective two of the first, second, third or fourth type of micro-bumps, micro-pillars or micro-pads 34 of the second device, or respective two of the metal bumps, pillars or pads 570 or 571, solder balls 538 or metal contacts 452 of the second device, or through, in sequence, another respective two of the small input/output (SIO) circuits 203, or metal pads or input/output (I/O) pads, of said each of the DFPIC or eFPIC chips 400 of its second type of interconnection substrate 177, respective two of the second group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and respective two of the first, second, third or fourth type of micro-bumps, micro-pillars or micro-pads 34 of the second device, or respective two of the metal bumps, pillars or pads 570 or 571, solder balls 538 or metal contacts 452 of the second device, to control coupling from the node N23 to one or more of the nodes N24-N26 or to control coupling from the node N26 to one or more of the nodes N23-N25, (5) the field programmable switch matrix 710 or 710-3 as illustrated in FIGS. 2C, 4D and 4E, each of the nodes P₁-P_{N} of which may couple to the first device through, in sequence, one of the first metal lines 281 of said each of the DFPIC or eFPIC chips 400 of its first type of interconnection substrate 177, one of the small input/output (SIO) circuits 203, or metal pads or input/output (I/O) pads, of said each of the DFPIC or eFPIC chips 400 of its first type of interconnection substrate 177, one of the first group of the first type of micro-bumps, micro-pillars or micro-pads 34 of said each of the DFPIC or eFPIC chips 400 of its first type of interconnection substrate 177 and one of the first, second, third or fourth type of micro-bumps, micro-pillars or micro-pads 34 of the first device, or one of the metal bumps, pillars or pads 570 or 571, solder balls 538 or metal contacts 452 of the first device, or through, in sequence, one of the first metal lines 281 of said each of the DFPIC or eFPIC chips 400 of its second type of interconnection substrate 177, one of the small input/output (SIO) circuits 203, or metal pads or input/output (I/O) pads, of said each of the DFPIC or eFPIC chips 400 of its second type of interconnection substrate 177, one of the first group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and one of the first, second, third or fourth type of micro-bumps, micro-pillars or micro-pads 34 of the first device, or one of the metal bumps, pillars or pads 570 or 571, solder balls 538 or metal contacts 452 of the first device, each of the nodes Q₁-Q_{M} of which may couple to the second device through, in sequence, one of the second metal lines 282 of said each of the DFPIC or eFPIC chips 400 of its first type of interconnection substrate 177, another of the small input/output (SIO) circuits 203, or metal pads or input/output (I/O) pads, of said each of the DFPIC or eFPIC chips 400 of its first type of interconnection substrate 177, one of the second group of the first type of micro-bumps, micro-pillars or micro-pads 34 of said each of the DFPIC or eFPIC chips 400 of its first type of interconnection substrate 177 and one of the first, second, third or fourth type of micro-bumps, micro-pillars or micro-pads 34 of the second device, or one of the metal bumps, pillars or pads 570 or 571, solder balls 538 or metal contacts 452 of the second device, or through, in sequence, one of the second metal lines 282 of said each of the DFPIC or eFPIC chips 400 of its second type of interconnection substrate 177, another of the small input/output (SIO) circuits 203, or metal pads or input/output (I/O) pads, of said each of the DFPIC or eFPIC chips 400 of its second type of interconnection substrate 177, one of the second group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and one of the first, second, third or fourth type of micro-bumps, micro-pillars or micro-pads 34 of the second device, or one of the metal bumps, pillars or pads 570 or 571, solder balls 538 or metal contacts 452 of the second device, and each of the pass/no-pass switches 778 of which may control coupling between the first and second devices, i.e., between one of the first group of the first type of micro-bumps, micro-pillars or micro-pads 34 of said each of the DFPIC or eFPIC chips 400 of its first or second type of interconnection substrate 177 and one of the second group of the first type of micro-bumps, micro-pillars or micro-pads 34 of said each of the DFPIC or eFPIC chips 400 of its first or second type of interconnection substrate 177, and/or (6) the field programmable switch matrix 710-2 as illustrated in FIGS. 2C and 4E, each of some of the nodes P₁-P_{N} of which may couple to the first device through, in sequence, one of the first metal lines 281 of said each of the DFPIC or eFPIC chips 400 of its first type of interconnection substrate 177, one of the small input/output (SIO) circuits 203, or metal pads or input/output (I/O) pads, of said each of the DFPIC or eFPIC chips 400 of its first type of interconnection substrate 177, one of the first group of the first type of micro-bumps, micro-pillars or micro-pads 34 of said each of the DFPIC or eFPIC chips 400 of its first type of interconnection substrate 177 and one of the first, second, third or fourth type of micro-bumps, micro-pillars or micro-pads 34 of the first device, or one of the metal bumps, pillars or pads 570 or 571, solder balls 538 or metal contacts 452 of the first device, or through, in sequence, one of the first metal lines 281 of said each of the DFPIC or eFPIC chips 400 of its second type of interconnection substrate 177, one of the small input/output (SIO) circuits 203, or metal pads or input/output (I/O) pads, of said each of the DFPIC or eFPIC chips 400 of its second type of interconnection substrate 177, one of the first group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and one of the first, second, third or fourth type of micro-bumps, micro-pillars or micro-pads 34 of the first device, or one of the metal bumps, pillars or pads 570 or 571, solder balls 538 or metal contacts 452 of the first device, each of the other some of the nodes P₁-P_{N} of which may couple to the second device through, in sequence, another of the first metal lines 281 of said each of the DFPIC or eFPIC chips 400 of its first type of interconnection substrate 177, another of the small input/output (SIO) circuits 203, or metal pads or input/output (I/O) pads, of said each of the DFPIC or eFPIC chips 400 of its first type of interconnection substrate 177, one of the second group of the first type of micro-bumps, micro-pillars or micro-pads 34 of said each of the DFPIC or eFPIC chips 400 of its first type of interconnection substrate 177 and one of the first, second, third or fourth type of micro-bumps, micro-pillars or micro-pads 34 of the second device, or one of the metal bumps, pillars or pads 570 or 571, solder balls 538 or metal contacts 452 of the second device, or through, in sequence, another of the first metal lines 281 of said each of the DFPIC or eFPIC chips 400 of its second type of interconnection substrate 177, another of the small input/output (SIO) circuits 203, or metal pads or input/output (I/O) pads, of said each of the DFPIC or eFPIC chips 400 of its second type of interconnection substrate 177, one of the second group of the first type of micro-bumps, micro-pillars or micro-pads 34 of said each of the DFPIC or eFPIC chips 400 of its second type of interconnection substrate 177, each of the interconnection metal layers 27 of the interconnection scheme 80 of its second type of interconnection substrate 177 and one of the first, second, third or fourth type of micro-bumps, micro-pillars or micro-pads 34 of the second device, or one of the metal bumps, pillars or pads 570 or 571, solder balls 538 or metal contacts 452 of the second device, and each of the pass/no-pass switches 778 of which may control coupling between one of the first and second devices and one of the internal circuits of the fourth one of the ASIC cores 215 of said each of the DFPIC or eFPIC chips 400 of its first or second type of interconnection substrate 177, i.e., between one of the first and second groups of the first type of micro-bumps, micro-pillars or micro-pads 34 of said each of the DFPIC or eFPIC chips 400 of its first or second type of interconnection substrate 177 and one of the internal circuits of the fourth one of the ASIC cores 215 of said each of the DFPIC or eFPIC chips 400 of its first or second type of interconnection substrate 177.

Referring to FIGS. 5A-3, 5A-4 and 9D, the fourth structure 304 for said each of the first type of FPMCPs 300 for the third and fourth alternatives may further include an underfill 564, i.e., polymer layer, between each of its semiconductor IC chips 601, 269a, 269b, 269c, 260, 602 and 603 and FPGA/NVM multi-chip package 259 for the third alternative, or each of its semiconductor IC chips 601, 269a, 269b, 269c, 270, 260, 602 and 603 and FPGA/NVM multi-chip package 259 for the fourth alternative, and its first or second type of interconnection substrate 177, covering a sidewall of each of the first, second, third or fourth type of micro-bumps, micro-pillars or micro-pads 34 of each of its semiconductor IC chips 601, 269a, 269b, 269c, 260, 602 and 603 for the third alternative, or a sidewall of each of the first, second, third or fourth type of micro-bumps, micro-pillars or micro-pads 34 of each of its semiconductor IC chips 601, 269a, 269b, 269c, 270, 260, 602 and 603 for the fourth alternative, and covering a sidewall of the metal bumps, pillars or pads 570 of its FPGA/NVM multi-chip package 259 for the first scenario, a sidewall of the metal bumps, pillars or pads 571 of its FPGA/NVM multi-chip package 259 for the second scenario, a sidewall of the solder balls 538 of its FPGA/NVM multi-chip package 259 for the third scenario or a sidewall of the metal contacts 452 of its FPGA/NVM multi-chip package 259 for the fourth scenario. Its polymer layer 192 may be formed on a top surface of its first or second type of interconnection substrate 177 and horizontally around each of its semiconductor IC chips 601, 269a, 269b, 269c, 260, 602 and 603 and FPGA/NVM multi-chip package 259 for the third alternative, or each of its semiconductor IC chips 601, 269a, 269b, 269c, 270, 260, 602 and 603 and FPGA/NVM multi-chip package 259 for the fourth alternative. Its polymer layer 192 may have a vertical sidewall coplanar with a vertical sidewall of its first or second type of interconnection substrate 177. The fourth structure 304 for said each of the first type of FPMCPs 300 for the third and fourth alternatives may further include multiple metal bumps, pillars or pads 575 in an array at its bottom to act as its external pins for coupling to the external circuits outside of the fourth structure 304 for said each of the first type of field-programmable multi-chip packages 300 for the third and fourth alternatives, wherein each of its metal bumps, pillars or pads 575 may be of a type selected from various types, i.e., first and second types, having the same specification as that of the first and second types of metal bumps, pillars or pads 575 respectively as illustrated in FIG. 6B, and may have the adhesion metal layer 26a on a bottom surface of one of the metal pads of the bottommost one of the interconnection metal layers 27 of the interconnection scheme 79 of its first or second type of interconnection substrate 177 and a bottom surface of the bottommost one of the polymer layers 42 of the interconnection scheme 79 of its first or second type of interconnection substrate 177. Each of its semiconductor IC chips 601, 269a, 269b, 269c, 260, 602 and 603 and FPGA/NVM multi-chip package 259 for the third alternative, or each of its semiconductor IC chips 601, 269a, 269b, 269c, 270, 260, 602 and 603 and FPGA/NVM multi-chip package 259 for the fourth alternative, may couple to one of its metal bumps, pillars or pads 575 for external connection through, in sequence, any of the through silicon vias (TSVs) 157 of any of the vertical-through-via (VTV) connectors 467 of its first type of interconnection substrate 177 and each of the interconnection metal layers 27 of the interconnection scheme 79 of its first type of interconnection substrate 177, or through, in sequence, each of the interconnection metal layers 27 of the interconnection scheme 80 of its second type of interconnection substrate 177, any of the through silicon vias (TSVs) 157 of any of the vertical-through-via (VTV) connectors 467 of its second type of interconnection substrate 177 and each of the interconnection metal layers 27 of the interconnection scheme 79 of its second type of interconnection substrate 177.

### Configuration for First Type of FPMCP for Third and Fourth Alternatives

Referring to FIGS. 5A-3 and 5A-4, for each of the first type of FPMCPs 300 for the third and fourth alternatives, any of the FPGA IC chip(s) 200, 100i and/or 100j of its FPGA/NVM multi-chip package 259 may include the first or second type of field programmable switch cell 379, i.e., field-programmable interconnection (FPI) circuits as illustrated in FIGS. 2A-2B, or the field programmable switch matrix 710 as illustrated in FIG. 2C to be programmed, configured or reconfigured to change or control inter-chip interconnection from a first one of its semiconductor IC chips, including (1) for the third alternative, its FPGA IC chip 601, dedicated control and input/output (I/O) chip 260, graphic-processing-unit (GPU) IC chips 269a, central-processing-unit (CPU) IC chip 269b, application-specific integrated-circuit (ASIC) chip or system-on-chip (SoC) chip 269c, high-bandwidth-memory (HBM) IC chips 602 and auxiliary IC chips 603, or (2) for the fourth alternative, its FPGA IC chip 601, dedicated control and input/output (I/O) chip 260, graphic-processing-unit (GPU) IC chips 269a, central-processing-unit (CPU) IC chip 269b, application-specific integrated-circuit (ASIC) chip or system-on-chip (SoC) chip 269c, digital-signal-processing (DSP) IC chip 270, high-bandwidth-memory (HBM) IC chip 602 and auxiliary IC chips 603, to a second one of its semiconductor IC chips. Said any of the FPGA IC chip(s) 200, 100i and/or 100j of its FPGA/NVM multi-chip package 259 may have (1) multiple first small input/output (SIO) circuits, or input/output (I/O) pads, each coupling to the node N21 of a first one of the first type of field programmable switch cells 379 thereof, as illustrated in FIG. 2A, one of the nodes N23-N26 of a first one of the second type of field programmable switch cells 379 thereof, as illustrated in FIG. 2B, or one of the nodes P₁-P_{N} of a first one of the field programmable switch matrices 710 thereof, as illustrated in FIG. 2C, through one of the programmable interconnects 361 thereof and to one of a first group of its bonded metal bumps or contacts 574 as illustrated in FIG. 6B, one of a first group of its high-density bonded metal bumps or contacts 574a as illustrated in FIG. 8B or one of a first group of the metal bumps, pillars or pads 570 or 571, solder balls 538 or metal contacts 452 of its FPGA/NVM multi-chip package 259 as illustrated in FIG. 9D, which may couple to one of multiple first small input/output (SIO) circuits, or input/output (I/O) pads, of the first one of its semiconductor IC chips through one of the programmable interconnects 361 of its inter-chip interconnects 371 as illustrated in FIG. 6B, 8B or 9D, to form a first signal path between the node N21 of the first one of the first type of field programmable switch cells 379 thereof and said one of the first small input/output (SIO) circuits, or input/output (I/O) pads, of the first one of its semiconductor IC chips, between said one of the nodes N23-N26 of the first one of the second type of field programmable switch cells 379 thereof and said one of the first small input/output (SIO) circuits, or input/output (I/O) pads, of the first one of its semiconductor IC chips or between said one of the nodes P₁-P_{N} of the first one of the field programmable switch matrices 710 thereof and said one of the first small input/output (SIO) circuits, or input/output (I/O) pads, of the first one of its semiconductor IC chips, (2) multiple second small input/output (SIO) circuits, or input/output (I/O) pads, each coupling to the node N22 of the first one of the first type of field programmable switch cells 379 thereof, as illustrated in FIG. 2A, one of the others of the nodes N23-N26 of the first one of the second type of field programmable switch cells 379 thereof, as illustrated in FIG. 2B, or one of the nodes Q₁-Q_{M} of the first one of the field programmable switch matrices 710 thereof, as illustrated in FIG. 2C, through another of the programmable interconnects 361 thereof and to one of a second group of its bonded metal bumps or contacts 574 as illustrated in FIG. 6B, one of a second group of its high-density bonded metal bumps or contacts 574a as illustrated in FIG. 8B or one of a second group of the metal bumps, pillars or pads 570 or 571, solder balls 538 or metal contacts 452 of its FPGA/NVM multi-chip package 259 as illustrated in FIG. 9D, which may couple to one of multiple first small input/output (SIO) circuits, or input/output (I/O) pads, of the second one of its semiconductor IC chips through another of the programmable interconnects 361 of its inter-chip interconnects 371 as illustrated in FIG. 6B, 8B or 9D, to form a second signal path between the node N22 of the first one of the first type of field programmable switch cells 379 thereof and said one of the first small input/output (SIO) circuits, or input/output (I/O) pads, of the second one of its semiconductor IC chips, between said one of the others of the nodes N23-N26 of the first one of the second type of field programmable switch cells 379 thereof and said one of the first small input/output (SIO) circuits, or input/output (I/O) pads, of the second one of its semiconductor IC chips or between said one of the nodes Q₁-Q_{M} of the first one of the field programmable switch matrices 710 thereof and said one of the first small input/output (SIO) circuits, or input/output (I/O) pads, of the second one of its semiconductor IC chips, (3) multiple third small input/output (SIO) circuits, or input/output (I/O) pads, each coupling to the node N21 of a second one of the first type of field programmable switch cells 379 thereof, as illustrated in FIG. 2A, one of the nodes N23-N26 of a second one of the second type of field programmable switch cells 379 thereof, as illustrated in FIG. 2B, or one of the nodes P₁-P_{N} of a second one of the field programmable switch matrices 710 thereof, as illustrated in FIG. 2C, through another of the programmable interconnects 361 thereof and to one of a third group of its bonded metal bumps or contacts 574 as illustrated in FIG. 6B, one of a third group of its high-density bonded metal bumps or contacts 574a as illustrated in FIG. 8B or one of a third group of the metal bumps, pillars or pads 570 or 571, solder balls 538 or metal contacts 452 of its FPGA/NVM multi-chip package 259 as illustrated in FIG. 9D, which may couple to one of multiple second small input/output (SIO) circuits, or input/output (I/O) pads, of the first one of its semiconductor IC chips through another of the programmable interconnects 361 of its inter-chip interconnects 371 as illustrated in FIG. 6B, 8B or 9D, to form a third signal path between the node N21 of the second one of the first type of field programmable switch cells 379 thereof and said one of the second small input/output (SIO) circuits, or input/output (I/O) pads, of the first one of its semiconductor IC chips, between said one of the nodes N23-N26 of the second one of the second type of field programmable switch cells 379 thereof and said one of the second small input/output (SIO) circuits, or input/output (I/O) pads, of the first one of its semiconductor IC chips or between said one of the nodes P₁-P_{N} of the second one of the field programmable switch matrices 710 thereof and said one of the second small input/output (SIO) circuits, or input/output (I/O) pads, of the first one of its semiconductor IC chips, (4) multiple fourth small input/output (SIO) circuits, or input/output (I/O) pads, each coupling to the node N22 of the second one of the first type of field programmable switch cells 379 thereof, as illustrated in FIG. 2A, one of the others of the nodes N23-N26 of the second one of the second type of field programmable switch cells 379 thereof, as illustrated in FIG. 2B, or one of the nodes Q₁-Q_{M} of the second one of the field programmable switch matrices 710 thereof, as illustrated in FIG. 2C, through another of the programmable interconnects 361 thereof and to one of a fourth group of its bonded metal bumps or contacts 574 as illustrated in FIG. 6B, one of a fourth group of its high-density bonded metal bumps or contacts 574a as illustrated in FIG. 8B or one of a fourth group of the metal bumps, pillars or pads 570 or 571, solder balls 538 or metal contacts 452 of its FPGA/NVM multi-chip package 259 as illustrated in FIG. 9D, which may couple to one of multiple third small input/output (SIO) circuits, or input/output (I/O) pads, of the first one of its semiconductor IC chips, through another of the programmable interconnects 361 of its inter-chip interconnects 371 as illustrated in FIG. 6B, 8B or 9D, to form a fourth signal path between the node N22 of the second one of the first type of field programmable switch cells 379 thereof and said one of the third small input/output (SIO) circuits, or input/output (I/O) pads, of the first one of its semiconductor IC chips, between said one of the others of the nodes N23-N26 of the second one of the second type of field programmable switch cells 379 thereof and said one of the third small input/output (SIO) circuits, or input/output (I/O) pads, of the first one of its semiconductor IC chips or between said one of the nodes Q₁-Q_{M} of the second one of the field programmable switch matrices 710 thereof and said one of the third small input/output (SIO) circuits, or input/output (I/O) pads, of the first one of its semiconductor IC chips, (5) multiple fifth small input/output (SIO) circuits, or input/output (I/O) pads, each coupling to one of the nodes N23-N26 of a third one of the second type of field programmable switch cells 379 thereof, as illustrated in FIG. 2B, or one of the nodes P₁-P_{N} of a third one of the field programmable switch matrices 710 thereof, as illustrated in FIG. 2C, through another of the programmable interconnects 361 thereof and to one of a fifth group of its bonded metal bumps or contacts 574 as illustrated in FIG. 6B, one of a fifth group of its high-density bonded metal bumps or contacts 574a as illustrated in FIG. 8B or one of a fifth group of the metal bumps, pillars or pads 570 or 571, solder balls 538 or metal contacts 452 of its FPGA/NVM multi-chip package 259 as illustrated in FIG. 9D, which may couple to one of multiple fourth small input/output (SIO) circuits, or input/output (I/O) pads, of the first one of its semiconductor IC chips, through another of the programmable interconnects 361 of its inter-chip interconnects 371 as illustrated in FIG. 6B, 8B or 9D, to form a fifth signal path between said one of the nodes N23-N26 of the third one of the second type of field programmable switch cells 379 thereof and said one of the fourth small input/output (SIO) circuits, or input/output (I/O) pads, of the first one of its semiconductor IC chips or between said one of the nodes P₁-P_{N} of the third one of the field programmable switch matrices 710 thereof and said one of the fourth small input/output (SIO) circuits, or input/output (I/O) pads, of the first one of its semiconductor IC chips, (6) multiple sixth small input/output (SIO) circuits, or input/output (I/O) pads, each coupling to another of the nodes N23-N26 of the third one of the second type of field programmable switch cells 379 thereof, as illustrated in FIG. 2B, or one of the nodes Q₁-Q_{M} of the third one of the field programmable switch matrices 710 thereof, as illustrated in FIG. 2C, through another of the programmable interconnects 361 thereof and to one of a sixth group of its bonded metal bumps or contacts 574 as illustrated in FIG. 6B, one of a sixth group of its high-density bonded metal bumps or contacts 574a as illustrated in FIG. 8B or one of a sixth group of the metal bumps, pillars or pads 570 or 571, solder balls 538 or metal contacts 452 of its FPGA/NVM multi-chip package 259 as illustrated in FIG. 9D, which may couple to one of multiple second small input/output (SIO) circuits, or input/output (I/O) pads, of the second one of its semiconductor IC chips through another of the programmable interconnects 361 of its inter-chip interconnects 371 as illustrated in FIG. 6B, 8B or 9D, to form a sixth signal path between said another of the nodes N23-N26 of the third one of the second type of field programmable switch cells 379 thereof and said one of the second small input/output (SIO) circuits, or input/output (I/O) pads, of the second one of its semiconductor IC chips or between said one of the nodes Q₁-Q_{M} of the third one of the field programmable switch matrices 710 thereof and said one of the second small input/output (SIO) circuits, or input/output (I/O) pads, of the second one of its semiconductor IC chips, (7) multiple seventh small input/output (SIO) circuits, or input/output (I/O) pads, each coupling to still another of the nodes N23-N26 of the third one of the second type of field programmable switch cells 379 thereof, as illustrated in FIG. 2B, or another of the nodes Q₁-Q_{M} of the third one of the field programmable switch matrices 710 thereof, as illustrated in FIG. 2C through another of the programmable interconnects 361 thereof and to one of a seventh group of its bonded metal bumps or contacts 574 as illustrated in FIG. 6B, one of a seventh group of its high-density bonded metal bumps or contacts 574a as illustrated in FIG. 8B or one of a seventh group of the metal bumps, pillars or pads 570 or 571, solder balls 538 or metal contacts 452 of its FPGA/NVM multi-chip package 259 as illustrated in FIG. 9D, which may couple to one of multiple third small input/output (SIO) circuits, or input/output (I/O) pads, of the second one of its semiconductor IC chips through another of the programmable interconnects 361 of its inter-chip interconnects 371 as illustrated in FIG. 6B, 8B or 9D, to form a seventh signal path between said still another of the nodes N23-N26 of the third one of the second type of field programmable switch cells 379 thereof and said one of the third small input/output (SIO) circuits 477, or input/output (I/O) pads, of the second one of its semiconductor IC chips or between said another of the nodes Q₁-Q_{M} of the third one of the field programmable switch matrices 710 thereof and said one of the third small input/output (SIO) circuits 477, or input/output (I/O) pads, of the second one of its semiconductor IC chips, (8) multiple eighth small input/output (SIO) circuits, or input/output (I/O) pads, each coupling to one of the nodes N23-N26 of a fourth one of the second type of field programmable switch cells 379 thereof, as illustrated in FIG. 2B, or one of the nodes P₁-P_{N} of a fourth one of the field programmable switch matrices 710 thereof, as illustrated in FIG. 2C, through another of the programmable interconnects 361 thereof and to one of an eighth group of its bonded metal bumps or contacts 574 as illustrated in FIG. 6B, one of an eighth group of its high-density bonded metal bumps or contacts 574a as illustrated in FIG. 8B or one of an eighth group of the metal bumps, pillars or pads 570 or 571, solder balls 538 or metal contacts 452 of its FPGA/NVM multi-chip package 259 as illustrated in FIG. 9D, which may couple to one of multiple fifth small input/output (SIO) circuits, or input/output (I/O) pads, of the first one of its semiconductor IC chips through another of the programmable interconnects 361 of its inter-chip interconnects 371 as illustrated in FIG. 6B, 8B or 9D, to form an eighth signal path between said one of the nodes N23-N26 of the fourth one of the second type of field programmable switch cells 379 thereof and said one of the fifth small input/output (SIO) circuits, or input/output (I/O) pads, of the first one of its semiconductor IC chips or between said one of the nodes P₁-P_{N} of the fourth one of the field programmable switch matrices 710 thereof and said one of the fifth small input/output (SIO) circuits, or input/output (I/O) pads, of the first one of its semiconductor IC chips, (9) multiple ninth small input/output (SIO) circuits, or input/output (I/O) pads, each coupling to another of the nodes N23-N26 of the fourth one of the second type of field programmable switch cells 379 thereof, as illustrated in FIG. 2B, or one of the nodes Q₁-Q_{M} of the fourth one of the field programmable switch matrices 710 thereof, as illustrated in FIG. 2C, through another of the programmable interconnects 361 thereof and to one of a ninth group of its bonded metal bumps or contacts 574 as illustrated in FIG. 6B, one of a ninth group of its high-density bonded metal bumps or contacts 574a as illustrated in FIG. 8B or one of a ninth group of the metal bumps, pillars or pads 570 or 571, solder balls 538 or metal contacts 452 of its FPGA/NVM multi-chip package 259 as illustrated in FIG. 9D, which may couple to one of multiple sixth small input/output (SIO) circuits, or input/output (I/O) pads, of the first one of its semiconductor IC chips through another of the programmable interconnects 361 of its inter-chip interconnects 371 as illustrated in FIG. 6B, 8B or 9D, to form a ninth signal path between said another of the nodes N23-N26 of the fourth one of the second type of field programmable switch cells 379 thereof and said one of the sixth small input/output (SIO) circuits, or input/output (I/O) pads, of the first one of its semiconductor IC chips or between said one of the nodes Q₁-Q_{M} of the fourth one of the field programmable switch matrices 710 thereof and said one of the sixth small input/output (SIO) circuits, or input/output (I/O) pads, of the first one of its semiconductor IC chips, and (10) multiple tenth small input/output (SIO) circuits, or input/output (I/O) pads, each coupling to still another of the nodes N23-N26 of the fourth one of the second type of field programmable switch cells 379 thereof, as illustrated in FIG. 2B, or another of the nodes P₁-P_{N} of the fourth one of the field programmable switch matrices 710 thereof, as illustrated in FIG. 2C, through another of the programmable interconnects 361 thereof and to one of a tenth group of its bonded metal bumps or contacts 574 as illustrated in FIG. 6B, one of a tenth group of its high-density bonded metal bumps or contacts 574a as illustrated in FIG. 8B or one of a tenth group of the metal bumps, pillars or pads 570 or 571, solder balls 538 or metal contacts 452 of its FPGA/NVM multi-chip package 259 as illustrated in FIG. 9D, which may couple to one of multiple seventh small input/output (SIO) circuits, or input/output (I/O) pads, of the first one of its semiconductor IC chips through another of the programmable interconnects 361 of its inter-chip interconnects 371 as illustrated in FIG. 6B, 8B or 9D, to form a tenth signal path between said still another of the nodes N23-N26 of the fourth one of the second type of field programmable switch cells 379 thereof and said one of the seventh small input/output (SIO) circuits, or input/output (I/O) pads, of the first one of its semiconductor IC chips or between said another of the nodes P₁-P_{N} of the fourth one of the field programmable switch matrices 710 thereof and said one of the seventh small input/output (SIO) circuits, or input/output (I/O) pads, of the first one of its semiconductor IC chips.

Accordingly, the first one of the first or second type of field programmable switch cells 379 of said any of the FPGA IC chip(s) 200, 100i and/or 100j of its FPGA/NVM multi-chip package 259 or the first one of the field programmable switch matrices 710 of said any of the FPGA IC chip(s) 200, 100i and/or 100j of its FPGA/NVM multi-chip package 259 may be programmed, configured or reconfigured in accordance with CPM data, i.e., programming codes, password or encryption/decryption codes, stored in the memory cells 362 thereof as seen in FIG. 2A, the four sets of memory cells 362 thereof as seen in FIG. 2B or the memory cell 398 of each of the field programmable switch units 711 of the first one of the field programmable switch matrices 710 thereof as seen in FIG. 2C to control coupling between the first and second signal paths. The second one of the first or second type of field programmable switch cells 379 of said any of the FPGA IC chip(s) 200, 100i and/or 100j of its FPGA/NVM multi-chip package 259 or the second one of the field programmable switch matrices 710 of said any of the FPGA IC chip(s) 200, 100i and/or 100j of its FPGA/NVM multi-chip package 259 may be programmed, configured or reconfigured in accordance with CPM data, i.e., programming codes, password or encryption/decryption codes, stored in the memory cells 362 thereof as seen in FIG. 2A, the four sets of memory cells 362 thereof as seen in FIG. 2B or the memory cell 398 of each of the field programmable switch units 711 thereof as seen in FIG. 2C to control coupling between the third and fourth signal paths. The third one of the second type of field programmable switch cells 379 of said any of the FPGA IC chip(s) 200, 100i and/or 100j of its FPGA/NVM multi-chip package 259 may be programmed, configured or reconfigured in accordance with CPM data stored in the four sets of memory cells 362 thereof as seen in FIG. 2B to select one from the fifth, sixth and seventh signal paths to couple to another of the fifth, sixth and seventh signal paths, and, for example, to select the fifth signal path to couple to one of the sixth and seventh signal paths or select the sixth signal path to couple to one of the fifth and seventh signal paths, or the third one of the field programmable switch matrices 710 of said any of the FPGA IC chip(s) 200, 100i and/or 100j of its FPGA/NVM multi-chip package 259 may be programmed, configured or reconfigured in accordance with CPM data, i.e., programming codes, password or encryption/decryption codes, stored in the memory cell 398 of each of the field programmable switch units 711 thereof as seen in FIG. 2C to select one from the sixth and seventh signal paths to couple to the fifth signal path. The fourth one of the second type of field programmable switch cells 379 of said any of the FPGA IC chip(s) 200, 100i and/or 100j of its FPGA/NVM multi-chip package 259 may be programmed, configured or reconfigured in accordance with CPM data stored in the four sets of memory cells 362 thereof as seen in FIG. 2B to select one from the eighth, ninth and tenth signal paths to couple to another of the eighth, ninth and tenth signal paths, and, for example, to select the eighth signal path to couple to one of the ninth and tenth signal paths, or the fourth one of the field programmable switch matrices 710 of said any of the FPGA IC chip(s) 200, 100i and/or 100j of its FPGA/NVM multi-chip package 259 may be programmed, configured or reconfigured in accordance with CPM data, i.e., programming codes, password or encryption/decryption codes, stored in the memory cell 398 of each of the field programmable switch units 711 thereof as seen in FIG. 2C to select one from the eighth and tenth signal paths to couple to the ninth signal path.

Further, referring to FIGS. 5A-3 and 5A-4, for said each of the first type of FPMCPs 300 for the third and fourth alternatives, said any of the FPGA IC chip(s) 200, 100i and/or 100j of its FPGA/NVM multi-chip package 259 may cooperate with each of the first and second ones of its semiconductor IC chips. For example, said any of the FPGA IC chip(s) 200, 100i and/or 100j of its FPGA/NVM multi-chip package 259 may have (1) an eleventh small input/output (SIO) circuit, or input/output (I/O) pad, coupling to a first one of its bonded metal bumps or contacts 574 as illustrated in FIG. 6B, a first one of its high-density bonded metal bumps or contacts 574a as illustrated in FIG. 8B or a first one of the metal bumps, pillars or pads 570 or 571, solder balls 538 or metal contacts 452 of its FPGA/NVM multi-chip package 259 as illustrated in FIG. 9D, which may couple to an eighth small input/output (SIO) circuit, or input/output (I/O) pad, of the first one of its semiconductor IC chips through another of the programmable interconnects 361 of its inter-chip interconnects 371 as illustrated in FIG. 6B, 8B or 9D, (2) a twelfth small input/output (SIO) circuit, or input/output (I/O) pad, coupling to a second one of its bonded metal bumps or contacts 574 as illustrated in FIG. 6B, a second one of its high-density bonded metal bumps or contacts 574a as illustrated in FIG. 8B or a second one of the metal bumps, pillars or pads 570 or 571, solder balls 538 or metal contacts 452 of its FPGA/NVM multi-chip package 259 as illustrated in FIG. 9D, which may couple to a ninth small input/output (SIO) circuit, or input/output (I/O) pad, of the first one of its semiconductor IC chips through another of the programmable interconnects 361 of its inter-chip interconnects 371 as illustrated in FIG. 6B, 8B or 9D, (3) a thirteenth small input/output (SIO) circuit, or input/output (I/O) pad, coupling to a third one of its bonded metal bumps or contacts 574 as illustrated in FIG. 6B, a third one of its high-density bonded metal bumps or contacts 574a as illustrated in FIG. 8B or a third one of the metal bumps, pillars or pads 570 or 571, solder balls 538 or metal contacts 452 of its FPGA/NVM multi-chip package 259 as illustrated in FIG. 9D, which may couple to a tenth small input/output (SIO) circuit, or input/output (I/O) pad, of the first one of its semiconductor IC chips through another of the programmable interconnects 361 of its inter-chip interconnects 371 as illustrated in FIG. 6B, 8B or 9D, (4) a fourteenth small input/output (SIO) circuit, or input/output (I/O) pad, coupling to a fourth one of its bonded metal bumps or contacts 574 as illustrated in FIG. 6B, a fourth one of its high-density bonded metal bumps or contacts 574a as illustrated in FIG. 8B or a fourth one of the metal bumps, pillars or pads 570 or 571, solder balls 538 or metal contacts 452 of its FPGA/NVM multi-chip package 259 as illustrated in FIG. 9D, which may couple to a third small input/output (SIO) circuit, or input/output (I/O) pad, of the second one of its semiconductor IC chips through another of the programmable interconnects 361 of its inter-chip interconnects 371 as illustrated in FIG. 6B, 8B or 9D, (5) a fifteenth small input/output (SIO) circuit, or input/output (I/O) pad, coupling to a fifth one of its bonded metal bumps or contacts 574 as illustrated in FIG. 6B, a fifth one of its high-density bonded metal bumps or contacts 574a as illustrated in FIG. 8B or a fifth one of the metal bumps, pillars or pads 570 or 571, solder balls 538 or metal contacts 452 of its FPGA/NVM multi-chip package 259 as illustrated in FIG. 9D, which may couple to a fourth small input/output (SIO) circuit, or input/output (I/O) pad, of the second one of its semiconductor IC chips through another of the programmable interconnects 361 of its inter-chip interconnects 371 as illustrated in FIG. 6B, 8B or 9D, and (6) a sixteenth small input/output (SIO) circuit, or input/output (I/O) pad, coupling to a sixth one of its bonded metal bumps or contacts 574 as illustrated in FIG. 6B, a sixth one of its high-density bonded metal bumps or contacts 574a as illustrated in FIG. 8B or a sixth one of the metal bumps, pillars or pads 570 or 571, solder balls 538 or metal contacts 452 of its FPGA/NVM multi-chip package 259 as illustrated in FIG. 9D, which may couple to an eleventh small input/output (SIO) circuit, or input/output (I/O) pad, of the first one of its semiconductor IC chips through another of the programmable interconnects 361 of its inter-chip interconnects 371 as illustrated in FIG. 6B, 8B or 9D. Further, said any of the FPGA IC chip(s) 200, 100i and/or 100j of its FPGA/NVM multi-chip package 259 may include (1) a first one of the first, second or third type of field programmable logic cells or elements (LCEs) 2014 thereof, as illustrated in FIGS. 1A-1C, having the data input t passed from the eleventh small input/output (SIO) circuit thereof through one of the programmable interconnects 361 thereof and the data output, i.e., Dout, passed to the twelfth small input/output (SIO) circuit thereof through another of the programmable interconnects 361 thereof, (2) a second one of the first, second or third type of field programmable logic cells or elements (LCEs) 2014 thereof having the data input A0 passed from the thirteenth small input/output (SIO) circuit thereof through another of the programmable interconnects 361 thereof and the data output, i.e., Dout, passed to the fourteenth small input/output (SIO) circuit thereof through another of the programmable interconnects 361 thereof, and (3) a third one of the first, second or third type of field programmable logic cells or elements (LCEs) 2014 thereof having the data input A0 passed from the fifteenth small input/output (SIO) circuit thereof through another of the programmable interconnects 361 thereof and the data output, i.e., Dout, passed to the sixteenth small input/output (SIO) circuit thereof through another of the programmable interconnects 361 thereof. Accordingly, the first one of the first, second or third type of field programmable logic cells or elements (LCEs) 2014 of said any of the FPGA IC chip(s) 200, 100i and/or 100j of its FPGA/NVM multi-chip package 259 may be programmed, configured or reconfigured in accordance with CPM data stored in the memory cells 490 thereof to select or process data in accordance with the input data set thereof, i.e., A0 and A1 or A0-A3, having the data input A0 from the eighth small input/output (SIO) circuit of the first one of its semiconductor IC chips through the eleventh small input/output (SIO) circuit of said any of the FPGA IC chip(s) 200, 100i and/or 100j of its FPGA/NVM multi-chip package 259, as or into the data output, i.e., Dout, to be passed back to the ninth small input/output (SIO) circuit of the first one of its semiconductor IC chips through the twelfth small input/output (SIO) circuit of said any of the FPGA IC chip(s) 200, 100i and/or 100j of its FPGA/NVM multi-chip package 259. The second one of the first, second or third type of field programmable logic cells or elements (LCEs) 2014 of said any of the FPGA IC chip(s) 200, 100i and/or 100j of its FPGA/NVM multi-chip package 259 may be programmed, configured or reconfigured in accordance with CPM data stored in the memory cells 490 thereof to select or process data in accordance with the input data set thereof, i.e., A0 and A1 or A0-A3, having the data input A0 from the tenth small input/output (SIO) circuit of the first one of its semiconductor IC chips through the thirteenth small input/output (SIO) circuit of said any of the FPGA IC chip(s) 200, 100i and/or 100j of its FPGA/NVM multi-chip package 259, as or into the data output, i.e., Dout, to be passed to the third small input/output (SIO) circuit of the second one of its semiconductor IC chips through the fourteenth small input/output (SIO) circuit of said any of the FPGA IC chip(s) 200, 100i and/or 100j of its FPGA/NVM multi-chip package 259. The third one of the first, second or third type of field programmable logic cells or elements (LCEs) 2014 of said any of the FPGA IC chip(s) 200, 100i and/or 100j of its FPGA/NVM multi-chip package 259 may be programmed, configured or reconfigured in accordance with CPM data stored in the memory cells 490 thereof to select or process data in accordance with the input data set thereof, i.e., A0 and A1 or A0-A3, having the data input A0 from the fourth small input/output (SIO) circuit of the second one of its semiconductor IC chips through the fifteenth small input/output (SIO) circuit of said any of the FPGA IC chip(s) 200, 100i and/or 100j of its FPGA/NVM multi-chip package 259, as or into the data output, i.e., Dout, to be passed to the eleventh small input/output (SIO) circuit of the first one of its semiconductor IC chips through the sixteenth small input/output (SIO) circuit of said any of the FPGA IC chip(s) 200, 100i and/or 100j of its FPGA/NVM multi-chip package 259. Thereby, changing the configuration of the first, second and third ones of the first, second or third type of field programmable logic cells or elements (LCEs) 2014 by changing the CPM data stored in the memory cells 490 of the first, second and third ones of the first type of field programmable logic cells or elements (LCEs) 2014 or by changing the CPM data stored in the memory cells of the first, second and third ones of the second or third type of field programmable logic cells or elements (LCEs) 2014 makes it possible for each of the first type of FPMCPs 300 for the third and fourth alternatives to be used for various applications thus resulting in great application flexibility.

Further, referring to FIGS. 5A-3 and 5A-4, for said each of the first type of FPMCPs 300 for the third and fourth alternatives, each of the first through sixteenth small input/output (SIO) circuits of said any of the FPGA IC chip(s) 200, 100i and/or 100j of its FPGA/NVM multi-chip package 259, each of the first through eleventh small input/output (SIO) circuits of the first one of its semiconductor IC chips and each of the first through fourth small input/output (SIO) circuits of the second one of its semiconductor IC chips may have an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts, respectively.

Referring to FIGS. 5A-3 and 5A-4, for said each of the first type of FPMCPs 300 for the third and fourth alternatives, the first one of its semiconductor IC chips may be one of its graphic-processing-unit (GPU) IC chips 269a and the second one of its semiconductor IC chips may be one of its central-processing-unit (CPU) IC chip 269b, its application-specific integrated-circuit (ASIC) chip or system-on-chip (SoC) chip 269c, its auxiliary IC chips 603, its high bandwidth memory (HBM) IC chip(s) 602, its dedicated control and input/output (I/O) chip 260, its digital-signal-processing (DSP) IC chip 270, its IAC chip 402, another of its graphic-processing-unit (GPU) IC chips 269a and its FPGA IC chip 601 selected in combination for one of the third and fourth alternatives. Alternatively, the first one its semiconductor IC chips may be its central-processing-unit (CPU) IC chip 269b and the second one of its semiconductor IC chips may be one of its graphic-processing-unit (GPU) IC chips 269a, its application-specific integrated-circuit (ASIC) chip or system-on-chip (SoC) chip 269c, its auxiliary IC chips 603, its high bandwidth memory (HBM) IC chip(s) 602, its dedicated control and input/output (I/O) chip 260, its digital-signal-processing (DSP) IC chip 270 and its FPGA IC chip 601 selected in combination for one of the third and fourth alternatives. Alternatively, the first one of its semiconductor IC chips may be its application-specific integrated-circuit (ASIC) chip or system-on-chip (SoC) chip 269c and the second one of its semiconductor IC chips may be one of its graphic-processing-unit (GPU) IC chips 269a, its central-processing-unit (CPU) IC chip 269b, its auxiliary IC chips 603, its high bandwidth memory (HBM) IC chip(s) 602, its dedicated control and input/output (I/O) chip 260, and its FPGA IC chip 601 selected in combination for one of the third and fourth alternatives. Alternatively, the first one of its semiconductor IC chips may be one of its auxiliary IC chips 603 and the second one of its semiconductor IC chips may be one of its graphic-processing-unit (GPU) IC chips 269a, its central-processing-unit (CPU) IC chip 269b, its application-specific integrated-circuit (ASIC) chip or system-on-chip (SoC) chip 269c, its high bandwidth memory (HBM) IC chip(s) 602, its dedicated control and input/output (I/O) chip 260, its digital-signal-processing (DSP) IC chip 270, another of its auxiliary IC chips 603 and its FPGA IC chip 601 selected in combination for one of the third and fourth alternatives. Alternatively, the first one of its semiconductor IC chips may be one of its high bandwidth memory (HBM) IC chip(s) 602 and the second one of its semiconductor IC chips may be one of its graphic-processing-unit (GPU) IC chips 269a, its central-processing-unit (CPU) IC chip 269b, its application-specific integrated-circuit (ASIC) chip or system-on-chip (SoC) chip 269c, its auxiliary IC chips 603, the other of its high bandwidth memory (HBM) IC chip(s) 602, its dedicated control and input/output (I/O) chip 260, its digital-signal-processing (DSP) IC chip 270 and its FPGA IC chip 601 selected in combination for one of the third and fourth alternatives. Alternatively, the first one of its semiconductor IC chips may be its FPGA IC chip 601 and the second one of its semiconductor IC chips may be one of its graphic-processing-unit (GPU) IC chips 269a, its central-processing-unit (CPU) IC chip 269b, its application-specific integrated-circuit (ASIC) chip or system-on-chip (SoC) chip 269c, its auxiliary IC chips 603, its high bandwidth memory (HBM) IC chips 602, its dedicated control and input/output (I/O) chip 260 and its digital-signal-processing (DSP) IC chip 270 selected in combination for one of the third and fourth alternatives. Alternatively, the first one of its semiconductor IC chips may be its digital-signal-processing (DSP) IC chip 270 for the fourth alternative and the second one of its semiconductor IC chips may be one of its graphic-processing-unit (GPU) IC chips 269a, its central-processing-unit (CPU) IC chip 269b, its auxiliary IC chips 602, its high bandwidth memory (HBM) IC chip(s) 602, its dedicated control and input/output (I/O) chip 260 and its FPGA IC chip 601 selected in combination for the fourth alternative.

### Second Type of FPMCP

FIGS. 10 and 10A are schematically cross-sectional views showing a second type of FPMCP in accordance with an embodiment of the present application. Referring to FIGS. 10 and 10A, the second type of FPMCP 305 may include a similar interconnection substrate 177 to one as illustrated in FIG. 9A. For an element indicated by the same reference number shown in FIGS. 9A, 10 and 10A, the specification of the element as seen in FIGS. 10 and 10A may be referred to that of the element as illustrated in FIG. 9A. The difference therebetween is that the NVM IC chip 250 of the fourth structure 304 for each of the first type of FPMCPs 300 for the first and second alternatives and one of the auxiliary IC chip 411 of the fourth structure 304 for each of the first type of FPMCPs 300 for the first and second alternatives may be arranged in the interconnection substrate 177 for the second type of FPMCP 305 as seen in FIGS. 10 and 10A. For the second type of FPMCP 305, its NVM IC chip 250 may have the same specification as the third type of semiconductor IC chip 100 as illustrated in FIG. 3C and its auxiliary IC chip 411 may have the same specification as the fourth type of semiconductor IC chip 100 as illustrated in FIGS. 3D and 3G-3J.

Referring to FIGS. 10 and 10A, the second type of FPMCP 305 may further include a FPGA IC chip 200 having the specification as illustrated for one in FIG. 5A-1 over its interconnection substrate 177, and a logic computing IC chip 269, such as the graphic-processing-unit (GPU) IC chip 269a, central-processing-unit (CPU) IC chip 269b or application-specific integrated-circuit (ASIC) chip or system-on-chip (SoC) chip 269c as illustrated in FIG. 5A-1 or such as data processing unit (DPU) IC chip, tensor flow processing unit (TPU) IC chip or digital-signal-processing (DSP) chip, over its interconnection substrate 177. For the second type of FPMCP 305, each of its FPGA IC chip 200 and logic computing IC chip 269 may have the same specification as the first type of semiconductor IC chip 100 illustrated in FIG. 3A to be turned upside down. For the second type of FPMCP 305, its FPGA IC chip 200 may be the dedicated field programmable integrated-circuit (DFPIC) chip as illustrated in FIG. 4D or embedded field programmable integrated-circuit (eFPIC) chip as illustrated in FIG. 4E.

Referring to FIGS. 10 and 10A, for the second type of FPMCP 305, its NVM IC chip 250 may be embedded in its interconnection substrate 177 and under its FPGA IC chip 200, and its auxiliary IC chip 411 may be embedded in its interconnection substrate 177 and under its logic computing IC chip 269. The polymer layer 92, i.e., insulating dielectric layer or sealing layer, of its interconnection substrate 177 may be horizontally around each of the vertical-through-via (VTV) connectors 467 of its interconnection substrate 177 and each of its NVM IC chip 250 and auxiliary IC chip 411 and in each gap between neighboring two of the vertical-through-via (VTV) connectors 467 of its interconnection substrate 177 and its NVM IC chip 250 and auxiliary IC chip 411, wherein the polymer layer 92 of its interconnection substrate 177 may have a top surface coplanar with the top surface of the polymer layer 257 of each of the vertical-through-via (VTV) connectors 467 of its interconnection substrate 177, the top surface of each of the first type of micro-bumps, micro-pillars or micro-pads 34 of each of the vertical-through-via (VTV) connectors 467 of its interconnection substrate 177, the top surface of the polymer layer 257 of each of its NVM IC chip 250 and auxiliary IC chip 411 and the top surface of each of the first type of micro-bumps, micro-pillars or micro-pads 34 of each of its NVM IC chip 250 and auxiliary IC chip 411. Each of the semiconductor substrate 2 of each of its NVM IC chip 250 and auxiliary IC chip 411 and the semiconductor substrate 2 of each of the vertical-through-via (VTV) connectors 467 of its interconnection substrate 177 may have a portion, at a backside of said each of the vertical-through-via (VTV) connectors 467, removed by a chemical-mechanical-polishing (CMP) or mechanical grinding process such that each of the through silicon vias (TSVs) 157, that is, the electroplated copper layer 156 thereof, of its auxiliary IC chip 411 may have a bottom surface substantially coplanar with a bottom surface of each of the through silicon vias (TSVs) 157, that is, the electroplated copper layer 156 thereof, of each of the vertical-through-via (VTV) connectors 467 of its interconnection substrate 177, a bottom surface of the semiconductor substrate 2 of each of its NVM IC chip 250 and auxiliary IC chip 411 and a bottom surface of the semiconductor substrate 2 of each of the vertical-through-via (VTV) connectors 467 of its interconnection substrate 177 and a bottom surface of the polymer layer 92 of its interconnection substrate 177, as seen in FIG. 10. For an alternative case, its interconnection substrates 177 may further include the insulating dielectric layer 185, such as silicon-oxide layer or silicon-nitride layer, illustrated in FIG. 4C formed on a bottom surface of the semiconductor substrate 2 of each of the vertical-through-via (VTV) connectors 467 of its interconnection substrate 177 and a bottom surface of the semiconductor substrate 2 of each of its NVM IC chip 250 and auxiliary IC chip 411, wherein the insulating dielectric layer 185 of its interconnection substrate 177 may have a bottom surface coplanar with the bottom surface of each of the through silicon vias 157 of each of the vertical-through-via (VTV) connectors 467 of its interconnection substrate 177, the bottom surface of each of the through silicon vias 157 of its auxiliary IC chip 411 and the bottom surface of the polymer layer 92 of its interconnection substrate 177, as seen in FIG. 10A. As seen in FIG. 10, the topmost one of the polymer layers 42 of the interconnection scheme 79 of its interconnection substrate 177 may have a top surface in contact with the bottom surface of the polymer layer 92 of its interconnection substrate 177, the bottom surface of the semiconductor substrate 2 of each of the vertical-through-via (VTV) connectors 467 of its interconnection substrate 177 and the bottom surface of the semiconductor substrate 2 of each of its NVM IC chip 250 and auxiliary IC chip 411. For the alternative case, as seen in FIG. 10A, the topmost one of the polymer layers 42 of the interconnection scheme 79 of its interconnection substrate 177 may have a top surface in contact with the bottom surface of the polymer layer 92 of its interconnection substrate 177 and the bottom surface of the insulating dielectric layer 185 of its interconnection substrate 177.

Referring to FIGS. 10 and 10A, each opening in the topmost one of the polymer layers 42 of the interconnection scheme 79 of its interconnection substrate 177 may be under one of the through silicon vias (TSVs) 157 of one of the vertical-through-via (VTV) connectors 467 of its interconnection substrate 177 or one of the through silicon vias (TSVs) 157 of its auxiliary IC chip 411, and thus the topmost one of the interconnection metal layers 27 of the interconnection scheme 79 of its interconnection substrate 177 may extend through said each opening to couple to said one of the through silicon vias (TSVs) 157. Each of the interconnection metal layers 27 of the interconnection scheme 79 of its interconnection substrate 177 may extend horizontally across an edge of each of its NVM IC chip 250 and auxiliary IC chip 411 and an edge of each of the vertical-through-via (VTV) connectors 467 of its interconnection substrate 177. Its interconnection substrate 177 may further include an interconnection scheme 80 over its NVM IC chip 250, its auxiliary IC chip 411, each of the vertical-through-via (VTV) connectors 467 of its interconnection substrate 177 and the polymer layer 92 of its interconnection substrate 177. Each of the first type of micro-bumps, micro-pillars or micro-pads 34 of each of its NVM IC chip 250 and auxiliary IC chip 411 and each of the first type of micro-bumps, micro-pillars or micro-pads 34 of each of the vertical-through-via (VTV) connectors 467 of its interconnection substrate 177 may couple to its interconnection scheme 80. The interconnection scheme 80 may include (1) multiple interconnection metal layers 27 coupling to each of the first type of micro-bumps, micro-pillars or micro-pads 34 of each of its NVM IC chip 250 and auxiliary IC chip 411 and each of the first type of micro-bumps, micro-pillars or micro-pads 34 of each of the vertical-through-via (VTV) connectors 467 of its interconnection substrate 177 and (2) one or more polymer layers 42, i.e., insulating dielectric layers, each between neighboring two of the interconnection metal layers 27 of the interconnection scheme 80 of its interconnection substrate 177, under the bottommost one of the interconnection metal layers 27 of the interconnection scheme 80 of its interconnection substrate 177 or over the topmost one of the interconnection metal layers 27 of the interconnection scheme 80 of its interconnection substrate 177, wherein an upper one of the interconnection metal layers 27 of the interconnection scheme 80 of its interconnection substrate 177 may couple to a lower one of the interconnection metal layers 27 of the interconnection scheme 80 of its interconnection substrate 177 through an opening in one of the polymer layers 42 of the interconnection scheme 80 of its interconnection substrate 177 between the upper and lower ones of the interconnection metal layers 27 of the interconnection scheme 80 of its interconnection substrate 177. The bottommost one of the polymer layers 42 of the interconnection scheme 80 of its interconnection substrate 177 may have a bottom surface in contact with the top surface of the polymer layer 257 of each of its NVM IC chip 250 and auxiliary IC chip 411, the top surface of the polymer layer 257 of each of the vertical-through-via (VTV) connectors 467 of its interconnection substrate 177 and the top surface of the polymer layer 92 of its interconnection substrate 177. Each opening in the bottommost one of the polymer layers 42 of the interconnection scheme 80 of its interconnection substrate 177 may be over one of the first type of micro-bumps, micro-pillars or micro-pads 34 of one of its NVM IC chip 250 and auxiliary IC chip 411 or one of the first type of micro-bumps, micro-pillars or micro-pads 34 of one of the vertical-through-via (VTV) connectors 467 of its interconnection substrate 177, and thus the bottommost one of the interconnection metal layers 27 of the interconnection scheme 80 of its interconnection substrate 177 may couple to said one of the first type of micro-bumps, micro-pillars or micro-pads 34 through said each opening. Each of the interconnection metal layers 27 of the interconnection scheme 80 of its interconnection substrate 177 may extend horizontally across an edge of each of its NVM IC chip 250 and auxiliary IC chip 411. The topmost one of the interconnection metal layers 27 of the interconnection scheme 80 of its interconnection substrate 177 may have multiple metal pads at bottoms of multiple respective openings in the topmost one of the polymer layers 42 of the interconnection scheme 80 of its interconnection substrate 177. The specification and process for the interconnection metal layers 27 and polymer layers 42 for the interconnection scheme 80 of its interconnection substrate 177 may be referred to those for the second interconnection scheme for a chip (SISC) 29 as illustrated in FIG. 3A. Each of the polymer layers 42 of the interconnection scheme 80 of its interconnection substrate 177 may be a layer of polyimide, benzocyclobutene (BCB), parylene, epoxy-based material or compound, photo epoxy SU-8, elastomer or silicone, having a thickness between, for example, 0.3 μm and 30 μm, 0.5 μm and 20 μm, 1 m and 10 μm, or 0.5 um and 5 μm, or thicker than or equal to 0.3 μm, 0.5 μm, 0.7 μm, 1 μm, 1.5 μm, 2 μm, 3 μm or 5 μm. Each of the interconnection metal layers 27 of the interconnection scheme 80 of its interconnection substrate 177 may be provided with multiple metal traces or lines each including (1) a copper layer 40 having one or more lower portions in openings in one of the polymer layers 42 of the interconnection scheme 80 of its interconnection substrate 177 and an upper portion having a thickness between 0.3 μm and 20 μm over said one of the polymer layers 42, (2) an adhesion metal layer 28a, such as titanium or titanium nitride having a thickness between 1 nm and 50 nm, at a bottom and sidewall of each of the one or more lower portions of the copper layer 40 of said each of the metal traces or lines and at a bottom of the upper portion of the copper layer 40 of said each of the metal traces or lines, and (3) an electroplating seed layer 28b, such as copper, between the copper layer 40 and adhesion metal layer 28a of said each of the metal traces or lines, wherein the upper portion of the copper layer 40 of said each of the metal traces or lines may have a sidewall not covered by the adhesion metal layer 28a of said each of the metal traces or lines. Each of the metal traces or lines of each of the interconnection metal layers 27 of the interconnection scheme 80 of its interconnection substrate 177 may have a thickness between, for example, 0.3 μm and 30 μm, 0.5 μm and 20 μm, 1 μm and 10 μm, or 0.5 μm and 5 μm, or thicker than or equal to 0.3 μm, 0.5 μm, 0.7 μm, 1 μm, 1.5 μm, 2 μm, 3 μm or 5 μm, and a width between, for example, 0.3 μm and 30 μm, 0.5 μm and 20 μm, 1 μm and 10 μm, or 0.5 μm and 5 μm, or wider than or equal to 0.3 μm, 0.5 μm, 0.7 μm, 1 μm, 1.5 μm, 2 μm, 3 μm or 5 μm. The adhesion metal layer 28a of the bottommost one of the interconnection metal layers 27 of the interconnection scheme 80 of its interconnection substrate 177 may be provided on and in contact with the copper layer 32 of each of the first type of micro-bumps, micro-pillars or micro-pads 34 of each of the vertical-through-via (VTV) connectors 467 of its interconnection substrate 177 and its NVM IC chip 250 and auxiliary IC chip 411 and between the copper layer 40 of the bottommost one of the interconnection metal layers 27 of the interconnection scheme 80 of its interconnection substrate 177 and the copper layer 32 of each of the first type of micro-bumps, micro-pillars or micro-pads 34 of each of the vertical-through-via (VTV) connectors 467 of its interconnection substrate 177 and its NVM IC chip 250 and auxiliary IC chip 411.

Referring to FIGS. 10 and 10A, for the second type of FPMCP 305, each of its FPGA IC chip 200 and logic computing IC chip 269 may have the first, second, third or fourth type of micro-bumps, micro-pillars or micro-pads 34 as illustrated in FIG. 3A each bonded to one of the metal pads of the topmost one of the interconnection metal layers 27 of the interconnection scheme 80 of its interconnection substrate 177. The bottom surface of the semiconductor substrate 2 of its FPGA IC chip 200, at which the semiconductor devices 4, such as transistors, of its FPGA IC chip 200 are formed as illustrated in FIG. 3A to be turned upside down, faces the top surface of the semiconductor substrate 2 of its NVM IC chip 250, at which the semiconductor devices 4, such as transistors, of its NVM IC chip 250 are formed as illustrated in FIG. 3C. The bottom surface of the semiconductor substrate 2 of its logic computing IC chip 269, at which the semiconductor devices 4, such as transistors, of its logic computing IC chip 269 are formed as illustrated in FIG. 3A to be turned upside down, faces the top surface of the semiconductor substrate 2 of its auxiliary IC chip 411, at which the semiconductor devices 4, such as transistors, of its auxiliary IC chip 411 are formed as illustrated in FIGS. 3D and 3G-3J. Its underfill 564, i.e., polymer layer, may be formed between its FPGA IC chip 200 and the interconnection scheme 80 of its interconnection substrate 177 and between its logic computing IC chip 269 and the interconnection scheme 80 of its interconnection substrate 177, covering a sidewall of each of the first, second, third or fourth type of micro-bumps, micro-pillars or micro-pads 34 of each of its FPGA IC chip 200 and logic computing IC chip 269. Its polymer layer 192, i.e., insulating dielectric layer or sealing layer, may be formed on the interconnection scheme 80 of its interconnection substrate 177 and horizontally around its FPGA IC chip 200 and logic computing IC chip 269, wherein its polymer layer 192 may have a top surface coplanar with a top surface of each of its FPGA IC chip 200 and logic computing IC chip 269. Its polymer layer 192 may have a vertical sidewall coplanar with a vertical sidewall of each of the polymer layer 92 and interconnection schemes 79 and 80 of its interconnection substrate 177.

Referring to FIGS. 10 and 10A, for the second type of FPMCP 305, each of its FPGA IC chip 200 and logic computing IC chip 269 may couple to one of its metal bumps, pillars or pads 570, which are in an array at its bottom to act as its external pins for coupling to external circuits outside of the second type of FPMCP 305, through, in sequence, each of the interconnection metal layers 27 of the interconnection scheme 80 of its interconnection substrate 177, one of the through silicon vias (TSVs) 157 of one of the vertical-through-via (VTV) connectors 467 of its interconnection substrate 177 and each of the interconnection metal layers 27 of the interconnection scheme 79 of its interconnection substrate 177 for transmitting a signal or clock or delivering a power or ground voltage therebetween. Alternatively, each of its FPGA IC chip 200 and logic computing IC chip 269 may couple to one of its metal bumps, pillars or pads 570, which are in an array at its bottom to act as its external pins for coupling to external circuits outside of the second type of FPMCP 305, through, in sequence, each of the interconnection metal layers 27 of the interconnection scheme 80 of its interconnection substrate 177, one of the through silicon vias (TSVs) 157 of its auxiliary IC chip 411 and each of the interconnection metal layers 27 of the interconnection scheme 79 of its interconnection substrate 177 for transmitting a signal or clock or delivering a power or ground voltage therebetween.

Referring to FIGS. 10 and 10A, the second type of FPMCP 305 may have the inter-chip interconnection between the first and second semiconductor IC chips 100a and 100b via the FPGA IC chip 200 as illustrated in FIG. 5B. For the second type of FPMCP 305, its FPGA IC chip 200 may have the same circuits as illustrated for one in FIG. 5B, its logic computing IC chip 269 may be the first semiconductor IC chip 100a as illustrated in FIG. 5B, and one of its NVM IC chip 250 and auxiliary IC chip 411 may be the second semiconductor IC chip 100b as illustrated in FIG. 5B. Any of the first, second, third or fourth type of micro-bumps, micro-pillars or micro-pads 34 of the FPGA IC chip 200, one or more of the interconnection metal layers 27 of the interconnection scheme 80 and any of the first, second, third or fourth type of micro-bumps, micro-pillars or micro-pads 34 of the first semiconductor IC chip 100a for the second type of FPMCP 305 as illustrated in FIGS. 10 and 10A may be formed for one of the programmable interconnects 361 of the inter-chip interconnects 371 between the FPGA IC chip 200 and first semiconductor IC chip 100a as illustrated in FIG. 5B, and any of the first, second, third or fourth type of micro-bumps, micro-pillars or micro-pads 34 of the FPGA IC chip 200, each of the interconnection metal layers 27 of the interconnection scheme 80 and any of the first type of micro-bumps, micro-pillars or micro-pads 34 of the second semiconductor IC chip 100b for the second type of FPMCP 305 as illustrated in FIGS. 10 and 10A may be formed for one of the programmable interconnects 361 of the inter-chip interconnects 371 between the FPGA IC chip 200 and second semiconductor IC chip 100b as illustrated in FIG. 5B. Alternatively, its auxiliary IC chip 411 may be the first semiconductor IC chip 100a as illustrated in FIG. 5B, and its NVM IC chip 250 may be the second semiconductor IC chip 100b as illustrated in FIG. 5B. Any of the first, second, third or fourth type of micro-bumps, micro-pillars or micro-pads 34 of the FPGA IC chip 200, each of the interconnection metal layers 27 of the interconnection scheme 80 and any of the first type of micro-bumps, micro-pillars or micro-pads 34 of the first semiconductor IC chip 100a for the second type of FPMCP 305 as illustrated in FIGS. 10 and 10A may be formed for one of the programmable interconnects 361 of the inter-chip interconnects 371 between the FPGA IC chip 200 and first semiconductor IC chip 100a as illustrated in FIG. 5B, and any of the first, second, third or fourth type of micro-bumps, micro-pillars or micro-pads 34 of the FPGA IC chip 200, each of the interconnection metal layers 27 of the interconnection scheme 80 and any of the first type of micro-bumps, micro-pillars or micro-pads 34 of the second semiconductor IC chip 100b for the second type of FPMCP 305 as illustrated in FIGS. 10 and 10A may be formed for one of the programmable interconnects 361 of the inter-chip interconnects 371 between the FPGA IC chip 200 and second semiconductor IC chip 100b as illustrated in FIG. 5B.

Referring to FIGS. 10 and 10A, the second type of FPMCP 305 may perform the operation between the FPGA IC chip 200 and each of the third and fourth semiconductor IC chips 100c and 100d as illustrated in FIG. 5C. For the second type of FPMCP 305, its FPGA IC chip 200 may have the same circuits as one illustrated in FIG. 5C, its logic computing IC chip 269 may be the third semiconductor IC chip 100c as illustrated in FIG. 5C, and one of its NVM IC chip 250 and auxiliary IC chip 411 may be the fourth semiconductor IC chip 100d as illustrated in FIG. 5C. Any of the first, second, third or fourth type of micro-bumps, micro-pillars or micro-pads 34 of the FPGA IC chip 200, one or more of the interconnection metal layers 27 of the interconnection scheme 80 and any of the first, second, third or fourth type of micro-bumps, micro-pillars or micro-pads 34 of the third semiconductor IC chip 100c for the second type of FPMCP 305 as illustrated in FIGS. 10 and 10A may be formed for one of the programmable interconnects 361 of the inter-chip interconnects 371 between the FPGA IC chip 200 and third semiconductor IC chip 100c as illustrated in FIG. 5C, and any of the first, second, third or fourth type of micro-bumps, micro-pillars or micro-pads 34 of the FPGA IC chip 200, each of the interconnection metal layers 27 of the interconnection scheme 80 and any of the first type of micro-bumps, micro-pillars or micro-pads 34 of the fourth semiconductor IC chip 100d for the second type of FPMCP 305 as illustrated in FIGS. 10 and 10A may be formed for one of the programmable interconnects 361 of the inter-chip interconnects 371 between the FPGA IC chip 200 and fourth semiconductor IC chip 100d as illustrated in FIG. 5C.

Referring to FIGS. 10 and 10A, the second type of FPMCP 305 may have the connection to external circuits as illustrated in FIG. 5D. For the third type of FPMCP 305, its FPGA IC chip 200 may have the same circuits as one illustrated in FIG. 5D, its auxiliary IC chip 411 may have the same circuits as one illustrated in FIG. 5D, its logic computing IC chip 269 may be the fifth semiconductor IC chip 100e as illustrated in FIG. 5D, and its NVM IC chip 250 may be the sixth semiconductor IC chip 100f as illustrated in FIG. 5D. Any of the first, second, third or fourth type of micro-bumps, micro-pillars or micro-pads 34 of the FPGA IC chip 200, one or more of the interconnection metal layers 27 of the interconnection scheme 80 and any of the first, second, third or fourth type of micro-bumps, micro-pillars or micro-pads 34 of the fifth semiconductor IC chip 100e for the second type of FPMCP 305 as illustrated in FIGS. 10 and 10A may be formed for one of the programmable interconnects 361 of the inter-chip interconnects 371 between the FPGA IC chip 200 and fifth semiconductor IC chip 100e as illustrated in FIG. 5D, any of the first, second, third or fourth type of micro-bumps, micro-pillars or micro-pads 34 of the FPGA IC chip 200, each of the interconnection metal layers 27 of the interconnection scheme 80 and any of the first type of micro-bumps, micro-pillars or micro-pads 34 of the sixth semiconductor IC chip 100f for the second type of FPMCP 305 as illustrated in FIGS. 10 and 10A may be formed for one of the programmable interconnects 361 of the inter-chip interconnects 371 between the FPGA IC chip 200 and sixth semiconductor IC chip 100f as illustrated in FIG. 5D and any of the first, second, third or fourth type of micro-bumps, micro-pillars or micro-pads 34 of the FPGA IC chip 200, each of the interconnection metal layers 27 of the interconnection scheme 80 and any of the first type of micro-bumps, micro-pillars or micro-pads 34 of the auxiliary IC chip 411 for the second type of FPMCP 305 as illustrated in FIGS. 10 and 10A may be formed for one of the programmable interconnects 361 of the inter-chip interconnects 371 between the FPGA IC chip 200 and auxiliary IC chip 411 as illustrated in FIG. 5D. Each of the large input/output (I/O) circuits 341 of the large-input/output (I/O) block of its auxiliary IC chip 411 may couple to one of its metal bumps, pillars or pads 570, which are in an array at its bottom to act as its external pins for coupling to the external circuits 340 as seen in FIG. 5D outside of the second type of FPMCP 305, through, in sequence, one of the through silicon vias (TSVs) 157 of its auxiliary IC chip 411 and each of the interconnection metal layers 27 of the interconnection scheme 79 of its interconnection substrate 177.

Referring to FIGS. 10 and 10A, for the second type of FPMCP 305, its auxiliary IC chip 411 may include a first small input/output (I/O) circuit coupling to a second small input/output (I/O) circuit of its FPGA IC chip 200 through its first signal path composed of one of the first, second, third or fourth type of micro-bumps, micro-pillars or micro-pads 34 of its FPGA IC chip 200, multiple metal traces or lines made from each of the interconnection metal layers 27 of the interconnection scheme 80 of its interconnection substrate 177 and one of the first type of micro-bumps, micro-pillars or micro-pads 34 of its auxiliary IC chip 411, wherein each of the first and second small input/output (I/O) circuits may have an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts. Its auxiliary IC chip 411 may include a large input/output (I/O) circuit coupling to any of its metal bumps, pillars or pads 570 through its second signal path composed of any of the through silicon vias (TSVs) 157 of its auxiliary IC chip 411 and each of the interconnection metal layers 27 of the interconnection scheme 79 of its interconnection substrate 177, wherein the large input/output (I/O) circuit may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or equal to or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Thereby, the first small input/output (I/O) circuit may receive first signals from the second small input/output (I/O) circuit via its first signal path to be converted by its auxiliary IC chip 411 as second signals and then the large input/output (I/O) circuit may transmit the second signals to said any of its metal bumps, pillars or pads 570 via its second signal path. Further, the large input/output (I/O) circuit may receive third signals from said any of its metal bumps, pillars or pads 570 via its second signal path to be converted by its auxiliary IC chip 411 as fourth signals and then the first small input/output (I/O) circuit may transmit the fourth signals to the second small input/output (I/O) circuit via its first signal path.

Referring to FIGS. 10 and 10A, for the second type of FPMCP 305, its FPGA IC chip 200 may be programmed, configured or reconfigured following the same way as any aspect of the first through eleventh aspects illustrated in FIGS. 5A-1, 5A-2 and 5E-5G, including (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with first data stored in its NVM IC chip 250 to be configured in accordance with the first data, (2) the first or second type of field programmable switch cell 379 as illustrated in FIG. 2A or 2B having the memory cells 362 as illustrated in FIG. 2A or the four sets of memory cells 362 as illustrated in FIG. 2B for storing data associated with second data stored in its NVM IC chip 250 to be configured in accordance with the second data, and (3) the programmable switch matrix 710 as illustrated in FIG. 2C having the memory cells 398 for storing data, i.e., programming codes, password or encryption/decryption codes, associated with third data stored in its NVM IC chip 250 to be configured in accordance with the third data. Alternatively, its FPGA IC chip 200 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MILU) IC chip, or digital-signal-processing (DSP) IC chip, each of which may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with the first data to be configured in accordance with the first data, (2) the first or second type of field programmable switch cell 379 as illustrated in FIG. 2A or 2B having the memory cells 362 as illustrated in FIG. 2A or the four sets of memory cells 362 as illustrated in FIG. 2B for storing data associated with the second data to be configured in accordance with the second data, and (3) the programmable switch matrix 710 as illustrated in FIG. 2C having the memory cells 398 for storing data, i.e., programming codes, password or encryption/decryption codes, associated with the third data to be configured in accordance with the third data. For the second type of FPMCP 305 for each aspect of the first through fourth aspects as illustrated in FIG. 5E, its FPGA IC chip 200 may have the same circuits as one illustrated in FIG. 5E, its auxiliary IC chip 411 may have the same circuits as one illustrated in FIG. 5E, its NVM IC chip 250 may have the same circuits as one illustrated in FIG. 5E, and its logic computing IC chip 269 may be any of the semiconductor IC chips 100g as illustrated in FIG. 5E. Any of the first, second, third or fourth type of micro-bumps, micro-pillars or micro-pads 34 of the FPGA IC chip 200, each of the interconnection metal layers 27 of the interconnection scheme 80 and any of the first type of micro-bumps, micro-pillars or micro-pads 34 of the auxiliary IC chip 411 for the second type of FPMCP 305 as illustrated in FIGS. 10 and 10A may be formed for one of the non-programmable interconnects 364 of the inter-chip interconnects 371 between the FPGA IC chip 200 and auxiliary IC chip 411 as illustrated in FIG. 5E; any of the first type of micro-bumps, micro-pillars or micro-pads 34 of the NVM IC chip 250, one or more of the interconnection metal layers 27 of the interconnection scheme 80 and any of the first type of micro-bumps, micro-pillars or micro-pads 34 of the auxiliary IC chip 411 for the second type of FPMCP 305 as illustrated in FIGS. 10 and 10A may be formed for one of the non-programmable interconnects 364 of the inter-chip interconnects 371 between the NVM IC chip 250 and auxiliary IC chip 411 as illustrated in FIG. 5E; any of the first, second, third or fourth type of micro-bumps, micro-pillars or micro-pads 34 of the FPGA IC chip 200, one or more of the interconnection metal layers 27 of the interconnection scheme 80 and any of the first, second, third or fourth type of micro-bumps, micro-pillars or micro-pads 34 of the logic computing IC chip 269 for the second type of FPMCP 305 as illustrated in FIGS. 10 and 10A may be formed for one of the programmable interconnects 361 of the inter-chip interconnects 371 between the FPGA IC chip 200 and any of the semiconductor IC chips 100g as illustrated in FIG. 5E; one or more of the interconnection metal layers 27 of the interconnection scheme 80, any of the through silicon vias 157 (TSVs) of any of the vertical-through-via (VTV) connectors 467, each of the interconnection metal layers 27 of the interconnection scheme 79 and any of the metal bumps, pillars or pads 570 for the second type of FPMCP 305 as illustrated in FIGS. 10 and 10A may be formed for the first group of the large input/output (I/O) circuits 342 of the NVM IC chip 250 receiving and transmitting the first and second (encrypted) CPM data from and to the external circuits 340 as illustrated in FIG. 5E outside of the second type of FPMCP 305; optionally for each aspect of the first through third aspects any of the through silicon vias 157 (TSVs) of the auxiliary IC chip 411, each of the interconnection metal layers 27 of the interconnection scheme 79 and any of the metal bumps, pillars or pads 570 for the second type of FPMCP 305 as illustrated in FIGS. 10 and 10A may be formed for the large input/output (I/O) circuits 341 of the large-input/output (I/O) block of the auxiliary IC chip 411 receiving and transmitting the first and second (encrypted) CPM data from and to the external circuits 340 as illustrated in FIG. 5E outside of the second type of FPMCP 305. For the second type of FPMCP 305 for each aspect of the fifth through eighth aspects as illustrated in FIG. 5F, its FPGA IC chip 200 may have the same circuits as one illustrated in FIG. 5F, its auxiliary IC chip 411 may have the same circuits as one illustrated in FIG. 5F, its NVM IC chip 250 may have the same circuits as one illustrated in FIG. 5F, and its logic computing IC chip 269 may be any of the semiconductor IC chips 100g as illustrated in FIG. 5F. Any of the first, second, third or fourth type of micro-bumps, micro-pillars or micro-pads 34 of the FPGA IC chip 200, each of the interconnection metal layers 27 of the interconnection scheme 80 and any of the first type of micro-bumps, micro-pillars or micro-pads 34 of the NVM IC chip 250 for the second type of FPMCP 305 as illustrated in FIGS. 10 and 10A may be formed for one of the non-programmable interconnects 364 of the inter-chip interconnects 371 between the FPGA IC chip 200 and NVM IC chip 250 as illustrated in FIG. 5F; any of the first type of micro-bumps, micro-pillars or micro-pads 34 of the NVM IC chip 250, one or more of the interconnection metal layers 27 of the interconnection scheme 80 and any of the first type of micro-bumps, micro-pillars or micro-pads 34 of the auxiliary IC chip 411 for the second type of FPMCP 305 as illustrated in FIGS. 10 and 10A may be formed for one of the non-programmable interconnects 364 of the inter-chip interconnects 371 between the NVM IC chip 250 and auxiliary IC chip 411 as illustrated in FIG. 5F; any of the first, second, third or fourth type of micro-bumps, micro-pillars or micro-pads 34 of the FPGA IC chip 200, one or more of the interconnection metal layers 27 of the interconnection scheme 80 and any of the first, second, third or fourth type of micro-bumps, micro-pillars or micro-pads 34 of the logic computing IC chip 269 for the second type of FPMCP 305 as illustrated in FIGS. 10 and 10A may be formed for one of the programmable interconnects 361 of the inter-chip interconnects 371 between the FPGA IC chip 200 and any of the semiconductor IC chips 100g as illustrated in FIG. 5F; any of the through silicon vias 157 (TSVs) of the auxiliary IC chip 411, each of the interconnection metal layers 27 of the interconnection scheme 79 and any of the metal bumps, pillars or pads 570 for the second type of FPMCP 305 as illustrated in FIGS. 10 and 10A may be formed for the large input/output (I/O) circuits 341 of the large-input/output (I/O) block of the auxiliary IC chip 411 receiving and transmitting the first and second (encrypted) CPM data from and to the external circuits 340 as illustrated in FIG. 5F outside of the second type of FPMCP 305. For the second type of FPMCP 305 for each aspect of the ninth through eleventh aspects as illustrated in FIG. 5G, its FPGA IC chip 200 may have the same circuits as one illustrated in FIG. 5G, its NVM IC chip 250 may have the same circuits as one illustrated in FIG. 5G, and its logic computing IC chip 269 may be any of the semiconductor IC chips 100g as illustrated in FIG. 5G. Any of the first, second, third or fourth type of micro-bumps, micro-pillars or micro-pads 34 of the FPGA IC chip 200, each of the interconnection metal layers 27 of the interconnection scheme 80 and any of the first type of micro-bumps, micro-pillars or micro-pads 34 of the NVM IC chip 250 for the second type of FPMCP 305 as illustrated in FIGS. 10 and 10A may be formed for one of the non-programmable interconnects 364 of the inter-chip interconnects 371 between the FPGA IC chip 200 and NVM IC chip 250 as illustrated in FIG. 5G; any of the first, second, third or fourth type of micro-bumps, micro-pillars or micro-pads 34 of the FPGA IC chip 200, one or more of the interconnection metal layers 27 of the interconnection scheme 80 and any of the first, second, third or fourth type of micro-bumps, micro-pillars or micro-pads 34 of the logic computing IC chip 269 for the second type of FPMCP 305 as illustrated in FIGS. 10 and 10A may be formed for one of the programmable interconnects 361 of the inter-chip interconnects 371 between the FPGA IC chip 200 and any of the semiconductor IC chips 100g as illustrated in FIG. 5G; one or more of the interconnection metal layers 27 of the interconnection scheme 80, any of the through silicon vias 157 (TSVs) of any of the vertical-through-via (VTV) connectors 467, each of the interconnection metal layers 27 of the interconnection scheme 79 and any of the metal bumps, pillars or pads 570 for the second type of FPMCP 305 as illustrated in FIGS. 10 and 10A may be formed for the large input/output (I/O) circuits 342 of the NVM IC chip 250 receiving and transmitting the first and second (encrypted) CPM data from and to the external circuits 340 as illustrated in FIG. 5G outside of the second type of FPMCP 305.

### Third Type of FPMCP

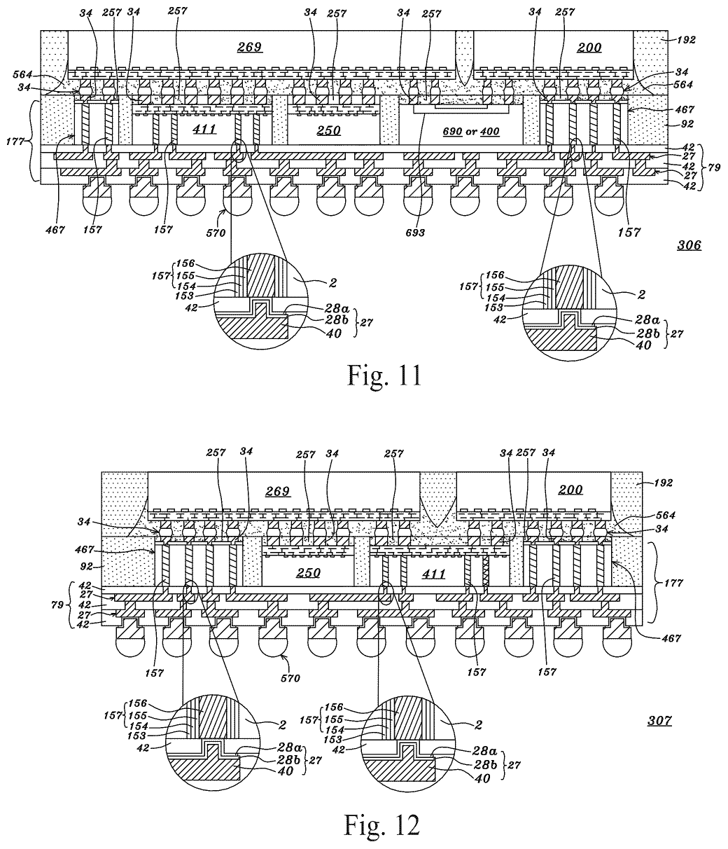

FIG. 11 is a schematically cross-sectional view showing a third type of FPMCP in accordance with an embodiment of the present application. Referring to FIG. 11, a third type of FPMCP 306 may include a similar interconnection substrate 177 to one as illustrated in FIG. 9A. For an element indicated by the same reference number shown in FIGS. 9A and 11, the specification of the element as seen in FIG. 11 may be referred to that of the element as illustrated in FIG. 9A. The difference therebetween is that the NVM IC chip 250 of the fourth structure 304 for each of the first type of FPMCPs 300 for the first and second alternatives and one of the auxiliary IC chip 411 of the fourth structure 304 for each of the first type of FPMCPs 300 for the first and second alternatives may be arranged in the interconnection substrate 177 for the third type of FPMCP 306 as seen in FIG. 11. For the third type of FPMCP 306, its NVM IC chip 250 may have the same specification as the third type of semiconductor IC chip 100 as illustrated in FIG. 3C and its auxiliary IC chip 411 may have the same specification as the fourth type of semiconductor IC chip 100 as illustrated in FIGS. 3D and 3G-3J.

Referring to FIG. 11, the third type of FPMCP 306 may further include a FPGA IC chip 200 having the specification as illustrated for one in FIG. 5A-1 over its interconnection substrate 177, and a logic computing IC chip 269, such as the graphic-processing-unit (GPU) IC chip 269a, central-processing-unit (CPU) IC chip 269b or application-specific integrated-circuit (ASIC) chip or system-on-chip (SoC) chip 269c as illustrated in FIG. 5A-1 or such as data processing unit (DPU) IC chip, tensor flow processing unit (TPU) IC chip or digital-signal-processing (DSP) chip, over its interconnection substrate 177. For the third type of FPMCP 306, each of its FPGA IC chip 200 and logic computing IC chip 269 may have the same specification as the first type of semiconductor IC chip 100 illustrated in FIG. 3A to be turned upside down. Its FPGA IC chip 200 may be the dedicated field programmable integrated-circuit (DFPIC) chip as illustrated in FIG. 4D or embedded field programmable integrated-circuit (eFPIC) chip as illustrated in FIG. 4E.

Referring to FIG. 11, for the third type of FPMCP 306, its NVM IC chip 250 may be embedded in its interconnection substrate 177 and under its FPGA IC chip 200, and its auxiliary IC chip 411 may be embedded in its interconnection substrate 177 and under its FPGA IC chip 200. The polymer layer 92, i.e., insulating dielectric layer or sealing layer, of its interconnection substrate 177 may be horizontally around each of the fine-line interconnection bridge (FIB) 690, or DFPIC or eFPIC chip 400, and vertical-through-via (VTV) connectors 467 of its interconnection substrate 177 and each of its NVM IC chip 250 and auxiliary IC chip 411 and in each gap between neighboring two of the fine-line interconnection bridge (FIB) 690, or DFPIC or eFPIC chip 400, and vertical-through-via (VTV) connectors 467 of its interconnection substrate 177 and its NVM IC chip 250 and auxiliary IC chip 411, wherein the polymer layer 92 of its interconnection substrate 177 may have a top surface coplanar with the top surface of the polymer layer 257 of each of the fine-line interconnection bridge (FIB) 690, or DFPIC or eFPIC chip 400, and vertical-through-via (VTV) connectors 467 of its interconnection substrate 177, the top surface of each of the first type of micro-bumps, micro-pillars or micro-pads 34 of each of the fine-line interconnection bridge (FIB) 690, or DFPIC or eFPIC chip 400, and vertical-through-via (VTV) connectors 467 of its interconnection substrate 177, the top surface of the polymer layer 257 of each of its NVM IC chip 250 and auxiliary IC chip 411 and the top surface of each of the first type of micro-bumps, micro-pillars or micro-pads 34 of each of its NVM IC chip 250 and auxiliary IC chip 411. Each of the semiconductor substrate 2 of each of its NVM IC chip 250 and auxiliary IC chip 411 and the semiconductor substrate 2 of each of the fine-line interconnection bridge (FIB) 690, or DFPIC or eFPIC chip 400, and vertical-through-via (VTV) connectors 467 of its interconnection substrate 177 may have a portion, at a backside of said each of the semiconductor substrates 2, removed by a chemical-mechanical-polishing (CMP) or mechanical grinding process such that each of the through silicon vias (TSVs) 157, that is, the electroplated copper layer 156 thereof, of its auxiliary IC chip 411 may have a bottom surface substantially coplanar with a bottom surface of each of the through silicon vias (TSVs) 157, that is, the electroplated copper layer 156 thereof, of each of the vertical-through-via (VTV) connectors 467 of its interconnection substrate 177, a bottom surface of the semiconductor substrate 2 of each of its NVM IC chip 250 and auxiliary IC chip 411 and a bottom surface of the semiconductor substrate 2 of each of the fine-line interconnection bridge (FIB) 690, or DFPIC or eFPIC chip 400, and vertical-through-via (VTV) connectors 467 of its interconnection substrate 177 and a bottom surface of the polymer layer 92 of its interconnection substrate 177. For an alternative case, its interconnection substrate 177 may further include the insulating dielectric layer 185, such as silicon-oxide layer or silicon-nitride layer, illustrated in FIG. 4C but not shown in FIG. 11 formed on a bottom surface of the semiconductor substrate 2 of each of the fine-line interconnection bridges (FIBs) 690, or DFPIC or eFPIC chips 400, and vertical-through-via (VTV) connectors 467 of its interconnection substrate 177 and a bottom surface of the semiconductor substrate 2 of each of its NVM IC chip 250 and auxiliary IC chip 411, wherein the insulating dielectric layer 185 of its interconnection substrate 177 may have a bottom surface coplanar with the bottom surface of each of the through silicon vias 157 of each of the vertical-through-via (VTV) connectors 467 of its interconnection substrate 177, the bottom surface of each of the through silicon vias 157 of its auxiliary IC chip 411 and the bottom surface of the polymer layer 92 of its interconnection substrate 177. The topmost one of the polymer layers 42 of the interconnection scheme 79 of its interconnection substrate 177 may have a top surface in contact with the bottom surface of the polymer layer 92 of its interconnection substrate 177, the bottom surface of the semiconductor substrate 2 of each of the fine-line interconnection bridge (FIB) 690, or DFPIC or eFPIC chip 400, and vertical-through-via (VTV) connectors 467 of its interconnection substrate 177 and the bottom surface of the semiconductor substrate 2 of each of its NVM IC chip 250 and auxiliary IC chip 411. For the alternative case, the topmost one of the polymer layers 42 of the interconnection scheme 79 of its interconnection substrate 177 may have a top surface in contact with the bottom surface of the polymer layer 92 of its interconnection substrate 177 and the bottom surface of the insulating dielectric layer 185 of its interconnection substrate 177. Each opening in the topmost one of the polymer layers 42 of the interconnection scheme 79 of its interconnection substrate 177 may be under one of the through silicon vias (TSVs) 157 of one of the vertical-through-via (VTV) connectors 467 of its interconnection substrate 177 or one of the through silicon vias (TSVs) 157 of its auxiliary IC chip 411, and thus the topmost one of the interconnection metal layers 27 of the interconnection scheme 79 of its interconnection substrate 177 may extend through said each opening to couple to said one of the through silicon vias (TSVs) 157. Each of the interconnection metal layers 27 of the interconnection scheme 79 of its interconnection substrate 177 may extend horizontally across an edge of each of its NVM IC chip 250 and auxiliary IC chip 411 and an edge of each of the fine-line interconnection bridge (FIB) 690, or DFPIC or eFPIC chip 400, and vertical-through-via (VTV) connectors 467 of its interconnection substrate 177.

Referring to FIG. 11, for the third type of FPMCP 306, each of its FPGA IC chip 200 and logic computing IC chip 269 may have the first, second, third or fourth type of micro-bumps, micro-pillars or micro-pads 34 as illustrated in FIG. 3A each bonded to one of the first type of micro-bumps, micro-pillars or micro-pads 34 of one of the fine-line interconnection bridge (FIB) 690, or DFPIC or eFPIC chip 400, and vertical-through-via (VTV) connectors 467 of its interconnection substrate 177 or one of the first type of micro-bumps, micro-pillars or micro-pads 34 of one of its NVM IC chip 250 and auxiliary IC chip 411. The bottom surface of the semiconductor substrate 2 of its FPGA IC chip 200, at which the semiconductor devices 4, such as transistors, of its FPGA IC chip 200 are formed as illustrated in FIG. 3A to be turned upside down, faces the top surface of the semiconductor substrate 2 of its NVM IC chip 250, at which the semiconductor devices 4, such as transistors, of its NVM IC chip 250 are formed as illustrated in FIG. 3C, and the top surface of the semiconductor substrate 2 of its auxiliary IC chip 411, at which the semiconductor devices 4, such as transistors, of its auxiliary IC chip 411 are formed as illustrated in FIGS. 3D and 3G-3J. Its underfill 564, i.e., polymer layer, may be formed between each of its FPGA IC chip 200 and logic computing IC chip 269 and its interconnection substrate 177, covering a sidewall of each of the first, second, third or fourth type of micro-bumps, micro-pillars or micro-pads 34 of each of its FPGA IC chip 200 and logic computing IC chip 269. Its polymer layer 192, i.e., insulating dielectric layer or sealing layer, may be formed on its interconnection substrate 177 and horizontally around its FPGA IC chip 200 and logic computing IC chip 269, wherein its polymer layer 192 may have a top surface coplanar with a top surface of each of its FPGA IC chip 200 and logic computing IC chip 269. Its polymer layer 192 may have a vertical sidewall coplanar with a vertical sidewall of each of the polymer layer 92 and interconnection scheme 79 of its interconnection substrate 177.

Referring to FIG. 11, for the third type of FPMCP 306, the fine-line interconnection bridge (FIB) 690, or DFPIC or eFPIC chips 400, of its interconnection substrate 177 may be arranged under its FPGA IC chip 200 and logic computing IC chip 269 and may have one of the metal lines or traces 693 coupling its FPGA IC chip 200 to its logic computing IC chip 269 for transmitting a signal or clock or delivering a power or ground voltage therebetween. Each of its FPGA IC chip 200 and logic computing IC chip 269 may couple to one of its metal bumps, pillars or pads 570, which are in an array at its bottom to act as its external pins for coupling to external circuits outside of the third type of FPMCP 306, through, in sequence, one of the through silicon vias (TSVs) 157 of one of the vertical-through-via (VTV) connectors 467 of its interconnection substrate 177 and each of the interconnection metal layers 27 of the interconnection scheme 79 of its interconnection substrate 177 for transmitting a signal or clock or delivering a power or ground voltage therebetween. Alternatively, its FPGA IC chip 200 may couple to one of its metal bumps, pillars or pads 570, which are in an array at its bottom to act as its external pins for coupling to external circuits outside of the third type of FPMCP 306, through, in sequence, one of the through silicon vias (TSVs) 157 of its auxiliary IC chip 411 and each of the interconnection metal layers 27 of the interconnection scheme 79 of its interconnection substrate 177 for transmitting a signal or clock or delivering a power or ground voltage therebetween.

Referring to FIG. 11, the third type of FPMCP 306 may have the inter-chip interconnection between the first and second semiconductor IC chips 100a and 100b via the FPGA IC chip 200 as illustrated in FIG. 5B. For the third type of FPMCP 306, its FPGA IC chip 200 may have the same circuits as one illustrated in FIG. 5B. For example, its logic computing IC chip 269 may be the first semiconductor IC chip 100a as illustrated in FIG. 5B, and one of its NVM IC chip 250 and auxiliary IC chip 411 may be the second semiconductor IC chip 100b as illustrated in FIG. 5B. Any bonded two of the first, second, third or fourth type of micro-bumps, micro-pillars or micro-pads 34 of the FPGA IC chip 200 and fine-line interconnection bridge (FIB) 690, or DFPIC or eFPIC chip 400, any of the metal lines or traces 693 of the fine-line interconnection bridge (FIB) 690, or DFPIC or eFPIC chip 400, and any bonded two of the first, second, third or fourth type of micro-bumps, micro-pillars or micro-pads 34 of the first semiconductor IC chip 100a and fine-line interconnection bridge (FIB) 690, or DFPIC or eFPIC chip 400, for the third type of FPMCP 306 as illustrated in FIG. 11 may be formed for one of the programmable interconnects 361 of the inter-chip interconnects 371 between the FPGA IC chip 200 and first semiconductor IC chip 100a as illustrated in FIG. 5B, and any bonded two of the first, second, third or fourth type of micro-bumps, micro-pillars or micro-pads 34 of the FPGA IC chip 200 and a first one of the vertical-through-via (VTV) connectors 467, any of the through silicon vias (TSVs) 157 of the first one of the vertical-through-via (VTV) connectors 467, one or more of the interconnection metal layers 27 of the interconnection scheme 79, any of the through silicon vias (TSVs) 157 of a second one of the vertical-through-via (VTV) connectors 467 under the first semiconductor IC chip 100a, any bonded two of the first, second, third or fourth type of micro-bumps, micro-pillars or micro-pads 34 of the first semiconductor IC chip 100a and second one of the vertical-through-via (VTV) connectors 467, one or more of the interconnection metal layers 6 and/or 27 of the first and/or second interconnection scheme for a chip (FISC and/or SISC) 20 and/or 29 of the first semiconductor IC chip 100a and any bonded two of the first, second, third or fourth type of micro-bumps, micro-pillars or micro-pads 34 of the first and second semiconductor IC chips 100a and 100b for the third type of FPMCP 306 as illustrated in FIG. 11 may be formed for one of the programmable interconnects 361 of the inter-chip interconnects 371 between the FPGA IC chip 200 and second semiconductor IC chip 100b as illustrated in FIG. 5B. Alternatively, its auxiliary IC chip 411 may be the first semiconductor IC chip 100a as illustrated in FIG. 5B, and its NVM IC chip 250 may be the second semiconductor IC chip 100b as illustrated in FIG. 5B. Any bonded two of the first, second, third or fourth type of micro-bumps, micro-pillars or micro-pads 34 of the FPGA IC chip 200 and first one of the vertical-through-via (VTV) connectors 467, any of the through silicon vias (TSVs) 157 of the first one of the vertical-through-via (VTV) connectors 467, one or more of the interconnection metal layers 27 of the interconnection scheme 79, any of the through silicon vias (TSVs) 157 of the second one of the vertical-through-via (VTV) connectors 467, any bonded two of the first, second, third or fourth type of micro-bumps, micro-pillars or micro-pads 34 of the logic computing IC chip 269 and second one of the vertical-through-via (VTV) connectors 467, one or more of the interconnection metal layers 6 and/or 27 of the first and/or second interconnection scheme for a chip (FISC and/or SISC) 20 and/or 29 of the logic computing IC chip 269 and any bonded two of the first, second, third or fourth type of micro-bumps, micro-pillars or micro-pads 34 of the logic computing IC chip 269 and first semiconductor IC chip 100a for the third type of FPMCP 306 as illustrated in FIG. 11 may be formed for one of the programmable interconnects 361 of the inter-chip interconnects 371 between the FPGA IC chip 200 and first semiconductor IC chip 100a as illustrated in FIG. 5B, or any bonded two of the first, second, third or fourth type of micro-bumps, micro-pillars or micro-pads 34 of the FPGA IC chip 200 and fine-line interconnection bridge (FIB) 690, or DFPIC or eFPIC chip 400, any of the metal lines or traces 693 of the fine-line interconnection bridge (FIB) 690, or DFPIC or eFPIC chip 400, and any bonded two of the first, second, third or fourth type of micro-bumps, micro-pillars or micro-pads 34 of the logic computing IC chip 269 and fine-line interconnection bridge (FIB) 690, or DFPIC or eFPIC chip 400, one or more of the interconnection metal layers 6 and/or 27 of the first and/or second interconnection scheme for a chip (FISC and/or SISC) 20 and/or 29 of the logic computing IC chip 269 and any bonded two of the first, second, third or fourth type of micro-bumps, micro-pillars or micro-pads 34 of the logic computing IC chip 269 and first semiconductor IC chip 100a for the third type of FPMCP 306 as illustrated in FIG. 11 may be formed for one of the programmable interconnects 361 of the inter-chip interconnects 371 between the FPGA IC chip 200 and first semiconductor IC chip 100a as illustrated in FIG. 5B. Further, any bonded two of the first, second, third or fourth type of micro-bumps, micro-pillars or micro-pads 34 of the FPGA IC chip 200 and first one of the vertical-through-via (VTV) connectors 467, any of the through silicon vias (TSVs) 157 of the first one of the vertical-through-via (VTV) connectors 467, one or more of the interconnection metal layers 27 of the interconnection scheme 79, any of the through silicon vias (TSVs) 157 of the second one of the vertical-through-via (VTV) connectors 467, any bonded two of the first, second, third or fourth type of micro-bumps, micro-pillars or micro-pads 34 of the logic computing IC chip 269 and second one of the vertical-through-via (VTV) connectors 467, one or more of the interconnection metal layers 6 and/or 27 of the first and/or second interconnection scheme for a chip (FISC and/or SISC) 20 and/or 29 of the logic computing IC chip 269 and any bonded two of the first, second, third or fourth type of micro-bumps, micro-pillars or micro-pads 34 of the logic computing IC chip 269 and second semiconductor IC chip 100b for the third type of FPMCP 306 as illustrated in FIG. 11 may be formed for one of the programmable interconnects 361 of the inter-chip interconnects 371 between the FPGA IC chip 200 and second semiconductor IC chip 100b as illustrated in FIG. 5B, or any bonded two of the first, second, third or fourth type of micro-bumps, micro-pillars or micro-pads 34 of the FPGA IC chip 200 and fine-line interconnection bridge (FIB) 690, or DFPIC or eFPIC chip 400, any of the metal lines or traces 693 of the fine-line interconnection bridge (FIB) 690, or DFPIC or eFPIC chip 400, and any bonded two of the first, second, third or fourth type of micro-bumps, micro-pillars or micro-pads 34 of the logic computing IC chip 269 and fine-line interconnection bridge (FIB) 690, or DFPIC or eFPIC chip 400, one or more of the interconnection metal layers 6 and/or 27 of the first and/or second interconnection scheme for a chip (FISC and/or SISC) 20 and/or 29 of the logic computing IC chip 269 and any bonded two of the first, second, third or fourth type of micro-bumps, micro-pillars or micro-pads 34 of the logic computing IC chip 269 and second semiconductor IC chip 100b for the third type of FPMCP 306 as illustrated in FIG. 11 may be formed for one of the programmable interconnects 361 of the inter-chip interconnects 371 between the FPGA IC chip 200 and second semiconductor IC chip 100b as illustrated in FIG. 5B.

Referring to FIG. 11, the third type of FPMCP 306 may perform the operation between the FPGA IC chip 200 and each of the third and fourth semiconductor IC chips 100c and 100d as illustrated in FIG. 5C. For the third type of FPMCP 306, its FPGA IC chip 200 may have the same circuits as one illustrated in FIG. 5C, its logic computing IC chip 269 may be the third semiconductor IC chip 100c as illustrated in FIG. 5C, and one of its NVM IC chip 250 and auxiliary IC chip 411 may be the fourth semiconductor IC chip 100d as illustrated in FIG. 5C. Any bonded two of the first, second, third or fourth type of micro-bumps, micro-pillars or micro-pads 34 of the FPGA IC chip 200 and fine-line interconnection bridge (FIB) 690, or DFPIC or eFPIC chip 400, any of the metal lines or traces 693 of the fine-line interconnection bridge (FIB) 690, or DFPIC or eFPIC chip 400, and any bonded two of the first, second, third or fourth type of micro-bumps, micro-pillars or micro-pads 34 of the third semiconductor IC chip 100c and fine-line interconnection bridge (FIB) 690, or DFPIC or eFPIC chip 400, for the third type of FPMCP 306 as illustrated in FIG. 11 may be formed for one of the programmable interconnects 361 of the inter-chip interconnects 371 between the FPGA IC chip 200 and third semiconductor IC chip 100c as illustrated in FIG. 5C, and any bonded two of the first, second, third or fourth type of micro-bumps, micro-pillars or micro-pads 34 of the FPGA IC chip 200 and first one of the vertical-through-via (VTV) connectors 467, any of the through silicon vias (TSVs) 157 of the first one of the vertical-through-via (VTV) connectors 467, one or more of the interconnection metal layers 27 of the interconnection scheme 79, any of the through silicon vias (TSVs) 157 of the second one of the vertical-through-via (VTV) connectors 467, any bonded two of the first, second, third or fourth type of micro-bumps, micro-pillars or micro-pads 34 of the third semiconductor IC chip 100c and second one of the vertical-through-via (VTV) connectors 467, one or more of the interconnection metal layers 6 and/or 27 of the first and/or second interconnection scheme for a chip (FISC and/or SISC) 20 and/or 29 of the third semiconductor IC chip 100c and any bonded two of the first, second, third or fourth type of micro-bumps, micro-pillars or micro-pads 34 of the third and fourth semiconductor IC chips 100c and 100d for the third type of FPMCP 306 as illustrated in FIG. 11 may be formed for one of the programmable interconnects 361 of the inter-chip interconnects 371 between the FPGA IC chip 200 and fourth semiconductor IC chip 100d as illustrated in FIG. 5C.

Referring to FIG. 11, the third type of FPMCP 306 may have the connection to external circuits as illustrated in FIG. 5D. For the third type of FPMCP 306, its FPGA IC chip 200 may have the same circuits as one illustrated in FIG. 5D, its auxiliary IC chip 411 may have the same circuits as one illustrated in FIG. 5D, its logic computing IC chip 269 may be the fifth semiconductor IC chip 100e as illustrated in FIG. 5D, and its NVM IC chip 250 may be the sixth semiconductor IC chip 100f as illustrated in FIG. 5D. Any bonded two of the first, second, third or fourth type of micro-bumps, micro-pillars or micro-pads 34 of the FPGA IC chip 200 and fine-line interconnection bridge (FIB) 690, or DFPIC or eFPIC chip 400, any of the metal lines or traces 693 of the fine-line interconnection bridge (FIB) 690, or DFPIC or eFPIC chip 400, and any bonded two of the first, second, third or fourth type of micro-bumps, micro-pillars or micro-pads 34 of the fifth semiconductor IC chip 100e and fine-line interconnection bridge (FIB) 690, or DFPIC or eFPIC chip 400, for the third type of FPMCP 306 as illustrated in FIG. 11 may be formed for one of the programmable interconnects 361 of the inter-chip interconnects 371 between the FPGA IC chip 200 and fifth semiconductor IC chip 100e as illustrated in FIG. 5D, and any bonded two of the first, second, third or fourth type of micro-bumps, micro-pillars or micro-pads 34 of the FPGA IC chip 200 and first one of the vertical-through-via (VTV) connectors 467, any of the through silicon vias (TSVs) 157 of the first one of the vertical-through-via (VTV) connectors 467, one or more of the interconnection metal layers 27 of the interconnection scheme 79, any of the through silicon vias (TSVs) 157 of the second one of the vertical-through-via (VTV) connectors 467, any bonded two of the first, second, third or fourth type of micro-bumps, micro-pillars or micro-pads 34 of the fifth semiconductor IC chip 100e and second one of the vertical-through-via (VTV) connectors 467, one or more of the interconnection metal layers 6 and/or 27 of the first and/or second interconnection scheme for a chip (FISC and/or SISC) 20 and/or 29 of the fifth semiconductor IC chip 100e and any bonded two of the first, second, third or fourth type of micro-bumps, micro-pillars or micro-pads 34 of the fifth and sixth semiconductor IC chip 100e and 100f for the third type of FPMCP 306 as illustrated in FIG. 11 may be formed for one of the programmable interconnects 361 of the inter-chip interconnects 371 between the FPGA IC chip 200 and sixth semiconductor IC chip 100f as illustrated in FIG. 5D. Any bonded two of the first, second, third or fourth type of micro-bumps, micro-pillars or micro-pads 34 of the FPGA IC chip 200 and fine-line interconnection bridge (FIB) 690, or DFPIC or eFPIC chip 400, any of the metal lines or traces 693 of the fine-line interconnection bridge (FIB) 690, or DFPIC or eFPIC chip 400, any bonded two of the first, second, third or fourth type of micro-bumps, micro-pillars or micro-pads 34 of the fifth semiconductor IC chip 100e and fine-line interconnection bridge (FIB) 690, or DFPIC or eFPIC chip 400, one or more of the interconnection metal layers 6 and/or 27 of the first and/or second interconnection scheme for a chip (FISC and/or SISC) 20 and/or 29 of the fifth semiconductor IC chip 100e and any bonded two of the first, second, third or fourth type of micro-bumps, micro-pillars or micro-pads 34 of the auxiliary IC chip 411 and fifth semiconductor IC chip 100e for the third type of FPMCP 306 as illustrated in FIG. 11 may be formed for one of the programmable interconnects 361 of the inter-chip interconnects 371 between the FPGA IC chip 200 and auxiliary IC chip 411 as illustrated in FIG. 5D, or any bonded two of the first, second, third or fourth type of micro-bumps, micro-pillars or micro-pads 34 of the FPGA IC chip 200 and first one of the vertical-through-via (VTV) connectors 467, any of the through silicon vias (TSVs) 157 of the first one of the vertical-through-via (VTV) connectors 467, one or more of the interconnection metal layers 27 of the interconnection scheme 79, any of the through silicon vias (TSVs) 157 of the second one of the vertical-through-via (VTV) connectors 467, any bonded two of the first, second, third or fourth type of micro-bumps, micro-pillars or micro-pads 34 of the fifth semiconductor IC chip 100e and second one of the vertical-through-via (VTV) connectors 467, one or more of the interconnection metal layers 6 and/or 27 of the first and/or second interconnection scheme for a chip (FISC and/or SISC) 20 and/or 29 of the fifth semiconductor IC chip 100e and any bonded two of the first, second, third or fourth type of micro-bumps, micro-pillars or micro-pads 34 of the auxiliary IC chip 411 and fifth semiconductor IC chip 100e for the third type of FPMCP 306 as illustrated in FIG. 11 may be formed for one of the programmable interconnects 361 of the inter-chip interconnects 371 between the FPGA IC chip 200 and auxiliary IC chip 411 as illustrated in FIG. 5D. Each of the large input/output (I/O) circuits 341 of the large-input/output (I/O) block of its auxiliary IC chip 411 may couple to one of its metal bumps, pillars or pads 570, which are in an array at its bottom to act as its external pins for coupling to the external circuits 340 as seen in FIG. 5D outside of the third type of FPMCP 306, through, in sequence, one of the through silicon vias (TSVs) 157 of its auxiliary IC chip 411 and each of the interconnection metal layers 27 of the interconnection scheme 79 of its interconnection substrate 177.

Referring to FIG. 11, for the third type of FPMCP 306, its auxiliary IC chip 411 may include a first small input/output (I/O) circuit coupling to a second small input/output (I/O) circuit of its FPGA IC chip 200 through its first signal path composed of bonded two of the first, second, third or fourth type of micro-bumps, micro-pillars or micro-pads 34 of its auxiliary IC chip 411 and FPGA IC chip 200, wherein each of the first and second small input/output (I/O) circuits may have an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts. Its auxiliary IC chip 411 may include a large input/output (I/O) circuit coupling to any of its metal bumps, pillars or pads 570 through its second signal path composed of any of the through silicon vias (TSVs) 157 of its auxiliary IC chip 411 and each of the interconnection metal layers 27 of the interconnection scheme 79 of its interconnection substrate 177, wherein the large input/output (I/O) circuit may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or equal to or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Thereby, the first small input/output (I/O) circuit may receive first signals from the second small input/output (I/O) circuit via its first signal path to be converted by its auxiliary IC chip 411 as second signals and then the large input/output (I/O) circuit may transmit the second signals to said any of its metal bumps, pillars or pads 570 via its second signal path. Further, the large input/output (I/O) circuit may receive third signals from said any of its metal bumps, pillars or pads 570 via its second signal path to be converted by its auxiliary IC chip 411 as fourth signals and then the first small input/output (I/O) circuit may transmit the fourth signals to the second small input/output (I/O) circuit via its first signal path.

Referring to FIG. 11, for the third type of FPMCP 306, its FPGA IC chip 200 may be programmed, configured or reconfigured following the same way as any aspect of the first through eleventh aspects illustrated in FIGS. 5A-1, 5A-2 and 5E-5G, including (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with first data stored in its NVM IC chip 250 to be configured in accordance with the first data, (2) the first or second type of field programmable switch cell 379 as illustrated in FIG. 2A or 2B having the memory cells 362 as illustrated in FIG. 2A or the four sets of memory cells 362 as illustrated in FIG. 2B for storing data associated with second data stored in its NVM IC chip 250 to be configured in accordance with the second data, and (3) the programmable switch matrix 710 as illustrated in FIG. 2C having the memory cells 398 for storing data, i.e., programming codes, password or encryption/decryption codes, associated with third data stored in its NVM IC chip 250 to be configured in accordance with the third data. Alternatively, its FPGA IC chip 200 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MLU) IC chip, or digital-signal-processing (DSP) IC chip, each of which may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with the first data to be configured in accordance with the first data, (2) the first or second type of field programmable switch cell 379 as illustrated in FIG. 2A or 2B having the memory cells 362 as illustrated in FIG. 2A or the four sets of memory cells 362 as illustrated in FIG. 2B for storing data associated with the second data to be configured in accordance with the second data, and (3) the programmable switch matrix 710 as illustrated in FIG. 2C having the memory cells 398 for storing data, i.e., programming codes, password or encryption/decryption codes, associated with the third data to be configured in accordance with the third data. For the third type of FPMCP 306 for each aspect of the first through fourth aspects as illustrated in FIG. 5E, its FPGA IC chip 200 may have the same circuits as one illustrated in FIG. 5E, its auxiliary IC chip 411 may have the same circuits as one illustrated in FIG. 5E, its NVM IC chip 250 may have the same circuits as one illustrated in FIG. 5E, and its logic computing IC chip 269 may be any of the semiconductor IC chips 100g as illustrated in FIG. 5E. Any bonded two of the first, second, third or fourth type of micro-bumps, micro-pillars or micro-pads 34 of the FPGA IC chip 200 and first one of the vertical-through-via (VTV) connectors 467, any of the through silicon vias (TSVs) 157 of the first one of the vertical-through-via (VTV) connectors 467, one or more of the interconnection metal layers 27 of the interconnection scheme 79, and any of the through silicon vias (TSVs) 157 of the auxiliary IC chip 411 for the third type of FPMCP 306 as illustrated in FIG. 11 may be formed for one of the non-programmable interconnects 364 of the inter-chip interconnects 371 between the FPGA IC chip 200 and auxiliary IC chip 411 as illustrated in FIG. 5E, or any bonded two of the first, second, third or fourth type of micro-bumps, micro-pillars or micro-pads 34 of the FPGA IC chip 200 and fine-line interconnection bridge (FIB) 690, or DFPIC or eFPIC chip 400, any of the metal lines or traces 693 of the fine-line interconnection bridge (FIB) 690, or DFPIC or eFPIC chip 400, any bonded two of the first, second, third or fourth type of micro-bumps, micro-pillars or micro-pads 34 of the logic computing IC chip 269 and fine-line interconnection bridge (FIB) 690, or DFPIC or eFPIC chip 400, one or more of the interconnection metal layers 6 and/or 27 of the first and/or second interconnection scheme for a chip (FISC and/or SISC) 20 and/or 29 of the logic computing IC chip 269 and any bonded two of the first, second, third or fourth type of micro-bumps, micro-pillars or micro-pads 34 of the logic computing IC chip 269 and auxiliary IC chip 411 for the third type of FPMCP 306 as illustrated in FIG. 11 may be formed for one of the non-programmable interconnects 364 of the inter-chip interconnects 371 between the FPGA IC chip 200 and auxiliary IC chip 411 as illustrated in FIG. 5E; any bonded two of the first, second, third or fourth type of micro-bumps, micro-pillars or micro-pads 34 of the logic computing IC chip 269 and NVM IC chip 250, one or more of the interconnection metal layers 6 and/or 27 of the first and/or second interconnection scheme for a chip (FISC and/or SISC) 20 and/or 29 of the logic computing IC chip 269 and any bonded two of the first, second, third or fourth type of micro-bumps, micro-pillars or micro-pads 34 of the logic computing IC chip 269 and auxiliary IC chip 411 for the third type of FPMCP 306 as illustrated in FIG. 11 may be formed for one of the non-programmable interconnects 364 of the inter-chip interconnects 371 between the NVM IC chip 250 and auxiliary IC chip 411 as illustrated in FIG. 5E; any bonded two of the first, second, third or fourth type of micro-bumps, micro-pillars or micro-pads 34 of the FPGA IC chip 200 and fine-line interconnection bridge (FIB) 690, or DFPIC or eFPIC chip 400, any of the metal lines or traces 693 of the fine-line interconnection bridge (FIB) 690, or DFPIC or eFPIC chip 400, and any bonded two of the first, second, third or fourth type of micro-bumps, micro-pillars or micro-pads 34 of the logic computing IC chip 269 and fine-line interconnection bridge (FIB) 690, or DFPIC or eFPIC chip 400, for the third type of FPMCP 306 as illustrated in FIG. 11 may be formed for one of the programmable interconnects 361 of the inter-chip interconnects 371 between the FPGA IC chip 200 and any of the semiconductor IC chips 100g as illustrated in FIG. 5E; any bonded two of the first, second, third or fourth type of micro-bumps, micro-pillars or micro-pads 34 of the logic computing IC chip 269 and NVM IC chip 250, one or more of the interconnection metal layers 6 and/or 27 of the first and/or second interconnection scheme for a chip (FISC and/or SISC) 20 and/or 29 of the logic computing IC chip 269 and any bonded two of the first, second, third or fourth type of micro-bumps, micro-pillars or micro-pads 34 of the logic computing IC chip 269 and second one of the vertical-through-via (VTV) connectors 467, any of the through silicon vias (TSVs) 157 of the second one of the vertical-through-via (VTV) connectors 467, each of the interconnection metal layers 27 of the interconnection scheme 79 and any of the metal bumps, pillars or pads 570 for the third type of FPMCP 306 as illustrated in FIG. 11 may be formed for the first group of the large input/output (I/O) circuits 342 of the NVM IC chip 250 receiving and transmitting the first and second (encrypted) CPM data from and to the external circuits 340 as illustrated in FIG. 5E outside of the third type of FPMCP 306; optionally for each aspect of the first through third aspects any of the through silicon vias 157 (TSVs) of the auxiliary IC chip 411, each of the interconnection metal layers 27 of the interconnection scheme 79 and any of the metal bumps, pillars or pads 570 for the third type of FPMCP 306 as illustrated in FIG. 11 may be formed for the large input/output (I/O) circuits 341 of the large-input/output (I/O) block of the auxiliary IC chip 411 receiving and transmitting the first and second (encrypted) CPM data from and to the external circuits 340 as illustrated in FIG. 5E outside of the third type of FPMCP 306. For the third type of FPMCP 306 for each aspect of the fifth through eighth aspects as illustrated in FIG. 5F, its FPGA IC chip 200 may have the same circuits as one illustrated in FIG. 5F, its auxiliary IC chip 411 may have the same circuits as one illustrated in FIG. 5F, its NVM IC chip 250 may have the same circuits as one illustrated in FIG. 5F, and its logic computing IC chip 269 may be any of the semiconductor IC chips 100g as illustrated in FIG. 5F. Any bonded two of the first, second, third or fourth type of micro-bumps, micro-pillars or micro-pads 34 of the FPGA IC chip 200 and first one of the vertical-through-via (VTV) connectors 467, any of the through silicon vias (TSVs) 157 of the first one of the vertical-through-via (VTV) connectors 467, one or more of the interconnection metal layers 27 of the interconnection scheme 79, any of the through silicon vias (TSVs) 157 of the second one of the vertical-through-via (VTV) connectors 467, any bonded two of the first, second, third or fourth type of micro-bumps, micro-pillars or micro-pads 34 of the logic computing IC chip 269 and second one of the vertical-through-via (VTV) connectors 467, one or more of the interconnection metal layers 6 and/or 27 of the first and/or second interconnection scheme for a chip (FISC and/or SISC) 20 and/or 29 of the logic computing IC chip 269 and any bonded two of the first, second, third or fourth type of micro-bumps, micro-pillars or micro-pads 34 of the logic computing IC chip 269 and NVM IC chip 250 for the third type of FPMCP 306 as illustrated in FIG. 11 may be formed for one of the non-programmable interconnects 364 of the inter-chip interconnects 371 between the FPGA IC chip 200 and NVM IC chip 250 as illustrated in FIG. 5F; any bonded two of the first, second, third or fourth type of micro-bumps, micro-pillars or micro-pads 34 of the logic computing IC chip 269 and NVM IC chip 250, one or more of the interconnection metal layers 6 and/or 27 of the first and/or second interconnection scheme for a chip (FISC and/or SISC) 20 and/or 29 of the logic computing IC chip 269 and any bonded two of the first, second, third or fourth type of micro-bumps, micro-pillars or micro-pads 34 of the logic computing IC chip 269 and auxiliary IC chip 411 for the third type of FPMCP 306 as illustrated in FIG. 11 may be formed for one of the non-programmable interconnects 364 of the inter-chip interconnects 371 between the NVM IC chip 250 and auxiliary IC chip 411 as illustrated in FIG. 5F; any bonded two of the first, second, third or fourth type of micro-bumps, micro-pillars or micro-pads 34 of the FPGA IC chip 200 and fine-line interconnection bridge (FIB) 690, or DFPIC or eFPIC chip 400, any of the metal lines or traces 693 of the fine-line interconnection bridge (FIB) 690, or DFPIC or eFPIC chip 400, and any bonded two of the first, second, third or fourth type of micro-bumps, micro-pillars or micro-pads 34 of the logic computing IC chip 269 and fine-line interconnection bridge (FIB) 690, or DFPIC or eFPIC chip 400, for the third type of FPMCP 306 as illustrated in FIG. 11 may be formed for one of the programmable interconnects 361 of the inter-chip interconnects 371 between the FPGA IC chip 200 and any of the semiconductor IC chips 100g as illustrated in FIG. 5F; any of the through silicon vias 157 (TSVs) of the auxiliary IC chip 411, each of the interconnection metal layers 27 of the interconnection scheme 79 and any of the metal bumps, pillars or pads 570 for the third type of FPMCP 306 as illustrated in FIG. 11 may be formed for the large input/output (I/O) circuits 341 of the large-input/output (I/O) block of the auxiliary IC chip 411 receiving and transmitting the first and second (encrypted) CPM data from and to the external circuits 340 as illustrated in FIG. 5F outside of the third type of FPMCP 306. For the third type of FPMCP 306 for each aspect of the ninth through eleventh aspects as illustrated in FIG. 5G, its FPGA IC chip 200 may have the same circuits as one illustrated in FIG. 5G, its NVM IC chip 250 may have the same circuits as one illustrated in FIG. 5G, and its logic computing IC chip 269 may be any of the semiconductor IC chips 100g as illustrated in FIG. 5G. Any bonded two of the first, second, third or fourth type of micro-bumps, micro-pillars or micro-pads 34 of the FPGA IC chip 200 and first one of the vertical-through-via (VTV) connectors 467, any of the through silicon vias (TSVs) 157 of the first one of the vertical-through-via (VTV) connectors 467, one or more of the interconnection metal layers 27 of the interconnection scheme 79, any of the through silicon vias (TSVs) 157 of the second one of the vertical-through-via (VTV) connectors 467, any bonded two of the first, second, third or fourth type of micro-bumps, micro-pillars or micro-pads 34 of the logic computing IC chip 269 and second one of the vertical-through-via (VTV) connectors 467, one or more of the interconnection metal layers 6 and/or 27 of the first and/or second interconnection scheme for a chip (FISC and/or SISC) 20 and/or 29 of the logic computing IC chip 269 and any bonded two of the first, second, third or fourth type of micro-bumps, micro-pillars or micro-pads 34 of the logic computing IC chip 269 and NVM IC chip 250 for the third type of FPMCP 306 as illustrated in FIG. 11 may be formed for one of the non-programmable interconnects 364 of the inter-chip interconnects 371 between the FPGA IC chip 200 and NVM IC chip 250 as illustrated in FIG. 5G; any bonded two of the first, second, third or fourth type of micro-bumps, micro-pillars or micro-pads 34 of the FPGA IC chip 200 and fine-line interconnection bridge (FIB) 690, or DFPIC or eFPIC chip 400, any of the metal lines or traces 693 of the fine-line interconnection bridge (FIB) 690, or DFPIC or eFPIC chip 400, and any bonded two of the first, second, third or fourth type of micro-bumps, micro-pillars or micro-pads 34 of the logic computing IC chip 269 and fine-line interconnection bridge (FIB) 690, or DFPIC or eFPIC chip 400, for the third type of FPMCP 306 as illustrated in FIG. 11 may be formed for one of the programmable interconnects 361 of the inter-chip interconnects 371 between the FPGA IC chip 200 and any of the semiconductor IC chips 100g as illustrated in FIG. 5G; any bonded two of the first, second, third or fourth type of micro-bumps, micro-pillars or micro-pads 34 of the logic computing IC chip 269 and NVM IC chip 250, one or more of the interconnection metal layers 6 and/or 27 of the first and/or second interconnection scheme for a chip (FISC and/or SISC) 20 and/or 29 of the logic computing IC chip 269 and any bonded two of the first, second, third or fourth type of micro-bumps, micro-pillars or micro-pads 34 of the logic computing IC chip 269 and second one of the vertical-through-via (VTV) connectors 467, any of the through silicon vias (TSVs) 157 of the second one of the vertical-through-via (VTV) connectors 467, each of the interconnection metal layers 27 of the interconnection scheme 79 and any of the metal bumps, pillars or pads 570 for the third type of FPMCP 306 as illustrated in FIG. 11 may be formed for the large input/output (I/O) circuits 342 of the NVM IC chip 250 receiving and transmitting the first and second (encrypted) CPM data from and to the external circuits 340 as illustrated in FIG. 5G outside of the third type of FPMCP 306.

Alternatively, referring to FIG. 11, for the third type of FPMCP 306, the DFPIC or eFPIC chip 400 of its interconnection substrate 177 may be vertically under its FPGA IC chip 200 and logic computing IC chip 269, wherein the DFPIC or eFPIC chip 400 of its interconnection substrate 177 may couple to a first device of its FPGA IC chip 200 and logic computing IC chip 269 through a first group of the first type of micro-bumps, micro-pillars or micro-pads 34 of the DFPIC or eFPIC chip 400 of its interconnection substrate 177 under the first device and couple to a second device of its FPGA IC chip 200 and logic computing IC chip 269 through a second group of the first type of micro-bumps, micro-pillars or micro-pads 34 of the DFPIC or eFPIC chip 400 of its interconnection substrate 177 under the second device, wherein the first device may be its FPGA IC chip 200 and the second device may be its logic computing IC chip 269, for example, or wherein the first device may be its logic computing IC chip 269 and the second device may be its FPGA IC chip 200, for example. The DFPIC or eFPIC chip 400 of its interconnection substrate 177 may include (1) the first type of field programmable logic cell or element (LCE) 2014 or 2014-2 as illustrated in FIGS. 1A, 4D and 4E, the data inputs A0 and A1 of which may couple to the first device through, in sequence, respective two of the small input/output (SIO) circuits 203, or metal pads or input/output (I/O) pads, of the DFPIC or eFPIC chip 400 of its interconnection substrate 177, respective two of the first group of the first type of micro-bumps, micro-pillars or micro-pads 34 of the DFPIC or eFPIC chip 400 of its interconnection substrate 177 and respective two of the first, second, third or fourth type of micro-bumps, micro-pillars or micro-pads 34 of the first device, and the data output Dout of which may couple to the second device through, in sequence, another of the small input/output (SIO) circuits 203, or metal pads or input/output (I/O) pads, of the DFPIC or eFPIC chip 400 of its interconnection substrate 177, one of the second group of the first type of micro-bumps, micro-pillars or micro-pads 34 of the DFPIC or eFPIC chip 400 of its interconnection substrate 177 and one of the first, second, third or fourth type of micro-bumps, micro-pillars or micro-pads 34 of the second device, (2) the second or third type of field programmable logic cell or element (LCE) 2014 or 2014-2 as illustrated in FIGS. 1B, 1C, 4D and 4E, the data inputs A0-A3 of which may couple to the first device through, in sequence, respective four of the small input/output (SIO) circuits 203, or metal pads or input/output (I/O) pads, of the DFPIC or eFPIC chip 400 of its interconnection substrate 177, respective four of the first group of the first type of micro-bumps, micro-pillars or micro-pads 34 of the DFPIC or eFPIC chip 400 of its interconnection substrate 177 and respective four of the first, second, third or fourth type of micro-bumps, micro-pillars or micro-pads 34 of the first device, and the data output Dout of which may couple to the second device through, in sequence, another of the small input/output (SIO) circuits 203, or metal pads or input/output (I/O) pads, of the DFPIC or eFPIC chip 400 of its interconnection substrate 177, one of the second group of the first type of micro-bumps, micro-pillars or micro-pads 34 of the DFPIC or eFPIC chip 400 of its interconnection substrate 177 and one of the first, second, third or fourth type of micro-bumps, micro-pillars or micro-pads 34 of the second device, (3) the first type of field programmable switch cell 379 or 379-2 as illustrated in FIGS. 2A, 4D and 4E, the node N21 of which may couple to the first device through, in sequence, one of the small input/output (SIO) circuits 203, or metal pads or input/output (I/O) pads, of the DFPIC or eFPIC chip 400 of its interconnection substrate 177, one of the first group of the first type of micro-bumps, micro-pillars or micro-pads 34 of the DFPIC or eFPIC chip 400 of its interconnection substrate 177 and one of the first, second, third or fourth type of micro-bumps, micro-pillars or micro-pads 34 of the first device, and the node N22 of which may couple to the second device through, in sequence, another of the small input/output (SIO) circuits 203, or metal pads or input/output (I/O) pads, of the DFPIC or eFPIC chip 400 of its interconnection substrate 177, one of the second group of the first type of micro-bumps, micro-pillars or micro-pads 34 of the DFPIC or eFPIC chip 400 of its interconnection substrate 177 and one of the first, second, third or fourth type of micro-bumps, micro-pillars or micro-pads 34 of the second device, to control coupling between the first and second devices, (4) the second type of field programmable switch cell 379 or 379-2 as illustrated in FIGS. 2B, 4D and 4E, the nodes N23 and N24 of which may couple to the first device through, in sequence, respective two of the small input/output (SIO) circuits 203, or metal pads or input/output (I/O) pads, of the DFPIC or eFPIC chip 400 of its interconnection substrate 177, respective two of the first group of the first type of micro-bumps, micro-pillars or micro-pads 34 of the DFPIC or eFPIC chip 400 of its interconnection substrate 177 and respective two of the first, second, third or fourth type of micro-bumps, micro-pillars or micro-pads 34 of the first device, and the nodes N25 and N26 of which may couple to the second device through, in sequence, another respective two of the small input/output (SIO) circuits 203, or metal pads or input/output (I/O) pads, of the DFPIC or eFPIC chip 400 of its interconnection substrate 177, respective two of the second group of the first type of micro-bumps, micro-pillars or micro-pads 34 of the DFPIC or eFPIC chip 400 of its interconnection substrate 177 and respective two of the first, second, third or fourth type of micro-bumps, micro-pillars or micro-pads 34 of the second device, to control coupling from the node N23 to one or more of the nodes N24-N26 or to control coupling from the node N26 to one or more of the nodes N23-N25, (5) the field programmable switch matrix 710 or 710-3 as illustrated in FIGS. 2C, 4D and 4E, each of the nodes P₁-P_{N} of which may couple to the first device through, in sequence, one of the first metal lines 281 of the DFPIC or eFPIC chip 400 of its interconnection substrate 177, one of the small input/output (SIO) circuits 203, or metal pads or input/output (I/O) pads, of the DFPIC or eFPIC chip 400 of its interconnection substrate 177, one of the first group of the first type of micro-bumps, micro-pillars or micro-pads 34 of the DFPIC or eFPIC chip 400 of its interconnection substrate 177 and one of the first, second, third or fourth type of micro-bumps, micro-pillars or micro-pads 34 of the first device, each of the nodes Q₁-Q_{M} of which may couple to the second device through, in sequence, one of the second metal lines 282 of the DFPIC or eFPIC chip 400 of its interconnection substrate 177, another of the small input/output (SIO) circuits 203, or metal pads or input/output (I/O) pads, of the DFPIC or eFPIC chip 400 of its interconnection substrate 177, one of the second group of the first type of micro-bumps, micro-pillars or micro-pads 34 of the DFPIC or eFPIC chip 400 of its interconnection substrate 177 and one of the first, second, third or fourth type of micro-bumps, micro-pillars or micro-pads 34 of the second device, and each of the pass/no-pass switches 778 of which may control coupling between the first and second devices, i.e., between one of the first group of the first type of micro-bumps, micro-pillars or micro-pads 34 of the DFPIC or eFPIC chip 400 of its interconnection substrate 177 and one of the second group of the first type of micro-bumps, micro-pillars or micro-pads 34 of the DFPIC or eFPIC chip 400 of its interconnection substrate 177, and/or (6) the field programmable switch matrix 710-2 as illustrated in FIGS. 2C and 4E, each of some of the nodes P₁-P_{N} of which may couple to the first device through, in sequence, one of the first metal lines 281 of the DFPIC or eFPIC chip 400 of its interconnection substrate 177, one of the small input/output (SIO) circuits 203, or metal pads or input/output (I/O) pads, of the DFPIC or eFPIC chip 400 of its interconnection substrate 177, one of the first group of the first type of micro-bumps, micro-pillars or micro-pads 34 of the DFPIC or eFPIC chip 400 of its interconnection substrate 177 and one of the first, second, third or fourth type of micro-bumps, micro-pillars or micro-pads 34 of the first device, each of the other some of the nodes P₁-P_{N} of which may couple to the second device through, in sequence, another of the first metal lines 281 of the DFPIC or eFPIC chip 400 of its interconnection substrate 177, another of the small input/output (SIO) circuits 203, or metal pads or input/output (I/O) pads, of the DFPIC or eFPIC chip 400 of its interconnection substrate 177, one of the second group of the first type of micro-bumps, micro-pillars or micro-pads 34 of the DFPIC or eFPIC chip 400 of its interconnection substrate 177 and one of the first, second, third or fourth type of micro-bumps, micro-pillars or micro-pads 34 of the second device, and each of the pass/no-pass switches 778 of which may control coupling between one of the first and second devices and one of the internal circuits of the fourth one of the ASIC cores 215 of the DFPIC or eFPIC chip 400 of its interconnection substrate 177, i.e., between one of the first and second groups of the first type of micro-bumps, micro-pillars or micro-pads 34 of the DFPIC or eFPIC chip 400 of its interconnection substrate 177 and one of the internal circuits of the fourth one of the ASIC cores 215 of the DFPIC or eFPIC chip 400 of its interconnection substrate 177.

### Fourth Type of FPMCP

FIG. 12 is a schematically cross-sectional view showing a fourth type of FPMCP in accordance with an embodiment of the present application. Referring to FIG. 12, a fourth type of FPMCP 307 may include a similar interconnection substrate 177 to one as illustrated in FIG. 9A. For an element indicated by the same reference number shown in FIGS. 9A and 12, the specification of the element as seen in FIG. 12 may be referred to that of the element as illustrated in FIG. 9A. The difference therebetween is that the NVM IC chip 250 of the fourth structure 304 for each of the first type of FPMCPs 300 for the first and second alternatives and one of the auxiliary IC chip 411 of the fourth structure 304 for each of the first type of FPMCPs 300 for the first and second alternatives may be arranged in the interconnection substrate 177 for the fourth type of FPMCP 307 as seen in FIG. 12. For the fourth type of FPMCP 307, its NVM IC chip 250 may have the same specification as the third type of semiconductor IC chip 100 as illustrated in FIG. 3C and its auxiliary IC chip 411 may have the same specification as the fourth type of semiconductor IC chip 100 as illustrated in FIGS. 3D and 3G-3J.

Referring to FIG. 12, the fourth type of FPMCP 307 may further include a FPGA IC chip 200 having the specification as illustrated for one in FIG. 5A-1 over its interconnection substrate 177, and a logic computing IC chip 269, such as the graphic-processing-unit (GPU) IC chip 269a, central-processing-unit (CPU) IC chip 269b or application-specific integrated-circuit (ASIC) chip or system-on-chip (SoC) chip 269c as illustrated in FIG. 5A-1 or such as data processing unit (DPU) IC chip, tensor flow processing unit (TPU) IC chip or digital-signal-processing (DSP) chip, over its interconnection substrate 177. For the fourth type of FPMCP 307, each of its FPGA IC chip 200 and logic computing IC chip 269 may have the same specification as the first type of semiconductor IC chip 100 illustrated in FIG. 3A to be turned upside down. Its FPGA IC chip 200 may be the dedicated field programmable integrated-circuit (DFPIC) chip as illustrated in FIG. 4D or embedded field programmable integrated-circuit (eFPIC) chip as illustrated in FIG. 4E.

Referring to FIG. 12, for the fourth type of FPMCP 307, its NVM IC chip 250 may be embedded in its interconnection substrate 177 and under its FPGA IC chip 200, and its auxiliary IC chip 411 may be embedded in its interconnection substrate 177 and under its FPGA IC chip 200 and logic computing IC chip 269. The polymer layer 92, i.e., insulating dielectric layer or sealing layer, of its interconnection substrate 177 may be horizontally around each of the vertical-through-via (VTV) connectors 467 of its interconnection substrate 177 and each of its NVM IC chip 250 and auxiliary IC chip 411 and in each gap between neighboring two of the vertical-through-via (VTV) connectors 467 of its interconnection substrate 177 and its NVM IC chip 250 and auxiliary IC chip 411, wherein the polymer layer 92 of its interconnection substrate 177 may have a top surface coplanar with the top surface of the polymer layer 257 of each of the vertical-through-via (VTV) connectors 467 of its interconnection substrate 177, the top surface of each of the first type of micro-bumps, micro-pillars or micro-pads 34 of each of the vertical-through-via (VTV) connectors 467 of its interconnection substrate 177, the top surface of the polymer layer 257 of each of its NVM IC chip 250 and auxiliary IC chip 411 and the top surface of each of the first type of micro-bumps, micro-pillars or micro-pads 34 of each of its NVM IC chip 250 and auxiliary IC chip 411. Each of the semiconductor substrate 2 of each of its NVM IC chip 250 and auxiliary IC chip 411 and the semiconductor substrate 2 of each of the vertical-through-via (VTV) connectors 467 of its interconnection substrate 177 may have a portion, at a backside of said each of the semiconductor substrates 2, removed by a chemical-mechanical-polishing (CMP) or mechanical grinding process such that each of the through silicon vias (TSVs) 157, that is, the electroplated copper layer 156 thereof, of its auxiliary IC chip 411 may have a bottom surface substantially coplanar with a bottom surface of each of the through silicon vias (TSVs) 157, that is, the electroplated copper layer 156 thereof, of each of the vertical-through-via (VTV) connectors 467 of its interconnection substrate 177, a bottom surface of the semiconductor substrate 2 of each of its NVM IC chip 250 and auxiliary IC chip 411 and a bottom surface of the semiconductor substrate 2 of each of the vertical-through-via (VTV) connectors 467 of its interconnection substrate 177 and a bottom surface of the polymer layer 92 of its interconnection substrate 177. For an alternative case, its interconnection substrates 177 may further include the insulating dielectric layer 185, such as silicon-oxide layer or silicon-nitride layer, illustrated in FIG. 4C but not shown in FIG. 12 formed on a bottom surface of the semiconductor substrate 2 of each of the vertical-through-via (VTV) connectors 467 of its interconnection substrate 177 and a bottom surface of the semiconductor substrate 2 of each of its NVM IC chip 250 and auxiliary IC chip 411, wherein the insulating dielectric layer 185 of its interconnection substrate 177 may have a bottom surface coplanar with the bottom surface of each of the through silicon vias 157 of each of the vertical-through-via (VTV) connectors 467 of its interconnection substrate 177, the bottom surface of each of the through silicon vias 157 of its auxiliary IC chip 411 and the bottom surface of the polymer layer 92 of its interconnection substrate 177. The topmost one of the polymer layers 42 of the interconnection scheme 79 of its interconnection substrate 177 may have a top surface in contact with the bottom surface of the polymer layer 92 of its interconnection substrate 177, the bottom surface of the semiconductor substrate 2 of each of the vertical-through-via (VTV) connectors 467 of its interconnection substrate 177 and the bottom surface of the semiconductor substrate 2 of each of its NVM IC chip 250 and auxiliary IC chip 411. For the alternative case, the topmost one of the polymer layers 42 of the interconnection scheme 79 of its interconnection substrate 177 may have a top surface in contact with the bottom surface of the polymer layer 92 of its interconnection substrate 177 and the bottom surface of the insulating dielectric layer 185 of its interconnection substrate 177. Each opening in the topmost one of the polymer layers 42 of the interconnection scheme 79 of its interconnection substrate 177 may be under one of the through silicon vias (TSVs) 157 of one of the vertical-through-via (VTV) connectors 467 of its interconnection substrate 177 or one of the through silicon vias (TSVs) 157 of its auxiliary IC chip 411, and thus the topmost one of the interconnection metal layers 27 of the interconnection scheme 79 of its interconnection substrate 177 may extend through said each opening to couple to said one of the through silicon vias (TSVs) 157. Each of the interconnection metal layers 27 of the interconnection scheme 79 of its interconnection substrate 177 may extend horizontally across an edge of each of its NVM IC chip 250 and auxiliary IC chip 411 and an edge of each of the vertical-through-via (VTV) connectors 467 of its interconnection substrate 177.

Referring to FIG. 12, for the fourth type of FPMCP 307, each of its FPGA IC chip 200 and logic computing IC chip 269 may have the first, second, third or fourth type of micro-bumps, micro-pillars or micro-pads 34 as illustrated in FIG. 3A each bonded to one of the first type of micro-bumps, micro-pillars or micro-pads 34 of one of the vertical-through-via (VTV) connectors 467 of its interconnection substrate 177 or one of the first type of micro-bumps, micro-pillars or micro-pads 34 of one of its NVM IC chip 250 and auxiliary IC chip 411. The bottom surface of the semiconductor substrate 2 of its FPGA IC chip 200, at which the semiconductor devices 4, such as transistors, of its FPGA IC chip 200 are formed as illustrated in FIG. 3A to be turned upside down, faces the top surface of the semiconductor substrate 2 of its NVM IC chip 250, at which the semiconductor devices 4, such as transistors, of its NVM IC chip 250 are formed as illustrated in FIG. 3C, and the top surface of the semiconductor substrate 2 of its auxiliary IC chip 411, at which the semiconductor devices 4, such as transistors, of its auxiliary IC chip 411 are formed as illustrated in FIGS. 3D and 3G-3J. The bottom surface of the semiconductor substrate 2 of its logic computing IC chip 269, at which the semiconductor devices 4, such as transistors, of its logic computing IC chip 269 are formed as illustrated in FIG. 3A to be turned upside down, faces the top surface of the semiconductor substrate 2 of its auxiliary IC chip 411, at which the semiconductor devices 4, such as transistors, of its auxiliary IC chip 411 are formed as illustrated in FIGS. 3D and 3G-3J. Its underfill 564, i.e., polymer layer, may be formed between each of its FPGA IC chip 200 and logic computing IC chip 269 and its interconnection substrate 177, covering a sidewall of each of the first, second, third or fourth type of micro-bumps, micro-pillars or micro-pads 34 of each of its FPGA IC chip 200 and logic computing IC chip 269. Its polymer layer 192, i.e., insulating dielectric layer or sealing layer, may be formed on its interconnection substrate 177 and horizontally around its FPGA IC chip 200 and logic computing IC chip 269, wherein its polymer layer 192 may have a top surface coplanar with a top surface of each of its FPGA IC chip 200 and logic computing IC chip 269. Its polymer layer 192 may have a vertical sidewall coplanar with a vertical sidewall of each of the polymer layer 92 and interconnection scheme 79 of its interconnection substrate 177.

Referring to FIG. 12, for the fourth type of FPMCP 307, its auxiliary IC chip 411 may be arranged under its FPGA IC chip 200 and logic computing IC chip 269 and may have the interconnection metal layers 6 and/or 27 of the first and/or second interconnection scheme for a chip (FISC and/or SISC) 20 and/or 29 coupling its FPGA IC chip 200 to its logic computing IC chip 269 for transmitting a signal or clock or delivering a power or ground voltage therebetween. Each of its FPGA IC chip 200 and logic computing IC chip 269 may couple to one of its metal bumps, pillars or pads 570, which are in an array at its bottom to act as its external pins for coupling to external circuits outside of the fourth type of FPMCP 307, through, in sequence, one of the through silicon vias (TSVs) 157 of one of the vertical-through-via (VTV) connectors 467 of its interconnection substrate 177 and each of the interconnection metal layers 27 of the interconnection scheme 79 of its interconnection substrate 177 for transmitting a signal or clock or delivering a power or ground voltage therebetween. Alternatively, each of its FPGA IC chip 200 and logic computing IC chip 269 may couple to one of its metal bumps, pillars or pads 570, which are in an array at its bottom to act as its external pins for coupling to external circuits outside of the fourth type of FPMCP 307, through, in sequence, one of the through silicon vias (TSVs) 157 of its auxiliary IC chip 411 and each of the interconnection metal layers 27 of the interconnection scheme 79 of its interconnection substrate 177 for transmitting a signal or clock or delivering a power or ground voltage therebetween.

Referring to FIG. 12, the fourth type of FPMCP 307 may have the inter-chip interconnection between the first and second semiconductor IC chips 100a and 100b via the FPGA IC chip 200 as illustrated in FIG. 5B. For the fourth type of FPMCP 307, its FPGA IC chip 200 may have the same circuits as one illustrated in FIG. 5B. For a first example, its logic computing IC chip 269 may be the first semiconductor IC chip 100a as illustrated in FIG. 5B, and its auxiliary IC chip 411 may be the second semiconductor IC chip 100b as illustrated in FIG. 5B. In the first example, any bonded two of the first, second, third or fourth type of micro-bumps, micro-pillars or micro-pads 34 of the FPGA IC chip 200 and second semiconductor IC chip 100b, one or more of the interconnection metal layers 6 and/or 27 of the first and/or second interconnection scheme for a chip (FISC and/or SISC) 20 and/or 29 of the second semiconductor IC chip 100b and any bonded two of the first, second, third or fourth type of micro-bumps, micro-pillars or micro-pads 34 of the first and second semiconductor IC chips 100a and 100b for the fourth type of FPMCP 307 may be formed for one of the programmable interconnects 361 of the inter-chip interconnects 371 between the FPGA IC chip 200 and first semiconductor IC chip 100a as illustrated in FIG. 5B, or any bonded two of the first, second, third or fourth type of micro-bumps, micro-pillars or micro-pads 34 of the FPGA IC chip 200 and a first one of the vertical-through-via (VTV) connectors 467, any of the through silicon vias (TSVs) 157 of the first one of the vertical-through-via (VTV) connectors 467, one or more of the interconnection metal layers 27 of the interconnection scheme 79, any of the through silicon vias (TSVs) 157 of a second one of the vertical-through-via (VTV) connectors 467 under the first semiconductor IC chip 100a, any bonded two of the first, second, third or fourth type of micro-bumps, micro-pillars or micro-pads 34 of the first semiconductor IC chip 100a and second one of the vertical-through-via (VTV) connectors 467 for the fourth type of FPMCP 307 may be formed for one of the programmable interconnects 361 of the inter-chip interconnects 371 between the FPGA IC chip 200 and first semiconductor IC chip 100a as illustrated in FIG. 5B. Each bonded two of the first, second, third or fourth type of micro-bumps, micro-pillars or micro-pads 34 of the FPGA IC chip 200 and second semiconductor IC chip 100b for the fourth type of FPMCP 307 may be formed for one of the programmable interconnects 361 of the inter-chip interconnects 371 between the FPGA IC chip 200 and second semiconductor IC chip 100b as illustrated in FIG. 5B. For a second example, its logic computing IC chip 269 may be the first semiconductor IC chip 100a as illustrated in FIG. 5B, and its NVM IC chip 250 may be the second semiconductor IC chip 100b as illustrated in FIG. 5B. In the second example, any bonded two of the first, second, third or fourth type of micro-bumps, micro-pillars or micro-pads 34 of the FPGA IC chip 200 and auxiliary IC chip 411, one or more of the interconnection metal layers 6 and/or 27 of the first and/or second interconnection scheme for a chip (FISC and/or SISC) 20 and/or 29 of the auxiliary IC chip 411 and any bonded two of the first, second, third or fourth type of micro-bumps, micro-pillars or micro-pads 34 of the first semiconductor IC chip 100a and auxiliary IC chip 411 for the fourth type of FPMCP 307 may be formed for one of the programmable interconnects 361 of the inter-chip interconnects 371 between the FPGA IC chip 200 and first semiconductor IC chip 100a as illustrated in FIG. 5B, or any bonded two of the first, second, third or fourth type of micro-bumps, micro-pillars or micro-pads 34 of the FPGA IC chip 200 and first one of the vertical-through-via (VTV) connectors 467, any of the through silicon vias (TSVs) 157 of the first one of the vertical-through-via (VTV) connectors 467, one or more of the interconnection metal layers 27 of the interconnection scheme 79, any of the through silicon vias (TSVs) 157 of a second one of the vertical-through-via (VTV) connectors 467 under the first semiconductor IC chip 100a and any bonded two of the first, second, third or fourth type of micro-bumps, micro-pillars or micro-pads 34 of the first semiconductor IC chip 100a and second one of the vertical-through-via (VTV) connectors 467 for the fourth type of FPMCP 307 may be formed for one of the programmable interconnects 361 of the inter-chip interconnects 371 between the FPGA IC chip 200 and first semiconductor IC chip 100a as illustrated in FIG. 5B. Any bonded two of the first, second, third or fourth type of micro-bumps, micro-pillars or micro-pads 34 of the FPGA IC chip 200 and auxiliary IC chip 411, one or more of the interconnection metal layers 6 and/or 27 of the first and/or second interconnection scheme for a chip (FISC and/or SISC) 20 and/or 29 of the auxiliary IC chip 411, any bonded two of the first, second, third or fourth type of micro-bumps, micro-pillars or micro-pads 34 of the auxiliary IC chip 411 and first semiconductor IC chip 100a, one or more of the interconnection metal layers 6 and/or 27 of the first and/or second interconnection scheme for a chip (FISC and/or SISC) 20 and/or 29 of the first semiconductor IC chip 100a and any bonded two of the first, second, third or fourth type of micro-bumps, micro-pillars or micro-pads 34 of the first and second semiconductor IC chips 100a and 100b for the fourth type of FPMCP 307 may be formed for one of the programmable interconnects 361 of the inter-chip interconnects 371 between the FPGA IC chip 200 and second semiconductor IC chip 100b as illustrated in FIG. 5B, or any bonded two of the first, second, third or fourth type of micro-bumps, micro-pillars or micro-pads 34 of the FPGA IC chip 200 and first one of the vertical-through-via (VTV) connectors 467, any of the through silicon vias (TSVs) 157 of the first one of the vertical-through-via (VTV) connectors 467, one or more of the interconnection metal layers 27 of the interconnection scheme 79, any of the through silicon vias (TSVs) 157 of the second one of the vertical-through-via (VTV) connectors 467, any bonded two of the first, second, third or fourth type of micro-bumps, micro-pillars or micro-pads 34 of the first semiconductor IC chip 100a and second one of the vertical-through-via (VTV) connectors 467, one or more of the interconnection metal layers 6 and/or 27 of the first and/or second interconnection scheme for a chip (FISC and/or SISC) 20 and/or 29 of the first semiconductor IC chip 100a and any bonded two of the first, second, third or fourth type of micro-bumps, micro-pillars or micro-pads 34 of the first and second semiconductor IC chips 100a and 100b for the fourth type of FPMCP 307 may be formed for one of the programmable interconnects 361 of the inter-chip interconnects 371 between the FPGA IC chip 200 and second semiconductor IC chip 100b as illustrated in FIG. 5B. For a third example, its auxiliary IC chip 411 may be the first semiconductor IC chip 100a as illustrated in FIG. 5B, and its NVM IC chip 250 may be the second semiconductor IC chip 100b as illustrated in FIG. 5B. In the third example, each bonded two of the first, second, third or fourth type of micro-bumps, micro-pillars or micro-pads 34 of the FPGA IC chip 200 and first semiconductor IC chip 100a for the fourth type of FPMCP 307 may be formed for one of the programmable interconnects 361 of the inter-chip interconnects 371 between the FPGA IC chip 200 and first semiconductor IC chip 100a as illustrated in FIG. 5B. Any bonded two of the first, second, third or fourth type of micro-bumps, micro-pillars or micro-pads 34 of the first semiconductor IC chip 100a and FPGA IC chip 200, one or more of the interconnection metal layers 6 and/or 27 of the first and/or second interconnection scheme for a chip (FISC and/or SISC) 20 and/or 29 of the first semiconductor IC chip 100a, any bonded two of the first, second, third or fourth type of micro-bumps, micro-pillars or micro-pads 34 of the logic computing IC chip 269 and first semiconductor IC chip 100a, one or more of the interconnection metal layers 6 and/or 27 of the first and/or second interconnection scheme for a chip (FISC and/or SISC) 20 and/or 29 of the logic computing IC chip 269 and any bonded two of the first, second, third or fourth type of micro-bumps, micro-pillars or micro-pads 34 of the second semiconductor IC chip 100b and logic computing IC chip 269 for the fourth type of FPMCP 307 may be formed for one of the programmable interconnects 361 of the inter-chip interconnects 371 between the FPGA IC chip 200 and second semiconductor IC chip 100b as illustrated in FIG. 5B, or any bonded two of the first, second, third or fourth type of micro-bumps, micro-pillars or micro-pads 34 of the FPGA IC chip 200 and first one of the vertical-through-via (VTV) connectors 467, any of the through silicon vias (TSVs) 157 of the first one of the vertical-through-via (VTV) connectors 467, one or more of the interconnection metal layers 27 of the interconnection scheme 79, any of the through silicon vias (TSVs) 157 of the second one of the vertical-through-via (VTV) connectors 467, any bonded two of the first, second, third or fourth type of micro-bumps, micro-pillars or micro-pads 34 of the logic computing IC chip 269 and second one of the vertical-through-via (VTV) connectors 467, one or more of the interconnection metal layers 6 and/or 27 of the first and/or second interconnection scheme for a chip (FISC and/or SISC) 20 and/or 29 of the logic computing IC chip 269 and any bonded two of the first, second, third or fourth type of micro-bumps, micro-pillars or micro-pads 34 of the second semiconductor IC chip 100b and logic computing IC chip 269 for the fourth type of FPMCP 307 may be formed for one of the programmable interconnects 361 of the inter-chip interconnects 371 between the FPGA IC chip 200 and second semiconductor IC chip 100b as illustrated in FIG. 5B.

Referring to FIG. 12, the fourth type of FPMCP 307 may perform the operation between the FPGA IC chip 200 and each of the third and fourth semiconductor IC chips 100c and 100d as illustrated in FIG. 5C. For the fourth type of FPMCP 307, its FPGA IC chip 200 may have the same circuits as one illustrated in FIG. 5C. For a first example, its logic computing IC chip 269 may be the third semiconductor IC chip 100c as illustrated in FIG. 5C, and its auxiliary IC chip 411 may be the fourth semiconductor IC chip 100d as illustrated in FIG. 5C. In the first example, any bonded two of the first, second, third or fourth type of micro-bumps, micro-pillars or micro-pads 34 of the FPGA IC chip 200 and fourth semiconductor IC chip 100d, one or more of the interconnection metal layers 6 and/or 27 of the first and/or second interconnection scheme for a chip (FISC and/or SISC) 20 and/or 29 of the fourth semiconductor IC chip 100d and any bonded two of the first, second, third or fourth type of micro-bumps, micro-pillars or micro-pads 34 of the third and fourth semiconductor IC chips 100c and 100d for the fourth type of FPMCP 307 may be formed for one of the programmable interconnects 361 of the inter-chip interconnects 371 between the FPGA IC chip 200 and third semiconductor IC chip 100c as illustrated in FIG. 5C, or any bonded two of the first, second, third or fourth type of micro-bumps, micro-pillars or micro-pads 34 of the FPGA IC chip 200 and first one of the vertical-through-via (VTV) connectors 467, any of the through silicon vias (TSVs) 157 of the first one of the vertical-through-via (VTV) connectors 467, one or more of the interconnection metal layers 27 of the interconnection scheme 79, any of the through silicon vias (TSVs) 157 of the second one of the vertical-through-via (VTV) connectors 467, any bonded two of the first, second, third or fourth type of micro-bumps, micro-pillars or micro-pads 34 of the third semiconductor IC chip 100c and second one of the vertical-through-via (VTV) connectors 467 for the fourth type of FPMCP 307 may be formed for one of the programmable interconnects 361 of the inter-chip interconnects 371 between the FPGA IC chip 200 and third semiconductor IC chip 100c as illustrated in FIG. 5C. Each bonded two of the first, second, third or fourth type of micro-bumps, micro-pillars or micro-pads 34 of the FPGA IC chip 200 and fourth semiconductor IC chip 100d for the fourth type of FPMCP 307 may be formed for one of the programmable interconnects 361 of the inter-chip interconnects 371 between the FPGA IC chip 200 and fourth semiconductor IC chip 100d as illustrated in FIG. 5C. For a second example, its logic computing IC chip 269 may be the third semiconductor IC chip 100c as illustrated in FIG. 5C, and its NVM IC chip 250 may be the fourth semiconductor IC chip 100d as illustrated in FIG. 5D. In the second example, any bonded two of the first, second, third or fourth type of micro-bumps, micro-pillars or micro-pads 34 of the FPGA IC chip 200 and auxiliary IC chip 411, one or more of the interconnection metal layers 6 and/or 27 of the first and/or second interconnection scheme for a chip (FISC and/or SISC) 20 and/or 29 of the auxiliary IC chip 411 and any bonded two of the first, second, third or fourth type of micro-bumps, micro-pillars or micro-pads 34 of the third semiconductor IC chip 100c and auxiliary IC chip 411 for the fourth type of FPMCP 307 may be formed for one of the programmable interconnects 361 of the inter-chip interconnects 371 between the FPGA IC chip 200 and third semiconductor IC chip 100c as illustrated in FIG. 5C, or any bonded two of the first, second, third or fourth type of micro-bumps, micro-pillars or micro-pads 34 of the FPGA IC chip 200 and first one of the vertical-through-via (VTV) connectors 467, any of the through silicon vias (TSVs) 157 of the first one of the vertical-through-via (VTV) connectors 467, one or more of the interconnection metal layers 27 of the interconnection scheme 79, any of the through silicon vias (TSVs) 157 of the second one of the vertical-through-via (VTV) connectors 467, any bonded two of the first, second, third or fourth type of micro-bumps, micro-pillars or micro-pads 34 of the third semiconductor IC chip 100c and second one of the vertical-through-via (VTV) connectors 467 for the fourth type of FPMCP 307 may be formed for one of the programmable interconnects 361 of the inter-chip interconnects 371 between the FPGA IC chip 200 and third semiconductor IC chip 100c as illustrated in FIG. 5C. Any bonded two of the first, second, third or fourth type of micro-bumps, micro-pillars or micro-pads 34 of the FPGA IC chip 200 and auxiliary IC chip 411, one or more of the interconnection metal layers 6 and/or 27 of the first and/or second interconnection scheme for a chip (FISC and/or SISC) 20 and/or 29 of the auxiliary IC chip 411, any bonded two of the first, second, third or fourth type of micro-bumps, micro-pillars or micro-pads 34 of the auxiliary IC chip 411 and third semiconductor IC chip 100c, one or more of the interconnection metal layers 6 and/or 27 of the first and/or second interconnection scheme for a chip (FISC and/or SISC) 20 and/or 29 of the third semiconductor IC chip 100c and any bonded two of the first, second, third or fourth type of micro-bumps, micro-pillars or micro-pads 34 of the third and fourth semiconductor IC chips 100c and 100d for the fourth type of FPMCP 307 may be formed for one of the programmable interconnects 361 of the inter-chip interconnects 371 between the FPGA IC chip 200 and fourth semiconductor IC chip 100d as illustrated in FIG. 5C, or any bonded two of the first, second, third or fourth type of micro-bumps, micro-pillars or micro-pads 34 of the FPGA IC chip 200 and first one of the vertical-through-via (VTV) connectors 467, any of the through silicon vias (TSVs) 157 of the first one of the vertical-through-via (VTV) connectors 467, one or more of the interconnection metal layers 27 of the interconnection scheme 79, any of the through silicon vias (TSVs) 157 of the second one of the vertical-through-via (VTV) connectors 467, any bonded two of the first, second, third or fourth type of micro-bumps, micro-pillars or micro-pads 34 of the third semiconductor IC chip 100c and second one of the vertical-through-via (VTV) connectors 467, one or more of the interconnection metal layers 6 and/or 27 of the first and/or second interconnection scheme for a chip (FISC and/or SISC) 20 and/or 29 of the third semiconductor IC chip 100c and any bonded two of the first, second, third or fourth type of micro-bumps, micro-pillars or micro-pads 34 of the third and fourth semiconductor IC chips 100c and 100d for the fourth type of FPMCP 307 may be formed for one of the programmable interconnects 361 of the inter-chip interconnects 371 between the FPGA IC chip 200 and fourth semiconductor IC chip 100d as illustrated in FIG. 5C.

Referring to FIG. 12, the fourth type of FPMCP 307 may have the connection to external circuits as illustrated in FIG. 5D. For the fourth type of FPMCP 307, its FPGA IC chip 200 may have the same circuits as one illustrated in FIG. 5D, its auxiliary IC chip 411 may have the same circuits as one illustrated in FIG. 5D, its logic computing IC chip 269 may be the fifth semiconductor IC chip 100e as illustrated in FIG. 5D, and its NVM IC chip 250 may be the sixth semiconductor IC chip 100f as illustrated in FIG. 5D. Any bonded two of the first, second, third or fourth type of micro-bumps, micro-pillars or micro-pads 34 of the FPGA IC chip 200 and auxiliary IC chip 411, one or more of the interconnection metal layers 6 and/or 27 of the first and/or second interconnection scheme for a chip (FISC and/or SISC) 20 and/or 29 of the auxiliary IC chip 411 and any bonded two of the first, second, third or fourth type of micro-bumps, micro-pillars or micro-pads 34 of the fifth semiconductor IC chips 100e and auxiliary IC chip 411 for the fourth type of FPMCP 307 may be formed for one of the programmable interconnects 361 of the inter-chip interconnects 371 between the FPGA IC chip 200 and fifth semiconductor IC chip 100e as illustrated in FIG. 5D, or any bonded two of the first, second, third or fourth type of micro-bumps, micro-pillars or micro-pads 34 of the FPGA IC chip 200 and first one of the vertical-through-via (VTV) connectors 467, any of the through silicon vias (TSVs) 157 of the first one of the vertical-through-via (VTV) connectors 467, one or more of the interconnection metal layers 27 of the interconnection scheme 79, any of the through silicon vias (TSVs) 157 of the second one of the vertical-through-via (VTV) connectors 467, any bonded two of the first, second, third or fourth type of micro-bumps, micro-pillars or micro-pads 34 of the fifth semiconductor IC chip 100e and second one of the vertical-through-via (VTV) connectors 467 for the fourth type of FPMCP 307 may be formed for one of the programmable interconnects 361 of the inter-chip interconnects 371 between the FPGA IC chip 200 and fifth semiconductor IC chip 100e as illustrated in FIG. 5D. Any bonded two of the first, second, third or fourth type of micro-bumps, micro-pillars or micro-pads 34 of the FPGA IC chip 200 and auxiliary IC chip 411, one or more of the interconnection metal layers 6 and/or 27 of the first and/or second interconnection scheme for a chip (FISC and/or SISC) 20 and/or 29 of the auxiliary IC chip 411, any bonded two of the first, second, third or fourth type of micro-bumps, micro-pillars or micro-pads 34 of the auxiliary IC chip 411 and fifth semiconductor IC chip 100e, one or more of the interconnection metal layers 6 and/or 27 of the first and/or second interconnection scheme for a chip (FISC and/or SISC) 20 and/or 29 of the fifth semiconductor IC chip 100e and any bonded two of the first, second, third or fourth type of micro-bumps, micro-pillars or micro-pads 34 of the fifth and sixth semiconductor IC chips 100e and 100f for the fourth type of FPMCP 307 may be formed for one of the programmable interconnects 361 of the inter-chip interconnects 371 between the FPGA IC chip 200 and sixth semiconductor IC chip 100f as illustrated in FIG. 5D, or any bonded two of the first, second, third or fourth type of micro-bumps, micro-pillars or micro-pads 34 of the FPGA IC chip 200 and first one of the vertical-through-via (VTV) connectors 467, any of the through silicon vias (TSVs) 157 of the first one of the vertical-through-via (VTV) connectors 467, one or more of the interconnection metal layers 27 of the interconnection scheme 79, any of the through silicon vias (TSVs) 157 of the second one of the vertical-through-via (VTV) connectors 467, any bonded two of the first, second, third or fourth type of micro-bumps, micro-pillars or micro-pads 34 of the fifth semiconductor IC chip 100e and second one of the vertical-through-via (VTV) connectors 467, one or more of the interconnection metal layers 6 and/or 27 of the first and/or second interconnection scheme for a chip (FISC and/or SISC) 20 and/or 29 of the fifth semiconductor IC chip 100e and any bonded two of the first, second, third or fourth type of micro-bumps, micro-pillars or micro-pads 34 of the fifth and sixth semiconductor IC chips 100e and 100f for the fourth type of FPMCP 307 may be formed for one of the programmable interconnects 361 of the inter-chip interconnects 371 between the FPGA IC chip 200 and sixth semiconductor IC chip 100f as illustrated in FIG. 5D. Each bonded two of the first, second, third or fourth type of micro-bumps, micro-pillars or micro-pads 34 of the FPGA IC chip 200 and auxiliary IC chip 411 for the fourth type of FPMCP 307 may be formed for one of the programmable interconnects 361 of the inter-chip interconnects 371 between the FPGA IC chip 200 and auxiliary IC chip 411 as illustrated in FIG. 5D. Each of the large input/output (I/O) circuits 341 of the large-input/output (I/O) block of its auxiliary IC chip 411 may couple to one of its metal bumps, pillars or pads 570, which are in an array at its bottom to act as its external pins for coupling to the external circuits 340 as seen in FIG. 5D outside of the fourth type of FPMCP 307, through, in sequence, one of the through silicon vias (TSVs) 157 of its auxiliary IC chip 411 and each of the interconnection metal layers 27 of the interconnection scheme 79 of its interconnection substrate 177.

Referring to FIG. 12, for the fourth type of FPMCP 307, its auxiliary IC chip 411 may include a first small input/output (I/O) circuit coupling to a second small input/output (I/O) circuit of its FPGA IC chip 200 through its first signal path composed of bonded two of the first, second, third or fourth type of micro-bumps, micro-pillars or micro-pads 34 of its auxiliary IC chip 411 and FPGA IC chip 200, wherein each of the first and second small input/output (I/O) circuits may have an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts. Its auxiliary IC chip 411 may include a large input/output (I/O) circuit coupling to any of its metal bumps, pillars or pads 570 through its second signal path composed of any of the through silicon vias (TSVs) 157 of its auxiliary IC chip 411 and each of the interconnection metal layers 27 of the interconnection scheme 79 of its interconnection substrate 177, wherein the large input/output (I/O) circuit may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or equal to or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Thereby, the first small input/output (I/O) circuit may receive first signals from the second small input/output (I/O) circuit via its first signal path to be converted by its auxiliary IC chip 411 as second signals and then the large input/output (I/O) circuit may transmit the second signals to said any of its metal bumps, pillars or pads 570 via its second signal path. Further, the large input/output (I/O) circuit may receive third signals from said any of its metal bumps, pillars or pads 570 via its second signal path to be converted by its auxiliary IC chip 411 as fourth signals and then the first small input/output (I/O) circuit may transmit the fourth signals to the second small input/output (I/O) circuit via its first signal path.

Referring to FIG. 12, for the fourth type of FPMCP 307, its FPGA IC chip 200 may be programmed, configured or reconfigured following the same way as any aspect of the first through eleventh aspects illustrated in FIGS. 5A-1, 5A-2 and 5E-5G, including (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with first data stored in its NVM IC chip 250 to be configured in accordance with the first data, (2) the first or second type of field programmable switch cell 379 as illustrated in FIG. 2A or 2B having the memory cells 362 as illustrated in FIG. 2A or the four sets of memory cells 362 as illustrated in FIG. 2B for storing data associated with second data stored in its NVM IC chip 250 to be configured in accordance with the second data, and (3) the programmable switch matrix 710 as illustrated in FIG. 2C having the memory cells 398 for storing data, i.e., programming codes, password or encryption/decryption codes, associated with third data stored in its NVM IC chip 250 to be configured in accordance with the third data. Alternatively, its FPGA IC chip 200 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MLU) IC chip, or digital-signal-processing (DSP) IC chip, each of which may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with the first data to be configured in accordance with the first data, (2) the first or second type of field programmable switch cell 379 as illustrated in FIG. 2A or 2B having the memory cells 362 as illustrated in FIG. 2A or the four sets of memory cells 362 as illustrated in FIG. 2B for storing data associated with the second data to be configured in accordance with the second data, and (3) the programmable switch matrix 710 as illustrated in FIG. 2C having the memory cells 398 for storing data, i.e., programming codes, password or encryption/decryption codes, associated with the third data to be configured in accordance with the third data. For the fourth type of FPMCP 307 for each aspect of the first through fourth aspects as illustrated in FIG. 5E, its FPGA IC chip 200 may have the same circuits as one illustrated in FIG. 5E, its auxiliary IC chip 411 may have the same circuits as one illustrated in FIG. 5E, its NVM IC chip 250 may have the same circuits as one illustrated in FIG. 5E, and its logic computing IC chip 269 may be any of the semiconductor IC chips 100g as illustrated in FIG. 5E. Any bonded two of the first, second, third or fourth type of micro-bumps, micro-pillars or micro-pads 34 of the FPGA IC chip 200 and auxiliary IC chip 411 for the fourth type of FPMCP 307 as illustrated in FIG. 12 may be formed for one of the non-programmable interconnects 364 of the inter-chip interconnects 371 between the FPGA IC chip 200 and auxiliary IC chip 411 as illustrated in FIG. 5E; any bonded two of the first, second, third or fourth type of micro-bumps, micro-pillars or micro-pads 34 of the logic computing IC chip 269 and NVM IC chip 250, one or more of the interconnection metal layers 6 and/or 27 of the first and/or second interconnection scheme for a chip (FISC and/or SISC) 20 and/or 29 of the logic computing IC chip 269 and any bonded two of the first, second, third or fourth type of micro-bumps, micro-pillars or micro-pads 34 of the logic computing IC chip 269 and auxiliary IC chip 411 for the fourth type of FPMCP 307 as illustrated in FIG. 12 may be formed for one of the non-programmable interconnects 364 of the inter-chip interconnects 371 between the NVM IC chip 250 and auxiliary IC chip 411 as illustrated in FIG. 5E; any bonded two of the first, second, third or fourth type of micro-bumps, micro-pillars or micro-pads 34 of the FPGA IC chip 200 and auxiliary IC chip 411, one or more of the interconnection metal layers 6 and/or 27 of the first and/or second interconnection scheme for a chip (FISC and/or SISC) 20 and/or 29 of the auxiliary IC chip 411 and any bonded two of the first, second, third or fourth type of micro-bumps, micro-pillars or micro-pads 34 of the logic computing IC chip 269 and auxiliary IC chip 411 for the fourth type of FPMCP 307 as illustrated in FIG. 12 may be formed for one of the programmable interconnects 361 of the inter-chip interconnects 371 between the FPGA IC chip 200 and any of the semiconductor IC chips 100g as illustrated in FIG. 5E; any bonded two of the first, second, third or fourth type of micro-bumps, micro-pillars or micro-pads 34 of the logic computing IC chip 269 and NVM IC chip 250, one or more of the interconnection metal layers 6 and/or 27 of the first and/or second interconnection scheme for a chip (FISC and/or SISC) 20 and/or 29 of the logic computing IC chip 269 and any bonded two of the first, second, third or fourth type of micro-bumps, micro-pillars or micro-pads 34 of the logic computing IC chip 269 and second one of the vertical-through-via (VTV) connectors 467, any of the through silicon vias (TSVs) 157 of the second one of the vertical-through-via (VTV) connectors 467, each of the interconnection metal layers 27 of the interconnection scheme 79 and any of the metal bumps, pillars or pads 570 for the fourth type of FPMCP 307 as illustrated in FIG. 12 may be formed for the first group of the large input/output (I/O) circuits 342 of the NVM IC chip 250 receiving and transmitting the first and second (encrypted) CPM data from and to the external circuits 340 as illustrated in FIG. 5E outside of the fourth type of FPMCP 307; optionally for each aspect of the first through third aspects any of the through silicon vias 157 (TSVs) of the auxiliary IC chip 411, each of the interconnection metal layers 27 of the interconnection scheme 79 and any of the metal bumps, pillars or pads 570 for the fourth type of FPMCP 307 as illustrated in FIG. 12 may be formed for the large input/output (I/O) circuits 341 of the large-input/output (I/O) block of the auxiliary IC chip 411 receiving and transmitting the first and second (encrypted) CPM data from and to the external circuits 340 as illustrated in FIG. 5E outside of the fourth type of FPMCP 307. For the fourth type of FPMCP 307 for each aspect of the fifth through eighth aspects as illustrated in FIG. 5F, its FPGA IC chip 200 may have the same circuits as one illustrated in FIG. 5F, its auxiliary IC chip 411 may have the same circuits as one illustrated in FIG. 5F, its NVM IC chip 250 may have the same circuits as one illustrated in FIG. 5F, and its logic computing IC chip 269 may be any of the semiconductor IC chips 100g as illustrated in FIG. 5F. Any bonded two of the first, second, third or fourth type of micro-bumps, micro-pillars or micro-pads 34 of the FPGA IC chip 200 and first one of the vertical-through-via (VTV) connectors 467, any of the through silicon vias (TSVs) 157 of the first one of the vertical-through-via (VTV) connectors 467, one or more of the interconnection metal layers 27 of the interconnection scheme 79, any of the through silicon vias (TSVs) 157 of the second one of the vertical-through-via (VTV) connectors 467, any bonded two of the first, second, third or fourth type of micro-bumps, micro-pillars or micro-pads 34 of the logic computing IC chip 269 and second one of the vertical-through-via (VTV) connectors 467, one or more of the interconnection metal layers 6 and/or 27 of the first and/or second interconnection scheme for a chip (FISC and/or SISC) 20 and/or 29 of the logic computing IC chip 269 and any bonded two of the first, second, third or fourth type of micro-bumps, micro-pillars or micro-pads 34 of the logic computing IC chip 269 and NVM IC chip 250 for the fourth type of FPMCP 307 as illustrated in FIG. 12 may be formed for one of the non-programmable interconnects 364 of the inter-chip interconnects 371 between the FPGA IC chip 200 and NVM IC chip 250 as illustrated in FIG. 5F; any bonded two of the first, second, third or fourth type of micro-bumps, micro-pillars or micro-pads 34 of the logic computing IC chip 269 and NVM IC chip 250, one or more of the interconnection metal layers 6 and/or 27 of the first and/or second interconnection scheme for a chip (FISC and/or SISC) 20 and/or 29 of the logic computing IC chip 269 and any bonded two of the first, second, third or fourth type of micro-bumps, micro-pillars or micro-pads 34 of the logic computing IC chip 269 and auxiliary IC chip 411 for the fourth type of FPMCP 307 as illustrated in FIG. 12 may be formed for one of the non-programmable interconnects 364 of the inter-chip interconnects 371 between the NVM IC chip 250 and auxiliary IC chip 411 as illustrated in FIG. 5F; any bonded two of the first, second, third or fourth type of micro-bumps, micro-pillars or micro-pads 34 of the FPGA IC chip 200 and auxiliary IC chip 411, one or more of the interconnection metal layers 6 and/or 27 of the first and/or second interconnection scheme for a chip (FISC and/or SISC) 20 and/or 29 of the auxiliary IC chip 411 and any bonded two of the first, second, third or fourth type of micro-bumps, micro-pillars or micro-pads 34 of the logic computing IC chip 269 and auxiliary IC chip 411 for the fourth type of FPMCP 307 as illustrated in FIG. 12 may be formed for one of the programmable interconnects 361 of the inter-chip interconnects 371 between the FPGA IC chip 200 and any of the semiconductor IC chips 100g as illustrated in FIG. 5F; any of the through silicon vias 157 (TSVs) of the auxiliary IC chip 411, each of the interconnection metal layers 27 of the interconnection scheme 79 and any of the metal bumps, pillars or pads 570 for the fourth type of FPMCP 307 as illustrated in FIG. 12 may be formed for the large input/output (I/O) circuits 341 of the large-input/output (I/O) block of the auxiliary IC chip 411 receiving and transmitting the first and second (encrypted) CPM data from and to the external circuits 340 as illustrated in FIG. 5F outside of the fourth type of FPMCP 307. For the fourth type of FPMCP 307 for each aspect of the ninth through eleventh aspects as illustrated in FIG. 5G, its FPGA IC chip 200 may have the same circuits as one illustrated in FIG. 5G, its NVM IC chip 250 may have the same circuits as one illustrated in FIG. 5G, and its logic computing IC chip 269 may be any of the semiconductor IC chips 100g as illustrated in FIG. 5G. Any bonded two of the first, second, third or fourth type of micro-bumps, micro-pillars or micro-pads 34 of the FPGA IC chip 200 and first one of the vertical-through-via (VTV) connectors 467, any of the through silicon vias (TSVs) 157 of the first one of the vertical-through-via (VTV) connectors 467, one or more of the interconnection metal layers 27 of the interconnection scheme 79, any of the through silicon vias (TSVs) 157 of the second one of the vertical-through-via (VTV) connectors 467, any bonded two of the first, second, third or fourth type of micro-bumps, micro-pillars or micro-pads 34 of the logic computing IC chip 269 and second one of the vertical-through-via (VTV) connectors 467, one or more of the interconnection metal layers 6 and/or 27 of the first and/or second interconnection scheme for a chip (FISC and/or SISC) 20 and/or 29 of the logic computing IC chip 269 and any bonded two of the first, second, third or fourth type of micro-bumps, micro-pillars or micro-pads 34 of the logic computing IC chip 269 and NVM IC chip 250 for the fourth type of FPMCP 307 as illustrated in FIG. 12 may be formed for one of the non-programmable interconnects 364 of the inter-chip interconnects 371 between the FPGA IC chip 200 and NVM IC chip 250 as illustrated in FIG. 5G; any bonded two of the first, second, third or fourth type of micro-bumps, micro-pillars or micro-pads 34 of the FPGA IC chip 200 and auxiliary IC chip 411, one or more of the interconnection metal layers 6 and/or 27 of the first and/or second interconnection scheme for a chip (FISC and/or SISC) 20 and/or 29 of the auxiliary IC chip 411 and any bonded two of the first, second, third or fourth type of micro-bumps, micro-pillars or micro-pads 34 of the logic computing IC chip 269 and auxiliary IC chip 411 for the fourth type of FPMCP 307 as illustrated in FIG. 12 may be formed for one of the programmable interconnects 361 of the inter-chip interconnects 371 between the FPGA IC chip 200 and any of the semiconductor IC chips 100g as illustrated in FIG. 5G; any bonded two of the first, second, third or fourth type of micro-bumps, micro-pillars or micro-pads 34 of the logic computing IC chip 269 and NVM IC chip 250, one or more of the interconnection metal layers 6 and/or 27 of the first and/or second interconnection scheme for a chip (FISC and/or SISC) 20 and/or 29 of the logic computing IC chip 269 and any bonded two of the first, second, third or fourth type of micro-bumps, micro-pillars or micro-pads 34 of the logic computing IC chip 269 and second one of the vertical-through-via (VTV) connectors 467, any of the through silicon vias (TSVs) 157 of the second one of the vertical-through-via (VTV) connectors 467, each of the interconnection metal layers 27 of the interconnection scheme 79 and any of the metal bumps, pillars or pads 570 for the fourth type of FPMCP 307 as illustrated in FIG. 12 may be formed for the large input/output (I/O) circuits 342 of the NVM IC chip 250 receiving and transmitting the first and second (encrypted) CPM data from and to the external circuits 340 as illustrated in FIG. 5G outside of the fourth type of FPMCP 307.

### Fifth Type of FPMCP

FIG. 13A is a schematically cross-sectional view showing a fifth type of FPMCP in accordance with an embodiment of the present application. Referring to FIG. 13A, a fifth type of FPMCP 308 may include (1) a FPGA IC chip 200, having the specification as illustrated for one in FIG. 5A-1, at its bottom, (2) a NVM IC chip 250, having the specification as illustrated for one in FIG. 5A-1, on a top of its FPGA IC chip 200, (3) a logic computing IC chip 269, such as the graphic-processing-unit (GPU) IC chip 269a, central-processing-unit (CPU) IC chip 269b or application-specific integrated-circuit (ASIC) chip or system-on-chip (SoC) chip 269c as illustrated in FIG. 5A-1 or such as data processing unit (DPU) IC chip, tensor flow processing unit (TPU) IC chip or digital-signal-processing (DSP) chip, on the top of its FPGA IC chip 200 and (4) an auxiliary IC chip 411, having the specification as illustrated for one in FIG. 5A-1, on the top of its FPGA IC chip 200, wherein its logic computing IC chip 269 may be horizontally between its NVM IC chip 250 and auxiliary IC chip 411. Its FPGA IC chip 200 may have the same specification as the sixth type of semiconductor IC chip 100 illustrated in FIG. 3F, and each of its logic computing IC chip 269, NVM IC chip 250 and auxiliary IC chip 411 may have the same specification as the fifth type of semiconductor IC chip 100 illustrated in FIG. 3E to be turned upside down. Its FPGA IC chip 200 may be the dedicated field programmable integrated-circuit (DFPIC) chip as illustrated in FIG. 4D or embedded field programmable integrated-circuit (eFPIC) chip as illustrated in FIG. 4E.

Referring to FIG. 13A, for the fifth type of FPMCP 308, each of its logic computing IC chip 269, NVM IC chip 250 and auxiliary IC chip 411 may be provided, for hybrid bonding, with (1) the insulating bonding layer 52, i.e., silicon oxide, having the bottom surface attached to and in contact with the top surface of the insulating bonding layer 52, i.e., silicon oxide, of its FPGA IC chip 200 and (2) the metal pads 6a, i.e., the copper layer 24 thereof, each having the bottom surface bonded to and in contact with the top surface of one of the metal pads 6a, i.e., the copper layer 24 thereof, of its FPGA IC chip 200. The top surface of the semiconductor substrate 2 of its FPGA IC chip 200, at which the semiconductor devices 4, such as transistors, of its FPGA IC chip 200 are formed as illustrated in FIG. 3F, faces the bottom surface of the semiconductor substrate 2 of each of its logic computing IC chip 269, NVM IC chip 250 and auxiliary IC chip 411, at which the semiconductor devices 4, such as transistors, of said each of its logic computing IC chip 269, NVM IC chip 250 and auxiliary IC chip 411 are formed as illustrated in FIG. 3E. Each of the metal pads 6a of each of its FPGA IC chip 200, logic computing IC chip 269, NVM IC chip 250 and auxiliary IC chip 411 may have a width, diameter or transverse dimension smaller than 5, 3, 1 or 0.5 micrometers, or between 0.1 and 5 micrometers, 0.1 and 3 micrometers, 0.1 and 1 micrometers, or 0.1 and 0.5 micrometers. The pitch between neighboring two of the metal pads 6a of each of its FPGA IC chip 200, logic computing IC chip 269, NVM IC chip 250 and auxiliary IC chip 411 may be smaller than 10, 5.2 or 1 micrometers, or between 0.2 and 10 micrometers, 0.2 and 5 micrometers, 0.2 and 2 micrometers, or 0.2 and 1 micrometers.

Referring to FIG. 13A, the fifth type of FPMCP 308 may include a polymer layer 92 or insulating dielectric layer, i.e., sealing layer, such as silicon-oxide-containing molding compound, epoxy-based material or polyimide, on its FPGA IC chip 200 and horizontally around each of its logic computing IC chip 269, NVM IC chip 250 and auxiliary IC chip 411, wherein its polymer layer 92 may have a top surface coplanar with a top surface of each of its logic computing IC chip 269, NVM IC chip 250 and auxiliary IC chip 411. Its polymer layer 92 may have a vertical sidewall coplanar with a vertical sidewall of its FPGA IC chip 200.

Referring to FIG. 13A, for the fifth type of FPMCP 308, the semiconductor substrate 2 of its FPGA IC chip 200 may have a portion, at a backside of the semiconductor substrate 2 of its FPGA IC chip 200, removed by a chemical-mechanical-polishing (CMP) or mechanical grinding process, and the insulating lining layer 153 at a backside of each of the through silicon vias 157 (TSVs) of its FPGA IC chip 200 and the adhesion metal layer 154 and electroplating seed layer 155 of each of the through silicon vias 157 (TSVs) of its FPGA IC chip 200 at the backside of each of the through silicon vias 157 (TSVs) of its FPGA IC chip 20 may be removed by the chemical-mechanical-polishing (CMP) or mechanical grinding process to expose to a bottom surface of the electroplated copper layer 156 of each of the through silicon vias 157 (TSVs) of its FPGA IC chip 200. Next, the semiconductor substrate 2 of its FPGA IC chip 200 may be etched to form a recess from the bottom surface of the electroplated copper layer 156 of each of the through silicon vias 157 (TSVs) of its FPGA IC chip 200, and then an insulating dielectric layer 185, such as silicon-oxide layer or silicon-nitride layer, may be formed in the recess and on the backside of the semiconductor substrate 2 of its FPGA IC chip 200, wherein the insulating dielectric layer 185 of its FPGA IC chip 200 may have a bottom surface coplanar with the bottom surface of the electroplated copper layer 156 of each of the through silicon vias 157 of its FPGA IC chip 200. The fifth type of FPMCP 308 may further include multiple metal bumps, pillars or pads 570 in an array at its bottom to act as its external pins for coupling to external circuits outside of the fifth type of FPMCP 308, wherein in a first aspect each of its metal bumps, pillars or pads 570 may be of a type selected from various types, i.e., first and second types, which may have the same specification as that of the first and second types of metal bumps, pillars or pads 570 respectively as illustrated in FIG. 6A, and may have the adhesion metal layer 26a on the bottom surface of one of the through silicon vias (TSVs) 157, i.e., the copper layer 156 thereof, of its FPGA IC chip 200 and the bottom surface of the insulating dielectric layer 185 of its FPGA IC chip 200. Alternatively, in a second aspect, each of its first or second type of metal bumps, pillars or pads 570 may have the adhesion metal layer 26a thereof formed on the bottom surface of the electroplated copper layer 156 of each of the set of through silicon vias 157 (TSVs) of its FPGA IC chip 200 and the bottom surface of the insulating dielectric layer 185 of its FPGA IC chip 200 to couple the set of through silicon vias 157 (TSVs) of its FPGA IC chip 200, wherein the reference layer 6f of the first interconnection scheme for a chip (FISC) 20 of its FPGA IC chip 200 for the second kind as illustrated in FIGS. 3G and 3H may couple the set of through silicon vias 157 (TSVs) of its FPGA IC chip 200, the reference layer 6f of the first interconnection scheme for a chip (FISC) 20 of its FPGA IC chip 200 for the third kind as illustrated in FIG. 3I may couple the set of through silicon vias 157 (TSVs) of its FPGA IC chip 200, and the second portion of the bottommost one of the interconnection metal layers 6 of the first interconnection scheme for a chip (FISC) 20 of its FPGA IC chip 200 for the fourth kind as illustrated in FIG. 3J may couple the set of through silicon vias 157 (TSVs) of its FPGA IC chip 200, wherein a pitch or space between each neighboring two of the set of through silicon vias 157 (TSVs) of its FPGA IC chip 200, i.e., the electroplated copper layers 156 thereof, may be between 5 and 50 micrometers.

Alternatively, FIG. 13E is a schematically cross-sectional view showing a second type of metal bump, pillar or pad provided under two through silicon vias (TSVs) in accordance with an embodiment of the present application. Referring to FIG. 13E, with regard to the fifth type of FPMCP 308, for any kind of the second through fourth kinds of connection structures for the through silicon vias 157 (TSVs) and the first interconnection scheme for a chip (FISC) for a third aspect for its FPGA IC chip 200, the third aspect for its FPGA IC chip 200 may have a similar structure to the second aspect for its FPGA IC chip 200. In FIG. 13E, its FPGA IC chip 200 takes the third kind as an example. The difference therebetween is that for the third aspect its FPGA IC chip 200 may further include an insulating dielectric layer 587, such as polymer, silicon oxide, silicon oxynitride or silicon nitride, having a thickness between 0.5 and 10 micrometers on the bottom surface of the insulating dielectric layer 185 of its FPGA IC chip 200 as illustrated for the second aspect for its FPGA IC chip 200, wherein an opening in the insulating dielectric layer 587 of its FPGA IC chip 200 may be vertically under the set of through silicon vias 157 (TSVs) of its FPGA IC chip 200 and said each of its first or second type of metal bumps, pillars or pads 570 may be formed in and under the opening in the insulating dielectric layer 587 of its FPGA IC chip 200 and under and on a bottom surface of the insulating dielectric layer 587 of its FPGA IC chip 200 and have the adhesion metal layer 26a thereof formed on the bottom surface of the electroplated copper layer 156 of each of the set of through silicon vias 157 (TSVs) of its FPGA IC chip 200, the bottom surface of the insulating dielectric layer 185 of its FPGA IC chip 200 and the bottom surface of the insulating dielectric layer 587 of its FPGA IC chip 200 to couple the set of through silicon vias 157 (TSVs) of its FPGA IC chip 200.

Referring to FIG. 13A, for the fifth type of FPMCP 308, each of its logic computing IC chip 269, NVM IC chip 250 and auxiliary IC chip 411 may couple to one of its metal bumps, pillars or pads 570 through one of the through silicon vias 157 of its FPGA IC chip 200 for transmitting a signal or clock or delivering a power or ground voltage therebetween.

Alternatively, for the fifth type of FPMCP 308, each of its logic computing IC chip 269, NVM IC chip 250 and auxiliary IC chip 411 may be bonded to its FPGA IC chip 200 by wafer bumping as seen in FIG. 13B, instead of the hybrid bonding as illustrated in FIG. 13A. FIG. 13B is a schematically cross-sectional view showing a fifth type of FPMCP in accordance with another embodiment of the present application. For an element indicated by the same reference number shown in FIGS. 13A and 13B, the specification of the element as seen in FIG. 13B may be referred to that of the element as illustrated in FIG. 13A. Referring to FIG. 13B, its FPGA IC chip 200 may have the same specification as the second type of semiconductor IC chip 100 illustrated in FIGS. 3B and 3G-3J, and each of its logic computing IC chip 269, NVM IC chip 250 and auxiliary IC chip 411 may have the same specification as the first type of semiconductor IC chip 100 illustrated in FIG. 3A to be turned upside down. Each of its logic computing IC chip 269, NVM IC chip 250 and auxiliary IC chip 411 may have the first, second, third or fourth type of micro-bumps, micro-pillars or micro-pads 34 each bonded to one of the first, second, third or fourth type of micro-bumps, micro-pillars or micro-pads 34 of its FPGA IC chip 200.

FIGS. 13C and 13D are schematically cross-sectional views showing a process of bonding a thermal compression bump to a thermal compression pad in accordance with an embodiment of the present application. For the fifth type of FPMCP 308, referring to FIGS. 13B and 13C, in a first case each of its logic computing IC chip 269, NVM IC chip 250 and auxiliary IC chip 411 may have the third type of micro-bumps, micro-pillars or micro-pads 34 to be bonded to the fourth type of micro-bumps, micro-pillars or micro-pads 34 of its FPGA IC chip 200. For more elaboration, each of the third type of micro-bumps, micro-pillars or micro-pads 34 of each of its logic computing IC chip 269, NVM IC chip 250 and auxiliary IC chip 411 may have the copper layer 37 having the thickness t3 greater than the thickness t2 of the copper layer 48 of each of the fourth type of micro-bumps, micro-pillars or micro-pads 34 of its FPGA IC chip 200 and having the largest transverse dimension w3 equal to between 0.7 and 0.1 times of the largest transverse dimension w2 of the copper layer 48 of each of the fourth type of micro-bumps, micro-pillars or micro-pads 34 of its FPGA IC chip 200. Alternatively, each of the third type of micro-bumps, micro-pillars or micro-pads 34 of each of its logic computing IC chip 269, NVM IC chip 250 and auxiliary IC chip 411 may be provided with the copper layer 37 having a cross-sectional area equal to between 0.5 and 0.01 times of the cross-sectional area of the copper layer 48 of each of the fourth type of micro-bumps, micro-pillars or micro-pads 34 of its FPGA IC chip 200.

In the first case, referring to FIGS. 13B and 13C, for each of the logic computing IC chip 269, NVM IC chip 250 and auxiliary IC chip 411 of the fifth type of FPMCP 308, each of its third type of micro-bumps, micro-pillars or micro-pads 34 may be formed on a front surface of one of its metal pads 6b provided by the frontmost one of the interconnection metal layers 27 of its second interconnection scheme for a chip (SISC) 29 or by, if the second interconnection scheme for a chip (SISC) 29 is not provided, the frontmost one of the interconnection metal layers 6 of its first interconnection scheme for a chip (FISC) 20, wherein each of its metal pads 6b may have a thickness t1 between 1 and 10 micrometers or between 2 and 10 micrometers and a largest transverse dimension w1, such as diameter in a circular shape, between 1 μm and 25 μm and each of its third type of micro-bumps, micro-pillars or micro-pads 34 may be provided with the copper layer 37 having the thickness t3 greater than the thickness t1 of its metal pads 6b and having the largest transverse dimension w3 equal to between 0.7 and 0.1 times of the largest transverse dimension w1 of its metal pads 6b; alternatively, each of its third type of micro-bumps, micro-pillars or micro-pads 34 may be provided with the copper layer 37 having a cross-sectional area equal to between 0.5 and 0.01 times of the cross-sectional area of its metal pads 6b.

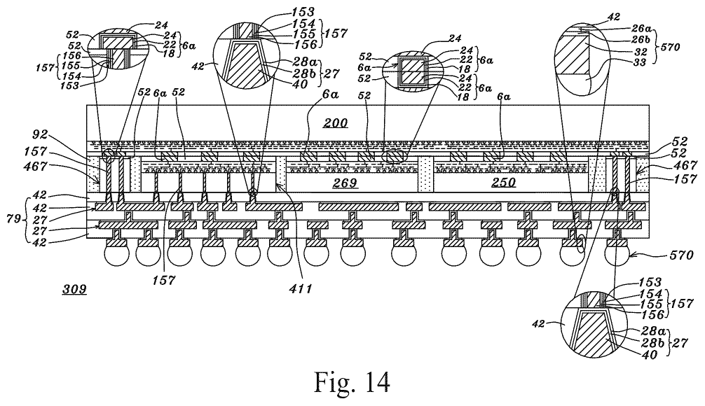

For of the fifth type of FPMCP 308 in the first case, referring to FIGS. 13B-13D, in the thermal-compression bonding process each of the third type of micro-bumps, micro-pillars or micro-pads 34 of each of its logic computing IC chip 269, NVM IC chip 250 and auxiliary IC chip 411 may have the solder cap 38 to be thermally compressed, at a temperature between 240 and 300 degrees Celsius, at a pressure between 0.3 and 3 MPa and for a time period between 3 and 15 seconds, onto the metal cap 49 of one of the fourth type of micro-bumps, micro-pillars or micro-pads 34 of its FPGA IC chip 200 into its bonded metal bumps or contacts 563 therebetween as seen in FIGS. 14B and 14D. A bonded solder between the copper layers 37 and 48 of each of its bonded metal bumps or contacts 563 may be mostly kept on a top surface of the copper layer 48 of said each of its bonded metal bumps or contacts 563 and extends out of the edge of the copper layer 48 of said each of its bonded metal bumps or contacts 563 less than 0.5 micrometers. Thus, a short between neighboring two of its bonded metal bumps or contacts 563 even in a fine-pitched fashion may be avoided.

Alternatively, for the fifth type of FPMCP 308, referring to FIG. 13B, in a second case each of its logic computing IC chip 269, NVM IC chip 250 and auxiliary IC chip 411 may have the second type of micro-bumps, micro-pillars or micro-pads 34 to be bonded to the first type of micro-bumps, micro-pillars or micro-pads 34 of its FPGA IC chip 200. For more elaboration, each of the second type of micro-bumps, micro-pillars or micro-pads 34 of each of its logic computing IC chip 269, NVM IC chip 250 and auxiliary IC chip 411 may have the solder caps 33 to be bonded onto the copper layer 32 of one of the first type of micro-bumps, micro-pillars or micro-pads 34 of its FPGA IC chip 200 into its bonded metal bump or contact 563 therebetween, wherein an upper one of the copper layers 32 of its bonded metal bump or contact 563, provided by said each of the second type of micro-bumps, micro-pillars or micro-pads 34, may have a thickness greater than that of a lower one of the copper layers 32 of its bonded metal bump or contact 563, provided by said one of the first type of micro-bumps, micro-pillars or micro-pads 34.

Alternatively, for the fifth type of FPMCP 308, referring to FIG. 13B, in a third case each of its logic computing IC chip 269, NVM IC chip 250 and auxiliary IC chip 411 may have the first type of micro-bumps, micro-pillars or micro-pads 34 to be bonded to the second type of micro-bumps, micro-pillars or micro-pads 34 of its FPGA IC chip 200. For more elaboration, each of the first type of micro-bumps, micro-pillars or micro-pads 34 of each of its logic computing IC chip 269, NVM IC chip 250 and auxiliary IC chip 411 may have the copper layer 32 to be bonded onto the solder cap 33 of one of the second type of micro-bumps, micro-pillars or micro-pads 34 of its FPGA IC chip 200 into its bonded metal bump or contact 563 therebetween, wherein an upper one of the copper layers 32 of its bonded metal bump or contact 563, provided by said each of the first type of micro-bumps, micro-pillars or micro-pads 34, may have a thickness greater than that of a lower one of the copper layers 32 of its bonded metal bump or contact 563, provided by said one of the second type of micro-bumps, micro-pillars or micro-pads 34.

Alternatively, for the fifth type of FPMCP 308, referring to FIG. 13B, in a fourth case each of its logic computing IC chip 269, NVM IC chip 250 and auxiliary IC chip 411 may have the second type of micro-bumps, micro-pillars or micro-pads 34 to be bonded to the second type of micro-bumps, micro-pillars or micro-pads 34 of its FPGA IC chip 200. For more elaboration, each of the second type of micro-bumps, micro-pillars or micro-pads 34 of each of its logic computing IC chip 269, NVM IC chip 250 and auxiliary IC chip 411 may have the solder caps 33 to be bonded onto the solder cap 33 of one of the second type of micro-bumps, micro-pillars or micro-pads 34 of its FPGA IC chip 200 into its bonded metal bump or contact 563 therebetween, wherein an upper one of the copper layers 32 of its bonded metal bump or contact 563, provided by said each of the second type of micro-bumps, micro-pillars or micro-pads 34, may have a thickness greater than that of a lower one of the copper layers 32 of its bonded metal bump or contact 563, provided by said one of the second type of micro-bumps, micro-pillars or micro-pads 34.

Referring to FIG. 13B, the fifth type of FPMCP 308 may further include an underfill 564, e.g., polymer layer, between its logic computing IC chip 269 and FPGA IC chip 200, between its NVM IC chip 250 and FPGA IC chip 200 and between its auxiliary IC chip 411 and FPGA IC chip 200, covering a sidewall of each of its bonded metal bumps or contacts 563.

Referring to FIG. 13B, for the fifth type of FPMCP 308, each of its logic computing IC chip 269, NVM IC chip 250 and auxiliary IC chip 411 may couple to one of its first or second type of metal bumps, pillars or pads 570 through, in sequence, one of its bonded metal bumps or contacts 563, which is between said each of its logic computing IC chip 269, NVM IC chip 250 and auxiliary IC chip 411 and its FPGA IC chip 200, and one of the through silicon vias 157 of its FPGA IC chip 200 for transmitting a signal or clock or delivering a power or ground voltage therebetween. Its first or second type of metal bumps, pillars or pads 570 may be formed at a bottom of its FPGA IC chip 200 following the same process to form the first or second type of metal bumps, pillars or pads 570 at a bottom of the FPGA IC chip 200 of the fifth type of FPMCP 308 as illustrated in the first through third aspects in FIGS. 13A and 13E. Thereby, the fifth type of FPMCP 308 illustrated in FIG. 13B may be provided in any of the first through third aspects as illustrated in FIG. 13A and/or 13E.

Referring to FIGS. 13A and 13B, each of the fifth type of FPMCPs 308 may have the inter-chip interconnection between the first and second semiconductor IC chips 100a and 100b via the FPGA IC chip 200 as illustrated in FIG. 5B. For each of the fifth type of FPMCPs 308, its FPGA IC chip 200 may have the same circuits as one illustrated in FIG. 5B, its logic computing IC chip 269 may be the first semiconductor IC chip 100a as illustrated in FIG. 5B, and one of its NVM IC chip 250 and auxiliary IC chip 411 may be the second semiconductor IC chip 100b as illustrated in FIG. 5B. Alternatively, its auxiliary IC chip 411 may be the first semiconductor IC chip 100a as illustrated in FIG. 5B, and its NVM IC chip 250 may be the second semiconductor IC chip 100b as illustrated in FIG. 5B. Each bonded two of the metal pads 6a of the FPGA IC chip 200 and first semiconductor IC chip 100a for the fifth type of FPMCP 308 as illustrated in FIG. 13A or each of the bonded metal bumps or contacts 563 between the FPGA IC chip 200 and first semiconductor IC chip 100a for the fifth type of FPMCP 308 as illustrated in FIG. 13B may be formed for one of the programmable interconnects 361 of the inter-chip interconnects 371 between the FPGA IC chip 200 and first semiconductor IC chip 100a as illustrated in FIG. 5B, and each bonded two of the metal pads 6a of the FPGA IC chip 200 and second semiconductor IC chip 100b for the fifth type of FPMCP 308 as illustrated in FIG. 13A or each of the bonded metal bumps or contacts 563 between the FPGA IC chip 200 and second semiconductor IC chip 100b for the fifth type of FPMCP 308 as illustrated in FIG. 13B may be formed for one of the programmable interconnects 361 of the inter-chip interconnects 371 between the FPGA IC chip 200 and second semiconductor IC chip 100b as illustrated in FIG. 5B.

Referring to FIGS. 13A and 13B, each of the fifth type of FPMCPs 308 may perform the operation between the FPGA IC chip 200 and each of the third and fourth semiconductor IC chips 100c and 100d as illustrated in FIG. 5C. For each of the fifth type of FPMCPs 308, its FPGA IC chip 200 may have the same circuits as one illustrated in FIG. 5C, its logic computing IC chip 269 may be the third semiconductor IC chip 100c as illustrated in FIG. 5C, and one of its NVM IC chip 250 and auxiliary IC chip 411 may be the fourth semiconductor IC chip 100d as illustrated in FIG. 5C. Alternatively, its auxiliary IC chip 411 may be the third semiconductor IC chip 100c as illustrated in FIG. 5C, and its NVM IC chip 250 may be the fourth semiconductor IC chip 100d as illustrated in FIG. 5C. Each bonded two of the metal pads 6a of the FPGA IC chip 200 and third semiconductor IC chip 100c for the fifth type of FPMCP 308 as illustrated in FIG. 13A or each of the bonded metal bumps or contacts 563 between the FPGA IC chip 200 and third semiconductor IC chip 100c for the fifth type of FPMCP 308 as illustrated in FIG. 13B may be formed for one of the programmable interconnects 361 of the inter-chip interconnects 371 between the FPGA IC chip 200 and third semiconductor IC chip 100c as illustrated in FIG. 5C, and each bonded two of the metal pads 6a of the FPGA IC chip 200 and fourth semiconductor IC chip 100d for the fifth type of FPMCP 308 as illustrated in FIG. 13A or each of the bonded metal bumps or contacts 563 between the FPGA IC chip 200 and fourth semiconductor IC chip 100d for the fifth type of FPMCP 308 as illustrated in FIG. 13B may be formed for one of the programmable interconnects 361 of the inter-chip interconnects 371 between the FPGA IC chip 200 and fourth semiconductor IC chip 100d as illustrated in FIG. 5C.

Referring to FIGS. 13A and 13B, each of the fifth type of FPMCPs 308 may have the connection to external circuits as illustrated in FIG. 5D. For each of the fifth type of FPMCPs 308, its FPGA IC chip 200 may have the same circuits as one illustrated in FIG. 5D, its auxiliary IC chip 411 may have the same circuits as one illustrated in FIG. 5D, its logic computing IC chip 269 may be the fifth semiconductor IC chip 100e as illustrated in FIG. 5D, and its NVM IC chip 250 may be the sixth semiconductor IC chip 100f as illustrated in FIG. 5D. Each bonded two of the metal pads 6a of the FPGA IC chip 200 and fifth semiconductor IC chip 100e for the fifth type of FPMCP 308 as illustrated in FIG. 13A or each of the bonded metal bumps or contacts 563 between the FPGA IC chip 200 and fifth semiconductor IC chip 100e for the fifth type of FPMCP 308 as illustrated in FIG. 13B may be formed for one of the programmable interconnects 361 of the inter-chip interconnects 371 between the FPGA IC chip 200 and fifth semiconductor IC chip 100e as illustrated in FIG. 5D, each bonded two of the metal pads 6a of the FPGA IC chip 200 and sixth semiconductor IC chip 100f for the fifth type of FPMCP 308 as illustrated in FIG. 13A or each of the bonded metal bumps or contacts 563 between the FPGA IC chip 200 and sixth semiconductor IC chip 100f for the fifth type of FPMCP 308 as illustrated in FIG. 13B may be formed for one of the programmable interconnects 361 of the inter-chip interconnects 371 between the FPGA IC chip 200 and sixth semiconductor IC chip 100f as illustrated in FIG. 5D, and each bonded two of the metal pads 6a of the FPGA IC chip 200 and auxiliary IC chip 411 for the fifth type of FPMCP 308 as illustrated in FIG. 13A or each of the bonded metal bumps or contacts 563 between the FPGA IC chip 200 and auxiliary IC chip 411 for the fifth type of FPMCP 308 as illustrated in FIG. 13B may be formed for one of the programmable interconnects 361 of the inter-chip interconnects 371 between the FPGA IC chip 200 and auxiliary IC chip 411 as illustrated in FIG. 5D. For each of the fifth type of FPMCPs 308 as illustrated in FIGS. 13A and 13B, each of the large input/output (I/O) circuits 341 of the large-input/output (I/O) block of its auxiliary IC chip 411 may couple to one of its metal bumps, pillars or pads 570, which are in an array at its bottom to act as its external pins for coupling to the external circuits 340 as seen in FIG. 5D outside of said each of the fifth type of FPMCPs 308, through, in sequence, (1) any bonded two of the metal pads 6a of its auxiliary IC chip 411 and FPGA IC chip 200 and any of the through silicon vias 157 of its FPGA IC chip 200, as illustrated in FIG. 13A, or (2) any of its bonded metal bumps or contacts 563 between its auxiliary IC chip 411 and FPGA IC chip 200 and any of the through silicon vias 157 of its FPGA IC chip 200, as illustrated in FIG. 13B.

For the fifth type of FPMCP 308 as illustrated in either FIG. 13A or 13B, its auxiliary IC chip 411 may include a first small input/output (I/O) circuit coupling to a second small input/output (I/O) circuit of its FPGA IC chip 200 through its first signal path composed of (1) bonded two of the metal pads 6a of its auxiliary IC chip 411 and FPGA IC chip 200 as seen in FIG. 13A or (2) one of its bonded metal bumps or contacts 563 between its auxiliary IC chip 411 and FPGA IC chip 200 as seen in FIG. 13B, wherein each of the first and second small input/output (I/O) circuits may have an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts. Its auxiliary IC chip 411 may include a large input/output (I/O) circuit coupling to any of its metal bumps, pillars or pads 570 through its second signal path composed of (1) bonded any two of the metal pads 6a of its auxiliary IC chip 411 and FPGA IC chip 200 and any of the through silicon vias (TSVs) 157 of its FPGA IC chip 200 as seen in FIG. 13A, or (2) any of its bonded metal bumps or contacts 563 between its auxiliary IC chip 411 and FPGA IC chip 200 and any of the through silicon vias (TSVs) 157 of its FPGA IC chip 200 as seen in FIG. 13B, wherein the large input/output (I/O) circuit may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or equal to or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Thereby, the first small input/output (I/O) circuit may receive first signals from the second small input/output (I/O) circuit via its first signal path to be converted by its auxiliary IC chip 411 as second signals and then the large input/output (I/O) circuit may transmit the second signals to said any of its metal bumps, pillars or pads 570 via its second signal path. Further, the large input/output (I/O) circuit may receive third signals from said any of its metal bumps, pillars or pads 570 via its second signal path to be converted by its auxiliary IC chip 411 as fourth signals and then the first small input/output (I/O) circuit may transmit the fourth signals to the second small input/output (I/O) circuit via its first signal path.

For the fifth type of FPMCP 308 as illustrated in either FIG. 13A or 13B, its FPGA IC chip 200 may be programmed, configured or reconfigured following the same way as any aspect of the first through eleventh aspects illustrated in FIGS. 5A-1, 5A-2 and 5E-5G, including (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with first data stored in its NVM IC chip 250 to be configured in accordance with the first data, (2) the first or second type of field programmable switch cell 379 as illustrated in FIG. 2A or 2B having the memory cells 362 as illustrated in FIG. 2A or the four sets of memory cells 362 as illustrated in FIG. 2B for storing data associated with second data stored in its NVM IC chip 250 to be configured in accordance with the second data, and (3) the programmable switch matrix 710 as illustrated in FIG. 2C having the memory cells 398 for storing data, i.e., programming codes, password or encryption/decryption codes, associated with third data stored in its NVM IC chip 250 to be configured in accordance with the third data. Alternatively, its FPGA IC chip 200 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MILU) IC chip, or digital-signal-processing (DSP) IC chip, each of which may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with the first data to be configured in accordance with the first data, (2) the first or second type of field programmable switch cell 379 as illustrated in FIG. 2A or 2B having the memory cells 362 as illustrated in FIG. 2A or the four sets of memory cells 362 as illustrated in FIG. 2B for storing data associated with the second data to be configured in accordance with the second data, and (3) the programmable switch matrix 710 as illustrated in FIG. 2C having the memory cells 398 for storing data, i.e., programming codes, password or encryption/decryption codes, associated with the third data to be configured in accordance with the third data. For either of the fifth type of FPMCPs 308 for each aspect of the first through fourth aspects as illustrated in FIG. 5E, its FPGA IC chip 200 may have the same circuits as one illustrated in FIG. 5E, its auxiliary IC chip 411 may have the same circuits as one illustrated in FIG. 5E, its NVM IC chip 250 may have the same circuits as one illustrated in FIG. 5E, and its logic computing IC chip 269 may be any of the semiconductor IC chips 100g as illustrated in FIG. 5E. Any bonded two of the metal pads 6a of the auxiliary IC chip 411 and FPGA IC chip 200 for the fifth type of FPMCP 308 as seen in FIG. 13A or any of the bonded metal bumps or contacts 563 between the auxiliary IC chip 411 and FPGA IC chip 200 for the fifth type of FPMCP 308 as seen in FIG. 13B may be formed for one of the non-programmable interconnects 364 of the inter-chip interconnects 371 between the FPGA IC chip 200 and auxiliary IC chip 411 as illustrated in FIG. 5E; (1) any bonded two of the metal pads 6a of the auxiliary IC chip 411 and FPGA IC chip 200, one or more of the interconnection metal layers 6 and/or 27 of the first and/or second interconnection scheme for a chip (FISC and/or SISC) 20 and/or 29 of the FPGA IC chip 200 and any bonded two of the metal pads 6a of the NVM IC chip 250 and FPGA IC chip 200 for the fifth type of FPMCP 308 as seen in FIG. 13A, or (2) any of the bonded metal bumps or contacts 563 between the auxiliary IC chip 411 and FPGA IC chip 200, one or more of the interconnection metal layers 6 and/or 27 of the first and/or second interconnection scheme for a chip (FISC and/or SISC) 20 and/or 29 of the FPGA IC chip 200 and any of the bonded metal bumps or contacts 563 between the NVM IC chip 250 and FPGA IC chip 200 for the fifth type of FPMCP 308 as seen in FIG. 13B, may be formed for one of the non-programmable interconnects 364 of the inter-chip interconnects 371 between the NVM IC chip 250 and auxiliary IC chip 411 as illustrated in FIG. 5E; any bonded two of the metal pads 6a of the logic computing IC chip 269 and FPGA IC chip 200 for the fifth type of FPMCP 308 as seen in FIG. 13A or any of the bonded metal bumps or contacts 563 between the logic computing IC chip 269 and FPGA IC chip 200 for the fifth type of FPMCP 308 as seen in FIG. 13B may be formed for one of the programmable interconnects 361 of the inter-chip interconnects 371 between the FPGA IC chip 200 and any of the semiconductor IC chips 100g as illustrated in FIG. 5E; (1) any bonded two of the metal pads 6a of the NVM IC chip 250 and FPGA IC chip 200, any of the through silicon vias (TSVs) 157 of the FPGA IC chip 200 and any of the metal bumps, pillars or pads 570 for the fifth type of FPMCP 308 as seen in FIG. 13A, or (2) any of the bonded metal bumps or contacts 563 between the NVM IC chip 250 and FPGA IC chip 200, any of the through silicon vias (TSVs) 157 of the FPGA IC chip 200 and any of the metal bumps, pillars or pads 570 for the fifth type of FPMCP 308 as seen in FIG. 13B, may be formed for the first group of the large input/output (I/O) circuits 342 of the NVM IC chip 250 receiving and transmitting the first and second (encrypted) CPM data from and to the external circuits 340 as illustrated in FIG. 5E outside of the fifth type of FPMCP 308; optionally for each aspect of the first through third aspects, (1) any bonded two of the metal pads 6a of the auxiliary IC chip 411 and FPGA IC chip 200, any of the through silicon vias (TSVs) 157 of the FPGA IC chip 200 and any of the metal bumps, pillars or pads 570 for the fifth type of FPMCP 308 as seen in FIG. 13A, or (2) any of the bonded metal bumps or contacts 563 between the auxiliary IC chip 411 and FPGA IC chip 200, any of the through silicon vias (TSVs) 157 of the FPGA IC chip 200 and any of the metal bumps, pillars or pads 570 for the fifth type of FPMCP 308 as seen in FIG. 13B, may be formed for the large input/output (I/O) circuits 341 of the large-input/output (I/O) block of the auxiliary IC chip 411 receiving and transmitting the first and second (encrypted) CPM data from and to the external circuits 340 as illustrated in FIG. 5E outside of the fifth type of FPMCP 308. For either of the fifth type of FPMCPs 308 for each aspect of the fifth through eighth aspects as illustrated in FIG. 5F, its FPGA IC chip 200 may have the same circuits as one illustrated in FIG. 5F, its auxiliary IC chip 411 may have the same circuits as one illustrated in FIG. 5F, its NVM IC chip 250 may have the same circuits as one illustrated in FIG. 5F, and its logic computing IC chip 269 may be any of the semiconductor IC chips 100g as illustrated in FIG. 5F. Any bonded two of the metal pads 6a of the NVM IC chip 250 and FPGA IC chip 200 for the fifth type of FPMCP 308 as seen in FIG. 13A or any of the bonded metal bumps or contacts 563 between the NVM IC chip 250 and FPGA IC chip 200 for the fifth type of FPMCP 308 as seen in FIG. 13B may be formed for one of the non-programmable interconnects 364 of the inter-chip interconnects 371 between the NVM IC chip 250 and FPGA IC chip 200 as illustrated in FIG. 5F; (1) any bonded two of the metal pads 6a of the auxiliary IC chip 411 and FPGA IC chip 200, one or more of the interconnection metal layers 6 and/or 27 of the first and/or second interconnection scheme for a chip (FISC and/or SISC) 20 and/or 29 of the FPGA IC chip 200 and any bonded two of the metal pads 6a of the NVM IC chip 250 and FPGA IC chip 200 for the fifth type of FPMCP 308 as seen in FIG. 13A, or (2) any of the bonded metal bumps or contacts 563 between the auxiliary IC chip 411 and FPGA IC chip 200, one or more of the interconnection metal layers 6 and/or 27 of the first and/or second interconnection scheme for a chip (FISC and/or SISC) 20 and/or 29 of the FPGA IC chip 200 and any of the bonded metal bumps or contacts 563 between the NVM IC chip 250 and FPGA IC chip 200 for the fifth type of FPMCP 308 as seen in FIG. 13B, may be formed for one of the non-programmable interconnects 364 of the inter-chip interconnects 371 between the NVM IC chip 250 and auxiliary IC chip 411 as illustrated in FIG. 5F; any bonded two of the metal pads 6a of the logic computing IC chip 269 and FPGA IC chip 200 for the fifth type of FPMCP 308 as seen in FIG. 13A or any of the bonded metal bumps or contacts 563 between the logic computing IC chip 269 and FPGA IC chip 200 for the fifth type of FPMCP 308 as seen in FIG. 13B may be formed for one of the programmable interconnects 361 of the inter-chip interconnects 371 between the FPGA IC chip 200 and any of the semiconductor IC chips 100g as illustrated in FIG. 5F; (1) any bonded two of the metal pads 6a of the NVM IC chip 250 and FPGA IC chip 200 and any of the through silicon vias (TSVs) 157 of the FPGA IC chip 200 for the fifth type of FPMCP 308 as seen in FIG. 13A, or (2) any of the bonded metal bumps or contacts 563 between the NVM IC chip 250 and FPGA IC chip 200, any of the through silicon vias (TSVs) 157 of the FPGA IC chip 200 and any of the metal bumps, pillars or pads 570 for the fifth type of FPMCP 308 as seen in FIG. 13B, may be formed for the large input/output (I/O) circuits 341 of the large-input/output (I/O) block of the auxiliary IC chip 411 receiving and transmitting the first and second (encrypted) CPM data from and to the external circuits 340 as illustrated in FIG. 5F outside of the fifth type of FPMCP 308. For either of the fifth type of FPMCPs 308 for each aspect of the ninth through eleventh aspects as illustrated in FIG. 5G, its FPGA IC chip 200 may have the same circuits as one illustrated in FIG. 5G, its NVM IC chip 250 may have the same circuits as one illustrated in FIG. 5G, and its logic computing IC chip 269 may be any of the semiconductor IC chips 100g as illustrated in FIG. 5G. Any bonded two of the metal pads 6a of the NVM IC chip 250 and FPGA IC chip 200 for the fifth type of FPMCP 308 as seen in FIG. 13A or any of the bonded metal bumps or contacts 563 between the NVM IC chip 250 and FPGA IC chip 200 for the fifth type of FPMCP 308 as seen in FIG. 13B may be formed for one of the non-programmable interconnects 364 of the inter-chip interconnects 371 between the FPGA IC chip 200 and NVM IC chip 250 as illustrated in FIG. 5G; any bonded two of the metal pads 6a of the logic computing IC chip 269 and FPGA IC chip 200 for the fifth type of FPMCP 308 as seen in FIG. 13A or any of the bonded metal bumps or contacts 563 between the logic computing IC chip 269 and FPGA IC chip 200 for the fifth type of FPMCP 308 as seen in FIG. 13B may be formed for one of the programmable interconnects 361 of the inter-chip interconnects 371 between the FPGA IC chip 200 and any of the semiconductor IC chips 100g as illustrated in FIG. 5G; (1) any bonded two of the metal pads 6a of the NVM IC chip 250 and FPGA IC chip 200 and any of the through silicon vias (TSVs) 157 of the FPGA IC chip 200 for the fifth type of FPMCP 308 as seen in FIG. 13A, or (2) any of the bonded metal bumps or contacts 563 between the NVM IC chip 250 and FPGA IC chip 200, any of the through silicon vias (TSVs) 157 of the FPGA IC chip 200 and any of the metal bumps, pillars or pads 570 for the fifth type of FPMCP 308 as seen in FIG. 13B, may be formed for the large input/output (I/O) circuits 342 of the NVM IC chip 250 receiving and transmitting the first and second (encrypted) CPM data from and to the external circuits 340 as illustrated in FIG. 5G outside of the fifth type of FPMCP 308.

### Sixth Type of FPMCP

FIG. 14 is a schematically cross-sectional view showing a sixth type of FPMCP in accordance with an embodiment of the present application. Referring to FIG. 14, a sixth type of FPMCP 309 may include (1) a FPGA IC chip 200, having the specification as illustrated for one in FIG. 5A-1, at its top, (2) a NVM IC chip 250, having the specification as illustrated for one in FIG. 5A-1, on a bottom of its FPGA IC chip 200, (3) a logic computing IC chip 269, such as the graphic-processing-unit (GPU) IC chip 269a, central-processing-unit (CPU) IC chip 269b or application-specific integrated-circuit (ASIC) chip or system-on-chip (SoC) chip 269c as illustrated in FIG. 5A-1 or such as data processing unit (DPU) IC chip, tensor flow processing unit (TPU) IC chip or digital-signal-processing (DSP) chip, on the bottom of its FPGA IC chip 200 and (4) an auxiliary IC chip 411, having the specification as illustrated for one in FIG. 5A-1, on the bottom of its FPGA IC chip 200, wherein its logic computing IC chip 269 may be horizontally between its NVM IC chip 250 and auxiliary IC chip 411. Its FPGA IC chip 200 may have the same specification as the sixth type of semiconductor IC chip 100 illustrated in FIG. 3E to be turned upside down, each of its logic computing IC chip 269 and NVM IC chip 250 may have the same specification as the sixth type of semiconductor IC chip 100 illustrated in FIG. 3E, its auxiliary IC chip 411 may have the same specification as the sixth type of semiconductor IC chip 100 illustrated in FIG. 3F and each of its vertical-through-via (VTV) connectors 467 may have the same specification as the second type of vertical-through-via (VTV) connector 467 illustrated in FIG. 4B. For the sixth type of FPMCP 309, its FPGA IC chip 200 may be the dedicated field programmable integrated-circuit (DFPIC) chip as illustrated in FIG. 4D or embedded field programmable integrated-circuit (eFPIC) chip as illustrated in FIG. 4E.

Referring to FIG. 14, for the sixth type of FPMCP 309, each of its logic computing IC chip 269, NVM IC chip 250 and auxiliary IC chip 411 may be provided, for hybrid bonding, with (1) the insulating bonding layer 52, i.e., silicon oxide, having the top surface attached to and in contact with the bottom surface of the insulating bonding layer 52, i.e., silicon oxide, of its FPGA IC chip 200 and (2) the metal pads 6a, i.e., the copper layer 24 thereof, each having the top surface bonded to and in contact with the bottom surface of one of the metal pads 6a, i.e., the copper layer 24 thereof, of its FPGA IC chip 200. The bottom surface of the semiconductor substrate 2 of its FPGA IC chip 200, at which the semiconductor devices 4, such as transistors, of its FPGA IC chip 200 are formed as illustrated in FIG. 3E, faces the top surface of the semiconductor substrate 2 of each of its logic computing IC chip 269 and NVM IC chip 250, at which the semiconductor devices 4, such as transistors, of said each of its logic computing IC chip 269 and NVM IC chip 250 are formed as illustrated in FIG. 3E. The bottom surface of the semiconductor substrate 2 of its FPGA IC chip 200, at which the semiconductor devices 4, such as transistors, of its FPGA IC chip 200 are formed as illustrated in FIG. 3E, faces the top surface of the semiconductor substrate 2 of its auxiliary IC chip 411, at which the semiconductor devices 4, such as transistors, of its auxiliary IC chip 411 are formed as illustrated in FIG. 3F. Each of its vertical-through-via (VTV) connectors 467 may be provided, for hybrid bonding, with (1) the insulating bonding layer 52, i.e., silicon oxide, having the top surface attached to and in contact with the bottom surface of the insulating bonding layer 52, i.e., silicon oxide, of its FPGA IC chip 200 and (2) the through silicon vias (TSVs) 157, i.e., the copper layer 24 thereof, each having the top surface bonded to and in contact with the bottom surface of one of the metal pads 6a, i.e., the copper layer 24 thereof, of its FPGA IC chip 200. Each of the metal pads 6a of each of its FPGA IC chip 200, logic computing IC chip 269, NVM IC chip 250 and auxiliary IC chip 411 may have a width, diameter or transverse dimension smaller than 5, 3, 1 or 0.5 micrometers, or between 0.1 and 5 micrometers, 0.1 and 3 micrometers, 0.1 and 1 micrometers, or 0.1 and 0.5 micrometers. The pitch between neighboring two of the metal pads 6a of each of its FPGA IC chip 200, logic computing IC chip 269, NVM IC chip 250 and auxiliary IC chip 411 may be smaller than 10, 5.2 or 1 micrometers, or between 0.2 and 10 micrometers, 0.2 and 5 micrometers, 0.2 and 2 micrometers, or 0.2 and 1 micrometers.

Referring to FIG. 14, the sixth type of FPMCP 309 may further include a polymer layer 92 or insulating dielectric layer, i.e., sealing layer, such as silicon-oxide-containing molding compound, epoxy-based material or polyimide, on the bottom of its FPGA IC chip 200 and horizontally around each of its logic computing IC chip 269, NVM IC chip 250, auxiliary IC chip 411 and vertical-through-via (VTV) connectors 467. The semiconductor substrate 2 of each of its logic computing IC chip 269, NVM IC chip 250, auxiliary IC chip 411 and vertical-through-via (VTV) connectors 467 may have a portion, at a backside of the semiconductor substrate 2 of said each of its logic computing IC chip 269, NVM IC chip 250, auxiliary IC chip 411 and vertical-through-via (VTV) connectors 467, removed by a chemical-mechanical-polishing (CMP) or mechanical grinding process such that each of the through silicon vias (TSVs) 157, i.e., the electroplated copper layer 156 thereof, of each of its auxiliary IC chip 411 and vertical-through-via (VTV) connectors 467 may have a bottom surface substantially coplanar with a bottom surface of the semiconductor substrate 2 of each of its logic computing IC chip 269, NVM IC chip 250, auxiliary IC chip 411 and vertical-through-via (VTV) connectors 467 and a bottom surface of its polymer layer 92. For an alternative case, the sixth type of FPMCP 309 may further include the insulating dielectric layer 185, such as silicon-oxide layer or silicon-nitride layer, illustrated in FIG. 4C but not shown in FIG. 14 formed on a bottom surface of the semiconductor substrate 2 of each of its logic computing IC chip 269, NVM IC chip 250, auxiliary IC chip 411 and vertical-through-via (VTV) connectors 467, wherein its insulating dielectric layer 185 may have a bottom surface coplanar with the bottom surface of each of the through silicon vias 157 of each of its auxiliary IC chip 411 and vertical-through-via (VTV) connectors 467 and the bottom surface of its polymer layer 92.

Referring to FIG. 14, the sixth type of FPMCP 309 may further include an interconnection scheme 79 under its logic computing IC chip 269, NVM IC chip 250, auxiliary IC chip 411, vertical-through-via (VTV) connectors 467 and polymer layer 92. Its interconnection scheme 79 may be provided with (1) one or more interconnection metal layers 27 coupling to each of the through silicon vias (TSV) 157 of each of its auxiliary IC chip 411 and vertical-through-via (VTV) connectors 467 and (2) multiple polymer layers 42 each between neighboring two of the interconnection metal layers 27 of its interconnection scheme 79, under the bottommost one of the interconnection metal layers 27 of its interconnection scheme 79 or over the topmost one of the interconnection metal layers 27 of its interconnection scheme 79, wherein an upper one of the interconnection metal layers 27 of its interconnection scheme 79 may couple to a lower one of the interconnection metal layers 27 of its interconnection scheme 79 through an opening in one of the polymer layers 42 of its interconnection scheme 79 between the upper and lower ones of the interconnection metal layers 27 of its interconnection scheme 79. The topmost one of the polymer layers 42 of its interconnection scheme 79 may have a top surface in contact with the bottom surface of its polymer layer 92 and the bottom surface of the semiconductor substrate 2 of each of its logic computing IC chip 269, NVM IC chip 250, auxiliary IC chip 411 and vertical-through-via (VTV) connectors 467. For the alternative case, the topmost one of the polymer layers 42 of its interconnection scheme 79 may have a top surface in contact with the bottom surface of its polymer layer 92 and the bottom surface of its insulating dielectric layer 185. Each opening in the topmost one of the polymer layers 42 of its interconnection scheme 79 may be under one of the through silicon vias (TSVs) 157 of one of its auxiliary IC chip 411 and vertical-through-via (VTV) connectors 467 and thus the topmost one of the interconnection metal layers 27 of its interconnection scheme 79 may extend through said each opening to couple to said one of the through silicon vias (TSVs) 157. Each of the interconnection metal layers 27 of its interconnection scheme 79 may extend horizontally across an edge of each of its logic computing IC chip 269, NVM IC chip 250, auxiliary IC chip 411 and vertical-through-via (VTV) connectors 467. The bottommost one of the interconnection metal layers 27 of its interconnection scheme 79 may have multiple metal pads at tops of multiple respective openings in the bottommost one of the polymer layers 42 of its interconnection scheme 79. The specification and process for the interconnection metal layers 27 and polymer layers 42 of its interconnection scheme 79 may be referred to those for the second interconnection scheme for a chip (SISC) 29 as illustrated in FIG. 3A to be turned upside down. Its polymer layer 92 may have a vertical sidewall coplanar with a vertical sidewall of its FPGA IC chip 200 and a vertical sidewall of its interconnection scheme 79.

Referring to FIG. 14, the sixth type of FPMCP 309 may further include multiple metal bumps, pillars or pads 570 in an array at its bottom to act as its external pins for coupling to external circuits outside of the sixth type of FPMCP 309. Each of its metal bumps, pillars or pads 570 may be of a type selected from various types, i.e., first and second types, which may have the same specification as that of the first and second types of metal bumps, pillars or pads 570 respectively as illustrated in FIG. 6A, and may have the adhesion metal layer 26a on a bottom surface of one of the metal pads of the bottommost one of the interconnection metal layers 27 of its interconnection scheme 79 and a bottom surface of the bottommost one of the polymer layers 42 of its interconnection scheme 79. For the sixth type of FPMCP 309, its FPGA IC chip 200 may couple to one of its metal bumps, pillars or pads 570 through, in sequence, one of the through silicon vias (TSVs) 157 of one of its auxiliary IC chip 411 and vertical-through-via (VTV) connectors 467 and each of the interconnection metal layers 27 of its interconnection scheme 79 for transmitting a signal or clock or delivering a power or ground voltage therebetween.

Referring to FIG. 14, the sixth type of FPMCP 309 may have the inter-chip interconnection between the first and second semiconductor IC chips 100a and 100b via the FPGA IC chip 200 as illustrated in FIG. 5B. For the sixth type of FPMCP 309, its FPGA IC chip 200 may have the same circuits as one illustrated in FIG. 5B, its logic computing IC chip 269 may be the first semiconductor IC chip 100a as illustrated in FIG. 5B, and one of its NVM IC chip 250 and auxiliary IC chip 411 may be the second semiconductor IC chip 100b as illustrated in FIG. 5B. Alternatively, its auxiliary IC chip 411 may be the first semiconductor IC chip 100a as illustrated in FIG. 5B, and its NVM IC chip 250 may be the second semiconductor IC chip 100b as illustrated in FIG. 5B. Each bonded two of the metal pads 6a of the FPGA IC chip 200 and first semiconductor IC chip 100a for the sixth type of FPMCP 309 as illustrated in FIG. 14 may be formed for one of the programmable interconnects 361 of the inter-chip interconnects 371 between the FPGA IC chip 200 and first semiconductor IC chip 100a as illustrated in FIG. 5B, and each bonded two of the metal pads 6a of the FPGA IC chip 200 and second semiconductor IC chip 100b for the sixth type of FPMCP 309 as illustrated in FIG. 14 may be formed for one of the programmable interconnects 361 of the inter-chip interconnects 371 between the FPGA IC chip 200 and second semiconductor IC chip 100b as illustrated in FIG. 5B.

Referring to FIG. 14, the sixth type of FPMCP 309 may perform the operation between the FPGA IC chip 200 and each of the third and fourth semiconductor IC chips 100c and 100d as illustrated in FIG. 5C. For the sixth type of FPMCP 309, its FPGA IC chip 200 may have the same circuits as one illustrated in FIG. 5C, its logic computing IC chip 269 may be the third semiconductor IC chip 100c as illustrated in FIG. 5C, and one of its NVM IC chip 250 and auxiliary IC chip 411 may be the fourth semiconductor IC chip 100d as illustrated in FIG. 5C. Each bonded two of the metal pads 6a of the FPGA IC chip 200 and third semiconductor IC chip 100c for the sixth type of FPMCP 309 as illustrated in FIG. 14 may be formed for one of the programmable interconnects 361 of the inter-chip interconnects 371 between the FPGA IC chip 200 and third semiconductor IC chip 100c as illustrated in FIG. 5C, and each bonded two of the metal pads 6a of the FPGA IC chip 200 and fourth semiconductor IC chip 100d for the sixth type of FPMCP 309 as illustrated in FIG. 14 may be formed for one of the programmable interconnects 361 of the inter-chip interconnects 371 between the FPGA IC chip 200 and fourth semiconductor IC chip 100d as illustrated in FIG. 5C.

Referring to FIG. 14, the sixth type of FPMCP 309 may have the connection to external circuits as illustrated in FIG. 5D. For the sixth type of FPMCP 309, its FPGA IC chip 200 may have the same circuits as one illustrated in FIG. 5D, its auxiliary IC chip 411 may have the same circuits as one illustrated in FIG. 5D, its logic computing IC chip 269 may be the fifth semiconductor IC chip 100e as illustrated in FIG. 5D, and its NVM IC chip 250 may be the sixth semiconductor IC chip 100f as illustrated in FIG. 5D. Each bonded two of the metal pads 6a of the FPGA IC chip 200 and fifth semiconductor IC chip 100e for the sixth type of FPMCP 309 as illustrated in FIG. 14 may be formed for one of the programmable interconnects 361 of the inter-chip interconnects 371 between the FPGA IC chip 200 and fifth semiconductor IC chip 100e as illustrated in FIG. 5D, each bonded two of the metal pads 6a of the FPGA IC chip 200 and sixth semiconductor IC chip 100f for the sixth type of FPMCP 309 as illustrated in FIG. 14 may be formed for one of the programmable interconnects 361 of the inter-chip interconnects 371 between the FPGA IC chip 200 and sixth semiconductor IC chip 100f as illustrated in FIG. 5D, and each bonded two of the metal pads 6a of the FPGA IC chip 200 and auxiliary IC chip 411 for the sixth type of FPMCP 309 as illustrated in FIG. 14 may be formed for one of the programmable interconnects 361 of the inter-chip interconnects 371 between the FPGA IC chip 200 and auxiliary IC chip 411 as illustrated in FIG. 5D. For the sixth type of FPMCP 309 as illustrated in FIG. 14, each of the large input/output (I/O) circuits 341 of the large-input/output (I/O) block of its auxiliary IC chip 411 may couple to one of its metal bumps, pillars or pads 570, which are in an array at its bottom to act as its external pins for coupling to the external circuits 340 as seen in FIG. 5D outside of the sixth type of FPMCP 309, through each of the interconnection metal layers 27 of its interconnection scheme 79.

For the sixth type of FPMCP 309 as seen in FIG. 14, its auxiliary IC chip 411 may include a first small input/output (I/O) circuit coupling to a second small input/output (I/O) circuit of its FPGA IC chip 200 through its first signal path composed of bonded two of the metal pads 6a of its auxiliary IC chip 411 and FPGA IC chip 200, wherein each of the first and second small input/output (I/O) circuits may have an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts. Its auxiliary IC chip 411 may include a large input/output (I/O) circuit coupling to any of its metal bumps, pillars or pads 570 through its second signal path composed of any of the through silicon vias (TSVs) 157 of its auxiliary IC chip 411 and each of the interconnection metal layers 27 of its interconnection scheme 79, wherein the large input/output (I/O) circuit may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or equal to or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Thereby, the first small input/output (I/O) circuit may receive first signals from the second small input/output (I/O) circuit via its first signal path to be converted by its auxiliary IC chip 411 as second signals and then the large input/output (I/O) circuit may transmit the second signals to said any of its metal bumps, pillars or pads 570 via its second signal path. Further, the large input/output (I/O) circuit may receive third signals from said any of its metal bumps, pillars or pads 570 via its second signal path to be converted by its auxiliary IC chip 411 as fourth signals and then the first small input/output (I/O) circuit may transmit the fourth signals to the second small input/output (I/O) circuit via its first signal path.

For the sixth type of FPMCP 309 as seen in FIG. 14, its FPGA IC chip 200 may be programmed, configured or reconfigured following the same way as any aspect of the first through eleventh aspects illustrated in FIGS. 5A-1, 5A-2 and 5E-5G, including (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with first data stored in its NVM IC chip 250 to be configured in accordance with the first data, (2) the first or second type of field programmable switch cell 379 as illustrated in FIG. 2A or 2B having the memory cells 362 as illustrated in FIG. 2A or the four sets of memory cells 362 as illustrated in FIG. 2B for storing data associated with second data stored in its NVM IC chip 250 to be configured in accordance with the second data, and (3) the programmable switch matrix 710 as illustrated in FIG. 2C having the memory cells 398 for storing data, i.e., programming codes, password or encryption/decryption codes, associated with third data stored in its NVM IC chip 250 to be configured in accordance with the third data. Alternatively, its FPGA IC chip 200 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MLU) IC chip, or digital-signal-processing (DSP) IC chip, each of which may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with the first data to be configured in accordance with the first data, (2) the first or second type of field programmable switch cell 379 as illustrated in FIG. 2A or 2B having the memory cells 362 as illustrated in FIG. 2A or the four sets of memory cells 362 as illustrated in FIG. 2B for storing data associated with the second data to be configured in accordance with the second data, and (3) the programmable switch matrix 710 as illustrated in FIG. 2C having the memory cells 398 for storing data, i.e., programming codes, password or encryption/decryption codes, associated with the third data to be configured in accordance with the third data. For the sixth type of FPMCP 309 for each aspect of the first through fourth aspects as illustrated in FIG. 5E, its FPGA IC chip 200 may have the same circuits as one illustrated in FIG. 5E, its auxiliary IC chip 411 may have the same circuits as one illustrated in FIG. 5E, its NVM IC chip 250 may have the same circuits as one illustrated in FIG. 5E, and its logic computing IC chip 269 may be any of the semiconductor IC chips 100g as illustrated in FIG. 5E. Any bonded two of the metal pads 6a of the auxiliary IC chip 411 and FPGA IC chip 200 for the sixth type of FPMCP 309 as seen in FIG. 14 may be formed for one of the non-programmable interconnects 364 of the inter-chip interconnects 371 between the FPGA IC chip 200 and auxiliary IC chip 411 as illustrated in FIG. 5E; any bonded two of the metal pads 6a of the auxiliary IC chip 411 and FPGA IC chip 200, one or more of the interconnection metal layers 6 and/or 27 of the first and/or second interconnection scheme for a chip (FISC and/or SISC) 20 and/or 29 of the FPGA IC chip 200 and any bonded two of the metal pads 6a of the NVM IC chip 250 and FPGA IC chip 200 for the sixth type of FPMCP 309 as seen in FIG. 14 may be formed for one of the non-programmable interconnects 364 of the inter-chip interconnects 371 between the NVM IC chip 250 and auxiliary IC chip 411 as illustrated in FIG. 5E; any bonded two of the metal pads 6a of the logic computing IC chip 269 and FPGA IC chip 200 for the sixth type of FPMCP 309 as seen in FIG. 14 may be formed for one of the programmable interconnects 361 of the inter-chip interconnects 371 between the FPGA IC chip 200 and any of the semiconductor IC chips 100g as illustrated in FIG. 5E; any bonded two of the metal pads 6a of the NVM IC chip 250 and FPGA IC chip 200, one or more of the interconnection metal layers 6 and/or 27 of the first and/or second interconnection scheme for a chip (FISC and/or SISC) 20 and/or 29 of the FPGA IC chip 200, any bonded two of the metal pads 6a of the FPGA IC chip 200 and any of the vertical-through-via (VTV) connectors 467, any of the through silicon vias (TSVs) of said any of the vertical-through-via (VTV) connectors 467, each of the interconnection metal layers 27 of the interconnection scheme 79 and any of the metal bumps, pillars or pads 570 for the sixth type of FPMCP 309 as seen in FIG. 14 may be formed for the first group of the large input/output (I/O) circuits 342 of the NVM IC chip 250 receiving and transmitting the first and second (encrypted) CPM data from and to the external circuits 340 as illustrated in FIG. 5E outside of the sixth type of FPMCP 309; optionally for each aspect of the first through third aspects, any of the through silicon vias (TSVs) 157 of the auxiliary IC chip 411, each of the interconnection metal layers 27 of the interconnection scheme 79 and any of the metal bumps, pillars or pads 570 for the sixth type of FPMCP 309 as seen in FIG. 14 may be formed for the large input/output (I/O) circuits 341 of the large-input/output (I/O) block of the auxiliary IC chip 411 receiving and transmitting the first and second (encrypted) CPM data from and to the external circuits 340 as illustrated in FIG. 5E outside of the sixth type of FPMCP 309 as seen in FIG. 14. For the sixth type of FPMCP 309 for each aspect of the fifth through eighth aspects as illustrated in FIG. 5F, its FPGA IC chip 200 may have the same circuits as one illustrated in FIG. 5F, its auxiliary IC chip 411 may have the same circuits as one illustrated in FIG. 5F, its NVM IC chip 250 may have the same circuits as one illustrated in FIG. 5F, and its logic computing IC chip 269 may be any of the semiconductor IC chips 100g as illustrated in FIG. 5F. Any bonded two of the metal pads 6a of the NVM IC chip 250 and FPGA IC chip 200 for the sixth type of FPMCP 309 as seen in FIG. 14 may be formed for one of the non-programmable interconnects 364 of the inter-chip interconnects 371 between the NVM IC chip 250 and FPGA IC chip 200 as illustrated in FIG. 5F; any bonded two of the metal pads 6a of the auxiliary IC chip 411 and FPGA IC chip 200, one or more of the interconnection metal layers 6 and/or 27 of the first and/or second interconnection scheme for a chip (FISC and/or SISC) 20 and/or 29 of the FPGA IC chip 200 and any bonded two of the metal pads 6a of the NVM IC chip 250 and FPGA IC chip 200 for the sixth type of FPMCP 309 as seen in FIG. 14 may be formed for one of the non-programmable interconnects 364 of the inter-chip interconnects 371 between the NVM IC chip 250 and auxiliary IC chip 411 as illustrated in FIG. 5F; any bonded two of the metal pads 6a of the logic computing IC chip 269 and FPGA IC chip 200 for the sixth type of FPMCP 309 as seen in FIG. 14 may be formed for one of the programmable interconnects 361 of the inter-chip interconnects 371 between the FPGA IC chip 200 and any of the semiconductor IC chips 100g as illustrated in FIG. 5F; any of the through silicon vias (TSVs) 157 of the auxiliary IC chip 411, each of the interconnection metal layers 27 of the interconnection scheme 79 and any of the metal bumps, pillars or pads 570 for the sixth type of FPMCP 309 as seen in FIG. 14 may be formed for the large input/output (I/O) circuits 341 of the large-input/output (I/O) block of the auxiliary IC chip 411 receiving and transmitting the first and second (encrypted) CPM data from and to the external circuits 340 as illustrated in FIG. 5F outside of the sixth type of FPMCP 309. For the sixth type of FPMCP 309 for each aspect of the ninth through eleventh aspects as illustrated in FIG. 5G, its FPGA IC chip 200 may have the same circuits as one illustrated in FIG. 5G, its NVM IC chip 250 may have the same circuits as one illustrated in FIG. 5G, and its logic computing IC chip 269 may be any of the semiconductor IC chips 100g as illustrated in FIG. 5G. Any bonded two of the metal pads 6a of the NVM IC chip 250 and FPGA IC chip 200 for the sixth type of FPMCP 309 as seen in FIG. 14 may be formed for one of the non-programmable interconnects 364 of the inter-chip interconnects 371 between the FPGA IC chip 200 and NVM IC chip 250 as illustrated in FIG. 5G; any bonded two of the metal pads 6a of the logic computing IC chip 269 and FPGA IC chip 200 for the sixth type of FPMCP 309 as seen in FIG. 14 may be formed for one of the programmable interconnects 361 of the inter-chip interconnects 371 between the FPGA IC chip 200 and any of the semiconductor IC chips 100g as illustrated in FIG. 5G; any bonded two of the metal pads 6a of the NVM IC chip 250 and FPGA IC chip 200, one or more of the interconnection metal layers 6 and/or 27 of the first and/or second interconnection scheme for a chip (FISC and/or SISC) 20 and/or 29 of the FPGA IC chip 200, any bonded two of the metal pads 6a of the FPGA IC chip 200 and any of the vertical-through-via (VTV) connectors 467, any of the through silicon vias (TSVs) of said any of the vertical-through-via (VTV) connectors 467, each of the interconnection metal layers 27 of the interconnection scheme 79 and any of the metal bumps, pillars or pads 570 for the sixth type of FPMCP 309 as seen in FIG. 14 may be formed for the large input/output (I/O) circuits 342 of the NVM IC chip 250 receiving and transmitting the first and second (encrypted) CPM data from and to the external circuits 340 as illustrated in FIG. 5G outside of the sixth type of FPMCP 309.

### Seventh Type of FPMCP

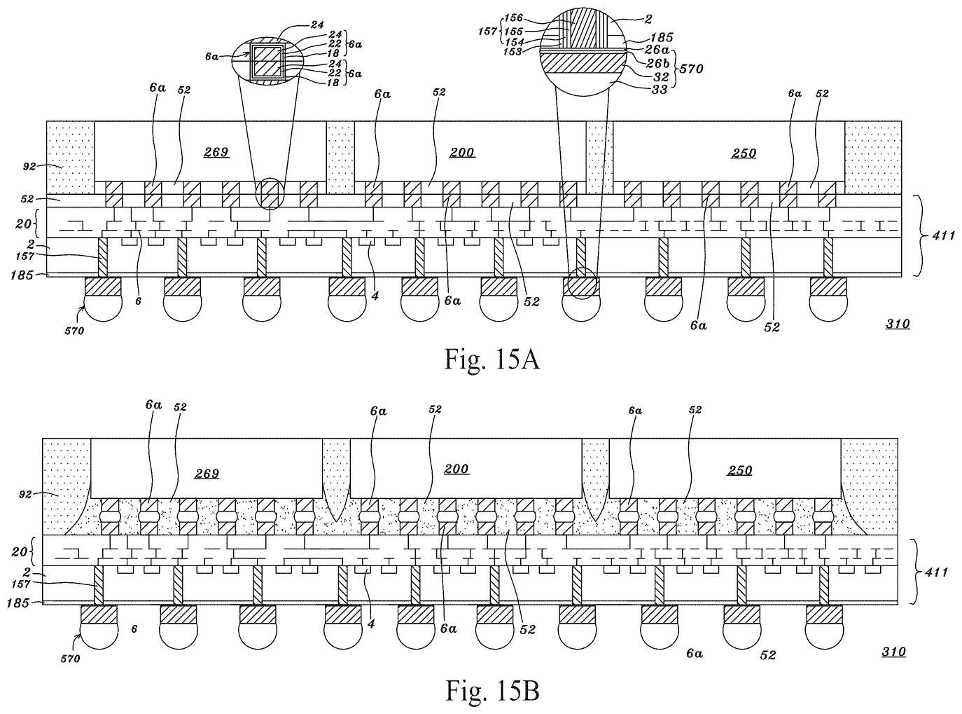

FIGS. 15A and 15B are schematically cross-sectional views showing a seventh type of two FPMCPs in accordance with an embodiment of the present application. A seventh type of FPMCP 310 as seen in FIG. 15A may have a similar structure to the fifth type of FPMCP 308 illustrated in FIG. 13A; a seventh type of FPMCP 310 as seen in FIG. 15B may have a similar structure to the fifth type of FPMCP 308 illustrated in FIG. 13B. For an element indicated by the same reference number shown in FIGS. 13A, 13B, 15A and 15B, the specification of the element as seen in FIG. 15A or 15B may be referred to that of the element as illustrated in FIG. 13A or 13B. The difference therebetween is that each of the FPGA IC chips 200 for the fifth type of FPMCPs 308 illustrated in FIGS. 13A and 13B may be replaced with the auxiliary IC chip 411 illustrated in FIG. 5A-1 for each of the seventh type of FPMCPs 310 as seen in FIGS. 15A and 15B; each of the auxiliary IC chips 411 for the fifth type of FPMCPs 308 illustrated in FIGS. 13A and 13B may be replaced with the logic computing IC chip 269, such as the graphic-processing-unit (GPU) IC chip 269a, central-processing-unit (CPU) IC chip 269b or application-specific integrated-circuit (ASIC) chip or system-on-chip (SoC) chip 269c as illustrated in FIG. 5A-1 or such as data processing unit (DPU) IC chip, tensor flow processing unit (TPU) IC chip or digital-signal-processing (DSP) chip, for each of the seventh type of FPMCPs 310 as seen in FIGS. 15A and 15B; each of the logic computing IC chips 269 for the fifth type of FPMCPs 308 illustrated in FIGS. 13A and 13B may be replaced with a FPGA IC chip 200 illustrated in FIG. 5A-1 for each of the seventh type of FPMCPs 310 as seen in FIGS. 15A and 15B. For each of the seventh type of FPMCPs 310 as seen in FIGS. 15A and 15B, each of its FPGA IC chip 200, logic computing IC chip 269 and NVM IC chip 250 may be formed over its auxiliary IC chip 411, wherein its FPGA IC chip 200 may be arranged horizontally between its logic computing IC chip 269 and NVM IC chip 250. For each of the seventh type of FPMCPs 310 as seen in FIGS. 15A and 15B, its FPGA IC chip 200 may be the dedicated field programmable integrated-circuit (DFPIC) chip as illustrated in FIG. 4D or embedded field programmable integrated-circuit (eFPIC) chip as illustrated in FIG. 4E.

For the seventh type of FPMCP 310 illustrated in FIG. 15A, its auxiliary IC chip 411 may have the same specification as the sixth type of semiconductor IC chip 100 illustrated in FIG. 3F, and each of its FPGA IC chip 200, logic computing IC chip 269 and NVM IC chip 250 may have the same specification as the fifth type of semiconductor IC chip 100 illustrated in FIG. 3E to be turned upside down to be bonded to its auxiliary IC chip 411 for hybrid bonding as illustrated in FIG. 13A. Its auxiliary IC chip 411 may be formed with the insulating dielectric layer 185 on a bottom surface of the semiconductor substrate 2 thereof following the process to form the insulating dielectric layer 185 on the bottom surface of the semiconductor substrate 2 of the FPGA IC chip 200 of the fifth type of FPMCP 308 as illustrated in FIG. 13A. Its first or second type of metal bumps, pillars or pads 570 may be formed at a bottom of its auxiliary IC chip 411 following the same process to form the first or second type of metal bumps, pillars or pads 570 at a bottom of the FPGA IC chip 200 of the fifth type of FPMCP 308 as illustrated in the first through third aspects in FIGS. 13A and 13E. Thereby, in the first aspect each of its first or second type of metal bumps, pillars or pads 570 may have the adhesion metal layer 26a on the bottom surface of one of the through silicon vias (TSVs) 157, i.e., the electroplated copper layer 156 thereof, of its auxiliary IC chip 411 and the bottom surface of the insulating dielectric layer 185 of its auxiliary IC chip 411. In the second aspect, each of its first or second type of metal bumps, pillars or pads 570 may have the adhesion metal layer 26a thereof formed on the bottom surface of the electroplated copper layer 156 of each of the set of through silicon vias 157 (TSVs) of its auxiliary IC chip 411 and the bottom surface of the insulating dielectric layer 185 of its auxiliary IC chip 411 to couple the set of through silicon vias 157 (TSVs) of its auxiliary IC chip 411, wherein the reference layer 6f of the first interconnection scheme for a chip (FISC) 20 of its auxiliary IC chip 411 for the second kind as illustrated in FIGS. 3G and 3H may couple the set of through silicon vias 157 (TSVs) of its auxiliary IC chip 411, the reference layer 6f of the first interconnection scheme for a chip (FISC) 20 of its auxiliary IC chip 411 for the third kind as illustrated in FIG. 3I may couple the set of through silicon vias 157 (TSVs) of its auxiliary IC chip 411, and the second portion of the bottommost one of the interconnection metal layers 6 of the first interconnection scheme for a chip (FISC) 20 of its auxiliary IC chip 411 for the fourth kind as illustrated in FIG. 3J may couple the set of through silicon vias 157 (TSVs) of its auxiliary IC chip 411, wherein a pitch or space between each neighboring two of the set of through silicon vias 157 (TSVs) of its auxiliary IC chip 411, i.e., the electroplated copper layers 156 thereof, may be between 5 and 50 micrometers. In the third aspect, its auxiliary IC chip 411 may be further formed with the insulating dielectric layer 587 as illustrated in FIG. 13E on the bottom surface of the insulating dielectric layer 185 of its auxiliary IC chip 411 as illustrated for the second aspect for its auxiliary IC chip 411, wherein an opening in the insulating dielectric layer 587 of its auxiliary IC chip 411 may be vertically under the set of through silicon vias 157 (TSVs) of its auxiliary IC chip 411 and said each of its first or second type of metal bumps, pillars or pads 570 may be formed in and under the opening in the insulating dielectric layer 587 of its auxiliary IC chip 411 and under and on a bottom surface of the insulating dielectric layer 587 of its auxiliary IC chip 411 and have the adhesion metal layer 26a thereof formed on the bottom surface of the electroplated copper layer 156 of each of the set of through silicon vias 157 (TSVs) of its auxiliary IC chip 411, the bottom surface of the insulating dielectric layer 185 of its auxiliary IC chip 411 and the bottom surface of the insulating dielectric layer 587 of its auxiliary IC chip 411 to couple the set of through silicon vias 157 (TSVs) of its auxiliary IC chip 411. Each of its FPGA IC chip 200, logic computing IC chip 269 and NVM IC chip 250 may couple to one of its metal bumps, pillars or pads 570 through one of the through silicon vias (TSVs) 157 of its auxiliary IC chip 411 for transmitting a signal or clock or delivering a power or ground voltage therebetween.

Alternatively, for the seventh type of FPMCP 310 illustrated in FIG. 15B, its auxiliary IC chip 411 may have the same specification as the second type of semiconductor IC chip 100 illustrated in FIGS. 3B and 3G-3J, and each of its FPGA IC chip 200, logic computing IC chip 269 and NVM IC chip 250 may have the same specification as the first type of semiconductor IC chip 100 illustrated in FIG. 3A to be turned upside down. Each of its FPGA IC chip 200, logic computing IC chip 269 and NVM IC chip 250 may have the first, second, third or fourth type of micro-bumps, micro-pillars or micro-pads 34 each bonded to one of the first, second, third or fourth type of micro-bumps, micro-pillars or micro-pads 34 of its auxiliary IC chip 411 for wafer bumping as illustrated in FIG. 13B for any case of the first through fourth cases. Each of its FPGA IC chip 200, logic computing IC chip 269 and NVM IC chip 250 may couple to one of its first or second type of metal bumps, pillars or pads 570 through, in sequence, one of its bonded metal bumps or contacts 563, which is between said each of its FPGA IC chip 200, logic computing IC chip 269 and NVM IC chip 250 and its auxiliary IC chip 411, and one of the through silicon vias 157 of its auxiliary IC chip 411 for transmitting a signal or clock or delivering a power or ground voltage therebetween. Its first or second type of metal bumps, pillars or pads 570 may be formed at a bottom of its auxiliary IC chip 411 following the same process to form the first or second type of metal bumps, pillars or pads 570 at a bottom of the FPGA IC chip 200 of the fifth type of FPMCP 308 as illustrated in the first through third aspects in FIGS. 13A and 13E. Thereby, the seventh type of FPMCP 310 illustrated in FIG. 15B may be provided in any of the first through third aspects as illustrated in FIG. 15A.

Referring to FIGS. 15A and 15B, each of the seventh type of FPMCPs 310 may have the inter-chip interconnection between the first and second semiconductor IC chips 100a and 100b via the FPGA IC chip 200 as illustrated in FIG. 5B. For each of the seventh type of FPMCPs 310, its FPGA IC chip 200 may have the same circuits as one illustrated in FIG. 5B. For a first scenario, one of its logic computing IC chip 269 and NVM IC chip 250 may be the first semiconductor IC chip 100a as illustrated in FIG. 5B, and its auxiliary IC chip 411 may be the second semiconductor IC chip 100b as illustrated in FIG. 5B. In the first scenario, any bonded two of a first portion of the metal pads 6a of the FPGA IC chip 200 and second semiconductor IC chip 100b, one or more of the interconnection metal layers 6 and/or 27 of the first and/or second interconnection scheme for a chip (FISC and/or SISC) 20 and/or 29 of the second semiconductor IC chip 100b and any bonded two of the metal pads 6a of the first and second semiconductor IC chips 100a and 100b for the seventh type of FPMCP 310 as illustrated in FIG. 15A may be formed for one of the programmable interconnects 361 of the inter-chip interconnects 371 between the FPGA IC chip 200 and first semiconductor IC chip 100a as illustrated in FIG. 5B, and each bonded two of a second portion of the metal pads 6a of the FPGA IC chip 200 and second semiconductor IC chip 100b for the seventh type of FPMCP 310 as illustrated in FIG. 15A may be formed for one of the programmable interconnects 361 of the inter-chip interconnects 371 between the FPGA IC chip 200 and second semiconductor IC chip 100b as illustrated in FIG. 5B. Alternatively, any of a first portion of the bonded metal bumps or contacts 563 between the FPGA IC chip 200 and second semiconductor IC chip 100b, one or more of the interconnection metal layers 6 and/or 27 of the first and/or second interconnection scheme for a chip (FISC and/or SISC) 20 and/or 29 of the second semiconductor IC chip 100b and any of the bonded metal bumps or contacts 563 between the first and second semiconductor IC chips 100a and 100b for the seventh type of FPMCP 310 as illustrated in FIG. 15B may be formed for one of the programmable interconnects 361 of the inter-chip interconnects 371 between the FPGA IC chip 200 and first semiconductor IC chip 100a as illustrated in FIG. 5B, and each of a second portion of the bonded metal bumps or contacts 563 between the FPGA IC chip 200 and second semiconductor IC chip 100b for the seventh type of FPMCP 310 as illustrated in FIG. 15B may be formed for one of the programmable interconnects 361 of the inter-chip interconnects 371 between the FPGA IC chip 200 and second semiconductor IC chip 100b as illustrated in FIG. 5B. For a second scenario, its logic computing IC chip 269 may be the first semiconductor IC chip 100a as illustrated in FIG. 5B, and its NVM IC chip 250 may be the second semiconductor IC chip 100b as illustrated in FIG. 5B. In the second scenario, any bonded two of a first portion of the metal pads 6a of the FPGA IC chip 200 and auxiliary IC chip 411, one or more of the interconnection metal layers 6 and/or 27 of the first and/or second interconnection scheme for a chip (FISC and/or SISC) 20 and/or 29 of the auxiliary IC chip 411 and any bonded two of the metal pads 6a of the auxiliary IC chip 411 and first semiconductor IC chip 100a for the seventh type of FPMCP 310 as illustrated in FIG. 15A may be formed for one of the programmable interconnects 361 of the inter-chip interconnects 371 between the FPGA IC chip 200 and first semiconductor IC chip 100a as illustrated in FIG. 5B, and any bonded two of a second portion of the metal pads 6a of the FPGA IC chip 200 and auxiliary IC chip 411, one or more of the interconnection metal layers 6 and/or 27 of the first and/or second interconnection scheme for a chip (FISC and/or SISC) 20 and/or 29 of the auxiliary IC chip 411 and any bonded two of the metal pads 6a of the auxiliary IC chip 411 and second semiconductor IC chip 100b for the seventh type of FPMCP 310 as illustrated in FIG. 15A may be formed for one of the programmable interconnects 361 of the inter-chip interconnects 371 between the FPGA IC chip 200 and second semiconductor IC chip 100b as illustrated in FIG. 5B. Alternatively, any of a first portion of the bonded metal bumps or contacts 563 between the FPGA IC chip 200 and auxiliary IC chip 411, one or more of the interconnection metal layers 6 and/or 27 of the first and/or second interconnection scheme for a chip (FISC and/or SISC) 20 and/or 29 of the auxiliary IC chip 411 and any of the bonded metal bumps or contacts 563 between the auxiliary IC chip 411 and first semiconductor IC chip 100a for the seventh type of FPMCP 310 as illustrated in FIG. 15B may be formed for one of the programmable interconnects 361 of the inter-chip interconnects 371 between the FPGA IC chip 200 and first semiconductor IC chip 100a as illustrated in FIG. 5B, and any of a second portion of the bonded metal bumps or contacts 563 between the FPGA IC chip 200 and auxiliary IC chip 411, one or more of the interconnection metal layers 6 and/or 27 of the first and/or second interconnection scheme for a chip (FISC and/or SISC) 20 and/or 29 of the auxiliary IC chip 411 and any of the bonded metal bumps or contacts 563 between the auxiliary IC chip 411 and second semiconductor IC chip 100b for the seventh type of FPMCP 310 as illustrated in FIG. 15B may be formed for one of the programmable interconnects 361 of the inter-chip interconnects 371 between the FPGA IC chip 200 and second semiconductor IC chip 100b as illustrated in FIG. 5B.

Referring to FIGS. 15A and 15B, each of the seventh type of FPMCPs 310 may perform the operation between the FPGA IC chip 200 and each of the third and fourth semiconductor IC chips 100c and 100d as illustrated in FIG. 5C. For each of the seventh type of FPMCPs 310, its FPGA IC chip 200 may have the same circuits as one illustrated in FIG. 5C. For a first scenario, its logic computing IC chip 269 may be the third semiconductor IC chip 100c as illustrated in FIG. 5C, and its auxiliary IC chip 411 may be the fourth semiconductor IC chip 100d as illustrated in FIG. 5C. In the first scenario, any bonded two of a first portion of the metal pads 6a of the FPGA IC chip 200 and fourth semiconductor IC chip 100d, one or more of the interconnection metal layers 6 and/or 27 of the first and/or second interconnection scheme for a chip (FISC and/or SISC) 20 and/or 29 of the fourth semiconductor IC chip 100d and any bonded two of the metal pads 6a of the third and fourth semiconductor IC chips 100c and 100d for the seventh type of FPMCP 310 as illustrated in FIG. 15A may be formed for one of the programmable interconnects 361 of the inter-chip interconnects 371 between the FPGA IC chip 200 and third semiconductor IC chip 100c as illustrated in FIG. 5C, and each bonded two of a second portion of the metal pads 6a of the FPGA IC chip 200 and fourth semiconductor IC chip 100d for the seventh type of FPMCP 310 as illustrated in FIG. 15A may be formed for one of the programmable interconnects 361 of the inter-chip interconnects 371 between the FPGA IC chip 200 and fourth semiconductor IC chip 100d as illustrated in FIG. 5C. Alternatively, any of a first portion of the bonded metal bumps or contacts 563 between the FPGA IC chip 200 and fourth semiconductor IC chip 100d, one or more of the interconnection metal layers 6 and/or 27 of the first and/or second interconnection scheme for a chip (FISC and/or SISC) 20 and/or 29 of the fourth semiconductor IC chip 100d and any of the bonded metal bumps or contacts 563 between the third and fourth semiconductor IC chips 100c and 100d for the seventh type of FPMCP 310 as illustrated in FIG. 15B may be formed for one of the programmable interconnects 361 of the inter-chip interconnects 371 between the FPGA IC chip 200 and third semiconductor IC chip 100c as illustrated in FIG. 5C, and each of a second portion of the bonded metal bumps or contacts 563 between the FPGA IC chip 200 and fourth semiconductor IC chip 100d for the seventh type of FPMCP 310 as illustrated in FIG. 15B may be formed for one of the programmable interconnects 361 of the inter-chip interconnects 371 between the FPGA IC chip 200 and fourth semiconductor IC chip 100d as illustrated in FIG. 5C. For a second scenario, its logic computing IC chip 269 may be the third semiconductor IC chip 100c as illustrated in FIG. 5C, and its NVM IC chip 250 may be the fourth semiconductor IC chip 100d as illustrated in FIG. 5C. In the second scenario, any bonded two of a first portion of the metal pads 6a of the FPGA IC chip 200 and auxiliary IC chip 411, one or more of the interconnection metal layers 6 and/or 27 of the first and/or second interconnection scheme for a chip (FISC and/or SISC) 20 and/or 29 of the auxiliary IC chip 411 and any bonded two of the metal pads 6a of the auxiliary IC chip 411 and third semiconductor IC chip 100c for the seventh type of FPMCP 310 as illustrated in FIG. 15A may be formed for one of the programmable interconnects 361 of the inter-chip interconnects 371 between the FPGA IC chip 200 and third semiconductor IC chip 100c as illustrated in FIG. 5C, and any bonded two of a second portion of the metal pads 6a of the FPGA IC chip 200 and auxiliary IC chip 411, one or more of the interconnection metal layers 6 and/or 27 of the first and/or second interconnection scheme for a chip (FISC and/or SISC) 20 and/or 29 of the auxiliary IC chip 411 and any bonded two of the metal pads 6a of the auxiliary IC chip 411 and fourth semiconductor IC chip 100d for the seventh type of FPMCP 310 as illustrated in FIG. 15A may be formed for one of the programmable interconnects 361 of the inter-chip interconnects 371 between the FPGA IC chip 200 and fourth semiconductor IC chip 100d as illustrated in FIG. 5C. Alternatively, any of a first portion of the bonded metal bumps or contacts 563 between the FPGA IC chip 200 and auxiliary IC chip 411, one or more of the interconnection metal layers 6 and/or 27 of the first and/or second interconnection scheme for a chip (FISC and/or SISC) 20 and/or 29 of the auxiliary IC chip 411 and any of the bonded metal bumps or contacts 563 between the auxiliary IC chip 411 and third semiconductor IC chip 100c for the seventh type of FPMCP 310 as illustrated in FIG. 15B may be formed for one of the programmable interconnects 361 of the inter-chip interconnects 371 between the FPGA IC chip 200 and third semiconductor IC chip 100c as illustrated in FIG. 5C, and any of a second portion of the bonded metal bumps or contacts 563 between the FPGA IC chip 200 and auxiliary IC chip 411, one or more of the interconnection metal layers 6 and/or 27 of the first and/or second interconnection scheme for a chip (FISC and/or SISC) 20 and/or 29 of the auxiliary IC chip 411 and any of the bonded metal bumps or contacts 563 between the auxiliary IC chip 411 and fourth semiconductor IC chip 100d for the seventh type of FPMCP 310 as illustrated in FIG. 15B may be formed for one of the programmable interconnects 361 of the inter-chip interconnects 371 between the FPGA IC chip 200 and fourth semiconductor IC chip 100d as illustrated in FIG. 5C.

Referring to FIGS. 15A and 15B, each of the seventh type of FPMCPs 310 may have the connection to external circuits as illustrated in FIG. 5D. For each of the seventh type of FPMCPs 310, its FPGA IC chip 200 may have the same circuits as one illustrated in FIG. 5D, its auxiliary IC chip 411 may have the same circuits as one illustrated in FIG. 5D, its logic computing IC chip 269 may be the fifth semiconductor IC chip 100e as illustrated in FIG. 5D, and its NVM IC chip 250 may be the sixth semiconductor IC chip 100f as illustrated in FIG. 5D. Any bonded two of a first portion of the metal pads 6a of the FPGA IC chip 200 and auxiliary IC chip 411, one or more of the interconnection metal layers 6 and/or 27 of the first and/or second interconnection scheme for a chip (FISC and/or SISC) 20 and/or 29 of the auxiliary IC chip 411 and any bonded two of the metal pads 6a of the auxiliary IC chip 411 and fifth semiconductor IC chip 100e for the seventh type of FPMCP 310 as illustrated in FIG. 15A may be formed for one of the programmable interconnects 361 of the inter-chip interconnects 371 between the FPGA IC chip 200 and fifth semiconductor IC chip 100e as illustrated in FIG. 5D, any bonded two of a second portion of the metal pads 6a of the FPGA IC chip 200 and auxiliary IC chip 411, one or more of the interconnection metal layers 6 and/or 27 of the first and/or second interconnection scheme for a chip (FISC and/or SISC) 20 and/or 29 of the auxiliary IC chip 411 and any bonded two of the metal pads 6a of the auxiliary IC chip 411 and sixth semiconductor IC chip 100f for the seventh type of FPMCP 310 as illustrated in FIG. 15A may be formed for one of the programmable interconnects 361 of the inter-chip interconnects 371 between the FPGA IC chip 200 and sixth semiconductor IC chip 100f as illustrated in FIG. 5D, and each bonded two of a third portion of the metal pads 6a of the FPGA IC chip 200 and auxiliary IC chip 411 for the seventh type of FPMCP 310 as illustrated in FIG. 15A may be formed for one of the programmable interconnects 361 of the inter-chip interconnects 371 between the FPGA IC chip 200 and auxiliary IC chip 411 as illustrated in FIG. 5D. Alternatively, any of a first portion of the bonded metal bumps or contacts 563 between the FPGA IC chip 200 and auxiliary IC chip 411, one or more of the interconnection metal layers 6 and/or 27 of the first and/or second interconnection scheme for a chip (FISC and/or SISC) 20 and/or 29 of the auxiliary IC chip 411 and any of the bonded metal bumps or contacts 563 between the auxiliary IC chip 411 and fifth semiconductor IC chip 100e for the seventh type of FPMCP 310 as illustrated in FIG. 15B may be formed for one of the programmable interconnects 361 of the inter-chip interconnects 371 between the FPGA IC chip 200 and fifth semiconductor IC chip 100e as illustrated in FIG. 5D, any of a second portion of the bonded metal bumps or contacts 563 between the FPGA IC chip 200 and auxiliary IC chip 411, one or more of the interconnection metal layers 6 and/or 27 of the first and/or second interconnection scheme for a chip (FISC and/or SISC) 20 and/or 29 of the auxiliary IC chip 411 and any of the bonded metal bumps or contacts 563 between the auxiliary IC chip 411 and sixth semiconductor IC chip 100f for the seventh type of FPMCP 310 as illustrated in FIG. 15B may be formed for one of the programmable interconnects 361 of the inter-chip interconnects 371 between the FPGA IC chip 200 and sixth semiconductor IC chip 100f as illustrated in FIG. 5D, and each of a third portion of the bonded metal bumps or contacts 563 between the FPGA IC chip 200 and auxiliary IC chip 411 for the seventh type of FPMCP 310 as illustrated in FIG. 15B may be formed for one of the programmable interconnects 361 of the inter-chip interconnects 371 between the FPGA IC chip 200 and auxiliary IC chip 411 as illustrated in FIG. 5D. For each of the seventh type of FPMCPs 310 as illustrated in FIGS. 15A and 15B, each of the large input/output (I/O) circuits 341 of the large-input/output (I/O) block of its auxiliary IC chip 411 may couple to one of its metal bumps, pillars or pads 570, which are in an array at its bottom to act as its external pins for coupling to the external circuits 340 as seen in FIG. 5D outside of said each of the seventh type of FPMCPs 310, through any of the through silicon vias 157 of its auxiliary IC chip 411.

For the seventh type of FPMCP 310 as illustrated in either FIG. 15A or 15B, its auxiliary IC chip 411 may include a first small input/output (I/O) circuit coupling to a second small input/output (I/O) circuit of its FPGA IC chip 200 through its first signal path composed of (1) bonded two of the metal pads 6a of its auxiliary IC chip 411 and FPGA IC chip 200 as seen in FIG. 15A or (2) one of its bonded metal bumps or contacts 563 between its auxiliary IC chip 411 and FPGA IC chip 200 as seen in FIG. 15B, wherein each of the first and second small input/output (I/O) circuits may have an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts. Its auxiliary IC chip 411 may include a large input/output (I/O) circuit coupling to any of its metal bumps, pillars or pads 570 through its second signal path composed of any of the through silicon vias (TSVs) 157 of its auxiliary IC chip 411 as seen in either FIG. 15A or 15B, wherein the large input/output (I/O) circuit may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or equal to or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Thereby, the first small input/output (I/O) circuit may receive first signals from the second small input/output (I/O) circuit via its first signal path to be converted by its auxiliary IC chip 411 as second signals and then the large input/output (I/O) circuit may transmit the second signals to said any of its metal bumps, pillars or pads 570 via its second signal path. Further, the large input/output (I/O) circuit may receive third signals from said any of its metal bumps, pillars or pads 570 via its second signal path to be converted by its auxiliary IC chip 411 as fourth signals and then the first small input/output (I/O) circuit may transmit the fourth signals to the second small input/output (I/O) circuit via its first signal path.

For the seventh type of FPMCP 310 as illustrated in either FIG. 15A or 15B, its FPGA IC chip 200 may be programmed, configured or reconfigured following the same way as any aspect of the first through eleventh aspects illustrated in FIGS. 5A-1, 5A-2 and 5E-5G, including (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with first data stored in its NVM IC chip 250 to be configured in accordance with the first data, (2) the first or second type of field programmable switch cell 379 as illustrated in FIG. 2A or 2B having the memory cells 362 as illustrated in FIG. 2A or the four sets of memory cells 362 as illustrated in FIG. 2B for storing data associated with second data stored in its NVM IC chip 250 to be configured in accordance with the second data, and (3) the programmable switch matrix 710 as illustrated in FIG. 2C having the memory cells 398 for storing data, i.e., programming codes, password or encryption/decryption codes, associated with third data stored in its NVM IC chip 250 to be configured in accordance with the third data. Alternatively, its FPGA IC chip 200 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MLU) IC chip, or digital-signal-processing (DSP) IC chip, each of which may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with the first data to be configured in accordance with the first data, (2) the first or second type of field programmable switch cell 379 as illustrated in FIG. 2A or 2B having the memory cells 362 as illustrated in FIG. 2A or the four sets of memory cells 362 as illustrated in FIG. 2B for storing data associated with the second data to be configured in accordance with the second data, and (3) the programmable switch matrix 710 as illustrated in FIG. 2C having the memory cells 398 for storing data, i.e., programming codes, password or encryption/decryption codes, associated with the third data to be configured in accordance with the third data. For either of the seventh type of FPMCPs 310 for each aspect of the first through fourth aspects as illustrated in FIG. 5E, its FPGA IC chip 200 may have the same circuits as one illustrated in FIG. 5E, its auxiliary IC chip 411 may have the same circuits as one illustrated in FIG. 5E, its NVM IC chip 250 may have the same circuits as one illustrated in FIG. 5E, and its logic computing IC chip 269 may be any of the semiconductor IC chips 100g as illustrated in FIG. 5E. Any bonded two of the metal pads 6a of the auxiliary IC chip 411 and FPGA IC chip 200 for the seventh type of FPMCP 310 as seen in FIG. 15A or any of the bonded metal bumps or contacts 563 between the auxiliary IC chip 411 and FPGA IC chip 200 for the seventh type of FPMCP 310 as seen in FIG. 15B may be formed for one of the non-programmable interconnects 364 of the inter-chip interconnects 371 between the FPGA IC chip 200 and auxiliary IC chip 411 as illustrated in FIG. 5E; any bonded two of the metal pads 6a of the auxiliary IC chip 411 and NVM IC chip 250 for the seventh type of FPMCP 310 as seen in FIG. 15A or any of the bonded metal bumps or contacts 563 between the auxiliary IC chip 411 and NVM IC chip 250 for the seventh type of FPMCP 310 as seen in FIG. 15B may be formed for one of the non-programmable interconnects 364 of the inter-chip interconnects 371 between the NVM IC chip 250 and auxiliary IC chip 411 as illustrated in FIG. 5E; (1) any bonded two of the metal pads 6a of the auxiliary IC chip 411 and FPGA IC chip 200, one or more of the interconnection metal layers 6 and/or 27 of the first and/or second interconnection scheme for a chip (FISC and/or SISC) 20 and/or 29 of the auxiliary IC chip 411 and any bonded two of the metal pads 6a of the logic computing IC chip 269 and auxiliary IC chip 411 for the seventh type of FPMCP 310 as seen in FIG. 15A, or (2) any of the bonded metal bumps or contacts 563 between the auxiliary IC chip 411 and FPGA IC chip 200, one or more of the interconnection metal layers 6 and/or 27 of the first and/or second interconnection scheme for a chip (FISC and/or SISC) 20 and/or 29 of the auxiliary IC chip 411 and any of the bonded metal bumps or contacts 563 between the logic computing IC chip 269 and auxiliary IC chip 411 for the seventh type of FPMCP 310 as seen in FIG. 15B, may be formed for one of the programmable interconnects 361 of the inter-chip interconnects 371 between the FPGA IC chip 200 and any of the semiconductor IC chips 100g as illustrated in FIG. 5E; (1) any bonded two of the metal pads 6a of the NVM IC chip 250 and auxiliary IC chip 411, any of the through silicon vias (TSVs) 157 of the auxiliary IC chip 411 and any of the metal bumps, pillars or pads 570 for the seventh type of FPMCP 310 as seen in FIG. 15A, or (2) any of the bonded metal bumps or contacts 563 between the NVM IC chip 250 and auxiliary IC chip 411, any of the through silicon vias (TSVs) 157 of the auxiliary IC chip 411 and any of the metal bumps, pillars or pads 570 for the seventh type of FPMCP 310 as seen in FIG. 15B, may be formed for the first group of the large input/output (I/O) circuits 342 of the NVM IC chip 250 receiving and transmitting the first and second (encrypted) CPM data from and to the external circuits 340 as illustrated in FIG. 5E outside of the seventh type of FPMCP 310; optionally for each aspect of the first through third aspects any of the through silicon vias (TSVs) 157 of the auxiliary IC chip 411 and any of the metal bumps, pillars or pads 570 for either of the seventh type of FPMCPs 310 as seen in FIGS. 15A and 15B may be formed for the large input/output (I/O) circuits 341 of the large-input/output (I/O) block of the auxiliary IC chip 411 receiving and transmitting the first and second (encrypted) CPM data from and to the external circuits 340 as illustrated in FIG. 5E outside of the seventh type of FPMCP 310. For either of the seventh type of FPMCPs 310 for each aspect of the fifth through eighth aspects as illustrated in FIG. 5F, its FPGA IC chip 200 may have the same circuits as one illustrated in FIG. 5F, its auxiliary IC chip 411 may have the same circuits as one illustrated in FIG. 5F, its NVM IC chip 250 may have the same circuits as one illustrated in FIG. 5F, and its logic computing IC chip 269 may be any of the semiconductor IC chips 100g as illustrated in FIG. 5F. (1) Any bonded two of the metal pads 6a of the auxiliary IC chip 411 and FPGA IC chip 200, one or more of the interconnection metal layers 6 and/or 27 of the first and/or second interconnection scheme for a chip (FISC and/or SISC) 20 and/or 29 of the auxiliary IC chip 411 and any bonded two of the metal pads 6a of the NVM IC chip 250 and auxiliary IC chip 411 for the seventh type of FPMCP 310 as seen in FIG. 15A, or (2) any of the bonded metal bumps or contacts 563 between the auxiliary IC chip 411 and FPGA IC chip 200, one or more of the interconnection metal layers 6 and/or 27 of the first and/or second interconnection scheme for a chip (FISC and/or SISC) 20 and/or 29 of the auxiliary IC chip 411 and any of the bonded metal bumps or contacts 563 between the NVM IC chip 250 and auxiliary IC chip 411 for the seventh type of FPMCP 310 as seen in FIG. 15B, may be formed for one of the non-programmable interconnects 364 of the inter-chip interconnects 371 between the NVM IC chip 250 and FPGA IC chip 200 as illustrated in FIG. 5F; any bonded two of the metal pads 6a of the auxiliary IC chip 411 and NVM IC chip 250 for the seventh type of FPMCP 310 as seen in FIG. 15A or any of the bonded metal bumps or contacts 563 between the auxiliary IC chip 411 and NVM IC chip 250 for the seventh type of FPMCP 310 as seen in FIG. 15B may be formed for one of the non-programmable interconnects 364 of the inter-chip interconnects 371 between the NVM IC chip 250 and auxiliary IC chip 411 as illustrated in FIG. 5F; (1) any bonded two of the metal pads 6a of the auxiliary IC chip 411 and FPGA IC chip 200, one or more of the interconnection metal layers 6 and/or 27 of the first and/or second interconnection scheme for a chip (FISC and/or SISC) 20 and/or 29 of the auxiliary IC chip 411 and any bonded two of the metal pads 6a of the logic computing IC chip 269 and auxiliary IC chip 411 for the seventh type of FPMCP 310 as seen in FIG. 15A, or (2) any of the bonded metal bumps or contacts 563 between the auxiliary IC chip 411 and FPGA IC chip 200, one or more of the interconnection metal layers 6 and/or 27 of the first and/or second interconnection scheme for a chip (FISC and/or SISC) 20 and/or 29 of the auxiliary IC chip 411 and any of the bonded metal bumps or contacts 563 between the logic computing IC chip 269 and auxiliary IC chip 411 for the seventh type of FPMCP 310 as seen in FIG. 15B, may be formed for one of the programmable interconnects 361 of the inter-chip interconnects 371 between the FPGA IC chip 200 and any of the semiconductor IC chips 100g as illustrated in FIG. 5F; any of the through silicon vias (TSVs) 157 of the auxiliary IC chip 411 and any of the metal bumps, pillars or pads 570 for either of the seventh type of FPMCPs 310 as seen in FIGS. 15A and 15B may be formed for the large input/output (I/O) circuits 341 of the large-input/output (I/O) block of the auxiliary IC chip 411 receiving and transmitting the first and second (encrypted) CPM data from and to the external circuits 340 as illustrated in FIG. 5F outside of the seventh type of FPMCP 310. For either of the fifth type of FPMCPs 308 for each aspect of the ninth through eleventh aspects as illustrated in FIG. 5G, its FPGA IC chip 200 may have the same circuits as one illustrated in FIG. 5G, its NVM IC chip 250 may have the same circuits as one illustrated in FIG. 5G, and its logic computing IC chip 269 may be any of the semiconductor IC chips 100g as illustrated in FIG. 5G. (1) Any bonded two of the metal pads 6a of the auxiliary IC chip 411 and FPGA IC chip 200, one or more of the interconnection metal layers 6 and/or 27 of the first and/or second interconnection scheme for a chip (FISC and/or SISC) 20 and/or 29 of the auxiliary IC chip 411 and any bonded two of the metal pads 6a of the NVM IC chip 250 and auxiliary IC chip 411 for the seventh type of FPMCP 310 as seen in FIG. 15A, or (2) any of the bonded metal bumps or contacts 563 between the auxiliary IC chip 411 and FPGA IC chip 200, one or more of the interconnection metal layers 6 and/or 27 of the first and/or second interconnection scheme for a chip (FISC and/or SISC) 20 and/or 29 of the auxiliary IC chip 411 and any of the bonded metal bumps or contacts 563 between the NVM IC chip 250 and auxiliary IC chip 411 for the seventh type of FPMCP 310 as seen in FIG. 15B, may be formed for one of the non-programmable interconnects 364 of the inter-chip interconnects 371 between the FPGA IC chip 200 and NVM IC chip 250 as illustrated in FIG. 5G; (1) any bonded two of the metal pads 6a of the auxiliary IC chip 411 and FPGA IC chip 200, one or more of the interconnection metal layers 6 and/or 27 of the first and/or second interconnection scheme for a chip (FISC and/or SISC) 20 and/or 29 of the auxiliary IC chip 411 and any bonded two of the metal pads 6a of the logic computing IC chip 269 and auxiliary IC chip 411 for the seventh type of FPMCP 310 as seen in FIG. 15A, or (2) any of the bonded metal bumps or contacts 563 between the auxiliary IC chip 411 and FPGA IC chip 200, one or more of the interconnection metal layers 6 and/or 27 of the first and/or second interconnection scheme for a chip (FISC and/or SISC) 20 and/or 29 of the auxiliary IC chip 411 and any of the bonded metal bumps or contacts 563 between the logic computing IC chip 269 and auxiliary IC chip 411 for the seventh type of FPMCP 310 as seen in FIG. 15B, may be formed for one of the programmable interconnects 361 of the inter-chip interconnects 371 between the FPGA IC chip 200 and any of the semiconductor IC chips 100g as illustrated in FIG. 5G; (1) any bonded two of the metal pads 6a of the NVM IC chip 250 and auxiliary IC chip 411, any of the through silicon vias (TSVs) 157 of the auxiliary IC chip 411 and any of the metal bumps, pillars or pads 570 for the seventh type of FPMCP 310 as seen in FIG. 15A, or (2) any of the bonded metal bumps or contacts 563 between the NVM IC chip 250 and auxiliary IC chip 411, any of the through silicon vias (TSVs) 157 of the auxiliary IC chip 411 and any of the metal bumps, pillars or pads 570 for the seventh type of FPMCP 310 as seen in FIG. 15B, may be formed for the large input/output (I/O) circuits 342 of the NVM IC chip 250 receiving and transmitting the first and second (encrypted) CPM data from and to the external circuits 340 as illustrated in FIG. 5G outside of the fifth type of FPMCP 308.

### Eighth Type of FPMCP

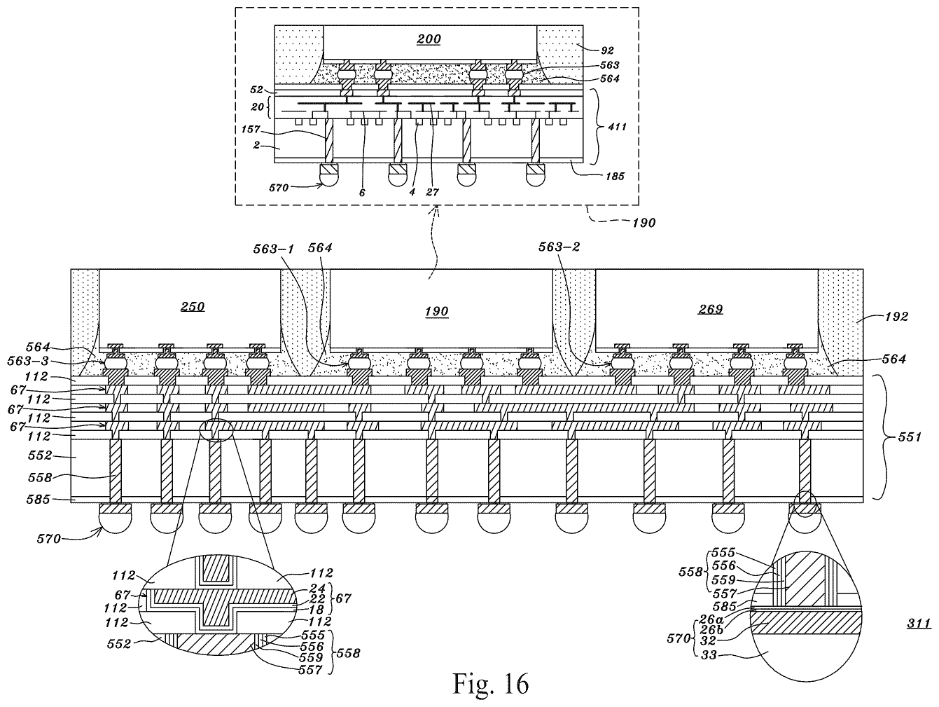

FIG. 16 is a schematically cross-sectional view showing an eighth type of FPMCP in accordance with an embodiment of the present application. An eighth type of FPMCP 311 as seen in FIG. 16 may include a subsystem unit 190 having a similar structure to either of the seventh type of FPMCPs 310 as illustrated in FIGS. 15A and 15B. The difference therebetween is that the logic computing IC chip 269 and NVM IC chip 250 of either of the seventh type of FPMCPs 310 as illustrated in FIGS. 15A and 15B may be saved for the subsystem unit 190 of the eighth type of FPMCP 311 as seen in FIG. 16. For the eighth type of FPMCP 311, the FPGA IC chip 200 of its subsystem unit 190 may be the dedicated field programmable integrated-circuit (DFPIC) chip as illustrated in FIG. 4D or embedded field programmable integrated-circuit (eFPIC) chip as illustrated in FIG. 4E. The eighth type of FPMCP 311 may further include (1) an interposer 551 as illustrated in FIG. 6A, (2) a NVM IC chip 250, having the specification as illustrated for one in FIG. 5A-1, on a top of its interposer 551 and (3) a logic computing IC chip 269, such as the graphic-processing-unit (GPU) IC chip 269a, central-processing-unit (CPU) IC chip 269b or application-specific integrated-circuit (ASIC) chip or system-on-chip (SoC) chip 269c as illustrated in FIG. 5A-1 or such as data processing unit (DPU) IC chip, tensor flow processing unit (TPU) IC chip or digital-signal-processing (DSP) chip, on the top of its interposer 551. For the eighth type of FPMCP 311, each of its logic computing IC chip 269 and NVM IC chip 250 may have the same specification as the first type of semiconductor IC chip 100 illustrated in FIG. 3A to be turned upside down. Its subsystem unit 190 may have the metal bumps, pillars or pads 570 each bonded to the top of its interposer 551 into a bonded metal bump or contact 563-1 therebetween. Its logic computing IC chip 269 may have the first, second, third or fourth type of micro-bumps, micro-pillars or micro-pads 34 each bonded to the top of its interposer 551 into a bonded metal bump or contact 563-2 therebetween. Its NVM IC chip 250 may have the first, second, third or fourth type of micro-bumps, micro-pillars or micro-pads 34 each bonded to the top of its interposer 551 into a bonded metal bump or contact 563-3 therebetween. The eighth type of FPMCP 311 may further include (1) an underfill 564, e.g., polymer layer, between its subsystem unit 190 and interposer 551, between its logic computing IC chip 269 and interposer 551 and between its NVM IC chip 250 and interposer 551, covering a sidewall of each of its bonded metal bumps or contacts 563-1, 563-2 and 563-3 and (2) a polymer layer 192 or insulating dielectric layer, i.e., sealing layer, such as silicon-oxide-containing molding compound, epoxy-based material or polyimide, on the top of its interposer 551 and horizontally around each of its logic computing IC chip 269, NVM IC chip 250 and subsystem unit 190, wherein its polymer layer 192 may cover a top surface of each of its logic computing IC chip 269 and NVM IC chip 250 and may have a top surface coplanar with a top surface of the FPGA IC chip 200 of its subsystem unit 190 and a top surface of the polymer layer 92 of its subsystem unit 190. Its polymer layer 192 may have a vertical sidewall coplanar with a vertical sidewall of its interposer 551.

Referring to FIG. 16, the eighth type of FPMCP 311 may have the inter-chip interconnection between the first and second semiconductor IC chips 100a and 100b via the FPGA IC chip 200 as illustrated in FIG. 5B. For the eighth type of FPMCP 311, the FPGA IC chip 200 of its subsystem unit 190 may have the same circuits as one illustrated in FIG. 5B. For a first scenario, one of its logic computing IC chip 269 and NVM IC chip 250 may be the first semiconductor IC chip 100a as illustrated in FIG. 5B, and the auxiliary IC chip 411 of its subsystem unit 190 may be the second semiconductor IC chip 100b as illustrated in FIG. 5B. In the first scenario, for its subsystem unit 190 formed by hybrid bonding as illustrated in FIGS. 13A and 15A, any bonded two of a first portion of the metal pads 6a of the FPGA IC chip 200 and second semiconductor IC chip 100b of its subsystem unit 190, any of the through silicon vias (TSVs) 157 of the second semiconductor IC chip 100b of its subsystem unit 190, any of its bonded metal bumps or contacts 563-1, one or more of the interconnection metal layers 67 of its interposer 551 and any of its bonded metal bumps or contacts 563-2 or 563-3 between its first semiconductor IC chip 100a and interposer 551 may be formed for one of the programmable interconnects 361 of the inter-chip interconnects 371 between the FPGA IC chip 200 and first semiconductor IC chip 100a as illustrated in FIG. 5B, and each bonded two of a second portion of the metal pads 6a of the FPGA IC chip 200 and second semiconductor IC chip 100b of its subsystem unit 190 may be formed for one of the programmable interconnects 361 of the inter-chip interconnects 371 between the FPGA IC chip 200 and second semiconductor IC chip 100b as illustrated in FIG. 5B. Alternatively, for its subsystem unit 190 formed by wafer bumping as illustrated in FIGS. 13B and 15B for any case of the first through fourth cases, any of a first portion of the bonded metal bumps or contacts 563 between the FPGA IC chip 200 and second semiconductor IC chip 100b of its subsystem unit 190, any of the through silicon vias (TSVs) 157 of the second semiconductor IC chip 100b of its subsystem unit 190, any of its bonded metal bumps or contacts 563-1, one or more of the interconnection metal layers 67 of its interposer 551 and any of its bonded metal bumps or contacts 563-2 or 563-3 between its first semiconductor IC chip 100a and interposer 551 may be formed for one of the programmable interconnects 361 of the inter-chip interconnects 371 between the FPGA IC chip 200 and first semiconductor IC chip 100a as illustrated in FIG. 5B, and each of a second portion of the bonded metal bumps or contacts 563 between the FPGA IC chip 200 and second semiconductor IC chip 100b of its subsystem unit 190 may be formed for one of the programmable interconnects 361 of the inter-chip interconnects 371 between the FPGA IC chip 200 and second semiconductor IC chip 100b as illustrated in FIG. 5B. For a second scenario, its logic computing IC chip 269 may be the first semiconductor IC chip 100a as illustrated in FIG. 5B, and its NVM IC chip 250 may be the second semiconductor IC chip 100b as illustrated in FIG. 5B. In the second scenario, for its subsystem unit 190 formed by hybrid bonding as illustrated in FIGS. 13A and 15A, any bonded two of a first portion of the metal pads 6a of the FPGA IC chip 200 and auxiliary IC chip 411 of its subsystem unit 190, any of a first portion of the through silicon vias (TSVs) 157 of the auxiliary IC chip 411 of its subsystem unit 190, any of a first portion of its bonded metal bumps or contacts 563-1, one or more of the interconnection metal layers 67 of its interposer 551 and any of its bonded metal bumps or contacts 563-2 may be formed for one of the programmable interconnects 361 of the inter-chip interconnects 371 between the FPGA IC chip 200 and first semiconductor IC chip 100a as illustrated in FIG. 5B, and any bonded two of a second portion of the metal pads 6a of the FPGA IC chip 200 and auxiliary IC chip 411 of its subsystem unit 190, any of a second portion of the through silicon vias (TSVs) 157 of the auxiliary IC chip 411 of its subsystem unit 190, any of a second portion of its bonded metal bumps or contacts 563-1, one or more of the interconnection metal layers 67 of its interposer 551 and any of its bonded metal bumps or contacts 563-3 may be formed for one of the programmable interconnects 361 of the inter-chip interconnects 371 between the FPGA IC chip 200 and second semiconductor IC chip 100b as illustrated in FIG. 5B. Alternatively, for its subsystem unit 190 formed by wafer bumping as illustrated in FIGS. 13B and 15B for any case of the first through fourth cases, any of a first portion of the bonded metal bumps or contacts 563 between the FPGA IC chip 200 and auxiliary IC chip 411 of its subsystem unit 190, any of a first portion of the through silicon vias (TSVs) 157 of the auxiliary IC chip 411 of its subsystem unit 190, any of a first portion of its bonded metal bumps or contacts 563-1, one or more of the interconnection metal layers 67 of its interposer 551 and any of its bonded metal bumps or contacts 563-2 may be formed for one of the programmable interconnects 361 of the inter-chip interconnects 371 between the FPGA IC chip 200 and first semiconductor IC chip 100a as illustrated in FIG. 5B, and any of a second portion of the bonded metal bumps or contacts 563 between the FPGA IC chip 200 and auxiliary IC chip 411 of its subsystem unit 190, any of a second portion of the through silicon vias (TSVs) 157 of the auxiliary IC chip 411 of its subsystem unit 190, any of a second portion of its bonded metal bumps or contacts 563-1, one or more of the interconnection metal layers 67 of its interposer 551 and any of its bonded metal bumps or contacts 563-3 may be formed for one of the programmable interconnects 361 of the inter-chip interconnects 371 between the FPGA IC chip 200 and second semiconductor IC chip 100b as illustrated in FIG. 5B.

Referring to FIG. 16, the eighth type of FPMCP 311 may perform the operation between the FPGA IC chip 200 and each of the third and fourth semiconductor IC chips 100c and 100d as illustrated in FIG. 5C. For the eighth type of FPMCP 311, the FPGA IC chip 200 of its subsystem unit 190 may have the same circuits as one illustrated in FIG. 5C. For a first scenario, its logic computing IC chip 269 may be the third semiconductor IC chip 100c as illustrated in FIG. 5C, and the auxiliary IC chip 411 of its subsystem unit 190 may be the fourth semiconductor IC chip 100d as illustrated in FIG. 5C. In the first scenario, for its subsystem unit 190 formed by hybrid bonding as illustrated in FIGS. 13A and 15A, any bonded two of a first portion of the metal pads 6a of the FPGA IC chip 200 and fourth semiconductor IC chip 100d of its subsystem unit 190, any of the through silicon vias (TSVs) 157 of the fourth semiconductor IC chip 100d of its subsystem unit 190, any of its bonded metal bumps or contacts 563-1 between its subsystem unit 190 and interposer 551, one or more of the interconnection metal layers 67 of its interposer 551 and any of its bonded metal bumps or contacts 563-2 may be formed for one of the programmable interconnects 361 of the inter-chip interconnects 371 between the FPGA IC chip 200 and third semiconductor IC chip 100c as illustrated in FIG. 5C, and each bonded two of a second portion of the metal pads 6a of the FPGA IC chip 200 and fourth semiconductor IC chip 100d of its subsystem unit 190 may be formed for one of the programmable interconnects 361 of the inter-chip interconnects 371 between the FPGA IC chip 200 and fourth semiconductor IC chip 100d as illustrated in FIG. 5C. Alternatively, for its subsystem unit 190 formed by wafer bumping as illustrated in FIGS. 13B and 15B for any case of the first through fourth cases, any of a first portion of the bonded metal bumps or contacts 563 between the FPGA IC chip 200 and fourth semiconductor IC chip 100d of its subsystem unit 190, any of the through silicon vias (TSVs) 157 of the fourth semiconductor IC chip 100d of its subsystem unit 190, any of its bonded metal bumps or contacts 563-1, one or more of the interconnection metal layers 67 of its interposer 551 and any of its bonded metal bumps or contacts 563-2 may be formed for one of the programmable interconnects 361 of the inter-chip interconnects 371 between the FPGA IC chip 200 and third semiconductor IC chip 100c as illustrated in FIG. 5C, and each of a second portion of the bonded metal bumps or contacts 563 between the FPGA IC chip 200 and fourth semiconductor IC chip 100d of its subsystem unit 190 may be formed for one of the programmable interconnects 361 of the inter-chip interconnects 371 between the FPGA IC chip 200 and fourth semiconductor IC chip 100d as illustrated in FIG. 5C. For a second scenario, its logic computing IC chip 269 may be the third semiconductor IC chip 100c as illustrated in FIG. 5C, and its NVM IC chip 250 may be the fourth semiconductor IC chip 100d as illustrated in FIG. 5C. In the second scenario, for its subsystem unit 190 formed by hybrid bonding as illustrated in FIGS. 13A and 15A, any bonded two of a first portion of the metal pads 6a of the FPGA IC chip 200 and auxiliary IC chip 411 of its subsystem unit 190, any of a first portion of the through silicon vias (TSVs) 157 of the auxiliary IC chip 411 of its subsystem unit 190, any of a first portion of its bonded metal bumps or contacts 563-1, one or more of the interconnection metal layers 67 of its interposer 551 and any of its bonded metal bumps or contacts 563-2 may be formed for one of the programmable interconnects 361 of the inter-chip interconnects 371 between the FPGA IC chip 200 and third semiconductor IC chip 100c as illustrated in FIG. 5C, and any bonded two of a second portion of the metal pads 6a of the FPGA IC chip 200 and auxiliary IC chip 411 of its subsystem unit 190, any of a second portion of the through silicon vias (TSVs) 157 of the auxiliary IC chip 411 of its subsystem unit 190, any of a second portion of its bonded metal bumps or contacts 563-1, one or more of the interconnection metal layers 67 of its interposer 551 and any of its bonded metal bumps or contacts 563-3 may be formed for one of the programmable interconnects 361 of the inter-chip interconnects 371 between the FPGA IC chip 200 and fourth semiconductor IC chip 100d as illustrated in FIG. 5C. Alternatively, for its subsystem unit 190 formed by wafer bumping as illustrated in FIGS. 13B and 15B for any case of the first through fourth cases, any of a first portion of the bonded metal bumps or contacts 563 between the FPGA IC chip 200 and auxiliary IC chip 411 of its subsystem unit 190, any of a first portion of the through silicon vias (TSVs) 157 of the auxiliary IC chip 411 of its subsystem unit 190, any of a first portion of its bonded metal bumps or contacts 563-1, one or more of the interconnection metal layers 67 of its interposer 551 and any of its bonded metal bumps or contacts 563-2 may be formed for one of the programmable interconnects 361 of the inter-chip interconnects 371 between the FPGA IC chip 200 and third semiconductor IC chip 100c as illustrated in FIG. 5C, and any of a second portion of the bonded metal bumps or contacts 563 between the FPGA IC chip 200 and auxiliary IC chip 411 of its subsystem unit 190, any of a second portion of the through silicon vias (TSVs) 157 of the auxiliary IC chip 411 of its subsystem unit 190, any of a second portion of its bonded metal bumps or contacts 563-1, one or more of the interconnection metal layers 67 of its interposer 551 and any of its bonded metal bumps or contacts 563-3 may be formed for one of the programmable interconnects 361 of the inter-chip interconnects 371 between the FPGA IC chip 200 and fourth semiconductor IC chip 100d as illustrated in FIG. 5C.

Referring to FIG. 16, the eighth type of FPMCP 311 may have the connection to external circuits as illustrated in FIG. 5D. For the eighth type of FPMCP 311, the FPGA IC chip 200 of its subsystem unit 190 may have the same circuits as one illustrated in FIG. 5D, the auxiliary IC chip 411 of its subsystem unit 190 may have the same circuits as one illustrated in FIG. 5D, its logic computing IC chip 269 may be the fifth semiconductor IC chip 100e as illustrated in FIG. 5D, and its NVM IC chip 250 may be the sixth semiconductor IC chip 100f as illustrated in FIG. 5D. For its subsystem unit 190 formed by hybrid bonding as illustrated in FIGS. 13A and 15A, any bonded two of a first portion of the metal pads 6a of the FPGA IC chip 200 and auxiliary IC chip 411 of its subsystem unit 190, any of a first portion of the through silicon vias (TSVs) 157 of the auxiliary IC chip 411 of its subsystem unit 190, any of a first portion of its bonded metal bumps or contacts 563-1, one or more of the interconnection metal layers 67 of its interposer 551 and any of its bonded metal bumps or contacts 563-2 may be formed for one of the programmable interconnects 361 of the inter-chip interconnects 371 between the FPGA IC chip 200 and fifth semiconductor IC chip 100e as illustrated in FIG. 5D, any bonded two of a second portion of the metal pads 6a of the FPGA IC chip 200 and auxiliary IC chip 411 of its subsystem unit 190, any of a second portion of the through silicon vias (TSVs) 157 of the auxiliary IC chip 411 of its subsystem unit 190, any of a second portion of its bonded metal bumps or contacts 563-1, one or more of the interconnection metal layers 67 of its interposer 551 and any of its bonded metal bumps or contacts 563-3 may be formed for one of the programmable interconnects 361 of the inter-chip interconnects 371 between the FPGA IC chip 200 and sixth semiconductor IC chip 100f as illustrated in FIG. 5D, and each bonded two of a third portion of the metal pads 6a of the FPGA IC chip 200 and auxiliary IC chip 411 of its subsystem unit 190 may be formed for one of the programmable interconnects 361 of the inter-chip interconnects 371 between the FPGA IC chip 200 and auxiliary IC chip 411 as illustrated in FIG. 5D. Alternatively, for its subsystem unit 190 formed by wafer bumping as illustrated in FIGS. 13B and 15B for any case of the first through fourth cases, any of a first portion of the bonded metal bumps or contacts 563 between the FPGA IC chip 200 and auxiliary IC chip 411 of its subsystem unit 190, any of a first portion of the through silicon vias (TSVs) 157 of the auxiliary IC chip 411 of its subsystem unit 190, any of a first portion of its bonded metal bumps or contacts 563-1, one or more of the interconnection metal layers 67 of its interposer 551 and any of its bonded metal bumps or contacts 563-2 may be formed for one of the programmable interconnects 361 of the inter-chip interconnects 371 between the FPGA IC chip 200 and fifth semiconductor IC chip 100e as illustrated in FIG. 5D, any of a second portion of the bonded metal bumps or contacts 563 between the FPGA IC chip 200 and auxiliary IC chip 411 of its subsystem unit 190, any of a second portion of the through silicon vias (TSVs) 157 of the auxiliary IC chip 411 of its subsystem unit 190, any of a second portion of its bonded metal bumps or contacts 563-1, one or more of the interconnection metal layers 67 of its interposer 551 and any of its bonded metal bumps or contacts 563-3 may be formed for one of the programmable interconnects 361 of the inter-chip interconnects 371 between the FPGA IC chip 200 and sixth semiconductor IC chip 100f as illustrated in FIG. 5D, and each of a third portion of the bonded metal bumps or contacts 563 between the FPGA IC chip 200 and auxiliary IC chip 411 of its subsystem unit 190 may be formed for one of the programmable interconnects 361 of the inter-chip interconnects 371 between the FPGA IC chip 200 and auxiliary IC chip 411 as illustrated in FIG. 5D. For the eighth type of FPMCP 311, each of the large input/output (I/O) circuits 341 of the large-input/output (I/O) block of the auxiliary IC chip 411 of its subsystem unit 190 may couple to one of its metal bumps, pillars or pads 570, which are in an array at its bottom to act as its external pins for coupling to the external circuits 340 as seen in FIG. 5D outside of the eighth type of FPMCP 311, through, in sequence, any of the through silicon vias 157 of the auxiliary IC chip 411 of its subsystem unit 190, any of its bonded metal bumps or contacts 563-1, each of the interconnection metal layers 67 of its interposer 551 and any of the through silicon vias (TSVs) 558 of its interposer 551.

For the eighth type of FPMCP 311 as illustrated in FIG. 16, the auxiliary IC chip 411 of its subsystem unit 190 may include a first small input/output (I/O) circuit coupling to a second small input/output (I/O) circuit of the FPGA IC chip 200 of its subsystem unit 190 through its first signal path composed of (1) bonded two of the metal pads 6a of the auxiliary IC chip 411 and FPGA IC chip 200 of its subsystem unit 190 as illustrated in FIGS. 13A and 15A or (2) one of the bonded metal bumps or contacts 563 between the auxiliary IC chip 411 and FPGA IC chip 200 of its subsystem unit 190 as illustrated in FIGS. 13B and 15B, wherein each of the first and second small input/output (I/O) circuits may have an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts. The auxiliary IC chip 411 of its subsystem unit 190 may include a large input/output (I/O) circuit coupling to any of its metal bumps, pillars or pads 570 through its second signal path composed of any of the through silicon vias 157 of the auxiliary IC chip 411 of its subsystem unit 190, any of its bonded metal bumps or contacts 563-1, each of the interconnection metal layers 67 of its interposer 551 and any of the through silicon vias 558 of its interposer 551, wherein the large input/output (I/O) circuit may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or equal to or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Thereby, the first small input/output (I/O) circuit may receive first signals from the second small input/output (I/O) circuit via its first signal path to be converted by the auxiliary IC chip 411 of its subsystem unit 190 as second signals and then the large input/output (I/O) circuit may transmit the second signals to said any of its metal bumps, pillars or pads 570 via its second signal path. Further, the large input/output (I/O) circuit may receive third signals from said any of its metal bumps, pillars or pads 570 via its second signal path to be converted by the auxiliary IC chip 411 of its subsystem unit 190 as fourth signals and then the first small input/output (I/O) circuit may transmit the fourth signals to the second small input/output (I/O) circuit via its first signal path.

For the eighth type of FPMCP 311 as illustrated in FIG. 16, the FPGA IC chip 200 of its subsystem unit 190 may be programmed, configured or reconfigured following the same way as any aspect of the first through eleventh aspects illustrated in FIGS. 5A-1, 5A-2 and 5E-5G, including (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with first data stored in its NVM IC chip 250 to be configured in accordance with the first data, (2) the first or second type of field programmable switch cell 379 as illustrated in FIG. 2A or 2B having the memory cells 362 as illustrated in FIG. 2A or the four sets of memory cells 362 as illustrated in FIG. 2B for storing data associated with second data stored in its NVM IC chip 250 to be configured in accordance with the second data, and (3) the programmable switch matrix 710 as illustrated in FIG. 2C having the memory cells 398 for storing data, i.e., programming codes, password or encryption/decryption codes, associated with third data stored in its NVM IC chip 250 to be configured in accordance with the third data. Alternatively, the FPGA IC chip 200 of its subsystem unit 190 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MILU) IC chip, or digital-signal-processing (DSP) IC chip, each of which may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with the first data to be configured in accordance with the first data, (2) the first or second type of field programmable switch cell 379 as illustrated in FIG. 2A or 2B having the memory cells 362 as illustrated in FIG. 2A or the four sets of memory cells 362 as illustrated in FIG. 2B for storing data associated with the second data to be configured in accordance with the second data, and (3) the programmable switch matrix 710 as illustrated in FIG. 2C having the memory cells 398 for storing data, i.e., programming codes, password or encryption/decryption codes, associated with the third data to be configured in accordance with the third data. For the eighth type of FPMCP 311 for each aspect of the first through fourth aspects as illustrated in FIG. 5E, the FPGA IC chip 200 of its subsystem unit 190 may have the same circuits as one illustrated in FIG. 5E, the auxiliary IC chip 411 of its subsystem unit 190 may have the same circuits as one illustrated in FIG. 5E, its NVM IC chip 250 may have the same circuits as one illustrated in FIG. 5E, and its logic computing IC chip 269 may be any of the semiconductor IC chips 100g as illustrated in FIG. 5E. For its subsystem unit 190 formed by hybrid bonding as illustrated in FIGS. 13A and 15A, each bonded two of a first portion of the metal pads 6a of the FPGA IC chip 200 and auxiliary IC chip 411 of the subsystem unit 190 for the eighth type of FPMCP 311 as seen in FIG. 16 may be formed for one of the non-programmable interconnects 364 of the inter-chip interconnects 371 between the FPGA IC chip 200 and auxiliary IC chip 411 as illustrated in FIG. 5E, and alternatively, for its subsystem unit 190 formed by wafer bumping as illustrated in FIGS. 13B and 15B for any case of the first through fourth cases, each of a first portion of the bonded metal bumps or contacts 563 between the FPGA IC chip 200 and auxiliary IC chip 411 of the subsystem unit 190 for the eighth type of FPMCP 311 as seen in FIG. 16 may be formed for one of the non-programmable interconnects 364 of the inter-chip interconnects 371 between the FPGA IC chip 200 and auxiliary IC chip 411 as illustrated in FIG. 5E; any of a first portion of the bonded metal bumps or contacts 563-1, one or more of the interconnection metal layers 67 of the interposer 551 and any of a first portion of the bonded metal bumps or contacts 563-3 for the eighth type of FPMCP 311 as seen in FIG. 16 may be formed for one of the non-programmable interconnects 364 of the inter-chip interconnects 371 between the NVM IC chip 250 and auxiliary IC chip 411 as illustrated in FIG. 5E; for its subsystem unit 190 formed by hybrid bonding as illustrated in FIGS. 13A and 15A, any bonded two of a second portion of the metal pads 6a of the FPGA IC chip 200 and auxiliary IC chip 411 of the subsystem unit 190, any of the through silicon vias (TSVs) 157 of the auxiliary IC chip 411 of the subsystem unit 190, any of a second portion of the bonded metal bumps or contacts 563-1, one or more of the interconnection metal layers 67 of the interposer 551 and any of the bonded metal bumps or contacts 563-2 for the eighth type of FPMCP 311 as seen in FIG. 16 may be formed for one of the programmable interconnects 361 of the inter-chip interconnects 371 between the FPGA IC chip 200 and any of the semiconductor IC chips 100g as illustrated in FIG. 5E, and alternatively, for its subsystem unit 190 formed by wafer bumping as illustrated in FIGS. 13B and 15B for any case of the first through fourth cases, any of a second portion of the bonded metal bumps or contacts 563 between the FPGA IC chip 200 and auxiliary IC chip 411 of the subsystem unit 190, any of the through silicon vias (TSVs) 157 of the auxiliary IC chip 411 of the subsystem unit 190, any of a second portion of the bonded metal bumps or contacts 563-1, one or more of the interconnection metal layers 67 of the interposer 551 and any of the bonded metal bumps or contacts 563-2 for the eighth type of FPMCP 311 as seen in FIG. 16 may be formed for one of the programmable interconnects 361 of the inter-chip interconnects 371 between the FPGA IC chip 200 and any of the semiconductor IC chips 100g as illustrated in FIG. 5E; any of a second portion of the bonded metal bumps or contacts 563-3, each of the interconnection metal layers 67 of the interposer 551, any of a first portion of the through silicon vias 558 of the interposer 551 and any of a first portion of the metal bumps, pillars or pads 570 for the eighth type of FPMCP 311 as seen in FIG. 16 may be formed for the first group of the large input/output (I/O) circuits 342 of the NVM IC chip 250 receiving and transmitting the first and second (encrypted) CPM data from and to the external circuits 340 as illustrated in FIG. 5E outside of the eighth type of FPMCP 311; optionally for each aspect of the first through third aspects any of a third portion of the bonded metal bumps or contacts 563-1, each of the interconnection metal layers 67 of the interposer 551, any of a second portion of the through silicon vias 558 of the interposer 551 and any of a second portion of the metal bumps, pillars or pads 570 for the eighth type of FPMCP 311 as seen in FIG. 16 may be formed for the large input/output (I/O) circuits 341 of the large-input/output (I/O) block of the auxiliary IC chip 411 receiving and transmitting the first and second (encrypted) CPM data from and to the external circuits 340 as illustrated in FIG. 5E outside of the eighth type of FPMCP 311. For the eighth type of FPMCPs 311 for each aspect of the fifth through eighth aspects as illustrated in FIG. 5F, the FPGA IC chip 200 of its subsystem unit 190 may have the same circuits as one illustrated in FIG. 5F, the auxiliary IC chip 411 of its subsystem unit 190 may have the same circuits as one illustrated in FIG. 5F, its NVM IC chip 250 may have the same circuits as one illustrated in FIG. 5F, and its logic computing IC chip 269 may be any of the semiconductor IC chips 100g as illustrated in FIG. 5F. For its subsystem unit 190 formed by hybrid bonding as illustrated in FIGS. 13A and 15A, any bonded two of a first portion of the metal pads 6a of the FPGA IC chip 200 and auxiliary IC chip 411 of the subsystem unit 190, any of a first portion of the through silicon vias (TSVs) 157 of the auxiliary IC chip 411 of the subsystem unit 190, any of a first portion of the bonded metal bumps or contacts 563-1, one or more of the interconnection metal layers 67 of the interposer 551 and any of a first portion of the bonded metal bumps or contacts 563-3 for the eighth type of FPMCP 311 as seen in FIG. 16 may be formed for one of the non-programmable interconnects 364 of the inter-chip interconnects 371 between the NVM IC chip 250 and FPGA IC chip 200 as illustrated in FIG. 5F, and alternatively, for its subsystem unit 190 formed by wafer bumping as illustrated in FIGS. 13B and 15B for any case of the first through fourth cases, any of a first portion of the bonded metal bumps or contacts 563 between the FPGA IC chip 200 and auxiliary IC chip 411 of the subsystem unit 190, any of a first portion of the through silicon vias (TSVs) 157 of the auxiliary IC chip 411 of the subsystem unit 190, any of a first portion of the bonded metal bumps or contacts 563-1, one or more of the interconnection metal layers 67 of the interposer 551 and any of a first portion of the bonded metal bumps or contacts 563-3 for the eighth type of FPMCP 311 as seen in FIG. 16 may be formed for one of the non-programmable interconnects 364 of the inter-chip interconnects 371 between the NVM IC chip 250 and FPGA IC chip 200 as illustrated in FIG. 5F; any of a second portion of the bonded metal bumps or contacts 563-1, one or more of the interconnection metal layers 67 of the interposer 551 and any of a second portion of the bonded metal bumps or contacts 563-3 for the eighth type of FPMCP 311 as seen in FIG. 16 may be formed for one of the non-programmable interconnects 364 of the inter-chip interconnects 371 between the NVM IC chip 250 and auxiliary IC chip 411 as illustrated in FIG. 5F; for its subsystem unit 190 formed by hybrid bonding as illustrated in FIGS. 13A and 15A, any bonded two of a second portion of the metal pads 6a of the FPGA IC chip 200 and auxiliary IC chip 411 of the subsystem unit 190, any of a second portion of the through silicon vias (TSVs) 157 of the auxiliary IC chip 411 of the subsystem unit 190, any of a third portion of the bonded metal bumps or contacts 563-1, one or more of the interconnection metal layers 67 of the interposer 551 and any of the bonded metal bumps or contacts 563-2 for the eighth type of FPMCP 311 as seen in FIG. 16 may be formed for one of the programmable interconnects 361 of the inter-chip interconnects 371 between the FPGA IC chip 200 and any of the semiconductor IC chips 100g as illustrated in FIG. 5F, and alternatively, for its subsystem unit 190 formed by wafer bumping as illustrated in FIGS. 13B and 15B for any case of the first through fourth cases, any of a second portion of the bonded metal bumps or contacts 563 between the FPGA IC chip 200 and auxiliary IC chip 411 of the subsystem unit 190, any of a second portion of the through silicon vias (TSVs) 157 of the auxiliary IC chip 411 of the subsystem unit 190, any of a third portion of the bonded metal bumps or contacts 563-1, one or more of the interconnection metal layers 67 of the interposer 551 and any of the bonded metal bumps or contacts 563-2 for the eighth type of FPMCP 311 as seen in FIG. 16 may be formed for one of the programmable interconnects 361 of the inter-chip interconnects 371 between the FPGA IC chip 200 and any of the semiconductor IC chips 100g as illustrated in FIG. 5F; any of a fourth portion of the bonded metal bumps or contacts 563-1, each of the interconnection metal layers 67 of the interposer 551, any of the through silicon vias 558 of the interposer 551 and any of the metal bumps, pillars or pads 570 for the eighth type of FPMCP 311 as seen in FIG. 16 may be formed for the large input/output (I/O) circuits 341 of the large-input/output (I/O) block of the auxiliary IC chip 411 receiving and transmitting the first and second (encrypted) CPM data from and to the external circuits 340 as illustrated in FIG. 5F outside of the eighth type of FPMCP 311. For the eighth type of FPMCP 311 for each aspect of the ninth through eleventh aspects as illustrated in FIG. 5G, the FPGA IC chip 200 of its subsystem unit 190 may have the same circuits as one illustrated in FIG. 5G, its NVM IC chip 250 may have the same circuits as one illustrated in FIG. 5G, and its logic computing IC chip 269 may be any of the semiconductor IC chips 100g as illustrated in FIG. 5G. For its subsystem unit 190 formed by hybrid bonding as illustrated in FIGS. 13A and 15A, any bonded two of a first portion of the metal pads 6a of the FPGA IC chip 200 and auxiliary IC chip 411 of the subsystem unit 190, any of a first portion of the through silicon vias (TSVs) 157 of the auxiliary IC chip 411 of the subsystem unit 190, any of a first portion of the bonded metal bumps or contacts 563-1, one or more of the interconnection metal layers 67 of the interposer 551 and any of a first portion of the bonded metal bumps or contacts 563-3 for the eighth type of FPMCP 311 as seen in FIG. 16 may be formed for one of the non-programmable interconnects 364 of the inter-chip interconnects 371 between the FPGA IC chip 200 and NVM IC chip 250 as illustrated in FIG. 5G, and alternatively, for its subsystem unit 190 formed by wafer bumping as illustrated in FIGS. 13B and 15B for any case of the first through fourth cases, any of a first portion of the bonded metal bumps or contacts 563 between the FPGA IC chip 200 and auxiliary IC chip 411 of the subsystem unit 190, any of a first portion of the through silicon vias (TSVs) 157 of the auxiliary IC chip 411 of the subsystem unit 190, any of a first portion of the bonded metal bumps or contacts 563-1, one or more of the interconnection metal layers 67 of the interposer 551 and any of a first portion of the bonded metal bumps or contacts 563-3 for the eighth type of FPMCP 311 as seen in FIG. 16 may be formed for one of the non-programmable interconnects 364 of the inter-chip interconnects 371 between the FPGA IC chip 200 and NVM IC chip 250 as illustrated in FIG. 5G; for its subsystem unit 190 formed by hybrid bonding as illustrated in FIGS. 13A and 15A, any bonded two of a second portion of the metal pads 6a of the FPGA IC chip 200 and auxiliary IC chip 411 of the subsystem unit 190, any of a second portion of the through silicon vias (TSVs) 157 of the auxiliary IC chip 411 of the subsystem unit 190, any of a second portion of the bonded metal bumps or contacts 563-1, one or more of the interconnection metal layers 67 of the interposer 551 and any of the bonded metal bumps or contacts 563-2 for the eighth type of FPMCP 311 as seen in FIG. 16 may be formed for one of the programmable interconnects 361 of the inter-chip interconnects 371 between the FPGA IC chip 200 and any of the semiconductor IC chips 100g as illustrated in FIG. 5G, and alternatively, for its subsystem unit 190 formed by wafer bumping as illustrated in FIGS. 13B and 15B for any case of the first through fourth cases, any of a second portion of the bonded metal bumps or contacts 563 between the FPGA IC chip 200 and auxiliary IC chip 411 of the subsystem unit 190, any of a second portion of the through silicon vias (TSVs) 157 of the auxiliary IC chip 411 of the subsystem unit 190, any of a second portion of the bonded metal bumps or contacts 563-1, one or more of the interconnection metal layers 67 of the interposer 551 and any of the bonded metal bumps or contacts 563-2 for the eighth type of FPMCP 311 as seen in FIG. 16 may be formed for one of the programmable interconnects 361 of the inter-chip interconnects 371 between the FPGA IC chip 200 and any of the semiconductor IC chips 100g as illustrated in FIG. 5G; any of a second portion of the bonded metal bumps or contacts 563-3, each of the interconnection metal layers 67 of the interposer 551, any of the through silicon vias 558 of the interposer 551 and any of the metal bumps, pillars or pads 570 for the eighth type of FPMCP 311 as seen in FIG. 16 may be formed for the large input/output (I/O) circuits 342 of the NVM IC chip 250 receiving and transmitting the first and second (encrypted) CPM data from and to the external circuits 340 as illustrated in FIG. 5G outside of the eighth type of FPMCP 311.

### Ninth Type of FPMCP

FIG. 17 is a schematically cross-sectional view showing a ninth type of FPMCP in accordance with an embodiment of the present application. A ninth type of FPMCP 312 as seen in FIG. 17 may include a subsystem unit 191 having a similar structure to either of the seventh type of FPMCPs 310 as illustrated in FIGS. 15A and 15B. The difference therebetween is that the logic computing IC chip 269 and NVM IC chip 250 of either of the seventh type of FPMCPs 310 as illustrated in FIGS. 15A and 15B may be saved for the subsystem unit 191 of the ninth type of FPMCP 312 as seen in FIG. 17. For the ninth type of FPMCP 312, the FPGA IC chip 200 of its subsystem unit 191 may be the dedicated field programmable integrated-circuit (DFPIC) chip as illustrated in FIG. 4D or embedded field programmable integrated-circuit (eFPIC) chip as illustrated in FIG. 4E. Further, for the ninth type of FPMCP 312 as seen in FIG. 17, each of the metal bumps, pillars or pads 570 of its subsystem unit 191 may be of the first type as illustrated in FIGS. 6A, 15A and 15B, and its subsystem unit 191 may include a polymer layer 257, i.e., insulating dielectric layer, on the bottom surface of the insulating dielectric layer 185 of the auxiliary IC chip 411 of its subsystem unit 191 in the first or second aspect or on the bottom surface of the insulating dielectric layer 587 of the auxiliary IC chip 411 of its subsystem unit 191 in the third aspect, wherein the polymer layer 257 of its subsystem unit 191 may be horizontally around each of the first type of metal bumps, pillars or pads 570 of its subsystem unit 191 and may have a bottom surface substantially coplanar with a bottom surface of each of the first type of metal bumps, pillars or pads 570, i.e., a bottom surface of the copper layer 32 thereof, of its subsystem unit 191, wherein the polymer layer 257 of its subsystem unit 191 is not extending under the bottom surface of each of the first type of metal bumps, pillars or pads 570 of its subsystem unit 191. The ninth type of FPMCP 312 may further include (1) a NVM IC chip 250, having the specification as illustrated for one in FIG. 5A-1, at the same horizontal level as its subsystem unit 191, (2) a logic computing IC chip 269, such as the graphic-processing-unit (GPU) IC chip 269a, central-processing-unit (CPU) IC chip 269b or application-specific integrated-circuit (ASIC) chip or system-on-chip (SoC) chip 269c as illustrated in FIG. 5A-1 or such as data processing unit (DPU) IC chip, tensor flow processing unit (TPU) IC chip or digital-signal-processing (DSP) chip, at the same horizontal level as its subsystem unit 191 and NVM IC chip 250, (3) a polymer layer 192 or insulating dielectric layer, i.e., sealing layer, such as silicon-oxide-containing molding compound, epoxy-based material or polyimide, horizontally around each of its subsystem unit 191, NVM IC chip 250 and logic computing IC chip 269, wherein its polymer layer 192 may have a top surface coplanar with a top surface of the FPGA IC chip 200 of its subsystem unit 190, a top surface of the polymer layer 92 of its subsystem unit 190 and a top surface of each of its logic computing IC chip 269 and NVM IC chip 250, (4) an interconnection scheme 79 under its subsystem unit 191, NVM IC chip 250, logic computing IC chip 269 and polymer layer 192 and (5) multiple metal bumps, pillars or pads 571 in an array at its bottom to act as its external pins for coupling to external circuits outside of the ninth type of FPMCP 312, wherein each of its metal bumps, pillars or pads 571 may be formed on a bottom surface of its interconnection scheme 79. Each of its NVM IC chip 250 and logic computing IC chip 269 may have the same specification as the third type of semiconductor IC chip 100 illustrated in FIG. 3C to be turned upside down. Each of the first type of micro-bumps, micro-pillars or micro-pads 34 of each of its NVM IC chip 250 and logic computing IC chip 269 and each of the first type of metal bumps, pillars or pads 570 of its subsystem unit 191 may couple to its interconnection scheme 79, and its polymer layer 192 may have a bottom surface substantially coplanar with a bottom surface of each of the first type of micro-bumps, micro-pillars or micro-pads 34 of each of its NVM IC chip 250 and logic computing IC chip 269, a bottom surface of the polymer layer 257 of each of its NVM IC chip 250 and logic computing IC chip 269, a bottom surface of each of the first type of metal bumps, pillars or pads 570 of its subsystem unit 191 and a bottom surface of the polymer layer 257 of its subsystem unit 191.

Referring to FIG. 17, for the ninth type of FPMCP 312, its interconnection scheme 79 may be provided with (1) one or more interconnection metal layers 27 coupling to each of the first type of micro-bumps, micro-pillars or micro-pads 34 of each of its NVM IC chip 250 and logic computing IC chip 269 and each of the first type of metal bumps, pillars or pads 570 of its subsystem unit 191 and (2) multiple polymer layers 42 each between neighboring two of the interconnection metal layers 27 of its interconnection scheme 79, under the bottommost one of the interconnection metal layers 27 of its interconnection scheme 79 or over the topmost one of the interconnection metal layers 27 of its interconnection scheme 79, wherein an upper one of the interconnection metal layers 27 of its interconnection scheme 79 may couple to a lower one of the interconnection metal layers 27 of its interconnection scheme 79 through an opening in one of the polymer layers 42 of its interconnection scheme 79 between the upper and lower ones of the interconnection metal layers 27 of its interconnection scheme 79. The topmost one of the polymer layers 42 of the interconnection scheme 79 of its interconnection substrate 177 may have a top surface in contact with the bottom surface of its polymer layer 192, the bottom surface of the polymer layer 257 of each of its NVM IC chip 250 and logic computing IC chip 269 and the bottom surface of the polymer layer 257 of its subsystem unit 191. Each opening in the topmost one of the polymer layers 42 of its interconnection scheme 79 may be under one of the first type of micro-bumps, micro-pillars or micro-pads 34 of one of its NVM IC chip 250 and logic computing IC chip 269 or one of the first type of metal bumps, pillars or pads 570 of its subsystem unit 191 and thus the topmost one of the interconnection metal layers 27 of its interconnection scheme 79 may extend through said each opening to couple to said one of the first type of micro-bumps, micro-pillars or micro-pads 34 of one of its NVM IC chip 250 and logic computing IC chip 269 or said one of the first type of metal bumps, pillars or pads 570 of its subsystem unit 191. Each of the interconnection metal layers 27 of its interconnection scheme 79 may extend horizontally across under an edge of each of its subsystem unit 191, NVM IC chip 250 and logic computing IC chip 269. The bottommost one of the interconnection metal layers 27 of its interconnection scheme 79 may have multiple metal pads at tops of multiple respective openings in the bottommost one of the polymer layers 42 of its interconnection scheme 79. The specification and process for the interconnection metal layers 27 and polymer layers 42 of its interconnection scheme 79 may be referred to those for the second interconnection scheme for a chip (SISC) 29 as illustrated in FIG. 3A to be turned upside down. Its polymer layer 192 may have a vertical sidewall coplanar with a vertical sidewall of its interconnection scheme 79.

Referring to FIG. 17, for the ninth type of FPMCP 312, each of its metal bumps, pillars or pads 571 may be of a type selected from various types, i.e., first and second types, having the same specification as that of the first and second types of metal bumps, pillars or pads 570 respectively as illustrated in FIG. 6A, and may have the adhesion metal layer 26a on a bottom surface of one of the metal pads of the bottommost one of the interconnection metal layers 27 of its interconnection scheme 79 and a bottom surface of the bottommost one of the polymer layers 42 of its interconnection scheme 79. Each of its subsystem unit 191, NVM IC chip 250 and logic computing IC chip 269 may couple to one of its metal bumps, pillars or pads 571 for external connection through each of the interconnection metal layers 27 of its interconnection scheme 79.

Referring to FIG. 17, the ninth type of FPMCP 312 may have the inter-chip interconnection between the first and second semiconductor IC chips 100a and 100b via the FPGA IC chip 200 as illustrated in FIG. 5B. For the ninth type of FPMCP 312, the FPGA IC chip 200 of its subsystem unit 191 may have the same circuits as one illustrated in FIG. 5B. For a first scenario, one of its logic computing IC chip 269 and NVM IC chip 250 may be the first semiconductor IC chip 100a as illustrated in FIG. 5B, and the auxiliary IC chip 411 of its subsystem unit 190 may be the second semiconductor IC chip 100b as illustrated in FIG. 5B. In the first scenario, for its subsystem unit 191 formed by hybrid bonding as illustrated in FIGS. 13A and 15A, any bonded two of a first portion of the metal pads 6a of the FPGA IC chip 200 and second semiconductor IC chip 100b of its subsystem unit 191, any of the through silicon vias (TSVs) 157 of the second semiconductor IC chip 100b of its subsystem unit 191, any of the first type of metal bumps, pillars or pads 570 of its subsystem unit 191, one or more of the interconnection metal layers 27 of its interconnection scheme 79 and any of the first type of micro-bumps, micro-pillars or micro-pads 34 of its first semiconductor IC chip 100a may be formed for one of the programmable interconnects 361 of the inter-chip interconnects 371 between the FPGA IC chip 200 and first semiconductor IC chip 100a as illustrated in FIG. 5B, and each bonded two of a second portion of the metal pads 6a of the FPGA IC chip 200 and second semiconductor IC chip 100b of its subsystem unit 190 may be formed for one of the programmable interconnects 361 of the inter-chip interconnects 371 between the FPGA IC chip 200 and second semiconductor IC chip 100b as illustrated in FIG. 5B. Alternatively, for its subsystem unit 190 formed by wafer bumping as illustrated in FIGS. 13B and 15B for any case of the first through fourth cases, any of a first portion of the bonded metal bumps or contacts 563 between the FPGA IC chip 200 and second semiconductor IC chip 100b of its subsystem unit 190, any of the through silicon vias (TSVs) 157 of the second semiconductor IC chip 100b of its subsystem unit 190, any of the first type of metal bumps, pillars or pads 570 of its subsystem unit 191, one or more of the interconnection metal layers 27 of its interconnection scheme 79 and any of the first type of micro-bumps, micro-pillars or micro-pads 34 of its first semiconductor IC chip 100a may be formed for one of the programmable interconnects 361 of the inter-chip interconnects 371 between the FPGA IC chip 200 and first semiconductor IC chip 100a as illustrated in FIG. 5B, and each of a second portion of the bonded metal bumps or contacts 563 between the FPGA IC chip 200 and second semiconductor IC chip 100b of its subsystem unit 190 may be formed for one of the programmable interconnects 361 of the inter-chip interconnects 371 between the FPGA IC chip 200 and second semiconductor IC chip 100b as illustrated in FIG. 5B. For a second scenario, its logic computing IC chip 269 may be the first semiconductor IC chip 100a as illustrated in FIG. 5B, and its NVM IC chip 250 may be the second semiconductor IC chip 100b as illustrated in FIG. 5B. In the second scenario, for its subsystem unit 190 formed by hybrid bonding as illustrated in FIGS. 13A and 15A, any bonded two of a first portion of the metal pads 6a of the FPGA IC chip 200 and auxiliary IC chip 411 of its subsystem unit 190, any of a first portion of the through silicon vias (TSVs) 157 of the auxiliary IC chip 411 of its subsystem unit 190, any of a first portion of the first type of metal bumps, pillars or pads 570 of its subsystem unit 191, one or more of the interconnection metal layers 27 of its interconnection scheme 79 and any of the first type of micro-bumps, micro-pillars or micro-pads 34 of its first semiconductor IC chip 100a may be formed for one of the programmable interconnects 361 of the inter-chip interconnects 371 between the FPGA IC chip 200 and first semiconductor IC chip 100a as illustrated in FIG. 5B, and any bonded two of a second portion of the metal pads 6a of the FPGA IC chip 200 and auxiliary IC chip 411 of its subsystem unit 190, any of a second portion of the through silicon vias (TSVs) 157 of the auxiliary IC chip 411 of its subsystem unit 190, any of a second portion of the first type of metal bumps, pillars or pads 570 of its subsystem unit 191, one or more of the interconnection metal layers 27 of its interconnection scheme 79 and any of the first type of micro-bumps, micro-pillars or micro-pads 34 of its second semiconductor IC chip 100b may be formed for one of the programmable interconnects 361 of the inter-chip interconnects 371 between the FPGA IC chip 200 and second semiconductor IC chip 100b as illustrated in FIG. 5B. Alternatively, for its subsystem unit 190 formed by wafer bumping as illustrated in FIGS. 13B and 15B for any case of the first through fourth cases, any of a first portion of the bonded metal bumps or contacts 563 between the FPGA IC chip 200 and auxiliary IC chip 411 of its subsystem unit 190, any of a first portion of the through silicon vias (TSVs) 157 of the auxiliary IC chip 411 of its subsystem unit 190, any of a first portion of the first type of metal bumps, pillars or pads 570 of its subsystem unit 191, one or more of the interconnection metal layers 27 of its interconnection scheme 79 and any of the first type of micro-bumps, micro-pillars or micro-pads 34 of its first semiconductor IC chip 100a may be formed for one of the programmable interconnects 361 of the inter-chip interconnects 371 between the FPGA IC chip 200 and first semiconductor IC chip 100a as illustrated in FIG. 5B, and any of a second portion of the bonded metal bumps or contacts 563 between the FPGA IC chip 200 and auxiliary IC chip 411 of its subsystem unit 190, any of a second portion of the through silicon vias (TSVs) 157 of the auxiliary IC chip 411 of its subsystem unit 190, any of a second portion of the first type of metal bumps, pillars or pads 570 of its subsystem unit 191, one or more of the interconnection metal layers 27 of its interconnection scheme 79 and any of the first type of micro-bumps, micro-pillars or micro-pads 34 of its second semiconductor IC chip 100b may be formed for one of the programmable interconnects 361 of the inter-chip interconnects 371 between the FPGA IC chip 200 and second semiconductor IC chip 100b as illustrated in FIG. 5B.

Referring to FIG. 17, the ninth type of FPMCP 312 may perform the operation between the FPGA IC chip 200 and each of the third and fourth semiconductor IC chips 100c and 100d as illustrated in FIG. 5C. For the ninth type of FPMCP 312, the FPGA IC chip 200 of its subsystem unit 190 may have the same circuits as one illustrated in FIG. 5C. For a first scenario, its logic computing IC chip 269 may be the third semiconductor IC chip 100c as illustrated in FIG. 5C, and the auxiliary IC chip 411 of its subsystem unit 190 may be the fourth semiconductor IC chip 100d as illustrated in FIG. 5C. In the first scenario, for its subsystem unit 190 formed by hybrid bonding as illustrated in FIGS. 13A and 15A, any bonded two of a first portion of the metal pads 6a of the FPGA IC chip 200 and fourth semiconductor IC chip 100d of its subsystem unit 190, any of the through silicon vias (TSVs) 157 of the fourth semiconductor IC chip 100d of its subsystem unit 190, any of the first type of metal bumps, pillars or pads 570 of its subsystem unit 191, one or more of the interconnection metal layers 27 of its interconnection scheme 79 and any of the first type of micro-bumps, micro-pillars or micro-pads 34 of its third semiconductor IC chip 100c may be formed for one of the programmable interconnects 361 of the inter-chip interconnects 371 between the FPGA IC chip 200 and third semiconductor IC chip 100c as illustrated in FIG. 5C, and each bonded two of a second portion of the metal pads 6a of the FPGA IC chip 200 and fourth semiconductor IC chip 100d of its subsystem unit 190 may be formed for one of the programmable interconnects 361 of the inter-chip interconnects 371 between the FPGA IC chip 200 and fourth semiconductor IC chip 100d as illustrated in FIG. 5C. Alternatively, for its subsystem unit 190 formed by wafer bumping as illustrated in FIGS. 13B and 15B for any case of the first through fourth cases, any of a first portion of the bonded metal bumps or contacts 563 between the FPGA IC chip 200 and fourth semiconductor IC chip 100d of its subsystem unit 190, any of the through silicon vias (TSVs) 157 of the fourth semiconductor IC chip 100d of its subsystem unit 190, any of the first type of metal bumps, pillars or pads 570 of its subsystem unit 191, one or more of the interconnection metal layers 27 of its interconnection scheme 79 and any of the first type of micro-bumps, micro-pillars or micro-pads 34 of its third semiconductor IC chip 100c may be formed for one of the programmable interconnects 361 of the inter-chip interconnects 371 between the FPGA IC chip 200 and third semiconductor IC chip 100c as illustrated in FIG. 5C, and each of a second portion of the bonded metal bumps or contacts 563 between the FPGA IC chip 200 and fourth semiconductor IC chip 100d of its subsystem unit 190 may be formed for one of the programmable interconnects 361 of the inter-chip interconnects 371 between the FPGA IC chip 200 and fourth semiconductor IC chip 100d as illustrated in FIG. 5C. For a second scenario, its logic computing IC chip 269 may be the third semiconductor IC chip 100c as illustrated in FIG. 5C, and its NVM IC chip 250 may be the fourth semiconductor IC chip 100d as illustrated in FIG. 5C. In the second scenario, for its subsystem unit 190 formed by hybrid bonding as illustrated in FIGS. 13A and 15A, any bonded two of a first portion of the metal pads 6a of the FPGA IC chip 200 and auxiliary IC chip 411 of its subsystem unit 190, any of a first portion of the through silicon vias (TSVs) 157 of the auxiliary IC chip 411 of its subsystem unit 190, any of a first portion of the first type of metal bumps, pillars or pads 570 of its subsystem unit 191, one or more of the interconnection metal layers 27 of its interconnection scheme 79 and any of the first type of micro-bumps, micro-pillars or micro-pads 34 of its third semiconductor IC chip 100c may be formed for one of the programmable interconnects 361 of the inter-chip interconnects 371 between the FPGA IC chip 200 and third semiconductor IC chip 100c as illustrated in FIG. 5C, and any bonded two of a second portion of the metal pads 6a of the FPGA IC chip 200 and auxiliary IC chip 411 of its subsystem unit 190, any of a second portion of the through silicon vias (TSVs) 157 of the auxiliary IC chip 411 of its subsystem unit 190, any of a second portion of the first type of metal bumps, pillars or pads 570 of its subsystem unit 191, one or more of the interconnection metal layers 27 of its interconnection scheme 79 and any of the first type of micro-bumps, micro-pillars or micro-pads 34 of its fourth semiconductor IC chip 100d may be formed for one of the programmable interconnects 361 of the inter-chip interconnects 371 between the FPGA IC chip 200 and fourth semiconductor IC chip 100d as illustrated in FIG. 5C. Alternatively, for its subsystem unit 190 formed by wafer bumping as illustrated in FIGS. 13B and 15B for any case of the first through fourth cases, any of a first portion of the bonded metal bumps or contacts 563 between the FPGA IC chip 200 and auxiliary IC chip 411 of its subsystem unit 190, any of a first portion of the through silicon vias (TSVs) 157 of the auxiliary IC chip 411 of its subsystem unit 190, any of a first portion of the first type of metal bumps, pillars or pads 570 of its subsystem unit 191, one or more of the interconnection metal layers 27 of its interconnection scheme 79 and any of the first type of micro-bumps, micro-pillars or micro-pads 34 of its third semiconductor IC chip 100c may be formed for one of the programmable interconnects 361 of the inter-chip interconnects 371 between the FPGA IC chip 200 and third semiconductor IC chip 100c as illustrated in FIG. 5C, and any of a second portion of the bonded metal bumps or contacts 563 between the FPGA IC chip 200 and auxiliary IC chip 411 of its subsystem unit 190, any of a second portion of the through silicon vias (TSVs) 157 of the auxiliary IC chip 411 of its subsystem unit 190, any of a second portion of the first type of metal bumps, pillars or pads 570 of its subsystem unit 191, one or more of the interconnection metal layers 27 of its interconnection scheme 79 and any of the first type of micro-bumps, micro-pillars or micro-pads 34 of its fourth semiconductor IC chip 100d may be formed for one of the programmable interconnects 361 of the inter-chip interconnects 371 between the FPGA IC chip 200 and fourth semiconductor IC chip 100d as illustrated in FIG. 5C.

Referring to FIG. 17, the ninth type of FPMCP 312 may have the connection to external circuits as illustrated in FIG. 5D. For the ninth type of FPMCP 312, the FPGA IC chip 200 of its subsystem unit 190 may have the same circuits as one illustrated in FIG. 5D, the auxiliary IC chip 411 of its subsystem unit 190 may have the same circuits as one illustrated in FIG. 5D, its logic computing IC chip 269 may be the fifth semiconductor IC chip 100e as illustrated in FIG. 5D, and its NVM IC chip 250 may be the sixth semiconductor IC chip 100f as illustrated in FIG. 5D. For its subsystem unit 190 formed by hybrid bonding as illustrated in FIGS. 13A and 15A, any bonded two of a first portion of the metal pads 6a of the FPGA IC chip 200 and auxiliary IC chip 411 of its subsystem unit 190, any of a first portion of the through silicon vias (TSVs) 157 of the auxiliary IC chip 411 of its subsystem unit 190, any of a first portion of the first type of metal bumps, pillars or pads 570 of its subsystem unit 191, one or more of the interconnection metal layers 27 of its interconnection scheme 79 and any of the first type of micro-bumps, micro-pillars or micro-pads 34 of its fifth semiconductor IC chip 100e may be formed for one of the programmable interconnects 361 of the inter-chip interconnects 371 between the FPGA IC chip 200 and fifth semiconductor IC chip 100e as illustrated in FIG. 5D, any bonded two of a second portion of the metal pads 6a of the FPGA IC chip 200 and auxiliary IC chip 411 of its subsystem unit 190, any of a second portion of the through silicon vias (TSVs) 157 of the auxiliary IC chip 411 of its subsystem unit 190, any of a second portion of the first type of metal bumps, pillars or pads 570 of its subsystem unit 191, one or more of the interconnection metal layers 27 of its interconnection scheme 79 and any of the first type of micro-bumps, micro-pillars or micro-pads 34 of its sixth semiconductor IC chip 100f may be formed for one of the programmable interconnects 361 of the inter-chip interconnects 371 between the FPGA IC chip 200 and sixth semiconductor IC chip 100f as illustrated in FIG. 5D, and each bonded two of a third portion of the metal pads 6a of the FPGA IC chip 200 and auxiliary IC chip 411 of its subsystem unit 190 may be formed for one of the programmable interconnects 361 of the inter-chip interconnects 371 between the FPGA IC chip 200 and auxiliary IC chip 411 as illustrated in FIG. 5D. Alternatively, for its subsystem unit 190 formed by wafer bumping as illustrated in FIGS. 13B and 15B for any case of the first through fourth cases, any of a first portion of the bonded metal bumps or contacts 563 between the FPGA IC chip 200 and auxiliary IC chip 411 of its subsystem unit 190, any of a first portion of the through silicon vias (TSVs) 157 of the auxiliary IC chip 411 of its subsystem unit 190, any of a first portion of the first type of metal bumps, pillars or pads 570 of its subsystem unit 191, one or more of the interconnection metal layers 27 of its interconnection scheme 79 and any of the first type of micro-bumps, micro-pillars or micro-pads 34 of its fifth semiconductor IC chip 100e may be formed for one of the programmable interconnects 361 of the inter-chip interconnects 371 between the FPGA IC chip 200 and fifth semiconductor IC chip 100e as illustrated in FIG. 5D, any of a second portion of the bonded metal bumps or contacts 563 between the FPGA IC chip 200 and auxiliary IC chip 411 of its subsystem unit 190, any of a second portion of the through silicon vias (TSVs) 157 of the auxiliary IC chip 411 of its subsystem unit 190, any of a second portion of the first type of metal bumps, pillars or pads 570 of its subsystem unit 191, one or more of the interconnection metal layers 27 of its interconnection scheme 79 and any of the first type of micro-bumps, micro-pillars or micro-pads 34 of its sixth semiconductor IC chip 100f may be formed for one of the programmable interconnects 361 of the inter-chip interconnects 371 between the FPGA IC chip 200 and sixth semiconductor IC chip 100f as illustrated in FIG. 5D, and each of a third portion of the bonded metal bumps or contacts 563 between the FPGA IC chip 200 and auxiliary IC chip 411 of its subsystem unit 190 may be formed for one of the programmable interconnects 361 of the inter-chip interconnects 371 between the FPGA IC chip 200 and auxiliary IC chip 411 as illustrated in FIG. 5D. For the ninth type of FPMCP 312, each of the large input/output (I/O) circuits 341 of the large-input/output (I/O) block of the auxiliary IC chip 411 of its subsystem unit 191 may couple to one of its metal bumps, pillars or pads 571, which are in an array at its bottom to act as its external pins for coupling to the external circuits 340 as seen in FIG. 5D outside of the ninth type of FPMCP 312, through, in sequence, any of the through silicon vias 157 of the auxiliary IC chip 411 of its subsystem unit 191, any of the first type of metal bumps, pillars or pads 570 of its subsystem unit 191 and each of the interconnection metal layers 27 of its interconnection scheme 79.

For the ninth type of FPMCP 312 as illustrated in FIG. 17, the auxiliary IC chip 411 of its subsystem unit 191 may include a first small input/output (I/O) circuit coupling to a second small input/output (I/O) circuit of the FPGA IC chip 200 of its subsystem unit 191 through its first signal path composed of (1) bonded two of the metal pads 6a of the auxiliary IC chip 411 and FPGA IC chip 200 of its subsystem unit 190 as illustrated in FIGS. 13A and 15A or (2) one of the bonded metal bumps or contacts 563 of its subsystem unit 190 between the auxiliary IC chip 411 and FPGA IC chip 200 of its subsystem unit 190 as illustrated in FIGS. 13B and 15B, wherein each of the first and second small input/output (I/O) circuits may have an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts. The auxiliary IC chip 411 of its subsystem unit 191 may include a large input/output (I/O) circuit coupling to any of its metal bumps, pillars or pads 571 through its second signal path composed of any of the through silicon vias 157 of the auxiliary IC chip 411 of its subsystem unit 191, any of the first type of metal bumps, pillars or pads 570 of its subsystem unit 191 and each of the interconnection metal layers 27 of its interconnection scheme 79, wherein the large input/output (I/O) circuit may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or equal to or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Thereby, the first small input/output (I/O) circuit may receive first signals from the second small input/output (I/O) circuit via its first signal path to be converted by the auxiliary IC chip 411 of its subsystem unit 191 as second signals and then the large input/output (I/O) circuit may transmit the second signals to said any of its metal bumps, pillars or pads 571 via its second signal path. Further, the large input/output (I/O) circuit may receive third signals from said any of its metal bumps, pillars or pads 571 via its second signal path to be converted by the auxiliary IC chip 411 of its subsystem unit 191 as fourth signals and then the first small input/output (I/O) circuit may transmit the fourth signals to the second small input/output (I/O) circuit via its first signal path.

For the ninth type of FPMCP 312 as illustrated in FIG. 17, the FPGA IC chip 200 of its subsystem unit 191 may be programmed, configured or reconfigured following the same way as any aspect of the first through eleventh aspects illustrated in FIGS. 5A-1, 5A-2 and 5E-5G, including (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with first data stored in its NVM IC chip 250 to be configured in accordance with the first data, (2) the first or second type of field programmable switch cell 379 as illustrated in FIG. 2A or 2B having the memory cells 362 as illustrated in FIG. 2A or the four sets of memory cells 362 as illustrated in FIG. 2B for storing data associated with second data stored in its NVM IC chip 250 to be configured in accordance with the second data, and (3) the programmable switch matrix 710 as illustrated in FIG. 2C having the memory cells 398 for storing data, i.e., programming codes, password or encryption/decryption codes, associated with third data stored in its NVM IC chip 250 to be configured in accordance with the third data. Alternatively, the FPGA IC chip 200 of its subsystem unit 191 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MILU) IC chip, or digital-signal-processing (DSP) IC chip, each of which may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with the first data to be configured in accordance with the first data, (2) the first or second type of field programmable switch cell 379 as illustrated in FIG. 2A or 2B having the memory cells 362 as illustrated in FIG. 2A or the four sets of memory cells 362 as illustrated in FIG. 2B for storing data associated with the second data to be configured in accordance with the second data, and (3) the programmable switch matrix 710 as illustrated in FIG. 2C having the memory cells 398 for storing data, i.e., programming codes, password or encryption/decryption codes, associated with the third data to be configured in accordance with the third data. For the ninth type of FPMCP 312 for each aspect of the first through fourth aspects as illustrated in FIG. 5E, the FPGA IC chip 200 of its subsystem unit 191 may have the same circuits as one illustrated in FIG. 5E, the auxiliary IC chip 411 of its subsystem unit 191 may have the same circuits as one illustrated in FIG. 5E, its NVM IC chip 250 may have the same circuits as one illustrated in FIG. 5E, and its logic computing IC chip 269 may be any of the semiconductor IC chips 100g as illustrated in FIG. 5E. For its subsystem unit 191 formed by hybrid bonding as illustrated in FIGS. 13A and 15A, each bonded two of a first portion of the metal pads 6a of the FPGA IC chip 200 and auxiliary IC chip 411 of the subsystem unit 191 for the ninth type of FPMCP 312 as seen in FIG. 17 may be formed for one of the non-programmable interconnects 364 of the inter-chip interconnects 371 between the FPGA IC chip 200 and auxiliary IC chip 411 as illustrated in FIG. 5E, and alternatively, for its subsystem unit 191 formed by wafer bumping as illustrated in FIGS. 13B and 15B for any case of the first through fourth cases, each of a first portion of the bonded metal bumps or contacts 563 between the FPGA IC chip 200 and auxiliary IC chip 411 of the subsystem unit 191 for the ninth type of FPMCP 312 as seen in FIG. 17 may be formed for one of the non-programmable interconnects 364 of the inter-chip interconnects 371 between the FPGA IC chip 200 and auxiliary IC chip 411 as illustrated in FIG. 5E; any of a first portion of the first type of metal bumps, pillars or pads 570 of the subsystem unit 191, one or more of the interconnection metal layers 27 of the interconnection scheme 79 and any of a first portion of the first type of micro-bumps, micro-pillars or micro-pads 34 of the NVM IC chip 250 for the ninth type of FPMCP 312 as seen in FIG. 17 may be formed for one of the non-programmable interconnects 364 of the inter-chip interconnects 371 between the NVM IC chip 250 and auxiliary IC chip 411 as illustrated in FIG. 5E; for its subsystem unit 191 formed by hybrid bonding as illustrated in FIGS. 13A and 15A, any bonded two of a second portion of the metal pads 6a of the FPGA IC chip 200 and auxiliary IC chip 411 of the subsystem unit 191, any of the through silicon vias (TSVs) 157 of the auxiliary IC chip 411 of the subsystem unit 191, any of a second portion of the first type of metal bumps, pillars or pads 570 of the subsystem unit 191, one or more of the interconnection metal layers 27 of the interconnection scheme 79 and any of the first type of micro-bumps, micro-pillars or micro-pads 34 of the logic computing IC chip 269 for the ninth type of FPMCP 312 as seen in FIG. 17 may be formed for one of the programmable interconnects 361 of the inter-chip interconnects 371 between the FPGA IC chip 200 and any of the semiconductor IC chips 100g as illustrated in FIG. 5E, and alternatively, for its subsystem unit 191 formed by wafer bumping as illustrated in FIGS. 13B and 15B for any case of the first through fourth cases, any of a second portion of the bonded metal bumps or contacts 563 between the FPGA IC chip 200 and auxiliary IC chip 411 of the subsystem unit 191, any of the through silicon vias (TSVs) 157 of the auxiliary IC chip 411 of the subsystem unit 191, any of a second portion of the first type of metal bumps, pillars or pads 570 of the subsystem unit 191, one or more of the interconnection metal layers 27 of the interconnection scheme 79 and any of the first type of micro-bumps, micro-pillars or micro-pads 34 of the logic computing IC chip 269 for the ninth type of FPMCP 312 as seen in FIG. 17 may be formed for one of the programmable interconnects 361 of the inter-chip interconnects 371 between the FPGA IC chip 200 and any of the semiconductor IC chips 100g as illustrated in FIG. 5E; any of a second portion of the first type of micro-bumps, micro-pillars or micro-pads 34 of the NVM IC chip 250, each of the interconnection metal layers 27 of the interconnection scheme 79 and any of a first portion of the metal bumps, pillars or pads 571 for the ninth type of FPMCP 312 as seen in FIG. 17 may be formed for the first group of the large input/output (I/O) circuits 342 of the NVM IC chip 250 receiving and transmitting the first and second (encrypted) CPM data from and to the external circuits 340 as illustrated in FIG. 5E outside of the ninth type of FPMCP 312; optionally for each aspect of the first through third aspects any of a third portion of the first type of metal bumps, pillars or pads 570 of the subsystem unit 191, each of the interconnection metal layers 27 of the interconnection scheme 79 and any of a second portion of the metal bumps, pillars or pads 571 for the ninth type of FPMCP 312 as seen in FIG. 17 may be formed for the large input/output (I/O) circuits 341 of the large-input/output (I/O) block of the auxiliary IC chip 411 receiving and transmitting the first and second (encrypted) CPM data from and to the external circuits 340 as illustrated in FIG. 5E outside of the ninth type of FPMCP 312. For the ninth type of FPMCP 312 for each aspect of the fifth through eighth aspects as illustrated in FIG. 5F, the FPGA IC chip 200 of its subsystem unit 191 may have the same circuits as one illustrated in FIG. 5F, the auxiliary IC chip 411 of its subsystem unit 191 may have the same circuits as one illustrated in FIG. 5F, its NVM IC chip 250 may have the same circuits as one illustrated in FIG. 5F, and its logic computing IC chip 269 may be any of the semiconductor IC chips 100g as illustrated in FIG. 5F. For its subsystem unit 191 formed by hybrid bonding as illustrated in FIGS. 13A and 15A, any bonded two of a first portion of the metal pads 6a of the FPGA IC chip 200 and auxiliary IC chip 411 of the subsystem unit 191, any of a first portion of the through silicon vias (TSVs) 157 of the auxiliary IC chip 411 of the subsystem unit 191, any of a first portion of the first type of metal bumps, pillars or pads 570 of the subsystem unit 191, one or more of the interconnection metal layers 27 of the interconnection scheme 79 and any of a first portion of the first type of micro-bumps, micro-pillars or micro-pads 34 of the NVM IC chip 250 for the ninth type of FPMCP 312 as seen in FIG. 17 may be formed for one of the non-programmable interconnects 364 of the inter-chip interconnects 371 between the NVM IC chip 250 and FPGA IC chip 200 as illustrated in FIG. 5F, and alternatively, for its subsystem unit 191 formed by wafer bumping as illustrated in FIGS. 13B and 15B for any case of the first through fourth cases, any of a first portion of the bonded metal bumps or contacts 563 between the FPGA IC chip 200 and auxiliary IC chip 411 of the subsystem unit 191, any of a first portion of the through silicon vias (TSVs) 157 of the auxiliary IC chip 411 of the subsystem unit 191, any of a first portion of the first type of metal bumps, pillars or pads 570 of the subsystem unit 191, one or more of the interconnection metal layers 27 of the interconnection scheme 79 and any of a first portion of the first type of micro-bumps, micro-pillars or micro-pads 34 of the NVM IC chip 250 for the ninth type of FPMCP 312 as seen in FIG. 17 may be formed for one of the non-programmable interconnects 364 of the inter-chip interconnects 371 between the NVM IC chip 250 and FPGA IC chip 200 as illustrated in FIG. 5F; any of a second portion of the first type of metal bumps, pillars or pads 570 of the subsystem unit 191, one or more of the interconnection metal layers 27 of the interconnection scheme 79 and any of a second portion of the first type of micro-bumps, micro-pillars or micro-pads 34 of the NVM IC chip 250 for the ninth type of FPMCP 312 as seen in FIG. 17 may be formed for one of the non-programmable interconnects 364 of the inter-chip interconnects 371 between the NVM IC chip 250 and auxiliary IC chip 411 as illustrated in FIG. 5F; for its subsystem unit 191 formed by hybrid bonding as illustrated in FIGS. 13A and 15A, any bonded two of a second portion of the metal pads 6a of the FPGA IC chip 200 and auxiliary IC chip 411 of the subsystem unit 191, any of a second portion of the through silicon vias (TSVs) 157 of the auxiliary IC chip 411 of the subsystem unit 191, any of a third portion of the first type of metal bumps, pillars or pads 570 of the subsystem unit 191, one or more of the interconnection metal layers 27 of the interconnection scheme 79 and any of the first type of micro-bumps, micro-pillars or micro-pads 34 of the logic computing IC chip 269 for the ninth type of FPMCP 312 as seen in FIG. 17 may be formed for one of the programmable interconnects 361 of the inter-chip interconnects 371 between the FPGA IC chip 200 and any of the semiconductor IC chips 100g as illustrated in FIG. 5F, and alternatively, for its subsystem unit 191 formed by wafer bumping as illustrated in FIGS. 13B and 15B for any case of the first through fourth cases, any of a second portion of the bonded metal bumps or contacts 563 between the FPGA IC chip 200 and auxiliary IC chip 411 of the subsystem unit 191, any of a second portion of the through silicon vias (TSVs) 157 of the auxiliary IC chip 411 of the subsystem unit 191, any of a third portion of the first type of metal bumps, pillars or pads 570 of the subsystem unit 191, one or more of the interconnection metal layers 27 of the interconnection scheme 79 and any of the first type of micro-bumps, micro-pillars or micro-pads 34 of the logic computing IC chip 269 for the ninth type of FPMCP 312 as seen in FIG. 17 may be formed for one of the programmable interconnects 361 of the inter-chip interconnects 371 between the FPGA IC chip 200 and any of the semiconductor IC chips 100g as illustrated in FIG. 5F, any of a fourth portion of the first type of metal bumps, pillars or pads 570 of the subsystem unit 191, each of the interconnection metal layers 27 of the interconnection scheme 79 and any of the metal bumps, pillars or pads 571 for the ninth type of FPMCP 312 as seen in FIG. 17 may be formed for the large input/output (I/O) circuits 341 of the large-input/output (I/O) block of the auxiliary IC chip 411 receiving and transmitting the first and second (encrypted) CPM data from and to the external circuits 340 as illustrated in FIG. 5F outside of the ninth type of FPMCP 312. For the ninth type of FPMCP 312 for each aspect of the ninth through eleventh aspects as illustrated in FIG. 5G, the FPGA IC chip 200 of its subsystem unit 191 may have the same circuits as one illustrated in FIG. 5G, its NVM IC chip 250 may have the same circuits as one illustrated in FIG. 5G, and its logic computing IC chip 269 may be any of the semiconductor IC chips 100g as illustrated in FIG. 5G. For its subsystem unit 191 formed by hybrid bonding as illustrated in FIGS. 13A and 15A, any bonded two of a first portion of the metal pads 6a of the FPGA IC chip 200 and auxiliary IC chip 411 of the subsystem unit 191, any of a first portion of the through silicon vias (TSVs) 157 of the auxiliary IC chip 411 of the subsystem unit 191, any of a first portion of the first type of metal bumps, pillars or pads 570 of the subsystem unit 191, one or more of the interconnection metal layers 27 of the interconnection scheme 79 and any of a first portion of the first type of micro-bumps, micro-pillars or micro-pads 34 of the NVM IC chip 250 for the ninth type of FPMCP 312 as seen in FIG. 17 may be formed for one of the non-programmable interconnects 364 of the inter-chip interconnects 371 between the FPGA IC chip 200 and NVM IC chip 250 as illustrated in FIG. 5G, and alternatively, for its subsystem unit 191 formed by wafer bumping as illustrated in FIGS. 13B and 15B for any case of the first through fourth cases, any of a first portion of the bonded metal bumps or contacts 563 between the FPGA IC chip 200 and auxiliary IC chip 411 of the subsystem unit 191, any of a first portion of the through silicon vias (TSVs) 157 of the auxiliary IC chip 411 of the subsystem unit 191, any of a first portion of the first type of metal bumps, pillars or pads 570 of the subsystem unit 191, one or more of the interconnection metal layers 27 of the interconnection scheme 79 and any of a first portion of the first type of micro-bumps, micro-pillars or micro-pads 34 of the NVM IC chip 250 for the ninth type of FPMCP 312 as seen in FIG. 17 may be formed for one of the non-programmable interconnects 364 of the inter-chip interconnects 371 between the FPGA IC chip 200 and NVM IC chip 250 as illustrated in FIG. 5G; for its subsystem unit 190 formed by hybrid bonding as illustrated in FIGS. 13A and 15A, any bonded two of a second portion of the metal pads 6a of the FPGA IC chip 200 and auxiliary IC chip 411 of the subsystem unit 191, any of a second portion of the through silicon vias (TSVs) 157 of the auxiliary IC chip 411 of the subsystem unit 191, any of a second portion of the first type of metal bumps, pillars or pads 570 of the subsystem unit 191, one or more of the interconnection metal layers 27 of the interconnection scheme 79 and any of the first type of micro-bumps, micro-pillars or micro-pads 34 of the logic computing IC chip 269 for the ninth type of FPMCP 312 as seen in FIG. 17 may be formed for one of the programmable interconnects 361 of the inter-chip interconnects 371 between the FPGA IC chip 200 and any of the semiconductor IC chips 100g as illustrated in FIG. 5G, and alternatively, for its subsystem unit 190 formed by wafer bumping as illustrated in FIGS. 13B and 15B for any case of the first through fourth cases, any of a second portion of the bonded metal bumps or contacts 563 between the FPGA IC chip 200 and auxiliary IC chip 411 of the subsystem unit 191, any of a second portion of the through silicon vias (TSVs) 157 of the auxiliary IC chip 411 of the subsystem unit 191, any of a second portion of the first type of metal bumps, pillars or pads 570 of the subsystem unit 191, one or more of the interconnection metal layers 27 of the interconnection scheme 79 and any of the first type of micro-bumps, micro-pillars or micro-pads 34 of the logic computing IC chip 269 for the ninth type of FPMCP 312 as seen in FIG. 17 may be formed for one of the programmable interconnects 361 of the inter-chip interconnects 371 between the FPGA IC chip 200 and any of the semiconductor IC chips 100g as illustrated in FIG. 5G; any of a second portion of the first type of micro-bumps, micro-pillars or micro-pads 34 of the NVM IC chip 250, each of the interconnection metal layers 27 of the interconnection scheme 79 and any of the metal bumps, pillars or pads 571 for the ninth type of FPMCP 312 as seen in FIG. 17 may be formed for the large input/output (I/O) circuits 342 of the NVM IC chip 250 receiving and transmitting the first and second (encrypted) CPM data from and to the external circuits 340 as illustrated in FIG. 5G outside of the ninth type of FPMCP 312.

### Tenth Type of FPMCP

FIG. 18 is a schematically cross-sectional view showing a tenth type of FPMCP in accordance with an embodiment of the present application. A tenth type of FPMCP 313 as seen in FIG. 18 may include (1) a ball-grid-array (BGA) substrate 537 having multiple interconnection metal layers and multiple insulating dielectric layers each between neighboring two of the interconnection metal layers of its ball-grid-array (BGA) substrate 537, on and over a topmost one of the interconnection metal layers of its ball-grid-array (BGA) substrate 537, or on and under a bottommost one of the interconnection metal layers of its ball-grid-array (BGA) substrate 537, wherein multiple openings in the topmost one of the insulating dielectric layers of its ball-grid-array (BGA) substrate 537 may be over multiple metal pads of the topmost one of the interconnection metal layers of its ball-grid-array (BGA) substrate 537 respectively, and multiple openings in the bottommost one of the insulating dielectric layers of its ball-grid-array (BGA) substrate 537 may be under multiple metal pads 528 of the bottommost one of the interconnection metal layers of its ball-grid-array (BGA) substrate 537 respectively, wherein its ball-grid-array (BGA) substrate 537 may have the specification as that illustrated in FIG. 19-1, (2) a first subsystem unit 193 over and bonded to the top surface of its ball-grid-array (BGA) substrate 537, and (3) multiple solder balls 538, made of a tin-lead alloy or tin-silver-copper alloy, in an array at its bottom to act as external pins of the tenth type of FPMCP 313, wherein each of its solder balls 538 may be formed on a bottom surface of one of the metal pads 528 of the bottommost one of the interconnection metal layers of its ball-grid-array (BGA) substrate 537.

Referring to FIG. 18, for the tenth type of FPMCP 313, its first subsystem unit 193 may include (1) the auxiliary IC chip 411 having the specification as illustrated for one in FIG. 5A-1, (2) a second subsystem unit 194 over the auxiliary IC chip 411 of its first subsystem unit 193 and (3) the NVM IC chip 250 having the specification as illustrated for one in FIG. 5A-1 over its second subsystem unit 194. The second subsystem unit 194 of its first subsystem unit 193 may have a similar structure to either of the fifth type of FPMCPs 308 as illustrated in FIGS. 13A and 13B. For an element of the second subsystem unit 194 of its first subsystem unit 193 indicated by the same reference number as that for either of the fifth type of FPMCPs 308 as illustrated in FIGS. 13A and 13B, the specification of the element as seen in FIG. 18 may be referred to that of the element as illustrated in FIG. 13A or 13B. The difference between the second subsystem unit 194 of the tenth type of FPMCP 313 and either of the fifth type of FPMCPs 308 is that each of the FPGA IC chips 200 for the fifth type of FPMCPs 308 illustrated in FIGS. 13A and 13B may be replaced with the logic computing IC chip 269, such as the graphic-processing-unit (GPU) IC chip 269a, central-processing-unit (CPU) IC chip 269b or application-specific integrated-circuit (ASIC) chip or system-on-chip (SoC) chip 269c as illustrated in FIG. 5A-1 or such as data processing unit (DPU) IC chip, tensor flow processing unit (TPU) IC chip or digital-signal-processing (DSP) chip, for the second subsystem unit 194 of its first subsystem unit 193, and each of the logic computing IC chips 269 for the fifth type of FPMCPs 308 illustrated in FIGS. 13A and 13B may be replaced with the FPGA IC chip 200 as illustrated in FIG. 5A-1 for the second subsystem unit 194 of its first subsystem unit 193 and the NVM IC chips 250 and auxiliary IC chips 411 for the fifth type of FPMCPs 308 illustrated in FIGS. 13A and 13B may be saved for the second subsystem unit 194 of its first subsystem unit 193. For the tenth type of FPMCP 313, the FPGA IC chip 200 of the second subsystem unit 194 of its first subsystem unit 193 may be the dedicated field programmable integrated-circuit (DFPIC) chip as illustrated in FIG. 4D or embedded field programmable integrated-circuit (eFPIC) chip as illustrated in FIG. 4E. Referring to FIG. 18, for the tenth type of FPMCP 313, if the second subsystem unit 194 of its first subsystem unit 193 is formed by the hybrid bonding as illustrated in FIG. 13A, the FPGA IC chip 200 of the second subsystem unit 194 of its first subsystem unit 193 may have the same specification as the sixth type of semiconductor IC chip 100 illustrated in FIG. 3F to be turned upside down to be bonded to the logic computing IC chip 269 of the second subsystem unit 194 of its first subsystem unit 193 having the same specification as the sixth type of semiconductor IC chip 100 illustrated in FIG. 3F. If the second subsystem unit 194 of its first subsystem unit 193 is formed by the wafer bumping as illustrated in FIG. 13B, the FPGA IC chip 200 of the second subsystem unit 194 of its first subsystem unit 193 may have the same specification as the second type of semiconductor IC chip 100 illustrated in FIGS. 3B and 3G-3J to be turned upside down to be bonded to the logic computing IC chip 269 of the second subsystem unit 194 of its first subsystem unit 193 having the same specification as the sixth type of semiconductor IC chip 100 illustrated in FIGS. 3B and 3G-3J. For forming its first subsystem unit 193, the semiconductor substrate 2 of the logic computing IC chip 269 of the second subsystem unit 194 may have a portion, at a backside of the semiconductor substrate 2 of the logic computing IC chip 269 of the second subsystem unit 194, removed by a chemical-mechanical-polishing (CMP) or mechanical grinding process, and the insulating lining layer 153 at a backside of each of the through silicon vias 157 (TSVs) of the logic computing IC chip 269 of the second subsystem unit 194 and the adhesion metal layer 154 and electroplating seed layer 155 of each of the through silicon vias 157 (TSVs) of the logic computing IC chip 269 of the second subsystem unit 194 at the backside of each of the through silicon vias 157 (TSVs) of the logic computing IC chip 269 of the second subsystem unit 194 may be removed by the chemical-mechanical-polishing (CMP) or mechanical grinding process to expose to a bottom surface of the electroplated copper layer 156 of each of the through silicon vias 157 (TSVs) of the logic computing IC chip 269 of the second subsystem unit 194. Next, the semiconductor substrate 2 of the logic computing IC chip 269 of the second subsystem unit 194 may be etched to form a recess from the bottom surface of the electroplated copper layer 156 of each of the through silicon vias 157 (TSVs) of the logic computing IC chip 269 of the second subsystem unit 194, and then an insulating dielectric layer 185, such as silicon-oxide layer or silicon-nitride layer, may be formed in the recess and on the backside of the semiconductor substrate 2 of the logic computing IC chip 269 of the second subsystem unit 194, wherein the insulating dielectric layer 185 of the logic computing IC chip 269 of the second subsystem unit 194 may have a bottom surface coplanar with the bottom surface of each of the through silicon vias 157 of the logic computing IC chip 269 of the second subsystem unit 194. The first or second type of metal bumps, pillars or pads 570 as illustrated in FIGS. 6A, 13A and 13B may be formed as bottom metal bumps, pillars or pads of the second subsystem unit 194 and at a bottom of the logic computing IC chip 269 of the second subsystem unit 194 following the same process to form the first or second type of metal bumps, pillars or pads 570 at a bottom of the FPGA IC chip 200 of the fifth type of FPMCP 308 as illustrated in the first through third aspects in FIGS. 13A and 13E. Thereby, in the first aspect each of the bottom metal bumps, pillars or pads 570 of the second subsystem unit 194 may have the adhesion metal layer 26a on the bottom surface of one of the through silicon vias (TSVs) 157, i.e., the copper layer 156 thereof, of the logic computing IC chip 269 of the second subsystem unit 194 and the bottom surface of the insulating dielectric layer 185 of the logic computing IC chip 269 of the second subsystem unit 194. In the second aspect, each of the bottom metal bumps, pillars or pads 570 of the logic computing IC chip 269 of the second subsystem unit 194 may have the adhesion metal layer 26a thereof formed on the bottom surface of the electroplated copper layer 156 of each of the set of through silicon vias 157 (TSVs) of the logic computing IC chip 269 of the second subsystem unit 194 and the bottom surface of the insulating dielectric layer 185 of the logic computing IC chip 269 of the second subsystem unit 194 to couple the set of through silicon vias 157 (TSVs) of the logic computing IC chip 269 of the second subsystem unit 194, wherein the reference layer 6f of the first interconnection scheme for a chip (FISC) 20 of the logic computing IC chip 269 of the second subsystem unit 194 for the second kind as illustrated in FIGS. 3G and 3H may couple the set of through silicon vias 157 (TSVs) of the logic computing IC chip 269 of the second subsystem unit 194, the reference layer 6f of the first interconnection scheme for a chip (FISC) 20 of the logic computing IC chip 269 of the second subsystem unit 194 for the third kind as illustrated in FIG. 3I may couple the set of through silicon vias 157 (TSVs) of the logic computing IC chip 269 of the second subsystem unit 194, and the second portion of the bottommost one of the interconnection metal layers 6 of the first interconnection scheme for a chip (FISC) 20 of the logic computing IC chip 269 of the second subsystem unit 194 for the fourth kind as illustrated in FIG. 3J may couple the set of through silicon vias 157 (TSVs) of the logic computing IC chip 269 of the second subsystem unit 194, wherein a pitch or space between each neighboring two of the set of through silicon vias 157 (TSVs) of the logic computing IC chip 269 of the second subsystem unit 194, i.e., the electroplated copper layers 156 thereof, may be between 5 and 50 micrometers. In the third aspect, the logic computing IC chip 269 of the second subsystem unit 194 may be further formed with the insulating dielectric layer 587 as illustrated in FIG. 13E on the bottom surface of the insulating dielectric layer 185 of the logic computing IC chip 269 of the second subsystem unit 194 as illustrated for the second aspect for the logic computing IC chip 269 of the second subsystem unit 194, wherein an opening in the insulating dielectric layer 587 of the logic computing IC chip 269 of the second subsystem unit 194 may be vertically under the set of through silicon vias 157 (TSVs) of the logic computing IC chip 269 of the second subsystem unit 194 and said each of the bottom metal bumps, pillars or pads 570 may be formed in and under the opening in the insulating dielectric layer 587 of the logic computing IC chip 269 of the second subsystem unit 194 and under and on a bottom surface of the insulating dielectric layer 587 of the logic computing IC chip 269 of the second subsystem unit 194 and have the adhesion metal layer 26a thereof formed on the bottom surface of the electroplated copper layer 156 of each of the set of through silicon vias 157 (TSVs) of the logic computing IC chip 269 of the second subsystem unit 194, the bottom surface of the insulating dielectric layer 185 of the logic computing IC chip 269 of the second subsystem unit 194 and the bottom surface of the insulating dielectric layer 587 of the logic computing IC chip 269 of the second subsystem unit 194 to couple the set of through silicon vias 157 (TSVs) of the logic computing IC chip 269 of the second subsystem unit 194.

Referring to FIG. 18, for the tenth type of FPMCP 313, the auxiliary IC chip 411 of its first subsystem unit 193 may have the same specification as the second type of semiconductor IC chip 100 illustrated in FIGS. 3B and 3G-3J to be turned upside down. For forming its first subsystem unit 193, the semiconductor substrate 2 of the auxiliary IC chip 411 may have a portion, at a backside of the semiconductor substrate 2 of the auxiliary IC chip 411, removed by a chemical-mechanical-polishing (CMP) or mechanical grinding process, and the insulating lining layer 153 at a backside of each of the through silicon vias 157 (TSVs) of the auxiliary IC chip 411 and the adhesion metal layer 154 and electroplating seed layer 155 of each of the through silicon vias 157 (TSVs) of the auxiliary IC chip 411 at the backside of each of the through silicon vias 157 (TSVs) of the auxiliary IC chip 411 may be removed by the chemical-mechanical-polishing (CMP) or mechanical grinding process to expose to a top surface of the electroplated copper layer 156 of each of the through silicon vias 157 (TSVs) of the auxiliary IC chip 411. Next, the semiconductor substrate 2 of the auxiliary IC chip 411 may be etched to form a recess from the top surface of the electroplated copper layer 156 of each of the through silicon vias 157 (TSVs) of the auxiliary IC chip 411, and then an insulating dielectric layer 185, such as silicon-oxide layer or silicon-nitride layer, may be formed in the recess and on the backside of the semiconductor substrate 2 of the auxiliary IC chip 411, wherein the insulating dielectric layer 185 of the auxiliary IC chip 411 may have a top surface coplanar with the top surface of the electroplated copper layer 156 of each of the through silicon vias 157 of the auxiliary IC chip 411, wherein the insulating dielectric layer 185 of the auxiliary IC chip 411 may have a top surface coplanar with a top surface of each of the through silicon vias 157 of the auxiliary IC chip 411. The first or second type of metal bumps, pillars or pads 570 as illustrated in FIG. 6A may be formed as top metal bumps, pillars or pads of the auxiliary IC chip 411 and at a top of the auxiliary IC chip 411 following the same process to form the first or second type of metal bumps, pillars or pads 570 at a bottom of the FPGA IC chip 200 of the fifth type of FPMCP 308 as illustrated in the first through third aspects in FIGS. 13A and 13E to be turned upside down. Thereby, in the first aspect each of the top metal bumps, pillars or pads 570 of the auxiliary IC chip 411 may have the adhesion metal layer 26a on the top surface of one of the through silicon vias (TSVs) 157, i.e., the electroplated copper layer 156 thereof, of the auxiliary IC chip 411 and the top surface of the insulating dielectric layer 185 of the auxiliary IC chip 411. In the second aspect, each of the top metal bumps, pillars or pads 570 of the auxiliary IC chip 411 may have the adhesion metal layer 26a thereof formed on the top surface of the electroplated copper layer 156 of each of the set of through silicon vias 157 (TSVs) of the auxiliary IC chip 411 and the top surface of the insulating dielectric layer 185 of the auxiliary IC chip 411 to couple the set of through silicon vias 157 (TSVs) of the auxiliary IC chip 411, wherein the reference layer 6f of the first interconnection scheme for a chip (FISC) 20 of the auxiliary IC chip 411 for the second kind as illustrated in FIGS. 3G and 3H to be turned upside down may couple the set of through silicon vias 157 (TSVs) of the auxiliary IC chip 411, the reference layer 6f of the first interconnection scheme for a chip (FISC) 20 of the auxiliary IC chip 411 for the third kind as illustrated in FIG. 3I to be turned upside down may couple the set of through silicon vias 157 (TSVs) of the auxiliary IC chip 411, and the second portion of the bottommost one of the interconnection metal layers 6 of the first interconnection scheme for a chip (FISC) 20 of the auxiliary IC chip 411 for the fourth kind as illustrated in FIG. 3J to be turned upside down may couple the set of through silicon vias 157 (TSVs) of the auxiliary IC chip 411, wherein a pitch or space between each neighboring two of the set of through silicon vias 157 (TSVs) of the auxiliary IC chip 411, i.e., the electroplated copper layers 156 thereof, may be between 5 and 50 micrometers. In the third aspect, the auxiliary IC chip 411 may be further formed with the insulating dielectric layer 587, as illustrated in FIG. 13E to be turned upside down, on the top surface of the insulating dielectric layer 185 of the auxiliary IC chip 411 as illustrated for the second aspect for the auxiliary IC chip 411, wherein an opening in the insulating dielectric layer 587 of the auxiliary IC chip 411 may be vertically over the set of through silicon vias 157 (TSVs) of the auxiliary IC chip 411 and said each of the top metal bumps, pillars or pads 570 may be formed in and over the opening in the insulating dielectric layer 587 of the auxiliary IC chip 411 and on a top surface of the insulating dielectric layer 587 of the auxiliary IC chip 411 and have the adhesion metal layer 26a thereof formed on the top surface of the electroplated copper layer 156 of each of the set of through silicon vias 157 (TSVs) of the auxiliary IC chip 411, the top surface of the insulating dielectric layer 185 of the auxiliary IC chip 411 and the top surface of the insulating dielectric layer 587 of the auxiliary IC chip 411 to couple the set of through silicon vias 157 (TSVs) of the auxiliary IC chip 411.

Referring to FIG. 18, for forming its first subsystem unit 193, each of the top metal bumps, pillars or pads 570 of the auxiliary IC chip 411 may join one of the bottom metal bumps, pillars or pads 570 of the second subsystem unit 194 into a bonded metal bump or contact 563-1 between the auxiliary IC chip 411 and the logic computing IC chip 269 of the second subsystem unit 194.

Referring to FIG. 18, for the tenth type of FPMCP 313, its first subsystem unit 193 may further include (1) an underfill 564, e.g., polymer layer, between the auxiliary IC chip 411 of its first subsystem unit 193 and the logic computing IC chip 269 of the second subsystem unit 194 of its first subsystem unit 193, covering a sidewall of each of the bonded metal bumps or contacts 563-1 of its first subsystem unit 193, and (2) a polymer layer 192 or insulating dielectric layer, i.e., sealing layer, such as silicon-oxide-containing molding compound, epoxy-based material or polyimide, on the auxiliary IC chip 411 of its first subsystem unit 193 and horizontally around the second subsystem unit 194 of its first subsystem unit 193. For forming its first subsystem unit 193, the semiconductor substrate 2 of the FPGA IC chip 200 of the second subsystem unit 194 may have a portion, at a backside of the semiconductor substrate 2 of the FPGA IC chip 200 of the second subsystem unit 194, removed by a chemical-mechanical-polishing (CMP) or mechanical grinding process, and the insulating lining layer 153 at a backside of each of the through silicon vias 157 (TSVs) of the FPGA IC chip 200 of the second subsystem unit 194 and the adhesion metal layer 154 and electroplating seed layer 155 of each of the through silicon vias 157 (TSVs) of the FPGA IC chip 200 of the second subsystem unit 194 at the backside of each of the through silicon vias 157 (TSVs) of the FPGA IC chip 200 of the second subsystem unit 194 may be removed by the chemical-mechanical-polishing (CMP) or mechanical grinding process to expose to a top surface of the electroplated copper layer 156 of each of the through silicon vias 157 (TSVs) of the FPGA IC chip 200 of the second subsystem unit 194. Next, the semiconductor substrate 2 of the FPGA IC chip 200 of the second subsystem unit 194 may be etched to form a recess from the top surface of the electroplated copper layer 156 of each of the through silicon vias 157 (TSVs) of the FPGA IC chip 200 of the second subsystem unit 194, and then an insulating dielectric layer 185, such as silicon-oxide layer or silicon-nitride layer, may be formed in the recess and on the backside of the semiconductor substrate 2 of the FPGA IC chip 200 of the second subsystem unit 194, wherein the insulating dielectric layer 185 of the FPGA IC chip 200 of the second subsystem unit 194 may have a top surface coplanar with the top surface of the electroplated copper layer 156 of each of the through silicon vias 157 of the FPGA IC chip 200 of the second subsystem unit 194, a top surface of the polymer layer 92 of the second subsystem unit 194 and a top surface of the polymer layer 192. The polymer layer 192 may have a vertical sidewall coplanar with a vertical sidewall of the auxiliary IC chip 411. The first or second type of metal bumps, pillars or pads 570 as illustrated in FIG. 6A may be formed as top metal bumps, pillars or pads of the second subsystem unit 194 and at a top of the FPGA IC chip 200 of the second subsystem unit 194 following the same process to form the first or second type of metal bumps, pillars or pads 570 at a bottom of the FPGA IC chip 200 of the fifth type of FPMCP 308 as illustrated in the first through third aspects in FIGS. 13A and 13E to be turned upside down. Thereby, in the first aspect each of the top metal bumps, pillars or pads 570 of the second subsystem unit 194 may have the adhesion metal layer 26a on the top surface of one of the through silicon vias (TSVs) 157, i.e., the electroplated copper layer 156 thereof, of the FPGA IC chip 200 of the second subsystem unit 194 and the top surface of the insulating dielectric layer 185 of the FPGA IC chip 200 of the second subsystem unit 194. In the second aspect, each of the top metal bumps, pillars or pads 570 of the second subsystem unit 194 may have the adhesion metal layer 26a thereof formed on the top surface of the electroplated copper layer 156 of each of the set of through silicon vias 157 (TSVs) of the FPGA IC chip 200 of the second subsystem unit 194 and the top surface of the insulating dielectric layer 185 of the FPGA IC chip 200 of the second subsystem unit 194 to couple the set of through silicon vias 157 (TSVs) of the FPGA IC chip 200 of the second subsystem unit 194, wherein the reference layer 6f of the first interconnection scheme for a chip (FISC) 20 of the FPGA IC chip 200 of the second subsystem unit 194 for the second kind as illustrated in FIGS. 3G and 3H to be turned upside down may couple the set of through silicon vias 157 (TSVs) of the FPGA IC chip 200 of the second subsystem unit 194, the reference layer 6f of the first interconnection scheme for a chip (FISC) 20 of the FPGA IC chip 200 of the second subsystem unit 194 for the third kind as illustrated in FIG. 3I to be turned upside down may couple the set of through silicon vias 157 (TSVs) of the FPGA IC chip 200 of the second subsystem unit 194, and the second portion of the bottommost one of the interconnection metal layers 6 of the first interconnection scheme for a chip (FISC) 20 of the FPGA IC chip 200 of the second subsystem unit 194 for the fourth kind as illustrated in FIG. 3J to be turned upside down may couple the set of through silicon vias 157 (TSVs) of the FPGA IC chip 200 of the second subsystem unit 194, wherein a pitch or space between each neighboring two of the set of through silicon vias 157 (TSVs) of the FPGA IC chip 200 of the second subsystem unit 194, i.e., the electroplated copper layers 156 thereof, may be between 5 and 50 micrometers. In the third aspect, the auxiliary IC chip 411 may be further formed with the insulating dielectric layer 587 as illustrated in FIG. 13E to be turned upside down on the top surface of the insulating dielectric layer 185 of the FPGA IC chip 200 of the second subsystem unit 194 as illustrated for the second aspect for the FPGA IC chip 200 of the second subsystem unit 194, wherein an opening in the insulating dielectric layer 587 of the FPGA IC chip 200 of the second subsystem unit 194 may be vertically over the set of through silicon vias 157 (TSVs) of the FPGA IC chip 200 of the second subsystem unit 194 and said each of the top metal bumps, pillars or pads 570 of the second subsystem unit 194 may be formed in and over the opening in the insulating dielectric layer 587 of the FPGA IC chip 200 of the second subsystem unit 194 and on a top surface of the insulating dielectric layer 587 of the FPGA IC chip 200 of the second subsystem unit 194 and have the adhesion metal layer 26a thereof formed on the top surface of the electroplated copper layer 156 of each of the set of through silicon vias 157 (TSVs) of the FPGA IC chip 200 of the second subsystem unit 194, the top surface of the insulating dielectric layer 185 of the FPGA IC chip 200 of the second subsystem unit 194 and the top surface of the insulating dielectric layer 587 of the FPGA IC chip 200 of the second subsystem unit 194 to couple the set of through silicon vias 157 (TSVs) of the FPGA IC chip 200 of the second subsystem unit 194.

Referring to FIG. 18, for forming its first subsystem unit 193, each of the top metal bumps, pillars or pads 570 of the second subsystem unit 194 may join one of the first, second, third or fourth type of micro-bumps, micro-pillars or micro-pads 34 of the NVM IC chip 250 into a bonded metal bump or contact 563-2 between the FPGA IC chip 200 of the second subsystem unit 194 and the NVM IC chip 250, wherein the NVM IC chip 250 may have the same specification as the first type of semiconductor IC chip 100 illustrated in FIG. 3A to be turned upside down. Its first subsystem unit 193 may further include an underfill 564, e.g., polymer layer, between the FPGA IC chip 200 of the second subsystem unit 194 and the NVM IC chip 250, covering a sidewall of each of the bonded metal bumps or contacts 563-2. Each of the first, second, third or fourth type of micro-bumps, micro-pillars or micro-pads 34 of the auxiliary IC chip 411 of its first subsystem unit 193 may be bonded to a metal pad, bump or contact 529, made of nickel, gold or copper for example, preformed on one of the metal pads of the topmost one of the interconnection metal layers of its ball-grid-array (BGA) substrate 537. The tenth type of FPMCP 313 may further include an underfill 564, e.g., polymer layer, between the auxiliary IC chip 411 of its first subsystem unit 193 and its ball-grid-array (BGA) substrate 537, covering a sidewall of each of the first, second, third or fourth type of micro-bumps, micro-pillars or micro-pads 34 of the auxiliary IC chip 411 of its first subsystem unit 193.

Referring to FIG. 18, the tenth type of FPMCP 313 may have the inter-chip interconnection between the first and second semiconductor IC chips 100a and 100b via the FPGA IC chip 200 as illustrated in FIG. 5B. For the tenth type of FPMCP 313, the FPGA IC chip 200 of the second subsystem unit 194 of its first subsystem unit 193 may have the same circuits as one illustrated in FIG. 5B. For a first scenario, the logic computing IC chip 269 of the second subsystem unit 194 of its first subsystem unit 193 may be the first semiconductor IC chip 100a as illustrated in FIG. 5B, and the auxiliary IC chip 411 of its first subsystem unit 193 may be the second semiconductor IC chip 100b as illustrated in FIG. 5B. In the first scenario, for the second subsystem unit 194 of its first subsystem unit 193 formed by hybrid bonding as illustrated in FIGS. 13A and 18, each bonded two of a first portion of the metal pads 6a of the FPGA IC chip 200 and logic computing IC chip 269 of the second subsystem unit 194 of its first subsystem unit 193 may be formed for one of the programmable interconnects 361 of the inter-chip interconnects 371 between the FPGA IC chip 200 and first semiconductor IC chip 100a as illustrated in FIG. 5B, and any bonded two of a second portion of the metal pads 6a of the FPGA IC chip 200 and logic computing IC chip 269 of the second subsystem unit 194 of its first subsystem unit 193, any of the through silicon vias (TSVs) 157 of the logic computing IC chip 269 of the second subsystem unit 194 of its first subsystem unit 193, any of the bonded metal bumps or contacts 563-1 of its first subsystem unit 193 and any of the through silicon vias (TSVs) 157 of the second semiconductor IC chip 100b of its first subsystem unit 193 may be formed for one of the programmable interconnects 361 of the inter-chip interconnects 371 between the FPGA IC chip 200 and second semiconductor IC chip 100b as illustrated in FIG. 5B. Alternatively, for the second subsystem unit 194 of its first subsystem unit 193 formed by wafer bumping as illustrated in FIGS. 13B and 18, each of a first portion of the bonded metal bumps or contacts 563 between the FPGA IC chip 200 and logic computing IC chip 269 of the second subsystem unit 194 of its first subsystem unit 193 may be formed for one of the programmable interconnects 361 of the inter-chip interconnects 371 between the FPGA IC chip 200 and first semiconductor IC chip 100a as illustrated in FIG. 5B, and any of a second portion of the bonded metal bumps or contacts 563 between the FPGA IC chip 200 and logic computing IC chip 269 of the second subsystem unit 194 of its first subsystem unit 193, any of the through silicon vias (TSVs) 157 of the logic computing IC chip 269 of the second subsystem unit 194 of its first subsystem unit 193, any of the bonded metal bumps or contacts 563-1 of its first subsystem unit 193 and any of the through silicon vias (TSVs) 157 of the second semiconductor IC chip 100b of its first subsystem unit 193 may be formed for one of the programmable interconnects 361 of the inter-chip interconnects 371 between the FPGA IC chip 200 and second semiconductor IC chip 100b as illustrated in FIG. 5B. For a second scenario, the logic computing IC chip 269 of the second subsystem unit 194 of its first subsystem unit 193 may be the first semiconductor IC chip 100a as illustrated in FIG. 5B, and the NVM IC chip 250 of its first subsystem unit 193 may be the second semiconductor IC chip 100b as illustrated in FIG. 5B. In the second scenario, for the second subsystem unit 194 of its first subsystem unit 193 formed by hybrid bonding as illustrated in FIGS. 13A and 18, each bonded two of the metal pads 6a of the FPGA IC chip 200 and logic computing IC chip 269 of the second subsystem unit 194 of its first subsystem unit 193 may be formed for one of the programmable interconnects 361 of the inter-chip interconnects 371 between the FPGA IC chip 200 and first semiconductor IC chip 100a as illustrated in FIG. 5B, and any of the through silicon vias (TSVs) 157 of the FPGA IC chip 200 of the second subsystem unit 194 of its first subsystem unit 193 and any of the bonded metal bumps or contacts 563-2 of its first subsystem unit 193 may be formed for one of the programmable interconnects 361 of the inter-chip interconnects 371 between the FPGA IC chip 200 and second semiconductor IC chip 100b as illustrated in FIG. 5B. Alternatively, for the second subsystem unit 194 of its first subsystem unit 193 formed by wafer bumping as illustrated in FIGS. 13B and 18, each of the bonded metal bumps or contacts 563 between the FPGA IC chip 200 and logic computing IC chip 269 of the second subsystem unit 194 of its first subsystem unit 193 may be formed for one of the programmable interconnects 361 of the inter-chip interconnects 371 between the FPGA IC chip 200 and first semiconductor IC chip 100a as illustrated in FIG. 5B, and any of the through silicon vias (TSVs) 157 of the FPGA IC chip 200 of the second subsystem unit 194 of its first subsystem unit 193 and any of the bonded metal bumps or contacts 563-2 of its first subsystem unit 193 may be formed for one of the programmable interconnects 361 of the inter-chip interconnects 371 between the FPGA IC chip 200 and second semiconductor IC chip 100b as illustrated in FIG. 5B. For a third scenario, the auxiliary IC chip 411 of its first subsystem unit 193 may be the first semiconductor IC chip 100a as illustrated in FIG. 5B, and the NVM IC chip 250 of its first subsystem unit 193 may be the second semiconductor IC chip 100b as illustrated in FIG. 5B. In the third scenario, for the second subsystem unit 194 of its first subsystem unit 193 formed by hybrid bonding as illustrated in FIGS. 13A and 18, any bonded two of the metal pads 6a of the FPGA IC chip 200 and logic computing IC chip 269 of the second subsystem unit 194 of its first subsystem unit 193, any of the through silicon vias (TSVs) 157 of the logic computing IC chip 269 of the second subsystem unit 194 of its first subsystem unit 193, any of the bonded metal bumps or contacts 563-1 of its first subsystem unit 193 and any of the through silicon vias (TSVs) 157 of the first semiconductor IC chip 100a of its first subsystem unit 193 may be formed for one of the programmable interconnects 361 of the inter-chip interconnects 371 between the FPGA IC chip 200 and first semiconductor IC chip 100a as illustrated in FIG. 5B, and any of the through silicon vias (TSVs) 157 of the FPGA IC chip 200 of the second subsystem unit 194 of its first subsystem unit 193 and any of the bonded metal bumps or contacts 563-2 of its first subsystem unit 193 may be formed for one of the programmable interconnects 361 of the inter-chip interconnects 371 between the FPGA IC chip 200 and second semiconductor IC chip 100b as illustrated in FIG. 5B. Alternatively, for the second subsystem unit 194 of its first subsystem unit 193 formed by wafer bumping as illustrated in FIGS. 13B and 18, any of the bonded metal bumps or contacts 563 between the FPGA IC chip 200 and logic computing IC chip 269 of the second subsystem unit 194 of its first subsystem unit 193, any of the through silicon vias (TSVs) 157 of the logic computing IC chip 269 of the second subsystem unit 194 of its first subsystem unit 193, any of the bonded metal bumps or contacts 563-1 of its first subsystem unit 193 and any of the through silicon vias (TSVs) 157 of the first semiconductor IC chip 100a of its first subsystem unit 193 may be formed for one of the programmable interconnects 361 of the inter-chip interconnects 371 between the FPGA IC chip 200 and first semiconductor IC chip 100a as illustrated in FIG. 5B, and any of the through silicon vias (TSVs) 157 of the FPGA IC chip 200 of the second subsystem unit 194 of its first subsystem unit 193 and any of the bonded metal bumps or contacts 563-2 of its first subsystem unit 193 may be formed for one of the programmable interconnects 361 of the inter-chip interconnects 371 between the FPGA IC chip 200 and second semiconductor IC chip 100b as illustrated in FIG. 5B.

Referring to FIG. 18, the tenth type of FPMCP 313 may perform the operation between the FPGA IC chip 200 and each of the third and fourth semiconductor IC chips 100c and 100d as illustrated in FIG. 5C. For the tenth type of FPMCP 313, the FPGA IC chip 200 of the second subsystem unit 194 of its first subsystem unit 193 may have the same circuits as one illustrated in FIG. 5C. For a first scenario, the logic computing IC chip 269 of the second subsystem unit 194 of its first subsystem unit 193 may be the third semiconductor IC chip 100c as illustrated in FIG. 5C, and the auxiliary IC chip 411 of its first subsystem unit 193 may be the fourth semiconductor IC chip 100d as illustrated in FIG. 5C. In the first scenario, for the second subsystem unit 194 of its first subsystem unit 193 formed by hybrid bonding as illustrated in FIGS. 13A and 18, each bonded two of a first portion of the metal pads 6a of the FPGA IC chip 200 and logic computing IC chip 269 of the second subsystem unit 194 of its first subsystem unit 193 may be formed for one of the programmable interconnects 361 of the inter-chip interconnects 371 between the FPGA IC chip 200 and third semiconductor IC chip 100c as illustrated in FIG. 5C, and any bonded two of a second portion of the metal pads 6a of the FPGA IC chip 200 and logic computing IC chip 269 of the second subsystem unit 194 of its first subsystem unit 193, any of the through silicon vias (TSVs) 157 of the logic computing IC chip 269 of the second subsystem unit 194 of its first subsystem unit 193, any of the bonded metal bumps or contacts 563-1 of its first subsystem unit 193 and any of the through silicon vias (TSVs) 157 of the fourth semiconductor IC chip 100d of its first subsystem unit 193 may be formed for one of the programmable interconnects 361 of the inter-chip interconnects 371 between the FPGA IC chip 200 and fourth semiconductor IC chip 100d as illustrated in FIG. 5C. Alternatively, for the second subsystem unit 194 of its first subsystem unit 193 formed by wafer bumping as illustrated in FIGS. 13B and 18, each of a first portion of the bonded metal bumps or contacts 563 between the FPGA IC chip 200 and logic computing IC chip 269 of the second subsystem unit 194 of its first subsystem unit 193 may be formed for one of the programmable interconnects 361 of the inter-chip interconnects 371 between the FPGA IC chip 200 and third semiconductor IC chip 100c as illustrated in FIG. 5C, and any of a second portion of the bonded metal bumps or contacts 563 between the FPGA IC chip 200 and logic computing IC chip 269 of the second subsystem unit 194 of its first subsystem unit 193, any of the through silicon vias (TSVs) 157 of the logic computing IC chip 269 of the second subsystem unit 194 of its first subsystem unit 193, any of the bonded metal bumps or contacts 563-1 of its first subsystem unit 193 and any of the through silicon vias (TSVs) 157 of the fourth semiconductor IC chip 100d of its first subsystem unit 193 may be formed for one of the programmable interconnects 361 of the inter-chip interconnects 371 between the FPGA IC chip 200 and fourth semiconductor IC chip 100d as illustrated in FIG. 5C. For a second scenario, the logic computing IC chip 269 of the second subsystem unit 194 of its first subsystem unit 193 may be the third semiconductor IC chip 100c as illustrated in FIG. 5C, and the NVM IC chip 250 of its first subsystem unit 193 may be the fourth semiconductor IC chip 100d as illustrated in FIG. 5C. In the second scenario, for the second subsystem unit 194 of its first subsystem unit 193 formed by hybrid bonding as illustrated in FIGS. 13A and 18, each bonded two of the metal pads 6a of the FPGA IC chip 200 and logic computing IC chip 269 of the second subsystem unit 194 of its first subsystem unit 193 may be formed for one of the programmable interconnects 361 of the inter-chip interconnects 371 between the FPGA IC chip 200 and third semiconductor IC chip 100c as illustrated in FIG. 5C, and any of the through silicon vias (TSVs) 157 of the FPGA IC chip 200 of the second subsystem unit 194 of its first subsystem unit 193 and any of the bonded metal bumps or contacts 563-2 of its first subsystem unit 193 may be formed for one of the programmable interconnects 361 of the inter-chip interconnects 371 between the FPGA IC chip 200 and fourth semiconductor IC chip 100d as illustrated in FIG. 5C. Alternatively, for the second subsystem unit 194 of its first subsystem unit 193 formed by wafer bumping as illustrated in FIGS. 13B and 18, each of the bonded metal bumps or contacts 563 between the FPGA IC chip 200 and logic computing IC chip 269 of the second subsystem unit 194 of its first subsystem unit 193 may be formed for one of the programmable interconnects 361 of the inter-chip interconnects 371 between the FPGA IC chip 200 and third semiconductor IC chip 100c as illustrated in FIG. 5C, and any of the through silicon vias (TSVs) 157 of the FPGA IC chip 200 of the second subsystem unit 194 of its first subsystem unit 193 and any of the bonded metal bumps or contacts 563-2 of its first subsystem unit 193 may be formed for one of the programmable interconnects 361 of the inter-chip interconnects 371 between the FPGA IC chip 200 and fourth semiconductor IC chip 100d as illustrated in FIG. 5C.

Referring to FIG. 18, the tenth type of FPMCP 313 may have the connection to external circuits as illustrated in FIG. 5D. For the tenth type of FPMCP 313, the FPGA IC chip 200 of the second subsystem unit 194 of its first subsystem unit 193 may have the same circuits as one illustrated in FIG. 5D, the auxiliary IC chip 411 of its first subsystem unit 193 may have the same circuits as one illustrated in FIG. 5D, the logic computing IC chip 269 of the second subsystem unit 194 of its first subsystem unit 193 may be the fifth semiconductor IC chip 100e as illustrated in FIG. 5D, and the NVM IC chip 250 of its first subsystem unit 193 may be the sixth semiconductor IC chip 100f as illustrated in FIG. 5D. For the second subsystem unit 194 of its first subsystem unit 193 formed by hybrid bonding as illustrated in FIGS. 13A and 18, each bonded two of a first portion of the metal pads 6a of the FPGA IC chip 200 and logic computing IC chip 269 of the second subsystem unit 194 of its first subsystem unit 193 may be formed for one of the programmable interconnects 361 of the inter-chip interconnects 371 between the FPGA IC chip 200 and fifth semiconductor IC chip 100e as illustrated in FIG. 5D, any of the through silicon vias (TSVs) 157 of the FPGA IC chip 200 of the second subsystem unit 194 of its first subsystem unit 193 and any of the bonded metal bumps or contacts 563-2 of its first subsystem unit 193 may be formed for one of the programmable interconnects 361 of the inter-chip interconnects 371 between the FPGA IC chip 200 and sixth semiconductor IC chip 100f as illustrated in FIG. 5D, and any bonded two of a second portion of the metal pads 6a of the FPGA IC chip 200 and logic computing IC chip 269 of the second subsystem unit 194 of its first subsystem unit 193, any of the through silicon vias (TSVs) 157 of the logic computing IC chip 269 of the second subsystem unit 194 of its first subsystem unit 193, any of the bonded metal bumps or contacts 563-1 of its first subsystem unit 193 and any of the through silicon vias (TSVs) 157 of the auxiliary IC chip 411 of its first subsystem unit 193 may be formed for one of the programmable interconnects 361 of the inter-chip interconnects 371 between the FPGA IC chip 200 and auxiliary IC chip 411 as illustrated in FIG. 5D. Alternatively, for the second subsystem unit 194 of its first subsystem unit 193 formed by wafer bumping as illustrated in FIGS. 13B and 18, each of a first portion of the bonded metal bumps or contacts 563 between the FPGA IC chip 200 and logic computing IC chip 269 of the second subsystem unit 194 of its first subsystem unit 193 may be formed for one of the programmable interconnects 361 of the inter-chip interconnects 371 between the FPGA IC chip 200 and fifth semiconductor IC chip 100e as illustrated in FIG. 5D, any of the through silicon vias (TSVs) 157 of the FPGA IC chip 200 of the second subsystem unit 194 of its first subsystem unit 193 and any of the bonded metal bumps or contacts 563-2 of its first subsystem unit 193 may be formed for one of the programmable interconnects 361 of the inter-chip interconnects 371 between the FPGA IC chip 200 and sixth semiconductor IC chip 100f as illustrated in FIG. 5D, and any of a second portion of the bonded metal bumps or contacts 563 between the FPGA IC chip 200 and logic computing IC chip 269 of the second subsystem unit 194 of its first subsystem unit 193, any of the through silicon vias (TSVs) 157 of the logic computing IC chip 269 of the second subsystem unit 194 of its first subsystem unit 193, any of the bonded metal bumps or contacts 563-1 of its first subsystem unit 193 and any of the through silicon vias (TSVs) 157 of the auxiliary IC chip 411 of its first subsystem unit 193 may be formed for one of the programmable interconnects 361 of the inter-chip interconnects 371 between the FPGA IC chip 200 and auxiliary IC chip 411 as illustrated in FIG. 5D. For the tenth type of FPMCP 313, each of the large input/output (I/O) circuits 341 of the large-input/output (I/O) block of the auxiliary IC chip 411 of its first subsystem unit 193 may couple to any of its solder balls 538, which are in an array at its bottom to act as its external pins for coupling to the external circuits 340 as seen in FIG. 5D outside of the tenth type of FPMCP 313, through, in sequence, any of the first, second, third or fourth type of micro-bumps, micro-pillars or micro-pads 34 of the auxiliary IC chip 411 of its first subsystem unit 193 and each of the interconnection metal layer of its ball-grid-array (BGA) substrate 537.

For the tenth type of FPMCP 313 as illustrated in FIG. 18, the auxiliary IC chip 411 of its first subsystem unit 193 may include a first small input/output (I/O) circuit coupling to a second small input/output (I/O) circuit of the FPGA IC chip 200 of the second subsystem unit 194 of its first subsystem unit 193 through its first signal path composed of (1) any of the through silicon vias (TSVs) 157 of the auxiliary IC chip 411 of its first subsystem unit 193, any of the bonded metal bumps or contacts 563-1 of its first subsystem unit 193, any of the through silicon vias (TSVs) 157 of the logic computing IC chip 269 of the second subsystem unit 194 of its first subsystem unit 193 and any bonded two of the metal pads 6a of the FPGA IC chip 200 and logic computing IC chip 269 of the second subsystem unit 194 of its first subsystem unit 193, or (2) any of the through silicon vias (TSVs) 157 of the auxiliary IC chip 411 of its first subsystem unit 193, any of the bonded metal bumps or contacts 563-1 of its first subsystem unit 193, any of the through silicon vias (TSVs) 157 of the logic computing IC chip 269 of the second subsystem unit 194 of its first subsystem unit 193 and any of the bonded metal bumps or contacts 563 between the FPGA IC chip 200 and logic computing IC chip 269 of the second subsystem unit 194 of its first subsystem unit 193, wherein each of the first and second small input/output (I/O) circuits may have an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts. The auxiliary IC chip 411 of its first subsystem unit 193 may include a large input/output (I/O) circuit coupling to any of its solder balls 538 through its second signal path composed of any of the first, second, third or fourth type of micro-bumps, micro-pillars or micro-pads 34 of the auxiliary IC chip 411 of its first subsystem unit 193 and each of the interconnection metal layer of its ball-grid-array (BGA) substrate 537, wherein the large input/output (I/O) circuit may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or equal to or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Thereby, the first small input/output (I/O) circuit may receive first signals from the second small input/output (I/O) circuit via its first signal path to be converted by the auxiliary IC chip 411 of its first subsystem unit 193 as second signals and then the large input/output (I/O) circuit may transmit the second signals to said any of its solder balls 538 via its second signal path. Further, the large input/output (I/O) circuit may receive third signals from said any of its solder balls 538 via its second signal path to be converted by the auxiliary IC chip 411 of its first subsystem unit 193 as fourth signals and then the first small input/output (I/O) circuit may transmit the fourth signals to the second small input/output (I/O) circuit via its first signal path.

For the tenth type of FPMCP 313 as illustrated in FIG. 18, the FPGA IC chip 200 of the second subsystem unit 194 of its first subsystem unit 193 may be programmed, configured or reconfigured following the same way as any aspect of the first through eleventh aspects illustrated in FIGS. 5A-1, 5A-2 and 5E-5G, including (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with first data stored in the NVM IC chip 250 of its first subsystem unit 193 to be configured in accordance with the first data, (2) the first or second type of field programmable switch cell 379 as illustrated in FIG. 2A or 2B having the memory cells 362 as illustrated in FIG. 2A or the four sets of memory cells 362 as illustrated in FIG. 2B for storing data associated with second data stored in the NVM IC chip 250 of its first subsystem unit 193 to be configured in accordance with the second data, and (3) the programmable switch matrix 710 as illustrated in FIG. 2C having the memory cells 398 for storing data, i.e., programming codes, password or encryption/decryption codes, associated with third data stored in its NVM IC chip 250 to be configured in accordance with the third data. Alternatively, the FPGA IC chip 200 of the second subsystem unit 194 of its first subsystem unit 193 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MLU) IC chip, or digital-signal-processing (DSP) IC chip, each of which may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with the first data to be configured in accordance with the first data, (2) the first or second type of field programmable switch cell 379 as illustrated in FIG. 2A or 2B having the memory cells 362 as illustrated in FIG. 2A or the four sets of memory cells 362 as illustrated in FIG. 2B for storing data associated with the second data to be configured in accordance with the second data, and (3) the programmable switch matrix 710 as illustrated in FIG. 2C having the memory cells 398 for storing data, i.e., programming codes, password or encryption/decryption codes, associated with the third data to be configured in accordance with the third data. For the tenth type of FPMCP 313 for each aspect of the first through fourth aspects as illustrated in FIG. 5E, the FPGA IC chip 200 of the second subsystem unit 194 of its first subsystem unit 193 may have the same circuits as one illustrated in FIG. 5E, the auxiliary IC chip 411 of its first subsystem unit 193 may have the same circuits as one illustrated in FIG. 5E, the NVM IC chip 250 of its first subsystem unit 193 may have the same circuits as one illustrated in FIG. 5E, and the logic computing IC chip 269 of the second subsystem unit 194 of its first subsystem unit 193 may be any of the semiconductor IC chips 100g as illustrated in FIG. 5E. For the second subsystem unit 194 of its first subsystem unit 193 formed by hybrid bonding as illustrated in FIGS. 13A and 15A, any bonded two of a first portion of the metal pads 6a of the FPGA IC chip 200 and logic computing IC chip 269 of the second subsystem unit 194 of the first subsystem unit 193, any of a first portion of the through silicon vias (TSVs) 157 of the logic computing IC chip 269 of the second subsystem unit 194 of the first subsystem unit 193, any of a first portion of the bonded metal bumps or contacts 563-1 and any of a first portion of the through silicon vias (TSVs) 157 of the auxiliary IC chip 411 of the first subsystem unit 193 for the tenth type of FPMCP 313 as seen in FIG. 18 may be formed for one of the non-programmable interconnects 364 of the inter-chip interconnects 371 between the FPGA IC chip 200 and auxiliary IC chip 411 as illustrated in FIG. 5E, and alternatively, for the second subsystem unit 194 of its first subsystem unit 193 formed by wafer bumping as illustrated in FIGS. 13B and 15B for any case of the first through fourth cases, any of a first portion of the bonded metal bumps or contacts 563 between the FPGA IC chip 200 and logic computing IC chip 269 of the second subsystem unit 194 of the first subsystem unit 193, any of a first portion of the through silicon vias (TSVs) 157 of the logic computing IC chip 269 of the second subsystem unit 194 of the first subsystem unit 193, any of a first portion of the bonded metal bumps or contacts 563-1 and any of a first portion of the through silicon vias (TSVs) 157 of the auxiliary IC chip 411 of the first subsystem unit 193 for the tenth type of FPMCP 313 as seen in FIG. 18 may be formed for one of the non-programmable interconnects 364 of the inter-chip interconnects 371 between the FPGA IC chip 200 and auxiliary IC chip 411 as illustrated in FIG. 5E; for the second subsystem unit 194 of its first subsystem unit 193 formed by hybrid bonding as illustrated in FIGS. 13A and 15A, any of a first portion of the bonded metal bumps or contacts 563-2, any of a first portion of the through silicon vias (TSVs) 157 of the FPGA IC chip 200 of the second subsystem unit 194 of the first subsystem unit 193, any bonded two of a second portion of the metal pads 6a of the FPGA IC chip 200 and logic computing IC chip 269 of the second subsystem unit 194 of the first subsystem unit 193, any of a second portion of the through silicon vias (TSVs) 157 of the logic computing IC chip 269 of the second subsystem unit 194 of the first subsystem unit 193, any of a second portion of the bonded metal bumps or contacts 563-1 and any of a second portion of the through silicon vias (TSVs) 157 of the auxiliary IC chip 411 of the first subsystem unit 193 for the tenth type of FPMCP 313 as seen in FIG. 18 may be formed for one of the non-programmable interconnects 364 of the inter-chip interconnects 371 between the NVM IC chip 250 and auxiliary IC chip 411 as illustrated in FIG. 5E, and alternatively, for the second subsystem unit 194 of its first subsystem unit 193 formed by wafer bumping as illustrated in FIGS. 13B and 15B for any case of the first through fourth cases, any of a first portion of the bonded metal bumps or contacts 563-2, any of a first portion of the through silicon vias (TSVs) 157 of the FPGA IC chip 200 of the second subsystem unit 194 of the first subsystem unit 193, any of a second portion of the bonded metal bumps or contacts 563 between the FPGA IC chip 200 and logic computing IC chip 269 of the second subsystem unit 194 of the first subsystem unit 193, any of a second portion of the through silicon vias (TSVs) 157 of the logic computing IC chip 269 of the second subsystem unit 194 of the first subsystem unit 193, any of a second portion of the bonded metal bumps or contacts 563-1 and any of a second portion of the through silicon vias (TSVs) 157 of the auxiliary IC chip 411 of the first subsystem unit 193 for the tenth type of FPMCP 313 as seen in FIG. 18 may be formed for one of the non-programmable interconnects 364 of the inter-chip interconnects 371 between the NVM IC chip 250 and auxiliary IC chip 411 as illustrated in FIG. 5E; for the second subsystem unit 194 of its first subsystem unit 193 formed by hybrid bonding as illustrated in FIGS. 13A and 15A, each bonded two of a third portion of the metal pads 6a of the FPGA IC chip 200 and logic computing IC chip 269 of the second subsystem unit 194 of the first subsystem unit 193 for the tenth type of FPMCP 313 as seen in FIG. 18 may be formed for one of the programmable interconnects 361 of the inter-chip interconnects 371 between the FPGA IC chip 200 and any of the semiconductor IC chips 100g as illustrated in FIG. 5E, and alternatively, for the second subsystem unit 194 of its first subsystem unit 193 formed by wafer bumping as illustrated in FIGS. 13B and 15B for any case of the first through fourth cases, each of a third portion of the bonded metal bumps or contacts 563 between the FPGA IC chip 200 and logic computing IC chip 269 of the second subsystem unit 194 of the first subsystem unit 193 for the tenth type of FPMCP 313 as seen in FIG. 18 may be formed for one of the programmable interconnects 361 of the inter-chip interconnects 371 between the FPGA IC chip 200 and any of the semiconductor IC chips 100g as illustrated in FIG. 5E; for the second subsystem unit 194 of its first subsystem unit 193 formed by hybrid bonding as illustrated in FIGS. 13A and 15A, any of a second portion of the bonded metal bumps or contacts 563-2, any of a second portion of the through silicon vias (TSVs) 157 of the FPGA IC chip 200 of the second subsystem unit 194 of the first subsystem unit 193, any bonded two of a fourth portion of the metal pads 6a of the FPGA IC chip 200 and logic computing IC chip 269 of the second subsystem unit 194 of the first subsystem unit 193, any of a third portion of the through silicon vias (TSVs) 157 of the logic computing IC chip 269 of the second subsystem unit 194 of the first subsystem unit 193, any of a third portion of the bonded metal bumps or contacts 563-1, any of a third portion of the through silicon vias (TSVs) 157 of the auxiliary IC chip 411 of the first subsystem unit 193, any of a first portion of the first, second, third or fourth type of micro-bumps, micro-pillars or micro-pads 34 of the auxiliary IC chip 411 of the first subsystem unit 193, each of the interconnection metal layer of the ball-grid-array (BGA) substrate 537 and any of the solder balls 538 for the tenth type of FPMCP 313 as seen in FIG. 18 may be formed for the first group of the large input/output (I/O) circuits 342 of the NVM IC chip 250 receiving and transmitting the first and second (encrypted) CPM data from and to the external circuits 340 as illustrated in FIG. 5E outside of the tenth type of FPMCP 313, and alternatively, for the second subsystem unit 194 of its first subsystem unit 193 formed by wafer bumping as illustrated in FIGS. 13B and 15B for any case of the first through fourth cases, any of a second portion of the bonded metal bumps or contacts 563-2, any of a second portion of the through silicon vias (TSVs) 157 of the FPGA IC chip 200 of the second subsystem unit 194 of the first subsystem unit 193, any of a fourth portion of the bonded metal bumps or contacts 563 between the FPGA IC chip 200 and logic computing IC chip 269 of the second subsystem unit 194 of the first subsystem unit 193, any of a third portion of the through silicon vias (TSVs) 157 of the logic computing IC chip 269 of the second subsystem unit 194 of the first subsystem unit 193, any of a third portion of the bonded metal bumps or contacts 563-1, any of a third portion of the through silicon vias (TSVs) 157 of the auxiliary IC chip 411 of the first subsystem unit 193, any of a first portion of the first, second, third or fourth type of micro-bumps, micro-pillars or micro-pads 34 of the auxiliary IC chip 411 of the first subsystem unit 193, each of the interconnection metal layer of the ball-grid-array (BGA) substrate 537 and any of the solder balls 538 for the tenth type of FPMCP 313 as seen in FIG. 18 may be formed for the first group of the large input/output (I/O) circuits 342 of the NVM IC chip 250 receiving and transmitting the first and second (encrypted) CPM data from and to the external circuits 340 as illustrated in FIG. 5E outside of the tenth type of FPMCP 313; optionally for each aspect of the first through third aspects any of a second portion of the first, second, third or fourth type of micro-bumps, micro-pillars or micro-pads 34 of the auxiliary IC chip 411 of the first subsystem unit 193, each of the interconnection metal layer of the ball-grid-array (BGA) substrate 537 and any of the solder balls 538 for the tenth type of FPMCP 313 as seen in FIG. 18 may be formed for the large input/output (I/O) circuits 341 of the large-input/output (I/O) block of the auxiliary IC chip 411 receiving and transmitting the first and second (encrypted) CPM data from and to the external circuits 340 as illustrated in FIG. 5E outside of the tenth type of FPMCP 313. For the tenth type of FPMCP 313 for each aspect of the fifth through eighth aspects as illustrated in FIG. 5F, the FPGA IC chip 200 of the second subsystem unit 194 of its first subsystem unit 193 may have the same circuits as one illustrated in FIG. 5F, the auxiliary IC chip 411 of its first subsystem unit 193 may have the same circuits as one illustrated in FIG. 5F, the NVM IC chip 250 of its first subsystem unit 193 may have the same circuits as one illustrated in FIG. 5F, and the logic computing IC chip 269 of the second subsystem unit 194 of its first subsystem unit 193 may be any of the semiconductor IC chips 100g as illustrated in FIG. 5F. Any of a first portion of the bonded metal bumps or contacts 563-2 and any of a first portion of the through silicon vias (TSVs) 157 of the FPGA IC chip 200 of the second subsystem unit 194 of the first subsystem unit 193 for the tenth type of FPMCP 313 as seen in FIG. 18 may be formed for one of the non-programmable interconnects 364 of the inter-chip interconnects 371 between the NVM IC chip 250 and FPGA IC chip 200 as illustrated in FIG. 5F; for the second subsystem unit 194 of its first subsystem unit 193 formed by hybrid bonding as illustrated in FIGS. 13A and 15A, any of a second portion of the bonded metal bumps or contacts 563-2, any of a second portion of the through silicon vias (TSVs) 157 of the FPGA IC chip 200 of the second subsystem unit 194 of the first subsystem unit 193, any bonded two of a first portion of the metal pads 6a of the FPGA IC chip 200 and logic computing IC chip 269 of the second subsystem unit 194 of the first subsystem unit 193, any of a first portion of the through silicon vias (TSVs) 157 of the logic computing IC chip 269 of the second subsystem unit 194 of the first subsystem unit 193, any of a first portion of the bonded metal bumps or contacts 563-1 and any of a first portion of the through silicon vias (TSVs) 157 of the auxiliary IC chip 411 of the first subsystem unit 193 for the tenth type of FPMCP 313 as seen in FIG. 18 may be formed for one of the non-programmable interconnects 364 of the inter-chip interconnects 371 between the NVM IC chip 250 and auxiliary IC chip 411 as illustrated in FIG. 5F, and alternatively, for the second subsystem unit 194 of its first subsystem unit 193 formed by wafer bumping as illustrated in FIGS. 13B and 15B for any case of the first through fourth cases, any of a second portion of the bonded metal bumps or contacts 563-2, any of a second portion of the through silicon vias (TSVs) 157 of the FPGA IC chip 200 of the second subsystem unit 194 of the first subsystem unit 193, any of a first portion of the bonded metal bumps or contacts 563 between the FPGA IC chip 200 and logic computing IC chip 269 of the second subsystem unit 194 of the first subsystem unit 193, any of a first portion of the through silicon vias (TSVs) 157 of the logic computing IC chip 269 of the second subsystem unit 194 of the first subsystem unit 193, any of a first portion of the bonded metal bumps or contacts 563-1 and any of a first portion of the through silicon vias (TSVs) 157 of the auxiliary IC chip 411 of the first subsystem unit 193 for the tenth type of FPMCP 313 as seen in FIG. 18 may be formed for one of the non-programmable interconnects 364 of the inter-chip interconnects 371 between the NVM IC chip 250 and auxiliary IC chip 411 as illustrated in FIG. 5F; for the second subsystem unit 194 of its first subsystem unit 193 formed by hybrid bonding as illustrated in FIGS. 13A and 15A, each bonded two of a second portion of the metal pads 6a of the FPGA IC chip 200 and logic computing IC chip 269 of the second subsystem unit 194 of the first subsystem unit 193 for the tenth type of FPMCP 313 as seen in FIG. 18 may be formed for one of the programmable interconnects 361 of the inter-chip interconnects 371 between the FPGA IC chip 200 and any of the semiconductor IC chips 100g as illustrated in FIG. 5F, and alternatively, for the second subsystem unit 194 of its first subsystem unit 193 formed by wafer bumping as illustrated in FIGS. 13B and 15B for any case of the first through fourth cases, each of a second portion of the bonded metal bumps or contacts 563 between the FPGA IC chip 200 and logic computing IC chip 269 of the second subsystem unit 194 of the first subsystem unit 193 for the tenth type of FPMCP 313 as seen in FIG. 18 may be formed for one of the programmable interconnects 361 of the inter-chip interconnects 371 between the FPGA IC chip 200 and any of the semiconductor IC chips 100g as illustrated in FIG. 5F; any of the first, second, third or fourth type of micro-bumps, micro-pillars or micro-pads 34 of the auxiliary IC chip 411 of the first subsystem unit 193, each of the interconnection metal layer of the ball-grid-array (BGA) substrate 537 and any of the solder balls 538 for the tenth type of FPMCP 313 as seen in FIG. 18 may be formed for the large input/output (I/O) circuits 341 of the large-input/output (I/O) block of the auxiliary IC chip 411 receiving and transmitting the first and second (encrypted) CPM data from and to the external circuits 340 as illustrated in FIG. 5F outside of the tenth type of FPMCP 313. For the tenth type of FPMCP 313 for each aspect of the ninth through eleventh aspects as illustrated in FIG. 5G, the FPGA IC chip 200 of the second subsystem unit 194 of its first subsystem unit 193 may have the same circuits as one illustrated in FIG. 5G, the NVM IC chip 250 of its first subsystem unit 193 may have the same circuits as one illustrated in FIG. 5G, and the logic computing IC chip 269 of the second subsystem unit 194 of its first subsystem unit 193 may be any of the semiconductor IC chips 100g as illustrated in FIG. 5G. Any of a first portion of the bonded metal bumps or contacts 563-2 and any of a first portion of the through silicon vias (TSVs) 157 of the FPGA IC chip 200 of the second subsystem unit 194 of the first subsystem unit 193 for the tenth type of FPMCP 313 as seen in FIG. 18 may be formed for one of the non-programmable interconnects 364 of the inter-chip interconnects 371 between the FPGA IC chip 200 and NVM IC chip 250 as illustrated in FIG. 5G; for the second subsystem unit 194 of its first subsystem unit 193 formed by hybrid bonding as illustrated in FIGS. 13A and 15A, each bonded two of a first portion of the metal pads 6a of the FPGA IC chip 200 and logic computing IC chip 269 of the second subsystem unit 194 of the first subsystem unit 193 for the tenth type of FPMCP 313 as seen in FIG. 18 may be formed for one of the programmable interconnects 361 of the inter-chip interconnects 371 between the FPGA IC chip 200 and any of the semiconductor IC chips 100g as illustrated in FIG. 5G, and alternatively, for the second subsystem unit 194 of its first subsystem unit 193 formed by wafer bumping as illustrated in FIGS. 13B and 15B for any case of the first through fourth cases, each of a first portion of the bonded metal bumps or contacts 563 between the FPGA IC chip 200 and logic computing IC chip 269 of the second subsystem unit 194 of the first subsystem unit 193 for the tenth type of FPMCP 313 as seen in FIG. 18 may be formed for one of the programmable interconnects 361 of the inter-chip interconnects 371 between the FPGA IC chip 200 and any of the semiconductor IC chips 100g as illustrated in FIG. 5G; for the second subsystem unit 194 of its first subsystem unit 193 formed by hybrid bonding as illustrated in FIGS. 13A and 15A, any of a second portion of the bonded metal bumps or contacts 563-2, any of a second portion of the through silicon vias (TSVs) 157 of the FPGA IC chip 200 of the second subsystem unit 194 of the first subsystem unit 193, any bonded two of a second portion of the metal pads 6a of the FPGA IC chip 200 and logic computing IC chip 269 of the second subsystem unit 194 of the first subsystem unit 193, any of the through silicon vias (TSVs) 157 of the logic computing IC chip 269 of the second subsystem unit 194 of the first subsystem unit 193, any of the bonded metal bumps or contacts 563-1, any of the through silicon vias (TSVs) 157 of the auxiliary IC chip 411 of the first subsystem unit 193, any of the first, second, third or fourth type of micro-bumps, micro-pillars or micro-pads 34 of the auxiliary IC chip 411 of the first subsystem unit 193, each of the interconnection metal layer of the ball-grid-array (BGA) substrate 537 and any of the solder balls 538 for the tenth type of FPMCP 313 as seen in FIG. 18 may be formed for the large input/output (I/O) circuits 342 of the NVM IC chip 250 receiving and transmitting the first and second (encrypted) CPM data from and to the external circuits 340 as illustrated in FIG. 5G outside of the tenth type of FPMCP 313, and alternatively, for the second subsystem unit 194 of its first subsystem unit 193 formed by wafer bumping as illustrated in FIGS. 13B and 15B for any case of the first through fourth cases, any of a second portion of the bonded metal bumps or contacts 563-2, any of a second portion of the through silicon vias (TSVs) 157 of the FPGA IC chip 200 of the second subsystem unit 194 of the first subsystem unit 193, any of a second portion of the bonded metal bumps or contacts 563 between the FPGA IC chip 200 and logic computing IC chip 269 of the second subsystem unit 194 of the first subsystem unit 193, any of the through silicon vias (TSVs) 157 of the logic computing IC chip 269 of the second subsystem unit 194 of the first subsystem unit 193, any of the bonded metal bumps or contacts 563-1, any of the through silicon vias (TSVs) 157 of the auxiliary IC chip 411 of the first subsystem unit 193, any of the first, second, third or fourth type of micro-bumps, micro-pillars or micro-pads 34 of the auxiliary IC chip 411 of the first subsystem unit 193, each of the interconnection metal layer of the ball-grid-array (BGA) substrate 537 and any of the solder balls 538 for the tenth type of FPMCP 313 as seen in FIG. 18 may be formed for the large input/output (I/O) circuits 342 of the NVM IC chip 250 receiving and transmitting the first and second (encrypted) CPM data from and to the external circuits 340 as illustrated in FIG. 5G outside of the tenth type of FPMCP 313.

### Eleventh Type of FPMCP

FIGS. 19 and 19-1 are schematically cross-sectional views showing an eleventh type of FPMCP for a first alternative in accordance with an embodiment of the present application. An eleventh type of FPMCP 314 for a first alternative as seen in FIGS. 19 and 19-1 may include (1) a ball-grid-array (BGA) substrate 537 having multiple interconnection metal layers 668 and multiple insulating dielectric layers 676 and 683 each between neighboring two of the interconnection metal layers 668 of its ball-grid-array (BGA) substrate 537, on and over a topmost one of the interconnection metal layers 668 of its ball-grid-array (BGA) substrate 537, or on and under a bottommost one of the interconnection metal layers 668 of its ball-grid-array (BGA) substrate 537, wherein multiple openings in the topmost one of the insulating dielectric layers 676 and 683 of its ball-grid-array (BGA) substrate 537 may be over multiple metal pads of the topmost one of the interconnection metal layers 668 of its ball-grid-array (BGA) substrate 537 respectively, and multiple openings in the bottommost one of the insulating dielectric layers 676 and 683 of its ball-grid-array (BGA) substrate 537 may be under multiple metal pads 528 of the bottommost one of the interconnection metal layers 668 of its ball-grid-array (BGA) substrate 537 respectively, (2) a logic chip package 422 over and bonded to a top surface of its ball-grid-array (BGA) substrate 537, (3) a NVM chip package 336 over and bonded to the top surface of its ball-grid-array (BGA) substrate 537, (4) an input/output (I/O) or control chip package 424 over and bonded to the top surface of its ball-grid-array (BGA) substrate 537, (5) multiple passive devices 566, each of which may be a capacitor, resistor or inductor, mounted to both top and bottom sides of its ball-grid-array (BGA) substrate 537 via a tin-containing solder 567, and (6) multiple solder balls 538, made of a tin-lead alloy or tin-silver-copper alloy, in an array at its bottom to act as external pins of the eleventh type of FPMCP 314 for the first alternative, wherein each of its solder balls 538 may be formed on a bottom surface of one of the metal pads 528 of the bottommost one of the interconnection metal layers of its ball-grid-array (BGA) substrate 537.

For more elaboration, for eleventh type of FPMCP 314 for the first alternative as seen in FIGS. 19 and 19-1, its ball-grid-array (BGA) substrate 537 may include (1) a core layer 661, such as FR4, containing epoxy or bismaleimide-triazine (BT) resin and having a thickness between 200 and 1000 micrometers or between 400 and 800 micrometers, wherein FR4 may be a composite material composed of woven fiberglass cloth and an epoxy resin binder, (2) the interconnection metal layers 668, made of copper, each having a thickness between 10 and 50 micrometers, between 25 and 50 micrometers, between 10 and 40 micrometers or between 10 and 20 micrometers and over or under the core layer 661 of its ball-grid-array (BGA) substrate 537, wherein each of the interconnection metal layers 668 of its ball-grid-array (BGA) substrate 537 over the core layer 661 of its ball-grid-array (BGA) substrate 537 may couple to any of the interconnection metal layers 668 of its ball-grid-array (BGA) substrate 537 under the core layer 661 of its ball-grid-array (BGA) substrate 537 through a through hole 661a in the core layer 661 of its ball-grid-array (BGA) substrate 537, (3) the insulating dielectric layers 676, i.e., polymer layers, such as Ajinomoto build-up films (ABFs) or layers of bismaleimide-triazine (BT) resin, each having a thickness between 10 and 50 micrometers, between 15 and 40 micrometers or between 20 and 30 micrometers and over or under the core layer 661 of its ball-grid-array (BGA) substrate 537 and between neighboring two of the interconnection metal layers 668 of its ball-grid-array (BGA) substrate 537, wherein each of the Ajinomoto build-up films (ABFs) may be made of epoxy, phenol hardener, cyanate ester and thermosetting olefin, and (4) two solder masks 683, i.e., insulating dielectric layers, each made of a polymer layer having a thickness between 10 and 50 micrometers, between 15 and 40 micrometers or between 20 and 30 micrometers, at the top and bottom of its ball-grid-array (BGA) substrate 537 respectively to cover the topmost and bottommost ones of the interconnection metal layers 668 of its ball-grid-array (BGA) substrate 537 respectively, wherein the topmost one of the interconnection metal layers 668 of its ball-grid-array (BGA) substrate 537 may include the metal pads each at a bottom of an opening in the top one of the two solder masks 683 of its ball-grid-array (BGA) substrate 537 and the bottommost one of the interconnection metal layers 668 of its ball-grid-array (BGA) substrate 537 may include the metal pads 528 each at a top of an opening in the bottom one of the two solder masks 683 of its ball-grid-array (BGA) substrate 537. Further, a topmost one of the interconnection metal layers 668 of its ball-grid-array (BGA) substrate 537 over the core layer 661 of its ball-grid-array (BGA) substrate 537 may be formed on a top surface of a topmost one of the insulating dielectric layers 676 of its ball-grid-array (BGA) substrate 537 over the core layer 661 of its ball-grid-array (BGA) substrate 537 and a top one of the solder masks 683 of its ball-grid-array (BGA) substrate 537 may be formed on the top surface of the topmost one of the insulating dielectric layers 676 and the topmost one of the interconnection metal layers 668. The topmost one of the interconnection metal layers 668 may include a first and second metal interconnect 111 and 113 each provided with a copper layer having a thickness between 10 and 50 micrometers, between 25 and 50 micrometers, between 10 and 40 micrometers or between 10 and 20 micrometers and having a bottom surface on and in contact with the top surface of the topmost one of the insulating dielectric layers 676 and a sidewall and top surface in contact with the top one of the solder masks 683. Alternatively, its ball-grid-array (BGA) substrate 537 may be formed without the core layer 661 to be formed as a coreless ball-grid-array (BGA) substrate.

Referring to FIGS. 19 and 19-1, for eleventh type of FPMCP 314 for the first alternative, its logic chip package 422 may include (1) a circuit substrate, such as the interposer 551 as illustrated in FIGS. 6A and 6C, for a 2.5D interposer package, wherein the interposer 551 of its logic chip package 422 may include (i) the silicon substrate 552, (ii) the through silicon vias 558 each vertically in the silicon substrate 552 of the interposer 551 of its logic chip package 422, (iii) the interconnection metal layers 67 over the silicon substrate 552 of the interposer 551 of its logic chip package 422, and (iv) the insulating dielectric layers 112 each between an upper and lower one of the interconnection metal layers 67 of the interposer 551 of its logic chip package 422, wherein the upper one of the interconnection metal layers 67 of the interposer 551 of its logic chip package 422 may horizontally extend on said each of the insulating dielectric layers 112 of the interposer 551 of its logic chip package 422 and into an opening in said each of the insulating dielectric layers 112 of the interposer 551 of its logic chip package 422 to contact the lower one of the interconnection metal layers 67 of the interposer 551 of its logic chip package 422, and (2) a logic chip, application-specific integrated-circuit (ASIC) chip or system-on-chip (SoC) IC chip, such as FPGA IC chip 200 having the same specification as one illustrated in FIG. 5A-1, having the same specification as the first type of semiconductor IC chip 100 as illustrated in FIG. 3A to be turned upside down. The FPGA IC chip 200 of its logic chip package 422 may have the first, second, third or fourth type of micro-bumps, micro-pillars or micro-pads 34 bonded to the interposer 551 of its logic chip package 422 to form multiple bonded metal bumps or contacts 563 between the FPGA IC chip 200 of its logic chip package 422 and the interposer 551 of its logic chip package 422, wherein each of the bonded metal bumps or contacts 563 of its logic chip package 422 may include (1) a copper layer having a thickness between 1 μm and 60 μm, between 2 μm and 20 μm or between 10 μm and 50 μm between the FPGA IC chip 200 of its logic chip package 422 and the interposer 551 of its logic chip package 422 and (2) a solder cap, made of a tin-silver alloy, a tin-gold alloy, a tin-copper alloy, a tin-indium alloy, indium or tin, having a thickness of between 1 μm and 15 μm, between 1 m and 50 μm or between 20 μm and 100 μm between the copper layer of said each of the bonded metal bumps or contacts 563 of its logic chip package 422 and the interposer 551 of its logic chip package 422. The FPGA IC chip 200 of its logic chip package 422 may be the dedicated field programmable integrated-circuit (DFPIC) chip as illustrated in FIG. 4D or embedded field programmable integrated-circuit (eFPIC) chip as illustrated in FIG. 4E. Its logic chip package 422 may further include (1) an underfill 564, i.e., polymer layer, between the FPGA IC chip 200 of its logic chip package 422 and the interposer 551 of its logic chip package 422, covering a sidewall of each of the bonded metal bumps or contacts 563 of its logic chip package 422, (2) a polymer layer 592 or insulating dielectric layer, i.e., sealing layer, such as silicon-oxide-containing molding compound, epoxy-based material or polyimide, over the top surface of the interposer 551 of its logic chip package 422, wherein the polymer layer 592 of its logic chip package 422 may cover a top surface of the FPGA IC chip 200 of its logic chip package 422, wherein the polymer layer 592 of its logic chip package 422 may have a vertical sidewall coplanar with a vertical sidewall of the interposer 551 of its logic chip package 422, and (3) multiple metal bumps, pillars or pads 570 in an array at a bottom of its logic chip package 422, wherein each of the metal bumps, pillars or pads 570 of its logic chip package 422 may be of one type selected from various types, i.e., first and second types, which may have the same specification as that of the first and second types of metal bumps, pillars or pads 570 respectively as illustrated in FIG. 6A, wherein each of the metal bumps, pillars or pads 570 of its logic chip package 422 may have the adhesion metal layer 26a, at a top of said each of the metal bumps, pillars or pads 570, formed on a bottom surface of one of the through silicon vias 558, i.e., the copper layer 557 thereof, of the interposer 551 of its logic chip package 422 and have a bottom end bonded to a metal pad, bump or contact 529, made of nickel, gold or copper for example, preformed on one of the metal pads of the topmost one of the interconnection metal layers 668 of its ball-grid-array (BGA) substrate 537. Alternatively, the interposer 551 of its logic chip package 422 may be replaced with a ball-grid-array (BGA) substrate for a flip-chip ball-grid-array (BGA) package.

Referring to FIGS. 19 and 19-1, for the eleventh type of FPMCP 314 for the first alternative, its input/output (I/O) or control chip package 424 may include (1) a circuit substrate, such as the interposer 551 as illustrated in FIGS. 6A and 6C for a 2.5D interposer package, wherein the interposer 551 of its input/output (I/O) or control chip package 424 may include (i) the silicon substrate 552, (ii) the through silicon vias 558 each vertically in the silicon substrate 552 of the interposer 551 of its input/output (I/O) or control chip package 424, (iii) the interconnection metal layers 67 over the silicon substrate 552 of the interposer 551 of its input/output (I/O) or control chip package 424, and (iv) the insulating dielectric layers 112 each between an upper and lower one of the interconnection metal layers 67 of the interposer 551 of its input/output (I/O) or control chip package 424, wherein the upper one of the interconnection metal layers 67 of the interposer 551 of its input/output (I/O) or control chip package 424 may horizontally extend on said each of the insulating dielectric layers 112 of the interposer 551 of its input/output (I/O) or control chip package 424 and into an opening in said each of the insulating dielectric layers 112 of the interposer 551 of its input/output (I/O) or control chip package 424 to contact the lower one of the interconnection metal layers 67 of the interposer 551 of its input/output (I/O) or control chip package 424, and (2) an application-specific integrated-circuit (ASIC) chip or system-on-chip (SoC) IC chip, such as auxiliary IC chip 411 having the same specification as one illustrated in FIG. 5A-1, having the same specification as the first type of semiconductor IC chip 100 as illustrated in FIG. 3A to be turned upside down, wherein its auxiliary IC chip 411 may be used as an input/output (I/O) or control chip. The auxiliary IC chip 411 of its input/output (I/O) or control chip package 424 may have the first, second, third or fourth type of micro-bumps, micro-pillars or micro-pads 34 bonded to the interposer 551 of its input/output (I/O) or control chip package 424 to form multiple bonded metal bumps or contacts 563 between the auxiliary IC chip 411 of its input/output (I/O) or control chip package 424 and the interposer 551 of its input/output (I/O) or control chip package 424, wherein each of the bonded metal bumps or contacts 563 of its input/output (I/O) or control chip package 424 may include (1) a copper layer having a thickness between 1 μm and 60 μm, between 2 μm and 20 μm or between 10 μm and 50 μm between the auxiliary IC chip 411 of its input/output (I/O) or control chip package 424 and the interposer 551 of its auxiliary IC chip 411 and (2) a solder cap, made of a tin-silver alloy, a tin-gold alloy, a tin-copper alloy, a tin-indium alloy, indium or tin, having a thickness of between 1 μm and 15 μm, between 1 μm and 50 μm or between 20 μm and 100 μm between the copper layer of said each of the bonded metal bumps or contacts 563 of its input/output (I/O) or control chip package 424 and the interposer 551 of its input/output (I/O) or control chip package 424. Its input/output (I/O) or control chip package 424 may further include (1) an underfill 564, i.e., polymer layer, between the auxiliary IC chip 411 of its input/output (I/O) or control chip package 424 and the interposer 551 of its input/output (I/O) or control chip package 424, covering a sidewall of each of the bonded metal bumps or contacts 563 of its input/output (I/O) or control chip package 424, (2) a polymer layer 592 or insulating dielectric layer, i.e., sealing layer, such as silicon-oxide-containing molding compound, epoxy-based material or polyimide, over the top surface of the interposer 551 of its input/output (I/O) or control chip package 424, wherein the polymer layer 592 of its input/output (I/O) or control chip package 424 may cover a top surface of the auxiliary IC chip 411 of its input/output (I/O) or control chip package 424, wherein the polymer layer 592 of its input/output (I/O) or control chip package 424 may have a vertical sidewall coplanar with a vertical sidewall of the interposer 551 of its input/output (I/O) or control chip package 424, and (3) multiple metal bumps, pillars or pads 570 in an array at a bottom of its input/output (I/O) or control chip package 424, wherein each of the metal bumps, pillars or pads 570 of its input/output (I/O) or control chip package 424 may be of one type selected from various types, i.e., first and second types, which may have the same specification as that of the first and second types of metal bumps, pillars or pads 570 respectively as illustrated in FIG. 6A, wherein each of the metal bumps, pillars or pads 570 of its input/output (I/O) or control chip package 424 may have the adhesion metal layer 26a, at a top of said each of the metal bumps, pillars or pads 570, formed on a bottom surface of one of the through silicon vias 558, i.e., the copper layer 557 thereof, of the interposer 551 of its input/output (I/O) or control chip package 424 and have a bottom end bonded to a metal pad, bump or contact 529, made of nickel, gold or copper for example, preformed on one of the metal pads of the topmost one of the interconnection metal layers 668 of its ball-grid-array (BGA) substrate 537. Alternatively, the interposer 551 of its input/output (I/O) or control chip package 424 may be replaced with a ball-grid-array (BGA) substrate.

Referring to FIGS. 19 and 19-1, for the eleventh type of FPMCP 314 for the first alternative, its non-volatile-memory (NVM) chip package 336 may include (1) two NVM IC chips 250, each of which may be a NAND or NOR flash IC chip, magnetoresistive random-access memory (MRAM) IC chip, resistive random-access memory (RRAM) IC chip or ferroelectric random-access memory (FRAM) IC chip, stacked with each other and mounted to each other via an adhesive layer 339 such as silver paste or a heat conductive paste, wherein an upper one of the two NVM IC chips 250 of its non-volatile-memory (NVM) chip package 336 may overhang from an edge of a lower one of the two NVM IC chips 250 of its non-volatile-memory (NVM) chip package 336, (2) a circuit board 335 under the two NVM IC chips 250 of its non-volatile-memory (NVM) chip package 336 to have the lower one of the two NVM IC chips 250 of its non-volatile-memory (NVM) chip package 336 to be attached to a top surface of the circuit board 335 of its non-volatile-memory (NVM) chip package 336 via an adhesive layer 334 such as silver paste or a heat conductive paste, (3) multiple wirebonded wires 333 each coupling one of the two NVM IC chips 250 of its non-volatile-memory (NVM) chip package 336 to the circuit board 335 of its non-volatile-memory (NVM) chip package 336, (4) a molded polymer 332 i.e., sealing layer, on the top surface of the circuit board 335 of its non-volatile-memory (NVM) chip package 336, encapsulating the two NVM IC chips 250 and wirebonded wires 333 of its non-volatile-memory (NVM) chip package 336 and (5) multiple solder balls 337 at a bottom of its non-volatile-memory (NVM) chip package 336, each having a top end attached to a bottom surface of circuit board 335 of its non-volatile-memory (NVM) chip package 336 and a bottom end bonded to a metal pad, bump or contact 529, made of nickel, gold or copper for example, preformed on one of the metal pads of the topmost one of the interconnection metal layers 668 of its ball-grid-array (BGA) substrate 537.

Referring to FIGS. 19 and 19-1, the eleventh type of FPMCP 314 for the first alternative may further include (1) an underfill 565, i.e., polymer layer, between its logic chip package 422 and ball-grid-array (BGA) substrate 537, between its input/output (I/O) or control chip package 424 and ball-grid-array (BGA) substrate 537 and between its NVM chip package 336 and ball-grid-array (BGA) substrate 537, covering a sidewall of each of the metal bumps, pillars or pads 570 of its logic chip package 422, a sidewall of each of the metal bumps, pillars or pads 570 of its input/output (I/O) or control chip package 424 and a sidewall of each of the solder balls 337 of its NVM chip package 336 and (2) a polymer layer 593 or insulating dielectric layer, i.e., sealing layer, such as silicon-oxide-containing molding compound, epoxy-based material or polyimide, on the top surface of its ball-grid-array (BGA) substrate 537, wherein its polymer layer 593 may cover a top surface of each of its logic chip package 422, input/output (I/O) or control chip package 424 and NVM chip package 336, and wherein its polymer layer 593 may have a vertical sidewall coplanar with a vertical sidewall of its ball-grid-array (BGA) substrate 537.

For the eleventh type of FPMCP 314 for the first alternative as seen in FIGS. 19 and 19-1, the auxiliary IC chip 411 of its input/output (I/O) or control chip package 424 may include a first small input/output (I/O) circuit coupling to a second small input/output (I/O) circuit of the FPGA IC chip 200 of its logic chip package 422 through the first metal interconnect 111 of its ball-grid-array (BGA) substrate 537, wherein the first metal interconnect 111 of its ball-grid-array (BGA) substrate 537 may comprise a first segment under across an edge of its input/output (I/O) or control chip package 424 and having a thickness between 10 and 50 micrometers, between 25 and 50 micrometers, between 10 and 40 micrometers or between 10 and 20 micrometers and a second segment under across an edge of its logic chip package 422 and having a thickness between 10 and 50 micrometers, between 25 and 50 micrometers, between 10 and 40 micrometers or between 10 and 20 micrometers, and wherein each of the first and second small input/output (I/O) circuits may have an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts. The auxiliary IC chip 411 of its input/output (I/O) or control chip package 424 may include a large input/output (I/O) circuit coupling to one of its solder balls 538 through its ball-grid-array (BGA) substrate 537, wherein the large I/O circuit may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or equal to or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Thereby, the first small input/output (I/O) circuit may receive first signals from the second small input/output (I/O) circuit via its ball-grid-array (BGA) substrate 537 to be converted by the auxiliary IC chip 411 of its input/output (I/O) or control chip package 424 as second signals and then the large input/output (I/O) circuit may transmit the second signals to said one of its solder balls 538 via its ball-grid-array (BGA) substrate 537. Further, the large input/output (I/O) circuit may receive third signals from said one of its solder balls 538 via its ball-grid-array (BGA) substrate 537 to be converted by the auxiliary IC chip 411 of its input/output (I/O) or control chip package 424 as fourth signals and then the first small input/output (I/O) circuit may transmit the fourth signals to the second small input/output (I/O) circuit via its ball-grid-array (BGA) substrate 537.

For the eleventh type of FPMCP 314 for the first alternative as seen in FIGS. 19 and 19-1, the FPGA IC chip 200 of its logic chip package 422 may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with first data stored in first non-volatile memory cells of either of the NVM IC chips 250 of its non-volatile-memory (NVM) chip package 336 and transmitted from the first non-volatile memory cells of said either of the NVM IC chips 250 of its non-volatile-memory (NVM) chip package 336 to the FPGA IC chip 200 of its logic chip package 422 through the second metal interconnect 113 of its ball-grid-array (BGA) substrate 537 to be configured in accordance with the first data, (2) the first or second type of field programmable switch cell 379 as illustrated in FIGS. 2A and 2B having the memory cells 362 for storing data associated with second data stored in second non-volatile memory cells of either of the NVM IC chips 250 of its non-volatile-memory (NVM) chip package 336 and transmitted from the second non-volatile memory cells of said either of the NVM IC chips 250 of its non-volatile-memory (NVM) chip package 336 to the FPGA IC chip 200 of its logic chip package 422 through a third metal interconnect 115 of its ball-grid-array (BGA) substrate 537 provided by one or more of the interconnection metal layers 668 of its ball-grid-array (BGA) substrate 537 to be configured in accordance with the second data, and (3) the programmable switch matrix 710 as illustrated in FIG. 2C having the memory cells 398 for storing data, i.e., programming codes, password or encryption/decryption codes, associated with third data stored in third non-volatile memory cells of either of the NVM IC chips 250 of its non-volatile-memory (NVM) chip package 336 and transmitted from the third non-volatile memory cells of said either of the NVM IC chips 250 of its non-volatile-memory (NVM) chip package 336 to the FPGA IC chip 200 of its logic chip package 422 through a fourth metal interconnect (not shown) of its ball-grid-array (BGA) substrate 537 provided by one or more of the interconnection metal layers 668 of its ball-grid-array (BGA) substrate 537 to be configured in accordance with the third data, wherein each of the second metal interconnect 113, third metal interconnect 115 and fourth metal interconnect of its ball-grid-array (BGA) substrate 537 may comprises a first segment under across an edge of its non-volatile-memory (NVM) chip package 336 and having a thickness between 10 and 50 micrometers, between 25 and 50 micrometers, between 10 and 40 micrometers or between 10 and 20 micrometers and a second segment under across an edge of its logic chip package 422 and having a thickness between 10 and 50 micrometers, between 25 and 50 micrometers, between 10 and 40 micrometers or between 10 and 20 micrometers. Alternatively, the FPGA IC chip 200 of its logic chip package 422 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MLU) IC chip, or digital-signal-processing (DSP) IC chip, each of which may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with the first data to be configured in accordance with the first data, (2) the first or second type of field programmable switch cell 379 as illustrated in FIGS. 2A and 2B having the memory cells 362 for storing data associated with the second data to be configured in accordance with the second data, and (3) the programmable switch matrix 710 as illustrated in FIG. 2C having the memory cells 398 for storing data, i.e., programming codes, password or encryption/decryption codes, associated with the third data to be configured in accordance with the third data.

Alternatively, FIG. 19-2 is a schematically cross-sectional view showing an eleventh type of FPMCP for a second alternative in accordance with an embodiment of the present application. Referring to FIG. 19-2, an eleventh type of FPMCP 314-1 for a second alternative may have a similar specification to the eleventh type of FPMCP 314 for the first alternative as illustrated in FIGS. 19 and 19-1. For an element indicated by the same reference number shown in FIGS. 19, 19-1 and 19-2, the specification of the element as seen in FIG. 19-2 may be referred to that of the element as illustrated in FIGS. 19 and 19-1. The difference therebetween is mentioned as below: for the eleventh type of FPMCP 314-1 for the second alternative as seen in FIG. 19-2, the logic chip package 422 of the eleventh type of FPMCP 314 for the first alternative as seen in FIGS. 19 and 19-1 may be replaced with a logic chip, application-specific integrated-circuit (ASIC) chip or system-on-chip (SoC) IC chip, such as FPGA IC chip 200 having the same specification as one illustrated in FIG. 5A-1, having the same specification as the first type of semiconductor IC chip 100 as illustrated in FIG. 3A to be turned upside down with the first, second, third or fourth type of micro-bumps, micro-pillars or micro-pads 34 to be bonded each to a metal pad, bump or contact 529, made of nickel, gold or copper for example, preformed on one of the metal pads of the topmost one of the interconnection metal layers 668 of its ball-grid-array (BGA) substrate 537 to form a bonded metal bump or contact 568 having a top end joining its FPGA IC chip 200 and a bottom end joining the metal pad, bump or contact 529 of its ball-grid-array (BGA) substrate 537, wherein said each of the bonded metal bumps or contacts 568 may include (1) a copper layer having a thickness between 1 μm and 60 μm, between 2 μm and 20 μm or between 10 μm and 50 m between its FPGA IC chip 200 and the metal pad, bump or contact 529 of its ball-grid-array (BGA) substrate 537 and (2) a solder cap, made of a tin-silver alloy, a tin-gold alloy, a tin-copper alloy, a tin-indium alloy, indium or tin, having a thickness of between 1 μm and 15 μm, between 1 μm and 50 μm or between 20 μm and 100 μm between the copper layer of said each of the bonded metal bumps or contacts 568 and the metal pad, bump or contact 529 of its ball-grid-array (BGA) substrate 537. Further, its underfill 565, i.e., polymer layer, may be formed between its FPGA IC chip 200 and its ball-grid-array (BGA) substrate 537, covering a sidewall of each of its bonded metal bumps or contacts 568, wherein its underfill 565 may have a top surface joining a bottom surface of its FPGA IC chip 200 and a bottom surface joining a top surface of its ball-grid-array (BGA) substrate 537. Further, its polymer layer 593 may cover a top surface of its FPGA IC chip 200. For the eleventh type of FPMCP 314-1 for the second alternative, its FPGA IC chip 200 may be the dedicated field programmable integrated-circuit (DFPIC) chip as illustrated in FIG. 4D or embedded field programmable integrated-circuit (eFPIC) chip as illustrated in FIG. 4E.

For the eleventh type of FPMCP 314-1 for the second alternative as seen in FIG. 19-2, the auxiliary IC chip 411 of its input/output (I/O) or control chip package 424 may include a first small input/output (I/O) circuit coupling to a second small input/output (I/O) circuit of its FPGA IC chip 200 through the first metal interconnect 111 of its ball-grid-array (BGA) substrate 537, wherein the first metal interconnect 111 of its ball-grid-array (BGA) substrate 537 may comprise a first segment under across an edge of its input/output (I/O) or control chip package 424 and having a thickness between 10 and 50 micrometers, between 25 and 50 micrometers, between 10 and 40 micrometers or between 10 and 20 micrometers and a second segment under across an edge of its FPGA IC chip 200 and having a thickness between 10 and 50 micrometers, between 25 and 50 micrometers, between 10 and 40 micrometers or between 10 and 20 micrometers, and wherein each of the first and second small input/output (I/O) circuits may have an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts. Thereby, the first small input/output (I/O) circuit may receive first signals from the second small input/output (I/O) circuit via its ball-grid-array (BGA) substrate 537 to be converted by the auxiliary IC chip 411 of its input/output (I/O) or control chip package 424 as second signals and then the large input/output (I/O) circuit may transmit the second signals to said one of its solder balls 538 via its ball-grid-array (BGA) substrate 537. Further, the large input/output (I/O) circuit may receive third signals from said one of its solder balls 538 via its ball-grid-array (BGA) substrate 537 to be converted by the auxiliary IC chip 411 of its input/output (I/O) or control chip package 424 as fourth signals and then the first small input/output (I/O) circuit may transmit the fourth signals to the second small input/output (I/O) circuit via its ball-grid-array (BGA) substrate 537.

For the eleventh type of FPMCP 314-1 for the second alternative as seen in FIG. 19-2, its FPGA IC chip 200 may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with first data stored in first non-volatile memory cells of either of the NVM IC chips 250 of its non-volatile-memory (NVM) chip package 336 and transmitted from the first non-volatile memory cells of said either of the NVM IC chips 250 of its non-volatile-memory (NVM) chip package 336 to its FPGA IC chip 200 through the second metal interconnect 113 of its ball-grid-array (BGA) substrate 537 to be configured in accordance with the first data, (2) the first or second type of field programmable switch cell 379 as illustrated in FIGS. 2A and 2B having the memory cells 362 for storing data associated with second data stored in second non-volatile memory cells of either of the NVM IC chips 250 of its non-volatile-memory (NVM) chip package 336 and transmitted from the second non-volatile memory cells of said either of the NVM IC chips 250 of its non-volatile-memory (NVM) chip package 336 to its FPGA IC chip 200 through the third metal interconnect 115 of its ball-grid-array (BGA) substrate 537 provided by one or more of the interconnection metal layers 668 of its ball-grid-array (BGA) substrate 537 to be configured in accordance with the second data and (3) the programmable switch matrix 710 as illustrated in FIG. 2C having the memory cells 398 for storing data, i.e., programming codes, password or encryption/decryption codes, associated with third data stored in third non-volatile memory cells of either of the NVM IC chips 250 of its non-volatile-memory (NVM) chip package 336 and transmitted from the third non-volatile memory cells of said either of the NVM IC chips 250 of its non-volatile-memory (NVM) chip package 336 to its FPGA IC chip 200 through a fourth metal interconnect (not shown) of its ball-grid-array (BGA) substrate 537 provided by one or more of the interconnection metal layers 668 of its ball-grid-array (BGA) substrate 537 to be configured in accordance with the third data, wherein each of the second metal interconnect 113, third metal interconnect 115 and fourth metal interconnect of its ball-grid-array (BGA) substrate 537 may comprises a first segment under across an edge of its non-volatile-memory (NVM) chip package 336 and having a thickness between 10 and 50 micrometers, between 25 and 50 micrometers, between 10 and 40 micrometers or between 10 and 20 micrometers and a second segment under across an edge of its FPGA IC chip 200 and having a thickness between 10 and 50 micrometers, between 25 and 50 micrometers, between 10 and 40 micrometers or between 10 and 20 micrometers. Alternatively, its FPGA IC chip 200 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MLU) IC chip, or digital-signal-processing (DSP) IC chip, each of which may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with the first data to be configured in accordance with the first data, (2) the first or second type of field programmable switch cell 379 as illustrated in FIGS. 2A and 2B having the memory cells 362 for storing data associated with the second data to be configured in accordance with the second data, and (3) the programmable switch matrix 710 as illustrated in FIG. 2C having the memory cells 398 for storing data, i.e., programming codes, password or encryption/decryption codes, associated with the third data to be configured in accordance with the third data.

Alternatively, FIG. 19-3 is a schematically cross-sectional view showing an eleventh type of FPMCP for a third alternative in accordance with an embodiment of the present application. Referring to FIG. 19-3, an eleventh type of FPMCP 314-2 for a third alternative may have a similar specification to the eleventh type of FPMCP 314-1 for the second alternative as illustrated in FIG. 19-2. For an element indicated by the same reference number shown in FIGS. 19, 19-1, 19-2 and 19-3, the specification of the element as seen in FIG. 19-3 may be referred to that of the element as illustrated in FIGS. 19, 19-1 and 19-2. The difference therebetween is mentioned as below: for the eleventh type of FPMCP 314-2 for the third alternative as seen in FIG. 19-3, the input/output (I/O) or control chip package 424 of the eleventh type of FPMCP 314-1 for the second alternative as seen in FIG. 19-2 may be replaced with an application-specific integrated-circuit (ASIC) chip or system-on-chip (SoC) IC chip, such as auxiliary IC chip 411 having the same specification as one illustrated in FIG. 5A-1, having the same specification as the first type of semiconductor IC chip 100 as illustrated in FIG. 3A to be turned upside down with the first, second, third or fourth type of micro-bumps, micro-pillars or micro-pads 34 to be bonded each to a metal pad, bump or contact 529, made of nickel, gold or copper for example, preformed on one of the metal pads of the topmost one of the interconnection metal layers 668 of its ball-grid-array (BGA) substrate 537 to form a bonded metal bump or contact 569 having a top end joining its auxiliary IC chip 411 and a bottom end joining the metal pad, bump or contact 529 of its ball-grid-array (BGA) substrate 537, wherein said each of the bonded metal bumps or contacts 569 may include (1) a copper layer having a thickness between 1 μm and 60 μm, between 2 μm and 20 μm or between 10 μm and 50 μm between its auxiliary IC chip 411 and the metal pad, bump or contact 529 of its ball-grid-array (BGA) substrate 537 and (2) a solder cap, made of a tin-silver alloy, a tin-gold alloy, a tin-copper alloy, a tin-indium alloy, indium or tin, having a thickness of between 1 μm and 15 μm, between 1 μm and 50 μm or between 20 μm and 100 μm between the copper layer of said each of the bonded metal bumps or contacts 569 and the metal pad, bump or contact 529 of its ball-grid-array (BGA) substrate 537. Further, its underfill 565, i.e., polymer layer, may be formed between its auxiliary IC chip 411 and its ball-grid-array (BGA) substrate 537, covering a sidewall of each of its bonded metal bumps or contacts 569, wherein its underfill 565 may have a top surface joining a bottom surface of its auxiliary IC chip 411 and a bottom surface joining a top surface of its ball-grid-array (BGA) substrate 537.

Further, referring to FIG. 19-3, the non-volatile-memory (NVM) chip package 336 of the eleventh type of FPMCP 314-1 for the second alternative as seen in FIG. 19-2 may be replaced with an NVM IC chip 250, such as NAND or NOR flash IC chip, magnetoresistive random-access memory (MRAM) IC chip, resistive random-access memory (RRAM) IC chip or ferroelectric random-access memory (FRAM) IC chip, having the same specification as the first type of semiconductor IC chip 100 as illustrated in FIG. 3A to be turned upside down with the first, second, third or fourth type of micro-bumps, micro-pillars or micro-pads 34 to be bonded each to a metal pad, bump or contact 529, made of nickel, gold or copper for example, preformed on one of the metal pads of the topmost one of the interconnection metal layers 668 of its ball-grid-array (BGA) substrate 537 to form a bonded metal bump or contact 573 having a top end joining its NVM IC chip 250 and a bottom end joining the metal pad, bump or contact 529 of its ball-grid-array (BGA) substrate 537, wherein said each of the bonded metal bumps or contacts 573 may include (1) a copper layer having a thickness between 1 μm and 60 μm, between 2 μm and 20 μm or between 10 μm and 50 m between its NVM IC chip 250 and the metal pad, bump or contact 529 of its ball-grid-array (BGA) substrate 537 and (2) a solder cap, made of a tin-silver alloy, a tin-gold alloy, a tin-copper alloy, a tin-indium alloy, indium or tin, having a thickness of between 1 μm and 15 μm, between 1 μm and 50 μm or between 20 μm and 100 μm between the copper layer of said each of the bonded metal bumps or contacts 573 and the metal pad, bump or contact 529 of its ball-grid-array (BGA) substrate 537. Further, its underfill 565, i.e., polymer layer, may be formed between its NVM IC chip 250 and its ball-grid-array (BGA) substrate 537, covering a sidewall of each of its bonded metal bumps or contacts 573, wherein its underfill 565 may have a top surface joining a bottom surface of its NVM IC chip 250 and a bottom surface joining a top surface of its ball-grid-array (BGA) substrate 537. Further, its polymer layer 593 may cover a top surface of each of its FPGA IC chip 200, NVM IC chip 250 and auxiliary IC chip 411.

For the eleventh type of FPMCP 314-2 for the third alternative as seen in FIG. 19-3, its auxiliary IC chip 411 may include a first small input/output (I/O) circuit coupling to a second small input/output (I/O) circuit of its FPGA IC chip 200 through the first metal interconnect 111 of its ball-grid-array (BGA) substrate 537, wherein the first metal interconnect 111 of its ball-grid-array (BGA) substrate 537 may comprises a first segment under across an edge of its auxiliary IC chip 411 and having a thickness between 10 and 50 micrometers, between 25 and 50 micrometers, between 10 and 40 micrometers or between 10 and 20 micrometers and a second segment under across an edge of its FPGA IC chip 200 and having a thickness between 10 and 50 micrometers, between 25 and 50 micrometers, between 10 and 40 micrometers or between 10 and 20 micrometers, and wherein each of the first and second small input/output (I/O) circuits may have an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts. Its auxiliary IC chip 411 may include a large input/output (I/O) circuit coupling to one of its solder balls 538 through its ball-grid-array (BGA) substrate 537, wherein the large I/O circuit may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or equal to or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Thereby, the first small input/output (I/O) circuit may receive first signals from the second small input/output (I/O) circuit via its ball-grid-array (BGA) substrate 537 to be converted by its auxiliary IC chip 411 as second signals and then the large input/output (I/O) circuit may transmit the second signals to said one of its solder balls 538 via its ball-grid-array (BGA) substrate 537. Further, the large input/output (I/O) circuit may receive third signals from said one of its solder balls 538 via its ball-grid-array (BGA) substrate 537 to be converted by its auxiliary IC chip 411 as fourth signals and then the first small input/output (I/O) circuit may transmit the fourth signals to the second small input/output (I/O) circuit via its ball-grid-array (BGA) substrate 537.

For the eleventh type of FPMCP 314-2 for the third alternative as seen in FIG. 19-3, its FPGA IC chip 200 may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with first data stored in first non-volatile memory cells of its NVM IC chip 250 and transmitted from the first non-volatile memory cells of its NVM IC chip 250 to its FPGA IC chip 200 through the second metal interconnect 113 of its ball-grid-array (BGA) substrate 537 to be configured in accordance with the first data, (2) the first or second type of field programmable switch cell 379 as illustrated in FIGS. 2A and 2B having the memory cells 362 for storing data associated with second data stored in second non-volatile memory cells of its NVM IC chip 250 and transmitted from the second non-volatile memory cells of its NVM IC chip 250 to its FPGA IC chip 200 through the third metal interconnect 115 of its ball-grid-array (BGA) substrate 537 provided by one or more of the interconnection metal layers 668 of its ball-grid-array (BGA) substrate 537 to be configured in accordance with the second data, and (3) the programmable switch matrix 710 as illustrated in FIG. 2C having the memory cells 398 for storing data, i.e., programming codes, password or encryption/decryption codes, associated with third data stored in third non-volatile memory cells of its NVM IC chip 250 and transmitted from the third non-volatile memory cells of its NVM IC chip 250 to its FPGA IC chip 200 through a fourth metal interconnect (not shown) of its ball-grid-array (BGA) substrate 537 provided by one or more of the interconnection metal layers 668 of its ball-grid-array (BGA) substrate 537 to be configured in accordance with the third data, wherein each of the second metal interconnect 113, third metal interconnect 115 and fourth metal interconnect of its ball-grid-array (BGA) substrate 537 may comprises a first segment under across an edge of its NVM IC chip 250 and having a thickness between 10 and 50 micrometers, between 25 and 50 micrometers, between 10 and 40 micrometers or between 10 and 20 micrometers and a second segment under across an edge of its FPGA IC chip 200 and having a thickness between 10 and 50 micrometers, between 25 and 50 micrometers, between 10 and 40 micrometers or between 10 and 20 micrometers. Alternatively, its FPGA IC chip 200 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MILU) IC chip, or digital-signal-processing (DSP) IC chip, each of which may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with the first data to be configured in accordance with the first data, (2) the first or second type of field programmable switch cell 379 as illustrated in FIGS. 2A and 2B having the memory cells 362 for storing data associated with the second data to be configured in accordance with the second data, and (3) the programmable switch matrix 710 as illustrated in FIG. 2C having the memory cells 398 for storing data, i.e., programming codes, password or encryption/decryption codes, associated with the third data to be configured in accordance with the third data.

Alternatively, FIG. 19-4 is a schematically cross-sectional view showing an eleventh type of FPMCP for a fourth alternative in accordance with an embodiment of the present application. Referring to FIG. 19-4, an eleventh type of FPMCP 314-3 for a fourth alternative may have a similar specification to the eleventh type of FPMCP 314 for the first alternative as illustrated in FIGS. 19 and 19-1. For an element indicated by the same reference number shown in FIGS. 19, 19-1 and 19-4, the specification of the element as seen in FIG. 19-4 may be referred to that of the element as illustrated in FIGS. 19 and 19-1. The difference therebetween is mentioned as below: the input/output (I/O) or control chip package 424 of the eleventh type of FPMCP 314 for the first alternative as seen in FIGS. 19 and 19-1 may be omitted for the eleventh type of FPMCP 314-3 for the fourth alternative.

Alternatively, FIG. 19-5 is a schematically cross-sectional view showing an eleventh type of FPMCP for a fifth alternative in accordance with an embodiment of the present application. Referring to FIG. 19-5, an eleventh type of FPMCP 314-4 for a fifth alternative may have a similar specification to the eleventh type of FPMCP 314-1 for the second alternative as illustrated in FIG. 19-2. For an element indicated by the same reference number shown in FIGS. 19-2 and 19-5, the specification of the element as seen in FIG. 19-5 may be referred to that of the element as illustrated in FIG. 19-2. The difference therebetween is mentioned as below: the input/output (I/O) or control chip package 424 of the eleventh type of FPMCP 314-1 for the second alternative as seen in FIG. 19-2 may be omitted for the eleventh type of FPMCP 314-4 for the fifth alternative.

Alternatively, FIG. 19-6 is a schematically cross-sectional view showing an eleventh type of FPMCP for a sixth alternative in accordance with an embodiment of the present application. Referring to FIG. 19-6, an eleventh type of FPMCP 314-5 for a sixth alternative may have a similar specification to the eleventh type of FPMCP 314-2 for the third alternative as illustrated in FIG. 19-3. For an element indicated by the same reference number shown in FIGS. 19-3 and 19-6, the specification of the element as seen in FIG. 19-6 may be referred to that of the element as illustrated in FIG. 19-3. The difference therebetween is mentioned as below: the auxiliary IC chip 411 of the eleventh type of FPMCP 314-2 for the third alternative as seen in FIG. 19-3 may be omitted for the eleventh type of FPMCP 314-5 for the sixth alternative.

Alternatively, FIG. 19-7 is a schematically cross-sectional view showing an eleventh type of FPMCP for a seventh alternative in accordance with an embodiment of the present application. Referring to FIG. 19-7, an eleventh type of FPMCP 314-6 for a seventh alternative may have a similar specification to the eleventh type of FPMCP 314-3 for the fourth alternative as illustrated in FIG. 19-4. For an element indicated by the same reference number shown in FIGS. 19-4 and 19-7, the specification of the element as seen in FIG. 19-7 may be referred to that of the element as illustrated in FIG. 19-4. The difference therebetween is mentioned as below: the logic chip package 422 of the eleventh type of FPMCP 314-3 for the fourth alternative as seen in FIG. 19-4 may be replaced with another logic chip package 425 for the eleventh type of FPMCP 314-6 for the seventh alternative. For the eleventh type of FPMCP 314-6 for the seventh alternative, its logic chip package 425 may be bonded onto a top surface of its ball-grid-array (BGA) substrate 537. Its logic chip package 425 may include (1) a logic chip, application-specific integrated-circuit (ASIC) chip or system-on-chip (SoC) IC chip, such as FPGA IC chip 200 having the same specification as one illustrated in FIG. 5A-1, having the same specification as the third type of semiconductor IC chip 100 as illustrated in FIG. 3C to be turned upside down, (2) a polymer layer 92 or insulating dielectric layer, i.e., sealing layer, such as silicon-oxide-containing molding compound, epoxy-based material or polyimide, horizontally around the FPGA IC chip 200 of its logic chip package 425, (3) a frontside interconnection scheme for a device (FISD) 101 under the FPGA IC chip 200 and polymer layer 92 of its logic chip package 425 and across an edge of the FPGA IC chip 200 of its logic chip package 425 and (4) multiple metal bumps, pillars or pads 570 in an array at the bottom of its logic chip package 425 to act as the external pins of its logic chip package 425 to be bonded to the top surface of its ball-grid-array (BGA) substrate 537 for coupling the frontside interconnection scheme for a device (FISD) 101 of its logic chip package 425 to its ball-grid-array (BGA) substrate 537. For the eleventh type of FPMCP 314-6 for the seventh alternative, the FPGA IC chip 200 of its logic chip package 425 may be the dedicated field programmable integrated-circuit (DFPIC) chip as illustrated in FIG. 4D or embedded field programmable integrated-circuit (eFPIC) chip as illustrated in FIG. 4E. Each of the first type of micro-bumps, micro-pillars or micro-pads 34 of the FPGA IC chip 200 of its logic chip package 425 may couple to the frontside interconnection scheme for a device (FISD) 101 of its logic chip package 425, and the bottom surface of the polymer layer 257 of the FPGA IC chip 200 of its logic chip package 425 may be substantially coplanar with the bottom surface of each of the first type of micro-bumps, micro-pillars or micro-pads 34 of the FPGA IC chip 200 of its logic chip package 425 and a bottom surface of the polymer layer 92 of its logic chip package 425. The frontside interconnection scheme for a device (FISD) 101 of its logic chip package 425 may include (1) multiple interconnection metal layers 27 coupling to each of the first type of micro-bumps, micro-pillars or micro-pads 34 of the FPGA IC chip 200 of its logic chip package 425, and (2) one or more polymer layers 42, i.e., insulating dielectric layers, each between neighboring two of the interconnection metal layers 27 of the frontside interconnection scheme for a device (FISD) 101 of its logic chip package 425, under the bottommost one of the interconnection metal layers 27 of the frontside interconnection scheme for a device (FISD) 101 of its logic chip package 425 or over the topmost one of the interconnection metal layers 27 of the frontside interconnection scheme for a device (FISD) 101 of its logic chip package 425, wherein a lower one of the interconnection metal layers 27 of the frontside interconnection scheme for a device (FISD) 101 of its logic chip package 425 may couple to an upper one of the interconnection metal layers 27 of the frontside interconnection scheme for a device (FISD) 101 of its logic chip package 425 through an opening in one of the polymer layers 42 of the frontside interconnection scheme for a device (FISD) 101 of its logic chip package 425 between the upper and lower ones of the interconnection metal layers 27 of the frontside interconnection scheme for a device (FISD) 101 of its logic chip package 425. The topmost one of the polymer layers 42 of the frontside interconnection scheme for a device (FISD) 101 of its logic chip package 425 may have a top surface in contact with the bottom surface of the polymer layer 257 of the FPGA IC chip 200 of its logic chip package 425 and the bottom surface of the polymer layer 92 of the FPGA IC chip 200 of its logic chip package 425. Each opening in the topmost one of the polymer layers 42 of the frontside interconnection scheme for a device (FISD) 101 of its logic chip package 425 may be under one of the first type of micro-bumps, micro-pillars or micro-pads 34 of the FPGA IC chip 200 of its logic chip package 425, and thus the topmost one of the interconnection metal layers 27 of the frontside interconnection scheme for a device (FISD) 101 of its logic chip package 425 may couple to said one of the first type of micro-bumps, micro-pillars or micro-pads 34 through said each opening. Each of the interconnection metal layers 27 of the frontside interconnection scheme for a device (FISD) 101 of its logic chip package 425 may extend horizontally across an edge of the FPGA IC chip 200 of its logic chip package 425. The bottommost one of the interconnection metal layers 27 of the frontside interconnection scheme for a device (FISD) 101 of its logic chip package 425 may have multiple metal pads at tops of multiple respective openings in the bottommost one of the polymer layers 42 of the frontside interconnection scheme for a device (FISD) 101 of its logic chip package 425. The specification and process for the interconnection metal layers 27 and polymer layers 42 for the frontside interconnection scheme for a device (FISD) 101 of its logic chip package 425 may be referred to those for the second interconnection scheme for a chip (SISC) 29 as illustrated in FIG. 3A to be turned upside down. Each of the polymer layers 42 of the frontside interconnection scheme for a device (FISD) 101 of its logic chip package 425 may be a layer of polyimide, benzocyclobutene (BCB), parylene, epoxy-based material or compound, photo epoxy SU-8, elastomer or silicone, having a thickness between, for example, 0.3 μm and 30 μm, 0.5 μm and 20 μm, 1 m and 10 μm, or 0.5 um and 5 μm, or thicker than or equal to 0.3 μm, 0.5 μm, 0.7 μm, 1 μm, 1.5 μm, 2 μm, 3 μm or 5 μm. Each of the interconnection metal layers 27 of the frontside interconnection scheme for a device (FISD) 101 of its logic chip package 425 may be provided with multiple metal traces or lines each including (1) a copper layer 40 having one or more upper portions in openings in one of the polymer layers 42 of the frontside interconnection scheme for a device (FISD) 101 of its logic chip package 425 and a lower portion having a thickness between 0.3 μm and 20 μm under said one of the polymer layers 42 of the frontside interconnection scheme for a device (FISD) 101 of its logic chip package 425, (2) an adhesion metal layer 28a, such as titanium or titanium nitride having a thickness between 1 nm and 50 nm, at a top and sidewall of each of the one or more upper portions of the copper layer 40 of said each of the metal traces or lines and at a top of the upper portion of the copper layer 40 of said each of the metal traces or lines, and (3) an electroplating seed layer 28b, such as copper, between the copper layer 40 and adhesion metal layer 28a of said each of the metal traces or lines, wherein the lower portion of the copper layer 40 of said each of the metal traces or lines may have a sidewall not covered by the adhesion metal layer 28a of said each of the metal traces or lines. Each of the metal traces or lines of each of the interconnection metal layers 27 of the frontside interconnection scheme for a device (FISD) 101 of its logic chip package 425 may have a thickness between, for example, 0.3 μm and 30 μm, 0.5 μm and 20 μm, 1 μm and 10 μm, or 0.5 μm and 5 μm, or thicker than or equal to 0.3 μm, 0.5 μm, 0.7 μm, 1 μm, 1.5 μm, 2 μm, 3 μm or 5 μm, and a width between, for example, 0.3 μm and 30 μm, 0.5 μm and 20 μm, 1 μm and 10 μm, or 0.5 μm and 5 μm, or wider than or equal to 0.3 μm, 0.5 μm, 0.7 μm, 1 μm, 1.5 μm, 2 μm, 3 μm or 5 μm. Further, the polymer layer 92 of its logic chip package 425 may have a vertical sidewall coplanar with a vertical sidewall of the frontside interconnection scheme for a device (FISD) 101 of its logic chip package 425. Each of the metal bumps, pillars or pads 570 of its logic chip package 425 may be of a type selected from various types, i.e., first and second types, which may have the same specification as that of the first and second types of metal bumps, pillars or pads 570 respectively as illustrated in FIG. 6A, and may have the adhesion metal layer 26a on a bottom surface of one of the metal pads of the bottommost one of the interconnection metal layers 27 of the frontside interconnection scheme for a device (FISD) 101 of its logic chip package 425 and a bottom surface of the bottommost one of the polymer layers 42 of the frontside interconnection scheme for a device (FISD) 101 of its logic chip package 425. The FPGA IC chip 200 of its logic chip package 425 may couple to one of the metal bumps, pillars or pads 570 of its logic chip package 425 for external connection to its ball-grid-array (BGA) substrate 537 through each of the interconnection metal layers 27 of the frontside interconnection scheme for a device (FISD) 101 of its logic chip package 425. Each of the metal bumps, pillars or pads 570 of its logic chip package 425 may have a bottom end bonded to a metal pad, bump or contact 529, made of nickel, gold or copper for example, preformed on one of the metal pads of the topmost one of the interconnection metal layers 668 of its ball-grid-array (BGA) substrate 537. The eleventh type of FPMCP 314-6 for the seventh alternative may further include (1) an underfill 565, i.e., polymer layer, between its logic chip package 425 and ball-grid-array (BGA) substrate 537 and between its NVM chip package 336 and ball-grid-array (BGA) substrate 537, covering a sidewall of each of the metal bumps, pillars or pads 570 of its logic chip package 422 and a sidewall of each of the solder balls 337 of its NVM chip package 336 and (2) a polymer layer 593 or insulating dielectric layer, i.e., sealing layer, such as silicon-oxide-containing molding compound, epoxy-based material or polyimide, on the top surface of its ball-grid-array (BGA) substrate 537, wherein its polymer layer 593 may cover a top surface of each of its logic chip package 425 and NVM chip package 336, and wherein its polymer layer 593 may have a vertical sidewall coplanar with a vertical sidewall of its ball-grid-array (BGA) substrate 537.

For the eleventh type of FPMCP 314-6 for the seventh alternative as seen in FIG. 19-7, the FPGA IC chip 200 of its logic chip package 425 may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with first data stored in first non-volatile memory cells of either of the NVM IC chips 250 of its non-volatile-memory (NVM) chip package 336 and transmitted from the first non-volatile memory cells of said either of the NVM IC chips 250 of its non-volatile-memory (NVM) chip package 336 to the FPGA IC chip 200 of its logic chip package 425 through the second metal interconnect 113 of its ball-grid-array (BGA) substrate 537 to be configured in accordance with the first data, (2) the first or second type of field programmable switch cell 379 as illustrated in FIGS. 2A and 2B having the memory cells 362 for storing data associated with second data stored in second non-volatile memory cells of either of the NVM IC chips 250 of its non-volatile-memory (NVM) chip package 336 and transmitted from the second non-volatile memory cells of said either of the NVM IC chips 250 of its non-volatile-memory (NVM) chip package 336 to the FPGA IC chip 200 of its logic chip package 425 through the third metal interconnect 115 of its ball-grid-array (BGA) substrate 537 provided by one or more of the interconnection metal layers 668 of its ball-grid-array (BGA) substrate 537 to be configured in accordance with the second data, and (3) the programmable switch matrix 710 as illustrated in FIG. 2C having the memory cells 398 for storing data, i.e., programming codes, password or encryption/decryption codes, associated with third data stored in third non-volatile memory cells of either of the NVM IC chips 250 of its non-volatile-memory (NVM) chip package 336 and transmitted from the third non-volatile memory cells of said either of the NVM IC chips 250 of its non-volatile-memory (NVM) chip package 336 to the FPGA IC chip 200 of its logic chip package 422 through a fourth metal interconnect (not shown) of its ball-grid-array (BGA) substrate 537 provided by one or more of the interconnection metal layers 668 of its ball-grid-array (BGA) substrate 537 to be configured in accordance with the third data, wherein each of the second metal interconnect 113, third metal interconnect 115 and fourth metal interconnect of its ball-grid-array (BGA) substrate 537 may comprises a first segment under across an edge of its non-volatile-memory (NVM) chip package 336 and having a thickness between 10 and 50 micrometers, between 25 and 50 micrometers, between 10 and 40 micrometers or between 10 and 20 micrometers and a second segment under across an edge of its logic chip package 425 and having a thickness between 10 and 50 micrometers, between 25 and 50 micrometers, between 10 and 40 micrometers or between 10 and 20 micrometers. Alternatively, the FPGA IC chip 200 of its logic chip package 425 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MLU) IC chip, or digital-signal-processing (DSP) IC chip, each of which may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with the first data to be configured in accordance with the first data, (2) the first or second type of field programmable switch cell 379 as illustrated in FIGS. 2A and 2B having the memory cells 362 for storing data associated with the second data to be configured in accordance with the second data, and (3) the programmable switch matrix 710 as illustrated in FIG. 2C having the memory cells 398 for storing data, i.e., programming codes, password or encryption/decryption codes, associated with the third data to be configured in accordance with the third data.

Alternatively, FIG. 19-8 is a schematically cross-sectional view showing an eleventh type of FPMCP for an eighth alternative in accordance with an embodiment of the present application. Referring to FIG. 19-8, an eleventh type of FPMCP 314-7 for an eighth alternative may have a similar specification to the eleventh type of FPMCP 314-6 for the seventh alternative as illustrated in FIG. 19-7. For an element indicated by the same reference number shown in FIGS. 19-7 and 19-8, the specification of the element as seen in FIG. 19-8 may be referred to that of the element as illustrated in FIG. 19-7. The difference therebetween is mentioned as below: for the eleventh type of FPMCP 314-7 for the eighth alternative as seen in FIG. 19-8, the non-volatile-memory (NVM) chip package 336 of the eleventh type of FPMCP 314-6 for the seventh alternative as seen in FIG. 19-7 may be replaced with an NVM IC chip 250, such as NAND or NOR flash IC chip, magnetoresistive random-access memory (MRAM) IC chip, resistive random-access memory (RRAM) IC chip or ferroelectric random-access memory (FRAM) IC chip, having the same specification as the first type of semiconductor IC chip 100 as illustrated in FIG. 3A to be turned upside down with the first, second, third or fourth type of micro-bumps, micro-pillars or micro-pads 34 to be bonded each to a metal pad, bump or contact 529, made of nickel, gold or copper for example, preformed on one of the metal pads of the topmost one of the interconnection metal layers 668 of its ball-grid-array (BGA) substrate 537 to form a bonded metal bump or contact 573 having a top end joining its NVM IC chip 250 and a bottom end joining the metal pad, bump or contact 529 of its ball-grid-array (BGA) substrate 537, wherein said each of the bonded metal bumps or contacts 573 may include (1) a copper layer having a thickness between 1 μm and 60 μm, between 2 μm and 20 μm or between 10 μm and 50 μm between its NVM IC chip 250 and the metal pad, bump or contact 529 of its ball-grid-array (BGA) substrate 537 and (2) a solder cap, made of a tin-silver alloy, a tin-gold alloy, a tin-copper alloy, a tin-indium alloy, indium or tin, having a thickness of between 1 μm and 15 μm, between 1 μm and 50 μm or between 20 μm and 100 μm between the copper layer of said each of the bonded metal bumps or contacts 573 and the metal pad, bump or contact 529 of its ball-grid-array (BGA) substrate 537. Further, its underfill 565, i.e., polymer layer, may be formed between its NVM IC chip 250 and ball-grid-array (BGA) substrate 537, covering a sidewall of each of its bonded metal bumps or contacts 573, wherein its underfill 565 may have a top surface joining a bottom surface of its NVM IC chip 250 and a bottom surface joining a top surface of its ball-grid-array (BGA) substrate 537. Further, its polymer layer 593 may cover a top surface of each of the FPGA IC chip 200 of its logic chip package 425 and its NVM IC chip 250.

For the eleventh type of FPMCP 314-7 for the eighth alternative as seen in FIG. 19-8, the FPGA IC chip 200 of its logic chip package 425 may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with first data stored in first non-volatile memory cells of its NVM IC chip 250 and transmitted from the first non-volatile memory cells of its NVM IC chip 250 to the FPGA IC chip 200 of its logic chip package 425 through the second metal interconnect 113 of its ball-grid-array (BGA) substrate 537 to be configured in accordance with the first data, (2) the first or second type of field programmable switch cell 379 as illustrated in FIGS. 2A and 2B having the memory cells 362 for storing data associated with second data stored in second non-volatile memory cells of its NVM IC chip 250 and transmitted from the second non-volatile memory cells of its NVM IC chip 250 to the FPGA IC chip 200 of its logic chip package 425 through the third metal interconnect 115 of its ball-grid-array (BGA) substrate 537 provided by one or more of the interconnection metal layers 668 of its ball-grid-array (BGA) substrate 537 to be configured in accordance with the second data, and (3) the programmable switch matrix 710 as illustrated in FIG. 2C having the memory cells 398 for storing data, i.e., programming codes, password or encryption/decryption codes, associated with third data stored in third non-volatile memory cells of its NVM IC chip 250 and transmitted from the third non-volatile memory cells of its NVM IC chip 250 to the FPGA IC chip 200 of its logic chip package 422 through a fourth metal interconnect (not shown) of its ball-grid-array (BGA) substrate 537 provided by one or more of the interconnection metal layers 668 of its ball-grid-array (BGA) substrate 537 to be configured in accordance with the third data, wherein each of the second metal interconnect 113, third metal interconnect 115 and fourth metal interconnect of its ball-grid-array (BGA) substrate 537 may comprises a first segment under across an edge of its NVM IC chip 250 and having a thickness between 10 and 50 micrometers, between 25 and 50 micrometers, between 10 and 40 micrometers or between 10 and 20 micrometers and a second segment under across an edge of its logic chip package 425 and having a thickness between 10 and 50 micrometers, between 25 and 50 micrometers, between 10 and 40 micrometers or between 10 and 20 micrometers. Alternatively, the FPGA IC chip 200 of its logic chip package 425 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MILU) IC chip, or digital-signal-processing (DSP) IC chip, each of which may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with the first data to be configured in accordance with the first data, (2) the first or second type of field programmable switch cell 379 as illustrated in FIGS. 2A and 2B having the memory cells 362 for storing data associated with the second data to be configured in accordance with the second data, and (3) the programmable switch matrix 710 as illustrated in FIG. 2C having the memory cells 398 for storing data, i.e., programming codes, password or encryption/decryption codes, associated with the third data to be configured in accordance with the third data.

Alternatively, FIG. 19-9 is a schematically cross-sectional view showing an eleventh type of FPMCP for a ninth alternative in accordance with an embodiment of the present application. Referring to FIG. 19-9, an eleventh type of FPMCP 314-8 for a ninth alternative may have a similar specification to the eleventh type of FPMCP 314-5 for the sixth alternative as illustrated in FIG. 19-6. For an element indicated by the same reference number shown in FIGS. 19-6 and 19-9, the specification of the element as seen in FIG. 19-9 may be referred to that of the element as illustrated in FIG. 19-6. The difference therebetween is mentioned as below: the NVM IC chips 250 for the eleventh type of FPMCP 314-5 for the sixth alternative may be rearranged under the ball-grid-array (BGA) substrate 537 for the eleventh type of FPMCP 314-8 for the ninth alternative. For the eleventh type of FPMCP 314-8 for the ninth alternative, its NVM IC chip 250, such as NAND or NOR flash IC chip, magnetoresistive random-access memory (MRAM) IC chip, resistive random-access memory (RRAM) IC chip or ferroelectric random-access memory (FRAM) IC chip, may have the same specification as the first type of semiconductor IC chip 100 as illustrated in FIG. 3A with the first, second, third or fourth type of micro-bumps, micro-pillars or micro-pads 34 to be bonded each to one of the metal pads 528 of the bottommost one of the interconnection metal layers 668 of its ball-grid-array (BGA) substrate 537 to form a bonded metal bump or contact 573 having a bottom end joining its NVM IC chip 250 and a top end joining one of the metal pads 528 of the bottommost one of the interconnection metal layers 668 of its ball-grid-array (BGA) substrate 537, wherein said each of the bonded metal bumps or contacts 573 may include (1) a copper layer having a thickness between 1 μm and 60 μm, between 2 μm and 20 μm or between 10 μm and 50 μm between its NVM IC chip 250 and said one of the metal pads 528 of the bottommost one of the interconnection metal layers 668 of its ball-grid-array (BGA) substrate 537 and (2) a solder cap, made of a tin-silver alloy, a tin-gold alloy, a tin-copper alloy, a tin-indium alloy, indium or tin, having a thickness of between 1 μm and 15 μm, between 1 μm and 50 μm or between 20 μm and 100 m between the copper layer of said each of the bonded metal bumps or contacts 573 and said one of the metal pads 528 of the bottommost one of the interconnection metal layers 668 of its ball-grid-array (BGA) substrate 537. Further, its underfill 565, i.e., polymer layer, may be formed between its NVM IC chip 250 and its ball-grid-array (BGA) substrate 537, covering a sidewall of each of its bonded metal bumps or contacts 573, wherein its underfill 565 may have a top surface joining a top surface of its NVM IC chip 250 and a bottom surface joining a bottom surface of its ball-grid-array (BGA) substrate 537 and cover a sidewall of its NVM IC chip 250. Further, each of its solder balls 538 may have a bottom portion below a horizontal level coplanar with a bottom surface of its NVM IC chip 250. Its FPGA IC chip 200 may be rearranged over a center area of its ball-grid-array (BGA) substrate 537 at a top of its ball-grid-array (BGA) substrate 537 and vertically over its NVM IC chip 250. Its FPGA IC chip 200 may have a top surface not covered by its polymer layer 593 and coplanar with a top surface of its polymer layer 593.

For the eleventh type of FPMCP 314-8 for the ninth alternative as seen in FIG. 19-9, its FPGA IC chip 200 may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with first data stored in first non-volatile memory cells of its NVM IC chip 250 and transmitted from the first non-volatile memory cells of its NVM IC chip 250 to its FPGA IC chip 200 via one or more of the through holes 661a in the core layer 661 of its interconnection substrate 684 to be configured in accordance with the first data, (2) the first or second type of field programmable switch cell 379 as illustrated in FIGS. 2A and 2B having the memory cells 362 for storing data associated with second data stored in second non-volatile memory cells of its NVM IC chip 250 and transmitted from the second non-volatile memory cells of its NVM IC chip 250 to its FPGA IC chip 200 via one or more of the through holes 661a in the core layer 661 of its interconnection substrate 684 to be configured in accordance with the second data, and (3) the programmable switch matrix 710 as illustrated in FIG. 2C having the memory cells 398 for storing data, i.e., programming codes, password or encryption/decryption codes, associated with third data stored in third non-volatile memory cells of its NVM IC chip 250 and transmitted from the third non-volatile memory cells of its NVM IC chip 250 to its FPGA IC chip 200 via one or more of the through holes 661a in the core layer 661 of its interconnection substrate 684 to be configured in accordance with the third data. Alternatively, its FPGA IC chip 200 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MILU) IC chip, or digital-signal-processing (DSP) IC chip, each of which may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with the first data to be configured in accordance with the first data, (2) the first or second type of field programmable switch cell 379 as illustrated in FIGS. 2A and 2B having the memory cells 362 for storing data associated with the second data to be configured in accordance with the second data, and (3) the programmable switch matrix 710 as illustrated in FIG. 2C having the memory cells 398 for storing data, i.e., programming codes, password or encryption/decryption codes, associated with the third data to be configured in accordance with the third data.

### Twelfth Type of FPMCP

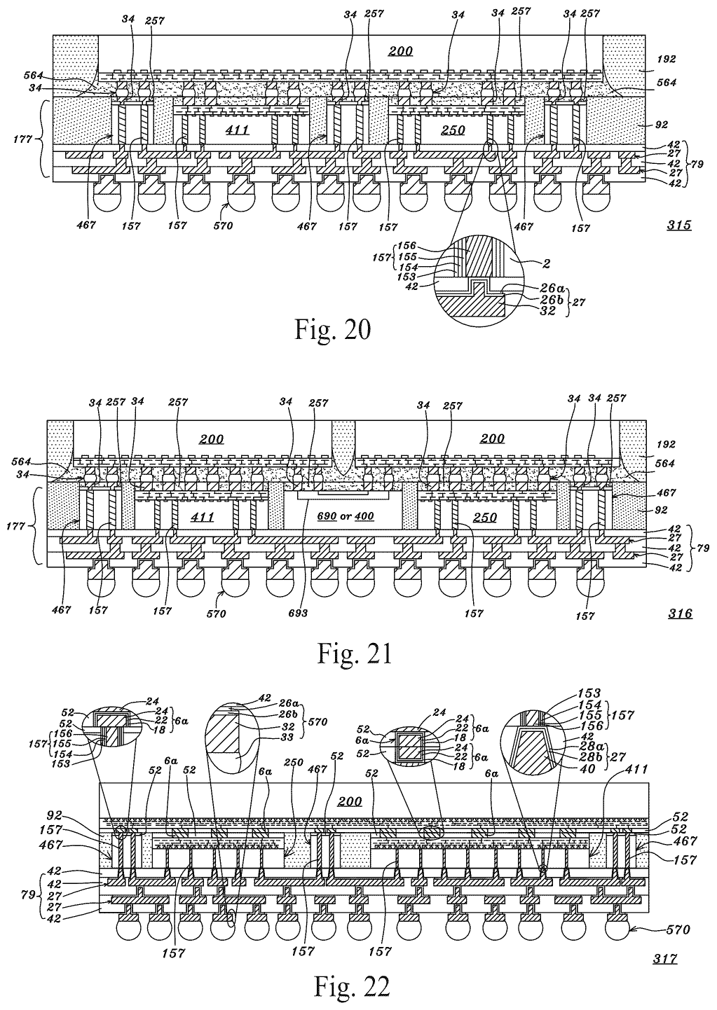

FIG. 20 is a schematically cross-sectional view showing a twelfth type of FPMCP in accordance with an embodiment of the present application. A twelfth type of FPMCP 315 as seen in FIG. 20 may have a similar structure to the fourth structure 304 for each of the first type of FPMCPs 300 for the first and second alternatives as seen in FIGS. 9A and 9B. For an element indicated by the same reference number shown in FIGS. 9A, 9B and 20, the specification of the element as seen in FIG. 20 may be referred to that of the element as illustrated in FIGS. 9A and 9B. The difference therebetween is that the NVM IC chip 250 and auxiliary IC chip 411 both as illustrated in FIGS. 5A-1 may be arranged in the interconnection substrate 177 for the twelfth type of FPMCP 315 as seen in FIG. 20. For the twelfth type of FPMCP 315, its FPGA IC chip 200 may have the same specification as one illustrated in FIG. 5A-1 and as the first type of semiconductor IC chip 100 illustrated in FIG. 3A to be turned upside down, and each of its NVM IC chip 250 and auxiliary IC chip 411 may have the same specification as the fourth type of semiconductor IC chip 100 as illustrated in FIGS. 3D and 3G-3J. Its FPGA IC chip 200 may be the dedicated field programmable integrated-circuit (DFPIC) chip as illustrated in FIG. 4D or embedded field programmable integrated-circuit (eFPIC) chip as illustrated in FIG. 4E.

Referring to FIG. 20, for the twelfth type of FPMCP 315, its NVM IC chip 250 and auxiliary IC chip 411 may be embedded in its interconnection substrate 177 and under its FPGA IC chip 200. The polymer layer 92, i.e., insulating dielectric layer or sealing layer, of its interconnection substrate 177 may be horizontally around each of the vertical-through-via (VTV) connectors 467 of its interconnection substrate 177 and each of its NVM IC chip 250 and auxiliary IC chip 411 and in each gap between neighboring two of the vertical-through-via (VTV) connectors 467 of its interconnection substrate 177 and its NVM IC chip 250 and auxiliary IC chip 411, wherein the polymer layer 92 of its interconnection substrate 177 may have a top surface coplanar with the top surface of the polymer layer 257 of each of the vertical-through-via (VTV) connectors 467 of its interconnection substrate 177, the top surface of each of the first type of micro-bumps, micro-pillars or micro-pads 34 of each of the vertical-through-via (VTV) connectors 467 of its interconnection substrate 177, the top surface of the polymer layer 257 of each of its NVM IC chip 250 and auxiliary IC chip 411 and the top surface of each of the first type of micro-bumps, micro-pillars or micro-pads 34 of each of its NVM IC chip 250 and auxiliary IC chip 411. The semiconductor substrate 2 of each of its NVM IC chip 250 and auxiliary IC chip 411 may have a portion, at a backside of the semiconductor substrate 2 of said each of its NVM IC chip 250 and auxiliary IC chip 411, removed by a chemical-mechanical-polishing (CMP) or mechanical grinding process such that each of the through silicon vias (TSVs) 157, that is, the electroplated copper layer 156 thereof, of said each of its NVM IC chip 250 and auxiliary IC chip 411 may have a bottom surface substantially coplanar with a bottom surface of the semiconductor substrate 2 of said each of its NVM IC chip 250 and auxiliary IC chip 411, a bottom surface of the semiconductor substrate 2 of each of the vertical-through-via (VTV) connectors 467 of its interconnection substrate 177 and a bottom surface of the polymer layer 92 of its interconnection substrate 177. For an alternative case, its interconnection substrates 177 may further include the insulating dielectric layer 185, such as silicon-oxide layer or silicon-nitride layer, illustrated in FIG. 4C but not shown in FIG. 20 formed on a bottom surface of the semiconductor substrate 2 of each of the vertical-through-via (VTV) connectors 467 of its interconnection substrate 177 and a bottom surface of the semiconductor substrate 2 of each of its NVM IC chip 250 and auxiliary IC chip 411, wherein the insulating dielectric layer 185 of its interconnection substrate 177 may have a bottom surface coplanar with the bottom surface of each of the through silicon vias 157 of each of the vertical-through-via (VTV) connectors 467 of its interconnection substrate 177, the bottom surface of each of the through silicon vias 157 of each of its NVM IC chip 250 and auxiliary IC chip 411 and the bottom surface of the polymer layer 92 of its interconnection substrate 177. The topmost one of the polymer layers 42 of the interconnection scheme 79 of its interconnection substrate 177 may have a top surface in contact with the bottom surface of the polymer layer 92 of its interconnection substrate 177, the bottom surface of the semiconductor substrate 2 of each of the vertical-through-via (VTV) connectors 467 of its interconnection substrate 177 and the bottom surface of the semiconductor substrate 2 of each of its NVM IC chip 250 and auxiliary IC chip 411. For the alternative case, the topmost one of the polymer layers 42 of the interconnection scheme 79 of its interconnection substrate 177 may have a top surface in contact with the bottom surface of the polymer layer 92 of its interconnection substrate 177 and the bottom surface of the insulating dielectric layer 185 of its interconnection substrate 177. Each opening in the topmost one of the polymer layers 42 of the interconnection scheme 79 of its interconnection substrate 177 may be under one of the through silicon vias (TSVs) 157 of one of the vertical-through-via (VTV) connectors 467 of its interconnection substrate 177, one of the through silicon vias (TSVs) 157 of its NVM IC chip 250 or one of the through silicon vias (TSVs) 157 of its auxiliary IC chip 411, and thus the topmost one of the interconnection metal layers 27 of the interconnection scheme 79 of its interconnection substrate 177 may extend through said each opening to couple to said one of the through silicon vias (TSVs) 157. Each of the interconnection metal layers 27 of the interconnection scheme 79 of its interconnection substrate 177 may extend horizontally across an edge of each of its NVM IC chip 250 and auxiliary IC chip 411 and an edge of each of the vertical-through-via (VTV) connectors 467 of its interconnection substrate 177.

Referring to FIG. 20, for the twelfth type of FPMCP 315, its FPGA IC chip 200 may have the first, second, third or fourth type of micro-bumps, micro-pillars or micro-pads 34 as illustrated in FIG. 3A each bonded to one of the first type of micro-bumps, micro-pillars or micro-pads 34 of one of the vertical-through-via (VTV) connectors 467 of its interconnection substrate 177, one of the first type of micro-bumps, micro-pillars or micro-pads 34 of its NVM IC chip 250 or one of the first type of micro-bumps, micro-pillars or micro-pads 34 of its auxiliary IC chip 411. The bottom surface of the semiconductor substrate 2 of its FPGA IC chip 200, at which the semiconductor devices 4, such as transistors, of its FPGA IC chip 200 are formed as illustrated in FIG. 3A, faces the top surface of the semiconductor substrate 2 of each of its NVM IC chip 250 and auxiliary IC chip 411, at which the semiconductor devices 4, such as transistors, of said each of its NVM IC chip 250 and auxiliary IC chip 411 are formed as illustrated in FIGS. 3D and 3G-3J. Its underfill 564, i.e., polymer layer, may be formed between its FPGA IC chip 200 and its interconnection substrate 177, between its FPGA IC chip 200 and NVM IC chip 250 and between its FPGA IC chip 200 and auxiliary IC chip 411, covering a sidewall of each of the first, second, third or fourth type of micro-bumps, micro-pillars or micro-pads 34 of its FPGA IC chip 200. Its polymer layer 192, i.e., insulating dielectric layer or sealing layer, may be formed on its interconnection substrate 177 and horizontally around its FPGA IC chip 200, wherein its polymer layer 192 may have a top surface coplanar with a top surface of its FPGA IC chip 200. Its polymer layer 192 may have a vertical sidewall coplanar with a vertical sidewall of its polymer layer 92 and a vertical sidewall of its interconnection scheme 79.

Referring to FIG. 20, for the twelfth type of FPMCP 315, its FPGA IC chip 200 may couple to one of its metal bumps, pillars or pads 570 through, in sequence, one of the through silicon vias (TSVs) 157 of one of the vertical-through-via (VTV) connectors 467 of its interconnection substrate 177 and each of the interconnection metal layers 27 of the interconnection scheme 79 of its interconnection substrate 177 for transmitting a signal or clock or delivering a power or ground voltage therebetween. Alternatively, its FPGA IC chip 200 may couple to one of its metal bumps, pillars or pads 570 through, in sequence, one of the through silicon vias (TSVs) 157 of its NVM IC chip 250 and each of the interconnection metal layers 27 of the interconnection scheme 79 of its interconnection substrate 177 for transmitting a signal or clock or delivering a power or ground voltage therebetween. Alternatively, its FPGA IC chip 200 may couple to one of its metal bumps, pillars or pads 570 through, in sequence, one of the through silicon vias (TSVs) 157 of its auxiliary IC chip 411 and each of the interconnection metal layers 27 of the interconnection scheme 79 of its interconnection substrate 177 for transmitting a signal or clock or delivering a power or ground voltage therebetween.

For the twelfth type of FPMCP 315 as seen in FIG. 20, its auxiliary IC chip 411 may include a first small input/output (I/O) circuit coupling to a second small input/output (I/O) circuit of its FPGA IC chip 200 through its first signal path composed of bonded two of the first, second, third or fourth type of micro-bumps, micro-pillars or micro-pads 34 of its auxiliary IC chip 411 and FPGA IC chip 200, wherein each of the first and second small input/output (I/O) circuits may have an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts. Its auxiliary IC chip 411 may include a large input/output (I/O) circuit coupling to one of its metal bumps, pillars or pads 570 through its second signal path composed of one of the through silicon vias (TSVs) 157 of its auxiliary IC chip 411 and each of the interconnection metal layers 27 of the interconnection scheme 79 of its interconnection substrate 177, wherein the large I/O circuit may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or equal to or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Thereby, the first small input/output (I/O) circuit may receive first signals from the second small input/output (I/O) circuit via its first signal path to be converted by its auxiliary IC chip 411 as second signals and then the large input/output (I/O) circuit may transmit the second signals to said one of its metal bumps, pillars or pads 570 via its second signal path. Further, the large input/output (I/O) circuit may receive third signals from said one of its metal bumps, pillars or pads 570 via its second signal path to be converted by its auxiliary IC chip 411 as fourth signals and then the first small input/output (I/O) circuit may transmit the fourth signals to the second small input/output (I/O) circuit via its first signal path.

For the twelfth type of FPMCP 315 as seen in FIG. 20, its FPGA IC chip 200 may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with first data stored in its NVM IC chip 250 to be configured in accordance with the first data, (2) the first or second type of field programmable switch cell 379 as illustrated in FIGS. 2A and 2B having the memory cells 362 for storing data associated with second data stored in its NVM IC chip 250 to be configured in accordance with the second data, and (3) the programmable switch matrix 710 as illustrated in FIG. 2C having the memory cells 398 for storing data, i.e., programming codes, password or encryption/decryption codes, associated with third data stored in its NVM IC chip 250 to be configured in accordance with the third data. Alternatively, its FPGA IC chip 200 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MLU) IC chip, or digital-signal-processing (DSP) IC chip, each of which may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with the first data to be configured in accordance with the first data, (2) the first or second type of field programmable switch cell 379 as illustrated in FIGS. 2A and 2B having the memory cells 362 for storing data associated with the second data to be configured in accordance with the second data, and (3) the programmable switch matrix 710 as illustrated in FIG. 2C having the memory cells 398 for storing data, i.e., programming codes, password or encryption/decryption codes, associated with the third data to be configured in accordance with the third data.

### Thirteenth Type of FPMCP

FIG. 21 is a schematically cross-sectional view showing a thirteenth type of FPMCP in accordance with an embodiment of the present application. A thirteenth type of FPMCP 316 as seen in FIG. 21 may have a similar structure to the twelfth type of FPMCP 315 as seen in FIG. 20. For an element indicated by the same reference number shown in FIGS. 20 and 21, the specification of the element as seen in FIG. 21 may be referred to that of the element as illustrated in FIG. 20. The difference therebetween is that the FPGA IC chip 200 of the twelfth type of FPMCP 315 may be replaced with two FPGA IC chips 200 for the thirteenth type of FPMCP 316 and the interconnection substrate 177 of the thirteenth type of FPMCP 316 may further include the fine-line interconnection bridge (FIB) 690, or DFPIC or eFPIC chip 400, as illustrated in FIG. 9A therein to couple the two FPGA IC chips 200 of the thirteenth type of FPMCP 316. For the thirteenth type of FPMCP 316, each of its two FPGA IC chips 200 may have the same specification as one illustrated in FIG. 5A-1 and the first type of semiconductor IC chip 100 illustrated in FIG. 3A to be turned upside down. Each of its FPGA IC chips 200 may be the dedicated field programmable integrated-circuit (DFPIC) chip as illustrated in FIG. 4D or embedded field programmable integrated-circuit (eFPIC) chip as illustrated in FIG. 4E.

Referring to FIG. 21, for the thirteenth type of FPMCP 316, the fine-line interconnection bridge (FIB) 690, or DFPIC or eFPIC chip 400, of its interconnection substrate 177 may be arranged under its two FPGA IC chips 200, its NVM IC chip 250 embedded in its interconnection substrate 177 may be arranged under a right one of its two FPGA IC chips 200 and its auxiliary IC chip 411 embedded in its interconnection substrate 177 may be arranged under a left one of its two FPGA IC chips 200. The polymer layer 92, i.e., insulating dielectric layer or sealing layer, of its interconnection substrate 177 may be horizontally around each of the fine-line interconnection bridge (FIB) 690, or DFPIC or eFPIC chip 400, and vertical-through-via (VTV) connectors 467 of its interconnection substrate 177 and each of its NVM IC chip 250 and auxiliary IC chip 411 and in each gap between neighboring two of the fine-line interconnection bridge (FIB) 690, or DFPIC or eFPIC chip 400, and vertical-through-via (VTV) connectors 467 of its interconnection substrate 177 and its NVM IC chip 250 and auxiliary IC chip 411, wherein the polymer layer 92 of its interconnection substrate 177 may have a top surface coplanar with the top surface of the polymer layer 257 of each of the fine-line interconnection bridge (FIB) 690, or DFPIC or eFPIC chip 400, and vertical-through-via (VTV) connectors 467 of its interconnection substrate 177, the top surface of each of the first type of micro-bumps, micro-pillars or micro-pads 34 of each of the fine-line interconnection bridge (FIB) 690, or DFPIC or eFPIC chip 400, and vertical-through-via (VTV) connectors 467 of its interconnection substrate 177, the top surface of the polymer layer 257 of each of its NVM IC chip 250 and auxiliary IC chip 411 and the top surface of each of the first type of micro-bumps, micro-pillars or micro-pads 34 of each of its NVM IC chip 250 and auxiliary IC chip 411. Each of the through silicon vias (TSVs) 157, i.e., the electroplated copper layer 156 thereof, of each of its NVM IC chip 250 and auxiliary IC chip 411 and each of the through silicon vias (TSVs) 157, i.e., the electroplated copper layer 156 thereof, of each of the vertical-through-via (VTV) connectors 467 of its interconnection substrate 177 may have a bottom surface substantially coplanar with a bottom surface of the semiconductor substrate 2 of each of its NVM IC chip 250 and auxiliary IC chip 411, a bottom surface of the semiconductor substrate 2 of each of the fine-line interconnection bridge (FIB) 690, or DFPIC or eFPIC chip 400, and vertical-through-via (VTV) connectors 467 of its interconnection substrate 177 and a bottom surface of the polymer layer 92 of its interconnection substrate 177. For an alternative case, its interconnection substrate 177 may further include the insulating dielectric layer 185, such as silicon-oxide layer or silicon-nitride layer, illustrated in FIG. 4C but not shown in FIG. 21 formed on a bottom surface of the semiconductor substrate 2 of each of the fine-line interconnection bridges (FIBs) 690, or DFPIC or eFPIC chips 400, and vertical-through-via (VTV) connectors 467 of its interconnection substrate 177 and a bottom surface of the semiconductor substrate 2 of each of its NVM IC chip 250 and auxiliary IC chip 411, wherein the insulating dielectric layer 185 of its interconnection substrate 177 may have a bottom surface coplanar with the bottom surface of each of the through silicon vias 157 of each of the vertical-through-via (VTV) connectors 467 of its interconnection substrate 177, the bottom surface of each of the through silicon vias 157 of each of its NVM IC chip 250 and auxiliary IC chip 411 and the bottom surface of the polymer layer 92 of its interconnection substrate 177. The topmost one of the polymer layers 42 of the interconnection scheme 79 of its interconnection substrate 177 may have a top surface in contact with the bottom surface of the polymer layer 92 of its interconnection substrate 177, the bottom surface of the semiconductor substrate 2 of each of the fine-line interconnection bridge (FIB) 690, or DFPIC or eFPIC chip 400, and vertical-through-via (VTV) connectors 467 of its interconnection substrate 177 and the bottom surface of the semiconductor substrate 2 of each of its NVM IC chip 250 and auxiliary IC chip 411. For the alternative case, the topmost one of the polymer layers 42 of the interconnection scheme 79 of its interconnection substrate 177 may have a top surface in contact with the bottom surface of the polymer layer 92 of its interconnection substrate 177 and the bottom surface of the insulating dielectric layer 185 of its interconnection substrate 177. Each of the interconnection metal layers 27 of the interconnection scheme 79 of its interconnection substrate 177 may extend horizontally across an edge of each of its NVM IC chip 250 and auxiliary IC chip 411 and an edge of each of the fine-line interconnection bridge (FIB) 690, or DFPIC or eFPIC chip 400, and vertical-through-via (VTV) connectors 467 of its interconnection substrate 177.

Referring to FIG. 21, for the thirteenth type of FPMCP 316, the left one of its two FPGA IC chips 200 may have the first, second, third or fourth type of micro-bumps, micro-pillars or micro-pads 34 as illustrated in FIG. 3A each bonded to one of the first type of micro-bumps, micro-pillars or micro-pads 34 of one of the fine-line interconnection bridges (FIBs) 690, or DFPIC or eFPIC chip 400, and vertical-through-via (VTV) connectors 467 of its interconnection substrate 177 or one of the first type of micro-bumps, micro-pillars or micro-pads 34 of its input/output (I/O) or control chip 265, and the right one of its two FPGA IC chips 200 may have the first, second, third or fourth type of micro-bumps, micro-pillars or micro-pads 34 as illustrated in FIG. 3A each bonded to one of the first type of micro-bumps, micro-pillars or micro-pads 34 of one of the fine-line interconnection bridges (FIBs) 690, or DFPIC or eFPIC chip 400, and vertical-through-via (VTV) connectors 467 of its interconnection substrate 177 or one of the first type of micro-bumps, micro-pillars or micro-pads 34 of its NVM IC chip 250. The bottom surface of the semiconductor substrate 2 of the left one of its FPGA IC chips 200, at which the semiconductor devices 4, such as transistors, of the left one of its FPGA IC chips 200 are formed as illustrated in FIG. 3A, faces the top surface of the semiconductor substrate 2 of its input/output (I/O) or control chip 265, at which the semiconductor devices 4, such as transistors, of its input/output (I/O) or control chip 265 are formed as illustrated in FIGS. 3D and 3G-3J, and the bottom surface of the semiconductor substrate 2 of the right one of its FPGA IC chips 200, at which the semiconductor devices 4, such as transistors, of the right one of its FPGA IC chips 200 are formed as illustrated in FIG. 3A, faces the top surface of the semiconductor substrate 2 of its NVM IC chip 250, at which the semiconductor devices 4, such as transistors, of its NVM IC chip 250 are formed as illustrated in FIGS. 3D and 3G-3J. Its underfill 564, i.e., polymer layer, may be formed between the left one of its two FPGA IC chips 200 and its interconnection substrate 177, between the left one of its two FPGA IC chips 200 and its input/output (I/O) or control chip 265, between the right one of its two FPGA IC chips 200 and its interconnection substrate 177, and between the right one of its two FPGA IC chips 200 and its NVM IC chip 250, covering a sidewall of each of the first, second, third or fourth type of micro-bumps, micro-pillars or micro-pads 34 of each of its two FPGA IC chips 200. Its polymer layer 192, i.e., insulating dielectric layer or sealing layer, may be formed on its interconnection substrate 177 and horizontally around each of its two FPGA IC chips 200, wherein its polymer layer 192 may have a top surface coplanar with a top surface of each of its two FPGA IC chips 200. Its polymer layer 192 may have a vertical sidewall coplanar with a vertical sidewall of its polymer layer 92 and a vertical sidewall of its interconnection scheme 79.

Referring to FIG. 21, for the thirteenth type of FPMCP 316, the fine-line interconnection bridge (FIB) 690, or DFPIC or eFPIC chip 400, of its interconnection substrate 177 may be arranged under its two FPGA IC chips 200 and may have one of the metal lines or traces 693 coupling the left one of its two FPGA IC chips 200 to the right one of its two FPGA IC chips 200 for transmitting a signal or clock or delivering a power or ground voltage therebetween. Each of its two FPGA IC chips 200 may couple to one of its metal bumps, pillars or pads 570 through, in sequence, one of the through silicon vias (TSVs) 157 of the underlying one of the vertical-through-via (VTV) connectors 467 of its interconnection substrate 177 and each of the interconnection metal layers 27 of the interconnection scheme 79 of its interconnection substrate 177 for transmitting a signal or clock or delivering a power or ground voltage therebetween. Alternatively, the left one of its two FPGA IC chips 200 may couple to one of its metal bumps, pillars or pads 570 through, in sequence, one of the through silicon vias (TSVs) 157 of its input/output (I/O) or control chip 265 and each of the interconnection metal layers 27 of the interconnection scheme 79 of its interconnection substrate 177 for transmitting a signal or clock or delivering a power or ground voltage therebetween. Alternatively, the right one of its two FPGA IC chips 200 may couple to one of its metal bumps, pillars or pads 570 through, in sequence, one of the through silicon vias (TSVs) 157 of its NVM IC chip 250 and each of the interconnection metal layers 27 of the interconnection scheme 79 of its interconnection substrate 177 for transmitting a signal or clock or delivering a power or ground voltage therebetween.

For the thirteenth type of FPMCP 316 as seen in FIG. 21, its input/output (I/O) or control chip 265 may include a first small input/output (I/O) circuit coupling to a second small input/output (I/O) circuit of a vertically overlying one of its FPGA IC chips 200 through its first signal path composed of bonded two of the first, second, third or fourth type of micro-bumps, micro-pillars or micro-pads 34 of its input/output (I/O) or control chip 265 and the vertically overlying one of its FPGA IC chips 200, wherein each of the first and second small input/output (I/O) circuits may have an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts. Its input/output (I/O) or control chip 265 may include a large input/output (I/O) circuit coupling to one of its metal bumps, pillars or pads 570 through its second signal path composed of one of the through silicon vias (TSVs) 157 of its input/output (I/O) or control chip 265 and each of the interconnection metal layers 27 of the interconnection scheme 79 of its interconnection substrate 177, wherein the large I/O circuit may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or equal to or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Thereby, the first small input/output (I/O) circuit may receive first signals from the second small input/output (I/O) circuit via its first signal path to be converted by its input/output (I/O) or control chip 265 as second signals and then the large input/output (I/O) circuit may transmit the second signals to said one of its metal bumps, pillars or pads 570 via its second signal path. Further, the large input/output (I/O) circuit may receive third signals from said one of its metal bumps, pillars or pads 570 via its second signal path to be converted by its input/output (I/O) or control chip 265 as fourth signals and then the first small input/output (I/O) circuit may transmit the fourth signals to the second small input/output (I/O) circuit via its first signal path.

For the thirteenth type of FPMCP 316 as seen in FIG. 21, each of its two FPGA IC chips 200 may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with first data stored in its NVM IC chip 250 to be configured in accordance with the first data, (2) the first or second type of field programmable switch cell 379 as illustrated in FIGS. 2A and 2B having the memory cells 362 for storing data associated with second data stored in its NVM IC chip 250 to be configured in accordance with the second data, and (3) the programmable switch matrix 710 as illustrated in FIG. 2C having the memory cells 398 for storing data, i.e., programming codes, password or encryption/decryption codes, associated with third data stored in its NVM IC chip 250 to be configured in accordance with the third data. Alternatively, either or each of its auxiliary IC chip 411 and NVM IC chip 250 may be replaced with a static random-access memory (SRAM) IC chip. Alternatively, either or each of its two FPGA IC chips 200 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MILU) IC chip, or digital-signal-processing (DSP) IC chip, each of which may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with the first data to be configured in accordance with the first data, (2) the first or second type of field programmable switch cell 379 as illustrated in FIGS. 2A and 2B having the memory cells 362 for storing data associated with the second data to be configured in accordance with the second data, and (3) the programmable switch matrix 710 as illustrated in FIG. 2C having the memory cells 398 for storing data, i.e., programming codes, password or encryption/decryption codes, associated with the third data to be configured in accordance with the third data.

Alternatively, referring to FIG. 21, for the thirteenth type of FPMCP 316, the DFPIC or eFPIC chip 400 of its interconnection substrate 177 may be vertically under its two FPGA IC chips 200, wherein the DFPIC or eFPIC chip 400 of its interconnection substrate 177 may couple to a first device of its two FPGA IC chips 200 through a first group of the first type of micro-bumps, micro-pillars or micro-pads 34 of the DFPIC or eFPIC chip 400 of its interconnection substrate 177 under the first device and couple to a second device of its two FPGA IC chips 200 through a second group of the first type of micro-bumps, micro-pillars or micro-pads 34 of the DFPIC or eFPIC chip 400 of its interconnection substrate 177 under the second device, wherein the first device may be a left one of its two FPGA IC chips 200 and the second device may be a right one of its two FPGA IC chips 200, for example. The DFPIC or eFPIC chip 400 of its interconnection substrate 177 may include (1) the first type of field programmable logic cell or element (LCE) 2014 or 2014-2 as illustrated in FIGS. 1A, 4D and 4E, the data inputs A0 and A1 of which may couple to the first device through, in sequence, respective two of the small input/output (SIO) circuits 203, or metal pads or input/output (I/O) pads, of the DFPIC or eFPIC chip 400 of its interconnection substrate 177, respective two of the first group of the first type of micro-bumps, micro-pillars or micro-pads 34 of the DFPIC or eFPIC chip 400 of its interconnection substrate 177 and respective two of the first, second, third or fourth type of micro-bumps, micro-pillars or micro-pads 34 of the first device, and the data output Dout of which may couple to the second device through, in sequence, another of the small input/output (SIO) circuits 203, or metal pads or input/output (I/O) pads, of the DFPIC or eFPIC chip 400 of its interconnection substrate 177, one of the second group of the first type of micro-bumps, micro-pillars or micro-pads 34 of the DFPIC or eFPIC chip 400 of its interconnection substrate 177 and one of the first, second, third or fourth type of micro-bumps, micro-pillars or micro-pads 34 of the second device, (2) the second or third type of field programmable logic cell or element (LCE) 2014 or 2014-2 as illustrated in FIGS. 1B, 1C, 4D and 4E, the data inputs A0-A3 of which may couple to the first device through, in sequence, respective four of the small input/output (SIO) circuits 203, or metal pads or input/output (I/O) pads, of the DFPIC or eFPIC chip 400 of its interconnection substrate 177, respective four of the first group of the first type of micro-bumps, micro-pillars or micro-pads 34 of the DFPIC or eFPIC chip 400 of its interconnection substrate 177 and respective four of the first, second, third or fourth type of micro-bumps, micro-pillars or micro-pads 34 of the first device, and the data output Dout of which may couple to the second device through, in sequence, another of the small input/output (SIO) circuits 203, or metal pads or input/output (I/O) pads, of the DFPIC or eFPIC chip 400 of its interconnection substrate 177, one of the second group of the first type of micro-bumps, micro-pillars or micro-pads 34 of the DFPIC or eFPIC chip 400 of its interconnection substrate 177 and one of the first, second, third or fourth type of micro-bumps, micro-pillars or micro-pads 34 of the second device, (3) the first type of field programmable switch cell 379 or 379-2 as illustrated in FIGS. 2A, 4D and 4E, the node N21 of which may couple to the first device through, in sequence, one of the small input/output (SIO) circuits 203, or metal pads or input/output (I/O) pads, of the DFPIC or eFPIC chip 400 of its interconnection substrate 177, one of the first group of the first type of micro-bumps, micro-pillars or micro-pads 34 of the DFPIC or eFPIC chip 400 of its interconnection substrate 177 and one of the first, second, third or fourth type of micro-bumps, micro-pillars or micro-pads 34 of the first device, and the node N22 of which may couple to the second device through, in sequence, another of the small input/output (SIO) circuits 203, or metal pads or input/output (I/O) pads, of the DFPIC or eFPIC chip 400 of its interconnection substrate 177, one of the second group of the first type of micro-bumps, micro-pillars or micro-pads 34 of the DFPIC or eFPIC chip 400 of its interconnection substrate 177 and one of the first, second, third or fourth type of micro-bumps, micro-pillars or micro-pads 34 of the second device, to control coupling between the first and second devices, (4) the second type of field programmable switch cell 379 or 379-2 as illustrated in FIGS. 2B, 4D and 4E, the nodes N23 and N24 of which may couple to the first device through, in sequence, respective two of the small input/output (SIO) circuits 203, or metal pads or input/output (I/O) pads, of the DFPIC or eFPIC chip 400 of its interconnection substrate 177, respective two of the first group of the first type of micro-bumps, micro-pillars or micro-pads 34 of the DFPIC or eFPIC chip 400 of its interconnection substrate 177 and respective two of the first, second, third or fourth type of micro-bumps, micro-pillars or micro-pads 34 of the first device, and the nodes N25 and N26 of which may couple to the second device through, in sequence, another respective two of the small input/output (SIO) circuits 203, or metal pads or input/output (I/O) pads, of the DFPIC or eFPIC chip 400 of its interconnection substrate 177, respective two of the second group of the first type of micro-bumps, micro-pillars or micro-pads 34 of the DFPIC or eFPIC chip 400 of its interconnection substrate 177 and respective two of the first, second, third or fourth type of micro-bumps, micro-pillars or micro-pads 34 of the second device, to control coupling from the node N23 to one or more of the nodes N24-N26 or to control coupling from the node N26 to one or more of the nodes N23-N25, (5) the field programmable switch matrix 710 or 710-3 as illustrated in FIGS. 2C, 4D and 4E, each of the nodes P₁-P_{N} of which may couple to the first device through, in sequence, one of the first metal lines 281 of the DFPIC or eFPIC chip 400 of its interconnection substrate 177, one of the small input/output (SIO) circuits 203, or metal pads or input/output (I/O) pads, of the DFPIC or eFPIC chip 400 of its interconnection substrate 177, one of the first group of the first type of micro-bumps, micro-pillars or micro-pads 34 of the DFPIC or eFPIC chip 400 of its interconnection substrate 177 and one of the first, second, third or fourth type of micro-bumps, micro-pillars or micro-pads 34 of the first device, each of the nodes Q₁-Q_{M} of which may couple to the second device through, in sequence, one of the second metal lines 282 of the DFPIC or eFPIC chip 400 of its interconnection substrate 177, another of the small input/output (SIO) circuits 203, or metal pads or input/output (I/O) pads, of the DFPIC or eFPIC chip 400 of its interconnection substrate 177, one of the second group of the first type of micro-bumps, micro-pillars or micro-pads 34 of the DFPIC or eFPIC chip 400 of its interconnection substrate 177 and one of the first, second, third or fourth type of micro-bumps, micro-pillars or micro-pads 34 of the second device, and each of the pass/no-pass switches 778 of which may control coupling between the first and second devices, i.e., between one of the first group of the first type of micro-bumps, micro-pillars or micro-pads 34 of the DFPIC or eFPIC chip 400 of its interconnection substrate 177 and one of the second group of the first type of micro-bumps, micro-pillars or micro-pads 34 of the DFPIC or eFPIC chip 400 of its interconnection substrate 177, and/or (6) the field programmable switch matrix 710-2 as illustrated in FIGS. 2C and 4E, each of some of the nodes P₁-P_{N} of which may couple to the first device through, in sequence, one of the first metal lines 281 of the DFPIC or eFPIC chip 400 of its interconnection substrate 177, one of the small input/output (SIO) circuits 203, or metal pads or input/output (I/O) pads, of the DFPIC or eFPIC chip 400 of its interconnection substrate 177, one of the first group of the first type of micro-bumps, micro-pillars or micro-pads 34 of the DFPIC or eFPIC chip 400 of its interconnection substrate 177 and one of the first, second, third or fourth type of micro-bumps, micro-pillars or micro-pads 34 of the first device, each of the other some of the nodes P₁-P_{N} of which may couple to the second device through, in sequence, another of the first metal lines 281 of the DFPIC or eFPIC chip 400 of its interconnection substrate 177, another of the small input/output (SIO) circuits 203, or metal pads or input/output (I/O) pads, of the DFPIC or eFPIC chip 400 of its interconnection substrate 177, one of the second group of the first type of micro-bumps, micro-pillars or micro-pads 34 of the DFPIC or eFPIC chip 400 of its interconnection substrate 177 and one of the first, second, third or fourth type of micro-bumps, micro-pillars or micro-pads 34 of the second device, and each of the pass/no-pass switches 778 of which may control coupling between one of the first and second devices and one of the internal circuits of the fourth one of the ASIC cores 215 of the DFPIC or eFPIC chip 400 of its interconnection substrate 177, i.e., between one of the first and second groups of the first type of micro-bumps, micro-pillars or micro-pads 34 of the DFPIC or eFPIC chip 400 of its interconnection substrate 177 and one of the internal circuits of the fourth one of the ASIC cores 215 of the DFPIC or eFPIC chip 400 of its interconnection substrate 177.

### Fourteenth Type of FPMCP

FIG. 22 is a schematically cross-sectional view showing a fourteenth type of FPMCP in accordance with an embodiment of the present application. A fourteenth type of FPMCP 317 as seen in FIG. 22 may include (1) a logic chip, application-specific integrated-circuit (ASIC) chip or system-on-chip (SoC) IC chip, such as FPGA IC chip 200 having the same specification as one illustrated in FIG. 5A-1, at its top, (2) a NVM IC chip 250 having the same specification as one illustrated in FIG. 5A-1 on a bottom of its FPGA IC chip 200, (3) an application-specific integrated-circuit (ASIC) chip or system-on-chip (SoC) IC chip, such as auxiliary IC chip 411 having the same specification as one illustrated in FIG. 5A-1, on the bottom of its FPGA IC chip 200, wherein its auxiliary IC chip 411 may be used as an input/output (I/O) or control chip, and (4) multiple vertical-through-via (VTV) connectors 467 on the bottom of its FPGA IC chip 200. Its FPGA IC chip 200 may have the same specification as the fifth type of semiconductor IC chip 100 illustrated in FIG. 3E to be turned upside down, each of its NVM IC chip 250 and auxiliary IC chip 411 may have the same specification as the sixth type of semiconductor IC chip 100 illustrated in FIGS. 3F-3J and each of its vertical-through-via (VTV) connectors 467 may have the same specification as the second type of vertical-through-via (VTV) connector 467 illustrated in FIG. 4B. Its FPGA IC chip 200 may be the dedicated field programmable integrated-circuit (DFPIC) chip as illustrated in FIG. 4D or embedded field programmable integrated-circuit (eFPIC) chip as illustrated in FIG. 4E.

Referring to FIG. 22, for the fourteenth type of FPMCP 317, each of its NVM IC chip 250 and auxiliary IC chip 411 may be provided, for hybrid bonding, with (1) the insulating bonding layer 52, i.e., silicon oxide, having the top surface attached to and in contact with the bottom surface of the insulating bonding layer 52, i.e., silicon oxide, of its FPGA IC chip 200 and (2) the metal pads 6a, i.e., the copper layer 24 thereof, each having the top surface bonded to and in contact with the bottom surface of one of the metal pads 6a, i.e., the copper layer 24 thereof, of its FPGA IC chip 200. The bottom surface of the semiconductor substrate 2 of its FPGA IC chip 200, at which the semiconductor devices 4, such as transistors, of its FPGA IC chip 200 are formed as illustrated in FIG. 3E, faces the top surface of the semiconductor substrate 2 of each of its NVM IC chip 250 and auxiliary IC chip 411, at which the semiconductor devices 4, such as transistors, of said each of its NVM IC chip 250 and auxiliary IC chip 411 are formed as illustrated in FIGS. 3F-3J. Each of its vertical-through-via (VTV) connectors 467 may be provided, for hybrid bonding, with (1) the insulating bonding layer 52, i.e., silicon oxide, having the top surface attached to and in contact with the bottom surface of the insulating bonding layer 52, i.e., silicon oxide, of its FPGA IC chip 200 and (2) the through silicon vias (TSVs) 157, i.e., the copper layer 24 thereof, each having the top surface bonded to and in contact with the bottom surface of one of the metal pads 6a, i.e., the copper layer 24 thereof, of its FPGA IC chip 200. Each of the metal pads 6a of each of its FPGA IC chip 200, NVM IC chip 250 and auxiliary IC chip 411 may have a width, diameter or transverse dimension smaller than 5, 3, 1 or 0.5 micrometers, or between 0.1 and 5 micrometers, 0.1 and 3 micrometers, 0.1 and 1 micrometers, or 0.1 and 0.5 micrometers. The pitch between neighboring two of the metal pads 6a of each of its FPGA IC chip 200, NVM IC chip 250 and auxiliary IC chip 411 may be smaller than 10, 5, 2 or 1 micrometers, or between 0.2 and 10 micrometers, 0.2 and 5 micrometers, 0.2 and 2 micrometers, or 0.2 and 1 micrometers.

Referring to FIG. 22, the fourteenth type of FPMCP 317 may further include a polymer layer 92 or insulating dielectric layer, i.e., sealing layer, such as silicon-oxide-containing molding compound, epoxy-based material or polyimide, on the bottom of its FPGA IC chip 200 and horizontally around each of its NVM IC chip 250, auxiliary IC chip 411 and vertical-through-via (VTV) connectors 467. The semiconductor substrate 2 of each of its NVM IC chip 250, auxiliary IC chip 411 and vertical-through-via (VTV) connectors 467 may have a portion, at a backside of the semiconductor substrate 2 of said each of its NVM IC chip 250, auxiliary IC chip 411 and vertical-through-via (VTV) connectors 467, removed by a chemical-mechanical-polishing (CMP) or mechanical grinding process such that each of the through silicon vias (TSVs) 157, i.e., the electroplated copper layer 156 thereof, of said each of its NVM IC chip 250, auxiliary IC chip 411 and vertical-through-via (VTV) connectors 467 may have a bottom surface substantially coplanar with a bottom surface of the semiconductor substrate 2 of said each of its NVM IC chip 250, auxiliary IC chip 411 and vertical-through-via (VTV) connectors 467 and a bottom surface of its polymer layer 92. For an alternative case, the fourteenth type of FPMCP 317 may further include the insulating dielectric layer 185, such as silicon-oxide layer or silicon-nitride layer, illustrated in FIG. 4C but not shown in FIG. 22 formed on a bottom surface of the semiconductor substrate 2 of each of its NVM IC chip 250, auxiliary IC chip 411 and vertical-through-via (VTV) connectors 467, wherein its insulating dielectric layer 185 may have a bottom surface coplanar with the bottom surface of each of the through silicon vias 157 of each of its NVM IC chip 250, auxiliary IC chip 411 and vertical-through-via (VTV) connectors 467 and the bottom surface of its polymer layer 92.

Referring to FIG. 22, the fourteenth type of FPMCP 317 may further include an interconnection scheme 79 under its NVM IC chip 250, auxiliary IC chip 411, vertical-through-via (VTV) connectors 467 and polymer layer 92. Its interconnection scheme 79 may be provided with one or more interconnection metal layers 27 coupling to each of the through silicon vias (TSV) 157 of each of its NVM IC chip 250, auxiliary IC chip 411 and vertical-through-via (VTV) connectors 467 and multiple polymer layers 42 each between neighboring two of the interconnection metal layers 27 of its interconnection scheme 79, under the bottommost one of the interconnection metal layers 27 of its interconnection scheme 79 or over the topmost one of the interconnection metal layers 27 of its interconnection scheme 79, wherein an upper one of the interconnection metal layers 27 of its interconnection scheme 79 may couple to a lower one of the interconnection metal layers 27 of its interconnection scheme 79 through an opening in one of the polymer layers 42 of its interconnection scheme 79 between the upper and lower ones of the interconnection metal layers 27 of its interconnection scheme 79. The topmost one of the polymer layers 42 of its interconnection scheme 79 may have a top surface in contact with the bottom surface of its polymer layer 92 and the bottom surface of the semiconductor substrate 2 of each of its NVM IC chip 250, auxiliary IC chip 411 and vertical-through-via (VTV) connectors 467. For the alternative case, the topmost one of the polymer layers 42 of its interconnection scheme 79 may have a top surface in contact with the bottom surface of its polymer layer 92 and the bottom surface of its insulating dielectric layer 185. Each opening in the topmost one of the polymer layers 42 of its interconnection scheme 79 may be under one of the through silicon vias (TSVs) 157 of one of its NVM IC chip 250, auxiliary IC chip 411 and vertical-through-via (VTV) connectors 467 and thus the topmost one of the interconnection metal layers 27 of its interconnection scheme 79 may extend through said each opening to couple to said one of the through silicon vias (TSVs) 157. Each of the interconnection metal layers 27 of its interconnection scheme 79 may extend horizontally across an edge of each of its NVM IC chip 250, auxiliary IC chip 411 and vertical-through-via (VTV) connectors 467. The bottommost one of the interconnection metal layers 27 of its interconnection scheme 79 may have multiple metal pads at tops of multiple respective openings in the bottommost one of the polymer layers 42 of its interconnection scheme 79. The specification and process for the interconnection metal layers 27 and polymer layers 42 of its interconnection scheme 79 may be referred to those for the second interconnection scheme for a chip (SISC) 29 as illustrated in FIG. 3A. Its polymer layer 92 may have a vertical sidewall coplanar with a vertical sidewall of its FPGA IC chip 200 and a vertical sidewall of its interconnection scheme 79.

Referring to FIG. 22, the fourteenth type of FPMCP 317 may further include multiple metal bumps, pillars or pads 570 in an array at its bottom to act as its external pins coupling or bonding to external circuits, e.g., a ball-grid-array (BGA) substrate 537. Each of its metal bumps, pillars or pads 570 may be of a type selected from various types, i.e., first and second types, which may have the same specification as that of the first and second types of metal bumps, pillars or pads 570 respectively as illustrated in FIG. 6A, and may have the adhesion metal layer 26a on a bottom surface of one of the metal pads of the bottommost one of the interconnection metal layers 27 of its interconnection scheme 79 and a bottom surface of the bottommost one of the polymer layers 42 of its interconnection scheme 79. For the fourteenth type of FPMCP 317, its FPGA IC chip 200 may couple to one of its metal bumps, pillars or pads 570 through, in sequence, one of the through silicon vias (TSVs) 157 of one of its NVM IC chip 250, auxiliary IC chip 411 and vertical-through-via (VTV) connectors 467 and each of the interconnection metal layers 27 of its interconnection scheme 79 for transmitting a signal or clock or delivering a power or ground voltage therebetween.

For the fourteenth type of FPMCP 317 as seen in FIG. 22, its auxiliary IC chip 411 may include a first small input/output (I/O) circuit coupling to a second small input/output (I/O) circuit of its FPGA IC chip 200 through its first signal path composed of bonded two of the metal pads 6a of its auxiliary IC chip 411 and FPGA IC chip 200, wherein each of the first and second small input/output (I/O) circuits may have an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage equal to or lower than 1.2 volts or 0.8 volts. Its auxiliary IC chip 411 may include a large input/output (I/O) circuit coupling to one of its metal bumps, pillars or pads 570 through its second signal path composed of one of the through silicon vias (TSVs) 157 of its auxiliary IC chip 411 and each of the interconnection metal layers 27 of its interconnection scheme 79, wherein the large I/O circuit may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or equal to or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Thereby, the first small input/output (I/O) circuit may receive first signals from the second small input/output (I/O) circuit via its first signal path to be converted by its auxiliary IC chip 411 as second signals and then the large input/output (I/O) circuit may transmit the second signals to said one of its metal bumps, pillars or pads 570 via its second signal path. Further, the large input/output (I/O) circuit may receive third signals from said one of its metal bumps, pillars or pads 570 via its second signal path to be converted by its auxiliary IC chip 411 as fourth signals and then the first small input/output (I/O) circuit may transmit the fourth signals to the second small input/output (I/O) circuit via its first signal path.

For the fourteenth type of FPMCP 317 as seen in FIG. 22, its FPGA IC chip 200 may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with first data stored in its NVM IC chip 250 to be configured in accordance with the first data, (2) the first or second type of field programmable switch cell 379 as illustrated in FIGS. 2A and 2B having the memory cells 362 for storing data associated with second data stored in its NVM IC chip 250 to be configured in accordance with the second data, and (3) the programmable switch matrix 710 as illustrated in FIG. 2C having the memory cells 398 for storing data, i.e., programming codes, password or encryption/decryption codes, associated with third data stored in its NVM IC chip 250 to be configured in accordance with the third data. Alternatively, its FPGA IC chip 200 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MILU) IC chip, or digital-signal-processing (DSP) IC chip, each of which may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with the first data to be configured in accordance with the first data, (2) the first or second type of field programmable switch cell 379 as illustrated in FIGS. 2A and 2B having the memory cells 362 for storing data associated with the second data to be configured in accordance with the second data, and (3) the programmable switch matrix 710 as illustrated in FIG. 2C having the memory cells 398 for storing data, i.e., programming codes, password or encryption/decryption codes, associated with the third data to be configured in accordance with the third data.

### Fifteenth Type of FPMCP

FIG. 23A is a schematically cross-sectional view showing a fifteenth type of FPMCP in accordance with an embodiment of the present application. A fifteenth type of FPMCP 318 as seen in FIG. 23A may include (1) a circuit substrate 451, such as interposer 551 as illustrated in FIG. 6A, wherein its interposer 551 may be replaced with a ball-grid-array (BGA) substrate 537 as illustrated in FIG. 19, (2) a three-dimensional chip package 461 over its circuit substrate 451 and (3) multiple metal contacts 452 in an array at its bottom to act as its external pins for coupling to external circuits outside of the fifteenth type of FPMCP 318, wherein each of its metal contacts 452 may be formed on a bottom surface of its circuit substrate 451.

Referring to FIG. 23A, for the fifteenth type of FPMCP 318, its three-dimensional chip package 461 may include (1) an application-specific integrated-circuit (ASIC) chip or system-on-chip (SoC) IC chip, such as auxiliary IC chip 411 having the same specification as one illustrated in FIG. 5A-1, at a bottom of its three-dimensional chip package 461, wherein its auxiliary IC chip 411 may be used as an input/output (I/O) or control chip, (2) multiple face-to-face chip assemblies 462 stacked with each other or one another and over the auxiliary IC chip 411 of its three-dimensional chip package 461 and (3) a NVM IC chip 250 over the face-to-face chip assemblies 462 of its three-dimensional chip package 461. Each of the face-to-face chip assemblies 462 of its three-dimensional chip package 461 may include upper and lower semiconductor IC chips 100i and 100j stacked with each other, wherein the upper semiconductor IC chip 100i of each of the face-to-face chip assemblies 462 of its three-dimensional chip package 461 may have the same specification as the sixth type of semiconductor IC chip 100 illustrated in FIGS. 3F-3J to be turned upside down and the lower semiconductor IC chip 100j of each of the face-to-face chip assemblies 462 of its three-dimensional chip package 461 may have the same specification as the sixth type of semiconductor IC chip 100 illustrated in FIGS. 3F-3J. For example, the upper semiconductor IC chip 100i of each of the face-to-face chip assemblies 462 of its three-dimensional chip package 461 may have the specification as illustrated for the third kind of connection structure for the through silicon vias (TSVs) 157 and first interconnection scheme for a chip 20 (FISC) as seen in FIG. 3I to be turned upside down, and the lower semiconductor IC chip 100j of each of the face-to-face chip assemblies 462 of its three-dimensional chip package 461 may have the specification as illustrated for the third kind of connection structure for the through silicon vias (TSVs) 157 and first interconnection scheme for a chip 20 (FISC) as seen in FIG. 3I. The auxiliary IC chip 411 of its three-dimensional chip package 461 may have the same specification as the second type of semiconductor IC chip 100 illustrated in FIGS. 3B and 3G-3J to be turned upside down. The NVM IC chip 250 of its three-dimensional chip package 461 may have the same specification as the first type of semiconductor IC chip 100 illustrated in FIG. 3A to be turned upside down.

Referring to FIG. 23A, for the fifteenth type of FPMCP 318, the lower semiconductor IC chip 100j of each of the face-to-face chip assemblies 462 of its three-dimensional chip package 461 may be provided, for hybrid bonding, with (1) the insulating bonding layer 52, i.e., silicon oxide, having the top surface attached to and in contact with the bottom surface of the insulating bonding layer 52, i.e., silicon oxide, of the upper semiconductor IC chip 100i of said each of the face-to-face chip assemblies 462 of its three-dimensional chip package 461 and (2) the metal pads 6a, i.e., the copper layer 24 thereof, each having the top surface bonded to and in contact with the bottom surface of one of the metal pads 6a, i.e., the copper layer 24 thereof, of the upper semiconductor IC chip 100i of said each of the face-to-face chip assemblies 462 of its three-dimensional chip package 461. The bottom surface of the semiconductor substrate 2 of the upper semiconductor IC chip 100i of said each of the face-to-face chip assemblies 462 of its three-dimensional chip package 461, at which the semiconductor devices 4, such as transistors, of the upper semiconductor IC chip 100i of said each of the face-to-face chip assemblies 462 of its three-dimensional chip package 461 are formed as illustrated in FIGS. 3F-3J, faces the top surface of the semiconductor substrate 2 of the lower semiconductor IC chip 100j of said each of the face-to-face chip assemblies 462 of its three-dimensional chip package 461, at which the semiconductor devices 4, such as transistors, of the lower semiconductor IC chip 100j of said each of the face-to-face chip assemblies 462 of its three-dimensional chip package 461 are formed as illustrated in FIGS. 3F-3J. Each of the metal pads 6a of each of the upper and lower semiconductor IC chips 100i and 100j of each of the face-to-face chip assemblies 462 of its three-dimensional chip package 461 may have a width, diameter or transverse dimension smaller than 5, 3, 1 or 0.5 micrometers, or between 0.1 and 5 micrometers, 0.1 and 3 micrometers, 0.1 and 1 micrometers, or 0.1 and 0.5 micrometers. The pitch between neighboring two of the metal pads 6a of each of the upper and lower semiconductor IC chips 100i and 100j of each of the face-to-face chip assemblies 462 of its three-dimensional chip package 461 may be smaller than 10, 5, 2 or 1 micrometers, or between 0.2 and 10 micrometers, 0.2 and 5 micrometers, 0.2 and 2 micrometers, or 0.2 and 1 micrometers. The upper semiconductor IC chip 100j of each of the face-to-face chip assemblies 462 of its three-dimensional chip package 461 may have a vertical sidewall coplanar with a vertical sidewall of the lower semiconductor IC chip 100j of each of the face-to-face chip assemblies 462 of its three-dimensional chip package 461.

Referring to FIG. 23A, with regard to the fifteenth type of FPMCP 318, for forming its three-dimensional chip package 461, the semiconductor substrate 2 of the upper semiconductor IC chip 100i of each of the face-to-face chip assemblies 462 may have a portion, at a backside of the semiconductor substrate 2 of the upper semiconductor IC chip 100i of said each of the face-to-face chip assemblies 462, removed by a chemical-mechanical-polishing (CMP) or mechanical grinding process, and the insulating lining layer 153 at a backside of each of the through silicon vias 157 (TSVs) of the upper semiconductor IC chip 100i of said each of the face-to-face chip assemblies 462 and the adhesion metal layer 154 and electroplating seed layer 155 of each of the through silicon vias 157 (TSVs) of the upper semiconductor IC chip 100i of said each of the face-to-face chip assemblies 462 at the backside of each of the through silicon vias 157 (TSVs) of the upper semiconductor IC chip 100i of said each of the face-to-face chip assemblies 462 may be removed by the chemical-mechanical-polishing (CMP) or mechanical grinding process to expose to a top surface of the electroplated copper layer 156 of each of the through silicon vias 157 (TSVs) of the upper semiconductor IC chip 100i of said each of the face-to-face chip assemblies 462. Next, the semiconductor substrate 2 of the upper semiconductor IC chip 100i of said each of the face-to-face chip assemblies 462 may be etched to form a recess from the top surface of the electroplated copper layer 156 of each of the through silicon vias 157 (TSVs) of the upper semiconductor IC chip 100i of said each of the face-to-face chip assemblies 462, and then an insulating dielectric layer 185, such as silicon-oxide layer or silicon-nitride layer, may be formed in the recess and on the backside of the semiconductor substrate 2 of the upper semiconductor IC chip 100i of said each of the face-to-face chip assemblies 462, wherein the insulating dielectric layer 185 of the upper semiconductor IC chip 100i of said each of the face-to-face chip assemblies 462 may have a top surface coplanar with the top surface of each of the through silicon vias 157 of the upper semiconductor IC chip 100i of said each of the face-to-face chip assemblies 462. The first or second type of metal bumps, pillars or pads 570 as illustrated in FIG. 6A may be formed as top metal bumps, pillars or pads of said each of the face-to-face chip assemblies 462 and at a top of the upper semiconductor IC chip 100i of said each of the face-to-face chip assemblies 462 following the same process to form the first or second type of metal bumps, pillars or pads 570 at a bottom of the FPGA IC chip 200 of the fifth type of FPMCP 308 as illustrated in the first through third aspects in FIGS. 13A and 13E to be turned upside down. Thereby, in the first aspect each of the top metal bumps, pillars or pads 570 of said each of the face-to-face chip assemblies 462 may have the adhesion metal layer 26a on the top surface of one of the through silicon vias (TSVs) 157, i.e., the electroplated copper layer 156 thereof, of the upper semiconductor IC chip 100i of said each of the face-to-face chip assemblies 462 and the top surface of the insulating dielectric layer 185 of the upper semiconductor IC chip 100i of said each of the face-to-face chip assemblies 462. In the second aspect, each of the top metal bumps, pillars or pads 570 of said each of the face-to-face chip assemblies 462 may have the adhesion metal layer 26a thereof formed on the top surface of the electroplated copper layer 156 of each of the set of through silicon vias 157 (TSVs) of the upper semiconductor IC chip 100i of said each of the face-to-face chip assemblies 462 and the top surface of the insulating dielectric layer 185 of the upper semiconductor IC chip 100i of said each of the face-to-face chip assemblies 462 to couple the set of through silicon vias 157 (TSVs) of the upper semiconductor IC chip 100i of said each of the face-to-face chip assemblies 462, wherein the reference layer 6f of the first interconnection scheme for a chip (FISC) 20 of the upper semiconductor IC chip 100i of said each of the face-to-face chip assemblies 462 for the second kind as illustrated in FIGS. 3G and 3H to be turned upside down may couple the set of through silicon vias 157 (TSVs) of the upper semiconductor IC chip 100i of said each of the face-to-face chip assemblies 462, the reference layer 6f of the first interconnection scheme for a chip (FISC) 20 of the upper semiconductor IC chip 100i of said each of the face-to-face chip assemblies 462 for the third kind as illustrated in FIG. 3I to be turned upside down may couple the set of through silicon vias 157 (TSVs) of the upper semiconductor IC chip 100i of said each of the face-to-face chip assemblies 462, and the second portion of the bottommost one of the interconnection metal layers 6 of the first interconnection scheme for a chip (FISC) 20 of the upper semiconductor IC chip 100i of said each of the face-to-face chip assemblies 462 for the fourth kind as illustrated in FIG. 3J to be turned upside down may couple the set of through silicon vias 157 (TSVs) of the upper semiconductor IC chip 100i of said each of the face-to-face chip assemblies 462, wherein a pitch or space between each neighboring two of the set of through silicon vias 157 (TSVs) of the upper semiconductor IC chip 100i of said each of the face-to-face chip assemblies 462, i.e., the electroplated copper layers 156 thereof, may be between 5 and 50 micrometers. In the third aspect, the upper semiconductor IC chip 100i of said each of the face-to-face chip assemblies 462 may be further formed with the insulating dielectric layer 587, as illustrated in FIG. 13E to be turned upside down, on the top surface of the insulating dielectric layer 185 of the upper semiconductor IC chip 100i of said each of the face-to-face chip assemblies 462 as illustrated for the second aspect for the upper semiconductor IC chip 100i of said each of the face-to-face chip assemblies 462, wherein an opening in the insulating dielectric layer 587 of the upper semiconductor IC chip 100i of said each of the face-to-face chip assemblies 462 may be vertically over the set of through silicon vias 157 (TSVs) of the upper semiconductor IC chip 100i of said each of the face-to-face chip assemblies 462 and said each of the top metal bumps, pillars or pads 570 may be formed in and over the opening in the insulating dielectric layer 587 of the upper semiconductor IC chip 100i of said each of the face-to-face chip assemblies 462 and on a top surface of the insulating dielectric layer 587 of the upper semiconductor IC chip 100i of said each of the face-to-face chip assemblies 462 and have the adhesion metal layer 26a thereof formed on the top surface of the electroplated copper layer 156 of each of the set of through silicon vias 157 (TSVs) of the upper semiconductor IC chip 100i of said each of the face-to-face chip assemblies 462, the top surface of the insulating dielectric layer 185 of the upper semiconductor IC chip 100i of said each of the face-to-face chip assemblies 462 and the top surface of the insulating dielectric layer 587 of the upper semiconductor IC chip 100i of said each of the face-to-face chip assemblies 462 to couple the set of through silicon vias 157 (TSVs) of the upper semiconductor IC chip 100i of said each of the face-to-face chip assemblies 462.

Referring to FIG. 23A, with regard to the fifteenth type of FPMCP 318, for forming its three-dimensional chip package 461, the semiconductor substrate 2 of the lower semiconductor IC chip 100j of each of the face-to-face chip assemblies 462 may have a portion, at a backside of the semiconductor substrate 2 of the lower semiconductor IC chip 100j of said each of the face-to-face chip assemblies 462, removed by a chemical-mechanical-polishing (CMP) or mechanical grinding process, and the insulating lining layer 153 at a backside of each of the through silicon vias 157 (TSVs) of the lower semiconductor IC chip 100j of said each of the face-to-face chip assemblies 462 and the adhesion metal layer 154 and electroplating seed layer 155 of each of the through silicon vias 157 (TSVs) of the lower semiconductor IC chip 100j of said each of the face-to-face chip assemblies 462 at the backside of each of the through silicon vias 157 (TSVs) of the lower semiconductor IC chip 100j of said each of the face-to-face chip assemblies 462 may be removed by the chemical-mechanical-polishing (CMP) or mechanical grinding process to expose to a bottom surface of the electroplated copper layer 156 of each of the through silicon vias 157 (TSVs) of the lower semiconductor IC chip 100j of said each of the face-to-face chip assemblies 462. Next, the semiconductor substrate 2 of the lower semiconductor IC chip 100j of said each of the face-to-face chip assemblies 462 may be etched to form a recess from the bottom surface of the electroplated copper layer 156 of each of the through silicon vias 157 (TSVs) of the lower semiconductor IC chip 100j of said each of the face-to-face chip assemblies 462, and then an insulating dielectric layer 185, such as silicon-oxide layer or silicon-nitride layer, may be formed in the recess and on the backside of the semiconductor substrate 2 of the lower semiconductor IC chip 100j of said each of the face-to-face chip assemblies 462, wherein the insulating dielectric layer 185 of the lower semiconductor IC chip 100j of said each of the face-to-face chip assemblies 462 may have a bottom surface coplanar with the bottom surface of each of the through silicon vias 157 of the lower semiconductor IC chip 100j of said each of the face-to-face chip assemblies 462. The first or second type of metal bumps, pillars or pads 570 as illustrated in FIG. 6A may be formed as bottom metal bumps, pillars or pads of said each of the face-to-face chip assemblies 462 and at a bottom of the lower semiconductor IC chip 100j of said each of the face-to-face chip assemblies 462 following the same process to form the first or second type of metal bumps, pillars or pads 570 at a bottom of the FPGA IC chip 200 of the fifth type of FPMCP 308 as illustrated in the first through third aspects in FIGS. 13A and 13E. Thereby, in the first aspect each of the bottom metal bumps, pillars or pads 570 of said each of the face-to-face chip assemblies 462 may have the adhesion metal layer 26a on the bottom surface of one of the through silicon vias (TSVs) 157, i.e., the electroplated copper layer 156 thereof, of the lower semiconductor IC chip 100j of said each of the face-to-face chip assemblies 462 and the bottom surface of the insulating dielectric layer 185 of the lower semiconductor IC chip 100j of said each of the face-to-face chip assemblies 462. In the second aspect, each of the bottom metal bumps, pillars or pads 570 of said each of the face-to-face chip assemblies 462 may have the adhesion metal layer 26a thereof formed on the bottom surface of the electroplated copper layer 156 of each of the set of through silicon vias 157 (TSVs) of the lower semiconductor IC chip 100j of said each of the face-to-face chip assemblies 462 and the bottom surface of the insulating dielectric layer 185 of the lower semiconductor IC chip 100j of said each of the face-to-face chip assemblies 462 to couple the set of through silicon vias 157 (TSVs) of the lower semiconductor IC chip 100j of said each of the face-to-face chip assemblies 462, wherein the reference layer 6f of the first interconnection scheme for a chip (FISC) 20 of the lower semiconductor IC chip 100j of said each of the face-to-face chip assemblies 462 for the second kind as illustrated in FIGS. 3G and 3H may couple the set of through silicon vias 157 (TSVs) of the lower semiconductor IC chip 100j of said each of the face-to-face chip assemblies 462, the reference layer 6f of the first interconnection scheme for a chip (FISC) 20 of the lower semiconductor IC chip 100j of said each of the face-to-face chip assemblies 462 for the third kind as illustrated in FIG. 3I may couple the set of through silicon vias 157 (TSVs) of the lower semiconductor IC chip 100j of said each of the face-to-face chip assemblies 462, and the second portion of the bottommost one of the interconnection metal layers 6 of the first interconnection scheme for a chip (FISC) 20 of the lower semiconductor IC chip 100j of said each of the face-to-face chip assemblies 462 for the fourth kind as illustrated in FIG. 3J may couple the set of through silicon vias 157 (TSVs) of the lower semiconductor IC chip 100j of said each of the face-to-face chip assemblies 462, wherein a pitch or space between each neighboring two of the set of through silicon vias 157 (TSVs) of the lower semiconductor IC chip 100j of said each of the face-to-face chip assemblies 462, i.e., the electroplated copper layers 156 thereof, may be between 5 and 50 micrometers. In the third aspect, the lower semiconductor IC chip 100j of said each of the face-to-face chip assemblies 462 may be further formed with the insulating dielectric layer 587 as illustrated in FIG. 13E on the bottom surface of the insulating dielectric layer 185 of the lower semiconductor IC chip 100j of said each of the face-to-face chip assemblies 462 as illustrated for the second aspect for the upper semiconductor IC chip 100i of said each of the face-to-face chip assemblies 462, wherein an opening in the insulating dielectric layer 587 of the lower semiconductor IC chip 100j of said each of the face-to-face chip assemblies 462 may be vertically under the set of through silicon vias 157 (TSVs) of the lower semiconductor IC chip 100j of said each of the face-to-face chip assemblies 462 and said each of the bottom metal bumps, pillars or pads 570 may be formed in and under the opening in the insulating dielectric layer 587 of the lower semiconductor IC chip 100j of said each of the face-to-face chip assemblies 462 and on a bottom surface of the insulating dielectric layer 587 of the lower semiconductor IC chip 100j of said each of the face-to-face chip assemblies 462 and have the adhesion metal layer 26a thereof formed on the bottom surface of the electroplated copper layer 156 of each of the set of through silicon vias 157 (TSVs) of the lower semiconductor IC chip 100j of said each of the face-to-face chip assemblies 462, the bottom surface of the insulating dielectric layer 185 of the lower semiconductor IC chip 100j of said each of the face-to-face chip assemblies 462 and the bottom surface of the insulating dielectric layer 587 of the lower semiconductor IC chip 100j of said each of the face-to-face chip assemblies 462 to couple the set of through silicon vias 157 (TSVs) of the lower semiconductor IC chip 100j of said each of the face-to-face chip assemblies 462. The upper semiconductor IC chip 100i of said each of the face-to-face chip assemblies 462 may have a vertical sidewall coplanar with a vertical sidewall of the lower semiconductor IC chip 100j of said each of the face-to-face chip assemblies 462.

Referring to FIG. 23A, with regard to the fifteenth type of FPMCP 318, for forming its three-dimensional chip package 461, the semiconductor substrate 2 of the auxiliary IC chip 411 may have a portion, at a backside of the semiconductor substrate 2 of the auxiliary IC chip 411, removed by a chemical-mechanical-polishing (CMP) or mechanical grinding process, and the insulating lining layer 153 at a backside of each of the through silicon vias 157 (TSVs) of the auxiliary IC chip 411 and the adhesion metal layer 154 and electroplating seed layer 155 of each of the through silicon vias 157 (TSVs) of the auxiliary IC chip 411 at the backside of each of the through silicon vias 157 (TSVs) of the auxiliary IC chip 411 may be removed by the chemical-mechanical-polishing (CMP) or mechanical grinding process to expose to a top surface of the electroplated copper layer 156 of each of the through silicon vias 157 (TSVs) of the auxiliary IC chip 411. Next, the semiconductor substrate 2 of the auxiliary IC chip 411 may be etched to form a recess from the top surface of the electroplated copper layer 156 of each of the through silicon vias 157 (TSVs) of the auxiliary IC chip 411, and then an insulating dielectric layer 185, such as silicon-oxide layer or silicon-nitride layer, may be formed in the recess and on the backside of the semiconductor substrate 2 of the auxiliary IC chip 411, wherein the insulating dielectric layer 185 of the auxiliary IC chip 411 may have a top surface coplanar with a top surface of each of the through silicon vias 157 of the auxiliary IC chip 411. The first or second type of metal bumps, pillars or pads 570 as illustrated in FIG. 6A may be formed as top metal bumps, pillars or pads of the auxiliary IC chip 411 and at a top of the auxiliary IC chip 411 following the same process to form the first or second type of metal bumps, pillars or pads 570 at a bottom of the FPGA IC chip 200 of the fifth type of FPMCP 308 as illustrated in the first through third aspects in FIGS. 13A and 13E to be turned upside down. Thereby, in the first aspect each of the top metal bumps, pillars or pads 570 of the auxiliary IC chip 411 may have the adhesion metal layer 26a on the top surface of one of the through silicon vias (TSVs) 157, i.e., the electroplated copper layer 156 thereof, of the auxiliary IC chip 411 and the top surface of the insulating dielectric layer 185 of the auxiliary IC chip 411. In the second aspect, each of the top metal bumps, pillars or pads 570 of the auxiliary IC chip 411 may have the adhesion metal layer 26a thereof formed on the top surface of the electroplated copper layer 156 of each of the set of through silicon vias 157 (TSVs) of the auxiliary IC chip 411 and the top surface of the insulating dielectric layer 185 of the auxiliary IC chip 411 to couple the set of through silicon vias 157 (TSVs) of the auxiliary IC chip 411, wherein the reference layer 6f of the first interconnection scheme for a chip (FISC) 20 of the auxiliary IC chip 411 for the second kind as illustrated in FIGS. 3G and 3H to be turned upside down may couple the set of through silicon vias 157 (TSVs) of the auxiliary IC chip 411, the reference layer 6f of the first interconnection scheme for a chip (FISC) 20 of the auxiliary IC chip 411 for the third kind as illustrated in FIG. 3I to be turned upside down may couple the set of through silicon vias 157 (TSVs) of the auxiliary IC chip 411, and the second portion of the bottommost one of the interconnection metal layers 6 of the first interconnection scheme for a chip (FISC) 20 of the auxiliary IC chip 411 for the fourth kind as illustrated in FIG. 3J to be turned upside down may couple the set of through silicon vias 157 (TSVs) of the auxiliary IC chip 411, wherein a pitch or space between each neighboring two of the set of through silicon vias 157 (TSVs) of the auxiliary IC chip 411, i.e., the electroplated copper layers 156 thereof, may be between 5 and 50 micrometers. In the third aspect, the auxiliary IC chip 411 may be further formed with the insulating dielectric layer 587, as illustrated in FIG. 13E to be turned upside down, on the top surface of the insulating dielectric layer 185 of the auxiliary IC chip 411 as illustrated for the second aspect for the auxiliary IC chip 411, wherein an opening in the insulating dielectric layer 587 of the auxiliary IC chip 411 may be vertically over the set of through silicon vias 157 (TSVs) of the auxiliary IC chip 411 and said each of the top metal bumps, pillars or pads 570 may be formed in and over the opening in the insulating dielectric layer 587 of the auxiliary IC chip 411 and on a top surface of the insulating dielectric layer 587 of the auxiliary IC chip 411 and have the adhesion metal layer 26a thereof formed on the top surface of the electroplated copper layer 156 of each of the set of through silicon vias 157 (TSVs) of the auxiliary IC chip 411, the top surface of the insulating dielectric layer 185 of the auxiliary IC chip 411 and the top surface of the insulating dielectric layer 587 of the auxiliary IC chip 411 to couple the set of through silicon vias 157 (TSVs) of the auxiliary IC chip 411.

Referring to FIG. 23A, with regard to the fifteenth type of FPMCP 318, for forming its three-dimensional chip package 461, each of the bottom metal bumps, pillars or pads 570 of the lower semiconductor IC chip 100j of an upper one of the face-to-face chip assemblies 462 may be boned to one of the top metal bumps, pillars or pads 570 of the upper semiconductor IC chip 100i of a lower one of the face-to-face chip assemblies 462 into a bonded metal bump or contact 563 between the lower semiconductor IC chip 100j of the upper one of the face-to-face chip assemblies 462 and the upper semiconductor IC chip 100i of the lower one of the face-to-face chip assemblies 462. For example, each of the bonded metal bumps or contacts 563 of its three-dimensional chip package 461 may include a copper bump having a thickness between 10 and 100 micrometers between the lower semiconductor IC chip 100j of the upper one of the face-to-face chip assemblies 462 and the upper semiconductor IC chip 100i of the lower one of the face-to-face chip assemblies 462 and a tin-containing layer between the copper layer of said each of the bonded metal bumps or contacts 563 and the upper semiconductor IC chip 100i of the lower one of the face-to-face chip assemblies 462.

Referring to FIG. 23A, with regard to the fifteenth type of FPMCP 318, for forming its three-dimensional chip package 461, each of the bottom metal bumps, pillars or pads 570 of the lower semiconductor IC chip 100j of the bottommost one of the face-to-face chip assemblies 462 may be boned to one of the top metal bumps, pillars or pads 570 of the auxiliary IC chip 411 into a bonded metal bump or contact 463 between the lower semiconductor IC chip 100j of the bottommost one of the face-to-face chip assemblies 462 and the auxiliary IC chip 411. For example, each of the bonded metal bumps or contacts 463 may include a copper bump having a thickness between 10 and 100 micrometers between the lower semiconductor IC chip 100j of the bottommost one of the face-to-face chip assemblies 462 and the auxiliary IC chip 411 and a tin-containing layer between the copper layer of said each of the bonded metal bumps or contacts 463 and the auxiliary IC chip 411.

Referring to FIG. 23A, with regard to the fifteenth type of FPMCP 318, for forming its three-dimensional chip package 461, the NVM IC chip 250 may have the first, second, third or fourth type of micro-bumps, micro-pillars or micro-pads 34 as illustrated in FIG. 3A each bonded to one of the metal bumps, pillars or pads of the upper semiconductor IC chip 100i of the topmost one of the face-to-face chip assemblies 462 into a bonded metal bump or contact 363 between the NVM IC chip 250 and the upper semiconductor IC chip 100i of the topmost one of the face-to-face chip assemblies 462. For example, each of the bonded metal bumps or contacts 363 may include a copper bump having a thickness between 10 and 100 micrometers between the NVM IC chip 250 and the upper semiconductor IC chip 100i of the topmost one of the face-to-face chip assemblies 462 and a tin-containing layer between the copper layer of said each of the bonded metal bumps or contacts 363 and the upper semiconductor IC chip 100i of the topmost one of the face-to-face chip assemblies 462.

Referring to FIG. 23A, for the fifteenth type of FPMCP 318, its three-dimensional chip package 461 may further include an underfill 564, i.e., polymer layer, between the lower semiconductor IC chip 100j of the upper one of the face-to-face chip assemblies 462 of its three-dimensional chip package 461 and the upper semiconductor IC chip 100i of the lower one of the face-to-face chip assemblies 462 of its three-dimensional chip package 461, between the lower semiconductor IC chip 100j of the bottommost one of the face-to-face chip assemblies 462 of its three-dimensional chip package 461 and the auxiliary IC chip 411 of its three-dimensional chip package 461 and between the NVM IC chip 250 of its three-dimensional chip package 461 and the upper semiconductor IC chip 100i of the topmost one of the face-to-face chip assemblies 462 of its three-dimensional chip package 461, covering a sidewall of each of the bonded metal bumps or contacts 363, 463 and 563 of its three-dimensional chip package 461.

Referring to FIG. 23A, for the fifteenth type of FPMCP 318, its three-dimensional chip package 461 may further include a polymer layer 92 or insulating dielectric layer, i.e., sealing layer, such as silicon-oxide-containing molding compound, epoxy-based material or polyimide, on the auxiliary IC chip 411 of its three-dimensional chip package 461 and horizontally around each of the upper and lower semiconductor IC chips 100i and 100j of each of the face-to-face chip assemblies 462 of its three-dimensional chip package 461 and the NVM IC chip 250 of its three-dimensional chip package 461, wherein the polymer layer 92 of its three-dimensional chip package 461 may have a top surface coplanar with a top surface of the NVM IC chip 250 of its three-dimensional chip package 461 and a vertical sidewall coplanar with a vertical sidewall of the auxiliary IC chip 411 of its three-dimensional chip package 461.

Referring to FIG. 23A, for the fifteenth type of FPMCP 318, the auxiliary IC chip 411 of its three-dimensional chip package 461 may have the first, second, third or fourth type of micro-bumps, micro-pillars or micro-pads 34 as illustrated in FIGS. 3A and 3B each bonded to a front side of its circuit substrate 451 into a bonded metal bump or contact 263 between the auxiliary IC chip 411 of its three-dimensional chip package 461 and its circuit substrate 451. For example, each of its bonded metal bumps or contacts 263 may include a copper bump having a thickness between 10 and 100 micrometers between the auxiliary IC chip 411 of its three-dimensional chip package 461 and its circuit substrate 451 and a tin-containing layer between the copper layer of said each of its bonded metal bumps or contacts 263 and its circuit substrate 451. The fifteenth type of FPMCP 318 may further include an underfill 564, i.e., polymer layer, between the auxiliary IC chip 411 of its three-dimensional chip package 461 and the front side of its circuit substrate 451, covering a sidewall of each of its bonded metal bumps or contacts 263.

Referring to FIG. 23A, for the fifteenth type of FPMCP 318, each of its metal contacts 452 may be one of the metal bumps, pillars or pads 570 as illustrated in FIGS. 6A and 6C to be formed on the bottom surface of its circuit substrate 451 when provided by the interposer 551 as illustrated in FIGS. 6A and 6C for any of the first through third aspects. Each of its metal bumps, pillars or pads 570 may be of a type selected from various types, i.e., first and second types, which may have the same specification as that of the first and second types of metal bumps, pillars or pads 570 respectively as illustrated in FIG. 6A, and may have the adhesion metal layer 26a on a bottom surface of one of the bottom surface of one of the through silicon vias 558, i.e., the copper layer 557 thereof, of its interposer 551 and on the bottom surface of the insulating dielectric layer 585 of its interposer 551. Alternatively, each of its metal contacts 452 may be one of the solder balls 538, made of a tin-lead alloy or tin-silver-copper alloy, as illustrated in FIGS. 19 and 19-1 to be formed on the bottom surface of its circuit substrate 451 when provided by the ball-grid-array (BGA) substrate 537 as illustrated in FIGS. 19 and 19-1. Each of its solder balls 538 may be formed on a bottom surface of one of the metal pads of the bottommost one of the interconnection metal layers of its ball-grid-array (BGA) substrate 537.

Referring to FIG. 23A, for the fifteenth type of FPMCP 318, the NVM IC chip 250 of its three-dimensional chip package 461 may couple to one of its metal contacts 452 through, in sequence, one of the through silicon vias (TSVs) 157 of each of the upper and lower semiconductor IC chips 100i and 100j of each of the face-to-face chip assemblies 462 of its three-dimensional chip package 461, one of the through silicon vias (TSVs) 157 of the auxiliary IC chip 411 of its three-dimensional chip package 461 and its circuit substrate 451 for transmitting a signal or clock or delivering a power or ground voltage therebetween. An upper one of the upper and lower semiconductor IC chips 100i and 100j of the face-to-face chip assemblies 462 of its three-dimensional chip package 461 may couple to one of its metal contacts 452 through, in sequence, one of the through silicon vias (TSVs) 157 of each lower one of the upper and lower semiconductor IC chips 100i and 100j of the face-to-face chip assemblies 462 of its three-dimensional chip package 461, one of the through silicon vias (TSVs) 157 of the auxiliary IC chip 411 of its three-dimensional chip package 461 and its circuit substrate 451 for transmitting a signal or clock or delivering a power or ground voltage therebetween. The auxiliary IC chip 411 of its three-dimensional chip package 461 may couple to one of its metal contacts 452 through its circuit substrate 451 for transmitting a signal or clock or delivering a power or ground voltage therebetween.

Alternatively, for the fifteenth type of FPMCP 318, the upper semiconductor IC chip 100i of each of the face-to-face chip assemblies 462 of its three-dimensional chip package 461 may be bonded to the lower semiconductor IC chip 100j of said each of the face-to-face chip assemblies 462 of its three-dimensional chip package 461 by wafer bumping as seen in FIG. 23B, instead of hybrid bonding. Referring to FIG. 23B, the upper semiconductor IC chip 100i of each of the face-to-face chip assemblies 462 of its three-dimensional chip package 461 may have the same specification as the second type of semiconductor IC chip 100 illustrated in FIGS. 3B and 3G-3J to be turned upside down, and the lower semiconductor IC chip 100j of each of the face-to-face chip assemblies 462 of its three-dimensional chip package 461 may have the same specification as the second type of semiconductor IC chip 100 illustrated in FIGS. 3B and 3G-3J. The upper semiconductor IC chip 100i of each of the face-to-face chip assemblies 462 of its three-dimensional chip package 461 may have the first, second, third or fourth type of micro-bumps, micro-pillars or micro-pads 34 each bonded to one of the first, second, third or fourth type of micro-bumps, micro-pillars or micro-pads 34 of the lower semiconductor IC chip 100j of said each of the face-to-face chip assemblies 462 of its three-dimensional chip package 461 into a bonded metal bump or contact 663 between the upper and lower semiconductor IC chips 100i and 100j of said each of the face-to-face chip assemblies 462 of its three-dimensional chip package 461. The bonding for its bonded metal bump or contact 663 as seen in FIG. 23B may be referred to that as illustrated in FIGS. 13B, 13C and 13D, wherein the first, second, third or fourth type of micro-bumps, micro-pillars or micro-pads 34 of the upper semiconductor IC chip 100i of said each of the face-to-face chip assemblies 462 of its three-dimensional chip package 461 may be analogous respectively to the first, second, third or fourth type of micro-bumps, micro-pillars or micro-pads 34 of the NVM IC chip 250 or auxiliary IC chip 411 as illustrated in FIGS. 13B, 13C and 13D, and the first, second, third or fourth type of metal bumps, pillars or pads of the lower semiconductor IC chip 100j of said each of the face-to-face chip assemblies 462 of its three-dimensional chip package 461 may be analogous respectively to the first, second, third or fourth type of micro-bumps, micro-pillars or micro-pads 34 of the FPGA IC chip 200 as illustrated in FIGS. 13B, 13C and 13D.

Referring to FIG. 23B, the fifteenth type of FPMCP 318 may further an underfill 564, e.g., polymer layer, between the upper and lower semiconductor IC chips 100i and 100j of each of the face-to-face chip assemblies 462 of its three-dimensional chip package 461, covering a sidewall of each of its bonded metal bumps or contacts 663.

For the fifteenth type of FPMCP 318 as seen in FIG. 23A or 23B, each of the upper and lower semiconductor IC chips 100i and 100j of each of the face-to-face chip assemblies 462 of its three-dimensional chip package 461 may include the first, second or third type of field programmable logic cell or element (LCE) 2014 as illustrated in FIGS. 1A-1C, the first or second type of field programmable switch cell 379 as illustrated in FIGS. 2A and 2B and the programmable switch matrix 710 as illustrated in FIG. 2C. One or more bonds each between one of the metal pads 6a of the upper semiconductor IC chip 100i of said each of the face-to-face chip assemblies 462 of its three-dimensional chip package 461 and one of the metal pads 6a of the lower semiconductor IC chip 100j of said each of the face-to-face chip assemblies 462 of its three-dimensional chip package 461, as illustrated in FIG. 23A, or one or more of its bonded metal bump or contact 663 as illustrated in FIG. 23B, may couple one of any type of the first, second and third types of field programmable logic cells or elements (LCE) 2014 of the upper semiconductor IC chip 100i of said each of the face-to-face chip assemblies 462 of its three-dimensional chip package 461 to one of any type of the first, second and third types of field programmable logic cells or elements (LCE) 2014 of the lower semiconductor IC chip 100j of said each of the face-to-face chip assemblies 462 of its three-dimensional chip package 461; accordingly, said one of any type of the first, second and third types of field programmable logic cells or elements (LCE) 2014 of the upper semiconductor IC chip 100i of said each of the face-to-face chip assemblies 462 of its three-dimensional chip package 461 may have the input data set having data associated with the output data of said one of any type of the first, second and third types of field programmable logic cells or elements (LCE) 2014 of the lower semiconductor IC chip 100j of said each of the face-to-face chip assemblies 462 of its three-dimensional chip package 461, or said one of any type of the first, second and third types of field programmable logic cells or elements (LCE) 2014 of the lower semiconductor IC chip 100j of said each of the face-to-face chip assemblies 462 of its three-dimensional chip package 461 may have the input data set having data associated with the output data of said one of any type of the first, second and third types of field programmable logic cells or elements (LCE) 2014 of the upper semiconductor IC chip 100i of said each of the face-to-face chip assemblies 462 of its three-dimensional chip package 461. Said one of any type of the first, second and third types of field programmable logic cells or elements (LCE) 2014 of the upper semiconductor IC chip 100i of said each of the face-to-face chip assemblies 462 of its three-dimensional chip package 461 may be configured in accordance with first data stored in the NVM IC chip 250 of its three-dimensional chip package 461 and have the memory cells, e.g., ones 490 as illustrated in FIG. 1A or ones as illustrated in FIG. 1B or 1C, for storing second data associated with the first data; said one of any type of the first, second and third types of field programmable logic cells or elements (LCE) 2014 of the lower semiconductor IC chip 100j of said each of the face-to-face chip assemblies 462 of its three-dimensional chip package 461 may be configured in accordance with third data stored in the NVM IC chip 250 of its three-dimensional chip package 461 and have the memory cells, e.g., ones 490 as illustrated in FIG. 1A or ones as illustrated in FIG. 1B or 1C, for storing fourth data associated with the third data. Further, one or more bonds each between one of the metal pads 6a of the upper semiconductor IC chip 100i of said each of the face-to-face chip assemblies 462 of its three-dimensional chip package 461 and one of the metal pads 6a of the lower semiconductor IC chip 100j of said each of the face-to-face chip assemblies 462 of its three-dimensional chip package 461, as illustrated in FIG. 23A, or one or more of its bonded metal bump or contact 663 as illustrated in FIG. 23B, may couple one of either type of the first and second types of field programmable switch cells 379 of the upper semiconductor IC chip 100i of said each of the face-to-face chip assemblies 462 of its three-dimensional chip package 461 to one of either type of the first and second types of field programmable switch cells 379 of the lower semiconductor IC chip 100j of said each of the face-to-face chip assemblies 462 of its three-dimensional chip package 461 or couple the programmable switch matrix 710 of the upper semiconductor IC chip 100i of said each of the face-to-face chip assemblies 462 of its three-dimensional chip package 461 to the programmable switch matrix 710 of the lower semiconductor IC chip 100j of said each of the face-to-face chip assemblies 462 of its three-dimensional chip package 461; accordingly, one of the nodes of said one of either type of the first and second types of field programmable switch cells 379 of the upper semiconductor IC chip 100i of said each of the face-to-face chip assemblies 462 of its three-dimensional chip package 461 may be associated with one of the nodes of said one of either type of the first and second types of field programmable switch cells 379 of the lower semiconductor IC chip 100j of said each of the face-to-face chip assemblies 462 of its three-dimensional chip package 461, and one of the nodes P₁-P_{N} of the programmable switch matrix 710 of the upper semiconductor IC chip 100i of said each of the face-to-face chip assemblies 462 of its three-dimensional chip package 461 may be associated with one of the nodes Q₁-Q_{M} of the programmable switch matrix 710 of the lower semiconductor IC chip 100j of said each of the face-to-face chip assemblies 462 of its three-dimensional chip package 461. Said one of either type of the first and second types of field programmable switch cells 379 of the upper semiconductor IC chip 100i of said each of the face-to-face chip assemblies 462 of its three-dimensional chip package 461 and the programmable switch matrix 710 of the upper semiconductor IC chip 100i of said each of the face-to-face chip assemblies 462 may be configured in accordance with fifth data stored in the NVM IC chip 250 of its three-dimensional chip package 461 and have the memory cells 362 as illustrated in FIG. 2A or 2B for storing sixth data associated with the fifth data, said one of either type of the first and second types of field programmable switch cells 379 of the lower semiconductor IC chip 100j of said each of the face-to-face chip assemblies 462 of its three-dimensional chip package 461 and the programmable switch matrix 710 of the lower semiconductor IC chip 100j of said each of the face-to-face chip assemblies 462 may be configured in accordance with seventh data stored in the NVM IC chip 250 of its three-dimensional chip package 461 and have the memory cells 362 as illustrated in FIG. 2A or 2B for storing eighth data associated with the seventh data.

For the fifteenth type of FPMCP 318 as seen in FIG. 23A or 23B, each of its bonded metal bumps or contacts 463 may couple to one of the through silicon vias (TSVs) 157 of each of the upper and lower semiconductor IC chips 100i and 100j of each of the face-to-face chip assemblies 462 of its three-dimensional chip package 461, to one of the bonded metal bumps or contacts 563 of its three-dimensional chip package 461 between each neighboring two of the face-to-face chip assemblies 462 of its three-dimensional chip package 461, to the bonded two of the metal pads 6a of the upper and lower semiconductor IC chips 100i and 100j of each of the face-to-face chip assemblies 462 of its three-dimensional chip package 461 and to one of the through silicon vias (TSVs) 157 of the auxiliary IC chip 411 of its three-dimensional chip package 461 to form a first signal path coupling a first small input/output (I/O) circuit of said each of the upper and lower semiconductor IC chips 100i and 100j to a second small input/output (I/O) circuit of the auxiliary IC chip 411 of its three-dimensional chip package 461, wherein each of the first and second small I/O circuits may have an input/output (I/O) power efficiency smaller than 0.5 pico-Joules per bit, per switch or per voltage swing, or between 0.01 and 0.5 pico-Joules per bit, per switch or per voltage swing and/or having an output capacitance or driving capability or loading between 0.05 pF and 2 pF, between 0.1 pF and 2 pF, between 0.05 pF and 1 pF or between 0.1 pF and 1 pF, or equal to or smaller than 2 pF, 1 pF or 0.5 pF with a power supply voltage (Vdd) equal to or lower than 1.2 volts, 1 volt, 0.8 volts or 0.5 volts and/or a voltage swing equal to or smaller than 1.2 volts, 1 volt, 0.8 volts or 0.5 volts. Each of its bonded metal bumps or contacts 263 may couple to its circuit substrate 451 to form a second signal path coupling a large input/output (I/O) circuit of the auxiliary IC chip 411 of its three-dimensional chip package 461 to one of its metal contacts 452, wherein the large input/output (I/O) circuit of the auxiliary IC chip 411 of its three-dimensional chip package 461 may have an input/output (I/O) power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, or between 2 pF and 5 pF, or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. Thereby, each of the second small input/output (I/O) circuits may receive first signals from one of the first small input/output (I/O) circuits of either of the upper and lower semiconductor IC chips 100i and 100j of either or any of the face-to-face chip assemblies 462 of its three-dimensional chip package 461 via one of its first signal paths to be converted by the auxiliary IC chip 411 of its three-dimensional chip package 461 as second signals and then any of the large input/output (I/O) circuits of the auxiliary IC chip 411 of its three-dimensional chip package 461 may transmit the second signals to one of its metal contacts 452 via one of its second signal paths. Further, each of the large input/output (I/O) circuits of the auxiliary IC chip 411 of its three-dimensional chip package 461 may receive third signals from one of its metal contacts 452 via one of its second signal paths to be converted by the auxiliary IC chip 411 of its three-dimensional chip package 461 as fourth signals and then any of the second small input/output (I/O) circuits may transmit the fourth signals to one of the first small input/output (I/O) circuits of either of the upper and lower semiconductor IC chips 100i and 100j of either or any of the face-to-face chip assemblies 462 of its three-dimensional chip package 461 via one of its first signal paths.

For the fifteenth type of FPMCP 318 as seen in FIG. 23A or 23B, for a first case each of the upper and lower semiconductor IC chips 100i and 100j of each of the face-to-face chip assemblies 462 of its three-dimensional chip package 461 may be a FPGA IC chip, the dedicated field programmable integrated-circuit (DFPIC) chip as illustrated in FIG. 4D or the embedded field programmable integrated-circuit (eFPIC) chip as illustrated in FIG. 4E. For a second case, the lower semiconductor IC chip 100j of each of the face-to-face chip assemblies 462 of its three-dimensional chip package 461 may be a FPGA IC chip, and the upper semiconductor IC chip 100i of said each of the face-to-face chip assemblies 462 of its three-dimensional chip package 461 may be a graphic-processing-unit (GPU) IC chip, central-processing-unit (CPU) IC chip, digital-signal-processing (DSP) IC chip, innovated application-specific-IC (ASIC) or customer-owned-tooling (COT) (abbreviated as IAC) chip, or cooperating and supporting (CS) logic IC chip. For a third case, the lower semiconductor IC chip 100j of each of the face-to-face chip assemblies 462 of its three-dimensional chip package 461 may be an IAC chip, and the upper semiconductor IC chip 100i of said each of the face-to-face chip assemblies 462 of its three-dimensional chip package 461 may be a FPGA IC chip, graphic-processing-unit (GPU) IC chip, central-processing-unit (CPU) IC chip, digital-signal-processing (DSP) IC chip, or cooperating and supporting (CS) logic IC chip. For a fourth case, the lower semiconductor IC chip 100j of each of the face-to-face chip assemblies 462 of its three-dimensional chip package 461 may be an auxiliary IC chip, and the upper semiconductor IC chip 100i of said each of the face-to-face chip assemblies 462 of its three-dimensional chip package 461 may be a FPGA IC chip, graphic-processing-unit (GPU) IC chips, central-processing-unit (CPU) IC chip, digital-signal-processing (DSP) IC chip, IAC chip or cooperating and supporting (CS) logic IC chip. For a fifth case, the lower semiconductor IC chip 100j of each of the face-to-face chip assemblies 462 of its three-dimensional chip package 461 may be a power management integrated-circuit (PMIC) chip, and the upper semiconductor IC chip 100i of said each of the face-to-face chip assemblies 462 of its three-dimensional chip package 461 may be a FPGA IC chip, graphic-processing-unit (GPU) IC chips, central-processing-unit (CPU) IC chip, digital-signal-processing (DSP) IC chip, IAC chip or cooperating and supporting (CS) logic IC chip. For a sixth case, the lower semiconductor IC chip 100j of each of the face-to-face chip assemblies 462 of its three-dimensional chip package 461 may be a static random-access memory (SRAM) IC chip, and the upper semiconductor IC chip 100i of said each of the face-to-face chip assemblies 462 of its three-dimensional chip package 461 may be a FPGA IC chip, graphic-processing-unit (GPU) IC chips, central-processing-unit (CPU) IC chip, digital-signal-processing (DSP) IC chip, IAC chip or cooperating and supporting (CS) logic IC chip. For a seventh case, the lower semiconductor IC chip 100j of each of the face-to-face chip assemblies 462 of its three-dimensional chip package 461 may be a FPGA IC chip, graphic-processing-unit (GPU) IC chips, central-processing-unit (CPU) IC chip, digital-signal-processing (DSP) IC chip, IAC chip or cooperating and supporting (CS) logic IC chip, and the upper semiconductor IC chip 100i of said each of the face-to-face chip assemblies 462 of its three-dimensional chip package 461 may be a static random-access memory (SRAM) IC chip. For the above second through seventh cases, the IAC chip may have intellectual-property (IP) circuits, application-specific (AS) circuits, analog circuits, mixed-mode signal circuits, radio-frequency (RF) circuits, and/or transmitter, receiver or transceiver circuits, etc therein, and the auxiliary IC chip may have the large input/output (I/O) block, small-input/output (I/O) block, cryptography block, regulating block, IAC block and hard-macro block as illustrated in FIG. 5A-1 for the cooperating and supporting (CS) IC chip 411 or 412 respectively. For the above fourth case, the auxiliary IC chip may have power management circuits, such as voltage regulators or voltage converters, therein and may be provided with the large and small I/O circuits having the same specification as those illustrated in FIG. 5A-1 for the auxiliary IC chip 411. For a purpose of increasing yield of the fifteenth type of FPMCP 318 for the above first through seventh cases, each of its FPGA IC chip(s) may have a self-test and repair capability circuit, wherein said each of its FPGA IC chip(s) may have spare ones for the first, second or third type of field programmable logic cells or elements (LCE) 2014 of said each of its FPGA IC chip(s) for repairing the first, second or third type of field programmable logic cells or elements (LCE) 2014 of said each of its FPGA IC chip(s), and a ratio of the spare ones for the first, second or third type of field programmable logic cells or elements (LCE) 2014 of said each of its FPGA IC chip(s) to a total of the first, second or third type of field programmable logic cells or elements (LCE) 2014 of said each of its FPGA IC chip(s) may be between 0.1% and 10% or between 1% and 5%. The repairing method may be referred to U.S. Pat. No. 10,623,000, which is incorporated by reference herein.

FIGS. 23C-23M are schematically cross-sectional views showing a process for fabricating a three-dimensional chip package for a fifteenth type of FPMCP in FIG. 23A in accordance with an embodiment of the present application. Referring to FIG. 23C, for the fifteenth type of FPMCP 318 as seen in FIG. 23A, an upper semiconductor wafer 110a formed for the upper semiconductor IC chip 100i of each of the face-to-face chip assemblies 462 of its three-dimensional chip package 461 and a lower semiconductor wafer 110b formed for the lower semiconductor IC chip 100j of said each of the face-to-face chip assemblies 462 of its three-dimensional chip package 461 may be provided. Next, the upper semiconductor wafer 110a may be bonded to the lower semiconductor wafer 110b by the hybrid bonding, that is, the insulating bonding layer 52, i.e., silicon oxide, of the lower semiconductor wafer 110b may have a top surface attached to and in contact with a bottom surface of the insulating bonding layer 52, i.e., silicon oxide, of the upper semiconductor wafer 110a, and each of the metal pads 6a, i.e., the copper layer 24 thereof, of the lower semiconductor wafer 110b may have a top surface bonded to and in contact with a bottom surface of one of the metal pads 6a, i.e., the copper layer 24 thereof, of the upper semiconductor wafer 110a. Next, the semiconductor substrate 2 of the upper semiconductor wafer 110a may have a portion, at a backside of the semiconductor substrate 2 of the upper semiconductor wafer 110a, to be removed by a chemical-mechanical-polishing (CMP) or mechanical grinding process to expose the top surface of each of the through silicon vias (TSVs) 157, i.e., the copper layer 156 thereof, of the upper semiconductor wafer 110a as seen in FIG. 23D, wherein the backside of the semiconductor substrate 2 of the upper semiconductor wafer 110a may be coplanar with the top surface of each of the through silicon vias (TSVs) 157, i.e., the copper layer 156 thereof, of the upper semiconductor wafer 110a.

Next, the backside of the semiconductor substrate 2 of the upper semiconductor wafer 110a may be etched by a plasma etching process to have the backside of the semiconductor substrate 2 of the upper semiconductor wafer 110a recessed from the top surface of each of the through silicon vias (TSVs) 157, i.e., the copper layer 156 thereof, of the upper semiconductor wafer 110a. Next, the insulating dielectric layer 185, such as silicon-oxide layer or silicon-nitride layer, may be deposited on the backside of the semiconductor substrate 2 of the upper semiconductor wafer 110a and the top surface of each of the through silicon vias (TSVs) 157, i.e., the copper layer 156 thereof, of the upper semiconductor wafer 110a. Next, the insulating dielectric layer 185 may have a portion, at a backside of the insulating dielectric layer 185 of the upper semiconductor wafer 110a, to be removed by a chemical-mechanical-polishing (CMP) or mechanical grinding process to expose the top surface of each of the through silicon vias (TSVs) 157, i.e., the copper layer 156 thereof, of the upper semiconductor wafer 110a as seen in FIG. 23E, wherein the top surface of the insulating dielectric layer 185 of the upper semiconductor wafer 110a may be coplanar with the top surface of each of the through silicon vias (TSVs) 157, i.e., the copper layer 156 thereof, of the upper semiconductor wafer 110a.

Next, referring to FIG. 23F, multiple top metal bumps, pillars or pads 570 may be formed in an array and on a backside of the upper semiconductor wafer 110a, wherein each of the top metal bumps, pillars or pads 570 may be formed on the top surface of one of the through silicon vias (TSVs) 157, i.e., the copper layer 156 thereof, of the upper semiconductor wafer 110a and may be of a type selected from various types, i.e., first and second types, which may have the same specification as that of the first and second types of metal bumps, pillars or pads 570 respectively as illustrated in FIG. 6A to be turned upside down, wherein each of the top metal bumps, pillars or pads 570 may have the adhesion metal layer 26a on the top surface of one of the through silicon vias (TSVs) 157, i.e., the copper layer 156 thereof, of the upper semiconductor wafer 110a and the top surface of the insulating dielectric layer 185 of the upper semiconductor wafer 110a.

Next, referring to FIG. 23G, a temporary substrate 590 may be provided with a glass or silicon substrate 589 and a sacrificial bonding layer 591 on a front side of the glass or silicon substrate 589 thereof. The sacrificial bonding layer 591 may have the glass or silicon substrate 589 to be easily debonded or released from a structure subsequently attached to the sacrificial bonding layer 591. For example, the sacrificial bonding layer 591 may be a material of light-to-heat conversion (LTHC) that may be deposited on the front side of the glass or silicon substrate 589 by printing or spin-on coating and then cured or dried with a thickness of about 1 micrometer or between 0.5 and 2 micrometers. The LTHC material may be a liquid ink containing carbon black and binder in a mixture of solvents. Next, the backside of the upper semiconductor wafer 110a may be attached to the sacrificial bonding layer 591 of the temporary substrate 590.

Next, referring to FIG. 23H, the semiconductor substrate 2 of the lower semiconductor wafer 110b may have a portion, at a backside of the semiconductor substrate 2 of the lower semiconductor wafer 110b, to be removed by a chemical-mechanical-polishing (CMP) or mechanical grinding process to expose the bottom surface of each of the through silicon vias (TSVs) 157, i.e., the copper layer 156 thereof, of the lower semiconductor wafer 110b, wherein the backside of the semiconductor substrate 2 of the lower semiconductor wafer 110b may be coplanar with the bottom surface of each of the through silicon vias (TSVs) 157, i.e., the copper layer 156 thereof, of the lower semiconductor wafer 110b. Next, the backside of the semiconductor substrate 2 of the lower semiconductor wafer 110b may be etched by a plasma etching process to have the backside of the semiconductor substrate 2 of the lower semiconductor wafer 110b recessed from the bottom surface of each of the through silicon vias (TSVs) 157, i.e., the copper layer 156 thereof, of the lower semiconductor wafer 110b. Next, the insulating dielectric layer 185, such as silicon-oxide layer or silicon-nitride layer, may be deposited on the backside of the semiconductor substrate 2 of the lower semiconductor wafer 110b and the bottom surface of each of the through silicon vias (TSVs) 157, i.e., the copper layer 156 thereof, of the lower semiconductor wafer 110b. Next, the insulating dielectric layer 185 may have a portion, at a backside of the insulating dielectric layer 185 of the lower semiconductor wafer 110b, to be removed by a chemical-mechanical-polishing (CMP) or mechanical grinding process to expose the bottom surface of each of the through silicon vias (TSVs) 157, i.e., the copper layer 156 thereof, of the lower semiconductor wafer 110b, wherein the bottom surface of the insulating dielectric layer 185 of the lower semiconductor wafer 110b may be coplanar with the bottom surface of each of the through silicon vias (TSVs) 157, i.e., the copper layer 156 thereof, of the lower semiconductor wafer 110b.

Next, referring to FIG. 23H, multiple bottom metal bumps, pillars or pads 570 may be formed in an array and on a backside of the lower semiconductor wafer 110b, wherein each of the bottom metal bumps, pillars or pads 570 may be formed on the bottom surface of one of the through silicon vias (TSVs) 157, i.e., the copper layer 156 thereof, of the lower semiconductor wafer 110b and may be of a type selected from various types, i.e., first and second types, which may have the same specification as that of the first and second types of metal bumps, pillars or pads 570 respectively as illustrated in FIG. 6A, wherein each of the bottom metal bumps, pillars or pads 570 may have the adhesion metal layer 26a on the bottom surface of one of the through silicon vias (TSVs) 157, i.e., the copper layer 156 thereof, of the lower semiconductor wafer 110b and the bottom surface of the insulating dielectric layer 185 of the lower semiconductor wafer 110b.

Next, the glass or silicon substrate 589 as seen in FIG. 23H may be released from the sacrificial bonding layer 591. For example, in the case that the sacrificial bonding layer 591 is the material of light-to-heat conversion (LTHC) and the substrate 589 is made of glass, a laser light, such as YAG laser having a wavelength of about 1064 nm, an output power between 20 and 50 W and a spot size of 0.3 mm in diameter at a focal point, may be generated to pass from a backside of the glass substrate 589 to the sacrificial bonding layer 591 through the glass substrate 589, scanning the sacrificial bonding layer 591 at a speed of 8.0 m/s, for example, such that the sacrificial bonding layer 591 may be decomposed and thus the glass substrate 589 may be easily released from the sacrificial bonding layer 591. Next, an adhesive peeling tape (not shown) may be attached to a backside of the remainder of the sacrificial bonding layer 591. Next, the adhesive peeling tape may be peeled off to pull off the remainder of the sacrificial bonding layer 591 attached to the adhesive peeling tape to expose the backside of the upper semiconductor wafer 110a. Next, the upper and lower semiconductor wafers 110a and 110b may be cut or diced to separate multiple individual units (only one is shown in FIG. 23I) each for one of the face-to-face chip assemblies 462 of the three-dimensional chip package 461 of the fifteenth type of FPMCP 318 as seen in FIG. 23A, wherein the upper semiconductor wafer 110a may be cut into multiple semiconductor IC chips each for the upper semiconductor IC chip 100e of the face-to-face chip assembly 462, and the lower semiconductor wafer 110b may be cut into multiple semiconductor IC chips each for the lower semiconductor IC chip 100f of the face-to-face chip assembly 462.

Next, referring to FIG. 23J, another temporary substrate 590 having the same specification as one illustrated in FIG. 23G for the temporary substrate 590 may be provided, wherein for an element indicated by the same reference number for the temporary substrate 590 shown in FIGS. 23G and 23J, the specification of the element as seen in FIG. 16J may be referred to that of the element as illustrated in FIG. 16G. Next, a semiconductor wafer 110c may have a front side attached to the sacrificial bonding layer 591 of the temporary substrate 590, wherein the semiconductor wafer 110c is provided with the first, second, third or fourth type of micro-bumps, micro-pillars or micro-pads 34, as illustrated in FIG. 3A, at the front side of the semiconductor wafer 110c. Next, the semiconductor substrate 2 of the semiconductor wafer 110c may have a portion, at a backside of the semiconductor substrate 2 of the semiconductor wafer 110c, to be removed by a chemical-mechanical-polishing (CMP) or mechanical grinding process to expose the bottom surface of each of the through silicon vias (TSVs) 157, i.e., the copper layer 156 thereof, of the semiconductor wafer 110c, wherein the backside of the semiconductor substrate 2 of the semiconductor wafer 110c may be coplanar with the top surface of each of the through silicon vias (TSVs) 157, i.e., the copper layer 156 thereof, of the semiconductor wafer 110c. Next, the backside of the semiconductor substrate 2 of the semiconductor wafer 110c may be etched by a plasma etching process to have the backside of the semiconductor substrate 2 of the semiconductor wafer 110c recessed from the top surface of each of the through silicon vias (TSVs) 157, i.e., the copper layer 156 thereof, of the semiconductor wafer 110c. Next, the insulating dielectric layer 185, such as silicon-oxide layer or silicon-nitride layer, may be deposited on the backside of the semiconductor substrate 2 of the semiconductor wafer 110c and the top surface of each of the through silicon vias (TSVs) 157, i.e., the copper layer 156 thereof, of the semiconductor wafer 110c. Next, the insulating dielectric layer 185 may have a portion, at a backside of the insulating dielectric layer 185 of the semiconductor wafer 110c, to be removed by a chemical-mechanical-polishing (CMP) or mechanical grinding process to expose the top surface of each of the through silicon vias (TSVs) 157, i.e., the copper layer 156 thereof, of the semiconductor wafer 110c, wherein the top surface of the insulating dielectric layer 185 of the semiconductor wafer 110c may be coplanar with the top surface of each of the through silicon vias (TSVs) 157, i.e., the copper layer 156 thereof, of the semiconductor wafer 110c. Next, multiple top metal bumps, pillars or pads 570 may be formed in an array and on a backside of the semiconductor wafer 110c, wherein each of the top metal bumps, pillars or pads 570 may be formed on the top surface of one of the through silicon vias (TSVs) 157, i.e., the copper layer 156 thereof, of the semiconductor wafer 110c and may be of a type selected from various types, i.e., first and second types, which may have the same specification as that of the first and second types of metal bumps, pillars or pads 570 respectively as illustrated in FIG. 6A, wherein each of the top metal bumps, pillars or pads 570 may have the adhesion metal layer 26a on the top surface of one of the through silicon vias (TSVs) 157, i.e., the copper layer 156 thereof, of the semiconductor wafer 110c and the top surface of the insulating dielectric layer 185 of the semiconductor wafer 110c.

Next, referring to FIG. 23K, the face-to-face chip assemblies 462 may be stacked in multiple stacks over the backside of the semiconductor wafer 100c. For each of the stacks, in step 1, each of the bottom metal bumps, pillars or pads 570 of a bottommost one of the face-to-face chip assemblies 462 may be bonded to one of the top metal bumps, pillars or pads 570 of the semiconductor wafer 100c into a bonded metal bump or contact 463 between the lower semiconductor IC chip 100j of the bottommost one of the face-to-face chip assemblies 462 and the semiconductor wafer 100c. Next, in step 2, the underfill 564 may be filled into a gap between the lower semiconductor IC chip 100j of the bottommost one of the face-to-face chip assemblies 462 and the semiconductor wafer 100c, covering each of the bonded metal bumps or contacts 463. Next, in step 3, each of the metal bumps, pillars or pads 570 of an upper one of the face-to-face chip assemblies 462 may be bonded to one of the metal bumps, pillars or pads 570 of a lower one of the face-to-face chip assemblies 462 into a bonded metal bump or contact 563 between the lower semiconductor IC chip 100j of the upper one of the face-to-face chip assemblies 462 and the upper semiconductor IC chip 100i of the lower one of the face-to-face chip assemblies 462. Next, in step 4, the underfill 564 may be filled into a gap between the lower semiconductor IC chip 100j of the upper one of the face-to-face chip assemblies 462 and the upper semiconductor IC chip 100i of the lower one of the face-to-face chip assemblies 462, covering each of the bonded metal bumps or contacts 563. Next, the process of the steps 3 and 4 may be performed multiple times to stack the face-to-face chip assemblies 462 over the backside of the semiconductor wafer 100c.

Next, referring to FIG. 23K, each of the first, second, third or fourth type of micro-bumps, micro-pillars or micro-pads 34 of each of the NVM IC chips 250 may be bonded to one of the top metal bumps, pillars or pads 570 of the topmost one of the face-to-face chip assemblies 462 stacked in one of the stacks into a bonded metal bump or contact 363 between said each of the NVM IC chips 250 and the top semiconductor IC chip 100i of the topmost one of the face-to-face chip assemblies 462 stacked in said one of the stacks. Next, the underfill 564 may be filled into a gap between said each of the NVM IC chips 250 and the top semiconductor IC chip 100i of the topmost one of the face-to-face chip assemblies 462 stacked in said one of the stacks, covering each of the bonded metal bumps or contacts 363.

Next, referring to FIG. 23L, the polymer layer 92 or insulating dielectric layer, i.e., sealing layer, such as silicon-oxide-containing molding compound, epoxy-based material or polyimide, may be molded over the backside of the semiconductor wafer 100c and horizontally around each of the upper and lower semiconductor IC chips 100i and 100j of each of the face-to-face chip assemblies 462 and the NVM IC chip 250, wherein the top surface of the polymer layer 92 may be coplanar with the top surface of the NVM IC chip 250.

Next, the glass or silicon substrate 589 as seen in FIG. 23L may be released from the sacrificial bonding layer 591. For example, in the case that the sacrificial bonding layer 591 is the material of light-to-heat conversion (LTHC) and the substrate 589 is made of glass, a laser light, such as YAG laser having a wavelength of about 1064 nm, an output power between 20 and 50 W and a spot size of 0.3 mm in diameter at a focal point, may be generated to pass from a backside of the glass substrate 589 to the sacrificial bonding layer 591 through the glass substrate 589, scanning the sacrificial bonding layer 591 at a speed of 8.0 m/s, for example, such that the sacrificial bonding layer 591 may be decomposed and thus the glass substrate 589 may be easily released from the sacrificial bonding layer 591. Next, an adhesive peeling tape (not shown) may be attached to a backside of the remainder of the sacrificial bonding layer 591. Next, the adhesive peeling tape may be peeled off to pull off the remainder of the sacrificial bonding layer 591 attached to the adhesive peeling tape to expose the front side of the semiconductor wafer 100c and the first, second, third or fourth type of micro-bumps, micro-pillars or micro-pads 34 of the semiconductor wafer 100c. Next, the polymer layer 92 and semiconductor wafer 100c may be cut or diced to separate multiple individual units each for the three-dimensional chip package 461 of the fifteenth type of FPMCP 318 as seen in FIG. 23M, wherein the semiconductor wafer 100c may be cut into multiple semiconductor IC chips each for the auxiliary IC chip 411 of the three-dimensional chip package 461.

### Sixteenth Type of FPMCP

FIG. 24 is a schematically cross-sectional view showing a sixteenth type of FPMCP in accordance with an embodiment of the present application. Referring to FIG. 24, the sixteenth type of FPMCP 319 may include (1) a logic chip, application-specific integrated-circuit (ASIC) chip or system-on-chip (SoC) IC chip, such as FPGA IC chip 200 having the same specification as one illustrated in FIG. 5A-1, (2) a polymer layer 92 or insulating dielectric layer, i.e., sealing layer, such as silicon-oxide-containing molding compound, epoxy-based material or polyimide, horizontally around its FPGA IC chip 200, (3) multiple through package vias (TPVs) 158, i.e., metal posts or vias, vertically in and through its polymer layer 92, wherein each of its through package vias (TPVs) 158 may have a top surface coplanar with a top surface of its polymer layer 92 and a bottom surface coplanar with a bottom surface of its polymer layer 92, (4) a frontside interconnection scheme for a device (FISD) 101 under its FPGA IC chip 200, polymer layer 92 and through package vias (TPVs) 158, (5) a backside interconnection scheme for a device (BISD) 79 over its FPGA IC chip 200, polymer layer 92 and through package vias (TPVs) 158, and (6) multiple metal bumps, pillars or pads 570 in an array at its bottom to act as its external pins for coupling to external circuits outside of the sixteenth type of FPMCP 319, wherein each of its metal bumps, pillars or pads 570 may be formed on a bottom surface of its frontside interconnection scheme for a device (FISD) 101. Its FPGA IC chip 200 may have the same specification as the third type of semiconductor IC chip 100 illustrated in FIG. 3C. For the sixteenth type of FPMCP 319, its FPGA IC chip 200 may be the dedicated field programmable integrated-circuit (DFPIC) chip as illustrated in FIG. 4D or embedded field programmable integrated-circuit (eFPIC) chip as illustrated in FIG. 4E. Each of the first type of micro-bumps, micro-pillars or micro-pads 34 of its FPGA IC chip 200 may couple to its frontside interconnection scheme for a device (FISD) 101, and the bottom surface of the polymer layer 257 of its FPGA IC chip 200 may be substantially coplanar with the bottom surface of each of the first type of micro-bumps, micro-pillars or micro-pads 34 of its FPGA IC chip 200, the bottom surface of its polymer layer 92 and the bottom surface of each of its through package vias (TPVs) 158. The top surface of each of its through package vias (TPVs) 158 may couple to its backside interconnection scheme for a device (BISD) 79, and the bottom surface of each of its through package vias (TPVs) 158 may couple to its frontside interconnection scheme for a device (FISD) 101. Its polymer layer 92 may have a vertical sidewall coplanar with a vertical sidewall of its frontside interconnection scheme for a device (FISD) 101 and a vertical sidewall of its backside interconnection scheme for a device (BISD) 79. Each of its through package vias (TPVs) 158 may be made of a copper layer having a height or thickness between 20 μm and 300 μm, 30 μm and 200 μm, 50 μm and 150 μm, 50 μm and 120 μm, 20 μm and 100 μm, 10 μm and 100 μm, 20 μm and 60 μm, 20 μm and 40 μm, or 20 μm and 30 μm, or greater than or equal to 100 μm, 50 μm, 30 μm or 20 μm.

Referring to FIG. 24, for the sixteenth type of FPMCP 319, its frontside interconnection scheme for a device (FISD) 101 may include (1) multiple interconnection metal layers 27 coupling to each of the first type of micro-bumps, micro-pillars or micro-pads 34 of its FPGA IC chip 200 and each of its through package vias (TPVs) 158 and (2) one or more polymer layers 42, i.e., insulating dielectric layers, each between neighboring two of the interconnection metal layers 27 of its frontside interconnection scheme for a device (FISD) 101, under the bottommost one of the interconnection metal layers 27 of its frontside interconnection scheme for a device (FISD) 101 or over the topmost one of the interconnection metal layers 27 of its frontside interconnection scheme for a device (FISD) 101, wherein a lower one of the interconnection metal layers 27 of its frontside interconnection scheme for a device (FISD) 101 may couple to an upper one of the interconnection metal layers 27 its frontside interconnection scheme for a device (FISD) 101 through an opening in one of the polymer layers 42 of its frontside interconnection scheme for a device (FISD) 101 between the upper and lower ones of the interconnection metal layers 27 of its frontside interconnection scheme for a device (FISD) 101. The topmost one of the polymer layers 42 of its frontside interconnection scheme for a device (FISD) 101 may have a top surface in contact with the bottom surface of the polymer layer 257 of its FPGA IC chip 200, the bottom surface of its polymer layer 92 and the bottom surface of each of its through package vias (TPVs) 158. Each opening in the topmost one of the polymer layers 42 of its frontside interconnection scheme for a device (FISD) 101 may be under one of the first type of micro-bumps, micro-pillars or micro-pads 34 of its FPGA IC chip 200 or the bottom surface of one of its through package vias (TPVs) 158, and thus the topmost one of the interconnection metal layers 27 of its frontside interconnection scheme for a device (FISD) 101 may couple to said one of the first type of micro-bumps, micro-pillars or micro-pads 34 or the bottom surface of said one of its through package vias (TPVs) 158 through said each opening. Each of the interconnection metal layers 27 of its frontside interconnection scheme for a device (FISD) 101 may extend horizontally across an edge of its FPGA IC chip 200. The bottommost one of the interconnection metal layers 27 of its frontside interconnection scheme for a device (FISD) 101 may have multiple metal pads at tops of multiple respective openings in the bottommost one of the polymer layers 42 of its frontside interconnection scheme for a device (FISD) 101. The specification and process for the interconnection metal layers 27 and polymer layers 42 for its frontside interconnection scheme for a device (FISD) 101 may be referred to those for the second interconnection scheme for a chip (SISC) 29 as illustrated in FIG. 3A to be turned upside down. Each of the polymer layers 42 of its frontside interconnection scheme for a device (FISD) 101 may be a layer of polyimide, benzocyclobutene (BCB), parylene, epoxy-based material or compound, photo epoxy SU-8, elastomer or silicone, having a thickness between, for example, 0.3 μm and 30 μm, 0.5 μm and 20 μm, 1 μm and 10 μm, or 0.5 um and 5 μm, or thicker than or equal to 0.3 μm, 0.5 μm, 0.7 μm, 1 μm, 1.5 μm, 2 μm, 3 μm or 5 μm. Each of the interconnection metal layers 27 of its frontside interconnection scheme for a device (FISD) 101 may be provided with multiple metal traces or lines each including (1) a copper layer 40 having one or more upper portions in openings in one of the polymer layers 42 of its frontside interconnection scheme for a device (FISD) 101 and a lower portion having a thickness between 0.3 μm and 20 μm under said one of the polymer layers 42 of its frontside interconnection scheme for a device (FISD) 101, (2) an adhesion metal layer 28a, such as titanium or titanium nitride having a thickness between 1 nm and 50 nm, at a top and sidewall of each of the one or more upper portions of the copper layer 40 of said each of the metal traces or lines and at a top of the lower portion of the copper layer 40 of said each of the metal traces or lines, and (3) an electroplating seed layer 28b, such as copper, between the copper layer 40 and adhesion metal layer 28a of said each of the metal traces or lines, wherein the lower portion of the copper layer 40 of said each of the metal traces or lines may have a sidewall not covered by the adhesion metal layer 28a of said each of the metal traces or lines. Each of the metal traces or lines of each of the interconnection metal layers 27 of its frontside interconnection scheme for a device (FISD) 101 may have a thickness between, for example, 0.3 μm and 30 μm, 0.5 μm and 20 μm, 1 μm and 10 μm, or 0.5 μm and 5 μm, or thicker than or equal to 0.3 μm, 0.5 μm, 0.7 μm, 1 μm, 1.5 μm, 2 μm, 3 μm or 5 μm, and a width between, for example, 0.3 μm and 30 μm, 0.5 μm and 20 μm, 1 μm and 10 μm, or 0.5 μm and 5 μm, or wider than or equal to 0.3 μm, 0.5 μm, 0.7 μm, 1 μm, 1.5 μm, 2 μm, 3 μm or 5 μm.

Referring to FIG. 24, for the sixteenth type of FPMCP 319, its backside interconnection scheme for a device (BISD) 79 may include (1) multiple interconnection metal layers 27 coupling to each of its through package vias (TPVs) 158 and (2) one or more polymer layers 42, i.e., insulating dielectric layers, each between neighboring two of the interconnection metal layers 27 of its backside interconnection scheme for a device (BISD) 79, under the bottommost one of the interconnection metal layers 27 of its backside interconnection scheme for a device (BISD) 79 or over the topmost one of the interconnection metal layers 27 of its backside interconnection scheme for a device (BISD) 79, wherein an upper one of the interconnection metal layers 27 of its backside interconnection scheme for a device (BISD) 79 may couple to a lower one of the interconnection metal layers 27 its backside interconnection scheme for a device (BISD) 79 through an opening in one of the polymer layers 42 of its backside interconnection scheme for a device (BISD) 79 between the upper and lower ones of the interconnection metal layers 27 of its backside interconnection scheme for a device (BISD) 79. The bottommost one of the polymer layers 42 of its backside interconnection scheme for a device (BISD) 79 may have a bottom surface in contact with the top surface of the semiconductor substrate 2 of its FPGA IC chip 200, the top surface of its polymer layer 92 and the top surface of each of its through package vias (TPVs) 158. Each opening in the bottommost one of the polymer layers 42 of its backside interconnection scheme for a device (BISD) 79 may be over the top surface of one of its through package vias (TPVs) 158, and thus the bottommost one of the interconnection metal layers 27 of its backside interconnection scheme for a device (BISD) 79 may couple to the top surface of said one of its through package vias (TPVs) 158 through said each opening. Each of the interconnection metal layers 27 of its backside interconnection scheme for a device (BISD) 79 may extend horizontally across an edge of its FPGA IC chip 200. The topmost one of the interconnection metal layers 27 of its backside interconnection scheme for a device (BISD) 79 may have multiple metal pads at bottoms of multiple respective openings in the topmost one of the polymer layers 42 of its backside interconnection scheme for a device (BISD) 79. The specification and process for the interconnection metal layers 27 and polymer layers 42 for its backside interconnection scheme for a device (BISD) 79 may be referred to those for the second interconnection scheme for a chip (SISC) 29 as illustrated in FIG. 3A. Each of the polymer layers 42 of its backside interconnection scheme for a device (BISD) 79 may be a layer of polyimide, benzocyclobutene (BCB), parylene, epoxy-based material or compound, photo epoxy SU-8, elastomer or silicone, having a thickness between, for example, 0.3 μm and 30 μm, 0.5 μm and 20 μm, 1 μm and 10 μm, or 0.5 um and 5 μm, or thicker than or equal to 0.3 μm, 0.5 μm, 0.7 μm, 1 μm, 1.5 μm, 2 μm, 3 μm or 5 μm. Each of the interconnection metal layers 27 of its backside interconnection scheme for a device (BISD) 79 may be provided with multiple metal traces or lines each including (1) a copper layer 40 having one or more lower portions in openings in one of the polymer layers 42 of its backside interconnection scheme for a device (BISD) 79 and an upper portion having a thickness between 0.3 μm and 20 μm over said one of the polymer layers 42 of its backside interconnection scheme for a device (BISD) 79, (2) an adhesion metal layer 28a, such as titanium or titanium nitride having a thickness between 1 nm and 50 nm, at a bottom and sidewall of each of the one or more lower portions of the copper layer 40 of said each of the metal traces or lines and at a bottom of the upper portion of the copper layer 40 of said each of the metal traces or lines, and (3) an electroplating seed layer 28b, such as copper, between the copper layer 40 and adhesion metal layer 28a of said each of the metal traces or lines, wherein the upper portion of the copper layer 40 of said each of the metal traces or lines may have a sidewall not covered by the adhesion metal layer 28a of said each of the metal traces or lines. Each of the metal traces or lines of each of the interconnection metal layers 27 of its backside interconnection scheme for a device (BISD) 79 may have a thickness between, for example, 0.3 μm and 30 μm, 0.5 μm and 20 μm, 1 μm and 10 μm, or 0.5 μm and 5 μm, or thicker than or equal to 0.3 μm, 0.5 μm, 0.7 μm, 1 μm, 1.5 μm, 2 μm, 3 μm or 5 μm, and a width between, for example, 0.3 μm and 30 μm, 0.5 μm and 20 μm, 1 μm and 10 μm, or 0.5 μm and 5 μm, or wider than or equal to 0.3 μm, 0.5 μm, 0.7 μm, 1 μm, 1.5 μm, 2 μm, 3 μm or 5 μm.

Referring to FIG. 24, for the sixteenth type of FPMCP 319, each of its metal bumps, pillars or pads 570 may be of a type selected from various types, i.e., first and second types, which may have the same specification as that of the first and second types of metal bumps, pillars or pads 570 respectively as illustrated in FIG. 7 to be turned upside down, and may have the adhesion metal layer 26a on a bottom surface of one of the metal pads of the bottommost one of the interconnection metal layers 27 of its frontside interconnection scheme for a device (FISD) 101 and a bottom surface of the bottommost one of the polymer layers 42 of its frontside interconnection scheme for a device (FISD) 101.

Referring to FIG. 24, the sixteenth type of FPMCP 319 may further include a NVM IC chip 250 having the same specification as one illustrated in FIG. 5A-1 over its backside interconnection scheme for a device (BISD) 79. Its NVM IC chip 250 may have the same specification as the first type of semiconductor IC chip 100 illustrated in FIG. 3A to be turned upside down. Its NVM IC chip 250 may have the first, second, third or fourth type of micro-bumps, micro-pillars or micro-pads 34 as illustrated in FIG. 3A each bonded to one of the metal pads of the topmost one of the interconnection metal layers 27 of its backside interconnection scheme for a device (BISD) 79. The sixteenth type of FPMCP 319 may further include an underfill 564, i.e., polymer layer, between its NVM IC chip 250 and backside interconnection scheme for a device (BISD) 79, covering a sidewall of each of the first, second, third or fourth type of micro-bumps, micro-pillars or micro-pads 34 of its NVM IC chip 250.

Referring to FIG. 24, for the sixteenth type of FPMCP 319, its FPGA IC chip 200 may couple to one of its metal bumps, pillars or pads 570 through each of the interconnection metal layers 27 of its frontside interconnection scheme for a device (FISD) 101. Its NVM IC chip 250 may couple to one of its metal bumps, pillars or pads 570 through, in sequence, each of the interconnection metal layers 27 of its backside interconnection scheme for a device (BISD) 79, one of its through package vias (TPVs) 158 and each of the interconnection metal layers 27 of its frontside interconnection scheme for a device (FISD) 101.

Referring to FIG. 24, for fabricating a ball-grid-array (BGA) chip package, the sixteenth type of FPMCP 319 may be bonded to a ball-grid-array (BGA) substrate 537 that may have the same specification as that illustrated in FIG. 19. For an element indicated by the same reference number for the ball-grid-array (BGA) substrate 537 shown in FIGS. 19 and 24, the specification of the element as seen in FIG. 24 may be referred to that of the element as illustrated in FIG. 19. For more elaboration, each of the metal bumps, pillars or pads 570 of the sixteenth type of FPMCP 319 may be bonded to a metal pad, bump or contact 529, made of nickel, gold or copper for example, preformed on one of the metal pads of the topmost one of the interconnection metal layers 668 of the ball-grid-array (BGA) substrate 537. An underfill 564, i.e., polymer layer, may be filled into a gap between frontside interconnection scheme for a device (FISD) 101 of the sixteenth type of FPMCP 319 and the ball-grid-array (BGA) substrate 537, covering a sidewall of each of the metal bumps, pillars or pads 570 of the sixteenth type of FPMCP 319. Multiple solder balls 538, made of a tin-lead alloy or tin-silver-copper alloy, may be formed in an array and each of the solder balls 538 may be formed on a bottom surface of one of the metal pads 528 of the bottommost one of the interconnection metal layers of the ball-grid-array (BGA) substrate 537.

For the sixteenth type of FPMCP 319 as seen in FIG. 24, its FPGA IC chip 200 may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with first data stored in its NVM IC chip 250 to be configured in accordance with the first data, (2) the first or second type of field programmable switch cell 379 as illustrated in FIGS. 2A and 2B having the memory cells 362 for storing data associated with second data stored in its NVM IC chip 250 to be configured in accordance with the second data, and (3) the programmable switch matrix 710 as illustrated in FIG. 2C having the memory cells 398 for storing data, i.e., programming codes, password or encryption/decryption codes, associated with third data stored in its NVM IC chip 250 to be configured in accordance with the third data. Alternatively, its FPGA IC chip 200 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MLU) IC chip, or digital-signal-processing (DSP) IC chip, each of which may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with the first data to be configured in accordance with the first data, (2) the first or second type of field programmable switch cell 379 as illustrated in FIGS. 2A and 2B having the memory cells 362 for storing data associated with the second data to be configured in accordance with the second data, and (3) the programmable switch matrix 710 as illustrated in FIG. 2C having the memory cells 398 for storing data, i.e., programming codes, password or encryption/decryption codes, associated with the third data to be configured in accordance with the third data.

### Seventeenth Type of FPMCP

FIG. 25A is a schematically cross-sectional view showing a seventeenth type of FPMCP for a first alternative in accordance with an embodiment of the present application. FIG. 25B is a schematically cross-sectional view showing a seventeenth type of FPMCP for a second alternative in accordance with an embodiment of the present application. FIG. 25C is a schematically cross-sectional view showing a seventeenth type of FPMCP for a third alternative in accordance with an embodiment of the present application. The seventeenth type of FPMCP 320 for the first alternative as seen in FIG. 25A may include a bottom chip package 511 having a similar structure to the sixteenth type of FPMCP 319 as seen in FIG. 24. For an element indicated by the same reference number shown in FIGS. 24 and 25A, the specification of the element as seen in FIG. 25A may be referred to that of the element as illustrated in FIG. 24. The difference therebetween is that the seventeenth type of FPMCP 320 for the first alternative may be provided without the backside interconnection scheme for a device (BISD) 79 and NVM IC chip 250 as illustrated for the sixteenth type of FPMCP 319, and the seventeenth type of FPMCP 320 for the first alternative may further include a non-volatile-memory (NVM) chip package 336 over its bottom chip package 511. For the seventeenth type of FPMCP 320 for the first alternative, its non-volatile-memory (NVM) chip package 336 may have the same specification as that illustrated for the eleventh type of FPMCP 314 for the first alternative in FIG. 19. For an element indicated by the same reference number shown in FIGS. 19 and 25A, the specification of the element as seen in FIG. 25A may be referred to that of the element as illustrated in FIG. 19.

Referring to FIG. 25A, for the seventeenth type of FPMCP 320 for the first alternative, each of the solder balls 337 of its non-volatile-memory (NVM) chip package 336 may have a bottom end bonded to the top surface of one of the through package vias (TPVs) 158 of its bottom chip package 511. The seventeenth type of FPMCP 320 for the first alternative may further include an underfill 564, i.e., polymer layer, between the circuit board 335 of its non-volatile-memory (NVM) chip package 336 and its bottom chip package 511, covering a sidewall of each of the solder balls 337 of its non-volatile-memory (NVM) chip package 336.

Referring to FIG. 25A, for the seventeenth type of FPMCP 320 for the first alternative, the FPGA IC chip 200 of its bottom chip package 511 may couple to one of the metal bumps, pillars or pads 570 of its bottom chip package 511 through each of the interconnection metal layers 27 of the frontside interconnection scheme for a device (FISD) 101 of its bottom chip package 511. The FPGA IC chip 200 of its bottom chip package 511 may be the dedicated field programmable integrated-circuit (DFPIC) chip as illustrated in FIG. 4D or embedded field programmable integrated-circuit (eFPIC) chip as illustrated in FIG. 4E. Each of the two NVM IC chips 250 of its non-volatile-memory (NVM) chip package 336 may couple to one of the metal bumps, pillars or pads 570 of its bottom chip package 511 through, in sequence, one of the wirebonded wires 333 of its non-volatile-memory (NVM) chip package 336, the circuit board 335 of its non-volatile-memory (NVM) chip package 336, one of the solder balls 337 of its non-volatile-memory (NVM) chip package 336, one of the through package vias (TPVs) 158 of its bottom chip package 511 and each of the interconnection metal layers 27 of the frontside interconnection scheme for a device (FISD) 101 of its bottom chip package 511.

Referring to FIG. 25A, for fabricating a ball-grid-array (BGA) chip package, the seventeenth type of FPMCP 320 for the first alternative may be bonded to a ball-grid-array (BGA) substrate 537 that may have the same specification as that illustrated in FIG. 19-1, 19-2 or 19-3. For an element indicated by the same reference number for the ball-grid-array (BGA) substrate 537 shown in FIG. 19-1, 19-2 or 19-3 and FIG. 25A, the specification of the element as seen in FIG. 25A may be referred to that of the element as illustrated in FIG. 19-1, 19-2 or 19-3. For more elaboration, each of the metal bumps, pillars or pads 570 of the seventeenth type of FPMCP 320 for the first alternative may be bonded to a metal pad, bump or contact 529, made of nickel, gold or copper for example, preformed on one of the metal pads of the topmost one of the interconnection metal layers 668 of the ball-grid-array (BGA) substrate 537. An underfill 564, i.e., polymer layer, may be filled into a gap between the frontside interconnection scheme for a device (FISD) 101 of the bottom chip package 511 of the seventeenth type of FPMCP 320 for the first alternative and the ball-grid-array (BGA) substrate 537, covering a sidewall of each of the metal bumps, pillars or pads 570 of the seventeenth type of FPMCP 320 for the first alternative. Multiple solder balls 538, made of a tin-lead alloy or tin-silver-copper alloy, may be formed in an array and each of the solder balls 538 may be formed on a bottom surface of one of the metal pads 528 of the bottommost one of the interconnection metal layers of the ball-grid-array (BGA) substrate 537.

For the seventeenth type of FPMCP 320 for the first alternative as seen in FIG. 25A, the FPGA IC chip 200 of its bottom chip package 511 may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with first data stored in either of the NVM IC chips 250 of its non-volatile-memory (NVM) chip package 336, (2) the first or second type of field programmable switch cell 379 as illustrated in FIGS. 2A and 2B having the memory cells 362 for storing data associated with second data stored in either of the NVM IC chips 250 of its non-volatile-memory (NVM) chip package 336 to be configured in accordance with the second data, and (3) the programmable switch matrix 710 as illustrated in FIG. 2C having the memory cells 398 for storing data, i.e., programming codes, password or encryption/decryption codes, associated with third data stored in its NVM IC chip 250 to be configured in accordance with the third data. Alternatively, the FPGA IC chip 200 of its bottom chip package 511 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MLU) IC chip, or digital-signal-processing (DSP) IC chip, each of which may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with the first data to be configured in accordance with the first data, (2) the first or second type of field programmable switch cell 379 as illustrated in FIGS. 2A and 2B having the memory cells 362 for storing data associated with the second data to be configured in accordance with the second data, and (3) the programmable switch matrix 710 as illustrated in FIG. 2C having the memory cells 398 for storing data, i.e., programming codes, password or encryption/decryption codes, associated with the third data to be configured in accordance with the third data.

The seventeenth type of FPMCP 320 for the second alternative as seen in FIG. 25B may include a bottom chip package 611 having a similar structure to the logic chip package 422 of the eleventh type of FPMCP 314 for the first alternative as seen in FIGS. 19 and 19-1. For an element indicated by the same reference number shown in FIGS. 19, 19-1 and 25B, the specification of the element as seen in FIG. 25B may be referred to that of the element as illustrated in FIGS. 19 and 19-1. The difference therebetween is that for the seventeenth type of FPMCP 320 for the second alternative as seen in FIG. 25B its bottom chip package 611 may be further provided with multiple through package vias (TPVs) 158 vertically in and through the polymer layer 592 of its bottom chip package 611 and on the circuit substrate, such as interposer 551 as illustrated in FIG. 6A or ball-grid-array (BGA) substrate 537 as illustrated in FIG. 18, 19 or 19-1, wherein a reference number “661” is added for denoting the circuit substrate and the circuit substrate 661 is shown as the ball-grid-array (BGA) substrate 537 as seen in FIG. 18 for example. Each of the through package vias (TPVs) 158 of its bottom chip package 611 may be formed on the interconnection metal layers 67 of the interposer 551 in case for the circuit substrate 661 of its bottom chip package 611 or a metal pad, bump or contact 529, made of nickel, gold or copper for example, preformed on one of the metal pads of the topmost one of the interconnection metal layers 668 of the ball-grid-array (BGA) substrate 537 in case for the circuit substrate 661 of its bottom chip package 611. Each of the through package vias (TPVs) 158 of its bottom chip package 611 may be made of a copper layer having a height or thickness between 20 μm and 300 μm, 30 μm and 200 μm, 50 μm and 150 μm, 50 μm and 120 μm, 20 μm and 100 μm, 10 μm and 100 μm, 20 μm and 60 μm, 20 μm and 40 μm, or 20 μm and 30 μm, or greater than or equal to 100 μm, 50 μm, 30 m or 20 m and have a top surface coplanar with a top surface of the polymer layer 592 of its bottom chip package 611 and a top surface coplanar with a top surface of the polymer layer 592 of its bottom chip package 611. The FPGA IC chip 200 of its bottom chip package 611 may be the dedicated field programmable integrated-circuit (DFPIC) chip as illustrated in FIG. 4D or embedded field programmable integrated-circuit (eFPIC) chip as illustrated in FIG. 4E. The seventeenth type of FPMCP 320 for the second alternative may further include a non-volatile-memory (NVM) chip package 336 over its bottom chip package 611. For the seventeenth type of FPMCP 320 for the second alternative, its non-volatile-memory (NVM) chip package 336 may have the same specification as that illustrated for the eleventh type of FPMCP 314 for the first alternative as seen in FIG. 19. For an element indicated by the same reference number shown in FIGS. 19 and 25B, the specification of the element as seen in FIG. 25B may be referred to that of the element as illustrated in FIG. 19. Each of the solder balls 337 of its non-volatile-memory (NVM) chip package 336 may have a bottom end bonded to the top surface of one of the through package vias (TPVs) 158 of its bottom chip package 611. The seventeenth type of FPMCP 320 for the second alternative may further include an underfill 564, i.e., polymer layer, between its non-volatile-memory (NVM) chip package 336 and its bottom chip package 611, covering a sidewall of each of the solder balls 337 of its non-volatile-memory (NVM) chip package 336.

Referring to FIG. 25B, for the seventeenth type of FPMCP 320 for the second alternative, its bottom chip package 611 may be provided with (1) the metal bumps, pillars or pads 570 as illustrated in FIG. 6A each on a bottom surface of one of the through silicon vias (TSVs) 157 of the interposer 551 in case for the circuit substrate 661 of its bottom chip package 611 or (2) the solder balls 538 as illustrated in FIG. 18 each on and under the metal pads 528 of the ball-grid-array (BGA) substrate 537 in case for the circuit substrate 661 of its bottom chip package 611. The FPGA IC chip 200 of its bottom chip package 611 may couple to one of the metal bumps, pillars or pads 570 or solder balls 538 of its bottom chip package 611 (1) through each of the interconnection metal layers 67 of the interposer 551 of its bottom chip package 611 in case for the circuit substrate 661 of its bottom chip package 611 and one of the through silicon vias 558 of the interposer 551 of its bottom chip package 611, or (2) through the ball-grid-array (BGA) substrate 537 of its bottom chip package 611 in case for the circuit substrate 661 of its bottom chip package 611. Each of the two NVM IC chips 250 of its non-volatile-memory (NVM) chip package 336 may couple to one of the metal bumps, pillars or pads 570 or solder balls 538 of its bottom chip package 611 (1) through, in sequence, one of the wirebonded wires 333 of its non-volatile-memory (NVM) chip package 336, the circuit board 335 of its non-volatile-memory (NVM) chip package 336, one of the solder balls 337 of its non-volatile-memory (NVM) chip package 336, one of the through package vias (TPVs) 158 of its bottom chip package 611, each of the interconnection metal layers 67 of the interposer 551 of its bottom chip package 611 in case for the circuit substrate 661 of its bottom chip package 611 and one of the through silicon vias 558 of the interposer 551 of its bottom chip package 611, or (2) through, in sequence, one of the wirebonded wires 333 of its non-volatile-memory (NVM) chip package 336, the circuit board 335 of its non-volatile-memory (NVM) chip package 336, one of the solder balls 337 of its non-volatile-memory (NVM) chip package 336, one of the through package vias (TPVs) 158 of its bottom chip package 611 and the ball-grid-array (BGA) substrate 537 of its bottom chip package 611 in case for the circuit substrate 661 of its bottom chip package 611.

For the seventeenth type of FPMCP 320 for the second alternative as seen in FIG. 25B, the FPGA IC chip 200 of its bottom chip package 611 may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with first data stored in either of the NVM IC chips 250 of its non-volatile-memory (NVM) chip package 336, (2) the first or second type of field programmable switch cell 379 as illustrated in FIGS. 2A and 2B having the memory cells 362 for storing data associated with second data stored in either of the NVM IC chips 250 of its non-volatile-memory (NVM) chip package 336 to be configured in accordance with the second data, and (3) the programmable switch matrix 710 as illustrated in FIG. 2C having the memory cells 398 for storing data, i.e., programming codes, password or encryption/decryption codes, associated with third data stored in either of the NVM IC chips 250 of its non-volatile-memory (NVM) chip package 336 to be configured in accordance with the third data. Alternatively, the FPGA IC chip 200 of its bottom chip package 611 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MLU) IC chip, or digital-signal-processing (DSP) IC chip, each of which may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with the first data to be configured in accordance with the first data, (2) the first or second type of field programmable switch cell 379 as illustrated in FIGS. 2A and 2B having the memory cells 362 for storing data associated with the second data to be configured in accordance with the second data, and (3) the programmable switch matrix 710 as illustrated in FIG. 2C having the memory cells 398 for storing data, i.e., programming codes, password or encryption/decryption codes, associated with the third data to be configured in accordance with the third data.

The seventeenth type of FPMCP 320 for the third alternative as seen in FIG. 25C may include a bottom chip package 612 having a similar structure to the logic chip package 422 of the eleventh type of FPMCP 314 for the first alternative as seen in FIGS. 19 and 19-1. For an element indicated by the same reference number shown in FIGS. 19, 19-1 and 25C, the specification of the element as seen in FIG. 25C may be referred to that of the element as illustrated in FIGS. 19 and 19-1. The difference therebetween is that for the seventeenth type of FPMCP 320 for the third alternative as seen in FIG. 25C its bottom chip package 612 may be further provided with multiple solder balls 613 in and through the polymer layer 592 of its bottom chip package 612 and on the circuit substrate, such as interposer 551 as illustrated in FIG. 6A or ball-grid-array (BGA) substrate 537 as illustrated in FIG. 18, wherein a reference number “661” is added for denoting the circuit substrate and the circuit substrate 661 is shown as the ball-grid-array (BGA) substrate 537 as seen in FIG. 18 for example. The FPGA IC chip 200 of its bottom chip package 612 may be the dedicated field programmable integrated-circuit (DFPIC) chip as illustrated in FIG. 4D or embedded field programmable integrated-circuit (eFPIC) chip as illustrated in FIG. 4E. Each of the solder balls 613 of its bottom chip package 612 may be formed on the interconnection metal layers 67 of the interposer 551 in case for the circuit substrate 661 of its bottom chip package 611 or a metal pad, bump or contact 529, made of nickel, gold or copper for example, preformed on one of the metal pads of the topmost one of the interconnection metal layers 668 of the ball-grid-array (BGA) substrate 537 in case for the circuit substrate 661 of its bottom chip package 612. Each of the solder balls 613 of its bottom chip package 612 may be made of tin, a tin-lead alloy or a tin-silver-copper alloy having a height or thickness between 100 μm and 500 μm or 200 μm and 400 μm or greater than or equal to 100 μm and have a sidewall covered by the polymer layer 592 of its bottom chip package 612. The seventeenth type of FPMCP 320 for the third alternative may further include a non-volatile-memory (NVM) chip package 336 over its bottom chip package 612. For the seventeenth type of FPMCP 320 for the third alternative, its non-volatile-memory (NVM) chip package 336 may have a similar structure to the non-volatile-memory (NVM) chip package 336 of the eleventh type of FPMCP 314 for the first alternative as seen in FIG. 19. For an element indicated by the same reference number shown in FIGS. 19 and 25C, the specification of the element as seen in FIG. 25C may be referred to that of the element as illustrated in FIG. 19. The difference therebetween is that for the seventeenth type of FPMCP 320 for the third alternative as seen in FIG. 25C its non-volatile-memory (NVM) chip package 336 may be formed without the solder balls 337 for the non-volatile-memory (NVM) chip package 336 of the eleventh type of FPMCP 314 for the first alternative as seen in FIG. 19 but the circuit board 335 of its non-volatile-memory (NVM) chip package 336 may have a bottom surface bonded to a top end of each of the solder balls 613 of its bottom chip package 612.

Referring to FIG. 25C, for the seventeenth type of FPMCP 320 for the third alternative, its bottom chip package 612 may be provided with (1) the metal bumps, pillars or pads 570 as illustrated in FIG. 6A each on a bottom surface of one of the through silicon vias (TSVs) 157 of the interposer 551 in case for the circuit substrate 661 of its bottom chip package 612 or (2) the solder balls 538 as illustrated in FIG. 18 each on and under the metal pads 528 of the ball-grid-array (BGA) substrate 537 in case for the circuit substrate 661 of its bottom chip package 612. The FPGA IC chip 200 of its bottom chip package 612 may couple to one of the metal bumps, pillars or pads 570 or solder balls 538 of its bottom chip package 612 (1) through each of the interconnection metal layers 67 of the interposer 551 of its bottom chip package 612 in case for the circuit substrate 661 of its bottom chip package 612 and one of the through silicon vias 558 of the interposer 551 of its bottom chip package 612, or (2) through the ball-grid-array (BGA) substrate 537 of its bottom chip package 612 in case for the circuit substrate 661 of its bottom chip package 612. Each of the two NVM IC chips 250 of its non-volatile-memory (NVM) chip package 336 may couple to one of the metal bumps, pillars or pads 570 or solder balls 538 of its bottom chip package 612 (1) through, in sequence, one of the wirebonded wires 333 of its non-volatile-memory (NVM) chip package 336, the circuit board 335 of its non-volatile-memory (NVM) chip package 336, one of the solder balls 613 of its bottom chip package 612, each of the interconnection metal layers 67 of the interposer 551 of its bottom chip package 612 in case for the circuit substrate 661 of its bottom chip package 612 and one of the through silicon vias 558 of the interposer 551 of its bottom chip package 612, or (2) through, in sequence, one of the wirebonded wires 333 of its non-volatile-memory (NVM) chip package 336, the circuit board 335 of its non-volatile-memory (NVM) chip package 336, one of the solder balls 613 of its bottom chip package 612 and the ball-grid-array (BGA) substrate 537 of its bottom chip package 612 in case for the circuit substrate 661 of its bottom chip package 612.

For the seventeenth type of FPMCP 320 for the third alternative as seen in FIG. 25C, the FPGA IC chip 200 of its bottom chip package 612 may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with first data stored in either of the NVM IC chips 250 of its non-volatile-memory (NVM) chip package 336, (2) the first or second type of field programmable switch cell 379 as illustrated in FIGS. 2A and 2B having the memory cells 362 for storing data associated with second data stored in either of the NVM IC chips 250 of its non-volatile-memory (NVM) chip package 336 to be configured in accordance with the second data, and (3) the programmable switch matrix 710 as illustrated in FIG. 2C having the memory cells 398 for storing data, i.e., programming codes, password or encryption/decryption codes, associated with third data stored in said either of the NVM IC chips 250 of its non-volatile-memory (NVM) chip package 336 to be configured in accordance with the third data. Alternatively, the FPGA IC chip 200 of its bottom chip package 612 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MLU) IC chip, or digital-signal-processing (DSP) IC chip, each of which may include (1) the first, second or third type of field programmable logic cell or element (LCE) 2014 as illustrated in FIGS. 1A-1C having the memory cells, e.g., ones 490 as illustrated in FIG. 1A or ones as illustrated in FIG. 1B or 1C, for storing data associated with the first data to be configured in accordance with the first data, (2) the first or second type of field programmable switch cell 379 as illustrated in FIGS. 2A and 2B having the memory cells 362 for storing data associated with the second data to be configured in accordance with the second data, and (3) the programmable switch matrix 710 as illustrated in FIG. 2C having the memory cells 398 for storing data, i.e., programming codes, password or encryption/decryption codes, associated with the third data to be configured in accordance with the third data.

### Eighteenth Type of FPMCP

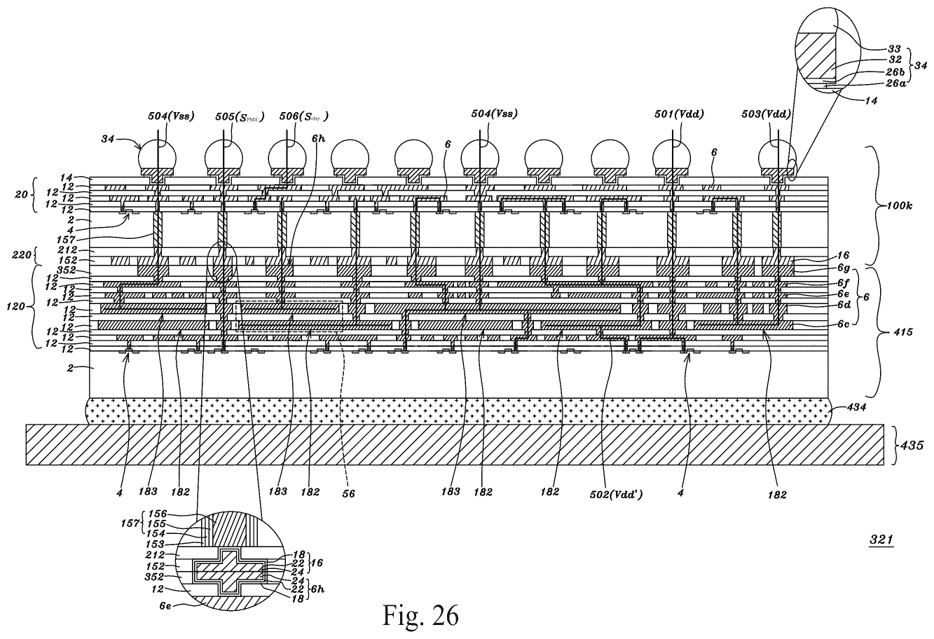

FIG. 26 is a schematically cross-sectional view showing an eighteenth type of FPMCP in accordance with an embodiment of the present application. The eighteenth type of FPMCP 321 as seen in FIG. 26 may fabricated by a wafer-to-wafer bonding process, including (1) a power-management integrated-circuit (PMIC) chip 415, (2) a semiconductor IC chip 100k having a backside attached to a front side of its power-management integrated-circuit (PMIC) chip 415, and (3) a heat sink or spreader 435, made of copper or aluminum, attached to a backside of its power-management integrated-circuit (PMIC) chip 415 via an adhesive material 434, e.g., heat-conductive paste.

Referring to FIG. 26, for the eighteenth type of FPMCP 321, its power-management integrated-circuit (PMIC) chip 415 may include (1) a semiconductor substrate 2, such as silicon substrate, GaAs substrate, SiGe substrate or silicon-on-insulator (SOI) substrate, (2) multiple semiconductor devices 4, such as planar metal-oxide-semiconductor (MOS) transistors, fin field effective transistors (FINFETs), gate-all-around field effective transistors (GAAFETs), resistors, capacitors, inductors or other passive devices, at a top surface of the semiconductor substrate 2 of its power-management integrated-circuit (PMIC) chip 415, and (3) an interconnection scheme 120 over the semiconductor substrate 2 of its power-management integrated-circuit (PMIC) chip 415, wherein the interconnection scheme 120 of its power-management integrated-circuit (PMIC) chip 415 may be provided with one or more interconnection metal layers 6 coupling to the semiconductor devices 4 of its power-management integrated-circuit (PMIC) chip 415 and one or more insulating dielectric layers 12 each between neighboring two of the interconnection metal layers 6 of the interconnection scheme 120 of its power-management integrated-circuit (PMIC) chip 415.

Referring to FIG. 26, for the power-management integrated-circuit (PMIC) chip 415 of the eighteenth type of FPMCP 321, each of the interconnection metal layers 6 of its interconnection scheme 120 may include (1) a copper layer 24 having lower portions in openings in a lower one of the insulating dielectric layers 12 of its interconnection scheme 120 and upper portions over the lower one of the insulating dielectric layers 12 and in openings in an upper one of the insulating dielectric layers 12 of its interconnection scheme 120, (2) an adhesion metal layer 18, such as titanium or titanium nitride having a thickness of between 1 nm and 50 nm, at a bottom and sidewall of each of the lower portions of the copper layer 24 and at a bottom and sidewall of each of the upper portions of the copper layer 24, and (3) an electroplating seed layer 22, such as copper, between the copper layer 24 and adhesion metal layer 18 of said each of the interconnection metal layers 6, wherein the copper layer 24 of said each of the interconnection metal layers 6 may have a top surface substantially coplanar with a top surface of the upper one of the insulating dielectric layers 12.

Referring to FIG. 26, for the power-management integrated-circuit (PMIC) chip 415 of the eighteenth type of FPMCP 321, the interconnection metal layers 6 of its interconnection scheme 120 may include (1) a first interconnection metal layer 6c provided with power-voltage planes, buses or interconnection 182 having a thickness between 0.1 and 10 micrometers or between 0.5 and 5 micrometers, (2) a second interconnection metal layer 6d over the first interconnection metal layer 6c of its interconnection scheme 120, provided with ground-voltage planes, buses or interconnection 183 having a thickness between 0.1 and 10 micrometers or between 0.5 and 5 micrometers and over the first interconnection metal layer 6c of its interconnection scheme 120, (3) a third interconnection metal layer 6e over the second interconnection metal layer 6d of its interconnection scheme 120, provided with multiple power distribution traces each having a thickness between 0.05 and 5 micrometers or between 0.1 and 2 micrometers and coupling to one of the power planes, buses or interconnection 182 of the first interconnection metal layer 6c of its interconnection scheme 120 through the second interconnection metal layer 6d of its interconnection scheme 120 and multiple ground distribution traces each having a thickness between 0.05 and 5 micrometers or between 0.1 and 2 micrometers and coupling to one of the ground planes, buses or interconnection 183 of the second interconnection metal layer 6c of its interconnection scheme 120, (4) a fourth interconnection metal layer 6f over the third interconnection metal layer 6e of its interconnection scheme 120, provided with multiple power distribution traces each having a thickness between 0.05 and 5 micrometers or between 0.1 and 2 micrometers and coupling to one of the power planes, buses or interconnection 182 of the first interconnection metal layer 6c of its interconnection scheme 120 through, in sequence, one of the power distribution traces of the third interconnection metal layer 6e of its interconnection scheme 120, the second interconnection metal layer 6d of its interconnection scheme 120 and multiple ground distribution traces each having a thickness between 0.05 and 5 micrometers or between 0.1 and 2 micrometers and coupling to one of the ground planes, buses or interconnection 183 of the second interconnection metal layer 6c of its interconnection scheme 120 through one of the ground distribution traces of the third interconnection metal layer 6e of its interconnection scheme 120, and (5) a fifth interconnection metal layer 6g over the fourth interconnection metal layer 6f of its interconnection scheme 120, provided with multiple metal pads 6h each in one of multiple openings in the topmost one of the insulating dielectric layers 12 of its interconnection scheme 120. The topmost one of the insulating dielectric layers 12 of its interconnection scheme 120 may act as an insulating bonding layer 352 having a silicon-oxide layer having a thickness between 0.1 and 2 micrometers and each of the metal pads 6h of the fifth interconnection metal layer 6g of its interconnection scheme 120 may be provided with the copper layer 24 having a thickness between 3 nm and 500 nm in the insulating bonding layer 352 of its interconnection scheme 120, wherein the insulating bonding layer 352 of its interconnection scheme 120 may have a top surface substantially coplanar with a top surface of each of the metal pads 6h, i.e., the copper layer 24 thereof, of the fifth interconnection metal layer 6g of its interconnection scheme 120. Each of the first and second interconnection metal layers 6c and 6d of its interconnection scheme 120 may have a thickness greater than that of either of the third and fourth interconnection metal layers 6e and 6f of its interconnection scheme 120.

Referring to FIG. 26, for the power-management integrated-circuit (PMIC) chip 415 of the eighteenth type of FPMCP 321, the power-voltage planes, buses or interconnection 182 of the first interconnection metal layer 6c of its interconnection scheme 120 may be provided for one of two electrodes of its decoupling capacitor 56; the ground-voltage planes, buses or interconnection 183 of the second interconnection metal layer 6d of its interconnection scheme 120 may be provided for the other of the two electrodes of its decoupling capacitor 56; one of the insulating dielectric layers 12 between the power-voltage planes, buses or interconnection 182 of the first interconnection metal layer 6c of its interconnection scheme 120 and the ground-voltage planes, buses or interconnection 183 of the second interconnection metal layer 6d of its interconnection scheme 120 may be provided for a dielectric layer of its decoupling capacitor 56 between the two electrodes of its decoupling capacitor 56, wherein the dielectric layer of its decoupling capacitor 56 may be made of a layer of hafnium oxide (HfO₂), tantalum oxide (Ta₂O₅), silicon oxide or silicon oxycarbide having a thickness between 0.1 and 2 micrometers, between 3 nm and 1,000 nm or between 10 nm and 500 nm, or thinner than 5 nm, 10 nm, 30 nm, 50 nm, 100 nm, 200 nm, 300 nm, 500 nm or 1,000 nm.

Referring to FIG. 26, for the power-management integrated-circuit (PMIC) chip 415 of the eighteenth type of FPMCP 321, besides the dielectric layer of its decoupling capacitor 56, each of the insulating dielectric layers 12 of its interconnection scheme 120 may have a layer of silicon oxide or silicon oxycarbide having a thickness between 0.1 and 2 micrometers, between 3 nm and 1,000 nm or between 10 nm and 500 nm, or thinner than 5 nm, 10 nm, 30 nm, 50 nm, 100 nm, 200 nm, 300 nm, 500 nm or 1,000 nm.

Referring to FIG. 26, for the eighteenth type of FPMCP 321, its semiconductor IC chip 100k may have the same specification as the second type of semiconductor IC chip 100 illustrated in FIGS. 3B and 3G-3J. For an element of its semiconductor IC chip 100k shown in FIG. 26, which is indicated by the same reference number as that for an element of the second type of semiconductor IC chip 100 shown in FIGS. 3B and 3G-3J, the specification of the element of its semiconductor IC chip 100k as shown in FIG. 26 may be referred to that of the element of the second type of semiconductor IC chip 100 as illustrated in FIGS. 3A, 3B and 3G-3J. The semiconductor substrate 2 of its semiconductor IC chip 100k may have a portion, at a backside of the semiconductor substrate 2 of its semiconductor IC chip 100k, removed by a chemical-mechanical-polishing (CMP) or mechanical grinding process such that each of the through silicon vias (TSVs) 157, that is, the electroplated copper layer 156 thereof, of its semiconductor IC chip 100k may have a bottom surface substantially coplanar with a bottom surface of the semiconductor substrate 2 of its semiconductor IC chip 100k. Thereby, in this example, the semiconductor substrate 2 of its semiconductor IC chip 100k may have a thickness between 0.1 and 20 micrometers, between 1 and 10 micrometers or between 1 and 5 micrometers, and each of the through silicon vias (TSVs) 157 of its semiconductor IC chip 100k may have a diameter between 0.5 and 20 micrometers, between 1 and 10 micrometers or between 1 and 5 micrometers. Its semiconductor IC chip 100k may further include an interconnection scheme 220 under and on the backside of the semiconductor substrate 2 of its semiconductor IC chip 100k, including an interconnection metal layer 16 under the backside of the semiconductor substrate 2 of its semiconductor IC chip 100k, an insulating dielectric layer 212 between the interconnection metal layer 16 of the interconnection scheme 220 of its semiconductor IC chip 100k and the backside of the semiconductor substrate 2 of its semiconductor IC chip 100k and an insulating bonding layer 152 under and on the insulating dielectric layer 212 of the interconnection scheme 220 of its semiconductor IC chip 100k, wherein the interconnection metal layer 16 of the interconnection scheme 220 of its semiconductor IC chip 100k may couple to each of the through silicon vias (TSVs) 157 of its semiconductor IC chip 100k. The insulating bonding layer 152 of the interconnection scheme 220 of its semiconductor IC chip 100k may include a silicon-oxide layer having a thickness between 0.1 and 2 micrometers.

Referring to FIG. 26, for the semiconductor IC chip 100k of the eighteenth type of FPMCP 321, the interconnection metal layer 16 of its interconnection scheme 220 may include (1) a copper layer 24 having upper portions in openings in the insulating dielectric layer 212 of its interconnection scheme 220 and lower portions having a thickness of between 3 nm and 500 nm under the insulating dielectric layer 212 of its interconnection scheme 220 and in openings in the insulating bonding layer 152 of its interconnection scheme 220, (2) an adhesion metal layer 18, such as titanium or titanium nitride having a thickness of between 1 nm and 50 nm, at a bottom and sidewall of each of the lower portions of the copper layer 24 and at a bottom and sidewall of each of the upper portions of the copper layer 24, and (3) an electroplating seed layer 22, such as copper, between the copper layer 24 and adhesion metal layer 18 of the interconnection metal layer 16 of its interconnection scheme 220, wherein the copper layer 24 of the interconnection metal layer 16 of its interconnection scheme 220 may have a bottom surface substantially coplanar with a bottom surface of the insulating bonding layer 152 of its interconnection scheme 220.

Referring to FIG. 26, for the eighteenth type of FPMCP 321, its semiconductor IC chip 100k may be provided, for hybrid bonding, with (1) the insulating bonding layer 152, i.e., silicon oxide, having the bottom surface attached to and in contact with the top surface of the insulating bonding layer 352, i.e., silicon oxide, of its power-management integrated-circuit (PMIC) chip 415 and (2) the interconnection metal layer 16, i.e., the copper layer 24 thereof, having the bottom surface bonded to and in contact with the top surface of each of the metal pads 6h, i.e., the copper layer 24 thereof, of its power-management integrated-circuit (PMIC) chip 415. The top surface of the semiconductor substrate 2 of its power-management integrated-circuit (PMIC) chip 415, at which the semiconductor devices 4, such as transistors, of its power-management integrated-circuit (PMIC) chip 415 are formed, faces the backside of the semiconductor substrate 2 of its semiconductor IC chip 100k. Each of the metal pads 6h of its power-management integrated-circuit (PMIC) chip 415 may have a width, diameter or transverse dimension smaller than 5, 3, 1 or 0.5 micrometers, or between 0.1 and 5 micrometers, 0.1 and 3 micrometers, 0.1 and 1 micrometers, or 0.1 and 0.5 micrometers. The pitch between neighboring two of the metal pads 6h of its power-management integrated-circuit (PMIC) chip 415 may be smaller than 10, 5, 2 or 1 micrometers, or between 0.2 and 10 micrometers, 0.2 and 5 micrometers, 0.2 and 2 micrometers, or 0.2 and 1 micrometers. Its semiconductor IC chip 100k may have a vertical sidewall coplanar with a vertical sidewall of its power-management integrated-circuit (PMIC) chip 415.

Referring to FIG. 26, for the eighteenth type of FPMCP 321, its power-management integrated-circuit (PMIC) chip 415 may include power management circuits for direct-current-to-direct-current (DC-to-DC) voltage conversion, voltage regulating, battery charging, power source selection, voltage scaling, and/or power sequencing. The power management circuits of its power-management integrated-circuit (PMIC) chip 415 may regulate a first power supply voltage or current at a voltage of Vdd from circuits external of the eighteenth type of FPMCP 321 via its power distribution network or scheme 501 as a second power supply voltage or current at a voltage of Vdd′. The first power supply voltage or current at the voltage of Vdd may be delivered to one of the power-voltage planes, buses or interconnection 182 of its power-management integrated-circuit (PMIC) chip 415 via its power distribution network or scheme 501. Further, the first power supply voltage or current at the voltage of Vdd may be delivered from said one of the power-voltage planes, buses or interconnection 182 of its power-management integrated-circuit (PMIC) chip 415 to the power management circuits of its power-management integrated-circuit (PMIC) chip 415 via its power distribution network or scheme 501. Its power distribution network or scheme 501 may be composed of one or more of the first, second, third or fourth type of micro-bumps, micro-pillars or micro-pads 34 of its semiconductor IC chip 100k, the interconnection metal layers 6 and/or 27 of the first and/or second interconnection schemes for a chip (FISC and/or SISC) 20 and/or 29 of its semiconductor IC chip 100k, one or more of the through silicon vias (TSVs) 157 of its semiconductor IC chip 100k, the interconnection metal layer 16 of the interconnection scheme 220 of its semiconductor IC chip 100k, one or more of the metal pads 6h of its power-management integrated-circuit (PMIC) chip 415 and the interconnection metal layers 6c, 6d, 6e and 6f of the interconnection scheme 120 of its power-management integrated-circuit (PMIC) chip 415. The second power supply voltage or current at the voltage of Vdd′ may be delivered to one of the power-voltage planes, buses or interconnection 182 of its power-management integrated-circuit (PMIC) chip 415 via its power distribution network or scheme 502. Further, the second power supply voltage or current at the voltage of Vdd′ may be delivered from said one of the power-voltage planes, buses or interconnection 182 of its power-management integrated-circuit (PMIC) chip 415 to one or more of the semiconductor devices 4, e.g., transistors, of its semiconductor IC chip 100k via its power distribution network or scheme 502. Its power distribution network or scheme 502 may be composed of the interconnection metal layers 6 and/or 27 of the first and/or second interconnection schemes for a chip (FISC and/or SISC) 20 and/or 29 of its semiconductor IC chip 100k, one or more of the through silicon vias (TSVs) 157 of its semiconductor IC chip 100k, the interconnection metal layer 16 of the interconnection scheme 220 of its semiconductor IC chip 100k, one or more of the metal pads 6h of its power-management integrated-circuit (PMIC) chip 415 and the interconnection metal layers 6c, 6d, 6e and 6f of the interconnection scheme 120 of its power-management integrated-circuit (PMIC) chip 415.

Alternatively, referring to FIG. 26, for the eighteenth type of FPMCP 321, the first power supply voltage or current at the voltage of Vdd may be delivered to one or more of the semiconductor devices 4, e.g., transistors, of its semiconductor IC chip 100k via its power distribution network or scheme 503 not coupling to any power management circuit of its power-management integrated-circuit (PMIC) chip 415. The first power supply voltage or current at the voltage of Vdd may be delivered to one of the power-voltage planes, buses or interconnection 182 of its power-management integrated-circuit (PMIC) chip 415 via its power distribution network or scheme 503. Further, the first power supply voltage or current at the voltage of Vdd may be delivered from said one of the power-voltage planes, buses or interconnection 182 of its power-management integrated-circuit (PMIC) chip 415 to said one or more of the semiconductor devices 4, e.g., transistors, of its semiconductor IC chip 100k via its power distribution network or scheme 503. Its power distribution network or scheme 503 may be composed of one or more of the first, second, third or fourth type of micro-bumps, micro-pillars or micro-pads 34 of its semiconductor IC chip 100k, the interconnection metal layers 6 and/or 27 of the first and/or second interconnection schemes for a chip (FISC and/or SISC) 20 and/or 29 of its semiconductor IC chip 100k, one or more of the through silicon vias (TSVs) 157 of its semiconductor IC chip 100k, the interconnection metal layer 16 of the interconnection scheme 220 of its semiconductor IC chip 100k, one or more of the metal pads 6h of its power-management integrated-circuit (PMIC) chip 415 and the interconnection metal layers 6c, 6d, 6e and 6f of the interconnection scheme 120 of its power-management integrated-circuit (PMIC) chip 415.

Referring to FIG. 26, for the eighteenth type of FPMCP 321, the power management circuits of its power-management integrated-circuit (PMIC) chip 415 may couple to the ground-voltage planes, buses or interconnection 183 of its power-management integrated-circuit (PMIC) chip 415 via its ground distribution network or scheme 504 to deliver a ground supply voltage or current at a voltage of Vss to the ground-voltage planes, buses or interconnection 183 of its power-management integrated-circuit (PMIC) chip 415. The ground-voltage planes, buses or interconnection 183 of its power-management integrated-circuit (PMIC) chip 415 may couple to circuits external of the eighteenth type of FPMCP 321 via its ground distribution network or scheme 504 and to one or more of the semiconductor devices 4, e.g., transistors, of its semiconductor IC chip 100k via its ground distribution network or scheme 504. Its ground distribution network or scheme 504 may be composed of one or more of the first, second, third or fourth type of micro-bumps, micro-pillars or micro-pads 34 of its semiconductor IC chip 100k, the interconnection metal layers 6 and/or 27 of the first and/or second interconnection schemes for a chip (FISC and/or SISC) 20 and/or 29 of its semiconductor IC chip 100k, one or more of the through silicon vias (TSVs) 157 of its semiconductor IC chip 100k, the interconnection metal layer 16 of the interconnection scheme 220 of its semiconductor IC chip 100k, one or more of the metal pads 6h of its power-management integrated-circuit (PMIC) chip 415 and the interconnection metal layers 6c, 6d, 6e and 6f of the interconnection scheme 120 of its power-management integrated-circuit (PMIC) chip 415.

Referring to FIG. 26, for the eighteenth type of FPMCP 321, the power management circuits of its power-management integrated-circuit (PMIC) chip 415 may couple to circuits external of the eighteenth type of FPMCP 321 via its signal distribution network or scheme 505 for transmission of signals S_{PMIC}. Its signal distribution network or scheme 505 may be composed of one or more of the first, second, third or fourth type of micro-bumps, micro-pillars or micro-pads 34 of its semiconductor IC chip 100k, the interconnection metal layers 6 and/or 27 of the first and/or second interconnection schemes for a chip (FISC and/or SISC) 20 and/or 29 of its semiconductor IC chip 100k, one or more of the through silicon vias (TSVs) 157 of its semiconductor IC chip 100k, the interconnection metal layer 16 of the interconnection scheme 220 of its semiconductor IC chip 100k, one or more of the metal pads 6h of its power-management integrated-circuit (PMIC) chip 415 and the interconnection metal layers 6c, 6d, 6e and 6f of the interconnection scheme 120 of its power-management integrated-circuit (PMIC) chip 415.

Referring to FIG. 26, for the eighteenth type of FPMCP 321, the semiconductor devices 4, e.g., transistors, of its semiconductor IC chip 100k may couple to circuits external of the eighteenth type of FPMCP 321 via its signal distribution network or scheme 506 for transmission of signals S_{chip}. Its signal distribution network or scheme 506 may be composed of one or more of the first, second, third or fourth type of micro-bumps, micro-pillars or micro-pads 34 of its semiconductor IC chip 100k and the interconnection metal layers 6 and/or 27 of the first and/or second interconnection schemes for a chip (FISC and/or SISC) 20 and/or 29 of its semiconductor IC chip 100k.

Referring to FIG. 26, for the eighteenth type of FPMCP 321, each of its semiconductor IC chip 100k and power-management integrated-circuit (PMIC) chip 415 may include the first, second or third type of field programmable logic cell or element (LCE) 2014 as illustrated in FIGS. 1A-IC, the first or second type of field programmable switch cell 379 as illustrated in FIGS. 2A and 2B and the programmable switch matrix 710 as illustrated in FIG. 2C. Further, its semiconductor IC chip 100k may be (i) a computing and processing logic IC chip, such as FPGA IC chip, central-processing-unit (CPU) IC chip, digital signal processor (DSP) IC chip, graphic processing unit (GPU) IC chip, data processing unit (DPU) IC chip, tensor flow processing unit (TPU) IC chip, micro-control unit (MCU) IC chip, artificial intelligent unit (AIU) IC chip, machine learning unit (MLU) IC chip, application-specific integrated-circuit (ASIC) chip or system-on-chip (SoC) IC chip; (ii) a volatile memory (VM) IC chip, such as static random-access memory (SRAM) IC chip or dynamic random-access memory (DRAM) IC chip; (iii) a non-volatile memory (NVM) IC chip, such as NAND flash memory IC chip, NOR flash memory IC chip, magnetoresistive random access memory (MRAM) IC chip, resistive random access memory (RRAM) IC chip or ferroelectric random access memory (FRAM) IC chip; or (iv) a mixed-mode or analog IC chip. Its FPGA IC chip 100k may be the dedicated field programmable integrated-circuit (DFPIC) chip as illustrated in FIG. 4D or embedded field programmable integrated-circuit (eFPIC) chip as illustrated in FIG. 4E.

### Nineteenth Type of FPMCP

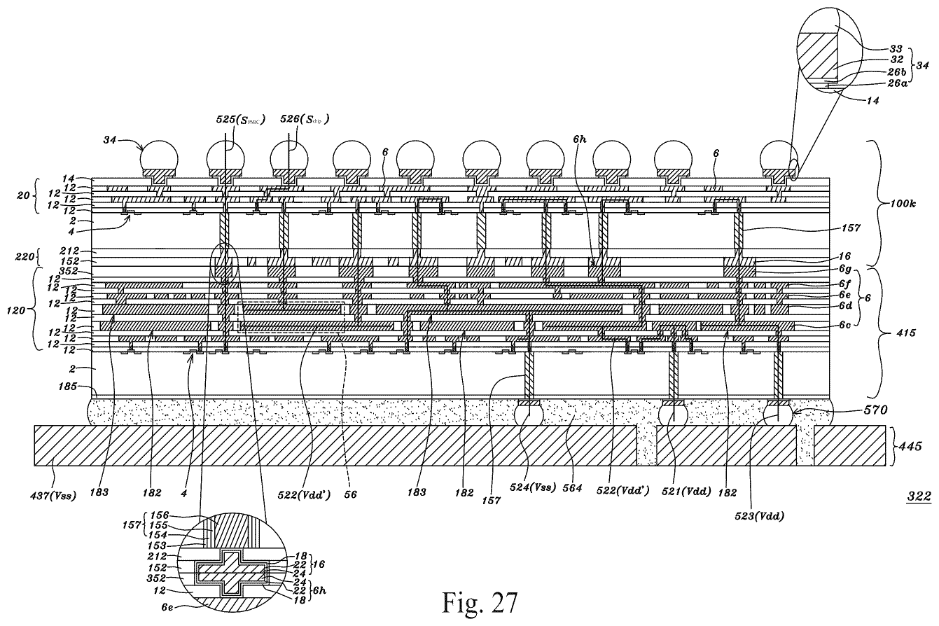

FIG. 27 is a schematically cross-sectional view showing a nineteenth type of FPMCP in accordance with an embodiment of the present application. The nineteenth type of FPMCP 322 as seen in FIG. 27 may have a similar structure to the eighteenth type of FPMCP 321 as seen in FIG. 26. For an element indicated by the same reference number shown in FIGS. 26 and 27, the specification of the element as seen in FIG. 27 may be referred to that of the element as illustrated in FIG. 26. The difference therebetween is mentioned as below: for the nineteenth type of FPMCP 322, its power-management integrated-circuit (PMIC) chip 415 may further include multiple through silicon vias (TSVs) 157 vertically in and through the semiconductor substrate 2 of its power-management integrated-circuit (PMIC) chip 415 and an insulating dielectric layer 185, such as silicon-oxide layer or silicon-nitride layer, on a backside of the semiconductor substrate 2 of its power-management integrated-circuit (PMIC) chip 415. Each of the through silicon vias (TSVs) 157 of its power-management integrated-circuit (PMIC) chip 415 may include (1) an electroplated copper layer 156 having a depth between 30 and 200 micrometers and a largest transverse dimension, such as diameter or width, between 2 and 20 micrometers or between 4 and 10 micrometers in the semiconductor substrate 2 of its power-management integrated-circuit (PMIC) chip 415, (2) an insulating lining layer 153, such as thermally grown silicon oxide (SiO₂) and/or CVD silicon nitride (Si₃N₄) at a bottom and sidewall of the electroplated copper layer 156 of said each of the through silicon vias (TSVs) 157, (3) an adhesion metal layer 154, such as titanium (Ti) or titanium nitride (TiN) layer having a thickness between 1 and 50 nanometers, at a sidewall of the electroplated copper layer 156 of said each of the through silicon vias (TSVs) 157 and between the electroplated copper layer 156 and insulating lining layer 153 of said each of the through silicon vias (TSVs) 157, and (4) an electroplating seed layer 155, such as copper seed layer 155 having a thickness between 3 and 200 nanometers, at the sidewall of the electroplated copper layer 156 of said each of the through silicon vias (TSVs) 157 and between the electroplated copper layer 156 and adhesion metal layer 154 of said each of the through silicon vias (TSVs) 157. Each of the through silicon vias (TSVs) 157 of its power-management integrated-circuit (PMIC) chip 415 may have a backside, i.e., a backside of the copper layer 156 thereof, coplanar with a bottom surface of the insulating dielectric layer 185 of its power-management integrated-circuit (PMIC) chip 415.

Referring to FIG. 27, for the nineteenth type of FPMCP 322, its power-management integrated-circuit (PMIC) chip 415 may further include multiple metal bumps, pillars or pads 570, which may have the same specification as that of a type of the first and second types of metal bumps, pillars or pads 570 as illustrated in FIG. 6A, each having the adhesion metal layer 26a on the backside of one of the through silicon vias (TSVs) 157 of its power-management integrated-circuit (PMIC) chip 415 and on the bottom surface of the insulating dielectric layer 185 of its power-management integrated-circuit (PMIC) chip 415. Each of the metal bumps, pillars or pads 570 of its power-management integrated-circuit (PMIC) chip 415 may be bonded to a power plate 436 of its heat sink or spreader 445, made of copper or aluminum, for delivering the first power supply voltage or current at the voltage of Vdd or to a ground plate 437 of its heat sink or spreader 445 for delivering the ground supply voltage or current at the voltage of Vss. The nineteenth type of FPMCP 322 may further include an underfill 564, i.e., polymer layer, between its heat sink or spreader 445 and power-management integrated-circuit (PMIC) chip 415, covering a sidewall of each of the metal bumps, pillars or pads 570 of its power-management integrated-circuit (PMIC) chip 415.

Referring to FIG. 27, for the nineteenth type of FPMCP 322, its power-management integrated-circuit (PMIC) chip 415 may include power management circuits for direct-current-to-direct-current (DC-to-DC) voltage conversion, voltage regulating, battery charging, power source selection, voltage scaling, and/or power sequencing. The power management circuits of its power-management integrated-circuit (PMIC) chip 415 may regulate the first power supply voltage or current at the voltage of Vdd from circuits external of the nineteenth type of FPMCP 322 via its power distribution network or scheme 521 as the second power supply voltage or current at the voltage of Vdd′. The first power supply voltage or current at the voltage of Vdd may be delivered to one of the power-voltage planes, buses or interconnection 182 of its power-management integrated-circuit (PMIC) chip 415 via its power distribution network or scheme 521. Further, the first power supply voltage or current at the voltage of Vdd may be delivered from said one of the power-voltage planes, buses or interconnection 182 of its power-management integrated-circuit (PMIC) chip 415 to the power management circuits of its power-management integrated-circuit (PMIC) chip 415 via its power distribution network or scheme 521. Its power distribution network or scheme 521 may be composed of the power plate 436 of its heat sink or spreader 445, one or more of the metal bumps, pillars or pads 570 of its power-management integrated-circuit (PMIC) chip 415, one or more of the through silicon vias (TSVs) 157 of its power-management integrated-circuit (PMIC) chip 415 and the interconnection metal layer 6c of the interconnection scheme 120 of its power-management integrated-circuit (PMIC) chip 415. The second power supply voltage or current at the voltage of Vdd′ may be delivered to one of the power-voltage planes, buses or interconnection 182 of its power-management integrated-circuit (PMIC) chip 415 via its power distribution network or scheme 522. Further, the second power supply voltage or current at the voltage of Vdd′ may be delivered from said one of the power-voltage planes, buses or interconnection 182 of its power-management integrated-circuit (PMIC) chip 415 to one or more of the semiconductor devices 4, e.g., transistors, of its semiconductor IC chip 100k via its power distribution network or scheme 522. Its power distribution network or scheme 522 may be composed of the interconnection metal layers 6 and/or 27 of the first and/or second interconnection schemes for a chip (FISC and/or SISC) 20 and/or 29 of its semiconductor IC chip 100k, one or more of the through silicon vias (TSVs) 157 of its semiconductor IC chip 100k, the interconnection metal layer 16 of the interconnection scheme 220 of its semiconductor IC chip 100k, one or more of the metal pads 6a of its power-management integrated-circuit (PMIC) chip 415 and the interconnection metal layers 6c, 6d, 6e and 6f of the interconnection scheme 120 of its power-management integrated-circuit (PMIC) chip 415.

Alternatively, referring to FIG. 27, for the nineteenth type of FPMCP 322, the first power supply voltage or current at the voltage of Vdd may be delivered to one or more of the semiconductor devices 4, e.g., transistors, of its semiconductor IC chip 100k via its power distribution network or scheme 523 not coupling to any power management circuit of its power-management integrated-circuit (PMIC) chip 415. The first power supply voltage or current at the voltage of Vdd may be delivered to one of the power-voltage planes, buses or interconnection 182 of its power-management integrated-circuit (PMIC) chip 415 via its power distribution network or scheme 523. Further, the first power supply voltage or current at the voltage of Vdd may be delivered from said one of the power-voltage planes, buses or interconnection 182 of its power-management integrated-circuit (PMIC) chip 415 to said one or more of the semiconductor devices 4, e.g., transistors, of its semiconductor IC chip 100k via its power distribution network or scheme 523. Its power distribution network or scheme 523 may be composed of the power plate 436 of its heat sink or spreader 445, one or more of the metal bumps, pillars or pads 570 of its power-management integrated-circuit (PMIC) chip 415, one or more of the through silicon vias (TSVs) 157 of its power-management integrated-circuit (PMIC) chip 415, the interconnection metal layers 6c, 6d, 6e and 6f of the interconnection scheme 120 of its power-management integrated-circuit (PMIC) chip 415, one or more of the metal pads 6a of its power-management integrated-circuit (PMIC) chip 415, the interconnection metal layer 16 of the interconnection scheme 220 of its semiconductor IC chip 100k, one or more of the through silicon vias (TSVs) 157 of its semiconductor IC chip 100k and the interconnection metal layers 6 and/or 27 of the first and/or second interconnection schemes for a chip (FISC and/or SISC) 20 and/or 29 of its semiconductor IC chip 100k.

Referring to FIG. 27, for the nineteenth type of FPMCP 322, the power management circuits of its power-management integrated-circuit (PMIC) chip 415 may couple to the ground-voltage planes, buses or interconnection 183 of its power-management integrated-circuit (PMIC) chip 415 via its ground distribution network or scheme 504 to deliver the ground supply voltage or current at the voltage of Vss to the ground-voltage planes, buses or interconnection 183 of its power-management integrated-circuit (PMIC) chip 415. The ground-voltage planes, buses or interconnection 183 of its power-management integrated-circuit (PMIC) chip 415 may couple to circuits external of the nineteenth type of FPMCP 322 via its ground distribution network or scheme 524 and to one or more of the semiconductor devices 4, e.g., transistors, of its semiconductor IC chip 100k via its ground distribution network or scheme 524. Its ground distribution network or scheme 524 may be composed of the ground plate 437 of its heat sink or spreader 445, one or more of the metal bumps, pillars or pads 570 of its power-management integrated-circuit (PMIC) chip 415, one or more of the through silicon vias (TSVs) 157 of its power-management integrated-circuit (PMIC) chip 415, the interconnection metal layers 6c, 6d, 6e and 6f of the interconnection scheme 120 of its power-management integrated-circuit (PMIC) chip 415, one or more of the metal pads 6a of its power-management integrated-circuit (PMIC) chip 415, the interconnection metal layer 16 of the interconnection scheme 220 of its semiconductor IC chip 100k, one or more of the through silicon vias (TSVs) 157 of its semiconductor IC chip 100k and the interconnection metal layers 6 and/or 27 of the first and/or second interconnection schemes for a chip (FISC and/or SISC) 20 and/or 29 of its semiconductor IC chip 100k.

Referring to FIG. 27, for the nineteenth type of FPMCP 322, the power management circuits of its power-management integrated-circuit (PMIC) chip 415 may couple to circuits external of the nineteenth type of FPMCP 322 via its signal distribution network or scheme 525 for transmission of signals S_{PMIC}. Its signal distribution network or scheme 525 may be composed of one or more of the first, second, third or fourth type of micro-bumps, micro-pillars or micro-pads 34 of its semiconductor IC chip 100k, the interconnection metal layers 6 and/or 27 of the first and/or second interconnection schemes for a chip (FISC and/or SISC) 20 and/or 29 of its semiconductor IC chip 100k, one or more of the through silicon vias (TSVs) 157 of its semiconductor IC chip 100k, the interconnection metal layer 16 of the interconnection scheme 220 of its semiconductor IC chip 100g, one or more of the metal pads 6a of its power-management integrated-circuit (PMIC) chip 415 and the interconnection metal layers 6c, 6d, 6e and 6f of the interconnection scheme 120 of its power-management integrated-circuit (PMIC) chip 415.

Referring to FIG. 27, for the nineteenth type of FPMCP 322, the semiconductor devices 4, e.g., transistors, of its semiconductor IC chip 100k may couple to circuits external of the nineteenth type of FPMCP 322 via its signal distribution network or scheme 526 for transmission of signals S_{chip}. Its signal distribution network or scheme 526 may be composed of one or more of the first, second, third or fourth type of micro-bumps, micro-pillars or micro-pads 34 of its semiconductor IC chip 100k and the interconnection metal layers 6 and/or 27 of the first and/or second interconnection schemes for a chip (FISC and/or SISC) 20 and/or 29 of its semiconductor IC chip 100k.

### Twentieth Type of FPMCP

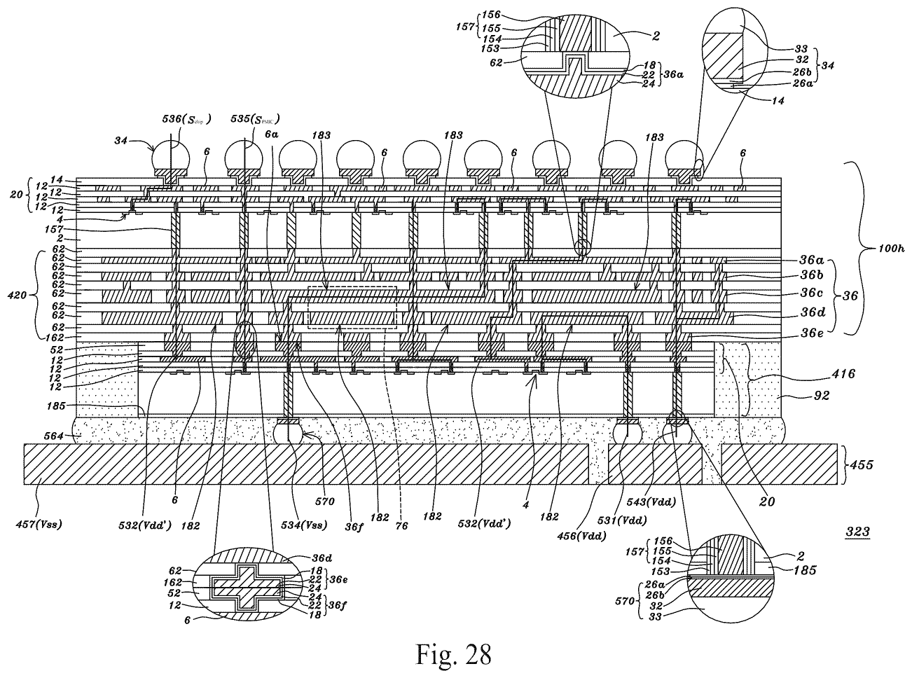

FIG. 28 is a schematically cross-sectional view showing a twentieth type of FPMCP in accordance with an embodiment of the present application. The twentieth type of FPMCP 323 as seen in FIG. 28 may fabricated by a die-to-wafer bonding process, including (1) a power-management integrated-circuit (PMIC) chip 416, (2) a semiconductor IC chip 100h having a backside attached to a front side of its power-management integrated-circuit (PMIC) chip 416, and (3) a heat sink or spreader 455, made of copper or aluminum, attached to a backside of its power-management integrated-circuit (PMIC) chip 416.

Referring to FIG. 28, for the twentieth type of FPMCP 323, its semiconductor IC chip 100h may have the same specification as the second type of semiconductor IC chip 100 illustrated in FIGS. 3B and 3G-3J. For an element of its semiconductor IC chip 100h shown in FIG. 28, which is indicated by the same reference number as that for an element of the second type of semiconductor IC chip 100 shown in FIGS. 3B and 3G-3J, the specification of the element of its semiconductor IC chip 100h as shown in FIG. 28 may be referred to that of the element of the second type of semiconductor IC chip 100 as illustrated in FIGS. 3A, 3B and 3G-3J. The semiconductor substrate 2 of its semiconductor IC chip 100h may have a portion, at a backside of the semiconductor substrate 2 of its semiconductor IC chip 100h, removed by a chemical-mechanical-polishing (CMP) or mechanical grinding process such that each of the through silicon vias (TSVs) 157, that is, the electroplated copper layer 156 thereof, of its semiconductor IC chip 100h may have a bottom surface substantially coplanar with a bottom surface of the semiconductor substrate 2 of its semiconductor IC chip 100h. Thereby, in this example, the semiconductor substrate 2 of its semiconductor IC chip 100h may have a thickness between 0.1 and 20 micrometers, between 1 and 10 micrometers or between 1 and 5 micrometers, and each of the through silicon vias (TSVs) 157 of its semiconductor IC chip 100h may have a diameter between 0.5 and 20 micrometers, between 1 and 10 micrometers or between 1 and 5 micrometers. Its semiconductor IC chip 100h may be provided with an interconnection scheme 420 under and on the backside of the semiconductor substrate 2 of its semiconductor IC chip 100h, including multiple interconnection metal layers 36 under the backside of the semiconductor substrate 2 of its semiconductor IC chip 100g and multiple insulating dielectric layers 62 each between neighboring two of the interconnection metal layers 36 of the interconnection scheme 420 of its semiconductor IC chip 100h or between the topmost one of the interconnection metal layers 36 of the interconnection scheme 420 of its semiconductor IC chip 100h and the backside of the semiconductor substrate 2 of its semiconductor IC chip 100h.

Referring to FIG. 28, for the semiconductor IC chip 100h of the twentieth type of FPMCP 323, each of the interconnection metal layers 36 of its interconnection scheme 420 may include (1) a copper layer 24 having upper portions in openings in a upper one of the insulating dielectric layers 62 of its interconnection scheme 420 and lower portions under the upper one of the insulating dielectric layers 62 and in openings in a lower one of the insulating dielectric layers 62 of its interconnection scheme 420, (2) an adhesion metal layer 18, such as titanium or titanium nitride having a thickness of between 1 nm and 50 nm, at a top and sidewall of each of the upper portions of the copper layer 24 and at a top and sidewall of each of the lower portions of the copper layer 24, and (3) an electroplating seed layer 22, such as copper, between the copper layer 24 and adhesion metal layer 18 of said each of the interconnection metal layers 36, wherein the copper layer 24 of said each of the interconnection metal layers 36 may have a bottom surface substantially coplanar with a bottom surface of the lower one of the insulating dielectric layers 62.

Referring to FIG. 28, for the semiconductor IC chip 100h of the twentieth type of FPMCP 323, the interconnection metal layers 36 of its interconnection scheme 420 may include (1) a first interconnection metal layer 36a provided with multiple power distribution traces each having a thickness between 0.05 and 5 micrometers or between 0.1 and 2 micrometers and multiple ground distribution traces each having a thickness between 0.05 and 5 micrometers or between 0.1 and 2 micrometers, (2) a second interconnection metal layer 36b under the first interconnection metal layer 36a of its interconnection scheme 420, provided with multiple power distribution traces each having a thickness between 0.05 and 5 micrometers or between 0.1 and 2 micrometers and coupling to one of the power distribution traces of the first interconnection metal layer 36a of its interconnection scheme 420 and multiple ground distribution traces each having a thickness between 0.05 and 5 micrometers or between 0.1 and 2 micrometers and coupling to one of the ground distribution traces of the first interconnection metal layer 36a of its interconnection scheme 420, (3) a third interconnection metal layer 36c under the second interconnection metal layer 36b of its interconnection scheme 420, provided with ground-voltage planes, buses or interconnection 183 each having a thickness between 0.1 and 10 micrometers or between 0.5 and 5 micrometers and coupling to one or more of the ground distribution traces of the first interconnection metal layer 36a of its interconnection scheme 420 through one or more of the ground distribution traces of the second interconnection metal layer 36b of its interconnection scheme 420, (4) a fourth interconnection metal layer 36d under the third interconnection metal layer 36c of its interconnection scheme 420, provided with power-voltage planes, buses or interconnection 182 each having a thickness between 0.1 and 10 micrometers or between 0.5 and 5 micrometers and coupling to one or more of the power distribution traces of the first interconnection metal layer 36a of its interconnection scheme 420 through one or more of the power distribution traces of the second interconnection metal layer 36b of its interconnection scheme 420, and (5) a fifth interconnection metal layer 36e under the fourth interconnection metal layer 36d of its interconnection scheme 420, provided with multiple metal pads 36f each in one of multiple openings in the bottommost one of the insulating dielectric layers 62 of its interconnection scheme 420. The bottommost one of the insulating dielectric layers 62 of its interconnection scheme 420 may act as an insulating bonding layer 162 having a silicon-oxide layer having a thickness between 0.1 and 2 micrometers and each of the metal pads 36f of the fifth interconnection metal layer 36e of its interconnection scheme 420 may be provided with the copper layer 24 having a thickness between 3 nm and 500 nm in the insulating bonding layer 162 of its interconnection scheme 420, wherein the insulating bonding layer 162 of its interconnection scheme 420 may have a bottom surface substantially coplanar with a bottom surface of each of the metal pads 36f, i.e., the copper layer 24 thereof, of the fifth interconnection metal layer 36e of its interconnection scheme 420. Each of the third and fourth interconnection metal layers 36c and 36d of its interconnection scheme 420 may have a thickness greater than that of either of the first and second interconnection metal layers 36a and 36b of its interconnection scheme 420.

Referring to FIG. 28, for the semiconductor IC chip 100h of the twentieth type of FPMCP 323, the power-voltage planes, buses or interconnection 182 of the fourth interconnection metal layer 36d of its interconnection scheme 420 may be provided for one of two electrodes of its decoupling capacitor 76, the ground-voltage planes, buses or interconnection 183 of the third interconnection metal layer 36c of its interconnection scheme 420 may be provided for the other of the two electrodes of its decoupling capacitor 76; one of the insulating dielectric layers 62 between the power-voltage planes, buses or interconnection 182 of the fourth interconnection metal layer 36d of its interconnection scheme 420 and the ground-voltage planes, buses or interconnection 183 of the third interconnection metal layer 36c of its interconnection scheme 420 may be provided for a dielectric layer of its decoupling capacitor 76 between the two electrodes of its decoupling capacitor 76, wherein the dielectric layer of its decoupling capacitor 76 may be made of a layer of hafnium oxide (HfO₂), tantalum oxide (Ta₂O₅), silicon oxide or silicon oxycarbide having a thickness between 0.1 and 2 micrometers, between 3 nm and 1,000 nm or between 10 nm and 500 nm, or thinner than 5 nm, 10 nm, 30 nm, 50 nm, 100 nm, 200 nm, 300 nm, 500 nm or 1,000 nm.

Referring to FIG. 28, for the semiconductor IC chip 100h of the twentieth type of FPMCP 323, besides the dielectric layer of its decoupling capacitor 76, each of the insulating dielectric layers 62 of its interconnection scheme 420 may have a thickness between 0.1 and 2 micrometers, between 3 nm and 1,000 nm or between 10 nm and 500 nm, or thinner than 5 nm, 10 nm, 30 nm, 50 nm, 100 nm, 200 nm, 300 nm, 500 nm or 1,000 nm.

Referring to FIG. 28, for the twentieth type of FPMCP 323, its power-management integrated-circuit (PMIC) chip 416 may have the same specification as that of the sixth type of semiconductor IC chip 100 illustrated in FIGS. 3F-3J. For an element of its power-management integrated-circuit (PMIC) chip 416 shown in FIG. 28, which is indicated by the same reference number as that for an element of the sixth type of semiconductor IC chip 100 shown in FIGS. 3F-3J, the specification of the element of its power-management integrated-circuit (PMIC) chip 416 shown in FIG. 28 may be referred to that of the element of the sixth type of semiconductor IC chip 100 as illustrated in FIGS. 3A, 3B and 3E-3J. It is noted that for the power-management integrated-circuit (PMIC) chip 416 of the twentieth type of FPMCP 323, its first interconnection scheme for a chip (FISC) 20 may further include another insulating dielectric layer 12, having the same specification as that of any of the insulating dielectric layers 12 illustrated in FIGS. 3A, 3B and 3E-3J, on the topmost one of the interconnection metal layers 6 of its first interconnection scheme for a chip (FISC) 20 and one of the insulating dielectric layers 12 of its first interconnection scheme for a chip (FISC) 20; each of its metal pads 6a and its insulating bonding layer 52 may be formed on said another insulating dielectric layer 12 of its first interconnection scheme for a chip (FISC) 20; and each of its metal pads 6a may couple to the topmost one of the interconnection metal layers 6 of its first interconnection scheme for a chip (FISC) 20 through an opening in said another insulating dielectric layer 12 of its first interconnection scheme for a chip (FISC) 20.

Referring to FIG. 28, for the twentieth type of FPMCP 323, its semiconductor IC chip 100h may be provided, for hybrid bonding, with (1) the insulating bonding layer 162, i.e., silicon oxide, having the bottom surface attached to and in contact with the top surface of the insulating bonding layer 52, i.e., silicon oxide, of its power-management integrated-circuit (PMIC) chip 416 and (2) the metal pads 36f, i.e., the copper layer 24 thereof, having the bottom surface bonded to and in contact with the top surface of each of the metal pads 6a, i.e., the copper layer 24 thereof, of its power-management integrated-circuit (PMIC) chip 416. The top surface of the semiconductor substrate 2 of its power-management integrated-circuit (PMIC) chip 416, at which the semiconductor devices 4, such as transistors, of its power-management integrated-circuit (PMIC) chip 416 are formed, faces the backside of the semiconductor substrate 2 of its semiconductor IC chip 100h. Each of the metal pads 6a of its power-management integrated-circuit (PMIC) chip 416 may have a width, diameter or transverse dimension smaller than 5, 3, 1 or 0.5 micrometers, or between 0.1 and 5 micrometers, 0.1 and 3 micrometers, 0.1 and 1 micrometers, or 0.1 and 0.5 micrometers. The pitch between neighboring two of the metal pads 6a of its power-management integrated-circuit (PMIC) chip 416 may be smaller than 10, 5, 2 or 1 micrometers, or between 0.2 and 10 micrometers, 0.2 and 5 micrometers, 0.2 and 2 micrometers, or 0.2 and 1 micrometers. Also, each of the metal pads 36f of its semiconductor IC chip 100h may have a width, diameter or transverse dimension smaller than 5, 3, 1 or 0.5 micrometers, or between 0.1 and 5 micrometers, 0.1 and 3 micrometers, 0.1 and 1 micrometers, or 0.1 and 0.5 micrometers. The pitch between neighboring two of the metal pads 36f of its semiconductor IC chip 100h may be smaller than 10, 5, 2 or 1 micrometers, or between 0.2 and 10 micrometers, 0.2 and 5 micrometers, 0.2 and 2 micrometers, or 0.2 and 1 micrometers.

Referring to FIG. 28, for the twentieth type of FPMCP 323, the semiconductor substrate 2 of its power-management integrated-circuit (PMIC) chip 416 may have a portion, at a backside of the semiconductor substrate 2 of its power-management integrated-circuit (PMIC) chip 416, removed by a chemical-mechanical-polishing (CMP) or mechanical grinding process, and an insulating dielectric layer 185, such as silicon-oxide layer or silicon-nitride layer, may be formed on the backside of the semiconductor substrate 2 of its power-management integrated-circuit (PMIC) chip 416, wherein the insulating dielectric layer 185 of its power-management integrated-circuit (PMIC) chip 416 may have a bottom surface coplanar with a bottom surface of each of the through silicon vias 157 of its power-management integrated-circuit (PMIC) chip 416.

Referring to FIG. 28, the twentieth type of FPMCP 323 may further include a polymer layer 92 or insulating dielectric layer, i.e., sealing layer, such as silicon-oxide-containing molding compound, epoxy-based material or polyimide, on the bottom surface of the insulating bonding layer 162 of its semiconductor IC chip 100h and at the same horizontal level as its power-management integrated-circuit (PMIC) chip 416, wherein its polymer layer 92 may contact a sidewall of its power-management integrated-circuit (PMIC) chip 416 and have a bottom surface substantially coplanar with the bottom surface of the insulating dielectric layer 185 of its power-management integrated-circuit (PMIC) chip 416. Its polymer layer 92 may have a vertical sidewall coplanar with a vertical sidewall of its semiconductor IC chip 100h.

Referring to FIG. 28, the twentieth type of FPMCP 323 may further include multiple metal bumps, pillars or pads 570, which may have the same specification as that of a type of the first and second types of metal bumps, pillars or pads 570 as illustrated in FIG. 7, each having the adhesion metal layer 26a on the backside of one of the through silicon vias (TSVs) 157 of its power-management integrated-circuit (PMIC) chip 416 and on the bottom surface of the insulating dielectric layer 185 of its power-management integrated-circuit (PMIC) chip 416. Each of its metal bumps, pillars or pads 570 may be bonded to a power plate 456 of its heat sink or spreader 455 for delivering a first power supply voltage or current at a voltage of Vdd or to a ground plate 457 of its heat sink or spreader 455 for delivering a ground supply voltage or current at a voltage of Vss. The twentieth type of FPMCP 323 may further include an underfill 564, i.e., polymer layer, between its heat sink or spreader 455 and power-management integrated-circuit (PMIC) chip 416 and between its heat sink or spreader 455 and polymer layer 92, covering a sidewall of each of its metal bumps, pillars or pads 570.

Referring to FIG. 28, for the twentieth type of FPMCP 323, its power-management integrated-circuit (PMIC) chip 416 may include power management circuits for direct-current-to-direct-current (DC-to-DC) voltage conversion, voltage regulating, battery charging, power source selection, voltage scaling, and/or power sequencing. The power management circuits of its power-management integrated-circuit (PMIC) chip 416 may regulate the first power supply voltage or current at the voltage of Vdd from circuits external of the twentieth type of FPMCP 323 via its power distribution network or scheme 531 as a second power supply voltage or current at a voltage of Vdd′. The first power supply voltage or current at the voltage of Vdd may be delivered to one of the power-voltage planes, buses or interconnection 182 of its semiconductor IC chip 100h via its power distribution network or scheme 531. Further, the first power supply voltage or current at the voltage of Vdd may be delivered from said one of the power-voltage planes, buses or interconnection 182 of its semiconductor IC chip 100h to the power management circuits of its power-management integrated-circuit (PMIC) chip 416 via its power distribution network or scheme 531. Its power distribution network or scheme 531 may be composed of the power plate 456 of its heat sink or spreader 455, one or more of its metal bumps, pillars or pads 570, one or more of the through silicon vias (TSVs) 157 of its power-management integrated-circuit (PMIC) chip 416, the interconnection metal layers 6 of the first interconnection scheme for a chip (FISC) 20 of its power-management integrated-circuit (PMIC) chip 416, one or more of the metal pads 6a of its power-management integrated-circuit (PMIC) chip 416, one or more of the metal pads 36f of its semiconductor IC chip 100h and the interconnection metal layer 36d of the interconnection scheme 420 of its semiconductor IC chip 100h. The second power supply voltage or current at the voltage of Vdd′ may be delivered to one of the power-voltage planes, buses or interconnection 182 of its semiconductor IC chip 100h via its power distribution network or scheme 532. Further, the second power supply voltage or current at the voltage of Vdd′ may be delivered from said one of the power-voltage planes, buses or interconnection 182 of its semiconductor IC chip 100h to one or more of the semiconductor devices 4, e.g., transistors, of its semiconductor IC chip 100h via its power distribution network or scheme 532. Its power distribution network or scheme 532 may be composed of the interconnection metal layers 6 and/or 27 of the first and/or second interconnection schemes for a chip (FISC and/or SISC) 20 and/or 29 of its semiconductor IC chip 100h, one or more of the through silicon vias (TSVs) 157 of its semiconductor IC chip 100h, the interconnection metal layers 36a-36d of the interconnection scheme 420 of its semiconductor IC chip 100h, one or more of the metal pads 36f of the interconnection scheme 420 of its semiconductor IC chip 100h, one or more of the metal pads 6a of its power-management integrated-circuit (PMIC) chip 416 and the interconnection metal layers 6 of the first interconnection scheme for a chip (FISC) 20 of its power-management integrated-circuit (PMIC) chip 416.

Alternatively, referring to FIG. 28, for the twentieth type of FPMCP 323, the first power supply voltage or current at the voltage of Vdd may be delivered to one or more of the semiconductor devices 4, e.g., transistors, of its semiconductor IC chip 100h via its power distribution network or scheme 543 not coupling to any power management circuit of its power-management integrated-circuit (PMIC) chip 416. The first power supply voltage or current at the voltage of Vdd may be delivered to one of the power-voltage planes, buses or interconnection 182 of its semiconductor IC chip 100h via its power distribution network or scheme 543. Further, the first power supply voltage or current at the voltage of Vdd may be delivered from said one of the power-voltage planes, buses or interconnection 182 of its semiconductor IC chip 100h to said one or more of the semiconductor devices 4, e.g., transistors, of its semiconductor IC chip 100h via its power distribution network or scheme 543. Its power distribution network or scheme 543 may be composed of the power plate 456 of its heat sink or spreader 455, one or more of its metal bumps, pillars or pads 570, one or more of the through silicon vias (TSVs) 157 of its power-management integrated-circuit (PMIC) chip 416, the interconnection metal layers 6 of the first interconnection scheme for a chip (FISC) 20 of its power-management integrated-circuit (PMIC) chip 416, one or more of the metal pads 6a of its power-management integrated-circuit (PMIC) chip 416, one or more of the metal pads 36f of its semiconductor IC chip 100h, the interconnection metal layers 36a-36d of the interconnection scheme 420 of its semiconductor IC chip 100h, one or more of the through silicon vias (TSVs) 157 of its semiconductor IC chip 100h and the interconnection metal layers 6 and/or 27 of the first and/or second interconnection schemes for a chip (FISC and/or SISC) 20 and/or 29 of its semiconductor IC chip 100h.

Referring to FIG. 28, for the twentieth type of FPMCP 323, the power management circuits of its power-management integrated-circuit (PMIC) chip 416 may couple to the ground-voltage planes, buses or interconnection 183 of its semiconductor IC chip 100h via its ground distribution network or scheme 534 to deliver the ground supply voltage or current at the voltage of Vss to the ground-voltage planes, buses or interconnection 183 of its semiconductor IC chip 100h. The ground-voltage planes, buses or interconnection 183 of its semiconductor IC chip 100h may couple to circuits external of the twentieth type of FPMCP 323 via its ground distribution network or scheme 534 and to one or more of the semiconductor devices 4, e.g., transistors, of its semiconductor IC chip 100h via its ground distribution network or scheme 534. Its ground distribution network or scheme 534 may be composed of the ground plate 457 of its heat sink or spreader 455, one or more of its metal bumps, pillars or pads 570, one or more of the through silicon vias (TSVs) 157 of its power-management integrated-circuit (PMIC) chip 416, the interconnection metal layers 6 of the first interconnection scheme for a chip (FISC) 20 of its power-management integrated-circuit (PMIC) chip 416, one or more of the metal pads 6a of its power-management integrated-circuit (PMIC) chip 416, one or more of the metal pads 36f of its semiconductor IC chip 100h, the interconnection metal layers 36a-36d of the interconnection scheme 420 of its semiconductor IC chip 100h, one or more of the through silicon vias (TSVs) 157 of its semiconductor IC chip 100h and the interconnection metal layers 6 and/or 27 of the first and/or second interconnection schemes for a chip (FISC and/or SISC) 20 and/or 29 of its semiconductor IC chip 100h.

Referring to FIG. 28, for the twentieth type of FPMCP 323, the power management circuits of its power-management integrated-circuit (PMIC) chip 416 may couple to circuits external of the twentieth type of FPMCP 323 via its signal distribution network or scheme 535 for transmission of signals S_{PMIC}. Its signal distribution network or scheme 535 may be composed of one or more of the first, second, third or fourth type of micro-bumps, micro-pillars or micro-pads 34 of its semiconductor IC chip 100h, the interconnection metal layers 6 and/or 27 of the first and/or second interconnection schemes for a chip (FISC and/or SISC) 20 and/or 29 of its semiconductor IC chip 100h, one or more of the through silicon vias (TSVs) 157 of its semiconductor IC chip 100h, the interconnection metal layers 36a-36d of the interconnection scheme 420 of its semiconductor IC chip 100h, one or more of the metal pads 36f of its semiconductor IC chip 100h, one or more of the metal pads 6a of its power-management integrated-circuit (PMIC) chip 416 and the interconnection metal layers 6 of the first interconnection scheme for a chip (FISC) 20 of its power-management integrated-circuit (PMIC) chip 416.

Referring to FIG. 28, for the twentieth type of FPMCP 323, the semiconductor devices 4, e.g., transistors, of its semiconductor IC chip 100h may couple to circuits external of the twentieth type of FPMCP 323 via its signal distribution network or scheme 536 for transmission of signals S_{chip}. Its signal distribution network or scheme 536 may be composed of one or more of the first, second, third or fourth type of micro-bumps, micro-pillars or micro-pads 34 of its semiconductor IC chip 100h and the interconnection metal layers 6 and/or 27 of the first and/or second interconnection schemes for a chip (FISC and/or SISC) 20 and/or 29 of its semiconductor IC chip 100h.

Referring to FIG. 28, for the twentieth type of FPMCP 323, each of its semiconductor IC chip 100h and power-management integrated-circuit (PMIC) chip 416 may include the first, second or third type of field programmable logic cell or element (LCE) 2014 as illustrated in FIGS. 1A-1C, the first or second type of field programmable switch cell 379 as illustrated in FIGS. 2A and 2B and the programmable switch matrix 710 as illustrated in FIG. 2C. Further, its semiconductor IC chip 100h may be (i) a computing and processing logic IC chip, such as FPGA IC chip, central-processing-unit (CPU) IC chip, digital signal processor (DSP) IC chip, graphic processing unit (GPU) IC chip, data processing unit (DPU) IC chip, tensor flow processing unit (TPU) IC chip, micro-control unit (MCU) IC chip, artificial intelligent unit (AIU) IC chip, machine learning unit (MLU) IC chip, application-specific integrated-circuit (ASIC) chip or system-on-chip (SoC) IC chip; (ii) a volatile memory IC chip, such as static random-access memory (SRAM) IC chip or dynamic random-access memory (DRAM) IC chip; (iii) a non-volatile memory IC chip, such as NAND flash memory IC chip, NOR flash memory IC chip, magnetoresistive random access memory (MRAM) IC chip, resistive random access memory (RRAM) IC chip or ferroelectric random access memory (FRAM) IC chip; or (iv) a mixed-mode or analog IC chip. Its FPGA IC chip 100h may be the dedicated field programmable integrated-circuit (DFPIC) chip as illustrated in FIG. 4D or embedded field programmable integrated-circuit (eFPIC) chip as illustrated in FIG. 4E.

### Twenty-First Type of FPMCP

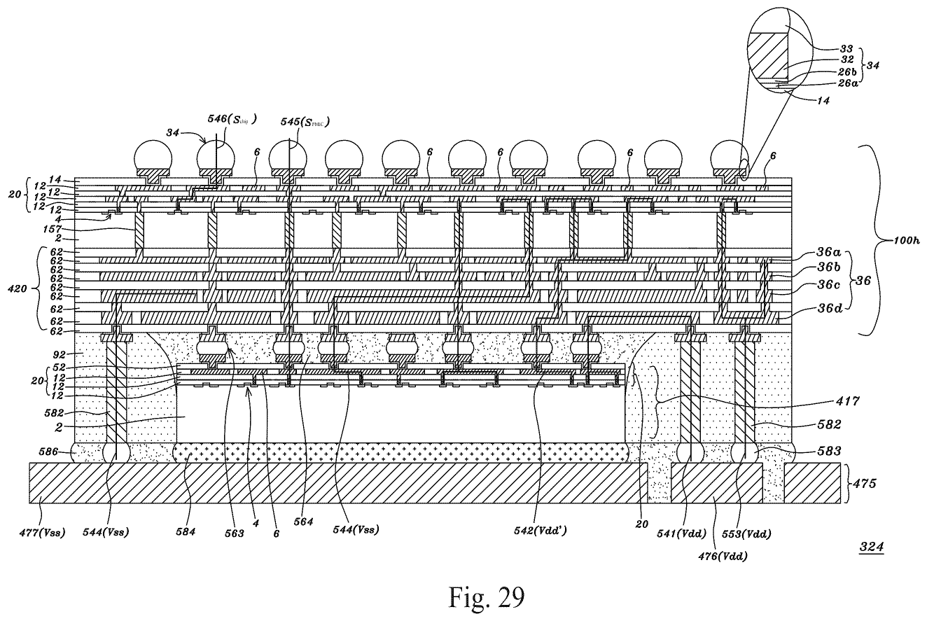

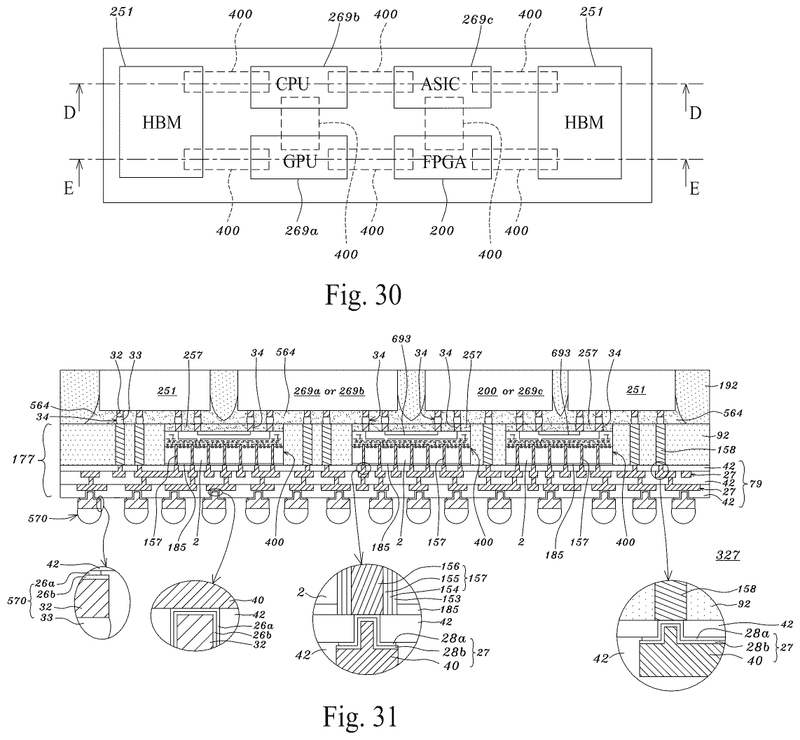

FIG. 29 is a schematically cross-sectional view showing a twenty-first type of FPMCP in accordance with an embodiment of the present application. The twenty-first type of FPMCP 324 as seen in FIG. 29 may have a similar structure to the twentieth type of FPMCP 323 as seen in FIG. 28. For an element indicated by the same reference number shown in FIGS. 28 and 29, the specification of the element as seen in FIG. 29 may be referred to that of the element as illustrated in FIG. 28. The difference therebetween is mentioned as below: The fifth interconnection metal layer 36e of the interconnection scheme 420 of the semiconductor IC chip 100h of the twentieth type of FPMCP 323 as seen in FIG. 28 may not be formed for the twenty-first type of FPMCP 324, but the semiconductor IC chip 100h of the twenty-first type of FPMCP 324 may be formed with multiple metal bumps, pillars or pads, each of which may be of a type selected from first through fourth types having the same specification as that of the first through fourth types of micro-bumps, micro-pillars or micro-pads 34 as illustrated in FIG. 3A to be turned upside down respectively, on the fifth interconnection metal layer 36e of the interconnection scheme 420 of the semiconductor IC chip 100h of the twenty-first type of FPMCP 324, and each of the metal bumps, pillars or pads of the semiconductor IC chip 100h of the twenty-first type of FPMCP 324 may have the adhesion metal layer 26a on a bottom surface of the fourth interconnection metal layer 36d of the interconnection scheme 420 of the semiconductor IC chip 100h of the twenty-first type of FPMCP 324. Further, the power-management integrated-circuit (PMIC) chip 416 of the twentieth type of FPMCP 323 as seen in FIG. 28 may be replaced with another power-management integrated-circuit (PMIC) chip 417 for the twenty-first type of FPMCP 324 as seen in FIG. 29. For the twenty-first type of FPMCP 324, its power-management integrated-circuit (PMIC) chip 417 may have the same specification as that of the first type of semiconductor IC chip 100 illustrated in FIG. 3A. For an element of its power-management integrated-circuit (PMIC) chip 417 shown in FIG. 22, which is indicated by the same reference number as that for an element of the first type of semiconductor IC chip 100 shown in FIG. 3A, the specification of the element of its power-management integrated-circuit (PMIC) chip 417 shown in FIG. 29 may be referred to that of the element of the first type of semiconductor IC chip 100 as illustrated in FIG. 3A.

Referring to FIG. 29, for the twenty-first type of FPMCP 324, its power-management integrated-circuit (PMIC) chip 417 may have the first, second, third or fourth type of micro-bumps, micro-pillars or micro-pads 34 each bonded to one of the first, second, third or fourth type of metal bumps, pillars or pads of its semiconductor IC chip 100h into a bonded metal bump or contact 563 between its power-management integrated-circuit (PMIC) chip 417 and its semiconductor IC chip 100h. The bonding for its bonded metal bump or contact 563 as seen in FIG. 29 may be referred to that as illustrated in FIGS. 13B, 13C and 13D, wherein the first, second, third or fourth type of micro-bumps, micro-pillars or micro-pads 34 of its power-management integrated-circuit (PMIC) chip 417 may be analogous respectively to the first, second, third or fourth type of micro-bumps, micro-pillars or micro-pads 34 of the NVM IC chip 250 or auxiliary IC chip 411 as illustrated in FIGS. 13B, 13C and 13D to be turned upside down, and the first, second, third or fourth type of metal bumps, pillars or pads of its semiconductor IC chip 100h may be analogous respectively to the first, second, third or fourth type of micro-bumps, micro-pillars or micro-pads 34 of the FPGA IC chip 200 as illustrated in FIGS. 13B, 13C and 13D to be turned upside down.

Referring to FIG. 29, the twenty-first type of FPMCP 324 may include an underfill 564, e.g., polymer layer, between its power-management integrated-circuit (PMIC) chip 417 and semiconductor IC chip 100h, covering a sidewall of each of its bonded metal bumps or contacts 563. The twenty-first type of FPMCP 324 may include multiple metal posts 582, i.e., through polymer metal-via (TPV), on the bottom surface of the fourth interconnection metal layer 36d of the interconnection scheme 420 of its semiconductor IC chip 100h and vertically in its polymer layer 92, wherein each of its metal posts 582 may have a copper layer having a thickness between 50 and 300 micrometers and a width or diameter between 20 and 200 micrometers. A bottom surface of each of its metal posts 582, i.e., bottom surface of the copper layer thereof, may be coplanar with a bottom surface of its polymer layer 92 and a backside of the semiconductor substrate 2 of its power-management integrated-circuit (PMIC) chip 417. The twenty-first type of FPMCP 324 may include multiple tin-containing solder bumps 583, such as a tin-silver alloy, each on the bottom surface of one of its metal posts 582, wherein each of its tin-containing solder bumps 583 may be bonded to a power plate 476 of its heat sink or spreader 475 for delivering a first power supply voltage or current at a voltage of Vdd or to a ground plate 477 of its heat sink or spreader 475 for delivering a ground supply voltage or current at a voltage of Vss. The twenty-first type of FPMCP 324 may include an adhesive material 584, e.g., heat-conductive paste, for adhering the backside of the semiconductor substrate 2 of its power-management integrated-circuit (PMIC) chip 417 to the ground plate 477 of its heat sink or spreader 475. The twenty-first type of FPMCP 324 may further include an underfill 586, i.e., polymer layer, between its heat sink or spreader 475 and polymer layer 92, covering a sidewall of each of its tin-containing solder bumps 583 and a sidewall of its adhesive material 584.

Referring to FIG. 29, for the twenty-first type of FPMCP 324, its power-management integrated-circuit (PMIC) chip 417 may include power management circuits for direct-current-to-direct-current (DC-to-DC) voltage conversion, voltage regulating, battery charging, power source selection, voltage scaling, and/or power sequencing. The power management circuits of its power-management integrated-circuit (PMIC) chip 417 may regulate the first power supply voltage or current at the voltage of Vdd from circuits external of the twenty-first type of FPMCP 324 via its power distribution network or scheme 541 as a second power supply voltage or current at a voltage of Vdd′. The first power supply voltage or current at the voltage of Vdd may be delivered to one of the power-voltage planes, buses or interconnection 182 of its semiconductor IC chip 100h via its power distribution network or scheme 541. Further, the first power supply voltage or current at the voltage of Vdd may be delivered from said one of the power-voltage planes, buses or interconnection 182 of its semiconductor IC chip 100h to the power management circuits of its power-management integrated-circuit (PMIC) chip 417 via its power distribution network or scheme 541. Its power distribution network or scheme 541 may be composed of the power plate 476 of its heat sink or spreader 475, one or more of its tin-containing solder bumps 583, one or more of its metal posts 582, the interconnection metal layer 36d of the interconnection scheme 420 of its semiconductor IC chip 100h, one or more of its bonded metal bumps or contacts 563 and the interconnection metal layers 6 and/or 27 of the first and/or second interconnection schemes for a chip (FISC and/or SISC) 20 and/or 29 of its power-management integrated-circuit (PMIC) chip 417. The second power supply voltage or current at the voltage of Vdd′ may be delivered to one of the power-voltage planes, buses or interconnection 182 of its semiconductor IC chip 100h via its power distribution network or scheme 542. Further, the second power supply voltage or current at the voltage of Vdd′ may be delivered from said one of the power-voltage planes, buses or interconnection 182 of its semiconductor IC chip 100h to one or more of the semiconductor devices 4, e.g., transistors, of its semiconductor IC chip 100h via its power distribution network or scheme 542. Its power distribution network or scheme 542 may be composed of the interconnection metal layers 6 and/or 27 of the first and/or second interconnection schemes for a chip (FISC and/or SISC) 20 and/or 29 of its semiconductor IC chip 100h, one or more of the through silicon vias (TSVs) 157 of its semiconductor IC chip 100h, the interconnection metal layers 36a-36d of the interconnection scheme 420 of its semiconductor IC chip 100h, one or more of its tin-containing solder bumps 583 and the interconnection metal layers 6 and/or 27 of the first and/or second interconnection schemes for a chip (FISC and/or SISC) 20 and/or 29 of its power-management integrated-circuit (PMIC) chip 417.

Alternatively, referring to FIG. 29, for the twenty-first type of FPMCP 324, the first power supply voltage or current at the voltage of Vdd may be delivered to one or more of the semiconductor devices 4, e.g., transistors, of its semiconductor IC chip 100h via its power distribution network or scheme 553 not coupling to any power management circuit of its power-management integrated-circuit (PMIC) chip 417. The first power supply voltage or current at the voltage of Vdd may be delivered to one of the power-voltage planes, buses or interconnection 182 of its semiconductor IC chip 100h via its power distribution network or scheme 553. Further, the first power supply voltage or current at the voltage of Vdd may be delivered from said one of the power-voltage planes, buses or interconnection 182 of its semiconductor IC chip 100h to said one or more of the semiconductor devices 4, e.g., transistors, of its semiconductor IC chip 100h via its power distribution network or scheme 553. Its power distribution network or scheme 553 may be composed of the power plate 476 of its heat sink or spreader 475, one or more of its tin-containing solder bumps 583, one or more of its metal posts 582, the interconnection metal layers 36a-36d of the interconnection scheme 420 of its semiconductor IC chip 100h, one or more of the through silicon vias (TSVs) 157 of its semiconductor IC chip 100h and the interconnection metal layers 6 and/or 27 of the first and/or second interconnection schemes for a chip (FISC and/or SISC) 20 and/or 29 of its semiconductor IC chip 100h.

Referring to FIG. 29, for the twenty-first type of FPMCP 324, the power management circuits of its power-management integrated-circuit (PMIC) chip 417 may couple to the ground-voltage planes, buses or interconnection 183 of its semiconductor IC chip 100h via its ground distribution network or scheme 544 to deliver the ground supply voltage or current at the voltage of Vss to the ground-voltage planes, buses or interconnection 183 of its semiconductor IC chip 100h. The ground-voltage planes, buses or interconnection 183 of its semiconductor IC chip 100h may couple to circuits external of the twenty-first type of FPMCP 324 via its ground distribution network or scheme 544 and to one or more of the semiconductor devices 4, e.g., transistors, of its semiconductor IC chip 100h via its ground distribution network or scheme 544. Its ground distribution network or scheme 544 may be composed of the ground plate 477 of its heat sink or spreader 475, one or more of its tin-containing solder bumps 583, one or more of its metal posts 582, the interconnection metal layers 36a-36d of the interconnection scheme 420 of its semiconductor IC chip 100h, one or more of the through silicon vias (TSVs) 157 of its semiconductor IC chip 100h and the interconnection metal layers 6 and/or 27 of the first and/or second interconnection schemes for a chip (FISC and/or SISC) 20 and/or 29 of its semiconductor IC chip 100h.

Referring to FIG. 29, for the twenty-first type of FPMCP 324, the power management circuits of its power-management integrated-circuit (PMIC) chip 417 may couple to circuits external of the sixteenth type of chip package 317 via its signal distribution network or scheme 545 for transmission of signals S_{PMIC}. Its signal distribution network or scheme 545 may be composed of one or more of the first, second, third or fourth type of micro-bumps, micro-pillars or micro-pads 34 of its semiconductor IC chip 100h, the interconnection metal layers 6 and/or 27 of the first and/or second interconnection schemes for a chip (FISC and/or SISC) 20 and/or 29 of its semiconductor IC chip 100h, one or more of the through silicon vias (TSVs) 157 of its semiconductor IC chip 100h, the interconnection metal layers 36a-36d of the interconnection scheme 420 of its semiconductor IC chip 100h, one or more of its bonded metal bumps or contacts 563 and the interconnection metal layers 6 and/or 27 of the first and/or second interconnection schemes for a chip (FISC and/or SISC) 20 and/or 29 of its power-management integrated-circuit (PMIC) chip 417.

Referring to FIG. 29, for the twenty-first type of FPMCP 324, the semiconductor devices 4, e.g., transistors, of its semiconductor IC chip 100h may couple to circuits external of the twenty-first type of FPMCP 324 via its signal distribution network or scheme 546 for transmission of signals S_{chip}. Its signal distribution network or scheme 536 may be composed of one or more of the first, second, third or fourth type of micro-bumps, micro-pillars or micro-pads 34 of its semiconductor IC chip 100h and the interconnection metal layers 6 and/or 27 of the first and/or second interconnection schemes for a chip (FISC and/or SISC) 20 and/or 29 of its semiconductor IC chip 100h.

Referring to FIG. 29, for the twenty-first type of FPMCP 324, each of its semiconductor IC chip 100h and power-management integrated-circuit (PMIC) chip 417 may include the first, second or third type of field programmable logic cell or element (LCE) 2014 as illustrated in FIGS. 1A-1C, the first or second type of field programmable switch cell 379 as illustrated in FIGS. 2A and 2B and the programmable switch matrix 710 as illustrated in FIG. 2C. Further, its semiconductor IC chip 100h may be (i) a computing and processing logic IC chip, such as FPGA IC chip, central-processing-unit (CPU) IC chip, digital signal processor (DSP) IC chip, graphic processing unit (GPU) IC chip, data processing unit (DPU) IC chip, tensor flow processing unit (TPU) IC chip, micro-control unit (MCU) IC chip, artificial intelligent unit (AIU) IC chip, machine learning unit (MLU) IC chip, application-specific integrated-circuit (ASIC) chip or system-on-chip (SoC) IC chip; (ii) a volatile memory IC chip, such as static random-access memory (SRAM) IC chip or dynamic random-access memory (DRAM) IC chip; (iii) a non-volatile memory IC chip, such as NAND flash memory IC chip, NOR flash memory IC chip, magnetoresistive random access memory (MRAM) IC chip, resistive random access memory (RRAM) IC chip or ferroelectric random access memory (FRAM) IC chip; or (iv) a mixed-mode or analog IC chip. Its FPGA IC chip 100h may be the dedicated field programmable integrated-circuit (DFPIC) chip as illustrated in FIG. 4D or embedded field programmable integrated-circuit (eFPIC) chip as illustrated in FIG. 4E.

### Twenty-Second Type of FPMCP

FIG. 13F is a schematically cross-sectional view showing a twenty-second type of FPMCP in accordance with an embodiment of the present application. A twenty-second type of FPMCP 325 as seen in FIG. 13F may have a similar structure to the fifth type of FPMCP 308 as seen in FIG. 13A. For an element indicated by the same reference number shown in FIGS. 13A and 13E and 13F, the specification of the element as seen in FIG. 13F may be referred to that of the element as illustrated in FIGS. 13A and 13E. The difference therebetween is mentioned as below: the NVM IC chip 250 as seen in FIG. 13A may be replaced with a high bandwidth memory (HBM) IC chip 251 having the same specification as one illustrated in FIG. 5A-1 for the twenty-second type of FPMCP 325, and the auxiliary IC chip 411 as seen in FIG. 13A may be replaced with an application-specific integrated-circuit (ASIC) chip or system-on-chip (SoC) chip 269c having the same specification as one illustrated in FIG. 5A-1 for the twenty-second type of FPMCP 325. For the twenty-second type of FPMCP 325, each of its high bandwidth memory (HBM) IC chip 251 and ASIC or SoC chip 269c may have the same specification as the fifth type of semiconductor IC chip 100 illustrated in FIG. 3E to be turned upside down to be bonded to its FPGA IC chip 200 by the hybrid bonding as illustrated in FIG. 13A. The twenty-second type of FPMCP 325 may have the inter-chip interconnection between the first and second semiconductor IC chips 100a and 100b via the FPGA IC chip 200 as illustrated in FIG. 5B. For the twenty-second type of FPMCP 325, its FPGA IC chip 200 may have the same circuits as one illustrated in FIG. 5B, its logic computing IC chip 269 may be the first semiconductor IC chip 100a as illustrated in FIG. 5B, and one of its HBM IC chip 251 or ASIC or SoC chip 269c may be the second semiconductor IC chip 100b as illustrated in FIG. 5B. Alternatively, its HBM IC chip 251 may be the first semiconductor IC chip 100a as illustrated in FIG. 5B, and its ASIC or SoC chip 269c may be the second semiconductor IC chip 100b as illustrated in FIG. 5B. Each bonded two of the metal pads 6a of the FPGA IC chip 200 and first semiconductor IC chip 100a for the twenty-second type of FPMCP 325 may be formed for one of the programmable interconnects 361 of the inter-chip interconnects 371 between the FPGA IC chip 200 and first semiconductor IC chip 100a as illustrated in FIG. 5B, and each bonded two of the metal pads 6a of the FPGA IC chip 200 and second semiconductor IC chip 100b for the twenty-second type of FPMCP 325 may be formed for one of the programmable interconnects 361 of the inter-chip interconnects 371 between the FPGA IC chip 200 and second semiconductor IC chip 100b as illustrated in FIG. 5B.

Referring to FIG. 13F, the twenty-second type of FPMCP 325 may perform the operation between the FPGA IC chip 200 and each of the third and fourth semiconductor IC chips 100c and 100d as illustrated in FIG. 5C. For the twenty-second type of FPMCP 325, its FPGA IC chip 200 may have the same circuits as one illustrated in FIG. 5C, its logic computing IC chip 269 may be the third semiconductor IC chip 100c as illustrated in FIG. 5C, and one of its HBM IC chip 251 or ASIC or SoC chip 269c may be the fourth semiconductor IC chip 100d as illustrated in FIG. 5C. Alternatively, its HBM IC chip 251 may be the third semiconductor IC chip 100c as illustrated in FIG. 5C, and its ASIC or SoC chip 269c may be the fourth semiconductor IC chip 100d as illustrated in FIG. 5C. Each bonded two of the metal pads 6a of the FPGA IC chip 200 and third semiconductor IC chip 100c for the twenty-second type of FPMCP 325 may be formed for one of the programmable interconnects 361 of the inter-chip interconnects 371 between the FPGA IC chip 200 and third semiconductor IC chip 100c as illustrated in FIG. 5C, and each bonded two of the metal pads 6a of the FPGA IC chip 200 and fourth semiconductor IC chip 100d for the twenty-second type of FPMCP 325 may be formed for one of the programmable interconnects 361 of the inter-chip interconnects 371 between the FPGA IC chip 200 and fourth semiconductor IC chip 100d as illustrated in FIG. 5C.

### Twenty-Third Type of FPMCP

FIG. 13G is a schematically cross-sectional view showing a twenty-third type of FPMCP in accordance with an embodiment of the present application. A twenty-third type of FPMCP 326 as seen in FIG. 13G may have a similar structure to the fifth type of FPMCP 308 as seen in FIG. 13B. For an element indicated by the same reference number shown in FIGS. 13B-13E and 13G, the specification of the element as seen in FIG. 13G may be referred to that of the element as illustrated in FIGS. 13B-13E. The difference therebetween is mentioned as below: the NVM IC chip 250 as seen in FIG. 13B may be replaced with a high bandwidth memory (HBM) IC chip 251 having the same specification as one illustrated in FIG. 5A-1 for the twenty-third type of FPMCP 326 and the auxiliary IC chip 411 as seen in FIG. 13B may be replaced with an application-specific integrated-circuit (ASIC) chip or system-on-chip (SoC) chip 269c having the same specification as one illustrated in FIG. 5A-1 for the twenty-third type of FPMCP 326. For the twenty-third type of FPMCP 326, each of its high bandwidth memory (HBM) IC chip 251 and ASIC or SoC chip 269c may have the same specification as the first type of semiconductor IC chip 100 illustrated in FIG. 3A to be turned upside down to be bonded to its FPGA IC chip 200 by the wafer bumping as illustrated in FIGS. 13B-13D. The twenty-third type of FPMCP 326 may have the inter-chip interconnection between the first and second semiconductor IC chips 100a and 100b via the FPGA IC chip 200 as illustrated in FIG. 5B. For the twenty-third type of FPMCP 326, its FPGA IC chip 200 may have the same circuits as one illustrated in FIG. 5B, its logic computing IC chip 269 may be the first semiconductor IC chip 100a as illustrated in FIG. 5B, and one of its HBM IC chip 251 or ASIC or SoC chip 269c may be the second semiconductor IC chip 100b as illustrated in FIG. 5B. Alternatively, its HBM IC chip 251 may be the first semiconductor IC chip 100a as illustrated in FIG. 5B, and its ASIC or SoC chip 269c may be the second semiconductor IC chip 100b as illustrated in FIG. 5B. Each of the bonded metal bumps or contacts 563 between the FPGA IC chip 200 and first semiconductor IC chip 100a for the twenty-third type of FPMCP 326 may be formed for one of the programmable interconnects 361 of the inter-chip interconnects 371 between the FPGA IC chip 200 and first semiconductor IC chip 100a as illustrated in FIG. 5B, and each of the bonded metal bumps or contacts 563 between the FPGA IC chip 200 and second semiconductor IC chip 100b for the twenty-third type of FPMCP 326 may be formed for one of the programmable interconnects 361 of the inter-chip interconnects 371 between the FPGA IC chip 200 and second semiconductor IC chip 100b as illustrated in FIG. 5B.

Referring to FIG. 13G, the twenty-third type of FPMCP 326 may perform the operation between the FPGA IC chip 200 and each of the third and fourth semiconductor IC chips 100c and 100d as illustrated in FIG. 5C. For the twenty-third type of FPMCP 326, its FPGA IC chip 200 may have the same circuits as one illustrated in FIG. 5C, its logic computing IC chip 269 may be the third semiconductor IC chip 100c as illustrated in FIG. 5C, and one of its HBM IC chip 251 or ASIC or SoC chip 269c may be the fourth semiconductor IC chip 100d as illustrated in FIG. 5C. Alternatively, its HBM IC chip 251 may be the third semiconductor IC chip 100c as illustrated in FIG. 5C, and its ASIC or SoC chip 269c may be the fourth semiconductor IC chip 100d as illustrated in FIG. 5C. Each of the bonded metal bumps or contacts 563 between the FPGA IC chip 200 and third semiconductor IC chip 100c for the twenty-third type of FPMCP 326 may be formed for one of the programmable interconnects 361 of the inter-chip interconnects 371 between the FPGA IC chip 200 and third semiconductor IC chip 100c as illustrated in FIG. 5C, and each of the bonded metal bumps or contacts 563 between the FPGA IC chip 200 and fourth semiconductor IC chip 100d for the twenty-third type of FPMCP 326 may be formed for one of the programmable interconnects 361 of the inter-chip interconnects 371 between the FPGA IC chip 200 and fourth semiconductor IC chip 100d as illustrated in FIG. 5C.

### Twenty-Fourth Type of FPMCP

FIG. 30 is a schematically top view showing each type of twenty-fourth through twenty-eighth types of FPMCP in accordance with an embodiment of the present application. FIG. 3I is a schematically cross-sectional view showing a twenty-fourth type of FPMCP along a cross-sectional line D-D or E-E in FIG. 30 in accordance with an embodiment of the present application. A twenty-fourth type of FPMCP 327 as seen in FIGS. 30 and 31 may have a similar structure to the fourth structure 304 for each of the first type of FPMCPs 300 for the first and second alternatives as seen in FIGS. 9A and 9B. For an element indicated by the same reference number shown in FIGS. 9A, 9B and 31, the specification of the element as seen in FIG. 3I may be referred to that of the element as illustrated in FIGS. 9A and 9B. The difference therebetween is mentioned as below: the first type of interconnection substrate 177 of the fourth structure 304 for each of the first type of FPMCPs 300 for the first and second alternatives as seen in FIGS. 9A and 9B may be provided with multiple through package vias (TPVs) 158, i.e., metal posts or vias, vertically in and through the polymer layer 92 for the interconnection substrate 177 of the twenty-fourth type of FPMCP 327, instead of the vertical-through-via (VTV) connector 467 of the first type of interconnection substrate 177 of the fourth structure 304 for each of the first type of FPMCPs 300 for the first and second alternatives. The first type of interconnection substrate 177 of the fourth structure 304 for each of the first type of FPMCPs 300 for the first and second alternatives as seen in FIGS. 9A and 9B may be provided with multiple DFPIC or eFPIC chips 400 as illustrated in FIG. 4D or 4E each used as an interconnection bridge having the same specification as the fourth type of semiconductor IC chip 100 illustrated in FIG. 3D. For the twenty-fourth type of FPMCP 327, the top surface of the polymer layer 257 of each of the DFPIC or eFPIC chips 400 of its interconnection substrate 177 may be substantially coplanar with the top surface of each of the first type of micro-bumps, micro-pillars or micro-pads 34 of each of the DFPIC or eFPIC chips 400 of its interconnection substrate 177, the top surface of the polymer layer 92 of its interconnection substrate 177 and a top surface of each of the through package vias (TPVs) 158 of its interconnection substrate 177. The semiconductor substrate 2 of each of DFPIC or eFPIC chips 400 of its interconnection substrate 177 may have a portion, at a backside of the semiconductor substrate 2 of said each of DFPIC or eFPIC chips 400, removed by a chemical-mechanical-polishing (CMP) or mechanical grinding process such that each of the through silicon vias (TSVs) 157, that is, the electroplated copper layer 156 thereof, of each of the DFPIC or eFPIC chips 400 of its interconnection substrate 177 may have a bottom surface substantially coplanar with a bottom surface of the semiconductor substrate 2 of said each of DFPIC or eFPIC chips 400, a bottom surface of each of the through package vias (TPVs) 158 of its interconnection substrate 177 and a bottom surface of the polymer layer 92 of its interconnection substrate 177, not shown in FIG. 3I for this case. For an alternative case as seen in FIG. 3I, its interconnection substrates 177 may further include the insulating dielectric layer 185, such as silicon-oxide layer or silicon-nitride layer, illustrated in FIG. 4C formed on a bottom surface of the semiconductor substrate 2 of each of the DFPIC or eFPIC chips 400 of its interconnection substrate 177, wherein the insulating dielectric layer 185 of its interconnection substrate 177 may have a bottom surface coplanar with the bottom surface of each of the through silicon vias 157 of each of the DFPIC or eFPIC chips 400 of its interconnection substrate 177 and the bottom surface of the polymer layer 92 of its interconnection substrate 177. Each of the through package vias (TPVs) 158 of its interconnection substrate 177 may be made of a copper layer having a height or thickness between 20 μm and 300 μm, 30 m and 200 μm, 50 μm and 150 μm, 50 μm and 120 μm, 20 μm and 100 μm, 10 μm and 100 μm, 20 μm and 60 μm, 20 μm and 40 μm, or 20 μm and 30 μm, or greater than or equal to 100 μm, 50 μm, 30 μm or 20 μm. The interconnection scheme 79 of its interconnection substrate 177 may be provided with one or more interconnection metal layers 27 coupling to each of the through silicon vias (TSV) 157 of each of the DFPIC or eFPIC chips 400 of its interconnection substrate 177 and each of the through package vias (TPVs) 158 of its interconnection substrate 177 and multiple polymer layers 42 each between neighboring two of the interconnection metal layers 27 of the interconnection scheme 79 of its interconnection substrate 177, under the bottommost one of the interconnection metal layers 27 of the interconnection scheme 79 of its interconnection substrate 177 or over the topmost one of the interconnection metal layers 27 of the interconnection scheme 79 of its interconnection substrate 177, wherein an upper one of the interconnection metal layers 27 of the interconnection scheme 79 of its interconnection substrate 177 may couple to a lower one of the interconnection metal layers 27 of the interconnection scheme 79 of its interconnection substrate 177 through an opening in one of the polymer layers 42 of the interconnection scheme 79 of its interconnection substrate 177 between the upper and lower ones of the interconnection metal layers 27 of the interconnection scheme 79 of its interconnection substrate 177. The topmost one of the polymer layers 42 of the interconnection scheme 79 of its interconnection substrate 177 may have a top surface in contact with the bottom surface of the polymer layer 92 of its interconnection substrate 177, the bottom surface of the semiconductor substrate 2 of each of the DFPIC or eFPIC chips 400 of its interconnection substrate 177 and the bottom surface of each of the through package vias (TPVs) 158 of its interconnection substrate 177, not shown in FIG. 3I for this case. For the alternative case as seen in FIG. 3I, the topmost one of the polymer layers 42 of the interconnection scheme 79 of its interconnection substrate 177 may have a top surface in contact with the bottom surface of the polymer layer 92 of its interconnection substrate 177, the bottom surface of the insulating dielectric layer 185 of its interconnection substrate 177 and the bottom surface of each of the through package vias (TPVs) 158 of its interconnection substrate 177. Each opening in the topmost one of the polymer layers 42 of the interconnection scheme 79 of its interconnection substrate 177 may be vertically under one of the through silicon vias (TSVs) 157 of one of the DFPIC or eFPIC chips 400 of its interconnection substrate 177 or one of the through package vias (TPVs) 158 of its interconnection substrate 177 and thus the topmost one of the interconnection metal layers 27 of the interconnection scheme 79 of its interconnection substrate 177 may extend through said each opening to couple to said one of the through silicon vias (TSVs) 157 or said one of the through package vias (TPVs) 158. Each of the interconnection metal layers 27 of the interconnection scheme 79 of its interconnection substrate 177 may extend horizontally across an edge of each of the DFPIC or eFPIC chips 400 of its interconnection substrate 177. The bottommost one of the interconnection metal layers 27 of the interconnection scheme 79 of its interconnection substrate 177 may have multiple metal pads or input/output (I/O) pads at tops of multiple respective openings in the bottommost one of the polymer layers 42 of the interconnection scheme 79 of its interconnection substrate 177. The specification and process for the interconnection metal layers 27 and polymer layers 42 of the interconnection scheme 79 of its interconnection substrate 177 may be referred to those for the second interconnection scheme for a chip (SISC) 29 as illustrated in FIG. 3A to be turned upside down.

Referring to FIGS. 30 and 31, for the twenty-fourth type of FPMCP 327, each of its semiconductor IC chips including the GPU IC chip 269a, CPU IC chip 269b, ASIC or SoC chip 269c, FPGA IC chip 200 and HBM IC chips 251 as illustrated in FIG. 5A-1 may have the same specification as the first type of semiconductor IC chip 100 illustrated in FIG. 3A to be turned upside down, wherein its HBM IC chips 251 may be arranged at its left and right sides and its GPU IC chip 269a, CPU IC chip 269b, ASIC or SoC chip 269c and FPGA IC chip 200 may be arranged in an array in its central portion between its HBM IC chips 251 as seen in FIG. 30. Each of its semiconductor IC chips 200, 269a, 269b, 269c and 251 may have the first, second, third or fourth type of micro-bumps, micro-pillars or micro-pads 34 each bonded to (1) the copper layer 32 of one of the first type of micro-bumps, micro-pillars or micro-pads 34 of one of the DFPIC or eFPIC chips 400 of its interconnection substrate 177 or (2) the copper layer of one of the through package vias (TPVs) 158 of its interconnection substrate 177. Accordingly, neighboring two of its semiconductor IC chips 200, 269a, 269b, 269c and 251 may couple to each other through, in sequence, (1) one of the first, second, third or fourth type of micro-bumps, micro-pillars or micro-pads 34 of one of said neighboring two of its semiconductor IC chips 200, 269a, 269b, 269c and 251, (2) one of the first type of micro-bumps, micro-pillars or micro-pads 34 of one of the DFPIC or eFPIC chips 400 of its interconnection substrate 177 vertically under said neighboring two of its semiconductor IC chips 200, 269a, 269b, 269c and 251, (3) one of the metal lines or traces 693 of said one of the DFPIC or eFPIC chips 400 of its interconnection substrate 177, (4) another of the first type of micro-bumps, micro-pillars or micro-pads 34 of said one of the DFPIC or eFPIC chips 400 of its interconnection substrate 177 and (5) one of the first, second, third or fourth type of micro-bumps, micro-pillars or micro-pads 34 of the other of said neighboring two of its semiconductor IC chips 200, 2269a, 269b, 269c and 251. Each of its semiconductor IC chips 200, 269a, 269b, 269c and 251 may couple to one of its metal bumps, pillars or pads 570 for external connection (1) through, in sequence, one of the through package vias (TPVs) 158 of its interconnection substrate 177 vertically under said each of its semiconductor IC chips 200, 269a, 269b, 269c and 251 and each of the interconnection metal layers 27 of the interconnection scheme 79 of its interconnection substrate 177 or (2) through, in sequence, one of the through silicon vias (TSVs) 157 of one of the DFPIC or eFPIC chips 400 of its interconnection substrate 177 vertically under said each of its semiconductor IC chips 200, 269a, 269b, 269c and 251 and each of the interconnection metal layers 27 of the interconnection scheme 79 of its interconnection substrate 177. Each of the DFPIC or eFPIC chips 400 of its interconnection substrate 177 may couple to one of its metal bumps, pillars or pads 570 for external connection through each of the interconnection metal layers 27 of the interconnection scheme 79 of its interconnection substrate 177.

Alternatively, referring to FIGS. 30 and 31, for the twenty-fourth type of FPMCP 327, each of the DFPIC or eFPIC chips 400 of its interconnection substrate 177 may be vertically under neighboring two of its semiconductor IC chips 200, 269a, 269b, 269c and 251, wherein said each of the DFPIC or eFPIC chips 400 of its interconnection substrate 177 may couple to a first device of said neighboring two of its semiconductor IC chips 200, 269a, 269b, 269c and 251, through, in sequence, a first group of the first type of micro-bumps, micro-pillars or micro-pads 34 of said each of the DFPIC or eFPIC chips 400 of its interconnection substrate 177 under the first device and the first, second, third or fourth type of micro-bumps, micro-pillars or micro-pads 34 of the first device and couple to a second device of said neighboring two of its semiconductor IC chips 200, 269a, 269b, 269c and 251 through, in sequence, a second group of the first type of micro-bumps, micro-pillars or micro-pads 34 of said each of the DFPIC or eFPIC chips 400 of its interconnection substrate 177 under the second device and the first, second, third or fourth type of micro-bumps, micro-pillars or micro-pads 34 of the second device, wherein with regard to a left front one of the DFPIC or eFPIC chips 400 of its interconnection substrate 177, the first device may be the left one of its HBM IC chips 251 and the second device may be its CPU IC chip 269b, or in another case the first device may be its CPU IC chip 269b and the second device may be the left one of its HBM IC chips 251; with regard to a left rear one of the DFPIC or eFPIC chips 400 of its interconnection substrate 177, the first device may be the left one of its HBM IC chips 251 and the second device may be its GPU IC chip 269a, or in another case the first device may be its GPU IC chip 269a and the second device may be the left one of its HBM IC chips 251; with regard to a right front one of the DFPIC or eFPIC chips 400 of its interconnection substrate 177, the first device may be the right one of its HBM IC chips 251 and the second device may be its ASIC or SoC chip 269c, or in another case the first device may be its ASIC or SoC chip 269c and the second device may be the right one of its HBM IC chips 251; with regard to a right rear one of the DFPIC or eFPIC chips 400 of its interconnection substrate 177, the first device may be the right one of its HBM IC chips 251 and the second device may be its FPGA IC chip 200, or in another case the first device may be its FPGA IC chip 200 and the second device may be the right one of its HBM IC chips 251; with regard to a center front one of the DFPIC or eFPIC chips 400 of its interconnection substrate 177, the first device may be its CPU IC chip 269b and the second device may be its ASIC or SoC chip 269c, or in another case the first device may be its ASIC or SoC chip 269c and the second device may be its CPU IC chip 269b; with regard to a center rear one of the DFPIC or eFPIC chips 400 of its interconnection substrate 177, the first device may be its GPU IC chip 269a and the second device may be its FPGA IC chip 200, or in another case the first device may be its FPGA IC chip 200 and the second device may be its GPU IC chip 269a; with regard to a center left one of the DFPIC or eFPIC chips 400 of its interconnection substrate 177, the first device may be its CPU IC chip 269b and the second device may be its GPU IC chip 269, or in another case the first device may be its GPU IC chip 269 and the second device may be its CPU IC chip 269b; with regard to a center right one of the DFPIC or eFPIC chips 400 of its interconnection substrate 177, the first device may be its ASIC or SoC chip 269c and the second device may be its FPGA IC chip 200, or in another case the first device may be its FPGA IC chip 200 and the second device may be its ASIC or SoC chip 269c. Said each of the DFPIC or eFPIC chips 400 may include (1) the first type of field programmable logic cell or element (LCE) 2014 or 2014-2 as illustrated in FIGS. 1A, 4D and 4E, the data inputs A0 and A1 of which may couple to the first device through, in sequence, respective two of the small input/output (SIO) circuits 203, or metal pads or input/output (I/O) pads, of said each of the DFPIC or eFPIC chips 400 of its interconnection substrate 177, respective two of the first group of the first type of micro-bumps, micro-pillars or micro-pads 34 of said each of the DFPIC or eFPIC chips 400 of its interconnection substrate 177 and respective two of the first, second, third or fourth type of micro-bumps, micro-pillars or micro-pads 34 of the first device, and the data output Dout of which may couple to the second device through, in sequence, another of the small input/output (SIO) circuits 203, or metal pads or input/output (I/O) pads, of said each of the DFPIC or eFPIC chips 400 of its interconnection substrate 177, one of the second group of the first type of micro-bumps, micro-pillars or micro-pads 34 of said each of the DFPIC or eFPIC chips 400 of its interconnection substrate 177 and one of the first, second, third or fourth type of micro-bumps, micro-pillars or micro-pads 34 of the second device, (2) the second or third type of field programmable logic cell or element (LCE) 2014 or 2014-2 as illustrated in FIGS. 1B, 1C, 4D and 4E, the data inputs A0-A3 of which may couple to the first device through, in sequence, respective four of the small input/output (SIO) circuits 203, or metal pads or input/output (I/O) pads, of said each of the DFPIC or eFPIC chips 400 of its interconnection substrate 177, respective four of the first group of the first type of micro-bumps, micro-pillars or micro-pads 34 of said each of the DFPIC or eFPIC chips 400 of its interconnection substrate 177 and respective four of the first, second, third or fourth type of micro-bumps, micro-pillars or micro-pads 34 of the first device, and the data output Dout of which may couple to the second device through, in sequence, another of the small input/output (SIO) circuits 203, or metal pads or input/output (I/O) pads, of said each of the DFPIC or eFPIC chips 400 of its interconnection substrate 177, one of the second group of the first type of micro-bumps, micro-pillars or micro-pads 34 of said each of the DFPIC or eFPIC chips 400 of its interconnection substrate 177 and one of the first, second, third or fourth type of micro-bumps, micro-pillars or micro-pads 34 of the second device, (3) the first type of field programmable switch cell 379 or 379-2 as illustrated in FIGS. 2A, 4D and 4E, the node N21 of which may couple to the first device through, in sequence, one of the small input/output (SIO) circuits 203, or metal pads or input/output (I/O) pads, of said each of the DFPIC or eFPIC chips 400 of its interconnection substrate 177, one of the first group of the first type of micro-bumps, micro-pillars or micro-pads 34 of said each of the DFPIC or eFPIC chips 400 of its interconnection substrate 177 and one of the first, second, third or fourth type of micro-bumps, micro-pillars or micro-pads 34 of the first device, and the node N22 of which may couple to the second device through, in sequence, another of the small input/output (SIO) circuits 203, or metal pads or input/output (I/O) pads, of said each of the DFPIC or eFPIC chips 400 of its interconnection substrate 177, one of the second group of the first type of micro-bumps, micro-pillars or micro-pads 34 of said each of the DFPIC or eFPIC chips 400 of its interconnection substrate 177 and one of the first, second, third or fourth type of micro-bumps, micro-pillars or micro-pads 34 of the second device, (4) the second type of field programmable switch cell 379 or 379-2 as illustrated in FIGS. 2B, 4D and 4E, the nodes N23 and N24 of which may couple to the first device through, in sequence, respective two of the small input/output (SIO) circuits 203, or metal pads or input/output (I/O) pads, of said each of the DFPIC or eFPIC chips 400 of its interconnection substrate 177, respective two of the first group of the first type of micro-bumps, micro-pillars or micro-pads 34 of said each of the DFPIC or eFPIC chips 400 of its interconnection substrate 177 and respective two of the first, second, third or fourth type of micro-bumps, micro-pillars or micro-pads 34 of the first device, and the nodes N25 and N26 of which may couple to the second device through, in sequence, another respective two of the small input/output (SIO) circuits 203, or metal pads or input/output (I/O) pads, of said each of the DFPIC or eFPIC chips 400 of its interconnection substrate 177, respective two of the second group of the first type of micro-bumps, micro-pillars or micro-pads 34 of said each of the DFPIC or eFPIC chips 400 of its interconnection substrate 177 and respective two of the first, second, third or fourth type of micro-bumps, micro-pillars or micro-pads 34 of the second device, to control coupling from the node N23 to one or more of the nodes N24-N26 or to control coupling from the node N26 to one or more of the nodes N23-N25, (5) the field programmable switch matrix 710 or 710-3 as illustrated in FIGS. 2C, 4D and 4E, each of the nodes P₁-P_{N} of which may couple to the first device through, in sequence, one of the first metal lines 281 of said each of the DFPIC or eFPIC chips 400 of its interconnection substrate 177, one of the small input/output (SIO) circuits 203, or metal pads or input/output (I/O) pads, of said each of the DFPIC or eFPIC chips 400 of its interconnection substrate 177, one of the first group of the first type of micro-bumps, micro-pillars or micro-pads 34 of said each of the DFPIC or eFPIC chips 400 of its interconnection substrate 177 and one of the first, second, third or fourth type of micro-bumps, micro-pillars or micro-pads 34 of the first device, each of the nodes Q₁-Q_{M} of which may couple to the second device through, in sequence, one of the second metal lines 282 of said each of the DFPIC or eFPIC chips 400 of its interconnection substrate 177, another of the small input/output (SIO) circuits 203, or metal pads or input/output (I/O) pads, of said each of the DFPIC or eFPIC chips 400 of its interconnection substrate 177, one of the second group of the first type of micro-bumps, micro-pillars or micro-pads 34 of said each of the DFPIC or eFPIC chips 400 of its interconnection substrate 177 and one of the first, second, third or fourth type of micro-bumps, micro-pillars or micro-pads 34 of the second device, and each of the pass/no-pass switches 778 of which may control coupling between the first and second devices, i.e., between one of the first group of the first type of micro-bumps, micro-pillars or micro-pads 34 of said each of the DFPIC or eFPIC chips 400 of its interconnection substrate 177 and one of the second group of the first type of micro-bumps, micro-pillars or micro-pads 34 of said each of the DFPIC or eFPIC chips 400 of its interconnection substrate 177, and/or (6) the field programmable switch matrix 710-2 as illustrated in FIGS. 2C and 4E, each of some of the nodes P₁-P_{N} of which may couple to the first device through, in sequence, one of the first metal lines 281 of said each of the DFPIC or eFPIC chips 400 of its interconnection substrate 177, one of the small input/output (SIO) circuits 203, or metal pads or input/output (I/O) pads, of said each of the DFPIC or eFPIC chips 400 of its interconnection substrate 177, one of the first group of the first type of micro-bumps, micro-pillars or micro-pads 34 of said each of the DFPIC or eFPIC chips 400 of its interconnection substrate 177 and one of the first, second, third or fourth type of micro-bumps, micro-pillars or micro-pads 34 of the first device, each of the other some of the nodes P₁-P_{N} of which may couple to the second device through, in sequence, another of the first metal lines 281 of said each of the DFPIC or eFPIC chips 400 of its interconnection substrate 177, another of the small input/output (SIO) circuits 203, or metal pads or input/output (I/O) pads, of said each of the DFPIC or eFPIC chips 400 of its interconnection substrate 177, one of the second group of the first type of micro-bumps, micro-pillars or micro-pads 34 of said each of the DFPIC or eFPIC chips 400 of its interconnection substrate 177 and one of the first, second, third or fourth type of micro-bumps, micro-pillars or micro-pads 34 of the second device, and each of the pass/no-pass switches 778 of which may control coupling between one of the first and second devices and one of the internal circuits of the fourth one of the ASIC cores 215 of said each of the DFPIC or eFPIC chips 400 of its interconnection substrate 177, i.e., between one of the first and second groups of the first type of micro-bumps, micro-pillars or micro-pads 34 of said each of the DFPIC or eFPIC chips 400 of its interconnection substrate 177 and one of the internal circuits of the fourth one of the ASIC cores 215 of said each of the DFPIC or eFPIC chips 400 of its interconnection substrate 177.

### Twenty-Fifth Type of FPMCP

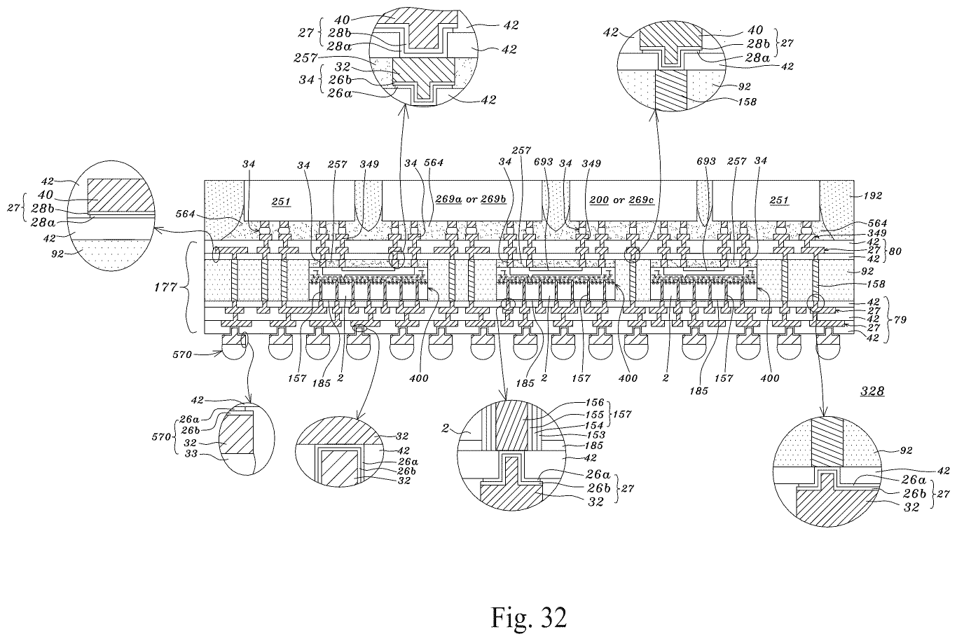

FIG. 32 is a schematically cross-sectional view showing a twenty-fifth type of FPMCP along a cross-sectional line D-D or E-E in FIG. 30 in accordance with an embodiment of the present application. A twenty-fifth type of FPMCP 328 as seen in FIG. 32 may have a similar structure to the twenty-fourth type of FPMCP 327 as seen in FIG. 3I. For an element indicated by the same reference number shown in FIGS. 31 and 32, the specification of the element as seen in FIG. 32 may be referred to that of the element as illustrated in FIG. 3I. The difference therebetween is mentioned as below: the interconnection substrate 177 of the twenty-fourth type of FPMCP 327 as seen in FIG. 3I may further include another interconnection scheme 80 over the DFPIC or eFPIC chips 400, through package vias (TPVs) 158 and polymer layer 92 thereof for the interconnection substrate 177 of the twenty-fifth type of FPMCP 328 as seen in FIG. 32. For the twenty-fifth type of FPMCP 328, each of the first type of micro-bumps, micro-pillars or micro-pads 34 of each of the DFPIC or eFPIC chips 400 of its interconnection substrate 177 and each of the through package vias (TPVs) 158 of its interconnection substrate 177 may couple to its interconnection scheme 80. The interconnection scheme 80 of its interconnection substrate 177 may include (1) multiple interconnection metal layers 27 (only one is shown) coupling to each of the first type of micro-bumps, micro-pillars or micro-pads 34 of each of the DFPIC or eFPIC chips 400 of its interconnection substrate 177 and each of the through package vias (TPVs) 158 of its interconnection substrate 177 and (2) one or more polymer layers 42, i.e., insulating dielectric layers, each between neighboring two of the interconnection metal layers 27 of the interconnection scheme 80 of its interconnection substrate 177, under the bottommost one of the interconnection metal layers 27 of the interconnection scheme 80 of its interconnection substrate 177 or over the topmost one of the interconnection metal layers 27 of the interconnection scheme 80 of its interconnection substrate 177, wherein an upper one of the interconnection metal layers 27 of the interconnection scheme 80 of its interconnection substrate 177 may couple to a lower one of the interconnection metal layers 27 of the interconnection scheme 80 of its interconnection substrate 177 through an opening in one of the polymer layers 42 of the interconnection scheme 80 of its interconnection substrate 177 between the upper and lower ones of the interconnection metal layers 27 of the interconnection scheme 80 of its interconnection substrate 177. The bottommost one of the polymer layers 42 of the interconnection scheme 80 of its interconnection substrate 177 may have a bottom surface in contact with the top surface of the polymer layer 257 of each of the DFPIC or eFPIC chips 400 of its interconnection substrate 177 and the top surface of the polymer layer 92 of its interconnection substrate 177. Each opening in the bottommost one of the polymer layers 42 of the interconnection scheme 80 of its interconnection substrate 177 may be over one of the first type of micro-bumps, micro-pillars or micro-pads 34 of one of the DFPIC or eFPIC chips 400 of its interconnection substrate 177 or one of the through package vias (TPVs) 158 of its interconnection substrate 177, and thus the bottommost one of the interconnection metal layers 27 of the interconnection scheme 80 of its interconnection substrate 177 may couple to said one of the first type of micro-bumps, micro-pillars or micro-pads 34 through said each opening or to said one of the through package vias (TPVs) 158 through said each opening. Each of the interconnection metal layers 27 of the interconnection scheme 80 of its interconnection substrate 177 may extend horizontally across an edge of each of the DFPIC or eFPIC chips 400 of its interconnection substrate 177. The topmost one of the interconnection metal layers 27 of the interconnection scheme 80 of its interconnection substrate 177 may have multiple metal pads at bottoms of multiple respective openings in the topmost one of the polymer layers 42 of the interconnection scheme 80 of its interconnection substrate 177. The specification and process for the interconnection metal layers 27 and polymer layers 42 for the interconnection scheme 80 of its interconnection substrate 177 may be referred to those for the second interconnection scheme for a chip (SISC) 29 as illustrated in FIG. 3A. Each of the polymer layers 42 of the interconnection scheme 80 of its interconnection substrate 177 may be a layer of polyimide, benzocyclobutene (BCB), parylene, epoxy-based material or compound, photo epoxy SU-8, elastomer or silicone, having a thickness between, for example, 0.3 μm and 30 μm, 0.5 μm and 20 μm, 1 μm and 10 μm, or 0.5 um and 5 μm, or thicker than or equal to 0.3 μm, 0.5 μm, 0.7 μm, 1 μm, 1.5 μm, 2 μm, 3 μm or 5 μm. Each of the interconnection metal layers 27 of the interconnection scheme 80 of its interconnection substrate 177 may be provided with multiple metal traces or lines each including (1) a copper layer 40 having one or more lower portions in openings in one of the polymer layers 42 of the interconnection scheme 80 of its interconnection substrate 177 and an upper portion having a thickness between 0.3 μm and 20 m over said one of the polymer layers 42, (2) an adhesion metal layer 28a, such as titanium or titanium nitride having a thickness between 1 nm and 50 nm, at a bottom and sidewall of each of the one or more lower portions of the copper layer 40 of said each of the metal traces or lines and at a bottom of the upper portion of the copper layer 40 of said each of the metal traces or lines, and (3) an electroplating seed layer 28b, such as copper, between the copper layer 40 and adhesion metal layer 28a of said each of the metal traces or lines, wherein the upper portion of the copper layer 40 of said each of the metal traces or lines may have a sidewall not covered by the adhesion metal layer 28a of said each of the metal traces or lines. Each of the metal traces or lines of each of the interconnection metal layers 27 of the interconnection scheme 80 of its interconnection substrate 177 may have a thickness between, for example, 0.3 μm and 30 μm, 0.5 μm and 20 μm, 1 μm and 10 μm, or 0.5 μm and 5 μm, or thicker than or equal to 0.3 μm, 0.5 μm, 0.7 μm, 1 μm, 1.5 μm, 2 μm, 3 μm or 5 μm, and a width between, for example, 0.3 μm and 30 μm, 0.5 μm and 20 μm, 1 μm and 10 μm, or 0.5 μm and 5 μm, or wider than or equal to 0.3 μm, 0.5 μm, 0.7 μm, 1 μm, 1.5 μm, 2 μm, 3 μm or 5 μm. The adhesion metal layer 28a of the bottommost one of the interconnection metal layers 27 of the interconnection scheme 80 of its interconnection substrate 177 may be provided on and in contact with the copper layer 32 of each of the first type of micro-bumps, micro-pillars or micro-pads 34 of each of the DFPIC or eFPIC chips 400 of its interconnection substrate 177 and the copper layer of each of the through package vias (TPVs) 158 of its interconnection substrate 177, between the copper layer 40 of the bottommost one of the interconnection metal layers 27 of the interconnection scheme 80 of its interconnection substrate 177 and the copper layer 32 of each of the first type of micro-bumps, micro-pillars or micro-pads 34 of each of the DFPIC or eFPIC chips 400 of its interconnection substrate 177 and between the copper layer 40 of the bottommost one of the interconnection metal layers 27 of the interconnection scheme 80 of its interconnection substrate 177 and the copper layer of each of the through package vias (TPVs) 158 of its interconnection substrate 177.

Referring to FIGS. 30 and 32, for the twenty-fifth type of FPMCP 328, each of its semiconductor IC chips 200, 269a, 269b, 269c and 251 may have the first, second, third or fourth type of micro-bumps, micro-pillars or micro-pads 34 each bonded to a metal contact 349, such as copper contact or tin-containing contact, preformed on one of the metal pads of the topmost one of the interconnection metal layers 27 of the interconnection scheme 80 of its interconnection substrate 177. Accordingly, neighboring two of its semiconductor IC chips 200, 269a, 269b, 269c and 251 may couple to each other through, in sequence, (1) one of the first, second, third or fourth type of micro-bumps, micro-pillars or micro-pads 34 of one of said neighboring two of its semiconductor IC chips 200, 269a, 269b, 269c and 251, (2) each of the interconnection metal layers 27 of the interconnection scheme 80 of its interconnection substrate 177, (3) one of the first type of micro-bumps, micro-pillars or micro-pads 34 of one of the DFPIC or eFPIC chips 400 of its interconnection substrate 177 vertically under said neighboring two of its semiconductor IC chips 200, 269a, 269b, 269c and 251, (4) one of the metal lines or traces 693 of said one of the DFPIC or eFPIC chips 400 of its interconnection substrate 177, (5) another of the first type of micro-bumps, micro-pillars or micro-pads 34 of said one of the DFPIC or eFPIC chips 400 of its interconnection substrate 177, (6) each of the interconnection metal layers 27 of the interconnection scheme 80 of its interconnection substrate 177 and (7) one of the first, second, third or fourth type of micro-bumps, micro-pillars or micro-pads 34 of the other of said neighboring two of its semiconductor IC chips 200, 269a, 269b, 269c and 251. Each of its semiconductor IC chips 200, 269a, 269b, 269c and 251 may couple to one of its metal bumps, pillars or pads 570 for external connection (1) through, in sequence, each of the interconnection metal layers 27 of the interconnection scheme 80 of its interconnection substrate 177, one of the through package vias (TPVs) 158 of its interconnection substrate 177 vertically under said each of its semiconductor IC chips 200, 269a, 269b, 269c and 251 and each of the interconnection metal layers 27 of the interconnection scheme 79 of its interconnection substrate 177 or (2) through, in sequence, each of the interconnection metal layers 27 of the interconnection scheme 80 of its interconnection substrate 177, one of the through silicon vias (TSVs) 157 of one of the DFPIC or eFPIC chips 400 of its interconnection substrate 177 vertically under said each of its semiconductor IC chips 200, 269a, 269b, 269c and 251 and each of the interconnection metal layers 27 of the interconnection scheme 79 of its interconnection substrate 177. Each of the DFPIC or eFPIC chips 400 of its interconnection substrate 177 may couple to one of its metal bumps, pillars or pads 570 for external connection through each of the interconnection metal layers 27 of the interconnection scheme 79 of its interconnection substrate 177.

Alternatively, referring to FIGS. 30 and 32, for the twenty-fifth type of FPMCP 328, each of the DFPIC or eFPIC chips 400 of its interconnection substrate 177 may be vertically under neighboring two of its semiconductor IC chips 200, 269a, 269b, 269c and 251, wherein said each of the DFPIC or eFPIC chips 400 of its interconnection substrate 177 may couple to a first device of said neighboring two of its semiconductor IC chips 200, 269a, 269b, 269c and 251, through, in sequence, a first group of the first type of micro-bumps, micro-pillars or micro-pads 34 of said each of the DFPIC or eFPIC chips 400 of its interconnection substrate 177 under the first device, each of the interconnection metal layers 27 of the interconnection scheme 80 of its interconnection substrate 177 and the first, second, third or fourth type of micro-bumps, micro-pillars or micro-pads 34 of the first device and couple to a second device of said neighboring two of its semiconductor IC chips 200, 269a, 269b, 269c and 251 through, in sequence, a second group of the first type of micro-bumps, micro-pillars or micro-pads 34 of said each of the DFPIC or eFPIC chips 400 of its interconnection substrate 177 under the second device, each of the interconnection metal layers 27 of the interconnection scheme 80 of its interconnection substrate 177 and the first, second, third or fourth type of micro-bumps, micro-pillars or micro-pads 34 of the second device, wherein with regard to a left front one of the DFPIC or eFPIC chips 400 of its interconnection substrate 177, the first device may be the left one of its HBM IC chips 251 and the second device may be its CPU IC chip 269b, or in another case the first device may be its CPU IC chip 269b and the second device may be the left one of its HBM IC chips 251; with regard to a left rear one of the DFPIC or eFPIC chips 400 of its interconnection substrate 177, the first device may be the left one of its HBM IC chips 251 and the second device may be its GPU IC chip 269a, or in another case the first device may be its GPU IC chip 269a and the second device may be the left one of its HBM IC chips 251; with regard to a right front one of the DFPIC or eFPIC chips 400 of its interconnection substrate 177, the first device may be the right one of its HBM IC chips 251 and the second device may be its ASIC or SoC chip 269c, or in another case the first device may be its ASIC or SoC chip 269c and the second device may be the right one of its HBM IC chips 251; with regard to a right rear one of the DFPIC or eFPIC chips 400 of its interconnection substrate 177, the first device may be the right one of its HBM IC chips 251 and the second device may be its FPGA IC chip 200, or in another case the first device may be its FPGA IC chip 200 and the second device may be the right one of its HBM IC chips 251; with regard to a center front one of the DFPIC or eFPIC chips 400 of its interconnection substrate 177, the first device may be its CPU IC chip 269b and the second device may be its ASIC or SoC chip 269c, or in another case the first device may be its ASIC or SoC chip 269c and the second device may be its CPU IC chip 269b; with regard to a center rear one of the DFPIC or eFPIC chips 400 of its interconnection substrate 177, the first device may be its GPU IC chip 269a and the second device may be its FPGA IC chip 200, or in another case the first device may be its FPGA IC chip 200 and the second device may be its GPU IC chip 269a; with regard to a center left one of the DFPIC or eFPIC chips 400 of its interconnection substrate 177, the first device may be its CPU IC chip 269b and the second device may be its GPU IC chip 269, or in another case the first device may be its GPU IC chip 269 and the second device may be its CPU IC chip 269b; with regard to a center right one of the DFPIC or eFPIC chips 400 of its interconnection substrate 177, the first device may be its ASIC or SoC chip 269c and the second device may be its FPGA IC chip 200, or in another case the first device may be its FPGA IC chip 200 and the second device may be its ASIC or SoC chip 269c. Said each of the DFPIC or eFPIC chips 400 may include (1) the first type of field programmable logic cell or element (LCE) 2014 or 2014-2 as illustrated in FIGS. 1A, 4D and 4E, the data inputs A0 and A1 of which may couple to the first device through, in sequence, respective two of the small input/output (SIO) circuits 203, or metal pads or input/output (I/O) pads, of said each of the DFPIC or eFPIC chips 400 of its interconnection substrate 177, respective two of the first group of the first type of micro-bumps, micro-pillars or micro-pads 34 of said each of the DFPIC or eFPIC chips 400 of its interconnection substrate 177, each of the interconnection metal layers 27 of the interconnection scheme 80 of its interconnection substrate 177 and respective two of the first, second, third or fourth type of micro-bumps, micro-pillars or micro-pads 34 of the first device, and the data output Dout of which may couple to the second device through, in sequence, another of the small input/output (SIO) circuits 203, or metal pads or input/output (I/O) pads, of said each of the DFPIC or eFPIC chips 400 of its interconnection substrate 177, one of the second group of the first type of micro-bumps, micro-pillars or micro-pads 34 of said each of the DFPIC or eFPIC chips 400 of its interconnection substrate 177, each of the interconnection metal layers 27 of the interconnection scheme 80 of its interconnection substrate 177 and one of the first, second, third or fourth type of micro-bumps, micro-pillars or micro-pads 34 of the second device, (2) the second or third type of field programmable logic cell or element (LCE) 2014 or 2014-2 as illustrated in FIGS. 1B, 1C, 4D and 4E, the data inputs A0-A3 of which may couple to the first device through, in sequence, respective four of the small input/output (SIO) circuits 203, or metal pads or input/output (I/O) pads, of said each of the DFPIC or eFPIC chips 400 of its interconnection substrate 177, respective four of the first group of the first type of micro-bumps, micro-pillars or micro-pads 34 of said each of the DFPIC or eFPIC chips 400 of its interconnection substrate 177, each of the interconnection metal layers 27 of the interconnection scheme 80 of its interconnection substrate 177 and respective four of the first, second, third or fourth type of micro-bumps, micro-pillars or micro-pads 34 of the first device, and the data output Dout of which may couple to the second device through, in sequence, another of the small input/output (SIO) circuits 203, or metal pads or input/output (I/O) pads, of said each of the DFPIC or eFPIC chips 400 of its interconnection substrate 177, one of the second group of the first type of micro-bumps, micro-pillars or micro-pads 34 of said each of the DFPIC or eFPIC chips 400 of its interconnection substrate 177, each of the interconnection metal layers 27 of the interconnection scheme 80 of its interconnection substrate 177 and one of the first, second, third or fourth type of micro-bumps, micro-pillars or micro-pads 34 of the second device, (3) the first type of field programmable switch cell 379 or 379-2 as illustrated in FIGS. 2A, 4D and 4E, the node N21 of which may couple to the first device through, in sequence, one of the small input/output (SIO) circuits 203, or metal pads or input/output (I/O) pads, of said each of the DFPIC or eFPIC chips 400 of its interconnection substrate 177, one of the first group of the first type of micro-bumps, micro-pillars or micro-pads 34 of said each of the DFPIC or eFPIC chips 400 of its interconnection substrate 177, each of the interconnection metal layers 27 of the interconnection scheme 80 of its interconnection substrate 177 and one of the first, second, third or fourth type of micro-bumps, micro-pillars or micro-pads 34 of the first device, and the node N22 of which may couple to the second device through, in sequence, another of the small input/output (SIO) circuits 203, or metal pads or input/output (I/O) pads, of said each of the DFPIC or eFPIC chips 400 of its interconnection substrate 177, one of the second group of the first type of micro-bumps, micro-pillars or micro-pads 34 of said each of the DFPIC or eFPIC chips 400 of its interconnection substrate 177, each of the interconnection metal layers 27 of the interconnection scheme 80 of its interconnection substrate 177 and one of the first, second, third or fourth type of micro-bumps, micro-pillars or micro-pads 34 of the second device, (4) the second type of field programmable switch cell 379 or 379-2 as illustrated in FIGS. 2B, 4D and 4E, the nodes N23 and N24 of which may couple to the first device through, in sequence, respective two of the small input/output (SIO) circuits 203, or metal pads or input/output (I/O) pads, of said each of the DFPIC or eFPIC chips 400 of its interconnection substrate 177, respective two of the first group of the first type of micro-bumps, micro-pillars or micro-pads 34 of said each of the DFPIC or eFPIC chips 400 of its interconnection substrate 177, each of the interconnection metal layers 27 of the interconnection scheme 80 of its interconnection substrate 177 and respective two of the first, second, third or fourth type of micro-bumps, micro-pillars or micro-pads 34 of the first device, and the nodes N25 and N26 of which may couple to the second device through, in sequence, another respective two of the small input/output (SIO) circuits 203, or metal pads or input/output (I/O) pads, of said each of the DFPIC or eFPIC chips 400 of its interconnection substrate 177, respective two of the second group of the first type of micro-bumps, micro-pillars or micro-pads 34 of said each of the DFPIC or eFPIC chips 400 of its interconnection substrate 177, each of the interconnection metal layers 27 of the interconnection scheme 80 of its interconnection substrate 177 and respective two of the first, second, third or fourth type of micro-bumps, micro-pillars or micro-pads 34 of the second device, to control coupling from the node N23 to one or more of the nodes N24-N26 or to control coupling from the node N26 to one or more of the nodes N23-N25, (5) the field programmable switch matrix 710 or 710-3 as illustrated in FIGS. 2C, 4D and 4E, each of the nodes P₁-P_{N} of which may couple to the first device through, in sequence, one of the first metal lines 281 of said each of the DFPIC or eFPIC chips 400 of its interconnection substrate 177, one of the small input/output (SIO) circuits 203, or metal pads or input/output (I/O) pads, of said each of the DFPIC or eFPIC chips 400 of its interconnection substrate 177, one of the first group of the first type of micro-bumps, micro-pillars or micro-pads 34 of said each of the DFPIC or eFPIC chips 400 of its interconnection substrate 177, each of the interconnection metal layers 27 of the interconnection scheme 80 of its interconnection substrate 177 and one of the first, second, third or fourth type of micro-bumps, micro-pillars or micro-pads 34 of the first device, each of the nodes Q₁-Q_{M} of which may couple to the second device through, in sequence, one of the second metal lines 282 of said each of the DFPIC or eFPIC chips 400 of its interconnection substrate 177, another of the small input/output (SIO) circuits 203, or metal pads or input/output (I/O) pads, of said each of the DFPIC or eFPIC chips 400 of its interconnection substrate 177, one of the second group of the first type of micro-bumps, micro-pillars or micro-pads 34 of said each of the DFPIC or eFPIC chips 400 of its interconnection substrate 177, each of the interconnection metal layers 27 of the interconnection scheme 80 of its interconnection substrate 177 and one of the first, second, third or fourth type of micro-bumps, micro-pillars or micro-pads 34 of the second device, and each of the pass/no-pass switches 778 of which may control coupling between the first and second devices, i.e., between one of the first group of the first type of micro-bumps, micro-pillars or micro-pads 34 of said each of the DFPIC or eFPIC chips 400 of its interconnection substrate 177 and one of the second group of the first type of micro-bumps, micro-pillars or micro-pads 34 of said each of the DFPIC or eFPIC chips 400 of its interconnection substrate 177, and/or (6) the field programmable switch matrix 710-2 as illustrated in FIGS. 2C and 4E, each of some of the nodes P₁-P_{N} of which may couple to the first device through, in sequence, one of the first metal lines 281 of said each of the DFPIC or eFPIC chips 400 of its interconnection substrate 177, one of the small input/output (SIO) circuits 203, or metal pads or input/output (I/O) pads, of said each of the DFPIC or eFPIC chips 400 of its interconnection substrate 177, one of the first group of the first type of micro-bumps, micro-pillars or micro-pads 34 of said each of the DFPIC or eFPIC chips 400 of its interconnection substrate 177, each of the interconnection metal layers 27 of the interconnection scheme 80 of its interconnection substrate 177 and one of the first, second, third or fourth type of micro-bumps, micro-pillars or micro-pads 34 of the first device, each of the other some of the nodes P₁-P_{N} of which may couple to the second device through, in sequence, another of the first metal lines 281 of said each of the DFPIC or eFPIC chips 400 of its interconnection substrate 177, another of the small input/output (SIO) circuits 203, or metal pads or input/output (I/O) pads, of said each of the DFPIC or eFPIC chips 400 of its interconnection substrate 177, one of the second group of the first type of micro-bumps, micro-pillars or micro-pads 34 of said each of the DFPIC or eFPIC chips 400 of its interconnection substrate 177, each of the interconnection metal layers 27 of the interconnection scheme 80 of its interconnection substrate 177 and one of the first, second, third or fourth type of micro-bumps, micro-pillars or micro-pads 34 of the second device, and each of the pass/no-pass switches 778 of which may control coupling between one of the first and second devices and one of the internal circuits of the fourth one of the ASIC cores 215 of said each of the DFPIC or eFPIC chips 400 of its interconnection substrate 177, i.e., between one of the first and second groups of the first type of micro-bumps, micro-pillars or micro-pads 34 of said each of the DFPIC or eFPIC chips 400 of its interconnection substrate 177 and one of the internal circuits of the fourth one of the ASIC cores 215 of said each of the DFPIC or eFPIC chips 400 of its interconnection substrate 177.

### Twenty-Sixth Type of FPMCP

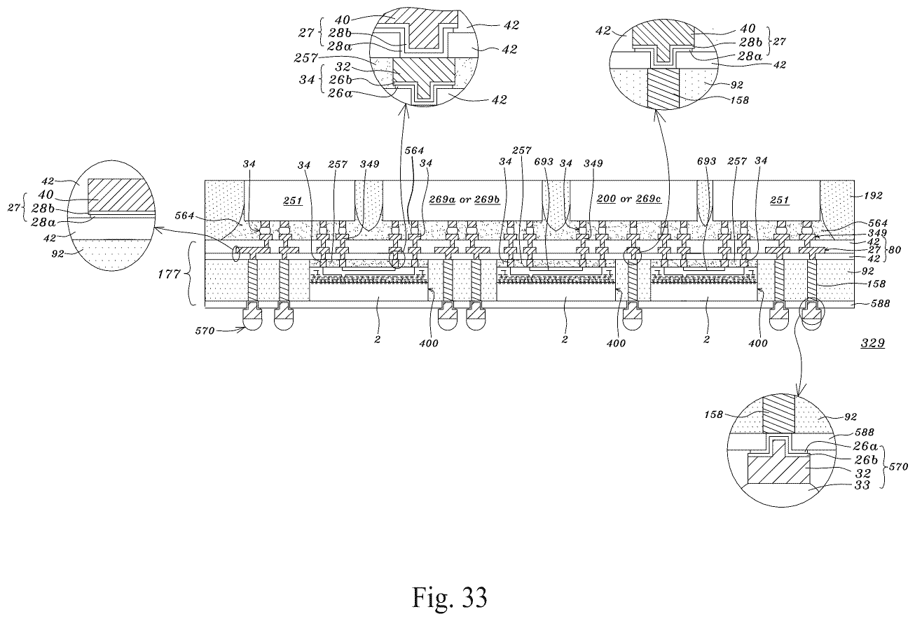

FIG. 33 is a schematically cross-sectional view showing a twenty-sixth type of FPMCP along a cross-sectional line D-D or E-E in FIG. 30 in accordance with an embodiment of the present application. A twenty-sixth type of FPMCP 329 as seen in FIG. 33 may have a similar structure to the twenty-fifth type of FPMCP 328 as seen in FIG. 32. For an element indicated by the same reference number shown in FIGS. 32 and 33, the specification of the element as seen in FIG. 33 may be referred to that of the element as illustrated in FIG. 32. The difference therebetween is mentioned as below: the interconnection scheme 79 of the interconnection substrate 177 for the twenty-fifth type of FPMCP 328 as seen in FIG. 32 may not be formed for the twenty-sixth type of FPMCP 329 as seen in FIG. 33, and each of the DFPIC or eFPIC chips 400 of the interconnection substrate 177 for the twenty-fifth type of FPMCP 328 as seen in FIG. 32 may not be formed with the through silicon vias (TSVs) 157 for the twenty-sixth type of FPMCP 329 as seen in FIG. 33. Thus, for the twenty-sixth type of FPMCP 329 as seen in FIG. 33, each of the DFPIC or eFPIC chips 400 of its interconnection substrate 177 may be used as an interconnection bridge and have the same specification as the first type of semiconductor IC chip 100 illustrated in FIG. 3A. The semiconductor substrate 2 of each of the DFPIC or eFPIC chips 400 of its interconnection substrate 177 may have a bottom surface substantially coplanar with a bottom surface of each of the through package vias (TPVs) 158 of its interconnection substrate 177 and a bottom surface of the polymer layer 92 of its interconnection substrate 177. Its interconnection substrate 177 may further include an insulating dielectric layer 588, such as polymer, silicon oxide, silicon oxynitride or silicon nitride, having a thickness between 0.5 and 10 micrometers on the bottom surface of the semiconductor substrate 2 of each of the DFPIC or eFPIC chips 400 of its interconnection substrate 177 and the bottom surface of the polymer layer 92 of its interconnection substrate 177. Each opening in the insulating dielectric layer 588 of its interconnection substrate 177 may be vertically under the bottom surface of one of the through package vias (TPVs) 158 of its interconnection substrate 177. The first or second type of metal bumps, pillars or pads 570 as illustrated in FIG. 6A may be provided for the twenty-sixth type of FPMCP 329 to be each aligned with one of the openings in the insulating dielectric layer 588 of its interconnection substrate 177 and formed with the adhesion metal layer 26a on the bottom surface of the through package vias (TPVs) 158 of its interconnection substrate 177 and a bottom surface of the insulating dielectric layer 588 of its interconnection substrate 177. Each of its semiconductor IC chips 200, 269, 269c and 251 may couple to one of its metal bumps, pillars or pads 570 for external connection through, in sequence, each of the interconnection metal layers 27 of the interconnection scheme 80 of its interconnection substrate 177 and one of the through package vias (TPVs) 158 of its interconnection substrate 177 vertically under said each of its semiconductor IC chips 200, 269, 269c and 251. Each of the DFPIC or eFPIC chips 400 of its interconnection substrate 177 may couple to one of its metal bumps, pillars or pads 570 for external connection through one or more of the interconnection metal layers 27 of the interconnection scheme 80 of its interconnection substrate 177 and one of the through package vias (TPVs) 158 of its interconnection substrate 177.

### Twenty-Seventh Type of FPMCP

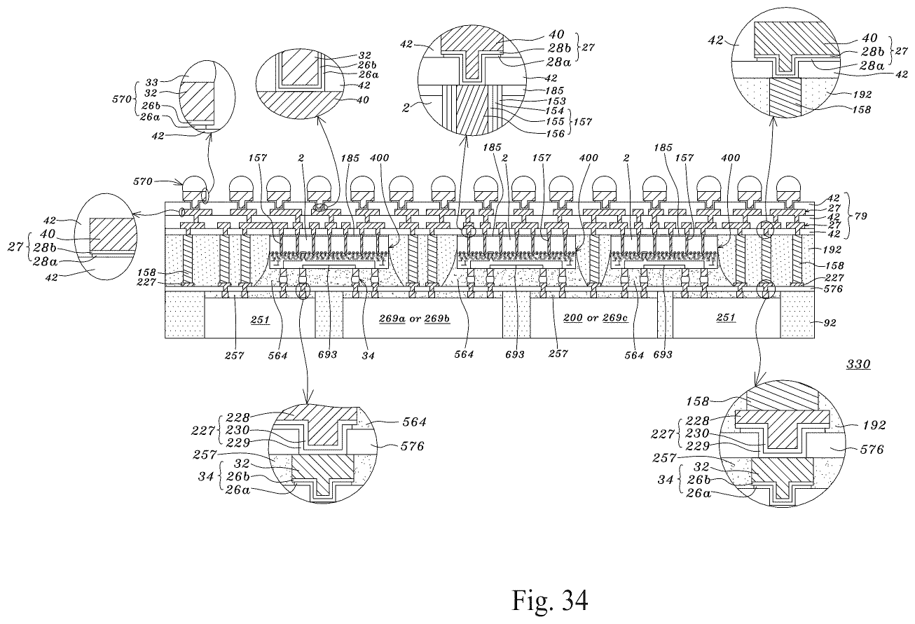

FIG. 34 is a schematically cross-sectional view showing a twenty-seventh type of FPMCP along a cross-sectional line D-D or E-E in FIG. 30 in accordance with an embodiment of the present application. A twenty-seventh type of FPMCP 330 as seen in FIGS. 30 and 34 may include (1) multiple semiconductor IC chips, including the GPU IC chip 269a, CPU IC chip 269b, ASIC or SoC chip 269c, FPGA IC chip 200 and HBM IC chips 251 as illustrated in FIG. 5A-1, arranged at a same horizontal level as one another and each having the same specification as the third type of semiconductor IC chip 100 illustrated in FIG. 3C, wherein its HBM IC chips 251 may be arranged at its left and right sides and its GPU IC chip 269a, CPU IC chip 269b, ASIC or SoC chip 269c and FPGA IC chip 200 may be arranged in an array in its central portion between its HBM IC chips 251 as seen in FIG. 30, (2) a polymer layer 92 or insulating dielectric layer, i.e., sealing layer, such as silicon-oxide-containing molding compound, epoxy-based material or polyimide, horizontally around and at the same horizontal level as its semiconductor IC chips 269a, 269b, 269c, 200 and 251, wherein its polymer layer 92 may have a portion between each neighboring two of its semiconductor IC chips 269a, 269b, 269c, 200 and 251, a top surface coplanar with a top surface of the polymer layer 257 of each of its semiconductor IC chips 269a, 269b, 269c, 200 and 251 and the top surface of each of the first type of micro-bumps, micro-pillars or micro-pads 34 of each of its semiconductor IC chips 269a, 269b, 269c, 200 and 251 and a bottom surface coplanar with a bottom surface of the semiconductor substrate 2 of each of its semiconductor IC chips 269a, 269b, 269c, 200 and 251, (3) an insulating dielectric layer 576, such as polymer, silicon oxide, silicon oxynitride or silicon nitride, having a thickness between 0.5 and 10 micrometers on the top surface of its polymer layer 92 and the top surface of the polymer layer 257 of each of its semiconductor IC chips 269a, 269b, 269c, 200 and 251, wherein each opening in its insulating dielectric layer 576 may be vertically over the top surface of one of the first type of micro-bumps, micro-pillars or micro-pads 34 of one of its semiconductor IC chips 269a, 269b, 269c, 200 and 251, (4) an interconnection metal layer 227 on its insulating dielectric layer 576 and in each opening in its insulating dielectric layer 576, wherein its interconnection metal layer 227 couples to each of the first type of micro-bumps, micro-pillars or micro-pads 34 of each of its semiconductor IC chips 269a, 269b, 269c, 200 and 251 through one of the openings in its insulating dielectric layer 576, wherein its interconnection metal layer 227 may include an electroplated copper layer 228 having a first portion in each of the openings in its insulating dielectric layer 576 and a second portion over each of the openings in its insulating dielectric layer 576 and a top surface of its insulating dielectric layer 576; its interconnection metal layer 227 may further include an adhesion metal layer 229 having a first portion in each of the openings in its insulating dielectric layer 576 and at a bottom and sidewall of the first portion of the electroplated copper layer 228 of its interconnection metal layer 227 and a second portion on the top surface of its insulating dielectric layer 576 and between the top surface of its insulating dielectric layer 576 and the second portion of the electroplated copper layer 228 of its interconnection metal layer 227; its interconnection metal layer 227 may further include an electroplating seed layer 230 having a first portion in each of the openings in its insulating dielectric layer 576, at a bottom and sidewall of the first portion of the electroplated copper layer 228 of its interconnection metal layer 227 and between the first portion of the electroplated copper layer 228 of its interconnection metal layer 227 and the first portion of the adhesion metal layer 229 of its interconnection metal layer 227 and a second portion over the top surface of its insulating dielectric layer 576 and between the second portion of the adhesion metal layer 229 of its interconnection metal layer 227 and the second portion of the electroplated copper layer 228 of its interconnection metal layer 227, and (5) multiple through package vias (TPVs) 158, i.e., metal posts or vias, each provided with an electroplated copper layer having a height or thickness between 20 μm and 300 μm, 30 μm and 200 μm, 50 μm and 150 μm, 50 μm and 120 μm, 20 μm and 100 μm, 10 μm and 100 μm, 20 μm and 60 μm, 20 μm and 40 μm, or 20 μm and 30 μm, or greater than or equal to 100 μm, 50 μm, 30 μm or 20 μm on a top surface of the electroplated copper layer 228 of its interconnection metal layer 227 and on a first area of its interconnection metal layer 227.

Referring to FIGS. 30 and 34, the twenty-seventh type of FPMCP 330 may further include (1) the DFPIC or eFPIC chips 400, i.e., interconnection bridges, each as illustrated in FIGS. 4D and 4E and having the same specification as the second type of semiconductor IC chip 100 illustrated in FIG. 3B to be turned upside down, wherein its DFPIC or eFPIC chips 400 may be arranged at a same horizontal level as one another and each having the first, second, third or fourth type of micro-bumps, micro-pillars or micro-pads 34 each bonded to the top surface of the electroplated copper layer 228 of its interconnection metal layer 227 and a second area of its interconnection metal layer 227, and (2) a polymer layer 192 or insulating dielectric layer, i.e., sealing layer, such as silicon-oxide-containing molding compound, epoxy-based material or polyimide, horizontally around and at the same horizontal level as its DFPIC or eFPIC chips 400 and through package vias (TPVs) 158 and on the top surface of its insulating dielectric layer 576. The semiconductor substrate 2 of each of its DFPIC or eFPIC chips 400 may have a portion, at a backside of said each of its DFPIC or eFPIC chips 400, removed by a chemical-mechanical-polishing (CMP) or mechanical grinding process such that each of the through silicon vias (TSVs) 157, that is, the electroplated copper layer 156 thereof, of each of its DFPIC or eFPIC chips 400 may have a top surface coplanar with a top surface of the semiconductor substrate 2 of each of its DFPIC or eFPIC chips 400, a top surface of its polymer layer 192 and a top surface of each of its through package vias (TPVs) 158, that is, the electroplated copper layer thereof, not shown in FIG. 34 for this case. For an alternative case as seen in FIG. 34, the twenty-seventh type of FPMCP 330 may further include the insulating dielectric layer 185, such as silicon-oxide layer or silicon-nitride layer, illustrated in FIG. 4C formed on a top surface of the semiconductor substrate 2 of each of its DFPIC or eFPIC chips 400, wherein its insulating dielectric layer 185 may have a top surface coplanar with the top surface of each of the through silicon vias 157 of each of its DFPIC or eFPIC chips 400 and the top surface of its polymer layer 192. Each of a first group of its through package vias (TPVs) 158 may be vertically over one of its semiconductor IC chips 269a, 269b, 269c, 200 and 251, but each of a second group of its through package vias (TPVs) 158 may not be vertically over any of its semiconductor IC chips 269a, 269b, 269c, 200 and 251 but vertically over its polymer layer 92.

Referring to FIG. 34, the twenty-seventh type of FPMCP 330 may further include the interconnection scheme 79 as illustrated for one in FIG. 9A to be turned upside down. The bottommost one of the polymer layers 42 of its interconnection scheme 79 may have a bottom surface in contact with the top surface of its polymer layer 192, the top surface of the semiconductor substrate 2 of each of its DFPIC or eFPIC chips 400 and the top surface of each of its through package vias (TPVs) 158, not shown in FIG. 34 for this case. For the alternative case as seen in FIG. 34, the bottommost one of the polymer layers 42 of its interconnection scheme 79 may have a bottom surface in contact with the top surface of its polymer layer 192, the top surface of its insulating dielectric layer 185 and the top surface of each of its through package vias (TPVs) 158. Each opening in the bottommost one of the polymer layers 42 of its interconnection scheme 79 may be vertically over one of the through silicon vias (TSVs) 157 of one of its DFPIC or eFPIC chips 400 or one of its through package vias (TPVs) 158 and thus the bottommost one of the interconnection metal layers 27 of its interconnection scheme 79 may extend through said each opening to couple to said one of the through silicon vias (TSVs) 157 or said one of its through package vias (TPVs) 158. The specification and process for the interconnection metal layers 27 and polymer layers 42 of its interconnection scheme 79 may be referred to those for the second interconnection scheme for a chip (SISC) 29 as illustrated in FIG. 3A.

Referring to FIG. 34, the twenty-seventh type of FPMCP 330 may further include multiple metal bumps, pillars or pads 570 in an array at its top to act as its external pins for coupling to the external circuits, wherein each of its metal bumps, pillars or pads 570 may be of a type selected from various types, i.e., first and second types, having the same specification as that of the first and second types of metal bumps, pillars or pads 570 respectively as illustrated in FIG. 6A to be turned upside down, and may have the adhesion metal layer 26a on a top surface of one of the metal pads of the topmost one of the interconnection metal layers 27 of its interconnection scheme 79 and a top surface of the topmost one of the polymer layers 42 of its interconnection scheme 79.

Accordingly, referring to FIGS. 30 and 34, for the twenty-seventh type of FPMCP 330, neighboring two of its semiconductor IC chips 200, 269a, 269b, 269c and 251 may couple to each other through, in sequence, (1) one of the first type of micro-bumps, micro-pillars or micro-pads 34 of one of said neighboring two of its semiconductor IC chips 200, 269a, 269b, 269c and 251, (2) its interconnection metal layer 227, (3) one of the first, second, third or fourth type of micro-bumps, micro-pillars or micro-pads 34 of one of its DFPIC or eFPIC chips 400 vertically over said neighboring two of its semiconductor IC chips 200, 269a, 269b, 269c and 251, (4) one of the metal lines or traces 693 of said one of its DFPIC or eFPIC chips 400, (5) another of the first, second, third or fourth type of micro-bumps, micro-pillars or micro-pads 34 of said one of its DFPIC or eFPIC chips 400, (6) its interconnection metal layer 227 and (7) one of the first type of micro-bumps, micro-pillars or micro-pads 34 of the other of said neighboring two of its semiconductor IC chips 200, 269a, 269b, 269c and 251. Each of its semiconductor IC chips 200, 269a, 269b, 269c and 251 may couple to one of its metal bumps, pillars or pads 570 for external connection (1) through, in sequence, its interconnection metal layer 227, one of its through package vias (TPVs) 158 vertically over said each of its semiconductor IC chips 200, 269a, 269b, 269c and 251 and each of the interconnection metal layers 27 of its interconnection scheme 79 or (2) through, in sequence, its interconnection metal layer 227, one of the through silicon vias (TSVs) 157 of one of its DFPIC or eFPIC chips 400 vertically over said each of its semiconductor IC chips 200, 269a, 269b, 269c and 251 and each of the interconnection metal layers 27 of its interconnection scheme 79. Each of its DFPIC or eFPIC chips 400 may couple to one of its metal bumps, pillars or pads 570 for external connection through each of the interconnection metal layers 27 of its interconnection scheme 79.

Alternatively, referring to FIGS. 30 and 34, for the twenty-seventh type of FPMCP 330, each of its DFPIC or eFPIC chips 400 may be vertically over neighboring two of its semiconductor IC chips 200, 269a, 269b, 269c and 251, wherein said each of its DFPIC or eFPIC chips 400 may couple to a first device of said neighboring two of its semiconductor IC chips 200, 269a, 269b, 269c and 251, through, in sequence, a first group of the first, second, third or fourth type of micro-bumps, micro-pillars or micro-pads 34 of said each of its DFPIC or eFPIC chips 400 over the first device, its interconnection metal layer 227 and the first type of micro-bumps, micro-pillars or micro-pads 34 of the first device and couple to a second device of said neighboring two of its semiconductor IC chips 200, 269a, 269b, 269c and 251 through, in sequence, a second group of the first, second, third or fourth type of micro-bumps, micro-pillars or micro-pads 34 of said each of its DFPIC or eFPIC chips 400 over the second device, its interconnection metal layer 227 and the first type of micro-bumps, micro-pillars or micro-pads 34 of the second device, wherein with regard to a left front one of the DFPIC or eFPIC chips 400 of its interconnection substrate 177, the first device may be the left one of its HBM IC chips 251 and the second device may be its CPU IC chip 269b, or in another case the first device may be its CPU IC chip 269b and the second device may be the left one of its HBM IC chips 251; with regard to a left rear one of the DFPIC or eFPIC chips 400 of its interconnection substrate 177, the first device may be the left one of its HBM IC chips 251 and the second device may be its GPU IC chip 269a, or in another case the first device may be its GPU IC chip 269a and the second device may be the left one of its HBM IC chips 251; with regard to a right front one of the DFPIC or eFPIC chips 400 of its interconnection substrate 177, the first device may be the right one of its HBM IC chips 251 and the second device may be its ASIC or SoC chip 269c, or in another case the first device may be its ASIC or SoC chip 269c and the second device may be the right one of its HBM IC chips 251; with regard to a right rear one of the DFPIC or eFPIC chips 400 of its interconnection substrate 177, the first device may be the right one of its HBM IC chips 251 and the second device may be its FPGA IC chip 200, or in another case the first device may be its FPGA IC chip 200 and the second device may be the right one of its HBM IC chips 251; with regard to a center front one of the DFPIC or eFPIC chips 400 of its interconnection substrate 177, the first device may be its CPU IC chip 269b and the second device may be its ASIC or SoC chip 269c, or in another case the first device may be its ASIC or SoC chip 269c and the second device may be its CPU IC chip 269b; with regard to a center rear one of the DFPIC or eFPIC chips 400 of its interconnection substrate 177, the first device may be its GPU IC chip 269a and the second device may be its FPGA IC chip 200, or in another case the first device may be its FPGA IC chip 200 and the second device may be its GPU IC chip 269a; with regard to a center left one of the DFPIC or eFPIC chips 400 of its interconnection substrate 177, the first device may be its CPU IC chip 269b and the second device may be its GPU IC chip 269, or in another case the first device may be its GPU IC chip 269 and the second device may be its CPU IC chip 269b; with regard to a center right one of the DFPIC or eFPIC chips 400 of its interconnection substrate 177, the first device may be its ASIC or SoC chip 269c and the second device may be its FPGA IC chip 200, or in another case the first device may be its FPGA IC chip 200 and the second device may be its ASIC or SoC chip 269c. Said each of its DFPIC or eFPIC chips 400 may include (1) the first type of field programmable logic cell or element (LCE) 2014 or 2014-2 as illustrated in FIGS. 1A, 4D and 4E, the data inputs A0 and A1 of which may couple to the first device through, in sequence, respective two of the small input/output (SIO) circuits 203, or metal pads or input/output (I/O) pads, of said each of its DFPIC or eFPIC chips 400, respective two of the first group of the first, second, third or fourth type of micro-bumps, micro-pillars or micro-pads 34 of said each of its DFPIC or eFPIC chips 400, its interconnection metal layer 227 and respective two of the first type of micro-bumps, micro-pillars or micro-pads 34 of the first device, and the data output Dout of which may couple to the second device through, in sequence, another of the small input/output (SIO) circuits 203, or metal pads or input/output (I/O) pads, of said each of its DFPIC or eFPIC chips 400, one of the second group of the first, second, third or fourth type of micro-bumps, micro-pillars or micro-pads 34 of said each of its DFPIC or eFPIC chips 400, its interconnection metal layer 227 and one of the first type of micro-bumps, micro-pillars or micro-pads 34 of the second device, (2) the second or third type of field programmable logic cell or element (LCE) 2014 or 2014-2 as illustrated in FIGS. 1B, 1C, 4D and 4E, the data inputs A0-A3 of which may couple to the first device through, in sequence, respective four of the small input/output (SIO) circuits 203, or metal pads or input/output (I/O) pads, of said each of its DFPIC or eFPIC chips 400, respective four of the first group of the first, second, third or fourth type of micro-bumps, micro-pillars or micro-pads 34 of said each of its DFPIC or eFPIC chips 400, its interconnection metal layer 227 and respective four of the first type of micro-bumps, micro-pillars or micro-pads 34 of the first device, and the data output Dout of which may couple to the second device through, in sequence, another of the small input/output (SIO) circuits 203, or metal pads or input/output (I/O) pads, of said each of its DFPIC or eFPIC chips 400, one of the second group of the first, second, third or fourth type of micro-bumps, micro-pillars or micro-pads 34 of said each of its DFPIC or eFPIC chips 400, its interconnection metal layer 227 and one of the first type of micro-bumps, micro-pillars or micro-pads 34 of the second device, (3) the first type of field programmable switch cell 379 or 379-2 as illustrated in FIGS. 2A, 4D and 4E, the node N21 of which may couple to the first device through, in sequence, one of the small input/output (SIO) circuits 203, or metal pads or input/output (I/O) pads, of said each of its DFPIC or eFPIC chips 400, one of the first group of the first, second, third or fourth type of micro-bumps, micro-pillars or micro-pads 34 of said each of its DFPIC or eFPIC chips 400, its interconnection metal layer 227 and one of the first type of micro-bumps, micro-pillars or micro-pads 34 of the first device, and the node N22 of which may couple to the second device through, in sequence, another of the small input/output (SIO) circuits 203, or metal pads or input/output (I/O) pads, of said each of its DFPIC or eFPIC chips 400, one of the second group of the first, second, third or fourth type of micro-bumps, micro-pillars or micro-pads 34 of said each of its DFPIC or eFPIC chips 400, its interconnection metal layer 227 and one of the first type of micro-bumps, micro-pillars or micro-pads 34 of the second device, (4) the second type of field programmable switch cell 379 or 379-2 as illustrated in FIGS. 2B, 4D and 4E, the nodes N23 and N24 of which may couple to the first device through, in sequence, respective two of the small input/output (SIO) circuits 203, or metal pads or input/output (I/O) pads, of said each of its DFPIC or eFPIC chips 400, respective two of the first group of the first, second, third or fourth type of micro-bumps, micro-pillars or micro-pads 34 of said each of its DFPIC or eFPIC chips 400, its interconnection metal layer 227 and respective two of the first type of micro-bumps, micro-pillars or micro-pads 34 of the first device, and the nodes N25 and N26 of which may couple to the second device through, in sequence, another respective two of the small input/output (SIO) circuits 203, or metal pads or input/output (I/O) pads, of said each of its DFPIC or eFPIC chips 400, respective two of the second group of the first, second, third or fourth type of micro-bumps, micro-pillars or micro-pads 34 of said each of its DFPIC or eFPIC chips 400, its interconnection metal layer 227 and respective two of the first type of micro-bumps, micro-pillars or micro-pads 34 of the second device, to control coupling from the node N23 to one or more of the nodes N24-N26 or to control coupling from the node N26 to one or more of the nodes N23-N25, (5) the field programmable switch matrix 710 or 710-3 as illustrated in FIGS. 2C, 4D and 4E, each of the nodes P₁-P_{N} of which may couple to the first device through, in sequence, one of the first metal lines 281 of said each of its DFPIC or eFPIC chips 400, one of the small input/output (SIO) circuits 203, or metal pads or input/output (I/O) pads, of said each of its DFPIC or eFPIC chips 400, one of the first group of the first, second, third or fourth type of micro-bumps, micro-pillars or micro-pads 34 of said each of its DFPIC or eFPIC chips 400, its interconnection metal layer 227 and one of the first type of micro-bumps, micro-pillars or micro-pads 34 of the first device, each of the nodes Q₁-Q_{M} of which may couple to the second device through, in sequence, one of the second metal lines 282 of said each of its DFPIC or eFPIC chips 400, another of the small input/output (SIO) circuits 203, or metal pads or input/output (I/O) pads, of said each of its DFPIC or eFPIC chips 400, one of the second group of the first, second, third or fourth type of micro-bumps, micro-pillars or micro-pads 34 of said each of its DFPIC or eFPIC chips 400, its interconnection metal layer 227 and one of the first type of micro-bumps, micro-pillars or micro-pads 34 of the second device, and each of the pass/no-pass switches 778 of which may control coupling between the first and second devices, i.e., between one of the first group of the first, second, third or fourth type of micro-bumps, micro-pillars or micro-pads 34 of said each of its DFPIC or eFPIC chips 400 and one of the second group of the first, second, third or fourth type of micro-bumps, micro-pillars or micro-pads 34 of said each of its DFPIC or eFPIC chips 400, and/or (6) the field programmable switch matrix 710-2 as illustrated in FIGS. 2C and 4E, each of some of the nodes P₁-P_{N} of which may couple to the first device through, in sequence, one of the first metal lines 281 of said each of its DFPIC or eFPIC chips 400, one of the small input/output (SIO) circuits 203, or metal pads or input/output (I/O) pads, of said each of its DFPIC or eFPIC chips 400, one of the first group of the first, second, third or fourth type of micro-bumps, micro-pillars or micro-pads 34 of said each of its DFPIC or eFPIC chips 400, its interconnection metal layer 227 and one of the first type of micro-bumps, micro-pillars or micro-pads 34 of the first device, each of the other some of the nodes P₁-P_{N} of which may couple to the second device through, in sequence, another of the first metal lines 281 of said each of its DFPIC or eFPIC chips 400, another of the small input/output (SIO) circuits 203, or metal pads or input/output (I/O) pads, of said each of its DFPIC or eFPIC chips 400, one of the second group of the first, second, third or fourth type of micro-bumps, micro-pillars or micro-pads 34 of said each of its DFPIC or eFPIC chips 400, its interconnection metal layer 227 and one of the first type of micro-bumps, micro-pillars or micro-pads 34 of the second device, and each of the pass/no-pass switches 778 of which may control coupling between one of the first and second devices and one of the internal circuits of the fourth one of the ASIC cores 215 of said each of its DFPIC or eFPIC chips 400, i.e., between one of the first and second groups of the first, second, third or fourth type of micro-bumps, micro-pillars or micro-pads 34 of said each of its DFPIC or eFPIC chips 400 and one of the internal circuits of the fourth one of the ASIC cores 215 of said each of its DFPIC or eFPIC chips 400.

### Twenty-Eighth Type of FPMCP

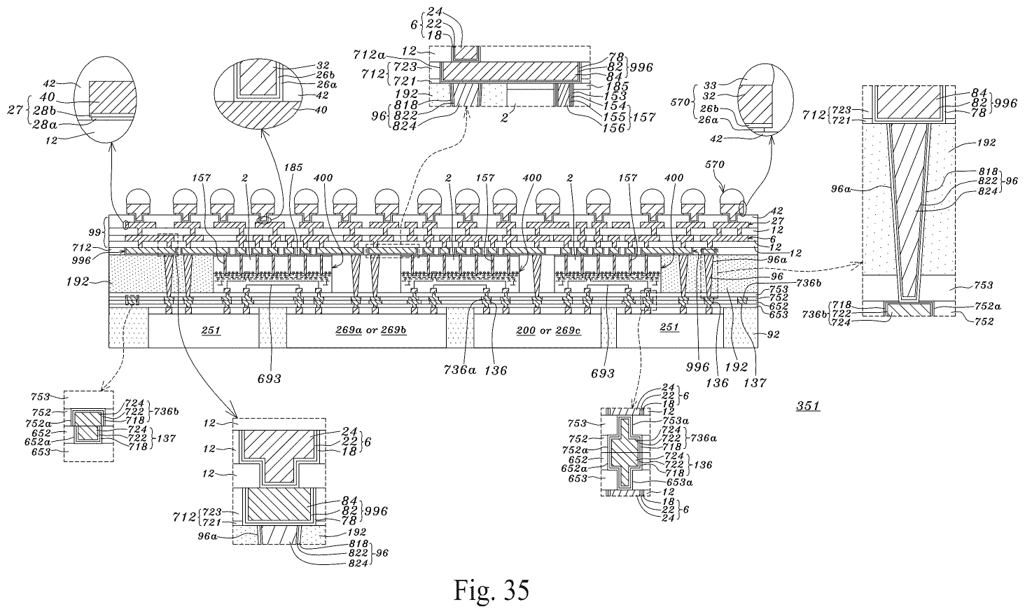

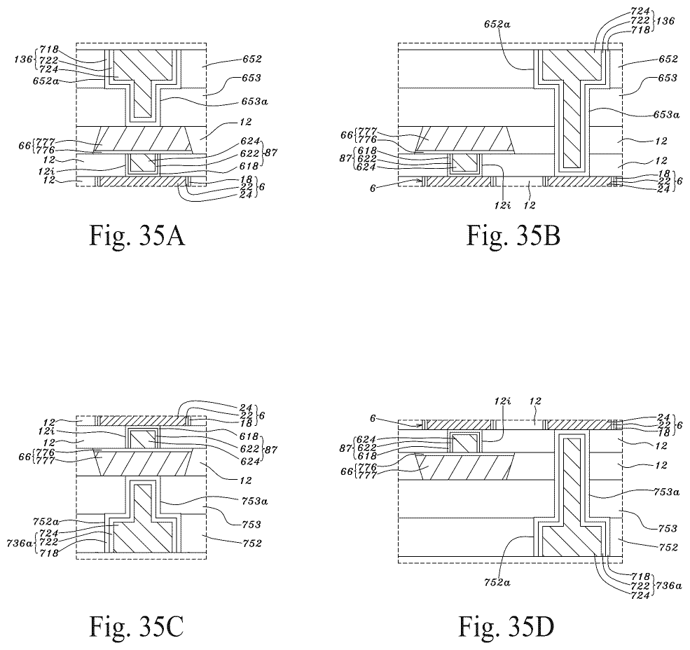

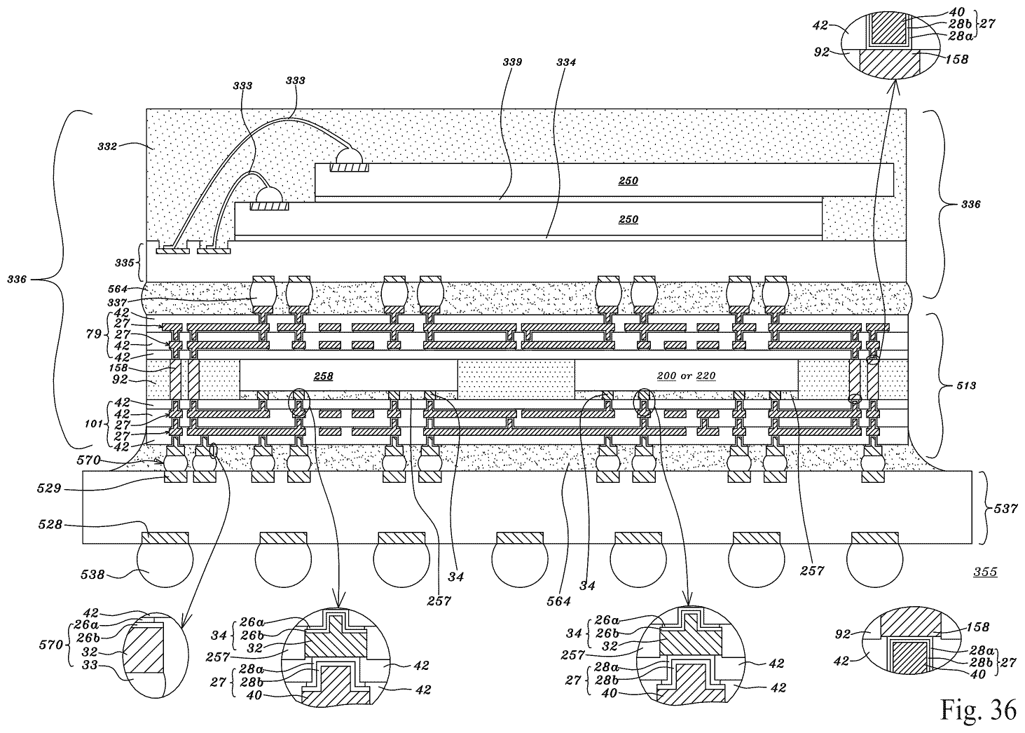

FIG. 35 is a schematically cross-sectional view showing a twenty-eighth type of FPMCP along a cross-sectional line D-D or E-E in FIG. 30 in accordance with an embodiment of the present application. FIGS. 35A and 35B are enlarged cross-sectional views showing a metal bonding pad and insulating bonding layer employed for a second form for a top structure of a semiconductor IC chip in accordance with an embodiment of the present application. A twenty-eighth type of FPMCP 351 as seen in FIGS. 30 and 35 may include multiple semiconductor IC chips, including the GPU IC chip 269a, CPU IC chip 269b, ASIC or SoC chip 269c, FPGA IC chip 200 and HBM IC chips 251 as illustrated in FIG. 5A-1, arranged at a same horizontal level as one another and each having the same specification as the first type of semiconductor IC chip 100 illustrated in FIG. 3A, but none of the passivation layer 14, second interconnection scheme for a chip (SISC) 29 and micro-bumps, micro-pillars or micro-pads 34 of the first type of semiconductor IC chip 100 is formed for each of its semiconductor IC chips 269a, 269b, 269c, 200 and 251, wherein its HBM IC chips 251 may be arranged at its left and right sides and its GPU IC chip 269a, CPU IC chip 269b, ASIC or SoC chip 269c and FPGA IC chip 200 may be arranged in an array in its central portion between its HBM IC chips 251 as seen in FIG. 30. In a first form as seen in FIG. 35 for a top structure of each of its semiconductor IC chips 269a, 269b, 269c, 200 and 251, the topmost one of the interconnection metal layers 6 of the first interconnection scheme for a chip (FISC) 20 of each of its semiconductor IC chips 269a, 269b, 269c, 200 and 251 may be formed in the upper and lower one of the topmost two of the insulating dielectric layers 12 of the first interconnection scheme for a chip (FISC) 20 of said each of its semiconductor IC chips 269a, 269b, 269c, 200 and 251 and composed of the copper layer 24, adhesion metal layer 18 and electroplating seed layer 22 as illustrated in FIG. 3A, wherein the upper one of the topmost two of the insulating dielectric layers 12 of the first interconnection scheme for a chip (FISC) 20 of said each of its semiconductor IC chips 269a, 269b, 269c, 200 and 251 may have a top surface coplanar with a top surface of the topmost one of the interconnection metal layers 6, that is the copper layer 24 thereof, of the first interconnection scheme for a chip (FISC) 20 of said each of its semiconductor IC chips 269a, 269b, 269c, 200 and 251. In a second form for a top structure of each of its semiconductor IC chips 269a, 269b, 269c, 200 and 251 as seen in FIGS. 35A and 35B, the topmost one of the interconnection metal layers 6 of the first interconnection scheme for a chip (FISC) 20 of each of its semiconductor IC chips 269a, 269b, 269c, 200 and 251 may include a metal via 87 in a lower one of the topmost two of the insulating dielectric layers 12 of the first interconnection scheme for a chip (FISC) 20 of said each of its semiconductor IC chips 269a, 269b, 269c, 200 and 251 and a horizontally extending layer 66 on the lower one of the topmost two of the insulating dielectric layers 12 of the first interconnection scheme for a chip (FISC) 20 of said each of its semiconductor IC chips 269a, 269b, 269c, 200 and 251 and each of the metal vias 87 of the topmost one of the interconnection metal layers 6 of the first interconnection scheme for a chip (FISC) 20 of said each of its semiconductor IC chips 269a, 269b, 269c, 200 and 251 and in an upper one of the topmost two of the insulating dielectric layers 12 of the first interconnection scheme for a chip (FISC) 20 of said each of its semiconductor IC chips 269a, 269b, 269c, 200 and 251, wherein each of the metal vias 87 of the topmost one of the interconnection metal layers 6 of the first interconnection scheme for a chip (FISC) 20 of said each of its semiconductor IC chips 269a, 269b, 269c, 200 and 251 may include (1) a copper layer 624 having a thickness between 0.1 and 2 micrometers or between 0.2 and 1 micrometer in an opening 12i in the lower one of the topmost two of the insulating dielectric layers 12 of the first interconnection scheme for a chip (FISC) 20 of said each of its semiconductor IC chips 269a, 269b, 269c, 200 and 251, (2) an adhesion metal layer 618, such as titanium, titanium nitride, tantalum or tantalum nitride, having a thickness between 1 nm and 50 nm at a bottom and sidewall of the copper layer 624 of said each of the metal vias 87, on the copper layer 24 of the second topmost one of the interconnection metal layers 6 of the first interconnection scheme for a chip (FISC) 20 of said each of its semiconductor IC chips 269a, 269b, 269c, 200 and 251 and between the copper layer 624 of said each of the metal vias 87 and the copper layer 24 of the second topmost one of the interconnection metal layers 6 of the first interconnection scheme for a chip (FISC) 20 of said each of its semiconductor IC chips 269a, 269b, 269c, 200 and 251, and (3) an electroplating seed layer 622, such as copper, between the copper layer 624 and adhesion metal layer 618 of said each of the metal vias 87, wherein said each of the metal vias 87, i.e., the copper layer 624 thereof, may have a top surface substantially coplanar with a top surface of the lower one of the topmost two of the insulating dielectric layers 12 of the first interconnection scheme for a chip (FISC) 20 of said each of its semiconductor IC chips 269a, 269b, 269c, 200 and 251. The horizontally extending layer 66 of the topmost one of the interconnection metal layers 6 of the first interconnection scheme for a chip (FISC) 20 of said each of its semiconductor IC chips 269a, 269b, 269c, 200 and 251 may include (1) an adhesion metal layer 776, such as titanium, titanium nitride, tantalum or tantalum nitride, having a thickness between 1 nm and 50 nm on the top surface of the lower one of the topmost two of the insulating dielectric layers 12 of the first interconnection scheme for a chip (FISC) 20 of said each of its semiconductor IC chips 269a, 269b, 269c, 200 and 251 and the top surface of said each of the metal vias 87, i.e., the copper layer 624 thereof, and (2) an aluminum layer 777 having a thickness between 0.5 and 4 micrometers or between 1 and 3 micrometers on a top surface of the adhesion metal layer 776 of the horizontally extending layer 66 of the topmost one of the interconnection metal layers 6 of the first interconnection scheme for a chip (FISC) 20 of said each of its semiconductor IC chips 269a, 269b, 269c, 200 and 251 and in the upper one of the topmost two of the insulating dielectric layers 12 of the first interconnection scheme for a chip (FISC) 20 of said each of its semiconductor IC chips 269a, 269b, 269c, 200 and 251, wherein the aluminum layer 777 of the horizontally extending layer 66 of the topmost one of the interconnection metal layers 6 of the first interconnection scheme for a chip (FISC) 20 of said each of its semiconductor IC chips 269a, 269b, 269c, 200 and 251 may have a top surface coplanar with a top surface of the upper one of the topmost two of the insulating dielectric layers 12 of the first interconnection scheme for a chip (FISC) 20 of said each of its semiconductor IC chips 269a, 269b, 269c, 200 and 251, wherein the adhesion metal layer 776 of the horizontally extending layer 66 of the topmost one of the interconnection metal layers 6 of the first interconnection scheme for a chip (FISC) 20 of said each of its semiconductor IC chips 269a, 269b, 269c, 200 and 251 is at a bottom of the aluminum layer 777 of the horizontally extending layer 66 of the topmost one of the interconnection metal layers 6 of the first interconnection scheme for a chip (FISC) 20 of said each of its semiconductor IC chips 269a, 269b, 269c, 200 and 251, on the copper layer 624 of each of the metal vias 87 of the topmost one of the interconnection metal layers 6 of the first interconnection scheme for a chip (FISC) 20 of said each of its semiconductor IC chips 269a, 269b, 269c, 200 and 251 and between the copper layer 624 of each of the metal vias 87 of the topmost one of the interconnection metal layers 6 of the first interconnection scheme for a chip (FISC) 20 of said each of its semiconductor IC chips 269a, 269b, 269c, 200 and 251 and the aluminum layer 777 of the horizontally extending layer 66 of the topmost one of the interconnection metal layers 6 of the first interconnection scheme for a chip (FISC) 20 of said each of its semiconductor IC chips 269a, 269b, 269c, 200 and 251, but not at a sidewall of the aluminum layer 777 of the horizontally extending layer 66 of the topmost one of the interconnection metal layers 6 of the first interconnection scheme for a chip (FISC) 20 of said each of its semiconductor IC chips 269a, 269b, 269c, 200 and 251. Alternatively, each of the metal vias 87 of the topmost one of the interconnection metal layers 6 of the first interconnection scheme for a chip (FISC) 20 of said each of its semiconductor IC chips 269a, 269b, 269c, 200 and 251 may be provided by the aluminum layer 777 and adhesion metal layer 776 of the horizontally extending layer 66 of the topmost one of the interconnection metal layers 6 of the first interconnection scheme for a chip (FISC) 20 of said each of its semiconductor IC chips 269a, 269b, 269c, 200 and 251, and in this case the aluminum layer 777 and adhesion metal layer 776 of the horizontally extending layer 66 of the topmost one of the interconnection metal layers 6 of the first interconnection scheme for a chip (FISC) 20 of said each of its semiconductor IC chips 269a, 269b, 269c, 200 and 251 may further extend into each opening 12i in the lower one of the topmost two of the insulating dielectric layers 12 of the first interconnection scheme for a chip (FISC) 20 of said each of its semiconductor IC chips 269a, 269b, 269c, 200 and 251 to act as one of the metal vias 87 of the topmost one of the interconnection metal layers 6 of the first interconnection scheme for a chip (FISC) 20 of said each of its semiconductor IC chips 269a, 269b, 269c, 200 and 251, wherein each of the metal vias 87 of the topmost one of the interconnection metal layers 6 of the first interconnection scheme for a chip (FISC) 20 of said each of its semiconductor IC chips 269a, 269b, 269c, 200 and 251 may include (1) the aluminum layer 777 having a thickness between 0.1 and 2 micrometers or between 0.2 and 1 micrometer in one of the openings 12i in the lower one of the topmost two of the insulating dielectric layers 12 of the first interconnection scheme for a chip (FISC) 20 of said each of its semiconductor IC chips 269a, 269b, 269c, 200 and 251 and (2) the adhesion metal layer 776, such as titanium, titanium nitride, tantalum or tantalum nitride, having a thickness between 1 nm and 50 nm at a bottom and sidewall of the aluminum layer 777 of said each of the metal vias 87, on the copper layer 24 of the second topmost one of the interconnection metal layers 6 of the first interconnection scheme for a chip (FISC) 20 of said each of its semiconductor IC chips 269a, 269b, 269c, 200 and 251 and between the aluminum layer 777 of said each of the metal vias 87 and the copper layer 24 of the second topmost one of the interconnection metal layers 6 of the first interconnection scheme for a chip (FISC) 20 of said each of its semiconductor IC chips 269a, 269b, 269c, 200 and 251.

Referring to FIGS. 30, 35, 35A and 35B, the twenty-eighth type of FPMCP 351 may further include a polymer layer 92 or insulating dielectric layer, i.e., sealing layer, such as silicon-oxide-containing molding compound, epoxy-based material or polyimide, horizontally around and at the same horizontal level as its semiconductor IC chips 269a, 269b, 269c, 200 and 251, wherein its polymer layer 92 may have a portion between each neighboring two of its semiconductor IC chips 269a, 269b, 269c, 200 and 251, a top surface coplanar with the top surface of the upper one of the topmost two of the insulating dielectric layers 12 of the first interconnection scheme for a chip (FISC) 20 of each of its semiconductor IC chips 269a, 269b, 269c, 200 and 251 and the top surface of the topmost one of the interconnection metal layers 6, that is the copper layer 24 thereof for the first form or the aluminum layer 777 thereof for the second form, of the first interconnection scheme for a chip (FISC) 20 of each of its semiconductor IC chips 269a, 269b, 269c, 200 and 251 and a bottom surface coplanar with a bottom surface of the semiconductor substrate 2 of each of its semiconductor IC chips 269a, 269b, 269c, 200 and 251.

Referring to FIGS. 30, 35, 35A and 35B, the twenty-eighth type of FPMCP 351 may further include (1) an insulating dielectric layer 653 on the top surface of its polymer layer 92 and the top surface of the topmost one of the interconnection metal layers 6, that is the copper layer 24 thereof for the first form or the aluminum layer 777 thereof for the second form, of the first interconnection scheme for a chip (FISC) 20 of each of its semiconductor IC chips 269a, 269b, 269c, 200 and 251, wherein its insulating dielectric layer 653 may be made of silicon oxide or silicon oxynitride having a thickness between 0.1 and 7 micrometers, between 0.1 and 5 micrometers, between 0.2 and 2 micrometers or between 0.2 and 1 micrometer, and (2) an insulating bonding layer 652 on a top surface of its insulating dielectric layer 653, wherein its insulating bonding layer 652 may be made of silicon oxide or silicon oxynitride having a thickness between 0.1 and 7 micrometers, between 0.2 and 5 micrometers, between 0.2 and 3 micrometers or between 0.2 and 1 micrometer. Alternatively, its insulating bonding layer 652 may be a composite having a silicon-oxide layer having a thickness between 0.1 and 7 micrometers, between 0.2 and 5 micrometers, between 0.2 and 3 micrometers or between 0.2 and 1 micrometer over the top surface of its insulating dielectric layer 653 and a silicon-oxynitride layer having a thickness between 0.05 and 0.2 micrometers at a top of its insulating bonding layer 652 and on a top surface of the silicon-oxide layer of its insulating bonding layer 652. In a first case for the first form for the top structure of each of its semiconductor IC chips 269a, 269b, 269c, 200 and 251 as seen in FIG. 35, multiple openings 653a may be formed each in its insulating dielectric layer 653 and over the topmost one of the interconnection metal layers 6, i.e., the copper layer 24 thereof, of the first interconnection scheme for a chip (FISC) 20 of one of its semiconductor IC chips 269a, 269b, 269c, 200 and 251, in a second case for the second form for the top structure of each of its semiconductor IC chips 269a, 269b, 269c, 200 and 251 as seen in FIG. 35A, multiple openings 653a may be formed each in its insulating dielectric layer 653 and over the topmost one of the interconnection metal layers 6, i.e., the aluminum layer 777 thereof, of the first interconnection scheme for a chip (FISC) 20 of one of its semiconductor IC chips 269a, 269b, 269c, 200 and 251, in a third case for the second form for the top structure of each of its semiconductor IC chips 269a, 269b, 269c, 200 and 251 as seen in FIG. 35B, multiple openings 653a may be formed each in its insulating dielectric layer 653 and the topmost two of the insulating dielectric layers 12 of the first interconnection scheme for a chip (FISC) 20 of one of its semiconductor IC chips 269a, 269b, 269c, 200 and 251 and over the second topmost one of the interconnection metal layers 6, i.e., the copper layer 24 thereof, of the first interconnection scheme for a chip (FISC) 20 of said one of its semiconductor IC chips 269a, 269b, 269c, 200 and 251. For each of the first, second and third cases, multiple openings 652a may be formed each in its insulating bonding layer 652 and over one of the openings 653a in its insulating dielectric layer 653.

For the first case as seen in FIGS. 30 and 35, the twenty-eighth type of FPMCP 351 may further include multiple metal bonding pads 136 each in one of the openings 652a in its insulating bonding layer 652 and one of the openings 653a in its insulating dielectric layer 653 and vertically over one of its semiconductor IC chips 269a, 269b, 269c, 200 and 251. Each of its metal bonding pads 136 may include (1) an electroplated copper layer 724 having a first portion in one of the openings 653a in its insulating dielectric layer 653 and a second portion having a thickness between 0.1 and 7 micrometers, between 0.1 and 5 micrometers, between 0.2 and 2 micrometers or between 0.2 and 1 micrometer in one of the openings 652a in its insulating bonding layer 652 and over said one of the openings 653a and the top surface of its insulating dielectric layer 653, (2) an adhesion metal layer 718 having a first portion in said one of the openings 653a, at a bottom and sidewall of the first portion of the electroplated copper layer 724 of said each of its metal bonding pads 136, between the first portion of the electroplated copper layer 724 of said each of its metal bonding pads 136 and the topmost one of the interconnection metal layers 6, i.e., the copper layer 24 thereof, of the first interconnection scheme for a chip (FISC) 20 of one of its semiconductor IC chips 269a, 269b, 269c, 200 and 251 and on the topmost one of the interconnection metal layers 6, i.e., the copper layer 24 thereof, of the first interconnection scheme for a chip (FISC) 20 of said one of its semiconductor IC chips 269a, 269b, 269c, 200 and 251 and a second portion in said one of the openings 652a, on the top surface of its insulating dielectric layer 653 and at a bottom and sidewall of the second portion of the electroplated copper layer 724 of said each of its metal bonding pads 136, and (3) an electroplating seed layer 722 having a first portion in said one of the openings 653a, at the bottom and sidewall of the first portion of the electroplated copper layer 724 of said each of its metal bonding pads 136 and between the first portion of the electroplated copper layer 724 of said each of its metal bonding pads 136 and the first portion of the adhesion metal layer 718 of said each of its metal bonding pads 136 and a second portion in said one of the openings 652a, at the bottom and sidewall of the second portion of the electroplated copper layer 724 of said each of its metal bonding pads 136 and between the second portion of the electroplated copper layer 724 of said each of its metal bonding pads 136 and the second portion of the adhesion metal layer 718 of said each of its metal bonding pads 136. Each of its metal bonding pads 136, i.e., the electroplated copper layer 724 thereof, may have a top surface coplanar with a top surface of its insulating bonding layer 652.

For the second case as seen in FIGS. 30 and 35A, the twenty-eighth type of FPMCP 351 may further include multiple metal bonding pads 136 each in one of the openings 652a in its insulating bonding layer 652 and one of the openings 653a in its insulating dielectric layer 653. Each of its metal bonding pads 136 may include (1) an electroplated copper layer 724 having a first portion in one of the openings 653a in its insulating dielectric layer 653 and a second portion having a thickness between 0.1 and 7 micrometers, between 0.1 and 5 micrometers, between 0.2 and 2 micrometers or between 0.2 and 1 micrometer in one of the openings 652a in its insulating bonding layer 652 and over said one of the openings 653a and the top surface of its insulating dielectric layer 653, (2) an adhesion metal layer 718 having a first portion in said one of the openings 653a, at a bottom and sidewall of the first portion of the electroplated copper layer 724 of said each of its metal bonding pads 136, between the first portion of the electroplated copper layer 724 of said each of its metal bonding pads 136 and the topmost one of the interconnection metal layers 6, i.e., the aluminum layer 777 thereof, of the first interconnection scheme for a chip (FISC) 20 of one of its semiconductor IC chips 269a, 269b, 269c, 200 and 251 and on the topmost one of the interconnection metal layers 6, i.e., the aluminum layer 777 thereof, of the first interconnection scheme for a chip (FISC) 20 of said one of its semiconductor IC chips 269a, 269b, 269c, 200 and 251 and a second portion in said one of the openings 652a, on the top surface of its insulating dielectric layer 653 and at a bottom and sidewall of the second portion of the electroplated copper layer 724 of said each of its metal bonding pads 136, and (3) an electroplating seed layer 722 having a first portion in said one of the openings 653a, at the bottom and sidewall of the first portion of the electroplated copper layer 724 of said each of its metal bonding pads 136 and between the first portion of the electroplated copper layer 724 of said each of its metal bonding pads 136 and the first portion of the adhesion metal layer 718 of said each of its metal bonding pads 136 and a second portion in said one of the openings 652a, at the bottom and sidewall of the second portion of the electroplated copper layer 724 of said each of its metal bonding pads 136 and between the second portion of the electroplated copper layer 724 of said each of its metal bonding pads 136 and the second portion of the adhesion metal layer 718 of said each of its metal bonding pads 136. Each of its metal bonding pads 136, i.e., the electroplated copper layer 724 thereof, may have a top surface coplanar with a top surface of its insulating bonding layer 652.

For the third case as seen in FIGS. 30 and 35B, the twenty-eighth type of FPMCP 351 may further include multiple metal bonding pads 136 each in one of the openings 652a in its insulating bonding layer 652 and one of the openings 653a in its insulating dielectric layer 653 and the topmost two of the insulating dielectric layers 12 of the first interconnection scheme for a chip (FISC) 20 of one of its semiconductor IC chips 269a, 269b, 269c, 200 and 251. Each of its metal bonding pads 136 may include (1) an electroplated copper layer 724 having a first portion in one of the openings 653a in its insulating dielectric layer 653 and the topmost two of the insulating dielectric layers 12 of the first interconnection scheme for a chip (FISC) 20 of one of its semiconductor IC chips 269a, 269b, 269c, 200 and 251 and a second portion having a thickness between 0.1 and 7 micrometers, between 0.1 and 5 micrometers, between 0.2 and 2 micrometers or between 0.2 and 1 micrometer in one of the openings 652a in its insulating bonding layer 652 and over said one of the openings 653a and the top surface of its insulating dielectric layer 653, (2) an adhesion metal layer 718 having a first portion in said one of the openings 653a, at a bottom and sidewall of the first portion of the electroplated copper layer 724 of said each of its metal bonding pads 136, between the first portion of the electroplated copper layer 724 of said each of its metal bonding pads 136 and the second topmost one of the interconnection metal layers 6, i.e., the copper layer 24 thereof, of the first interconnection scheme for a chip (FISC) 20 of said one of its semiconductor IC chips 269a, 269b, 269c, 200 and 251 and on the second topmost one of the interconnection metal layers 6, i.e., the copper layer 24 thereof, of the first interconnection scheme for a chip (FISC) 20 of said one of its semiconductor IC chips 269a, 269b, 269c, 200 and 251 and a second portion in said one of the openings 652a, on the top surface of its insulating dielectric layer 653 and at a bottom and sidewall of the second portion of the electroplated copper layer 724 of said each of its metal bonding pads 136, and (3) an electroplating seed layer 722 having a first portion in said one of the openings 653a, at the bottom and sidewall of the first portion of the electroplated copper layer 724 of said each of its metal bonding pads 136 and between the first portion of the electroplated copper layer 724 of said each of its metal bonding pads 136 and the first portion of the adhesion metal layer 718 of said each of its metal bonding pads 136 and a second portion in said one of the openings 652a, at the bottom and sidewall of the second portion of the electroplated copper layer 724 of said each of its metal bonding pads 136 and between the second portion of the electroplated copper layer 724 of said each of its metal bonding pads 136 and the second portion of the adhesion metal layer 718 of said each of its metal bonding pads 136. Each of its metal bonding pads 136, i.e., the electroplated copper layer 724 thereof, may have a top surface coplanar with a top surface of its insulating bonding layer 652.

Referring to FIG. 35, the twenty-eighth type of FPMCP 351 may further include multiple metal bonding pads 137 each in one of the openings 652a in its insulating bonding layer 652, on its insulating dielectric layer 653, vertically over its polymer layer 92 and not vertically over any of its semiconductor IC chips 269a, 269b, 269c, 200 and 251. Each of its metal bonding pads 137 may include (1) an electroplated copper layer 724 having a thickness between 0.1 and 7 micrometers, between 0.1 and 5 micrometers, between 0.2 and 2 micrometers or between 0.2 and 1 micrometer in one of the openings 652a in its insulating bonding layer 652 and over the top surface of its insulating dielectric layer 653, (2) an adhesion metal layer 718 in said one of the openings 652a, on the top surface of its insulating dielectric layer 653 and at a bottom and sidewall of the electroplated copper layer 724 of said each of its metal bonding pads 137, and (3) an electroplating seed layer 722 in said one of the openings 652a, at the bottom and sidewall of the electroplated copper layer 724 of said each of its metal bonding pads 137 and between the electroplated copper layer 724 of said each of its metal bonding pads 137 and the adhesion metal layer 718 of said each of its metal bonding pads 137. Each of its metal bonding pads 137, i.e., the electroplated copper layer 724 thereof, may have a top surface coplanar with the top surface of its insulating bonding layer 652.

FIGS. 35C and 35D are enlarged cross-sectional views showing a metal bonding pad and insulating bonding layer employed for a second form for a bottom structure of a DFPIC or eFPIC chip in accordance with an embodiment of the present application. Referring to FIGS. 30 and 35, the twenty-eighth type of FPMCP 351 may further include (1) the DFPIC or eFPIC chips 400, i.e., interconnection bridges, each as illustrated in FIGS. 4D and 4E and having the same specification as the second type of semiconductor IC chip 100 illustrated in FIG. 3B to be turned upside down, but none of the passivation layer 14, second interconnection scheme for a chip (SISC) 29 and micro-bumps, micro-pillars or micro-pads 34 of the second type of semiconductor IC chip 100 is formed for each of its DFPIC or eFPIC chips 400, wherein its DFPIC or eFPIC chips 400 may be arranged at a same horizontal level as one another. Each form of the first and second forms for the top structure of each of its semiconductor IC chips 269a, 269b, 269c, 200 and 251 to be turned upside down may be employed into a bottom structure of each of its DFPIC or eFPIC chips 400; a first form for the bottom structure of each of its DFPIC or eFPIC chips 400 as seen in FIG. 35 may be provided with the same specification as the first form for the top structure of each of its semiconductor IC chips 269a, 269b, 269c, 200 and 251 as seen in FIG. 35 to be turned upside down, and a second form for the bottom structure of each of its DFPIC or eFPIC chips 400 as seen in FIGS. 35C and 35D may be provided with the same specification as the second form for the top structure of each of its semiconductor IC chips 269a, 269b, 269c, 200 and 251 as seen in FIGS. 35A and 35B to be turned upside down, and (2) a polymer layer 192 or insulating dielectric layer, i.e., sealing layer, such as silicon-oxide-containing molding compound, epoxy-based material or polyimide, horizontally around and at the same horizontal level as its DFPIC or eFPIC chips 400, wherein its polymer layer 192 may have a portion between each neighboring two of its DFPIC or eFPIC chips 400, a bottom surface coplanar with the bottom surface of the lower one of the bottommost two of the insulating dielectric layers 12 of the first interconnection scheme for a chip (FISC) 20 of each of its DFPIC or eFPIC chips 400 and the bottom surface of the bottommost one of the interconnection metal layers 6, that is the copper layer 24 thereof for the first form or the aluminum layer 777 thereof for the second form, of the first interconnection scheme for a chip (FISC) 20 of each of its DFPIC or eFPIC chips 400 and a top surface coplanar with a top surface of the semiconductor substrate 2 of each of its DFPIC or eFPIC chips 400.

Referring to FIGS. 35, 35C and 35D, the twenty-eighth type of FPMCP 351 may further include (1) an insulating dielectric layer 753 on the bottom surface of its polymer layer 192 and the bottom surface of the bottommost one of the interconnection metal layers 6, that is the copper layer 24 thereof for the first form or the aluminum layer 777 thereof for the second form, of the first interconnection scheme for a chip (FISC) 20 of each of its DFPIC or eFPIC chips 400, wherein its insulating dielectric layer 753 may be made of silicon oxide or silicon oxynitride having a thickness between 0.1 and 7 micrometers, between 0.1 and 5 micrometers, between 0.2 and 2 micrometers or between 0.2 and 1 micrometer, and (2) an insulating bonding layer 752 on a bottom surface of its insulating dielectric layer 753, wherein its insulating bonding layer 752 may be made of silicon oxide or silicon oxynitride having a thickness between 0.1 and 7 micrometers, between 0.2 and 5 micrometers, between 0.2 and 3 micrometers or between 0.2 and 1 micrometer. Alternatively, its insulating bonding layer 752 may be a composite having a silicon-oxide layer having a thickness between 0.1 and 7 micrometers, between 0.2 and 5 micrometers, between 0.2 and 3 micrometers or between 0.2 and 1 micrometer under the bottom surface of its insulating dielectric layer 753 and a silicon-oxynitride layer having a thickness between 0.05 and 0.2 micrometers at a bottom of its insulating bonding layer 752 and on a bottom surface of the silicon-oxide layer of its insulating bonding layer 752. In a fourth case for the first form for the bottom structure of each of its DFPIC or eFPIC chips 400 as seen in FIG. 35, multiple openings 753a may be formed each in its insulating dielectric layer 753 and under the bottommost one of the interconnection metal layers 6, i.e., the copper layer 24 thereof, of the first interconnection scheme for a chip (FISC) 20 of one of its DFPIC or eFPIC chips 400; in a fifth case for the second form for the bottom structure of each of its DFPIC or eFPIC chips 400 as seen in FIG. 35C, multiple openings 753a may be formed each in its insulating dielectric layer 753 and under the bottommost one of the interconnection metal layers 6, i.e., the aluminum layer 777 thereof, of the first interconnection scheme for a chip (FISC) 20 of one of its DFPIC or eFPIC chips 400; in a sixth case for the second form for the bottom structure of each of its DFPIC or eFPIC chips 400 as seen in FIG. 35D, multiple openings 753a may be formed each in its insulating dielectric layer 753 and the bottommost two of the insulating dielectric layers 12 of the first interconnection scheme for a chip (FISC) 20 of one of its DFPIC or eFPIC chips 400 and under the second bottommost one of the interconnection metal layers 6, i.e., the copper layer 24 thereof, of the first interconnection scheme for a chip (FISC) 20 of said one of its DFPIC or eFPIC chips 400. For each of the fourth, fifth and sixth cases, multiple openings 752a may be formed each in its insulating bonding layer 752 and under one of the openings 753a in its insulating dielectric layer 753 and multiple openings 752b may be formed each in its insulating bonding layer 752 but not under any of the openings 753a in its insulating dielectric layer 753.

For the fourth case as seen in FIG. 35, the twenty-eighth type of FPMCP 351 may further include multiple metal bonding pads 736a each in one of the openings 752a in its insulating bonding layer 752 and one of the openings 753a in its insulating dielectric layer 753 and multiple metal bonding pads 736b each in one of the openings 752b in its insulating bonding layer 752. Each of its metal bonding pads 736a may include (1) an electroplated copper layer 724 having a first portion in one of the openings 753a in its insulating dielectric layer 753 and a second portion having a thickness between 0.1 and 7 micrometers, between 0.1 and 5 micrometers, between 0.2 and 2 micrometers or between 0.2 and 1 micrometer in one of the openings 752a in its insulating bonding layer 752 and under said one of the openings 753a and the bottom surface of its insulating dielectric layer 753, (2) an adhesion metal layer 718 having a first portion in said one of the openings 753a, at a top and sidewall of the first portion of the electroplated copper layer 724 of said each of its metal bonding pads 736a, between the first portion of the electroplated copper layer 724 of said each of its metal bonding pads 736a and the bottommost one of the interconnection metal layers 6, i.e., the copper layer 24 thereof, of the first interconnection scheme for a chip (FISC) 20 of one of its DFPIC or eFPIC chips 400 and on the bottommost one of the interconnection metal layers 6, i.e., the copper layer 24 thereof, of the first interconnection scheme for a chip (FISC) 20 of said one of its DFPIC or eFPIC chips 400 and a second portion in said one of the openings 752a, on the bottom surface of its insulating dielectric layer 753 and at a top and sidewall of the second portion of the electroplated copper layer 724 of said each of its metal bonding pads 736a, and (3) an electroplating seed layer 722 having a first portion in said one of the openings 753a, at the top and sidewall of the first portion of the electroplated copper layer 724 of said each of its metal bonding pads 736a and between the first portion of the electroplated copper layer 724 of said each of its metal bonding pads 736a and the first portion of the adhesion metal layer 718 of said each of its metal bonding pads 736a and a second portion in said one of the openings 752a, at the top and sidewall of the second portion of the electroplated copper layer 724 of said each of its metal bonding pads 736a and between the second portion of the electroplated copper layer 724 of said each of its metal bonding pads 736a and the second portion of the adhesion metal layer 718 of said each of its metal bonding pads 736a.

For the fifth case as seen in FIG. 35C, the twenty-eighth type of FPMCP 351 may further include multiple metal bonding pads 736a each in one of the openings 752a in its insulating bonding layer 752 and one of the openings 753a in its insulating dielectric layer 753 and multiple metal bonding pads 736b each in one of the openings 752b in its insulating bonding layer 752. Each of its metal bonding pads 736a may include (1) an electroplated copper layer 724 having a first portion in one of the openings 753a in its insulating dielectric layer 753 and a second portion having a thickness between 0.1 and 7 micrometers, between 0.1 and 5 micrometers, between 0.2 and 2 micrometers or between 0.2 and 1 micrometer in one of the openings 752a in its insulating bonding layer 752 and under said one of the openings 753a and the bottom surface of its insulating dielectric layer 753, (2) an adhesion metal layer 718 having a first portion in said one of the openings 753a, at a top and sidewall of the first portion of the electroplated copper layer 724 of said each of its metal bonding pads 736a, between the first portion of the electroplated copper layer 724 of said each of its metal bonding pads 736a and the bottommost one of the interconnection metal layers 6, i.e., the aluminum layer 777 thereof, of the first interconnection scheme for a chip (FISC) 20 of one of its DFPIC or eFPIC chips 400 and on the bottommost one of the interconnection metal layers 6, i.e., the aluminum layer 777 thereof, of the first interconnection scheme for a chip (FISC) 20 of said one of its DFPIC or eFPIC chips 400 and a second portion in said one of the openings 752a, on the bottom surface of its insulating dielectric layer 753 and at a top and sidewall of the second portion of the electroplated copper layer 724 of said each of its metal bonding pads 736a, and (3) an electroplating seed layer 722 having a first portion in said one of the openings 753a, at the top and sidewall of the first portion of the electroplated copper layer 724 of said each of its metal bonding pads 736a and between the first portion of the electroplated copper layer 724 of said each of its metal bonding pads 736a and the first portion of the adhesion metal layer 718 of said each of its metal bonding pads 736a and a second portion in said one of the openings 752a, at the top and sidewall of the second portion of the electroplated copper layer 724 of said each of its metal bonding pads 736a and between the second portion of the electroplated copper layer 724 of said each of its metal bonding pads 736a and the second portion of the adhesion metal layer 718 of said each of its metal bonding pads 736a.

For the sixth case as seen in FIG. 35D, the twenty-eighth type of FPMCP 351 may further include multiple metal bonding pads 736a each in one of the openings 752a in its insulating bonding layer 752 and one of the openings 753a in its insulating dielectric layer 753 and the bottommost two of the insulating dielectric layers 12 of the first interconnection scheme for a chip (FISC) 20 of one of its DFPIC or eFPIC chips 400 and multiple metal bonding pads 736b each in one of the openings 752b in its insulating bonding layer 752. Each of its metal bonding pads 736a may include (1) an electroplated copper layer 724 having a first portion in one of the openings 753a in its insulating dielectric layer 753 and the bottommost two of the insulating dielectric layers 12 of the first interconnection scheme for a chip (FISC) 20 of one of its DFPIC or eFPIC chips 400 and a second portion having a thickness between 0.1 and 7 micrometers, between 0.1 and 5 micrometers, between 0.2 and 2 micrometers or between 0.2 and 1 micrometer in one of the openings 752a in its insulating bonding layer 752 and under said one of the openings 753a and the bottom surface of its insulating dielectric layer 753, (2) an adhesion metal layer 718 having a first portion in said one of the openings 753a, at a top and sidewall of the first portion of the electroplated copper layer 724 of said each of its metal bonding pads 736a, between the first portion of the electroplated copper layer 724 of said each of its metal bonding pads 736a and the second bottommost one of the interconnection metal layers 6, i.e., the copper layer 24 thereof, of the first interconnection scheme for a chip (FISC) 20 of said one of its DFPIC or eFPIC chips 400 and on the bottommost one of the interconnection metal layers 6, i.e., the copper layer 24 thereof, of the first interconnection scheme for a chip (FISC) 20 of said one of its DFPIC or eFPIC chips 400 and a second portion in said one of the openings 752a, on the bottom surface of its insulating dielectric layer 753 and at a top and sidewall of the second portion of the electroplated copper layer 724 of said each of its metal bonding pads 736a, and (3) an electroplating seed layer 722 having a first portion in said one of the openings 753a, at the top and sidewall of the first portion of the electroplated copper layer 724 of said each of its metal bonding pads 736a and between the first portion of the electroplated copper layer 724 of said each of its metal bonding pads 736a and the first portion of the adhesion metal layer 718 of said each of its metal bonding pads 736a and a second portion in said one of the openings 752a, at the top and sidewall of the second portion of the electroplated copper layer 724 of said each of its metal bonding pads 736a and between the second portion of the electroplated copper layer 724 of said each of its metal bonding pads 736a and the second portion of the adhesion metal layer 718 of said each of its metal bonding pads 736a.

For the twenty-eighth type of FPMCP 351 for each of the fourth through sixth cases as seen in FIGS. 35, 35C and 35D, each of its metal bonding pads 736b may include (1) an electroplated copper layer 724 having a thickness between 0.1 and 7 micrometers, between 0.1 and 5 micrometers, between 0.2 and 2 micrometers or between 0.2 and 1 micrometer in one of the openings 752b in its insulating bonding layer 752 and under the bottom surface of its insulating dielectric layer 753, (2) an adhesion metal layer 718 in said one of the openings 752b, on the bottom surface of its insulating dielectric layer 753 and at a top and sidewall of the electroplated copper layer 724 of said each of its metal bonding pads 736b, and (3) an electroplating seed layer 722 in said one of the openings 752b, at the top and sidewall of the electroplated copper layer 724 of said each of its metal bonding pads 736b and between the electroplated copper layer 724 of said each of its metal bonding pads 736b and the adhesion metal layer 718 of said each of its metal bonding pads 736b. Each of its metal bonding pads 736a and 736b, i.e., the electroplated copper layer 724 thereof, may have a bottom surface coplanar with a bottom surface of its insulating bonding layer 752.

Referring to FIGS. 35, 35A, 35B, 35C and 35D, for the twenty-eighth type of FPMCP 351, the bottom surface of the electroplated copper layer 724 of each of its metal bonding pads 736a and a first group of its metal bonding pads 736b for the fourth case may be bonded to the top surface of the electroplated copper layer 724 of one of its metal bonding pads 136 for any case of the first through third cases via copper-to-copper bonding; alternatively, the bottom surface of the electroplated copper layer 724 of each of its metal bonding pads 736a and a first group of its metal bonding pads 736b for the fifth case may be bonded to the top surface of the electroplated copper layer 724 of one of its metal bonding pads 136 for any case of the first through third cases via copper-to-copper bonding; alternatively, the bottom surface of the electroplated copper layer 724 of each of its metal bonding pads 736a and a first group of its metal bonding pads 736b for the sixth case may be bonded to the top surface of the electroplated copper layer 724 of one of its metal bonding pads 136 for any case of the first through third cases via copper-to-copper bonding. Further, the bottom surface of its insulating bonding layer 752 may be bonded to the top surface of its insulating bonding layer 652 via oxide-to-oxide bonding. The bottom surface of the electroplated copper layer 724 of each of a second group of its metal bonding pads 736b may be bonded to the top surface of the electroplated copper layer 724 of one of its metal bonding pads 137 via copper-to-copper bonding. Each of a first combination of its metal bonding pads 736a and the first group of its metal bonding pads 736b may have the same width as one of a first combination of its metal bonding pads 136 with covering a first edge of said one of the first combination of its metal bonding pads 136 but without covering a second edge of said one of the first combination of its metal bonding pads 136 opposite to the first edge of said one of the first combination of its metal bonding pads 136, and said one of the first combination of its metal bonding pads 136 may cover a first edge of said each of the first combination of its metal bonding pads 736a and the first group of its metal bonding pads 736b but may not cover a second edge of said each of the first combination of its metal bonding pads 736a and the first group of its metal bonding pads 736b opposite to the first edge of said each of the first combination of its metal bonding pads 736a and the first group of its metal bonding pads 736b. Each of a second combination of its metal bonding pads 736a and the first group of its metal bonding pads 736b may have a width larger than that of one of a second combination of its metal bonding pads 136 with covering a first edge of said one of the second combination of its metal bonding pads 136 but without covering a second edge of said one of the second combination of its metal bonding pads 136 opposite to the first edge of said one of the second combination of its metal bonding pads 136, and said one of the second combination of its metal bonding pads 136 may cover a first edge of said each of the second combination of its metal bonding pads 736a and the first group of its metal bonding pads 736b but may not cover a second edge of said each of the second combination of its metal bonding pads 736a and the first group of its metal bonding pads 736b opposite to the first edge of said each of the second combination of its metal bonding pads 736a and the first group of its metal bonding pads 736b. Each of a third combination of its metal bonding pads 736a and the first group of its metal bonding pads 736b may have a width larger than that of one of a third combination of its metal bonding pads 136 with covering a first edge of said one of the third combination of its metal bonding pads 136 and a second edge of said one of the third combination of its metal bonding pads 136 opposite to the first edge of said one of the third combination of its metal bonding pads 136. Each of a fourth combination of its metal bonding pads 136 may have a width larger than that of one of a fourth combination of its metal bonding pads 736a and the first group of its metal bonding pads 736b with covering a first edge of said one of the fourth combination of its metal bonding pads 736a and the first group of its metal bonding pads 736b but without covering a second edge of said one of the fourth combination of its metal bonding pads 736a and the first group of its metal bonding pads 736b opposite to the first edge of said one of the fourth combination of its metal bonding pads 736a and the first group of its metal bonding pads 736b, and said one of the fourth combination of its metal bonding pads 736a and the first group of its metal bonding pads 736b may cover a first edge of said each of the fourth combination of its metal bonding pads 136 but may not cover a second edge of said each of the fourth combination of its metal bonding pads 136 opposite to the first edge of said each of the fourth combination of its metal bonding pads 136. Each of a fifth combination of its metal bonding pads 136 may have a width larger than that of one of a fifth combination of its metal bonding pads 736a and the first group of its metal bonding pads 736b with covering a first edge of said one of the fifth combination of its metal bonding pads 736a and the first group of its metal bonding pads 736b and a second edge of said one of the fifth combination of its metal bonding pads 736a and the first group of its metal bonding pads 736b opposite to the first edge of said one of the fifth combination of its metal bonding pads 736a and the first group of its metal bonding pads 736b. Further, each of a first combination of the second group of its metal bonding pads 736b may have the same width as one of a first combination of its metal bonding pads 137 with covering a first edge of said one of the first combination of its metal bonding pads 137 but without covering a second edge of said one of the first combination of its metal bonding pads 137 opposite to the first edge of said one of the first combination of its metal bonding pads 137, and said one of the first combination of its metal bonding pads 137 may cover a first edge of said each of the first combination of the second group of its metal bonding pads 736b but may not cover a second edge of said each of the first combination of the second group of its metal bonding pads 736b opposite to the first edge of said each of the first combination of the second group of its metal bonding pads 736b. Each of a second combination of the second group of its metal bonding pads 736b may have a width larger than that of one of a second combination of its metal bonding pads 137 with covering a first edge of said one of the second combination of its metal bonding pads 137 but without covering a second edge of said one of the second combination of its metal bonding pads 137 opposite to the first edge of said one of the second combination of its metal bonding pads 137, and said one of the second combination of its metal bonding pads 137 may cover a first edge of said each of the second combination of the second group of its metal bonding pads 736b but may not cover a second edge of said each of the second combination of the second group of its metal bonding pads 736b opposite to the first edge of said each of the second combination of the second group of its metal bonding pads 736b. Each of a third combination of the second group of its metal bonding pads 736b may have a width larger than that of one of a third combination of its metal bonding pads 137 with covering a first edge of said one of the third combination of its metal bonding pads 137 and a second edge of said one of the third combination of its metal bonding pads 137 opposite to the first edge of said one of the third combination of its metal bonding pads 137. Each of a fourth combination of its metal bonding pads 137 may have a width larger than that of one of a fourth combination of the second group of its metal bonding pads 736b with covering a first edge of said one of the fourth combination of the second group of its metal bonding pads 736b but without covering a second edge of said one of the fourth combination of the second group of its metal bonding pads 736b opposite to the first edge of said one of the fourth combination of the second group of its metal bonding pads 736b, and said one of the fourth combination of the second group of its metal bonding pads 736b may cover a first edge of said each of the fourth combination of its metal bonding pads 137 but may not cover a second edge of said each of the fourth combination of its metal bonding pads 137 opposite to the first edge of said each of the fourth combination of its metal bonding pads 137. Each of a fifth combination of its metal bonding pads 137 may have a width larger than that of one of a fifth combination of the second group of its metal bonding pads 736b with covering a first edge of said one of the fifth combination of the second group of its metal bonding pads 736b and a second edge of said one of the fifth combination of the second group of its metal bonding pads 736b opposite to the first edge of said one of the fifth combination of the second group of its metal bonding pads 736b. Each bonding structure of one of the second group of its metal bonding pads 736b and one of its metal bonding pads 137 may be vertically over its polymer layer 92 and not vertically over any of its semiconductor IC chips 269a, 269b, 269c, 200 and 251.

Referring to FIGS. 35, 35A, 35B, 35C and 35D, for the twenty-eighth type of FPMCP 351, multiple openings 96a may be formed in and through its polymer layer 192 and insulating dielectric layer 753, and the adhesion metal layer 718 of each of the first group of its metal bonding pads 736b under one of the openings 96a may be etched to make a top surface of the electroplating seed layer 722 of said each of the first group of its metal bonding pads 736b exposed by said one of the openings 96a. The twenty-eighth type of FPMCP 351 may further include multiple through package vias (TPVs) 96, i.e., metal posts or vias, each in one of the openings 96a and on the top surface of the electroplating seed layer 722 of one of the first group of its metal bonding pads 736b. Each of its through package vias (TPVs) 96 may include (1) an electroplated copper layer 824 having a thickness between 2 and 30 micrometers, between 3 and 20 micrometers, between 3 and 15 micrometers, between 3 and 10 micrometers or between 3 and 7 micrometers in one of the openings 96a and over the top surface of the electroplating seed layer 722 of one of the first group of its metal bonding pads 736b, (2) an adhesion metal layer 818 in said one of the openings 96a, on the top surface of the electroplating seed layer 722 of one of the first group of its metal bonding pads 736b and at a bottom and sidewall of the electroplated copper layer 824 of said each of its through package vias (TPVs) 96, and (3) an electroplating seed layer 822 in said one of the openings 96a, at the bottom and sidewall of the electroplated copper layer 824 of said each of its through package vias (TPVs) 96 and between the electroplated copper layer 824 of said each of its through package vias (TPVs) 96 and the adhesion metal layer 818 of said each of its through package vias (TPVs) 96. Each of its through package vias (TPVs) 96, i.e., the electroplated copper layer 824 thereof, may have a top surface coplanar with a top surface of its polymer layer 192. For the twenty-eighth type of FPMCP 351, none of its through package vias (TPVs) 96 may be provided on any bonding structure of one of the second group of its metal bonding pads 736b and one of its metal bonding pads 137.

Referring to FIG. 35, for the twenty-eighth type of FPMCP 351, the semiconductor substrate 2 of each of its DFPIC or eFPIC chips 400 may have a portion, at a backside of the semiconductor substrate 2 of said each of its DFPIC or eFPIC chips 400, removed by a chemical-mechanical-polishing (CMP) or mechanical grinding process such that each of the through silicon vias (TSVs) 157, that is, the electroplated copper layer 156 thereof, of each of its DFPIC or eFPIC chips 400 may be exposed. The twenty-eighth type of FPMCP 351 may further include the insulating dielectric layer 185, such as silicon-oxide layer or silicon-nitride layer, illustrated in FIG. 4C formed on a top surface of the semiconductor substrate 2 of each of its DFPIC or eFPIC chips 400, wherein its insulating dielectric layer 185 may have a top surface coplanar with the top surface of each of the through silicon vias 157, i.e., the electroplated copper layer 156 thereof, of each of its DFPIC or eFPIC chips 400, the top surface of its polymer layer 192 and the top surface of each of its through package vias (TPVs) 96, i.e., the electroplated copper layer 824 thereof.

Referring to FIG. 35, the twenty-eighth type of FPMCP 351 may further include an insulating dielectric layer 712 on the top surface of its insulating dielectric layer 185 and the top surface of its polymer layer 192. For the twenty-eighth type of FPMCP 351, its insulating dielectric layer 712 may include (1) a silicon-oxynitride layer 721 having a thickness between 0.05 and 0.2 micrometer on the top surface of its insulating dielectric layer 185 and the top surface of its polymer layer 192 and (2) a silicon-oxide layer 723 having a thickness between 0.1 and 2 micrometers, between 3 nm and 1,000 nm, between 10 nm and 500 nm or thinner than 5 nm, 10 nm, 30 nm, 50 nm, 100 nm, 200 nm, 300 nm, 500 nm or 1,000 nm on a top surface of the silicon-oxynitride layer 721 of its insulating dielectric layer 712. Each opening 712a of its insulating dielectric layer 712 may be vertically over a top surface of one or more of the through silicon vias (TSVs) 157 of one or more of its DFPIC or eFPIC chips 400 and/or a top surface of one or more of its through insulator vias (TIVs) 96. The twenty-eighth type of FPMCP 351 may further include an interconnection metal layer 996 in each of the openings 712a in its insulating dielectric layer 712 and on the top surface of the through silicon vias (TSVs) 157 of each of its DFPIC or eFPIC chips 400, the top surface of its through insulator vias (TIVs) 96, the top surface of its insulating dielectric layer 185 and the top surface of its polymer layer 192. Its interconnection metal layer 996 may include (1) an electroplated copper layer 84 having a thickness between 0.1 and 2 micrometers, between 3 nm and 1,000 nm or between 10 nm and 500 nm or thinner than or equal to 5 nm, 10 nm, 30 nm, 50 nm, 100 nm, 200 nm, 300 nm, 500 nm or 1,000 nm in each of the openings 712a in its insulating dielectric layer 712 and over the top surface of the through silicon vias (TSVs) 157 of each of its DFPIC or eFPIC chips 400, the top surface of its through insulator vias (TIVs) 96, the top surface of its insulating dielectric layer 185 and the top surface of its polymer layer 192, (2) an adhesion metal layer 78, such as titanium, titanium nitride, tantalum or tantalum nitride, having a thickness between 1 nm and 50 nm in each of the openings 712a in its insulating dielectric layer 712, at a bottom and sidewall of the electroplated copper layer 84 of its interconnection metal layer 996, between the electroplated copper layer 84 of its interconnection metal layer 996 and the top surface of the through silicon vias (TSVs) 157 of each of its DFPIC or eFPIC chips 400, between the electroplated copper layer 84 of its interconnection metal layer 996 and the top surface of its through insulator vias (TIVs) 96, between the electroplated copper layer 84 of its interconnection metal layer 996 and the top surface of its insulating dielectric layer 185, between the electroplated copper layer 84 of its interconnection metal layer 996 and the top surface of its polymer layer 192 and on the top surface of the through silicon vias (TSVs) 157 of each of its DFPIC or eFPIC chips 400, the top surface of its through insulator vias (TIVs) 96, the top surface of its insulating dielectric layer 185 and the top surface of its polymer layer 192, and (3) an electroplating seed layer 82, such as copper, in each of the openings 712a in its insulating dielectric layer 712, at a bottom and sidewall of the electroplated copper layer 84 of its interconnection metal layer 996 and between the electroplated copper layer 84 and adhesion metal layer 78 of its interconnection metal layer 996. Its interconnection metal layer 996 may be patterned with a metal line or trace having a thickness between 0.1 and 2 micrometers, between 3 nm and 1,000 nm, between 10 nm and 500 nm or thinner than or equal to 5 nm, 10 nm, 30 nm, 50 nm, 100 nm, 200 nm, 300 nm, 500 nm or 1,000 nm and a width between 3 nm and 1,000 nm or between 10 nm and 500 nm or narrower than 5 nm, 10 nm, 20 nm, 30 nm, 70 nm, 100 nm, 300 nm, 500 nm or 1,000 nm, for example. The insulating dielectric layer 612 may have a thickness between 0.1 and 2 micrometers, between 3 nm and 1,000 nm, between 10 nm and 500 nm or thinner than 5 nm, 10 nm, 30 nm, 50 nm, 100 nm, 200 nm, 300 nm, 500 nm or 1,000 nm.

Referring to FIG. 35, the twenty-eighth type of FPMCP 351 may further include an interconnection scheme 99 on a top surface of its insulating dielectric layer 712 and a top surface of its interconnection metal layer 996. For the twenty-eighth type of FPMCP 351, its interconnection scheme 99 may include (1) one or more interconnection metal layers 6 (only one is shown) coupling to each of its through insulator vias (TIVs) 96 and (2) one or more insulating dielectric layers 12 each between neighboring two of the one or more interconnection metal layers 6 of its interconnection scheme 99, under and on the bottommost one of the one or more interconnection metal layers 6 of its interconnection scheme 99 or over and on the topmost one of the one or more interconnection metal layers 6 of its interconnection scheme 99, wherein neighboring two of the one or more interconnection metal layers 6 of its interconnection scheme 99 may couple to each other through openings in one of the one or more insulating dielectric layers 12 of the interconnection scheme 99 therebetween, and the bottommost one of the one or more insulating dielectric layers 12 of its interconnection scheme 99 may be provided on the top surface of its insulating dielectric layer 712 and the top surface of its interconnection metal layer 996. Each of the interconnection metal layers 6 of its interconnection scheme 99 may have the same specification as that of the interconnection metal layer 6 of the FISC 20 as illustrated in FIG. 3A; each of the insulating dielectric layers 12 of its interconnection scheme 99 may have the same specification as that of the insulating dielectric layer 12 of the FISC 20 as illustrated in FIG. 3A. For more elaboration, each of the one or more interconnection metal layers 6 of its interconnection scheme 99 may include (1) a copper layer 24 having lower portions in openings in a lower one of the one or more insulating dielectric layers 12, such as silicon oxide or silicon oxycarbide (SiOC) layers each having a thickness between 3 nm and 500 nm, of its interconnection scheme 99 and upper portions having a thickness between 0.1 and 2 micrometers, between 3 nm and 1,000 nm, between 10 nm and 500 nm or thinner than or equal to 5 nm, 10 nm, 30 nm, 50 nm, 100 nm, 200 nm, 300 nm, 500 nm or 1,000 nm over the lower one of the one or more insulating dielectric layers 12 of its interconnection scheme 99 and in openings in an upper one of the one or more insulating dielectric layers 12 of its interconnection scheme 99, (2) an adhesion metal layer 18, such as titanium, titanium nitride, tantalum or tantalum nitride, having a thickness between 1 nm and 50 nm at a bottom and sidewall of each of the lower portions of the copper layer 24 of said each of the one or more interconnection metal layers 6 and at a bottom and sidewall of each of the upper portions of the copper layer 24 of said each of the one or more interconnection metal layers 6, and (3) a seed layer 22, such as copper, between the copper layer 24 and adhesion metal layer 18 of said each of the one or more interconnection metal layers 6, wherein the copper layer 24 of said each of the one or more interconnection metal layers 6 may have a top surface substantially coplanar with a top surface of the upper one of the one or more insulating dielectric layers 12. Each of the one or more interconnection metal layers 6 of its interconnection scheme 99 may be patterned with a metal line or trace having a thickness between 0.1 and 2 micrometers, between 3 nm and 1,000 nm, between 10 nm and 500 nm or thinner than or equal to 5 nm, 10 nm, 30 nm, 50 nm, 100 nm, 200 nm, 300 nm, 500 nm or 1,000 nm and a width between 3 nm and 1,000 nm or between 10 nm and 500 nm, or narrower than 5 nm, 10 nm, 20 nm, 30 nm, 70 nm, 100 nm, 300 nm, 500 nm or 1,000 nm, for example. Each of the one or more insulating dielectric layers 12 of its interconnection scheme 99 may be made of a layer of silicon oxide or silicon oxycarbide having a thickness between 0.1 and 2 micrometers, between 3 nm and 1,000 nm, between 10 nm and 500 nm or thinner than 5 nm, 10 nm, 30 nm, 50 nm, 100 nm, 200 nm, 300 nm, 500 nm or 1,000 nm. Its interconnection scheme 99 may further include (1) one or more interconnection metal layers 27 (only one is shown) over the one or more interconnection metal layers 6 and one or more insulating dielectric layers 12 of its interconnection scheme 99 and (2) one or more insulating dielectric layers 42 each between neighboring two of the one or more interconnection metal layers 27 of its interconnection scheme 99, under and on the bottommost one of the one or more interconnection metal layers 27 of its interconnection scheme 99 or over and on the topmost one of the one or more interconnection metal layers 27 of its interconnection scheme 99. Between the topmost one of the one or more interconnection metal layers 6 of its interconnection scheme 99 and the bottommost one of the one or more interconnection metal layers 27 of its interconnection scheme 99 may be (1) the topmost one of the one or more insulating dielectric layers 12 of its interconnection scheme 99 for a first aspect, (2) the topmost one of the one or more insulating dielectric layers 12 of its interconnection scheme 99 and the bottommost one of the one or more insulating dielectric layers 42 of its interconnection scheme 99 for a second aspect or (3) the bottommost one of the one or more insulating dielectric layers 42 of its interconnection scheme 99 for a third aspect. For the first aspect, the bottommost one of the one or more interconnection metal layers 27 of its interconnection scheme 99 may couple to the topmost one of the one or more interconnection metal layers 6 of its interconnection scheme 99 through one or more openings in the topmost one of the one or more insulating dielectric layers 12 of its interconnection scheme 99. For the second aspect, the bottommost one of the one or more interconnection metal layers 27 of its interconnection scheme 99 may couple to the topmost one of the one or more interconnection metal layers 6 of its interconnection scheme 99 through one or more openings in the topmost one of the one or more insulating dielectric layers 12 of its interconnection scheme 99 and the bottommost one of the one or more insulating dielectric layers 42 of its interconnection scheme 99. For the third aspect, the bottommost one of the one or more interconnection metal layers 27 of its interconnection scheme 99 may couple to the topmost one of the one or more interconnection metal layers 6 of its interconnection scheme 99 through one or more openings in the bottommost one of the one or more insulating dielectric layers 42 of its interconnection scheme 99. Each opening in the topmost one of the one or more insulating dielectric layers 42 of its interconnection scheme 99 may be vertically over a metal pad of the topmost one of the one or more interconnection metal layers 27 of its interconnection scheme 99. Each of the interconnection metal layers 27 of its interconnection scheme 99 may have the same specification as that of the interconnection metal layer 27 of the SISC 29 as illustrated in FIG. 3A; each of the insulating dielectric layers 42 of its interconnection scheme 99 may have the same specification as that of the insulating dielectric layer 42 of the SISC 29 as illustrated in FIG. 3A. For more elaboration, each of the one or more interconnection metal layers 27 of its interconnection scheme 99 may include (1) a bulk metal layer 40, such as copper layer having a thickness between 0.3 μm and 20 μm for a first aspect or aluminum layer having a thickness between 0.5 and 4 micrometers or between 1 and 3 micrometers for a second aspect, and (2) an adhesion metal layer 28a, such as titanium, titanium nitride, tantalum or tantalum nitride, having a thickness between 1 nm and 50 nm, at a bottom of the bulk metal layer 40 of said each of the one or more interconnection metal layers 27 but not at a sidewall of the bulk metal layer 40 of said each of the one or more interconnection metal layers 27. Alternatively, for the first aspect, said each of the one or more interconnection metal layers 27 may further include a seed layer 28b, such as copper, between the bulk metal layer 40 of said each of the one or more interconnection metal layers 27 and the adhesion metal layer 28a of said each of the one or more interconnection metal layers 27. Each of the one or more interconnection metal layers 27 of the interconnection scheme 99 may be patterned with a metal line or trace having a thickness between, for example, 0.3 μm and 20 μm, 0.5 μm and 10 μm, 1 μm and 5 μm, 1 μm and 10 μm, or 2 m and 10 μm, or thicker than or equal to 0.3 μm, 0.5 μm, 0.7 μm, 1 μm, 1.5 μm, 2 m or 3 m and a width between, for example, 0.3 μm and 20 μm, 0.5 μm and 10 μm, 1 μm and 5 μm, 1 μm and 10 μm, or 2 μm and 10 μm, or wider than or equal to 0.3 μm, 0.5 μm, 0.7 μm, 1 μm, 1.5 μm, 2 μm or 3 μm. Each of the one or more insulating dielectric layers 42 of its interconnection scheme 99 may be made of (1) a polymer layer, such as polyimide, benzocyclobutene (BCB), parylene, epoxy-based material or compound, photo epoxy SU-8, elastomer or silicone, having a thickness between 0.3 μm and 20 μm, 0.5 μm and 10 μm, 1 μm and 5 μm, or 1 μm and 10 m or thicker than or equal to 0.3 μm, 0.5 μm, 0.7 μm, 1 μm, 1.5 μm, 2 μm or 3 μm, or (2) an inorganic layer, such as silicon oxide, silicon oxynitride or silicon nitride, having a thickness between 0.5 μm and 3 μm. Alternatively, the one or more interconnection metal layers 27 and one or more insulating dielectric layers 42 may not be provided for its interconnection scheme 99, and the topmost one of the one or more insulating dielectric layers 12 of its interconnection scheme 99 may be provided on and over the topmost one of the one or more interconnection metal layers 6 of its interconnection scheme 99 with multiple openings therein each over a metal pad of the topmost one of the one or more interconnection metal layers 6 of its interconnection scheme 99 for the second alternative. Alternatively, the one or more interconnection metal layers 6 and one or more insulating dielectric layers 12 may not be provided for its interconnection scheme 99 and the bottommost one of the one or more insulating dielectric layers 42 of its interconnection scheme 99 may be provided on and over the top surface of its insulating dielectric layer 712 and the top surface of its interconnection metal layer 996, wherein the bottommost one of the one or more interconnection metal layers 27 of its interconnection scheme 99 may couple to each of the through insulator vias (TIVs) 96 through an opening in the bottommost one of the one or more insulating dielectric layers 42 of its interconnection scheme 99.

Referring to FIG. 35, the twenty-eighth type of FPMCP 351 may further include multiple metal bumps, pillars or pads 570 in an array at its top to act as its external pins for coupling to the external circuits, wherein each of its metal bumps, pillars or pads 570 may be of a type selected from various types, i.e., first and second types, having the same specification as that of the first and second types of metal bumps, pillars or pads 570 respectively as illustrated in FIG. 6A to be turned upside down, and may have the adhesion metal layer 26a on a top surface of one of the metal pads of the topmost one of the interconnection metal layers 27 of its interconnection scheme 99 and a top surface of the topmost one of the one or more polymer layers 42 of its interconnection scheme 99 or on a top surface of one of the metal pads of the topmost one of the interconnection metal layers 6 of its interconnection scheme 99 and a top surface of the topmost one of the one or more insulating dielectric layers 12 of its interconnection scheme 99.

Accordingly, referring to FIGS. 30, 35, 35A, 35B, 35C and 35D, for twenty-eighth type of FPMCP 351, neighboring two of its semiconductor IC chips 200, 269a, 269b, 269c and 251 may couple to each other through, in sequence, one of its metal bonding pads 136, one of its metal bonding pads 736a, one of the metal lines or traces 693 of one of its DFPIC or eFPIC chips 400 vertically over said neighboring two of its semiconductor IC chips 200, 269a, 269b, 269c and 251, another of its metal bonding pads 736a and another of its metal bonding pads 136. Each of its semiconductor IC chips 200, 269a, 269b, 269c and 251 may couple to one of its metal bumps, pillars or pads 570 for external connection (1) through, in sequence, one of its metal bonding pads 136, one of its metal bonding pads 736b, one of its through package vias (TPVs) 96 vertically over said each of its semiconductor IC chips 200, 269a, 269b, 269c and 251, its interconnection metal layer 996 and each of the interconnection metal layers 6 and/or 27 of its interconnection scheme 99 or (2) through, in sequence, one of its metal bonding pads 136, one of its metal bonding pads 736a, one of the through silicon vias (TSVs) 157 of one of its DFPIC or eFPIC chips 400 vertically over said each of its semiconductor IC chips 200, 269a, 269b, 269c and 251, its interconnection metal layer 996 and each of the interconnection metal layers 6 and/or 27 of its interconnection scheme 99. Each of its DFPIC or eFPIC chips 400 may couple to one of its metal bumps, pillars or pads 570 for external connection through, in sequence, its interconnection metal layer 996 and each of the interconnection metal layers 6 and/or 27 of its interconnection scheme 99.

Alternatively, referring to FIGS. 30, 35, 35A, 35B, 35C and 35D, for the twenty-eighth type of FPMCP 351, each of its DFPIC or eFPIC chips 400 may be vertically over neighboring two of its semiconductor IC chips 200, 269a, 269b, 269c and 251, wherein said each of its DFPIC or eFPIC chips 400 may couple to a first device of said neighboring two of its semiconductor IC chips 200, 269a, 269b, 269c and 251, through, in sequence, a first group of its metal bonding pads 736a over the first device and a first group of its metal bonding pads 136 over the first device and couple to a second device of said neighboring two of its semiconductor IC chips 200, 269a, 269b, 269c and 251 through, in sequence, a second group of its metal bonding pads 736a over the second device and a second group of its metal bonding pads 136 over the second device, wherein with regard to a left front one of the DFPIC or eFPIC chips 400 of its interconnection substrate 177, the first device may be the left one of its HBM IC chips 251 and the second device may be its CPU IC chip 269b, or in another case the first device may be its CPU IC chip 269b and the second device may be the left one of its HBM IC chips 251; with regard to a left rear one of the DFPIC or eFPIC chips 400 of its interconnection substrate 177, the first device may be the left one of its HBM IC chips 251 and the second device may be its GPU IC chip 269a, or in another case the first device may be its GPU IC chip 269a and the second device may be the left one of its HBM IC chips 251; with regard to a right front one of the DFPIC or eFPIC chips 400 of its interconnection substrate 177, the first device may be the right one of its HBM IC chips 251 and the second device may be its ASIC or SoC chip 269c, or in another case the first device may be its ASIC or SoC chip 269c and the second device may be the right one of its HBM IC chips 251; with regard to a right rear one of the DFPIC or eFPIC chips 400 of its interconnection substrate 177, the first device may be the right one of its HBM IC chips 251 and the second device may be its FPGA IC chip 200, or in another case the first device may be its FPGA IC chip 200 and the second device may be the right one of its HBM IC chips 251; with regard to a center front one of the DFPIC or eFPIC chips 400 of its interconnection substrate 177, the first device may be its CPU IC chip 269b and the second device may be its ASIC or SoC chip 269c, or in another case the first device may be its ASIC or SoC chip 269c and the second device may be its CPU IC chip 269b; with regard to a center rear one of the DFPIC or eFPIC chips 400 of its interconnection substrate 177, the first device may be its GPU IC chip 269a and the second device may be its FPGA IC chip 200, or in another case the first device may be its FPGA IC chip 200 and the second device may be its GPU IC chip 269a; with regard to a center left one of the DFPIC or eFPIC chips 400 of its interconnection substrate 177, the first device may be its CPU IC chip 269b and the second device may be its GPU IC chip 269, or in another case the first device may be its GPU IC chip 269 and the second device may be its CPU IC chip 269b; with regard to a center right one of the DFPIC or eFPIC chips 400 of its interconnection substrate 177, the first device may be its ASIC or SoC chip 269c and the second device may be its FPGA IC chip 200, or in another case the first device may be its FPGA IC chip 200 and the second device may be its ASIC or SoC chip 269c. Said each of its DFPIC or eFPIC chips 400 may include (1) the first type of field programmable logic cell or element (LCE) 2014 or 2014-2 as illustrated in FIGS. 1A, 4D and 4E, the data inputs A0 and A1 of which may couple to the first device through, in sequence, respective two of the small input/output (SIO) circuits 203, or metal pads or input/output (I/O) pads, of said each of its DFPIC or eFPIC chips 400, respectively two of the first group of its metal bonding pads 736a over the first device and respectively two of the first group of its metal bonding pads 136 over the first device, and the data output Dout of which may couple to the second device through, in sequence, another of the small input/output (SIO) circuits 203, or metal pads or input/output (I/O) pads, of said each of its DFPIC or eFPIC chips 400, one of the second group of its metal bonding pads 736a over the second device and one of the second group of its metal bonding pads 136 over the second device, (2) the second or third type of field programmable logic cell or element (LCE) 2014 or 2014-2 as illustrated in FIGS. 1B, 1C, 4D and 4E, the data inputs A0-A3 of which may couple to the first device through, in sequence, respective four of the small input/output (SIO) circuits 203, or metal pads or input/output (I/O) pads, of said each of its DFPIC or eFPIC chips 400, respective four of the first group of its metal bonding pads 736a over the first device and respectively four of the first group of its metal bonding pads 136 over the first device, and the data output Dout of which may couple to the second device through, in sequence, another of the small input/output (SIO) circuits 203, or metal pads or input/output (I/O) pads, of said each of its DFPIC or eFPIC chips 400, one of the second group of its metal bonding pads 736a over the second device and one of the second group of its metal bonding pads 136 over the second device, (3) the first type of field programmable switch cell 379 or 379-2 as illustrated in FIGS. 2A, 4D and 4E, the node N21 of which may couple to the first device through, in sequence, one of the small input/output (SIO) circuits 203, or metal pads or input/output (I/O) pads, of said each of its DFPIC or eFPIC chips 400, one of the first group of its metal bonding pads 736a over the first device and one of the first group of its metal bonding pads 136 over the first device, and the node N22 of which may couple to the second device through, in sequence, another of the small input/output (SIO) circuits 203, or metal pads or input/output (I/O) pads, of said each of its DFPIC or eFPIC chips 400, one of the second group of its metal bonding pads 736a over the second device and one of the second group of its metal bonding pads 136 over the second device, (4) the second type of field programmable switch cell 379 or 379-2 as illustrated in FIGS. 2B, 4D and 4E, the nodes N23 and N24 of which may couple to the first device through, in sequence, respective two of the small input/output (SIO) circuits 203, or metal pads or input/output (I/O) pads, of said each of its DFPIC or eFPIC chips 400, respectively two of the first group of its metal bonding pads 736a over the first device and respectively two of the first group of its metal bonding pads 136 over the first device, and the nodes N25 and N26 of which may couple to the second device through, in sequence, another respective two of the small input/output (SIO) circuits 203, or metal pads or input/output (I/O) pads, of said each of its DFPIC or eFPIC chips 400, respective two of the second group of its metal bonding pads 736a over the second device and respective two of the second group of its metal bonding pads 136 over the second device, to control coupling from the node N23 to one or more of the nodes N24-N26 or to control coupling from the node N26 to one or more of the nodes N23-N25, (5) the field programmable switch matrix 710 or 710-3 as illustrated in FIGS. 2C, 4D and 4E, each of the nodes P₁-P_{N} of which may couple to the first device through, in sequence, one of the first metal lines 281 of said each of its DFPIC or eFPIC chips 400, one of the small input/output (SIO) circuits 203, or metal pads or input/output (I/O) pads, of said each of its DFPIC or eFPIC chips 400, one of the first group of its metal bonding pads 736a over the first device and one of the first group of its metal bonding pads 136 over the first device, each of the nodes Q₁-Q_{M} of which may couple to the second device through, in sequence, one of the second metal lines 282 of said each of its DFPIC or eFPIC chips 400, another of the small input/output (SIO) circuits 203, or metal pads or input/output (I/O) pads, of said each of its DFPIC or eFPIC chips 400, one of the second group of its metal bonding pads 736a over the second device and one of the second group of its metal bonding pads 136 over the second device, and each of the pass/no-pass switches 778 of which may control coupling between the first and second devices, i.e., between one of the first group of its metal bonding pads 736a over the first device and one of the second group of its metal bonding pads 736a over the second device, and/or (6) the field programmable switch matrix 710-2 as illustrated in FIGS. 2C and 4E, each of some of the nodes P₁-P_{N} of which may couple to the first device through, in sequence, one of the first metal lines 281 of said each of its DFPIC or eFPIC chips 400, one of the small input/output (SIO) circuits 203, or metal pads or input/output (I/O) pads, of said each of its DFPIC or eFPIC chips 400, one of the first group of its metal bonding pads 736a over the first device and one of the first group of its metal bonding pads 136 over the first device, each of the other some of the nodes P₁-P_{N} of which may couple to the second device through, in sequence, another of the first metal lines 281 of said each of its DFPIC or eFPIC chips 400, another of the small input/output (SIO) circuits 203, or metal pads or input/output (I/O) pads, of said each of its DFPIC or eFPIC chips 400, one of the second group of its metal bonding pads 736a over the second device and one of the second group of its metal bonding pads 136 over the second device, and each of the pass/no-pass switches 778 of which may control coupling between one of the first and second devices and one of the internal circuits of the fourth one of the ASIC cores 215 of said each of its DFPIC or eFPIC chips 400, i.e., between one of the first and second groups of its metal bonding pads 736a over the first and second devices and one of the internal circuits of the fourth one of the ASIC cores 215 of said each of its DFPIC or eFPIC chips 400.

### Twenty-Ninth Type of FPMCP

FIG. 36 is a schematically cross-sectional view showing a twenty-ninth type of FPMCP in accordance with an embodiment of the present application. Referring to FIG. 36, the twenty-ninth type of FPMCP 355 may be provided with a bottom chip package 513 including (1) a logic chip, such as FPGA IC chip 200 having the same specification as one illustrated in FIGS. 5A-5, or a computing integrated-circuit (IC) chip 220, such as graphic-processing-unit (GPU) IC chip, central-processing-unit (CPU) IC chip or application-specific integrated-circuit (ASIC) chip or system-on-chip (SoC) IC chip, (2) a volatile memory (VM) IC chip 258, (2) a polymer layer 92 or insulating dielectric layer, such as molding compound, epoxy-based material or polyimide, horizontally around its FPGA IC chip 200, or its computing IC chip 220 in case of replacing its FPGA IC chip 200, and horizontally around its volatile memory (VM) IC chip 258, (3) multiple through package vias (TPVs) 158 vertically in and through its polymer layer 92, wherein each of its through package vias (TPVs) 158 may have a top surface coplanar with a top surface of its polymer layer 92 and a bottom surface coplanar with a bottom surface of its polymer layer 92, (4) a frontside interconnection scheme for a device (FISD) 101 under its FPGA IC chip 200, or its computing IC chip 220 in case of replacing its FPGA IC chip 200, and under its volatile memory (VM) IC chip 258, polymer layer 92 and through package vias (TPVs) 158, (5) a backside interconnection scheme for a device (BISD) 79 over its FPGA IC chip 200, or its computing IC chip 220 in case of replacing its FPGA IC chip 200, and over its volatile memory (VM) IC chip 258, polymer layer 92 and through package vias (TPVs) 158, and (6) multiple metal bumps, pillars or pads 570 in an array at its bottom to act as its external pins for coupling to external circuits outside of the twenty-ninth type of FPMCP 355, wherein each of its metal bumps, pillars or pads 570 may be formed on a bottom surface of its frontside interconnection scheme for a device (FISD) 101. Its FPGA IC chip 200, or its computing IC chip 220 in case of replacing its FPGA IC chip 200, may have the same specification as the third type of semiconductor IC chip 100 illustrated in FIG. 3C. Its volatile memory (VM) IC chip 258 may have the same specification as the third type of semiconductor IC chip 100 illustrated in FIG. 3C. Each of the first type of micro-bumps, micro-pillars or micro-pads 34 of its FPGA IC chip 200, or each of the first type of micro-bumps, micro-pillars or micro-pads 34 of its computing IC chip 220 in case of replacing its FPGA IC chip 200, and each of the first type of micro-bumps, micro-pillars or micro-pads 34 of its volatile memory (VM) IC chip 258 may couple to its frontside interconnection scheme for a device (FISD) 101, and the bottom surface of the polymer layer 257 of its FPGA IC chip 200, or the bottom surface of the polymer layer 257 of its computing IC chip 220 in case of replacing its FPGA IC chip 200, may be substantially coplanar with the bottom surface of each of the first type of micro-bumps, micro-pillars or micro-pads 34 of its FPGA IC chip 200, or the bottom surface of each of the first type of micro-bumps, micro-pillars or micro-pads 34 of its computing IC chip 220 in case of replacing its FPGA IC chip 200, and with the bottom surface of each of the first type of micro-bumps, micro-pillars or micro-pads 34 of its volatile memory (VM) IC chip 258, the bottom surface of the polymer layer 257 of its volatile memory (VM) IC chip 258, the bottom surface of its polymer layer 92 and the bottom surface of each of its through package vias (TPVs) 158. The top surface of each of its through package vias (TPVs) 158 may couple to its backside interconnection scheme for a device (BISD) 79, and the bottom surface of each of its through package vias (TPVs) 158 may couple to its frontside interconnection scheme for a device (FISD) 101. Its polymer layer 92 may have a vertical sidewall coplanar with a vertical sidewall of its frontside interconnection scheme for a device (FISD) 101 and a vertical sidewall of its backside interconnection scheme for a device (BISD) 79. Each of its through package vias (TPVs) 158 may be made of a copper layer having a height or thickness between 20 μm and 300 μm, 30 μm and 200 μm, 50 μm and 150 μm, 50 μm and 120 μm, 20 μm and 100 μm, 10 μm and 100 μm, 20 μm and 60 μm, 20 μm and 40 μm, or 20 m and 30 μm, or greater than or equal to 100 μm, 50 μm, 30 μm or m.

Referring to FIG. 36, for the bottom chip package 513 of the twenty-ninth type of FPMCP 355, its frontside interconnection scheme for a device (FISD) 101 may include (1) multiple interconnection metal layers 27 coupling to each of the first type of micro-bumps, micro-pillars or micro-pads 34 of its FPGA IC chip 200, or each of the first type of micro-bumps, micro-pillars or micro-pads 34 of its computing IC chip 220 in case of replacing its FPGA IC chip 200, and to each of the first type of micro-bumps, micro-pillars or micro-pads 34 of its volatile memory (VM) IC chip 258 and each of its through package vias (TPVs) 158 and (2) one or more polymer layers 42, i.e., insulating dielectric layers, each between neighboring two of the interconnection metal layers 27 of its frontside interconnection scheme for a device (FISD) 101, under the bottommost one of the interconnection metal layers 27 of its frontside interconnection scheme for a device (FISD) 101 or over the topmost one of the interconnection metal layers 27 of its frontside interconnection scheme for a device (FISD) 101, wherein a lower one of the interconnection metal layers 27 of its frontside interconnection scheme for a device (FISD) 101 may couple to an upper one of the interconnection metal layers 27 its frontside interconnection scheme for a device (FISD) 101 through an opening in one of the polymer layers 42 of its frontside interconnection scheme for a device (FISD) 101 between the upper and lower ones of the interconnection metal layers 27 of its frontside interconnection scheme for a device (FISD) 101. The topmost one of the polymer layers 42 of its frontside interconnection scheme for a device (FISD) 101 may have a top surface in contact with the bottom surface of the polymer layer 257 of its FPGA IC chip 200, or the bottom surface of the polymer layer 257 of its computing IC chip 220 in case of replacing its FPGA IC chip 200, and with the bottom surface of the polymer layer 257 of its volatile memory (VM) IC chip 258, the bottom surface of its polymer layer 92 and the bottom surface of each of its through package vias (TPVs) 158. Each opening in the topmost one of the polymer layers 42 of its frontside interconnection scheme for a device (FISD) 101 may be under one of the first type of micro-bumps, micro-pillars or micro-pads 34 of its FPGA IC chip 200, or one of the first type of micro-bumps, micro-pillars or micro-pads 34 of its computing IC chip 220 in case of replacing its FPGA IC chip 200, or under one of the first type of micro-bumps, micro-pillars or micro-pads 34 of its volatile memory (VM) IC chip 258 or the bottom surface of one of its through package vias (TPVs) 158, and thus the topmost one of the interconnection metal layers 27 of its frontside interconnection scheme for a device (FISD) 101 may couple to said one of the first type of micro-bumps, micro-pillars or micro-pads 34 or the bottom surface of said one of its through package vias (TPVs) 158 through said each opening. Each of the interconnection metal layers 27 of its frontside interconnection scheme for a device (FISD) 101 may extend horizontally across an edge of its FPGA IC chip 200, or an edge of its computing IC chip 220 in case of replacing its FPGA IC chip 200, and horizontally across an edge of its volatile memory (VM) IC chip 258. The bottommost one of the interconnection metal layers 27 of its frontside interconnection scheme for a device (FISD) 101 may have multiple metal pads at tops of multiple respective openings in the bottommost one of the polymer layers 42 of its frontside interconnection scheme for a device (FISD) 101. The specification and process for the interconnection metal layers 27 and polymer layers 42 for its frontside interconnection scheme for a device (FISD) 101 may be referred to those for the frontside interconnection scheme for a device (FISD) 101 as illustrated in FIG. 24.

Referring to FIG. 36, for the bottom chip package 513 of the twenty-ninth type of FPMCP 355, its backside interconnection scheme for a device (BISD) 79 may include (1) multiple interconnection metal layers 27 coupling to each of its through package vias (TPVs) 158 and (2) one or more polymer layers 42, i.e., insulating dielectric layers, each between neighboring two of the interconnection metal layers 27 of its backside interconnection scheme for a device (BISD) 79, under the bottommost one of the interconnection metal layers 27 of its backside interconnection scheme for a device (BISD) 79 or over the topmost one of the interconnection metal layers 27 of its backside interconnection scheme for a device (BISD) 79, wherein an upper one of the interconnection metal layers 27 of its backside interconnection scheme for a device (BISD) 79 may couple to a lower one of the interconnection metal layers 27 its backside interconnection scheme for a device (BISD) 79 through an opening in one of the polymer layers 42 of its backside interconnection scheme for a device (BISD) 79 between the upper and lower ones of the interconnection metal layers 27 of its backside interconnection scheme for a device (BISD) 79. The bottommost one of the polymer layers 42 of its backside interconnection scheme for a device (BISD) 79 may have a bottom surface in contact with the top surface of the semiconductor substrate 2 of its FPGA IC chip 200, or the top surface of the semiconductor substrate 2 of its computing IC chip 220 in case of replacing its FPGA IC chip 200, and with the top surface of the semiconductor substrate 2 of its volatile memory (VM) IC chip 258, the top surface of its polymer layer 92 and the top surface of each of its through package vias (TPVs) 158. Each opening in the bottommost one of the polymer layers 42 of its backside interconnection scheme for a device (BISD) 79 may be over the top surface of one of its through package vias (TPVs) 158, and thus the bottommost one of the interconnection metal layers 27 of its backside interconnection scheme for a device (BISD) 79 may couple to the top surface of said one of its through package vias (TPVs) 158 through said each opening. Each of the interconnection metal layers 27 of its backside interconnection scheme for a device (BISD) 79 may extend horizontally across an edge of its FPGA IC chip 200, or an edge of its computing IC chip 220 in case of replacing its FPGA IC chip 200, and horizontally across an edge of its volatile memory (VM) IC chip 258. The topmost one of the interconnection metal layers 27 of its backside interconnection scheme for a device (BISD) 79 may have multiple metal pads at bottoms of multiple respective openings in the topmost one of the polymer layers 42 of its backside interconnection scheme for a device (BISD) 79. The specification and process for the interconnection metal layers 27 and polymer layers 42 for its backside interconnection scheme for a device (BISD) 79 may be referred to those for the backside interconnection scheme for a device (BISD) 79 as illustrated in FIG. 24.

Referring to FIG. 36, for the bottom chip package 513 of the twenty-ninth type of FPMCP 355, each of its metal bumps, pillars or pads 570 may be of a type selected from various types, i.e., first and second types, which may have the same specification as that of the first and second types of metal bumps, pillars or pads 570 respectively as illustrated in FIG. 7 to be turned upside down, and may have the adhesion layer 26a on a bottom surface of one of the metal pads of the bottommost one of the interconnection metal layers 27 of its frontside interconnection scheme for a device (FISD) 101 and a bottom surface of the bottommost one of the polymer layers 42 of its frontside interconnection scheme for a device (FISD) 101.

Referring to FIG. 36, the twenty-ninth type of FPMCP 355 may further include a non-volatile-memory (NVM) chip package 336 over its bottom chip package 513. For the twenty-ninth type of FPMCP 355, its non-volatile-memory (NVM) chip package 336 may have the same specification as one illustrated for the eleventh type of FPMCP 314 for the first alternative in FIG. 19. For an element indicated by the same reference number shown in FIGS. 19 and 36, the specification of the element as seen in FIG. 36 may be referred to that of the element as illustrated in FIG. 19. Each of the solder balls 337 of its non-volatile-memory (NVM) chip package 336 may have a bottom end bonded to one of the metal pads of the topmost one of the interconnection metal layers 27 of the backside interconnection scheme for a device (BISD) 79 of its bottom chip package 513. The twenty-ninth type of FPMCP 355 may further include an underfill 564, i.e., polymer layer, between the circuit board 335 of its non-volatile-memory (NVM) chip package 336 and its bottom chip package 511, covering a sidewall of each of the solder balls 337 of its non-volatile-memory (NVM) chip package 336.

Referring to FIG. 36, for the twenty-ninth type of FPMCP 355, the FPGA IC chip 200 of its bottom chip package 513, or the computing IC chip 220 of its bottom chip package 513 in case of replacing the FPGA IC chip 200 thereof, may couple to one of the metal bumps, pillars or pads 570 of its bottom chip package 513 through each of the interconnection metal layers 27 of the frontside interconnection scheme for a device (FISD) 101 of its bottom chip package 513. The volatile memory (VM) IC chip 258 of its bottom chip package 513 may couple to one of the metal bumps, pillars or pads 570 of its bottom chip package 513 through each of the interconnection metal layers 27 of the frontside interconnection scheme for a device (FISD) 101 of its bottom chip package 513. Each of the two NVM IC chips 250 of its non-volatile-memory (NVM) chip package 336 may couple to one of the metal bumps, pillars or pads 570 of its bottom chip package 513 through, in sequence, one of the wirebonded wires 333 of its non-volatile-memory (NVM) chip package 336, the circuit board 335 of its non-volatile-memory (NVM) chip package 336, one of the solder balls 337 of its non-volatile-memory (NVM) chip package 336, each of the interconnection metal layers 27 of the backside interconnection scheme for a device (BISD) 79 of its bottom chip package 513, one of the through package vias (TPVs) 158 of its bottom chip package 513 and each of the interconnection metal layers 27 of the frontside interconnection scheme for a device (FISD) 101 of its bottom chip package 513.

Referring to FIG. 36, for fabricating a ball-grid-array (BGA) chip package, the twenty-ninth type of FPMCP 355 may be bonded to a ball-grid-array (BGA) substrate 537 that may have the same specification as that illustrated in FIG. 19-1. For an element indicated by the same reference number for the ball-grid-array (BGA) substrate 537 shown in FIGS. 19-1 and 36, the specification of the element as seen in FIG. 36 may be referred to that of the element as illustrated in FIG. 19-1. For more elaboration, each of the metal bumps, pillars or pads 570 of the twenty-ninth type of FPMCP 355 may be bonded to one of the metal pads 529 of the topmost one of the interconnection metal layers 668 of the ball-grid-array (BGA) substrate 537. An underfill 564, i.e., polymer layer, may be filled into a gap between the frontside interconnection scheme for a device (FISD) 101 of the bottom chip package 513 of the twenty-ninth type of FPMCP 355 and the ball-grid-array (BGA) substrate 537, covering a sidewall of each of the metal bumps, pillars or pads 570 of the twenty-ninth type of FPMCP 355. Multiple solder balls 538, made of a tin-lead alloy or tin-silver-copper alloy, may be formed in an array and each of the solder balls 538 may be formed on a bottom surface of one of the metal pads 528 of the bottommost one of the interconnection metal layers of the ball-grid-array (BGA) substrate 537.

Referring to FIG. 36, for the twenty-ninth type of FPMCP 355, in case that its bottom chip package 513 is packaged with the FPGA IC chip 200 and VM IC chip 258, for a configuration mode either of the NVM IC chips 250 of its non-volatile-memory (NVM) chip package 336 may include multiple large input/output (LIO) circuits, each of a first group of which may have a first large receiver or metal input/output (I/O) pad for receiving first CPM data from a circuit external of the twenty-ninth type of FPMCP 355, such as the ball-grid-array (BGA) substrate 537, through, in sequence, one of the metal bumps, pillars or pads 570 of its bottom chip package 513, each of the interconnection metal layers 27 of the frontside interconnection scheme for a device (FISD) 101 of its bottom chip package 513, one of a first group of the through package vias (TPVs) 158 of its bottom chip package 513, each of the interconnection metal layers 27 of the backside interconnection scheme for a device (BISD) 79 of its bottom chip package 513, one of a first group of the solder balls 337 of its non-volatile-memory (NVM) chip package 336, the circuit board 335 of its non-volatile-memory (NVM) chip package 336 and one of a first group of the wirebonded wires 333 of its non-volatile-memory (NVM) chip package 336, for storing the first CPM data in one of a first group of non-volatile memory cells (NVMCs) of said either of the NVM IC chips 250 of its non-volatile-memory (NVM) chip package 336. Each of a second group of the large input/output (LIO) circuits of said either of the NVM IC chips 250 of its non-volatile-memory (NVM) chip package 336 may have a first large driver coupling to a second large receiver, i.e., input buffer 273 as seen in FIG. 5I, or metal input/output (I/O) pad of one of large input/output (LIO) circuits of the VM IC chip 258 of its bottom chip package 513 through, in sequence, one of a second group of the wirebonded wires 333 of its non-volatile-memory (NVM) chip package 336, the circuit board 335 of its non-volatile-memory (NVM) chip package 336, one of a second group of the solder balls 337 of its non-volatile-memory (NVM) chip package 336, each of the interconnection metal layers 27 of the backside interconnection scheme for a device (BISD) 79 of its bottom chip package 513, one of a second group of the through package vias (TPVs) 158 of its bottom chip package 513, one or more of the interconnection metal layers 27 of the frontside interconnection scheme for a device (FISD) 101 of its bottom chip package 513 and one of a first group of the first type of micro-bumps, micro-pillars or micro-pads 34 of the volatile memory (VM) IC chip 258 of its bottom chip package 513 and for passing the first CPM data from the first large driver to the second large receiver to be stored in one of a first group of volatile memory cells, such as dynamic random-access memory (DRAM) or static random-access memory (SRAM) cells, of its VM IC chip 258. It is noted that each of the large input/output (LIO) circuits of said either of the NVM IC chips 250 of its non-volatile-memory (NVM) chip package 336 and each of the large input/output (LIO) circuits of the VM IC chip 258 of its bottom chip package 513 may have an I/O power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, between 2 pF and 5 pF, or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts. The volatile memory (VM) IC chip 258 of its bottom chip package 513 may include the voltage-level shift-down circuit 207, as seen in FIG. 5I, for shifting the first CPM data to be carried with the voltage VddL of low-voltage power supply and then the volatile memory (VM) IC chip 258 of its bottom chip package 513 may include small input/output (SIO) circuits each having a first small driver, i.e., output buffer 272 as seen in FIG. 5I, or metal input/output (I/O) pad coupling to a first small receiver or metal input/output (I/O) pad of one of small input/output (SIO) circuits of the FPGA IC chip 200 of its bottom chip package 513 through, in sequence, one of a second group of the first type of micro-bumps, micro-pillars or micro-pads 34 of the volatile memory (VM) IC chip 258 of its bottom chip package 513, one or more of the interconnection metal layers 27 of the frontside interconnection scheme for a device (FISD) 101 of its bottom chip package 513 and one of the first type of micro-bumps, micro-pillars or micro-pads 34 of the FPGA IC chip 200 of its bottom chip package 513 and for passing the first CPM data from the first small driver to the first small receiver. Next, the memory cells 490 of one of the first type of field programmable logic cells or elements (LCEs) 2014, as illustrated in FIG. 1A, of the FPGA IC chip 200 of its bottom chip package 513 or the memory cells of one of the second or third type of field programmable logic cells or elements (LCEs) 2014, as illustrated in FIGS. 1B-1C, of the FPGA IC chip 200 of its bottom chip package 513 may store therein data associated with the first CPM data to be programmed, configured or reconfigured in accordance with the first CPM data, and/or the memory cell(s) 362 of the first type of field programmable switch cells 379, as illustrated in FIG. 2A, of the FPGA IC chip 200 of its bottom chip package 513 or the four sets of memory cell(s) 362 of the second type of field programmable switch cells 379, as illustrated in FIG. 2B, of the FPGA IC chip 200 of its bottom chip package 513 may store therein data associated with the first CPM data to be programmed, configured or reconfigured in accordance with the first CPM data. It is noted that each of the small input/output (SIO) circuits of the volatile memory (VM) IC chip 258 of its bottom chip package 513 and each of the small input/output (SIO) circuits of the FPGA IC chip 200 of its bottom chip package 513 may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts, 0.7 volts or 0.5 volts and/or a voltage swing equal to or smaller than 1.2 volts, 1 volt, 0.8 volts, 0.7 volts or 0.5 volts, for example. Communication between the large input/output (LIO) circuits of said either of the NVM IC chips 250 of its non-volatile-memory (NVM) chip package 336 and the large input/output (LIO) circuits of the VM IC chip 258 of its bottom chip package 513 may be in accordance with a protocol of Serial Advanced Technology Attachment (SATA) for data serial transmission; communication between the small input/output (SIO) circuits of the VM IC chip 258 of its bottom chip package 513 and the small input/output (SIO) circuits of the FPGA IC chip 200 of its bottom chip package 513 may be in accordance with a protocol of Peripheral Component Interconnect Express (PCIe) for data parallel transmission. Furthermore, for a backup mode each of the small input/output (SIO) circuits 209 of the FPGA IC chip 200 of its bottom chip package 513 may have a first small driver or metal input/output (I/O) pad coupling to a second small receiver of one of the small input/output (SIO) circuits 217 of the VM IC chip 258 of its bottom chip package 513 through, in sequence, one of the first type of micro-bumps, micro-pillars or micro-pads 34 of the FPGA IC chip 200 of its bottom chip package 513, one or more of the interconnection metal layers 27 of the frontside interconnection scheme for a device (FISD) 101 of its bottom chip package 513 and one of the second group of the first type of micro-bumps, micro-pillars or micro-pads 34 of the volatile memory (VM) IC chip 258 of its bottom chip package 513 and for passing second CPM data, associated with data stored (1) in the memory cells 490 of one of the first type of field programmable logic cells or elements (LCEs) 2014, as illustrated in FIG. 1A, of the FPGA IC chip 200 of its bottom chip package 513 or the memory cells of one of the second or third type of field programmable logic cell or elements (LCEs) 2014, as illustrated in FIGS. 1B-1C, of the FPGA IC chip 200 of its bottom chip package 513 and/or (2) in the memory cell(s) 362 of the first type of field programmable switch cells 379, as illustrated in FIG. 2A, of the FPGA IC chip 200 of its bottom chip package 513 or the four sets of memory cell(s) 362 of the second type of field programmable switch cells 379, as illustrated in FIG. 2B, of the FPGA IC chip 200 of its bottom chip package 513, from the second small driver to the second small receiver to be stored in one of the first group of the volatile memory cells 218 of the VM IC chip 258 of its bottom chip package 513. The volatile memory (VM) IC chip 258 of its bottom chip package 513 may include the voltage-level shift-up circuit 206, as seen in FIG. 5H, for shifting the second CPM data to be carried with the voltage VddH of high-voltage power supply and then the volatile memory (VM) IC chip 258 of its bottom chip package 513 may include the large input/output (LIO) circuits each having a second large driver, i.e., output buffer 274 as seen in FIG. 5H, or metal input/output (I/O) pad coupling to a third large receiver or metal input/output (I/O) pad of the second group of the large input/output (LIO) circuits of said either of the NVM IC chips 250 of its non-volatile-memory (NVM) chip package 336 through, in sequence, one of the second group of the first type of micro-bumps, micro-pillars or micro-pads 34 of the volatile memory (VM) IC chip 258 of its bottom chip package 513, one or more of the interconnection metal layers 27 of the frontside interconnection scheme for a device (FISD) 101 of its bottom chip package 513, one of the second group of the through package vias (TPVs) 158 of its bottom chip package 513, each of the interconnection metal layers 27 of the backside interconnection scheme for a device (BISD) 79 of its bottom chip package 513, one of the second group of the solder balls 337 of its non-volatile-memory (NVM) chip package 336, the circuit board 335 of its non-volatile-memory (NVM) chip package 336 and one of the second group of the wirebonded wires 333 of its non-volatile-memory (NVM) chip package 336 and for passing the second CPM data from the second large driver to the third large receiver to be stored in one of the first group of non-volatile memory cells (NVMCs) of said either of the NVM IC chips 250 of its non-volatile-memory (NVM) chip package 336. Next, each of the first group of the large input/output (I/O) circuits of said either of the NVM IC chips 250 of its non-volatile-memory (NVM) chip package 336 may have a third large driver for passing the second CPM data to a circuit external of the twenty-ninth type of FPMCP 355, such as the ball-grid-array (BGA) substrate 537, through, in sequence, one of the first group of the wirebonded wires 333 of its non-volatile-memory (NVM) chip package 336, the circuit board 335 of its non-volatile-memory (NVM) chip package 336, one of the first group of the solder balls 337 of its non-volatile-memory (NVM) chip package 336, each of the interconnection metal layers 27 of the backside interconnection scheme for a device (BISD) 79 of its bottom chip package 513, one of the first group of the through package vias (TPVs) 158 of its bottom chip package 513, each of the interconnection metal layers 27 of the frontside interconnection scheme for a device (FISD) 101 of its bottom chip package 513 and one of the metal bumps, pillars or pads 570 of its bottom chip package 513.

Referring to FIG. 36, for the twenty-ninth type of FPMCP 355, in case that its bottom chip package 513 is packaged with the FPGA IC chip 200 and VM IC chip 258, for an operation mode the first large receiver or metal input/output (I/O) pad of each of the first group of the large input/output (LIO) circuits of said either of the NVM IC chips 250 of its non-volatile-memory (NVM) chip package 336 may receive first operation data from a circuit external of the twenty-ninth type of FPMCP 355, such as the ball-grid-array (BGA) substrate 537, for storing the first operation data in one of a second group of non-volatile memory cells (NVMCs) of said either of the NVM IC chips 250 of its non-volatile-memory (NVM) chip package 336. Each of the second group of the large input/output (LIO) circuits of said either of the NVM IC chips 250 of its non-volatile-memory (NVM) chip package 336 may have the first large driver coupling to the second large receiver, i.e., input buffer 273 as seen in FIG. 5I, or metal input/output (I/O) pad of one of the large input/output (LIO) circuits of the VM IC chip 258 of its bottom chip package 513 for passing the first operation data from the first large driver to the second large receiver to be stored in one of a second group of the volatile memory cells of its VM IC chip 258. The volatile memory (VM) IC chip 258 of its bottom chip package 513 may include the voltage-level shift-down circuit 207, as seen in FIG. 5I, for shifting the first operation data to be carried with the voltage VddL of low-voltage power supply and then the volatile memory (VM) IC chip 258 of its bottom chip package 513 may include the small input/output (SIO) circuits each having the first small driver, i.e., output buffer 272 as seen in FIG. 5I, or metal input/output (I/O) pad coupling to the first small receiver or metal input/output (I/O) pad of one of the small input/output (SIO) circuits of the FPGA IC chip 200 of its bottom chip package 513 for passing the first operation data from the first small driver to the first small receiver. Next, one of the first type of field programmable logic cells or elements (LCEs) 2014, as illustrated in FIG. 1A, of the FPGA IC chip 200 of its bottom chip package 513 may have a piece of input data in its input data set, i.e., A0 and A1, which is associated with the first operation data, or one of the second or third type of field programmable logic cells or elements (LCEs) 2014, as illustrated in FIGS. 1B-1C, of the FPGA IC chip 200 of its bottom chip package 513 may have a piece of input data in its input data set, i.e., A0-A3, which is associated with the first operation data. Alternatively, one of the nodes N21 and N22 of the first type of field programmable switch cells 379, as illustrated in FIG. 2A, of the FPGA IC chip 200 of its bottom chip package 513 may have a piece of input data associated with the first operation data, or one of the nodes N23-N26 of the second type of field programmable switch cells 379, as illustrated in FIG. 2B, of the FPGA IC chip 200 of its bottom chip package 513 may have a piece of input data associated with the first operation data. Furthermore, for the backup mode each of the small input/output (SIO) circuits of the FPGA IC chip 200 of its bottom chip package 513 may have the second small driver or metal input/output (I/O) pad coupling to the second small receiver of one of the small input/output (SIO) circuits of the VM IC chip 258 of its bottom chip package 513 for passing second operation data, associated with (1) the data output, i.e., Dout, of one of the first type of field programmable logic cells or elements (LCEs) 2014, as illustrated in FIG. 1A, of said any of its FPGA IC chips 200 or the data output, i.e., Dout, of one of the second or third type of field programmable logic cell or elements (LCEs) 2014, as illustrated in FIGS. 1B-1C, of said any of its FPGA IC chips 200 and/or (2) output data at one of the nodes N21 and N22 of the first type of field programmable switch cells 379, as illustrated in FIG. 2A, of said any of its FPGA IC chips 200 or output data at one of the nodes N23-N26 of the second type of field programmable switch cells 379, as illustrated in FIG. 2B, of said any of its FPGA IC chips 200, from the second small driver to the second small receiver to be stored in one of the second group of the volatile memory cells of the VM IC chip 258 of its bottom chip package 513. The volatile memory (VM) IC chip 258 of its bottom chip package 513 may include the voltage-level shift-up circuit 206, as seen in FIG. 5H, for shifting the second operation data to be carried with the voltage VddH of high-voltage power supply and then the volatile memory (VM) IC chip 258 of its bottom chip package 513 may include the large input/output (LIO) circuits each having the second large driver, i.e., output buffer 274 as seen in FIG. 5H, or metal input/output (I/O) pad coupling to the third large receiver or metal input/output (I/O) pad of the second group of the large input/output (LIO) circuits of said either of the NVM IC chips 250 of its non-volatile-memory (NVM) chip package 336 for passing the second operation data from the second large driver to the third large receiver to be stored in one of the second group of non-volatile memory cells (NVMCs) of said either of the NVM IC chips 250 of its non-volatile-memory (NVM) chip package 336. Next, each of the first group of the large input/output (I/O) circuits of said either of the NVM IC chips 250 of its non-volatile-memory (NVM) chip package 336 may have the third large driver for passing the second operation data to a circuit external of the twenty-ninth type of FPMCP 355, such as the ball-grid-array (BGA) substrate 537.

Alternatively, referring to FIG. 36, for the twenty-ninth type of FPMCP 355, in case that its bottom chip package 513 is packaged with the computing integrated-circuit (IC) chip 220 and VM IC chip 258, for the operation mode each of the small input/output (SIO) circuits of the VM IC chip 258 of its bottom chip package 513 may have the first small driver coupling to a third small receiver or metal input/output (I/O) pad of one of small input/output (SIO) circuits of the computing integrated-circuit (IC) chip 220 of its bottom chip package 513 through one of the second group of the first type of micro-bumps, micro-pillars or micro-pads 34 of the volatile memory (VM) IC chip 258 of its bottom chip package 513, one or more of the interconnection metal layers 27 of the frontside interconnection scheme for a device (FISD) 101 of its bottom chip package 513 and one of the first type of micro-bumps, micro-pillars or micro-pads 34 of the computing integrated-circuit (IC) chip 220 of its bottom chip package 513 and for passing the first operation data from the first small driver to the third small receiver to be stored in one of volatile memory cells, such as dynamic random-access memory (DRAM) or static random-access memory (SRAM) cells, of the computing IC chip 220 of its bottom chip package 513 and to be computed by a computing circuit of the computing IC chip 220 of its bottom chip package 513. Next, third operation data resulted from the computing circuit of the computing IC chip 220 of its bottom chip package 513 may be stored in another of the volatile memory cells of the computing IC chip 220 of its bottom chip package 513 and passed from a third small driver or metal input/output (I/O) pad of one of the small input/output (SIO) circuits of the computing IC chip 220 of its bottom chip package 513 to the second small receiver of one of the small input/output (SIO) circuits of its VM IC chip 258 of its bottom chip package 513 through, in sequence, one of the first type of micro-bumps, micro-pillars or micro-pads 34 of the computing IC chip 220 of its bottom chip package 513, one or more of the interconnection metal layers 27 of the frontside interconnection scheme for a device (FISD) 101 of its bottom chip package 513 and one of the second group of the first type of micro-bumps, micro-pillars or micro-pads 34 of the volatile memory (VM) IC chip 258 of its bottom chip package 513 and for passing the third operation data from the third small driver to the second small receiver to be stored in one of the second group of the volatile memory cells of the VM IC chip 258 of its bottom chip package 513. The volatile memory (VM) IC chip 258 of its bottom chip package 513 may include the voltage-level shift-up circuit 206, as seen in FIG. 5H, for shifting the third operation data to be carried with the voltage VddH of high-voltage power supply and then the volatile memory (VM) IC chip 258 of its bottom chip package 513 may include the large input/output (LIO) circuits each having the second large driver, i.e., output buffer 274 as seen in FIG. 5H, or metal input/output (I/O) pad coupling to the third large receiver or metal input/output (I/O) pad of the second group of the large input/output (LIO) circuits of said either of the NVM IC chips 250 of its non-volatile-memory (NVM) chip package 336 for passing the third operation data from the second large driver to the third large receiver to be stored in one of the second group of non-volatile memory cells (NVMCs) of said either of the NVM IC chips 250 of its non-volatile-memory (NVM) chip package 336. Next, each of the first group of the large input/output (I/O) circuits of said either of the NVM IC chips 250 of its non-volatile-memory (NVM) chip package 336 may have the third large driver for passing the third operation data to a circuit external of the twenty-ninth type of FPMCP 355, such as the ball-grid-array (BGA) substrate 537.

### MISCELLANEOUS

Referring to FIGS. 6A, 7, 8A, 9A-9C, 10, 10A, 11, 12, 13A, 13B, 14, 15A, 15B, 16-19, 19-1 through 19-9, 20-22, 23A and 23B, for each of the first through fourth structures 301-304 for each of the first type of FPMCPs 300 for the first and second alternatives and the second through fifteenth types of FPMCPs 305-314, 314-1 through 314-8 and 315-318, each of its FPGA IC chip(s) 200, 100i or 100j may include the first type of field programmable logic cells or elements (LCEs) 2014 as illustrated in FIGS. 1A-1C, the first or second type of field programmable switch cells 379 as illustrated in FIGS. 2A and 2B and the programmable switch matrix 710 as illustrated in FIG. 2C. Its auxiliary IC chips 411 may include a buffer, i.e., driver circuits, for (1) downloading the resulting values from each of its NVM IC chip(s) 250 to the memory cells 490 of each of its FPGA IC chip(s) 200, 100i or 100j to be stored therein and (2) downloading the programmable codes from each of its NVM IC chip(s) 250 to the memory cells 362 of each of its FPGA IC chip(s) 200, 100i or 100j to be stored therein. The buffer and/or driver circuits of its auxiliary IC chips 411 may latch first data associated with the resulting values from each of its NVM IC chip(s) 250 and amplify and transmit the first data to the memory cells 490 of each of its FPGA IC chip(s) 200, 100i or 100j. The buffer and/or driver circuits of its auxiliary IC chips 411 may latch second data associated with the programming codes from each of its NVM IC chip(s) 250 and amplify and transmit the second data to the memory cells 362 of each of its FPGA IC chip(s) 200, 100i or 100j. For example, the first and/or second data from each of its NVM IC chip(s) 250 to its auxiliary IC chips 411 may have a bit-width of 1 bit in a standard of serial advanced technology attachment (SATA), and the buffer of its auxiliary IC chips 411 may latch the first and/or second data in multiple memory cells, e.g., static random-access memory (SRAM) cells, therein. Next, the buffer of its auxiliary IC chips 411 may simultaneously output and amplify the first and/or second data in parallel to the memory cells 490 and 362 of each of its FPGA IC chip(s) 200, 100i or 100j respectively with an increased bit width of the first and/or second data of equal to or more than 4, 8, 16, 32 or 64. For another example, the first and/or second data from each of its NVM IC chip(s) 250 to its auxiliary IC chips 411 may have a bit-width of 32 bits in a standard of peripheral component interconnect express (PCIe), and the buffer of its auxiliary IC chips 411 may latch the first and/or second data in multiple memory cells, e.g., static random-access memory (SRAM) cells, therein. Next, the buffer of its auxiliary IC chips 411 may simultaneously output and amplify the first and/or second data in parallel to the memory cells 490 and 362 of each of its FPGA IC chip(s) 200, 100i or 100j respectively with an increased bit width of the first and/or second data of equal to or more than 64, 128 or 256.

Referring to FIGS. 24, 25A, 25B and 25C, for each type of the sixteenth and seventeenth types of FPMCPs 319 and 320, its FPGA IC chip 200 may include the logic gate or circuit 2014 of the field programmable logic cells or elements (LCEs) as illustrated in FIGS. 1A-1C, the first or second type of field programmable switch cells 379 as illustrated in FIGS. 2A and 2B and the programmable switch matrix 710 as illustrated in FIG. 2C. The resulting values may be downloaded from each of its NVM IC chip(s) 250 to the memory cells 490 of its FPGA IC chip 200 to be stored therein, the programmable codes may be downloaded from each of its NVM IC chip(s) 250 to the memory cells 362 of its FPGA IC chip 200 to be stored therein.

Referring to FIGS. 6A, 7, 8A, 9A-9C, 10, 10A, 11, 12, 13A, 13B, 14, 15A, 15B, 16-19, 19-1 through 19-3, 20-22, 23A and 23B, for each of the first through fourth structures 301-304 for each of the first type of FPMCPs 300 for the first and second alternatives and the second through fifteenth types of FPMCPs 305-314, 314-1, 314-2 and 315-318, its auxiliary IC chips 411 may include multiple small input/output (I/O) circuits each coupling to one of multiple small input/output (I/O) circuits of one of its FPGA IC chip(s) 200, 100i or 100j, wherein each of the small input/output (I/O) circuits of each of its auxiliary IC chips 411 and FPGA IC chip(s) 200, 100i or 100j may have an input/output (I/O) power efficiency smaller than 0.5 pico-Joules per bit, per switch or per voltage swing, or between 0.01 and 0.5 pico-Joules per bit, per switch or per voltage swing and/or may have an output capacitance or driving capability or loading between 0.05 pF and 2 pF, between 0.1 pF and 2 pF, between 0.05 pF and 1 pF or between 0.1 pF and 1 pF, or smaller than 2 pF, 1 pF or 0.5 pF with a power supply voltage (Vdd) equal to or lower than 1.2 volts, 1 volt, 0.8 volts or 0.5 volts and/or a voltage swing equal to or smaller than 1.2 volts, 1 volt, 0.8 volts or 0.5 volts, for example. Further, its auxiliary IC chips 411 may include multiple large I/O circuits each coupling to the circuits external of said each type of the first through tenth types of chip packages 301-310 or to one of multiple large I/O circuits of any of its NVM IC chip(s) 250, wherein each of the large input/output (I/O) circuits of each of its auxiliary IC chips 411 and NVM IC chip(s) 250 may have an input/output (I/O) power efficiency greater than 3, 5 or 10 pico-Joules per bit, per switch or per voltage swing and/or may have an output capacitance or driving capability or loading between 2 pF and 100 pF, between 2 pF and 50 pF, between 2 pF and 30 pF, between 2 pF and 20 pF, between 2 pF and 15 pF, between 2 pF and 10 pF, or between 2 pF and 5 pF, or greater than 1 pF, 2 pF, 5 pF, 10 pF, 15 pF or 20 pF with a power supply voltage (Vdd) equal to or higher than 0.7 volts, 1 volt, 1.2 volts, 1.5 volts or 2 volts and/or a voltage swing equal to or greater than 0.7 volts, 1 volt, 1.2 volts, 1.5 volts or 2 volts, for example. A voltage (Vcc) of power supply supplied for each of the large I/O circuits of each of its auxiliary IC chips 411 and NVM IC chip(s) 250 may be greater than that supplied for each of the small I/O circuits 203 of each of its auxiliary IC chips 411 and FPGA IC chip(s) 200, 100i or 100j, wherein the voltage (Vcc) of power supply supplied for each of the small I/O circuits 203 of its auxiliary IC chips 411 may be the same as that supplied for each of the small I/O circuits 203 of each of its FPGA IC chip(s) 200, 100i or 100j. Further, gate oxide of each of the large I/O circuits 341 of its auxiliary IC chips 411 may have a greater thickness than that of each of the small I/O circuits 203 of its auxiliary IC chips 411.

Alternatively, referring to FIGS. 6A, 6B, 7, 8A, 8B, 9A-9D, 10, 10A, 11, 12, 13A, 13B, 13F, 13G, 14, 15A, 15B, 16-19, 19-1 through 19-9, 20-22, 23A, 23B, 24, 25A, 25B, 25C and 26-35, for each of the first, third and fourth structures 301, 303 and 304 for each of the first type of FPMCPs 300 for the first through fourth alternatives, the second structure 302 for the first type of FPMCPs 300 for the first and second alternatives and the second through twenty-eighth types of FPMCPs 305-314, 314-1 through 314-8, 315-330 and 351, besides the logic gate or circuit 2014 of the field programmable logic cells or elements (LCEs) as illustrated in FIGS. 1A-1C, the field programmable switch cell 379 as illustrated in FIGS. 2A and 2B and the programmable switch matrix 710 as illustrated in FIG. 2C, each of its FPGA IC chip(s) 200, 100h, 100i, 100j, 100k or 601 may further include multiple central-processing-unit (CPU) cores, graphic-processing-unit (GPU) cores, data-processing-unit (DPU) cores, application-processing-unit (APU) cores, intellectual property (IP) cores, digital-signal-processing (DSP) slices, floating-point calculators, machine-learning-processing (MILP) circuits, phase locked loop (PLL) circuits and digital clock manager (DCM) circuits, each coupling to the logic gate or circuit 2014 of the field programmable logic cells or elements (LCEs) of said each of its FPGA IC chip(s) 200, 100h, 100i, 100j, 100k or 601, the field programmable switch cell 379 of said each of its FPGA IC chip(s) 200, 100h, 100i, 100j, 100k or 601 and/or the programmable switch matrix 710 of said each of its FPGA IC chip(s) 200, 100h, 100i, 100j, 100k or 601.

Alternatively, referring to FIGS. 6A, 6B, 7, 8A, 8B, 9A-9D, 10, 10A, 11, 12, 13A, 13B, 13E, 13F, 14, 15A, 15B, 16-19, 19-1 through 19-9, 20-22, 23A, 23B, 24, 25A, 25B, 25C and 26-35, for each of the first, third and fourth structures 301, 303 and 304 for each of the first type of FPMCPs 300 for the first through fourth alternatives, the second structure 302 for the first type of FPMCPs 300 for the first and second alternatives and the second through twenty-eighth types of FPMCPs 305-314, 314-1 through 314-8, 315-330 and 351, each of its FPGA IC chip(s) 200, 100h, 100i, 100j, 100k or 601 may be replaced with a central-processing-unit (CPU) IC chip, graphic-processing-unit (GPU) IC chip, data-processing-unit (DPU) IC chip, application-processing-unit (APU) IC chip, a tensor-flow-processing-unit (TPU) IC chip, micro-control-unit (MCU) IC chip, artificial-intelligent-unit (AIU) IC chip, machine-learning-unit (MLU) IC chip, or digital-signal-processing (DSP) IC chip.

Further, referring to FIGS. 6A, 6B, 7, 8A, 8B, 9A-9D, 10, 10A, 11, 12, 13A, 13B, 14, 15A, 15B, 16-19, 19-1 through 19-9, 20-22, 23A, 23B, 24, 25A, 25B and 25C, for each of the first through fourth structures 301-304 for each of the first type of FPMCPs 300 for the first and second alternatives and the second through seventeenth types of FPMCPs 305-314, 314-1 through 314-8 and 315-320, each of its NVM IC chip(s) 250 may be a NAND or NOR flash IC chip, magnetoresistive-random-access-memory (MRAM) IC chip, resistive-random-access-memory (RRAM) IC chip or ferroelectric-random-access-memory (FRAM) IC chip.

Further, referring to FIGS. 6A, 6B, 7, 8A, 8B, 9A-9D, 10, 10A, 11, 12, 13A, 13B, 14, 15A, 15B, 16-19, 19-1 through 19-3, 20-22, 23A and 23B, for each of the first, third and fourth structures 301, 303 and 304 for each of the first type of FPMCPs 300 for the first through fourth alternatives, the second structure 302 for the first type of FPMCPs 300 for the first and second alternatives and the second through fifteenth types of FPMCPs 305-314, 314-1, 314-2 and 315-318, each of its FPGA IC chip(s) 200, 100i, 100j or 601 may be fabricated by an advanced technology node or generation, and its auxiliary IC chips 411 or 603 may be fabricated by a technology node more mature or less advanced than each of its FPGA IC chip(s) 200, 100i, 100j or 601. For example, each of its FPGA IC chip(s) 200, 100i, 100j or 601 may be fabricated by a technology node more advanced than 20 nm or 10 nm, while its auxiliary IC chips 411 or 603 may be fabricated by a technology node less advanced than 20 nm or 30 nm, and each of its FPGA IC chip(s) 200, 100i, 100j or 603 may be fabricated by fin field effective transistors (FINFETs) or gate-all-around field effective transistors (GAAFETs) while its auxiliary IC chips 411 may be fabricated by planar metal-oxide-semiconductor field effective transistors (MOSFETs).

Further, referring to FIGS. 13F, 13G, 24, 25A, 25B, 25C and 26-35, for each of the sixteenth through twenty-eighth types of FPMCPs 319-330 and 351, each of its FPGA IC chips 200, 100h or 100k may be fabricated by an advanced technology node or generation more advanced than 20 nm or 10 nm and with fin field effective transistors (FINFETs) or gate-all-around field effective transistors (GAAFETs).

Further, throughout the specification, the central-processing-unit (CPU) IC chip means that an IC chip includes one or more central processing units; the digital signal processor (DSP) IC chip means that an IC chip includes one or more digital signal processors; the graphic processing unit (GPU) IC chip means that an IC chip includes one or more graphic processing units; the data processing unit (DPU) IC chip means that an IC chip includes one or more data processing units; the tensor flow processing unit (TPU) IC chip means that an IC chip includes one or more tensor flow processing units; the micro-control unit (MCU) IC chip means that an IC chip includes one or more micro-control units; the artificial intelligent unit (AIU) IC chip means that an IC chip includes one or more artificial intelligent units; the machine learning unit (MLU) IC chip means that an IC chip includes one or more machine learning units; the application-specific integrated-circuit (ASIC) chip means that an IC chip includes one or more application-specific circuits.

The components, steps, features, benefits and advantages that have been discussed are merely illustrative. None of them, nor the discussions relating to them, are intended to limit the scope of protection in any way. Numerous other embodiments are also contemplated. These include embodiments that have fewer, additional, and/or different components, steps, features, benefits and advantages. These also include embodiments in which the components and/or steps are arranged and/or ordered differently.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain. Furthermore, unless stated otherwise, the numerical ranges provided are intended to be inclusive of the stated lower and upper values. Moreover, unless stated otherwise, all material selections and numerical values are representative of preferred embodiments and other ranges and/or materials may be used.

The scope of protection is limited solely by the claims, and such scope is intended and should be interpreted to be as broad as is consistent with the ordinary meaning of the language that is used in the claims when interpreted in light of this specification and the prosecution history that follows, and to encompass all structural and functional equivalents thereof.

What is claimed is:

1. A multi-chip package comprising:
a first semiconductor integrated-circuit (IC) chip;
a second semiconductor integrated-circuit (IC) chip at a same first horizontal level as the first semiconductor integrated-circuit (IC) chip;
a third semiconductor integrated-circuit (IC) chip at the same first horizontal level as the first and second semiconductor integrated-circuit (IC) chips;
a first sealing layer at the same first horizontal level as the first, second and third semiconductor integrated-circuit (IC) chips, wherein the first sealing layer has a first portion between and in contact with the first and second semiconductor integrated-circuit (IC) chips and a second portion between and in contact with the second and third semiconductor integrated-circuit (IC) chips;
a first silicon-oxide-containing layer over the first semiconductor integrated-circuit (IC) chip;
a first bonding pad over the first semiconductor integrated-circuit (IC) chip and in a first opening in the first silicon-oxide-containing layer, wherein the first bonding pad comprises a first copper layer in the first opening and a first adhesion metal layer at a sidewall and a bottom of the first copper layer;
a first interconnection bridge over the first and second semiconductor integrated-circuit (IC) chips and the first portion of the first sealing layer and across an edge of each of the first and second semiconductor integrated-circuit (IC) chips, wherein the first semiconductor integrated-circuit (IC) chip couples to the second semiconductor integrated-circuit (IC) chip through the first interconnection bride;
a second interconnection bridge at a same second horizontal level as the first interconnection bridge, over the second and third semiconductor integrated-circuit (IC) chips and the second portion of the first sealing layer and across an edge of each of the second and third semiconductor integrated-circuit (IC) chips, wherein the second semiconductor integrated-circuit (IC) chip couples to the third semiconductor integrated-circuit (IC) chip through the second interconnection bride;
a second sealing layer at the same second horizontal level as the first and second interconnection bridges and over the first, second and third semiconductor integrated-circuit (IC) chips and first sealing layer;
a second silicon-oxide-containing layer under the first interconnection bridge and bonded to the first silicon-oxide-containing layer; and
a second bonding pad under the first interconnection bridge and in a second opening in the second silicon-oxide-containing layer, wherein the second bonding pad comprises a second copper layer in the second opening and a second adhesion metal layer at a sidewall and a top of the second copper layer, wherein the second copper layer has a bottom surface bonded to and in contact with a top surface of the first copper layer.

2. The multi-chip package of claim 1 further comprising an interconnection scheme over the first and second interconnection bridges and second sealing layer.

3. The multi-chip package of claim 2 further comprising a metal via at the same second horizontal level as the first and second interconnection bridges and second sealing layer and vertically over the first semiconductor integrated-circuit (IC) chip, wherein the metal via couples the interconnection scheme to the first semiconductor integrated-circuit (IC) chip.

4. The multi-chip package of claim 2 further comprising a metal via at the same second horizontal level as the first and second interconnection bridges and second sealing layer and vertically over the second semiconductor integrated-circuit (IC) chip, wherein the metal via couples the interconnection scheme to the second semiconductor integrated-circuit (IC) chip.

5. The multi-chip package of claim 2, wherein the first interconnection bridge comprises a silicon substrate and a through silicon via vertically in the silicon substrate and coupling to the interconnection scheme.

6. The multi-chip package of claim 5 further comprising a metal via at the same second horizontal level as the first and second interconnection bridges and second sealing layer and vertically over the first semiconductor integrated-circuit (IC) chip, wherein the through silicon via couples to the first semiconductor integrated-circuit (IC) chip through, in sequence, the interconnection scheme and metal via.

7. The multi-chip package of claim 1, wherein the first silicon-oxide-containing layer is further over the second and third semiconductor integrated-circuit (IC) chip and first sealing layer and the second silicon-oxide-containing layer is further under the second interconnection bridge and second sealing layer.

8. The multi-chip package of claim 1, wherein each of the first and second sealing layers is a molding compound.

9. The multi-chip package of claim 1, wherein the first sealing layer has an outer sidewall coplanar, in a vertical direction, with an outer sidewall of the second sealing layer.

10. The multi-chip package of claim 1, wherein the second semiconductor integrated-circuit (IC) chip comprises a graphic processing unit (GPU).

11. A multi-chip package comprising:
a first semiconductor integrated-circuit (IC) chip;
a second semiconductor integrated-circuit (IC) chip at a same first horizontal level as the first semiconductor integrated-circuit (IC) chip;
a third semiconductor integrated-circuit (IC) chip at the same first horizontal level as the first and second semiconductor integrated-circuit (IC) chips;
a fourth semiconductor integrated-circuit (IC) chip at the same first horizontal level as the first, second and third semiconductor integrated-circuit (IC) chips;
a first sealing layer at the same first horizontal level as the first, second, third and fourth semiconductor integrated-circuit (IC) chips, wherein the first sealing layer has a first portion between and in contact with the first and second semiconductor integrated-circuit (IC) chips and a second portion between and in contact with the third and fourth semiconductor integrated-circuit (IC) chips;
a first silicon-oxide-containing layer over the first semiconductor integrated-circuit (IC) chip;
a first bonding pad over the first semiconductor integrated-circuit (IC) chip and in a first opening in the first silicon-oxide-containing layer, wherein the first bonding pad comprises a first copper layer in the first opening and a first adhesion metal layer at a sidewall and a bottom of the first copper layer;
a first interconnection bridge over the first and second semiconductor integrated-circuit (IC) chips and the first portion of the first sealing layer and across an edge of each of the first and second semiconductor integrated-circuit (IC) chips, wherein the first semiconductor integrated-circuit (IC) chip couples to the second semiconductor integrated-circuit (IC) chip through the first interconnection bride;
a second interconnection bridge at a same second horizontal level as the first interconnection bridge, over the third and fourth semiconductor integrated-circuit (IC) chips and the second portion of the first sealing layer and across an edge of each of the third and fourth semiconductor integrated-circuit (IC) chips, wherein the third semiconductor integrated-circuit (IC) chip couples to the fourth semiconductor integrated-circuit (IC) chip through the second interconnection bride;
a second sealing layer at the same second horizontal level as the first and second interconnection bridges and over the first, second, third and third semiconductor integrated-circuit (IC) chips and first sealing layer;
a second silicon-oxide-containing layer under the first interconnection bridge and bonded to the first silicon-oxide-containing layer; and
a second bonding pad under the first interconnection bridge and in a second opening in the second silicon-oxide-containing layer, wherein the second bonding pad comprises a second copper layer in the second opening and a second adhesion metal layer at a sidewall and a top of the second copper layer, wherein the second copper layer has a bottom surface bonded to and in contact with a top surface of the first copper layer.

12. The multi-chip package of claim 11 further comprising an interconnection scheme over the first and second interconnection bridges and second sealing layer.

13. The multi-chip package of claim 12 further comprising a metal via at the same second horizontal level as the first and second interconnection bridges and second sealing layer and vertically over the first semiconductor integrated-circuit (IC) chip, wherein the metal via couples the interconnection scheme to the first semiconductor integrated-circuit (IC) chip.

14. The multi-chip package of claim 12 further comprising a metal via at the same second horizontal level as the first and second interconnection bridges and second sealing layer and vertically over the second semiconductor integrated-circuit (IC) chip, wherein the metal via couples the interconnection scheme to the second semiconductor integrated-circuit (IC) chip.

15. The multi-chip package of claim 12, wherein the first interconnection bridge comprises a silicon substrate and a through silicon via vertically in the silicon substrate and coupling to the interconnection scheme.

16. The multi-chip package of claim 15 further comprising a metal via at the same second horizontal level as the first and second interconnection bridges and second sealing layer and vertically over the first semiconductor integrated-circuit (IC) chip, wherein the through silicon via couples to the first semiconductor integrated-circuit (IC) chip through, in sequence, the interconnection scheme and metal via.

17. The multi-chip package of claim 11, wherein the first silicon-oxide-containing layer is further over the second and third semiconductor integrated-circuit (IC) chip and first sealing layer and the second silicon-oxide-containing layer is further under the second interconnection bridge and second sealing layer.

18. The multi-chip package of claim 11, wherein each of the first and second sealing layers is a molding compound.

19. The multi-chip package of claim 11, wherein the first sealing layer has an outer sidewall coplanar, in a vertical direction, with an outer sidewall of the second sealing layer.

20. The multi-chip package of claim 1, wherein the second semiconductor integrated-circuit (IC) chip comprises a graphic processing unit (GPU) and the first semiconductor integrated-circuit (IC) chip is a memory chip.
